(19) United States
(12) Patent Application Publication
(10) Pub. No.: US 2025/0120304 A1
(43) Pub. Date: Apr. 10, 2025

(54) ORGANIC LIGHT EMITTING DEVICE

(71) Applicant: LG CHEM, LTD., Seoul (KR)

(72) Inventors: Kyunghee KIM, Daejeon (KR); Moung Gon KIM, Daejeon (KR); Yonghan LEE, Daejeon (KR); Woochul LEE, Daejeon (KR); Yongbum CHA, Daejeon (KR); Sunghyun HWANG, Daejeon (KR)

(21) Appl. No.: 18/899,067

(22) Filed: Sep. 27, 2024

(30) Foreign Application Priority Data
Oct. 6, 2023 (KR) 10-2023-0133469

(51) Int. Cl. H10K 85/40; C09K 11/02; C09K 11/06; H10K 50/12; H10K 85/30; H10K 85/60

(52) U.S. Cl. CPC H10K 85/40; C09K 11/02; C09K 11/06; H10K 85/346; H10K 85/658; C09K 2211/1007; C09K 2211/1014; C09K 2211/1022; C09K 2211/1029; C09K 2211/1044; C09K 2211/185; H10K 50/12

(57) ABSTRACT

An organic light emitting device including: an anode; a cathode; and an organic material layer having one or more layers provided between the anode and the cathode, in which one or more layers of the organic material layer include a compound of Chemical Formula 1 and a compound of Chemical Formula 2:

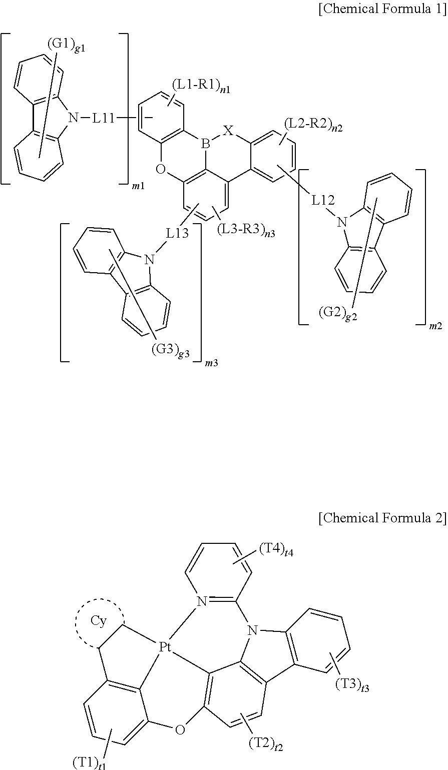

where the substituents are as defined in the specification.

### CROSS-REFERENCE TO RELATED APPLICATIONS

This application claims priority to and the benefit of Korean Patent Application No. 10-2023-0133469 filed in the Korean Intellectual Property Office on Oct. 6, 2023, the entire contents of which are incorporated herein by reference.

### TECHNICAL FIELD

The present specification relates to an organic light emitting device.

### BACKGROUND ART

An organic light emission phenomenon generally refers to a phenomenon converting electrical energy to light energy using an organic material. An organic light emitting device using an organic light emission phenomenon normally has a structure including a positive electrode, a negative electrode, and an organic material layer therebetween. Here, the organic material layer has in many cases a multi-layered structure composed of different materials in order to improve the efficiency and stability of the organic light emitting device, and for example, may be composed of a hole injection layer, a hole transport layer, a light emitting layer, an electron transport layer, an electron injection layer, and the like. In such a structure of the organic light emitting device, if a voltage is applied between the two electrodes, holes are injected from the positive electrode into the organic material layer and electrons are injected from the negative electrode into the organic material layer, and when the injected holes and electrons meet each other, an exciton is formed, and light is emitted when the exciton falls down again to a ground state.

There is a continuous need for developing a new material for the aforementioned organic light emitting device.

### RELATED ART DOCUMENTS

### Patent Documents

(Patent Document 1) Japanese Patent Application Laid-Open No. 2021-095342 A

### SUMMARY OF THE INVENTION

The present invention has been made in an effort to provide an organic light emitting device having a low driving voltage, a high efficiency, and/or a long service life.

An exemplary embodiment of the present specification provides an organic light emitting device including: an anode; a cathode; and an organic material layer having one or more layers provided between the anode and the cathode, in which one or more layers of the organic material layer include a compound represented by the following Chemical Formula 1 and a compound represented by the following Chemical Formula 2.

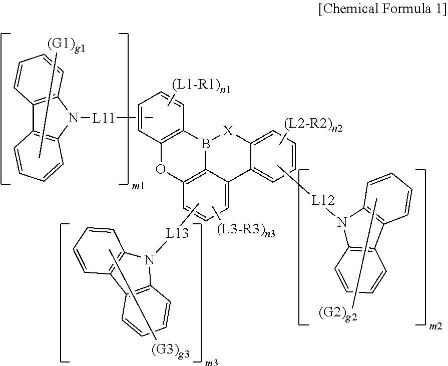

In Chemical Formula 1,
X is NR; O; or S,
at least one of R and R1 to R3 is a substituted or unsubstituted silyl group; a substituted or unsubstituted aryl group; or a substituted or unsubstituted heterocyclic group, and the other are the same as or different from each other, and are each independently hydrogen; deuterium; a halogen group; a nitrile group; a substituted or unsubstituted alkyl group; or a substituted or unsubstituted cycloalkyl group,
L1 to L3 and L11 to L13 are the same as or different from each other, and are each independently a direct bond; a substituted or unsubstituted arylene group; or a substituted or unsubstituted divalent heterocyclic group,
G1 to G3 are the same as or different from each other, and are each independently hydrogen; deuterium; a halogen group; a nitrile group; a substituted or unsubstituted silyl group; a substituted or unsubstituted alkyl group; a substituted or unsubstituted cycloalkyl group; a substituted or unsubstituted aryl group; or a substituted or unsubstituted heterocyclic group,
n1 and n2 are each an integer from 1 to 4, and m1 and m2 are each an integer from 0 to 4,
n3 is an integer from 1 to 3, and m3 is an integer from 0 to 3,
g1 to g3 are each an integer from 0 to 8,
when n1 to n3, m1 to m3 and g1 to g3 are each 2 or higher, substituents in the parenthesis are the same as or different from each other,
n1+m1 is 4 or less, n2+m2 is 4 or less, and n3+m3 is 3 or less,
m1+m2+m3 is an integer of 1 or higher,

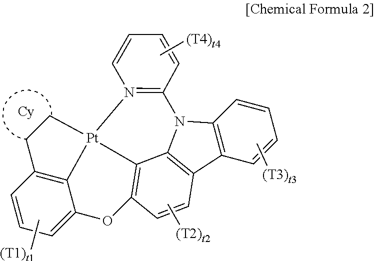

in Chemical Formula 2,
Cy is a substituted or unsubstituted N-containing monocyclic ring,
T1 to T4 are the same as or different from each other, and are each independently hydrogen; deuterium; a halogen group; a nitrile group; a substituted or unsubstituted silyl group; a substituted or unsubstituted alkyl group; a substituted or unsubstituted cycloalkyl group; a substituted or unsubstituted aryl group; or a substituted or unsubstituted heterocyclic group, or are bonded to an adjacent group to form a substituted or unsubstituted ring,
t1 and t4 are each an integer from 0 to 3,
t2 is an integer from 0 to 2,
t3 is an integer from 0 to 4,
when t1, t3, and t4 are each 2 or higher, substituents in the parenthesis are the same as or different from each other, and
when t2 is 2, substituents in the parenthesis are the same as or different from each other.

The organic light emitting device according to an exemplary embodiment of the present invention has effects of low driving voltage, high efficiency and/or long service life by including a compound represented by Chemical Formula 1 and a compound represented by Chemical Formula 2.

### BRIEF DESCRIPTION OF THE DRAWINGS

FIG. 1 illustrates an example of an organic light emitting device in which a substrate 1, an anode 2, a light emitting layer 6, and a cathode 10 are sequentially stacked.

FIG. 2 illustrates an example of an organic light emitting device in which a substrate 1, an anode 2, a hole injection layer 3, a hole transport layer 4, an electron blocking layer 5, a light emitting layer 6, a hole blocking layer 7, an electron transport layer 8, an electron injection layer 9, and a cathode 10 are sequentially stacked.

FIG. 3 illustrates an example of an organic light emitting device in which a substrate 1, an anode 2, a hole injection layer 3, a hole transport layer 4, an electron blocking layer 5, a light emitting layer 6, a hole blocking layer 7, an electron transport and injection layer 11, and a cathode 10 are sequentially stacked.

### DETAILED DESCRIPTION

Hereinafter, the present specification will be described in more detail.

When one part “includes” one constituent element in the present specification, unless otherwise specifically described, this does not mean that another constituent element is excluded, but means that another constituent element may be further included.

When one member is disposed “on” another member in the present specification, this includes not only a case where the one member is brought into contact with another member, but also a case where still another member is present between the two members.

In the present specification,

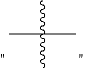

or a dotted line means a position bonded to a chemical formula or a compound.

In the present specification, N % substitution with deuterium means that N % of hydrogen available in the corresponding structure is substituted with deuterium. For example, 25% substitution of dibenzofuran with deuterium means that two of eight hydrogens of dibenzofuran are substituted with deuteriums.

In the present specification, the degree of deuteration may be confirmed by a publicly-known method such as nuclear magnetic resonance spectroscopy (1H NMR) or GC/MS.

Examples of the substituents in the present specification will be described below, but are not limited thereto.

The term “substitution” means that a hydrogen atom bonded to a carbon atom of a compound is changed into another substituent, and a position to be substituted is not limited as long as the position is a position at which the hydrogen atom is substituted, that is, a position at which the substituent may be substituted, and when two or more are substituted, the two or more substituents may be the same as or different from each other.

In the present specification, the term “substituted or unsubstituted” means being substituted with one or two or more substituents selected from the group consisting of deuterium; a halogen group; a nitrile group (—CN); a nitro group; a hydroxyl group; an alkyl group; a cycloalkyl group; an alkoxy group; a phosphine oxide group; an aryloxy group; an alkylthioxy group; an arylthioxy group; an alkylsulfoxy group; an arylsulfoxy group; an alkenyl group; a silyl group; a boron group; an amine group; an aryl group; or a heterocyclic group, being substituted with a substituent to which two or more substituents among the exemplified substituents are linked, or having no substituent. For example, “the substituent to which two or more substituents are linked” may be a biphenyl group. That is, the biphenyl group may also be an aryl group, and may be interpreted as a substituent to which two phenyl groups are linked.

In the present specification, the term “substituted or unsubstituted” means being substituted with one or two or more substituents selected from the group consisting of deuterium; a halogen group; a nitrile group; a nitro group; a hydroxyl group; an amino group; a silyl group; a boron group; an alkoxy group; an aryloxy group; an alkyl group; a cycloalkyl group; an aryl group; and a heterocyclic group, being substituted with a substituent to which two or more substituents among the above-exemplified substituents are linked, or having no substituent.

In the present specification, the term “substituted or unsubstituted” means being substituted with one or two or more substituents selected from the group consisting of deuterium; an alkyl group; an aryl group; and a heterocyclic group, being substituted with a substituent to which two or more substituents among the exemplified substituents are linked, or having no substituent.

Examples of the substituents will be described below; however, the substituents are not limited thereto.

In the present specification, examples of a halogen group include fluorine (—F), chlorine (—Cl), bromine (—Br) or iodine (—I).

In the present specification, a silyl group may be represented by a chemical formula of —SiYₐY_{b}Y_{c}, and the Yₐ, Y_{b}, and Y_{c} may be each hydrogen; a substituted or unsubstituted alkyl group; or a substituted or unsubstituted aryl group. Specific examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and the like, but are not limited thereto.

In the present specification, a boron group may be represented by a chemical formula of —BY_{d}Yₑ, and the Y_{d} and Yₑ may be each hydrogen; a substituted or unsubstituted alkyl group; or a substituted or unsubstituted aryl group. Specific examples of the boron group include a trimethylboron group, a triethylboron group, a t-butyl-dimethylboron group, a triphenylboron group, a phenylboron group, and the like, but are not limited thereto.

In the present specification, the alkyl group may be straight-chained or branched, and the number of carbon atoms thereof is not particularly limited, but is preferably 1 to 60. According to an exemplary embodiment, the number of carbon atoms of the alkyl group is 1 to 30. According to another exemplary embodiment, the number of carbon atoms of the alkyl group is 1 to 20. According to still another exemplary embodiment, the number of carbon atoms of the alkyl group is 1 to 10. Specific examples of the alkyl group include a methyl group, an ethyl group, a propyl group, an n-propyl group, an isopropyl group, a butyl group, an n-butyl group, an isobutyl group, a tert-butyl group, a pentyl group, an n-pentyl group, a hexyl group, an n-hexyl group, a heptyl group, an n-heptyl group, an octyl group, an n-octyl group, and the like, but are not limited thereto.

In the present specification, the above-described description on the alkyl group may be applied to an arylalkyl group, except that the arylalkyl group is substituted with an aryl group.

In the present specification, the alkoxy group may be straight-chained, branched, or cyclic. The number of carbon atoms of the alkoxy group is not particularly limited, but is preferably 1 to 20. Specific examples thereof include methoxy, ethoxy, n-propoxy, isopropoxy, n-butoxy, isobutoxy, tert-butoxy, sec-butoxy, n-pentyloxy, neopentyloxy, isopentyloxy, n-hexyloxy, 3,3-dimethylbutyloxy, 2-ethylbutyloxy, n-octyloxy, n-nonyloxy, n-decyloxy, and the like, but are not limited thereto.

Substituents including an alkyl group, an alkoxy group, and other alkyl group moieties described in the present specification include both a straight-chained form and a branched form.

In the present specification, an alkenyl group may be straight-chained or branched, and the number of carbon atoms thereof is not particularly limited, but is preferably 2 to 40. According to an exemplary embodiment, the number of carbon atoms of the alkenyl group is 2 to 20. According to another exemplary embodiment, the number of carbon atoms of the alkenyl group is 2 to 10. According to still another exemplary embodiment, the number of carbon atoms of the alkenyl group is 2 to 6. Specific examples thereof include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a styrenyl group, and the like, but are not limited thereto.

In the present specification, the alkynyl group may be straight-chained or branched as a substituent including a triple bond between a carbon atom and a carbon atom, and the number of carbon atoms thereof is not particularly limited, but is preferably 2 to 40. According to an exemplary embodiment, the number of carbon atoms of the alkynyl group is 2 to 20. According to another exemplary embodiment, the number of carbon atoms of the alkynyl group is 2 to 10.

In the present specification, a cycloalkyl group is not particularly limited, but has preferably 3 to 60 carbon atoms, and according to an exemplary embodiment, the number of carbon atoms of the cycloalkyl group is 3 to 30. According to another exemplary embodiment, the number of carbon atoms of the cycloalkyl group is 3 to 20. According to another embodiment, the number of carbon atoms of the cycloalkyl group is from 3 to 6. Specific examples thereof may include a cyclopropyl group, a cyclobutyl group, a cyclopentyl group, a cyclohexyl group, a cycloheptyl group, a cyclooctyl group and the like, but are not limited thereto.

In the present specification, an amine group is —NH₂, and the amine group may be substituted with the above-described alkyl group, aryl group, heterocyclic group, alkenyl group, cycloalkyl group, a combination thereof, and the like. The number of carbon atoms of the substituted amine group is not particularly limited, but is preferably 1 to 30. According to an exemplary embodiment, the number of carbon atoms of the amine group is 1 to 20. According to an exemplary embodiment, the number of carbon atoms of the amine group is 1 to 10. Specific examples of the substituted amine group include a methylamine group, a dimethylamine group, an ethylamine group, a diethylamine group, a phenylamine group, a 9,9-dimethylfluorenylphenylamine group, a pyridylphenylamine group, a diphenylamine group, a phenylpyridylamine group, a naphthylamine group, a biphenylamine group, an anthracenylamine group, a dibenzofuranylphenylamine group, a 9-methylanthracenylamine group, a diphenylamine group, a phenylnaphthylamine group, a ditolylamine group, a phenyltolylamine group, a diphenylamine group, and the like, but are not limited thereto.

In the present specification, an aryl group is not particularly limited, but has preferably 6 to 60 carbon atoms. According to an exemplary embodiment, the number of carbon atoms of the aryl group is from 6 to 30. According to an exemplary embodiment, the number of carbon atoms of the aryl group is from 6 to 20. The aryl group may be an aryl group composed of a single ring or a polycyclic aryl group (a bicyclic or more aryl group). The aryl group composed of the single ring may also be represented by a monocyclic aryl group, and may mean a phenyl group; or a group to which two or more phenyl groups are linked. Examples of the aryl group composed of the sing ring include a phenyl group, a biphenyl group, a terphenyl group, a quaterphenyl group, and the like, but are not limited thereto. The polycyclic aryl group may mean a group in which two or more monocyclic rings such as a naphthyl group and a phenanthrenyl group are fused. Examples of the polycyclic aryl group include a naphthyl group, an anthracenyl group, a phenanthrenyl group, a pyrenyl group, a perylenyl group, a chrysenyl group, a fluorenyl group, a triphenylenyl group, and the like, but are not limited thereto.

In the present specification, a fluorenyl group may be substituted, and two substituents may be bonded to each other to form a spiro structure. In this case, the spiro structure may be an aromatic hydrocarbon ring or an aliphatic hydrocarbon ring.

When the fluorneyl group is substituted, the substituent may be a spirofluorenyl group

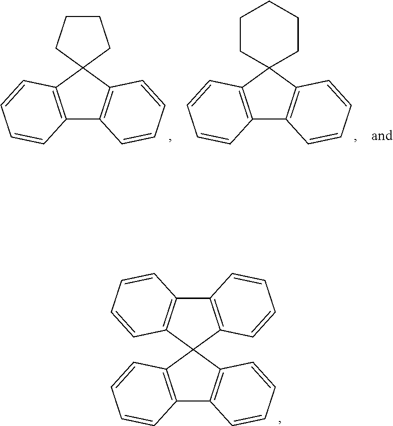

and, and a substituted fluorenyl group such as

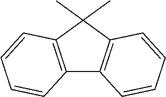

(a 9,9-dimethylfluorenyl group), and

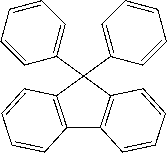 [SMILES: c1ccc(C2(c3ccccc3)c3ccccc3-c3ccccc32)cc1]

(a 9,9-diphenylfluorenyl group). However, the substituent is not limited thereto.

In the present specification, the above-described description on the aryl group may be applied to an aryl group in an aryloxy group.

In the present specification, the above-described description on the alkyl group may be applied to an alkyl group in the alkylthioxy group and the alkylsulfoxy group.

In the present specification, the above-described description on the aryl group may be applied to an aryl group in the arylthioxy group and the arylsulfoxy group.

In the present specification, a heterocyclic group is a cyclic group including one or more of N, 0, P, S, Si, and Se as a heteroatom, and the number of carbon atoms thereof is not particularly limited, but is preferably 2 to 60. According to one embodiment, the number of carbon atoms of the heterocyclic group is from 2 to 30. According to one embodiment, the number of carbon atoms of the heterocyclic group is from 2 to 20. Examples of the heterocyclic group include a pyridine group, a pyrrole group, a pyrimidine group, a quinoline group, a pyridazinyl group, a furan group, a thiophene group, an imidazole group, a pyrazole group, a dibenzofuran group, a dibenzothiophene group, a carbazole group, a benzocarbazole group, a naphthobenzofuran group, a benzonaphthothiophene group, an indenocarbazole group, a triazinyl group, and the like, but are not limited thereto.

In the present specification, the above-described description on the heterocyclic group may be applied to a heteroaryl group except for an aromatic heteroaryl group.

In the present specification, the description on the aryl group may be applied to an arylene group except for a divalent arylene group.

In the present specification, the description on the heterocyclic group may be applied to a divalent heterocyclic group except for a divalent heterocyclic group.

In the present specification, in a substituted or unsubstituted ring formed by being bonded to an adjacent group, the “ring” means a hydrocarbon ring; or a hetero ring.

The hydrocarbon ring may be an aromatic ring, an aliphatic ring, or a fused ring of the aromatic ring and the aliphatic ring, and may be selected from the examples of the cycloalkyl group or the aryl group.

In the present specification, being bonded to an adjacent group to form a ring means being bonded to an adjacent group to form a substituted or unsubstituted aliphatic hydrocarbon ring; a substituted or unsubstituted aromatic hydrocarbon ring; a substituted or unsubstituted aliphatic hetero ring; a substituted or unsubstituted aromatic hetero ring; or a fused ring thereof. The hydrocarbon ring means a ring composed only of carbon and hydrogen atoms. The hetero ring means a ring including one or more selected from elements such as N, O, P, S, Si and Se. In the present specification, the aliphatic hydrocarbon ring, the aromatic hydrocarbon ring, the aliphatic hetero ring, and the aromatic hetero ring may be monocyclic or polycyclic.

In the present specification, the aliphatic hydrocarbon ring means a ring composed only of carbon and hydrogen atoms as a non-aromatic ring. Examples of the aliphatic hydrocarbon ring include cyclopropane, cyclobutane, cyclobutene, cyclopentane, cyclopentene, cyclohexane, cyclohexene, 1,4-cyclohexadiene, cycloheptane, cycloheptene, cyclooctane, cyclooctene, and the like, but are not limited thereto.

In the present specification, an aromatic hydrocarbon ring means an aromatic ring composed only of carbon and hydrogen atoms. Examples of the aromatic hydrocarbon ring include benzene, naphthalene, anthracene, phenanthrene, perylene, fluoranthene, triphenylene, phenalene, pyrene, tetracene, chrysene, pentacene, fluorene, indene, acenaphthylene, benzofluorene, spirofluorene, and the like, but are not limited thereto. In the present specification, the aromatic hydrocarbon ring may be interpreted to have the same meaning as the aryl group.

In the present specification, an aliphatic hetero ring means an aliphatic ring including one or more of hetero atoms. Examples of the aliphatic hetero ring include oxirane, tetrahydrofuran, 1,4-dioxane, pyrrolidine, piperidine, morpholine, oxepane, azocane, thiocane, and the like, but are not limited thereto.

In the present specification, an aromatic hetero ring means an aromatic ring including one or more of hetero atoms. Examples of the aromatic hetero ring include pyridine, pyrrole, pyrimidine, pyridazine, furan, thiophene, imidazole, pyrazole, oxazole, isoxazole, thiazole, isothiazole, triazole, oxadiazole, thiadiazole, dithiazole, tetrazole, pyran, thiopyran, diazine, oxazine, thiazine, dioxine, triazine, tetrazine, isoquinoline, quinoline, quinone, quinazoline, quinoxaline, naphthyridine, acridine, phenanthridine, diaza naphthalene, triazaindene, indole, indolizine, benzothiazole, benzoxazole, benzoimidazole, benzothiophene, benzofuran, dibenzothiophene, dibenzofuran, carbazole, benzocarbazole, dibenzocarbazole, phenazine, imidazopyridine, phenoxazine, indolocarbazole, indenocarbazole, and the like, but are not limited thereto.

Hereinafter, preferred exemplary embodiments of the present invention will be described in detail. However, the exemplary embodiments of the present invention may be modified into various other forms, and the scope of the present invention is not limited to the exemplary embodiments which will be described below.

The organic light emitting device according to the present invention has effects of low driving voltage, high efficiency and/or long service life by including both the compound represented by Chemical Formula 1 and the compound represented by Chemical Formula 2 in a light emitting layer.

Specifically, by using the compound of Chemical Formula 1 with the compound of Chemical Formula 2, excitons produced between the compound represented by Chemical Formula 1 and a p-type host facilitate the transfer of energy to the compound represented by Chemical Formula 2 to have an effect of high efficiency and/or long service life. In particular, the compound represented by Chemical Formula 2 has a narrower full width at half maximum than when an Ir complex is used as a dopant, and thus is also effective for improving color purity. Therefore, a device using both the compound represented by Chemical Formula 1 and the compound represented by Chemical Formula 2 may have remarkably strengthened characteristics of low voltage, high efficiency and/or long service life of the device due to a synergistic effect in the organic light emitting device.

Hereinafter, Chemical Formula 1 will be described in detail.

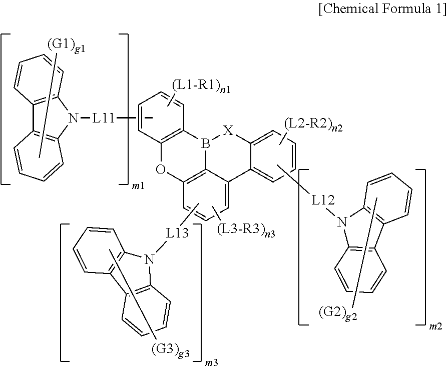

In Chemical Formula 1,
X is NR; O; or S,
at least one of R and R1 to R3 is a substituted or unsubstituted silyl group; a substituted or unsubstituted aryl group; or a substituted or unsubstituted heterocyclic group, and the other are the same as or different from each other, and are each independently hydrogen; deuterium; a halogen group; a nitrile group; a substituted or unsubstituted alkyl group; or a substituted or unsubstituted cycloalkyl group,
L1 to L3 and L11 to L13 are the same as or different from each other, and are each independently a direct bond; a substituted or unsubstituted arylene group; or a substituted or unsubstituted divalent heterocyclic group,
G1 to G3 are the same as or different from each other, and are each independently hydrogen; deuterium; a halogen group; a nitrile group; a substituted or unsubstituted silyl group; a substituted or unsubstituted alkyl group; a substituted or unsubstituted cycloalkyl group; a substituted or unsubstituted aryl group; or a substituted or unsubstituted heterocyclic group,
n1 and n2 are each an integer from 1 to 4, and m1 and m2 are each an integer from 0 to 4,
n3 is an integer from 1 to 3, and m3 is an integer from 0 to 3,
g1 to g3 are each an integer from 0 to 8,
when n1 to n3, m1 to m3 and g1 to g3 are each 2 or higher, substituents in the parenthesis are the same as or different from each other,
n1+m1 is 4 or less, n2+m2 is 4 or less, and n3+m3 is 3 or less, and
m1+m2+m3 is an integer of 1 or higher.

In an exemplary embodiment of the present specification, X is NR; O; or S.

In an exemplary embodiment of the present specification, X is NR.

In an exemplary embodiment of the present specification, X is O.

In an exemplary embodiment of the present specification, X is S.

In an exemplary embodiment of the present specification, R is hydrogen; deuterium; a halogen group; a nitrile group; a substituted or unsubstituted alkyl group; a substituted or unsubstituted cycloalkyl group; a substituted or unsubstituted aryl group; or a substituted or unsubstituted heterocyclic group.

In an exemplary embodiment of the present specification, R is a substituted or unsubstituted aryl group; or a substituted or unsubstituted heterocyclic group.

In an exemplary embodiment of the present specification, R is a substituted or unsubstituted aryl group.

In an exemplary embodiment of the present specification, R is a phenyl group or a biphenyl group.

In an exemplary embodiment of the present specification, at least one of R1 to R3 is a substituted or unsubstituted silyl group; a substituted or unsubstituted aryl group; or a substituted or unsubstituted heterocyclic group, and the other are the same as or different from each other, and are each independently hydrogen; deuterium; a halogen group; a nitrile group; a substituted or unsubstituted alkyl group; or a substituted or unsubstituted cycloalkyl group.

In an exemplary embodiment of the present specification, at least of R1 to R3 is a substituted or unsubstituted silyl group; a substituted or unsubstituted aryl group having 6 to 60 carbon atoms; or a substituted or unsubstituted heterocyclic group having 2 to 60 carbon atoms, and the others are the same as or different from each other, and are each independently hydrogen; deuterium; a halogen group; a nitrile group; a substituted or unsubstituted alkyl group having 1 to 60 carbon atoms; or a substituted or unsubstituted cycloalkyl group having 3 to 60 carbon atoms.

In an exemplary embodiment of the present specification, at least of R1 to R3 is a substituted or unsubstituted silyl group; a substituted or unsubstituted aryl group having 6 to 30 carbon atoms; or a substituted or unsubstituted heterocyclic group having 2 to 30 carbon atoms, and the others are the same as or different from each other, and are each independently hydrogen; deuterium; a halogen group; a nitrile group; a substituted or unsubstituted alkyl group having 1 to 30 carbon atoms; or a substituted or unsubstituted cycloalkyl group having 3 to 30 carbon atoms.

In an exemplary embodiment of the present specification, at least one of R1 to R3 is a substituted or unsubstituted silyl group; a substituted or unsubstituted aryl group having 6 to 20 carbon atoms; or a substituted or unsubstituted heterocyclic group having 2 to 20 carbon atoms, and the others are the same as or different from each other, and are each independently hydrogen; deuterium; a halogen group; a nitrile group; a substituted or unsubstituted alkyl group having 1 to 20 carbon atoms; or a substituted or unsubstituted cycloalkyl group having 3 to 20 carbon atoms.

In an exemplary embodiment of the present specification, at least one of R1 to R3 is a silyl group unsubstituted or substituted with deuterium, an alkyl group, or an aryl group; an aryl group unsubstituted or substituted with deuterium or an aryl group; or a heterocyclic group unsubstituted or substituted with deuterium or a heterocyclic group, and the others are the same as or different from each other, and are each independently hydrogen; or deuterium.

In an exemplary embodiment of the present specification, at least one of R1 to R3 is a silyl group unsubstituted or substituted with deuterium, an alkyl group having 1 to 60 carbon atoms, or an aryl group having 6 to 60 carbon atoms; an aryl group having 6 to 60 carbon atoms, which is unsubstituted or substituted with deuterium or an aryl group having 6 to 60 carbon atoms; or a heterocyclic group having 2 to 60 carbon atoms, which is unsubstituted or substituted with deuterium or a heterocyclic group having 2 to 60 carbon atoms, and the others are the same as or different from each other, and are each independently hydrogen; or deuterium.

In an exemplary embodiment of the present specification, at least one of R1 to R3 is a silyl group unsubstituted or substituted with deuterium, an alkyl group having 1 to 30 carbon atoms, or an aryl group having 6 to 30 carbon atoms; an aryl group having 6 to 30 carbon atoms, which is unsubstituted or substituted with deuterium or an aryl group having 6 to 30 carbon atoms; or a heterocyclic group having 2 to 30 carbon atoms, which is unsubstituted or substituted with deuterium or a heterocyclic group having 2 to 30 carbon atoms, and the others are the same as or different from each other, and are each independently hydrogen; or deuterium.

In an exemplary embodiment of the present specification, at least one of R1 to R3 is a silyl group unsubstituted or substituted with deuterium, an alkyl group having 1 to 20 carbon atoms, or an aryl group having 6 to 20 carbon atoms; an aryl group having 6 to 20 carbon atoms, which is unsubstituted or substituted with deuterium or an aryl group having 6 to 20 carbon atoms; or a heterocyclic group having 2 to 20 carbon atoms, which is unsubstituted or substituted with deuterium or a heterocyclic group having 2 to 20 carbon atoms, and the others are the same as or different from each other, and are each independently hydrogen; or deuterium.

In an exemplary embodiment of the present specification, at least one of R1 to R3 is a silyl group substituted with a phenyl group; a phenyl group; a biphenyl group; a carbazole group; a dibenzofuran group; a dibenzothiophene group; or a heterocyclic group having 2 to 60 carbon atoms, which includes one or more of N and 0 as a heteroatom, and the others are the same as or different from each other, and are each independently hydrogen; or deuterium.

In an exemplary embodiment of the present specification, at least one of R1 to R3 is a triphenylsilyl group; a phenyl group; a biphenyl group; a carbazole group; a dibenzofuran group; a dibenzothiophene group; a benzofurano dibenzofuran group; or an indolocarbazole group, and the others are the same as or different from each other, and are each independently hydrogen; or deuterium.

In an exemplary embodiment of the present specification, the benzofurano dibenzofuran group is a benzo[1,2-b:3,4-b′]bisbenzofuran group.

In an exemplary embodiment of the present specification, the indolocarbazole group is indolo[3,2,1-jk]carbazole.

In an exemplary embodiment of the present specification, at least one of R1 to R3 is a group represented by the following structural formula, or a substituted or unsubstituted aryl group.

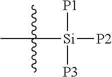

In the structural formula, P1 to P3 are a substituted or unsubstituted aryl group, and

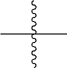

means a position bonded to L1 to L3.

In an exemplary embodiment of the present specification, P1 to P3 are a substituted or unsubstituted aryl group having 6 to 60 carbon atoms.

In an exemplary embodiment of the present specification, P1 to P3 are a substituted or unsubstituted aryl group having 6 to 30 carbon atoms.

In an exemplary embodiment of the present specification, P1 to P3 are a substituted or unsubstituted aryl group having 6 to 20 carbon atoms.

In an exemplary embodiment of the present specification, P1 to P3 are a phenyl group.

In an exemplary embodiment of the present specification, L1 to L3 are the same as or different from each other, and are each independently a direct bond; a substituted or unsubstituted arylene group; or a substituted or unsubstituted divalent heterocyclic group.

In an exemplary embodiment of the present specification, L1 to L3 are the same as or different from each other, and are each independently a direct bond; a substituted or unsubstituted arylene group having 6 to 60 carbon atoms; or a substituted or unsubstituted divalent heterocyclic group having 2 to 60 carbon atoms.

In an exemplary embodiment of the present specification, L1 to L3 are the same as or different from each other, and are each independently a direct bond; a substituted or unsubstituted arylene group having 6 to 30 carbon atoms; or a substituted or unsubstituted divalent heterocyclic group having 2 to 30 carbon atoms.

In an exemplary embodiment of the present specification, L1 to L3 are the same as or different from each other, and are each independently a direct bond; a substituted or unsubstituted arylene group having 6 to 20 carbon atoms; or a substituted or unsubstituted divalent heterocyclic group having 2 to 20 carbon atoms.

In an exemplary embodiment of the present specification, L1 to L3 are the same as or different from each other, and are each independently a direct bond; or a substituted or unsubstituted arylene group.

In an exemplary embodiment of the present specification, L1 to L3 are the same as or different from each other, and are each independently a direct bond; or an arylene group having 6 to 60 carbon atoms.

In an exemplary embodiment of the present specification, L1 to L3 are the same as or different from each other, and are each independently a direct bond; or an arylene group having 6 to 30 carbon atoms.

In an exemplary embodiment of the present specification, L1 to L3 are the same as or different from each other, and are each independently a direct bond; or an arylene group having 6 to 20 carbon atoms.

In an exemplary embodiment of the present specification, L1 to L3 are the same as or different from each other, and are each independently a direct bond; or a phenylene group.

In an exemplary embodiment of the present specification, L11 to L13 are the same as or different from each other, and are each independently a direct bond; a substituted or unsubstituted arylene group; or a substituted or unsubstituted divalent heterocyclic group.

In an exemplary embodiment of the present specification, L11 to L13 are the same as or different from each other, and are each independently a direct bond; a substituted or unsubstituted arylene group having 6 to 60 carbon atoms; or a substituted or unsubstituted divalent heterocyclic group having 2 to 60 carbon atoms.

In an exemplary embodiment of the present specification, L11 to L13 are the same as or different from each other, and are each independently a direct bond; a substituted or unsubstituted arylene group having 6 to 30 carbon atoms; or a substituted or unsubstituted divalent heterocyclic group having 2 to 30 carbon atoms.

In an exemplary embodiment of the present specification, L11 to L13 are the same as or different from each other, and are each independently a direct bond; a substituted or unsubstituted arylene group having 6 to 20 carbon atoms; or a substituted or unsubstituted divalent heterocyclic group having 2 to 20 carbon atoms.

In an exemplary embodiment of the present specification, L11 to L13 are the same as or different from each other, and are each independently a direct bond; or a substituted or unsubstituted arylene group.

In an exemplary embodiment of the present specification, L11 to L13 are the same as or different from each other, and are each independently a direct bond; or an arylene group.

In an exemplary embodiment of the present specification, L11 to L13 are the same as or different from each other, and are each independently a direct bond; or an arylene group having 6 to 60 carbon atoms.

In an exemplary embodiment of the present specification, L11 to L13 are the same as or different from each other, and are each independently a direct bond; or an arylene group having 6 to 30 carbon atoms.

In an exemplary embodiment of the present specification, L11 to L13 are the same as or different from each other, and are each independently a direct bond; or an arylene group having 6 to 20 carbon atoms.

In an exemplary embodiment of the present specification, L11 to L13 are the same as or different from each other, and are each independently a direct bond; or a phenylene group.

In an exemplary embodiment of the present specification, G1 to G3 are the same as or different from each other, and are each independently hydrogen; deuterium; a halogen group; a nitrile group; a substituted or unsubstituted silyl group; a substituted or unsubstituted alkyl group; a substituted or unsubstituted cycloalkyl group; a substituted or unsubstituted aryl group; or a substituted or unsubstituted heterocyclic group.

In an exemplary embodiment of the present specification, G1 to G3 are the same as or different from each other, and are each independently hydrogen; deuterium; a halogen group; a nitrile group; a substituted or unsubstituted silyl group; a substituted or unsubstituted alkyl group having 1 to 60 carbon atoms; a substituted or unsubstituted cycloalkyl group having 3 to 60 carbon atoms; a substituted or unsubstituted aryl group having 6 to 60 carbon atoms; or a substituted or unsubstituted heterocyclic group having 2 to 60 carbon atoms.

In an exemplary embodiment of the present specification, G1 to G3 are the same as or different from each other, and are each independently hydrogen; deuterium; a halogen group; a nitrile group; a substituted or unsubstituted silyl group; a substituted or unsubstituted alkyl group having 1 to 30 carbon atoms; a substituted or unsubstituted cycloalkyl group having 3 to 30 carbon atoms; a substituted or unsubstituted aryl group having 6 to 30 carbon atoms; or a substituted or unsubstituted heterocyclic group having 2 to 30 carbon atoms.

In an exemplary embodiment of the present specification, G1 to G3 are the same as or different from each other, and are each independently hydrogen; deuterium; a halogen group; a nitrile group; a substituted or unsubstituted silyl group; a substituted or unsubstituted alkyl group having 1 to 20 carbon atoms; a substituted or unsubstituted cycloalkyl group having 3 to 20 carbon atoms; a substituted or unsubstituted aryl group having 6 to 20 carbon atoms; or a substituted or unsubstituted heterocyclic group having 2 to 20 carbon atoms.

In an exemplary embodiment of the present specification, G1 to G3 are the same as or different from each other, and are each independently hydrogen; or deuterium.

In an exemplary embodiment of the present specification, G1 to G3 are hydrogen.

In an exemplary embodiment of the present specification, n1 and n2 are each an integer from 1 to 4, and m1 and m2 are each an integer from 0 to 4.

In an exemplary embodiment of the present specification, n3 is an integer from 1 to 3, and m3 is an integer from 0 to 3.

In an exemplary embodiment of the present specification, n1 is 1.

In an exemplary embodiment of the present specification, n2 is 1.

In an exemplary embodiment of the present specification, n3 is 1.

In an exemplary embodiment of the present specification, m1 is 0.

In an exemplary embodiment of the present specification, m1 is 1.

In an exemplary embodiment of the present specification, m2 is 0.

In an exemplary embodiment of the present specification, m2 is 1.

In an exemplary embodiment of the present specification, m3 is 0.

In an exemplary embodiment of the present specification, m3 is 1.

In an exemplary embodiment of the present specification, g1 to g3 are each an integer from 0 to 8.

In an exemplary embodiment of the present specification, g1 to g3 are 0.

In an exemplary embodiment of the present specification, g1 to g3 are 8.

In an exemplary embodiment of the present specification, n1+m1 is 4 or less, n2+m2 is 4 or less, and n3+m3 is 3 or less.

In an exemplary embodiment of the present specification, m1+m2+m3 is an integer of 1 or higher.

In an exemplary embodiment of the present specification, m1+m2+m3 is 1 to 3.

In an exemplary embodiment of the present specification, m1+m2+m3 is 1 or 2.

In an exemplary embodiment of the present specification, Chemical Formula 1 is represented by any one of the following Chemical Formulae 1-A-1 to 1-A-3.

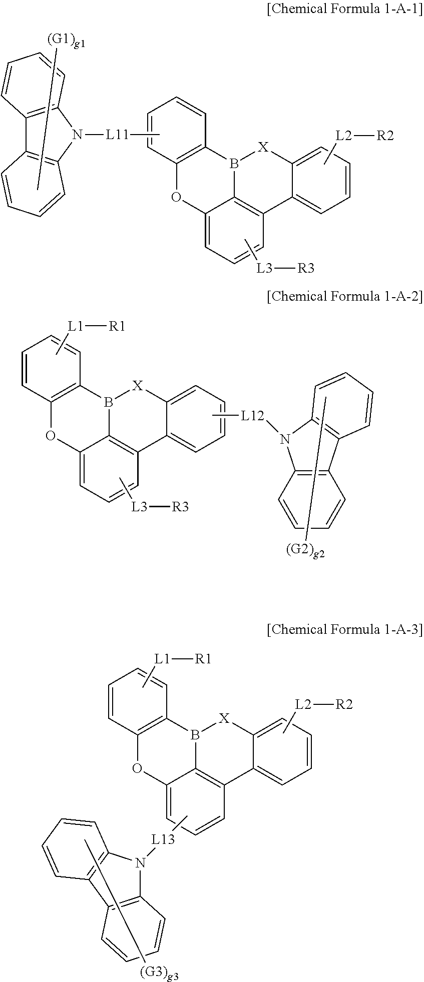

In Chemical Formulae 1-A-1 to 1-A-3,
the definitions of X, R1 to R3, L1 to L3, L11 to L13, G1 to G3, and g1 to g3 are the same as the definitions in Chemical Formula 1.

In an exemplary embodiment of the present specification, Chemical Formula 1 is represented by any one of the following Chemical Formulae 1-B-1 to 1-B-3.

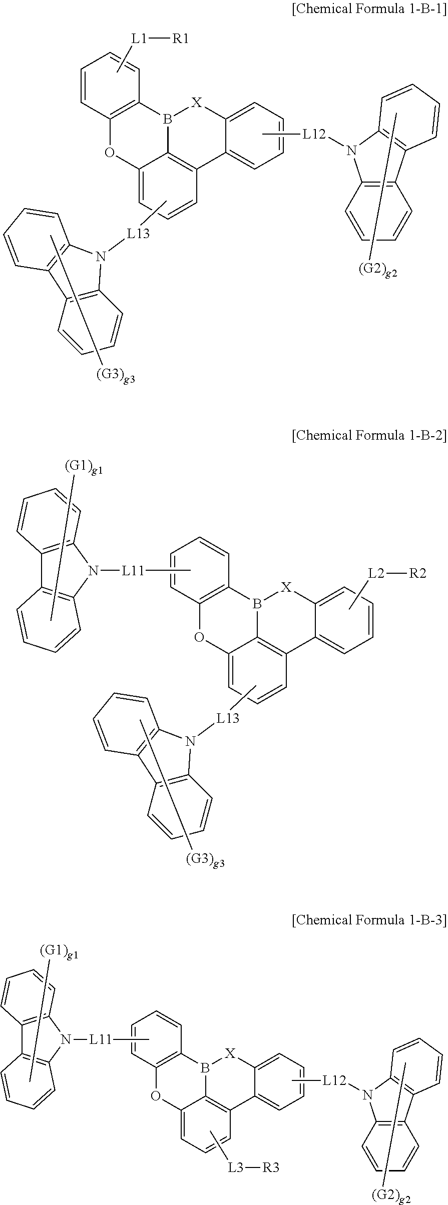

In Chemical Formulae 1-B-1 to 1-B-3,
the definitions of X, R1 to R3, L1 to L3, L11 to L13, G1 to G3, and g1 to g3 are the same as the definitions in Chemical Formula 1.

In an exemplary embodiment of the present specification, the compound of Chemical Formula 1 including deuterium may be prepared by a publicly-known deuteration reaction. In an exemplary embodiment of the present specification, the compound represented by Chemical Formula 1 may be formed using a deuterated compound as a precursor, or deuterium may also be introduced into a compound via a hydrogen-deuterium exchange reaction in the presence of an acid catalyst using a deuterated solvent.

In an exemplary embodiment of the present specification, 20% or more of the compound represented by Chemical Formula 1 is substituted with deuterium. In another exemplary embodiment, 30% or more of the compound represented by Chemical Formula 1 is substituted with deuterium. In still another exemplary embodiment, 40% or more of the compound represented by Chemical Formula 1 is substituted with deuterium. In yet another exemplary embodiment, 50% or more of the compound represented by Chemical Formula 1 is substituted with deuterium. In still yet another exemplary embodiment, 60% or more of the compound represented by Chemical Formula 1 is substituted with deuterium. In yet another exemplary embodiment, 70% or more of the compound represented by Chemical Formula 1 is substituted with deuterium. In still yet another exemplary embodiment, 80% or more of the compound represented by Chemical Formula 1 is substituted with deuterium. In a further exemplary embodiment, 90% or more of the compound represented by Chemical Formula 1 is substituted with deuterium. In another further exemplary embodiment, 100% of the compound represented by Chemical Formula 1 is substituted with deuterium.

In an exemplary embodiment of the present specification, the compound represented by Chemical Formula 1 includes 40% to 60% of deuterium. In another exemplary embodiment, the compound represented by Chemical Formula 1 includes 40% to 80% of deuterium. In still another exemplary embodiment, the compound represented by Chemical Formula 1 includes 60% to 80% of deuterium. In yet another exemplary embodiment, the compound represented by Chemical Formula 1 includes 80% to 100% of deuterium.

In an exemplary embodiment of the present specification, Chemical Formula 1 is represented by any one of the following compounds.

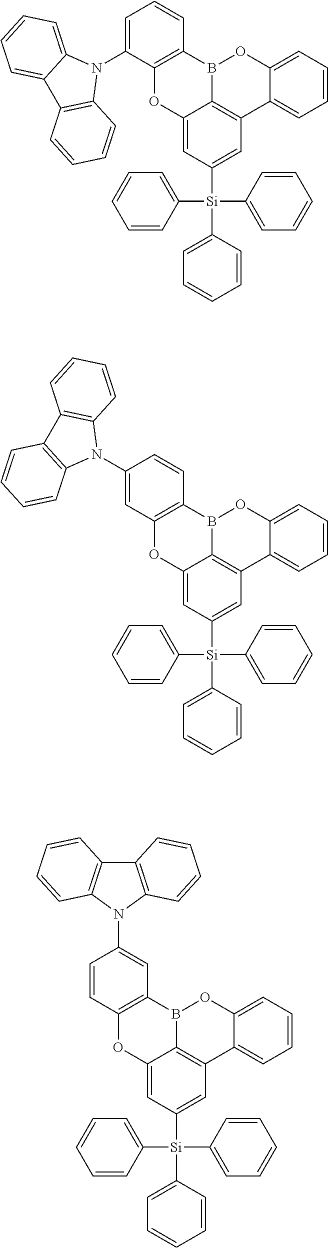 [SMILES: c1ccc([Si](c2ccccc2)(c2ccccc2)c2cc3c4c(c2)-c2ccccc2OB4c2cccc(-n4c5ccccc5c5ccccc54)c2O3)cc1 ; c1ccc([Si](c2ccccc2)(c2ccccc2)c2cc3c4c(c2)-c2ccccc2OB4c2ccc(-n4c5ccccc5c5ccccc54)cc2O3)cc1 ; c1ccc([Si](c2ccccc2)(c2ccccc2)c2cc3c4c(c2)-c2ccccc2OB4c2cc(-n4c5ccccc5c5ccccc54)ccc2O3)cc1]

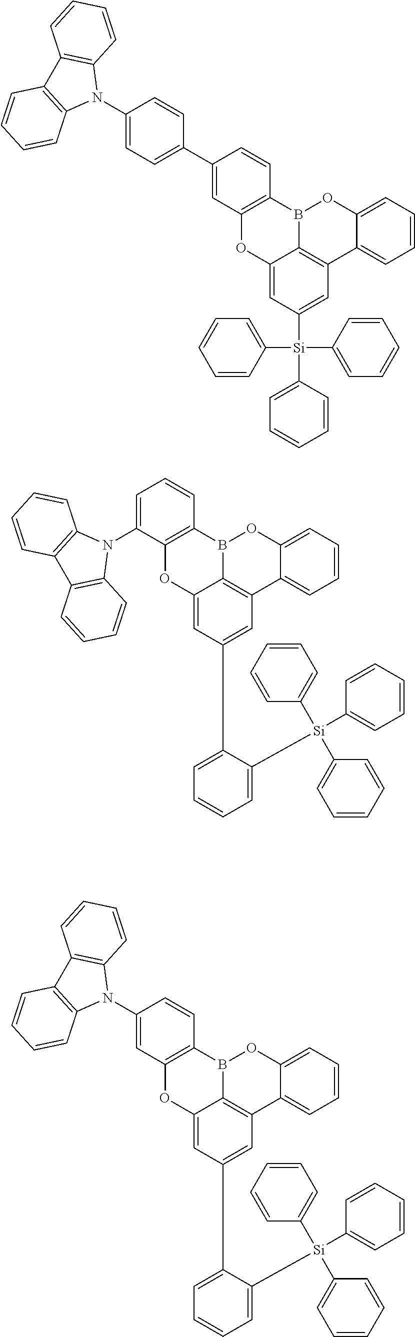 [SMILES: c1ccc([Si](c2ccccc2)(c2ccccc2)c2cc3c4c(c2)-c2ccccc2OB4c2ccc(-c4ccc(-n5c6ccccc6c6ccccc65)cc4)cc2O3)cc1 ; c1ccc([Si](c2ccccc2)(c2ccccc2)c2ccccc2-c2cc3c4c(c2)-c2ccccc2OB4c2cccc(-n4c5ccccc5c5ccccc54)c2O3)cc1 ; c1ccc([Si](c2ccccc2)(c2ccccc2)c2ccccc2-c2cc3c4c(c2)-c2ccccc2OB4c2ccc(-n4c5ccccc5c5ccccc54)cc2O3)cc1]

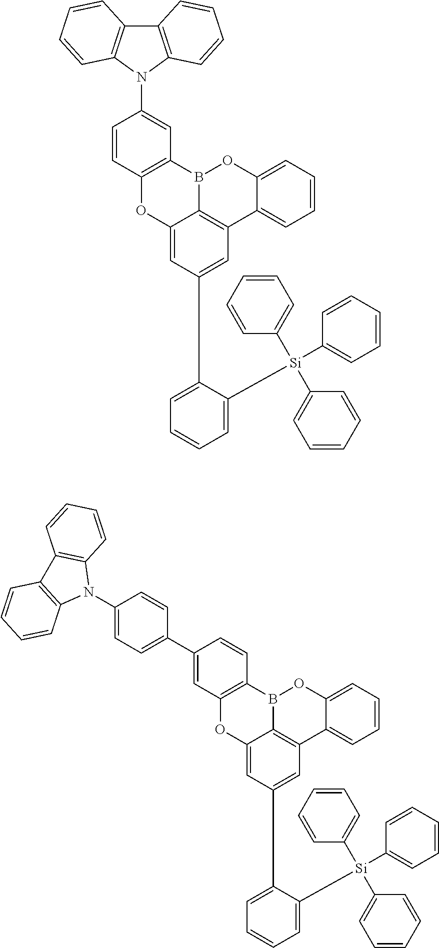 [SMILES: c1ccc([Si](c2ccccc2)(c2ccccc2)c2ccccc2-c2cc3c4c(c2)-c2ccccc2OB4c2cc(-n4c5ccccc5c5ccccc54)ccc2O3)cc1 ; c1ccc([Si](c2ccccc2)(c2ccccc2)c2ccccc2-c2cc3c4c(c2)-c2ccccc2OB4c2ccc(-c4ccc(-n5c6ccccc6c6ccccc65)cc4)cc2O3)cc1]

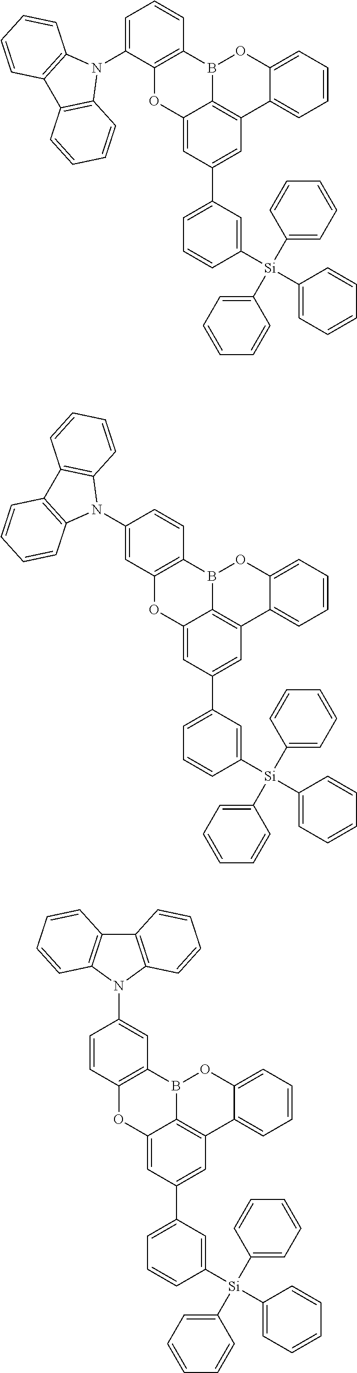 [SMILES: c1ccc([Si](c2ccccc2)(c2ccccc2)c2cccc(-c3cc4c5c(c3)-c3ccccc3OB5c3cccc(-n5c6ccccc6c6ccccc65)c3O4)c2)cc1 ; c1ccc([Si](c2ccccc2)(c2ccccc2)c2cccc(-c3cc4c5c(c3)-c3ccccc3OB5c3ccc(-n5c6ccccc6c6ccccc65)cc3O4)c2)cc1 ; c1ccc([Si](c2ccccc2)(c2ccccc2)c2cccc(-c3cc4c5c(c3)-c3ccccc3OB5c3cc(-n5c6ccccc6c6ccccc65)ccc3O4)c2)cc1]

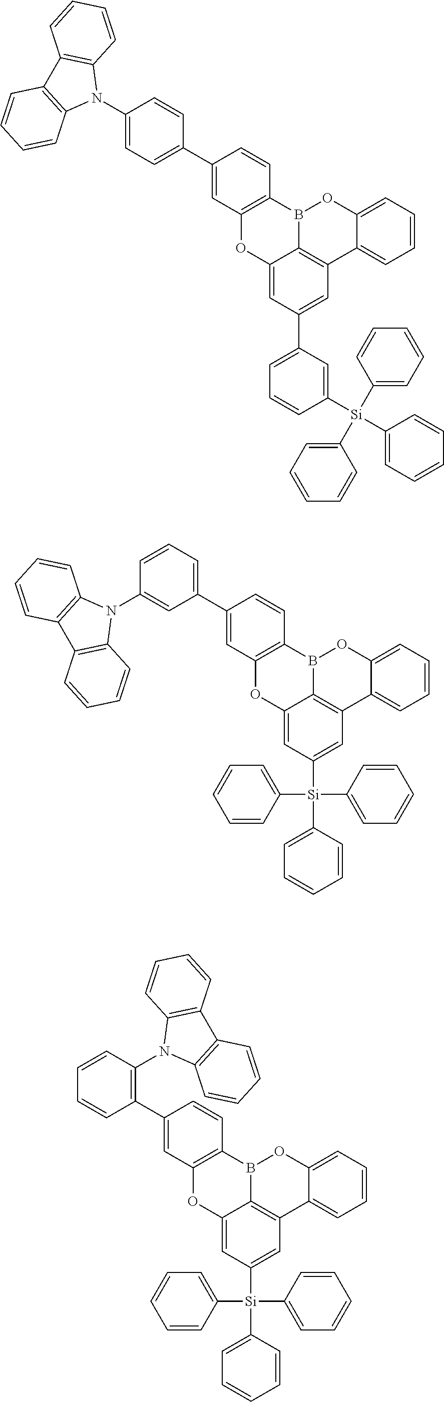 [SMILES: c1ccc([Si](c2ccccc2)(c2ccccc2)c2cccc(-c3cc4c5c(c3)-c3ccccc3OB5c3ccc(-c5ccc(-n6c7ccccc7c7ccccc76)cc5)cc3O4)c2)cc1 ; c1ccc([Si](c2ccccc2)(c2ccccc2)c2cc3c4c(c2)-c2ccccc2OB4c2ccc(-c4cccc(-n5c6ccccc6c6ccccc65)c4)cc2O3)cc1 ; c1ccc([Si](c2ccccc2)(c2ccccc2)c2cc3c4c(c2)-c2ccccc2OB4c2ccc(-c4ccccc4-n4c5ccccc5c5ccccc54)cc2O3)cc1]

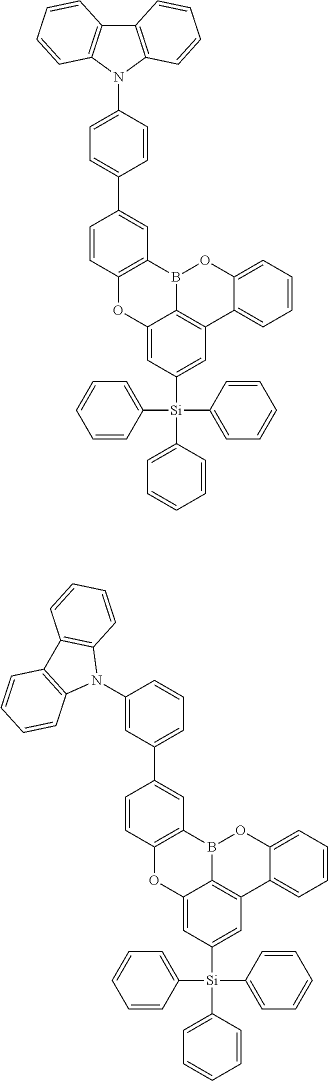 [SMILES: c1ccc([Si](c2ccccc2)(c2ccccc2)c2cc3c4c(c2)-c2ccccc2OB4c2cc(-c4ccc(-n5c6ccccc6c6ccccc65)cc4)ccc2O3)cc1 ; c1ccc([Si](c2ccccc2)(c2ccccc2)c2cc3c4c(c2)-c2ccccc2OB4c2cc(-c4cccc(-n5c6ccccc6c6ccccc65)c4)ccc2O3)cc1]

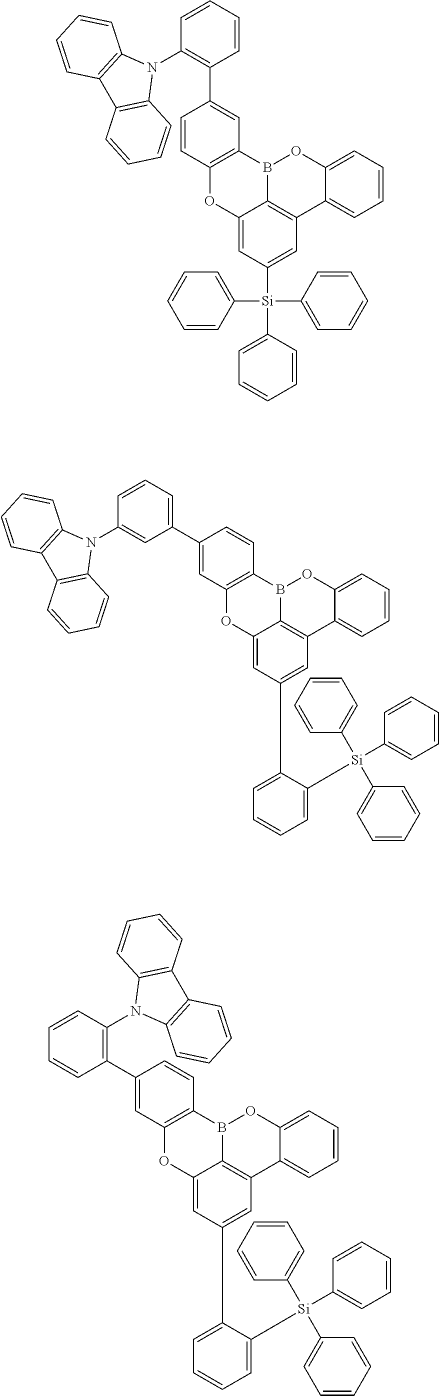 [SMILES: c1ccc([Si](c2ccccc2)(c2ccccc2)c2cc3c4c(c2)-c2ccccc2OB4c2cc(-c4ccccc4-n4c5ccccc5c5ccccc54)ccc2O3)cc1 ; c1ccc([Si](c2ccccc2)(c2ccccc2)c2ccccc2-c2cc3c4c(c2)-c2ccccc2OB4c2ccc(-c4cccc(-n5c6ccccc6c6ccccc65)c4)cc2O3)cc1 ; c1ccc([Si](c2ccccc2)(c2ccccc2)c2ccccc2-c2cc3c4c(c2)-c2ccccc2OB4c2ccc(-c4ccccc4-n4c5ccccc5c5ccccc54)cc2O3)cc1]

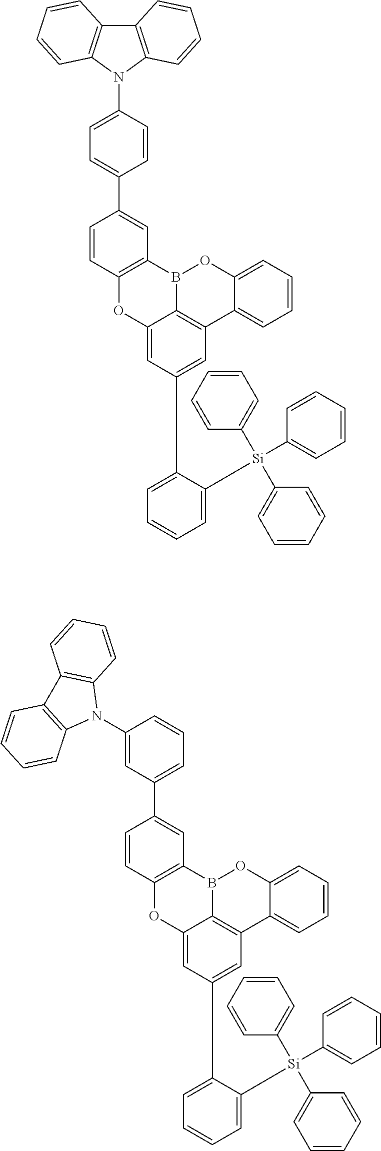 [SMILES: c1ccc([Si](c2ccccc2)(c2ccccc2)c2ccccc2-c2cc3c4c(c2)-c2ccccc2OB4c2cc(-c4ccc(-n5c6ccccc6c6ccccc65)cc4)ccc2O3)cc1 ; c1ccc([Si](c2ccccc2)(c2ccccc2)c2ccccc2-c2cc3c4c(c2)-c2ccccc2OB4c2cc(-c4cccc(-n5c6ccccc6c6ccccc65)c4)ccc2O3)cc1]

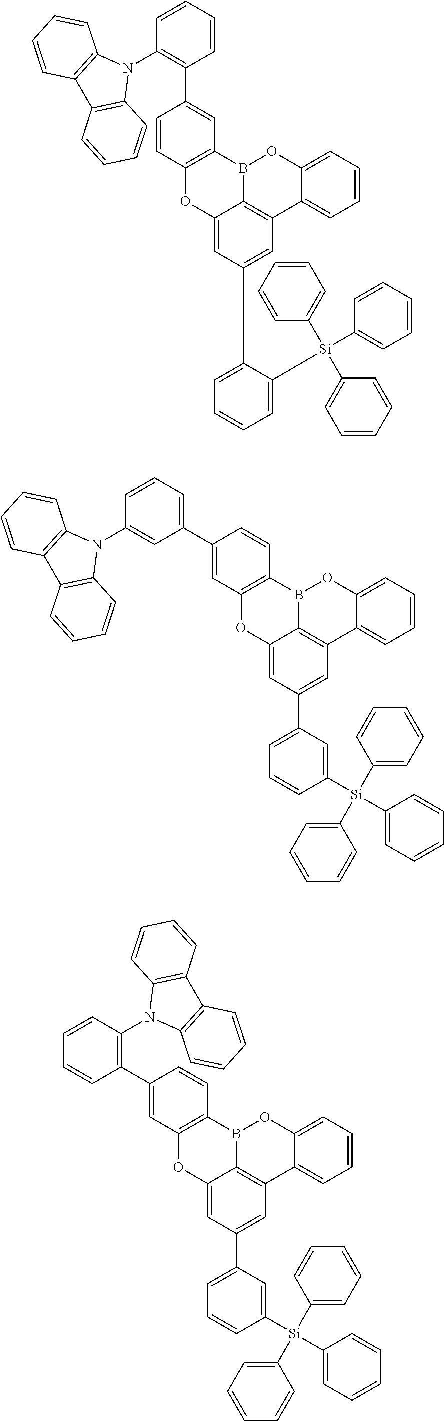 [SMILES: c1ccc([Si](c2ccccc2)(c2ccccc2)c2ccccc2-c2cc3c4c(c2)-c2ccccc2OB4c2cc(-c4ccccc4-n4c5ccccc5c5ccccc54)ccc2O3)cc1 ; c1ccc([Si](c2ccccc2)(c2ccccc2)c2cccc(-c3cc4c5c(c3)-c3ccccc3OB5c3ccc(-c5cccc(-n6c7ccccc7c7ccccc76)c5)cc3O4)c2)cc1 ; c1ccc([Si](c2ccccc2)(c2ccccc2)c2cccc(-c3cc4c5c(c3)-c3ccccc3OB5c3ccc(-c5ccccc5-n5c6ccccc6c6ccccc65)cc3O4)c2)cc1]

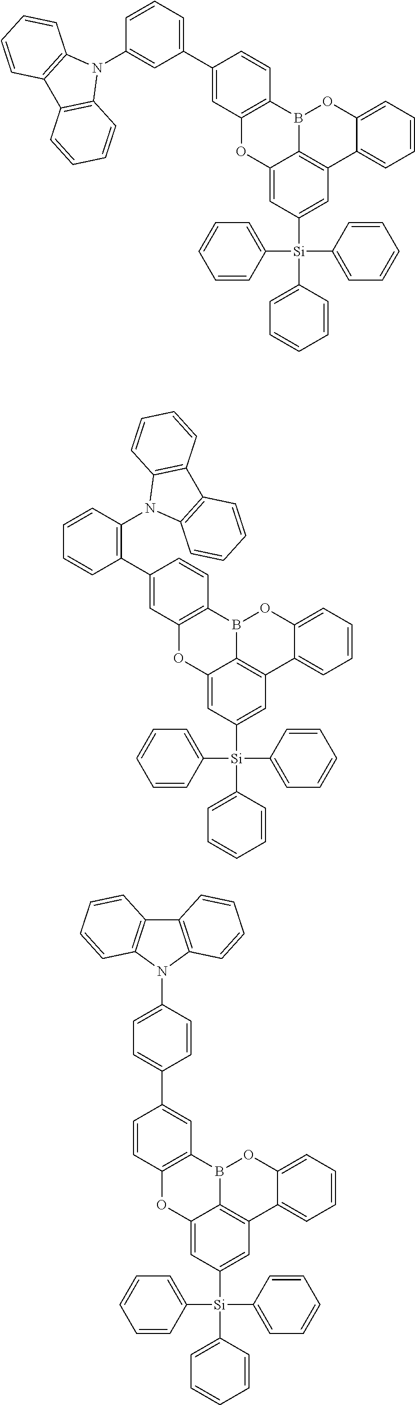

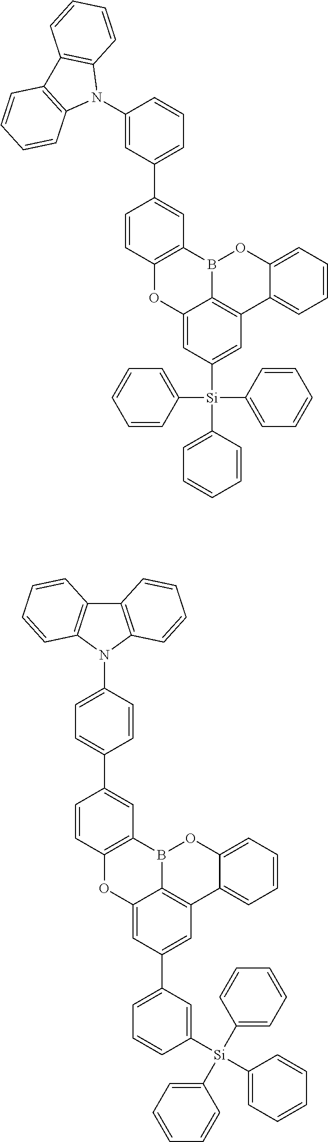 [SMILES: c1ccc([Si](c2ccccc2)(c2ccccc2)c2cc3c4c(c2)-c2ccccc2OB4c2cc(-c4cccc(-n5c6ccccc6c6ccccc65)c4)ccc2O3)cc1 ; c1ccc([Si](c2ccccc2)(c2ccccc2)c2cccc(-c3cc4c5c(c3)-c3ccccc3OB5c3cc(-c5ccc(-n6c7ccccc7c7ccccc76)cc5)ccc3O4)c2)cc1]

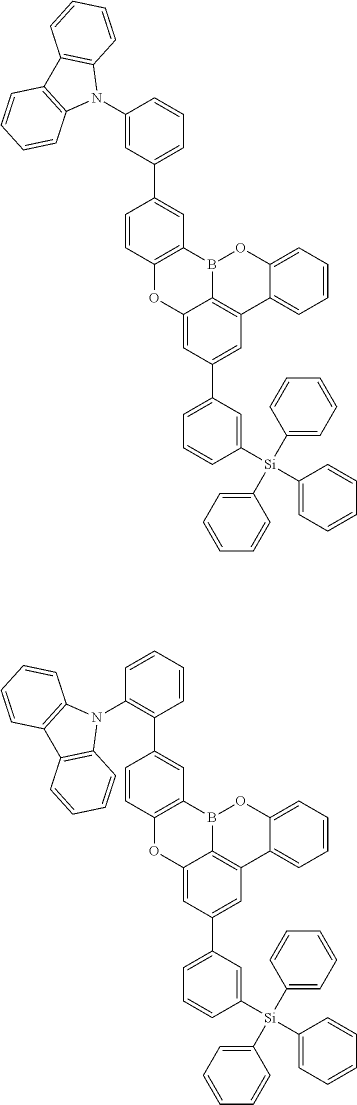 [SMILES: c1ccc([Si](c2ccccc2)(c2ccccc2)c2cccc(-c3cc4c5c(c3)-c3ccccc3OB5c3cc(-c5cccc(-n6c7ccccc7c7ccccc76)c5)ccc3O4)c2)cc1 ; c1ccc([Si](c2ccccc2)(c2ccccc2)c2cccc(-c3cc4c5c(c3)-c3ccccc3OB5c3cc(-c5ccccc5-n5c6ccccc6c6ccccc65)ccc3O4)c2)cc1]

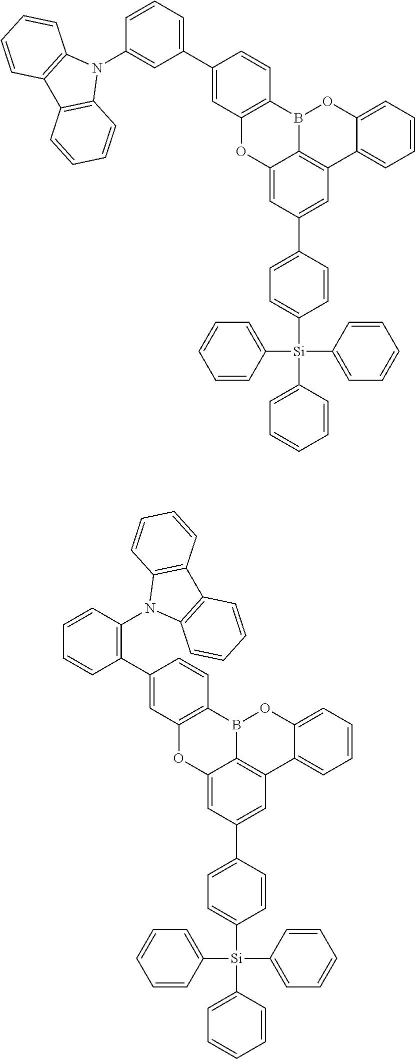 [SMILES: c1ccc([Si](c2ccccc2)(c2ccccc2)c2ccc(-c3cc4c5c(c3)-c3ccccc3OB5c3ccc(-c5cccc(-n6c7ccccc7c7ccccc76)c5)cc3O4)cc2)cc1 ; c1ccc([Si](c2ccccc2)(c2ccccc2)c2ccc(-c3cc4c5c(c3)-c3ccccc3OB5c3ccc(-c5ccccc5-n5c6ccccc6c6ccccc65)cc3O4)cc2)cc1]

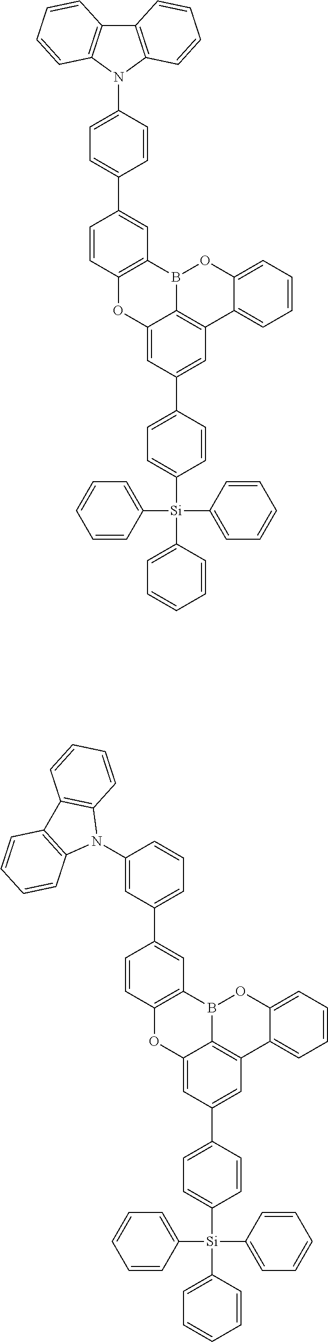 [SMILES: c1ccc([Si](c2ccccc2)(c2ccccc2)c2ccc(-c3cc4c5c(c3)-c3ccccc3OB5c3cc(-c5ccc(-n6c7ccccc7c7ccccc76)cc5)ccc3O4)cc2)cc1 ; c1ccc([Si](c2ccccc2)(c2ccccc2)c2ccc(-c3cc4c5c(c3)-c3ccccc3OB5c3cc(-c5cccc(-n6c7ccccc7c7ccccc76)c5)ccc3O4)cc2)cc1]

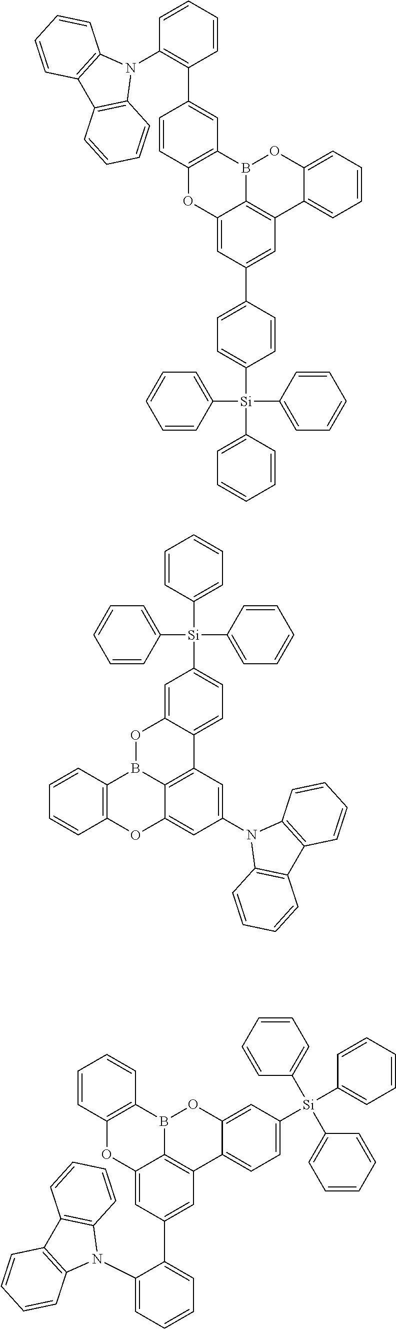 [SMILES: c1ccc([Si](c2ccccc2)(c2ccccc2)c2ccc(-c3cc4c5c(c3)-c3ccccc3OB5c3cc(-c5ccccc5-n5c6ccccc6c6ccccc65)ccc3O4)cc2)cc1 ; c1ccc([Si](c2ccccc2)(c2ccccc2)c2ccc3c(c2)OB2c4ccccc4Oc4cc(-n5c6ccccc6c6ccccc65)cc-3c42)cc1 ; c1ccc([Si](c2ccccc2)(c2ccccc2)c2ccc3c(c2)OB2c4ccccc4Oc4cc(-c5ccccc5-n5c6ccccc6c6ccccc65)cc-3c42)cc1]

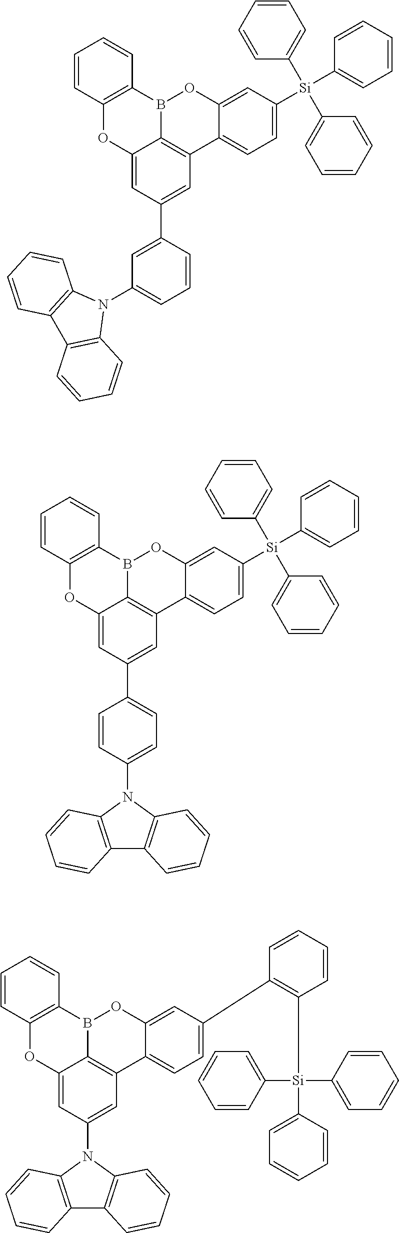 [SMILES: c1ccc([Si](c2ccccc2)(c2ccccc2)c2ccc3c(c2)OB2c4ccccc4Oc4cc(-c5cccc(-n6c7ccccc7c7ccccc76)c5)cc-3c42)cc1 ; c1ccc([Si](c2ccccc2)(c2ccccc2)c2ccc3c(c2)OB2c4ccccc4Oc4cc(-c5ccc(-n6c7ccccc7c7ccccc76)cc5)cc-3c42)cc1 ; c1ccc([Si](c2ccccc2)(c2ccccc2)c2ccccc2-c2ccc3c(c2)OB2c4ccccc4Oc4cc(-n5c6ccccc6c6ccccc65)cc-3c42)cc1]

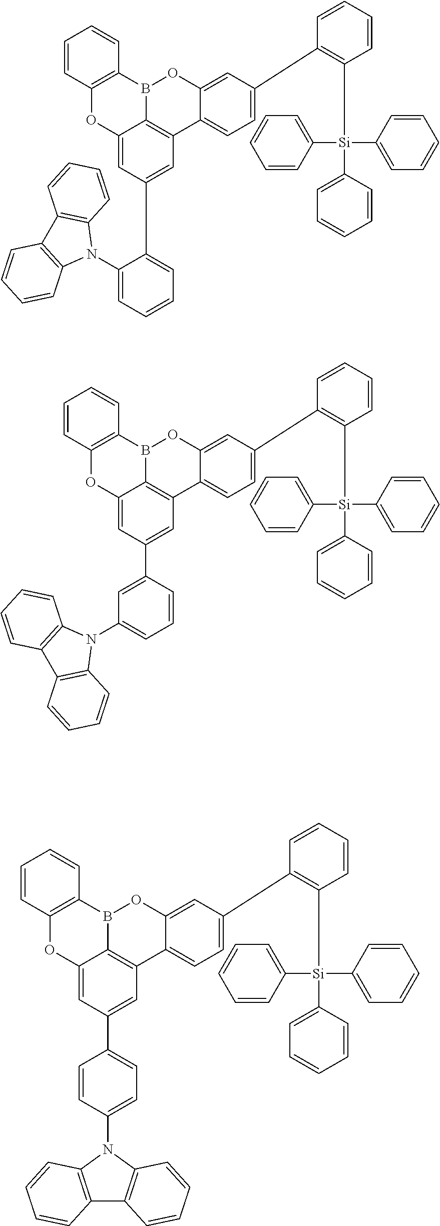 [SMILES: c1ccc([Si](c2ccccc2)(c2ccccc2)c2ccccc2-c2ccc3c(c2)OB2c4ccccc4Oc4cc(-c5ccccc5-n5c6ccccc6c6ccccc65)cc-3c42)cc1 ; c1ccc([Si](c2ccccc2)(c2ccccc2)c2ccccc2-c2ccc3c(c2)OB2c4ccccc4Oc4cc(-c5cccc(-n6c7ccccc7c7ccccc76)c5)cc-3c42)cc1 ; c1ccc([Si](c2ccccc2)(c2ccccc2)c2ccccc2-c2ccc3c(c2)OB2c4ccccc4Oc4cc(-c5ccc(-n6c7ccccc7c7ccccc76)cc5)cc-3c42)cc1]

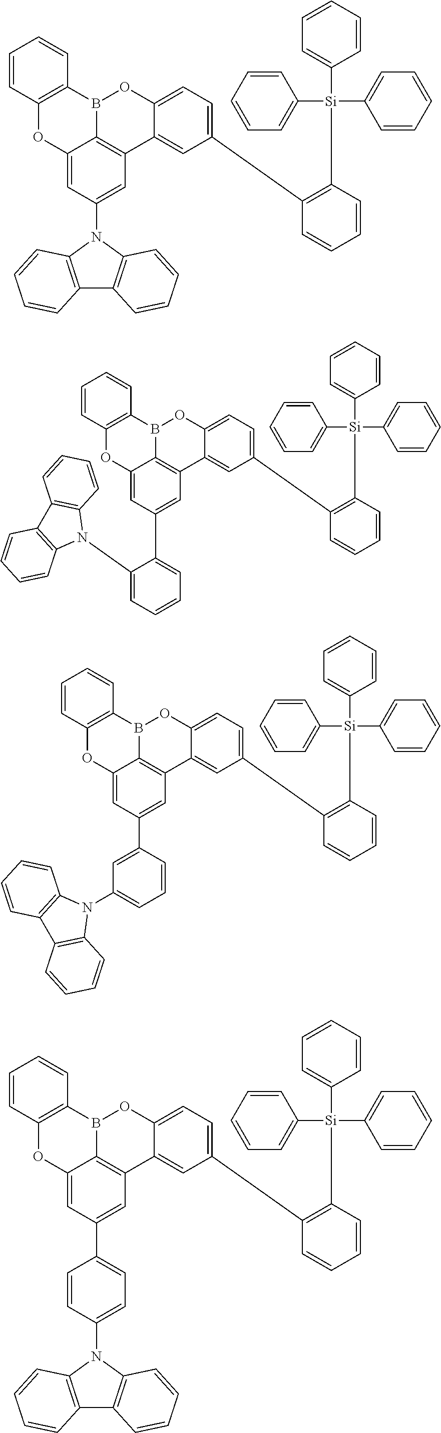 [SMILES: c1ccc([Si](c2ccccc2)(c2ccccc2)c2ccccc2-c2ccc3c(c2)-c2cc(-n4c5ccccc5c5ccccc54)cc4c2B(O3)c2ccccc2O4)cc1 ; c1ccc([Si](c2ccccc2)(c2ccccc2)c2ccccc2-c2ccc3c(c2)-c2cc(-c4ccccc4-n4c5ccccc5c5ccccc54)cc4c2B(O3)c2ccccc2O4)cc1 ; c1ccc([Si](c2ccccc2)(c2ccccc2)c2ccccc2-c2ccc3c(c2)-c2cc(-c4cccc(-n5c6ccccc6c6ccccc65)c4)cc4c2B(O3)c2ccccc2O4)cc1 ; c1ccc([Si](c2ccccc2)(c2ccccc2)c2ccccc2-c2ccc3c(c2)-c2cc(-c4ccc(-n5c6ccccc6c6ccccc65)cc4)cc4c2B(O3)c2ccccc2O4)cc1]

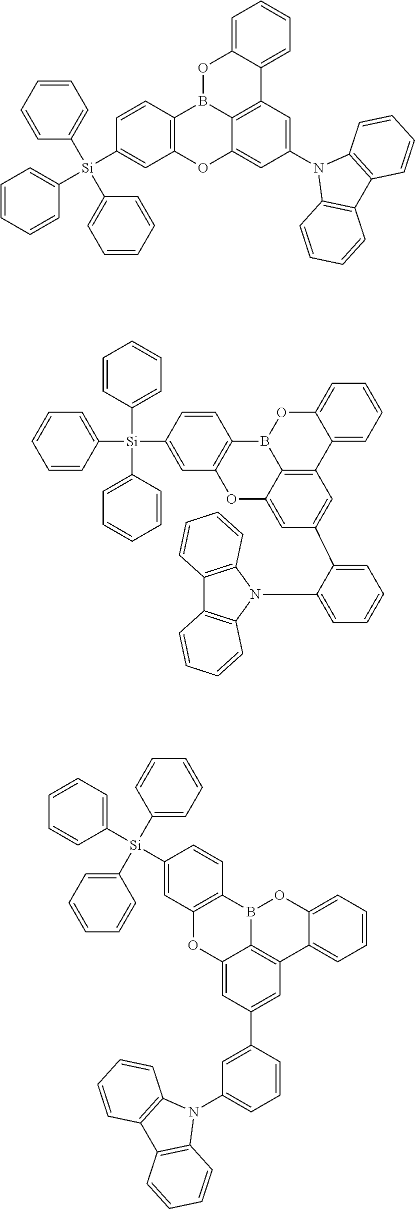 [SMILES: c1ccc([Si](c2ccccc2)(c2ccccc2)c2ccc3c(c2)Oc2cc(-n4c5ccccc5c5ccccc54)cc4c2B3Oc2ccccc2-4)cc1 ; c1ccc([Si](c2ccccc2)(c2ccccc2)c2ccc3c(c2)Oc2cc(-c4ccccc4-n4c5ccccc5c5ccccc54)cc4c2B3Oc2ccccc2-4)cc1 ; c1ccc([Si](c2ccccc2)(c2ccccc2)c2ccc3c(c2)Oc2cc(-c4cccc(-n5c6ccccc6c6ccccc65)c4)cc4c2B3Oc2ccccc2-4)cc1]

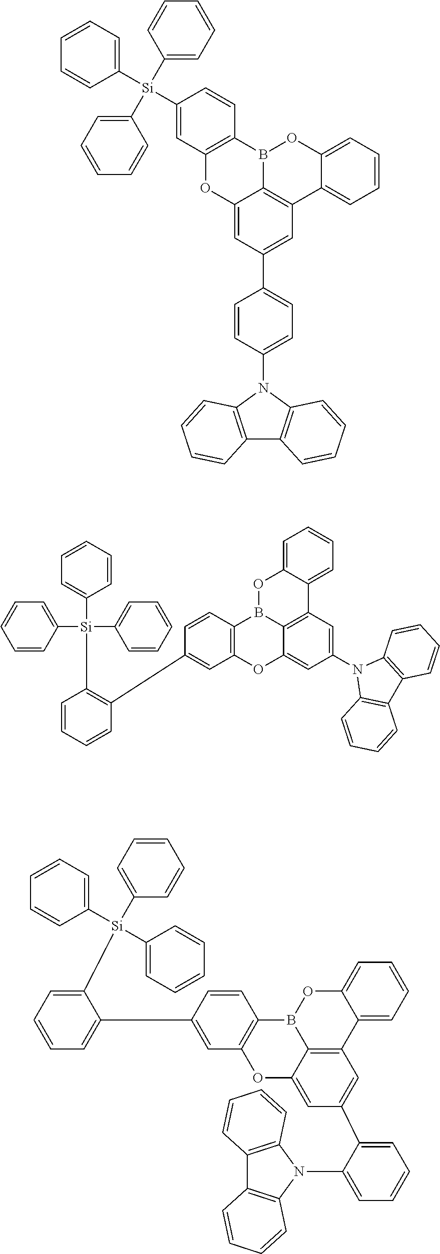 [SMILES: c1ccc([Si](c2ccccc2)(c2ccccc2)c2ccc3c(c2)Oc2cc(-c4ccc(-n5c6ccccc6c6ccccc65)cc4)cc4c2B3Oc2ccccc2-4)cc1 ; c1ccc([Si](c2ccccc2)(c2ccccc2)c2ccccc2-c2ccc3c(c2)Oc2cc(-n4c5ccccc5c5ccccc54)cc4c2B3Oc2ccccc2-4)cc1 ; c1ccc([Si](c2ccccc2)(c2ccccc2)c2ccccc2-c2ccc3c(c2)Oc2cc(-c4ccccc4-n4c5ccccc5c5ccccc54)cc4c2B3Oc2ccccc2-4)cc1]

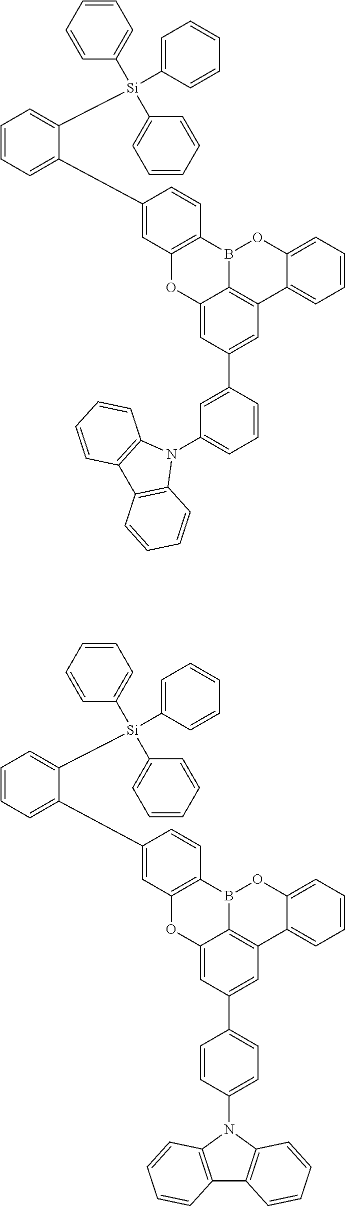 [SMILES: c1ccc([Si](c2ccccc2)(c2ccccc2)c2ccccc2-c2ccc3c(c2)Oc2cc(-c4cccc(-n5c6ccccc6c6ccccc65)c4)cc4c2B3Oc2ccccc2-4)cc1 ; c1ccc([Si](c2ccccc2)(c2ccccc2)c2ccccc2-c2ccc3c(c2)Oc2cc(-c4ccc(-n5c6ccccc6c6ccccc65)cc4)cc4c2B3Oc2ccccc2-4)cc1]

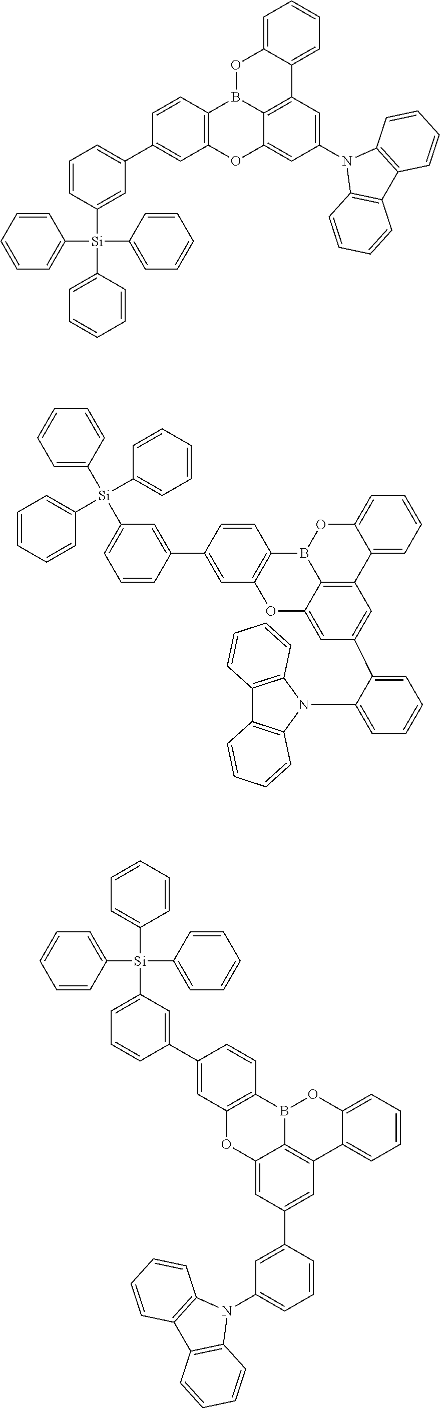 [SMILES: c1ccc([Si](c2ccccc2)(c2ccccc2)c2cccc(-c3ccc4c(c3)Oc3cc(-n5c6ccccc6c6ccccc65)cc5c3B4Oc3ccccc3-5)c2)cc1 ; c1ccc([Si](c2ccccc2)(c2ccccc2)c2cccc(-c3ccc4c(c3)Oc3cc(-c5ccccc5-n5c6ccccc6c6ccccc65)cc5c3B4Oc3ccccc3-5)c2)cc1 ; c1ccc([Si](c2ccccc2)(c2ccccc2)c2cccc(-c3ccc4c(c3)Oc3cc(-c5cccc(-n6c7ccccc7c7ccccc76)c5)cc5c3B4Oc3ccccc3-5)c2)cc1]

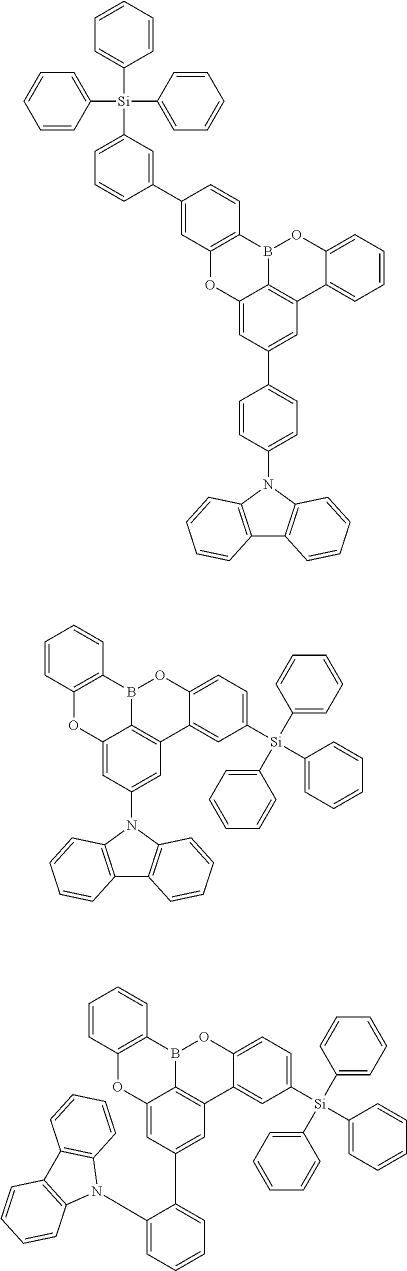 [SMILES: c1ccc([Si](c2ccccc2)(c2ccccc2)c2cccc(-c3ccc4c(c3)Oc3cc(-c5ccc(-n6c7ccccc7c7ccccc76)cc5)cc5c3B4Oc3ccccc3-5)c2)cc1 ; c1ccc([Si](c2ccccc2)(c2ccccc2)c2ccc3c(c2)-c2cc(-n4c5ccccc5c5ccccc54)cc4c2B(O3)c2ccccc2O4)cc1 ; c1ccc([Si](c2ccccc2)(c2ccccc2)c2ccc3c(c2)-c2cc(-c4ccccc4-n4c5ccccc5c5ccccc54)cc4c2B(O3)c2ccccc2O4)cc1]

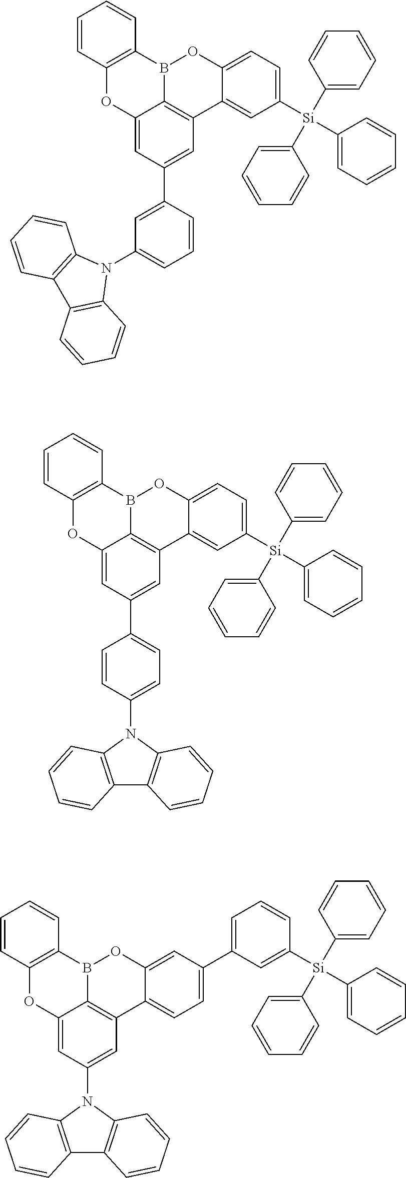 [SMILES: c1ccc([Si](c2ccccc2)(c2ccccc2)c2ccc3c(c2)-c2cc(-c4cccc(-n5c6ccccc6c6ccccc65)c4)cc4c2B(O3)c2ccccc2O4)cc1 ; c1ccc([Si](c2ccccc2)(c2ccccc2)c2ccc3c(c2)-c2cc(-c4ccc(-n5c6ccccc6c6ccccc65)cc4)cc4c2B(O3)c2ccccc2O4)cc1 ; c1ccc([Si](c2ccccc2)(c2ccccc2)c2cccc(-c3ccc4c(c3)OB3c5ccccc5Oc5cc(-n6c7ccccc7c7ccccc76)cc-4c53)c2)cc1]

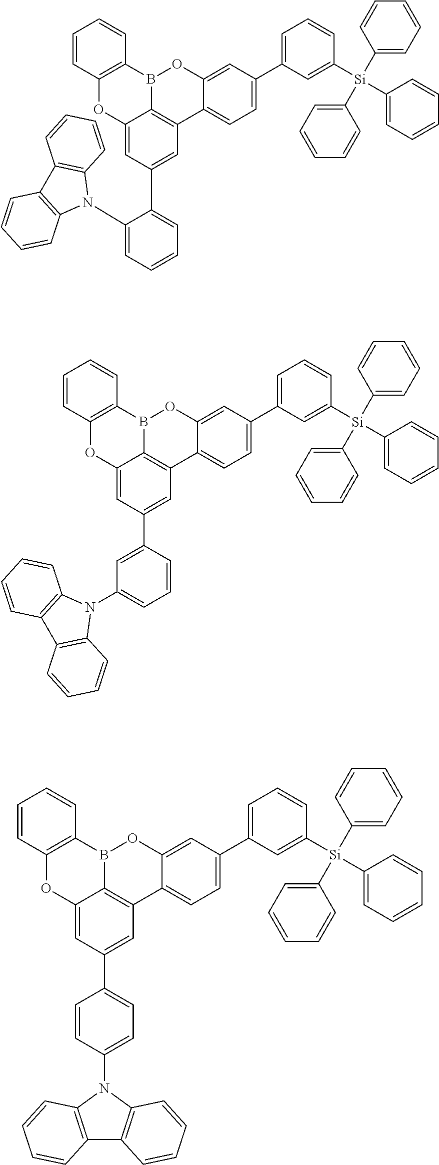 [SMILES: c1ccc([Si](c2ccccc2)(c2ccccc2)c2cccc(-c3ccc4c(c3)OB3c5ccccc5Oc5cc(-c6ccccc6-n6c7ccccc7c7ccccc76)cc-4c53)c2)cc1 ; c1ccc([Si](c2ccccc2)(c2ccccc2)c2cccc(-c3ccc4c(c3)OB3c5ccccc5Oc5cc(-c6cccc(-n7c8ccccc8c8ccccc87)c6)cc-4c53)c2)cc1 ; c1ccc([Si](c2ccccc2)(c2ccccc2)c2cccc(-c3ccc4c(c3)OB3c5ccccc5Oc5cc(-c6ccc(-n7c8ccccc8c8ccccc87)cc6)cc-4c53)c2)cc1]

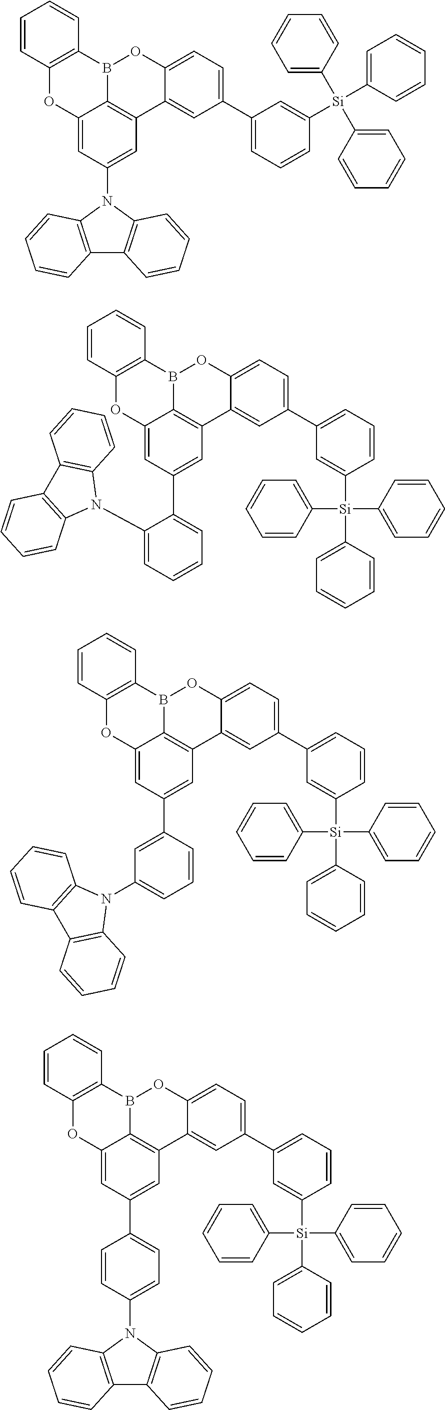

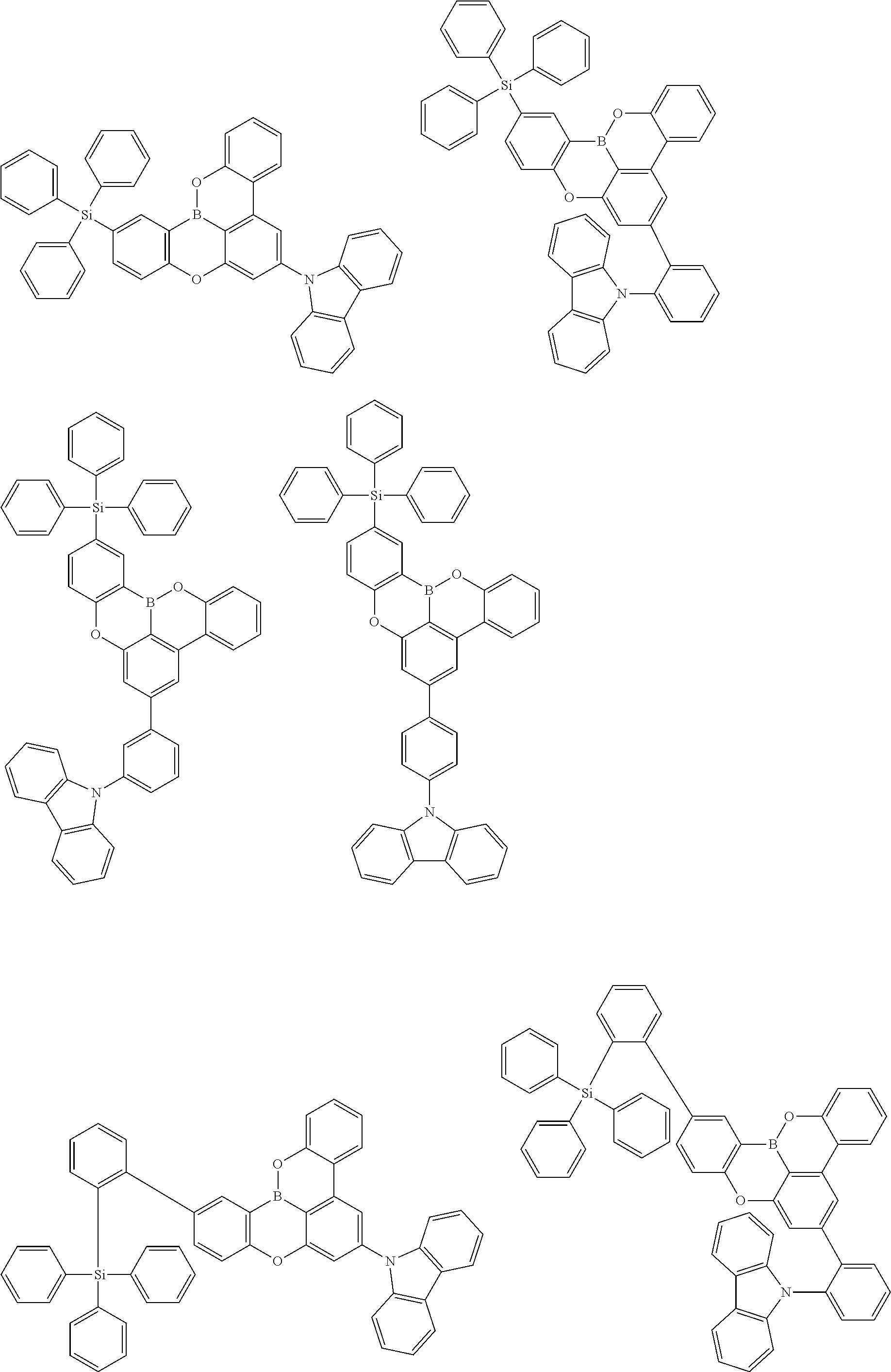

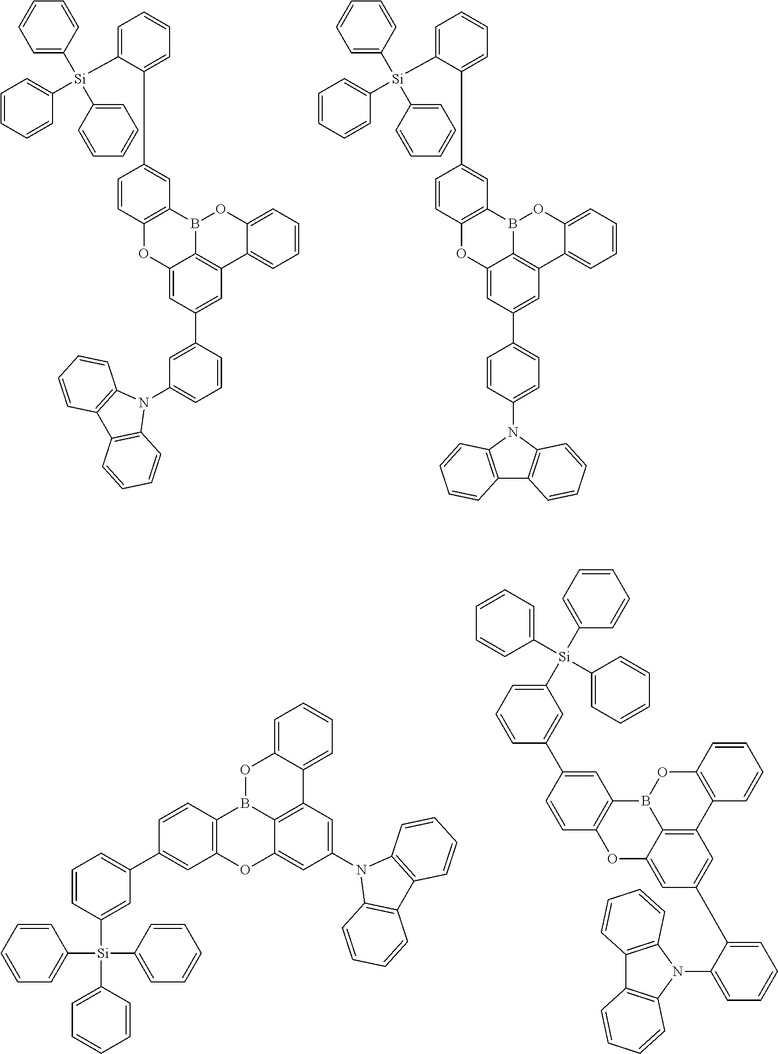 [SMILES: c1ccc([Si](c2ccccc2)(c2ccccc2)c2ccccc2-c2ccc3c(c2)B2Oc4ccccc4-c4cc(-c5cccc(-n6c7ccccc7c7ccccc76)c5)cc(c42)O3)cc1 ; c1ccc([Si](c2ccccc2)(c2ccccc2)c2ccccc2-c2ccc3c(c2)B2Oc4ccccc4-c4cc(-c5ccc(-n6c7ccccc7c7ccccc76)cc5)cc(c42)O3)cc1 ; c1ccc([Si](c2ccccc2)(c2ccccc2)c2cccc(-c3ccc4c(c3)Oc3cc(-n5c6ccccc6c6ccccc65)cc5c3B4Oc3ccccc3-5)c2)cc1 ; c1ccc([Si](c2ccccc2)(c2ccccc2)c2cccc(-c3ccc4c(c3)B3Oc5ccccc5-c5cc(-c6ccccc6-n6c7ccccc7c7ccccc76)cc(c53)O4)c2)cc1]

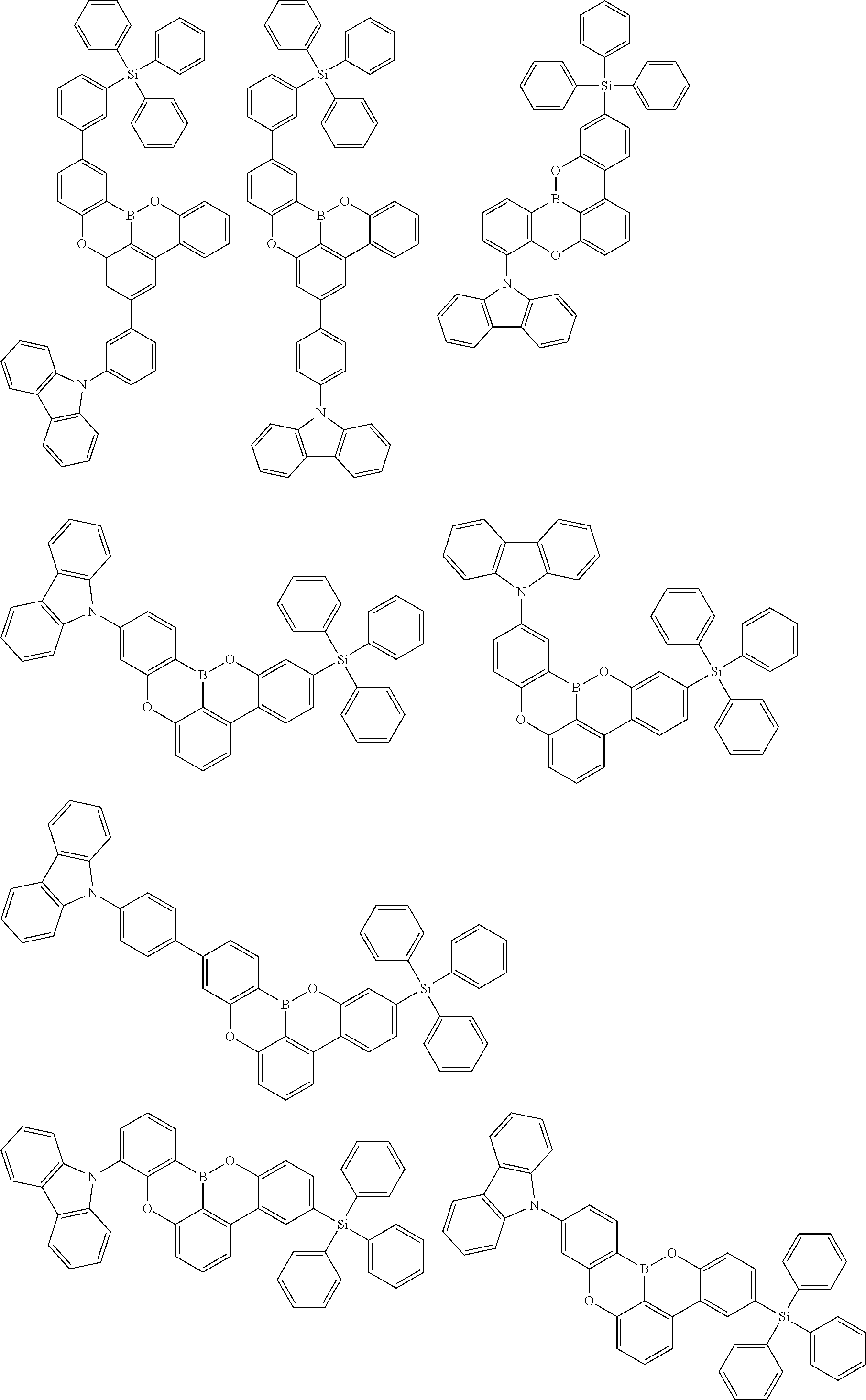

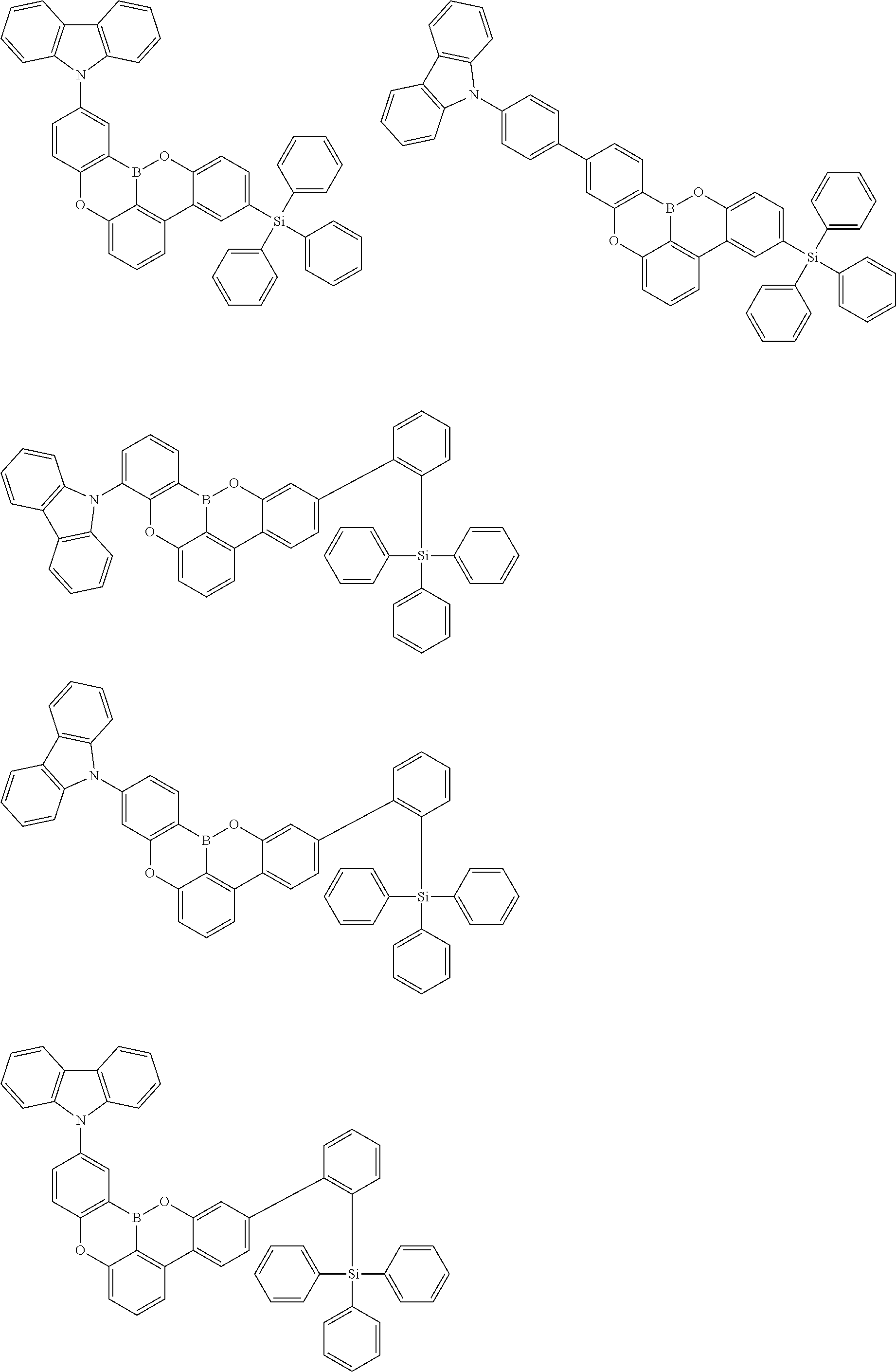

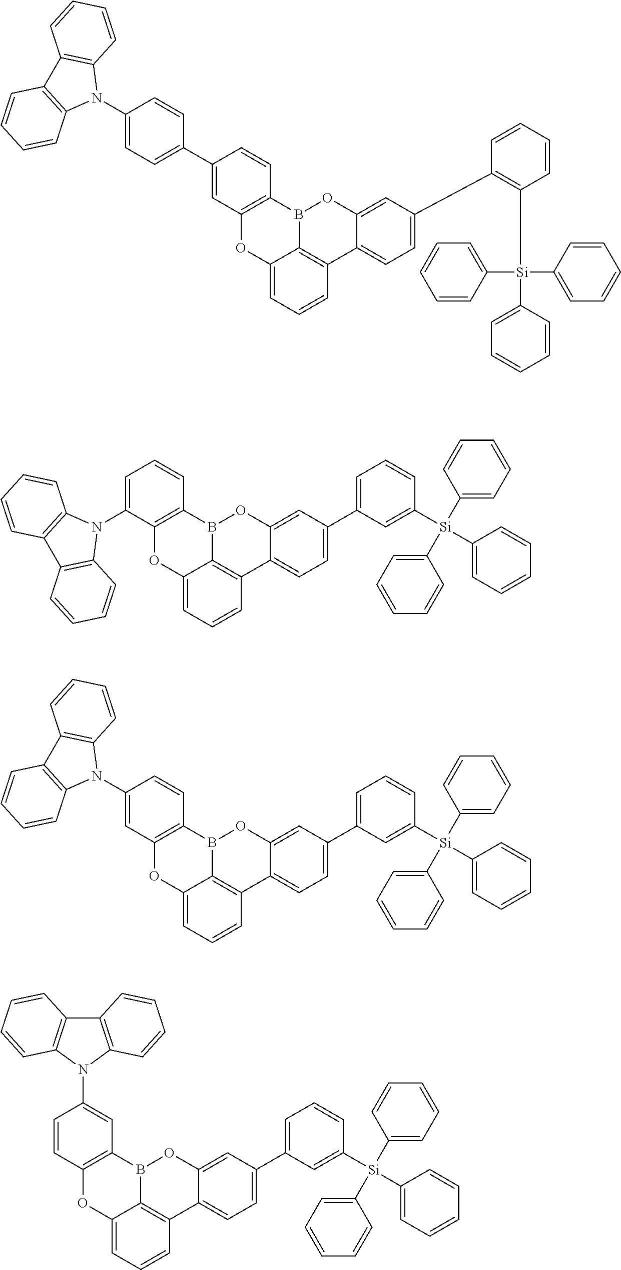 [SMILES: c1ccc([Si](c2ccccc2)(c2ccccc2)c2ccccc2-c2ccc3c(c2)OB2c4ccc(-c5ccc(-n6c7ccccc7c7ccccc76)cc5)cc4Oc4cccc-3c42)cc1 ; c1ccc([Si](c2ccccc2)(c2ccccc2)c2cccc(-c3ccc4c(c3)OB3c5cccc(-n6c7ccccc7c7ccccc76)c5Oc5cccc-4c53)c2)cc1 ; c1ccc([Si](c2ccccc2)(c2ccccc2)c2cccc(-c3ccc4c(c3)OB3c5ccc(-n6c7ccccc7c7ccccc76)cc5Oc5cccc-4c53)c2)cc1 ; c1ccc([Si](c2ccccc2)(c2ccccc2)c2cccc(-c3ccc4c(c3)OB3c5cc(-n6c7ccccc7c7ccccc76)ccc5Oc5cccc-4c53)c2)cc1]

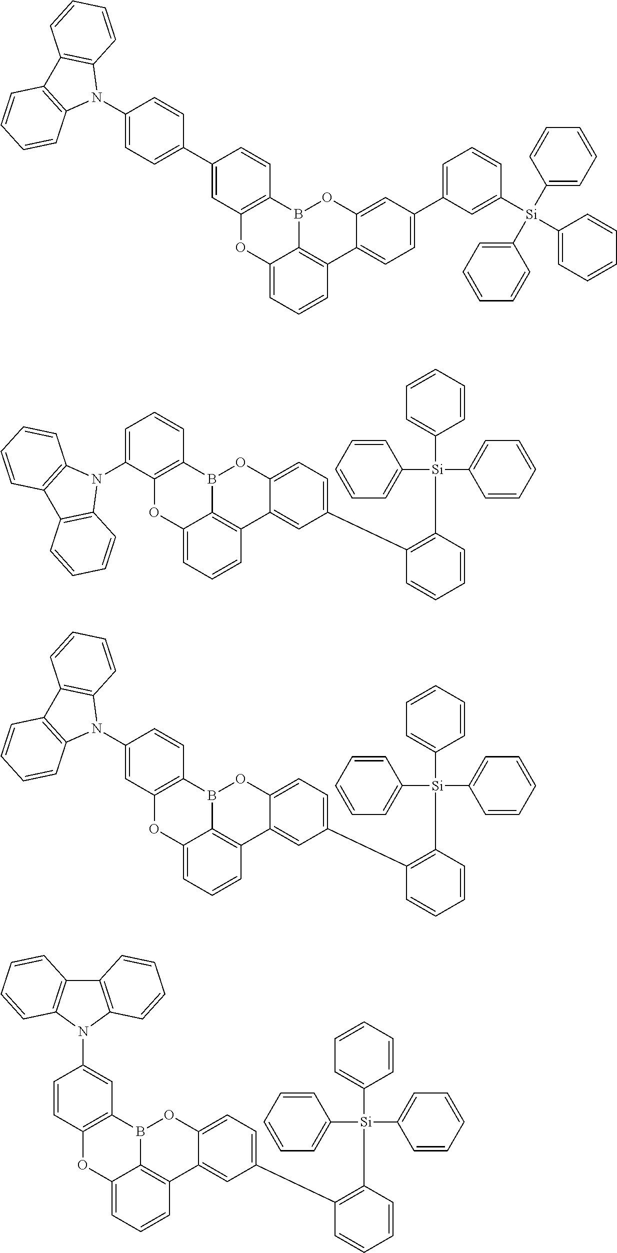 [SMILES: c1ccc([Si](c2ccccc2)(c2ccccc2)c2cccc(-c3ccc4c(c3)OB3c5ccc(-c6ccc(-n7c8ccccc8c8ccccc87)cc6)cc5Oc5cccc-4c53)c2)cc1 ; c1ccc([Si](c2ccccc2)(c2ccccc2)c2ccccc2-c2ccc3c(c2)-c2cccc4c2B(O3)c2cccc(-n3c5ccccc5c5ccccc53)c2O4)cc1 ; c1ccc([Si](c2ccccc2)(c2ccccc2)c2ccccc2-c2ccc3c(c2)-c2cccc4c2B(O3)c2ccc(-n3c5ccccc5c5ccccc53)cc2O4)cc1 ; c1ccc([Si](c2ccccc2)(c2ccccc2)c2ccccc2-c2ccc3c(c2)-c2cccc4c2B(O3)c2cc(-n3c5ccccc5c5ccccc53)ccc2O4)cc1]

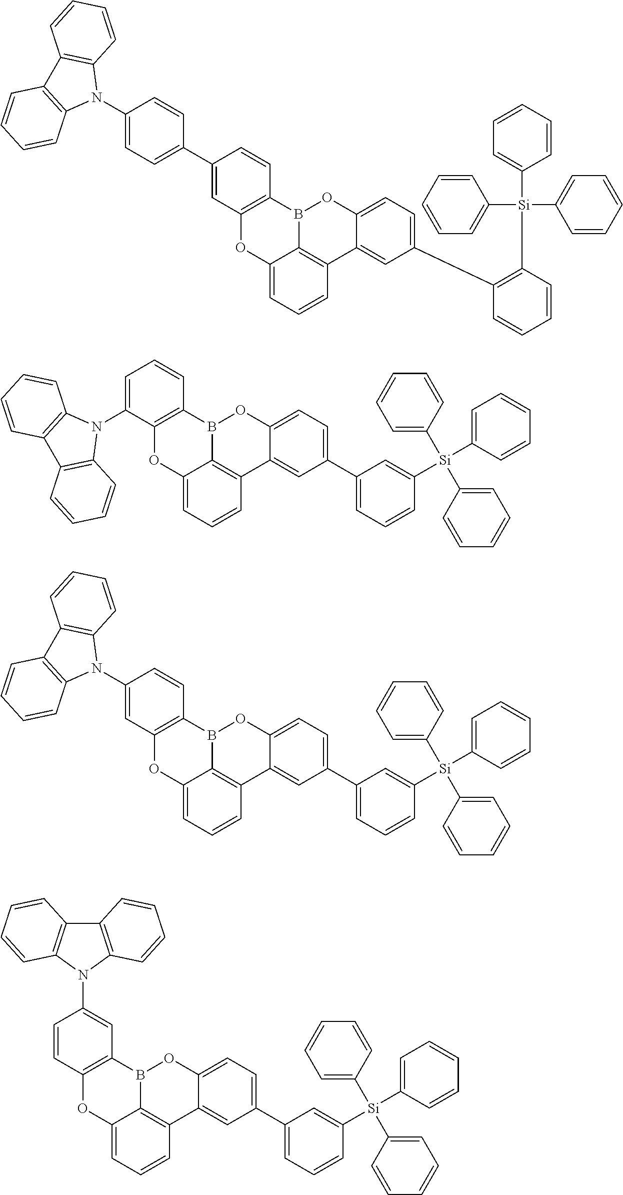 [SMILES: c1ccc([Si](c2ccccc2)(c2ccccc2)c2ccccc2-c2ccc3c(c2)-c2cccc4c2B(O3)c2ccc(-c3ccc(-n5c6ccccc6c6ccccc65)cc3)cc2O4)cc1 ; c1ccc([Si](c2ccccc2)(c2ccccc2)c2cccc(-c3ccc4c(c3)-c3cccc5c3B(O4)c3cccc(-n4c6ccccc6c6ccccc64)c3O5)c2)cc1 ; c1ccc([Si](c2ccccc2)(c2ccccc2)c2cccc(-c3ccc4c(c3)-c3cccc5c3B(O4)c3ccc(-n4c6ccccc6c6ccccc64)cc3O5)c2)cc1 ; c1ccc([Si](c2ccccc2)(c2ccccc2)c2cccc(-c3ccc4c(c3)-c3cccc5c3B(O4)c3cc(-n4c6ccccc6c6ccccc64)ccc3O5)c2)cc1]

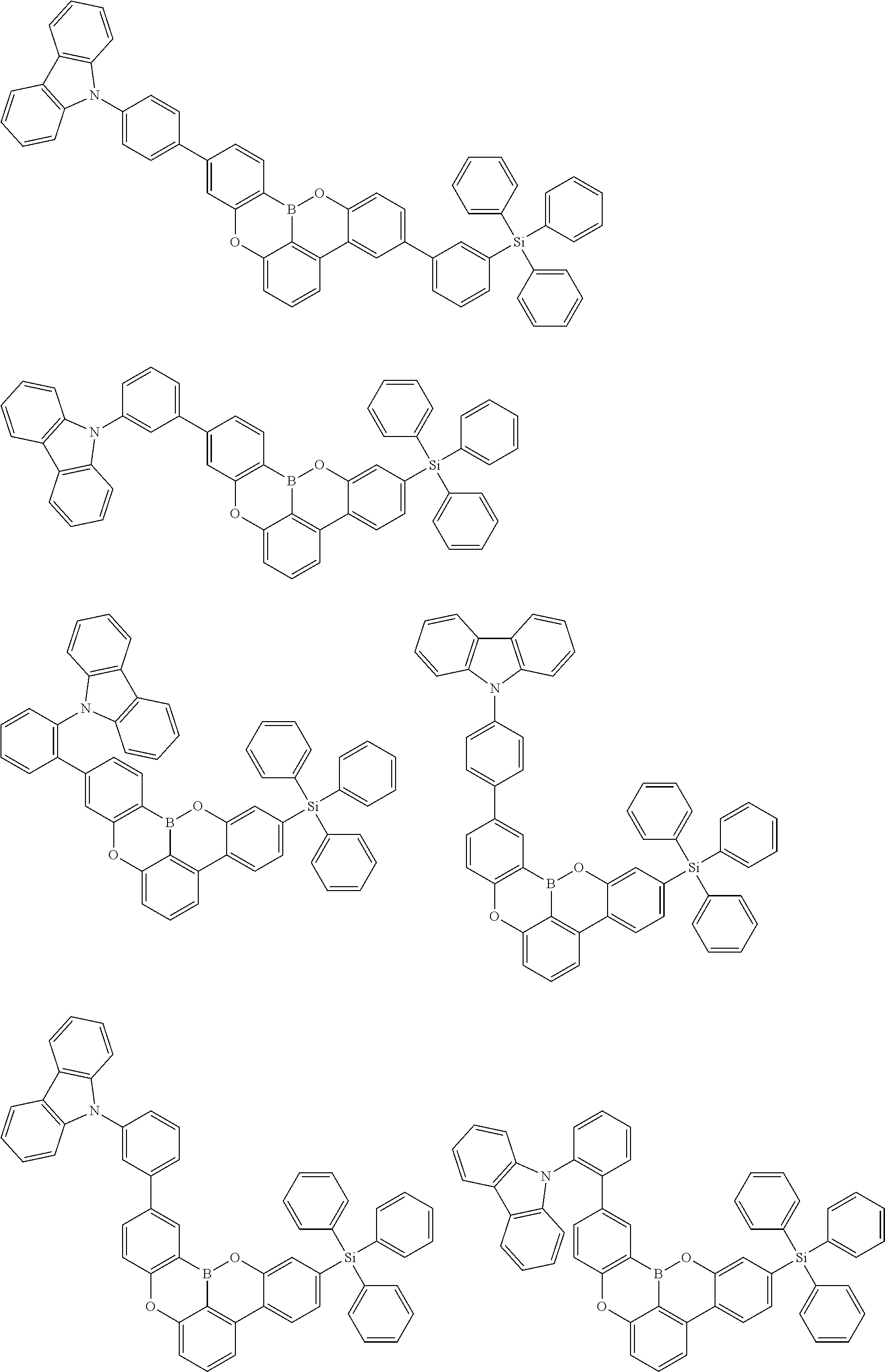

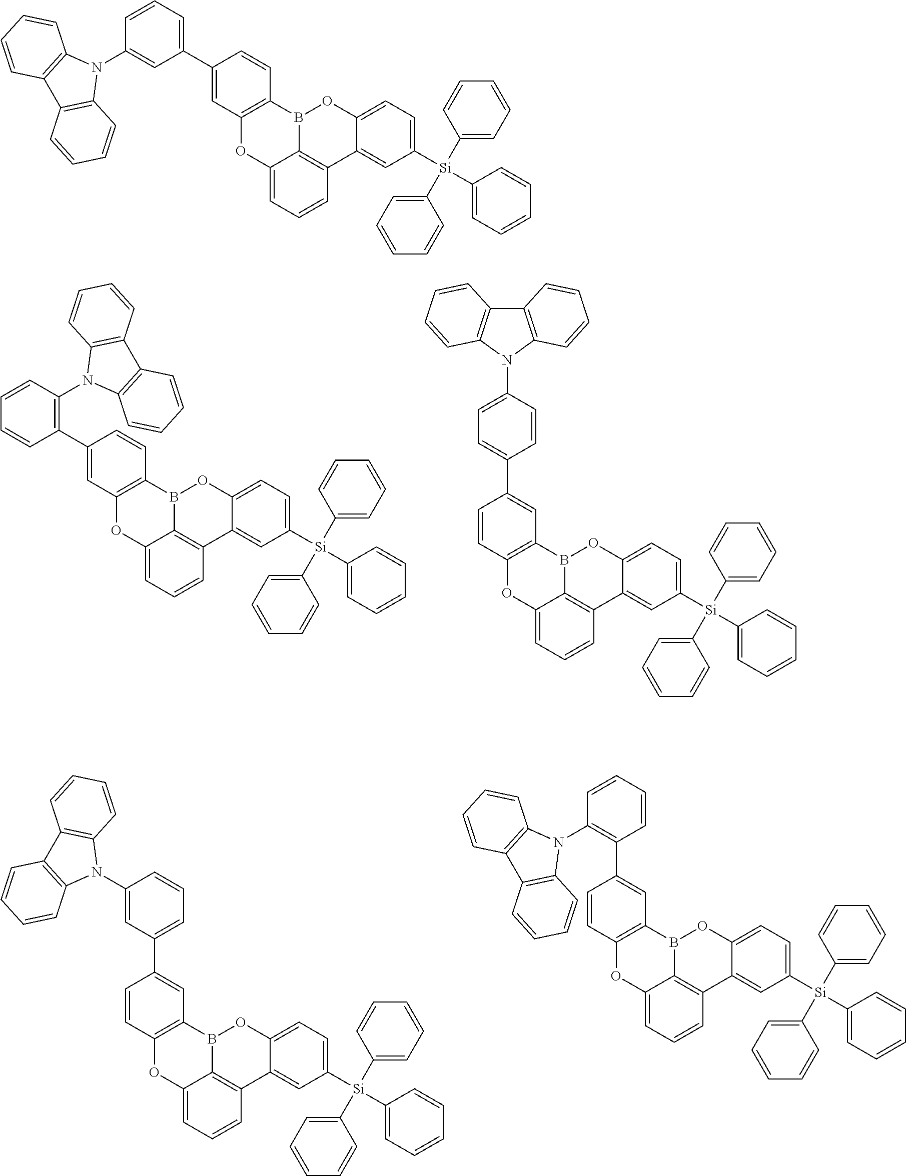

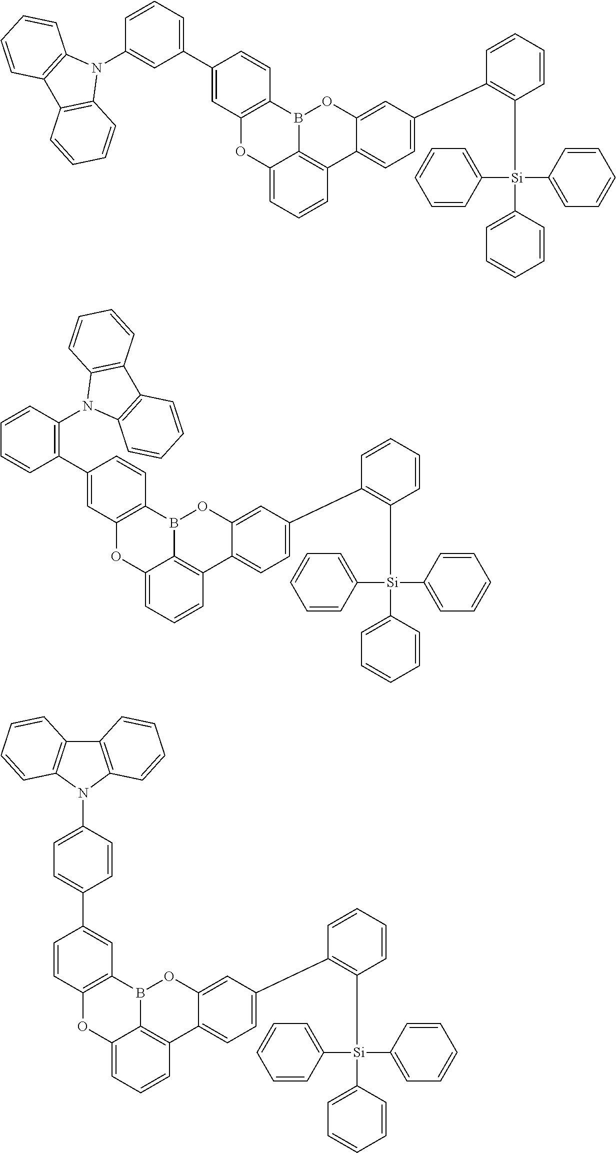 [SMILES: c1ccc([Si](c2ccccc2)(c2ccccc2)c2ccccc2-c2ccc3c(c2)OB2c4ccc(-c5cccc(-n6c7ccccc7c7ccccc76)c5)cc4Oc4cccc-3c42)cc1 ; c1ccc([Si](c2ccccc2)(c2ccccc2)c2ccccc2-c2ccc3c(c2)OB2c4ccc(-c5ccccc5-n5c6ccccc6c6ccccc65)cc4Oc4cccc-3c42)cc1 ; c1ccc([Si](c2ccccc2)(c2ccccc2)c2ccccc2-c2ccc3c(c2)OB2c4cc(-c5ccc(-n6c7ccccc7c7ccccc76)cc5)ccc4Oc4cccc-3c42)cc1]

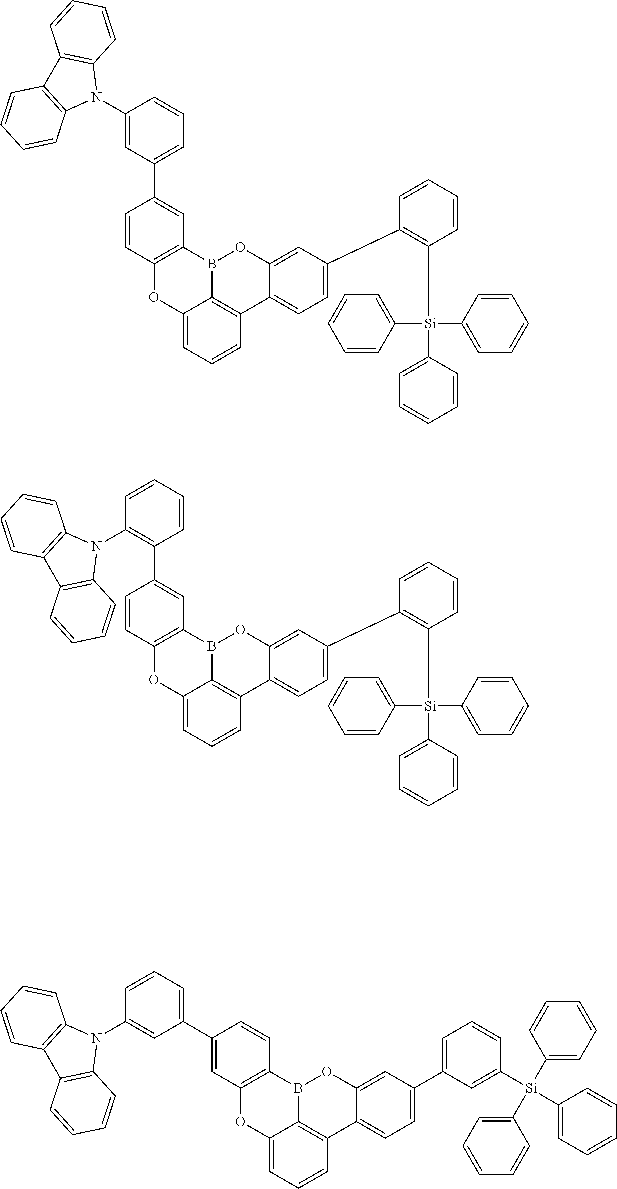 [SMILES: c1ccc([Si](c2ccccc2)(c2ccccc2)c2ccccc2-c2ccc3c(c2)OB2c4cc(-c5cccc(-n6c7ccccc7c7ccccc76)c5)ccc4Oc4cccc-3c42)cc1 ; c1ccc([Si](c2ccccc2)(c2ccccc2)c2ccccc2-c2ccc3c(c2)OB2c4cc(-c5ccccc5-n5c6ccccc6c6ccccc65)ccc4Oc4cccc-3c42)cc1 ; c1ccc([Si](c2ccccc2)(c2ccccc2)c2cccc(-c3ccc4c(c3)OB3c5ccc(-c6cccc(-n7c8ccccc8c8ccccc87)c6)cc5Oc5cccc-4c53)c2)cc1]

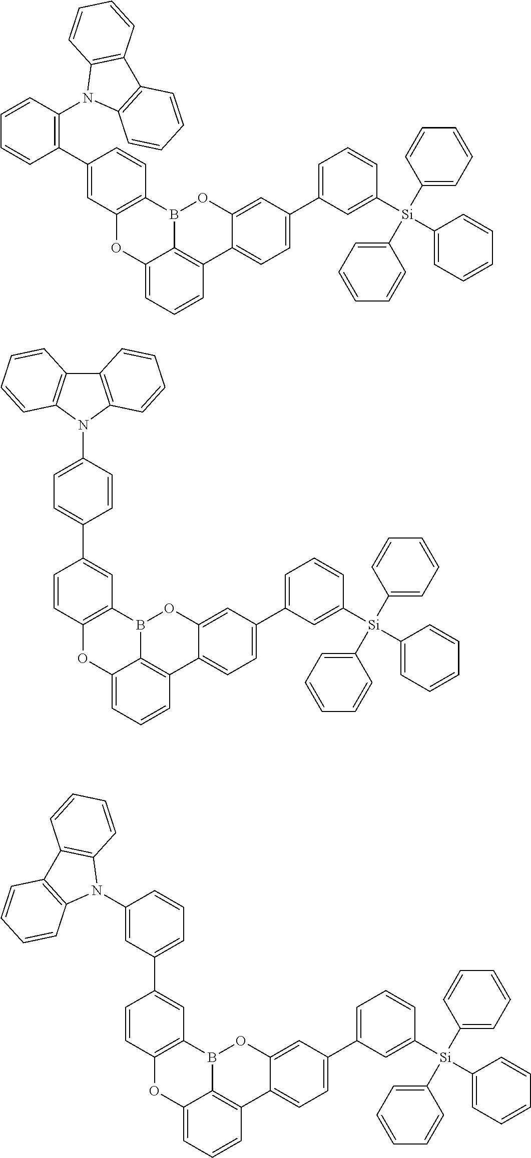

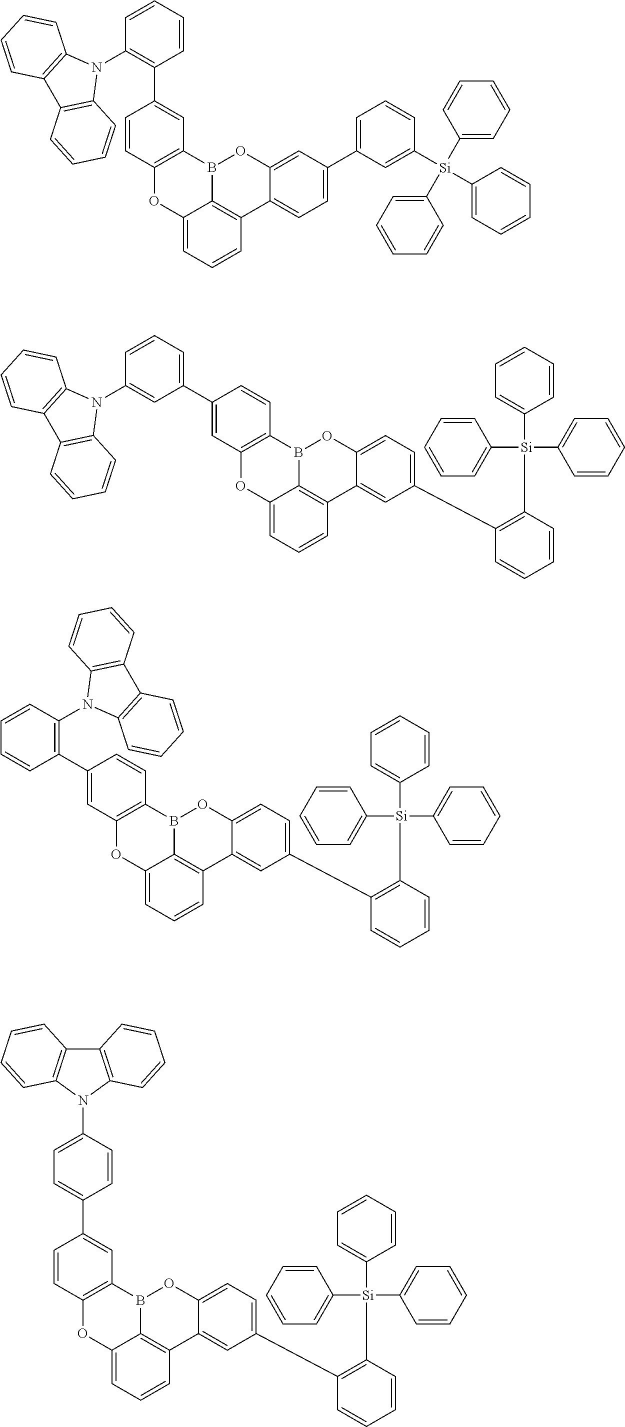 [SMILES: c1ccc([Si](c2ccccc2)(c2ccccc2)c2cccc(-c3ccc4c(c3)OB3c5cc(-c6ccccc6-n6c7ccccc7c7ccccc76)ccc5Oc5cccc-4c53)c2)cc1 ; c1ccc([Si](c2ccccc2)(c2ccccc2)c2ccccc2-c2ccc3c(c2)-c2cccc4c2B(O3)c2ccc(-c3cccc(-n5c6ccccc6c6ccccc65)c3)cc2O4)cc1 ; c1ccc([Si](c2ccccc2)(c2ccccc2)c2ccccc2-c2ccc3c(c2)-c2cccc4c2B(O3)c2ccc(-c3ccccc3-n3c5ccccc5c5ccccc53)cc2O4)cc1 ; c1ccc([Si](c2ccccc2)(c2ccccc2)c2ccccc2-c2ccc3c(c2)-c2cccc4c2B(O3)c2cc(-c3ccc(-n5c6ccccc6c6ccccc65)cc3)ccc2O4)cc1]

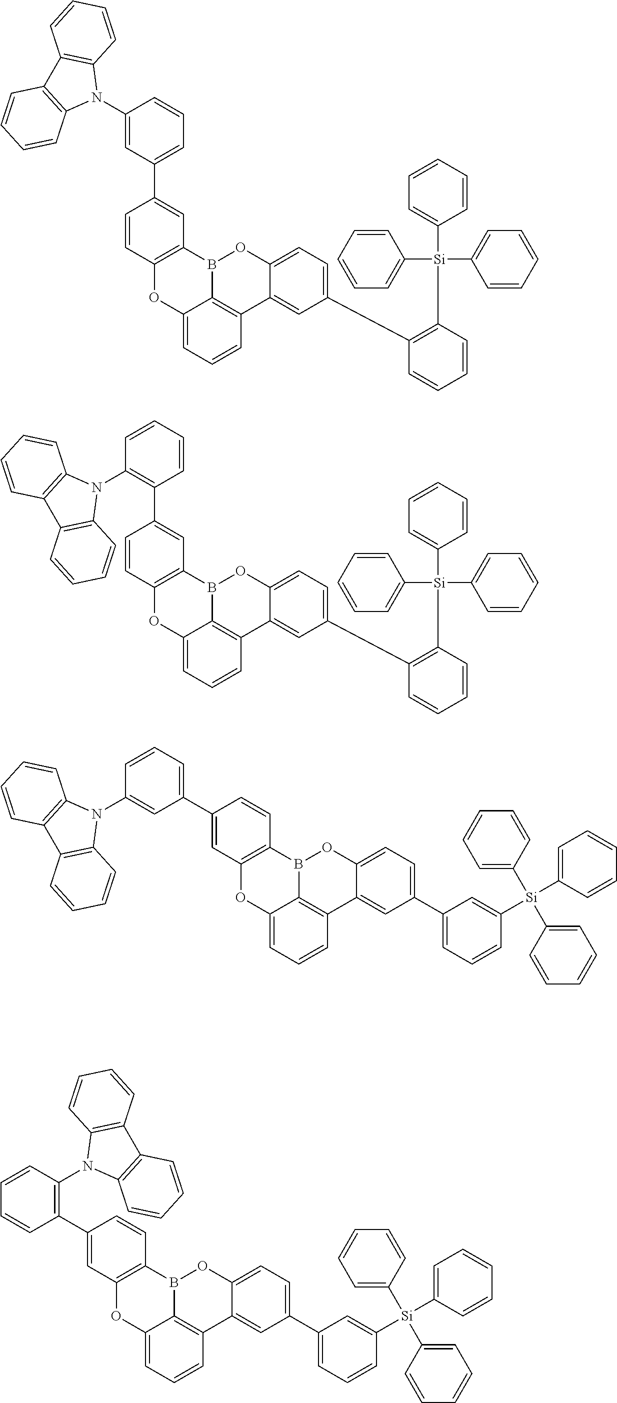 [SMILES: c1ccc([Si](c2ccccc2)(c2ccccc2)c2ccccc2-c2ccc3c(c2)-c2cccc4c2B(O3)c2cc(-c3cccc(-n5c6ccccc6c6ccccc65)c3)ccc2O4)cc1 ; c1ccc([Si](c2ccccc2)(c2ccccc2)c2ccccc2-c2ccc3c(c2)-c2cccc4c2B(O3)c2cc(-c3ccccc3-n3c5ccccc5c5ccccc53)ccc2O4)cc1 ; c1ccc([Si](c2ccccc2)(c2ccccc2)c2cccc(-c3ccc4c(c3)-c3cccc5c3B(O4)c3ccc(-c4cccc(-n6c7ccccc7c7ccccc76)c4)cc3O5)c2)cc1 ; c1ccc([Si](c2ccccc2)(c2ccccc2)c2cccc(-c3ccc4c(c3)-c3cccc5c3B(O4)c3ccc(-c4ccccc4-n4c6ccccc6c6ccccc64)cc3O5)c2)cc1]

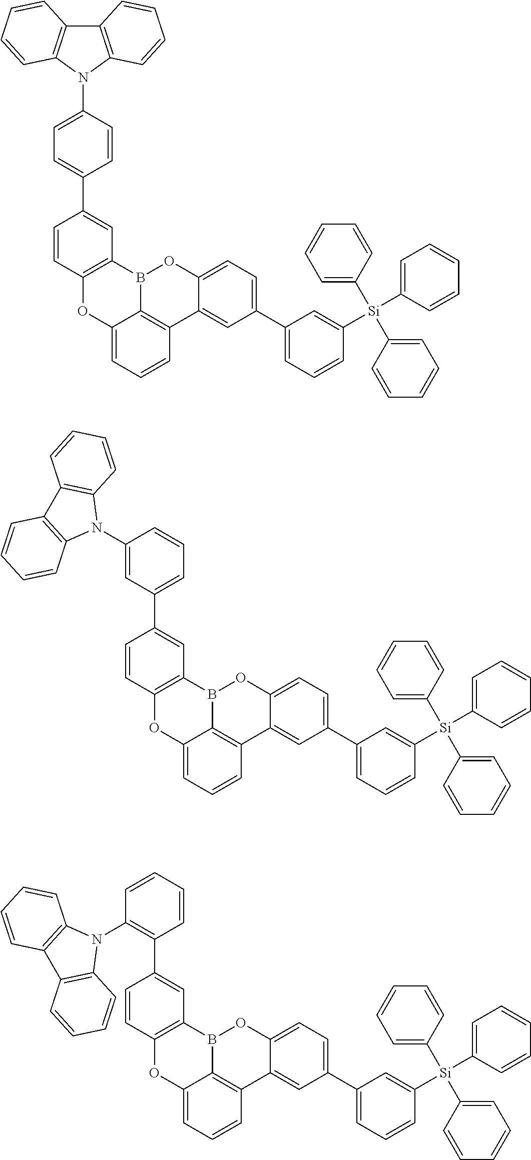 [SMILES: c1ccc([Si](c2ccccc2)(c2ccccc2)c2cccc(-c3ccc4c(c3)-c3cccc5c3B(O4)c3cc(-c4ccc(-n6c7ccccc7c7ccccc76)cc4)ccc3O5)c2)cc1 ; c1ccc([Si](c2ccccc2)(c2ccccc2)c2cccc(-c3ccc4c(c3)-c3cccc5c3B(O4)c3cc(-c4cccc(-n6c7ccccc7c7ccccc76)c4)ccc3O5)c2)cc1 ; c1ccc([Si](c2ccccc2)(c2ccccc2)c2cccc(-c3ccc4c(c3)-c3cccc5c3B(O4)c3cc(-c4ccccc4-n4c6ccccc6c6ccccc64)ccc3O5)c2)cc1]

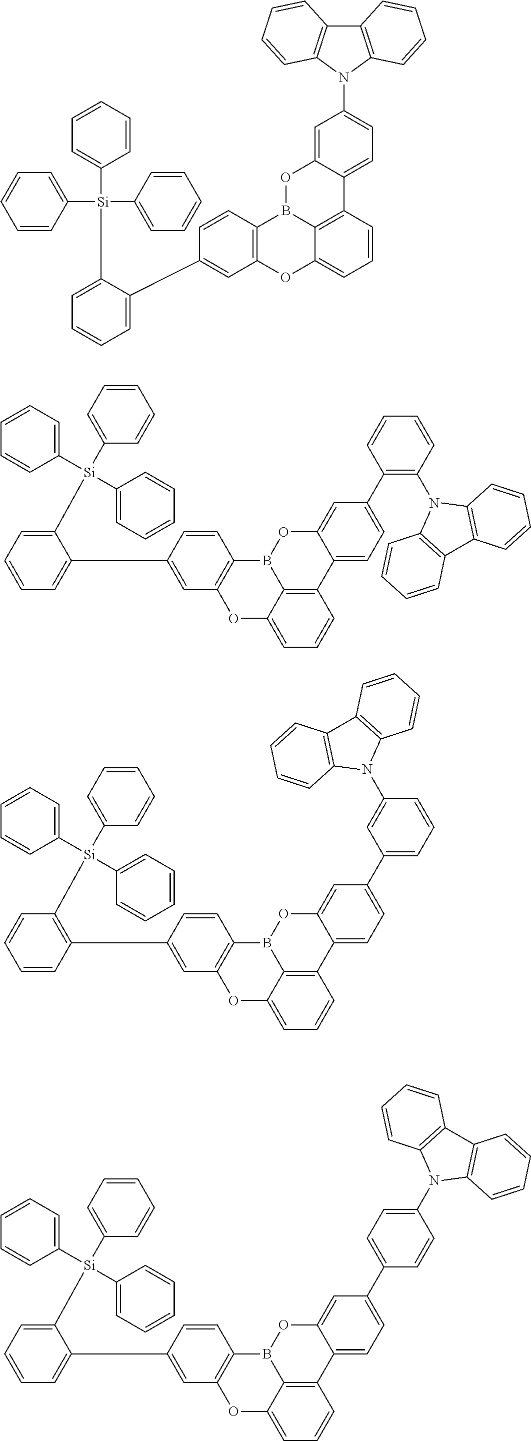

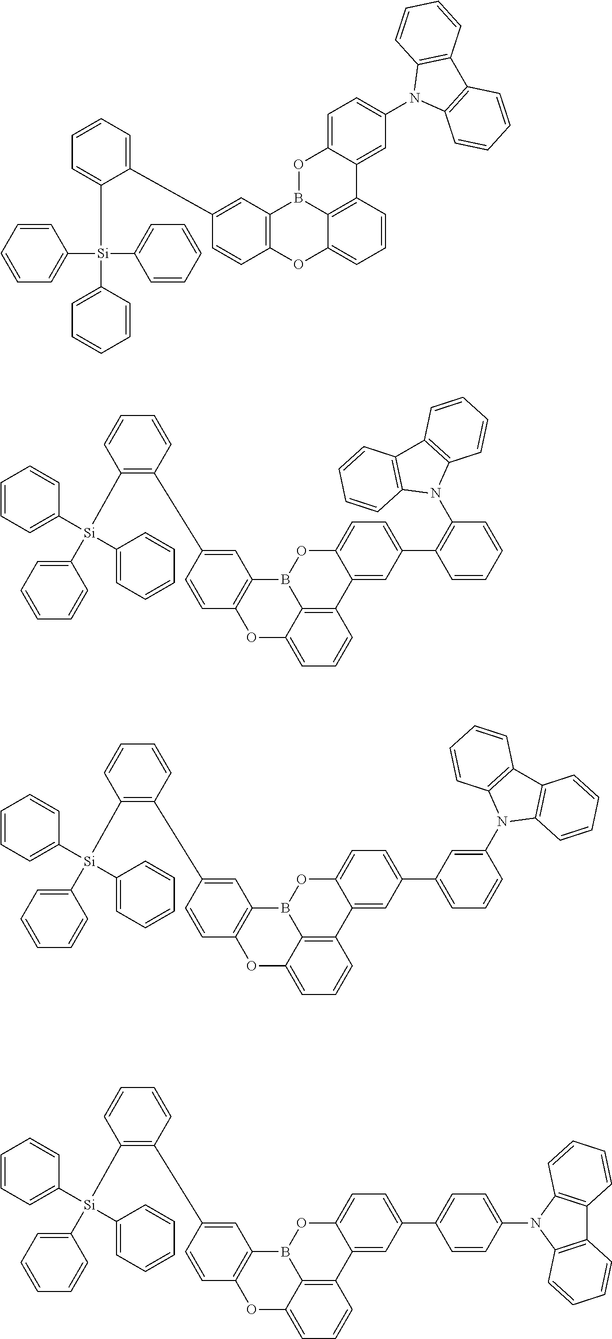 [SMILES: c1ccc([Si](c2ccccc2)(c2ccccc2)c2ccccc2-c2ccc3c(c2)B2Oc4ccc(-n5c6ccccc6c6ccccc65)cc4-c4cccc(c42)O3)cc1 ; c1ccc([Si](c2ccccc2)(c2ccccc2)c2ccccc2-c2ccc3c(c2)B2Oc4ccc(-c5ccccc5-n5c6ccccc6c6ccccc65)cc4-c4cccc(c42)O3)cc1 ; c1ccc([Si](c2ccccc2)(c2ccccc2)c2ccccc2-c2ccc3c(c2)B2Oc4ccc(-c5cccc(-n6c7ccccc7c7ccccc76)c5)cc4-c4cccc(c42)O3)cc1 ; c1ccc([Si](c2ccccc2)(c2ccccc2)c2ccccc2-c2ccc3c(c2)B2Oc4ccc(-c5ccc(-n6c7ccccc7c7ccccc76)cc5)cc4-c4cccc(c42)O3)cc1]

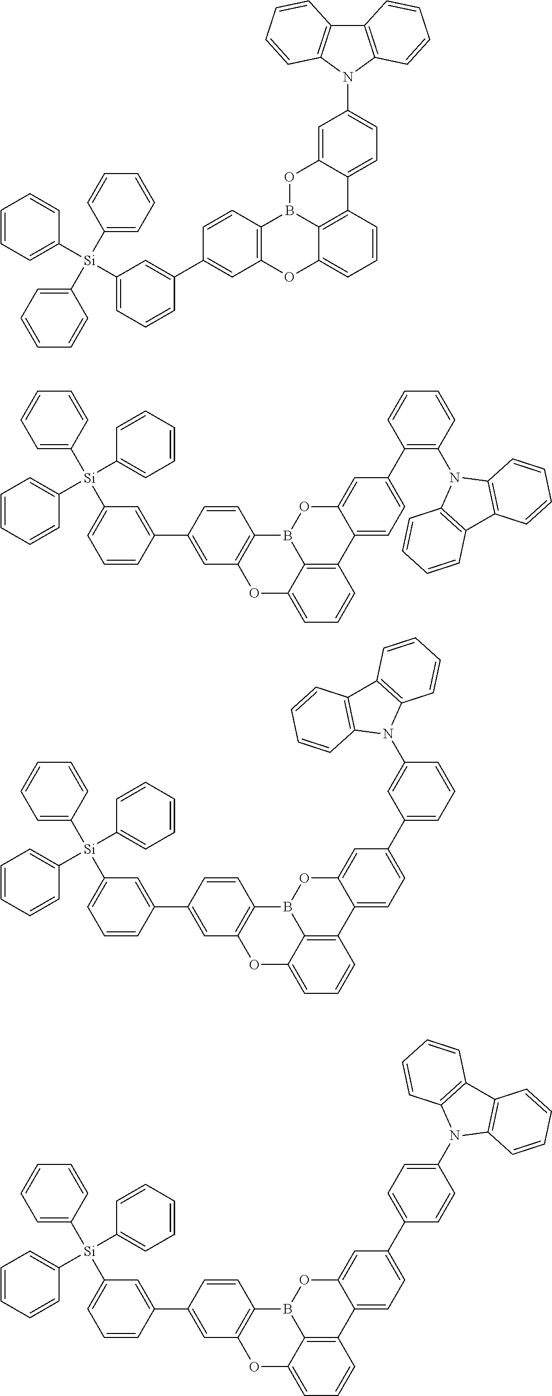

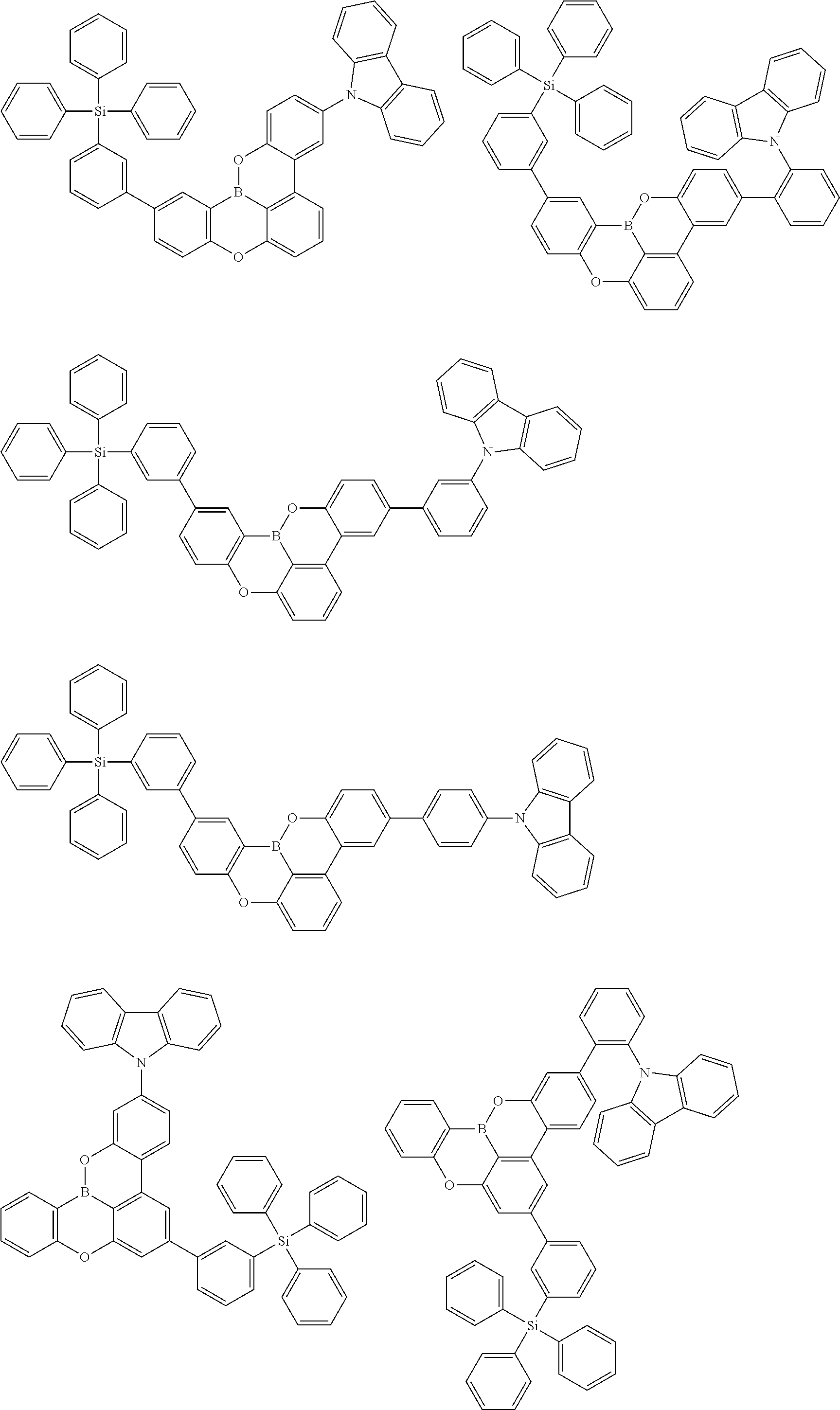

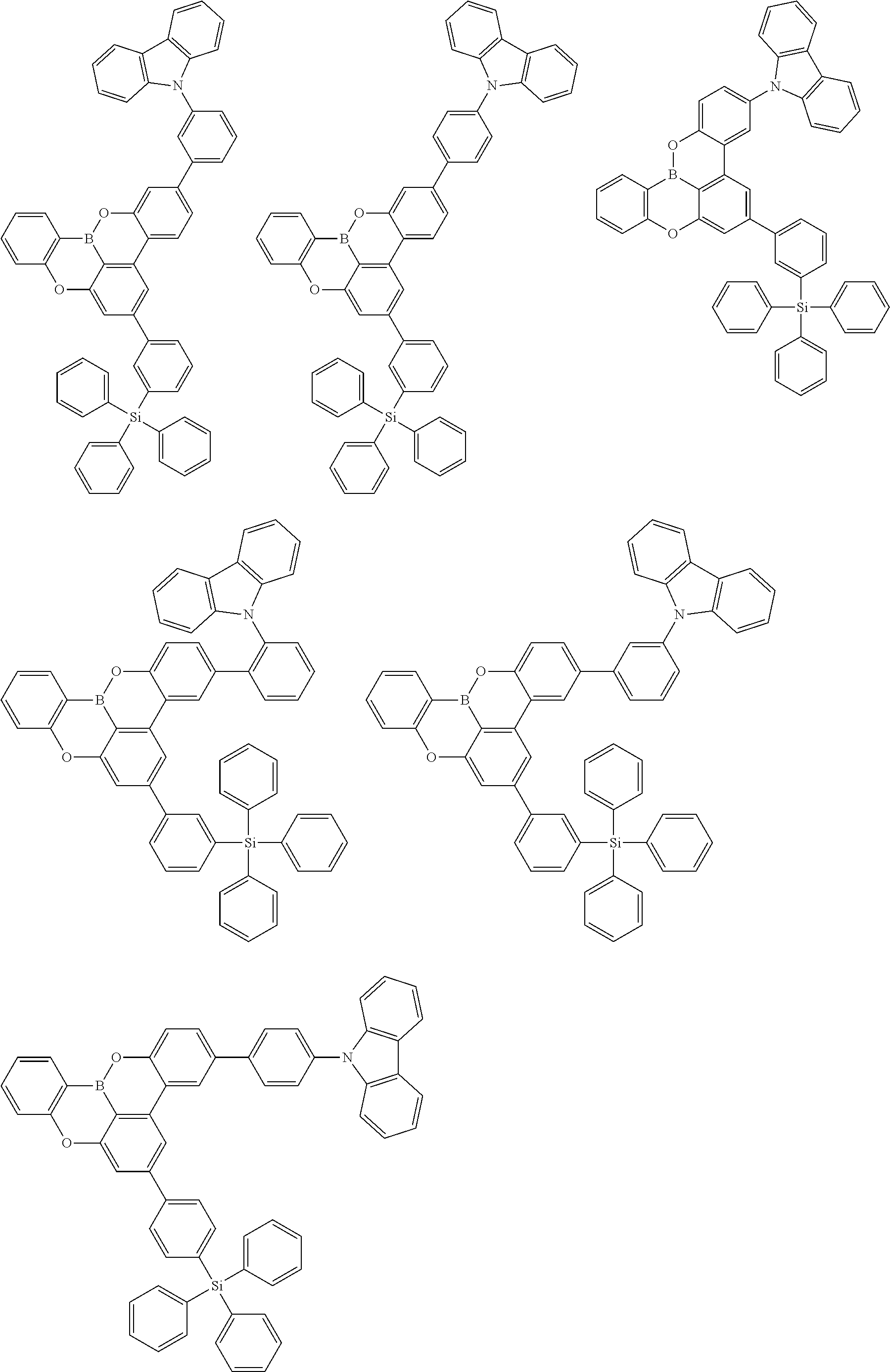

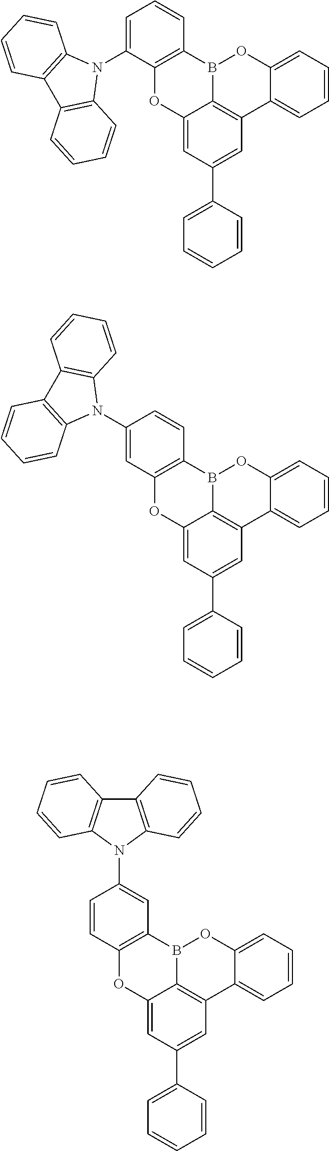 [SMILES: c1ccc(-c2cc3c4c(c2)-c2ccccc2OB4c2cccc(-n4c5ccccc5c5ccccc54)c2O3)cc1 ; c1ccc(-c2cc3c4c(c2)-c2ccccc2OB4c2ccc(-n4c5ccccc5c5ccccc54)cc2O3)cc1 ; c1ccc(-c2cc3c4c(c2)-c2ccccc2OB4c2cc(-n4c5ccccc5c5ccccc54)ccc2O3)cc1]

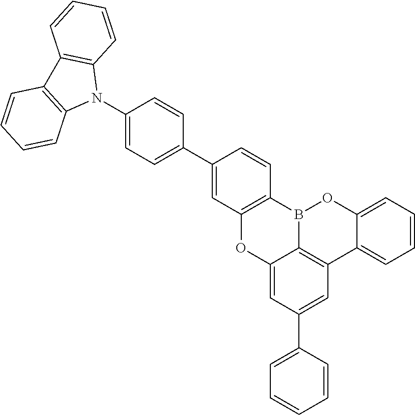 [SMILES: c1ccc(-c2cc3c4c(c2)-c2ccccc2OB4c2ccc(-c4ccc(-n5c6ccccc6c6ccccc65)cc4)cc2O3)cc1]

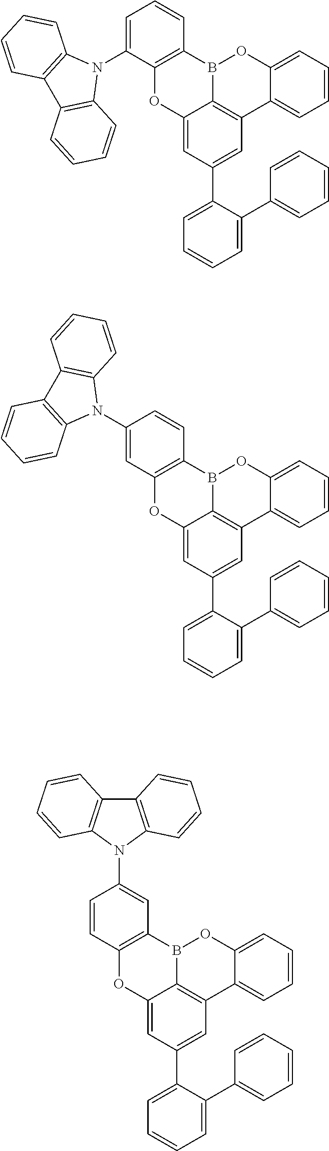 [SMILES: c1ccc(-c2ccccc2-c2cc3c4c(c2)-c2ccccc2OB4c2cccc(-n4c5ccccc5c5ccccc54)c2O3)cc1 ; c1ccc(-c2ccccc2-c2cc3c4c(c2)-c2ccccc2OB4c2ccc(-n4c5ccccc5c5ccccc54)cc2O3)cc1 ; c1ccc(-c2ccccc2-c2cc3c4c(c2)-c2ccccc2OB4c2cc(-n4c5ccccc5c5ccccc54)ccc2O3)cc1]

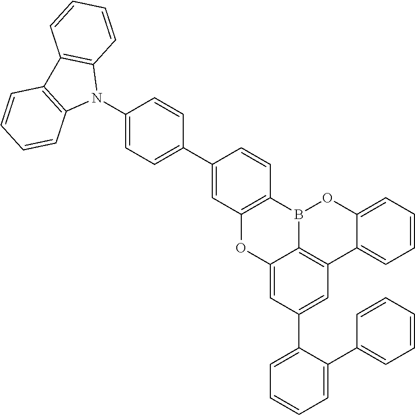 [SMILES: c1ccc(-c2ccccc2-c2cc3c4c(c2)-c2ccccc2OB4c2ccc(-c4ccc(-n5c6ccccc6c6ccccc65)cc4)cc2O3)cc1]

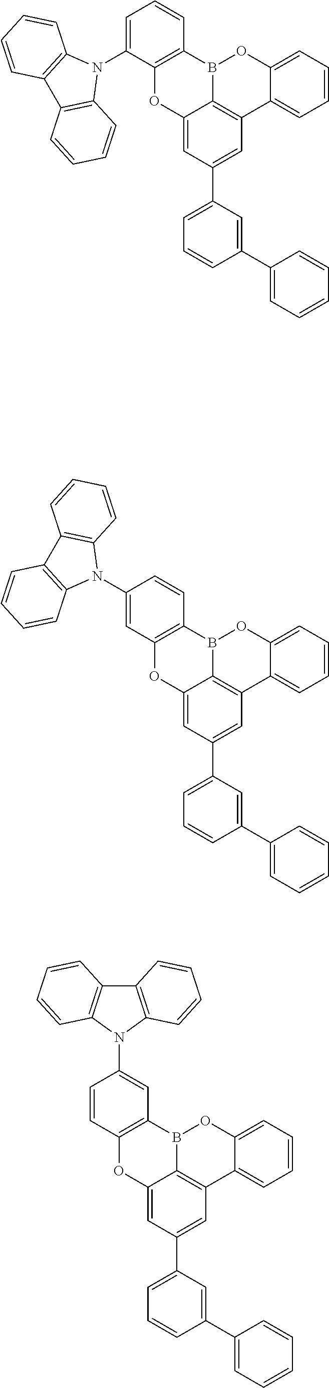 [SMILES: c1ccc(-c2cccc(-c3cc4c5c(c3)-c3ccccc3OB5c3cccc(-n5c6ccccc6c6ccccc65)c3O4)c2)cc1 ; c1ccc(-c2cccc(-c3cc4c5c(c3)-c3ccccc3OB5c3ccc(-n5c6ccccc6c6ccccc65)cc3O4)c2)cc1 ; c1ccc(-c2cccc(-c3cc4c5c(c3)-c3ccccc3OB5c3cc(-n5c6ccccc6c6ccccc65)ccc3O4)c2)cc1]

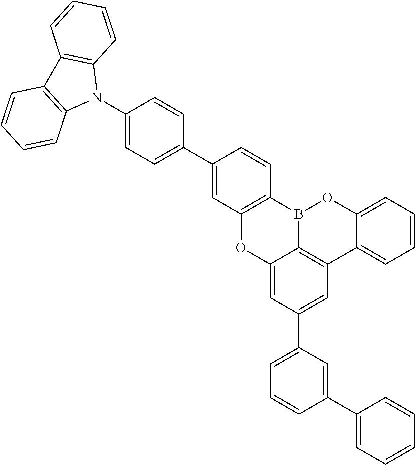 [SMILES: c1ccc(-c2cccc(-c3cc4c5c(c3)-c3ccccc3OB5c3ccc(-c5ccc(-n6c7ccccc7c7ccccc76)cc5)cc3O4)c2)cc1]

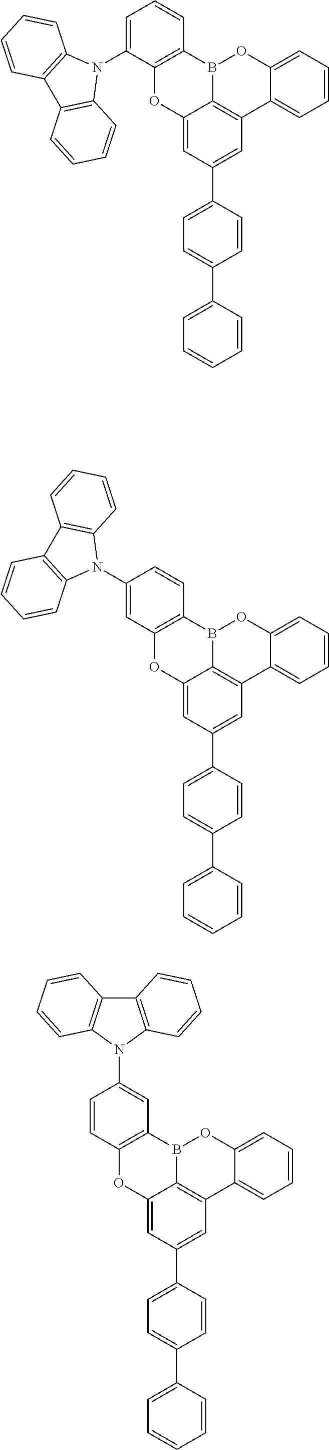 [SMILES: c1ccc(-c2ccc(-c3cc4c5c(c3)-c3ccccc3OB5c3cccc(-n5c6ccccc6c6ccccc65)c3O4)cc2)cc1 ; c1ccc(-c2ccc(-c3cc4c5c(c3)-c3ccccc3OB5c3ccc(-n5c6ccccc6c6ccccc65)cc3O4)cc2)cc1 ; c1ccc(-c2ccc(-c3cc4c5c(c3)-c3ccccc3OB5c3cc(-n5c6ccccc6c6ccccc65)ccc3O4)cc2)cc1]

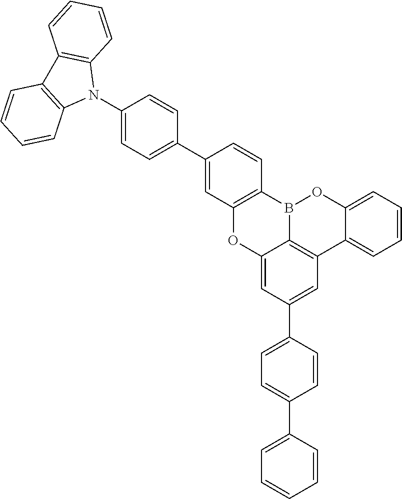 [SMILES: c1ccc(-c2ccc(-c3cc4c5c(c3)-c3ccccc3OB5c3ccc(-c5ccc(-n6c7ccccc7c7ccccc76)cc5)cc3O4)cc2)cc1]

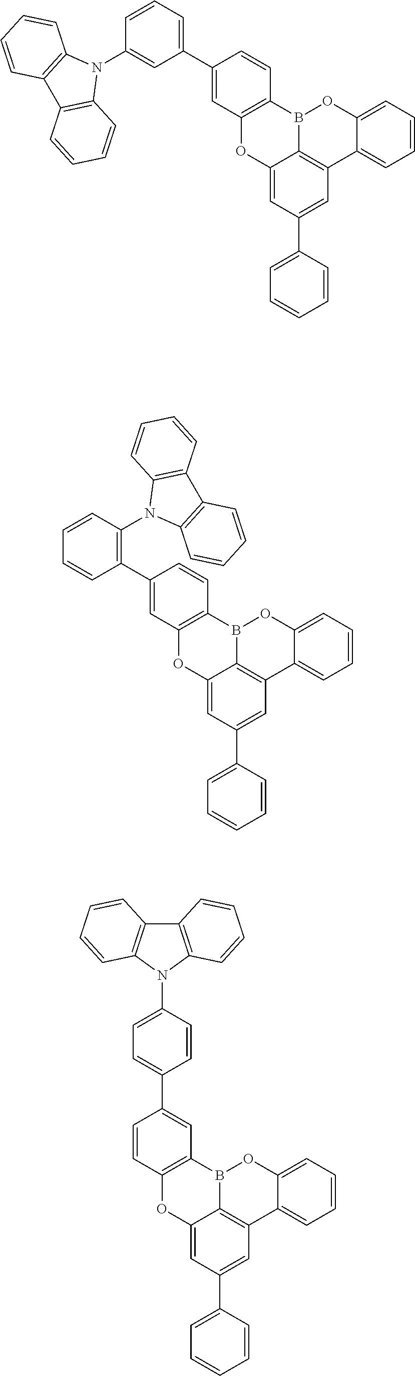 [SMILES: c1ccc(-c2cc3c4c(c2)-c2ccccc2OB4c2ccc(-c4cccc(-n5c6ccccc6c6ccccc65)c4)cc2O3)cc1 ; c1ccc(-c2cc3c4c(c2)-c2ccccc2OB4c2ccc(-c4ccccc4-n4c5ccccc5c5ccccc54)cc2O3)cc1 ; c1ccc(-c2cc3c4c(c2)-c2ccccc2OB4c2cc(-c4ccc(-n5c6ccccc6c6ccccc65)cc4)ccc2O3)cc1]

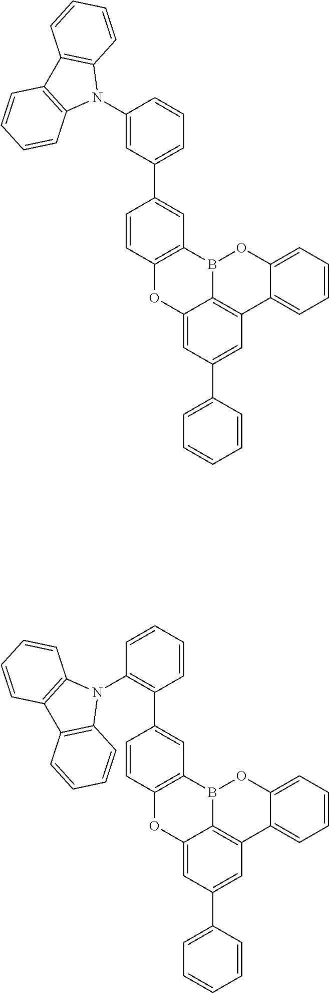 [SMILES: c1ccc(-c2cc3c4c(c2)-c2ccccc2OB4c2cc(-c4cccc(-n5c6ccccc6c6ccccc65)c4)ccc2O3)cc1 ; c1ccc(-c2cc3c4c(c2)-c2ccccc2OB4c2cc(-c4ccccc4-n4c5ccccc5c5ccccc54)ccc2O3)cc1]

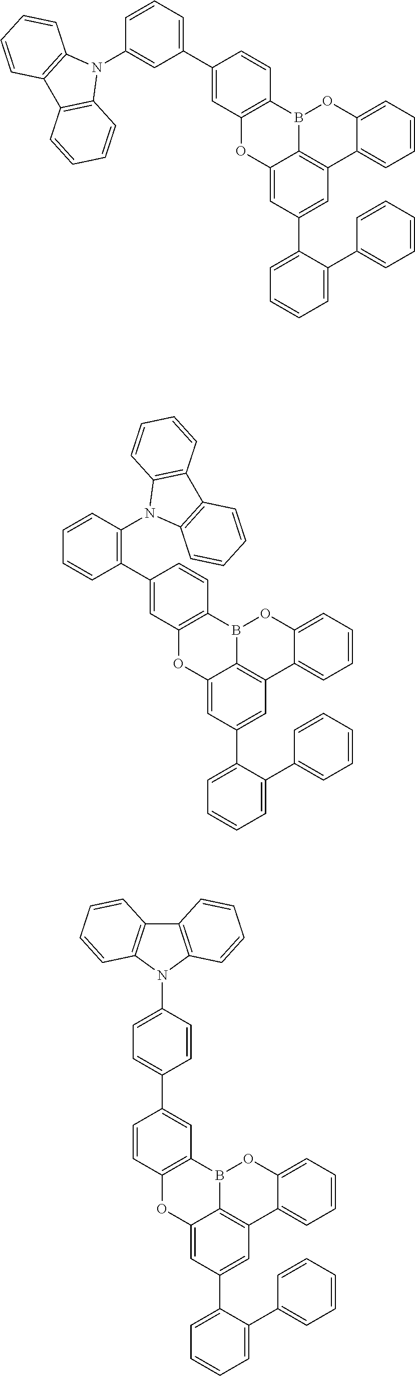 [SMILES: c1ccc(-c2ccccc2-c2cc3c4c(c2)-c2ccccc2OB4c2ccc(-c4cccc(-n5c6ccccc6c6ccccc65)c4)cc2O3)cc1 ; c1ccc(-c2ccccc2-c2cc3c4c(c2)-c2ccccc2OB4c2ccc(-c4ccccc4-n4c5ccccc5c5ccccc54)cc2O3)cc1 ; c1ccc(-c2ccccc2-c2cc3c4c(c2)-c2ccccc2OB4c2cc(-c4ccc(-n5c6ccccc6c6ccccc65)cc4)ccc2O3)cc1]

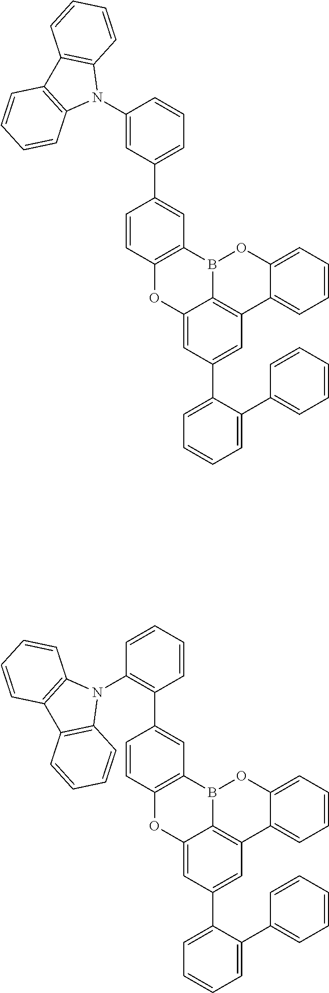 [SMILES: c1ccc(-c2ccccc2-c2cc3c4c(c2)-c2ccccc2OB4c2cc(-c4cccc(-n5c6ccccc6c6ccccc65)c4)ccc2O3)cc1 ; c1ccc(-c2ccccc2-c2cc3c4c(c2)-c2ccccc2OB4c2cc(-c4ccccc4-n4c5ccccc5c5ccccc54)ccc2O3)cc1]

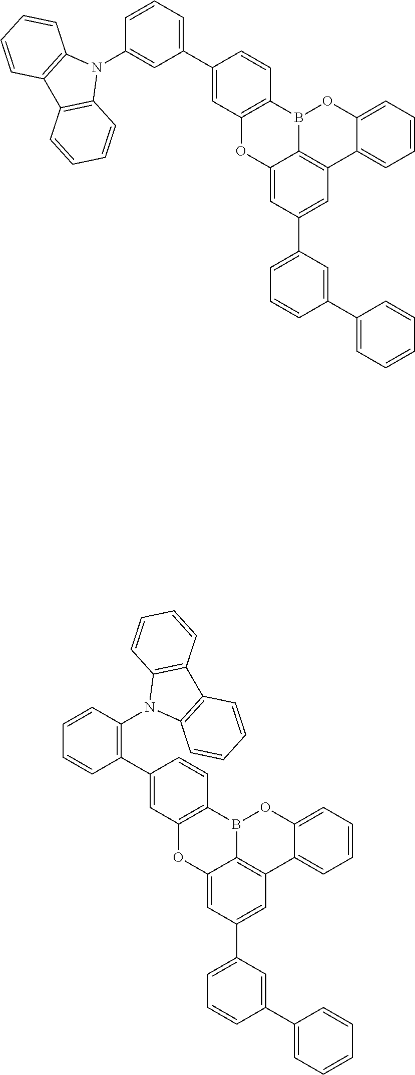 [SMILES: c1ccc(-c2cccc(-c3cc4c5c(c3)-c3ccccc3OB5c3ccc(-c5cccc(-n6c7ccccc7c7ccccc76)c5)cc3O4)c2)cc1 ; c1ccc(-c2cccc(-c3cc4c5c(c3)-c3ccccc3OB5c3ccc(-c5ccccc5-n5c6ccccc6c6ccccc65)cc3O4)c2)cc1]

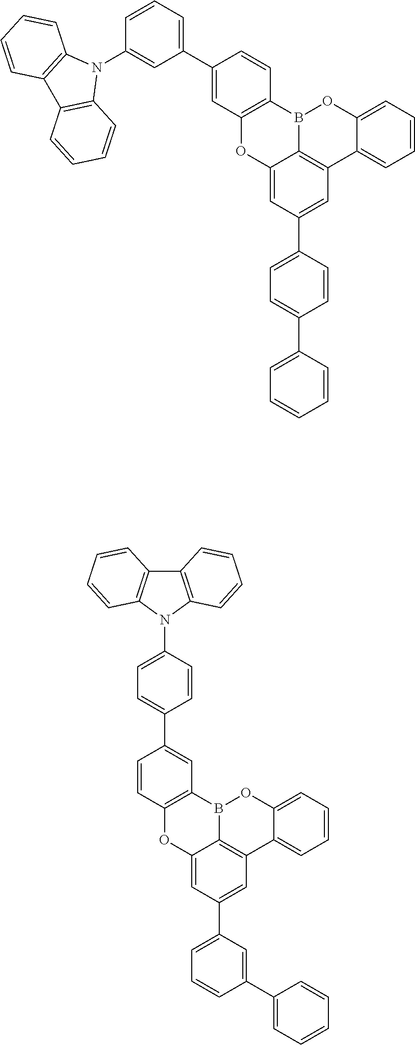 [SMILES: c1ccc(-c2ccc(-c3cc4c5c(c3)-c3ccccc3OB5c3ccc(-c5cccc(-n6c7ccccc7c7ccccc76)c5)cc3O4)cc2)cc1 ; c1ccc(-c2cccc(-c3cc4c5c(c3)-c3ccccc3OB5c3cc(-c5ccc(-n6c7ccccc7c7ccccc76)cc5)ccc3O4)c2)cc1]

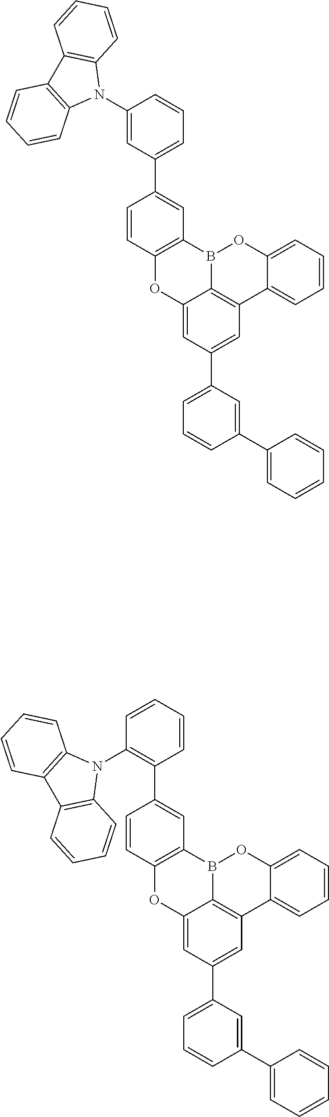 [SMILES: c1ccc(-c2cccc(-c3cc4c5c(c3)-c3ccccc3OB5c3cc(-c5cccc(-n6c7ccccc7c7ccccc76)c5)ccc3O4)c2)cc1 ; c1ccc(-c2cccc(-c3cc4c5c(c3)-c3ccccc3OB5c3cc(-c5ccccc5-n5c6ccccc6c6ccccc65)ccc3O4)c2)cc1]

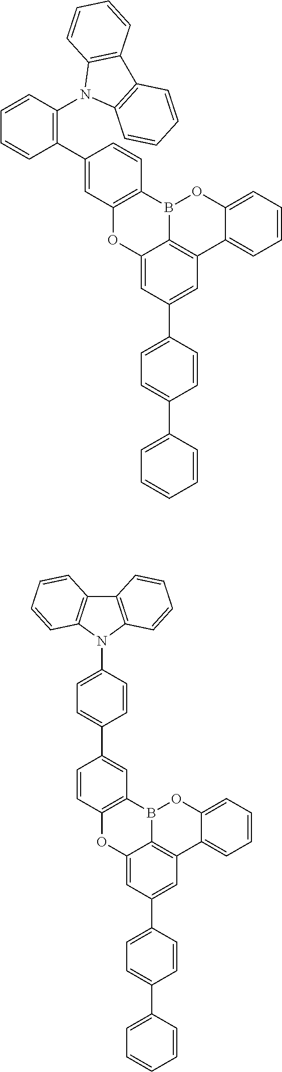 [SMILES: c1ccc(-c2ccc(-c3cc4c5c(c3)-c3ccccc3OB5c3ccc(-c5ccccc5-n5c6ccccc6c6ccccc65)cc3O4)cc2)cc1 ; c1ccc(-c2ccc(-c3cc4c5c(c3)-c3ccccc3OB5c3cc(-c5ccc(-n6c7ccccc7c7ccccc76)cc5)ccc3O4)cc2)cc1]

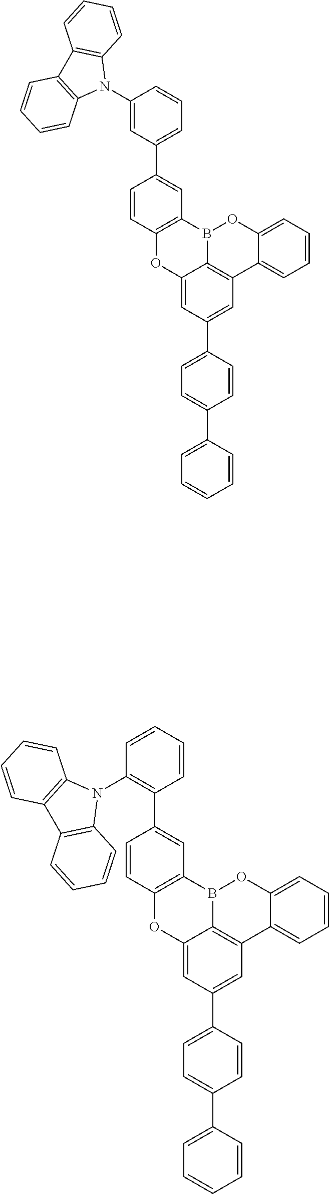 [SMILES: c1ccc(-c2ccc(-c3cc4c5c(c3)-c3ccccc3OB5c3cc(-c5cccc(-n6c7ccccc7c7ccccc76)c5)ccc3O4)cc2)cc1 ; c1ccc(-c2ccc(-c3cc4c5c(c3)-c3ccccc3OB5c3cc(-c5ccccc5-n5c6ccccc6c6ccccc65)ccc3O4)cc2)cc1]

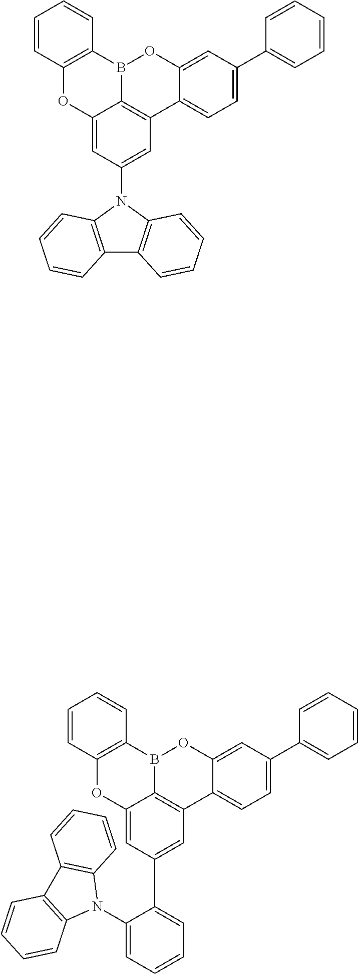 [SMILES: c1ccc(-c2ccc3c(c2)OB2c4ccccc4Oc4cc(-n5c6ccccc6c6ccccc65)cc-3c42)cc1 ; c1ccc(-c2ccc3c(c2)OB2c4ccccc4Oc4cc(-c5ccccc5-n5c6ccccc6c6ccccc65)cc-3c42)cc1]

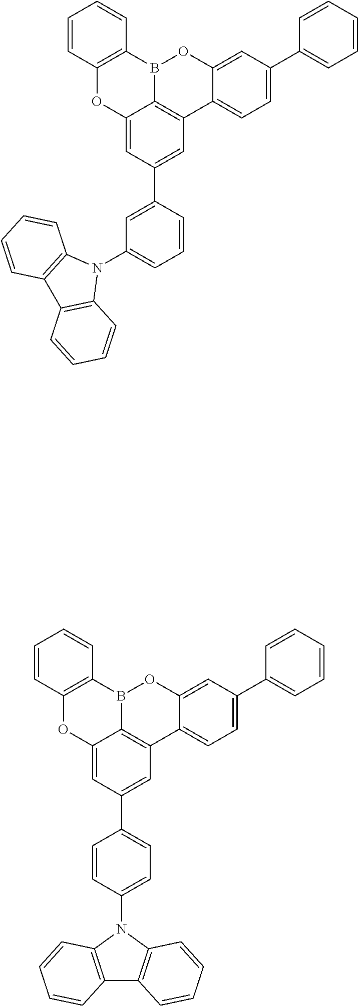 [SMILES: c1ccc(-c2ccc3c(c2)OB2c4ccccc4Oc4cc(-c5cccc(-n6c7ccccc7c7ccccc76)c5)cc-3c42)cc1 ; c1ccc(-c2ccc3c(c2)OB2c4ccccc4Oc4cc(-c5ccc(-n6c7ccccc7c7ccccc76)cc5)cc-3c42)cc1]

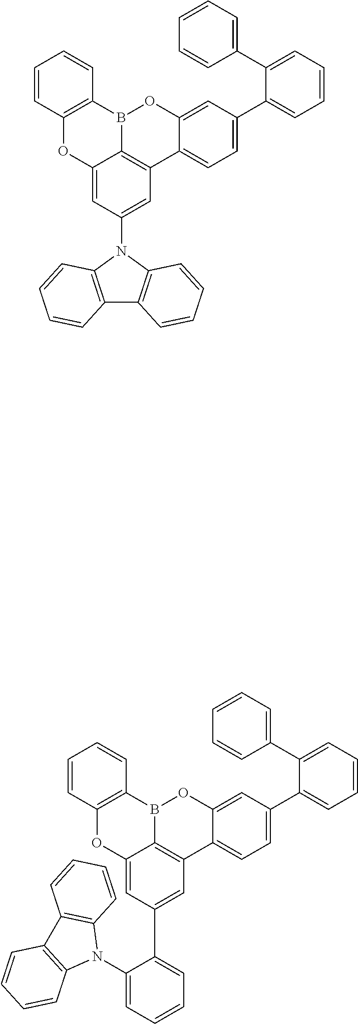 [SMILES: c1ccc(-c2ccccc2-c2ccc3c(c2)OB2c4ccccc4Oc4cc(-n5c6ccccc6c6ccccc65)cc-3c42)cc1 ; c1ccc(-c2ccccc2-c2ccc3c(c2)OB2c4ccccc4Oc4cc(-c5ccccc5-n5c6ccccc6c6ccccc65)cc-3c42)cc1]

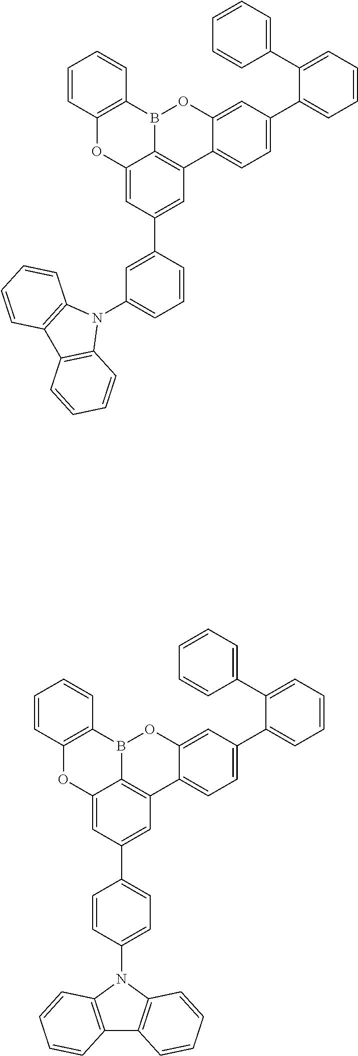 [SMILES: c1ccc(-c2ccccc2-c2ccc3c(c2)OB2c4ccccc4Oc4cc(-c5cccc(-n6c7ccccc7c7ccccc76)c5)cc-3c42)cc1 ; c1ccc(-c2ccccc2-c2ccc3c(c2)OB2c4ccccc4Oc4cc(-c5ccc(-n6c7ccccc7c7ccccc76)cc5)cc-3c42)cc1]

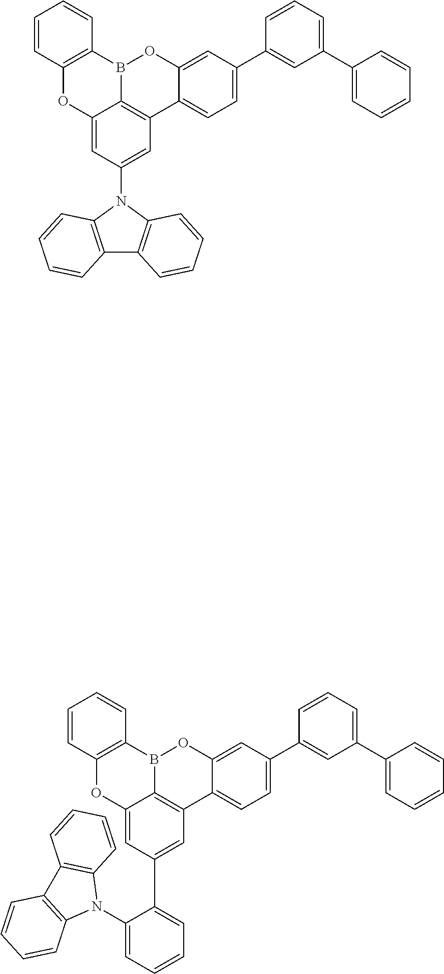 [SMILES: c1ccc(-c2cccc(-c3ccc4c(c3)OB3c5ccccc5Oc5cc(-n6c7ccccc7c7ccccc76)cc-4c53)c2)cc1 ; c1ccc(-c2cccc(-c3ccc4c(c3)OB3c5ccccc5Oc5cc(-c6ccccc6-n6c7ccccc7c7ccccc76)cc-4c53)c2)cc1]

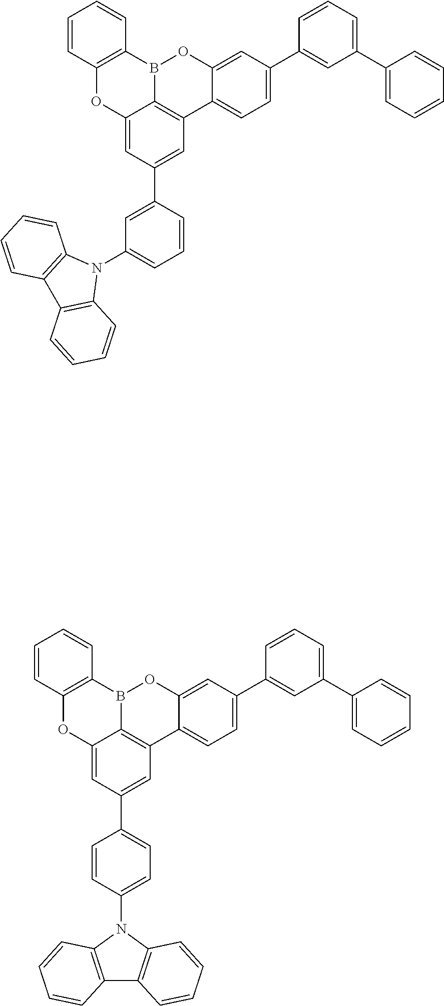 [SMILES: c1ccc(-c2cccc(-c3ccc4c(c3)OB3c5ccccc5Oc5cc(-c6cccc(-n7c8ccccc8c8ccccc87)c6)cc-4c53)c2)cc1 ; c1ccc(-c2cccc(-c3ccc4c(c3)OB3c5ccccc5Oc5cc(-c6ccc(-n7c8ccccc8c8ccccc87)cc6)cc-4c53)c2)cc1]

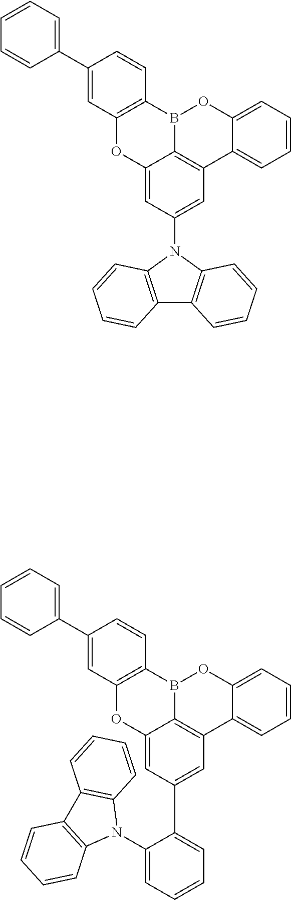 [SMILES: c1ccc(-c2ccc3c(c2)Oc2cc(-n4c5ccccc5c5ccccc54)cc4c2B3Oc2ccccc2-4)cc1 ; c1ccc(-c2ccc3c(c2)Oc2cc(-c4ccccc4-n4c5ccccc5c5ccccc54)cc4c2B3Oc2ccccc2-4)cc1]

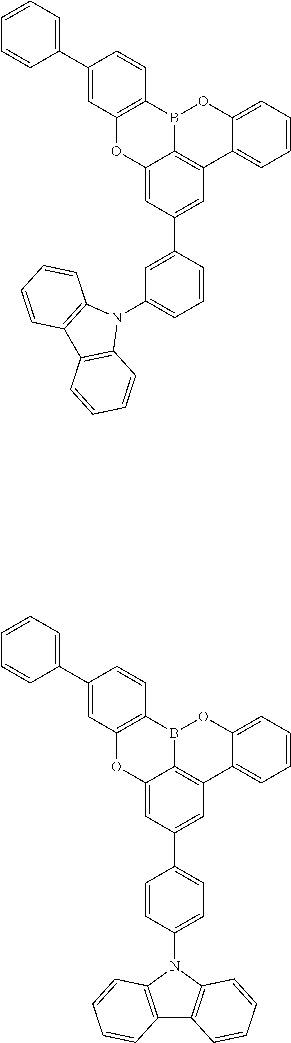 [SMILES: c1ccc(-c2ccc3c(c2)Oc2cc(-c4cccc(-n5c6ccccc6c6ccccc65)c4)cc4c2B3Oc2ccccc2-4)cc1 ; c1ccc(-c2ccc3c(c2)Oc2cc(-c4ccc(-n5c6ccccc6c6ccccc65)cc4)cc4c2B3Oc2ccccc2-4)cc1]

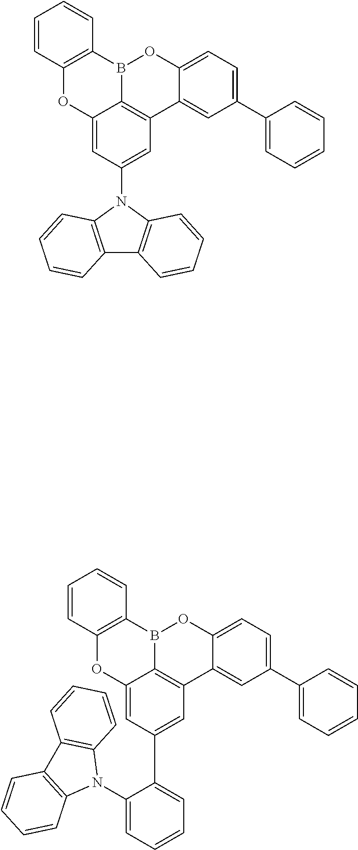 [SMILES: c1ccc(-c2ccc3c(c2)-c2cc(-n4c5ccccc5c5ccccc54)cc4c2B(O3)c2ccccc2O4)cc1 ; c1ccc(-c2ccc3c(c2)-c2cc(-c4ccccc4-n4c5ccccc5c5ccccc54)cc4c2B(O3)c2ccccc2O4)cc1]

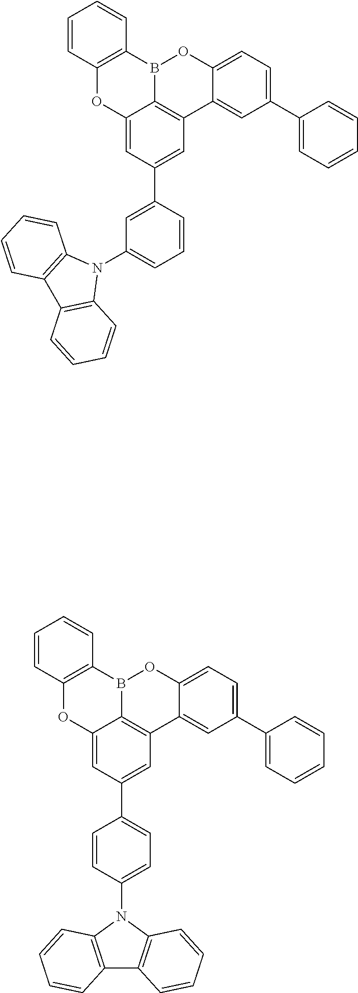 [SMILES: c1ccc(-c2ccc3c(c2)-c2cc(-c4cccc(-n5c6ccccc6c6ccccc65)c4)cc4c2B(O3)c2ccccc2O4)cc1 ; c1ccc(-c2ccc3c(c2)-c2cc(-c4ccc(-n5c6ccccc6c6ccccc65)cc4)cc4c2B(O3)c2ccccc2O4)cc1]

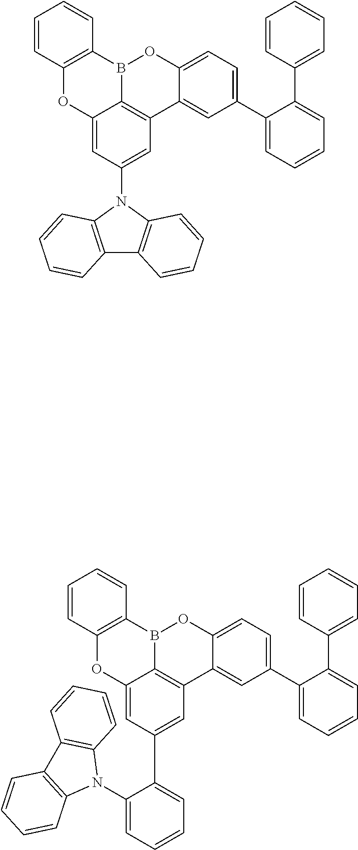 [SMILES: c1ccc(-c2ccccc2-c2ccc3c(c2)-c2cc(-n4c5ccccc5c5ccccc54)cc4c2B(O3)c2ccccc2O4)cc1 ; c1ccc(-c2ccccc2-c2ccc3c(c2)-c2cc(-c4ccccc4-n4c5ccccc5c5ccccc54)cc4c2B(O3)c2ccccc2O4)cc1]

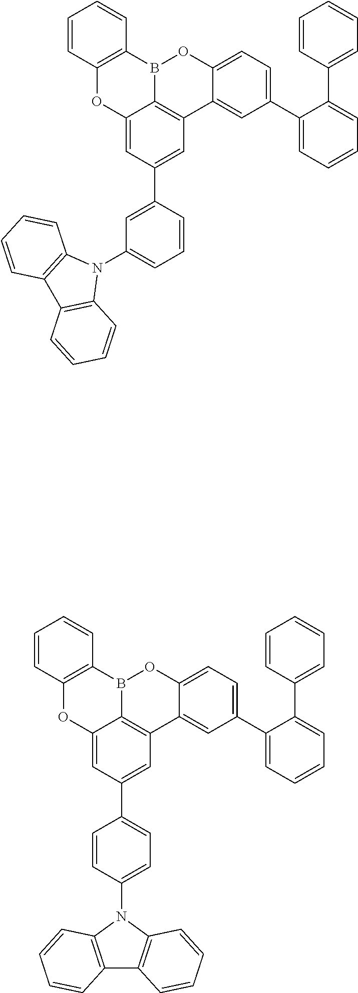 [SMILES: c1ccc(-c2ccccc2-c2ccc3c(c2)-c2cc(-c4cccc(-n5c6ccccc6c6ccccc65)c4)cc4c2B(O3)c2ccccc2O4)cc1 ; c1ccc(-c2ccccc2-c2ccc3c(c2)-c2cc(-c4ccc(-n5c6ccccc6c6ccccc65)cc4)cc4c2B(O3)c2ccccc2O4)cc1]

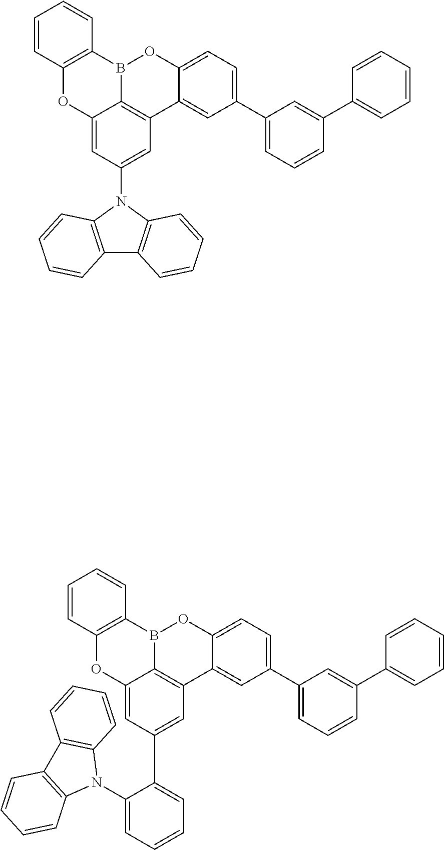 [SMILES: c1ccc(-c2cccc(-c3ccc4c(c3)-c3cc(-n5c6ccccc6c6ccccc65)cc5c3B(O4)c3ccccc3O5)c2)cc1 ; c1ccc(-c2cccc(-c3ccc4c(c3)-c3cc(-c5ccccc5-n5c6ccccc6c6ccccc65)cc5c3B(O4)c3ccccc3O5)c2)cc1]

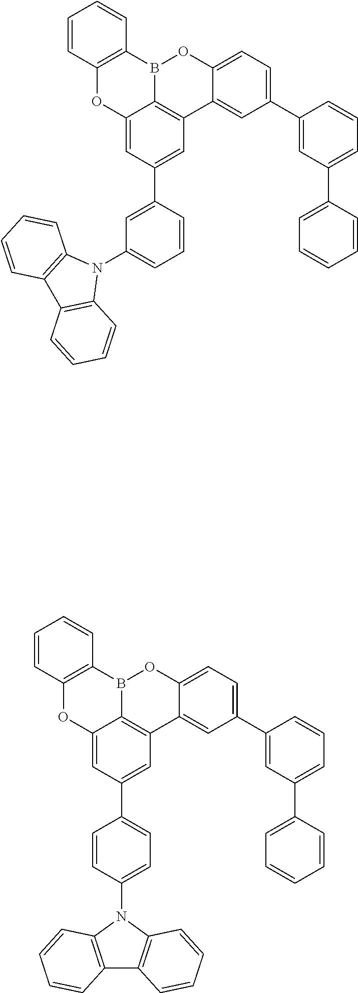 [SMILES: c1ccc(-c2cccc(-c3ccc4c(c3)-c3cc(-c5cccc(-n6c7ccccc7c7ccccc76)c5)cc5c3B(O4)c3ccccc3O5)c2)cc1 ; c1ccc(-c2cccc(-c3ccc4c(c3)-c3cc(-c5ccc(-n6c7ccccc7c7ccccc76)cc5)cc5c3B(O4)c3ccccc3O5)c2)cc1]

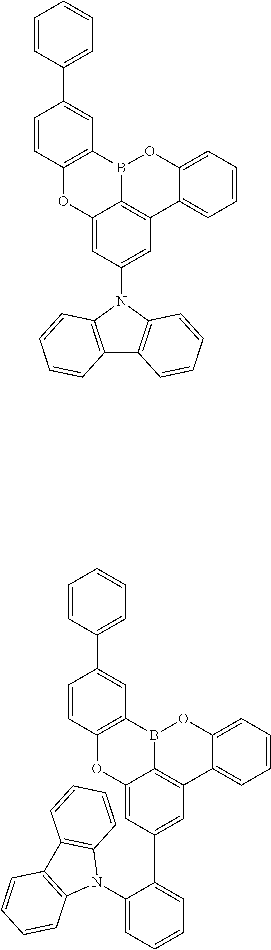 [SMILES: c1ccc(-c2ccc3c(c2)B2Oc4ccccc4-c4cc(-n5c6ccccc6c6ccccc65)cc(c42)O3)cc1 ; c1ccc(-c2ccc3c(c2)B2Oc4ccccc4-c4cc(-c5ccccc5-n5c6ccccc6c6ccccc65)cc(c42)O3)cc1]

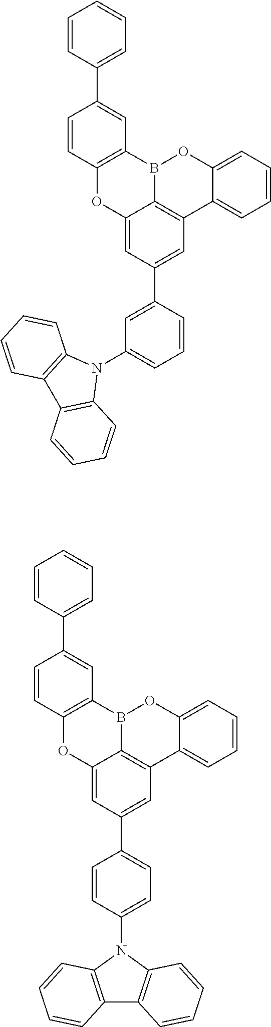 [SMILES: c1ccc(-c2ccc3c(c2)B2Oc4ccccc4-c4cc(-c5cccc(-n6c7ccccc7c7ccccc76)c5)cc(c42)O3)cc1 ; c1ccc(-c2ccc3c(c2)B2Oc4ccccc4-c4cc(-c5ccc(-n6c7ccccc7c7ccccc76)cc5)cc(c42)O3)cc1]

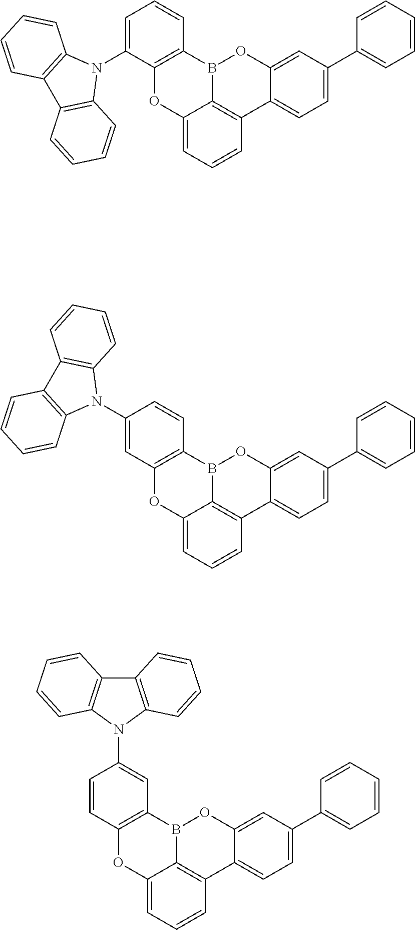 [SMILES: c1ccc(-c2ccc3c(c2)OB2c4cccc(-n5c6ccccc6c6ccccc65)c4Oc4cccc-3c42)cc1 ; c1ccc(-c2ccc3c(c2)OB2c4ccc(-n5c6ccccc6c6ccccc65)cc4Oc4cccc-3c42)cc1 ; c1ccc(-c2ccc3c(c2)OB2c4cc(-n5c6ccccc6c6ccccc65)ccc4Oc4cccc-3c42)cc1]

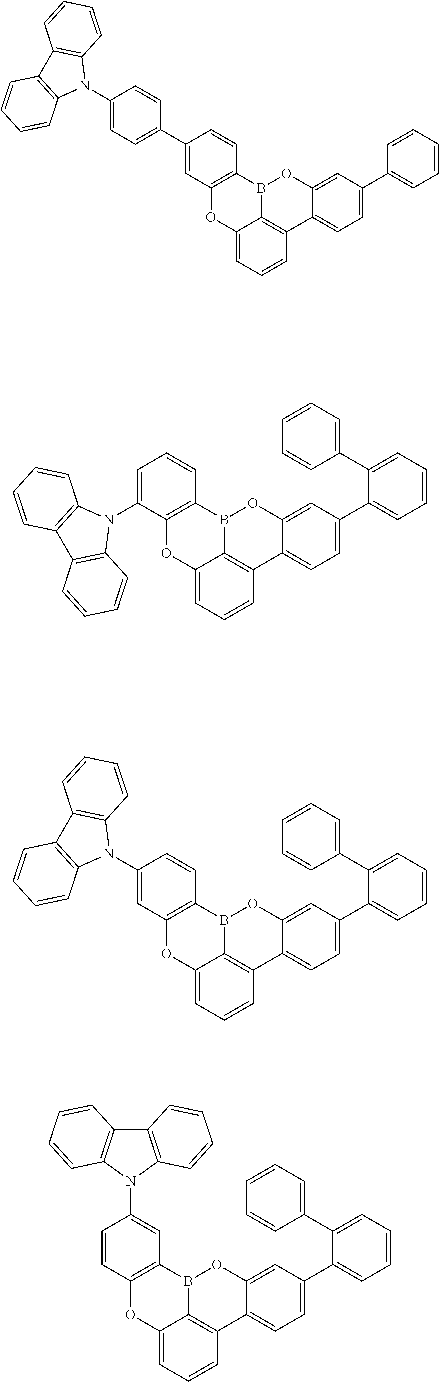 [SMILES: c1ccc(-c2ccc3c(c2)OB2c4ccc(-c5ccc(-n6c7ccccc7c7ccccc76)cc5)cc4Oc4cccc-3c42)cc1 ; c1ccc(-c2ccccc2-c2ccc3c(c2)OB2c4cccc(-n5c6ccccc6c6ccccc65)c4Oc4cccc-3c42)cc1 ; c1ccc(-c2ccccc2-c2ccc3c(c2)OB2c4ccc(-n5c6ccccc6c6ccccc65)cc4Oc4cccc-3c42)cc1 ; c1ccc(-c2ccccc2-c2ccc3c(c2)OB2c4cc(-n5c6ccccc6c6ccccc65)ccc4Oc4cccc-3c42)cc1]

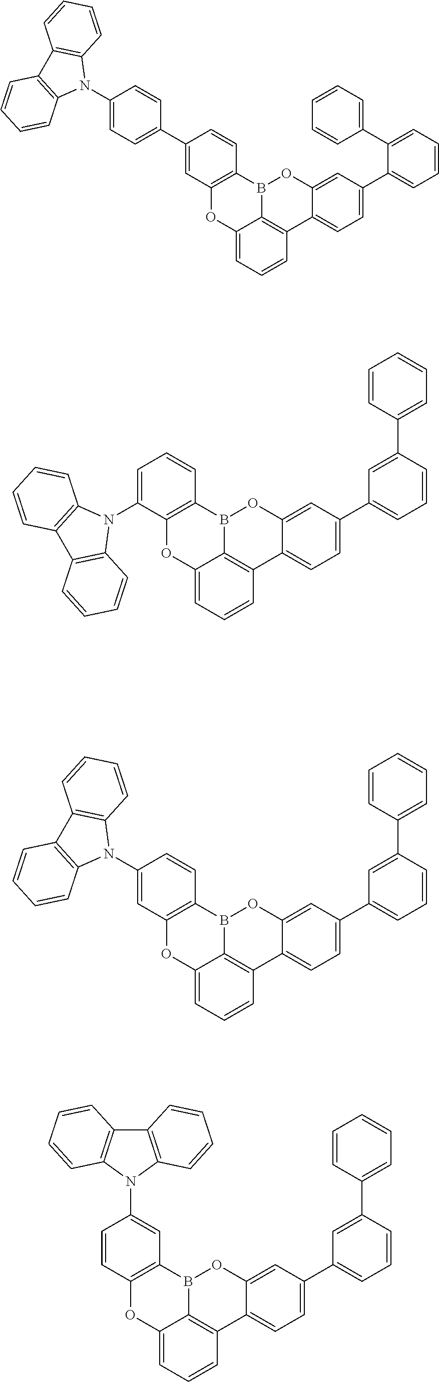 [SMILES: c1ccc(-c2ccccc2-c2ccc3c(c2)OB2c4ccc(-c5ccc(-n6c7ccccc7c7ccccc76)cc5)cc4Oc4cccc-3c42)cc1 ; c1ccc(-c2cccc(-c3ccc4c(c3)OB3c5cccc(-n6c7ccccc7c7ccccc76)c5Oc5cccc-4c53)c2)cc1 ; c1ccc(-c2cccc(-c3ccc4c(c3)OB3c5ccc(-n6c7ccccc7c7ccccc76)cc5Oc5cccc-4c53)c2)cc1 ; c1ccc(-c2cccc(-c3ccc4c(c3)OB3c5cc(-n6c7ccccc7c7ccccc76)ccc5Oc5cccc-4c53)c2)cc1]

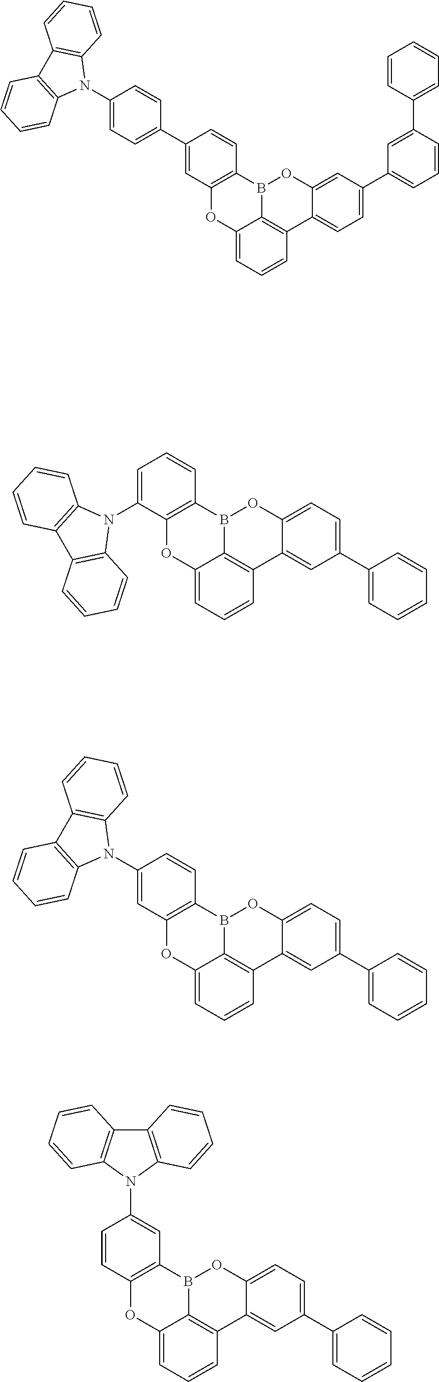 [SMILES: c1ccc(-c2cccc(-c3ccc4c(c3)OB3c5ccc(-c6ccc(-n7c8ccccc8c8ccccc87)cc6)cc5Oc5cccc-4c53)c2)cc1 ; c1ccc(-c2ccc3c(c2)-c2cccc4c2B(O3)c2cccc(-n3c5ccccc5c5ccccc53)c2O4)cc1 ; c1ccc(-c2ccc3c(c2)-c2cccc4c2B(O3)c2ccc(-n3c5ccccc5c5ccccc53)cc2O4)cc1 ; c1ccc(-c2ccc3c(c2)-c2cccc4c2B(O3)c2cc(-n3c5ccccc5c5ccccc53)ccc2O4)cc1]

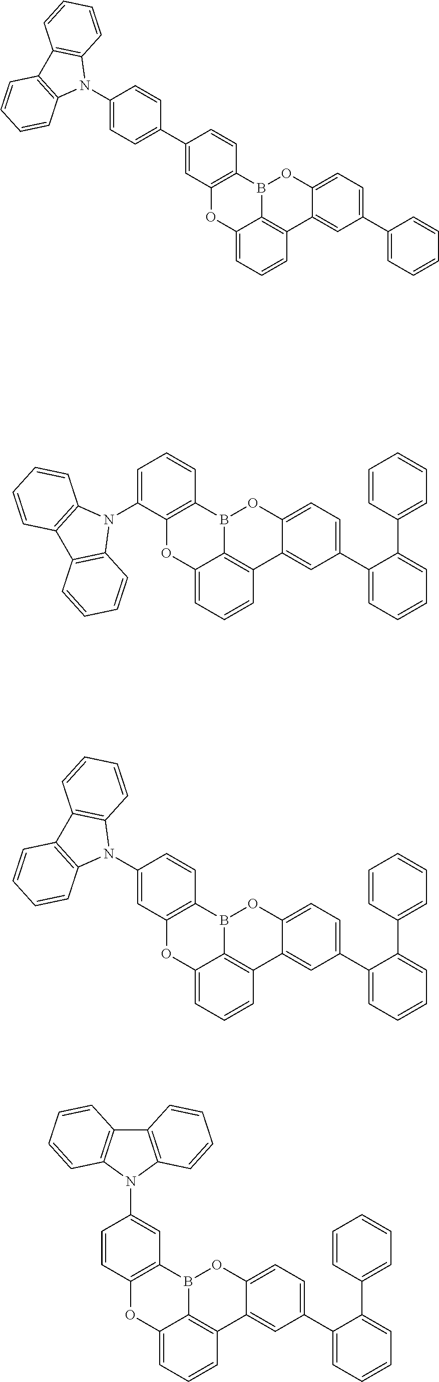 [SMILES: c1ccc(-c2ccc3c(c2)-c2cccc4c2B(O3)c2ccc(-c3ccc(-n5c6ccccc6c6ccccc65)cc3)cc2O4)cc1 ; c1ccc(-c2ccccc2-c2ccc3c(c2)-c2cccc4c2B(O3)c2cccc(-n3c5ccccc5c5ccccc53)c2O4)cc1 ; c1ccc(-c2ccccc2-c2ccc3c(c2)-c2cccc4c2B(O3)c2ccc(-n3c5ccccc5c5ccccc53)cc2O4)cc1 ; c1ccc(-c2ccccc2-c2ccc3c(c2)-c2cccc4c2B(O3)c2cc(-n3c5ccccc5c5ccccc53)ccc2O4)cc1]

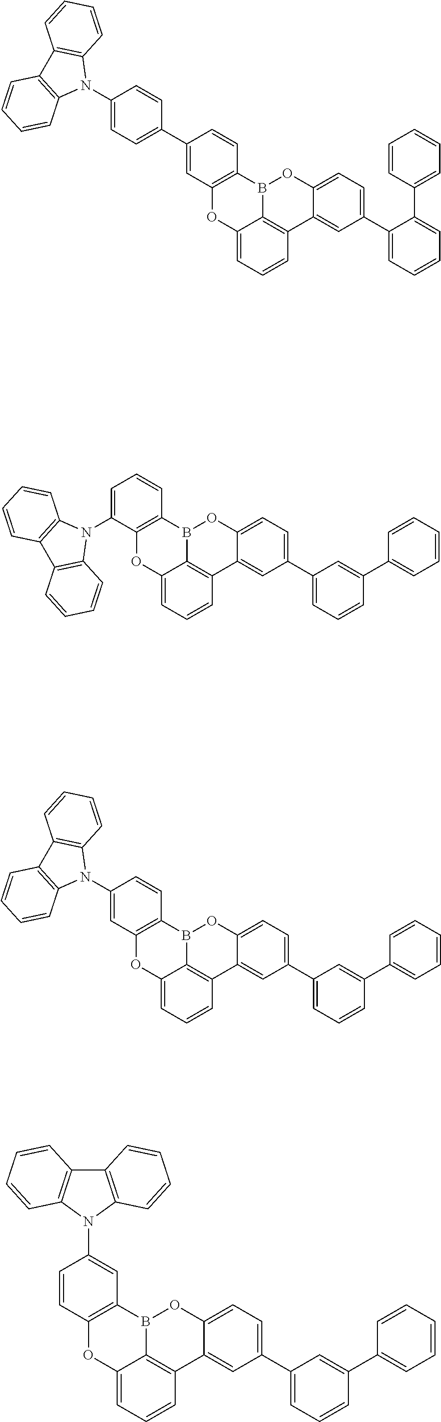 [SMILES: c1ccc(-c2ccccc2-c2ccc3c(c2)-c2cccc4c2B(O3)c2ccc(-c3ccc(-n5c6ccccc6c6ccccc65)cc3)cc2O4)cc1 ; c1ccc(-c2cccc(-c3ccc4c(c3)-c3cccc5c3B(O4)c3cccc(-n4c6ccccc6c6ccccc64)c3O5)c2)cc1 ; c1ccc(-c2cccc(-c3ccc4c(c3)-c3cccc5c3B(O4)c3ccc(-n4c6ccccc6c6ccccc64)cc3O5)c2)cc1 ; c1ccc(-c2cccc(-c3ccc4c(c3)-c3cccc5c3B(O4)c3cc(-n4c6ccccc6c6ccccc64)ccc3O5)c2)cc1]

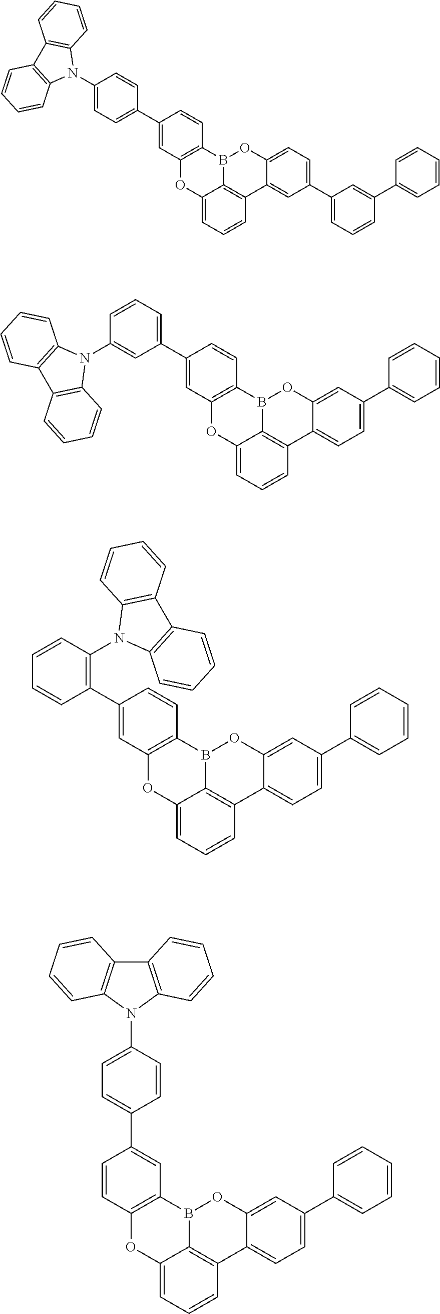 [SMILES: c1ccc(-c2cccc(-c3ccc4c(c3)-c3cccc5c3B(O4)c3ccc(-c4ccc(-n6c7ccccc7c7ccccc76)cc4)cc3O5)c2)cc1 ; c1ccc(-c2ccc3c(c2)OB2c4ccc(-c5cccc(-n6c7ccccc7c7ccccc76)c5)cc4Oc4cccc-3c42)cc1 ; c1ccc(-c2ccc3c(c2)OB2c4ccc(-c5ccccc5-n5c6ccccc6c6ccccc65)cc4Oc4cccc-3c42)cc1 ; c1ccc(-c2ccc3c(c2)OB2c4cc(-c5ccc(-n6c7ccccc7c7ccccc76)cc5)ccc4Oc4cccc-3c42)cc1]

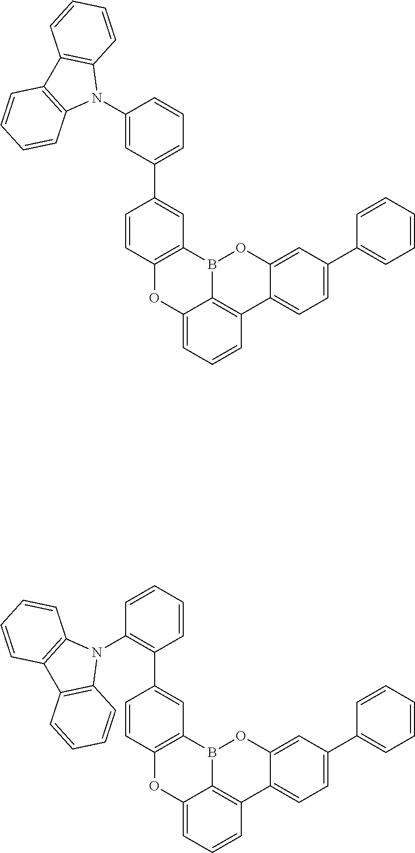 [SMILES: c1ccc(-c2ccc3c(c2)OB2c4cc(-c5cccc(-n6c7ccccc7c7ccccc76)c5)ccc4Oc4cccc-3c42)cc1 ; c1ccc(-c2ccc3c(c2)OB2c4cc(-c5ccccc5-n5c6ccccc6c6ccccc65)ccc4Oc4cccc-3c42)cc1]

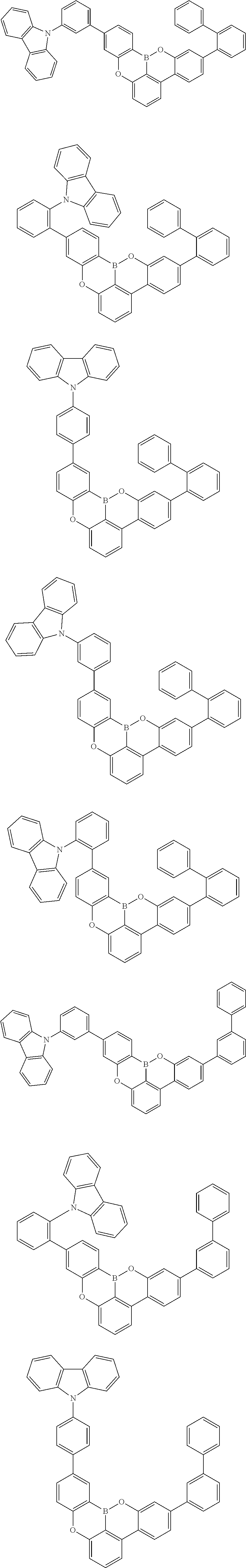

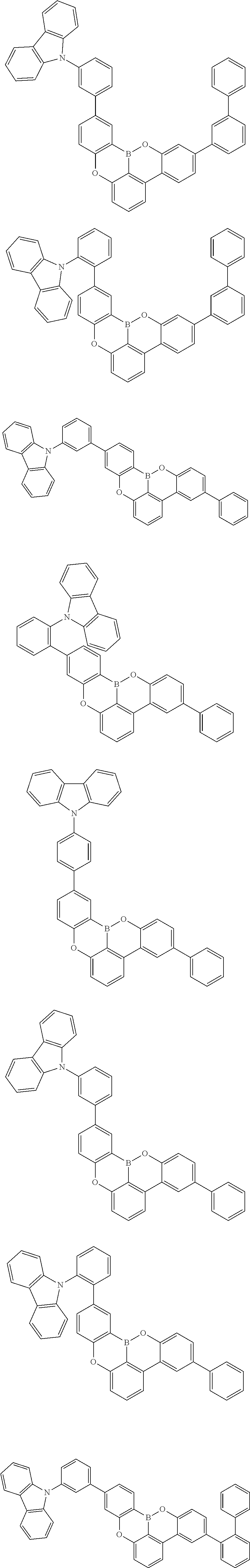

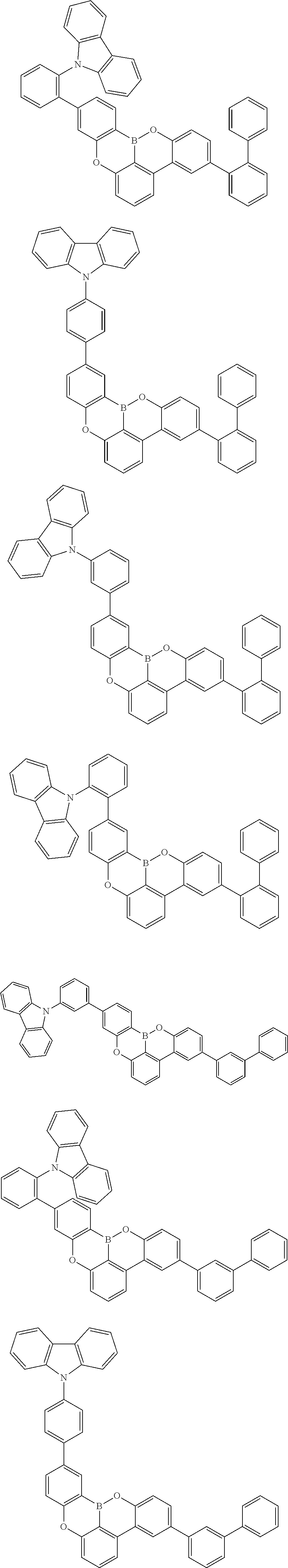

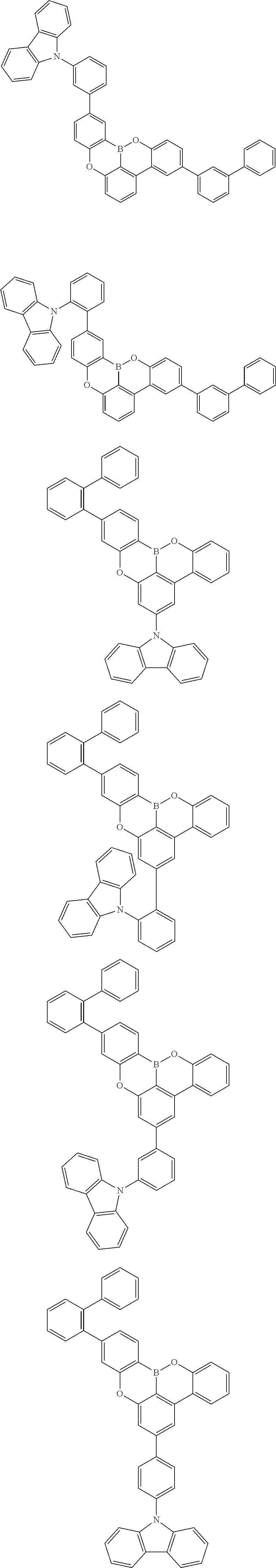

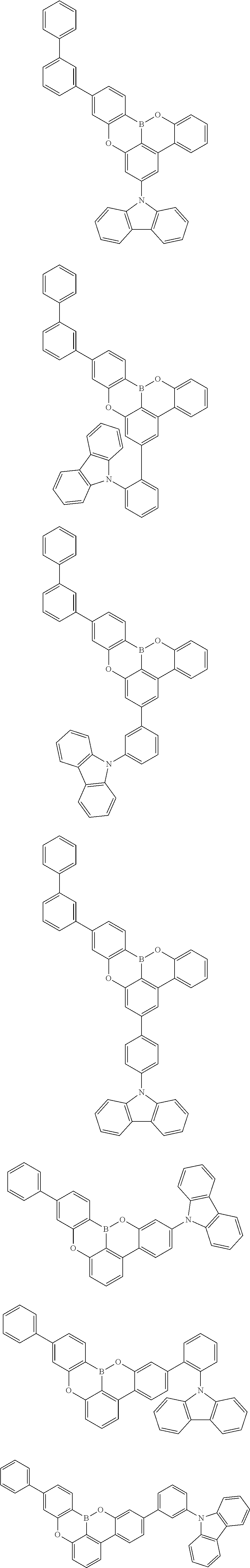

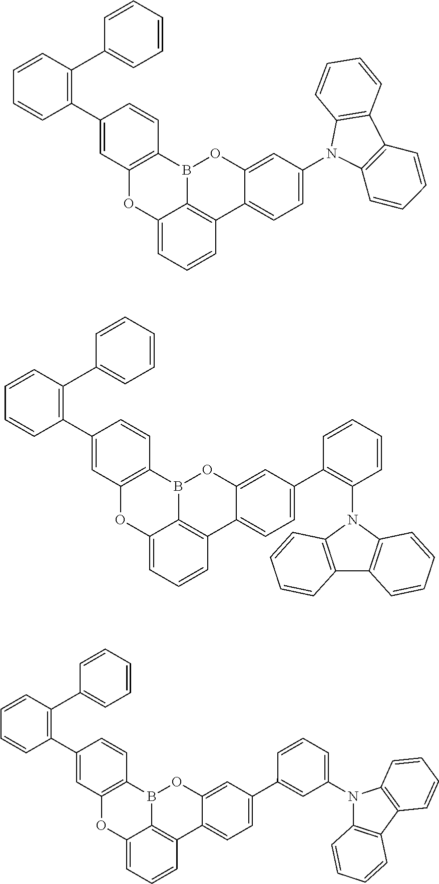 [SMILES: c1ccc(-c2ccccc2-c2ccc3c(c2)Oc2cccc4c2B3Oc2cc(-n3c5ccccc5c5ccccc53)ccc2-4)cc1 ; c1ccc(-c2ccccc2-c2ccc3c(c2)Oc2cccc4c2B3Oc2cc(-c3ccccc3-n3c5ccccc5c5ccccc53)ccc2-4)cc1 ; c1ccc(-c2ccccc2-c2ccc3c(c2)Oc2cccc4c2B3Oc2cc(-c3cccc(-n5c6ccccc6c6ccccc65)c3)ccc2-4)cc1]

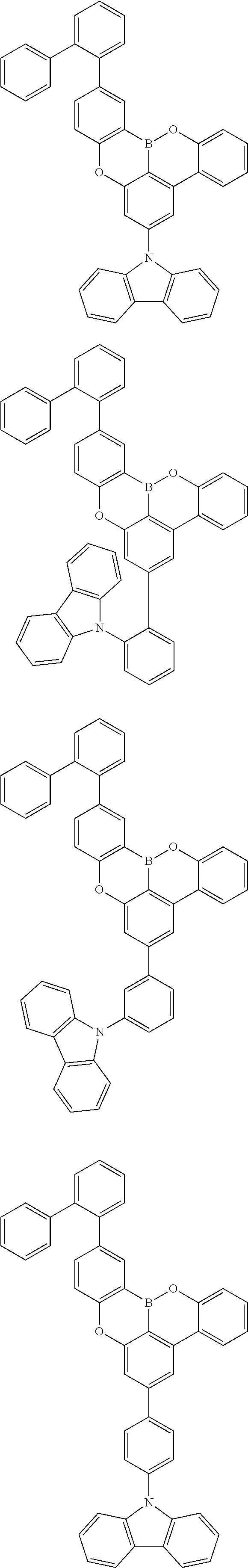

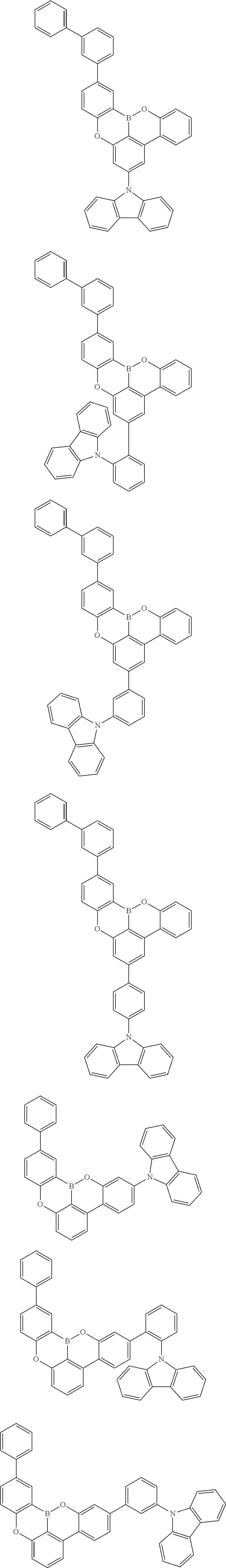

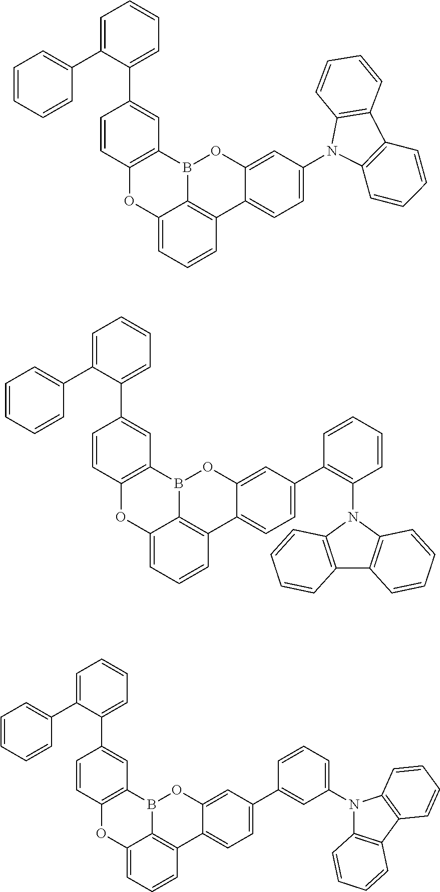 [SMILES: c1ccc(-c2ccccc2-c2ccc3c(c2)B2Oc4cc(-n5c6ccccc6c6ccccc65)ccc4-c4cccc(c42)O3)cc1 ; c1ccc(-c2ccccc2-c2ccc3c(c2)B2Oc4cc(-c5ccccc5-n5c6ccccc6c6ccccc65)ccc4-c4cccc(c42)O3)cc1 ; c1ccc(-c2ccccc2-c2ccc3c(c2)B2Oc4cc(-c5cccc(-n6c7ccccc7c7ccccc76)c5)ccc4-c4cccc(c42)O3)cc1]

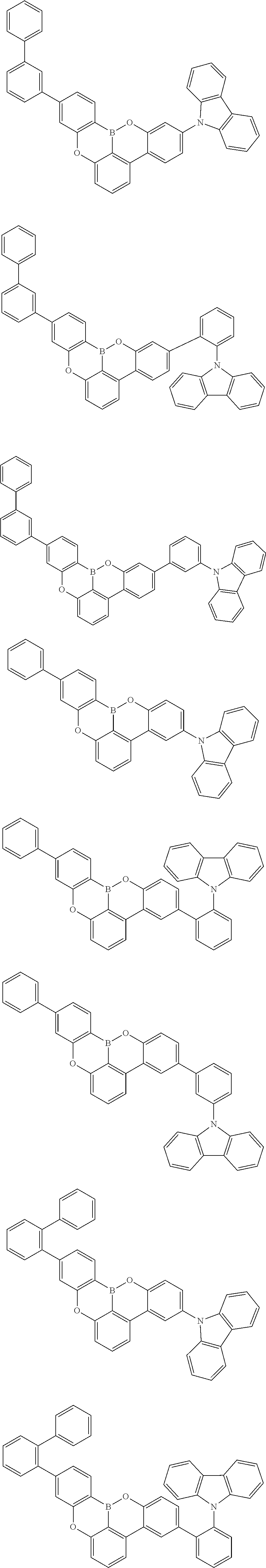

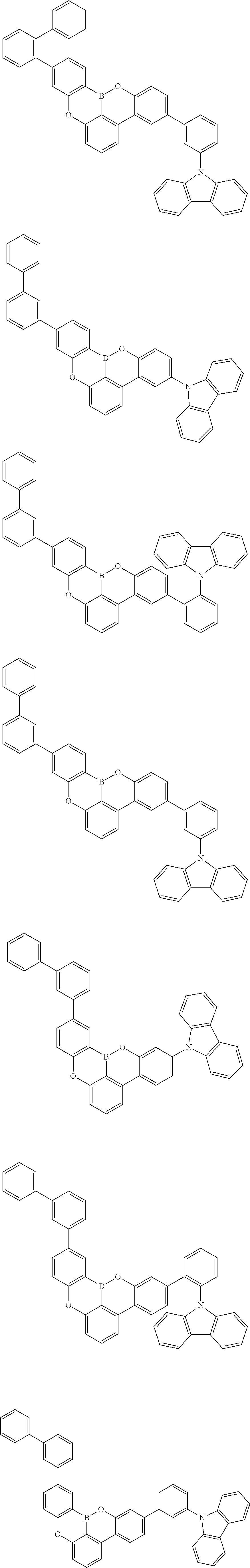

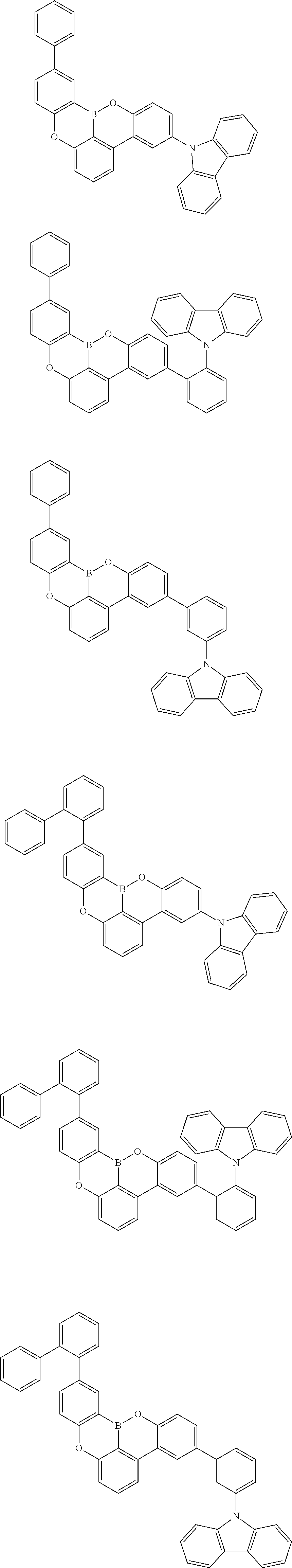 [SMILES: c1ccc(-c2ccc3c(c2)B2Oc4ccc(-n5c6ccccc6c6ccccc65)cc4-c4cccc(c42)O3)cc1 ; c1ccc(-c2ccc3c(c2)B2Oc4ccc(-c5ccccc5-n5c6ccccc6c6ccccc65)cc4-c4cccc(c42)O3)cc1 ; c1ccc(-c2ccc3c(c2)B2Oc4ccc(-c5cccc(-n6c7ccccc7c7ccccc76)c5)cc4-c4cccc(c42)O3)cc1 ; c1ccc(-c2ccccc2-c2ccc3c(c2)B2Oc4ccc(-n5c6ccccc6c6ccccc65)cc4-c4cccc(c42)O3)cc1 ; c1ccc(-c2ccccc2-c2ccc3c(c2)B2Oc4ccc(-c5ccccc5-n5c6ccccc6c6ccccc65)cc4-c4cccc(c42)O3)cc1 ; c1ccc(-c2ccccc2-c2ccc3c(c2)B2Oc4ccc(-c5cccc(-n6c7ccccc7c7ccccc76)c5)cc4-c4cccc(c42)O3)cc1]

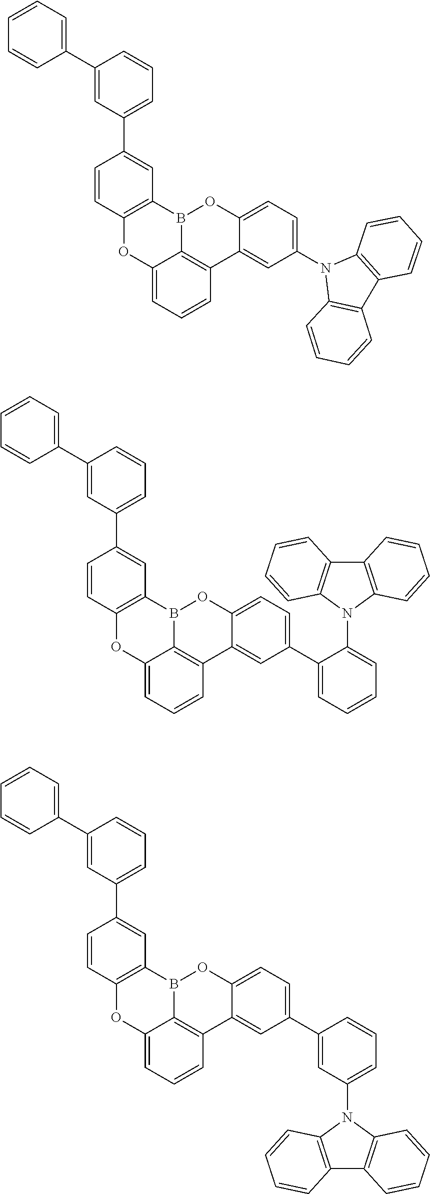 [SMILES: c1ccc(-c2cccc(-c3ccc4c(c3)B3Oc5ccc(-n6c7ccccc7c7ccccc76)cc5-c5cccc(c53)O4)c2)cc1 ; c1ccc(-c2cccc(-c3ccc4c(c3)B3Oc5ccc(-c6ccccc6-n6c7ccccc7c7ccccc76)cc5-c5cccc(c53)O4)c2)cc1 ; c1ccc(-c2cccc(-c3ccc4c(c3)B3Oc5ccc(-c6cccc(-n7c8ccccc8c8ccccc87)c6)cc5-c5cccc(c53)O4)c2)cc1]

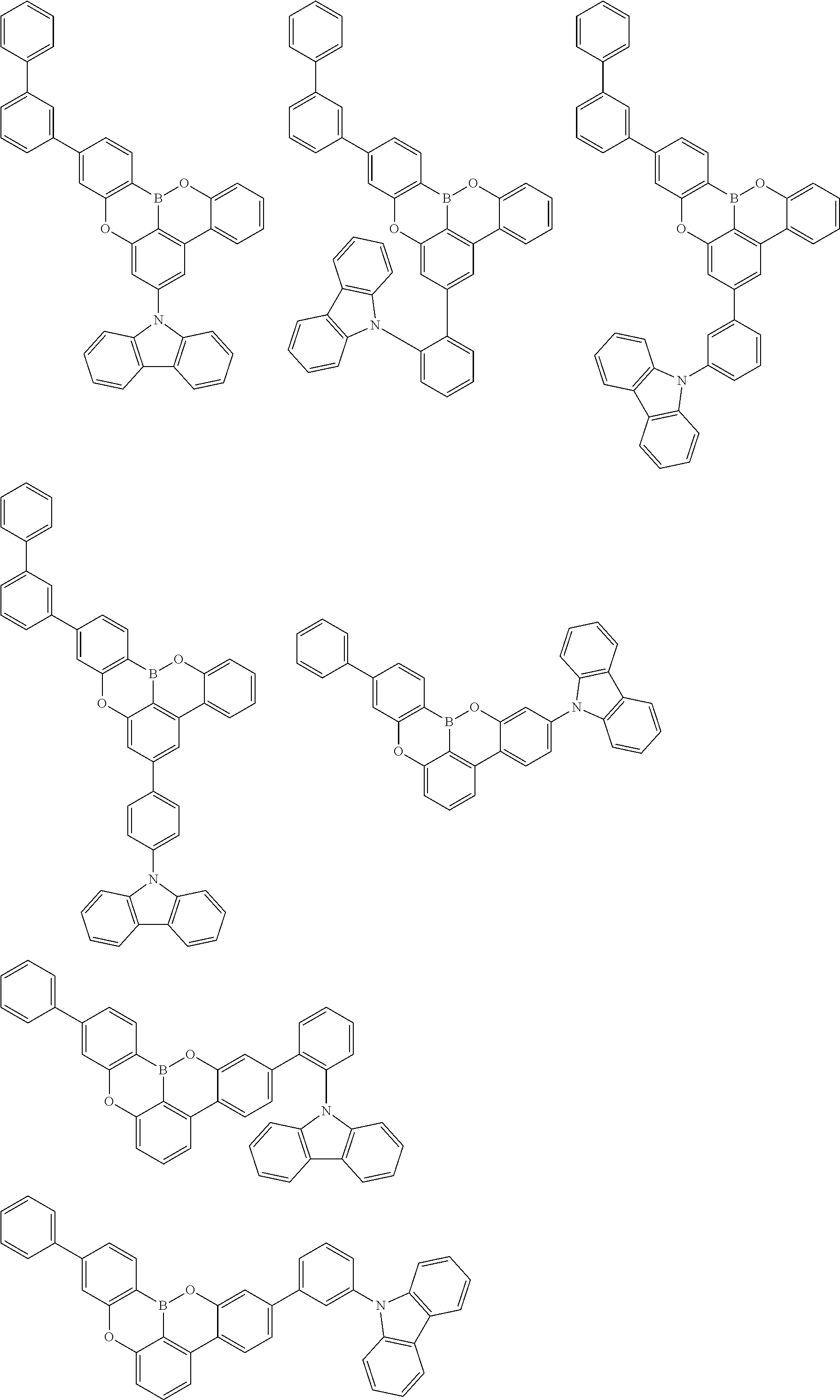

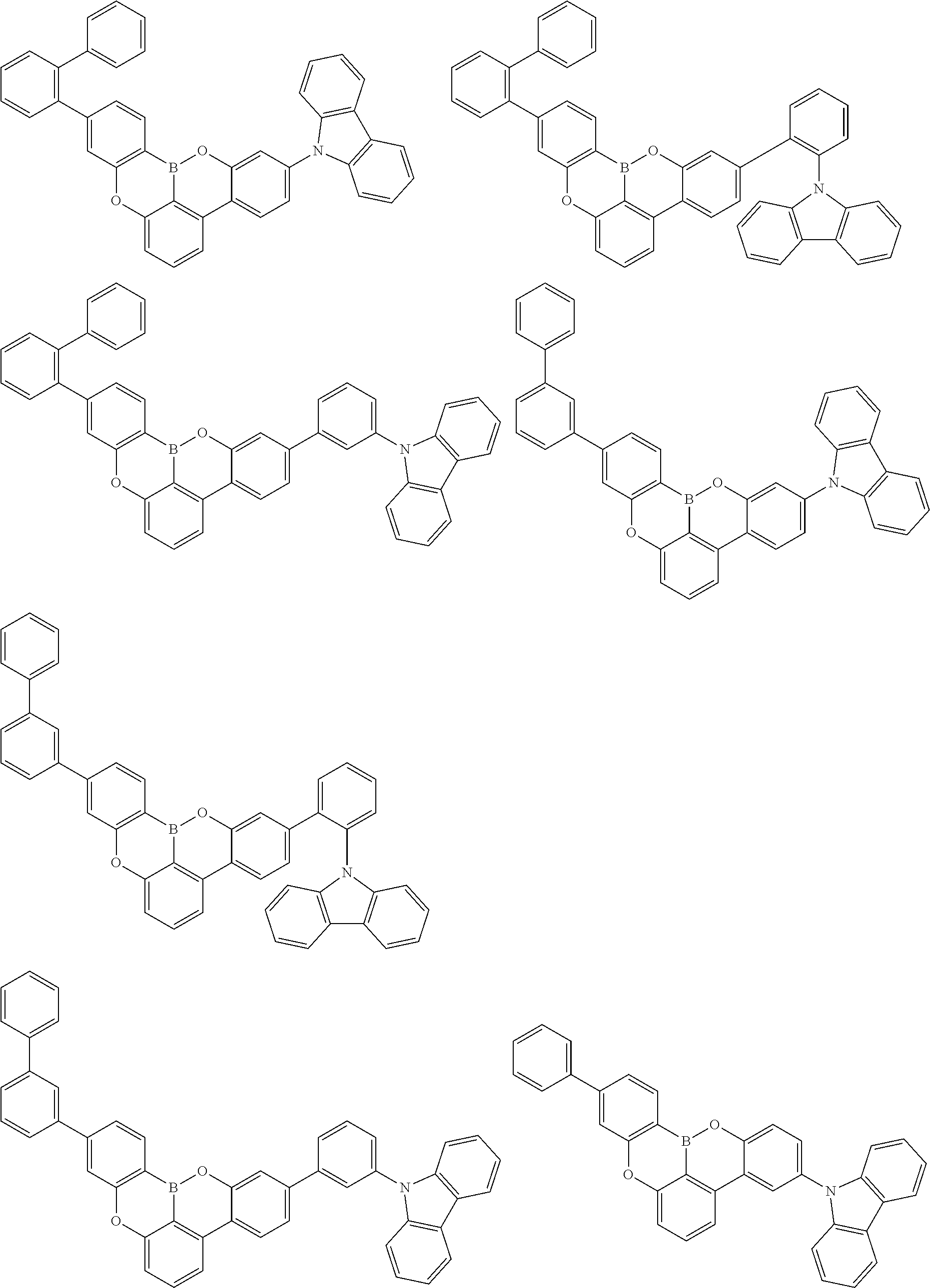

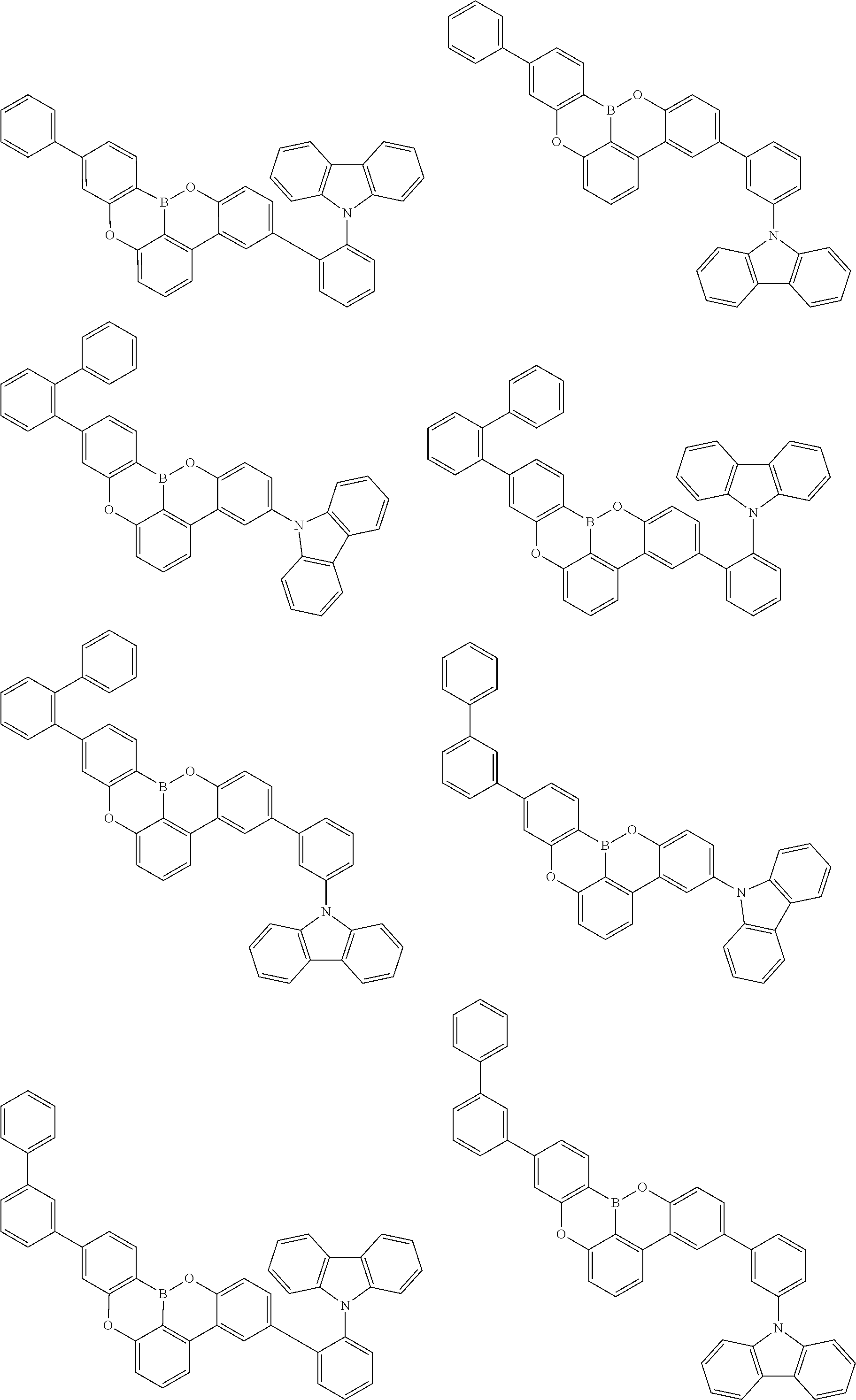

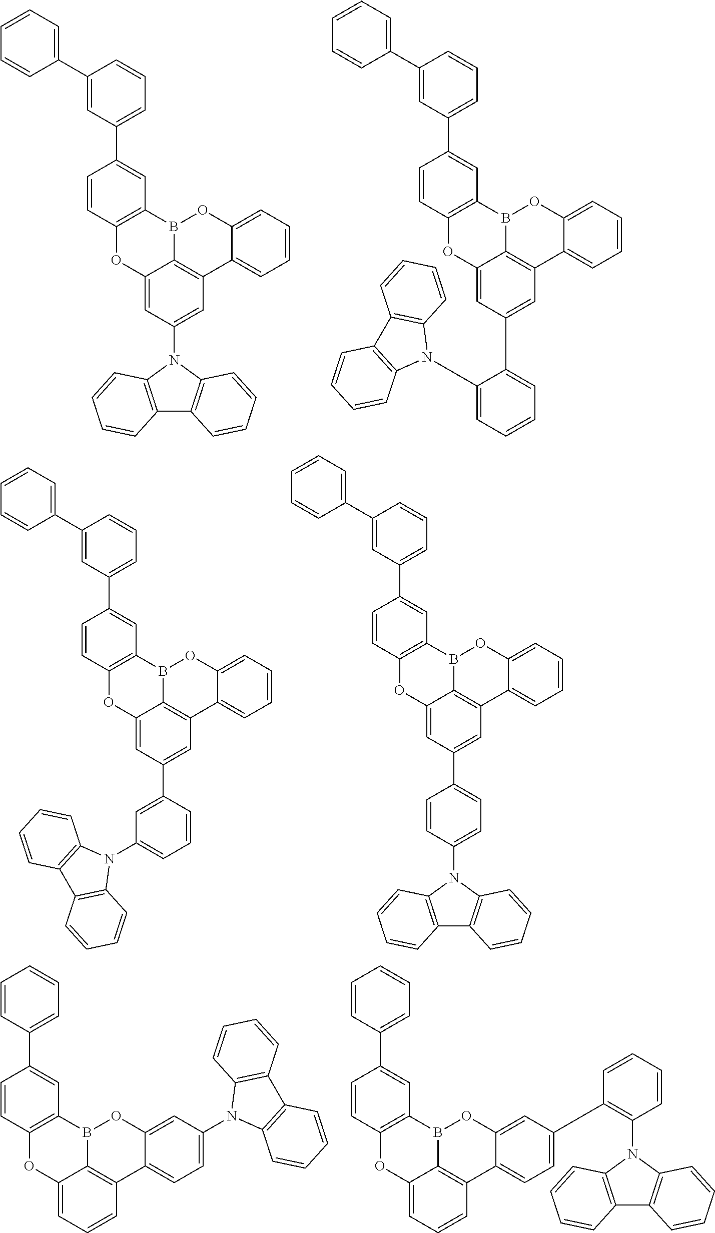

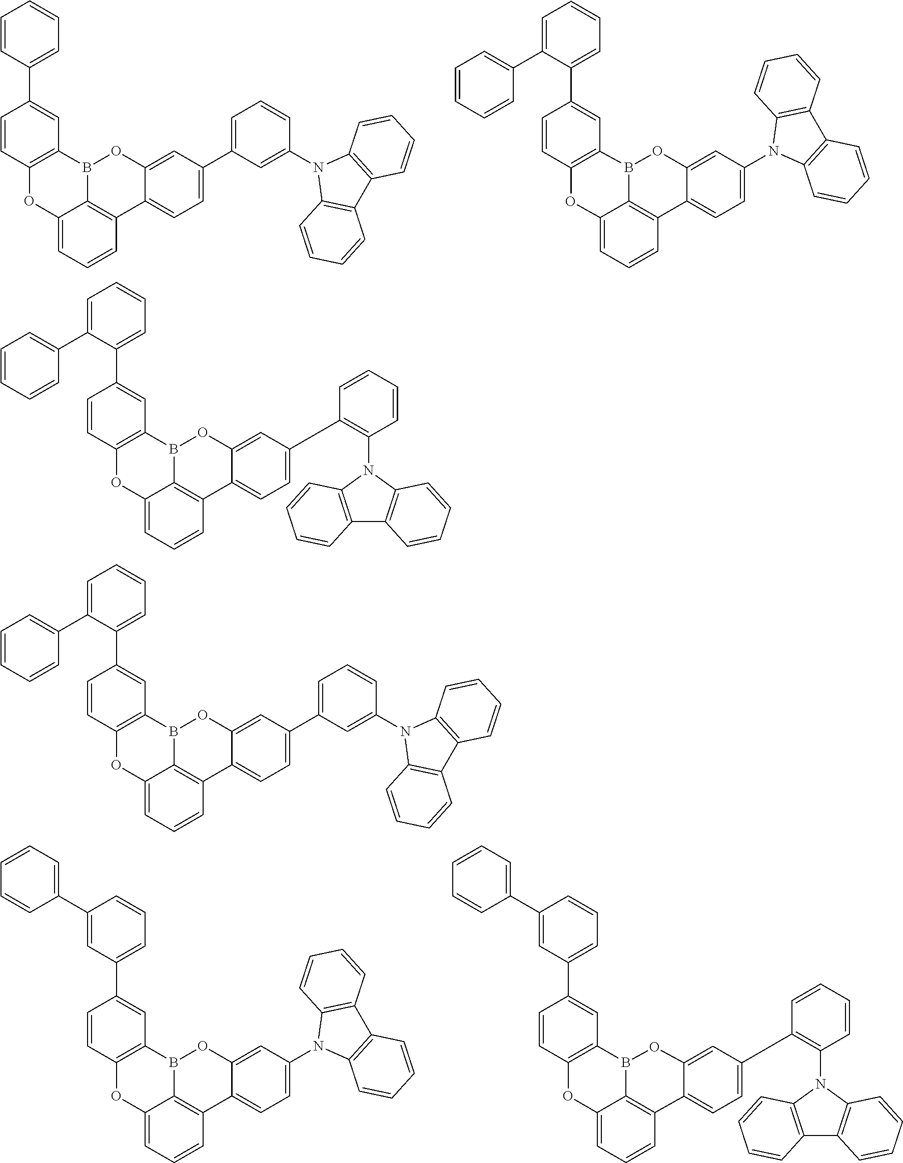

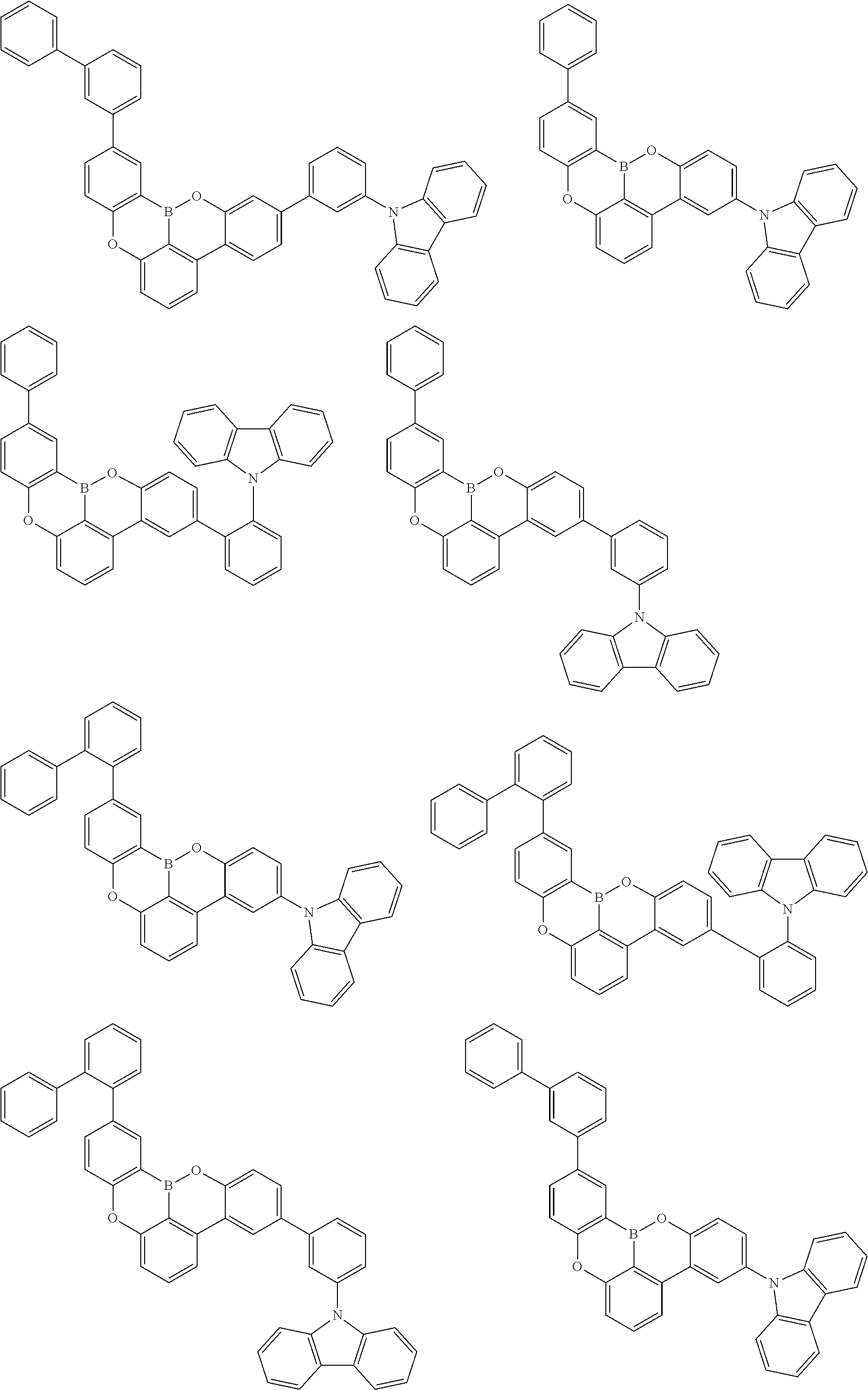

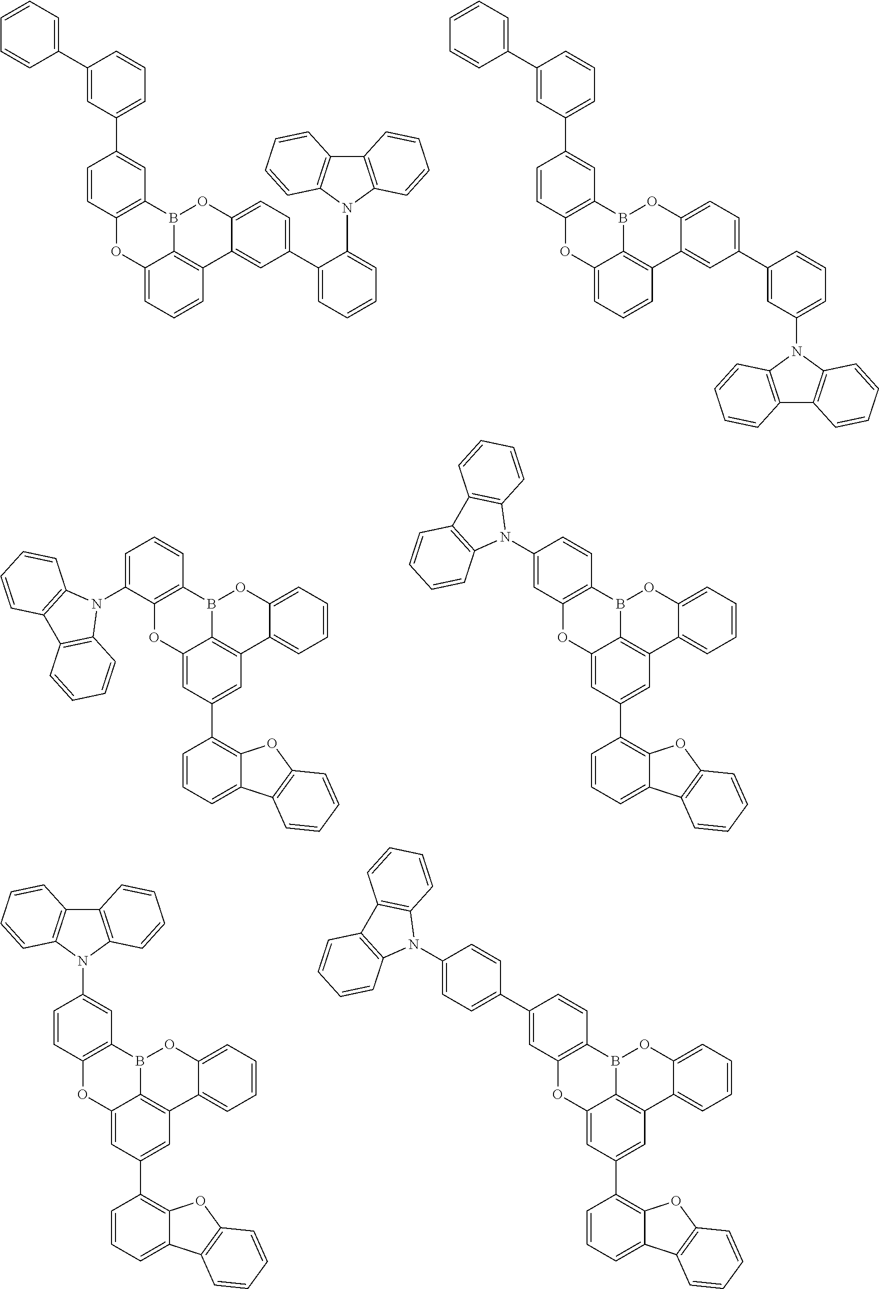

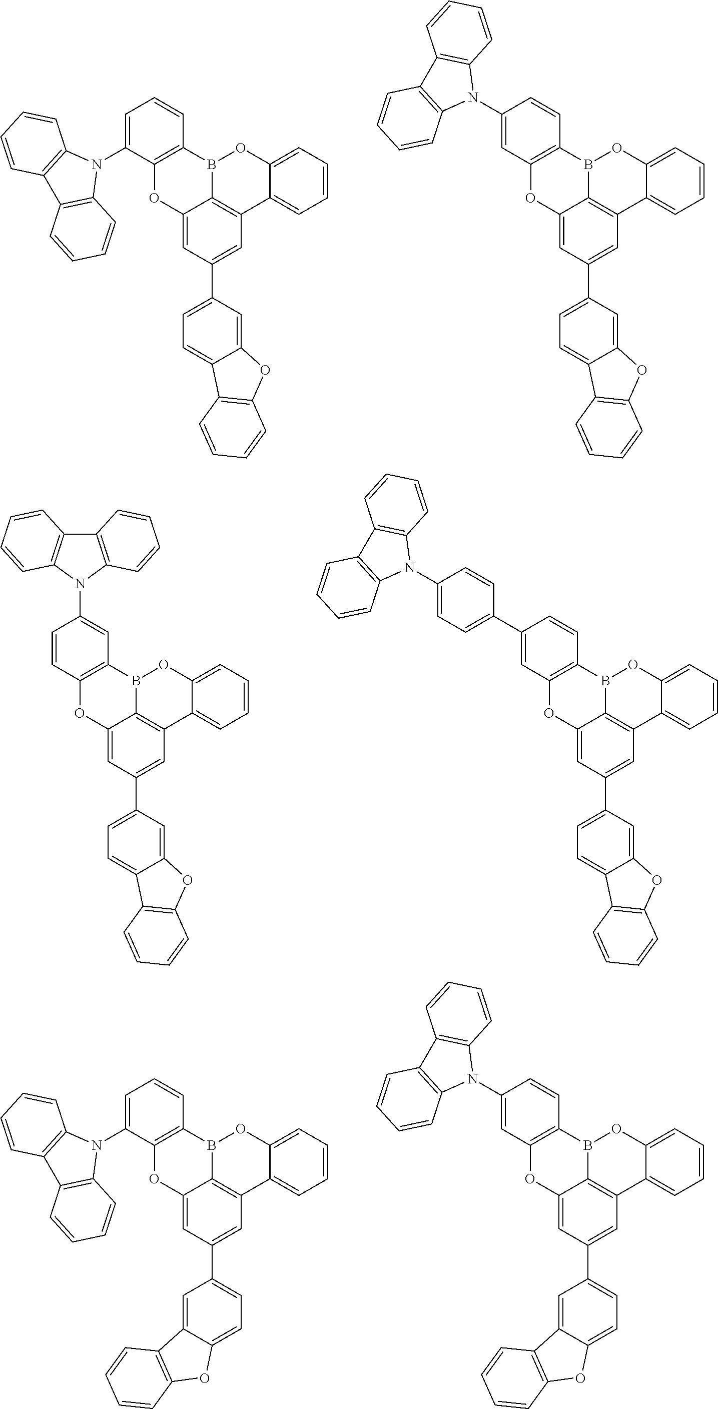

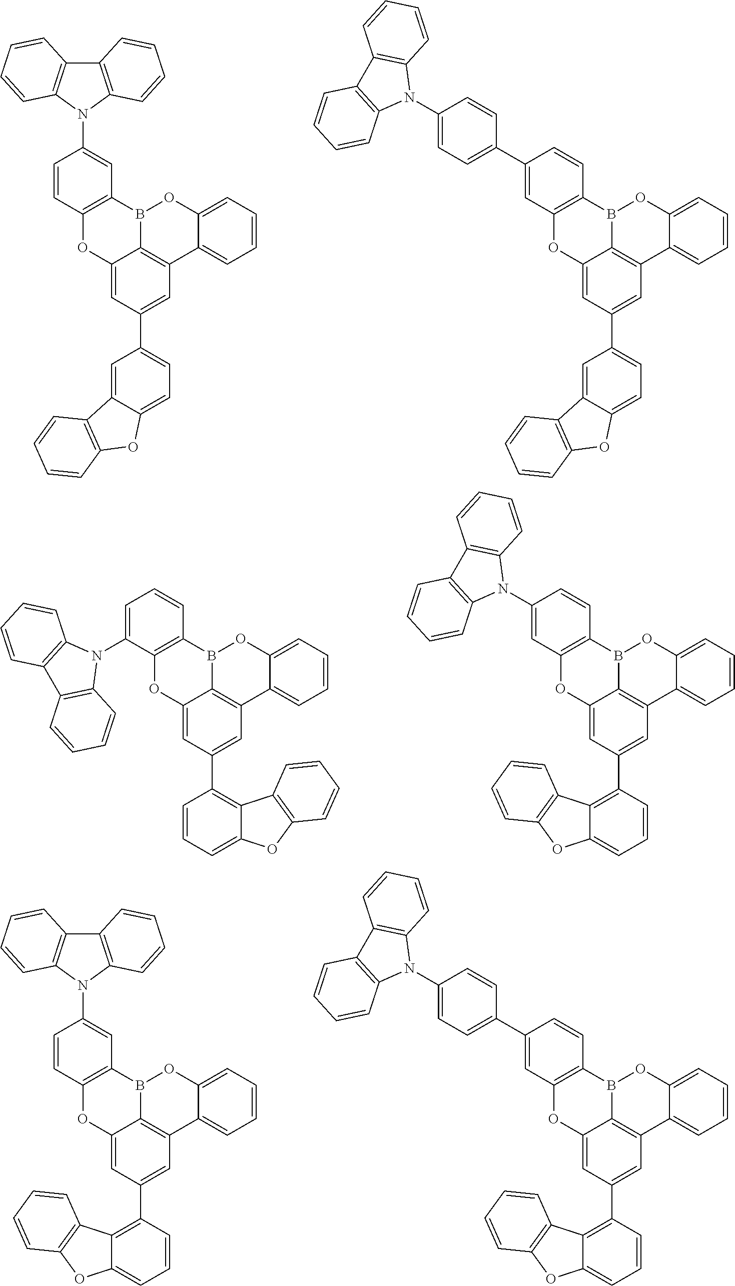

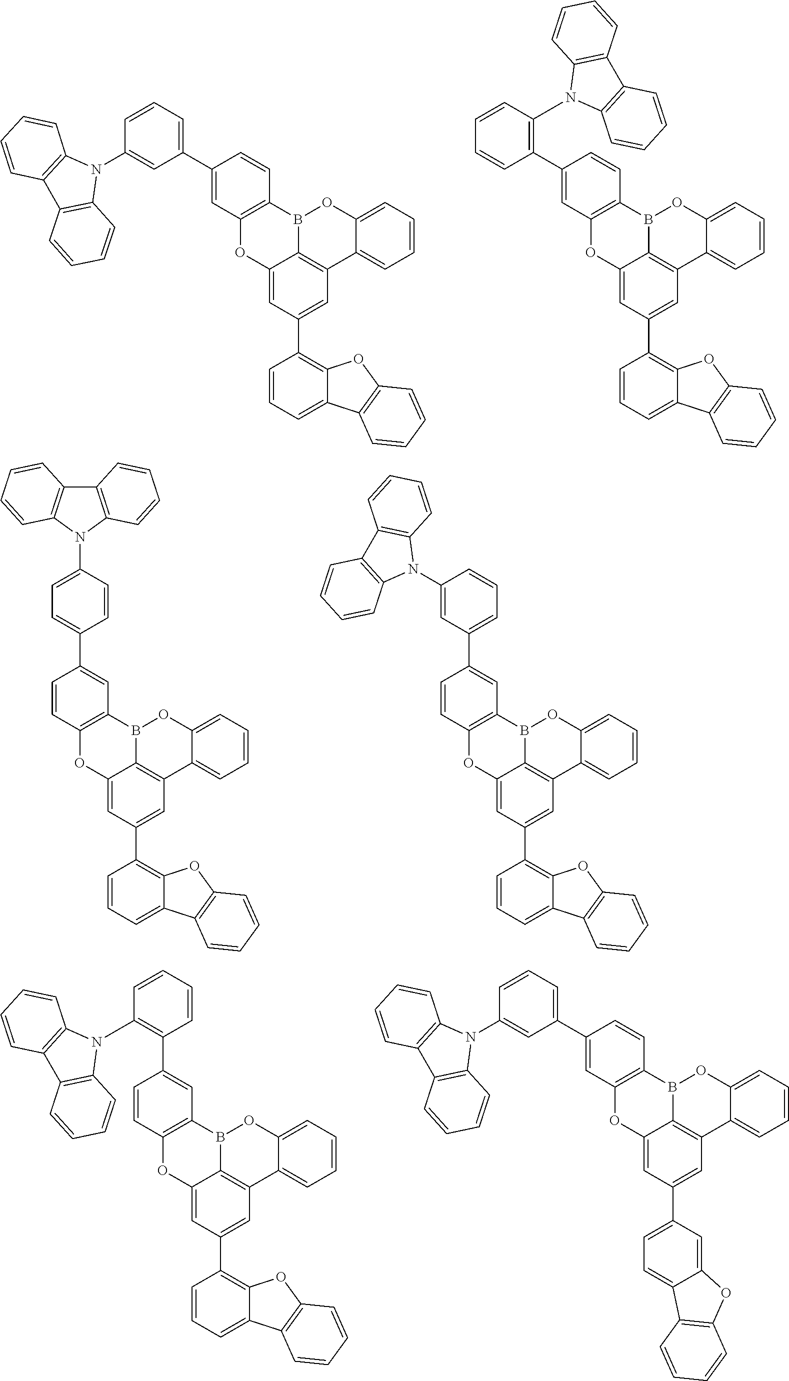

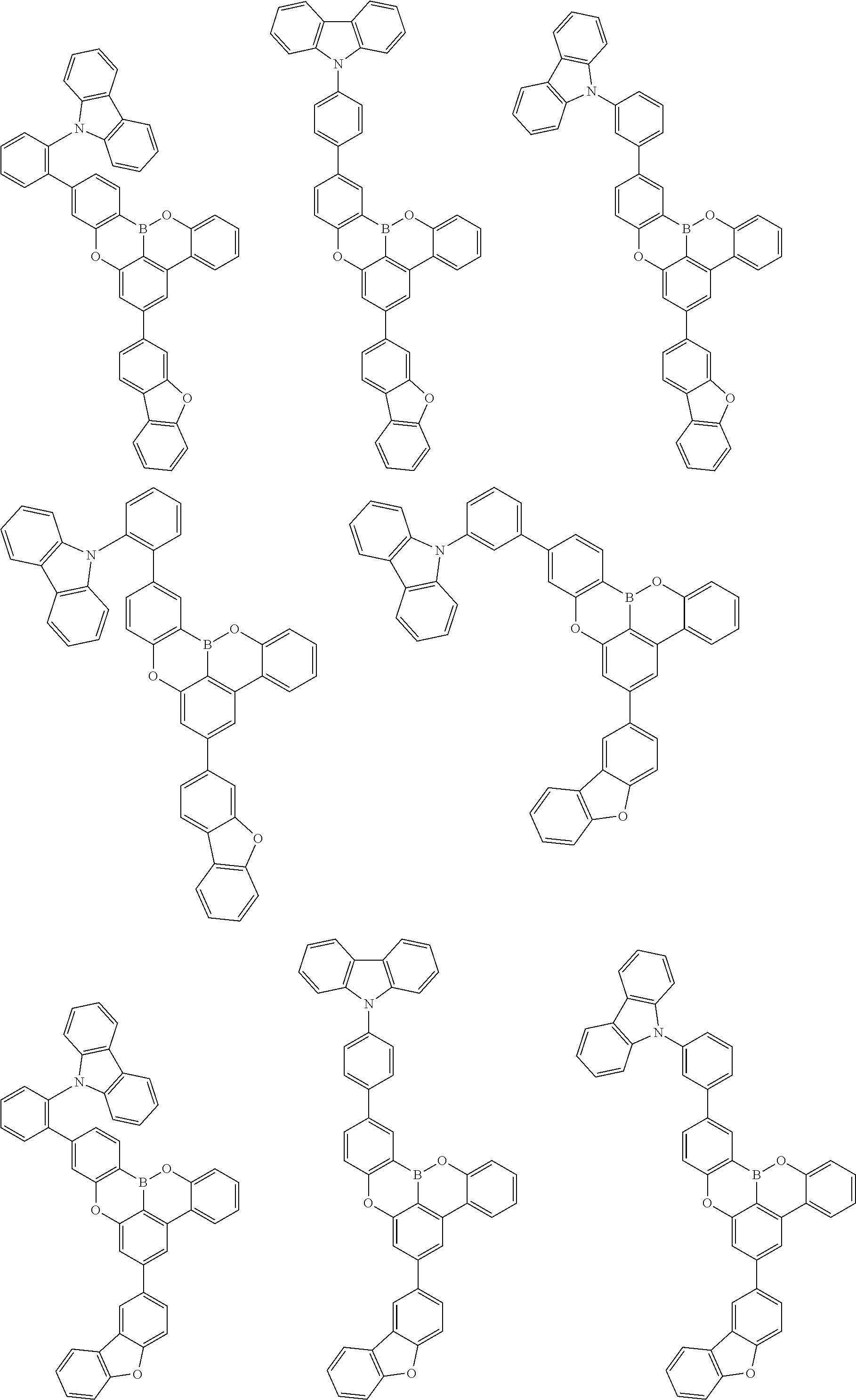

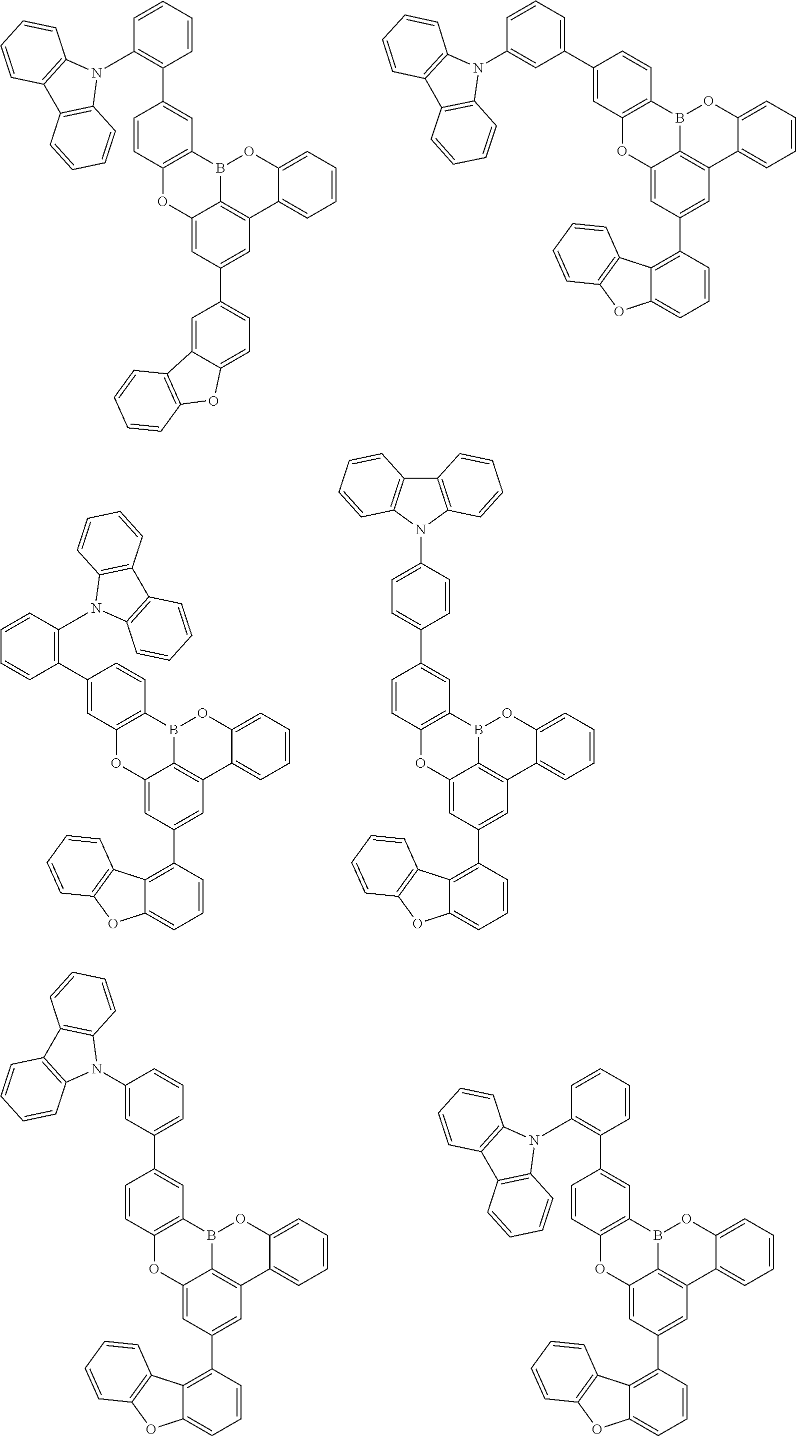

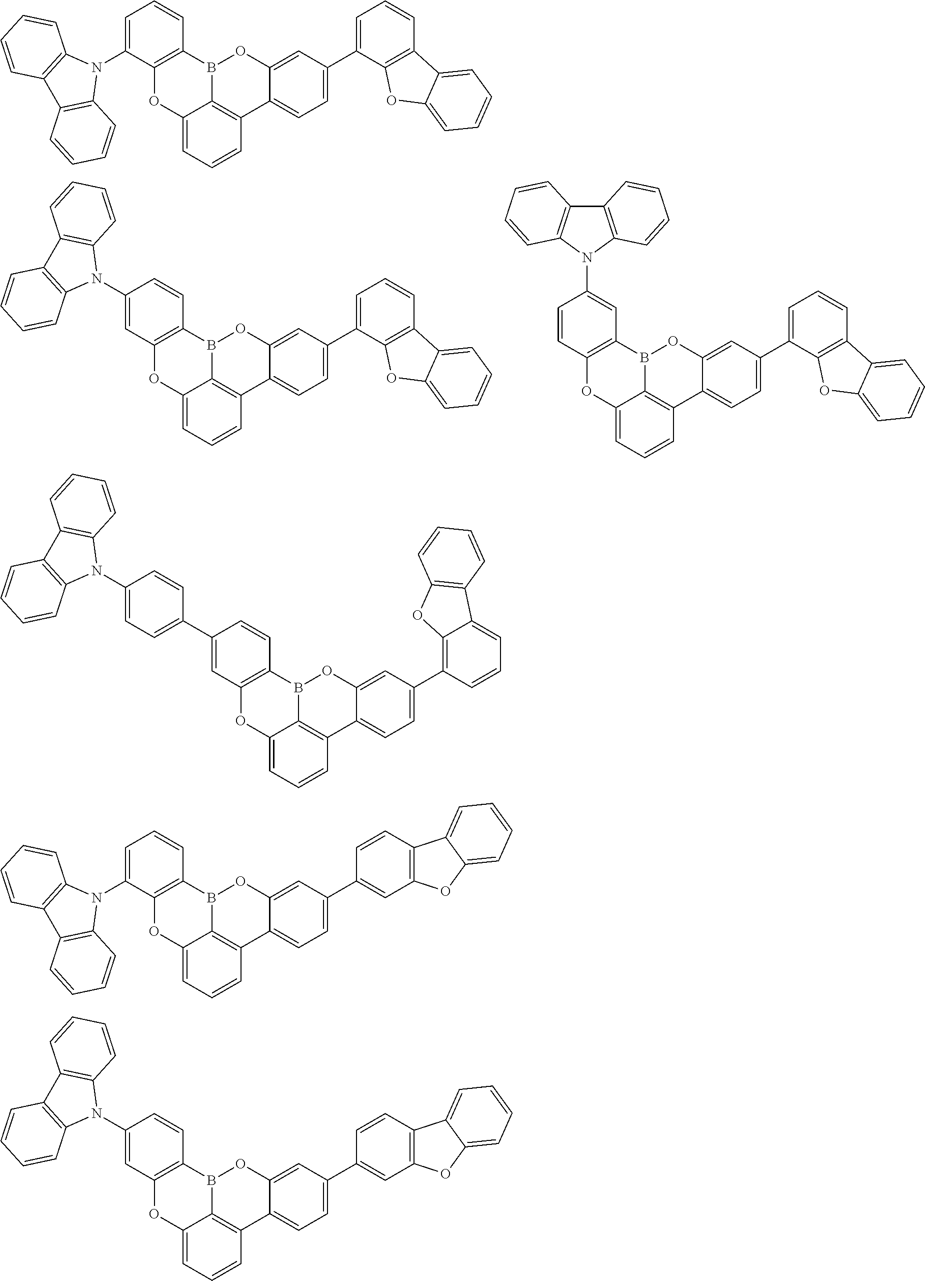

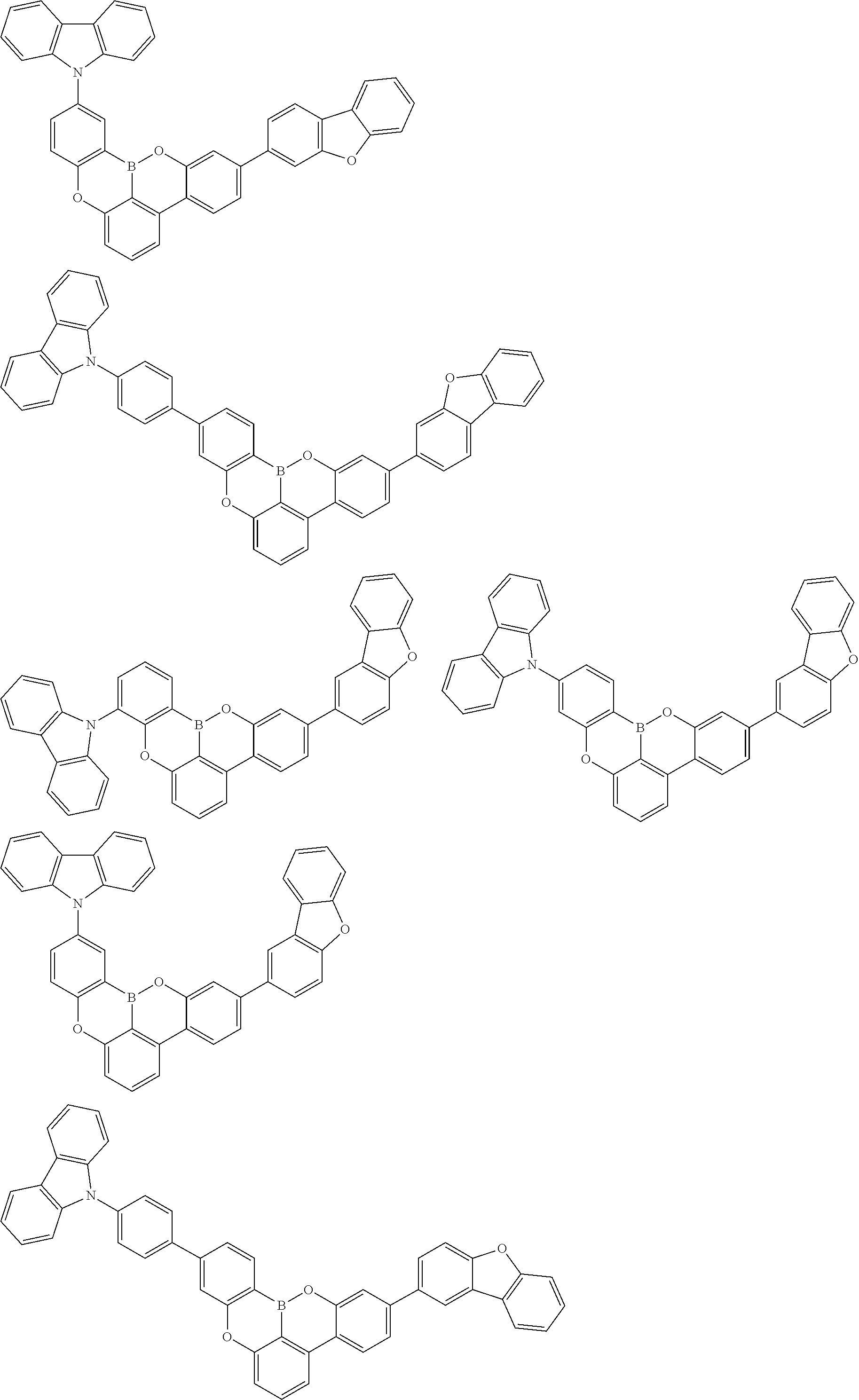

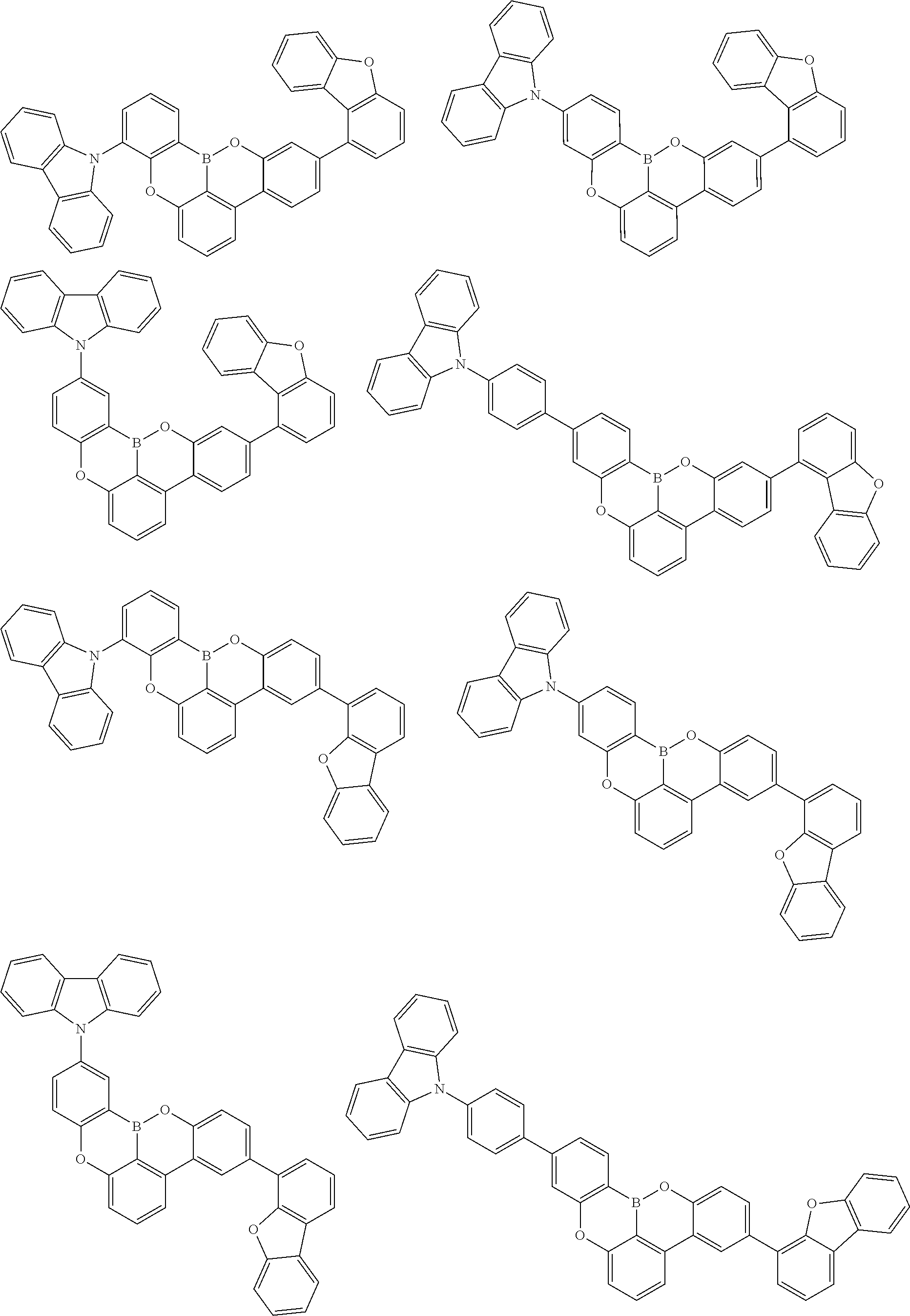

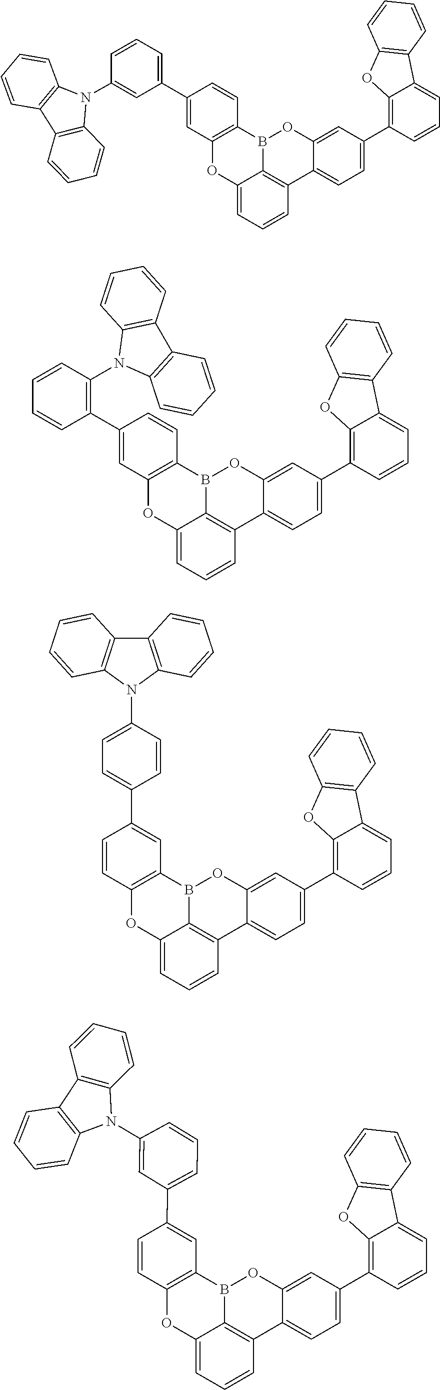

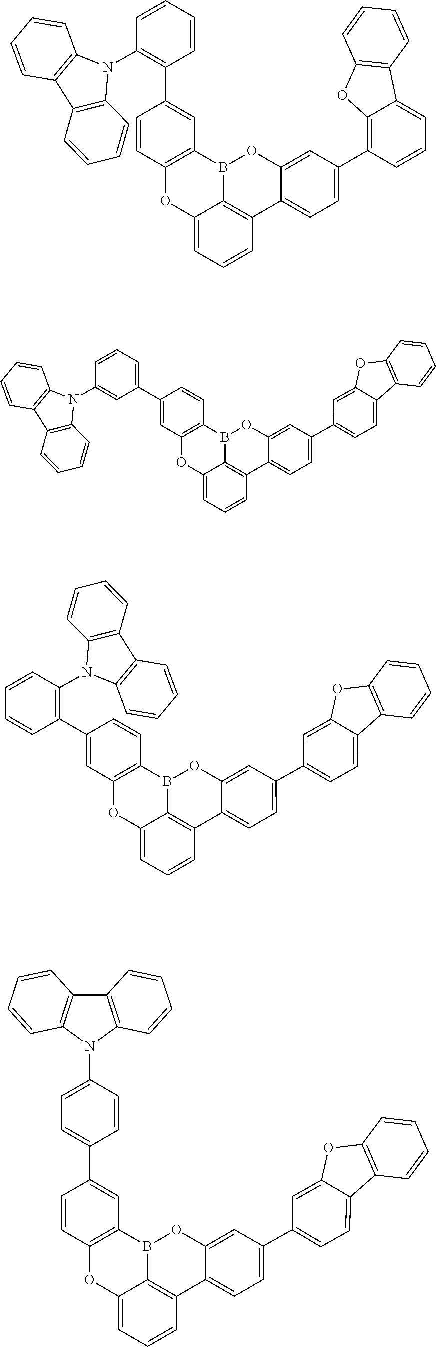 [SMILES: c1ccc(-n2c3ccccc3c3ccccc32)c(-c2ccc3c(c2)B2Oc4cc(-c5cccc6c5oc5ccccc56)ccc4-c4cccc(c42)O3)c1 ; c1cc(-c2ccc3c(c2)Oc2cccc4c2B3Oc2cc(-c3ccc5c(c3)oc3ccccc35)ccc2-4)cc(-n2c3ccccc3c3ccccc32)c1 ; c1ccc(-n2c3ccccc3c3ccccc32)c(-c2ccc3c(c2)Oc2cccc4c2B3Oc2cc(-c3ccc5c(c3)oc3ccccc35)ccc2-4)c1 ; c1cc2c3c(c1)-c1ccc(-c4ccc5c(c4)oc4ccccc45)cc1OB3c1cc(-c3ccc(-n4c5ccccc5c5ccccc54)cc3)ccc1O2]

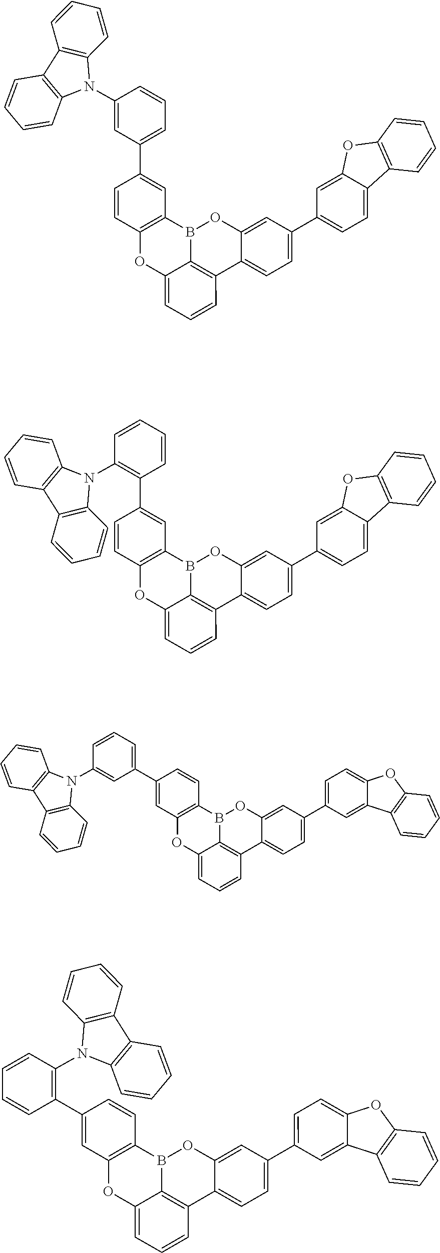 [SMILES: c1cc(-c2ccc3c(c2)B2Oc4cc(-c5ccc6c(c5)oc5ccccc56)ccc4-c4cccc(c42)O3)cc(-n2c3ccccc3c3ccccc32)c1 ; c1ccc(-n2c3ccccc3c3ccccc32)c(-c2ccc3c(c2)B2Oc4cc(-c5ccc6c(c5)oc5ccccc56)ccc4-c4cccc(c42)O3)c1 ; c1cc(-c2ccc3c(c2)Oc2cccc4c2B3Oc2cc(-c3ccc5oc6ccccc6c5c3)ccc2-4)cc(-n2c3ccccc3c3ccccc32)c1 ; c1ccc(-n2c3ccccc3c3ccccc32)c(-c2ccc3c(c2)Oc2cccc4c2B3Oc2cc(-c3ccc5oc6ccccc6c5c3)ccc2-4)c1]

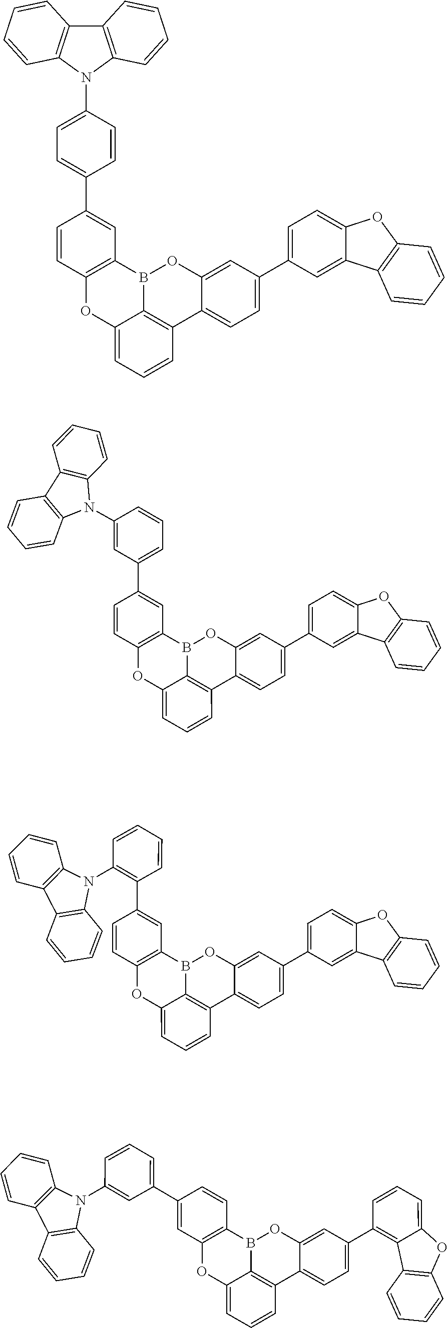 [SMILES: c1cc2c3c(c1)-c1ccc(-c4ccc5oc6ccccc6c5c4)cc1OB3c1cc(-c3ccc(-n4c5ccccc5c5ccccc54)cc3)ccc1O2 ; c1cc(-c2ccc3c(c2)B2Oc4cc(-c5ccc6oc7ccccc7c6c5)ccc4-c4cccc(c42)O3)cc(-n2c3ccccc3c3ccccc32)c1 ; c1ccc(-n2c3ccccc3c3ccccc32)c(-c2ccc3c(c2)B2Oc4cc(-c5ccc6oc7ccccc7c6c5)ccc4-c4cccc(c42)O3)c1 ; c1cc(-c2ccc3c(c2)Oc2cccc4c2B3Oc2cc(-c3cccc5oc6ccccc6c35)ccc2-4)cc(-n2c3ccccc3c3ccccc32)c1]

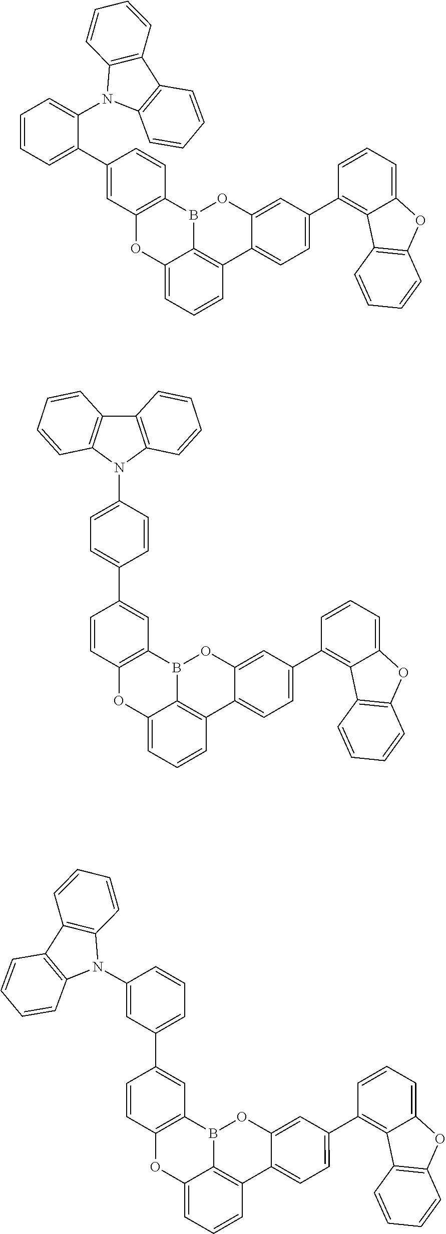 [SMILES: c1ccc(-n2c3ccccc3c3ccccc32)c(-c2ccc3c(c2)Oc2cccc4c2B3Oc2cc(-c3cccc5oc6ccccc6c35)ccc2-4)c1 ; c1cc2c3c(c1)-c1ccc(-c4cccc5oc6ccccc6c45)cc1OB3c1cc(-c3ccc(-n4c5ccccc5c5ccccc54)cc3)ccc1O2 ; c1cc(-c2ccc3c(c2)B2Oc4cc(-c5cccc6oc7ccccc7c56)ccc4-c4cccc(c42)O3)cc(-n2c3ccccc3c3ccccc32)c1]

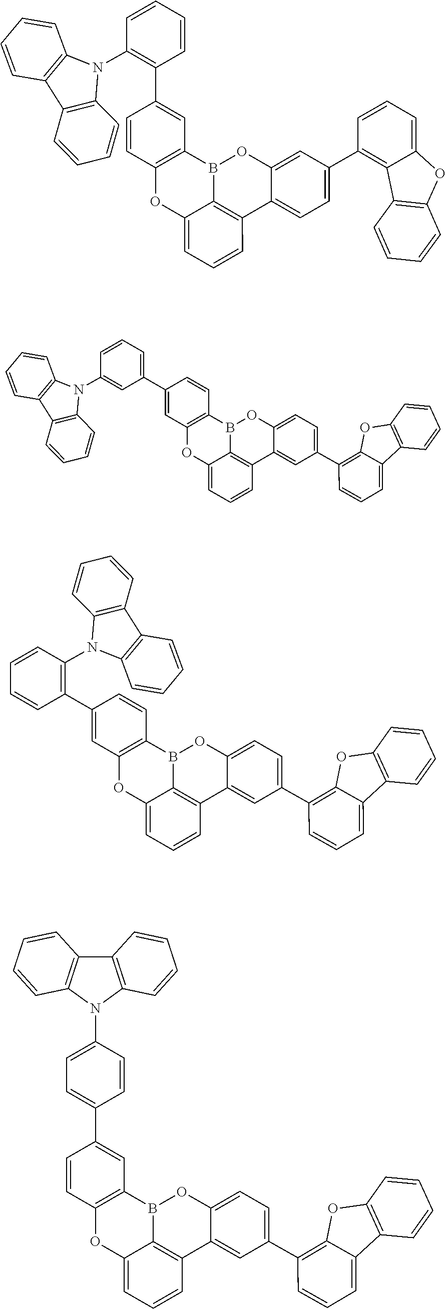 [SMILES: c1ccc(-n2c3ccccc3c3ccccc32)c(-c2ccc3c(c2)B2Oc4cc(-c5cccc6oc7ccccc7c56)ccc4-c4cccc(c42)O3)c1 ; c1cc(-c2ccc3c(c2)Oc2cccc4c2B3Oc2ccc(-c3cccc5c3oc3ccccc35)cc2-4)cc(-n2c3ccccc3c3ccccc32)c1 ; c1ccc(-n2c3ccccc3c3ccccc32)c(-c2ccc3c(c2)Oc2cccc4c2B3Oc2ccc(-c3cccc5c3oc3ccccc35)cc2-4)c1 ; c1cc2c3c(c1)-c1cc(-c4cccc5c4oc4ccccc45)ccc1OB3c1cc(-c3ccc(-n4c5ccccc5c5ccccc54)cc3)ccc1O2]

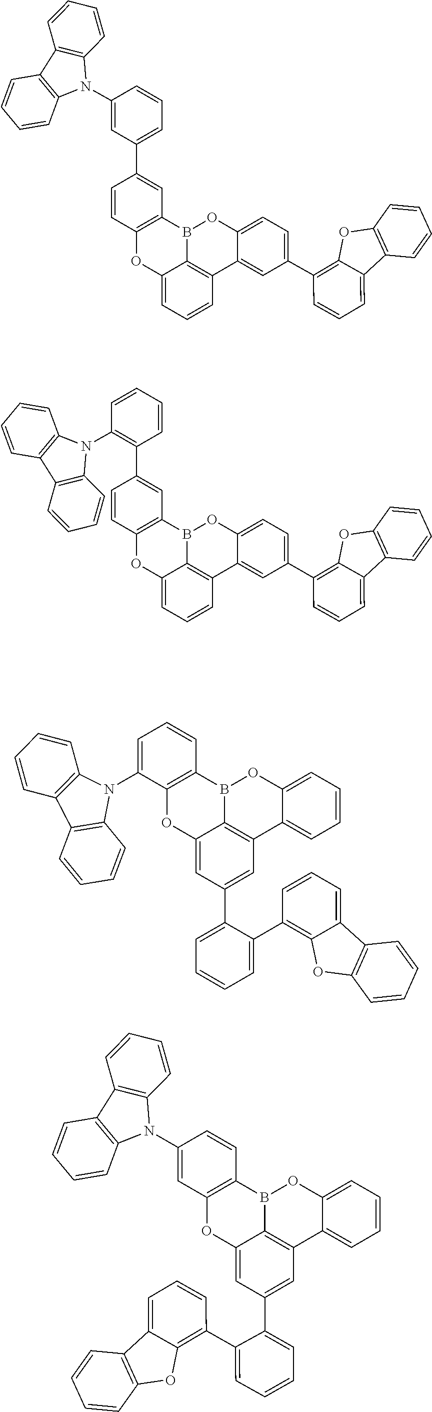 [SMILES: c1cc(-c2ccc3c(c2)B2Oc4ccc(-c5cccc6c5oc5ccccc56)cc4-c4cccc(c42)O3)cc(-n2c3ccccc3c3ccccc32)c1 ; c1ccc(-n2c3ccccc3c3ccccc32)c(-c2ccc3c(c2)B2Oc4ccc(-c5cccc6c5oc5ccccc56)cc4-c4cccc(c42)O3)c1 ; c1ccc2c(c1)OB1c3cccc(-n4c5ccccc5c5ccccc54)c3Oc3cc(-c4ccccc4-c4cccc5c4oc4ccccc45)cc-2c31 ; c1ccc2c(c1)OB1c3ccc(-n4c5ccccc5c5ccccc54)cc3Oc3cc(-c4ccccc4-c4cccc5c4oc4ccccc45)cc-2c31]

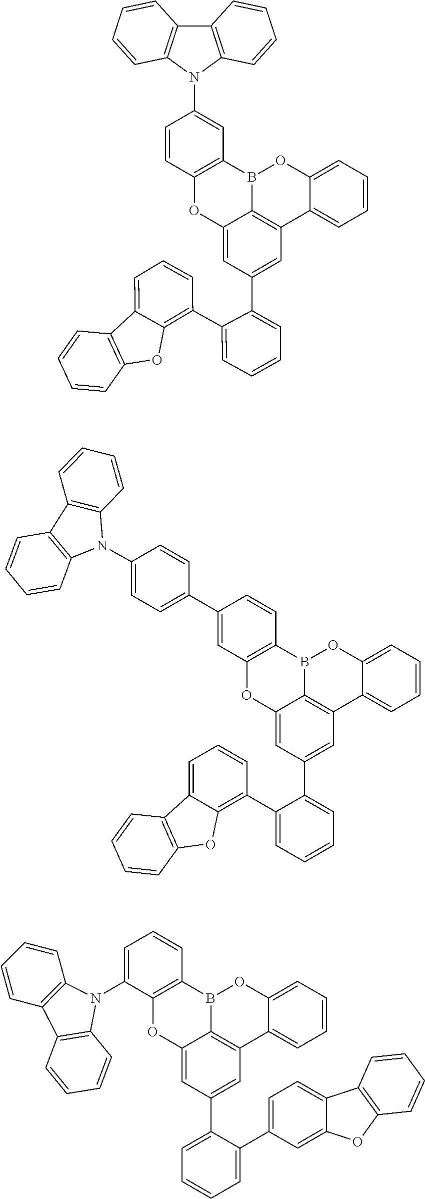 [SMILES: c1ccc2c(c1)OB1c3cc(-n4c5ccccc5c5ccccc54)ccc3Oc3cc(-c4ccccc4-c4cccc5c4oc4ccccc45)cc-2c31 ; c1ccc2c(c1)OB1c3ccc(-c4ccc(-n5c6ccccc6c6ccccc65)cc4)cc3Oc3cc(-c4ccccc4-c4cccc5c4oc4ccccc45)cc-2c31 ; c1ccc2c(c1)OB1c3cccc(-n4c5ccccc5c5ccccc54)c3Oc3cc(-c4ccccc4-c4ccc5c(c4)oc4ccccc45)cc-2c31]

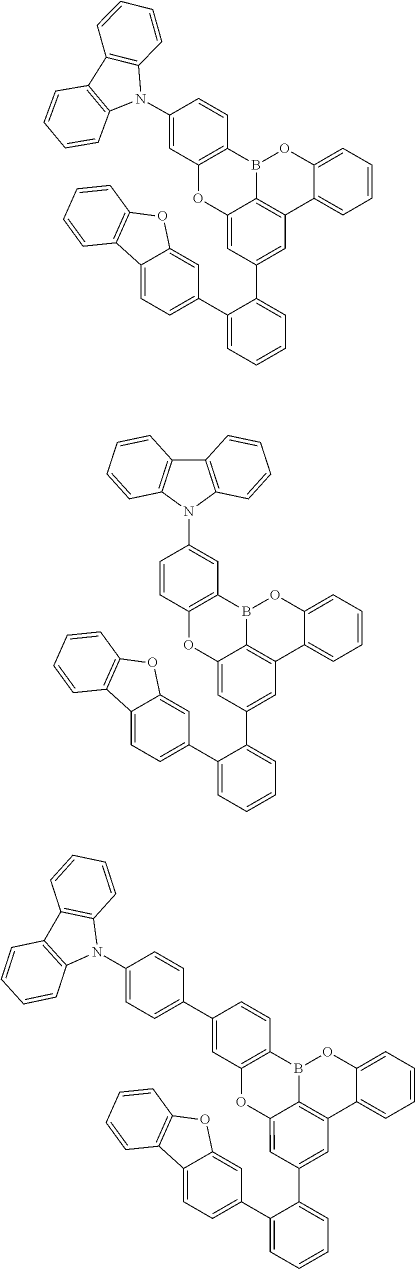 [SMILES: c1ccc2c(c1)OB1c3ccc(-n4c5ccccc5c5ccccc54)cc3Oc3cc(-c4ccccc4-c4ccc5c(c4)oc4ccccc45)cc-2c31 ; c1ccc2c(c1)OB1c3cc(-n4c5ccccc5c5ccccc54)ccc3Oc3cc(-c4ccccc4-c4ccc5c(c4)oc4ccccc45)cc-2c31 ; c1ccc2c(c1)OB1c3ccc(-c4ccc(-n5c6ccccc6c6ccccc65)cc4)cc3Oc3cc(-c4ccccc4-c4ccc5c(c4)oc4ccccc45)cc-2c31]

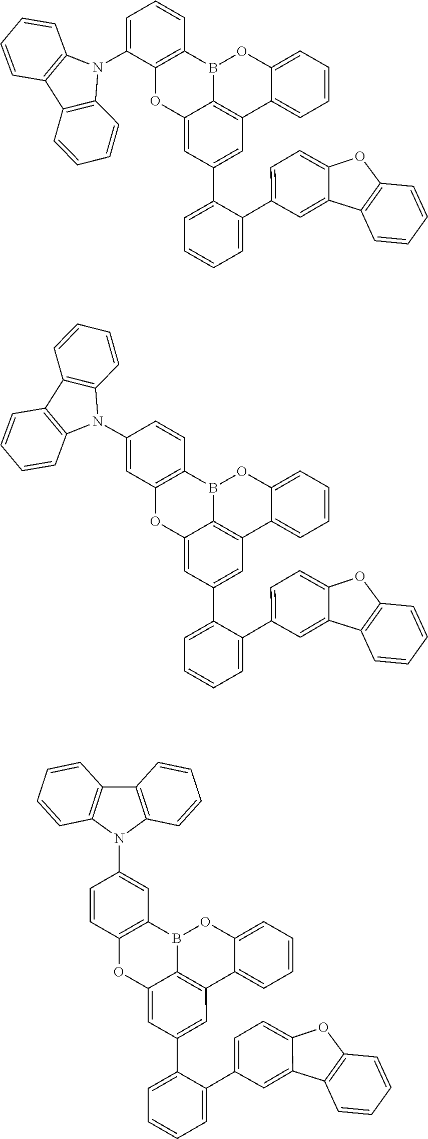 [SMILES: c1ccc2c(c1)OB1c3cccc(-n4c5ccccc5c5ccccc54)c3Oc3cc(-c4ccccc4-c4ccc5oc6ccccc6c5c4)cc-2c31 ; c1ccc2c(c1)OB1c3ccc(-n4c5ccccc5c5ccccc54)cc3Oc3cc(-c4ccccc4-c4ccc5oc6ccccc6c5c4)cc-2c31 ; c1ccc2c(c1)OB1c3cc(-n4c5ccccc5c5ccccc54)ccc3Oc3cc(-c4ccccc4-c4ccc5oc6ccccc6c5c4)cc-2c31]

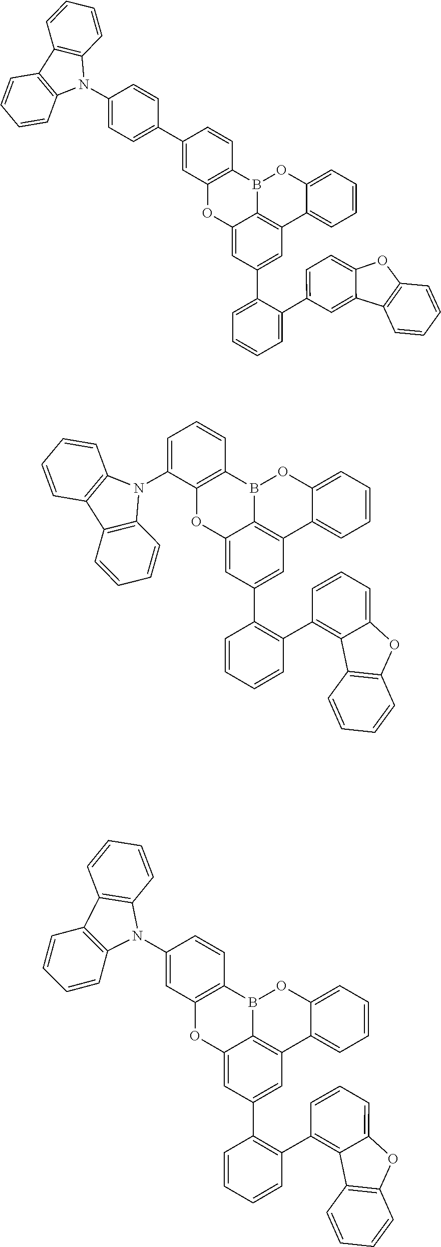 [SMILES: c1ccc2c(c1)OB1c3ccc(-c4ccc(-n5c6ccccc6c6ccccc65)cc4)cc3Oc3cc(-c4ccccc4-c4ccc5oc6ccccc6c5c4)cc-2c31 ; c1ccc2c(c1)OB1c3cccc(-n4c5ccccc5c5ccccc54)c3Oc3cc(-c4ccccc4-c4cccc5oc6ccccc6c45)cc-2c31 ; c1ccc2c(c1)OB1c3ccc(-n4c5ccccc5c5ccccc54)cc3Oc3cc(-c4ccccc4-c4cccc5oc6ccccc6c45)cc-2c31]

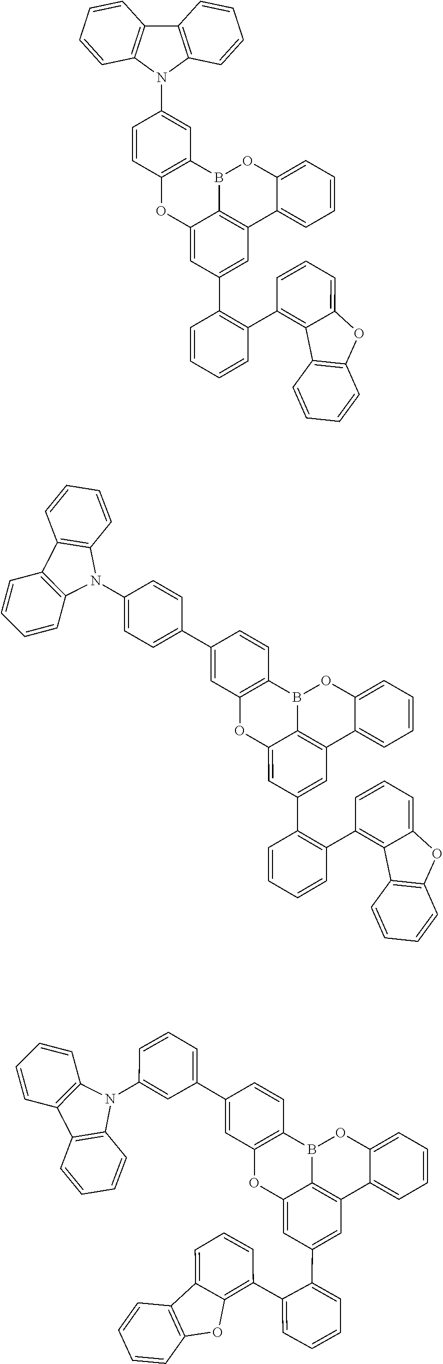 [SMILES: c1ccc2c(c1)OB1c3cc(-n4c5ccccc5c5ccccc54)ccc3Oc3cc(-c4ccccc4-c4cccc5oc6ccccc6c45)cc-2c31 ; c1ccc2c(c1)OB1c3ccc(-c4ccc(-n5c6ccccc6c6ccccc65)cc4)cc3Oc3cc(-c4ccccc4-c4cccc5oc6ccccc6c45)cc-2c31 ; c1cc(-c2ccc3c(c2)Oc2cc(-c4ccccc4-c4cccc5c4oc4ccccc45)cc4c2B3Oc2ccccc2-4)cc(-n2c3ccccc3c3ccccc32)c1]

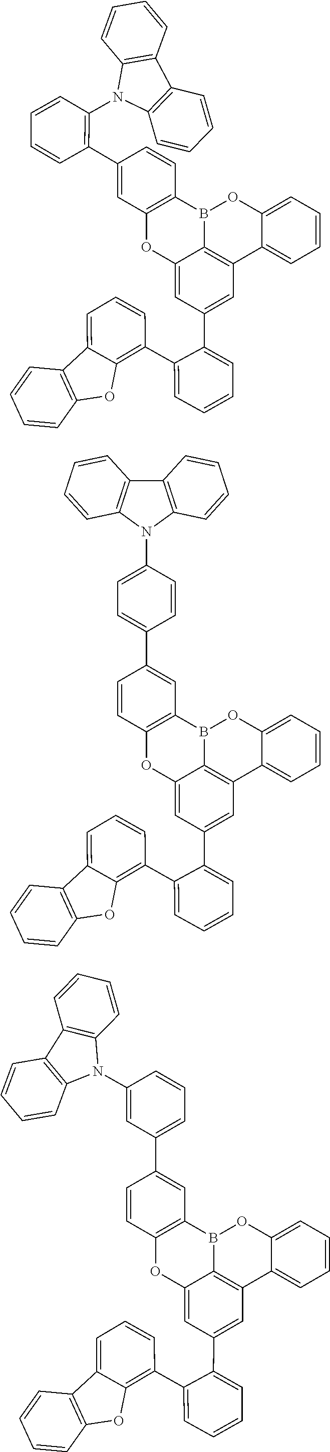

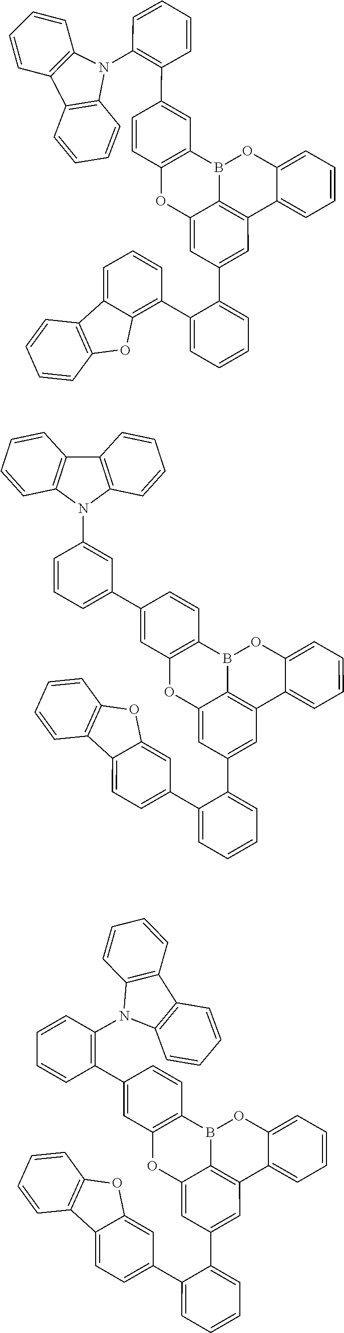 [SMILES: c1ccc2c(c1)OB1c3cc(-c4ccccc4-n4c5ccccc5c5ccccc54)ccc3Oc3cc(-c4ccccc4-c4cccc5c4oc4ccccc45)cc-2c31 ; c1cc(-c2ccc3c(c2)Oc2cc(-c4ccccc4-c4ccc5c(c4)oc4ccccc45)cc4c2B3Oc2ccccc2-4)cc(-n2c3ccccc3c3ccccc32)c1 ; c1ccc2c(c1)OB1c3ccc(-c4ccccc4-n4c5ccccc5c5ccccc54)cc3Oc3cc(-c4ccccc4-c4ccc5c(c4)oc4ccccc45)cc-2c31]

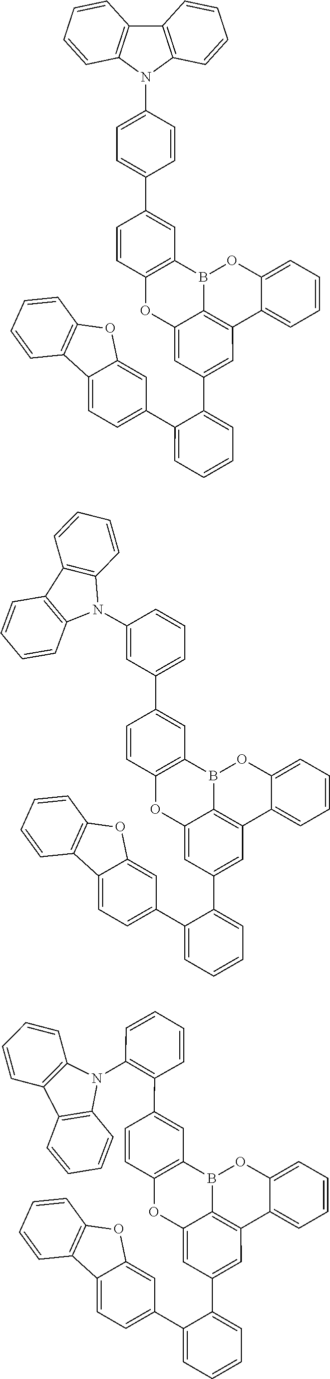 [SMILES: c1ccc2c(c1)OB1c3cc(-c4ccc(-n5c6ccccc6c6ccccc65)cc4)ccc3Oc3cc(-c4ccccc4-c4ccc5c(c4)oc4ccccc45)cc-2c31 ; c1cc(-c2ccc3c(c2)B2Oc4ccccc4-c4cc(-c5ccccc5-c5ccc6c(c5)oc5ccccc56)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-c4ccccc4-c4ccc5c(c4)oc4ccccc45)cc-2c31]

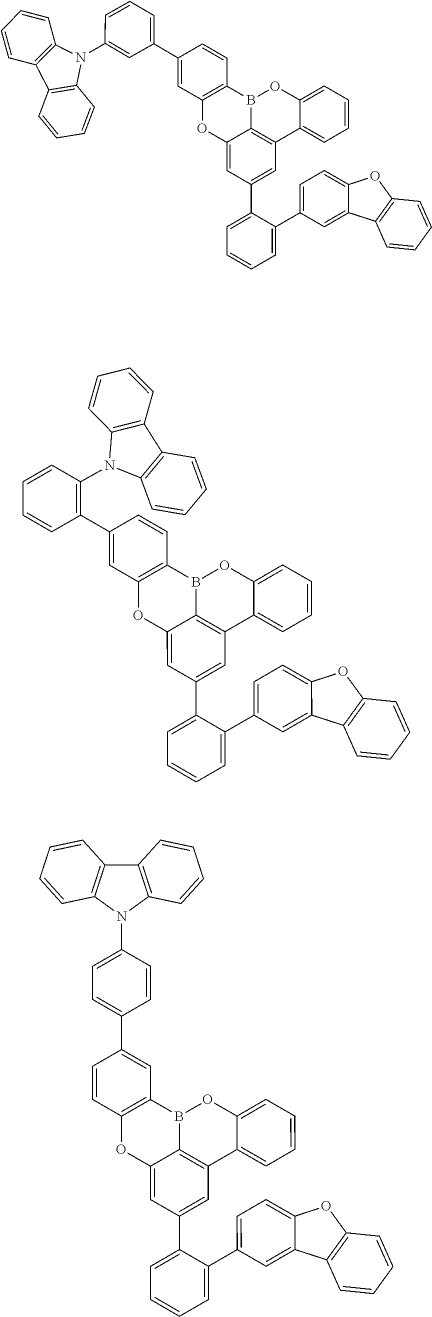 [SMILES: c1cc(-c2ccc3c(c2)Oc2cc(-c4ccccc4-c4ccc5oc6ccccc6c5c4)cc4c2B3Oc2ccccc2-4)cc(-n2c3ccccc3c3ccccc32)c1 ; c1ccc2c(c1)OB1c3ccc(-c4ccccc4-n4c5ccccc5c5ccccc54)cc3Oc3cc(-c4ccccc4-c4ccc5oc6ccccc6c5c4)cc-2c31 ; c1ccc2c(c1)OB1c3cc(-c4ccc(-n5c6ccccc6c6ccccc65)cc4)ccc3Oc3cc(-c4ccccc4-c4ccc5oc6ccccc6c5c4)cc-2c31]

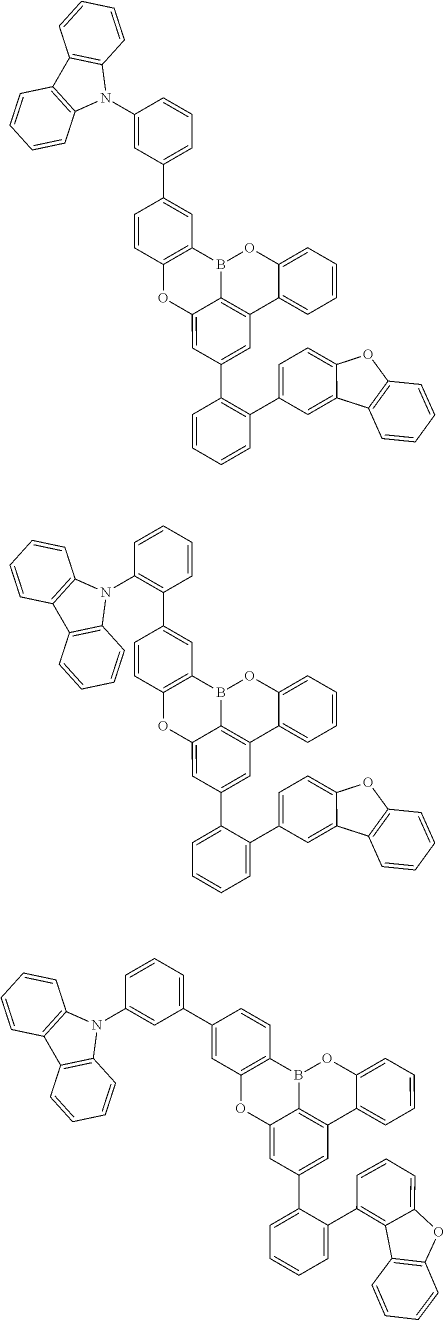 [SMILES: c1cc(-c2ccc3c(c2)B2Oc4ccccc4-c4cc(-c5ccccc5-c5ccc6oc7ccccc7c6c5)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-c4ccccc4-c4ccc5oc6ccccc6c5c4)cc-2c31 ; c1cc(-c2ccc3c(c2)Oc2cc(-c4ccccc4-c4cccc5oc6ccccc6c45)cc4c2B3Oc2ccccc2-4)cc(-n2c3ccccc3c3ccccc32)c1]

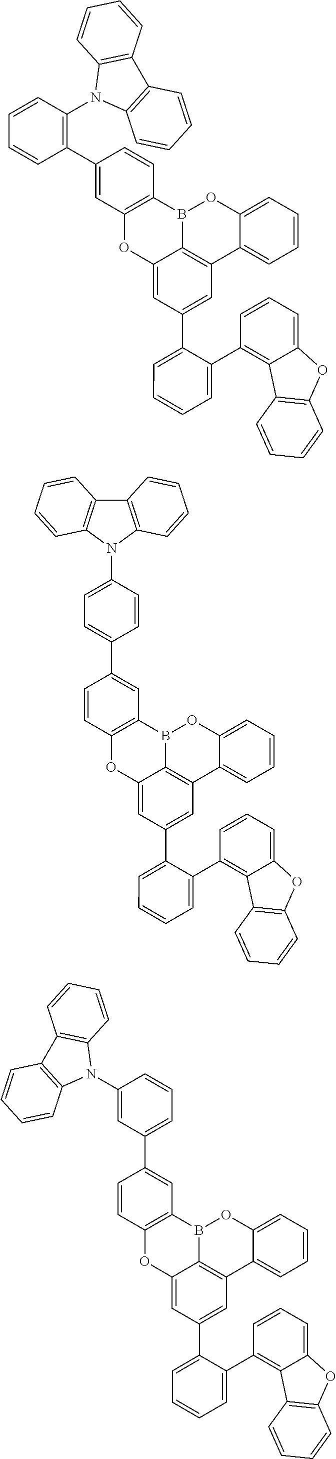 [SMILES: c1ccc2c(c1)OB1c3ccc(-c4ccccc4-n4c5ccccc5c5ccccc54)cc3Oc3cc(-c4ccccc4-c4cccc5oc6ccccc6c45)cc-2c31 ; c1ccc2c(c1)OB1c3cc(-c4ccc(-n5c6ccccc6c6ccccc65)cc4)ccc3Oc3cc(-c4ccccc4-c4cccc5oc6ccccc6c45)cc-2c31 ; c1cc(-c2ccc3c(c2)B2Oc4ccccc4-c4cc(-c5ccccc5-c5cccc6oc7ccccc7c56)cc(c42)O3)cc(-n2c3ccccc3c3ccccc32)c1]

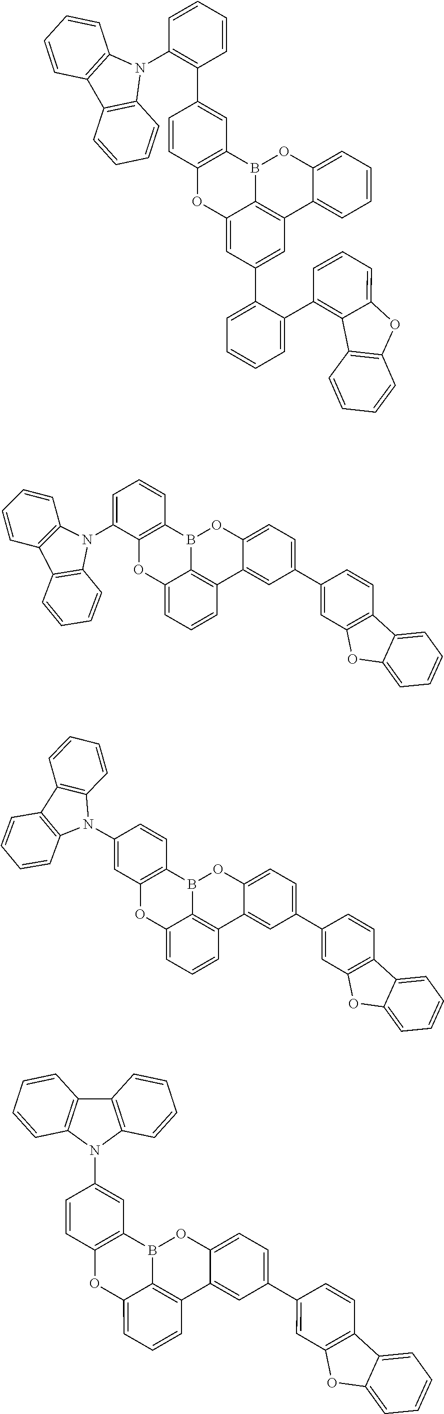 [SMILES: c1ccc2c(c1)OB1c3cc(-c4ccccc4-n4c5ccccc5c5ccccc54)ccc3Oc3cc(-c4ccccc4-c4cccc5oc6ccccc6c45)cc-2c31 ; c1cc2c3c(c1)-c1cc(-c4ccc5c(c4)oc4ccccc45)ccc1OB3c1cccc(-n3c4ccccc4c4ccccc43)c1O2 ; c1cc2c3c(c1)-c1cc(-c4ccc5c(c4)oc4ccccc45)ccc1OB3c1ccc(-n3c4ccccc4c4ccccc43)cc1O2 ; c1cc2c3c(c1)-c1cc(-c4ccc5c(c4)oc4ccccc45)ccc1OB3c1cc(-n3c4ccccc4c4ccccc43)ccc1O2]

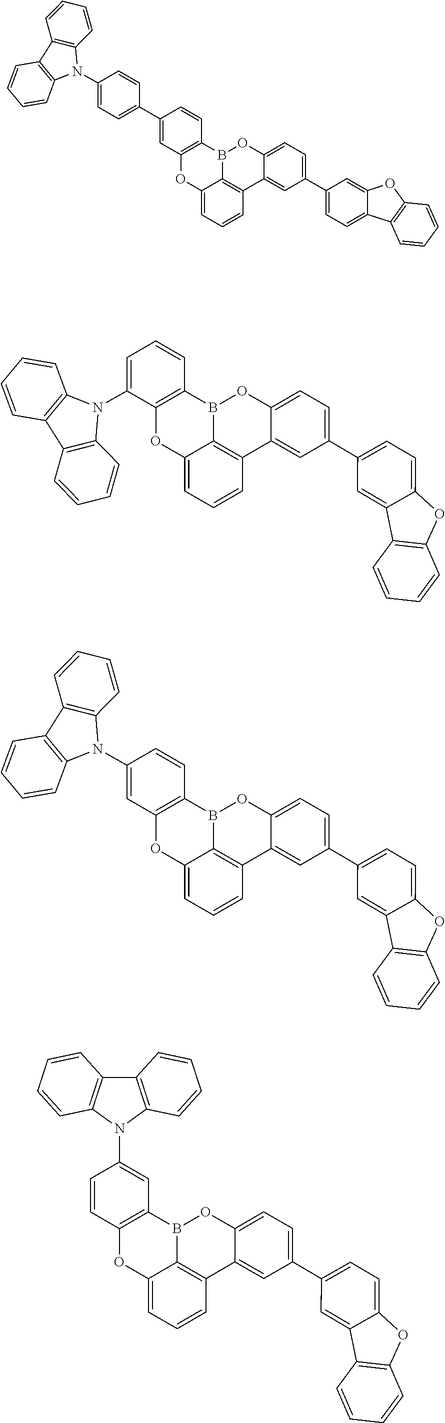 [SMILES: c1cc2c3c(c1)-c1cc(-c4ccc5c(c4)oc4ccccc45)ccc1OB3c1ccc(-c3ccc(-n4c5ccccc5c5ccccc54)cc3)cc1O2 ; c1cc2c3c(c1)-c1cc(-c4ccc5oc6ccccc6c5c4)ccc1OB3c1cccc(-n3c4ccccc4c4ccccc43)c1O2 ; c1cc2c3c(c1)-c1cc(-c4ccc5oc6ccccc6c5c4)ccc1OB3c1ccc(-n3c4ccccc4c4ccccc43)cc1O2 ; c1cc2c3c(c1)-c1cc(-c4ccc5oc6ccccc6c5c4)ccc1OB3c1cc(-n3c4ccccc4c4ccccc43)ccc1O2]

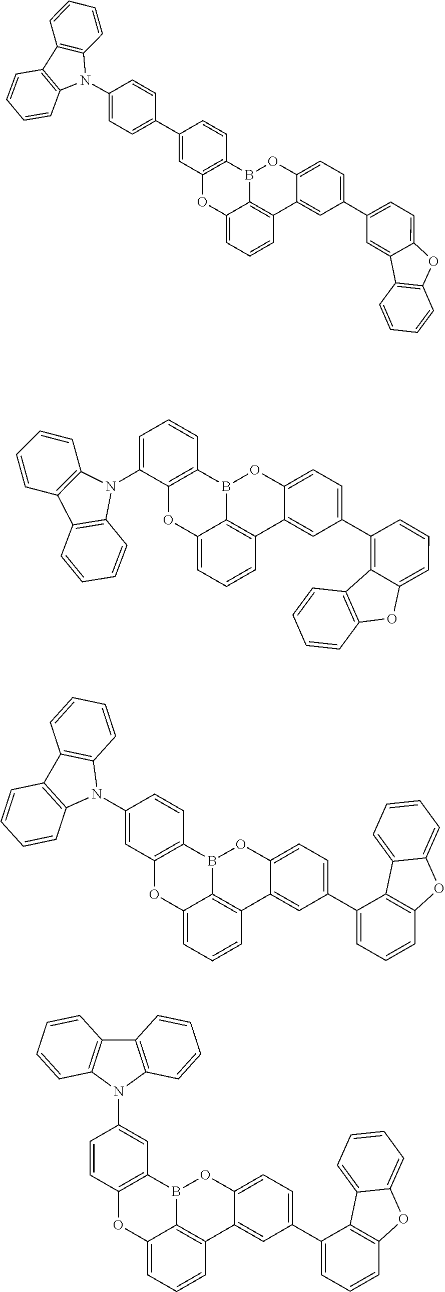 [SMILES: c1cc2c3c(c1)-c1cc(-c4ccc5oc6ccccc6c5c4)ccc1OB3c1ccc(-c3ccc(-n4c5ccccc5c5ccccc54)cc3)cc1O2 ; c1cc2c3c(c1)-c1cc(-c4cccc5oc6ccccc6c45)ccc1OB3c1cccc(-n3c4ccccc4c4ccccc43)c1O2 ; c1cc2c3c(c1)-c1cc(-c4cccc5oc6ccccc6c45)ccc1OB3c1ccc(-n3c4ccccc4c4ccccc43)cc1O2 ; c1cc2c3c(c1)-c1cc(-c4cccc5oc6ccccc6c45)ccc1OB3c1cc(-n3c4ccccc4c4ccccc43)ccc1O2]

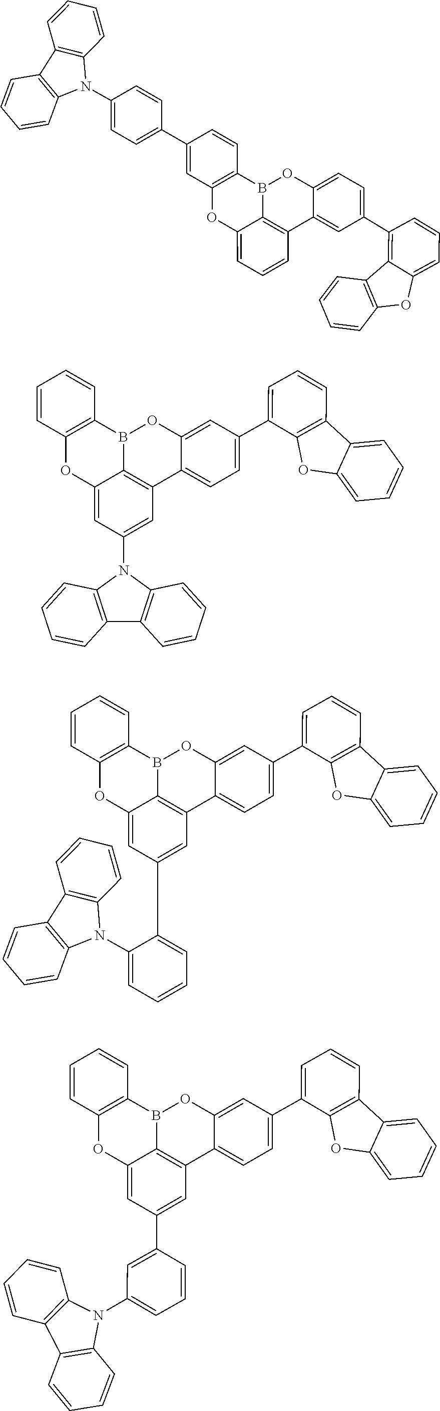 [SMILES: c1cc2c3c(c1)-c1cc(-c4cccc5oc6ccccc6c45)ccc1OB3c1ccc(-c3ccc(-n4c5ccccc5c5ccccc54)cc3)cc1O2 ; c1ccc2c(c1)Oc1cc(-n3c4ccccc4c4ccccc43)cc3c1B2Oc1cc(-c2cccc4c2oc2ccccc24)ccc1-3 ; c1ccc2c(c1)Oc1cc(-c3ccccc3-n3c4ccccc4c4ccccc43)cc3c1B2Oc1cc(-c2cccc4c2oc2ccccc24)ccc1-3 ; c1cc(-c2cc3c4c(c2)-c2ccc(-c5cccc6c5oc5ccccc56)cc2OB4c2ccccc2O3)cc(-n2c3ccccc3c3ccccc32)c1]

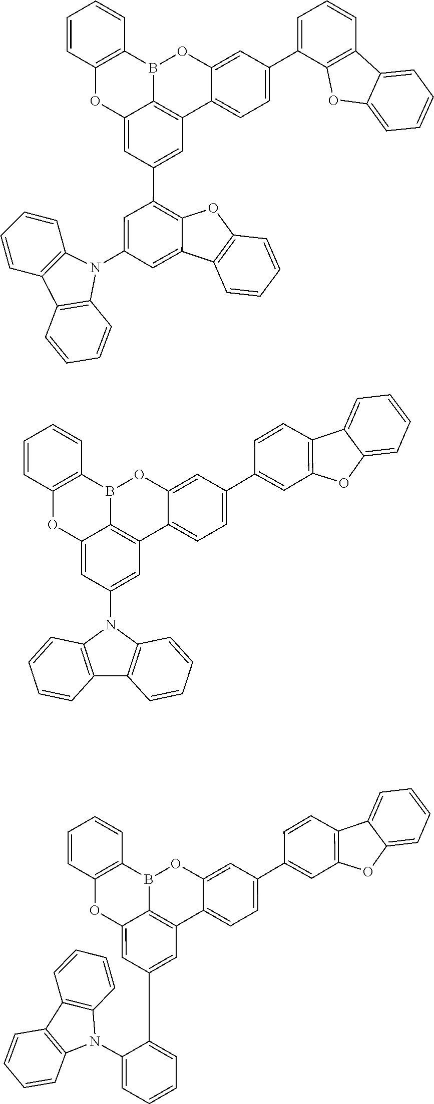 [SMILES: c1ccc2c(c1)Oc1cc(-c3cc(-n4c5ccccc5c5ccccc54)cc4c3oc3ccccc34)cc3c1B2Oc1cc(-c2cccc4c2oc2ccccc24)ccc1-3 ; c1ccc2c(c1)Oc1cc(-n3c4ccccc4c4ccccc43)cc3c1B2Oc1cc(-c2ccc4c(c2)oc2ccccc24)ccc1-3 ; c1ccc2c(c1)Oc1cc(-c3ccccc3-n3c4ccccc4c4ccccc43)cc3c1B2Oc1cc(-c2ccc4c(c2)oc2ccccc24)ccc1-3]

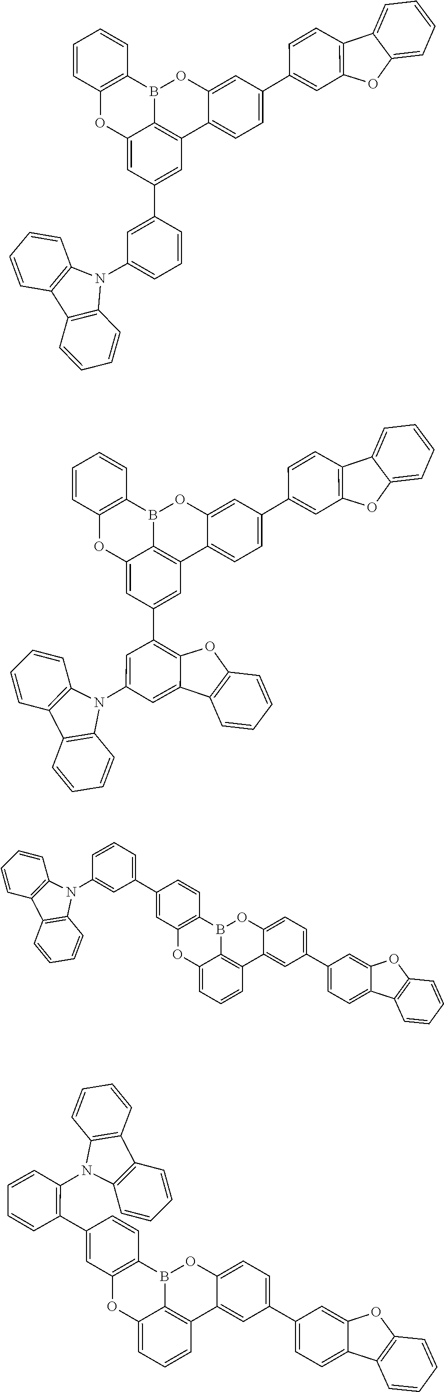 [SMILES: c1cc(-c2cc3c4c(c2)-c2ccc(-c5ccc6c(c5)oc5ccccc56)cc2OB4c2ccccc2O3)cc(-n2c3ccccc3c3ccccc32)c1 ; c1ccc2c(c1)Oc1cc(-c3cc(-n4c5ccccc5c5ccccc54)cc4c3oc3ccccc34)cc3c1B2Oc1cc(-c2ccc4c(c2)oc2ccccc24)ccc1-3 ; c1cc(-c2ccc3c(c2)Oc2cccc4c2B3Oc2ccc(-c3ccc5c(c3)oc3ccccc35)cc2-4)cc(-n2c3ccccc3c3ccccc32)c1 ; c1ccc(-n2c3ccccc3c3ccccc32)c(-c2ccc3c(c2)Oc2cccc4c2B3Oc2ccc(-c3ccc5c(c3)oc3ccccc35)cc2-4)c1]

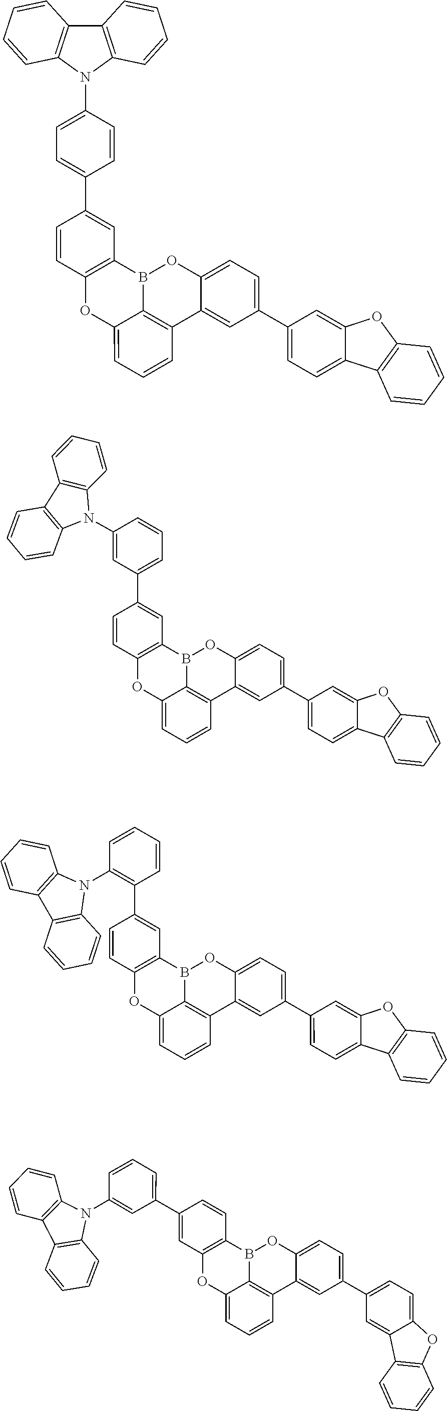 [SMILES: c1cc2c3c(c1)-c1cc(-c4ccc5c(c4)oc4ccccc45)ccc1OB3c1cc(-c3ccc(-n4c5ccccc5c5ccccc54)cc3)ccc1O2 ; c1cc(-c2ccc3c(c2)B2Oc4ccc(-c5ccc6c(c5)oc5ccccc56)cc4-c4cccc(c42)O3)cc(-n2c3ccccc3c3ccccc32)c1 ; c1ccc(-n2c3ccccc3c3ccccc32)c(-c2ccc3c(c2)B2Oc4ccc(-c5ccc6c(c5)oc5ccccc56)cc4-c4cccc(c42)O3)c1 ; c1cc(-c2ccc3c(c2)Oc2cccc4c2B3Oc2ccc(-c3ccc5oc6ccccc6c5c3)cc2-4)cc(-n2c3ccccc3c3ccccc32)c1]

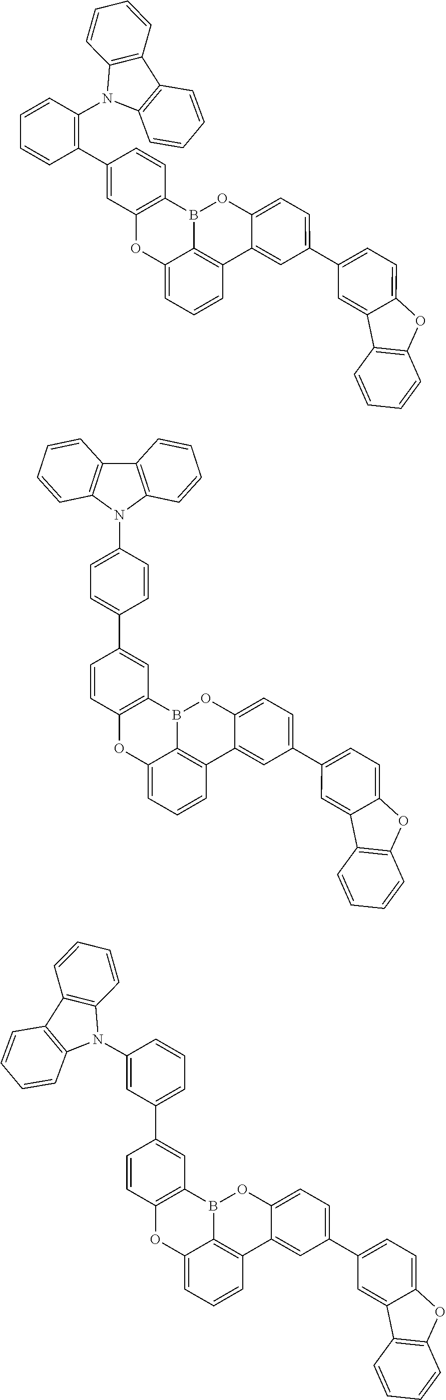 [SMILES: c1ccc(-n2c3ccccc3c3ccccc32)c(-c2ccc3c(c2)Oc2cccc4c2B3Oc2ccc(-c3ccc5oc6ccccc6c5c3)cc2-4)c1 ; c1cc2c3c(c1)-c1cc(-c4ccc5oc6ccccc6c5c4)ccc1OB3c1cc(-c3ccc(-n4c5ccccc5c5ccccc54)cc3)ccc1O2 ; c1cc(-c2ccc3c(c2)B2Oc4ccc(-c5ccc6oc7ccccc7c6c5)cc4-c4cccc(c42)O3)cc(-n2c3ccccc3c3ccccc32)c1]

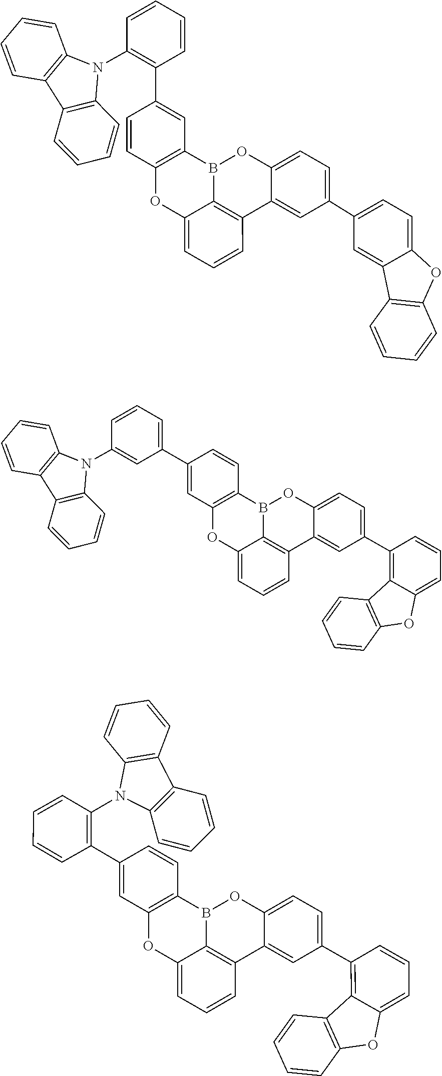 [SMILES: c1ccc(-n2c3ccccc3c3ccccc32)c(-c2ccc3c(c2)B2Oc4ccc(-c5ccc6oc7ccccc7c6c5)cc4-c4cccc(c42)O3)c1 ; c1cc(-c2ccc3c(c2)Oc2cccc4c2B3Oc2ccc(-c3cccc5oc6ccccc6c35)cc2-4)cc(-n2c3ccccc3c3ccccc32)c1 ; c1ccc(-n2c3ccccc3c3ccccc32)c(-c2ccc3c(c2)Oc2cccc4c2B3Oc2ccc(-c3cccc5oc6ccccc6c35)cc2-4)c1]

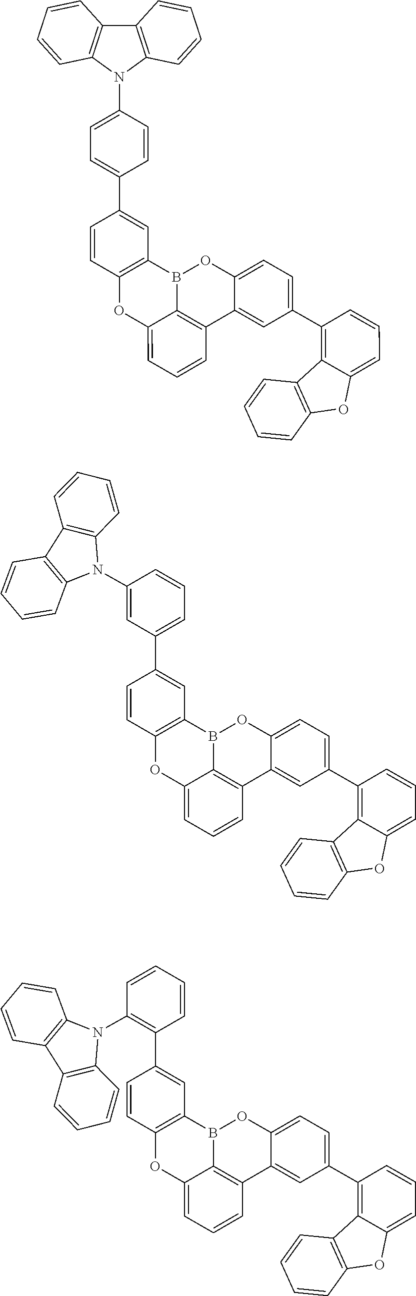 [SMILES: c1cc2c3c(c1)-c1cc(-c4cccc5oc6ccccc6c45)ccc1OB3c1cc(-c3ccc(-n4c5ccccc5c5ccccc54)cc3)ccc1O2 ; c1cc(-c2ccc3c(c2)B2Oc4ccc(-c5cccc6oc7ccccc7c56)cc4-c4cccc(c42)O3)cc(-n2c3ccccc3c3ccccc32)c1 ; c1ccc(-n2c3ccccc3c3ccccc32)c(-c2ccc3c(c2)B2Oc4ccc(-c5cccc6oc7ccccc7c56)cc4-c4cccc(c42)O3)c1]

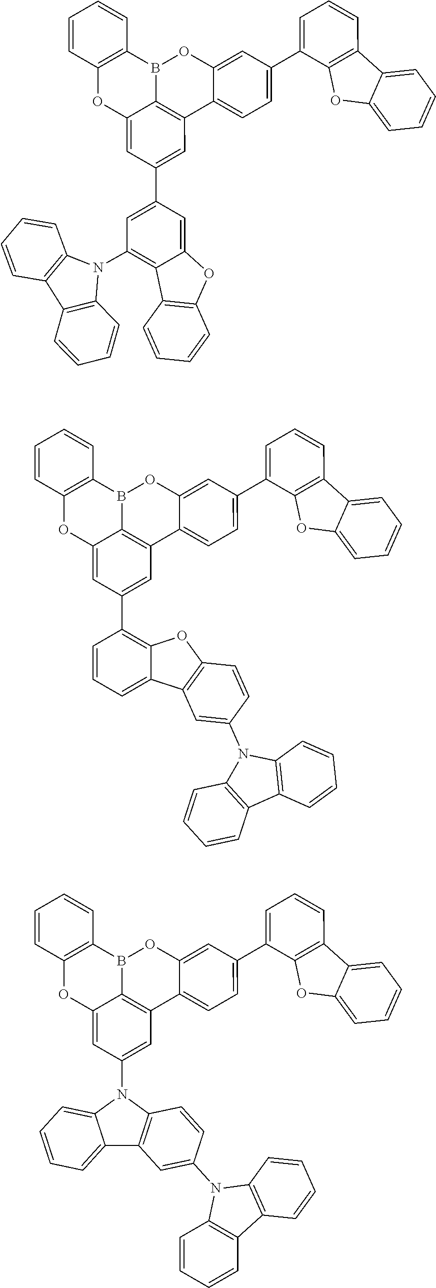 [SMILES: c1ccc2c(c1)Oc1cc(-c3cc(-n4c5ccccc5c5ccccc54)c4c(c3)oc3ccccc34)cc3c1B2Oc1cc(-c2cccc4c2oc2ccccc24)ccc1-3 ; c1ccc2c(c1)Oc1cc(-c3cccc4c3oc3ccc(-n5c6ccccc6c6ccccc65)cc34)cc3c1B2Oc1cc(-c2cccc4c2oc2ccccc24)ccc1-3 ; c1ccc2c(c1)Oc1cc(-n3c4ccccc4c4cc(-n5c6ccccc6c6ccccc65)ccc43)cc3c1B2Oc1cc(-c2cccc4c2oc2ccccc24)ccc1-3]

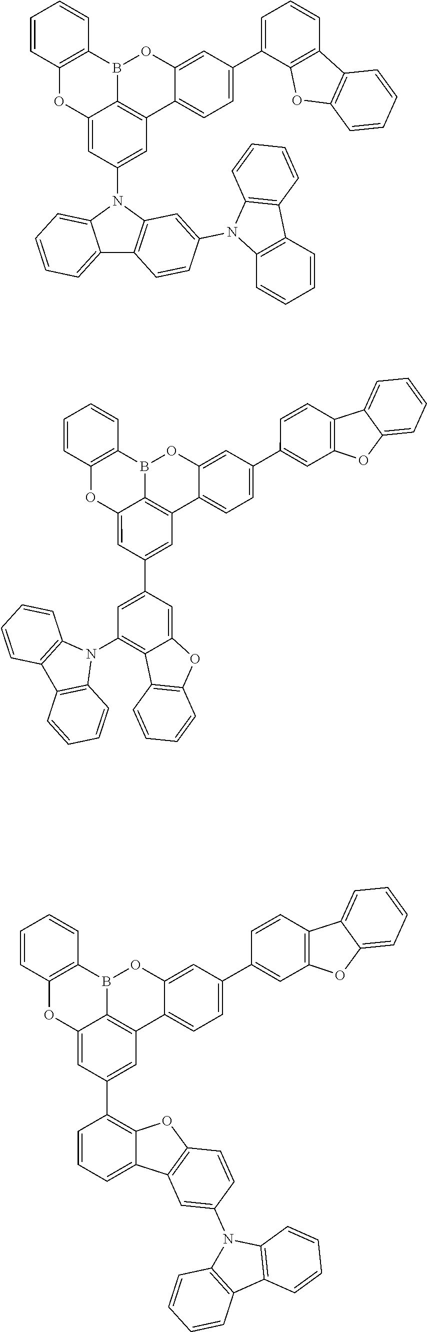 [SMILES: c1ccc2c(c1)Oc1cc(-n3c4ccccc4c4ccc(-n5c6ccccc6c6ccccc65)cc43)cc3c1B2Oc1cc(-c2cccc4c2oc2ccccc24)ccc1-3 ; c1ccc2c(c1)Oc1cc(-c3cc(-n4c5ccccc5c5ccccc54)c4c(c3)oc3ccccc34)cc3c1B2Oc1cc(-c2ccc4c(c2)oc2ccccc24)ccc1-3 ; c1ccc2c(c1)Oc1cc(-c3cccc4c3oc3ccc(-n5c6ccccc6c6ccccc65)cc34)cc3c1B2Oc1cc(-c2ccc4c(c2)oc2ccccc24)ccc1-3]

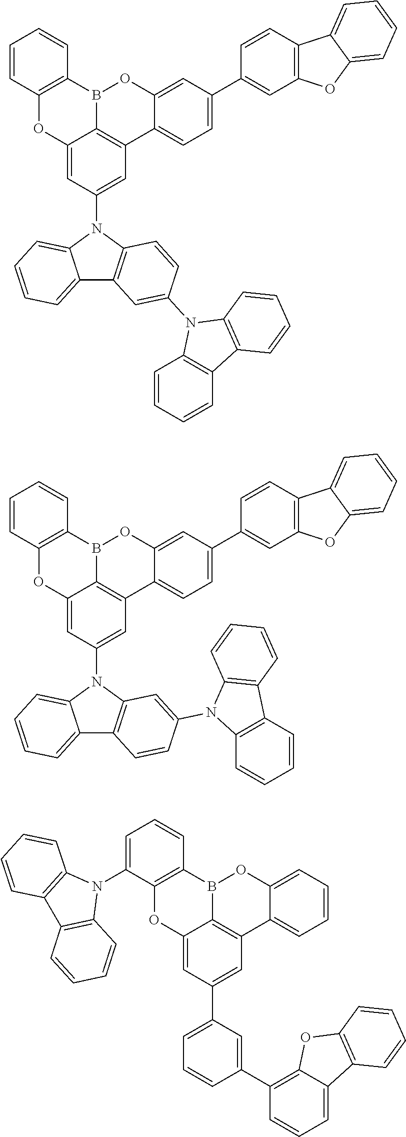

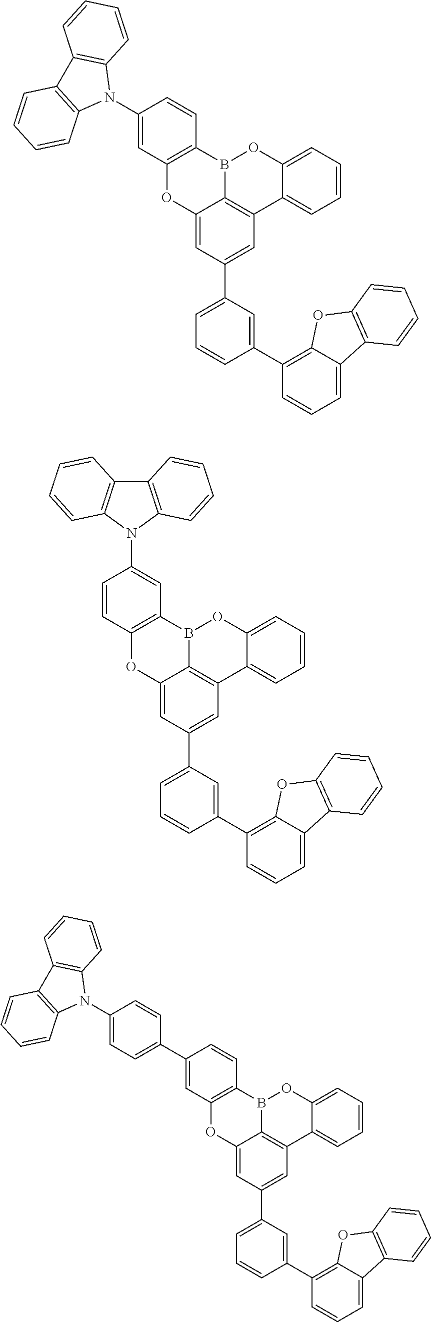 [SMILES: c1cc(-c2cc3c4c(c2)-c2ccccc2OB4c2ccc(-n4c5ccccc5c5ccccc54)cc2O3)cc(-c2cccc3c2oc2ccccc23)c1 ; c1cc(-c2cc3c4c(c2)-c2ccccc2OB4c2cc(-n4c5ccccc5c5ccccc54)ccc2O3)cc(-c2cccc3c2oc2ccccc23)c1 ; c1cc(-c2cc3c4c(c2)-c2ccccc2OB4c2ccc(-c4ccc(-n5c6ccccc6c6ccccc65)cc4)cc2O3)cc(-c2cccc3c2oc2ccccc23)c1]

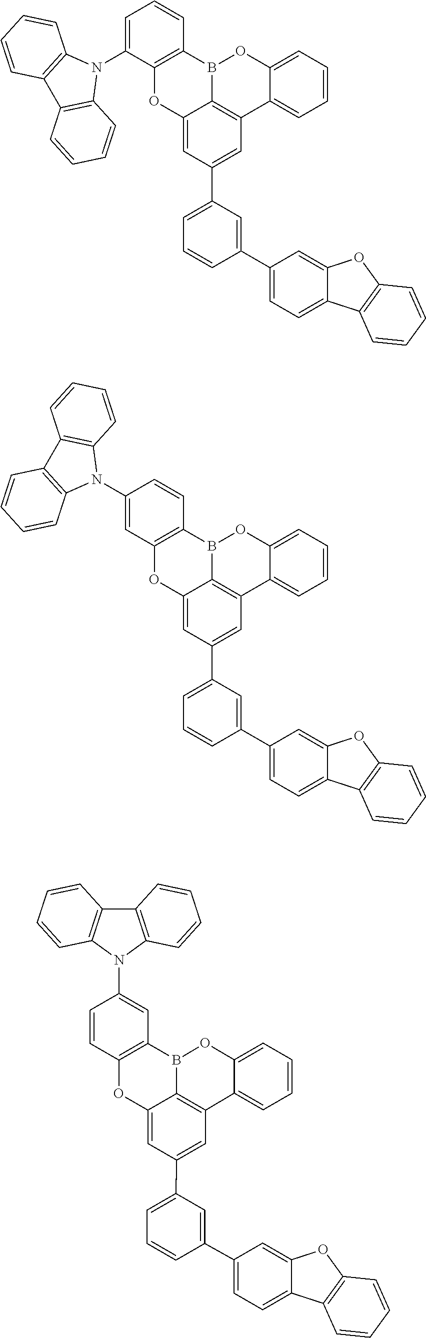

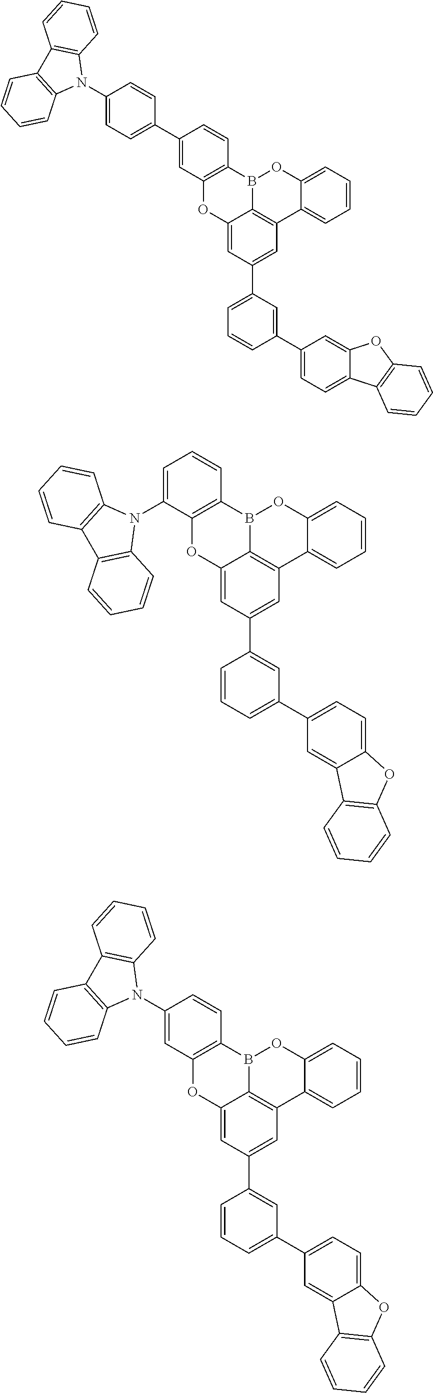

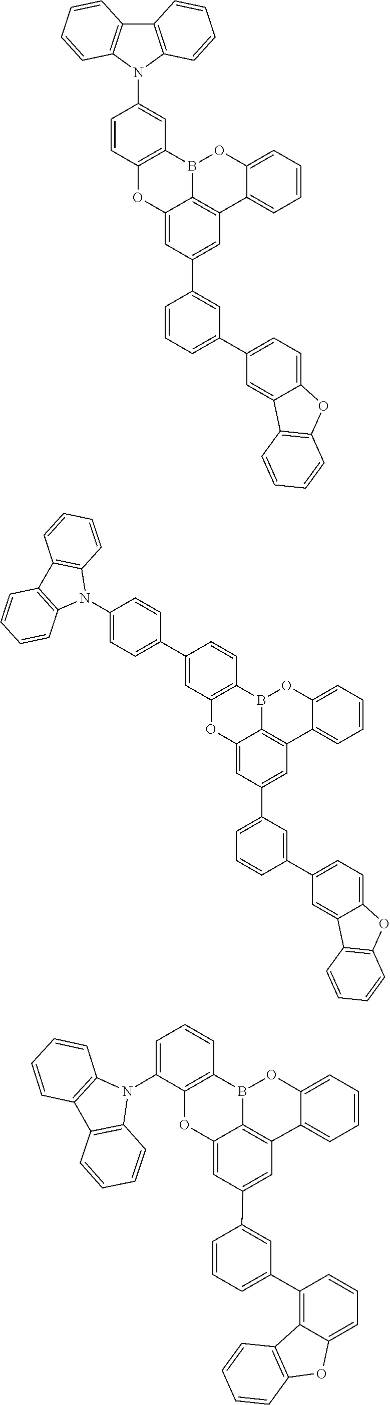

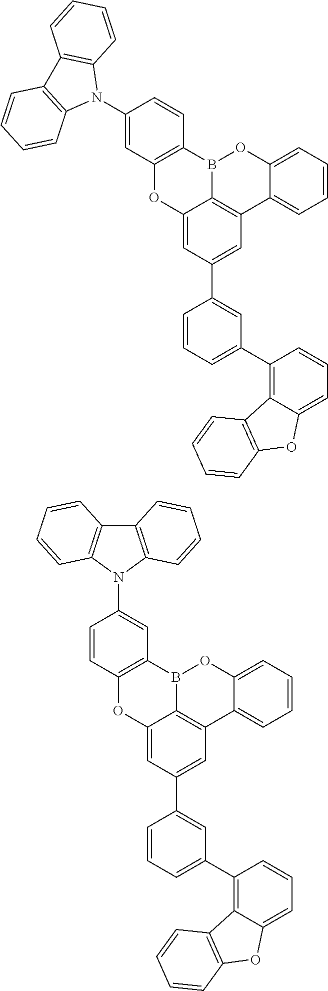

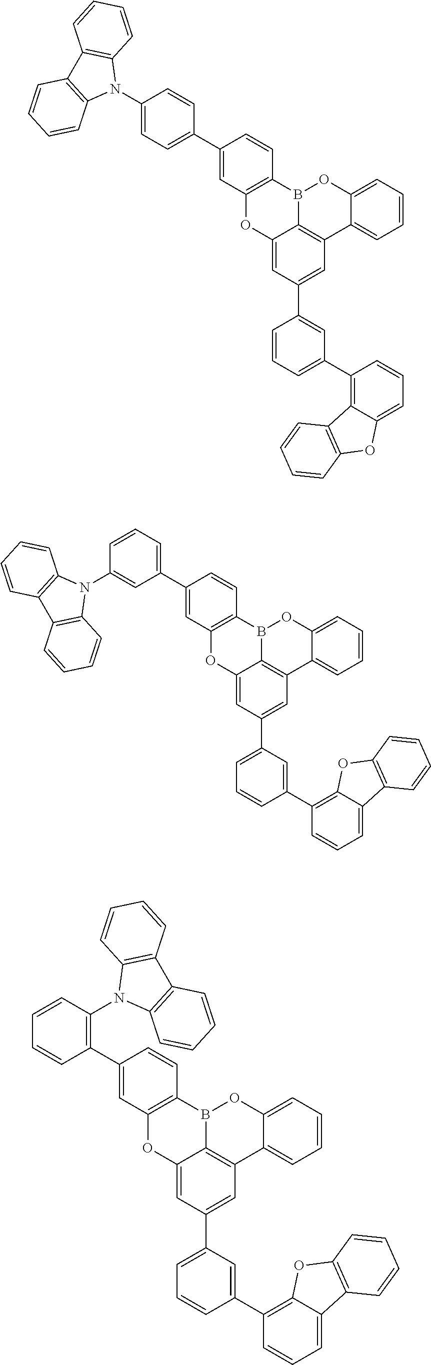 [SMILES: c1cc(-c2cc3c4c(c2)-c2ccccc2OB4c2ccc(-c4ccc(-n5c6ccccc6c6ccccc65)cc4)cc2O3)cc(-c2cccc3oc4ccccc4c23)c1 ; c1cc(-c2cc3c4c(c2)-c2ccccc2OB4c2ccc(-c4cccc(-n5c6ccccc6c6ccccc65)c4)cc2O3)cc(-c2cccc3c2oc2ccccc23)c1 ; c1cc(-c2cc3c4c(c2)-c2ccccc2OB4c2ccc(-c4ccccc4-n4c5ccccc5c5ccccc54)cc2O3)cc(-c2cccc3c2oc2ccccc23)c1]

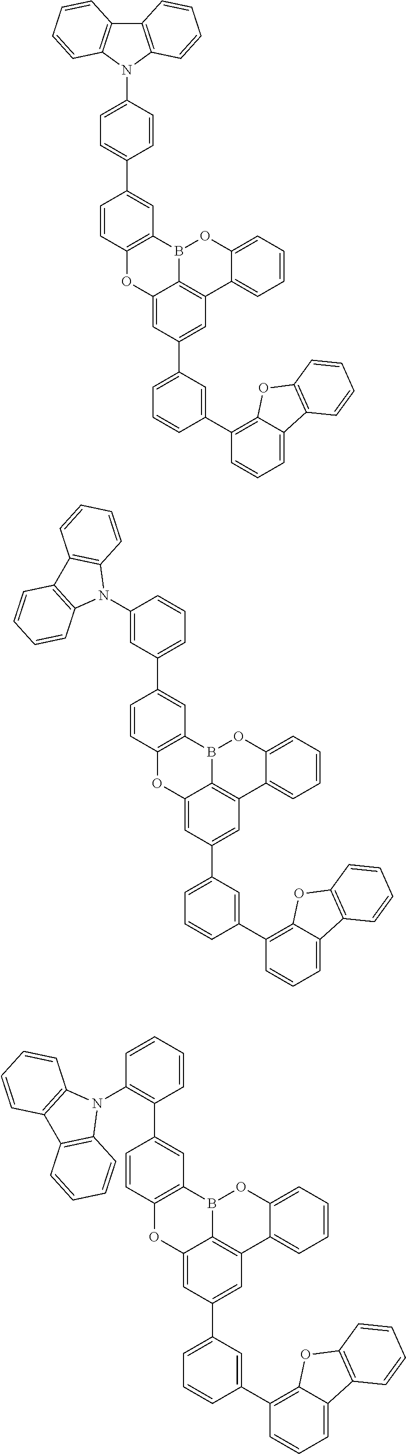

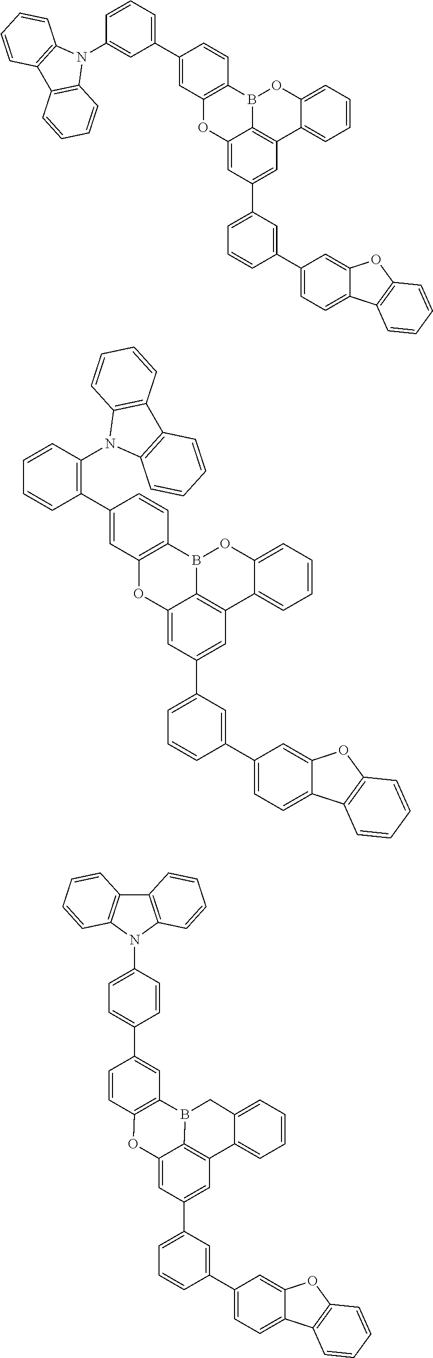 [SMILES: c1cc(-c2cc3c4c(c2)-c2ccccc2OB4c2ccc(-c4cccc(-n5c6ccccc6c6ccccc65)c4)cc2O3)cc(-c2ccc3c(c2)oc2ccccc23)c1 ; c1cc(-c2cc3c4c(c2)-c2ccccc2OB4c2ccc(-c4ccccc4-n4c5ccccc5c5ccccc54)cc2O3)cc(-c2ccc3c(c2)oc2ccccc23)c1 ; c1cc(-c2cc3c4c(c2)-c2ccccc2CB4c2cc(-c4ccc(-n5c6ccccc6c6ccccc65)cc4)ccc2O3)cc(-c2ccc3c(c2)oc2ccccc23)c1]

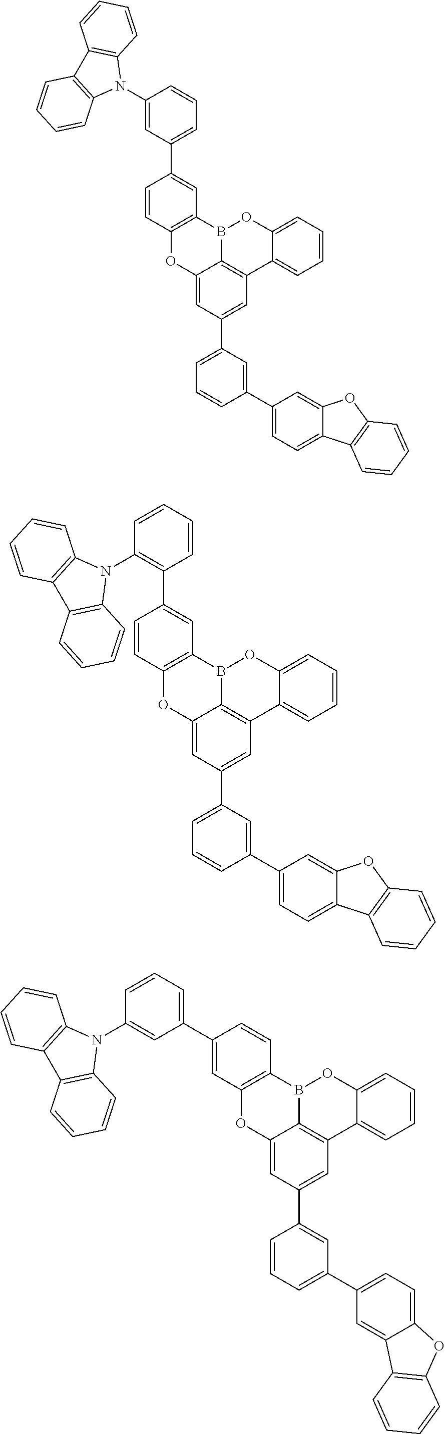 [SMILES: c1cc(-c2cc3c4c(c2)-c2ccccc2OB4c2cc(-c4cccc(-n5c6ccccc6c6ccccc65)c4)ccc2O3)cc(-c2ccc3c(c2)oc2ccccc23)c1 ; c1cc(-c2cc3c4c(c2)-c2ccccc2OB4c2cc(-c4ccccc4-n4c5ccccc5c5ccccc54)ccc2O3)cc(-c2ccc3c(c2)oc2ccccc23)c1 ; c1cc(-c2cc3c4c(c2)-c2ccccc2OB4c2ccc(-c4cccc(-n5c6ccccc6c6ccccc65)c4)cc2O3)cc(-c2ccc3oc4ccccc4c3c2)c1]

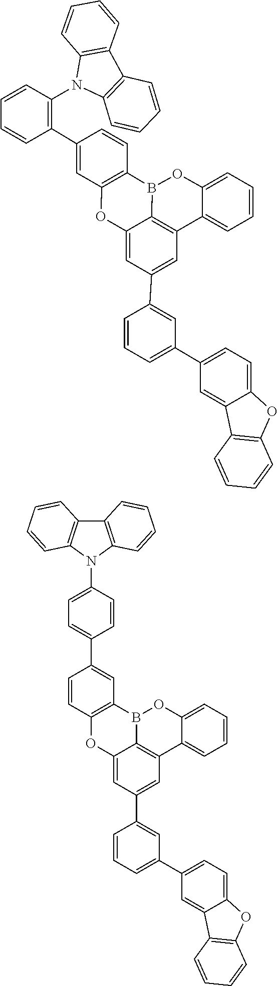

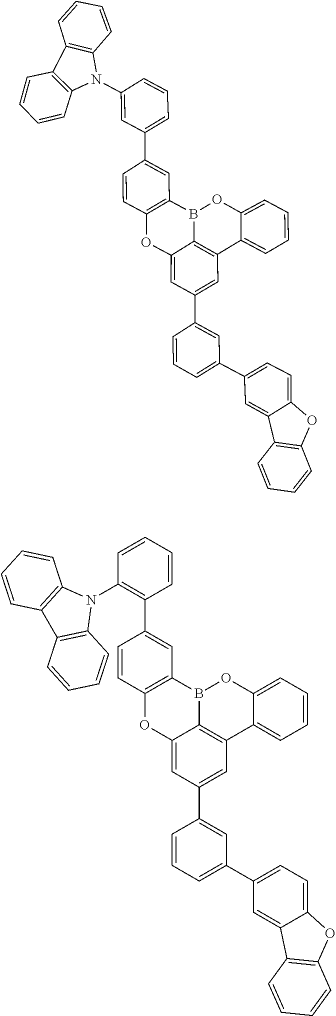 [SMILES: c1cc(-c2cc3c4c(c2)-c2ccccc2OB4c2cc(-c4cccc(-n5c6ccccc6c6ccccc65)c4)ccc2O3)cc(-c2ccc3oc4ccccc4c3c2)c1 ; c1cc(-c2cc3c4c(c2)-c2ccccc2OB4c2cc(-c4ccccc4-n4c5ccccc5c5ccccc54)ccc2O3)cc(-c2ccc3oc4ccccc4c3c2)c1]

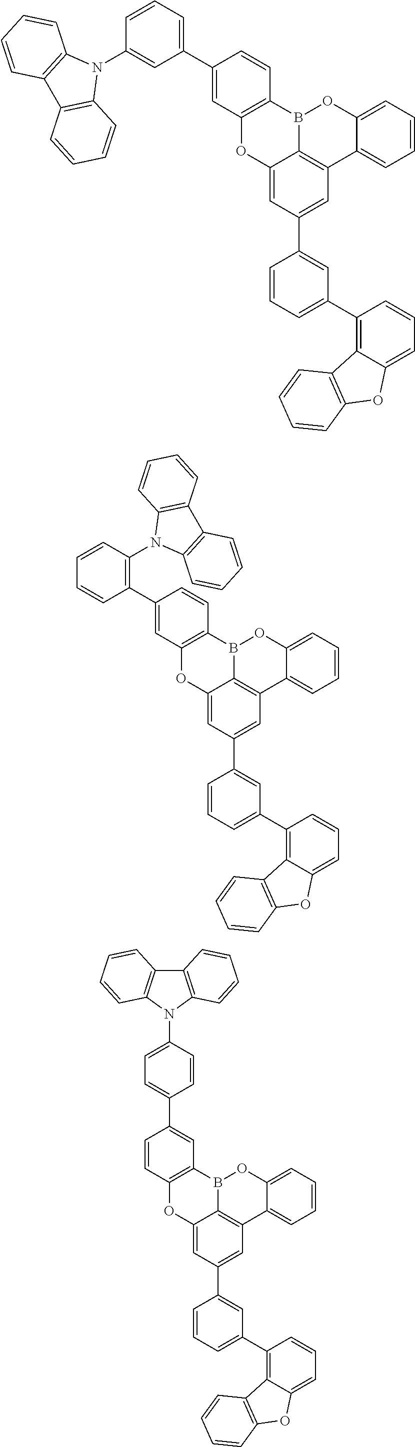

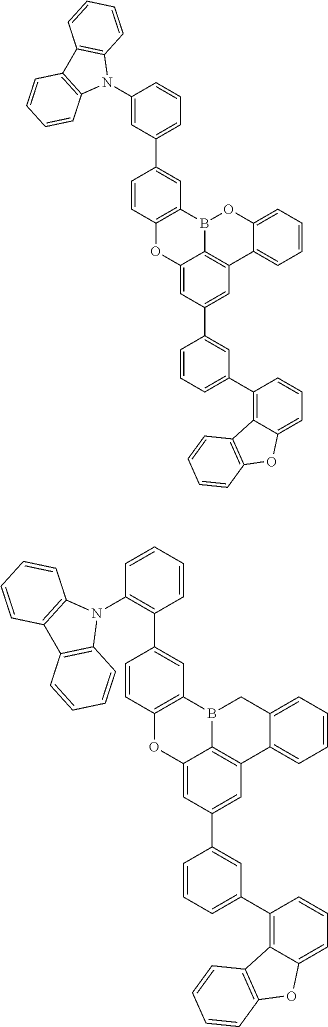 [SMILES: c1cc(-c2cc3c4c(c2)-c2ccccc2OB4c2cc(-c4cccc(-n5c6ccccc6c6ccccc65)c4)ccc2O3)cc(-c2cccc3oc4ccccc4c23)c1 ; c1cc(-c2cc3c4c(c2)-c2ccccc2CB4c2cc(-c4ccccc4-n4c5ccccc5c5ccccc54)ccc2O3)cc(-c2cccc3oc4ccccc4c23)c1]

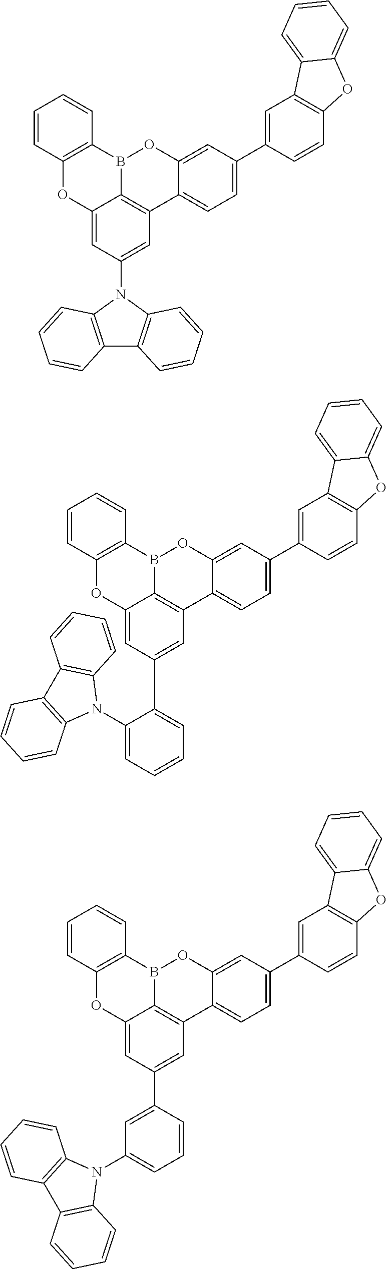

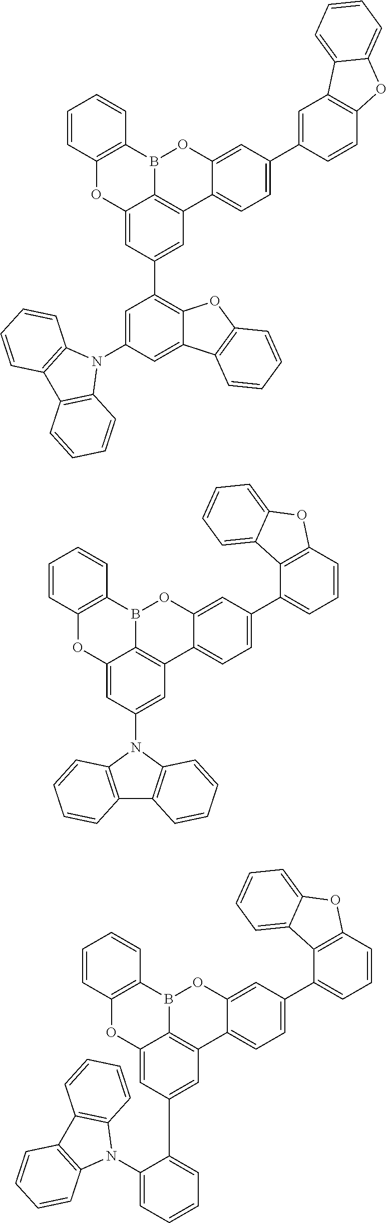

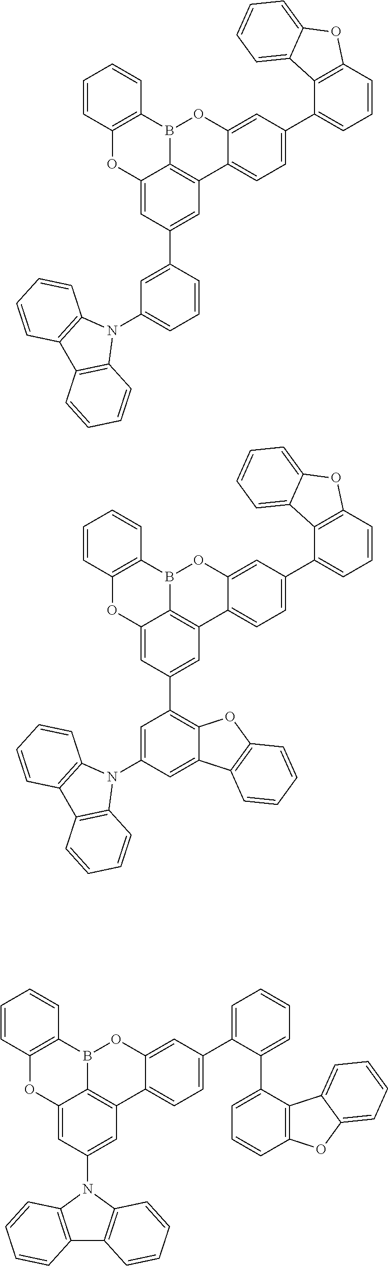 [SMILES: c1cc(-c2cc3c4c(c2)-c2ccc(-c5cccc6oc7ccccc7c56)cc2OB4c2ccccc2O3)cc(-n2c3ccccc3c3ccccc32)c1 ; c1ccc2c(c1)Oc1cc(-c3cc(-n4c5ccccc5c5ccccc54)cc4c3oc3ccccc34)cc3c1B2Oc1cc(-c2cccc4oc5ccccc5c24)ccc1-3 ; c1ccc2c(c1)Oc1cc(-n3c4ccccc4c4ccccc43)cc3c1B2Oc1cc(-c2ccccc2-c2cccc4oc5ccccc5c24)ccc1-3]

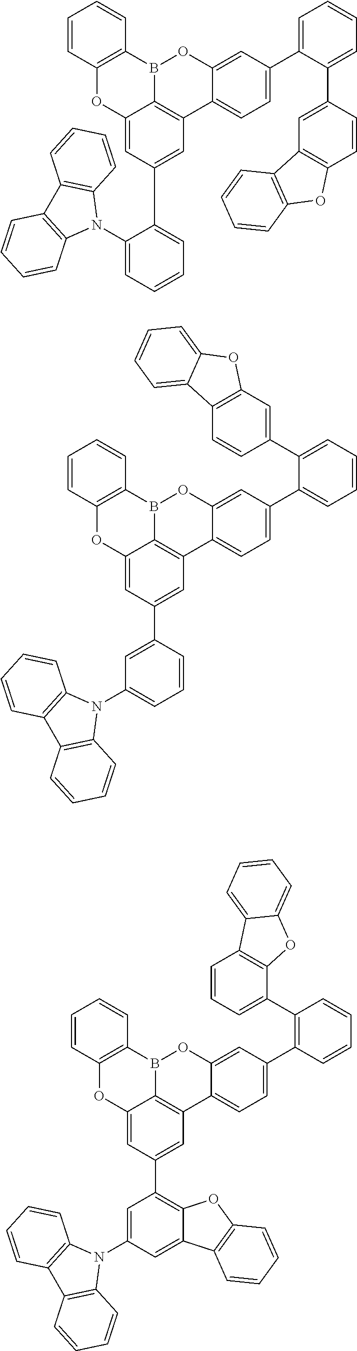

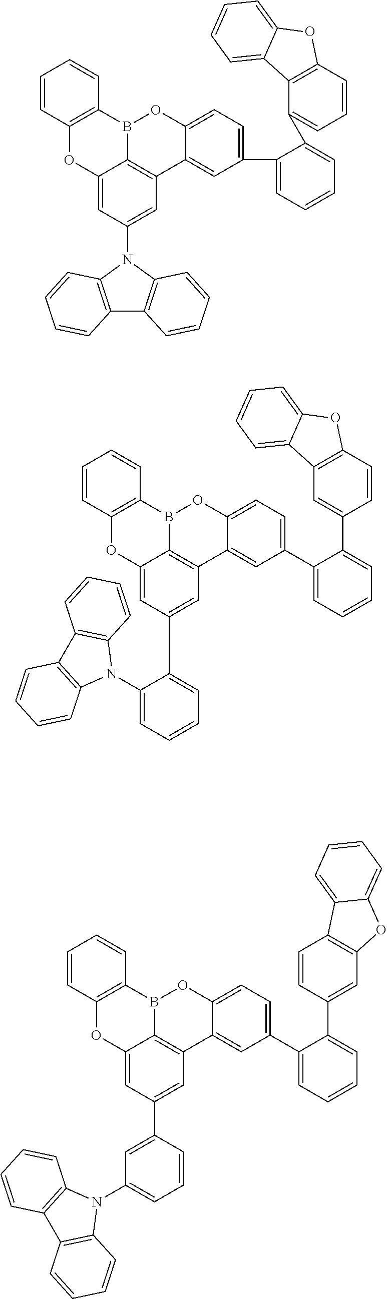 [SMILES: c1ccc2c(c1)Oc1cc(-n3c4ccccc4c4ccccc43)cc3c1B2Oc1ccc(-c2ccccc2-c2cccc4oc5ccccc5c24)cc1-3 ; c1ccc2c(c1)Oc1cc(-c3ccccc3-n3c4ccccc4c4ccccc43)cc3c1B2Oc1ccc(-c2ccccc2-c2ccc4oc5ccccc5c4c2)cc1-3 ; c1cc(-c2cc3c4c(c2)-c2cc(-c5ccccc5-c5ccc6c(c5)oc5ccccc56)ccc2OB4c2ccccc2O3)cc(-n2c3ccccc3c3ccccc32)c1]

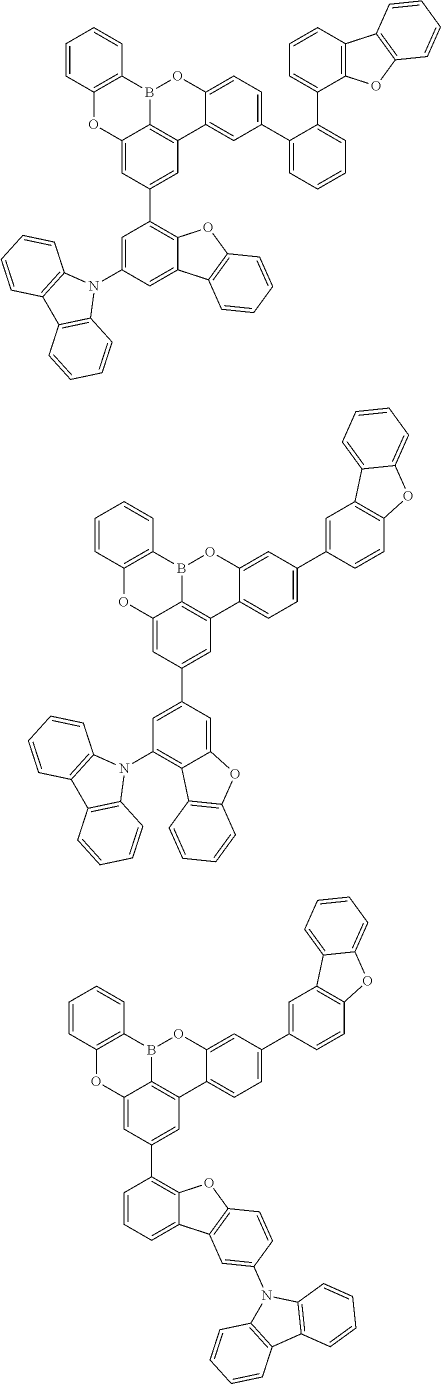 [SMILES: c1ccc2c(c1)Oc1cc(-c3cc(-n4c5ccccc5c5ccccc54)cc4c3oc3ccccc34)cc3c1B2Oc1ccc(-c2ccccc2-c2cccc4c2oc2ccccc24)cc1-3 ; c1ccc2c(c1)Oc1cc(-c3cc(-n4c5ccccc5c5ccccc54)c4c(c3)oc3ccccc34)cc3c1B2Oc1cc(-c2ccc4oc5ccccc5c4c2)ccc1-3 ; c1ccc2c(c1)Oc1cc(-c3cccc4c3oc3ccc(-n5c6ccccc6c6ccccc65)cc34)cc3c1B2Oc1cc(-c2ccc4oc5ccccc5c4c2)ccc1-3]

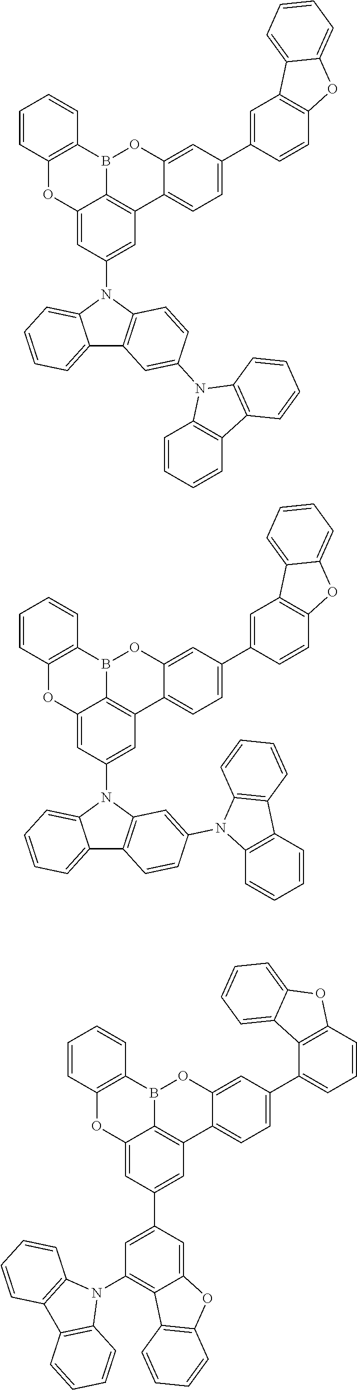 [SMILES: c1ccc2c(c1)Oc1cc(-n3c4ccccc4c4cc(-n5c6ccccc6c6ccccc65)ccc43)cc3c1B2Oc1cc(-c2ccc4oc5ccccc5c4c2)ccc1-3 ; c1ccc2c(c1)Oc1cc(-n3c4ccccc4c4ccc(-n5c6ccccc6c6ccccc65)cc43)cc3c1B2Oc1cc(-c2ccc4oc5ccccc5c4c2)ccc1-3 ; c1ccc2c(c1)Oc1cc(-c3cc(-n4c5ccccc5c5ccccc54)c4c(c3)oc3ccccc34)cc3c1B2Oc1cc(-c2cccc4oc5ccccc5c24)ccc1-3]

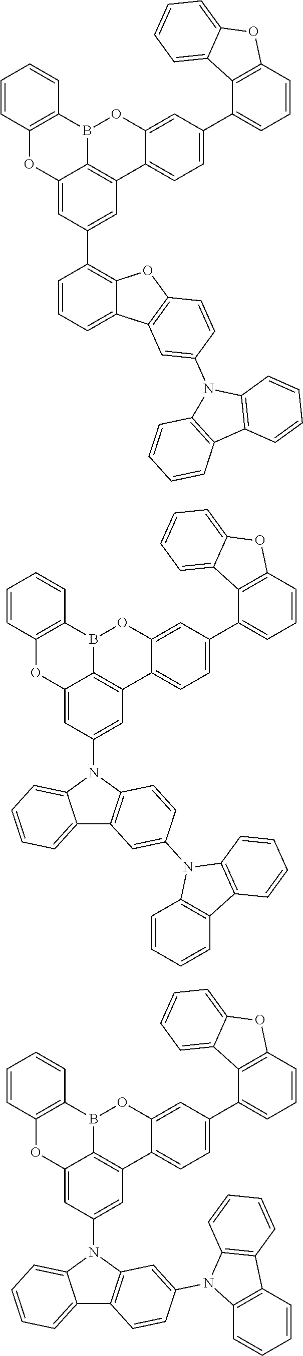

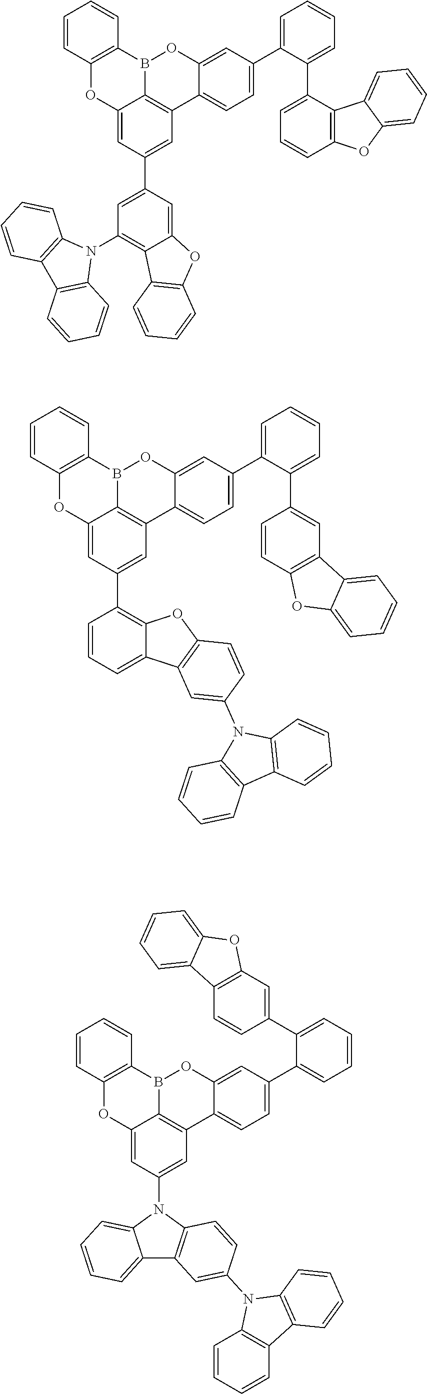 [SMILES: c1ccc2c(c1)Oc1cc(-c3cc(-n4c5ccccc5c5ccccc54)c4c(c3)oc3ccccc34)cc3c1B2Oc1cc(-c2ccccc2-c2cccc4oc5ccccc5c24)ccc1-3 ; c1ccc2c(c1)Oc1cc(-c3cccc4c3oc3ccc(-n5c6ccccc6c6ccccc65)cc34)cc3c1B2Oc1cc(-c2ccccc2-c2ccc4oc5ccccc5c4c2)ccc1-3 ; c1ccc2c(c1)Oc1cc(-n3c4ccccc4c4cc(-n5c6ccccc6c6ccccc65)ccc43)cc3c1B2Oc1cc(-c2ccccc2-c2ccc4c(c2)oc2ccccc24)ccc1-3]

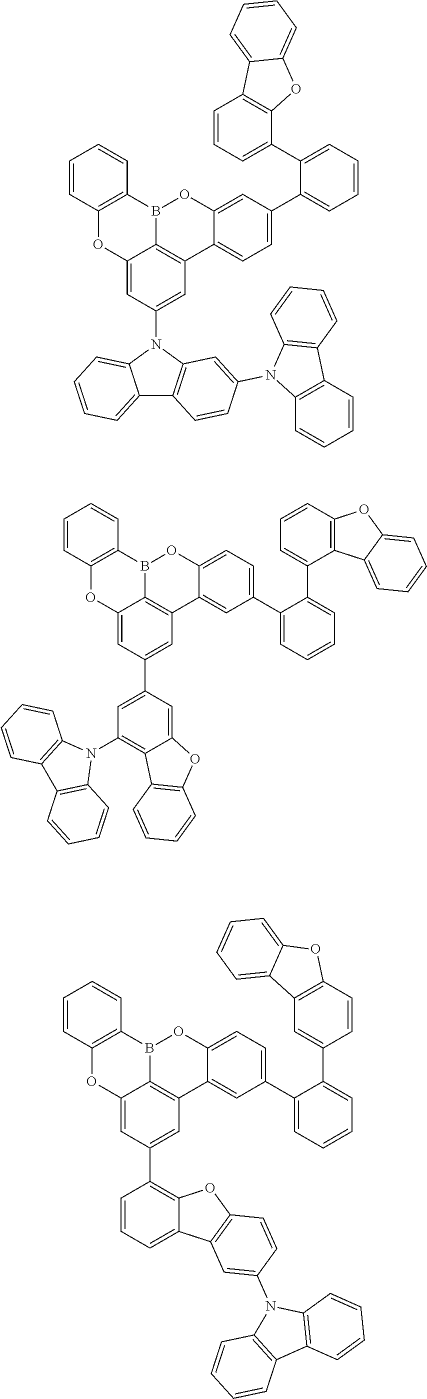 [SMILES: c1ccc2c(c1)Oc1cc(-n3c4ccccc4c4ccc(-n5c6ccccc6c6ccccc65)cc43)cc3c1B2Oc1cc(-c2ccccc2-c2cccc4c2oc2ccccc24)ccc1-3 ; c1ccc2c(c1)Oc1cc(-c3cc(-n4c5ccccc5c5ccccc54)c4c(c3)oc3ccccc34)cc3c1B2Oc1ccc(-c2ccccc2-c2cccc4oc5ccccc5c24)cc1-3 ; c1ccc2c(c1)Oc1cc(-c3cccc4c3oc3ccc(-n5c6ccccc6c6ccccc65)cc34)cc3c1B2Oc1ccc(-c2ccccc2-c2ccc4oc5ccccc5c4c2)cc1-3]

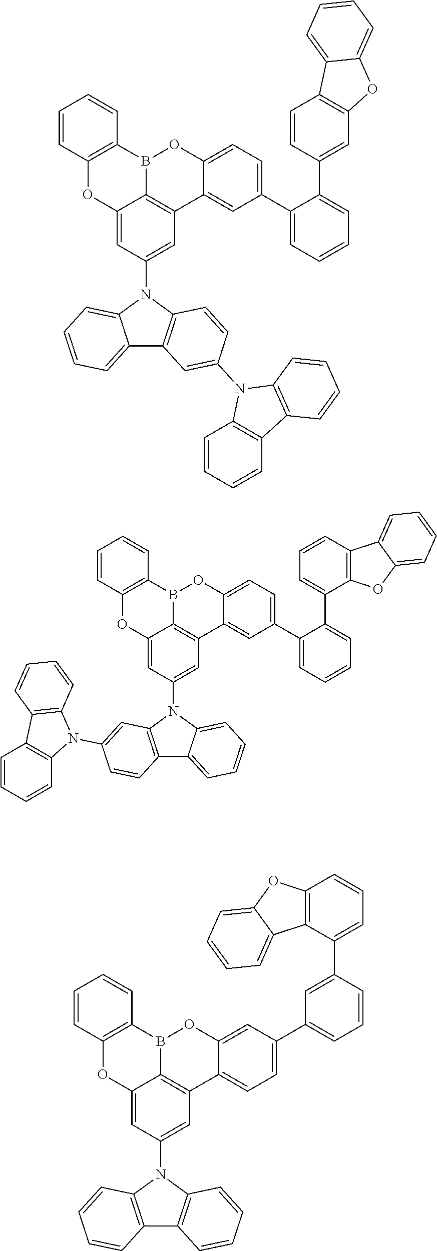 [SMILES: c1ccc2c(c1)Oc1cc(-n3c4ccccc4c4cc(-n5c6ccccc6c6ccccc65)ccc43)cc3c1B2Oc1ccc(-c2ccccc2-c2ccc4c(c2)oc2ccccc24)cc1-3 ; c1ccc2c(c1)Oc1cc(-n3c4ccccc4c4ccc(-n5c6ccccc6c6ccccc65)cc43)cc3c1B2Oc1ccc(-c2ccccc2-c2cccc4c2oc2ccccc24)cc1-3 ; c1cc(-c2ccc3c(c2)OB2c4ccccc4Oc4cc(-n5c6ccccc6c6ccccc65)cc-3c42)cc(-c2cccc3oc4ccccc4c23)c1]

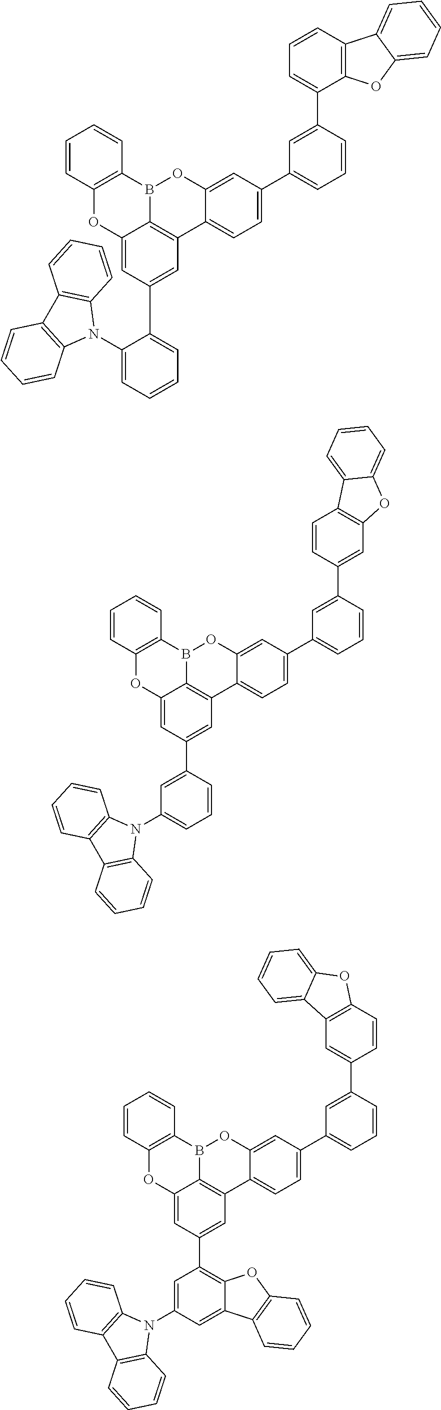

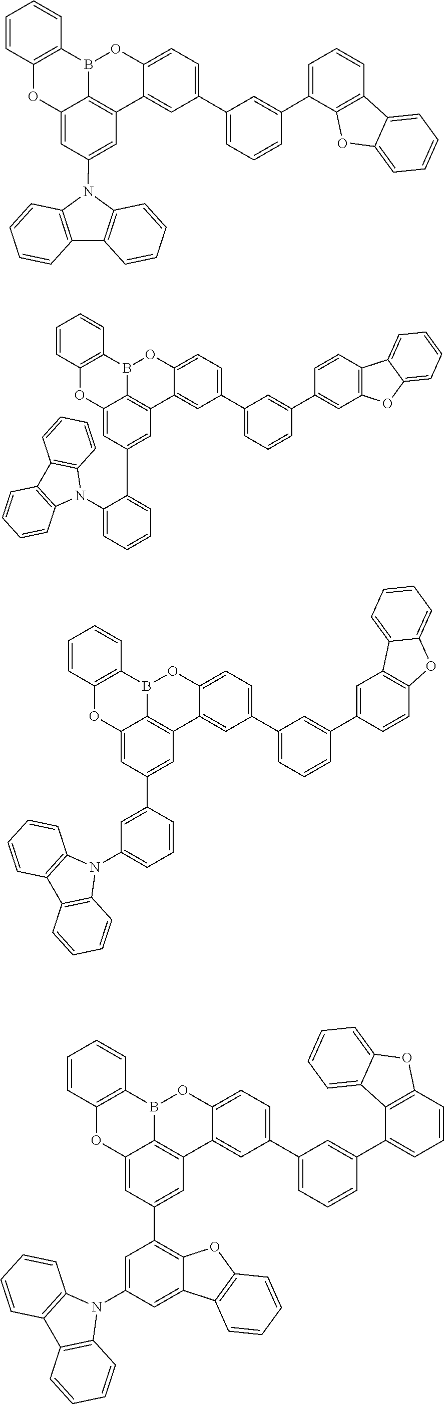 [SMILES: c1cc(-c2ccc3c(c2)-c2cc(-n4c5ccccc5c5ccccc54)cc4c2B(O3)c2ccccc2O4)cc(-c2cccc3c2oc2ccccc23)c1 ; c1cc(-c2ccc3c(c2)-c2cc(-c4ccccc4-n4c5ccccc5c5ccccc54)cc4c2B(O3)c2ccccc2O4)cc(-c2ccc3c(c2)oc2ccccc23)c1 ; c1cc(-c2ccc3c(c2)-c2cc(-c4cccc(-n5c6ccccc6c6ccccc65)c4)cc4c2B(O3)c2ccccc2O4)cc(-c2ccc3oc4ccccc4c3c2)c1 ; c1cc(-c2ccc3c(c2)-c2cc(-c4cc(-n5c6ccccc6c6ccccc65)cc5c4oc4ccccc45)cc4c2B(O3)c2ccccc2O4)cc(-c2cccc3oc4ccccc4c23)c1]

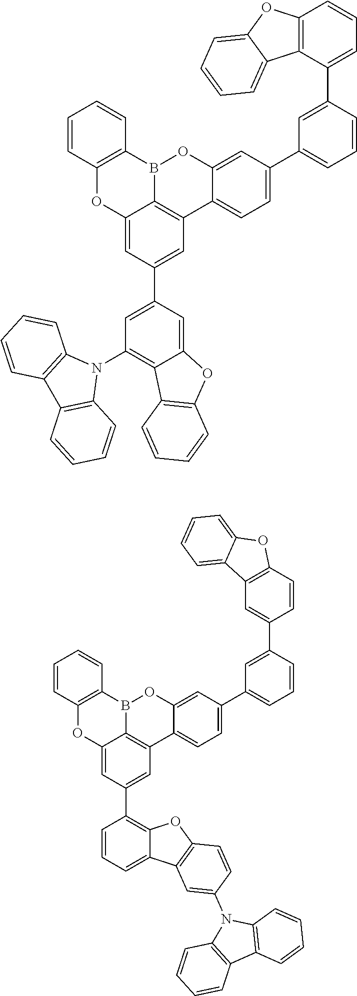 [SMILES: c1cc(-c2ccc3c(c2)OB2c4ccccc4Oc4cc(-c5cc(-n6c7ccccc7c7ccccc76)c6c(c5)oc5ccccc56)cc-3c42)cc(-c2cccc3oc4ccccc4c23)c1 ; c1cc(-c2ccc3c(c2)OB2c4ccccc4Oc4cc(-c5cccc6c5oc5ccc(-n7c8ccccc8c8ccccc87)cc56)cc-3c42)cc(-c2ccc3oc4ccccc4c3c2)c1]

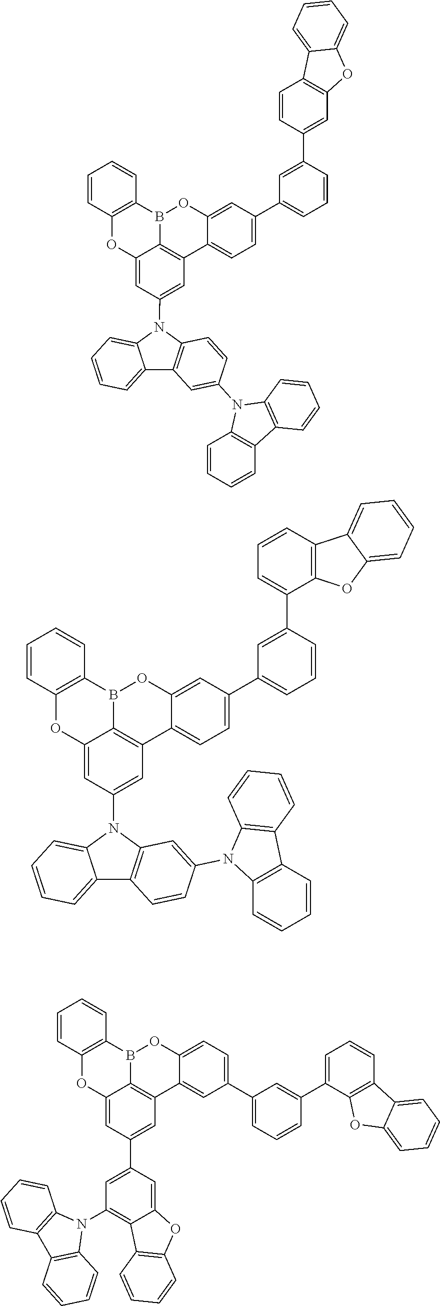 [SMILES: c1cc(-c2ccc3c(c2)OB2c4ccccc4Oc4cc(-n5c6ccccc6c6cc(-n7c8ccccc8c8ccccc87)ccc65)cc-3c42)cc(-c2ccc3c(c2)oc2ccccc23)c1 ; c1cc(-c2ccc3c(c2)OB2c4ccccc4Oc4cc(-n5c6ccccc6c6ccc(-n7c8ccccc8c8ccccc87)cc65)cc-3c42)cc(-c2cccc3c2oc2ccccc23)c1 ; c1cc(-c2ccc3c(c2)-c2cc(-c4cc(-n5c6ccccc6c6ccccc65)c5c(c4)oc4ccccc45)cc4c2B(O3)c2ccccc2O4)cc(-c2cccc3c2oc2ccccc23)c1]

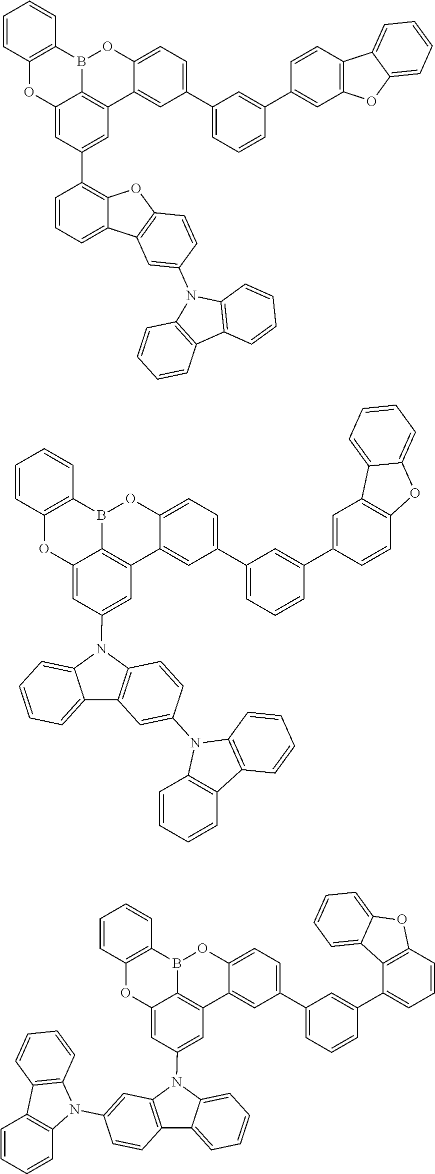 [SMILES: c1cc(-c2ccc3c(c2)-c2cc(-c4cccc5c4oc4ccc(-n6c7ccccc7c7ccccc76)cc45)cc4c2B(O3)c2ccccc2O4)cc(-c2ccc3c(c2)oc2ccccc23)c1 ; c1cc(-c2ccc3c(c2)-c2cc(-n4c5ccccc5c5cc(-n6c7ccccc7c7ccccc76)ccc54)cc4c2B(O3)c2ccccc2O4)cc(-c2ccc3oc4ccccc4c3c2)c1 ; c1cc(-c2ccc3c(c2)-c2cc(-n4c5ccccc5c5ccc(-n6c7ccccc7c7ccccc76)cc54)cc4c2B(O3)c2ccccc2O4)cc(-c2cccc3oc4ccccc4c23)c1]

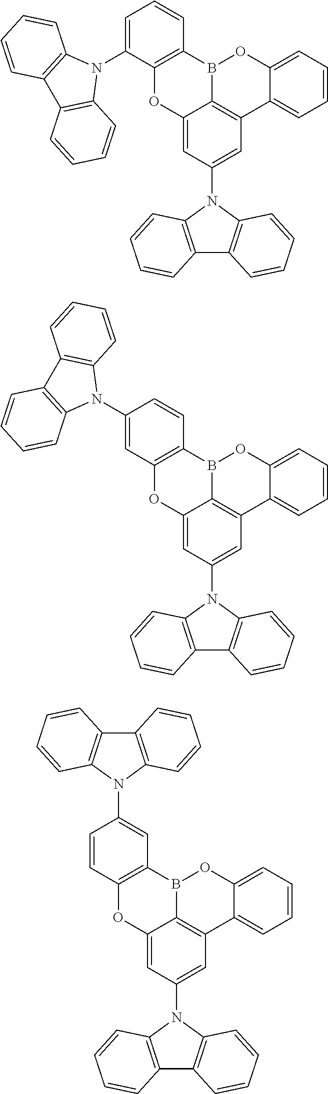

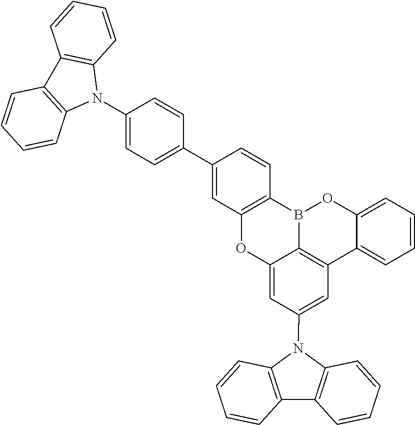 [SMILES: c1ccc2c(c1)OB1c3ccc(-c4ccc(-n5c6ccccc6c6ccccc65)cc4)cc3Oc3cc(-n4c5ccccc5c5ccccc54)cc-2c31]

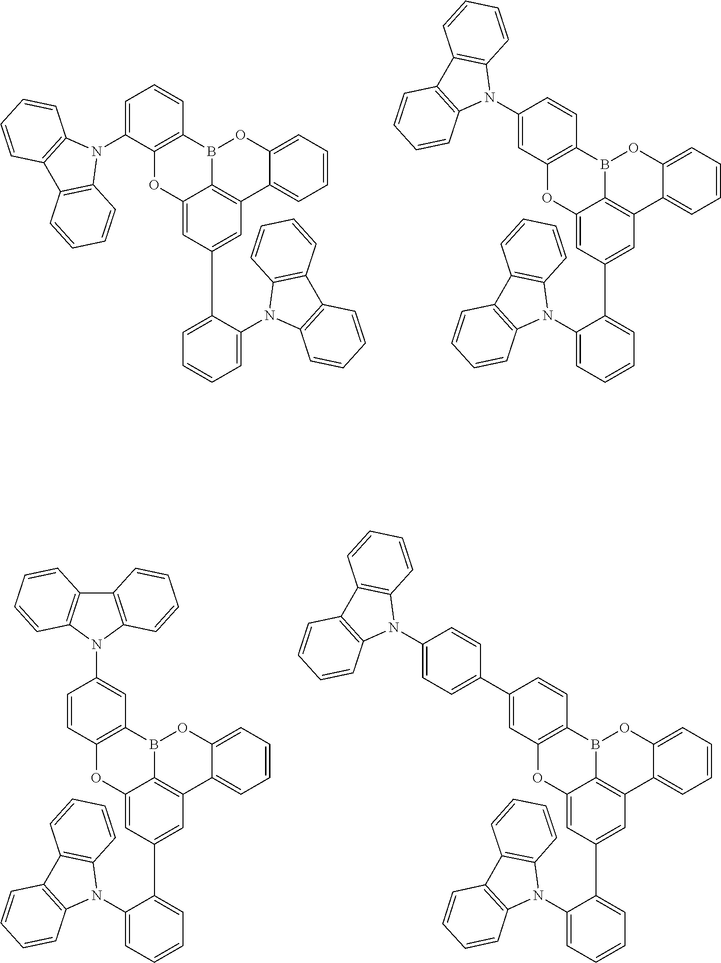 [SMILES: c1ccc2c(c1)OB1c3cccc(-n4c5ccccc5c5ccccc54)c3Oc3cc(-c4ccccc4-n4c5ccccc5c5ccccc54)cc-2c31 ; c1ccc2c(c1)OB1c3ccc(-n4c5ccccc5c5ccccc54)cc3Oc3cc(-c4ccccc4-n4c5ccccc5c5ccccc54)cc-2c31 ; c1ccc2c(c1)OB1c3cc(-n4c5ccccc5c5ccccc54)ccc3Oc3cc(-c4ccccc4-n4c5ccccc5c5ccccc54)cc-2c31 ; c1ccc2c(c1)OB1c3ccc(-c4ccc(-n5c6ccccc6c6ccccc65)cc4)cc3Oc3cc(-c4ccccc4-n4c5ccccc5c5ccccc54)cc-2c31]

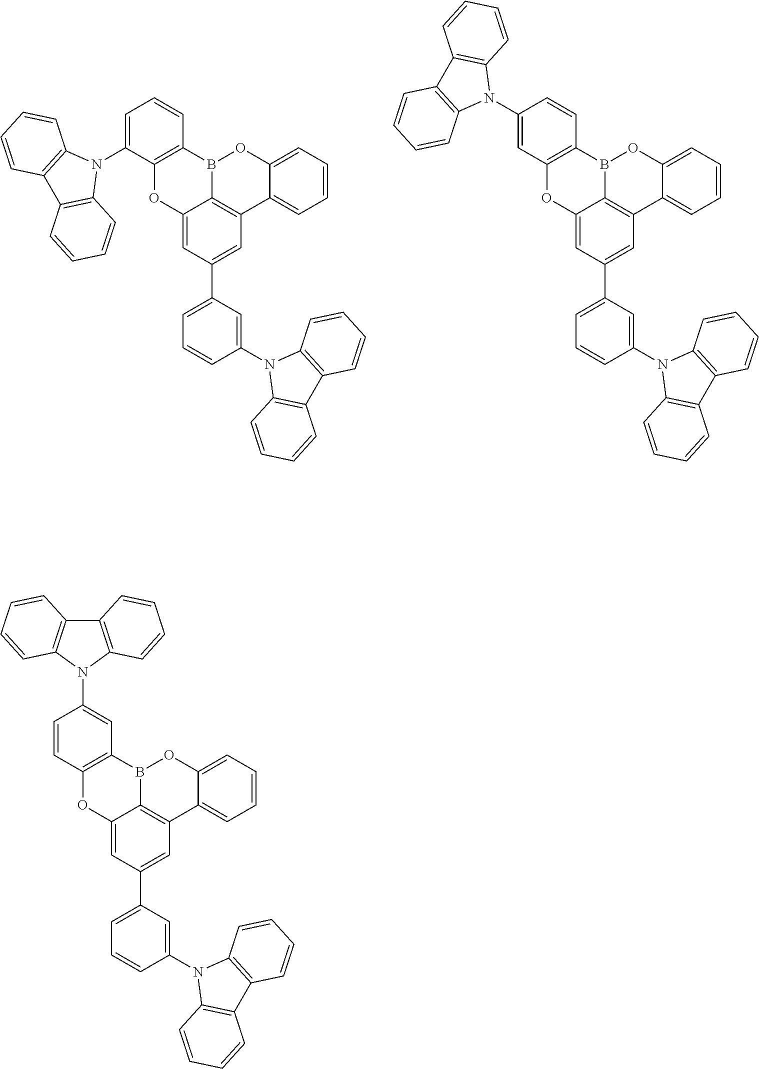 [SMILES: c1cc(-c2cc3c4c(c2)-c2ccccc2OB4c2cccc(-n4c5ccccc5c5ccccc54)c2O3)cc(-n2c3ccccc3c3ccccc32)c1 ; c1cc(-c2cc3c4c(c2)-c2ccccc2OB4c2ccc(-n4c5ccccc5c5ccccc54)cc2O3)cc(-n2c3ccccc3c3ccccc32)c1 ; c1cc(-c2cc3c4c(c2)-c2ccccc2OB4c2cc(-n4c5ccccc5c5ccccc54)ccc2O3)cc(-n2c3ccccc3c3ccccc32)c1]

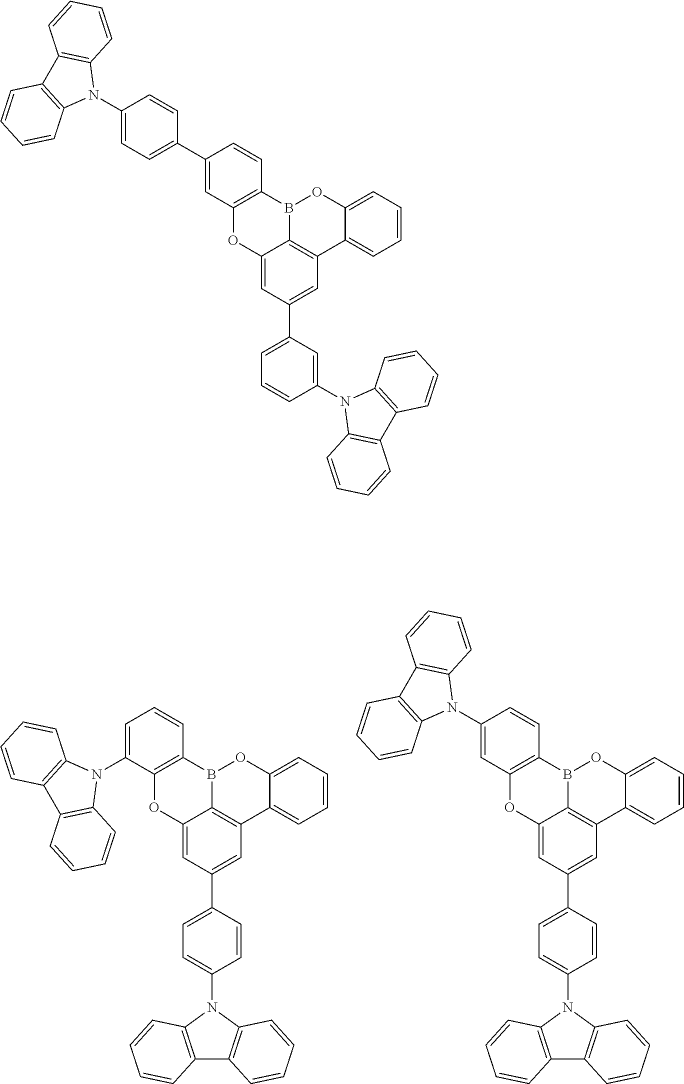 [SMILES: c1cc(-c2cc3c4c(c2)-c2ccccc2OB4c2ccc(-c4ccc(-n5c6ccccc6c6ccccc65)cc4)cc2O3)cc(-n2c3ccccc3c3ccccc32)c1 ; c1ccc2c(c1)OB1c3cccc(-n4c5ccccc5c5ccccc54)c3Oc3cc(-c4ccc(-n5c6ccccc6c6ccccc65)cc4)cc-2c31 ; c1ccc2c(c1)OB1c3ccc(-n4c5ccccc5c5ccccc54)cc3Oc3cc(-c4ccc(-n5c6ccccc6c6ccccc65)cc4)cc-2c31]

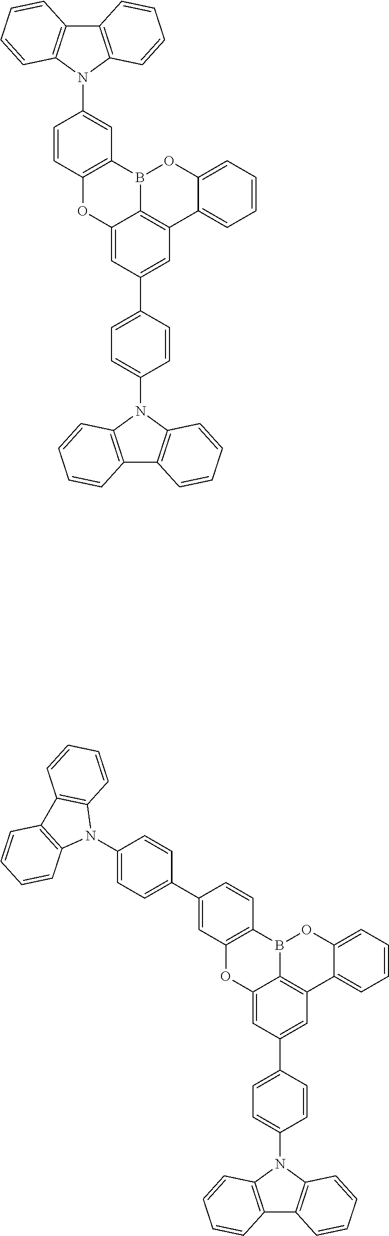 [SMILES: c1ccc2c(c1)OB1c3cc(-n4c5ccccc5c5ccccc54)ccc3Oc3cc(-c4ccc(-n5c6ccccc6c6ccccc65)cc4)cc-2c31 ; c1ccc2c(c1)OB1c3ccc(-c4ccc(-n5c6ccccc6c6ccccc65)cc4)cc3Oc3cc(-c4ccc(-n5c6ccccc6c6ccccc65)cc4)cc-2c31]

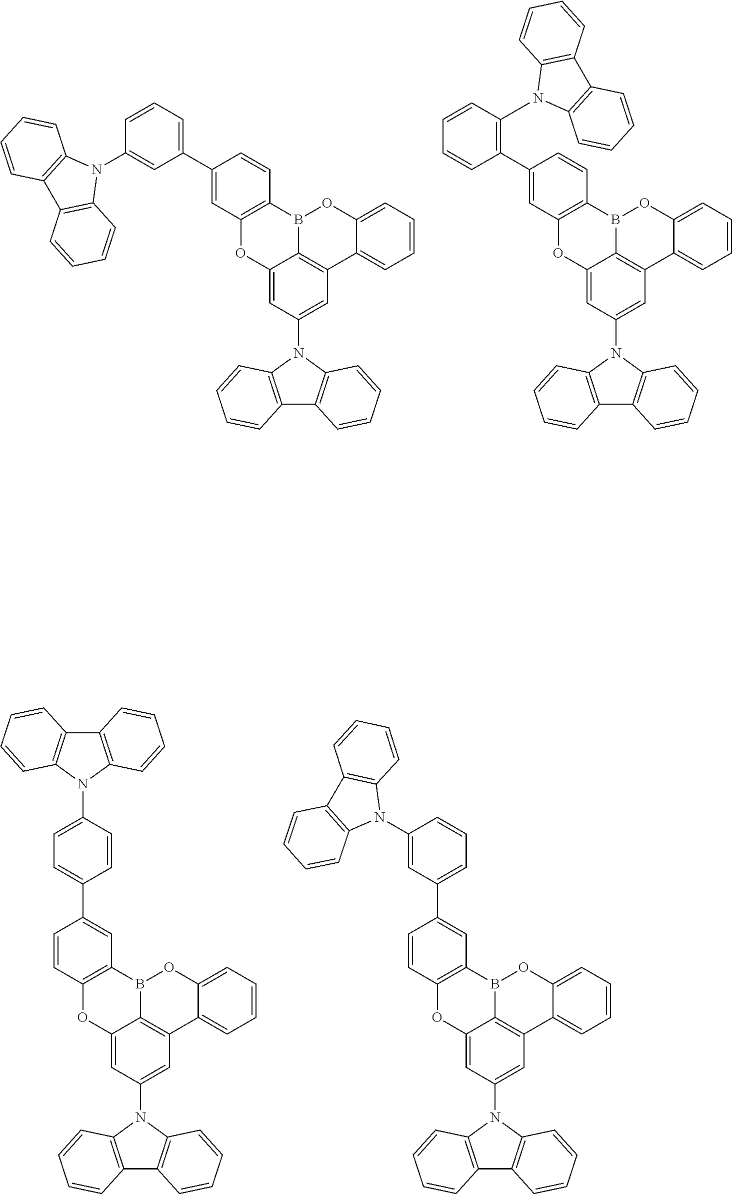 [SMILES: c1cc(-c2ccc3c(c2)Oc2cc(-n4c5ccccc5c5ccccc54)cc4c2B3Oc2ccccc2-4)cc(-n2c3ccccc3c3ccccc32)c1 ; c1ccc2c(c1)OB1c3ccc(-c4ccccc4-n4c5ccccc5c5ccccc54)cc3Oc3cc(-n4c5ccccc5c5ccccc54)cc-2c31 ; c1ccc2c(c1)OB1c3cc(-c4ccc(-n5c6ccccc6c6ccccc65)cc4)ccc3Oc3cc(-n4c5ccccc5c5ccccc54)cc-2c31 ; c1cc(-c2ccc3c(c2)B2Oc4ccccc4-c4cc(-n5c6ccccc6c6ccccc65)cc(c42)O3)cc(-n2c3ccccc3c3ccccc32)c1]

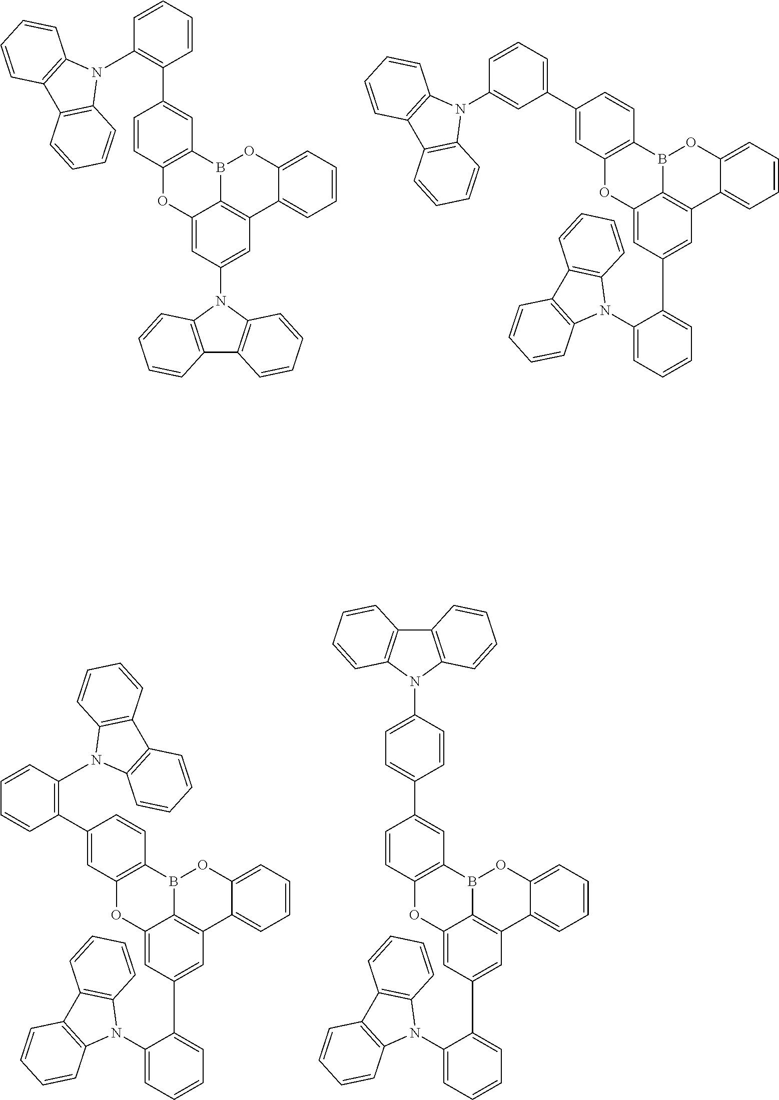 [SMILES: c1ccc2c(c1)OB1c3cc(-c4ccccc4-n4c5ccccc5c5ccccc54)ccc3Oc3cc(-n4c5ccccc5c5ccccc54)cc-2c31 ; c1cc(-c2ccc3c(c2)Oc2cc(-c4ccccc4-n4c5ccccc5c5ccccc54)cc4c2B3Oc2ccccc2-4)cc(-n2c3ccccc3c3ccccc32)c1 ; c1ccc2c(c1)OB1c3ccc(-c4ccccc4-n4c5ccccc5c5ccccc54)cc3Oc3cc(-c4ccccc4-n4c5ccccc5c5ccccc54)cc-2c31 ; c1ccc2c(c1)OB1c3cc(-c4ccc(-n5c6ccccc6c6ccccc65)cc4)ccc3Oc3cc(-c4ccccc4-n4c5ccccc5c5ccccc54)cc-2c31]

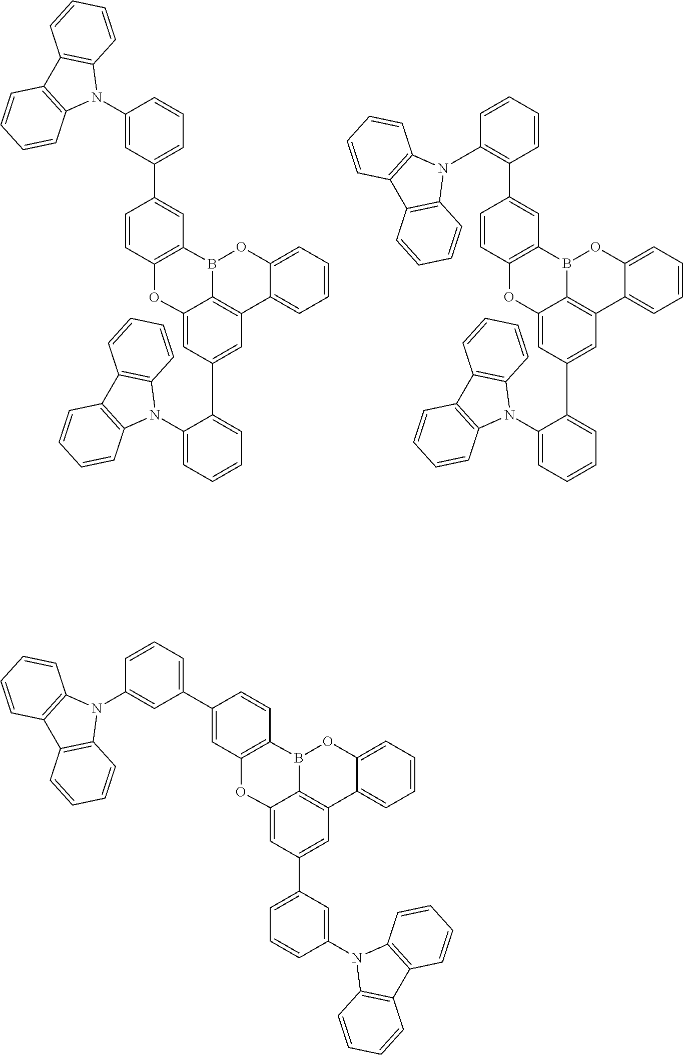

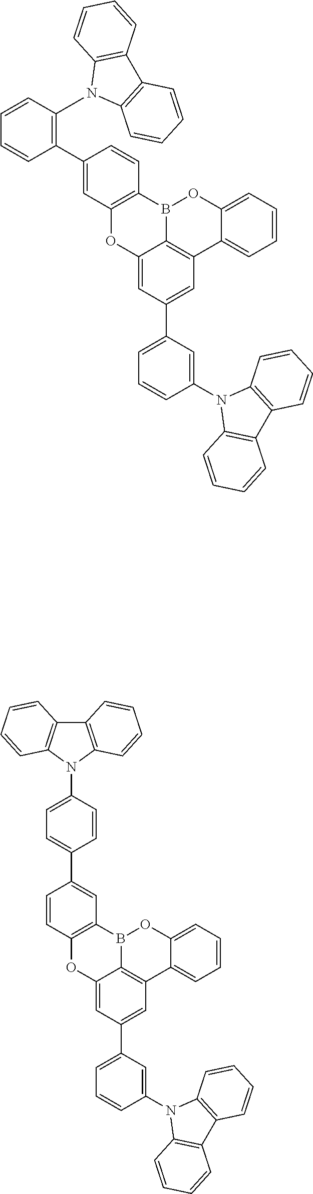 [SMILES: c1cc(-c2cc3c4c(c2)-c2ccccc2OB4c2ccc(-c4ccccc4-n4c5ccccc5c5ccccc54)cc2O3)cc(-n2c3ccccc3c3ccccc32)c1 ; c1cc(-c2cc3c4c(c2)-c2ccccc2OB4c2cc(-c4ccc(-n5c6ccccc6c6ccccc65)cc4)ccc2O3)cc(-n2c3ccccc3c3ccccc32)c1]

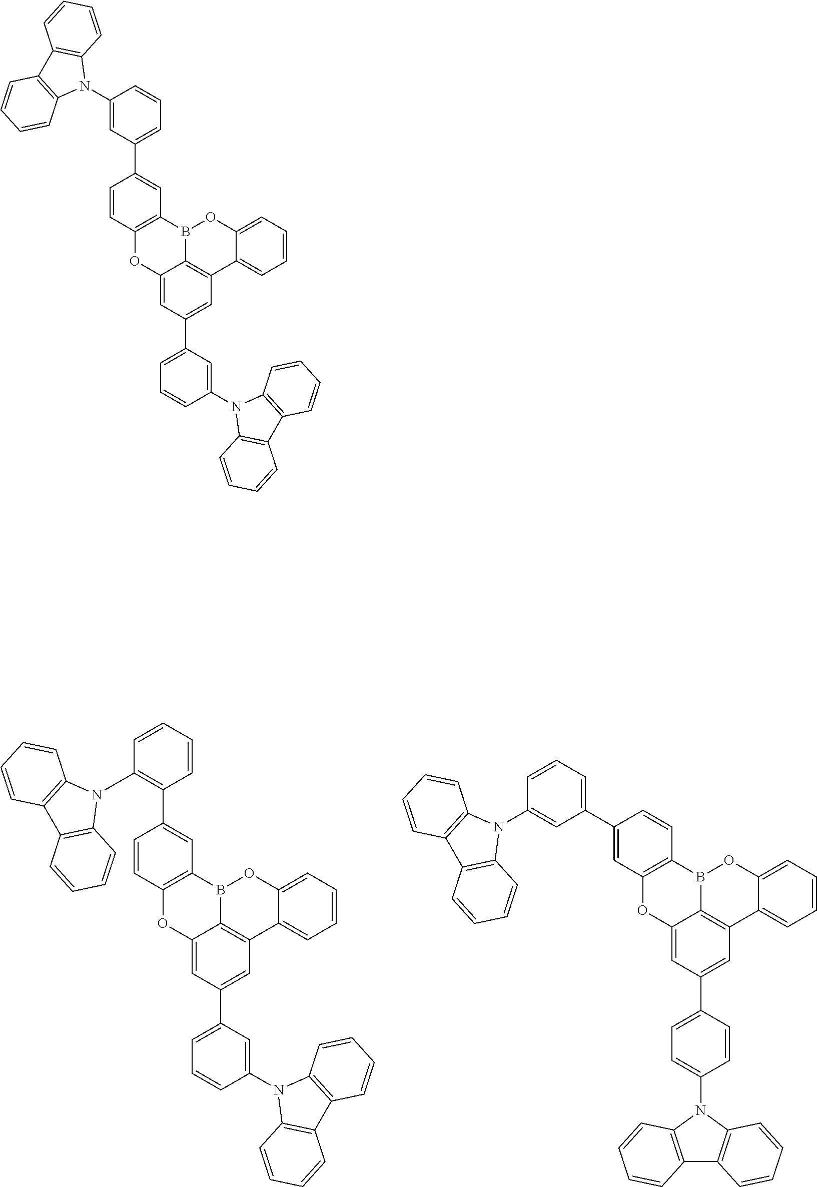 [SMILES: c1cc(-c2ccc3c(c2)B2Oc4ccccc4-c4cc(-c5cccc(-n6c7ccccc7c7ccccc76)c5)cc(c42)O3)cc(-n2c3ccccc3c3ccccc32)c1 ; c1cc(-c2cc3c4c(c2)-c2ccccc2OB4c2cc(-c4ccccc4-n4c5ccccc5c5ccccc54)ccc2O3)cc(-n2c3ccccc3c3ccccc32)c1 ; c1cc(-c2ccc3c(c2)Oc2cc(-c4ccc(-n5c6ccccc6c6ccccc65)cc4)cc4c2B3Oc2ccccc2-4)cc(-n2c3ccccc3c3ccccc32)c1]

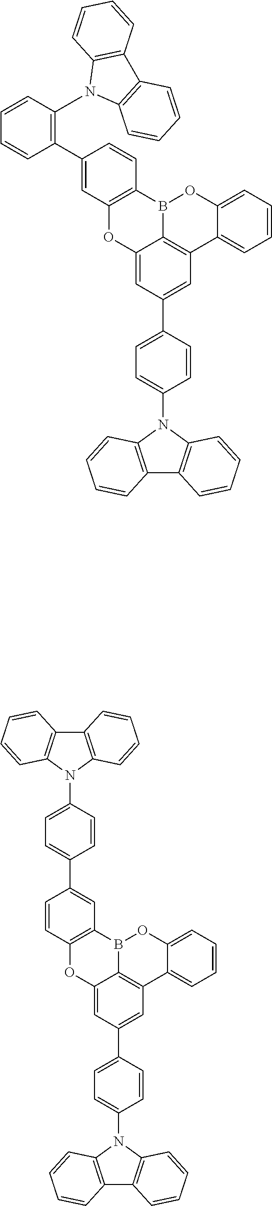 [SMILES: c1ccc2c(c1)OB1c3ccc(-c4ccccc4-n4c5ccccc5c5ccccc54)cc3Oc3cc(-c4ccc(-n5c6ccccc6c6ccccc65)cc4)cc-2c31 ; c1ccc2c(c1)OB1c3cc(-c4ccc(-n5c6ccccc6c6ccccc65)cc4)ccc3Oc3cc(-c4ccc(-n5c6ccccc6c6ccccc65)cc4)cc-2c31]

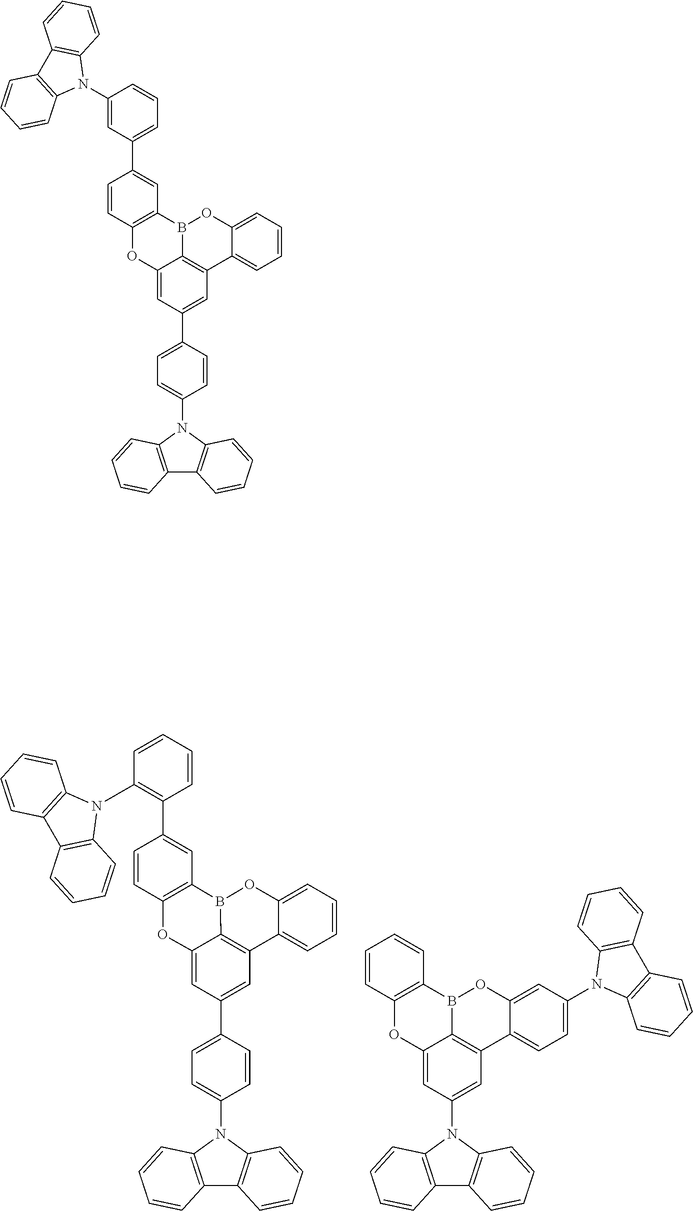

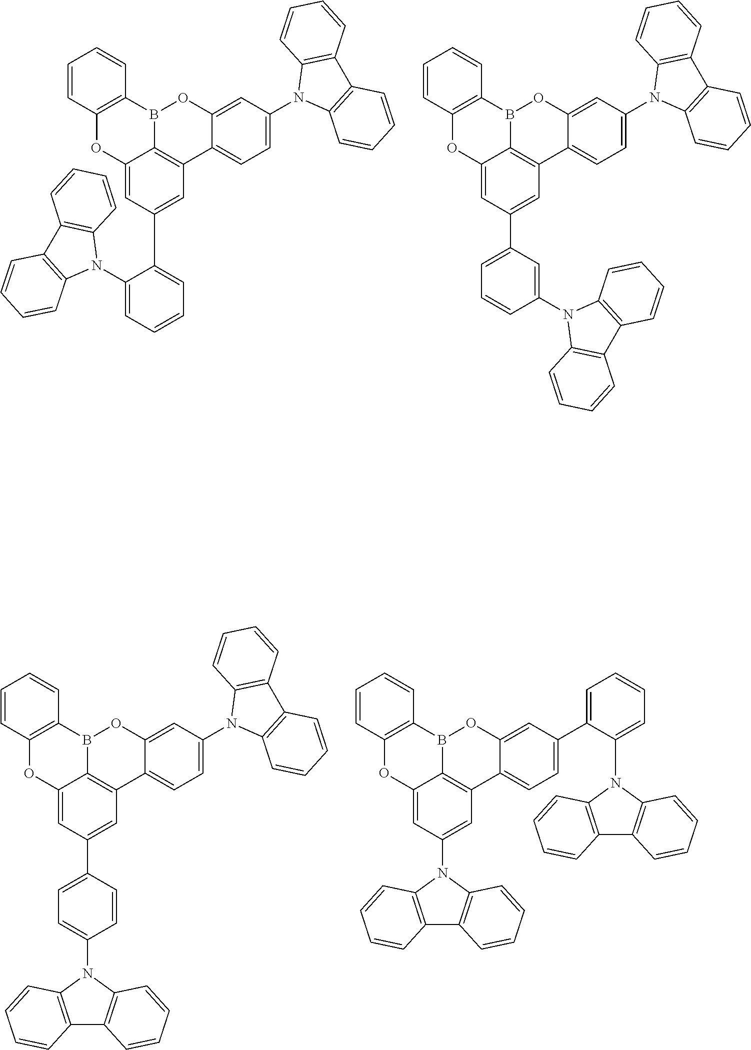

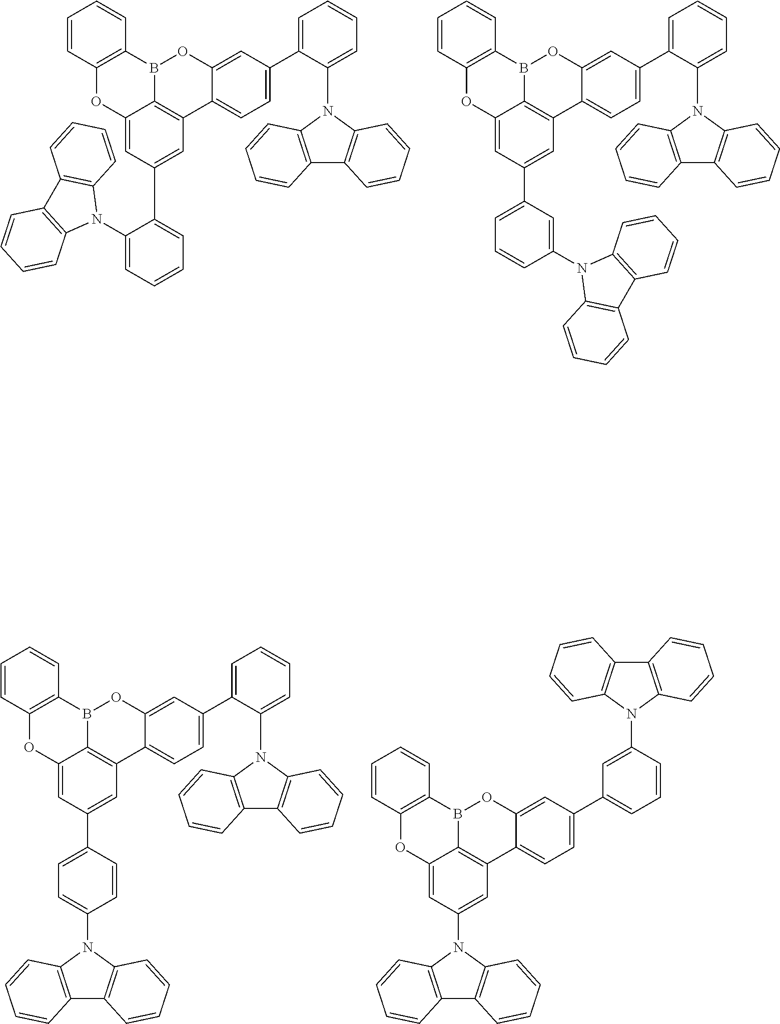

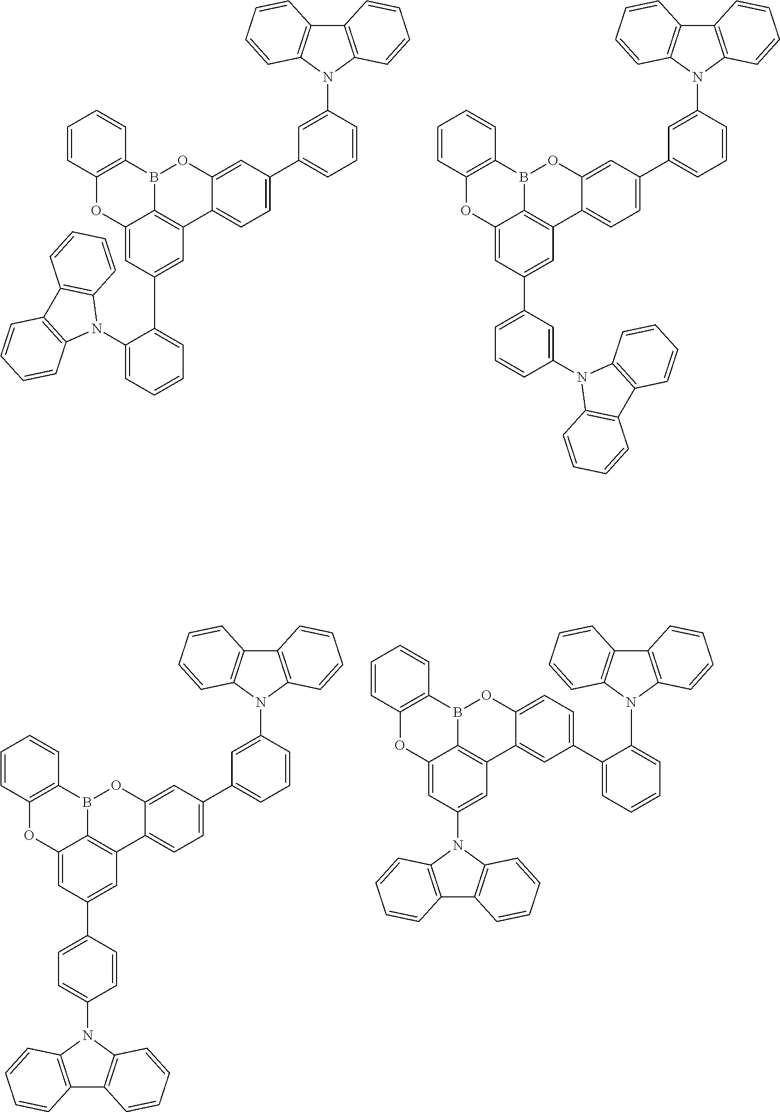

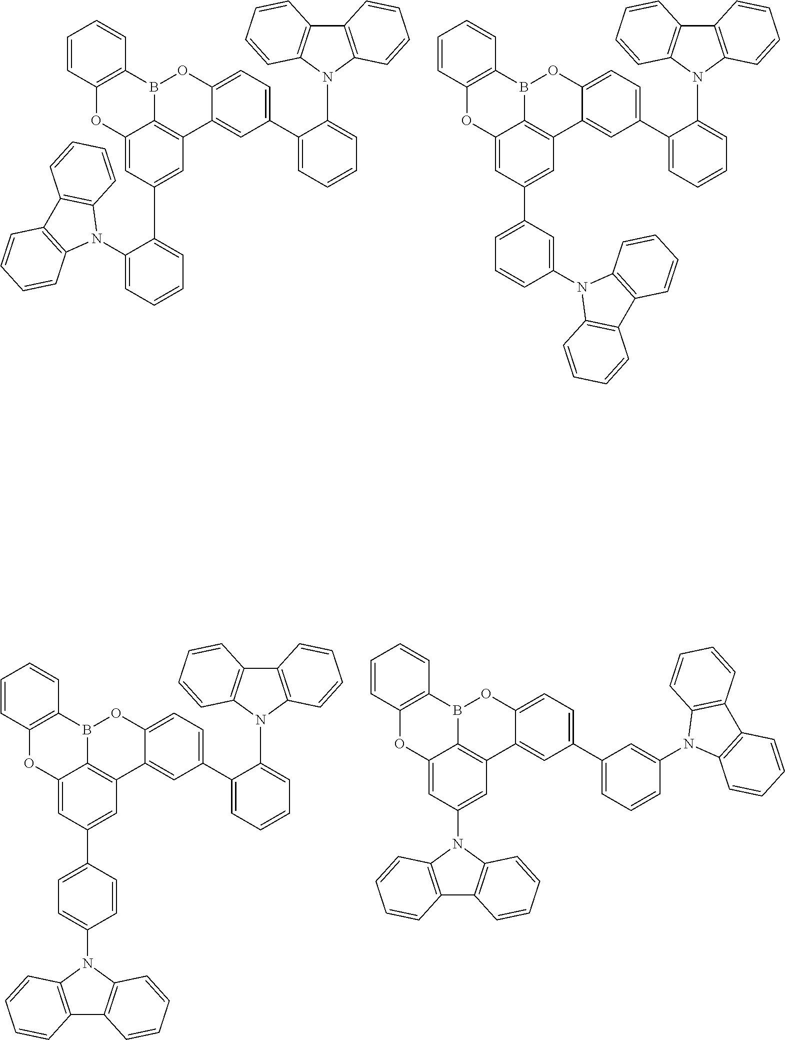

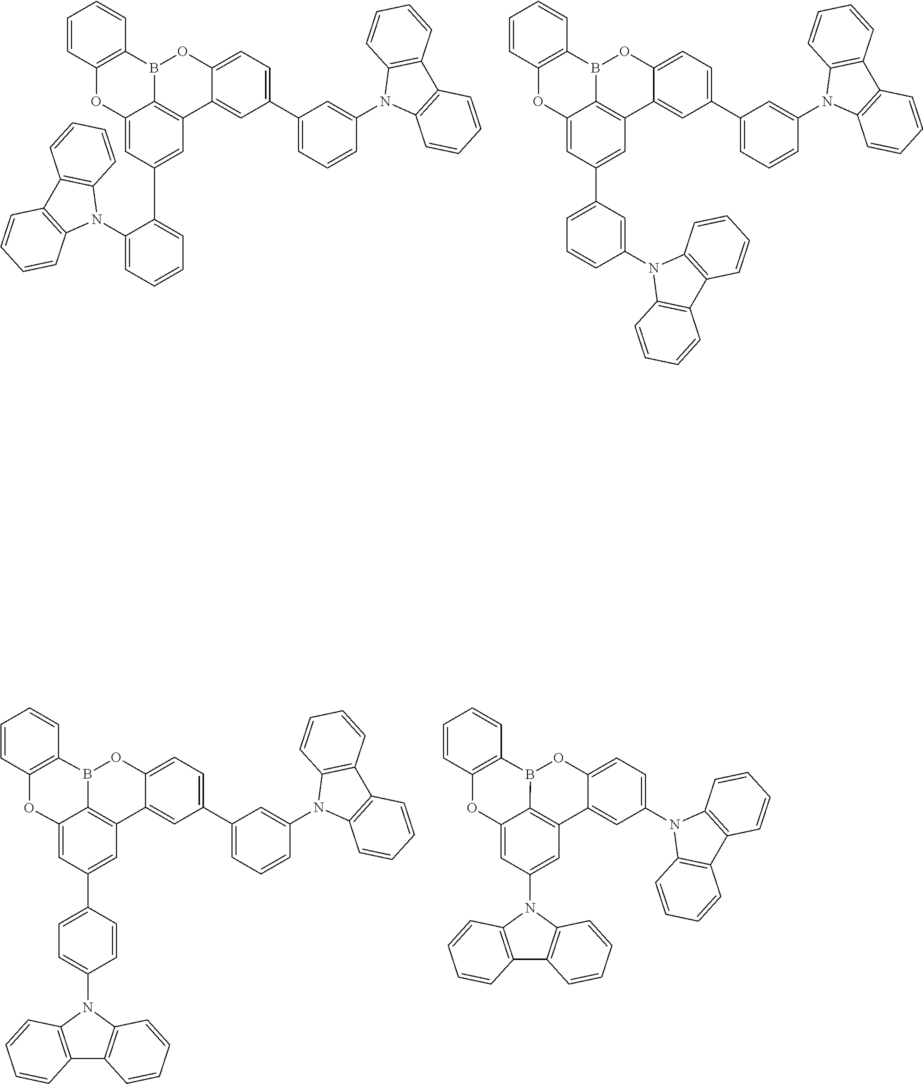

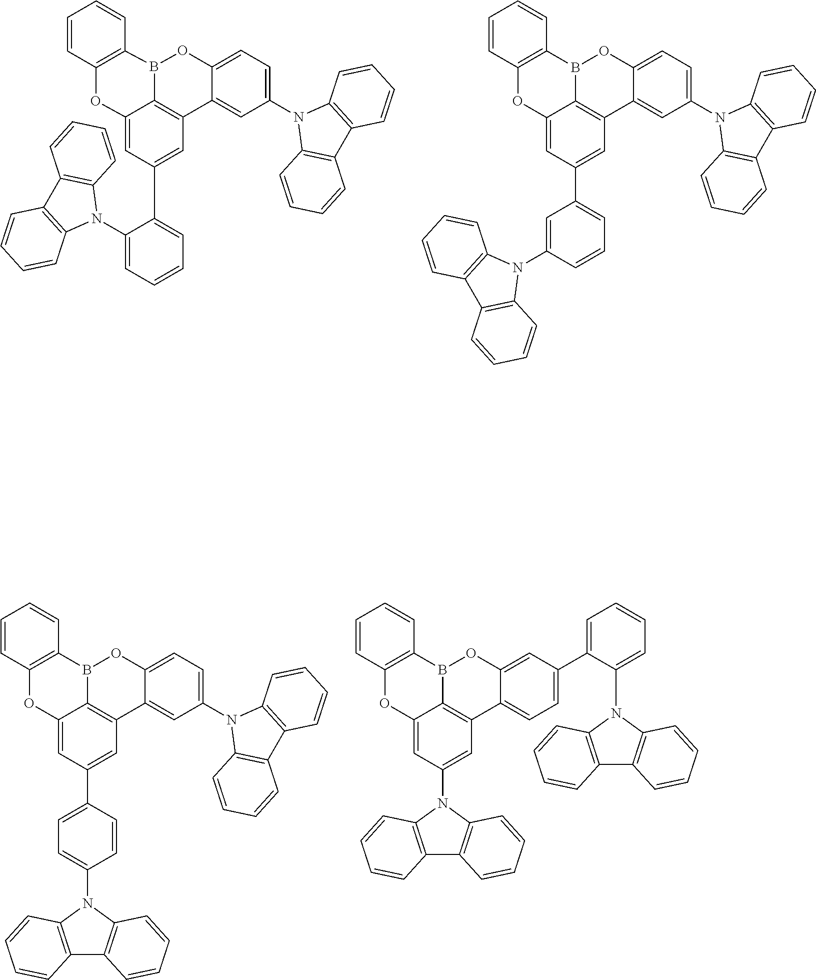

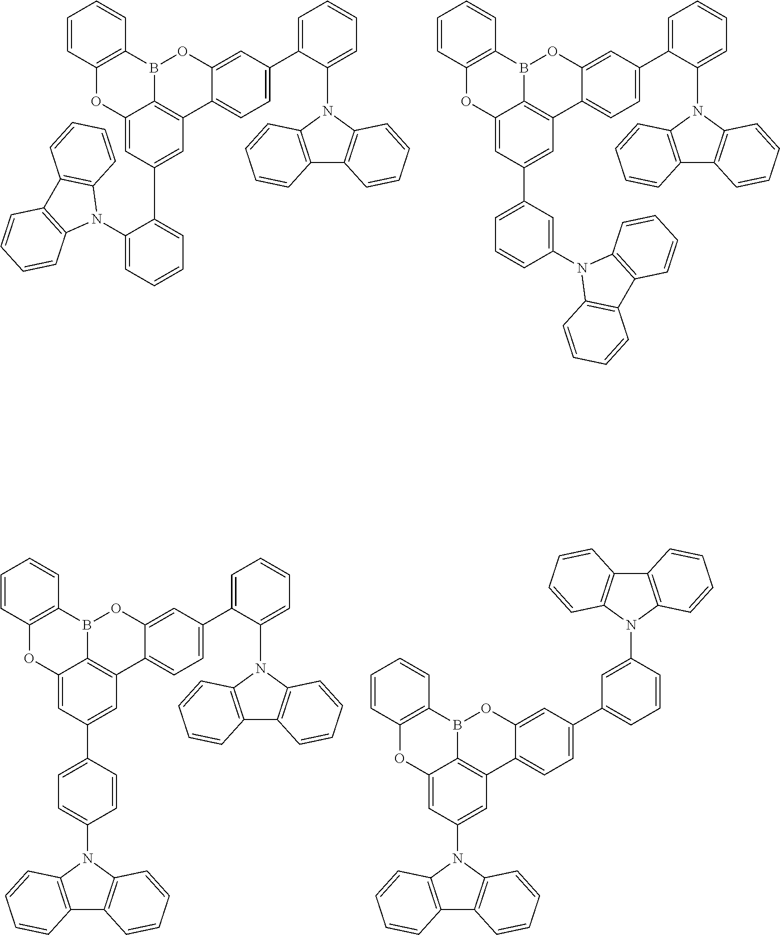

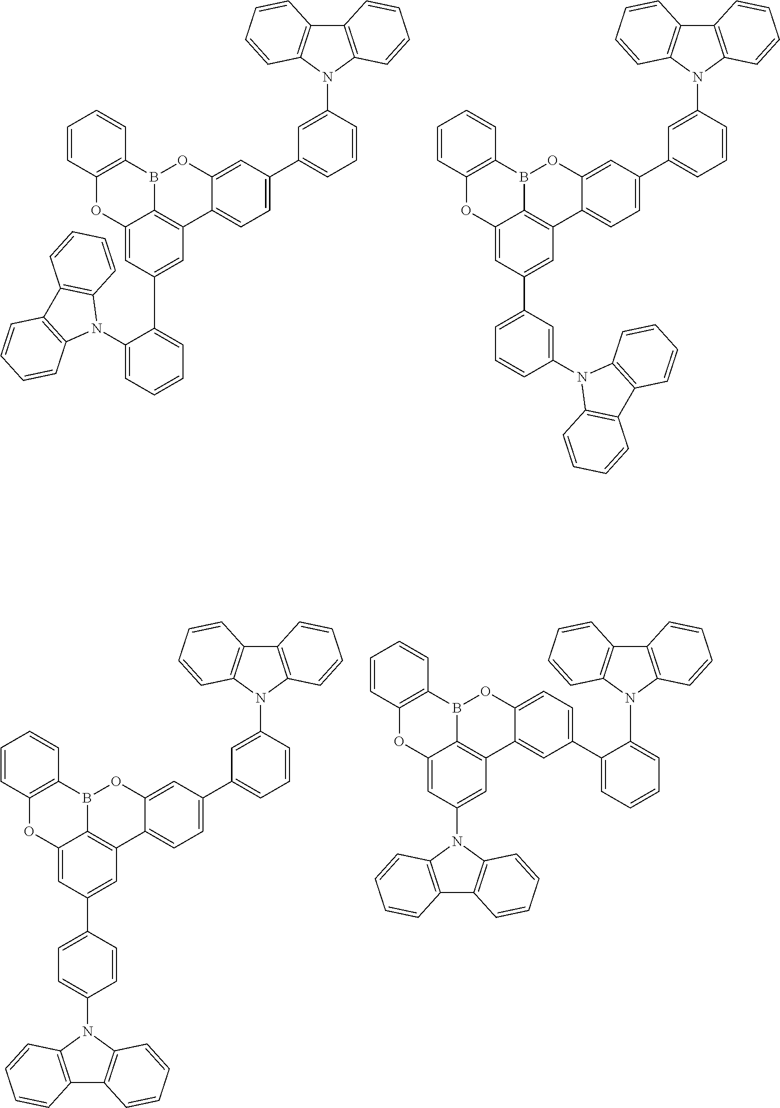

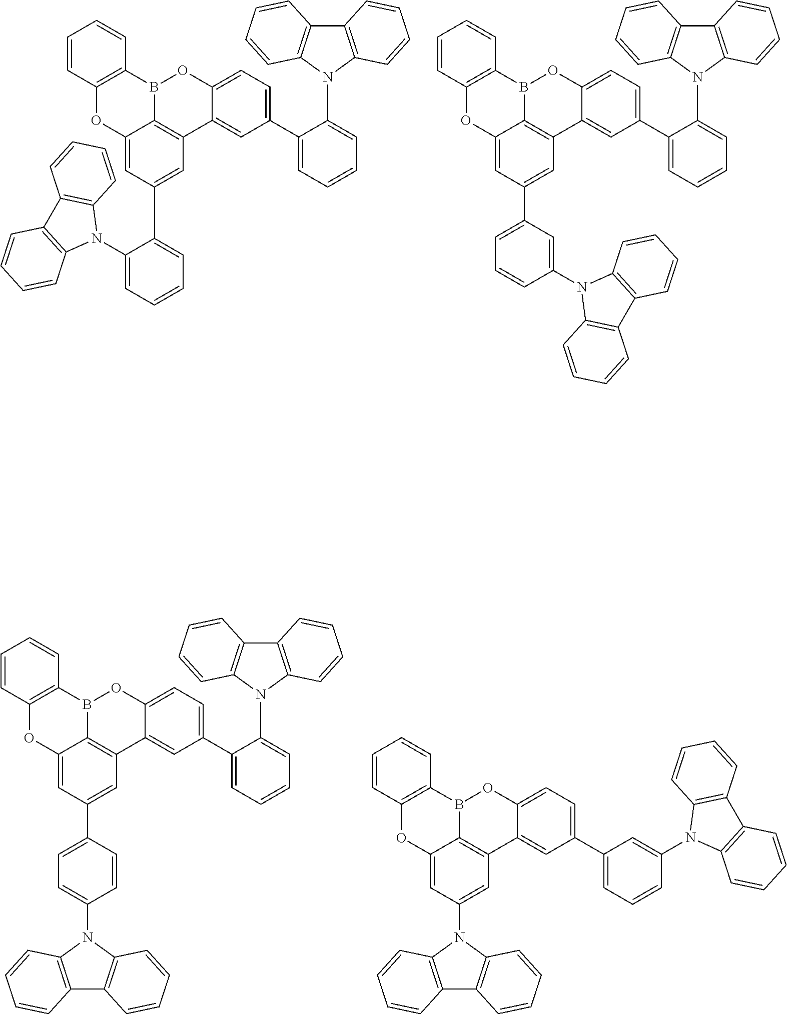

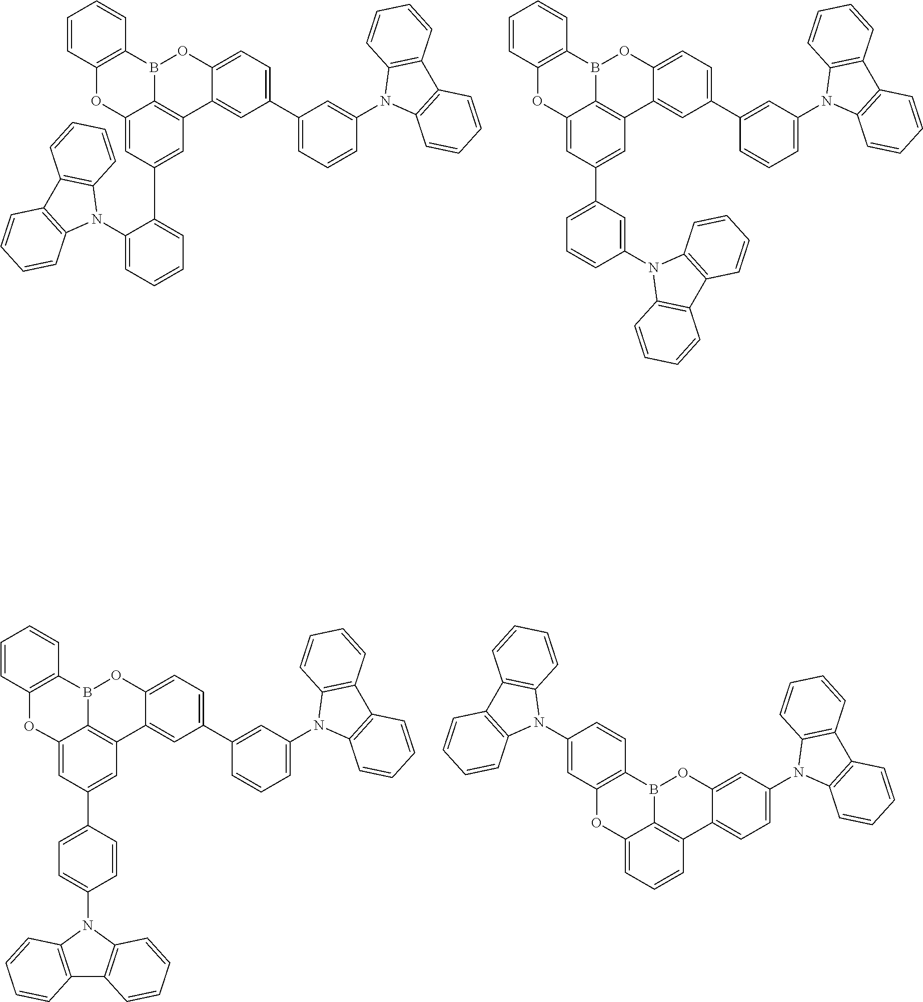

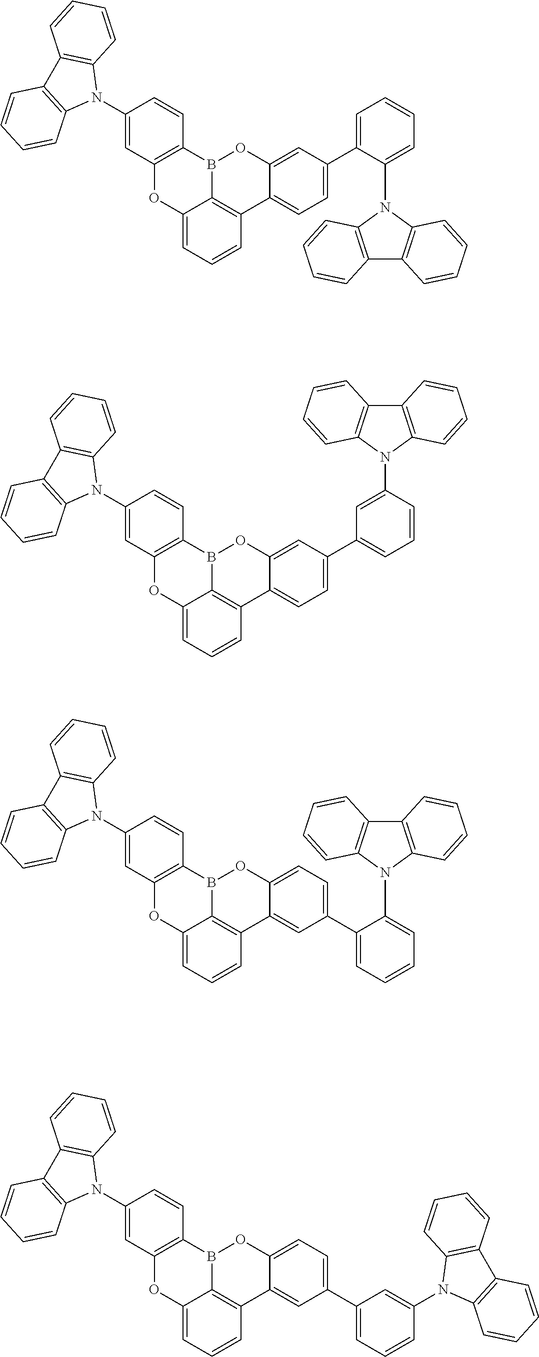 [SMILES: c1ccc(-n2c3ccccc3c3ccccc32)c(-c2ccc3c(c2)OB2c4ccc(-n5c6ccccc6c6ccccc65)cc4Oc4cccc-3c42)c1 ; c1cc(-c2ccc3c(c2)OB2c4ccc(-n5c6ccccc6c6ccccc65)cc4Oc4cccc-3c42)cc(-n2c3ccccc3c3ccccc32)c1 ; c1ccc(-n2c3ccccc3c3ccccc32)c(-c2ccc3c(c2)-c2cccc4c2B(O3)c2ccc(-n3c5ccccc5c5ccccc53)cc2O4)c1 ; c1cc(-c2ccc3c(c2)-c2cccc4c2B(O3)c2ccc(-n3c5ccccc5c5ccccc53)cc2O4)cc(-n2c3ccccc3c3ccccc32)c1]

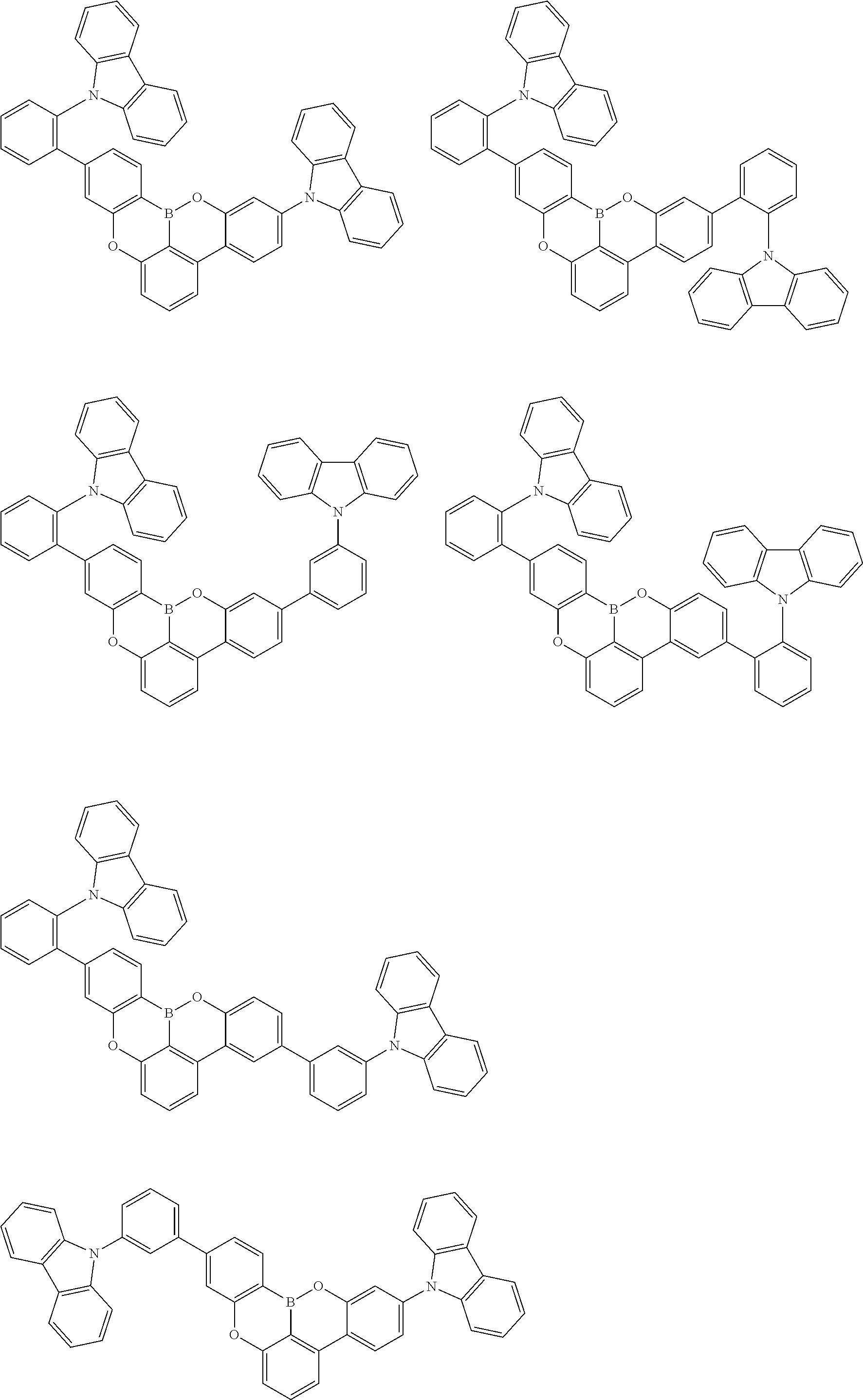

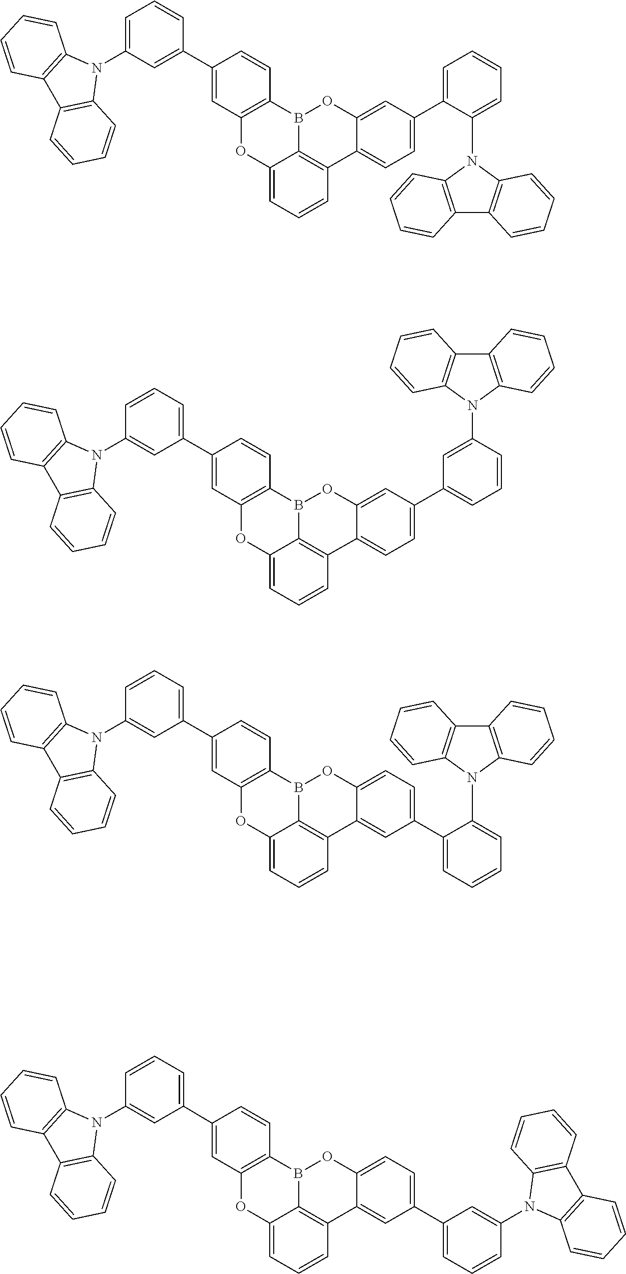

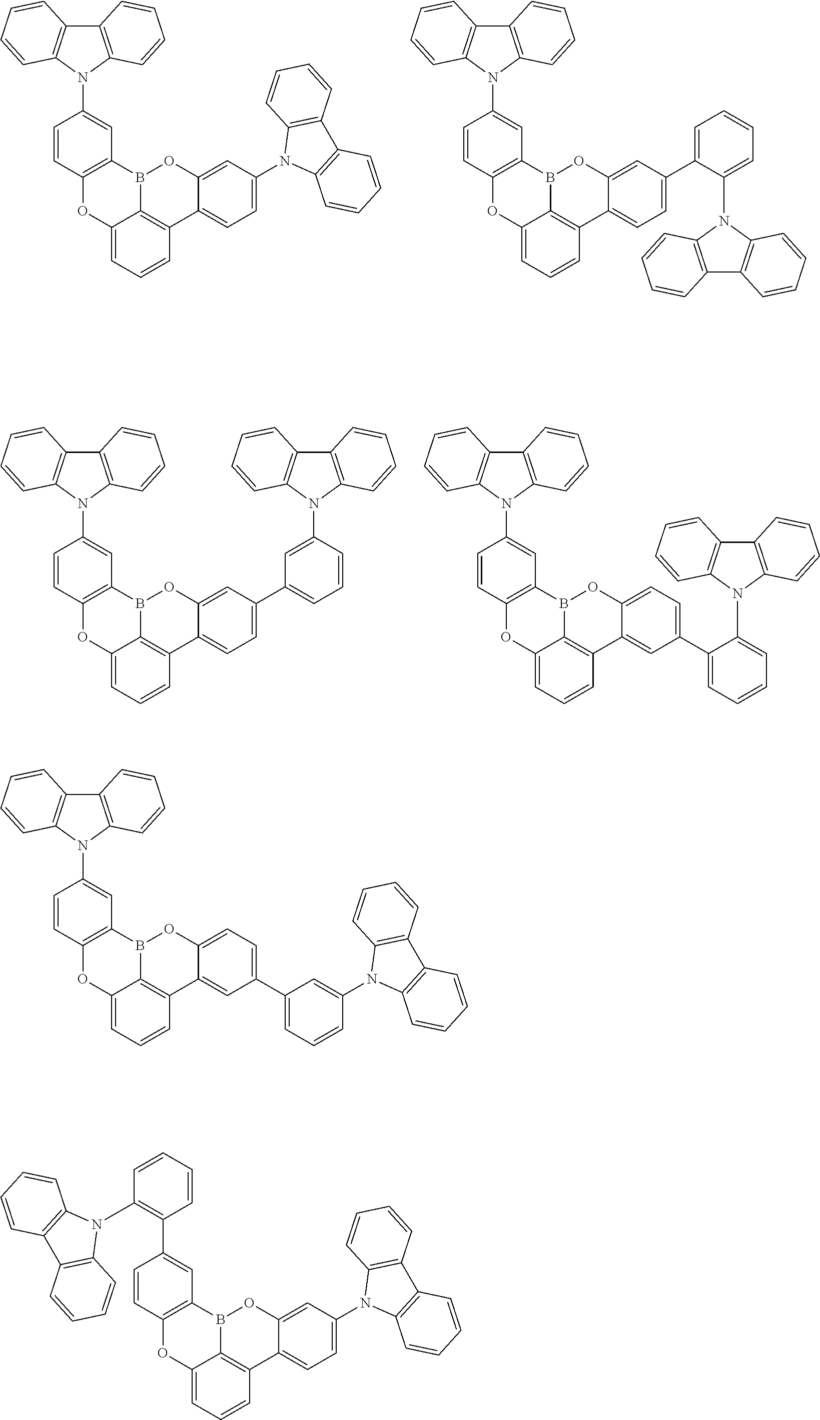

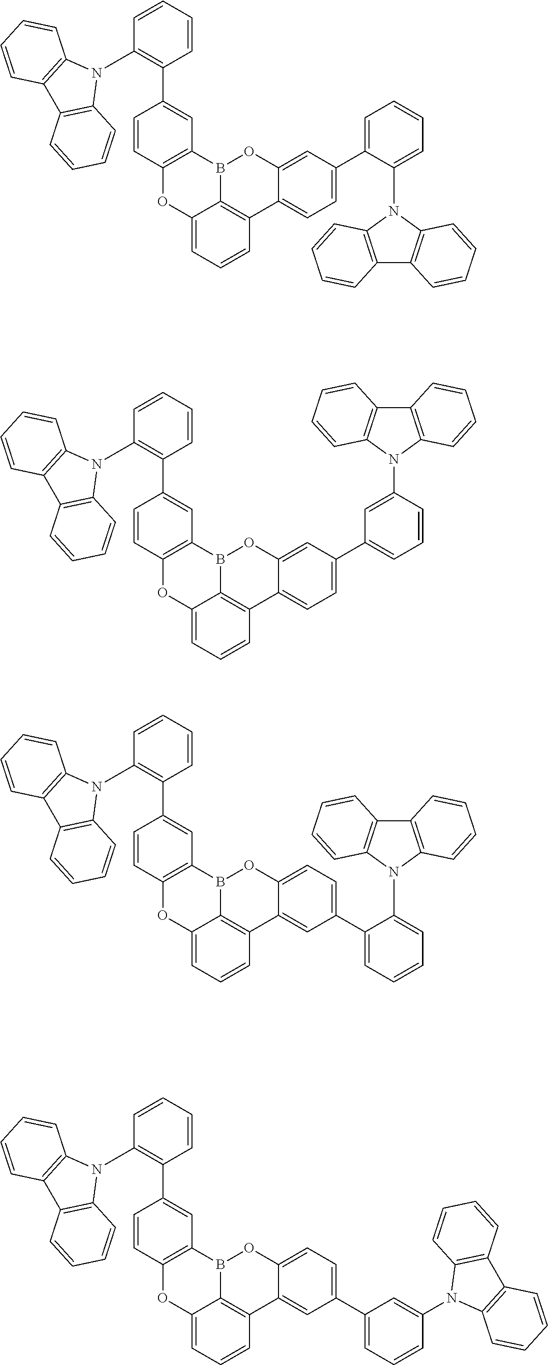

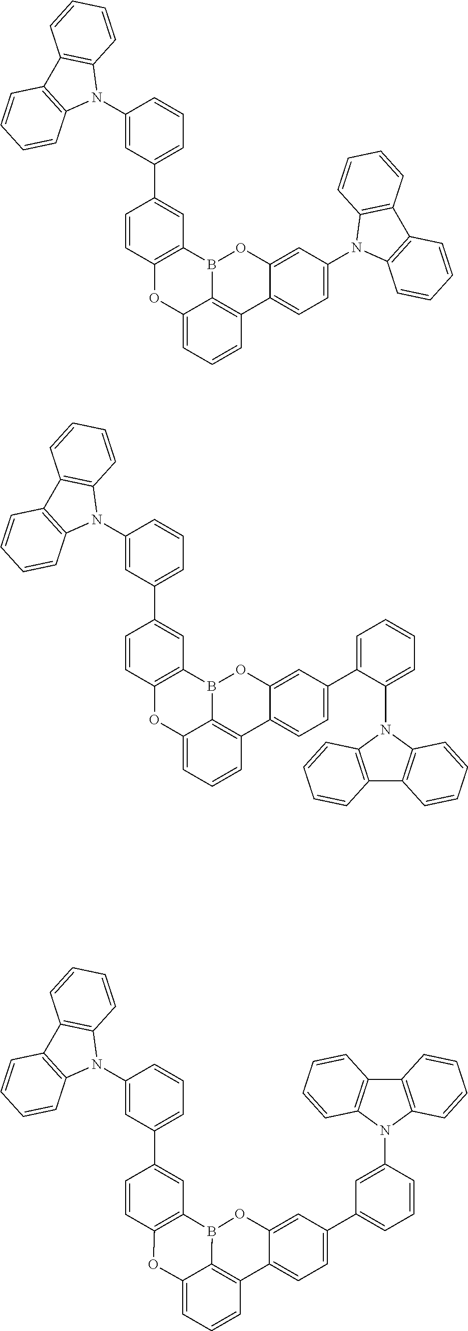 [SMILES: c1cc(-c2ccc3c(c2)B2Oc4cc(-n5c6ccccc6c6ccccc65)ccc4-c4cccc(c42)O3)cc(-n2c3ccccc3c3ccccc32)c1 ; c1cc(-c2ccc3c(c2)B2Oc4cc(-c5ccccc5-n5c6ccccc6c6ccccc65)ccc4-c4cccc(c42)O3)cc(-n2c3ccccc3c3ccccc32)c1 ; c1cc(-c2ccc3c(c2)OB2c4cc(-c5cccc(-n6c7ccccc7c7ccccc76)c5)ccc4Oc4cccc-3c42)cc(-n2c3ccccc3c3ccccc32)c1]

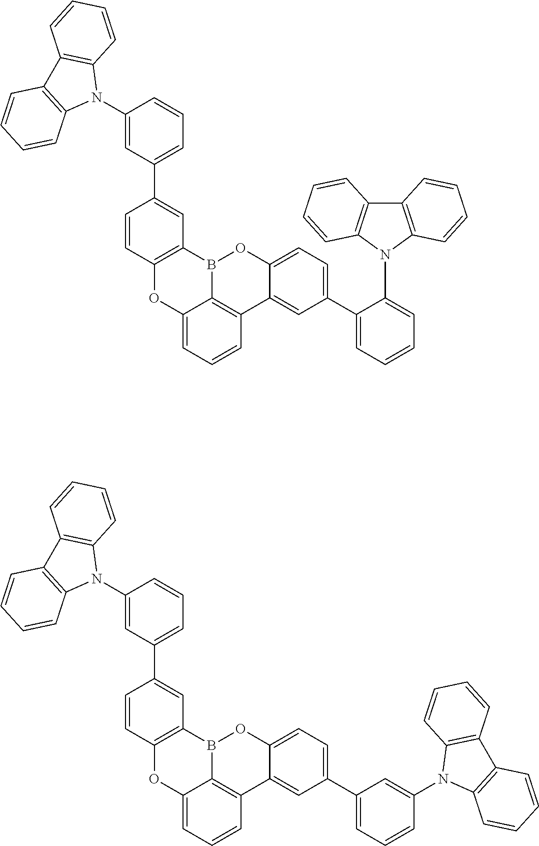 [SMILES: c1cc(-c2ccc3c(c2)B2Oc4ccc(-c5ccccc5-n5c6ccccc6c6ccccc65)cc4-c4cccc(c42)O3)cc(-n2c3ccccc3c3ccccc32)c1 ; c1cc(-c2ccc3c(c2)B2Oc4ccc(-c5cccc(-n6c7ccccc7c7ccccc76)c5)cc4-c4cccc(c42)O3)cc(-n2c3ccccc3c3ccccc32)c1]

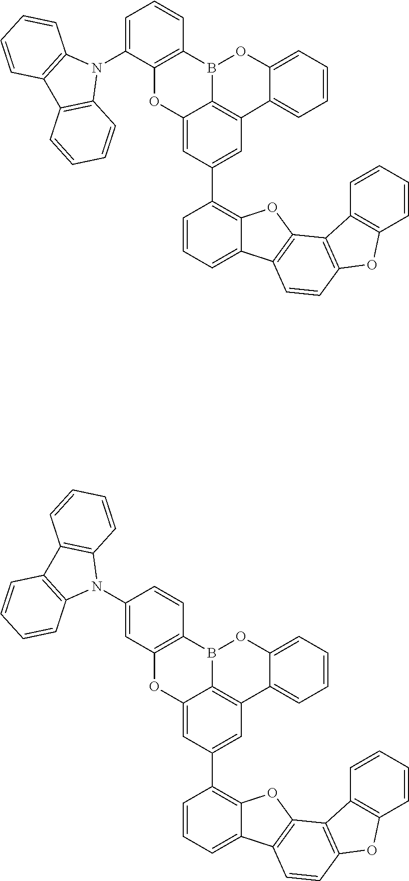 [SMILES: c1ccc2c(c1)OB1c3cccc(-n4c5ccccc5c5ccccc54)c3Oc3cc(-c4cccc5c4oc4c5ccc5oc6ccccc6c54)cc-2c31 ; c1ccc2c(c1)OB1c3ccc(-n4c5ccccc5c5ccccc54)cc3Oc3cc(-c4cccc5c4oc4c5ccc5oc6ccccc6c54)cc-2c31]

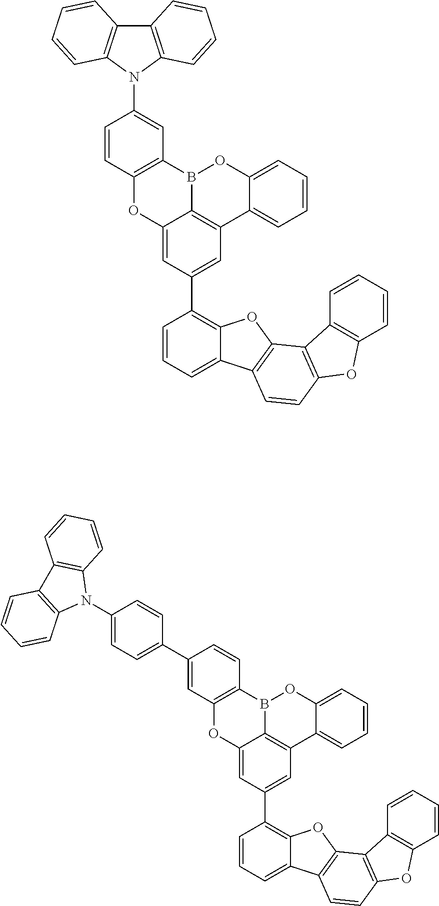 [SMILES: c1ccc2c(c1)OB1c3cc(-n4c5ccccc5c5ccccc54)ccc3Oc3cc(-c4cccc5c4oc4c5ccc5oc6ccccc6c54)cc-2c31 ; c1ccc2c(c1)OB1c3ccc(-c4ccc(-n5c6ccccc6c6ccccc65)cc4)cc3Oc3cc(-c4cccc5c4oc4c5ccc5oc6ccccc6c54)cc-2c31]

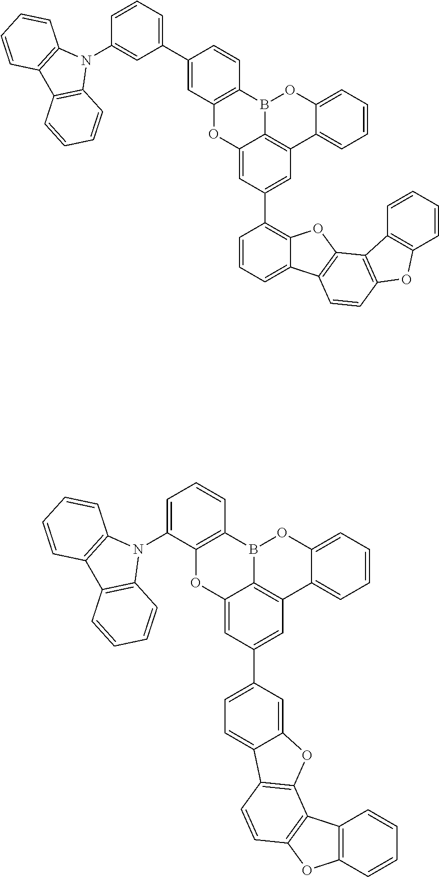 [SMILES: c1cc(-c2ccc3c(c2)Oc2cc(-c4cccc5c4oc4c5ccc5oc6ccccc6c54)cc4c2B3Oc2ccccc2-4)cc(-n2c3ccccc3c3ccccc32)c1 ; c1ccc2c(c1)OB1c3cccc(-n4c5ccccc5c5ccccc54)c3Oc3cc(-c4ccc5c(c4)oc4c5ccc5oc6ccccc6c54)cc-2c31]

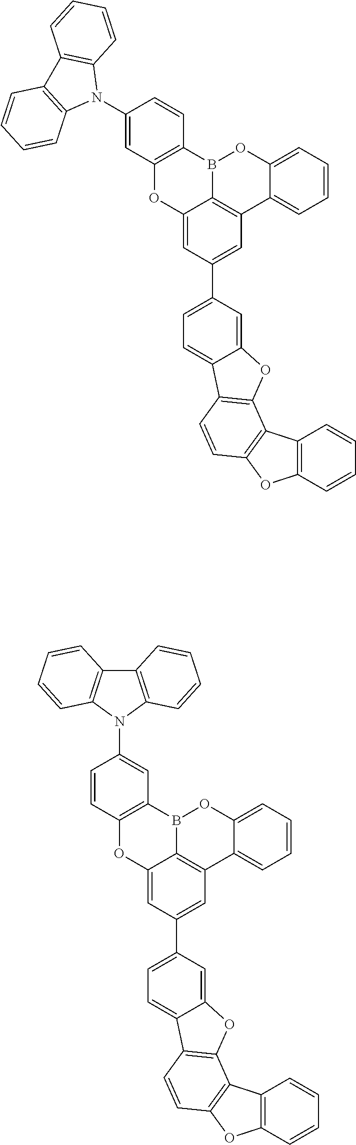 [SMILES: c1ccc2c(c1)OB1c3ccc(-n4c5ccccc5c5ccccc54)cc3Oc3cc(-c4ccc5c(c4)oc4c5ccc5oc6ccccc6c54)cc-2c31 ; c1ccc2c(c1)OB1c3cc(-n4c5ccccc5c5ccccc54)ccc3Oc3cc(-c4ccc5c(c4)oc4c5ccc5oc6ccccc6c54)cc-2c31]

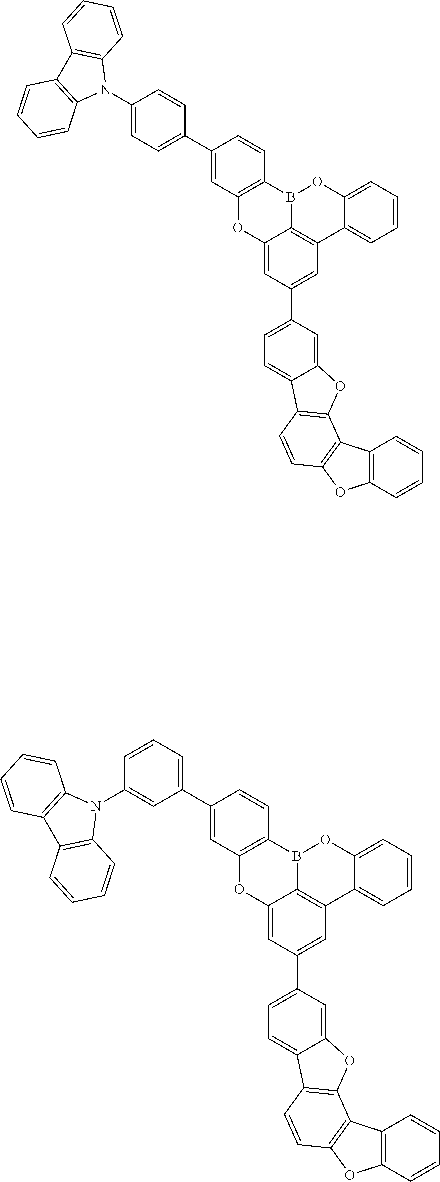 [SMILES: c1ccc2c(c1)OB1c3ccc(-c4ccc(-n5c6ccccc6c6ccccc65)cc4)cc3Oc3cc(-c4ccc5c(c4)oc4c5ccc5oc6ccccc6c54)cc-2c31 ; c1cc(-c2ccc3c(c2)Oc2cc(-c4ccc5c(c4)oc4c5ccc5oc6ccccc6c54)cc4c2B3Oc2ccccc2-4)cc(-n2c3ccccc3c3ccccc32)c1]

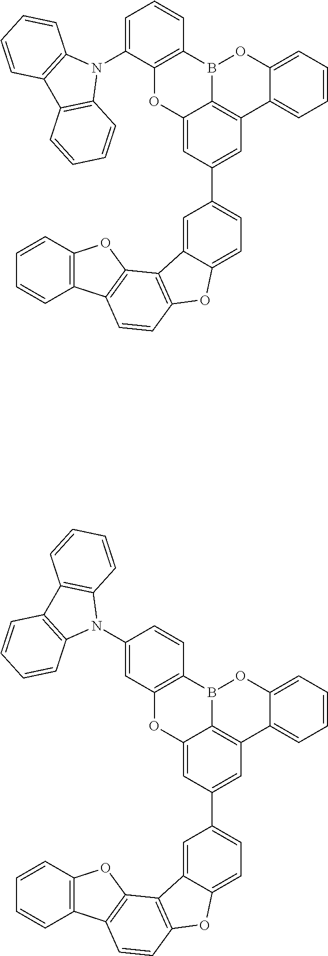 [SMILES: c1ccc2c(c1)OB1c3cccc(-n4c5ccccc5c5ccccc54)c3Oc3cc(-c4ccc5oc6ccc7c8ccccc8oc7c6c5c4)cc-2c31 ; c1ccc2c(c1)OB1c3ccc(-n4c5ccccc5c5ccccc54)cc3Oc3cc(-c4ccc5oc6ccc7c8ccccc8oc7c6c5c4)cc-2c31]

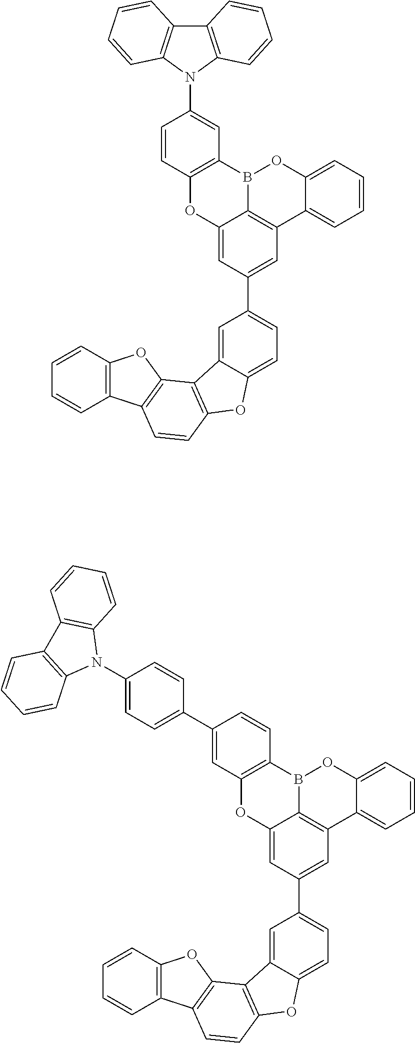 [SMILES: c1ccc2c(c1)OB1c3cc(-n4c5ccccc5c5ccccc54)ccc3Oc3cc(-c4ccc5oc6ccc7c8ccccc8oc7c6c5c4)cc-2c31 ; c1ccc2c(c1)OB1c3ccc(-c4ccc(-n5c6ccccc6c6ccccc65)cc4)cc3Oc3cc(-c4ccc5oc6ccc7c8ccccc8oc7c6c5c4)cc-2c31]

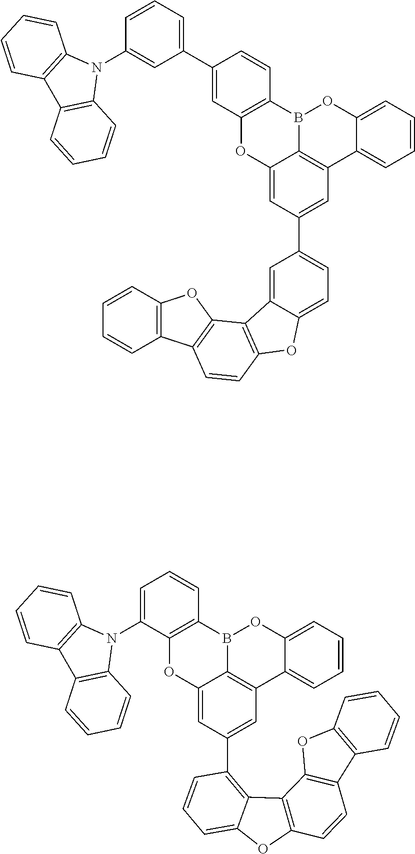

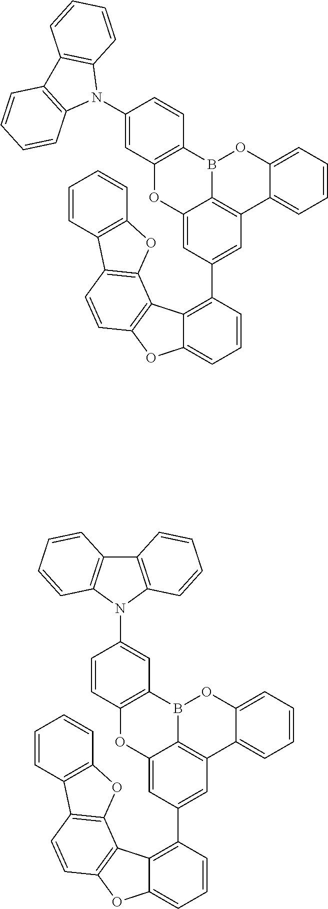 [SMILES: c1ccc2c(c1)OB1c3ccc(-n4c5ccccc5c5ccccc54)cc3Oc3cc(-c4cccc5oc6ccc7c8ccccc8oc7c6c45)cc-2c31 ; c1ccc2c(c1)OB1c3cc(-n4c5ccccc5c5ccccc54)ccc3Oc3cc(-c4cccc5oc6ccc7c8ccccc8oc7c6c45)cc-2c31]

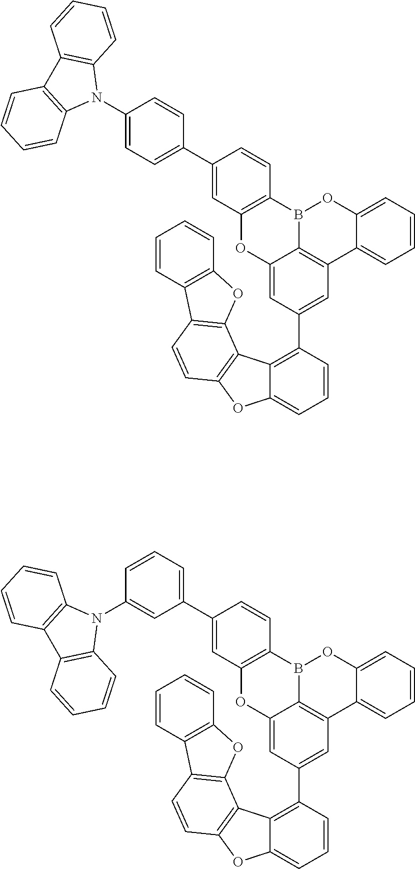 [SMILES: c1ccc2c(c1)OB1c3ccc(-c4ccc(-n5c6ccccc6c6ccccc65)cc4)cc3Oc3cc(-c4cccc5oc6ccc7c8ccccc8oc7c6c45)cc-2c31 ; c1cc(-c2ccc3c(c2)Oc2cc(-c4cccc5oc6ccc7c8ccccc8oc7c6c45)cc4c2B3Oc2ccccc2-4)cc(-n2c3ccccc3c3ccccc32)c1]

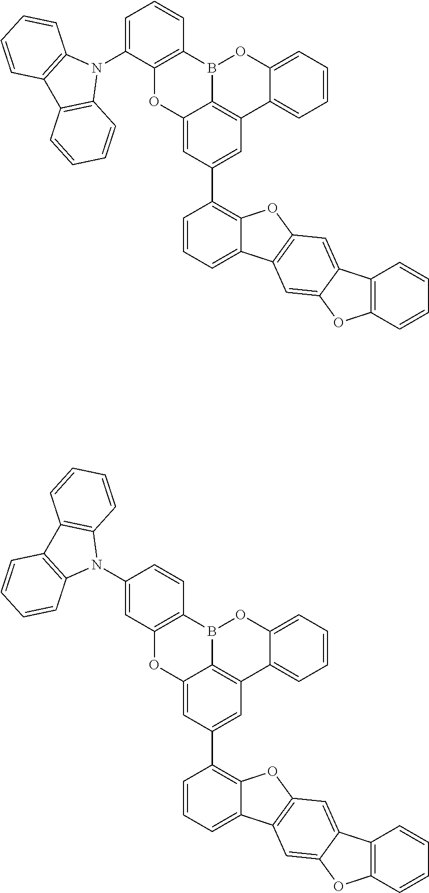 [SMILES: c1ccc2c(c1)OB1c3cccc(-n4c5ccccc5c5ccccc54)c3Oc3cc(-c4cccc5c4oc4cc6c(cc45)oc4ccccc46)cc-2c31 ; c1ccc2c(c1)OB1c3ccc(-n4c5ccccc5c5ccccc54)cc3Oc3cc(-c4cccc5c4oc4cc6c(cc45)oc4ccccc46)cc-2c31]

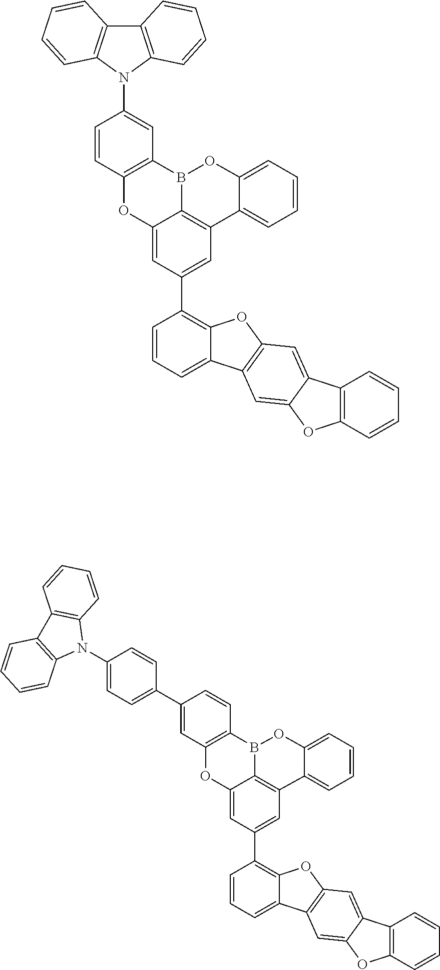

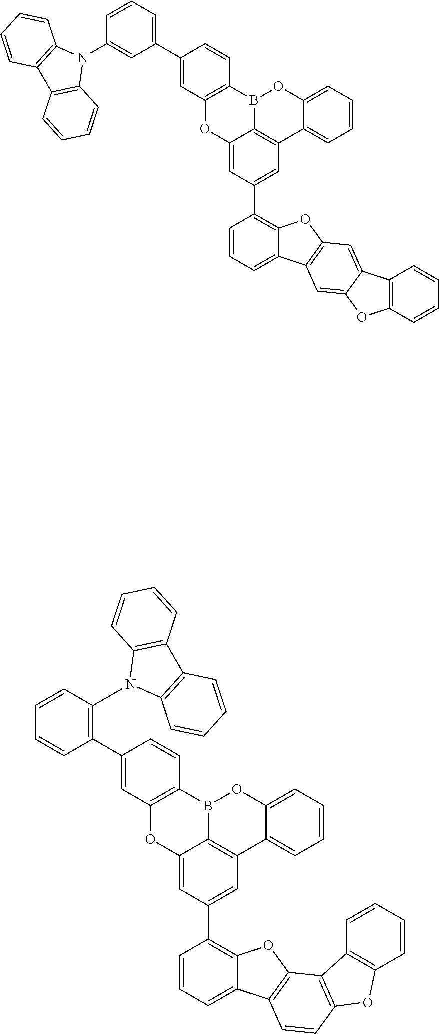 [SMILES: c1cc(-c2ccc3c(c2)Oc2cc(-c4cccc5c4oc4cc6c(cc45)oc4ccccc46)cc4c2B3Oc2ccccc2-4)cc(-n2c3ccccc3c3ccccc32)c1 ; c1ccc2c(c1)OB1c3ccc(-c4ccccc4-n4c5ccccc5c5ccccc54)cc3Oc3cc(-c4cccc5c4oc4c5ccc5oc6ccccc6c54)cc-2c31]

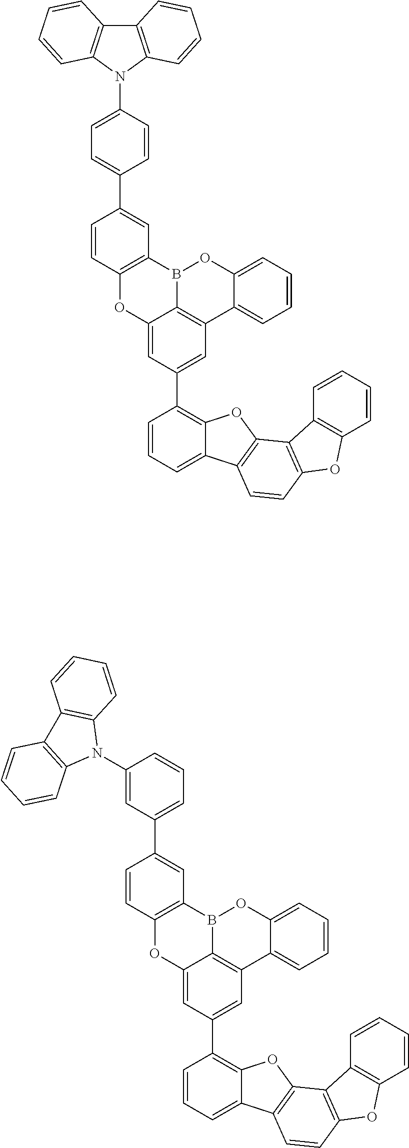 [SMILES: c1ccc2c(c1)OB1c3cc(-c4ccc(-n5c6ccccc6c6ccccc65)cc4)ccc3Oc3cc(-c4cccc5c4oc4c5ccc5oc6ccccc6c54)cc-2c31 ; c1cc(-c2ccc3c(c2)B2Oc4ccccc4-c4cc(-c5cccc6c5oc5c6ccc6oc7ccccc7c65)cc(c42)O3)cc(-n2c3ccccc3c3ccccc32)c1]

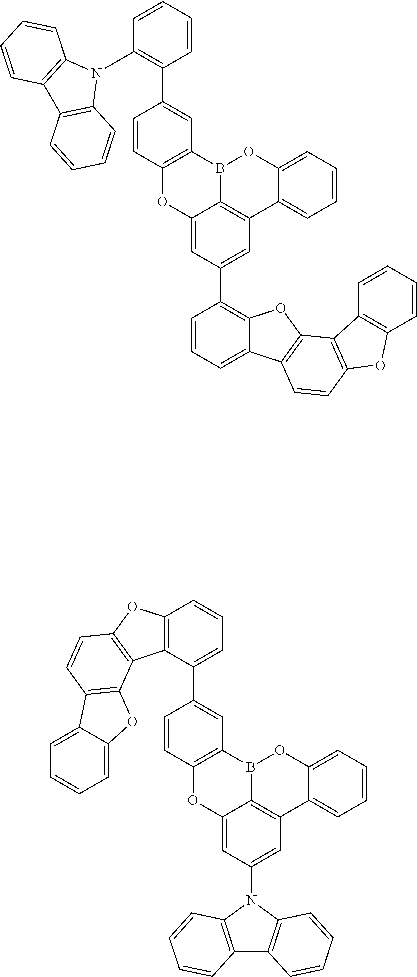 [SMILES: c1ccc2c(c1)OB1c3cc(-c4ccccc4-n4c5ccccc5c5ccccc54)ccc3Oc3cc(-c4cccc5c4oc4c5ccc5oc6ccccc6c54)cc-2c31 ; c1ccc2c(c1)OB1c3cc(-c4cccc5oc6ccc7c8ccccc8oc7c6c45)ccc3Oc3cc(-n4c5ccccc5c5ccccc54)cc-2c31]

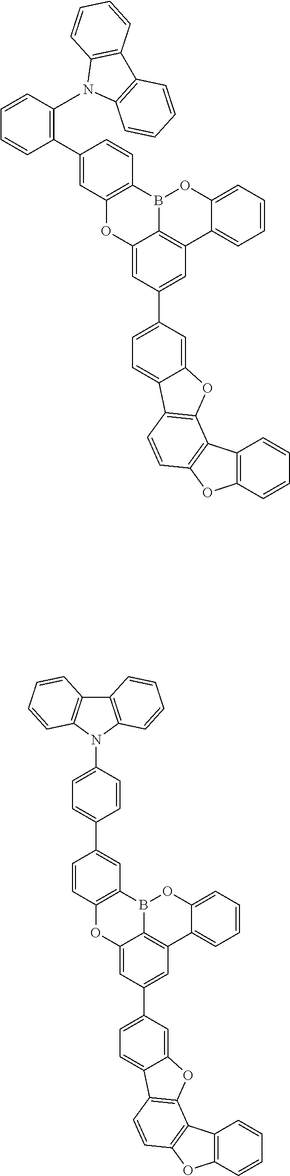 [SMILES: c1ccc2c(c1)OB1c3ccc(-c4ccccc4-n4c5ccccc5c5ccccc54)cc3Oc3cc(-c4ccc5c(c4)oc4c5ccc5oc6ccccc6c54)cc-2c31 ; c1ccc2c(c1)OB1c3cc(-c4ccc(-n5c6ccccc6c6ccccc65)cc4)ccc3Oc3cc(-c4ccc5c(c4)oc4c5ccc5oc6ccccc6c54)cc-2c31]

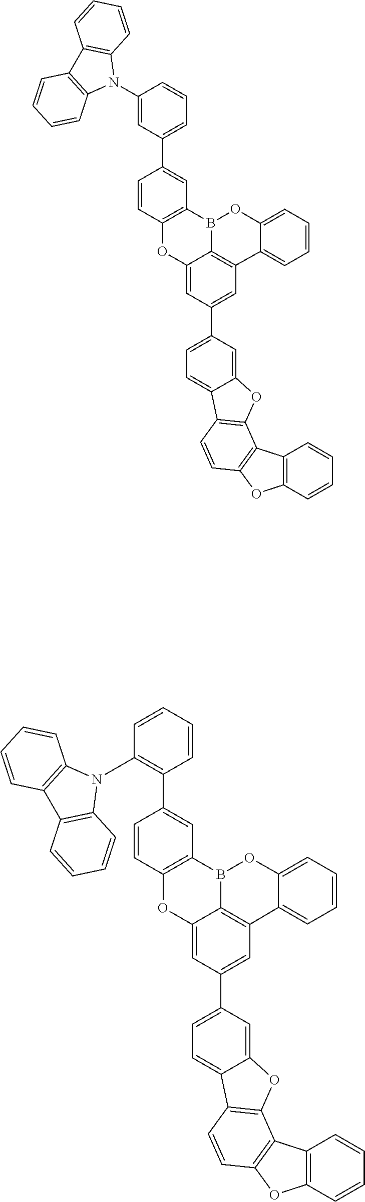 [SMILES: c1cc(-c2ccc3c(c2)B2Oc4ccccc4-c4cc(-c5ccc6c(c5)oc5c6ccc6oc7ccccc7c65)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-c4ccc5c(c4)oc4c5ccc5oc6ccccc6c54)cc-2c31]

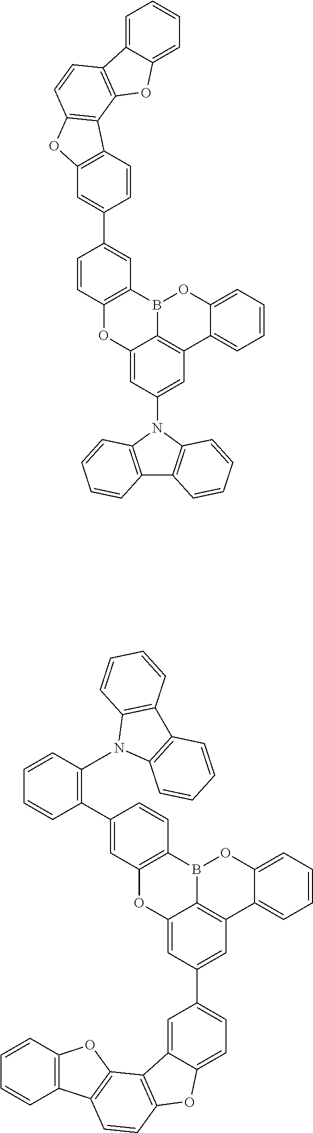 [SMILES: c1ccc2c(c1)OB1c3cc(-c4ccc5c(c4)oc4ccc6c7ccccc7oc6c45)ccc3Oc3cc(-n4c5ccccc5c5ccccc54)cc-2c31 ; c1ccc2c(c1)OB1c3ccc(-c4ccccc4-n4c5ccccc5c5ccccc54)cc3Oc3cc(-c4ccc5oc6ccc7c8ccccc8oc7c6c5c4)cc-2c31]

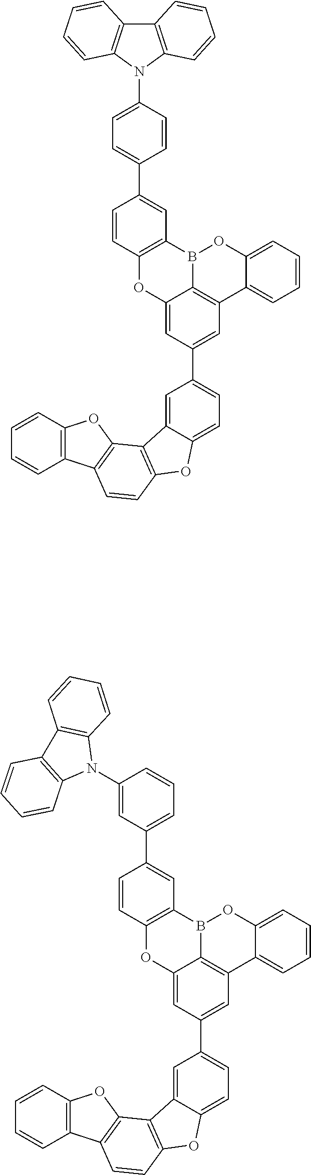 [SMILES: c1ccc2c(c1)OB1c3cc(-c4ccc(-n5c6ccccc6c6ccccc65)cc4)ccc3Oc3cc(-c4ccc5oc6ccc7c8ccccc8oc7c6c5c4)cc-2c31 ; c1cc(-c2ccc3c(c2)B2Oc4ccccc4-c4cc(-c5ccc6oc7ccc8c9ccccc9oc8c7c6c5)cc(c42)O3)cc(-n2c3ccccc3c3ccccc32)c1]

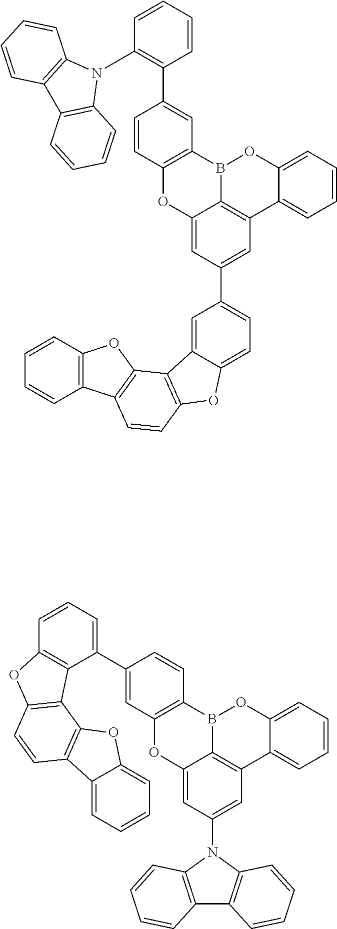 [SMILES: c1ccc2c(c1)OB1c3cc(-c4ccccc4-n4c5ccccc5c5ccccc54)ccc3Oc3cc(-c4ccc5oc6ccc7c8ccccc8oc7c6c5c4)cc-2c31 ; c1ccc2c(c1)OB1c3ccc(-c4cccc5oc6ccc7c8ccccc8oc7c6c45)cc3Oc3cc(-n4c5ccccc5c5ccccc54)cc-2c31]

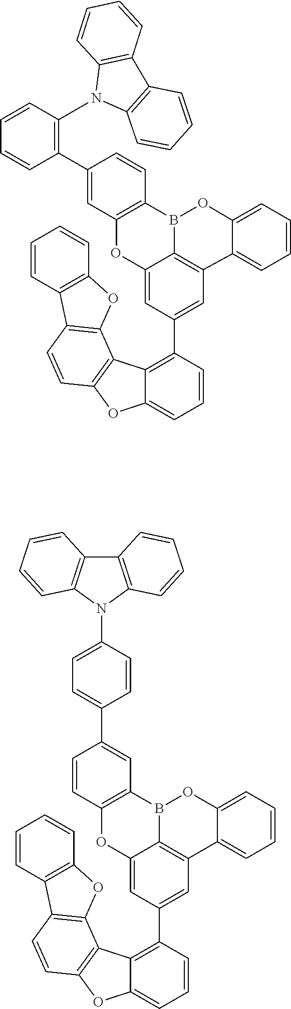 [SMILES: c1ccc2c(c1)OB1c3ccc(-c4ccccc4-n4c5ccccc5c5ccccc54)cc3Oc3cc(-c4cccc5oc6ccc7c8ccccc8oc7c6c45)cc-2c31 ; c1ccc2c(c1)OB1c3cc(-c4ccc(-n5c6ccccc6c6ccccc65)cc4)ccc3Oc3cc(-c4cccc5oc6ccc7c8ccccc8oc7c6c45)cc-2c31]

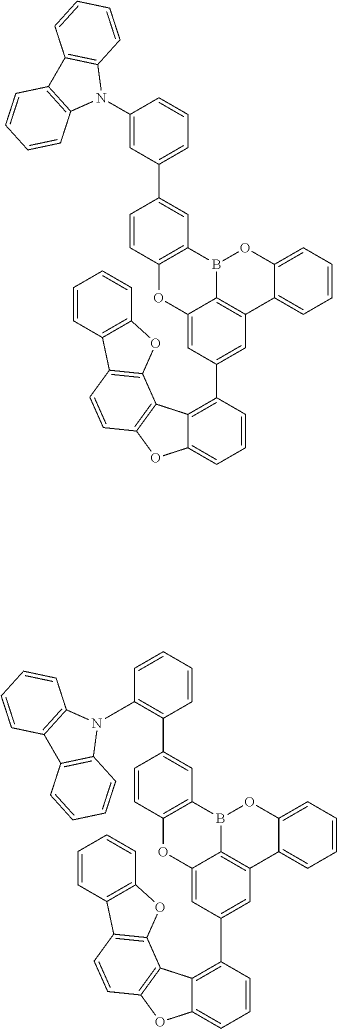 [SMILES: c1cc(-c2ccc3c(c2)B2Oc4ccccc4-c4cc(-c5cccc6oc7ccc8c9ccccc9oc8c7c56)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-c4cccc5oc6ccc7c8ccccc8oc7c6c45)cc-2c31]

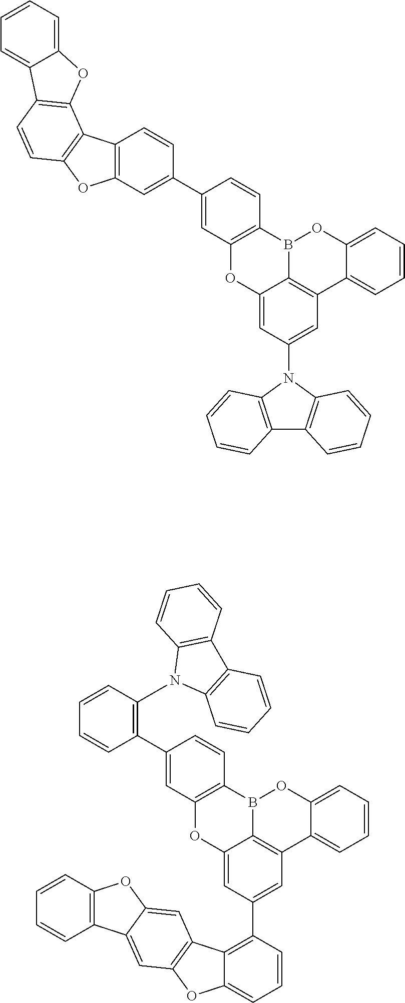 [SMILES: c1ccc2c(c1)OB1c3ccc(-c4ccc5c(c4)oc4ccc6c7ccccc7oc6c45)cc3Oc3cc(-n4c5ccccc5c5ccccc54)cc-2c31 ; c1ccc2c(c1)OB1c3ccc(-c4ccccc4-n4c5ccccc5c5ccccc54)cc3Oc3cc(-c4cccc5oc6cc7c(cc6c45)oc4ccccc47)cc-2c31]

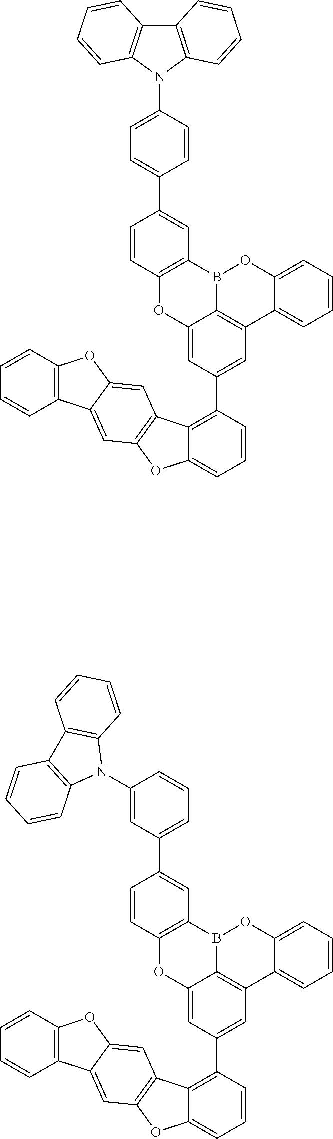 [SMILES: c1ccc2c(c1)OB1c3cc(-c4ccc(-n5c6ccccc6c6ccccc65)cc4)ccc3Oc3cc(-c4cccc5oc6cc7c(cc6c45)oc4ccccc47)cc-2c31 ; c1cc(-c2ccc3c(c2)B2Oc4ccccc4-c4cc(-c5cccc6oc7cc8c(cc7c56)oc5ccccc58)cc(c42)O3)cc(-n2c3ccccc3c3ccccc32)c1]

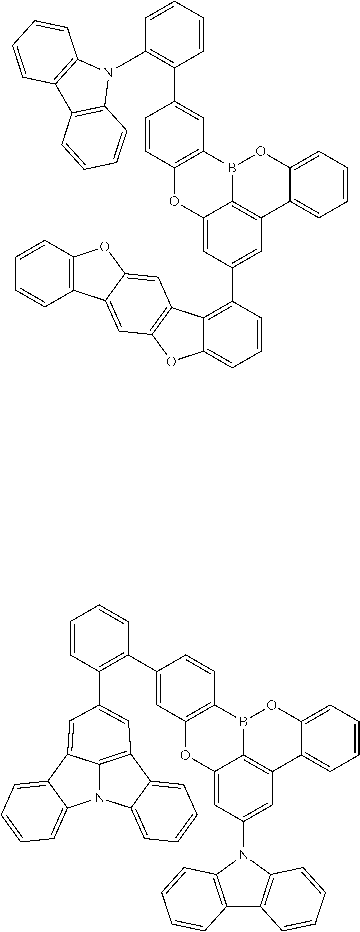 [SMILES: c1ccc2c(c1)OB1c3cc(-c4ccccc4-n4c5ccccc5c5ccccc54)ccc3Oc3cc(-c4cccc5oc6cc7c(cc6c45)oc4ccccc47)cc-2c31 ; c1ccc2c(c1)OB1c3ccc(-c4ccccc4-c4cc5c6ccccc6n6c7ccccc7c(c4)c56)cc3Oc3cc(-n4c5ccccc5c5ccccc54)cc-2c31]

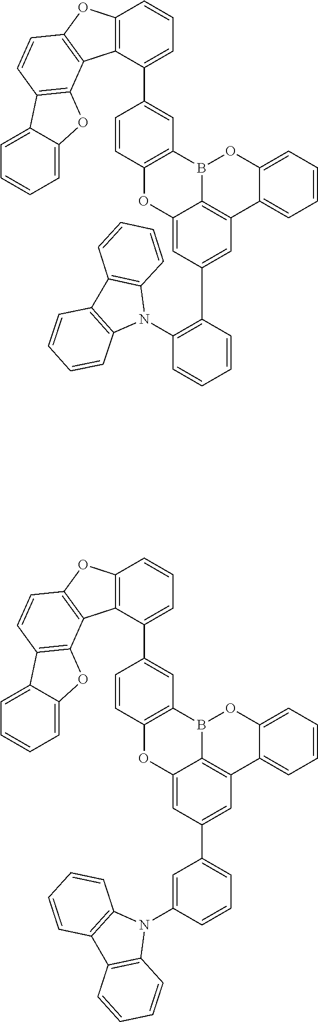 [SMILES: c1ccc2c(c1)OB1c3cc(-c4cccc5oc6ccc7c8ccccc8oc7c6c45)ccc3Oc3cc(-c4ccccc4-n4c5ccccc5c5ccccc54)cc-2c31 ; c1cc(-c2cc3c4c(c2)-c2ccccc2OB4c2cc(-c4cccc5oc6ccc7c8ccccc8oc7c6c45)ccc2O3)cc(-n2c3ccccc3c3ccccc32)c1]

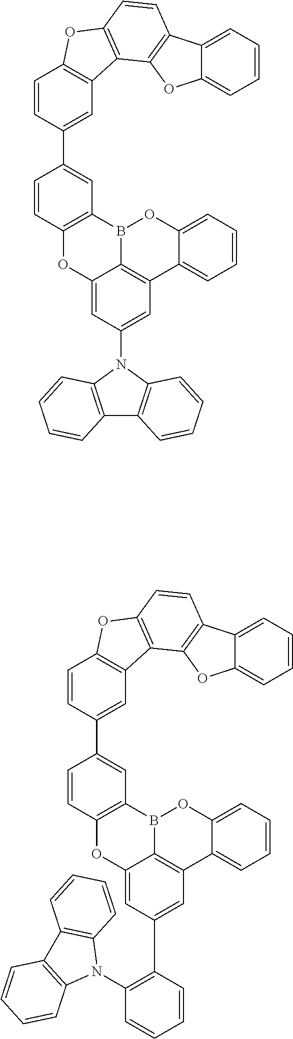 [SMILES: c1ccc2c(c1)OB1c3cc(-c4ccc5oc6ccc7c8ccccc8oc7c6c5c4)ccc3Oc3cc(-n4c5ccccc5c5ccccc54)cc-2c31 ; c1ccc2c(c1)OB1c3cc(-c4ccc5oc6ccc7c8ccccc8oc7c6c5c4)ccc3Oc3cc(-c4ccccc4-n4c5ccccc5c5ccccc54)cc-2c31]

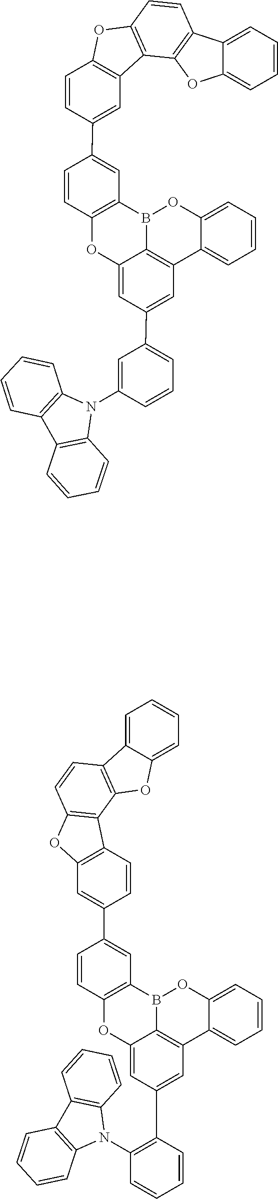 [SMILES: c1cc(-c2cc3c4c(c2)-c2ccccc2OB4c2cc(-c4ccc5oc6ccc7c8ccccc8oc7c6c5c4)ccc2O3)cc(-n2c3ccccc3c3ccccc32)c1 ; c1ccc2c(c1)OB1c3cc(-c4ccc5c(c4)oc4ccc6c7ccccc7oc6c45)ccc3Oc3cc(-c4ccccc4-n4c5ccccc5c5ccccc54)cc-2c31]

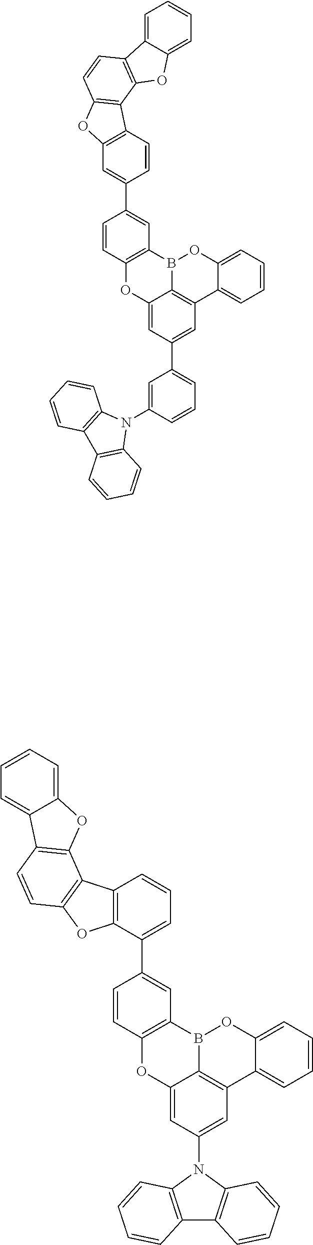 [SMILES: c1cc(-c2cc3c4c(c2)-c2ccccc2OB4c2cc(-c4ccc5c(c4)oc4ccc6c7ccccc7oc6c45)ccc2O3)cc(-n2c3ccccc3c3ccccc32)c1 ; c1ccc2c(c1)OB1c3cc(-c4cccc5c4oc4ccc6c7ccccc7oc6c45)ccc3Oc3cc(-n4c5ccccc5c5ccccc54)cc-2c31]

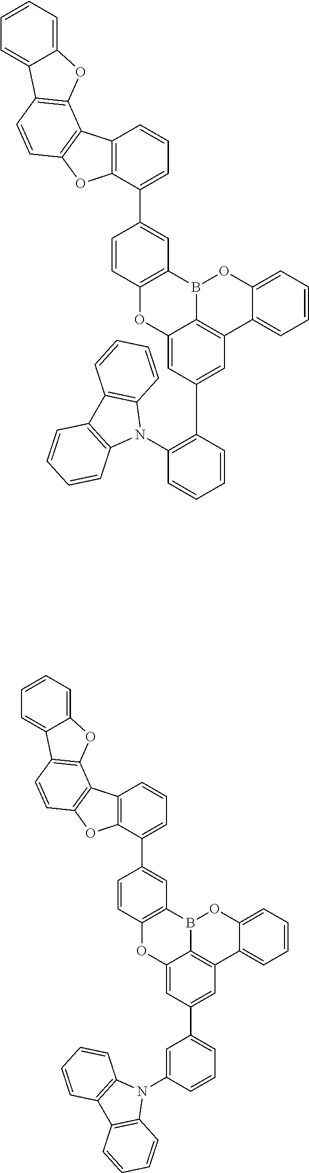 [SMILES: c1ccc2c(c1)OB1c3cc(-c4cccc5c4oc4ccc6c7ccccc7oc6c45)ccc3Oc3cc(-c4ccccc4-n4c5ccccc5c5ccccc54)cc-2c31 ; c1cc(-c2cc3c4c(c2)-c2ccccc2OB4c2cc(-c4cccc5c4oc4ccc6c7ccccc7oc6c45)ccc2O3)cc(-n2c3ccccc3c3ccccc32)c1]

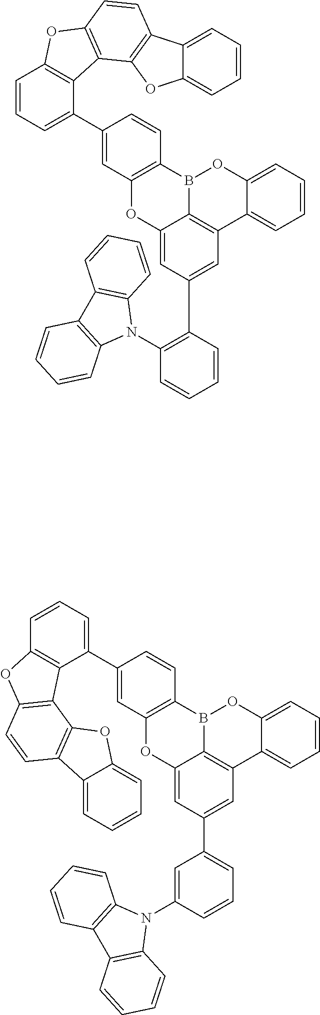 [SMILES: c1ccc2c(c1)OB1c3ccc(-c4cccc5oc6ccc7c8ccccc8oc7c6c45)cc3Oc3cc(-c4ccccc4-n4c5ccccc5c5ccccc54)cc-2c31 ; c1cc(-c2cc3c4c(c2)-c2ccccc2OB4c2ccc(-c4cccc5oc6ccc7c8ccccc8oc7c6c45)cc2O3)cc(-n2c3ccccc3c3ccccc32)c1]

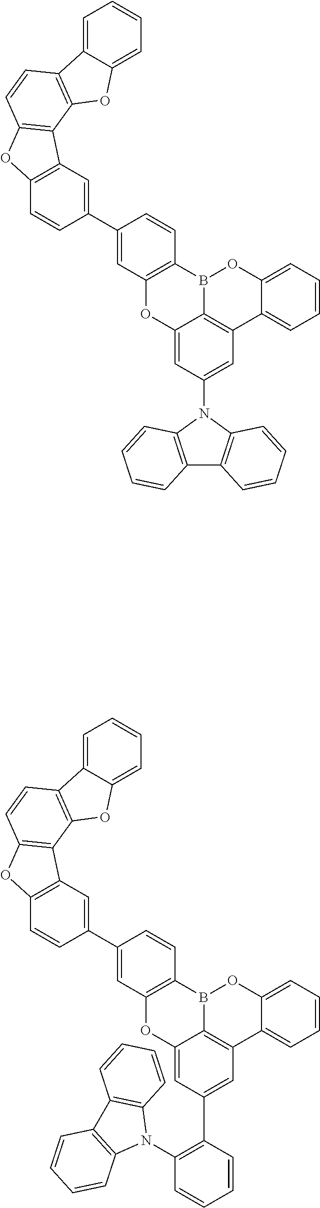 [SMILES: c1ccc2c(c1)OB1c3ccc(-c4ccc5oc6ccc7c8ccccc8oc7c6c5c4)cc3Oc3cc(-n4c5ccccc5c5ccccc54)cc-2c31 ; c1ccc2c(c1)OB1c3ccc(-c4ccc5oc6ccc7c8ccccc8oc7c6c5c4)cc3Oc3cc(-c4ccccc4-n4c5ccccc5c5ccccc54)cc-2c31]

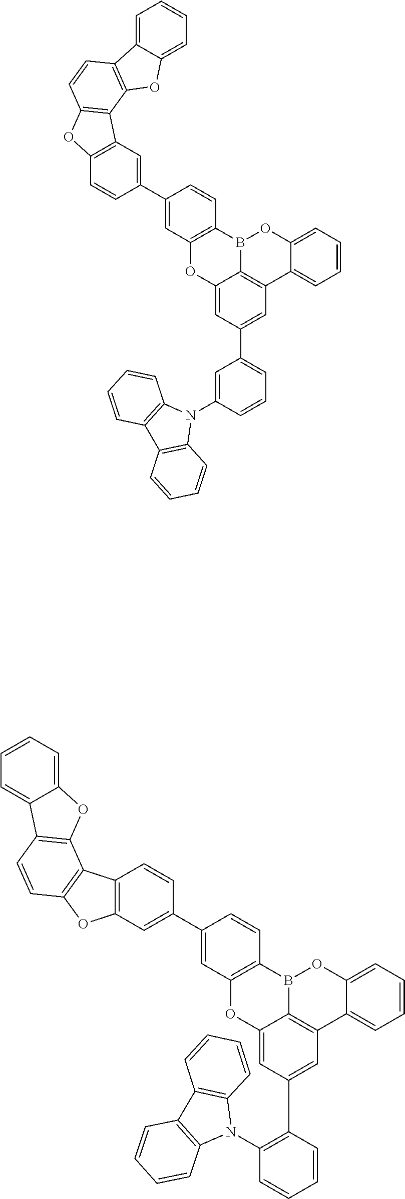 [SMILES: c1cc(-c2cc3c4c(c2)-c2ccccc2OB4c2ccc(-c4ccc5oc6ccc7c8ccccc8oc7c6c5c4)cc2O3)cc(-n2c3ccccc3c3ccccc32)c1 ; c1ccc2c(c1)OB1c3ccc(-c4ccc5c(c4)oc4ccc6c7ccccc7oc6c45)cc3Oc3cc(-c4ccccc4-n4c5ccccc5c5ccccc54)cc-2c31]

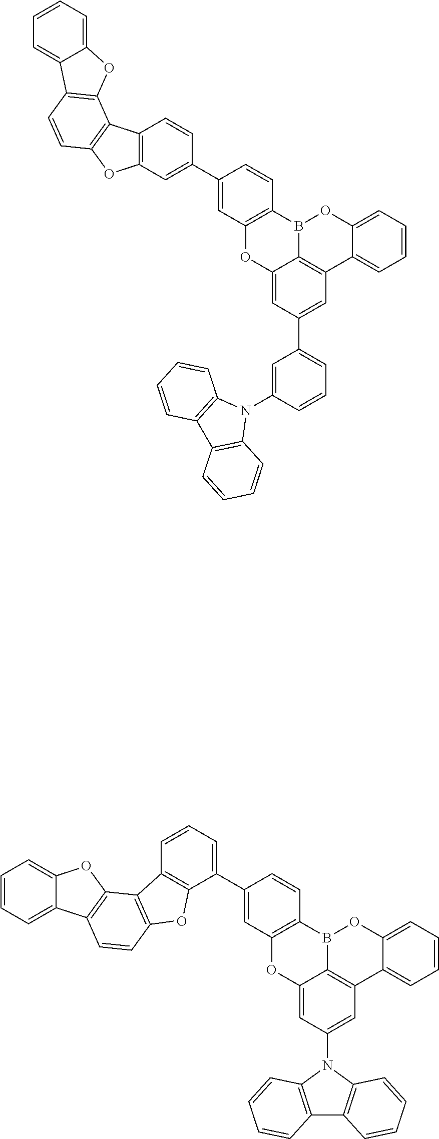 [SMILES: c1cc(-c2cc3c4c(c2)-c2ccccc2OB4c2ccc(-c4ccc5c(c4)oc4ccc6c7ccccc7oc6c45)cc2O3)cc(-n2c3ccccc3c3ccccc32)c1 ; c1ccc2c(c1)OB1c3ccc(-c4cccc5c4oc4ccc6c7ccccc7oc6c45)cc3Oc3cc(-n4c5ccccc5c5ccccc54)cc-2c31]

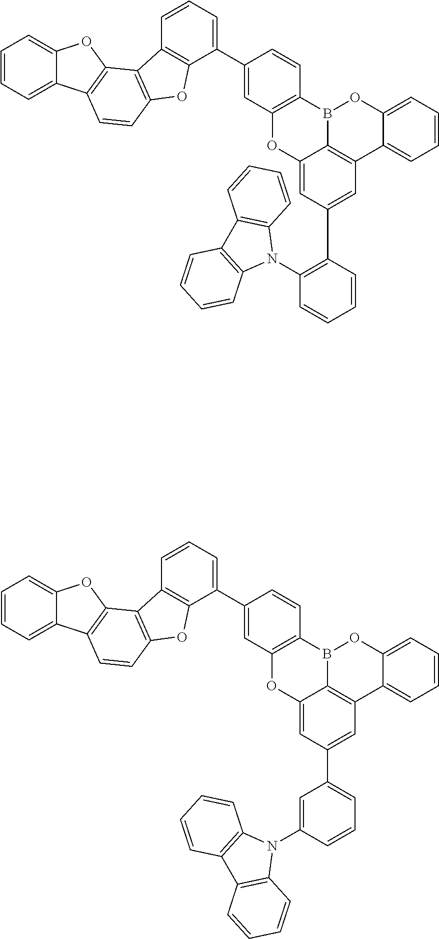 [SMILES: c1ccc2c(c1)OB1c3ccc(-c4cccc5c4oc4ccc6c7ccccc7oc6c45)cc3Oc3cc(-c4ccccc4-n4c5ccccc5c5ccccc54)cc-2c31 ; c1cc(-c2cc3c4c(c2)-c2ccccc2OB4c2ccc(-c4cccc5c4oc4ccc6c7ccccc7oc6c45)cc2O3)cc(-n2c3ccccc3c3ccccc32)c1]

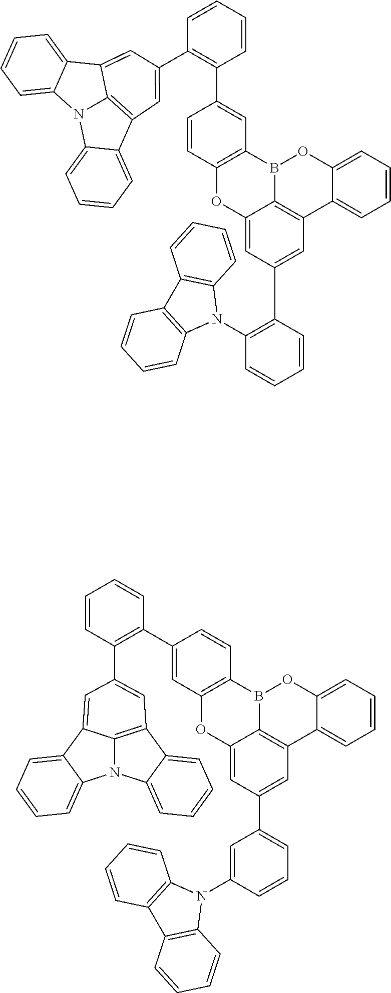 [SMILES: c1ccc2c(c1)OB1c3cc(-c4ccccc4-c4cc5c6ccccc6n6c7ccccc7c(c4)c56)ccc3Oc3cc(-c4ccccc4-n4c5ccccc5c5ccccc54)cc-2c31 ; c1cc(-c2cc3c4c(c2)-c2ccccc2OB4c2ccc(-c4ccccc4-c4cc5c6ccccc6n6c7ccccc7c(c4)c56)cc2O3)cc(-n2c3ccccc3c3ccccc32)c1]

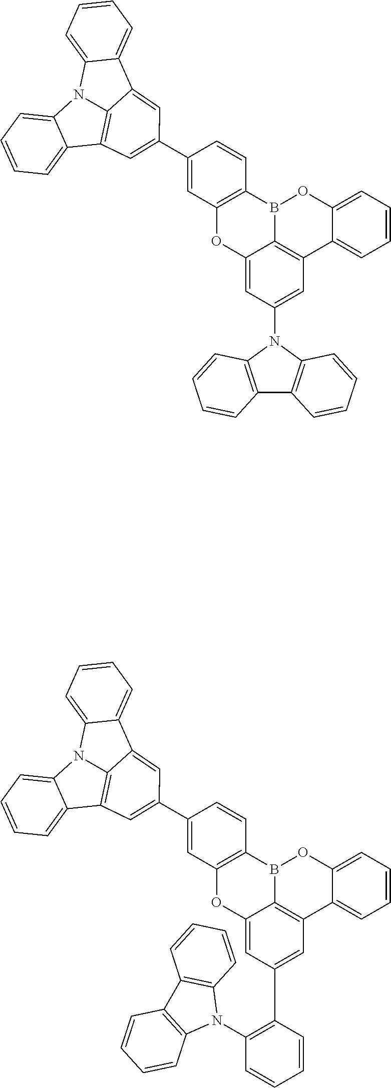 [SMILES: c1ccc2c(c1)OB1c3ccc(-c4cc5c6ccccc6n6c7ccccc7c(c4)c56)cc3Oc3cc(-n4c5ccccc5c5ccccc54)cc-2c31 ; c1ccc2c(c1)OB1c3ccc(-c4cc5c6ccccc6n6c7ccccc7c(c4)c56)cc3Oc3cc(-c4ccccc4-n4c5ccccc5c5ccccc54)cc-2c31]

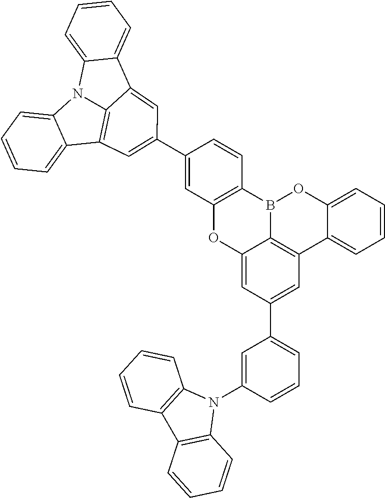 [SMILES: c1cc(-c2cc3c4c(c2)-c2ccccc2OB4c2ccc(-c4cc5c6ccccc6n6c7ccccc7c(c4)c56)cc2O3)cc(-n2c3ccccc3c3ccccc32)c1]

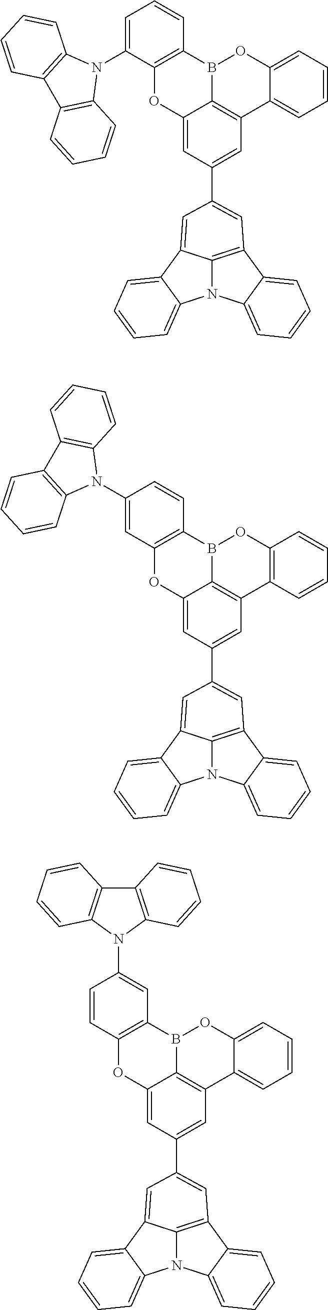 [SMILES: c1ccc2c(c1)OB1c3cccc(-n4c5ccccc5c5ccccc54)c3Oc3cc(-c4cc5c6ccccc6n6c7ccccc7c(c4)c56)cc-2c31 ; c1ccc2c(c1)OB1c3ccc(-n4c5ccccc5c5ccccc54)cc3Oc3cc(-c4cc5c6ccccc6n6c7ccccc7c(c4)c56)cc-2c31 ; c1ccc2c(c1)OB1c3cc(-n4c5ccccc5c5ccccc54)ccc3Oc3cc(-c4cc5c6ccccc6n6c7ccccc7c(c4)c56)cc-2c31]

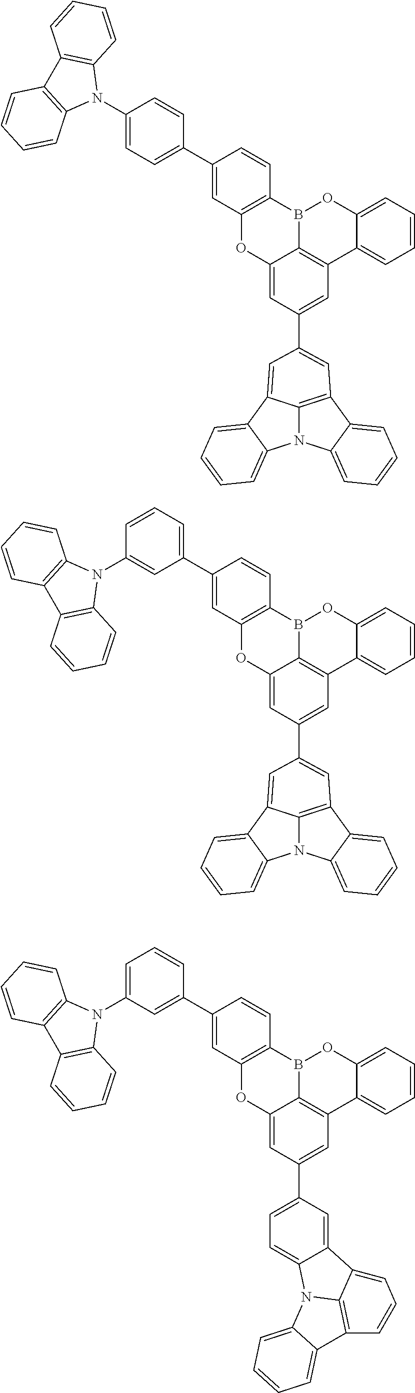 [SMILES: c1ccc2c(c1)OB1c3ccc(-c4ccc(-n5c6ccccc6c6ccccc65)cc4)cc3Oc3cc(-c4cc5c6ccccc6n6c7ccccc7c(c4)c56)cc-2c31 ; c1cc(-c2ccc3c(c2)Oc2cc(-c4cc5c6ccccc6n6c7ccccc7c(c4)c56)cc4c2B3Oc2ccccc2-4)cc(-n2c3ccccc3c3ccccc32)c1 ; c1cc(-c2ccc3c(c2)Oc2cc(-c4ccc5c(c4)c4cccc6c7ccccc7n5c64)cc4c2B3Oc2ccccc2-4)cc(-n2c3ccccc3c3ccccc32)c1]

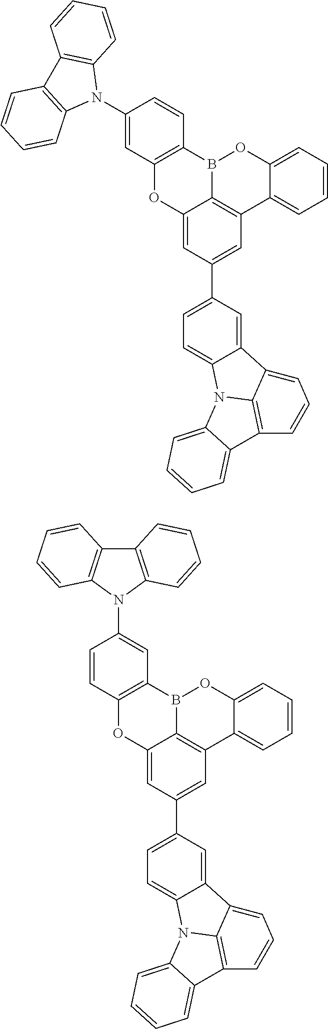

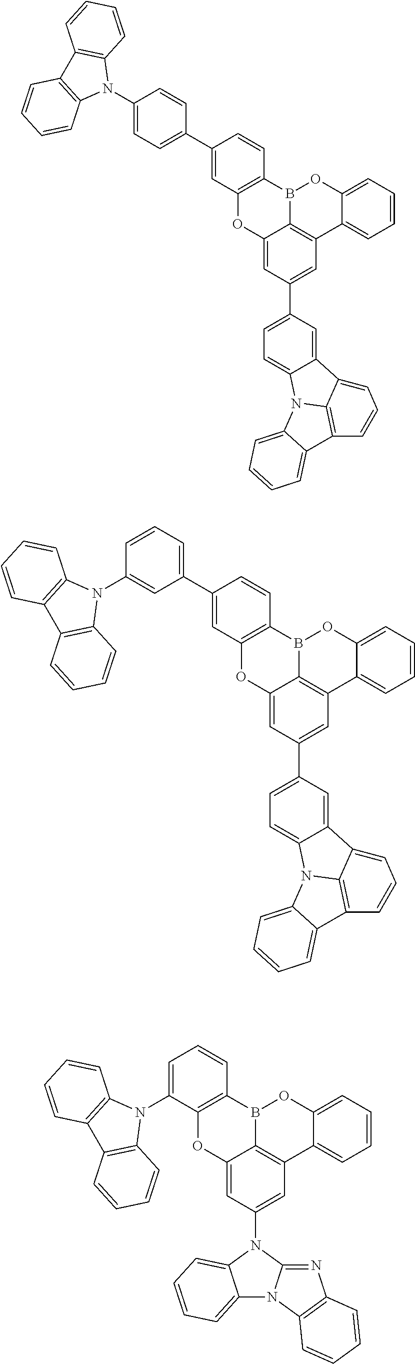 [SMILES: c1ccc2c(c1)OB1c3ccc(-c4ccc(-n5c6ccccc6c6ccccc65)cc4)cc3Oc3cc(-c4ccc5c(c4)c4cccc6c7ccccc7n5c64)cc-2c31 ; c1cc(-c2ccc3c(c2)Oc2cc(-c4ccc5c(c4)c4cccc6c7ccccc7n5c64)cc4c2B3Oc2ccccc2-4)cc(-n2c3ccccc3c3ccccc32)c1 ; c1ccc2c(c1)OB1c3cccc(-n4c5ccccc5c5ccccc54)c3Oc3cc(-n4c5ccccc5n5c6ccccc6nc45)cc-2c31]

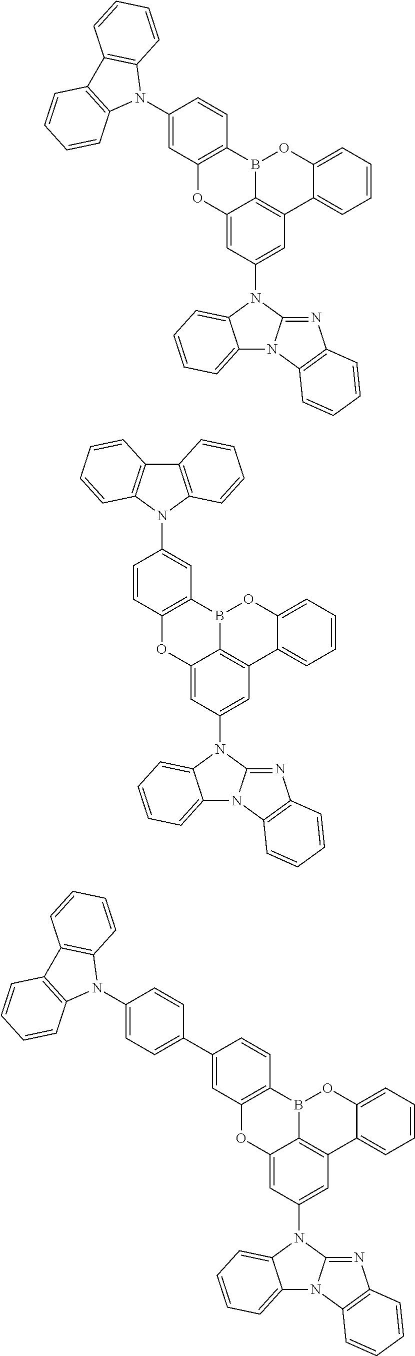 [SMILES: c1ccc2c(c1)OB1c3ccc(-n4c5ccccc5c5ccccc54)cc3Oc3cc(-n4c5ccccc5n5c6ccccc6nc45)cc-2c31 ; c1ccc2c(c1)OB1c3cc(-n4c5ccccc5c5ccccc54)ccc3Oc3cc(-n4c5ccccc5n5c6ccccc6nc45)cc-2c31 ; c1ccc2c(c1)OB1c3ccc(-c4ccc(-n5c6ccccc6c6ccccc65)cc4)cc3Oc3cc(-n4c5ccccc5n5c6ccccc6nc45)cc-2c31]

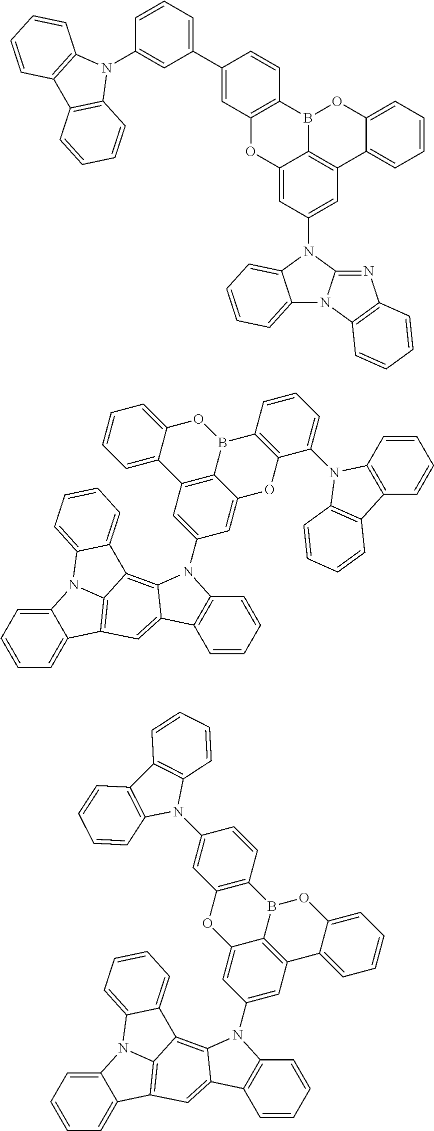 [SMILES: c1cc(-c2ccc3c(c2)Oc2cc(-n4c5ccccc5n5c6ccccc6nc45)cc4c2B3Oc2ccccc2-4)cc(-n2c3ccccc3c3ccccc32)c1 ; c1ccc2c(c1)OB1c3cccc(-n4c5ccccc5c5ccccc54)c3Oc3cc(-n4c5ccccc5c5cc6c7ccccc7n7c8ccccc8c(c54)c67)cc-2c31 ; c1ccc2c(c1)OB1c3ccc(-n4c5ccccc5c5ccccc54)cc3Oc3cc(-n4c5ccccc5c5cc6c7ccccc7n7c8ccccc8c(c54)c67)cc-2c31]

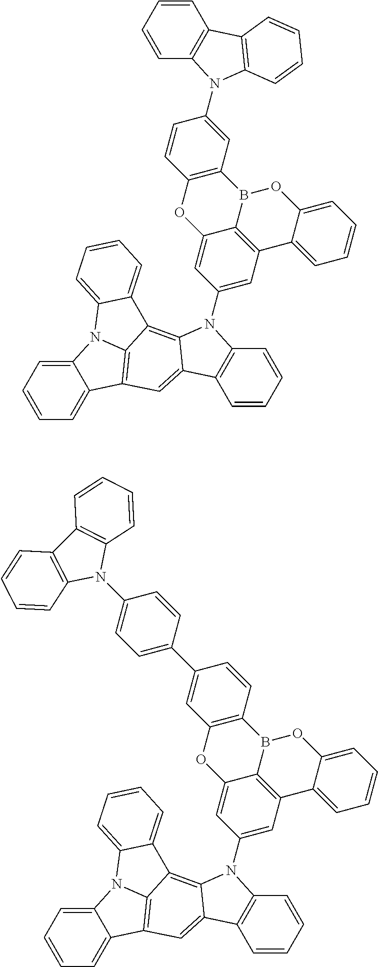 [SMILES: c1ccc2c(c1)OB1c3cc(-n4c5ccccc5c5ccccc54)ccc3Oc3cc(-n4c5ccccc5c5cc6c7ccccc7n7c8ccccc8c(c54)c67)cc-2c31 ; c1ccc2c(c1)OB1c3ccc(-c4ccc(-n5c6ccccc6c6ccccc65)cc4)cc3Oc3cc(-n4c5ccccc5c5cc6c7ccccc7n7c8ccccc8c(c54)c67)cc-2c31]

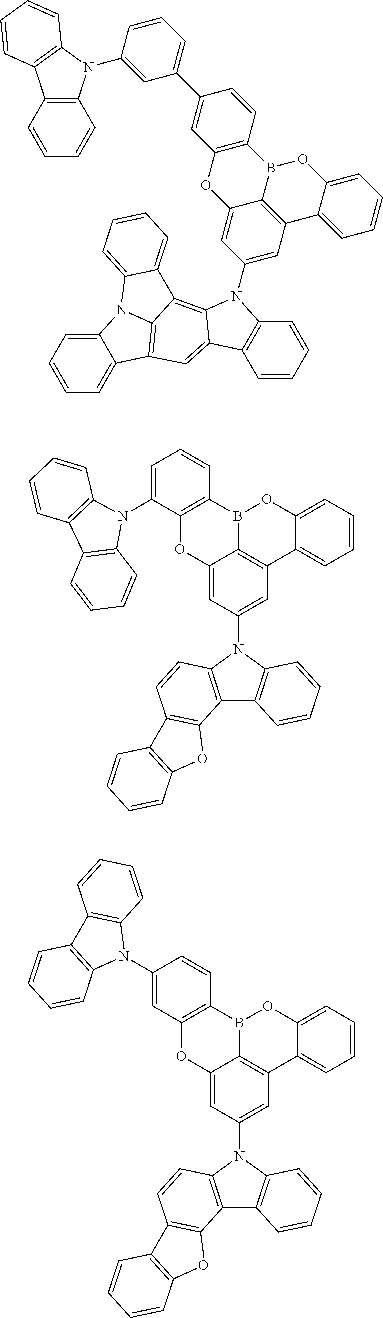 [SMILES: c1cc(-c2ccc3c(c2)Oc2cc(-n4c5ccccc5c5cc6c7ccccc7n7c8ccccc8c(c54)c67)cc4c2B3Oc2ccccc2-4)cc(-n2c3ccccc3c3ccccc32)c1 ; c1ccc2c(c1)OB1c3cccc(-n4c5ccccc5c5ccccc54)c3Oc3cc(-n4c5ccccc5c5c6oc7ccccc7c6ccc54)cc-2c31 ; c1ccc2c(c1)OB1c3ccc(-n4c5ccccc5c5ccccc54)cc3Oc3cc(-n4c5ccccc5c5c6oc7ccccc7c6ccc54)cc-2c31]

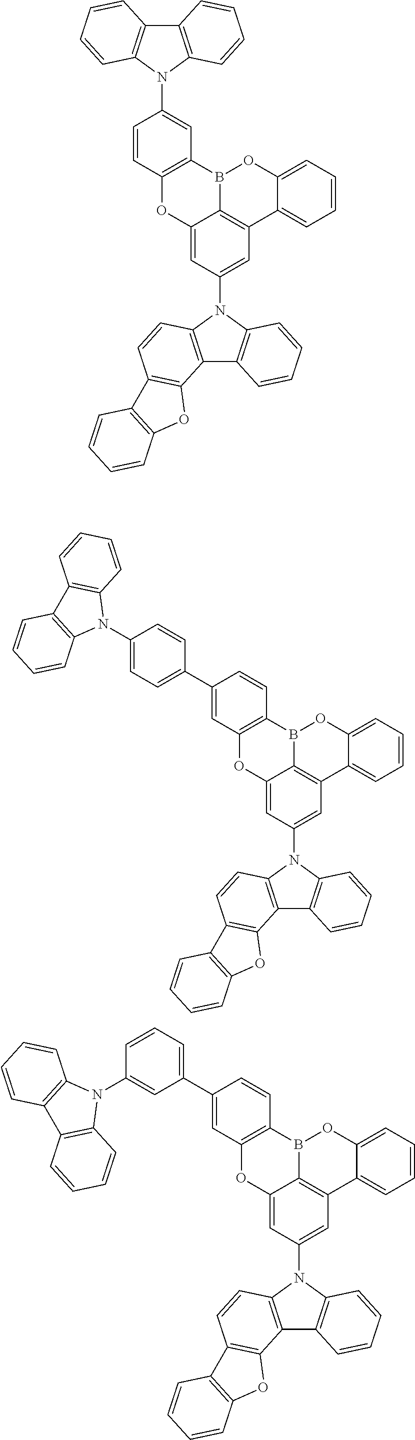

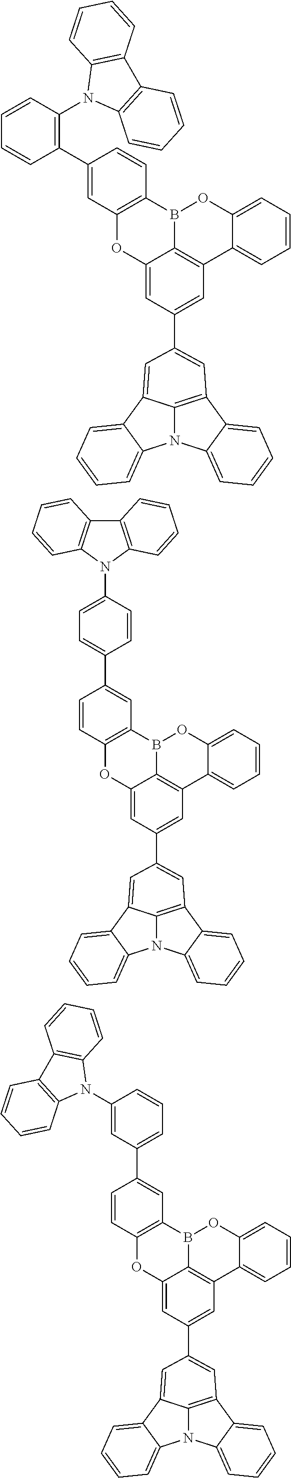

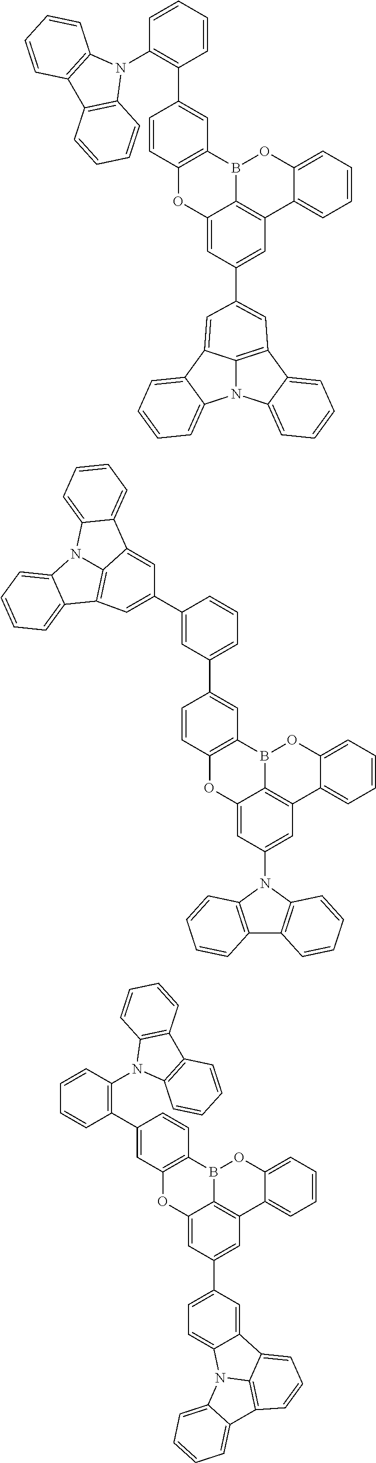 [SMILES: c1ccc2c(c1)OB1c3cc(-c4ccccc4-n4c5ccccc5c5ccccc54)ccc3Oc3cc(-c4cc5c6ccccc6n6c7ccccc7c(c4)c56)cc-2c31 ; c1cc(-c2ccc3c(c2)B2Oc4ccccc4-c4cc(-n5c6ccccc6c6ccccc65)cc(c42)O3)cc(-c2cc3c4ccccc4n4c5ccccc5c(c2)c34)c1 ; c1ccc2c(c1)OB1c3ccc(-c4ccccc4-n4c5ccccc5c5ccccc54)cc3Oc3cc(-c4ccc5c(c4)c4cccc6c7ccccc7n5c64)cc-2c31]

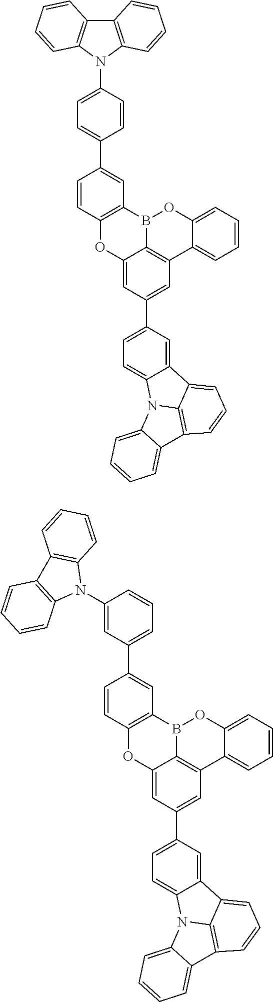 [SMILES: c1ccc2c(c1)OB1c3cc(-c4ccc(-n5c6ccccc6c6ccccc65)cc4)ccc3Oc3cc(-c4ccc5c(c4)c4cccc6c7ccccc7n5c64)cc-2c31 ; c1cc(-c2ccc3c(c2)B2Oc4ccccc4-c4cc(-c5ccc6c(c5)c5cccc7c8ccccc8n6c75)cc(c42)O3)cc(-n2c3ccccc3c3ccccc32)c1]

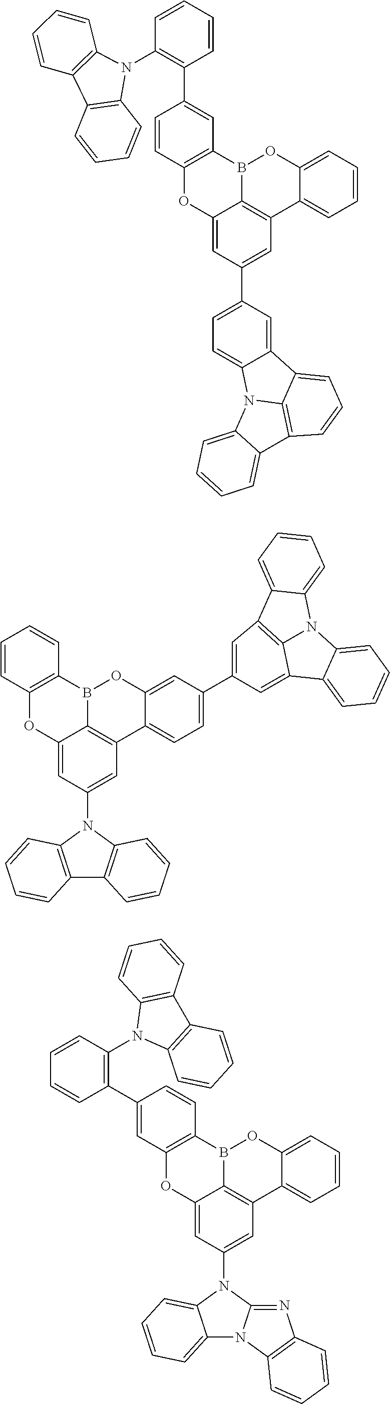

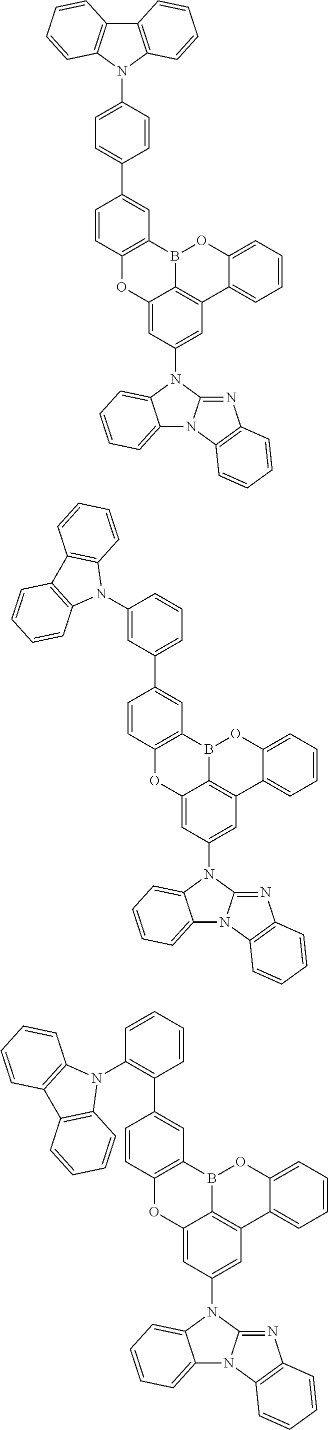 [SMILES: c1ccc2c(c1)OB1c3cc(-c4ccc(-n5c6ccccc6c6ccccc65)cc4)ccc3Oc3cc(-n4c5ccccc5n5c6ccccc6nc45)cc-2c31 ; c1cc(-c2ccc3c(c2)B2Oc4ccccc4-c4cc(-n5c6ccccc6n6c7ccccc7nc56)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-n4c5ccccc5n5c6ccccc6nc45)cc-2c31]

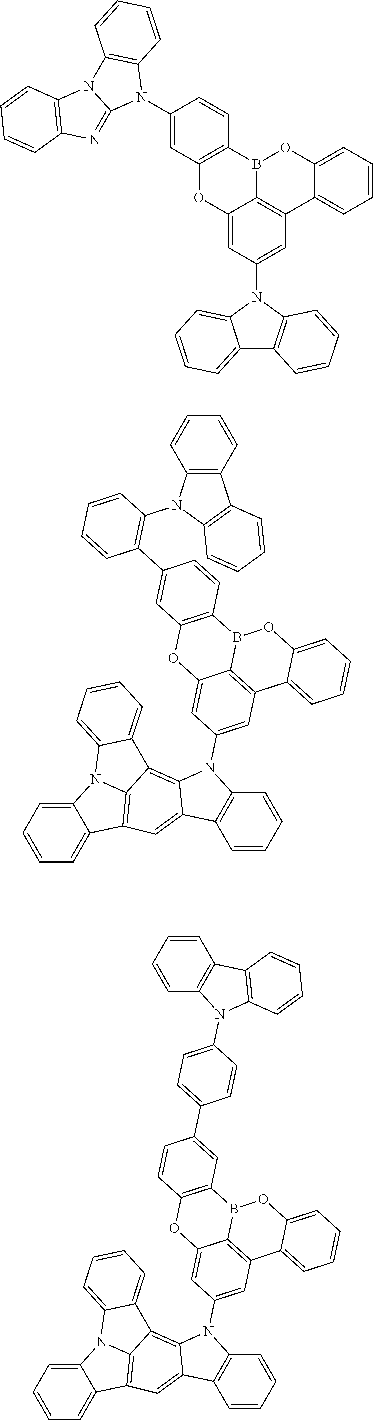

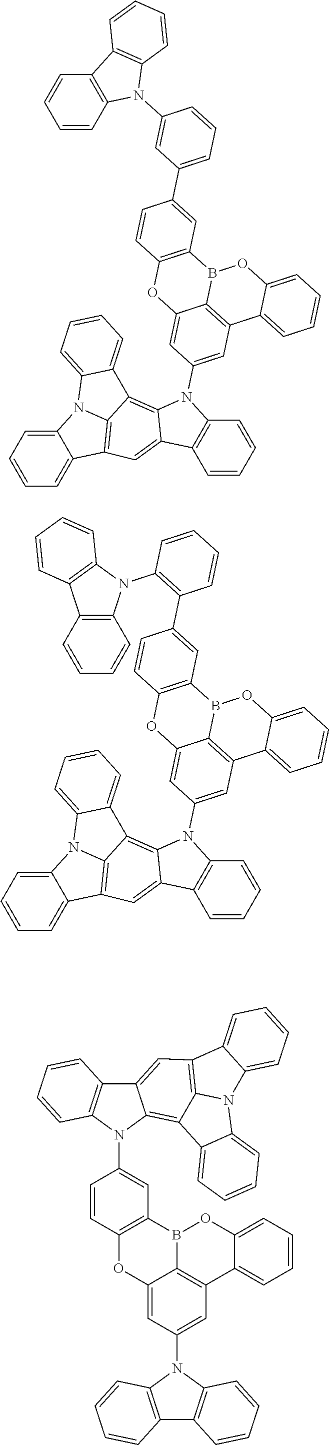

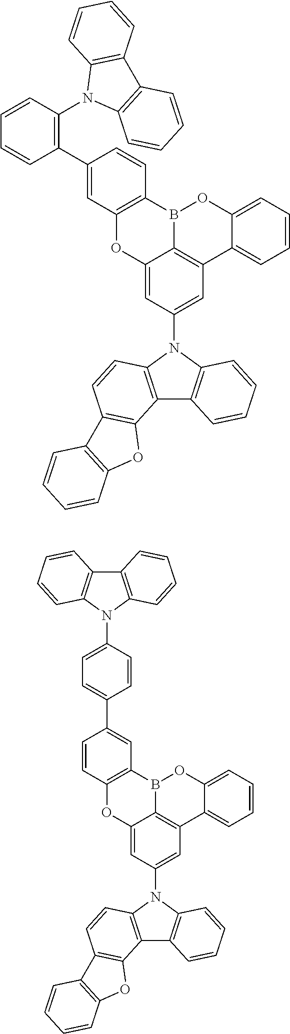

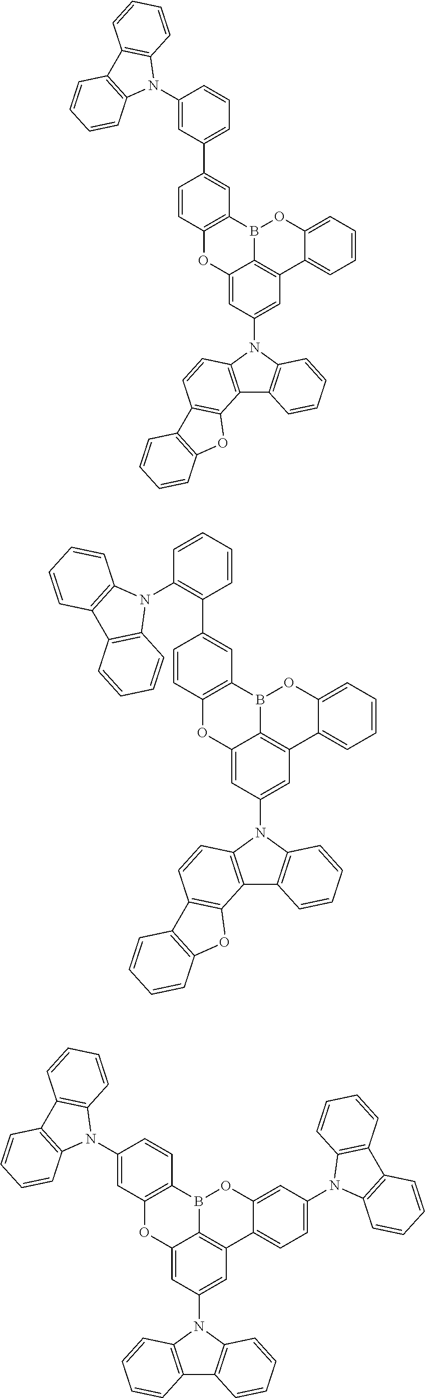 [SMILES: c1cc(-c2ccc3c(c2)B2Oc4ccccc4-c4cc(-n5c6ccccc6c6c7oc8ccccc8c7ccc65)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-n4c5ccccc5c5c6oc7ccccc7c6ccc54)cc-2c31 ; c1ccc2c(c1)c1ccccc1n2-c1ccc2c(c1)Oc1cc(-n3c4ccccc4c4ccccc43)cc3c1B2Oc1cc(-n2c4ccccc4c4ccccc42)ccc1-3]

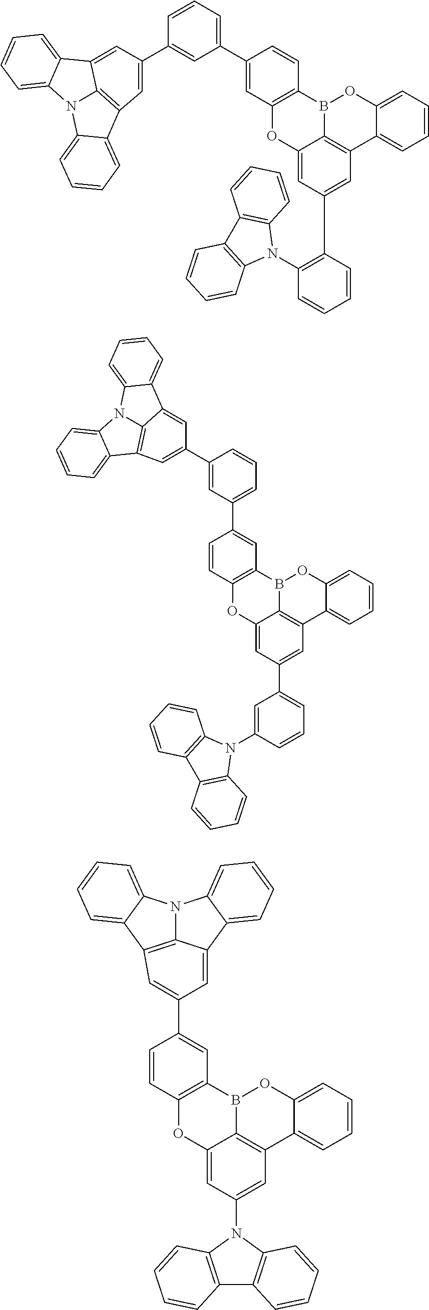

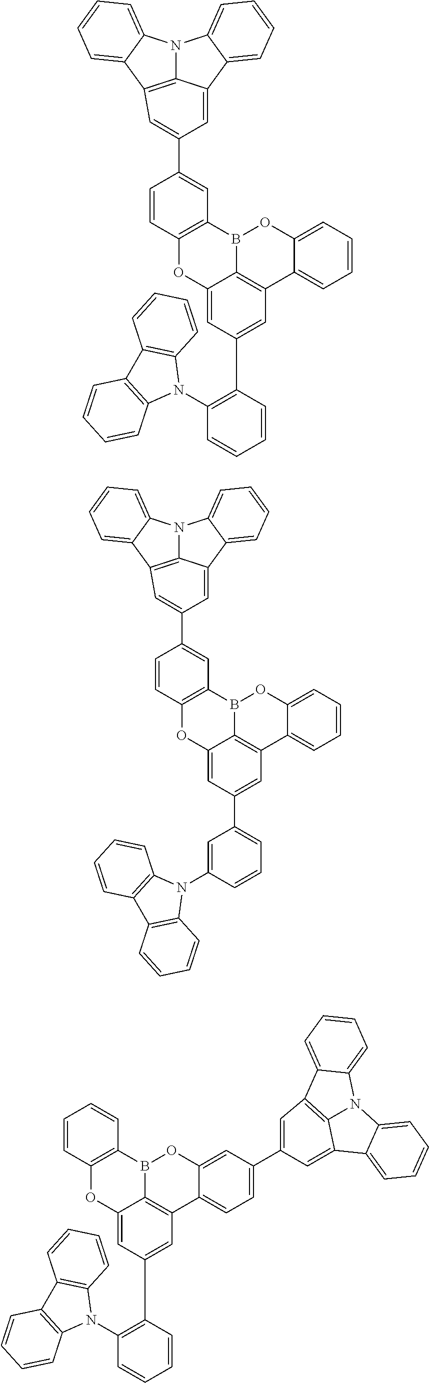

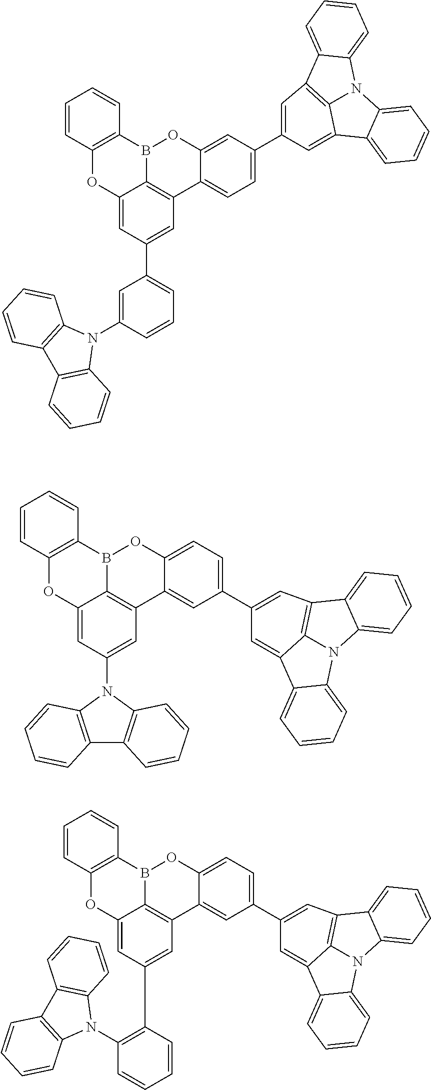 [SMILES: c1cc(-c2cc3c4c(c2)-c2ccc(-c5cc6c7ccccc7n7c8ccccc8c(c5)c67)cc2OB4c2ccccc2O3)cc(-n2c3ccccc3c3ccccc32)c1 ; c1ccc2c(c1)Oc1cc(-n3c4ccccc4c4ccccc43)cc3c1B2Oc1ccc(-c2cc4c5ccccc5n5c6ccccc6c(c2)c45)cc1-3 ; c1ccc2c(c1)Oc1cc(-c3ccccc3-n3c4ccccc4c4ccccc43)cc3c1B2Oc1ccc(-c2cc4c5ccccc5n5c6ccccc6c(c2)c45)cc1-3]

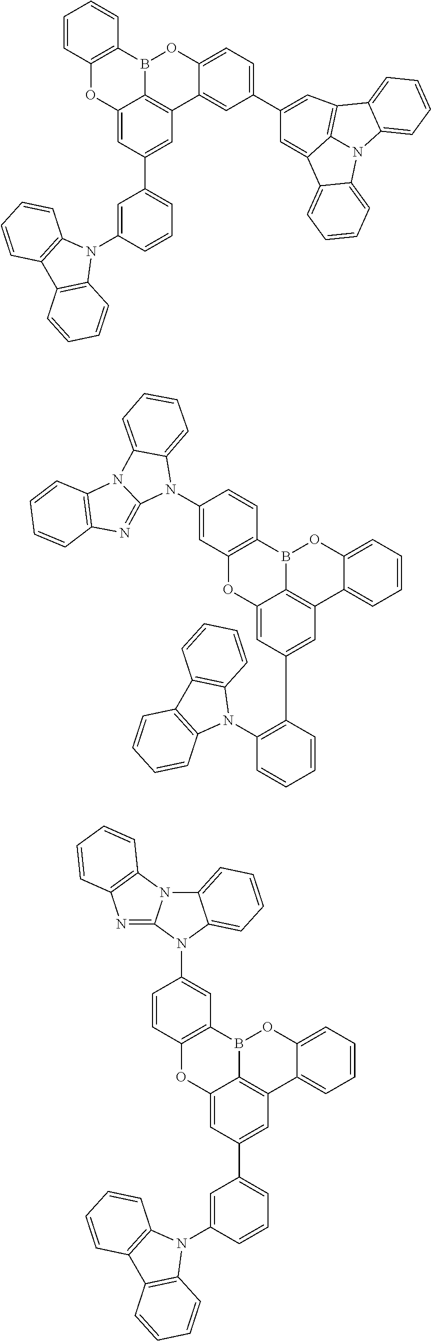 [SMILES: c1cc(-c2cc3c4c(c2)-c2cc(-c5cc6c7ccccc7n7c8ccccc8c(c5)c67)ccc2OB4c2ccccc2O3)cc(-n2c3ccccc3c3ccccc32)c1 ; c1ccc2c(c1)OB1c3ccc(-n4c5ccccc5n5c6ccccc6nc45)cc3Oc3cc(-c4ccccc4-n4c5ccccc5c5ccccc54)cc-2c31 ; c1cc(-c2cc3c4c(c2)-c2ccccc2OB4c2cc(-n4c5ccccc5n5c6ccccc6nc45)ccc2O3)cc(-n2c3ccccc3c3ccccc32)c1]

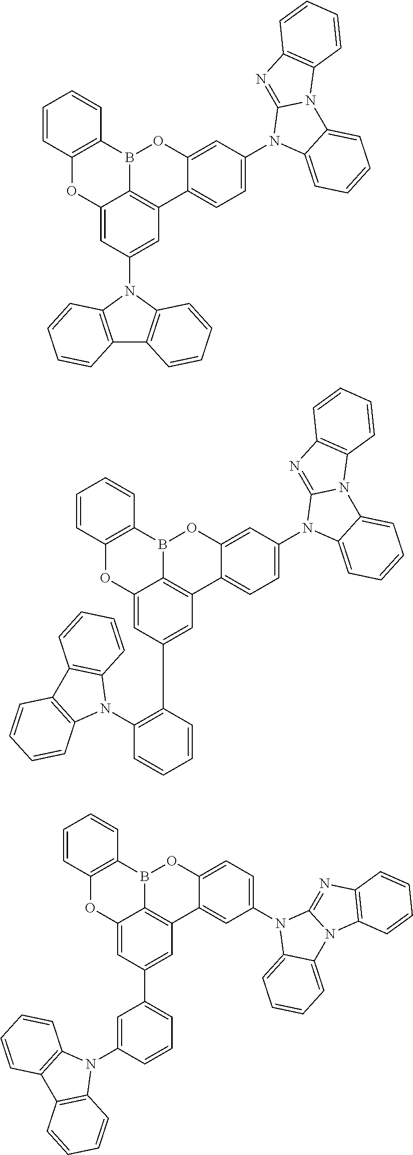 [SMILES: c1ccc2c(c1)Oc1cc(-n3c4ccccc4c4ccccc43)cc3c1B2Oc1cc(-n2c4ccccc4n4c5ccccc5nc24)ccc1-3 ; c1ccc2c(c1)Oc1cc(-c3ccccc3-n3c4ccccc4c4ccccc43)cc3c1B2Oc1cc(-n2c4ccccc4n4c5ccccc5nc24)ccc1-3 ; c1cc(-c2cc3c4c(c2)-c2cc(-n5c6ccccc6n6c7ccccc7nc56)ccc2OB4c2ccccc2O3)cc(-n2c3ccccc3c3ccccc32)c1]

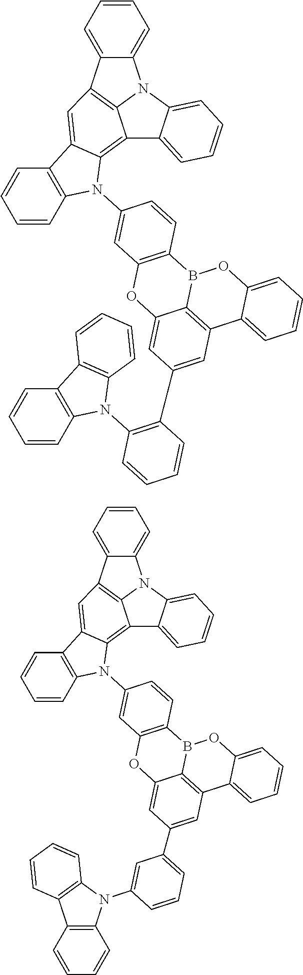

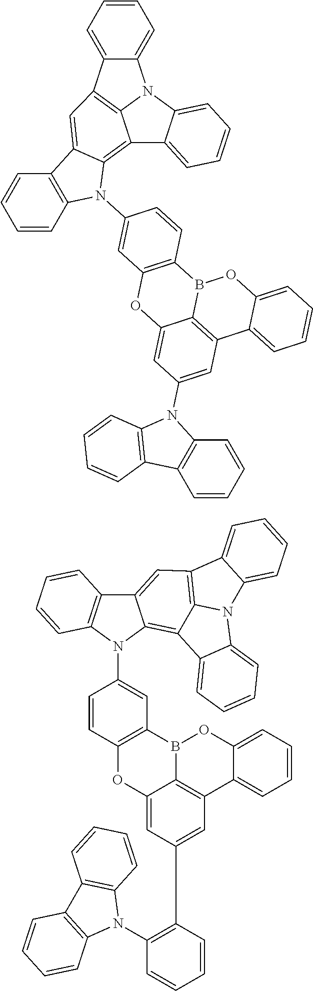

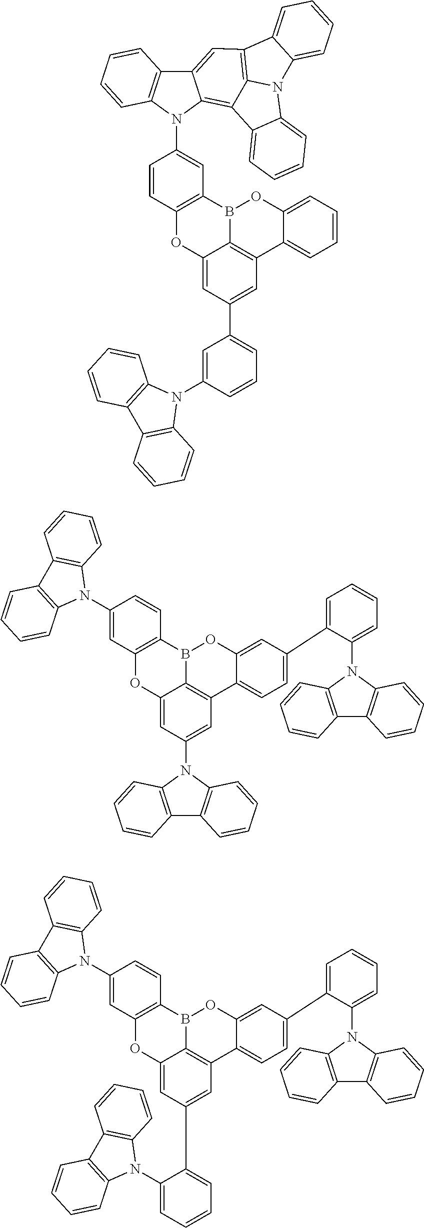 [SMILES: c1cc(-c2cc3c4c(c2)-c2ccccc2OB4c2cc(-n4c5ccccc5c5cc6c7ccccc7n7c8ccccc8c(c54)c67)ccc2O3)cc(-n2c3ccccc3c3ccccc32)c1 ; c1ccc(-n2c3ccccc3c3ccccc32)c(-c2ccc3c(c2)OB2c4ccc(-n5c6ccccc6c6ccccc65)cc4Oc4cc(-n5c6ccccc6c6ccccc65)cc-3c42)c1 ; c1ccc(-n2c3ccccc3c3ccccc32)c(-c2ccc3c(c2)OB2c4ccc(-n5c6ccccc6c6ccccc65)cc4Oc4cc(-c5ccccc5-n5c6ccccc6c6ccccc65)cc-3c42)c1]

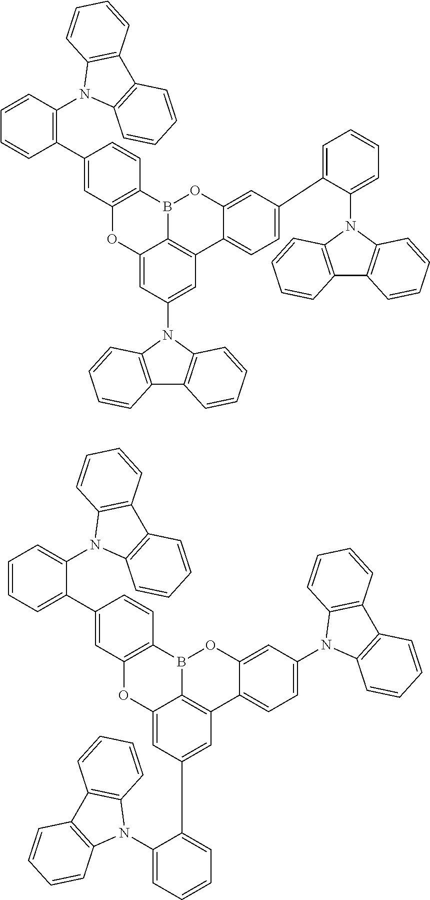

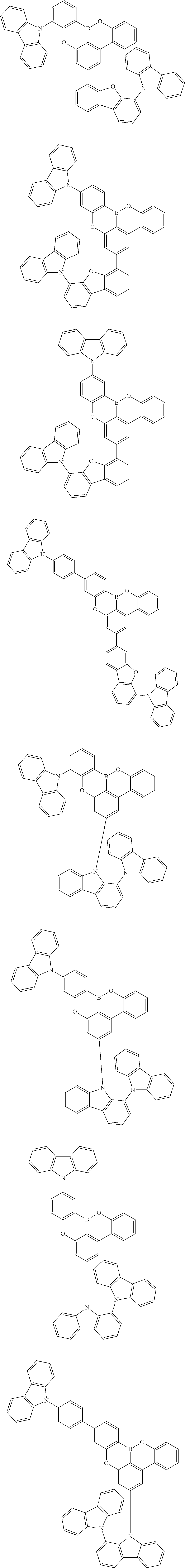

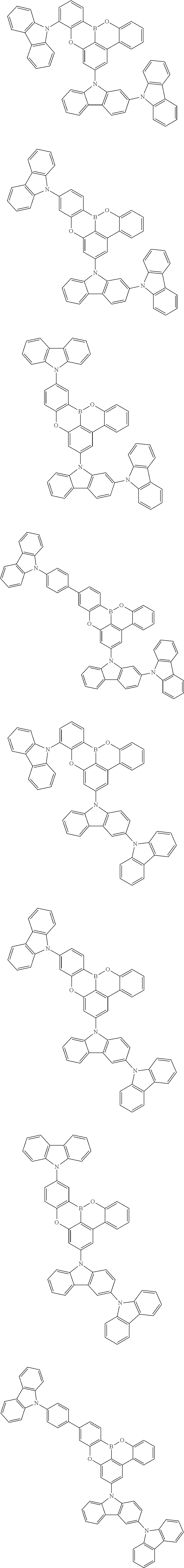

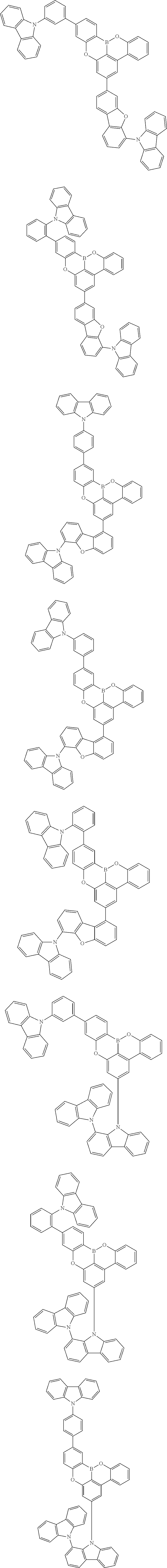

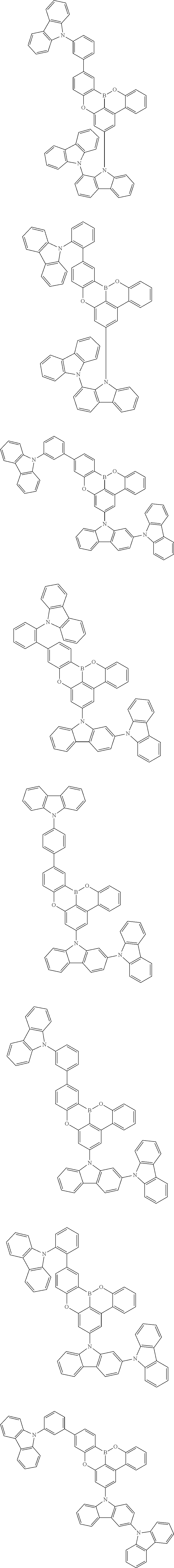

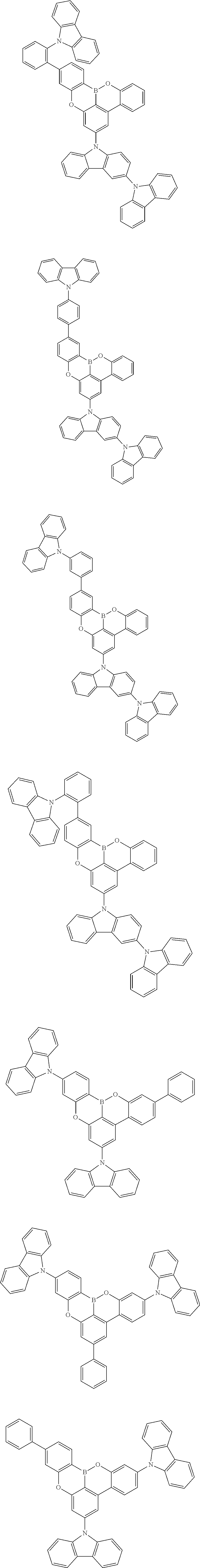

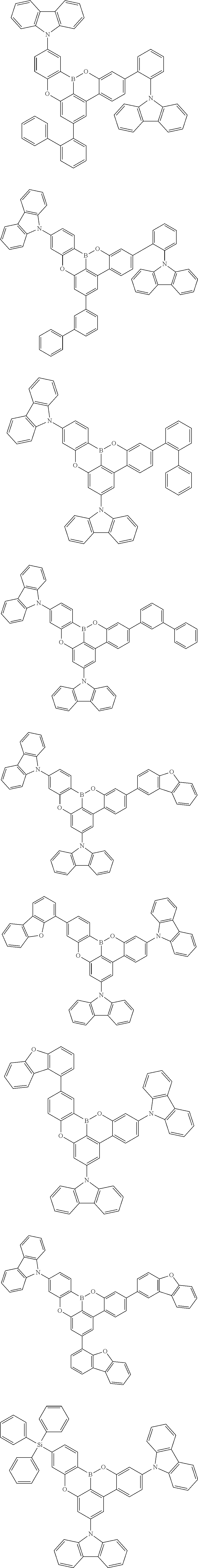

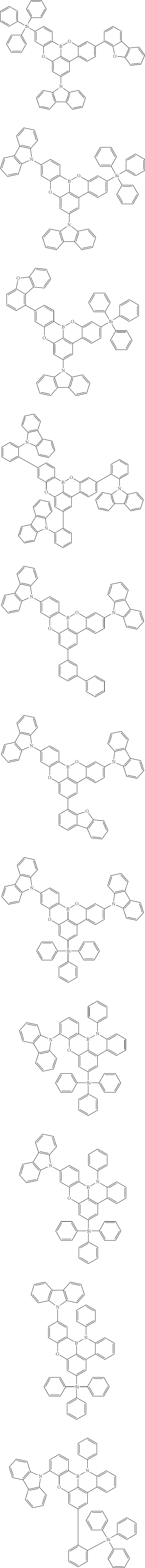

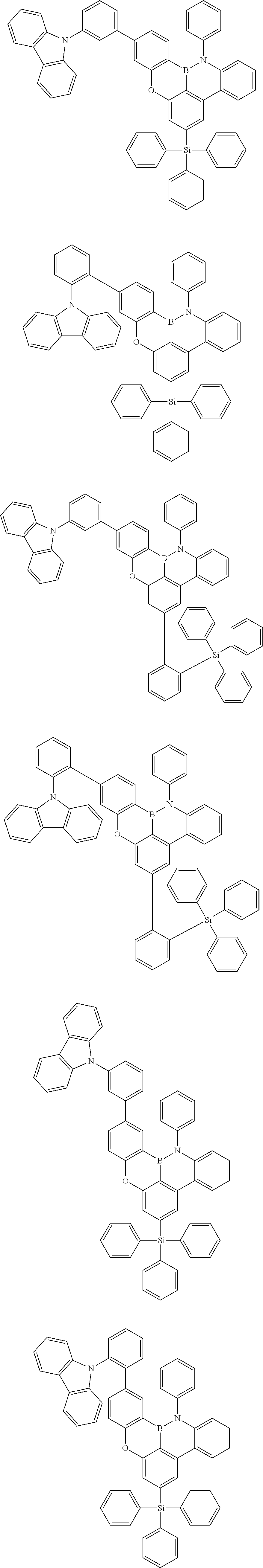

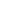

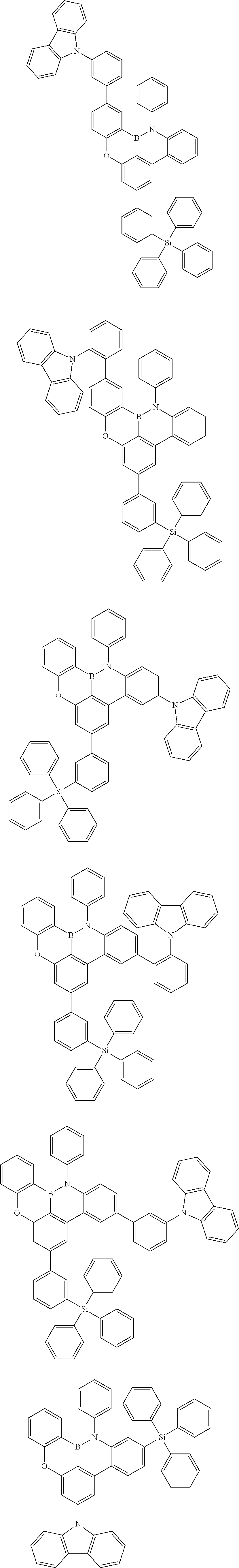

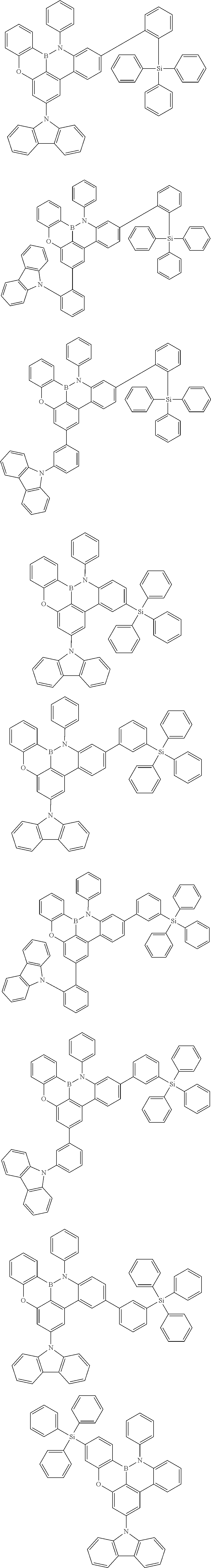

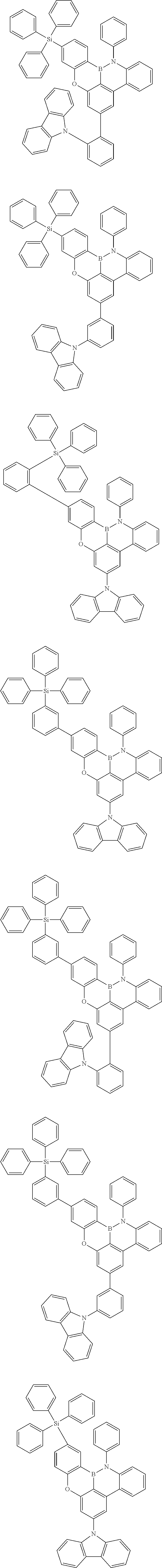

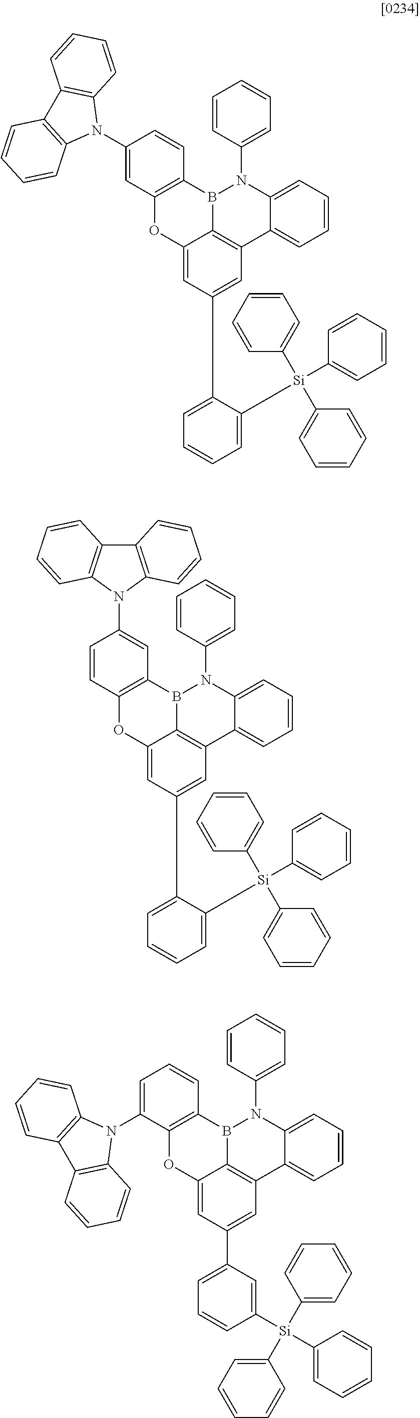 [SMILES: c1ccc(N2B3c4ccc(-n5c6ccccc6c6ccccc65)cc4Oc4cc(-c5ccccc5[Si](c5ccccc5)(c5ccccc5)c5ccccc5)cc(c43)-c3ccccc32)cc1 ; c1ccc(N2B3c4cc(-n5c6ccccc6c6ccccc65)ccc4Oc4cc(-c5ccccc5[Si](c5ccccc5)(c5ccccc5)c5ccccc5)cc(c43)-c3ccccc32)cc1 ; c1ccc(N2B3c4cccc(-n5c6ccccc6c6ccccc65)c4Oc4cc(-c5cccc([Si](c6ccccc6)(c6ccccc6)c6ccccc6)c5)cc(c43)-c3ccccc32)cc1]

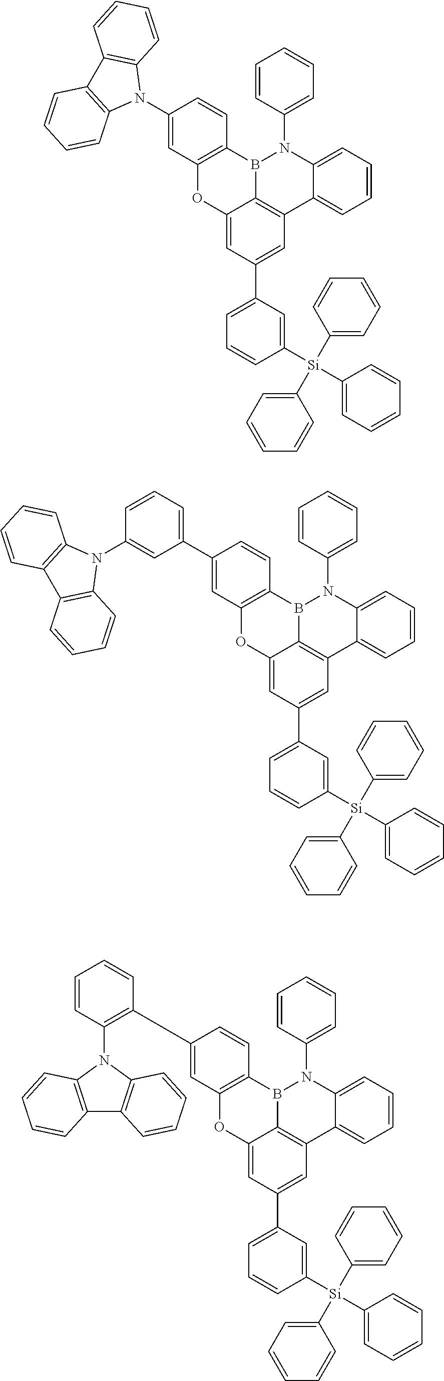 [SMILES: c1ccc(N2B3c4ccc(-n5c6ccccc6c6ccccc65)cc4Oc4cc(-c5cccc([Si](c6ccccc6)(c6ccccc6)c6ccccc6)c5)cc(c43)-c3ccccc32)cc1 ; c1ccc(N2B3c4ccc(-c5cccc(-n6c7ccccc7c7ccccc76)c5)cc4Oc4cc(-c5cccc([Si](c6ccccc6)(c6ccccc6)c6ccccc6)c5)cc(c43)-c3ccccc32)cc1 ; c1ccc(N2B3c4ccc(-c5ccccc5-n5c6ccccc6c6ccccc65)cc4Oc4cc(-c5cccc([Si](c6ccccc6)(c6ccccc6)c6ccccc6)c5)cc(c43)-c3ccccc32)cc1]

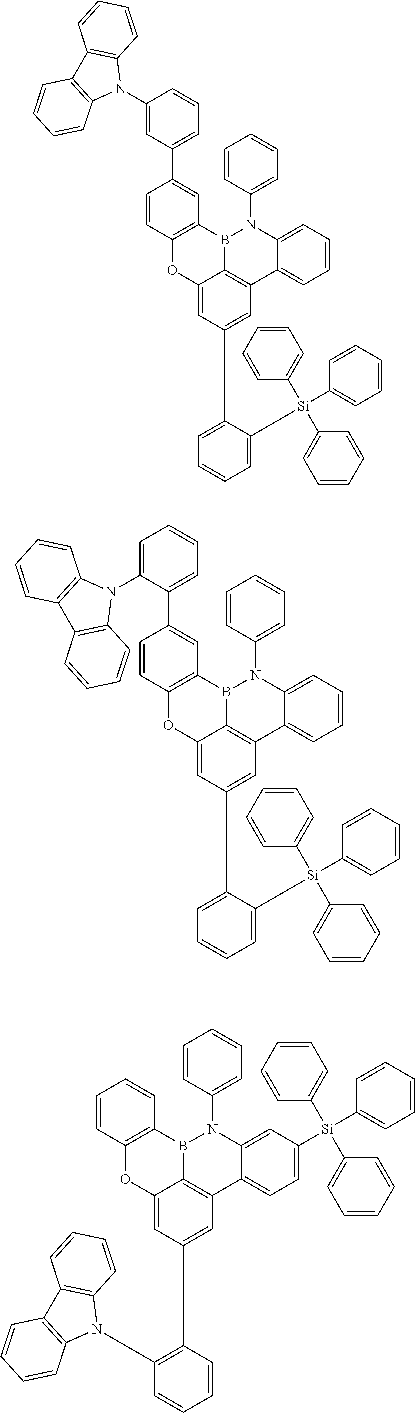 [SMILES: c1ccc(N2B3c4cc(-c5cccc(-n6c7ccccc7c7ccccc76)c5)ccc4Oc4cc(-c5ccccc5[Si](c5ccccc5)(c5ccccc5)c5ccccc5)cc(c43)-c3ccccc32)cc1 ; c1ccc(N2B3c4cc(-c5ccccc5-n5c6ccccc6c6ccccc65)ccc4Oc4cc(-c5ccccc5[Si](c5ccccc5)(c5ccccc5)c5ccccc5)cc(c43)-c3ccccc32)cc1 ; c1ccc(N2B3c4ccccc4Oc4cc(-c5ccccc5-n5c6ccccc6c6ccccc65)cc(c43)-c3ccc([Si](c4ccccc4)(c4ccccc4)c4ccccc4)cc32)cc1]

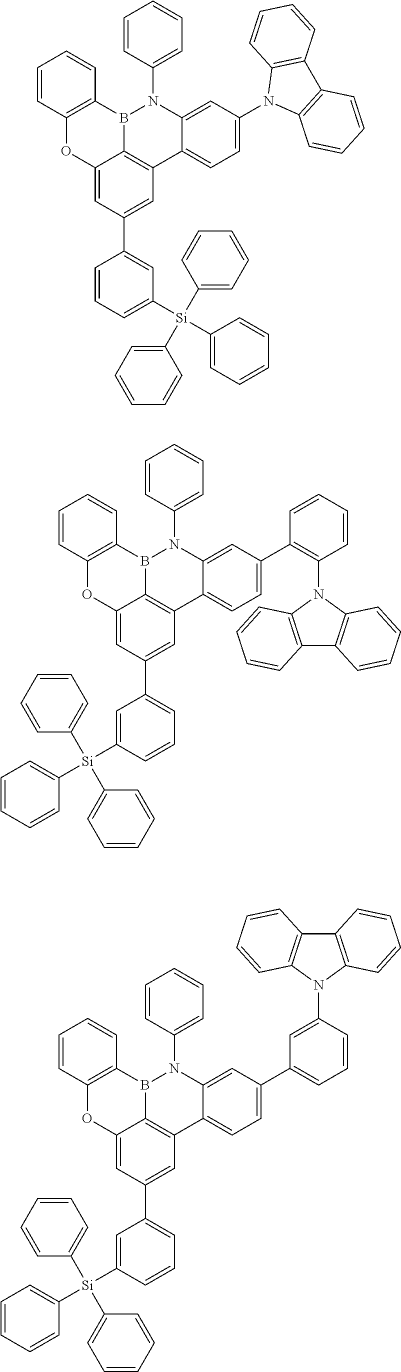

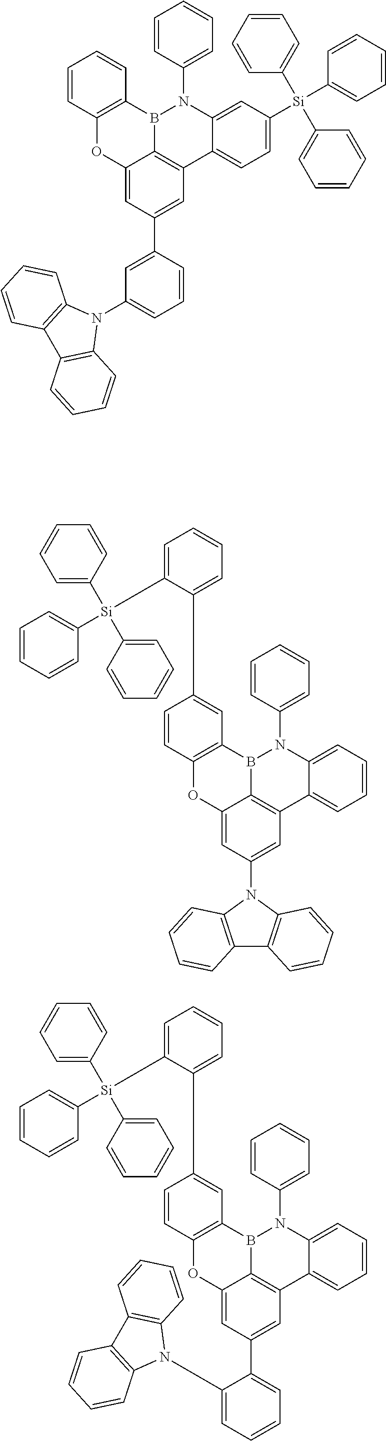

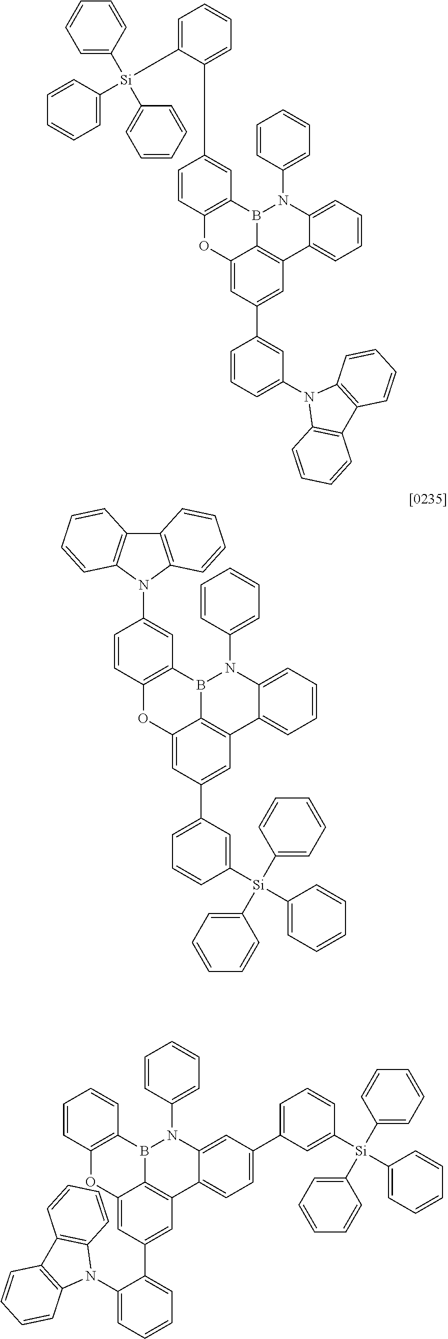 [SMILES: c1ccc(N2B3c4cc(-c5ccccc5[Si](c5ccccc5)(c5ccccc5)c5ccccc5)ccc4Oc4cc(-c5cccc(-n6c7ccccc7c7ccccc76)c5)cc(c43)-c3ccccc32)cc1 ; c1ccc(N2B3c4cc(-n5c6ccccc6c6ccccc65)ccc4Oc4cc(-c5cccc([Si](c6ccccc6)(c6ccccc6)c6ccccc6)c5)cc(c43)-c3ccccc32)cc1 ; c1ccc(N2B3c4ccccc4Oc4cc(-c5ccccc5-n5c6ccccc6c6ccccc65)cc(c43)-c3ccc(-c4cccc([Si](c5ccccc5)(c5ccccc5)c5ccccc5)c4)cc32)cc1]

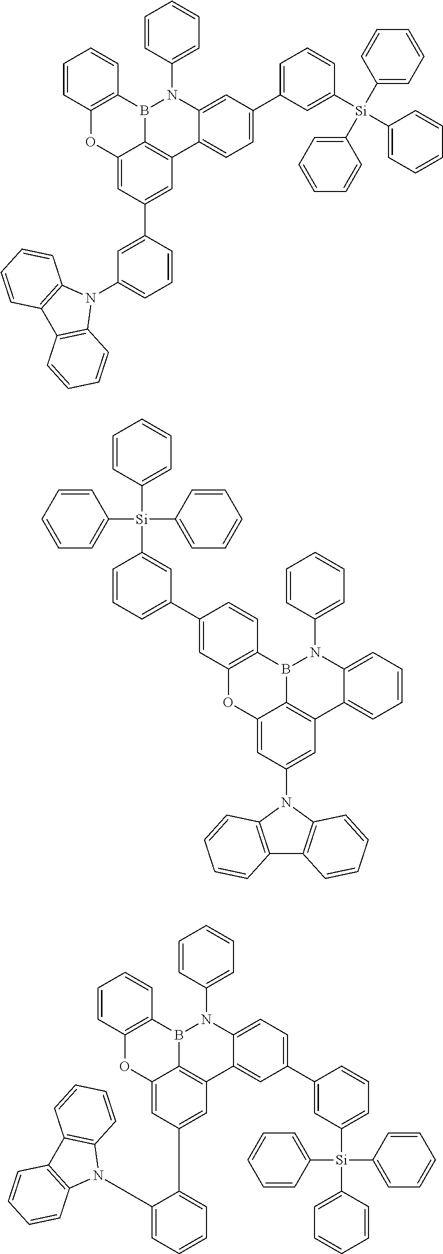 [SMILES: c1ccc(N2B3c4ccccc4Oc4cc(-c5cccc(-n6c7ccccc7c7ccccc76)c5)cc(c43)-c3ccc(-c4cccc([Si](c5ccccc5)(c5ccccc5)c5ccccc5)c4)cc32)cc1 ; c1ccc(N2B3c4ccc(-c5cccc([Si](c6ccccc6)(c6ccccc6)c6ccccc6)c5)cc4Oc4cc(-n5c6ccccc6c6ccccc65)cc(c43)-c3ccccc32)cc1 ; c1ccc(N2B3c4ccccc4Oc4cc(-c5ccccc5-n5c6ccccc6c6ccccc65)cc(c43)-c3cc(-c4cccc([Si](c5ccccc5)(c5ccccc5)c5ccccc5)c4)ccc32)cc1]

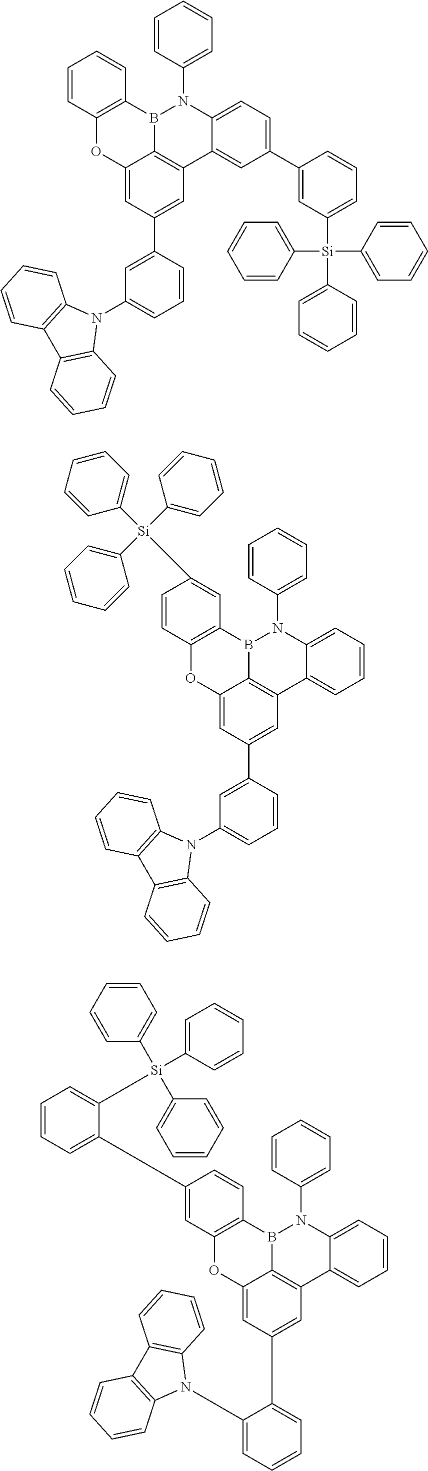

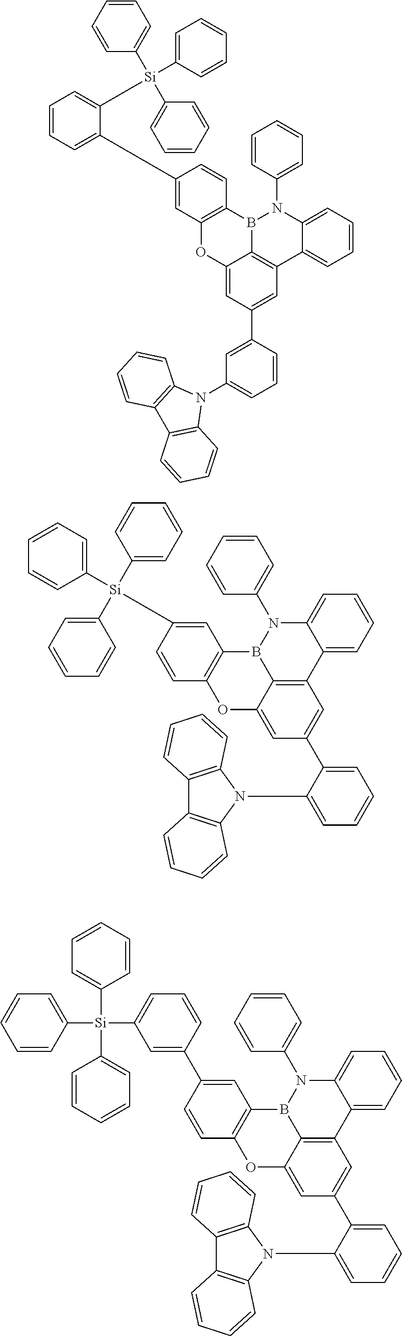

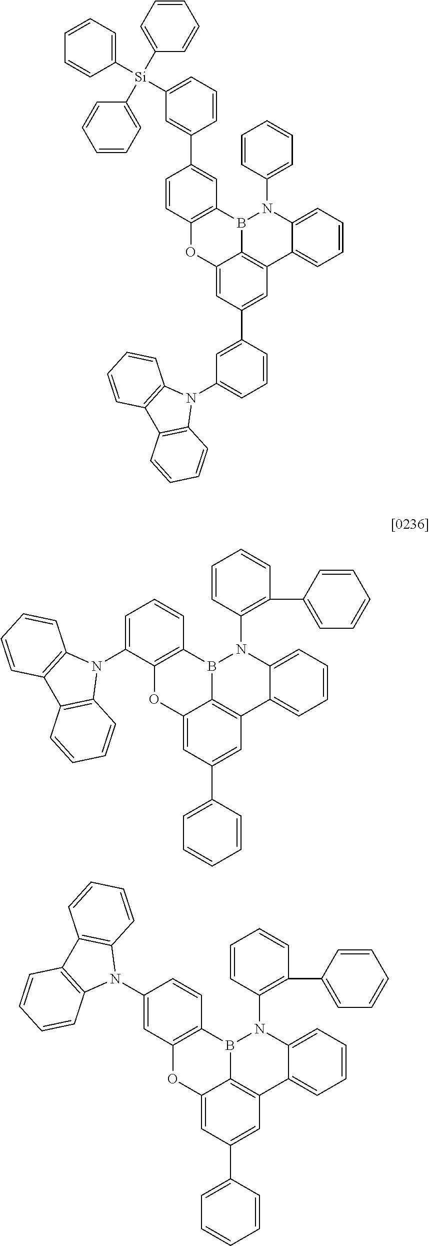 [SMILES: c1ccc(N2B3c4cc(-c5cccc([Si](c6ccccc6)(c6ccccc6)c6ccccc6)c5)ccc4Oc4cc(-c5cccc(-n6c7ccccc7c7ccccc76)c5)cc(c43)-c3ccccc32)cc1 ; c1ccc(-c2cc3c4c(c2)-c2ccccc2N(c2ccccc2-c2ccccc2)B4c2cccc(-n4c5ccccc5c5ccccc54)c2O3)cc1 ; c1ccc(-c2cc3c4c(c2)-c2ccccc2N(c2ccccc2-c2ccccc2)B4c2ccc(-n4c5ccccc5c5ccccc54)cc2O3)cc1]

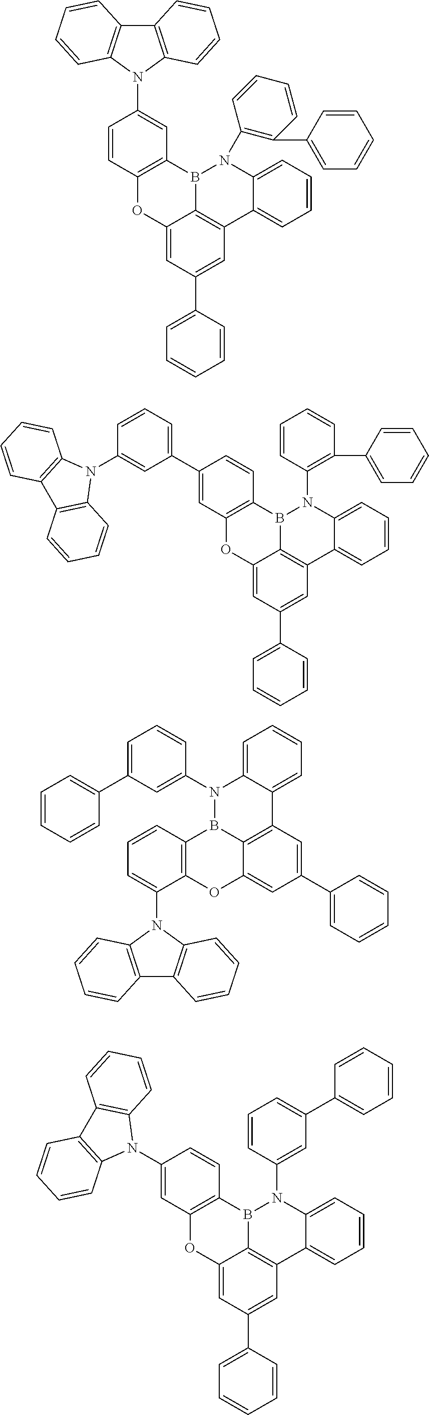

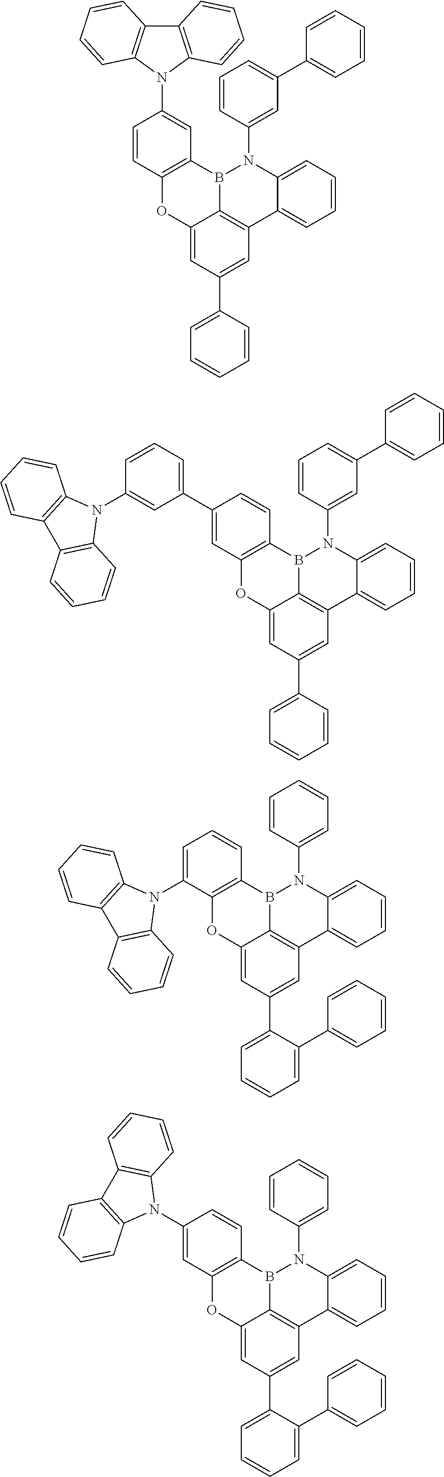

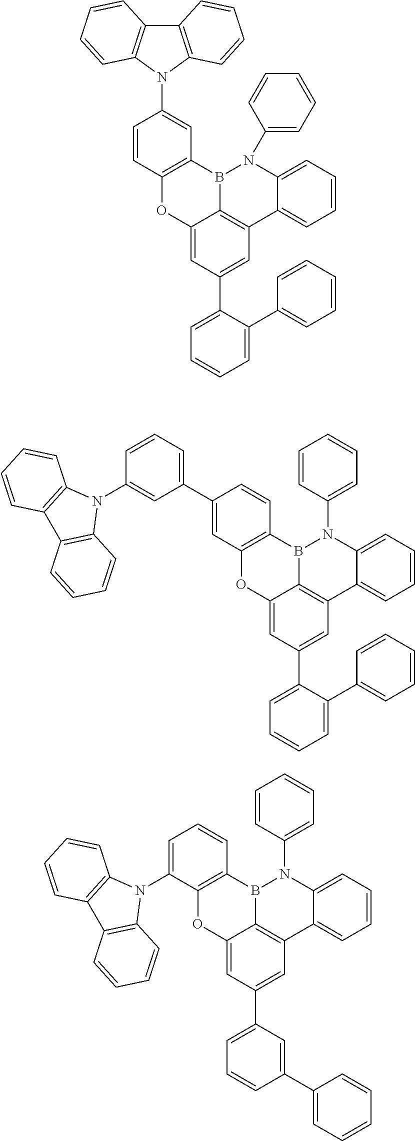

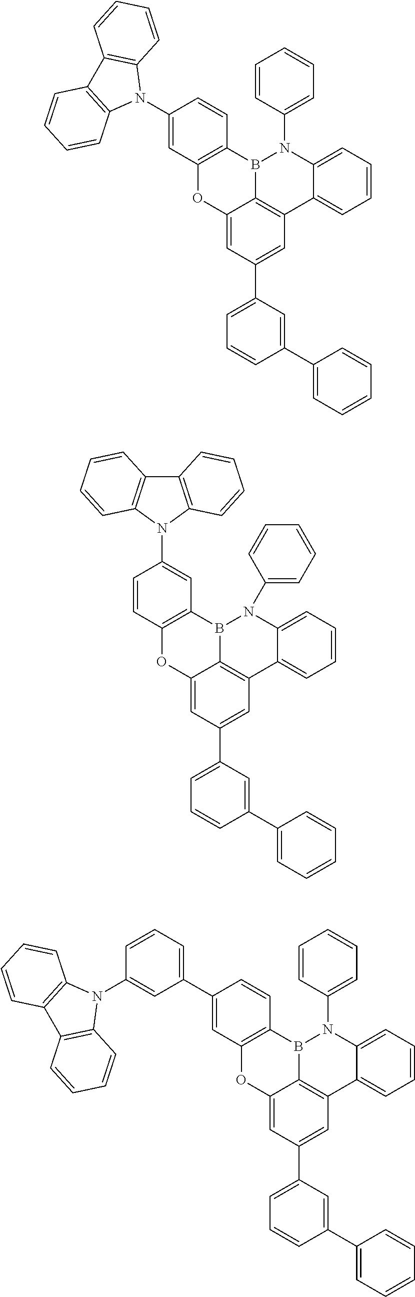 [SMILES: c1ccc(-c2cccc(-c3cc4c5c(c3)-c3ccccc3N(c3ccccc3)B5c3ccc(-n5c6ccccc6c6ccccc65)cc3O4)c2)cc1 ; c1ccc(-c2cccc(-c3cc4c5c(c3)-c3ccccc3N(c3ccccc3)B5c3cc(-n5c6ccccc6c6ccccc65)ccc3O4)c2)cc1 ; c1ccc(-c2cccc(-c3cc4c5c(c3)-c3ccccc3N(c3ccccc3)B5c3ccc(-c5cccc(-n6c7ccccc7c7ccccc76)c5)cc3O4)c2)cc1]

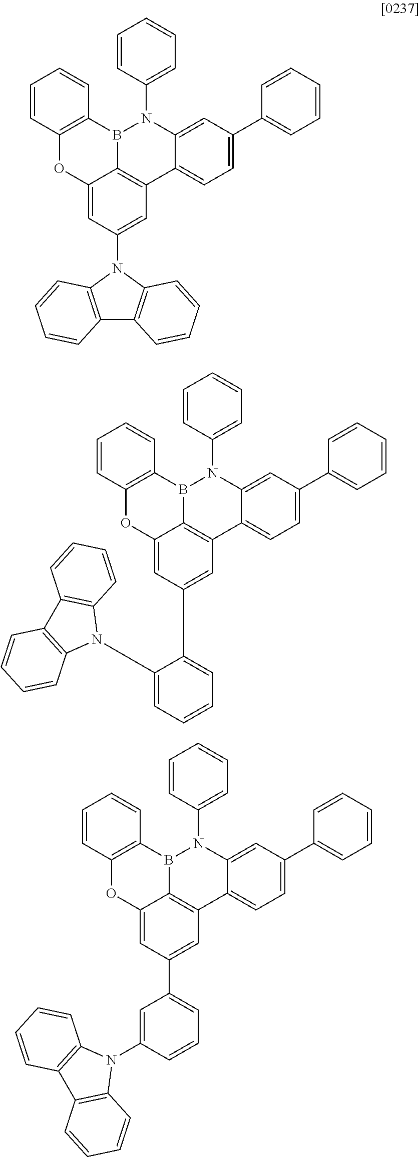

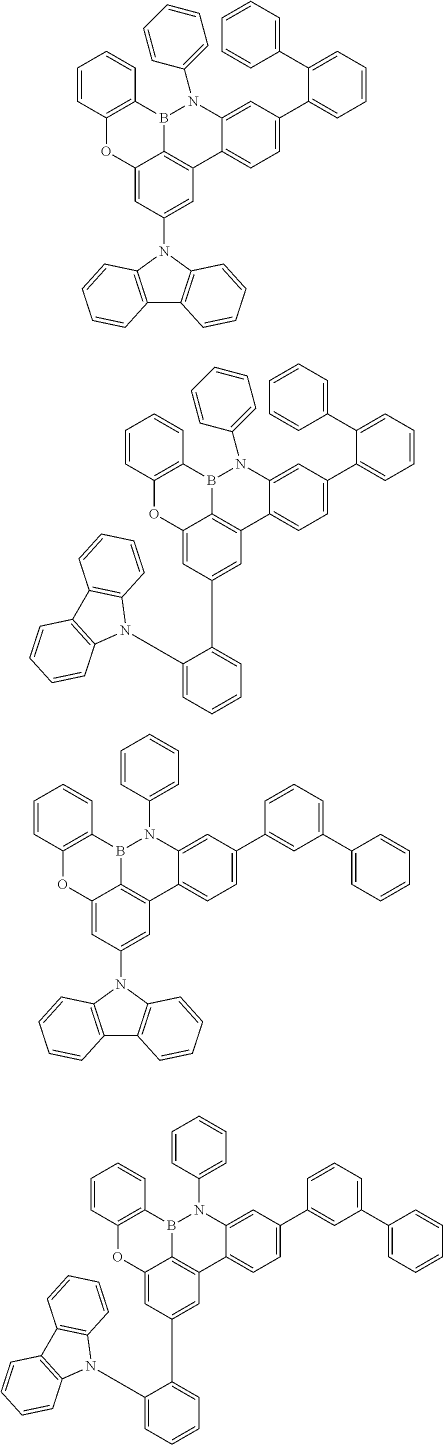

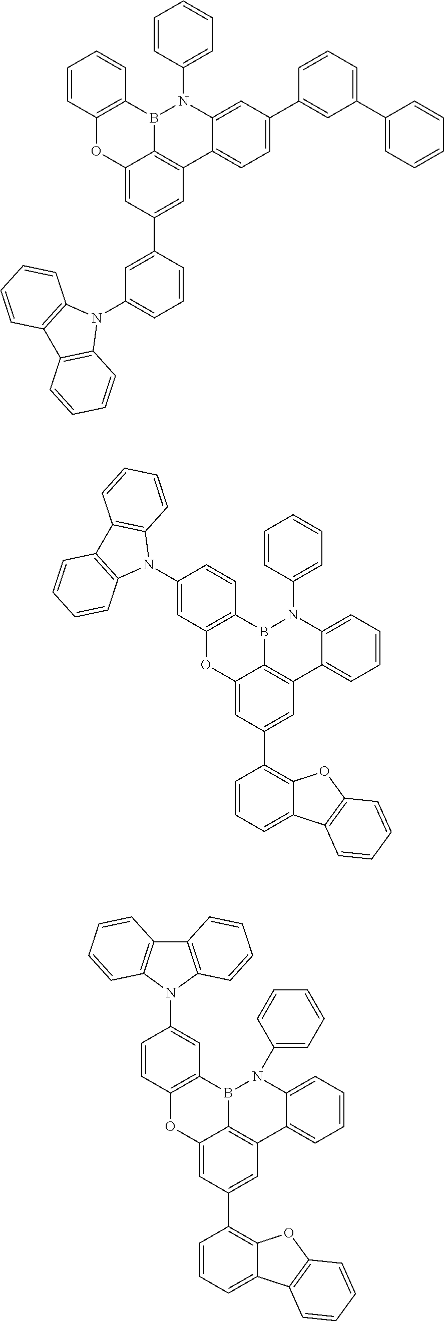 [SMILES: c1ccc(-c2cccc(-c3ccc4c(c3)N(c3ccccc3)B3c5ccccc5Oc5cc(-c6cccc(-n7c8ccccc8c8ccccc87)c6)cc-4c53)c2)cc1 ; c1ccc(N2B3c4ccc(-n5c6ccccc6c6ccccc65)cc4Oc4cc(-c5cccc6c5oc5ccccc56)cc(c43)-c3ccccc32)cc1 ; c1ccc(N2B3c4cc(-n5c6ccccc6c6ccccc65)ccc4Oc4cc(-c5cccc6c5oc5ccccc56)cc(c43)-c3ccccc32)cc1]

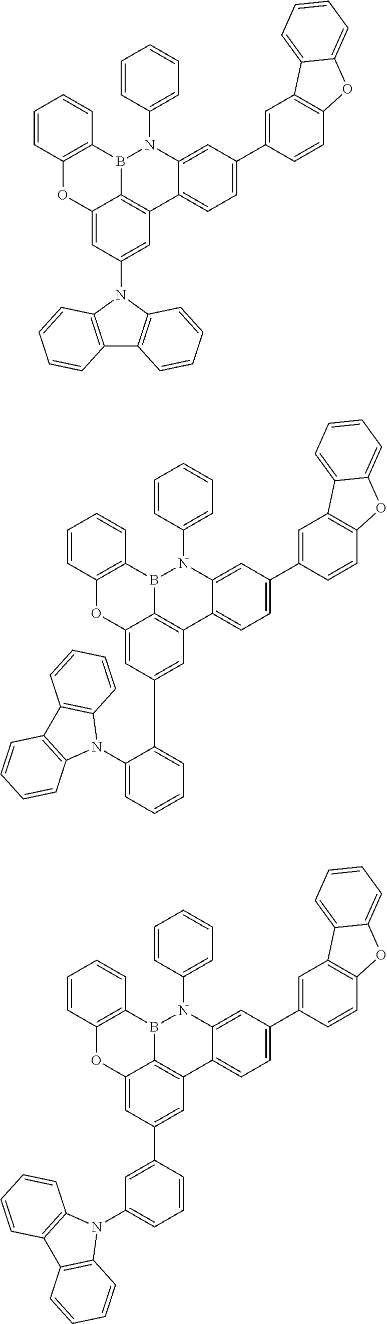 [SMILES: c1ccc(N2B3c4ccccc4Oc4cc(-n5c6ccccc6c6ccccc65)cc(c43)-c3ccc(-c4ccc5oc6ccccc6c5c4)cc32)cc1 ; c1ccc(N2B3c4ccccc4Oc4cc(-c5ccccc5-n5c6ccccc6c6ccccc65)cc(c43)-c3ccc(-c4ccc5oc6ccccc6c5c4)cc32)cc1 ; c1ccc(N2B3c4ccccc4Oc4cc(-c5cccc(-n6c7ccccc7c7ccccc76)c5)cc(c43)-c3ccc(-c4ccc5oc6ccccc6c5c4)cc32)cc1]

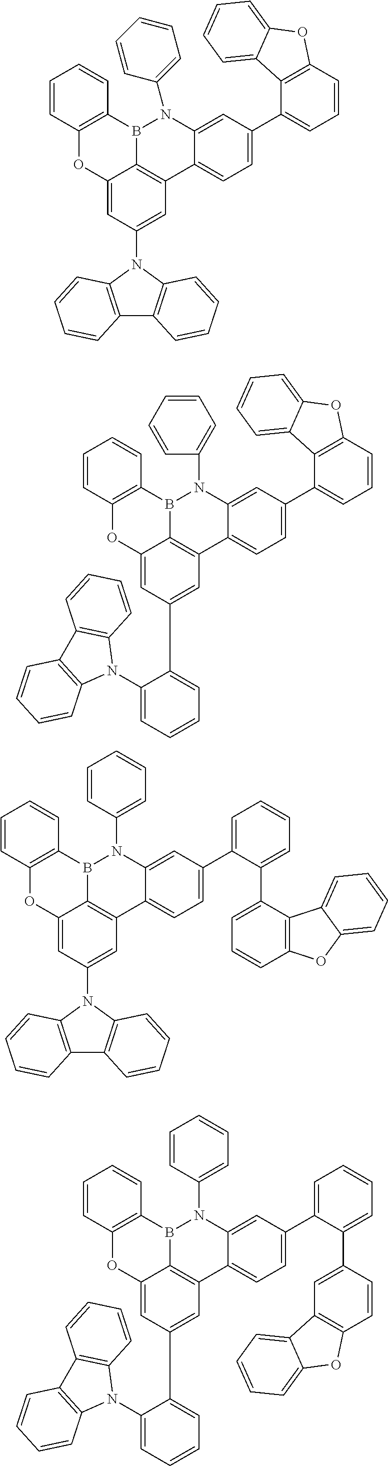

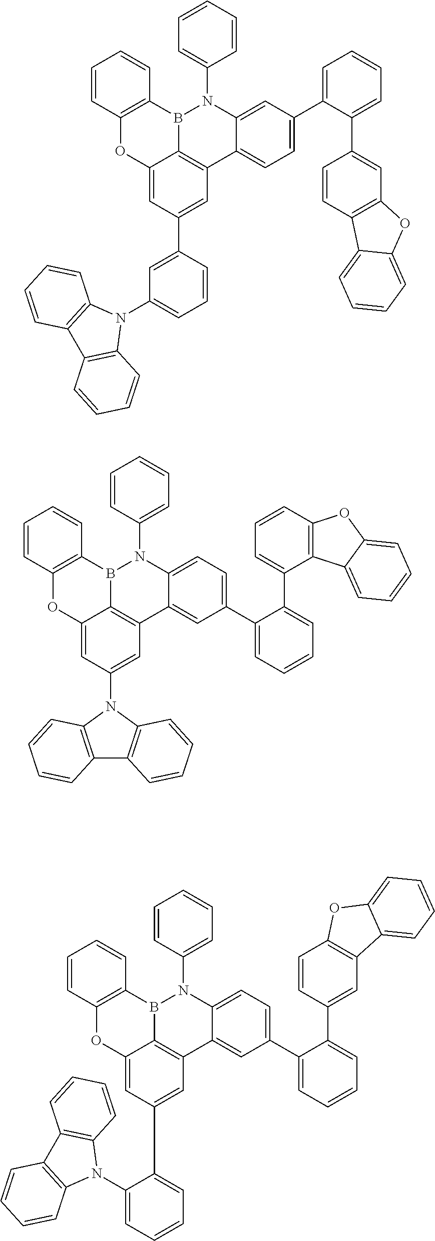 [SMILES: c1ccc(N2B3c4ccccc4Oc4cc(-c5cccc(-n6c7ccccc7c7ccccc76)c5)cc(c43)-c3ccc(-c4ccccc4-c4ccc5c(c4)oc4ccccc45)cc32)cc1 ; c1ccc(N2B3c4ccccc4Oc4cc(-n5c6ccccc6c6ccccc65)cc(c43)-c3cc(-c4ccccc4-c4cccc5oc6ccccc6c45)ccc32)cc1 ; c1ccc(N2B3c4ccccc4Oc4cc(-c5ccccc5-n5c6ccccc6c6ccccc65)cc(c43)-c3cc(-c4ccccc4-c4ccc5oc6ccccc6c5c4)ccc32)cc1]

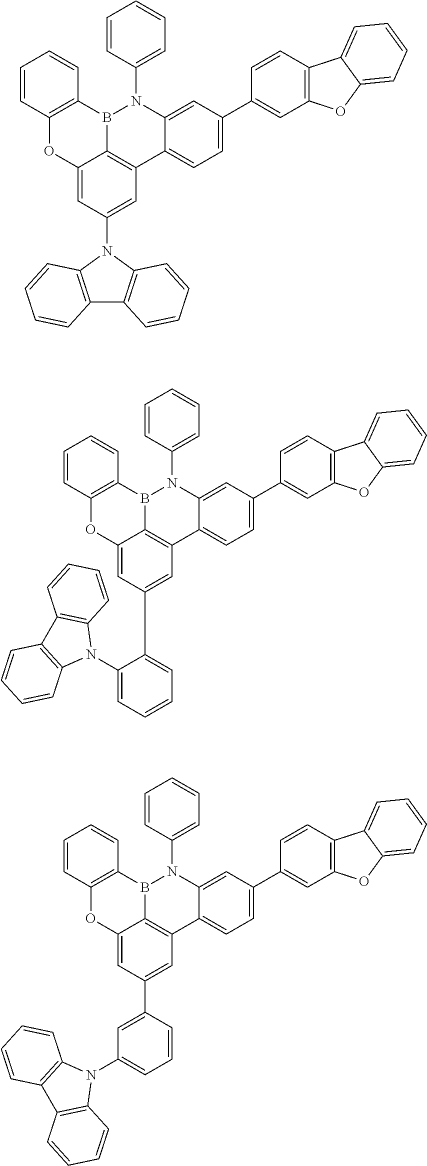 [SMILES: c1ccc(N2B3c4ccccc4Oc4cc(-n5c6ccccc6c6ccccc65)cc(c43)-c3ccc(-c4ccc5c(c4)oc4ccccc45)cc32)cc1 ; c1ccc(N2B3c4ccccc4Oc4cc(-c5ccccc5-n5c6ccccc6c6ccccc65)cc(c43)-c3ccc(-c4ccc5c(c4)oc4ccccc45)cc32)cc1 ; c1ccc(N2B3c4ccccc4Oc4cc(-c5cccc(-n6c7ccccc7c7ccccc76)c5)cc(c43)-c3ccc(-c4ccc5c(c4)oc4ccccc45)cc32)cc1]

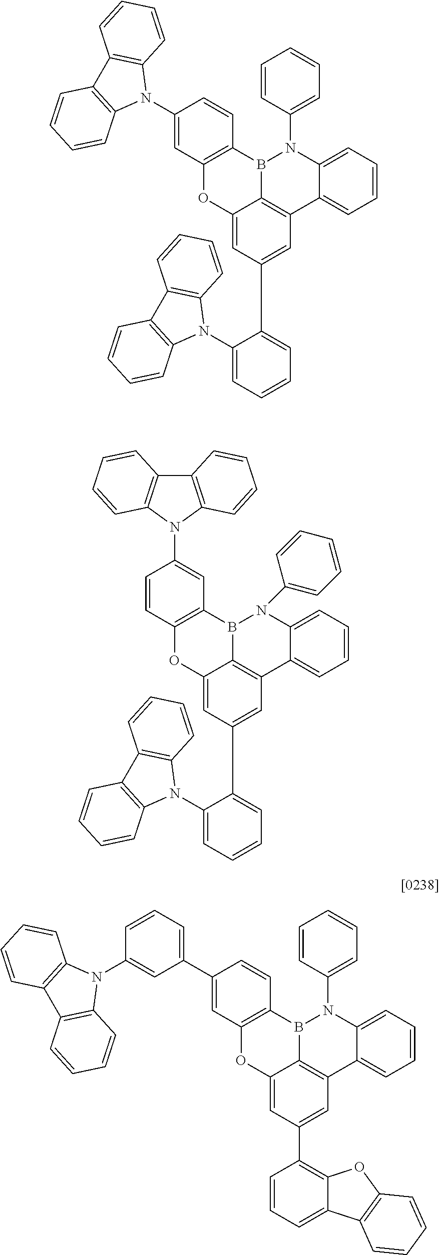 [SMILES: c1ccc(N2B3c4ccc(-n5c6ccccc6c6ccccc65)cc4Oc4cc(-c5ccccc5-n5c6ccccc6c6ccccc65)cc(c43)-c3ccccc32)cc1 ; c1ccc(N2B3c4cc(-n5c6ccccc6c6ccccc65)ccc4Oc4cc(-c5ccccc5-n5c6ccccc6c6ccccc65)cc(c43)-c3ccccc32)cc1 ; c1ccc(N2B3c4ccc(-c5cccc(-n6c7ccccc7c7ccccc76)c5)cc4Oc4cc(-c5cccc6c5oc5ccccc56)cc(c43)-c3ccccc32)cc1]

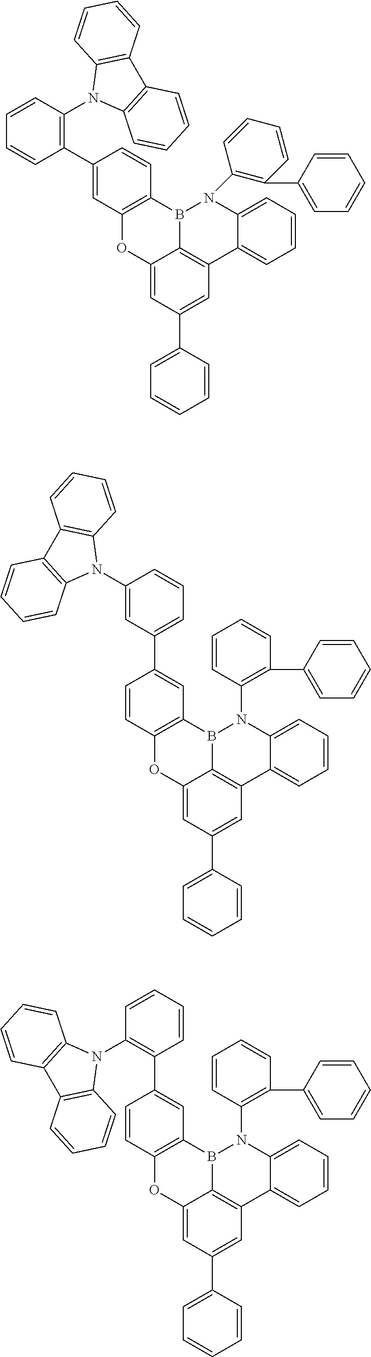 [SMILES: c1ccc(-c2cc3c4c(c2)-c2ccccc2N(c2ccccc2-c2ccccc2)B4c2ccc(-c4ccccc4-n4c5ccccc5c5ccccc54)cc2O3)cc1 ; c1ccc(-c2cc3c4c(c2)-c2ccccc2N(c2ccccc2-c2ccccc2)B4c2cc(-c4cccc(-n5c6ccccc6c6ccccc65)c4)ccc2O3)cc1 ; c1ccc(-c2cc3c4c(c2)-c2ccccc2N(c2ccccc2-c2ccccc2)B4c2cc(-c4ccccc4-n4c5ccccc5c5ccccc54)ccc2O3)cc1]

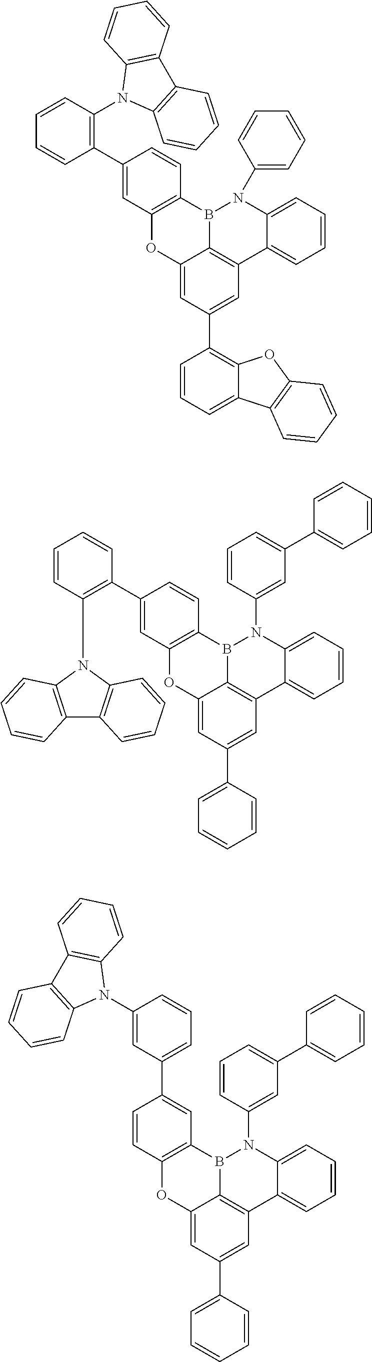 [SMILES: c1ccc(N2B3c4ccc(-c5ccccc5-n5c6ccccc6c6ccccc65)cc4Oc4cc(-c5cccc6c5oc5ccccc56)cc(c43)-c3ccccc32)cc1 ; c1ccc(-c2cccc(N3B4c5ccc(-c6ccccc6-n6c7ccccc7c7ccccc76)cc5Oc5cc(-c6ccccc6)cc(c54)-c4ccccc43)c2)cc1 ; c1ccc(-c2cccc(N3B4c5cc(-c6cccc(-n7c8ccccc8c8ccccc87)c6)ccc5Oc5cc(-c6ccccc6)cc(c54)-c4ccccc43)c2)cc1]

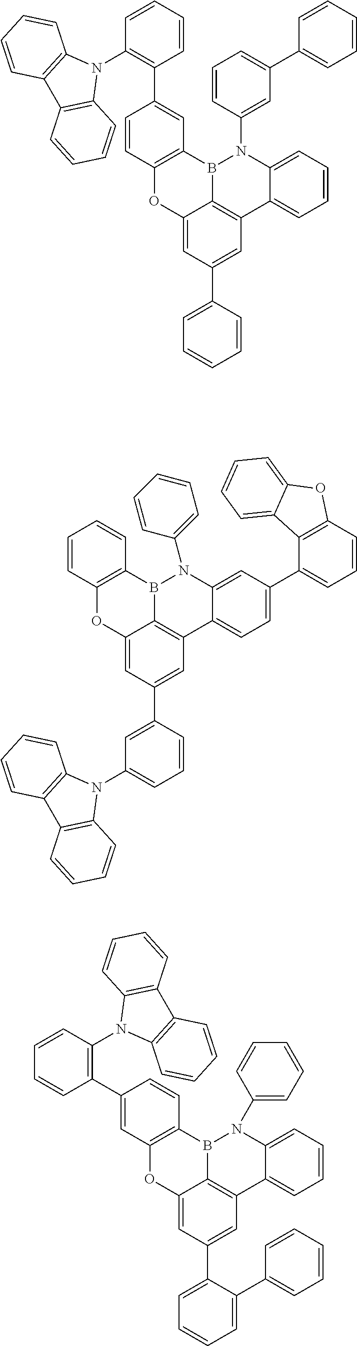 [SMILES: c1ccc(-c2cccc(N3B4c5cc(-c6ccccc6-n6c7ccccc7c7ccccc76)ccc5Oc5cc(-c6ccccc6)cc(c54)-c4ccccc43)c2)cc1 ; c1ccc(N2B3c4ccccc4Oc4cc(-c5cccc(-n6c7ccccc7c7ccccc76)c5)cc(c43)-c3ccc(-c4cccc5oc6ccccc6c45)cc32)cc1 ; c1ccc(-c2ccccc2-c2cc3c4c(c2)-c2ccccc2N(c2ccccc2)B4c2ccc(-c4ccccc4-n4c5ccccc5c5ccccc54)cc2O3)cc1]

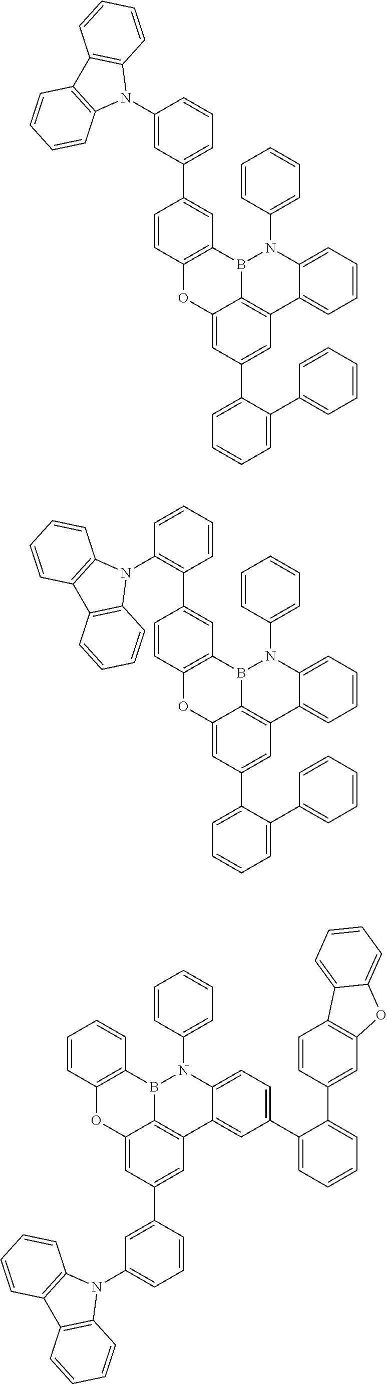 [SMILES: c1ccc(-c2ccccc2-c2cc3c4c(c2)-c2ccccc2N(c2ccccc2)B4c2cc(-c4cccc(-n5c6ccccc6c6ccccc65)c4)ccc2O3)cc1 ; c1ccc(-c2ccccc2-c2cc3c4c(c2)-c2ccccc2N(c2ccccc2)B4c2cc(-c4ccccc4-n4c5ccccc5c5ccccc54)ccc2O3)cc1 ; c1ccc(N2B3c4ccccc4Oc4cc(-c5cccc(-n6c7ccccc7c7ccccc76)c5)cc(c43)-c3cc(-c4ccccc4-c4ccc5c(c4)oc4ccccc45)ccc32)cc1]

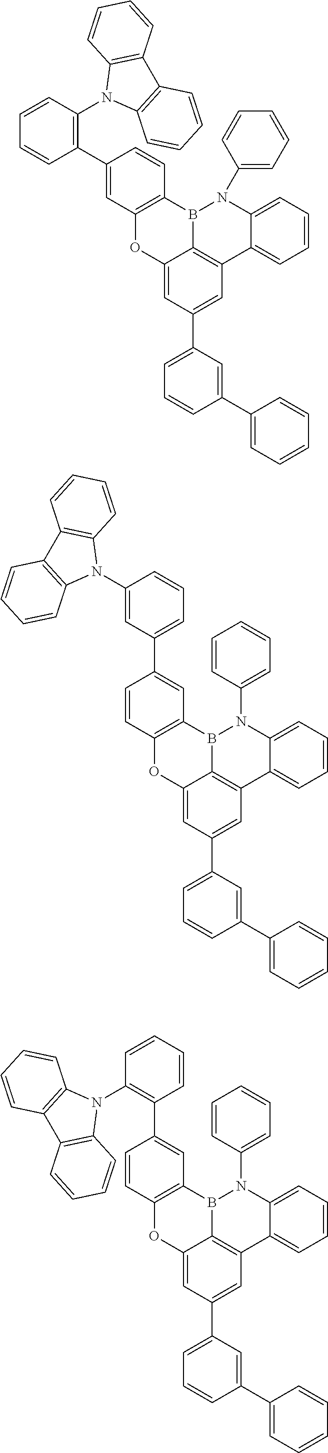 [SMILES: c1ccc(-c2cccc(-c3cc4c5c(c3)-c3ccccc3N(c3ccccc3)B5c3ccc(-c5ccccc5-n5c6ccccc6c6ccccc65)cc3O4)c2)cc1 ; c1ccc(-c2cccc(-c3cc4c5c(c3)-c3ccccc3N(c3ccccc3)B5c3cc(-c5cccc(-n6c7ccccc7c7ccccc76)c5)ccc3O4)c2)cc1 ; c1ccc(-c2cccc(-c3cc4c5c(c3)-c3ccccc3N(c3ccccc3)B5c3cc(-c5ccccc5-n5c6ccccc6c6ccccc65)ccc3O4)c2)cc1]

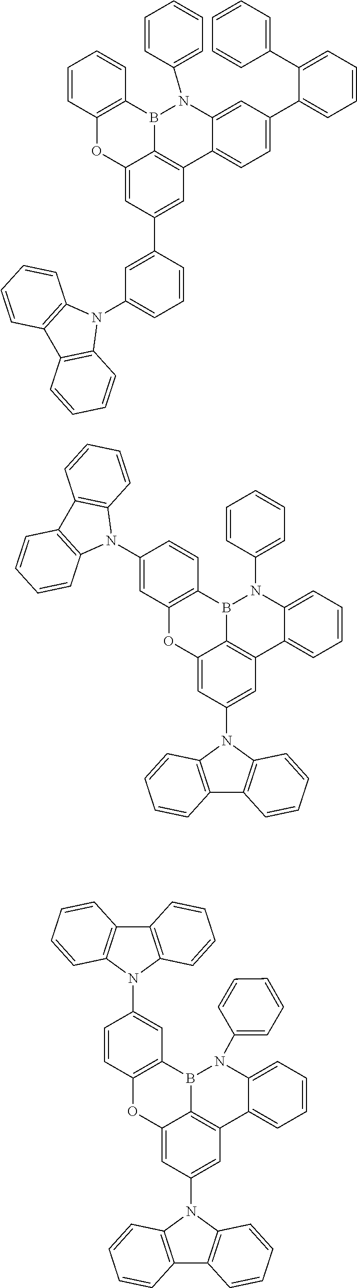

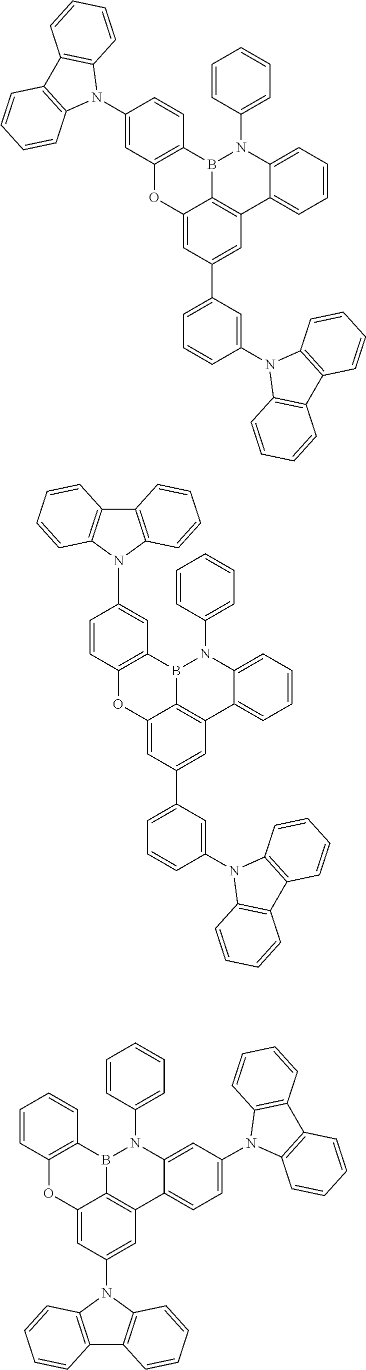 [SMILES: c1ccc(N2B3c4ccc(-n5c6ccccc6c6ccccc65)cc4Oc4cc(-c5cccc(-n6c7ccccc7c7ccccc76)c5)cc(c43)-c3ccccc32)cc1 ; c1ccc(N2B3c4cc(-n5c6ccccc6c6ccccc65)ccc4Oc4cc(-c5cccc(-n6c7ccccc7c7ccccc76)c5)cc(c43)-c3ccccc32)cc1 ; c1ccc(N2B3c4ccccc4Oc4cc(-n5c6ccccc6c6ccccc65)cc(c43)-c3ccc(-n4c5ccccc5c5ccccc54)cc32)cc1]

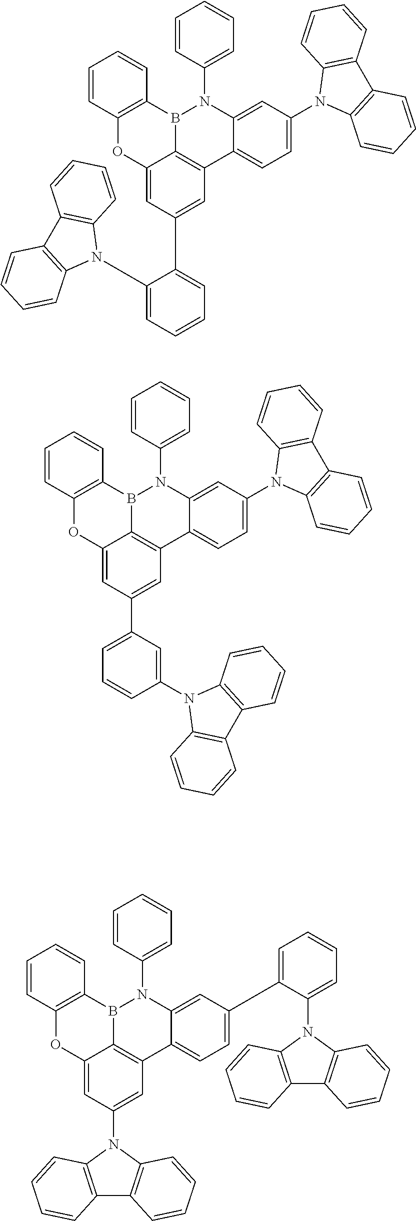 [SMILES: c1ccc(N2B3c4ccccc4Oc4cc(-c5ccccc5-n5c6ccccc6c6ccccc65)cc(c43)-c3ccc(-n4c5ccccc5c5ccccc54)cc32)cc1 ; c1ccc(N2B3c4ccccc4Oc4cc(-c5cccc(-n6c7ccccc7c7ccccc76)c5)cc(c43)-c3ccc(-n4c5ccccc5c5ccccc54)cc32)cc1 ; c1ccc(N2B3c4ccccc4Oc4cc(-n5c6ccccc6c6ccccc65)cc(c43)-c3ccc(-c4ccccc4-n4c5ccccc5c5ccccc54)cc32)cc1]

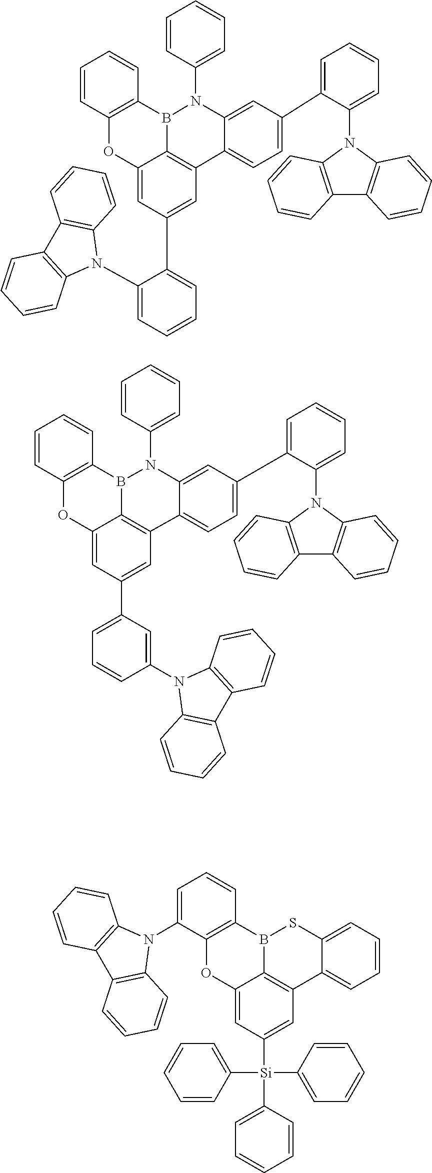

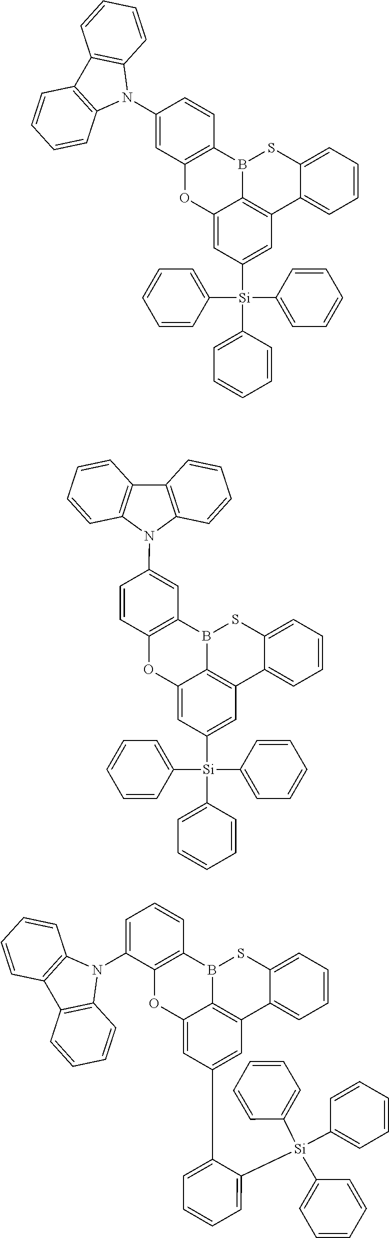 [SMILES: c1ccc([Si](c2ccccc2)(c2ccccc2)c2cc3c4c(c2)-c2ccccc2SB4c2ccc(-n4c5ccccc5c5ccccc54)cc2O3)cc1 ; c1ccc([Si](c2ccccc2)(c2ccccc2)c2cc3c4c(c2)-c2ccccc2SB4c2cc(-n4c5ccccc5c5ccccc54)ccc2O3)cc1 ; c1ccc([Si](c2ccccc2)(c2ccccc2)c2ccccc2-c2cc3c4c(c2)-c2ccccc2SB4c2cccc(-n4c5ccccc5c5ccccc54)c2O3)cc1]

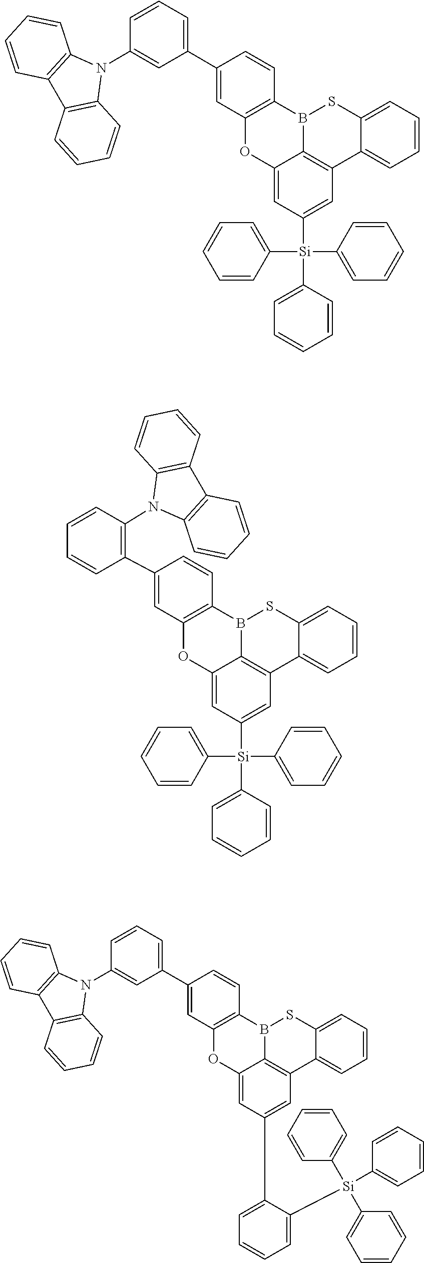 [SMILES: c1ccc([Si](c2ccccc2)(c2ccccc2)c2cc3c4c(c2)-c2ccccc2SB4c2ccc(-c4cccc(-n5c6ccccc6c6ccccc65)c4)cc2O3)cc1 ; c1ccc([Si](c2ccccc2)(c2ccccc2)c2cc3c4c(c2)-c2ccccc2SB4c2ccc(-c4ccccc4-n4c5ccccc5c5ccccc54)cc2O3)cc1 ; c1ccc([Si](c2ccccc2)(c2ccccc2)c2ccccc2-c2cc3c4c(c2)-c2ccccc2SB4c2ccc(-c4cccc(-n5c6ccccc6c6ccccc65)c4)cc2O3)cc1]

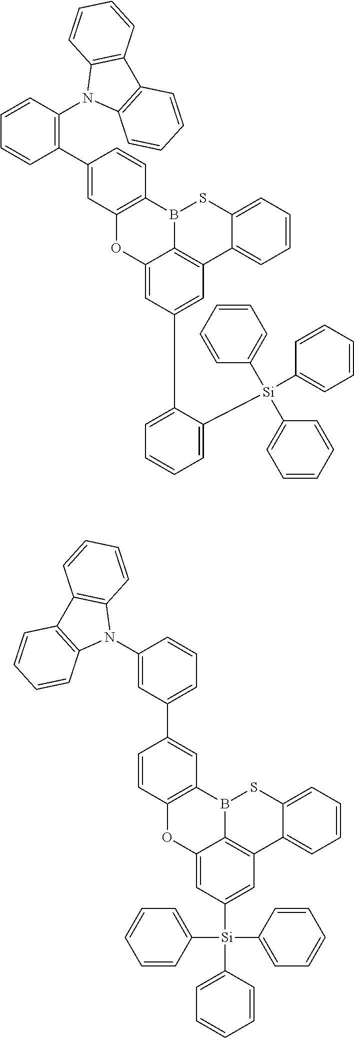 [SMILES: c1ccc([Si](c2ccccc2)(c2ccccc2)c2ccccc2-c2cc3c4c(c2)-c2ccccc2SB4c2ccc(-c4ccccc4-n4c5ccccc5c5ccccc54)cc2O3)cc1 ; c1ccc([Si](c2ccccc2)(c2ccccc2)c2cc3c4c(c2)-c2ccccc2SB4c2cc(-c4cccc(-n5c6ccccc6c6ccccc65)c4)ccc2O3)cc1]

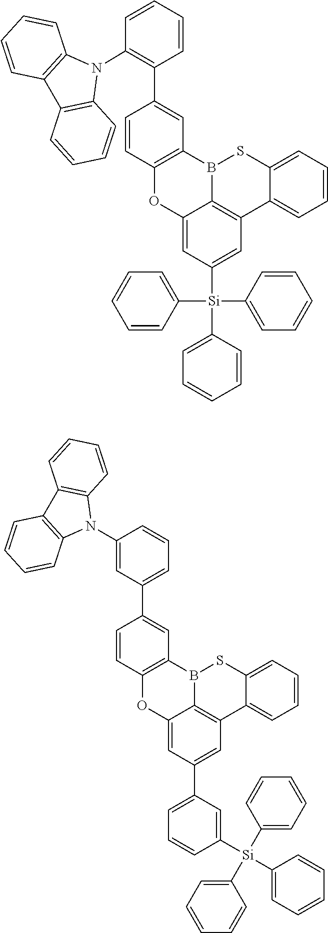 [SMILES: c1ccc([Si](c2ccccc2)(c2ccccc2)c2cc3c4c(c2)-c2ccccc2SB4c2cc(-c4ccccc4-n4c5ccccc5c5ccccc54)ccc2O3)cc1 ; c1ccc([Si](c2ccccc2)(c2ccccc2)c2cccc(-c3cc4c5c(c3)-c3ccccc3SB5c3cc(-c5cccc(-n6c7ccccc7c7ccccc76)c5)ccc3O4)c2)cc1]

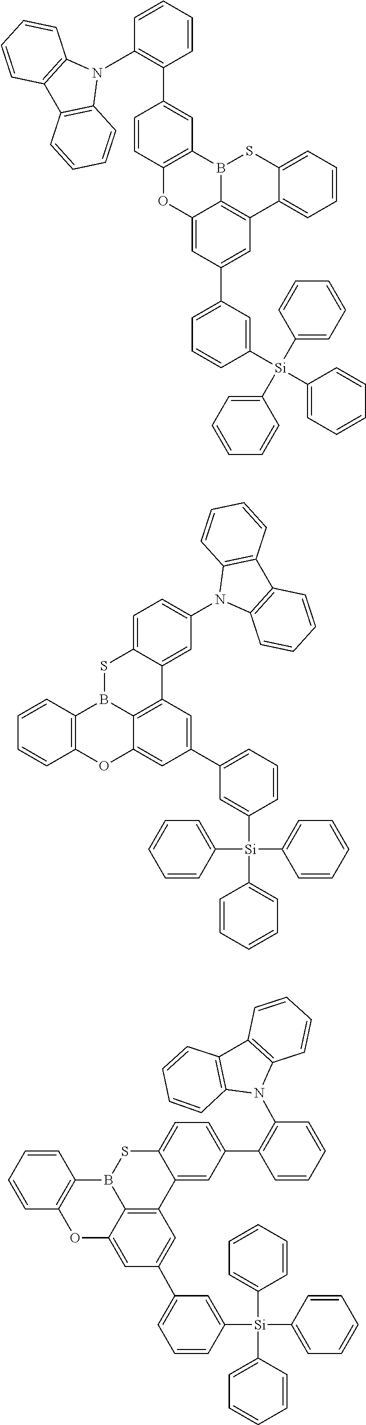 [SMILES: c1ccc([Si](c2ccccc2)(c2ccccc2)c2cccc(-c3cc4c5c(c3)-c3ccccc3SB5c3cc(-c5ccccc5-n5c6ccccc6c6ccccc65)ccc3O4)c2)cc1 ; c1ccc([Si](c2ccccc2)(c2ccccc2)c2cccc(-c3cc4c5c(c3)-c3cc(-n6c7ccccc7c7ccccc76)ccc3SB5c3ccccc3O4)c2)cc1 ; c1ccc([Si](c2ccccc2)(c2ccccc2)c2cccc(-c3cc4c5c(c3)-c3cc(-c6ccccc6-n6c7ccccc7c7ccccc76)ccc3SB5c3ccccc3O4)c2)cc1]

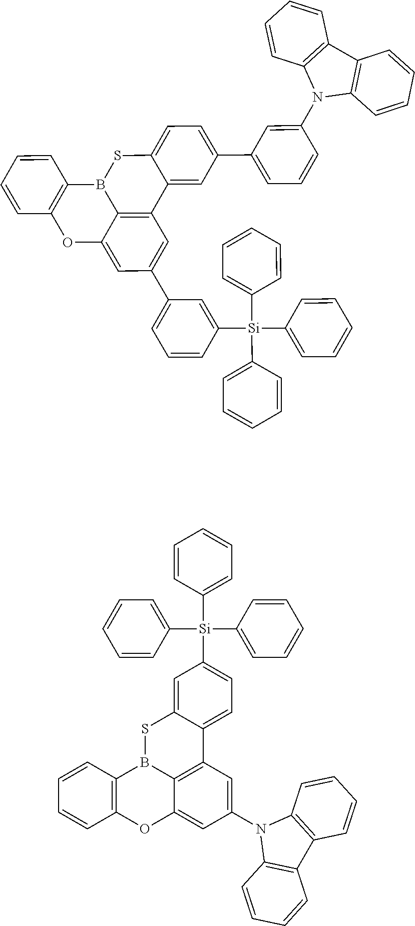

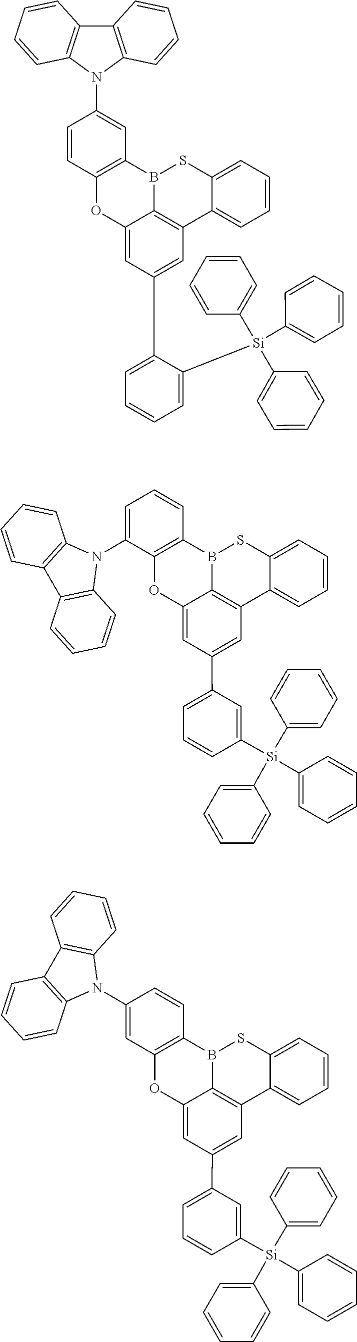 [SMILES: c1ccc([Si](c2ccccc2)(c2ccccc2)c2ccccc2-c2cc3c4c(c2)-c2ccccc2SB4c2cc(-n4c5ccccc5c5ccccc54)ccc2O3)cc1 ; c1ccc([Si](c2ccccc2)(c2ccccc2)c2cccc(-c3cc4c5c(c3)-c3ccccc3SB5c3cccc(-n5c6ccccc6c6ccccc65)c3O4)c2)cc1 ; c1ccc([Si](c2ccccc2)(c2ccccc2)c2cccc(-c3cc4c5c(c3)-c3ccccc3SB5c3ccc(-n5c6ccccc6c6ccccc65)cc3O4)c2)cc1]

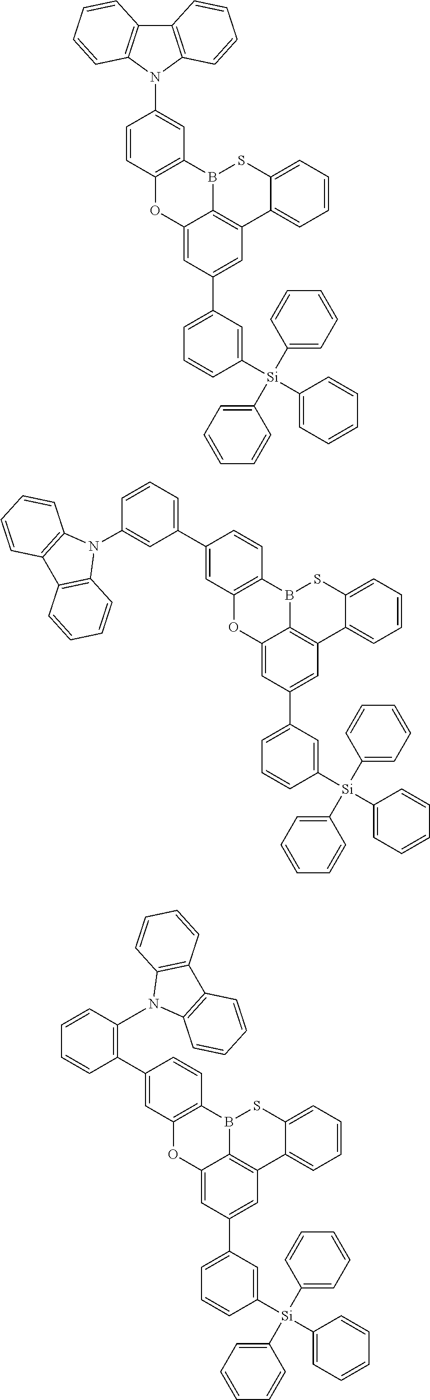 [SMILES: c1ccc([Si](c2ccccc2)(c2ccccc2)c2cccc(-c3cc4c5c(c3)-c3ccccc3SB5c3cc(-n5c6ccccc6c6ccccc65)ccc3O4)c2)cc1 ; c1ccc([Si](c2ccccc2)(c2ccccc2)c2cccc(-c3cc4c5c(c3)-c3ccccc3SB5c3ccc(-c5cccc(-n6c7ccccc7c7ccccc76)c5)cc3O4)c2)cc1 ; c1ccc([Si](c2ccccc2)(c2ccccc2)c2cccc(-c3cc4c5c(c3)-c3ccccc3SB5c3ccc(-c5ccccc5-n5c6ccccc6c6ccccc65)cc3O4)c2)cc1]

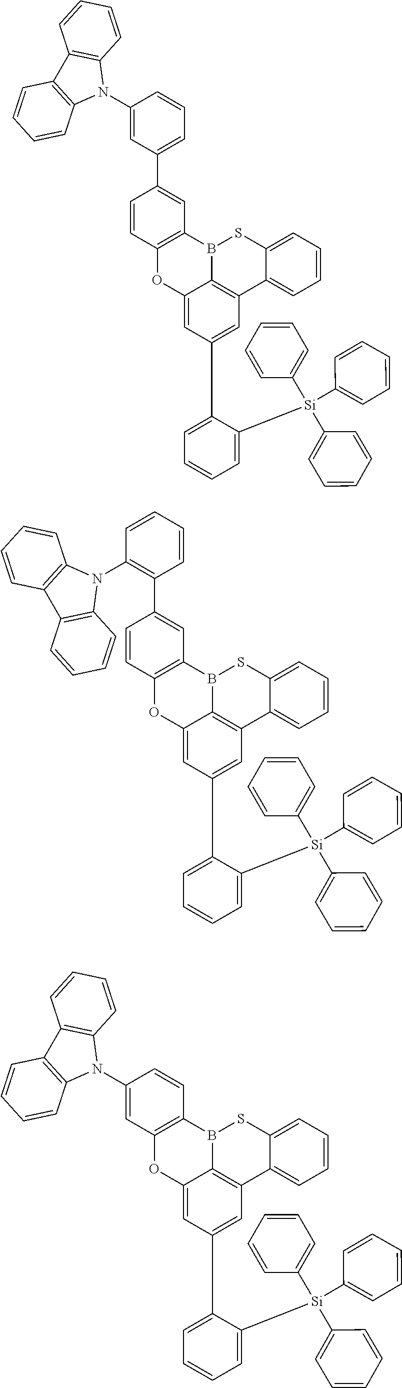 [SMILES: c1ccc([Si](c2ccccc2)(c2ccccc2)c2ccccc2-c2cc3c4c(c2)-c2ccccc2SB4c2cc(-c4cccc(-n5c6ccccc6c6ccccc65)c4)ccc2O3)cc1 ; c1ccc([Si](c2ccccc2)(c2ccccc2)c2ccccc2-c2cc3c4c(c2)-c2ccccc2SB4c2cc(-c4ccccc4-n4c5ccccc5c5ccccc54)ccc2O3)cc1 ; c1ccc([Si](c2ccccc2)(c2ccccc2)c2ccccc2-c2cc3c4c(c2)-c2ccccc2SB4c2ccc(-n4c5ccccc5c5ccccc54)cc2O3)cc1]

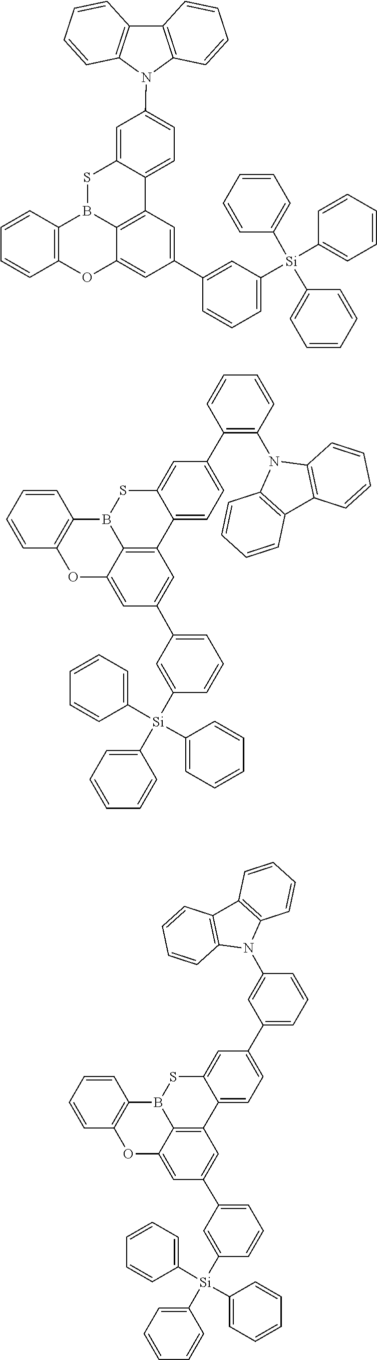

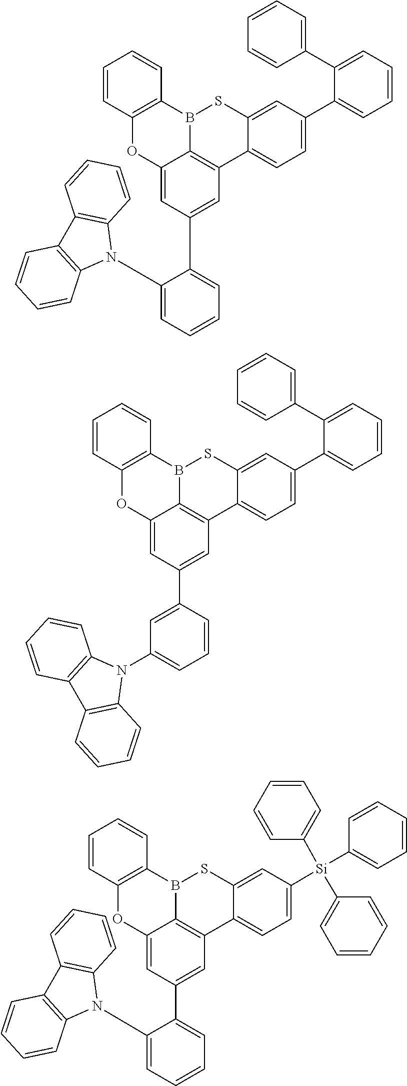 [SMILES: c1ccc(-c2ccccc2-c2ccc3c(c2)SB2c4ccccc4Oc4cc(-c5ccccc5-n5c6ccccc6c6ccccc65)cc-3c42)cc1 ; c1ccc(-c2ccccc2-c2ccc3c(c2)SB2c4ccccc4Oc4cc(-c5cccc(-n6c7ccccc7c7ccccc76)c5)cc-3c42)cc1 ; c1ccc([Si](c2ccccc2)(c2ccccc2)c2ccc3c(c2)SB2c4ccccc4Oc4cc(-c5ccccc5-n5c6ccccc6c6ccccc65)cc-3c42)cc1]

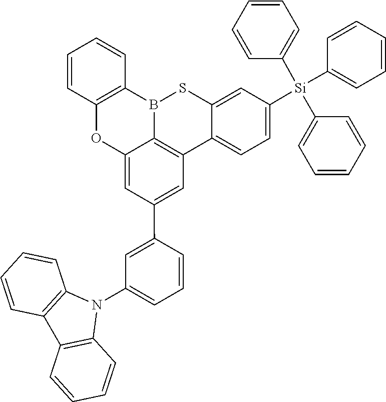 [SMILES: c1ccc([Si](c2ccccc2)(c2ccccc2)c2ccc3c(c2)SB2c4ccccc4Oc4cc(-c5cccc(-n6c7ccccc7c7ccccc76)c5)cc-3c42)cc1]

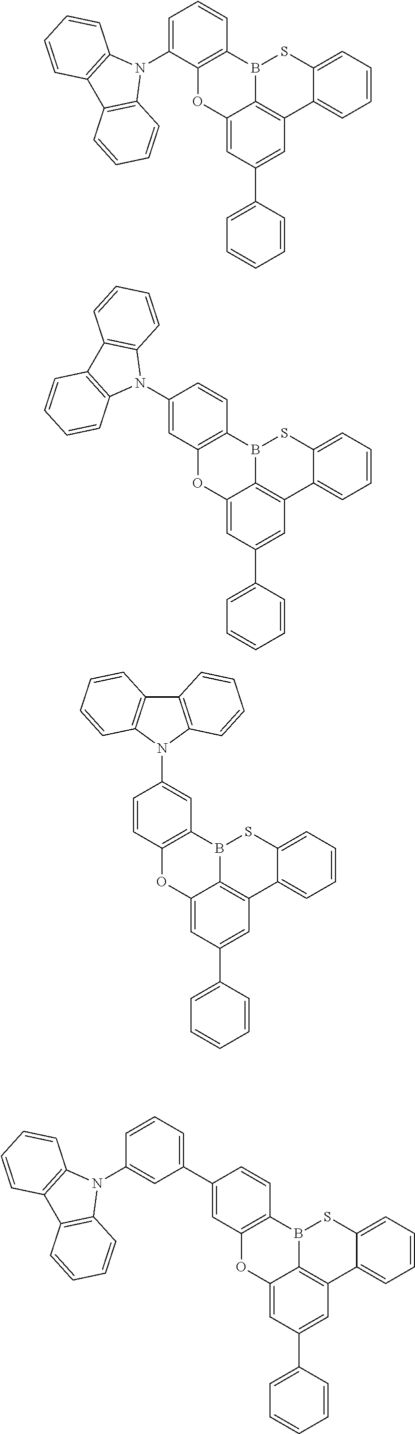

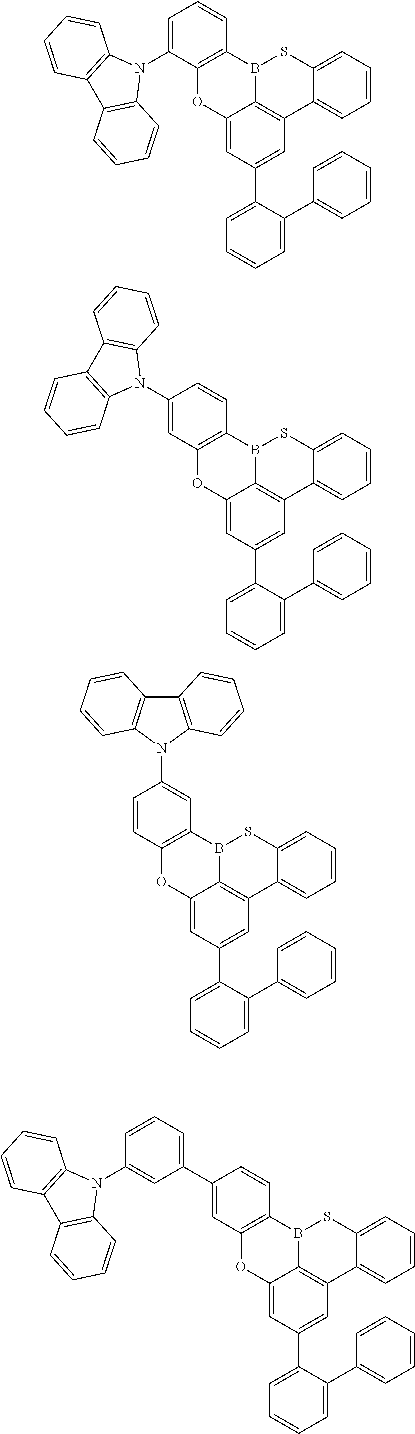

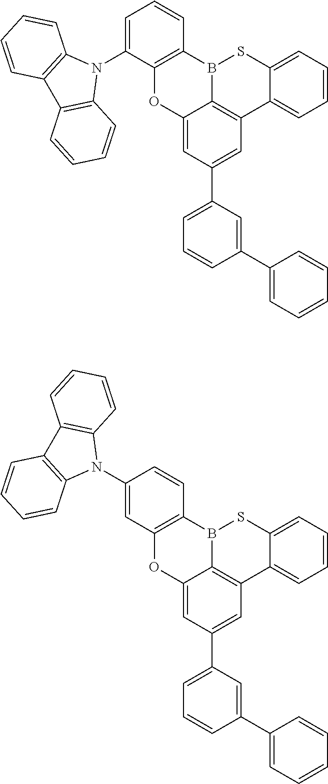 [SMILES: c1ccc(-c2cccc(-c3cc4c5c(c3)-c3ccccc3SB5c3cccc(-n5c6ccccc6c6ccccc65)c3O4)c2)cc1 ; c1ccc(-c2cccc(-c3cc4c5c(c3)-c3ccccc3SB5c3ccc(-n5c6ccccc6c6ccccc65)cc3O4)c2)cc1]

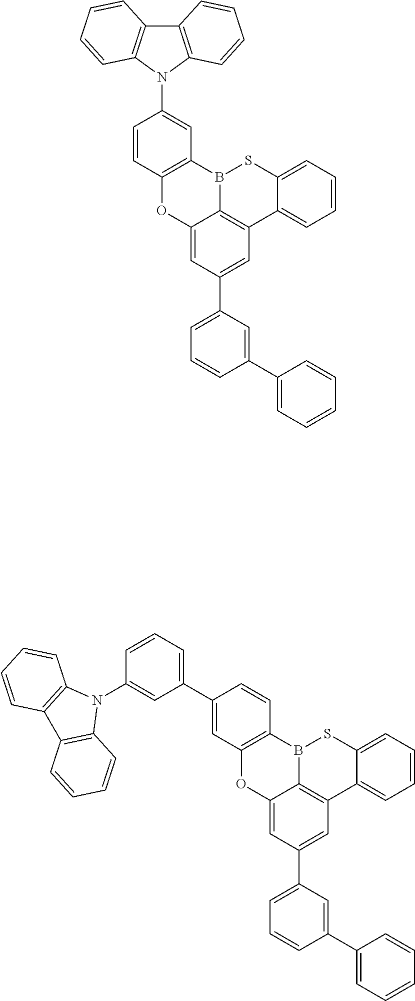 [SMILES: c1ccc(-c2cccc(-c3cc4c5c(c3)-c3ccccc3SB5c3cc(-n5c6ccccc6c6ccccc65)ccc3O4)c2)cc1 ; c1ccc(-c2cccc(-c3cc4c5c(c3)-c3ccccc3SB5c3ccc(-c5cccc(-n6c7ccccc7c7ccccc76)c5)cc3O4)c2)cc1]

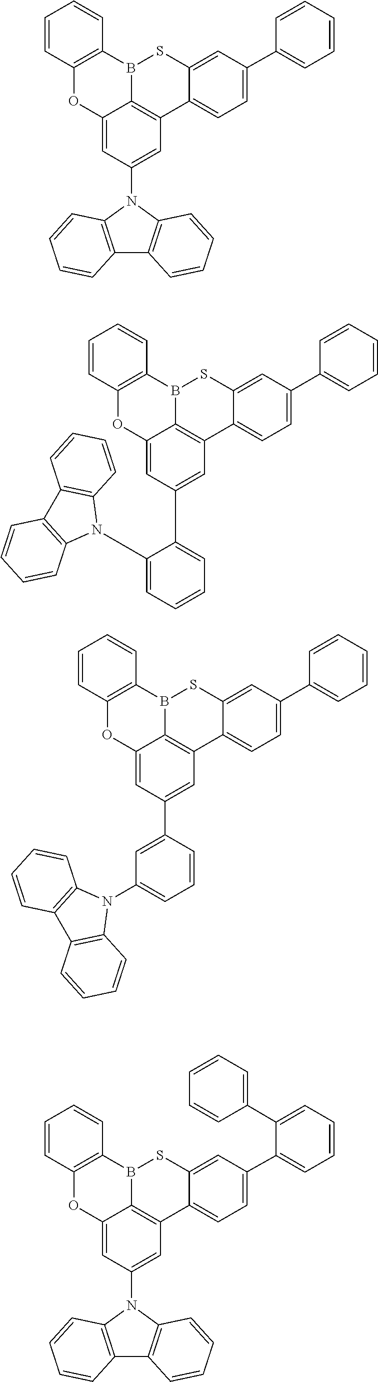 [SMILES: c1ccc(-c2ccc3c(c2)SB2c4ccccc4Oc4cc(-n5c6ccccc6c6ccccc65)cc-3c42)cc1 ; c1ccc(-c2ccc3c(c2)SB2c4ccccc4Oc4cc(-c5ccccc5-n5c6ccccc6c6ccccc65)cc-3c42)cc1 ; c1ccc(-c2ccc3c(c2)SB2c4ccccc4Oc4cc(-c5cccc(-n6c7ccccc7c7ccccc76)c5)cc-3c42)cc1 ; c1ccc(-c2ccccc2-c2ccc3c(c2)SB2c4ccccc4Oc4cc(-n5c6ccccc6c6ccccc65)cc-3c42)cc1]

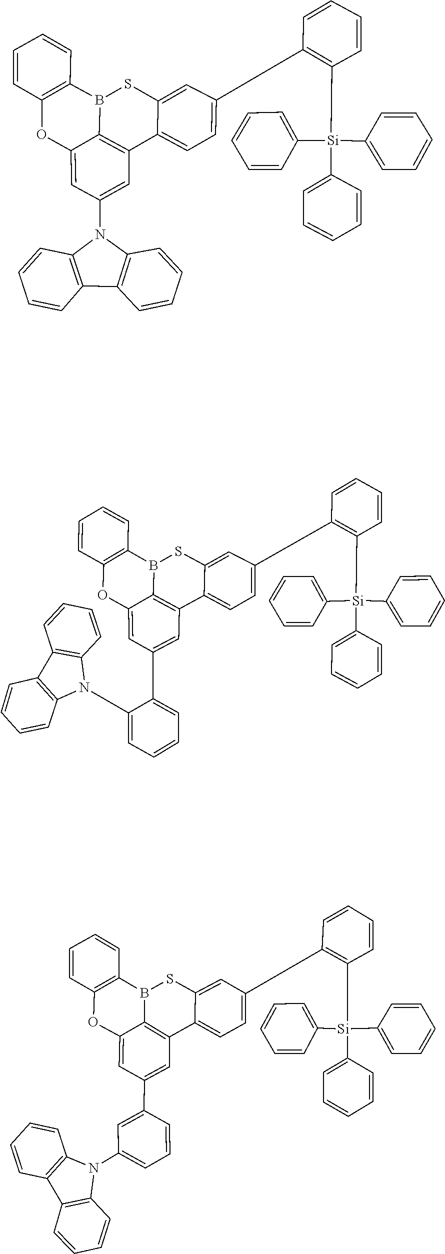 [SMILES: c1ccc([Si](c2ccccc2)(c2ccccc2)c2ccccc2-c2ccc3c(c2)SB2c4ccccc4Oc4cc(-n5c6ccccc6c6ccccc65)cc-3c42)cc1 ; c1ccc([Si](c2ccccc2)(c2ccccc2)c2ccccc2-c2ccc3c(c2)SB2c4ccccc4Oc4cc(-c5ccccc5-n5c6ccccc6c6ccccc65)cc-3c42)cc1 ; c1ccc([Si](c2ccccc2)(c2ccccc2)c2ccccc2-c2ccc3c(c2)SB2c4ccccc4Oc4cc(-c5cccc(-n6c7ccccc7c7ccccc76)c5)cc-3c42)cc1]

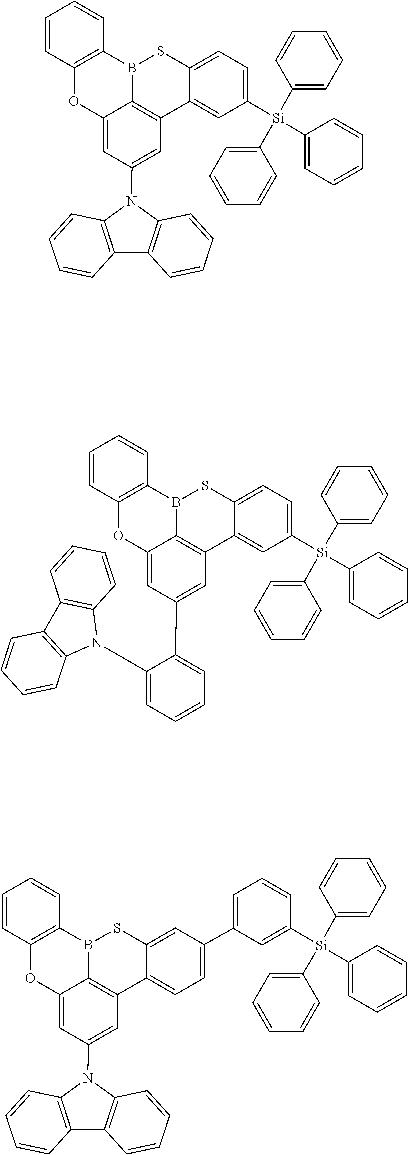 [SMILES: c1ccc([Si](c2ccccc2)(c2ccccc2)c2ccc3c(c2)-c2cc(-n4c5ccccc5c5ccccc54)cc4c2B(S3)c2ccccc2O4)cc1 ; c1ccc([Si](c2ccccc2)(c2ccccc2)c2ccc3c(c2)-c2cc(-c4ccccc4-n4c5ccccc5c5ccccc54)cc4c2B(S3)c2ccccc2O4)cc1 ; c1ccc([Si](c2ccccc2)(c2ccccc2)c2cccc(-c3ccc4c(c3)SB3c5ccccc5Oc5cc(-n6c7ccccc7c7ccccc76)cc-4c53)c2)cc1]

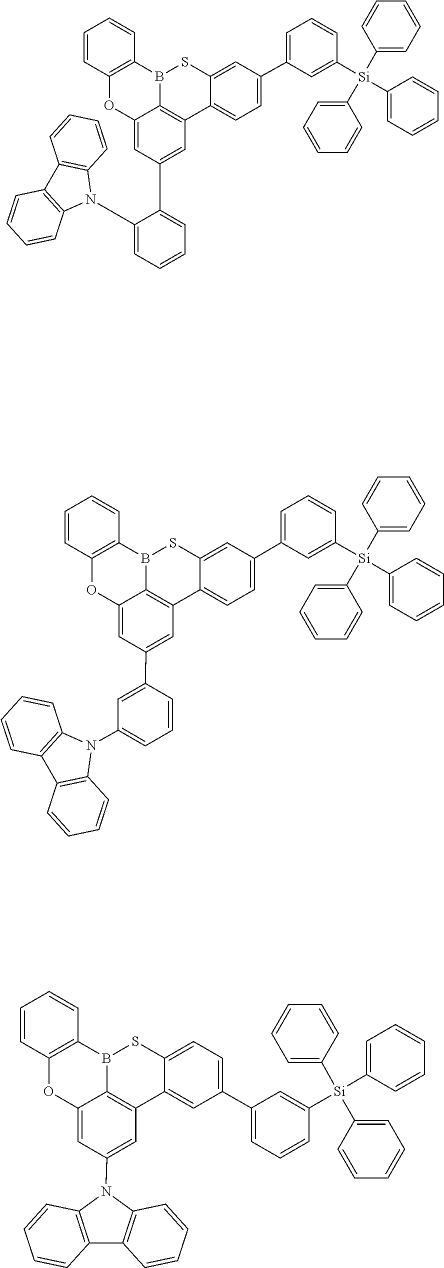 [SMILES: c1ccc([Si](c2ccccc2)(c2ccccc2)c2cccc(-c3ccc4c(c3)SB3c5ccccc5Oc5cc(-c6ccccc6-n6c7ccccc7c7ccccc76)cc-4c53)c2)cc1 ; c1ccc([Si](c2ccccc2)(c2ccccc2)c2cccc(-c3ccc4c(c3)SB3c5ccccc5Oc5cc(-c6cccc(-n7c8ccccc8c8ccccc87)c6)cc-4c53)c2)cc1 ; c1ccc([Si](c2ccccc2)(c2ccccc2)c2cccc(-c3ccc4c(c3)-c3cc(-n5c6ccccc6c6ccccc65)cc5c3B(S4)c3ccccc3O5)c2)cc1]

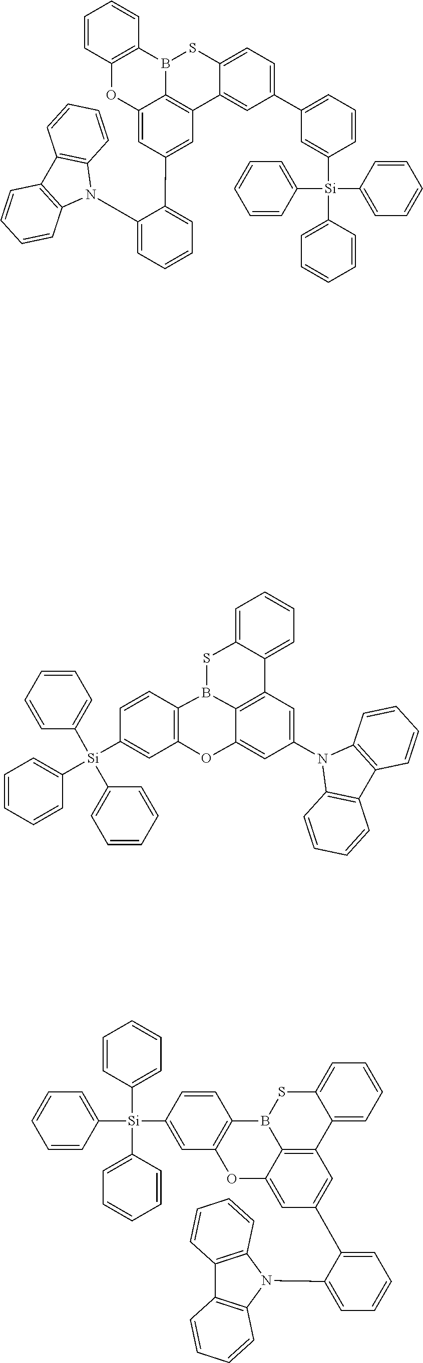 [SMILES: c1ccc([Si](c2ccccc2)(c2ccccc2)c2cccc(-c3ccc4c(c3)-c3cc(-c5ccccc5-n5c6ccccc6c6ccccc65)cc5c3B(S4)c3ccccc3O5)c2)cc1 ; c1ccc([Si](c2ccccc2)(c2ccccc2)c2ccc3c(c2)Oc2cc(-n4c5ccccc5c5ccccc54)cc4c2B3Sc2ccccc2-4)cc1 ; c1ccc([Si](c2ccccc2)(c2ccccc2)c2ccc3c(c2)Oc2cc(-c4ccccc4-n4c5ccccc5c5ccccc54)cc4c2B3Sc2ccccc2-4)cc1]

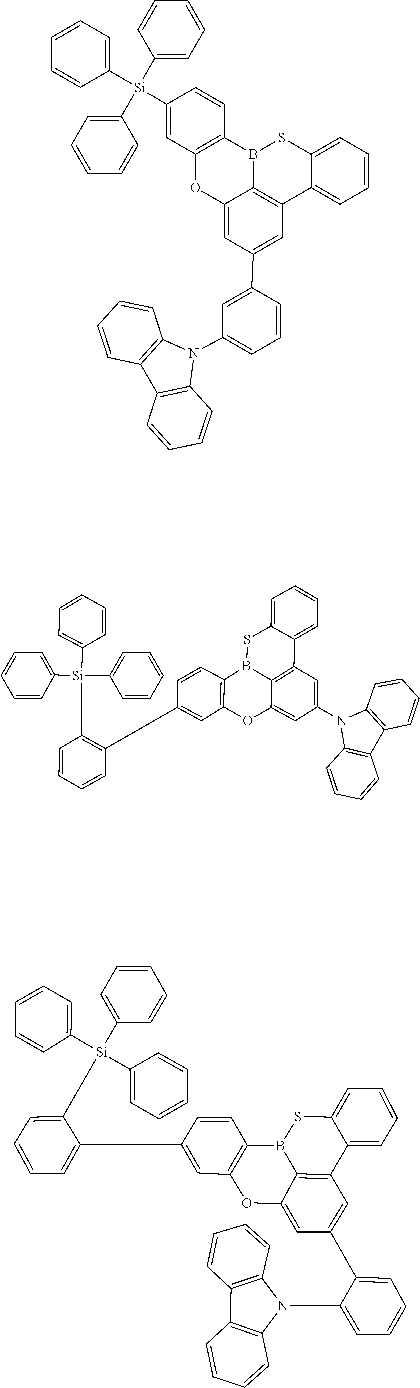 [SMILES: c1ccc([Si](c2ccccc2)(c2ccccc2)c2ccc3c(c2)Oc2cc(-c4cccc(-n5c6ccccc6c6ccccc65)c4)cc4c2B3Sc2ccccc2-4)cc1 ; c1ccc([Si](c2ccccc2)(c2ccccc2)c2ccccc2-c2ccc3c(c2)Oc2cc(-n4c5ccccc5c5ccccc54)cc4c2B3Sc2ccccc2-4)cc1 ; c1ccc([Si](c2ccccc2)(c2ccccc2)c2ccccc2-c2ccc3c(c2)Oc2cc(-c4ccccc4-n4c5ccccc5c5ccccc54)cc4c2B3Sc2ccccc2-4)cc1]

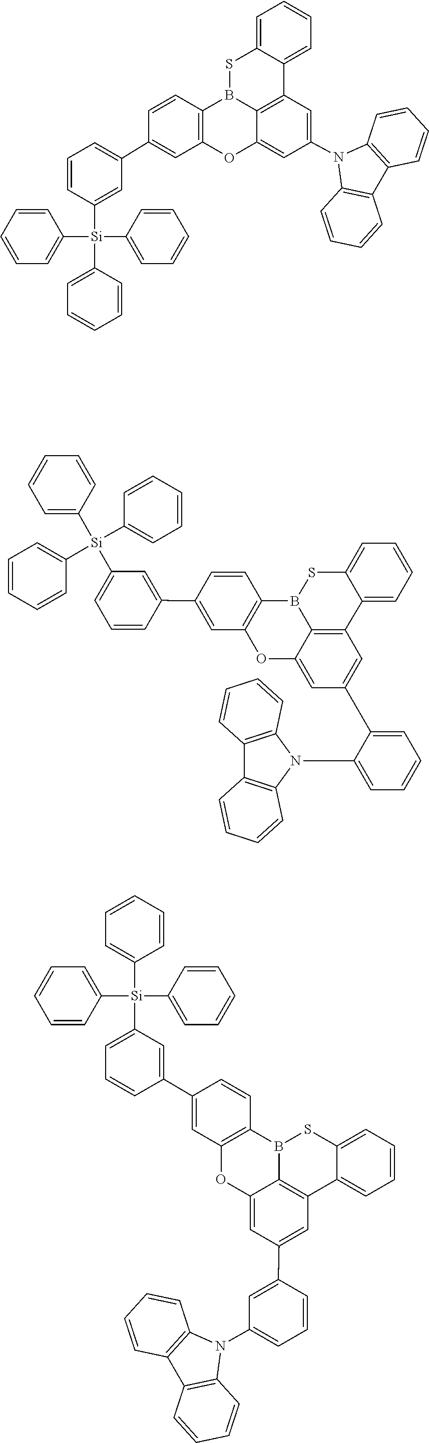

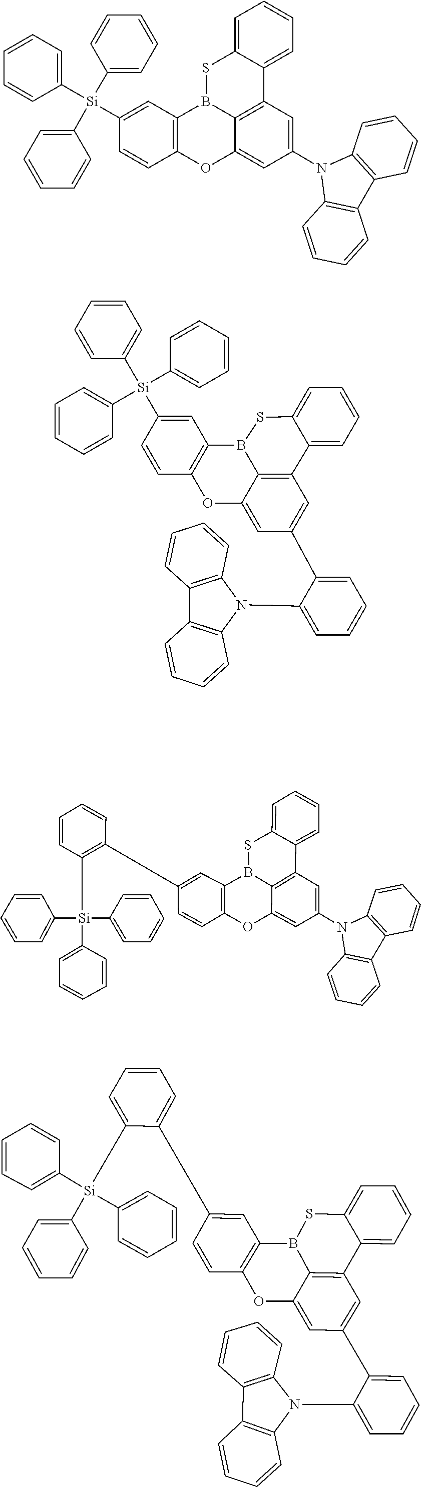

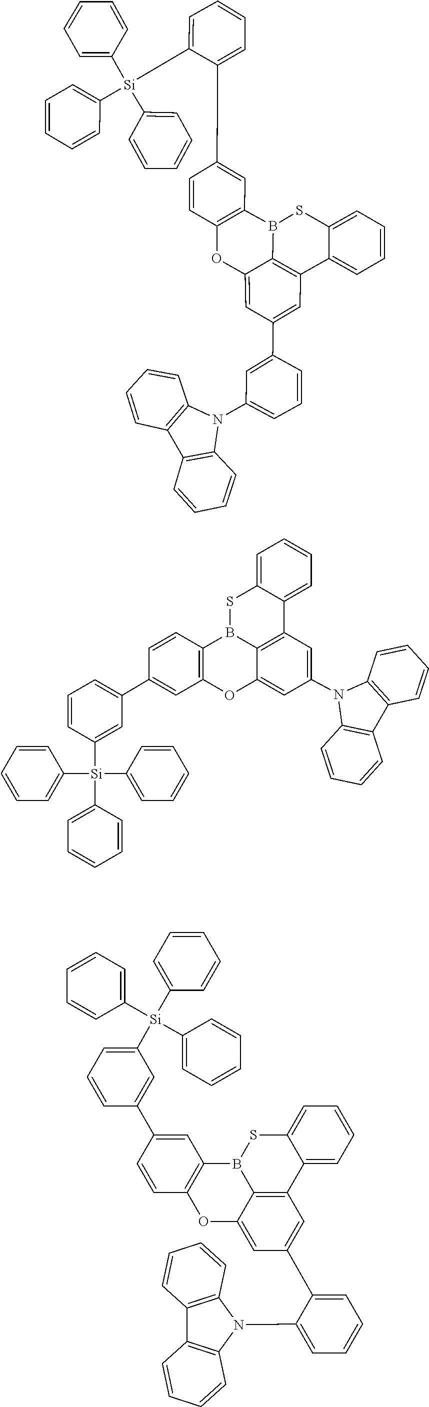 [SMILES: c1ccc([Si](c2ccccc2)(c2ccccc2)c2ccccc2-c2ccc3c(c2)B2Sc4ccccc4-c4cc(-c5cccc(-n6c7ccccc7c7ccccc76)c5)cc(c42)O3)cc1 ; c1ccc([Si](c2ccccc2)(c2ccccc2)c2cccc(-c3ccc4c(c3)Oc3cc(-n5c6ccccc6c6ccccc65)cc5c3B4Sc3ccccc3-5)c2)cc1 ; c1ccc([Si](c2ccccc2)(c2ccccc2)c2cccc(-c3ccc4c(c3)B3Sc5ccccc5-c5cc(-c6ccccc6-n6c7ccccc7c7ccccc76)cc(c53)O4)c2)cc1]

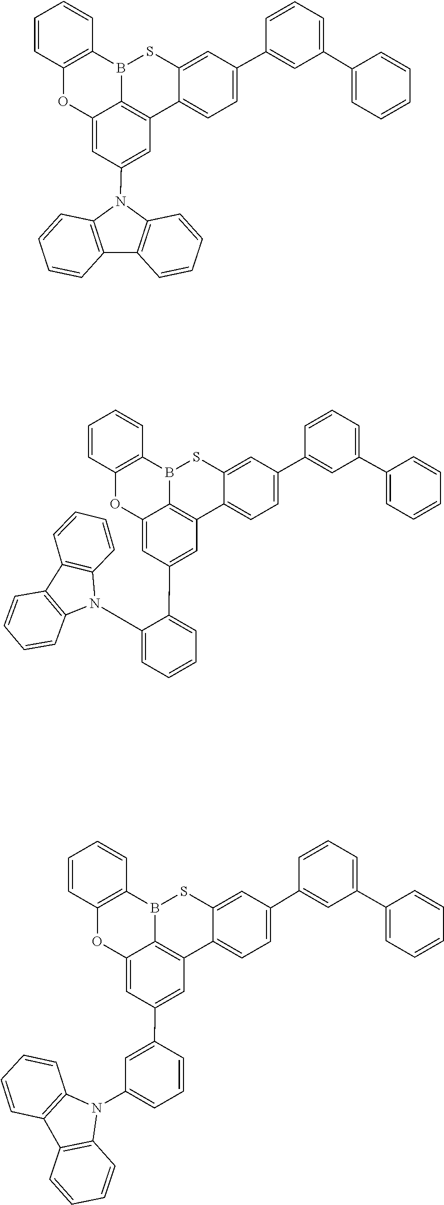 [SMILES: c1ccc(-c2cccc(-c3ccc4c(c3)SB3c5ccccc5Oc5cc(-n6c7ccccc7c7ccccc76)cc-4c53)c2)cc1 ; c1ccc(-c2cccc(-c3ccc4c(c3)SB3c5ccccc5Oc5cc(-c6ccccc6-n6c7ccccc7c7ccccc76)cc-4c53)c2)cc1 ; c1ccc(-c2cccc(-c3ccc4c(c3)SB3c5ccccc5Oc5cc(-c6cccc(-n7c8ccccc8c8ccccc87)c6)cc-4c53)c2)cc1]

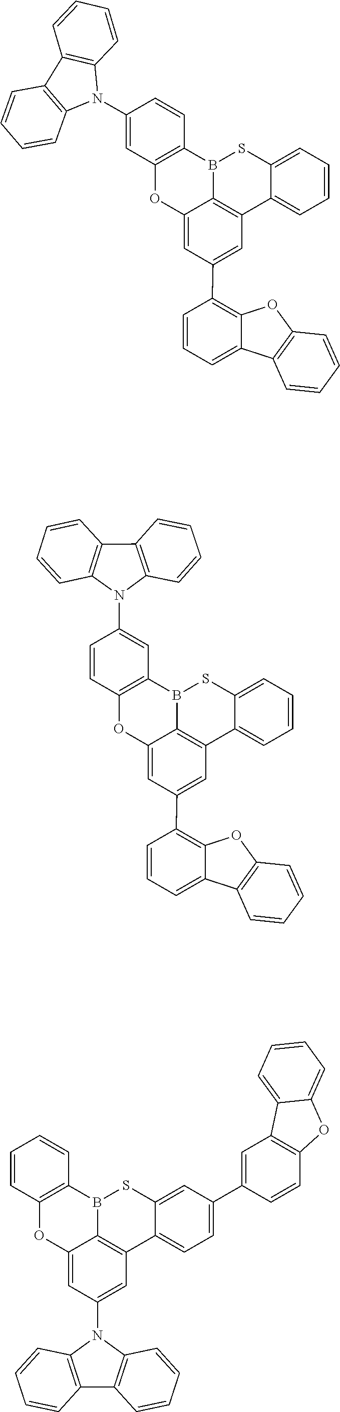 [SMILES: c1ccc2c(c1)SB1c3ccc(-n4c5ccccc5c5ccccc54)cc3Oc3cc(-c4cccc5c4oc4ccccc45)cc-2c31 ; c1ccc2c(c1)SB1c3cc(-n4c5ccccc5c5ccccc54)ccc3Oc3cc(-c4cccc5c4oc4ccccc45)cc-2c31 ; c1ccc2c(c1)Oc1cc(-n3c4ccccc4c4ccccc43)cc3c1B2Sc1cc(-c2ccc4oc5ccccc5c4c2)ccc1-3]

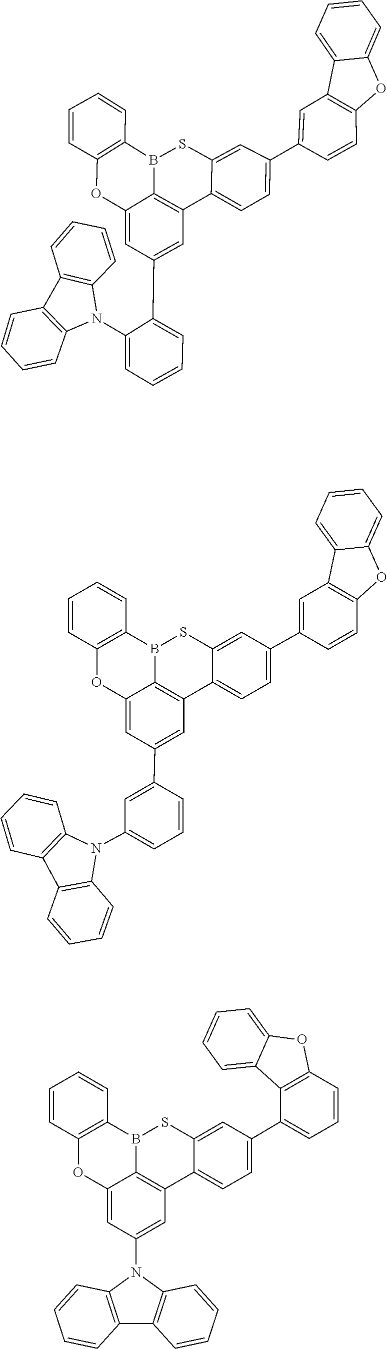 [SMILES: c1ccc2c(c1)Oc1cc(-c3ccccc3-n3c4ccccc4c4ccccc43)cc3c1B2Sc1cc(-c2ccc4oc5ccccc5c4c2)ccc1-3 ; c1cc(-c2cc3c4c(c2)-c2ccc(-c5ccc6oc7ccccc7c6c5)cc2SB4c2ccccc2O3)cc(-n2c3ccccc3c3ccccc32)c1 ; c1ccc2c(c1)Oc1cc(-n3c4ccccc4c4ccccc43)cc3c1B2Sc1cc(-c2cccc4oc5ccccc5c24)ccc1-3]

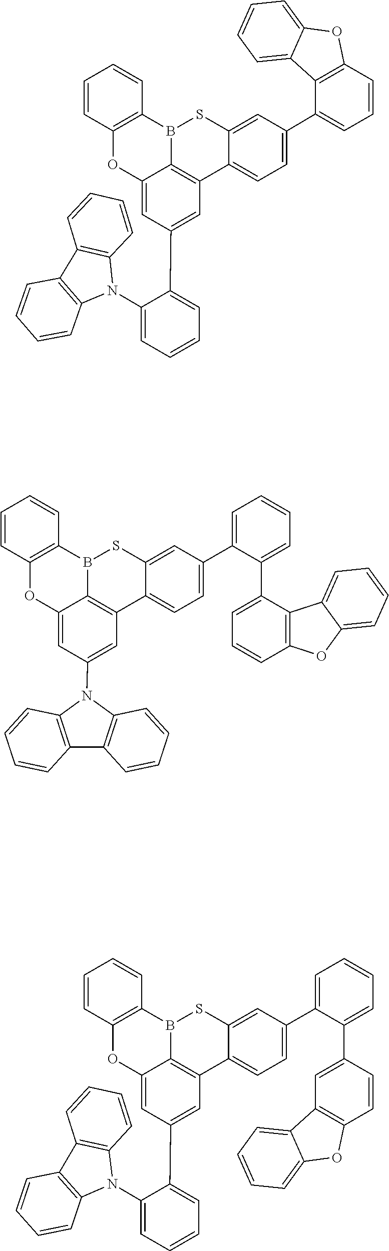 [SMILES: c1ccc2c(c1)Oc1cc(-c3ccccc3-n3c4ccccc4c4ccccc43)cc3c1B2Sc1cc(-c2cccc4oc5ccccc5c24)ccc1-3 ; c1ccc2c(c1)Oc1cc(-n3c4ccccc4c4ccccc43)cc3c1B2Sc1cc(-c2ccccc2-c2cccc4oc5ccccc5c24)ccc1-3 ; c1ccc2c(c1)Oc1cc(-c3ccccc3-n3c4ccccc4c4ccccc43)cc3c1B2Sc1cc(-c2ccccc2-c2ccc4oc5ccccc5c4c2)ccc1-3]

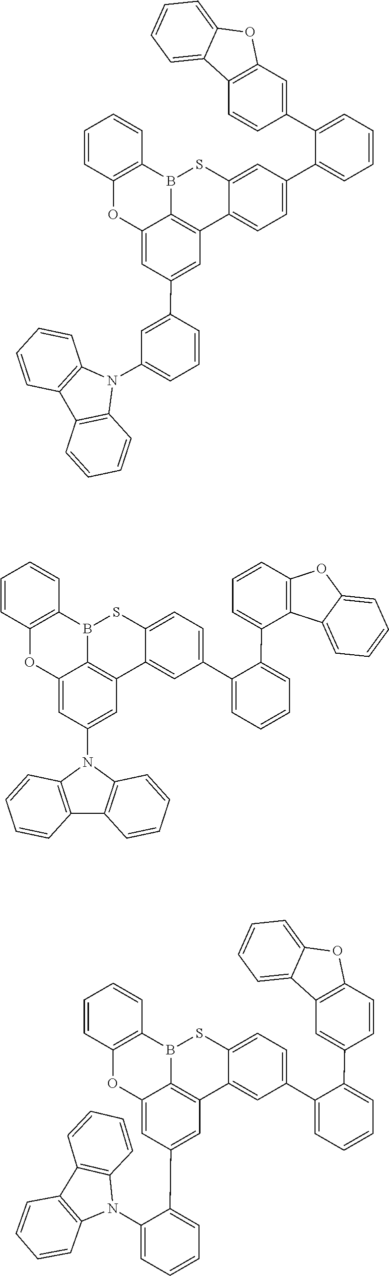 [SMILES: c1cc(-c2cc3c4c(c2)-c2ccc(-c5ccccc5-c5ccc6c(c5)oc5ccccc56)cc2SB4c2ccccc2O3)cc(-n2c3ccccc3c3ccccc32)c1 ; c1ccc2c(c1)Oc1cc(-n3c4ccccc4c4ccccc43)cc3c1B2Sc1ccc(-c2ccccc2-c2cccc4oc5ccccc5c24)cc1-3 ; c1ccc2c(c1)Oc1cc(-c3ccccc3-n3c4ccccc4c4ccccc43)cc3c1B2Sc1ccc(-c2ccccc2-c2ccc4oc5ccccc5c4c2)cc1-3]

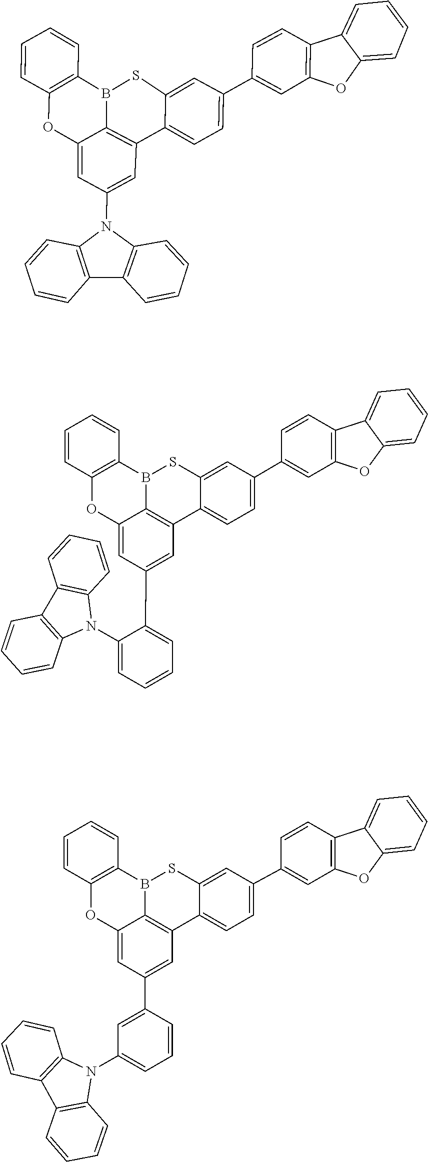 [SMILES: c1ccc2c(c1)Oc1cc(-n3c4ccccc4c4ccccc43)cc3c1B2Sc1cc(-c2ccc4c(c2)oc2ccccc24)ccc1-3 ; c1ccc2c(c1)Oc1cc(-c3ccccc3-n3c4ccccc4c4ccccc43)cc3c1B2Sc1cc(-c2ccc4c(c2)oc2ccccc24)ccc1-3 ; c1cc(-c2cc3c4c(c2)-c2ccc(-c5ccc6c(c5)oc5ccccc56)cc2SB4c2ccccc2O3)cc(-n2c3ccccc3c3ccccc32)c1]

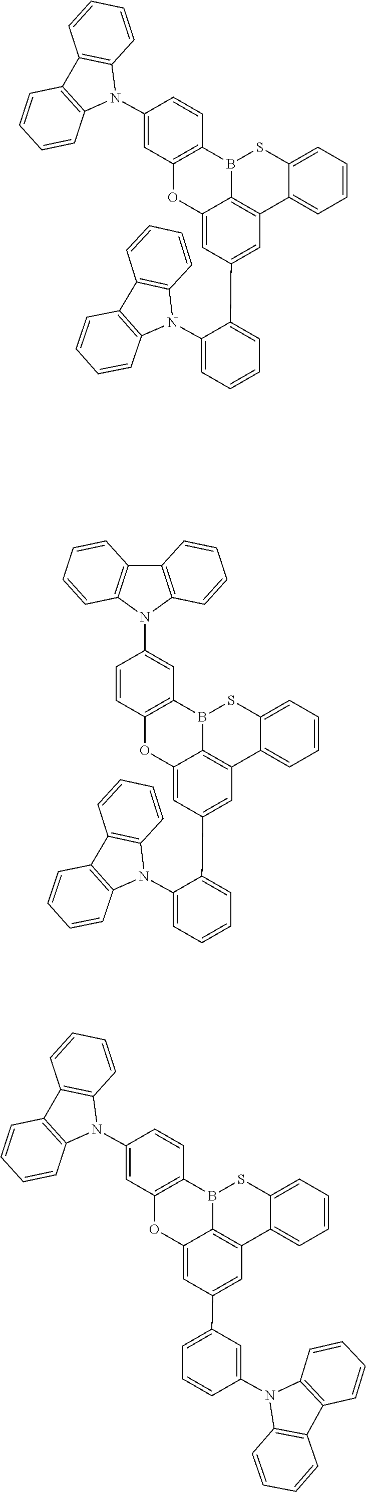 [SMILES: c1ccc2c(c1)SB1c3ccc(-n4c5ccccc5c5ccccc54)cc3Oc3cc(-c4ccccc4-n4c5ccccc5c5ccccc54)cc-2c31 ; c1ccc2c(c1)SB1c3cc(-n4c5ccccc5c5ccccc54)ccc3Oc3cc(-c4ccccc4-n4c5ccccc5c5ccccc54)cc-2c31 ; c1cc(-c2cc3c4c(c2)-c2ccccc2SB4c2ccc(-n4c5ccccc5c5ccccc54)cc2O3)cc(-n2c3ccccc3c3ccccc32)c1]

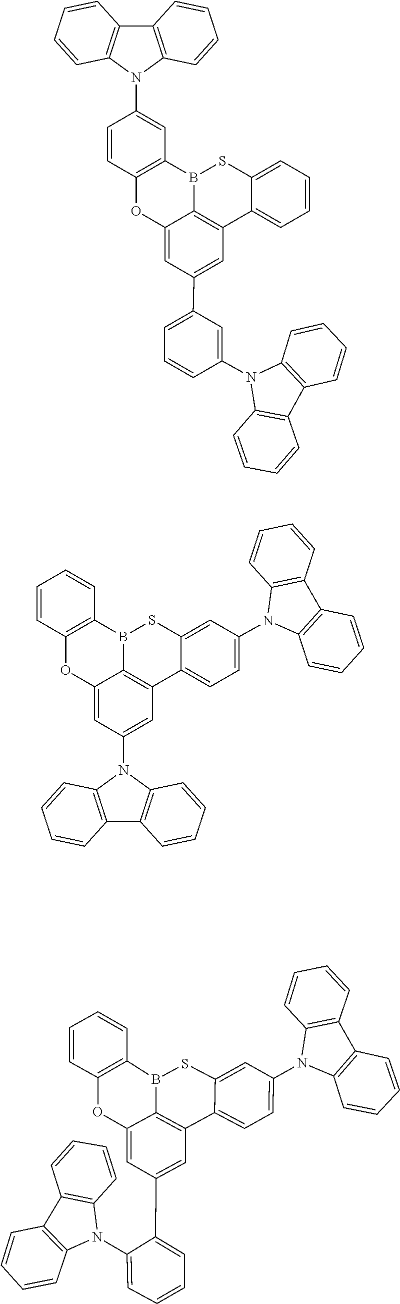 [SMILES: c1cc(-c2cc3c4c(c2)-c2ccccc2SB4c2cc(-n4c5ccccc5c5ccccc54)ccc2O3)cc(-n2c3ccccc3c3ccccc32)c1 ; c1ccc2c(c1)Oc1cc(-n3c4ccccc4c4ccccc43)cc3c1B2Sc1cc(-n2c4ccccc4c4ccccc42)ccc1-3 ; c1ccc2c(c1)Oc1cc(-c3ccccc3-n3c4ccccc4c4ccccc43)cc3c1B2Sc1cc(-n2c4ccccc4c4ccccc42)ccc1-3]

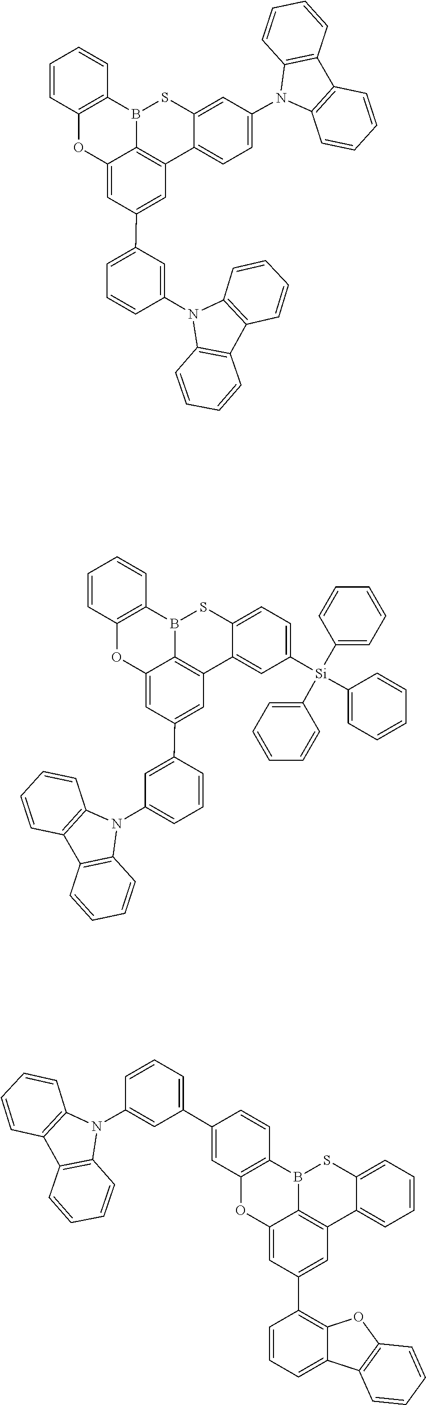 [SMILES: c1cc(-c2cc3c4c(c2)-c2ccc(-n5c6ccccc6c6ccccc65)cc2SB4c2ccccc2O3)cc(-n2c3ccccc3c3ccccc32)c1 ; c1ccc([Si](c2ccccc2)(c2ccccc2)c2ccc3c(c2)-c2cc(-c4cccc(-n5c6ccccc6c6ccccc65)c4)cc4c2B(S3)c2ccccc2O4)cc1 ; c1cc(-c2ccc3c(c2)Oc2cc(-c4cccc5c4oc4ccccc45)cc4c2B3Sc2ccccc2-4)cc(-n2c3ccccc3c3ccccc32)c1]

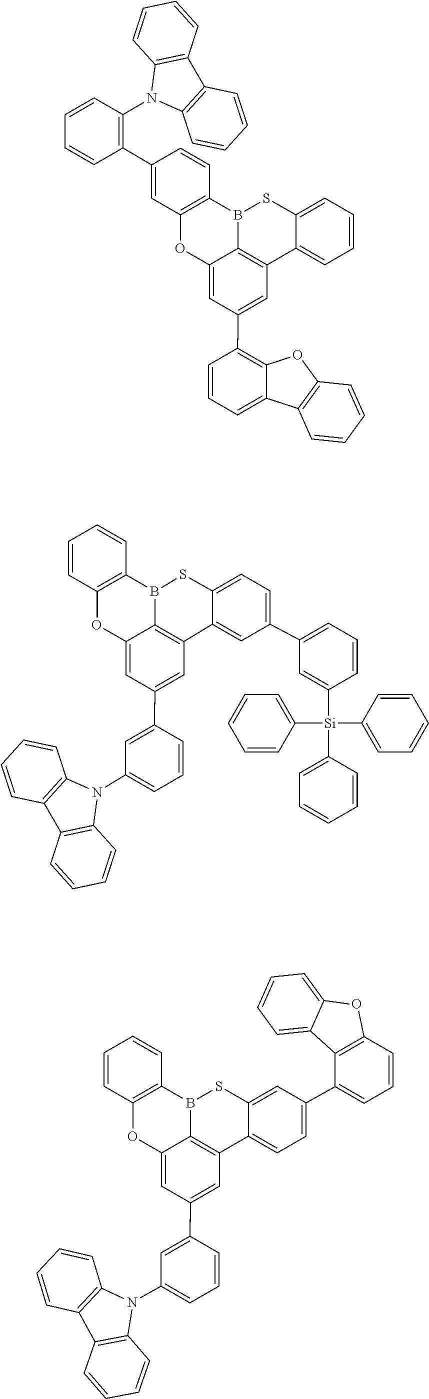

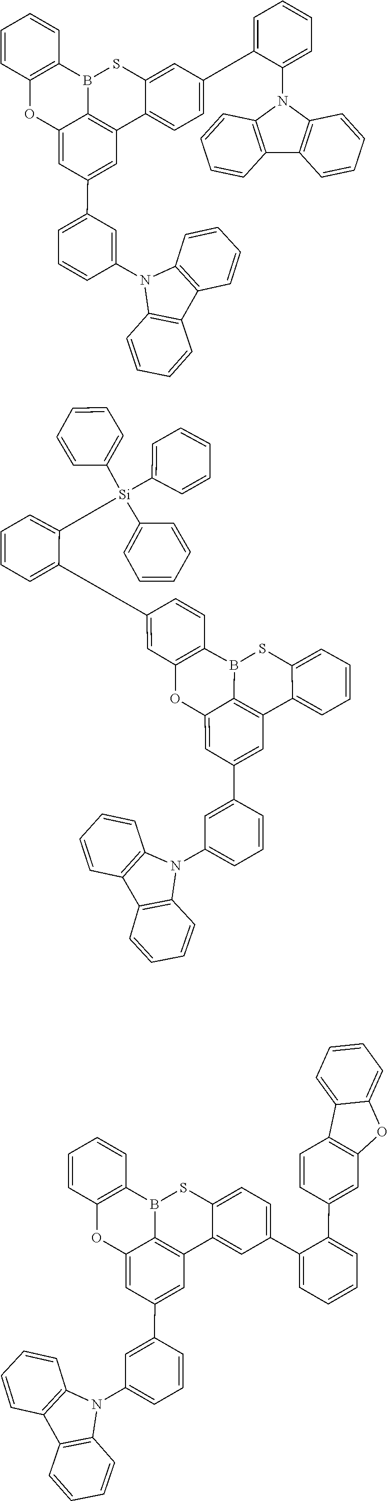 [SMILES: c1cc(-c2cc3c4c(c2)-c2ccc(-c5ccccc5-n5c6ccccc6c6ccccc65)cc2SB4c2ccccc2O3)cc(-n2c3ccccc3c3ccccc32)c1 ; c1ccc([Si](c2ccccc2)(c2ccccc2)c2ccccc2-c2ccc3c(c2)Oc2cc(-c4cccc(-n5c6ccccc6c6ccccc65)c4)cc4c2B3Sc2ccccc2-4)cc1 ; c1cc(-c2cc3c4c(c2)-c2cc(-c5ccccc5-c5ccc6c(c5)oc5ccccc56)ccc2SB4c2ccccc2O3)cc(-n2c3ccccc3c3ccccc32)c1]

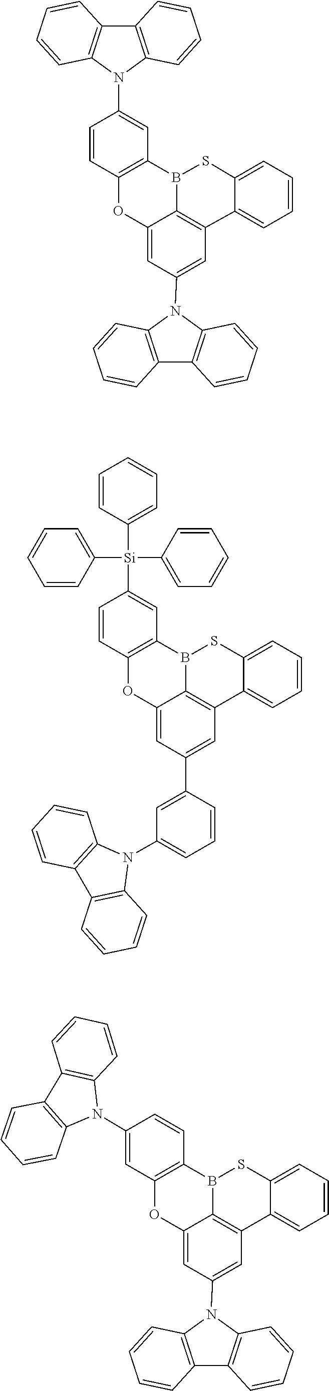

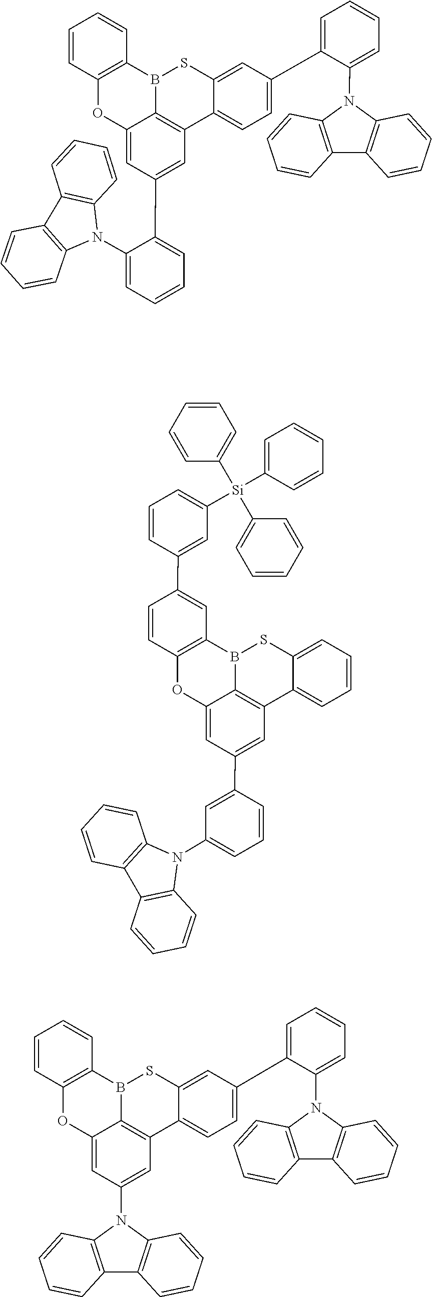 [SMILES: c1ccc2c(c1)Oc1cc(-c3ccccc3-n3c4ccccc4c4ccccc43)cc3c1B2Sc1cc(-c2ccccc2-n2c4ccccc4c4ccccc42)ccc1-3 ; c1ccc([Si](c2ccccc2)(c2ccccc2)c2cccc(-c3ccc4c(c3)B3Sc5ccccc5-c5cc(-c6cccc(-n7c8ccccc8c8ccccc87)c6)cc(c53)O4)c2)cc1 ; c1ccc2c(c1)Oc1cc(-n3c4ccccc4c4ccccc43)cc3c1B2Sc1cc(-c2ccccc2-n2c4ccccc4c4ccccc42)ccc1-3]

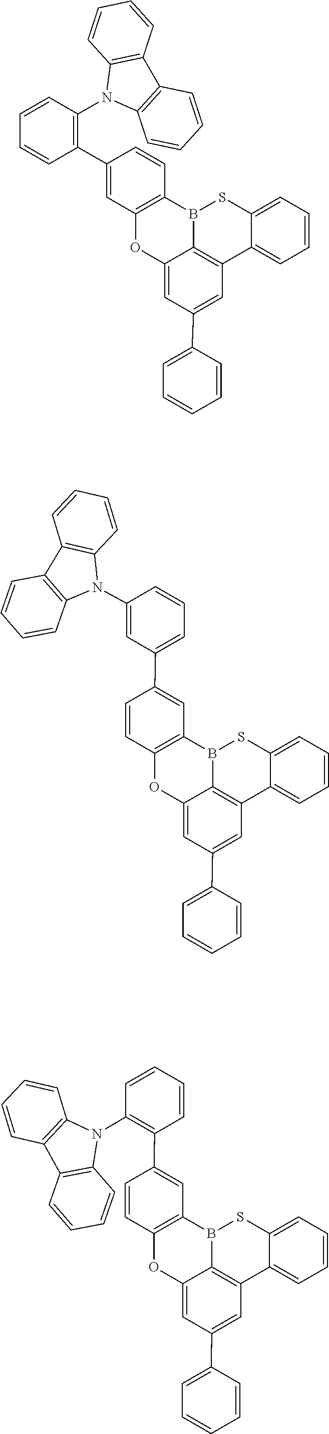 [SMILES: c1ccc(-c2cc3c4c(c2)-c2ccccc2SB4c2ccc(-c4ccccc4-n4c5ccccc5c5ccccc54)cc2O3)cc1 ; c1ccc(-c2cc3c4c(c2)-c2ccccc2SB4c2cc(-c4cccc(-n5c6ccccc6c6ccccc65)c4)ccc2O3)cc1 ; c1ccc(-c2cc3c4c(c2)-c2ccccc2SB4c2cc(-c4ccccc4-n4c5ccccc5c5ccccc54)ccc2O3)cc1]

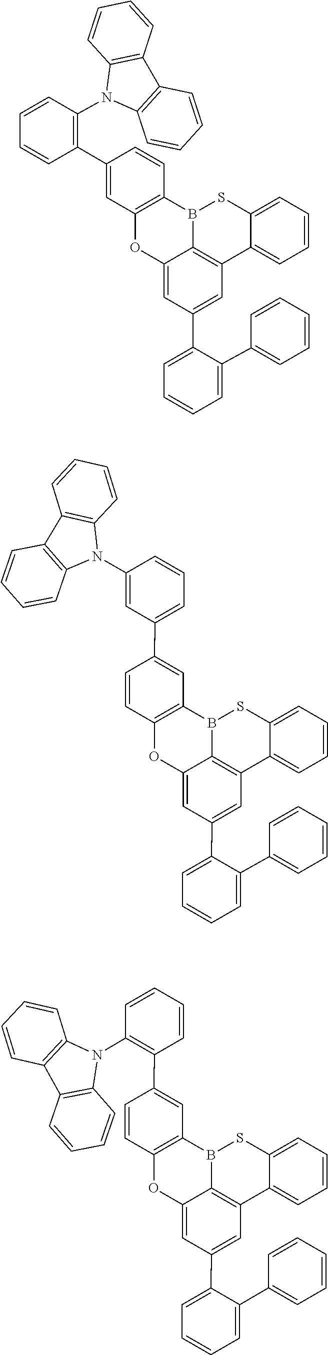 [SMILES: c1ccc(-c2ccccc2-c2cc3c4c(c2)-c2ccccc2SB4c2ccc(-c4ccccc4-n4c5ccccc5c5ccccc54)cc2O3)cc1 ; c1ccc(-c2ccccc2-c2cc3c4c(c2)-c2ccccc2SB4c2cc(-c4cccc(-n5c6ccccc6c6ccccc65)c4)ccc2O3)cc1 ; c1ccc(-c2ccccc2-c2cc3c4c(c2)-c2ccccc2SB4c2cc(-c4ccccc4-n4c5ccccc5c5ccccc54)ccc2O3)cc1]

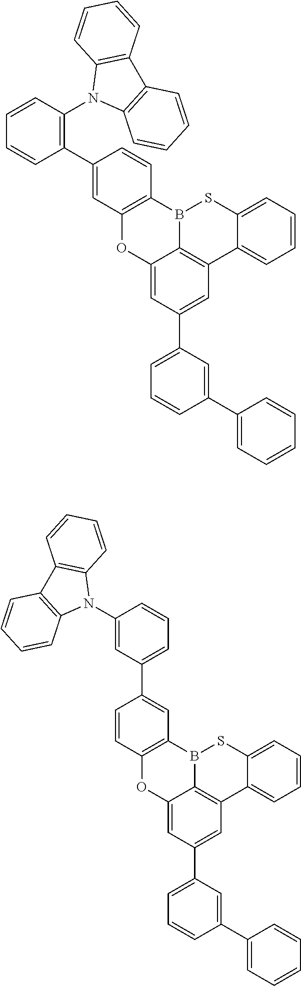 [SMILES: c1ccc(-c2cccc(-c3cc4c5c(c3)-c3ccccc3SB5c3ccc(-c5ccccc5-n5c6ccccc6c6ccccc65)cc3O4)c2)cc1 ; c1ccc(-c2cccc(-c3cc4c5c(c3)-c3ccccc3SB5c3cc(-c5cccc(-n6c7ccccc7c7ccccc76)c5)ccc3O4)c2)cc1]

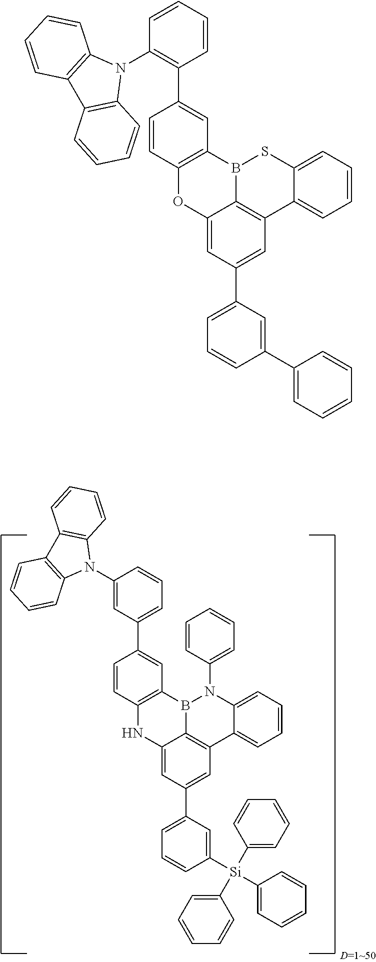

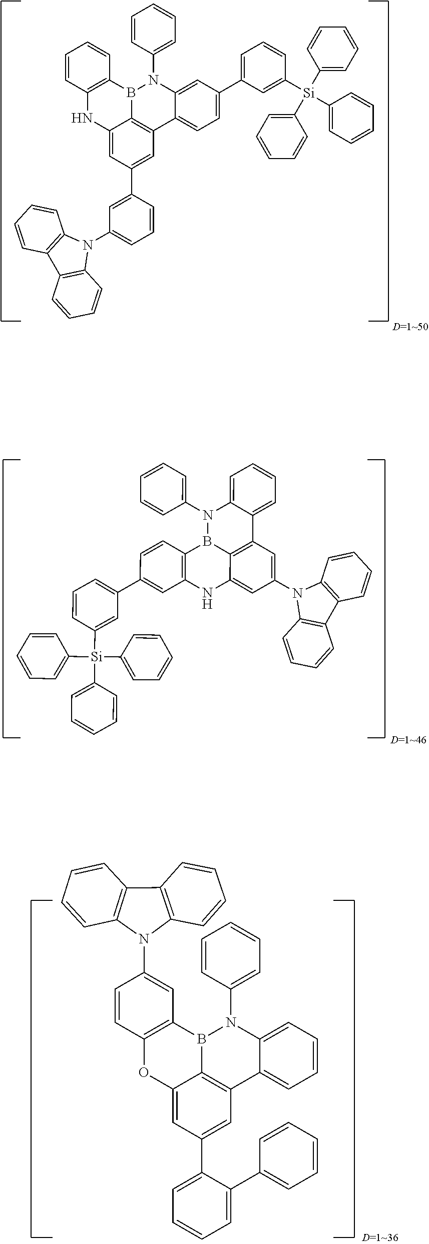

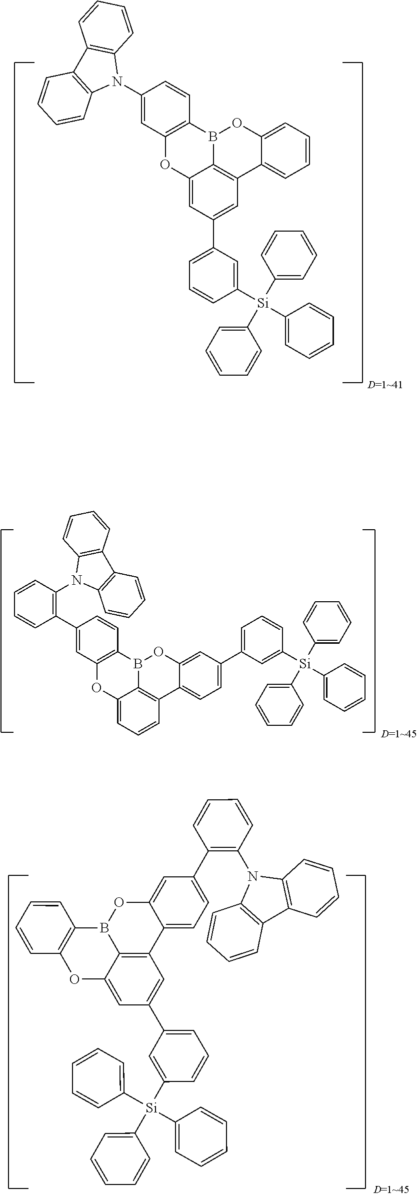

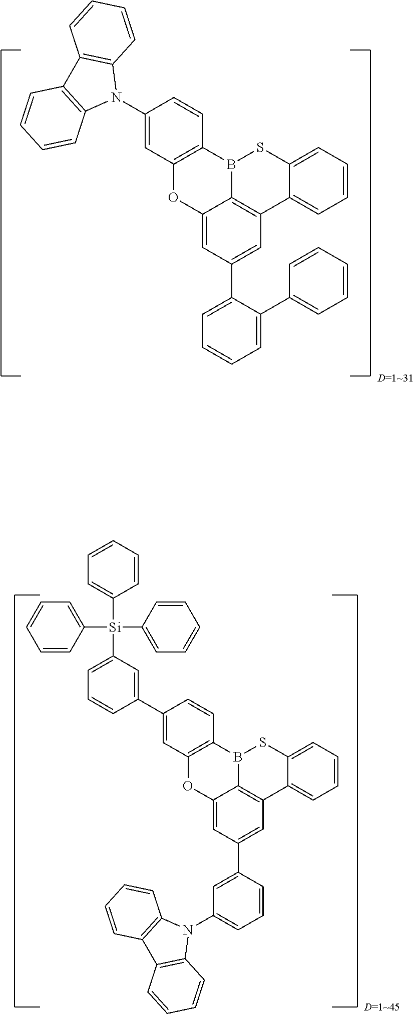

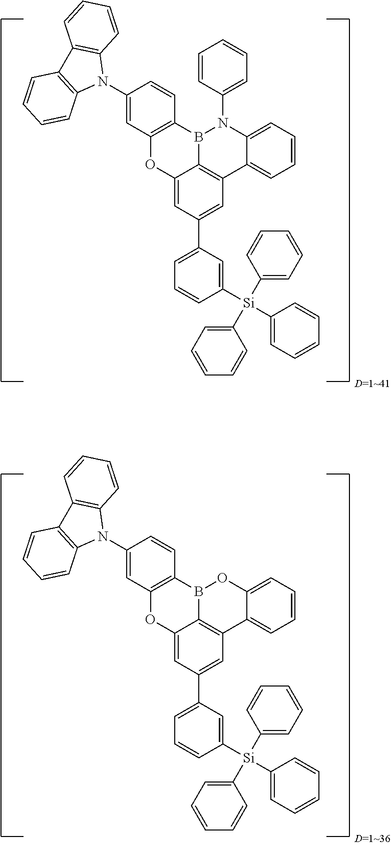

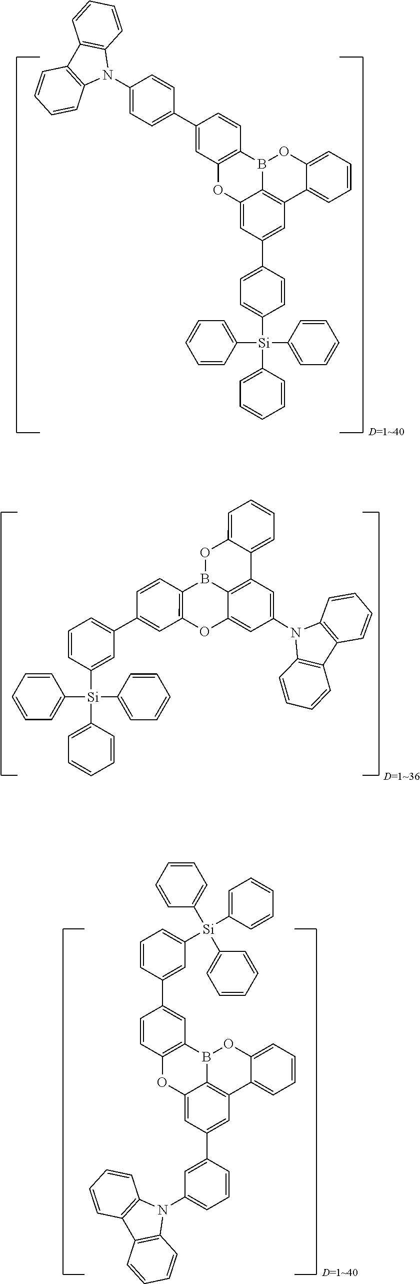

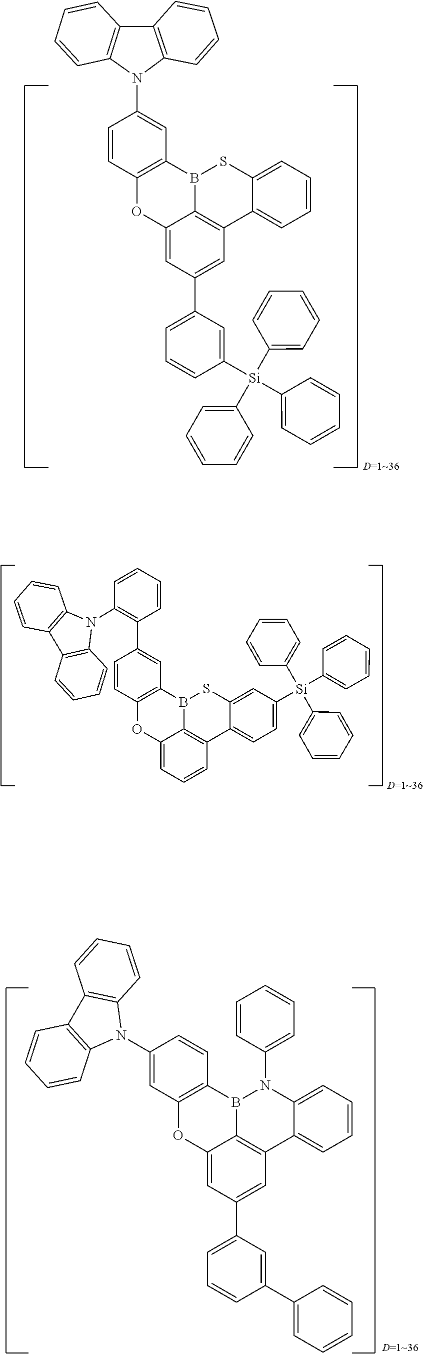

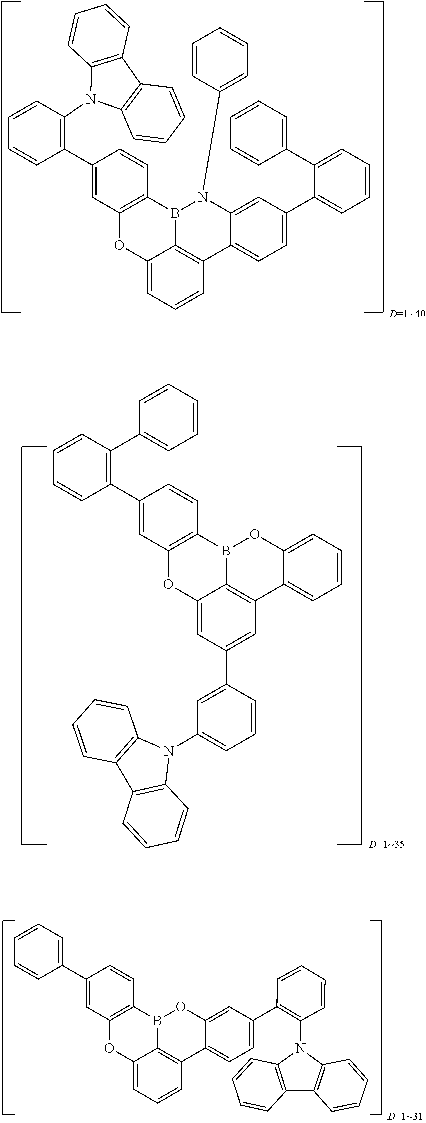

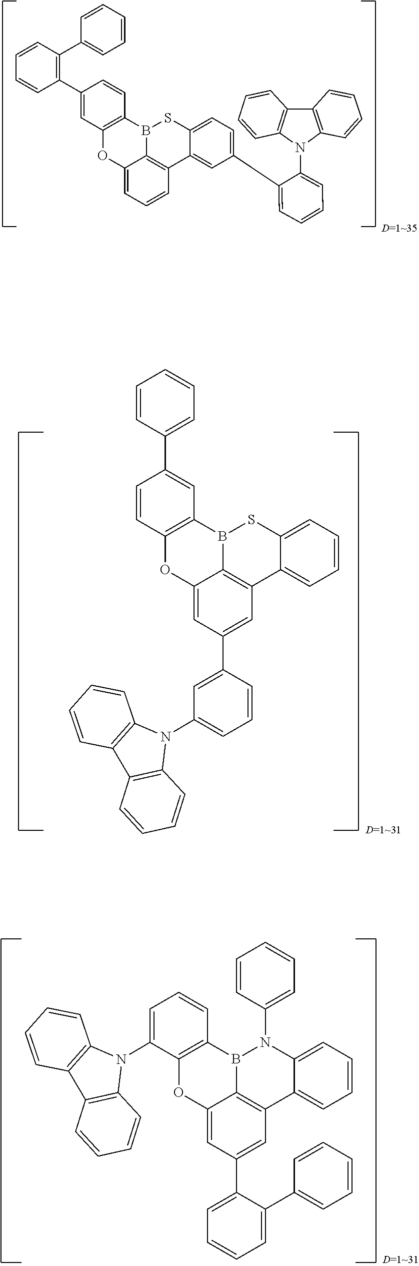

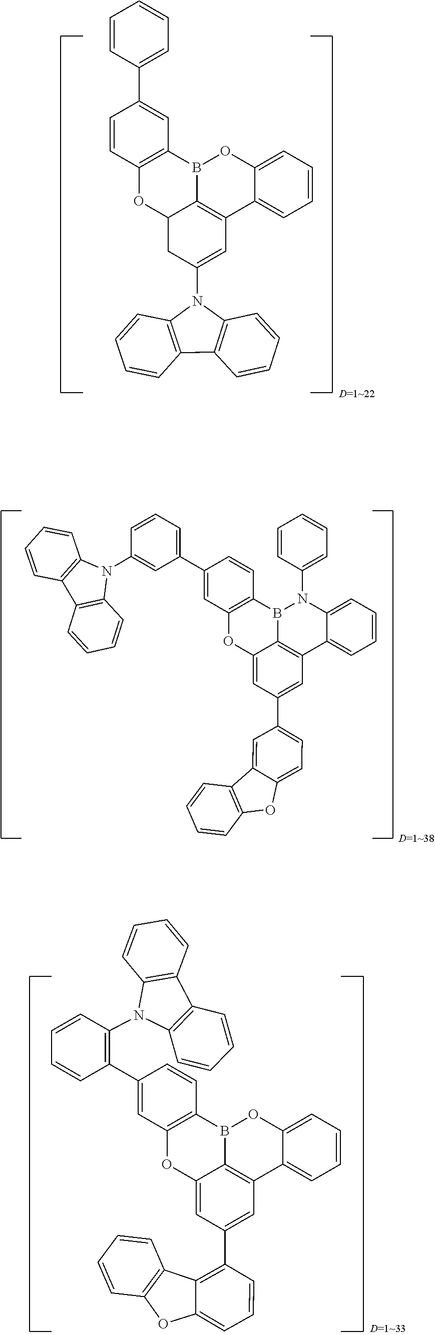

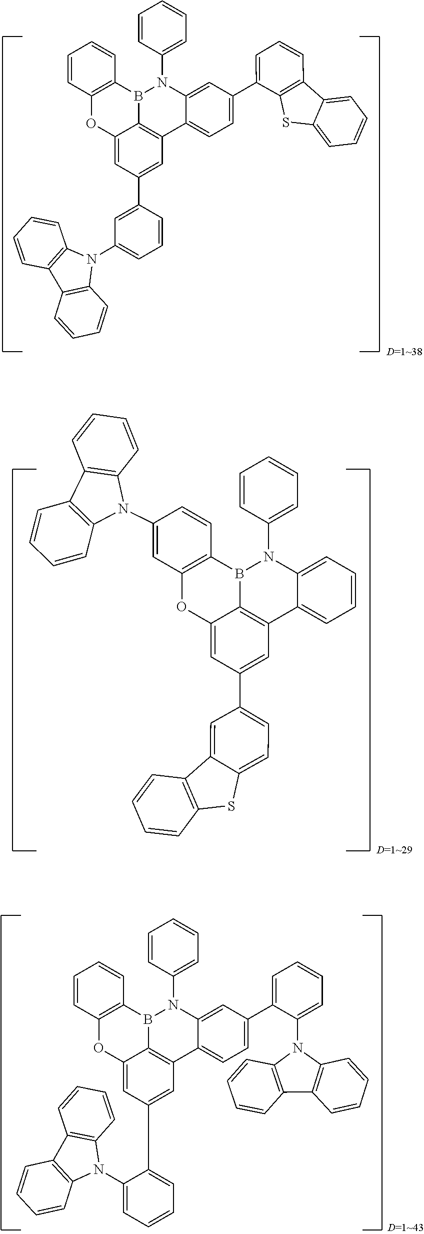

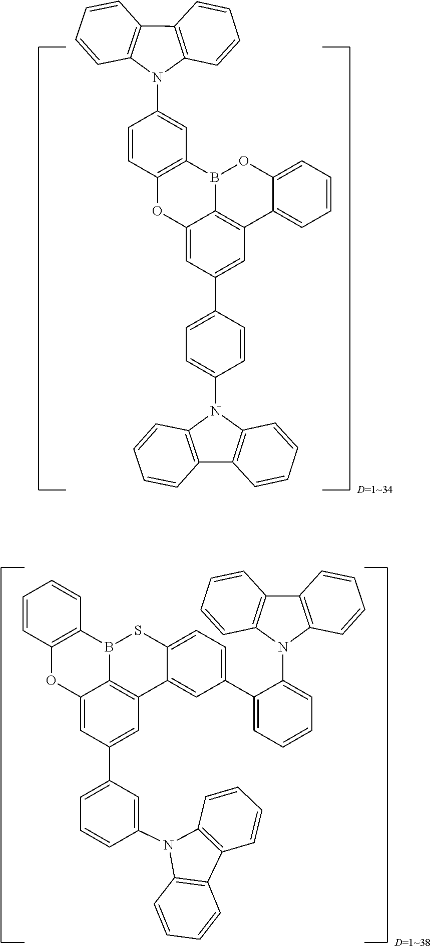

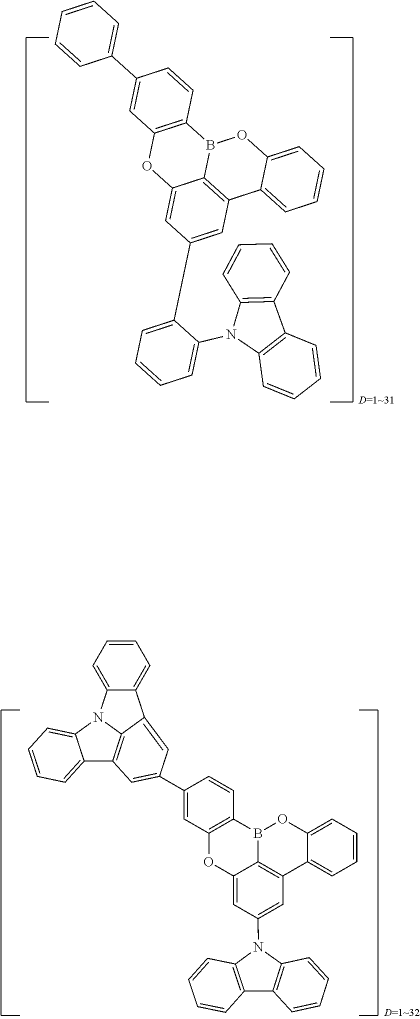

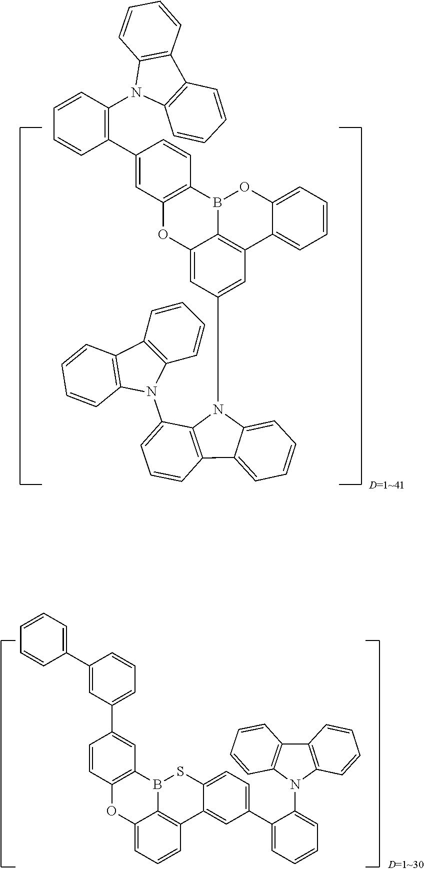

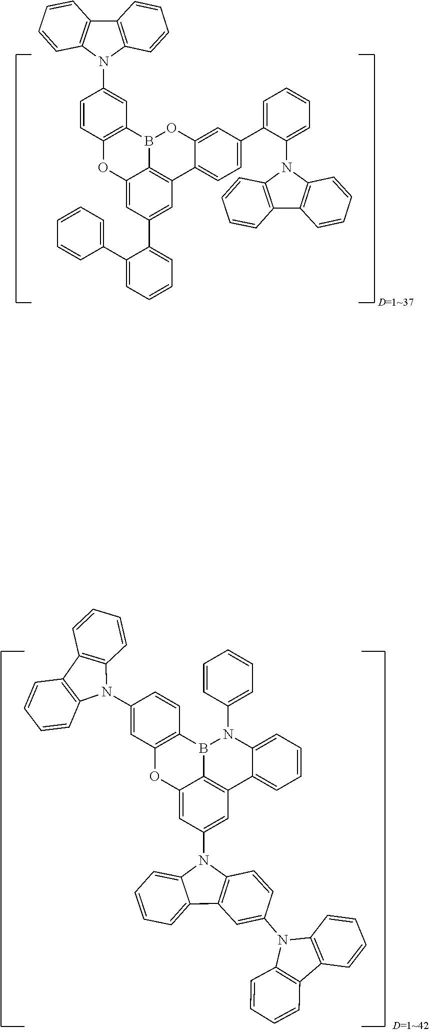

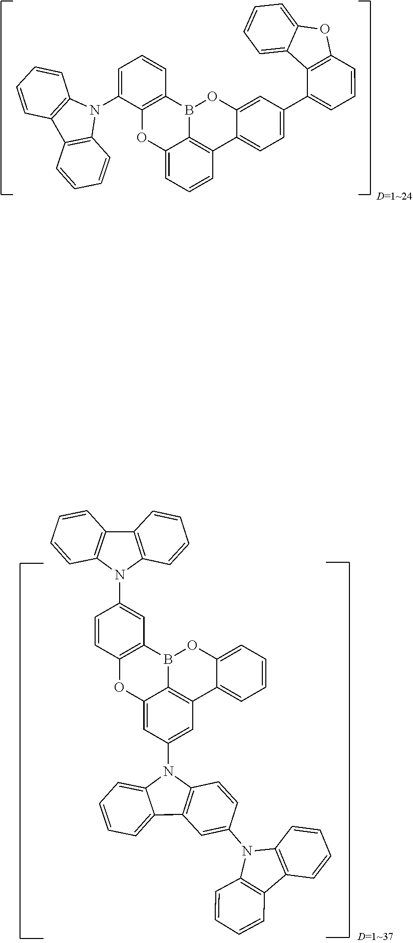

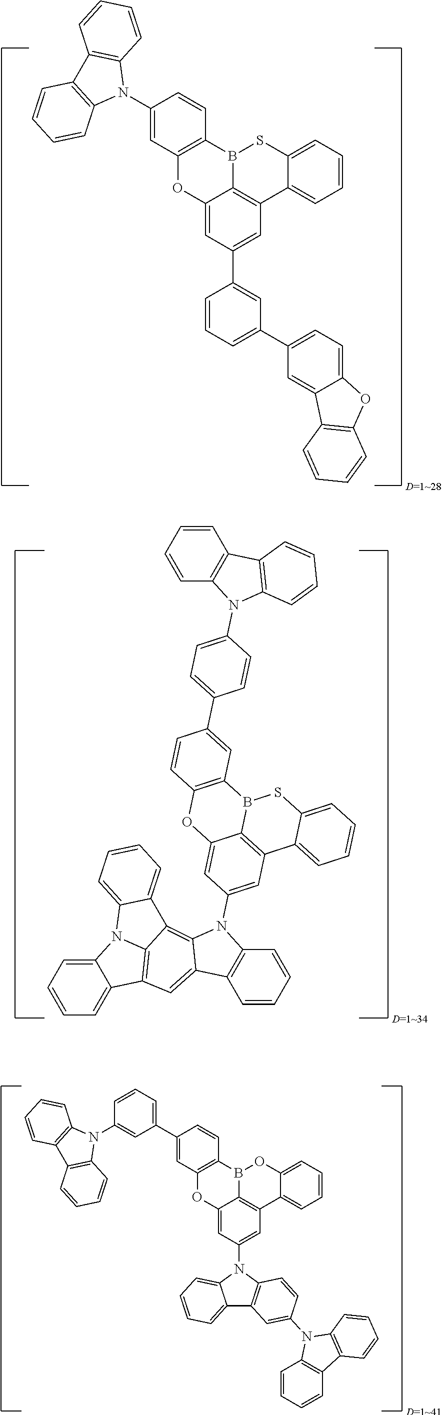

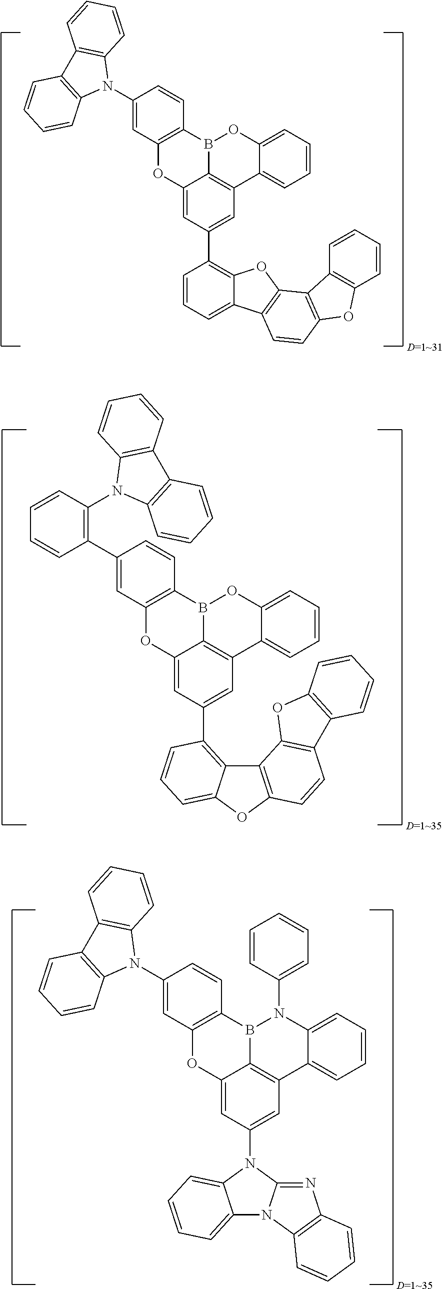

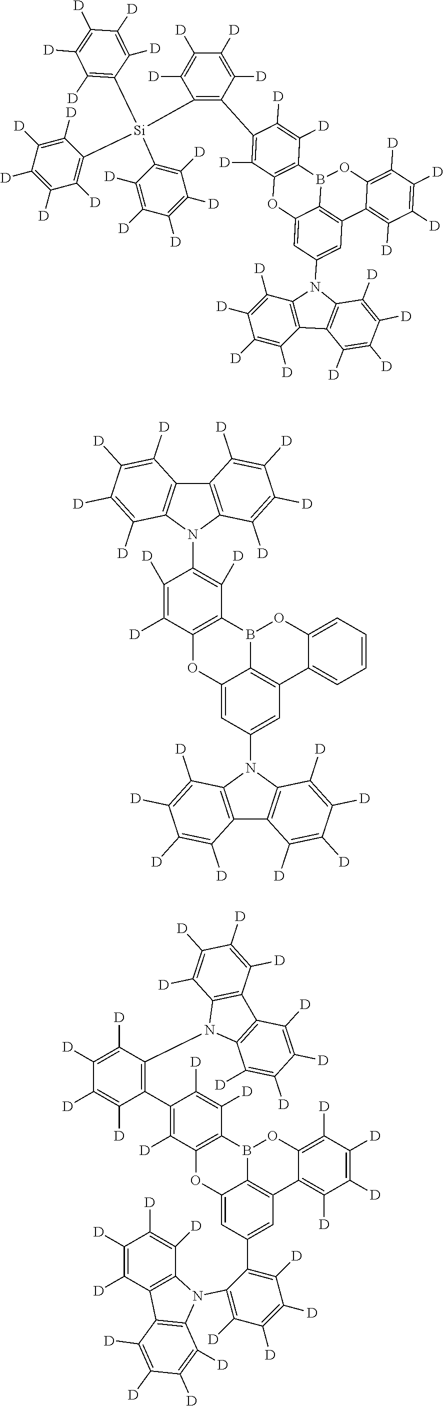

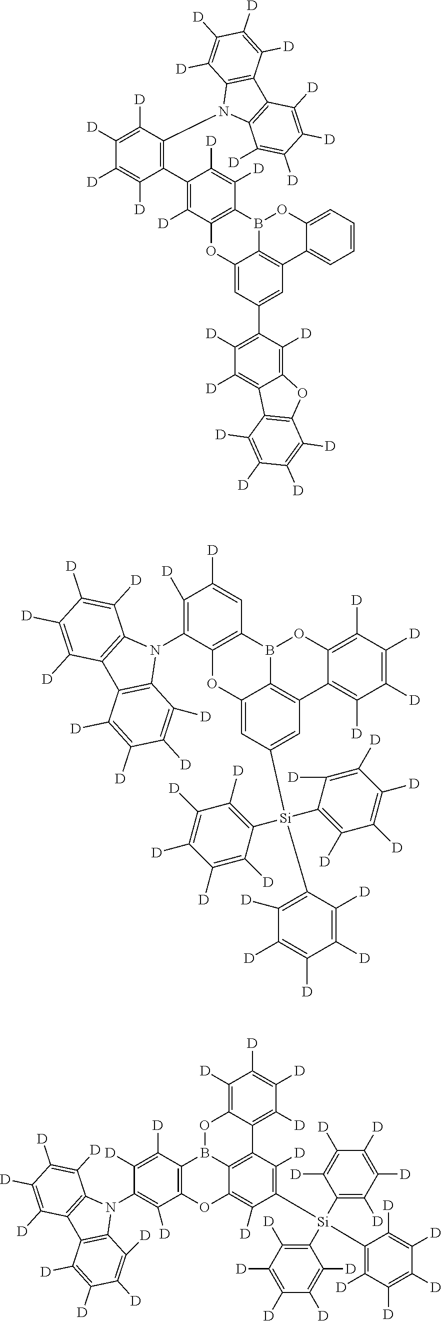

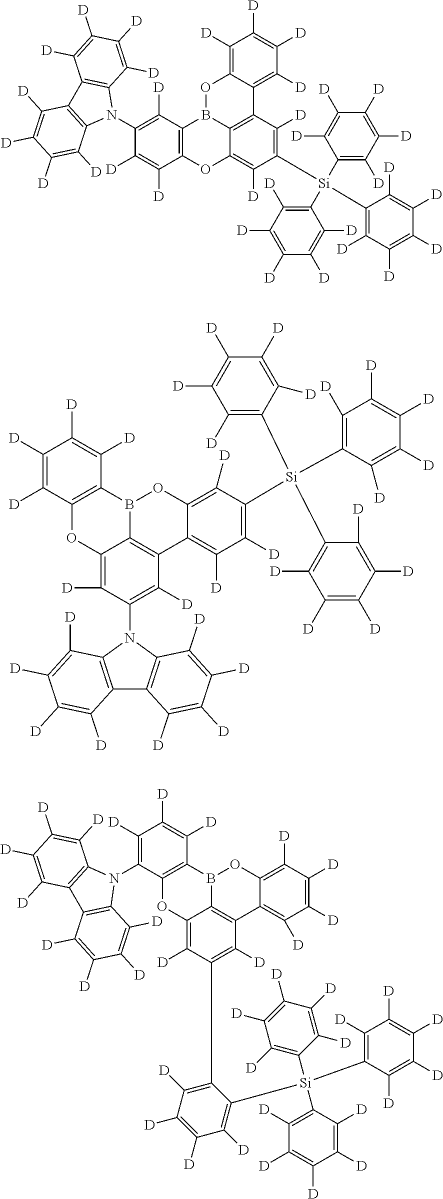

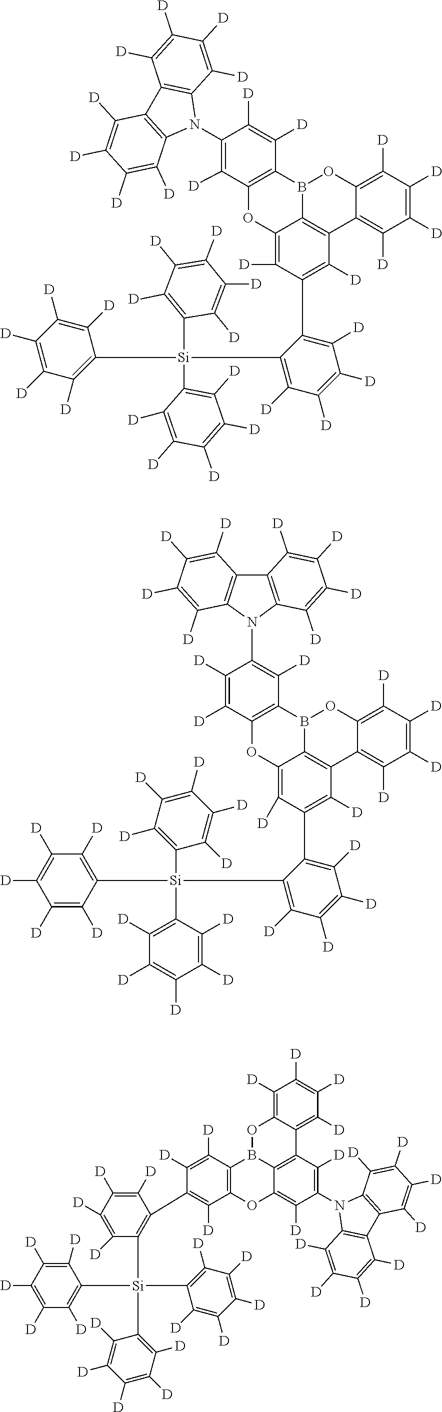

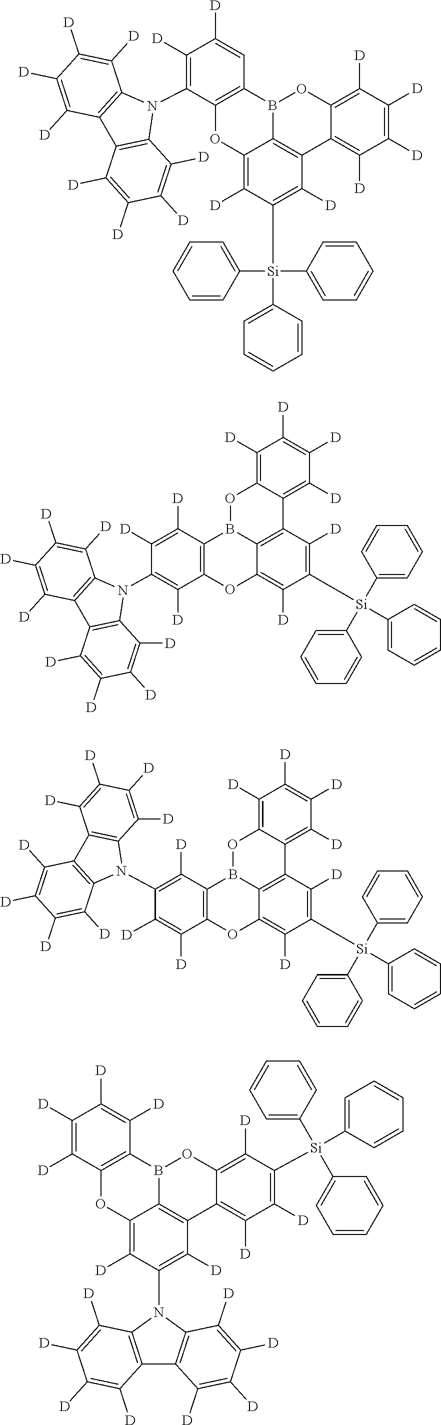

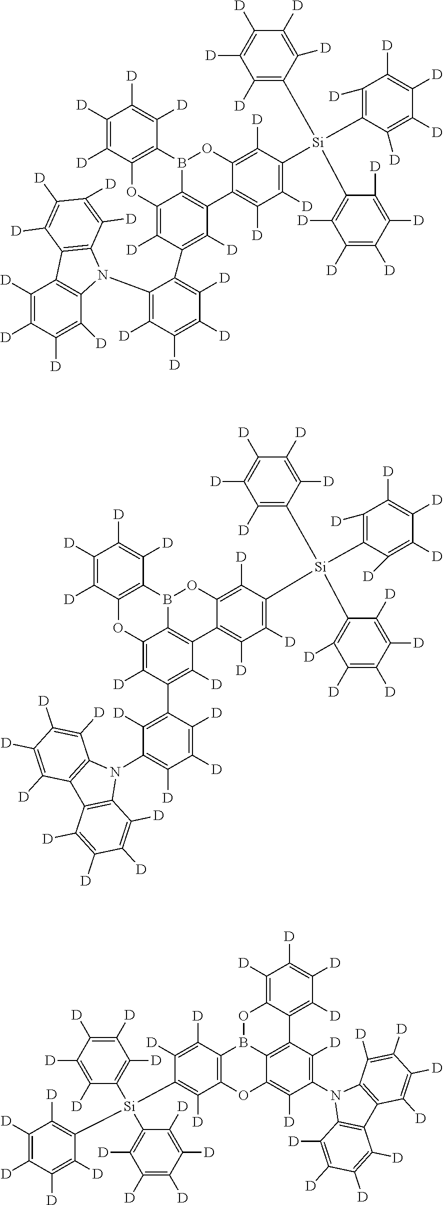

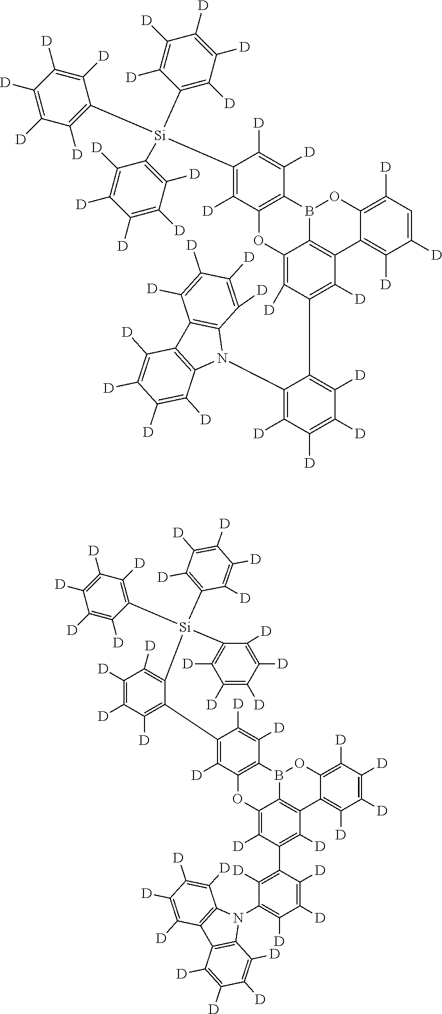

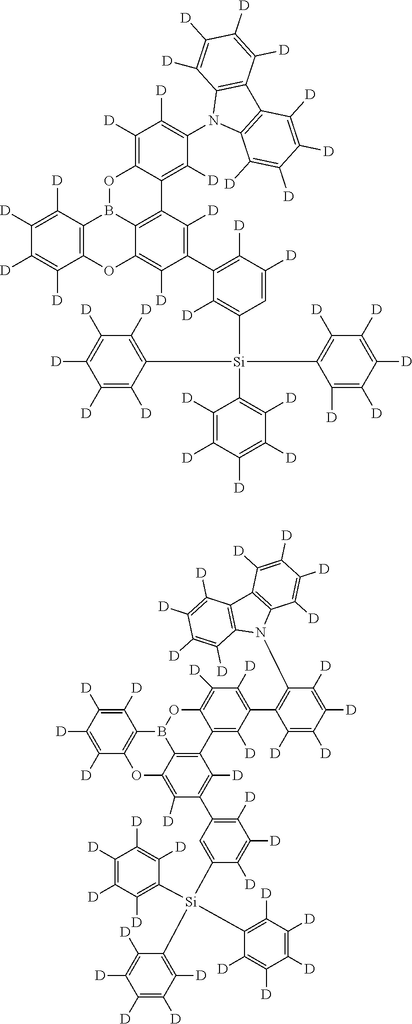

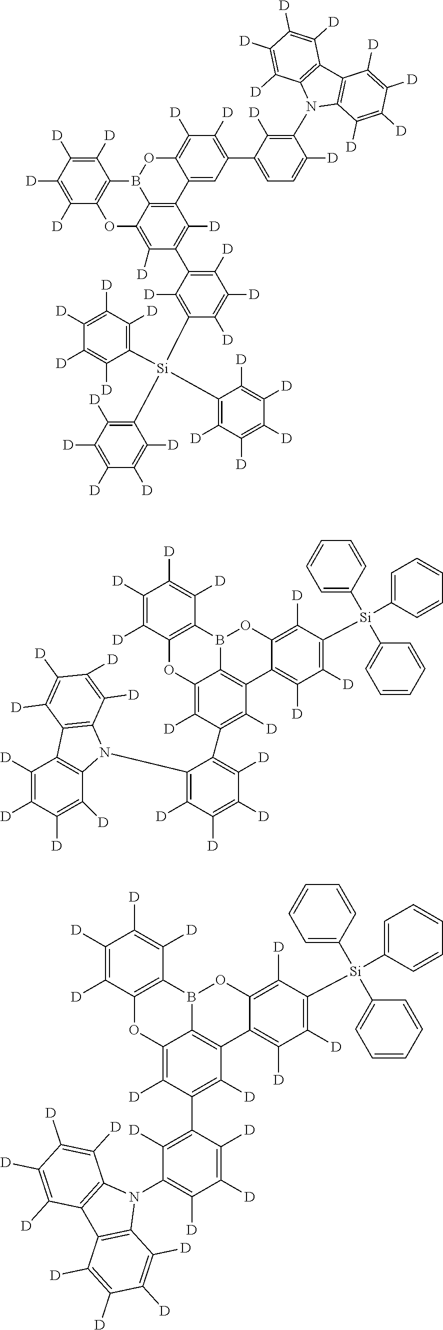

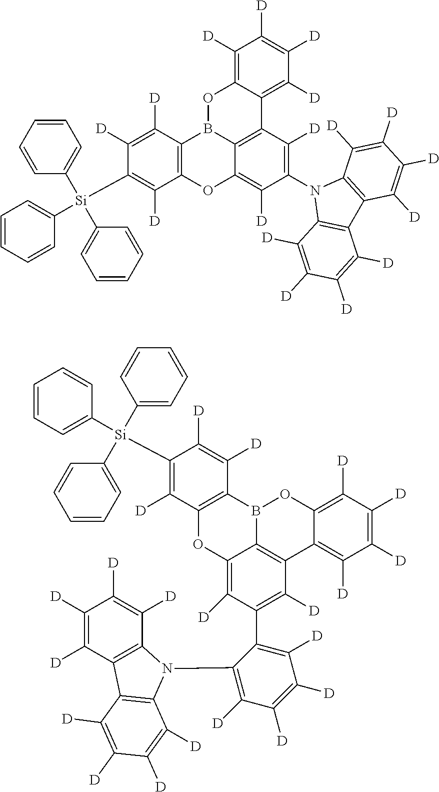 [SMILES: [2H]c1c([2H])c([2H])c2c(c1[2H])OB1c3c([2H])c([2H])c([Si](c4ccccc4)(c4ccccc4)c4ccccc4)c([2H])c3Oc3c([2H])c(-n4c5c([2H])c([2H])c([2H])c([2H])c5c5c([2H])c([2H])c([2H])c([2H])c54)c([2H])c-2c31 ; [2H]c1c([2H])c([2H])c2c(c1[2H])OB1c3c([2H])c([2H])c([Si](c4ccccc4)(c4ccccc4)c4ccccc4)c([2H])c3Oc3c([2H])c(-c4c([2H])c([2H])c([2H])c([2H])c4-n4c5c([2H])c([2H])c([2H])c([2H])c5c5c([2H])c([2H])c([2H])c([2H])c54)c([2H])c-2c31]

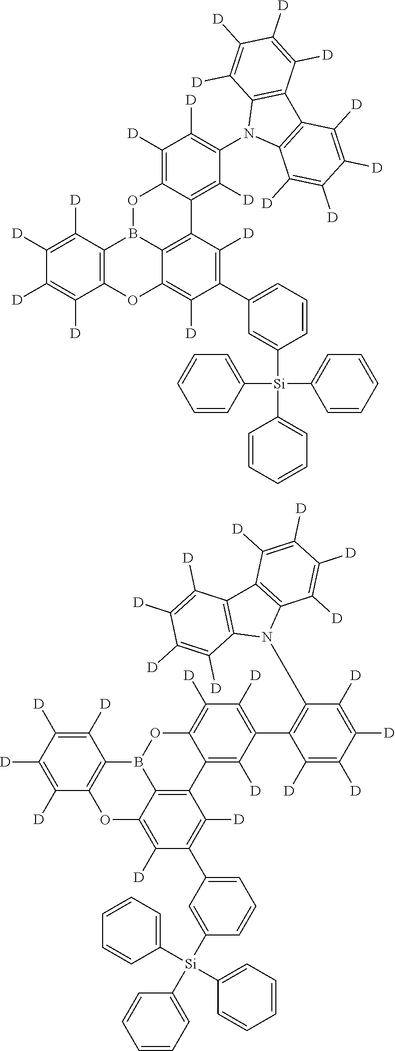

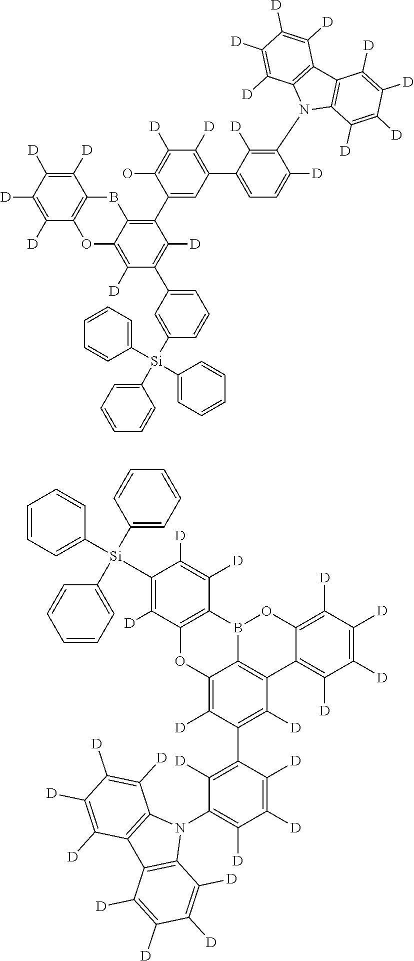

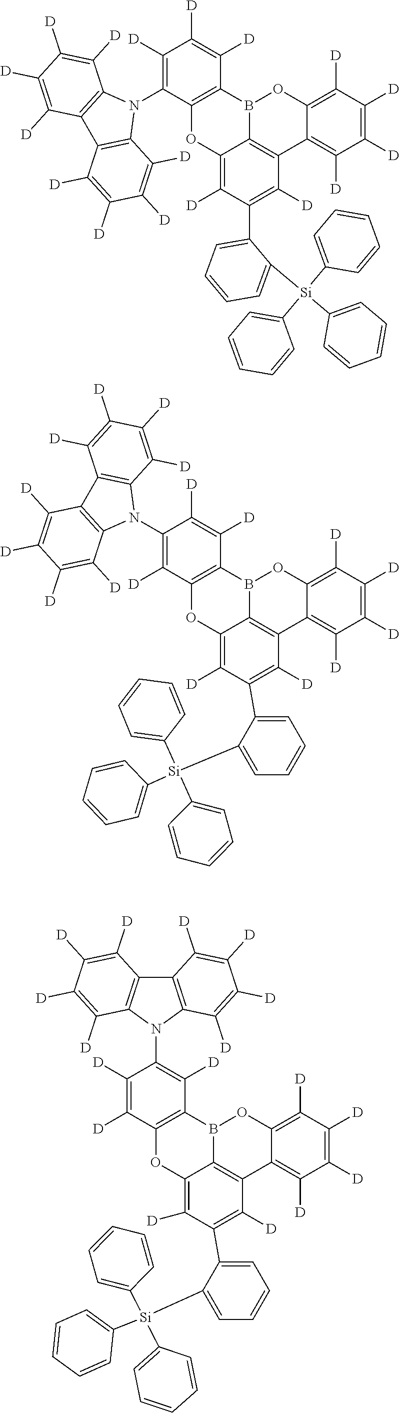

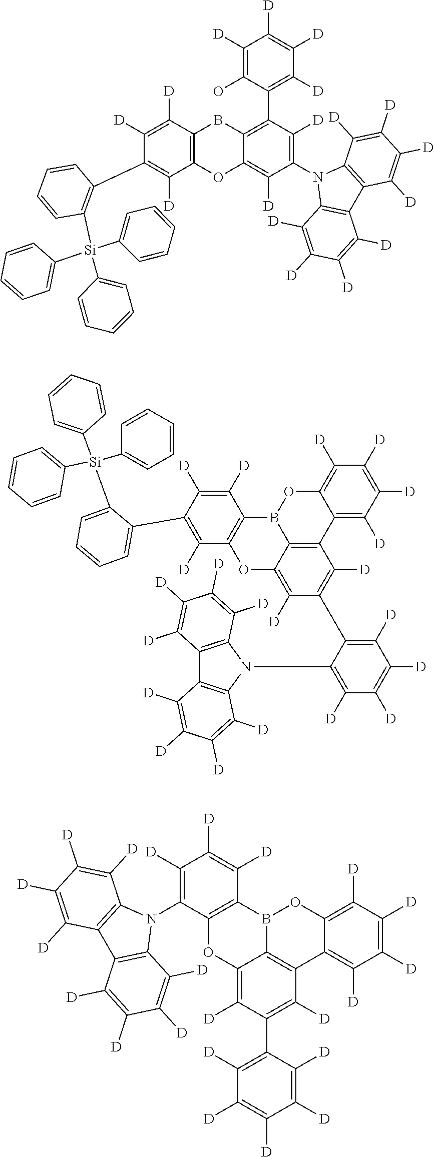

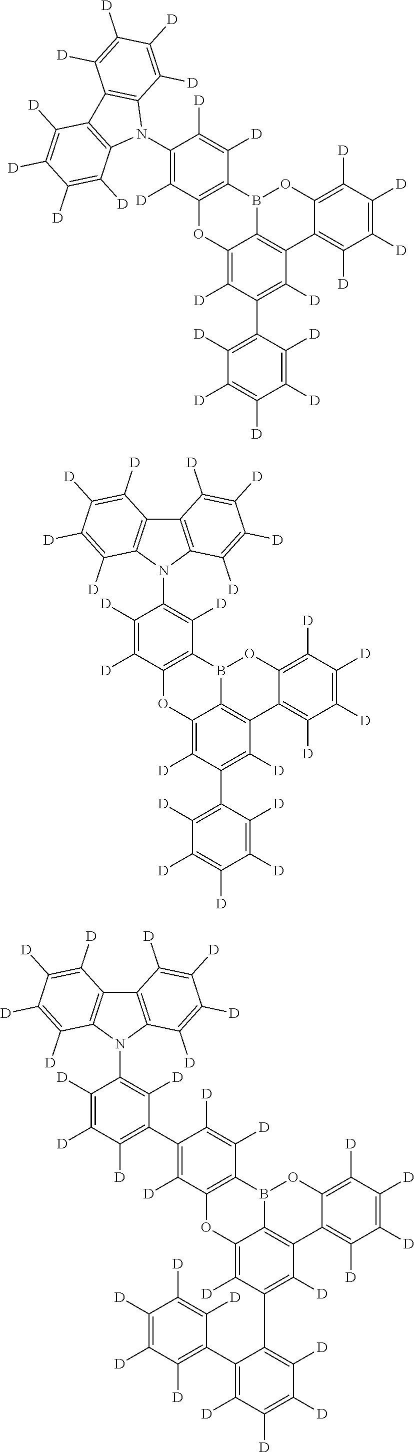

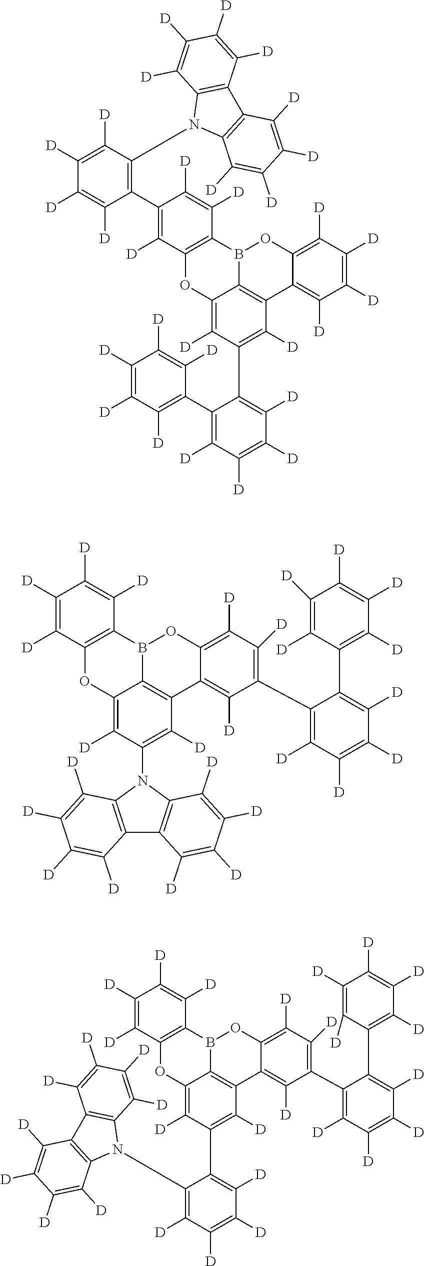

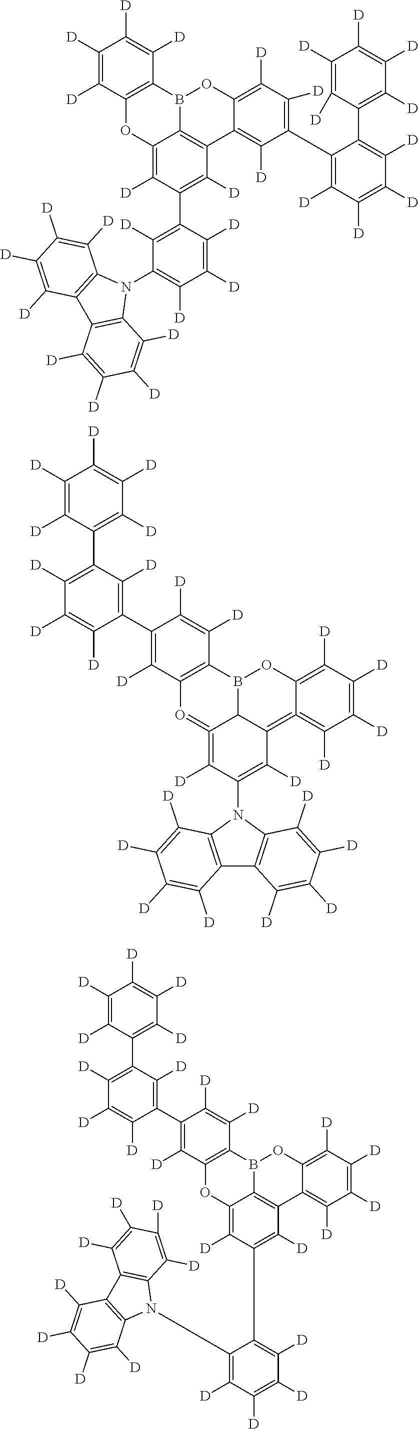

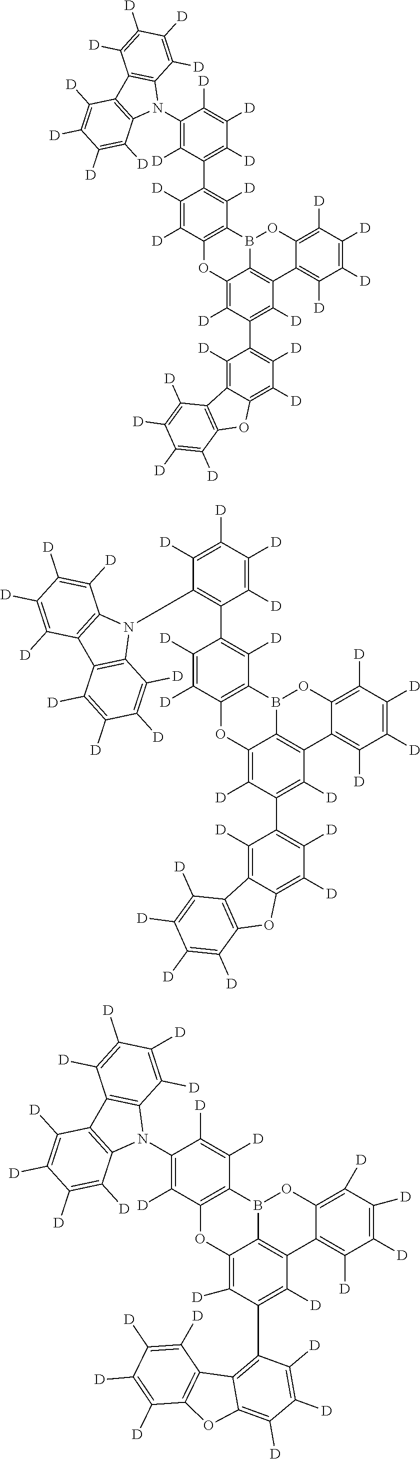

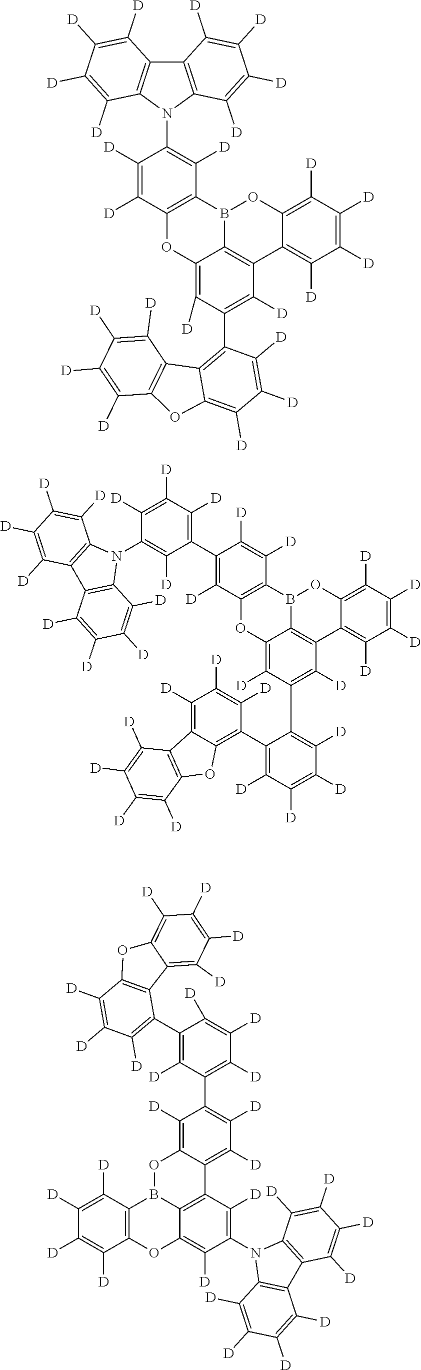

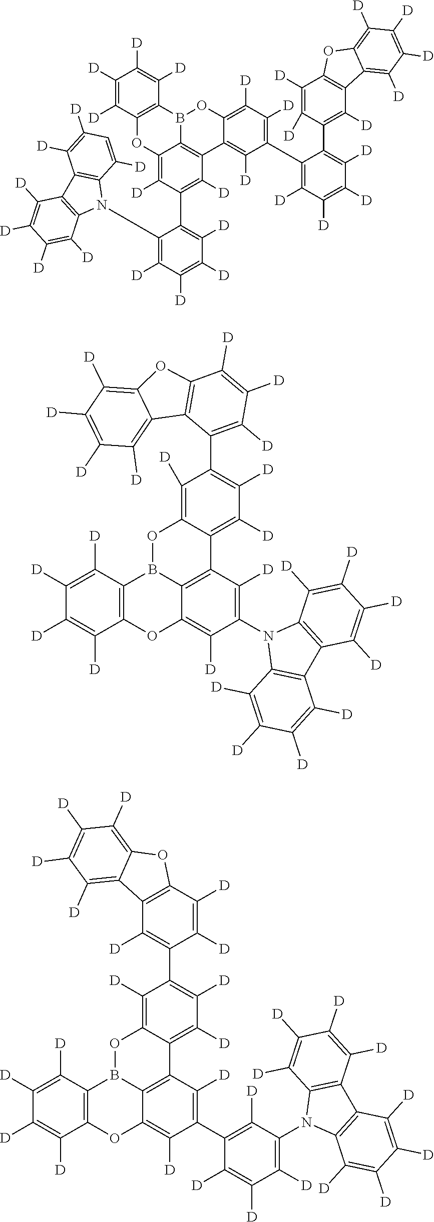

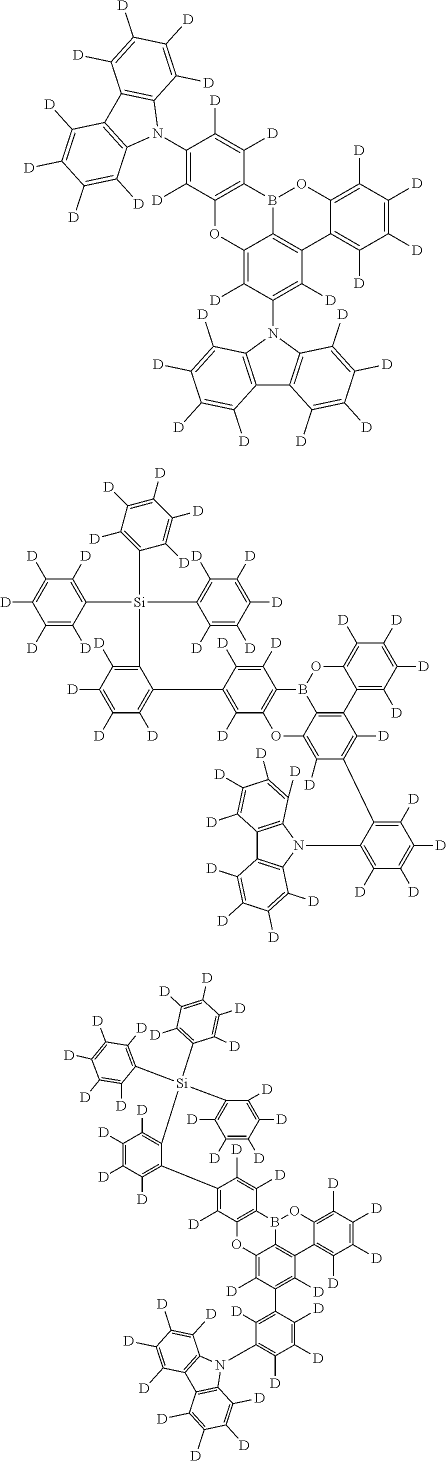

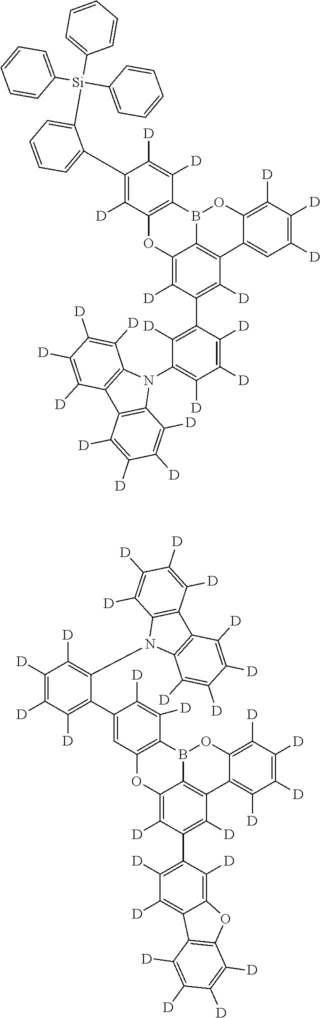

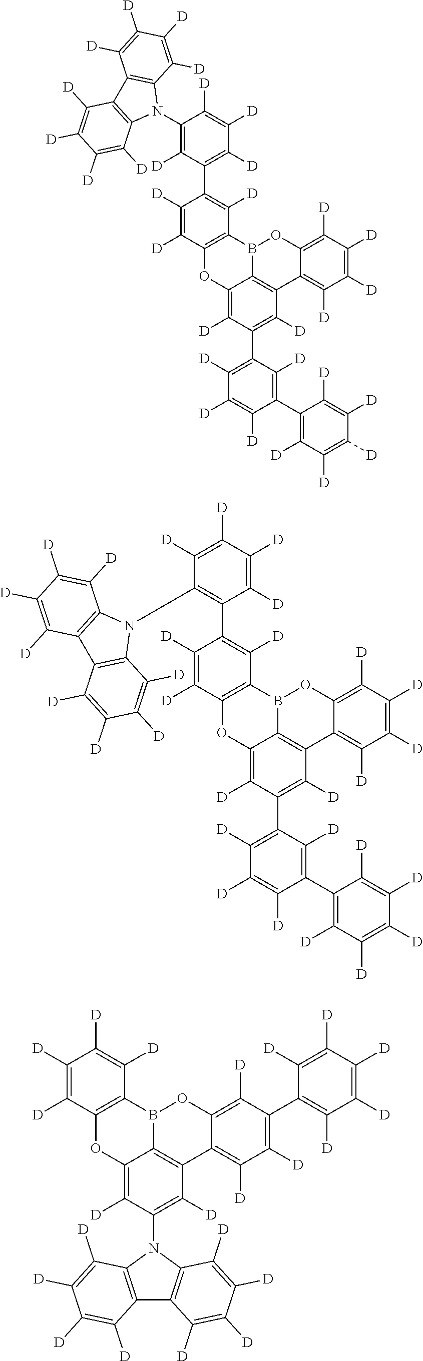

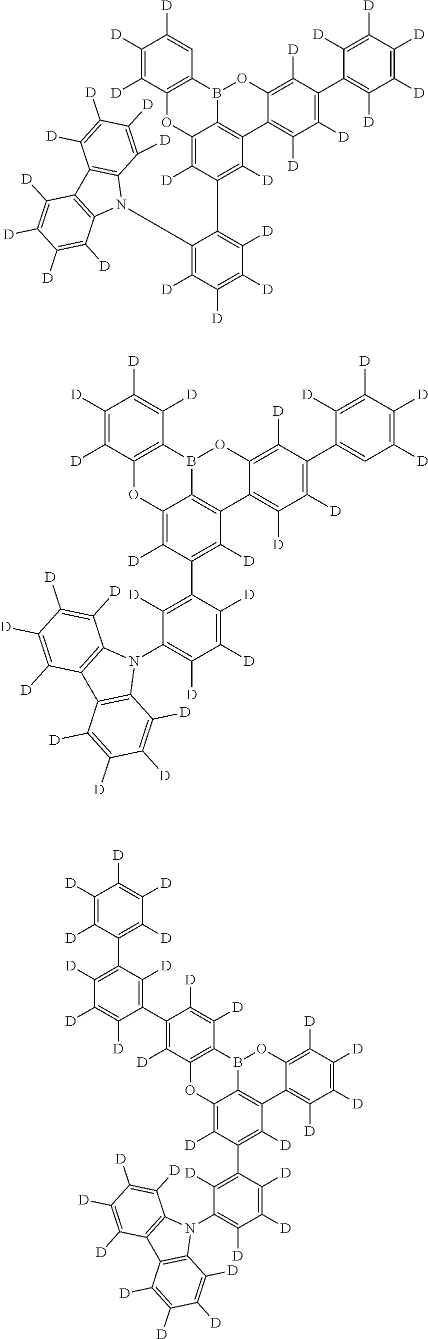

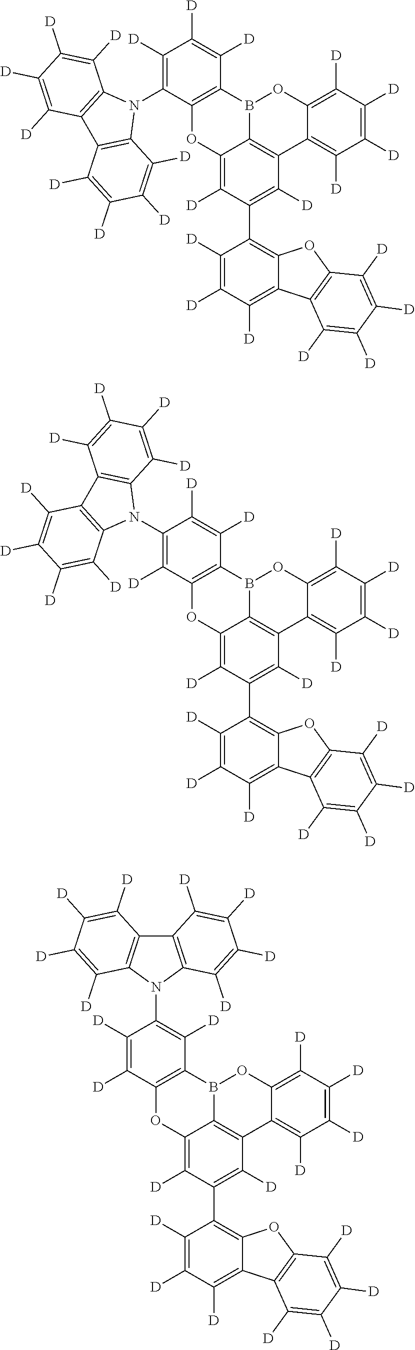

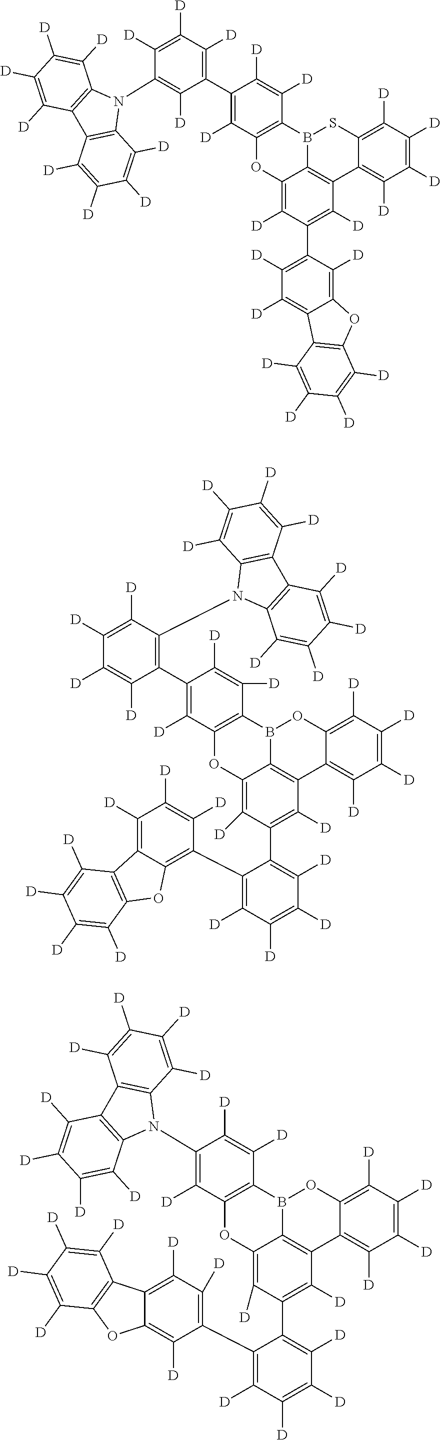

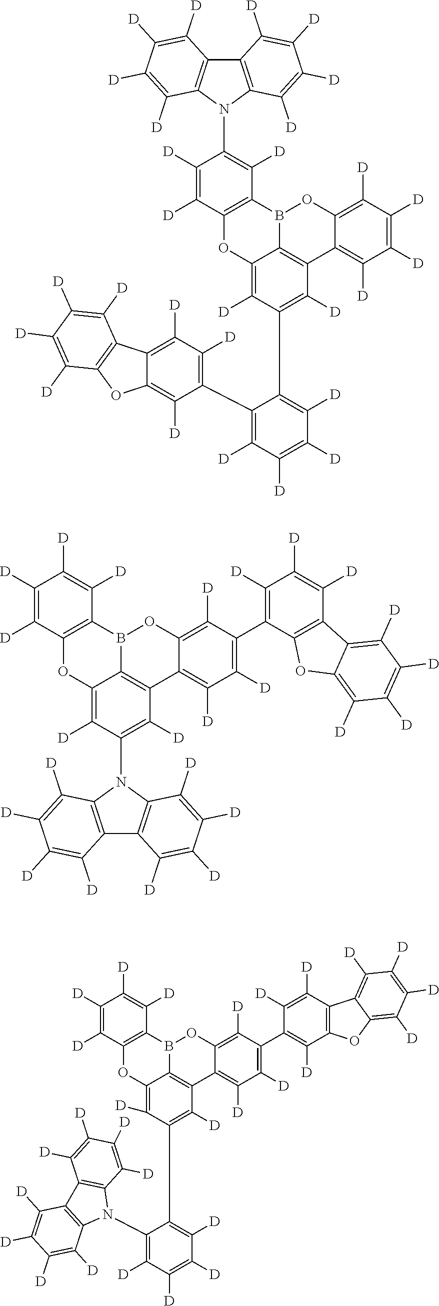

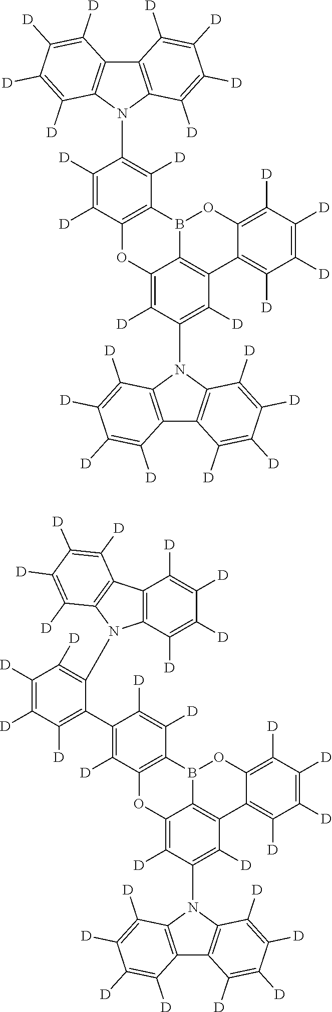 [SMILES: [2H]c1c([2H])c([2H])c2c(c1[2H])OB1c3c([2H])c(-n4c5c([2H])c([2H])c([2H])c([2H])c5c5c([2H])c([2H])c([2H])c([2H])c54)c([2H])c([2H])c3Oc3c([2H])c(-n4c5c([2H])c([2H])c([2H])c([2H])c5c5c([2H])c([2H])c([2H])c([2H])c54)c([2H])c-2c31 ; [2H]c1c([2H])c([2H])c2c(c1[2H])OB1c3c([2H])c([2H])c(-c4c([2H])c([2H])c([2H])c([2H])c4-n4c5c([2H])c([2H])c([2H])c([2H])c5c5c([2H])c([2H])c([2H])c([2H])c54)c([2H])c3Oc3c([2H])c(-n4c5c([2H])c([2H])c([2H])c([2H])c5c5c([2H])c([2H])c([2H])c([2H])c54)c([2H])c-2c31]

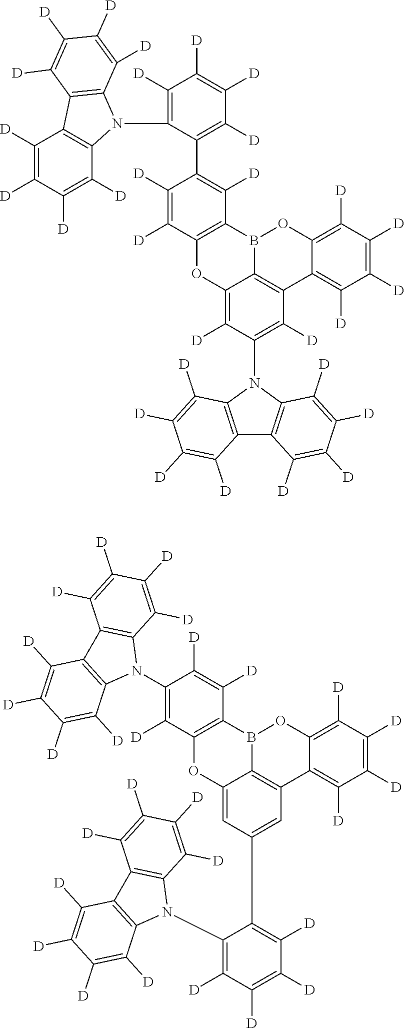

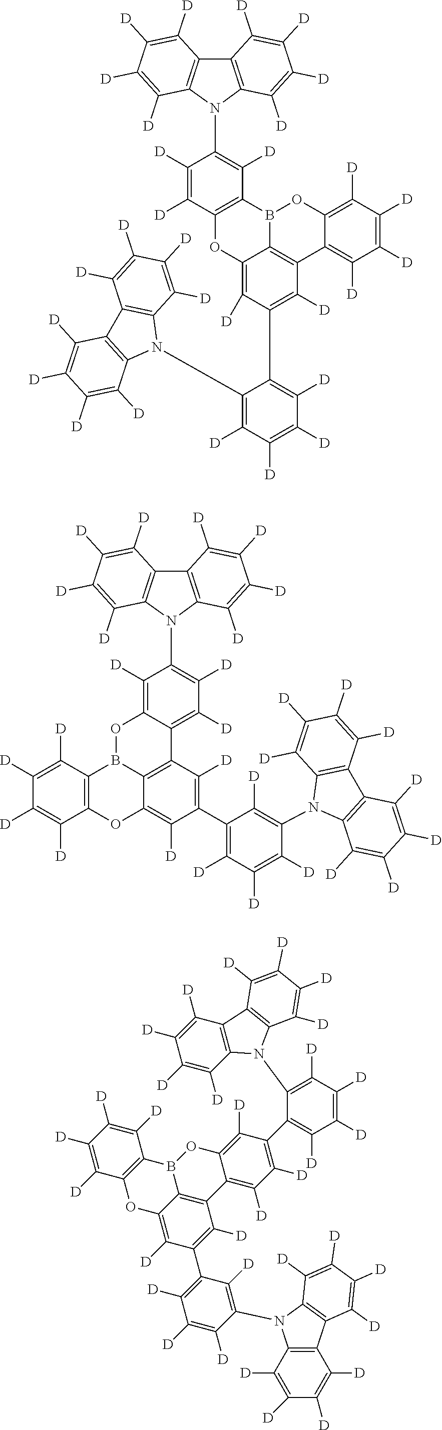

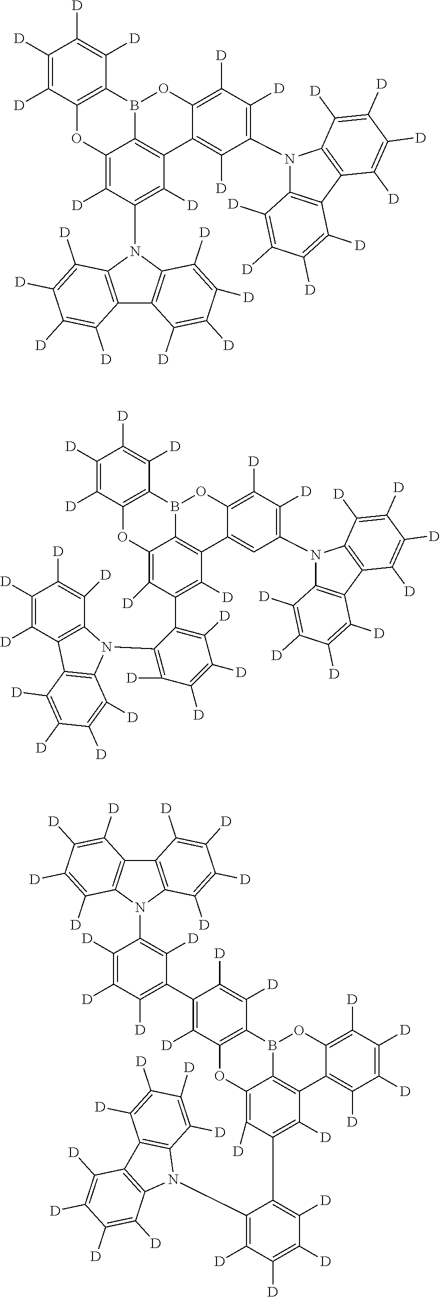

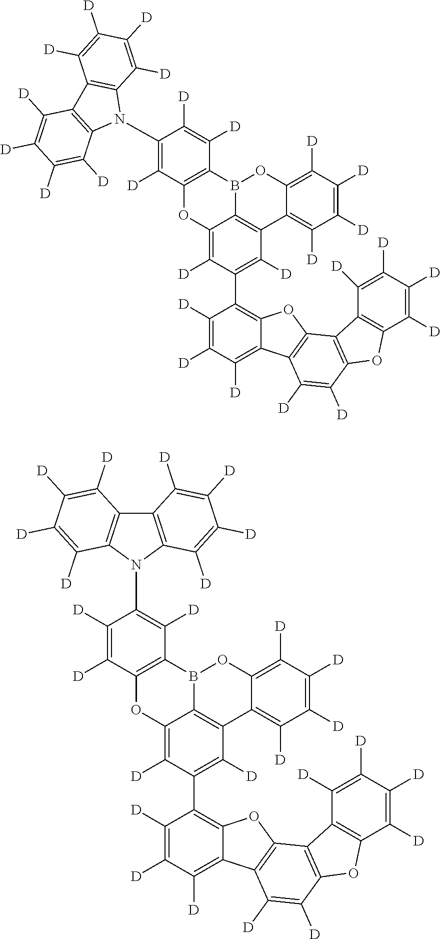 [SMILES: [2H]c1c([2H])c([2H])c2c(c1[2H])OB1c3c([2H])c([2H])c(-n4c5c([2H])c([2H])c([2H])c([2H])c5c5c([2H])c([2H])c([2H])c([2H])c54)c([2H])c3Oc3c([2H])c(-c4c([2H])c([2H])c([2H])c5c4oc4c5c([2H])c([2H])c5oc6c([2H])c([2H])c([2H])c([2H])c6c54)c([2H])c-2c31 ; [2H]c1c([2H])c([2H])c2c(c1[2H])OB1c3c([2H])c(-n4c5c([2H])c([2H])c([2H])c([2H])c5c5c([2H])c([2H])c([2H])c([2H])c54)c([2H])c([2H])c3Oc3c([2H])c(-c4c([2H])c([2H])c([2H])c5c4oc4c5c([2H])c([2H])c5oc6c([2H])c([2H])c([2H])c([2H])c6c54)c([2H])c-2c31]

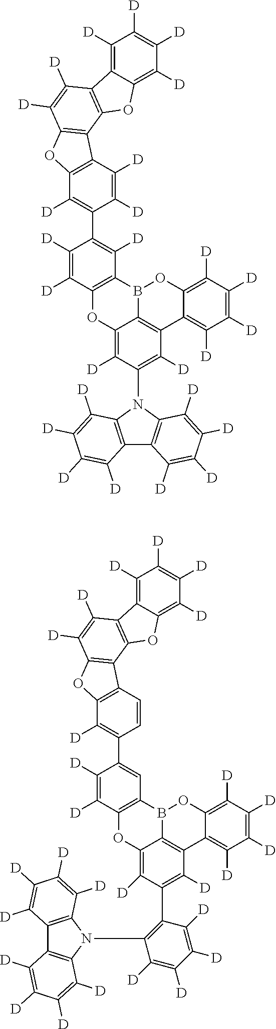

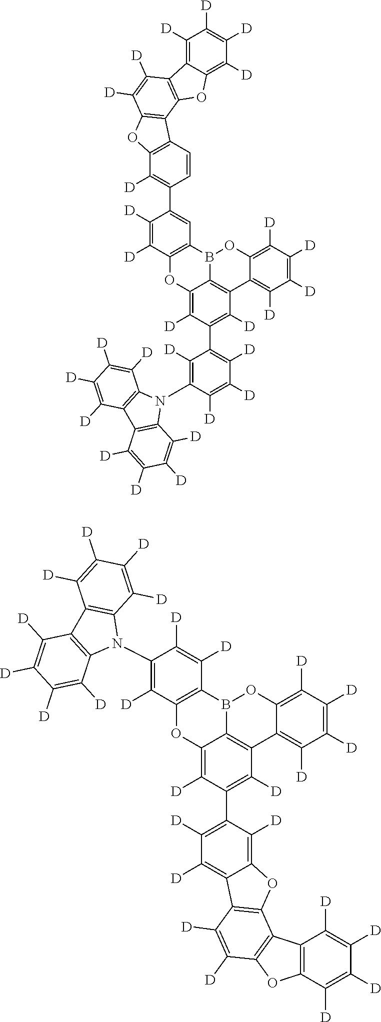

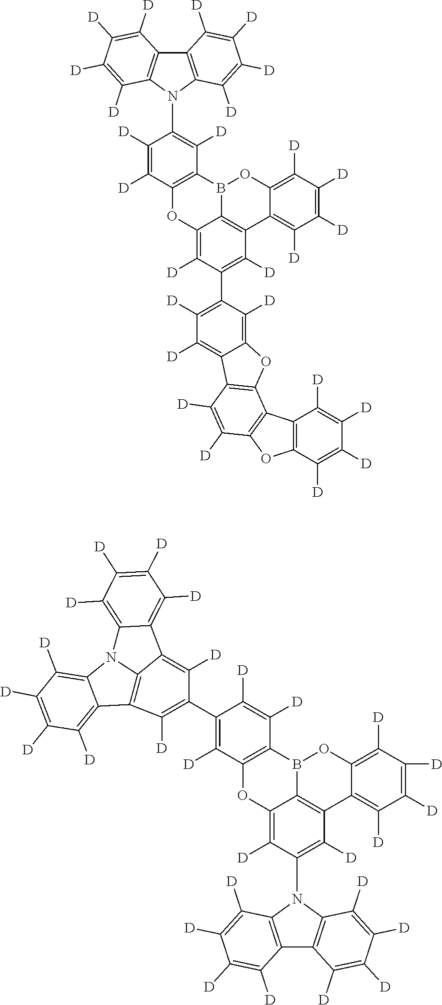 [SMILES: [2H]c1c([2H])c([2H])c2c(c1[2H])OB1c3c([2H])c(-n4c5c([2H])c([2H])c([2H])c([2H])c5c5c([2H])c([2H])c([2H])c([2H])c54)c([2H])c([2H])c3Oc3c([2H])c(-c4c([2H])c([2H])c5c(oc6c5c([2H])c([2H])c5oc7c([2H])c([2H])c([2H])c([2H])c7c56)c4[2H])c([2H])c-2c31 ; [2H]c1c([2H])c([2H])c2c(c1[2H])OB1c3c([2H])c([2H])c(-c4c([2H])c5c6c([2H])c([2H])c([2H])c([2H])c6n6c7c([2H])c([2H])c([2H])c([2H])c7c(c4[2H])c56)c([2H])c3Oc3c([2H])c(-n4c5c([2H])c([2H])c([2H])c([2H])c5c5c([2H])c([2H])c([2H])c([2H])c54)c([2H])c-2c31]

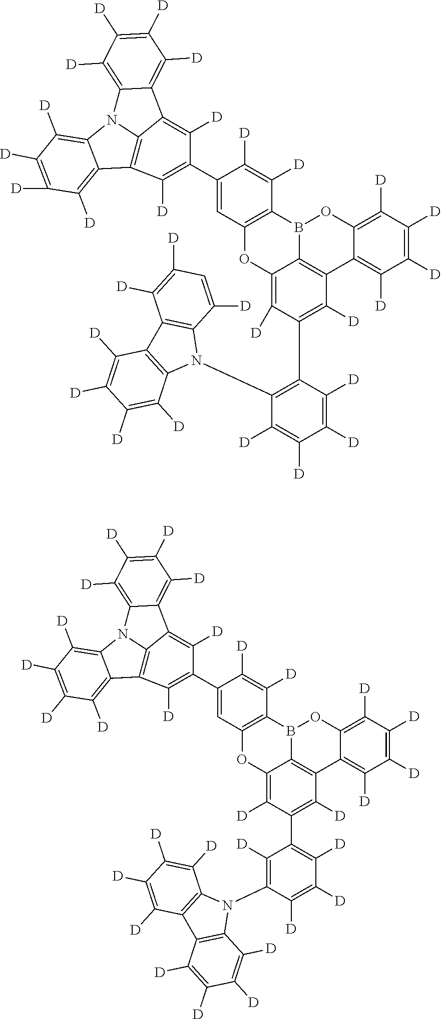

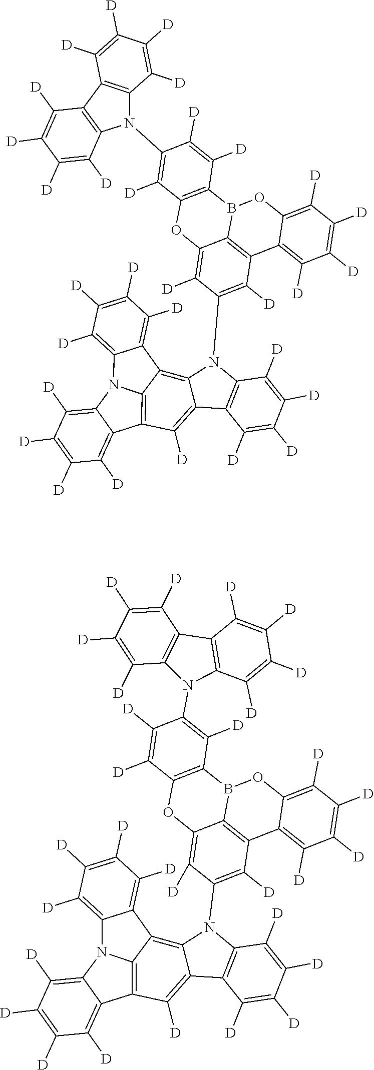

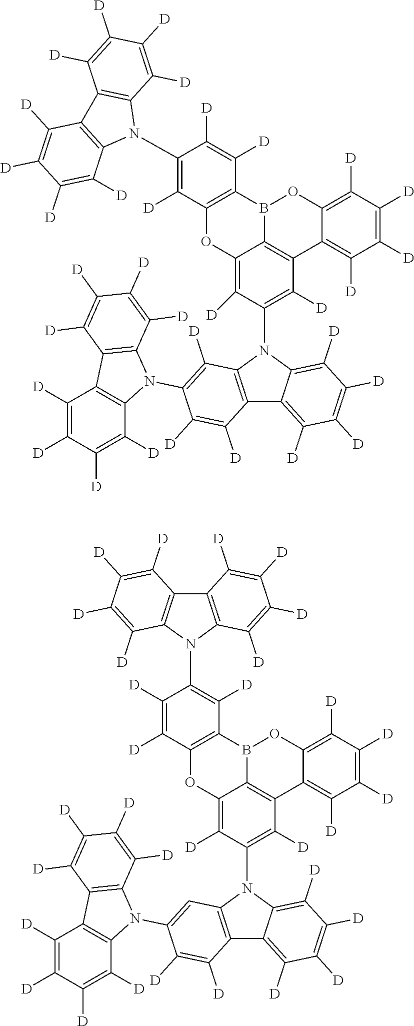

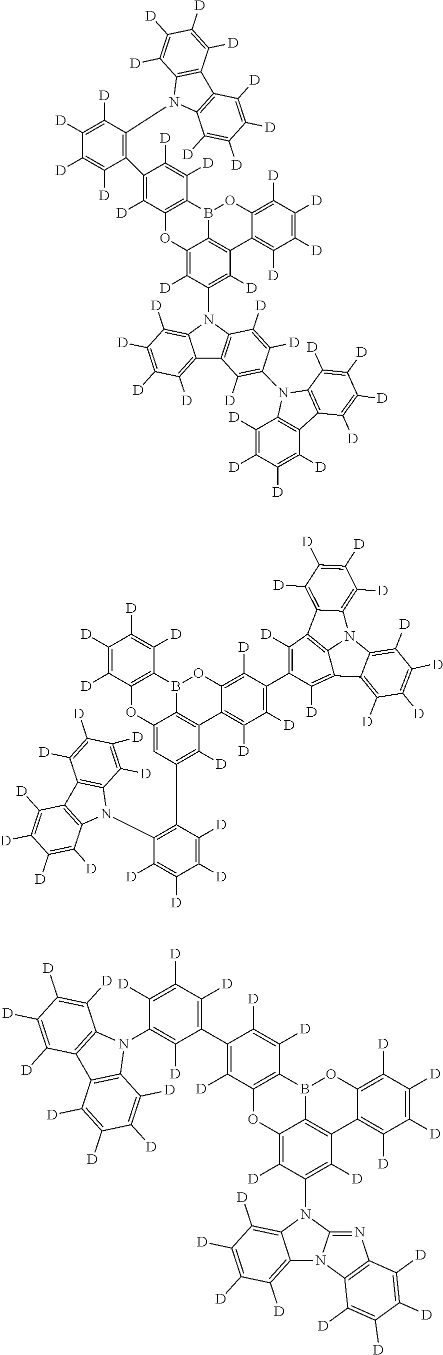

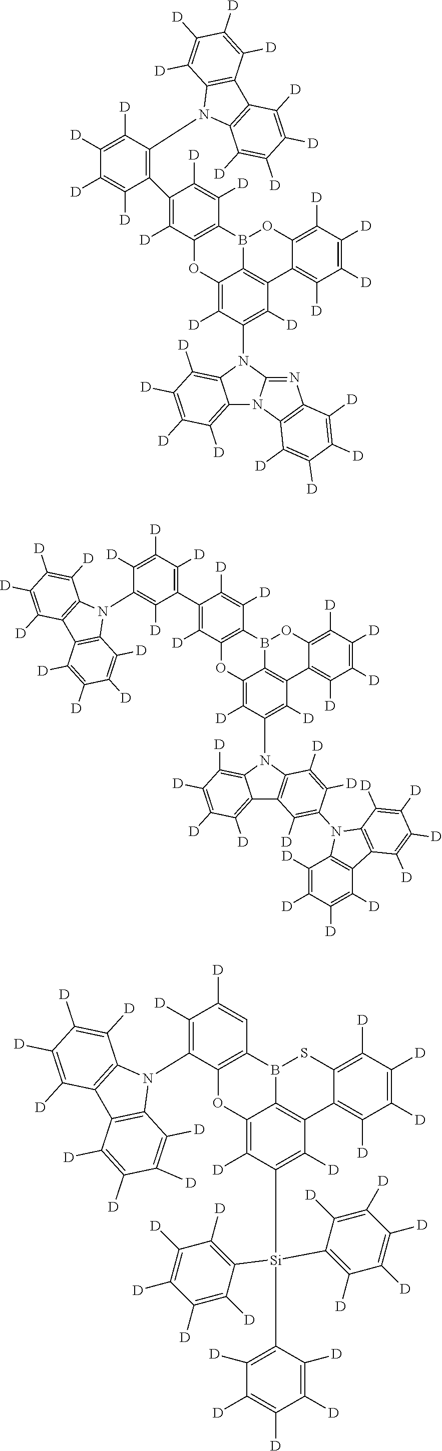

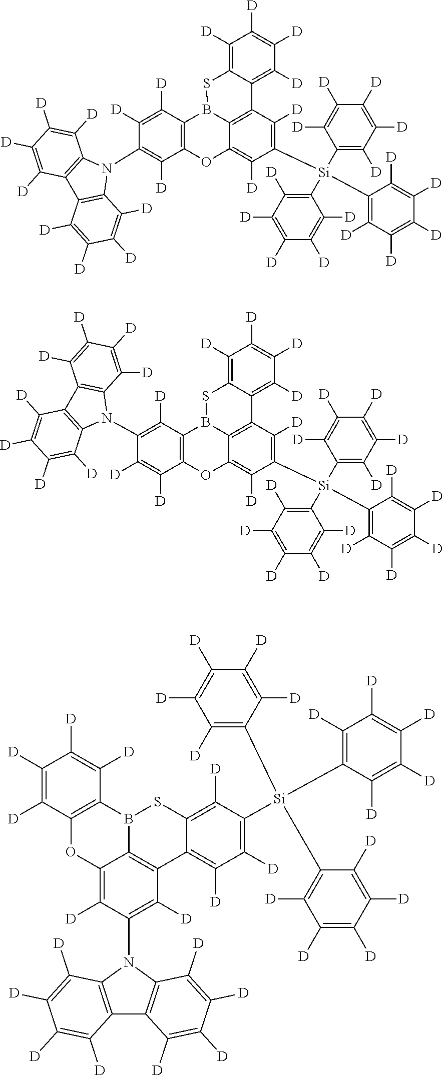

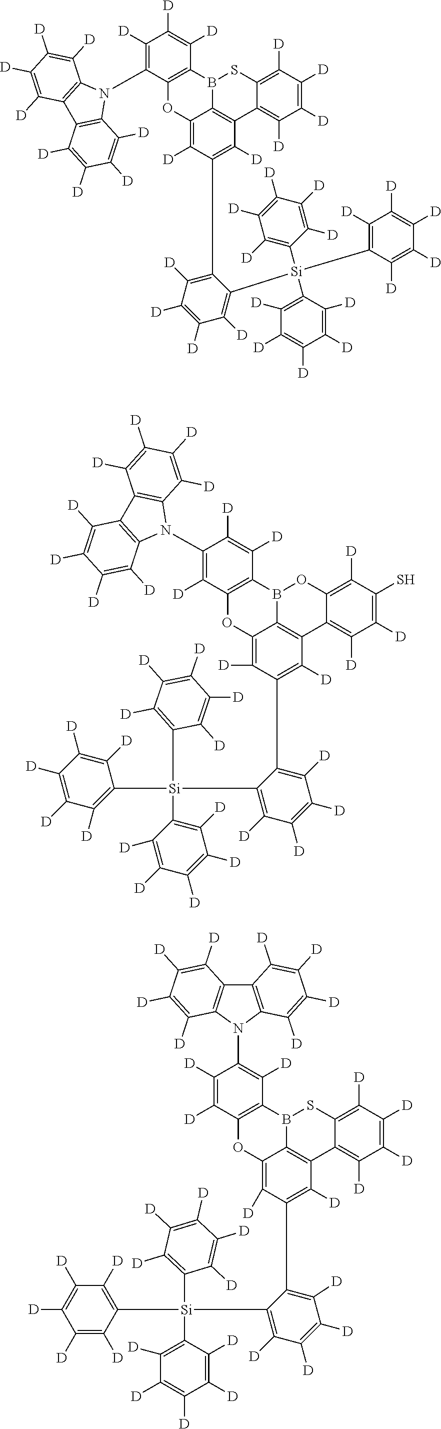

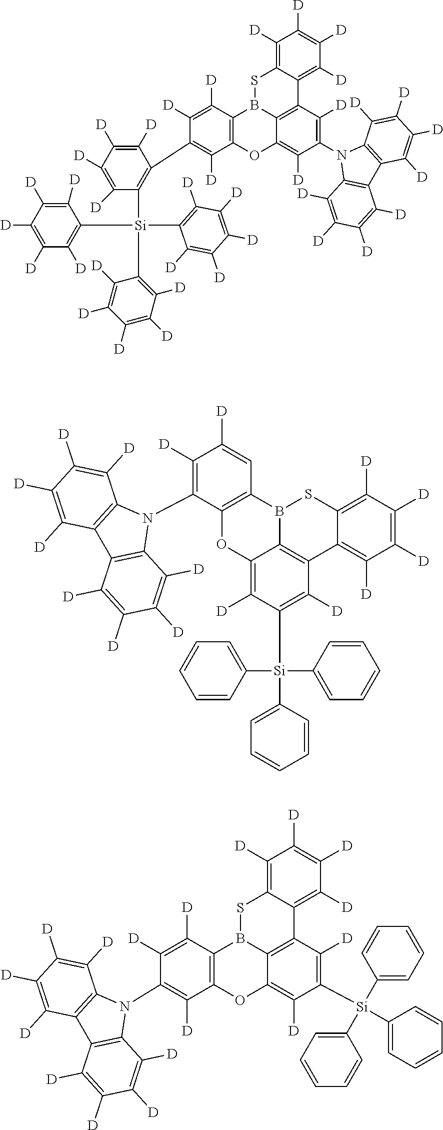

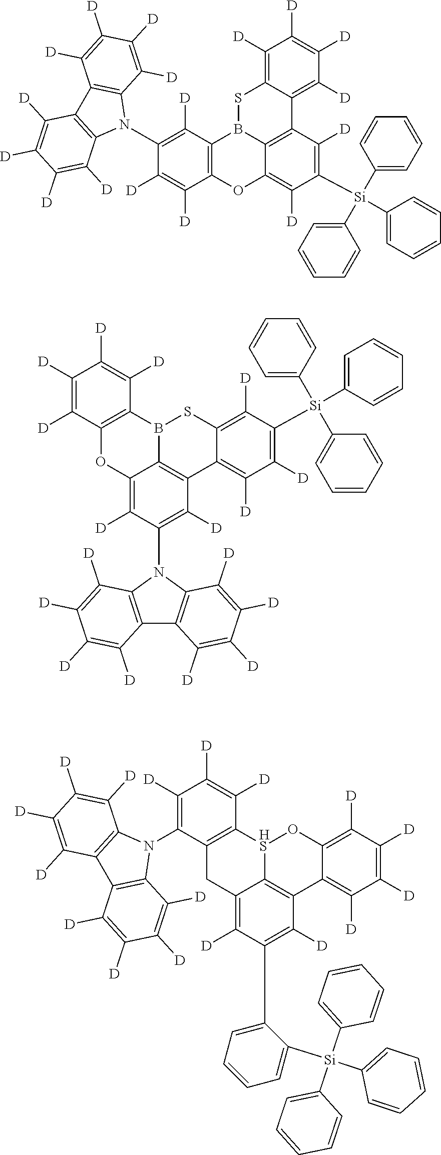

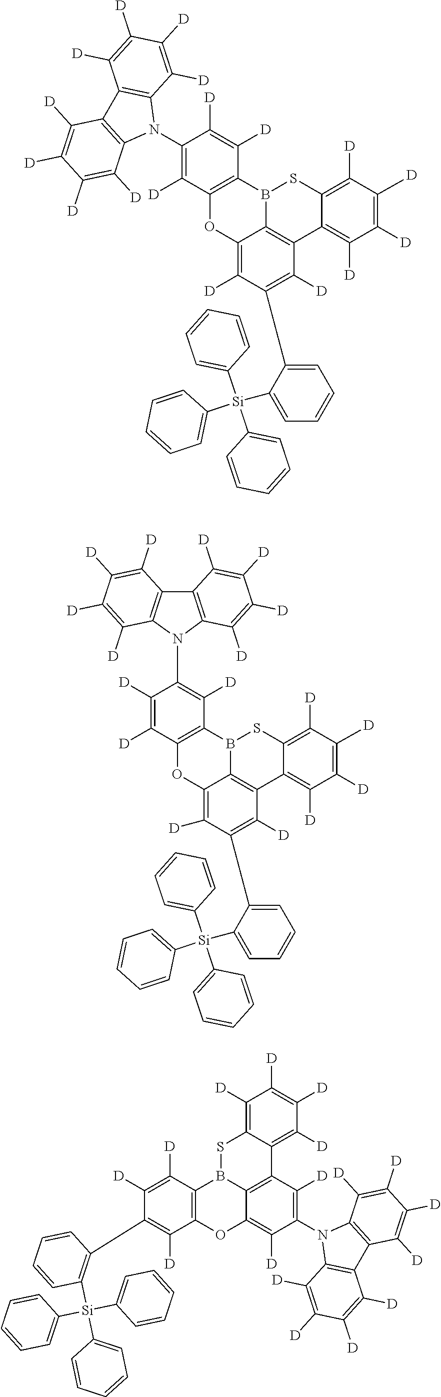

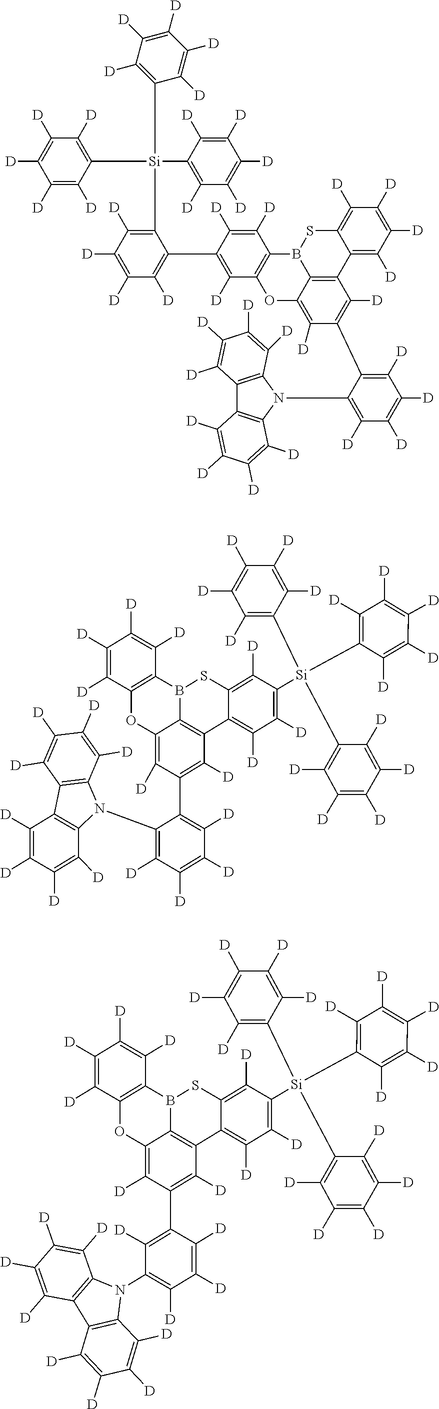

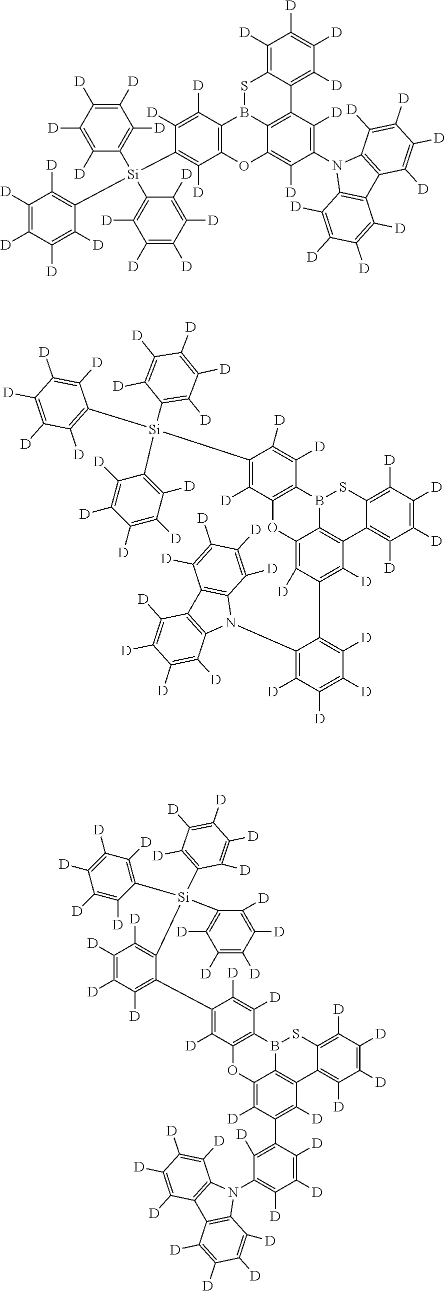

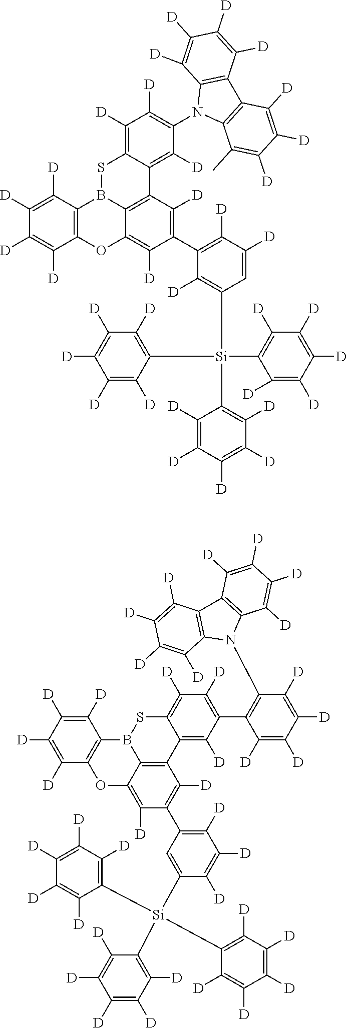

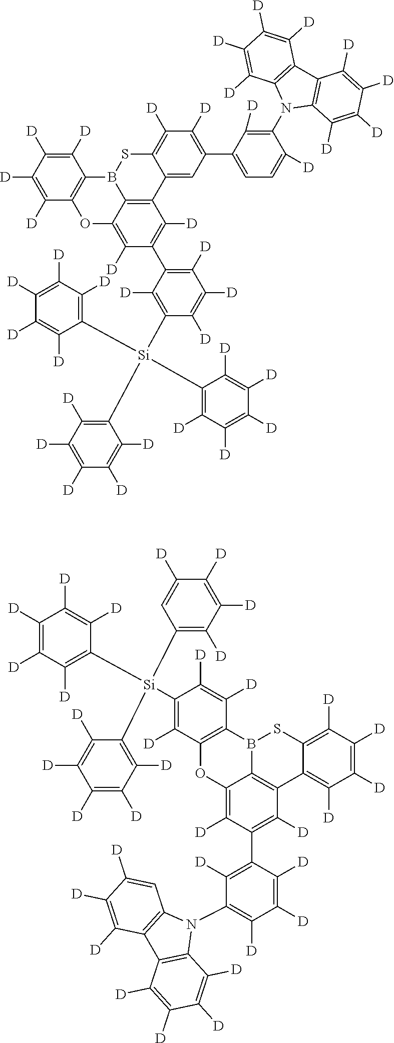

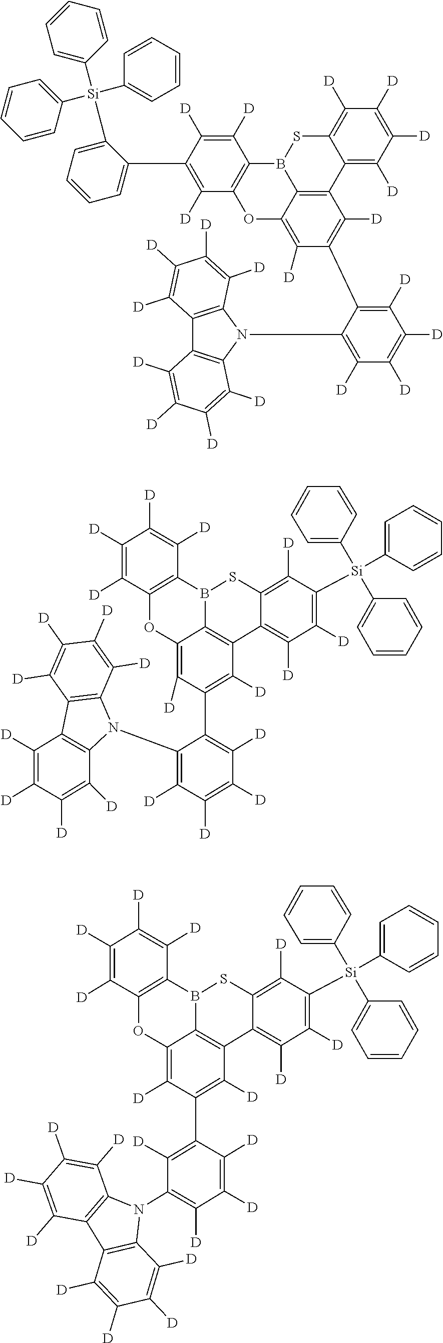

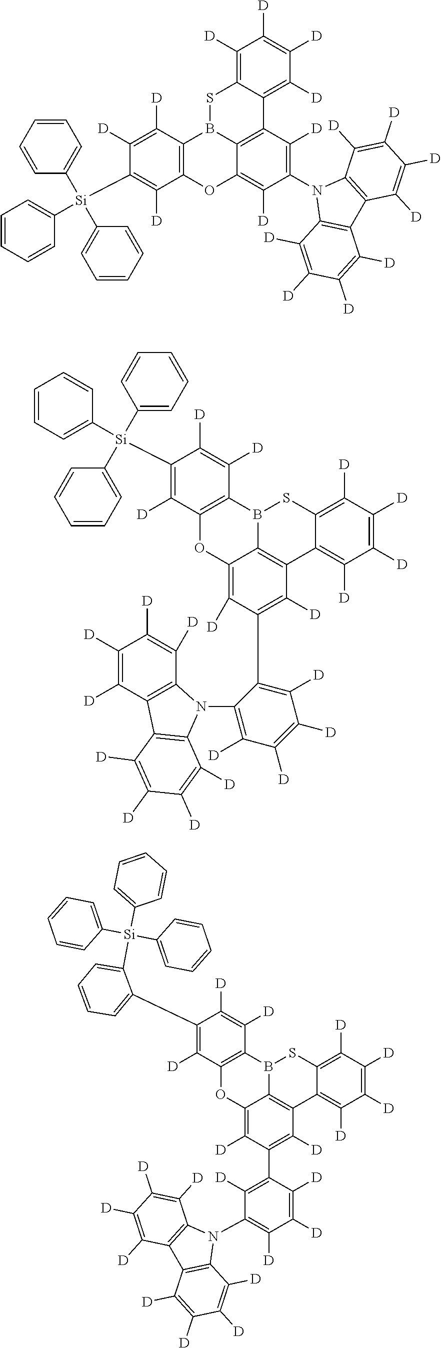

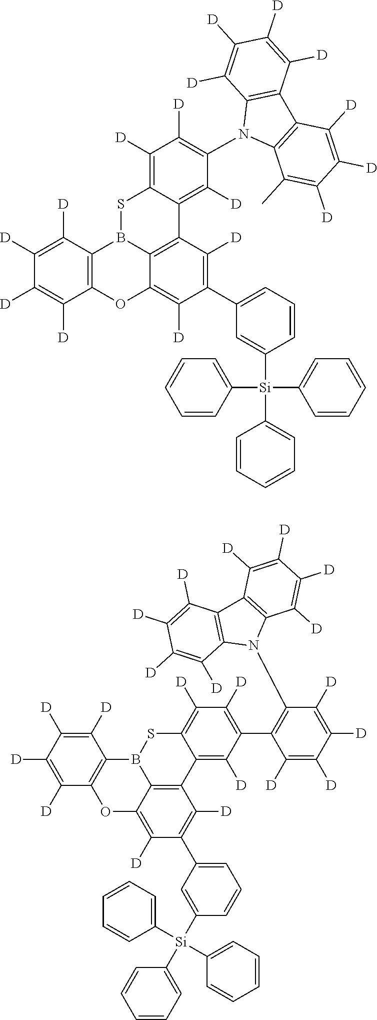 [SMILES: [2H]c1c([2H])c([2H])c2c(c1[2H])Oc1c([2H])c(-c3cccc([Si](c4ccccc4)(c4ccccc4)c4ccccc4)c3)c([2H])c3c1B2Sc1c([2H])c([2H])c(-n2c4c([2H])c([2H])c([2H])c([2H])c4c4c([2H])c([2H])c([2H])c(C)c42)c([2H])c1-3 ; [2H]c1c([2H])c([2H])c2c(c1[2H])Oc1c([2H])c(-c3cccc([Si](c4ccccc4)(c4ccccc4)c4ccccc4)c3)c([2H])c3c1B2Sc1c([2H])c([2H])c(-c2c([2H])c([2H])c([2H])c([2H])c2-n2c4c([2H])c([2H])c([2H])c([2H])c4c4c([2H])c([2H])c([2H])c([2H])c42)c([2H])c1-3]

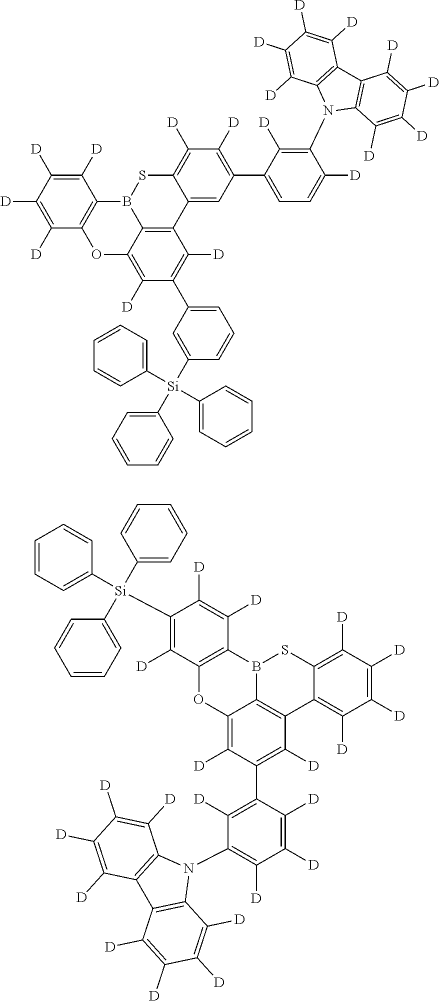

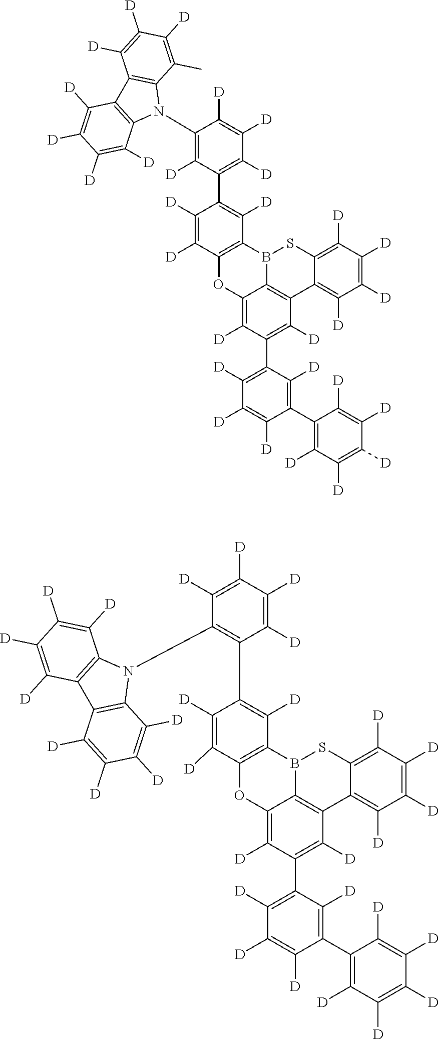

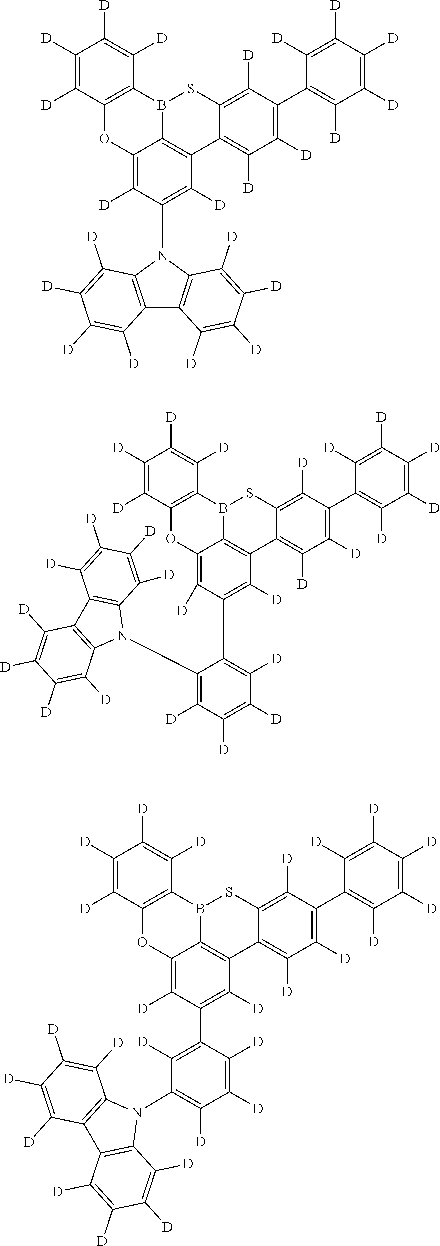

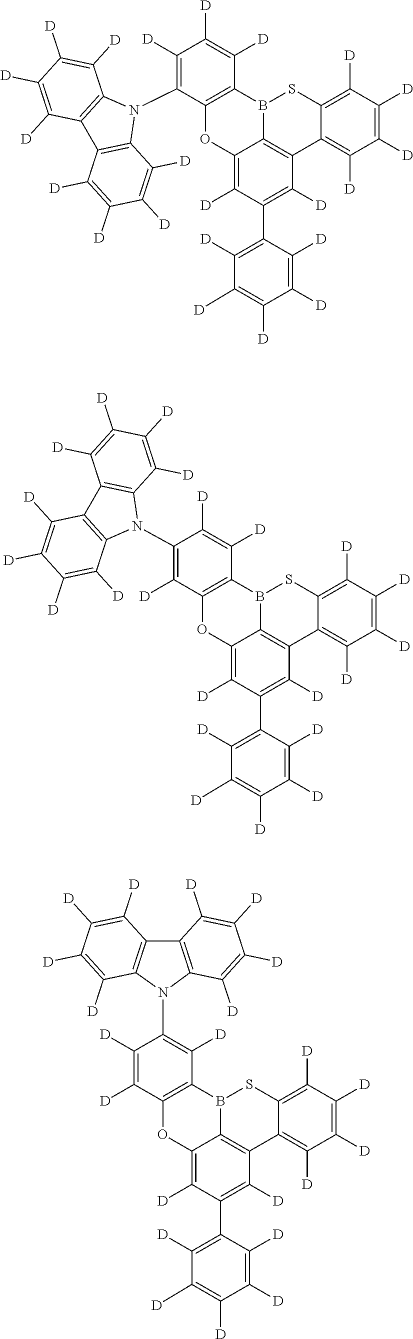

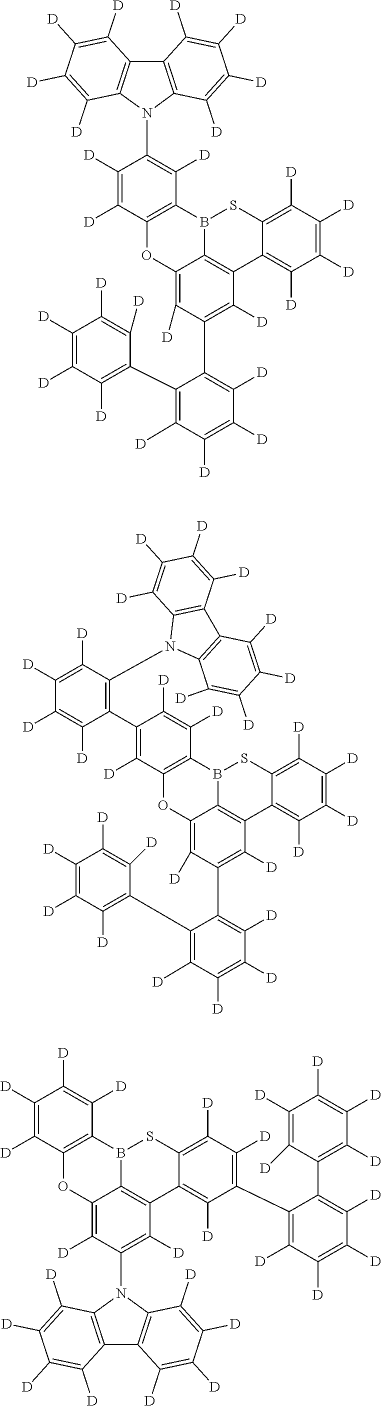

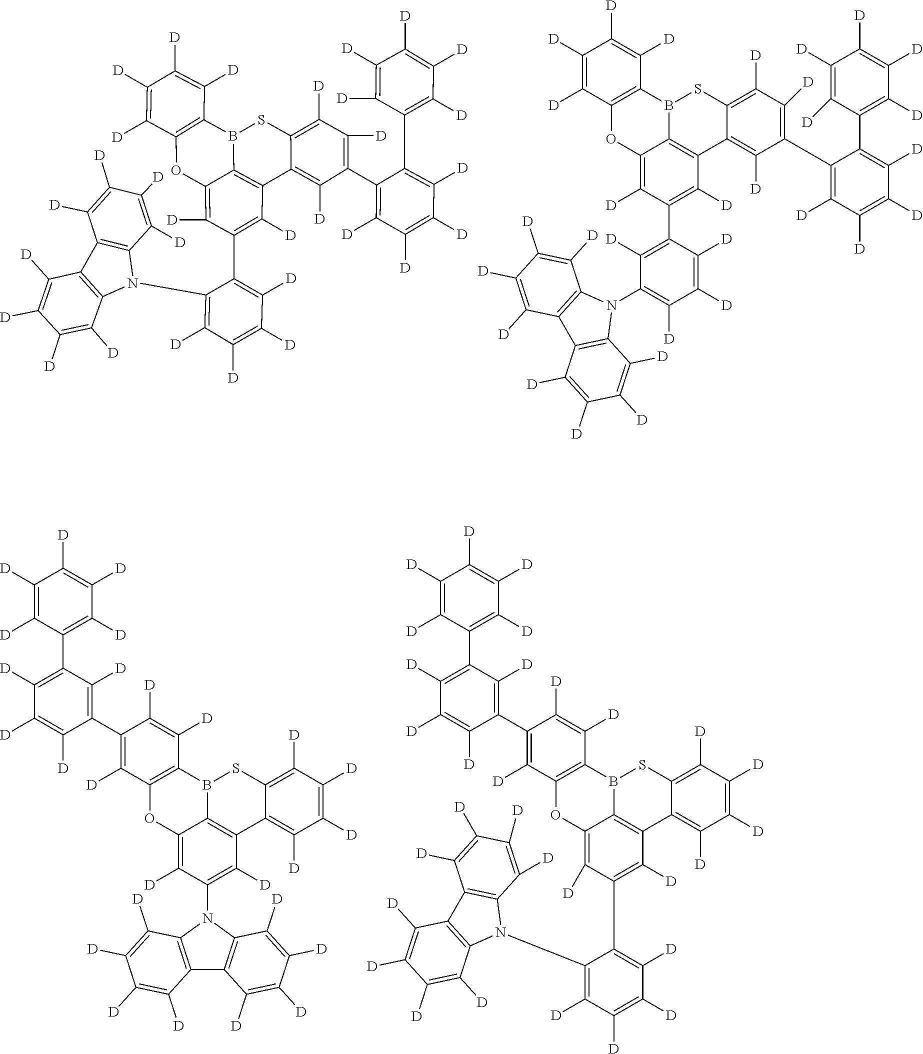

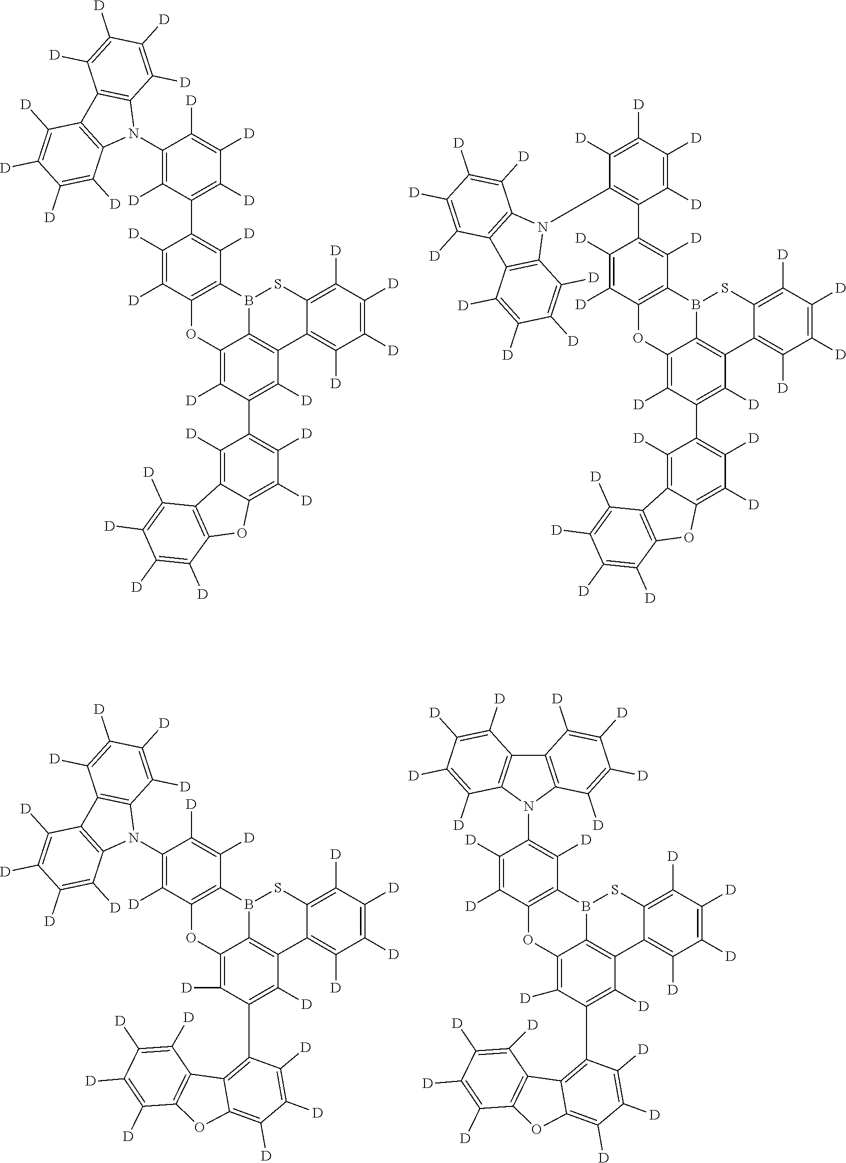

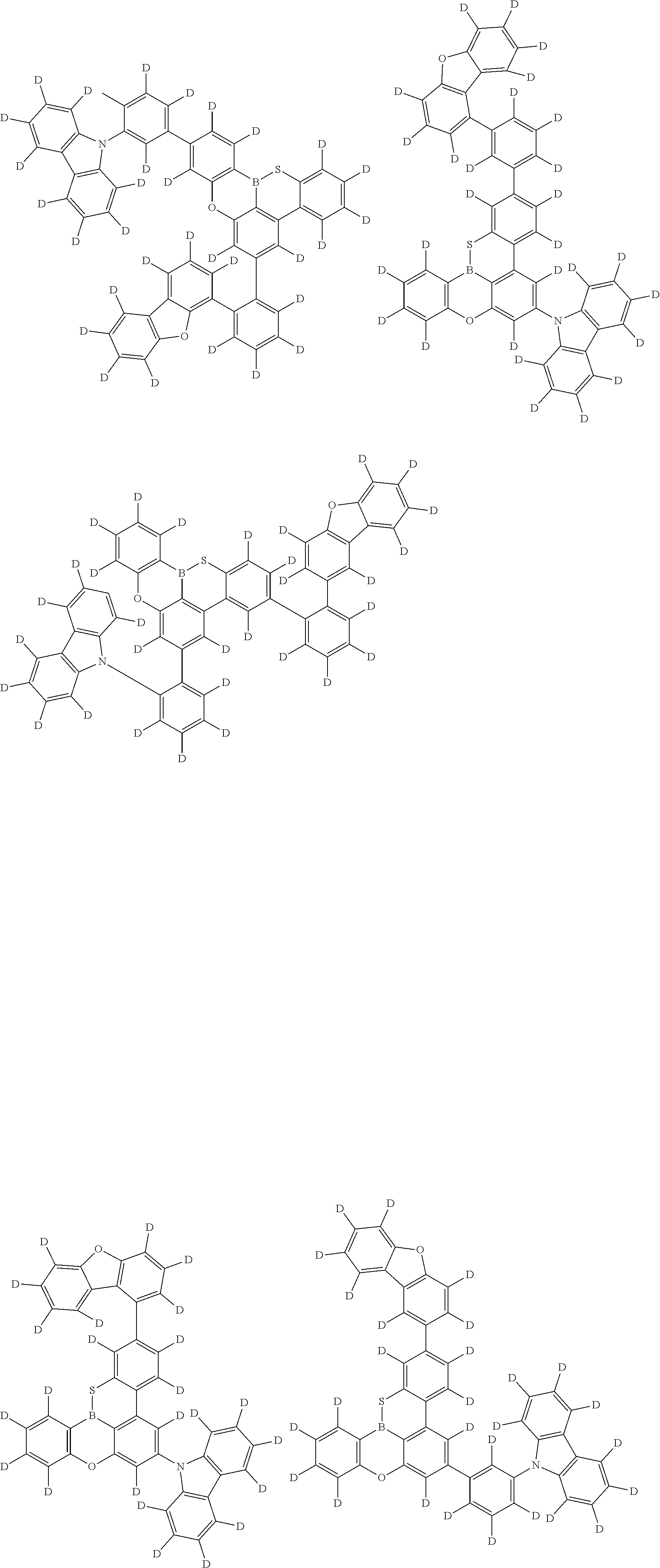

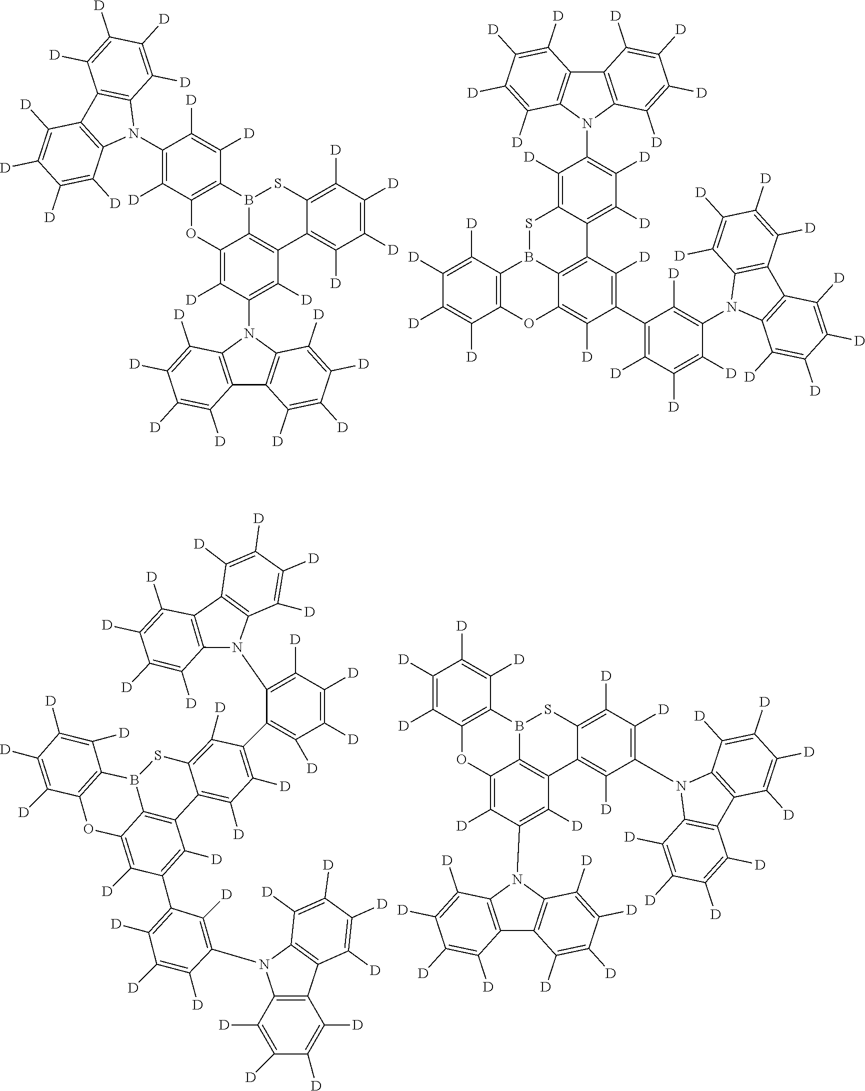

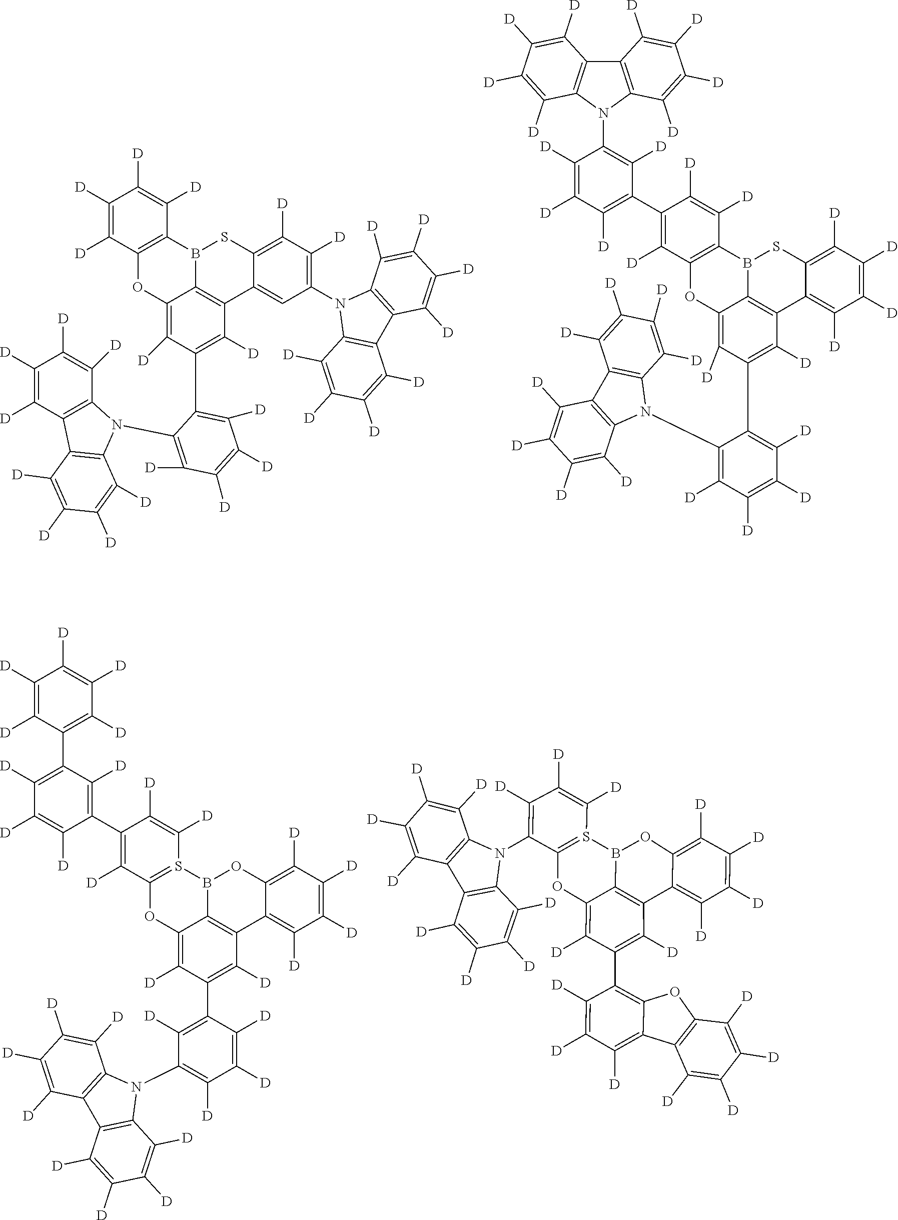

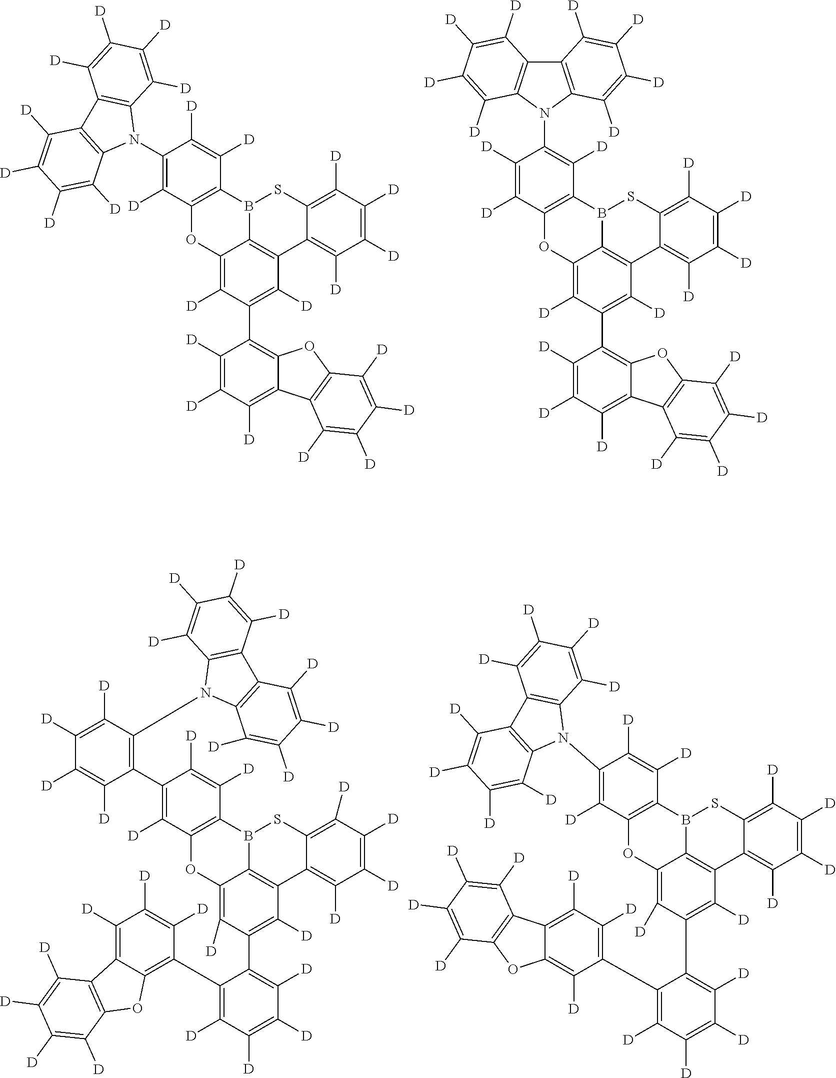

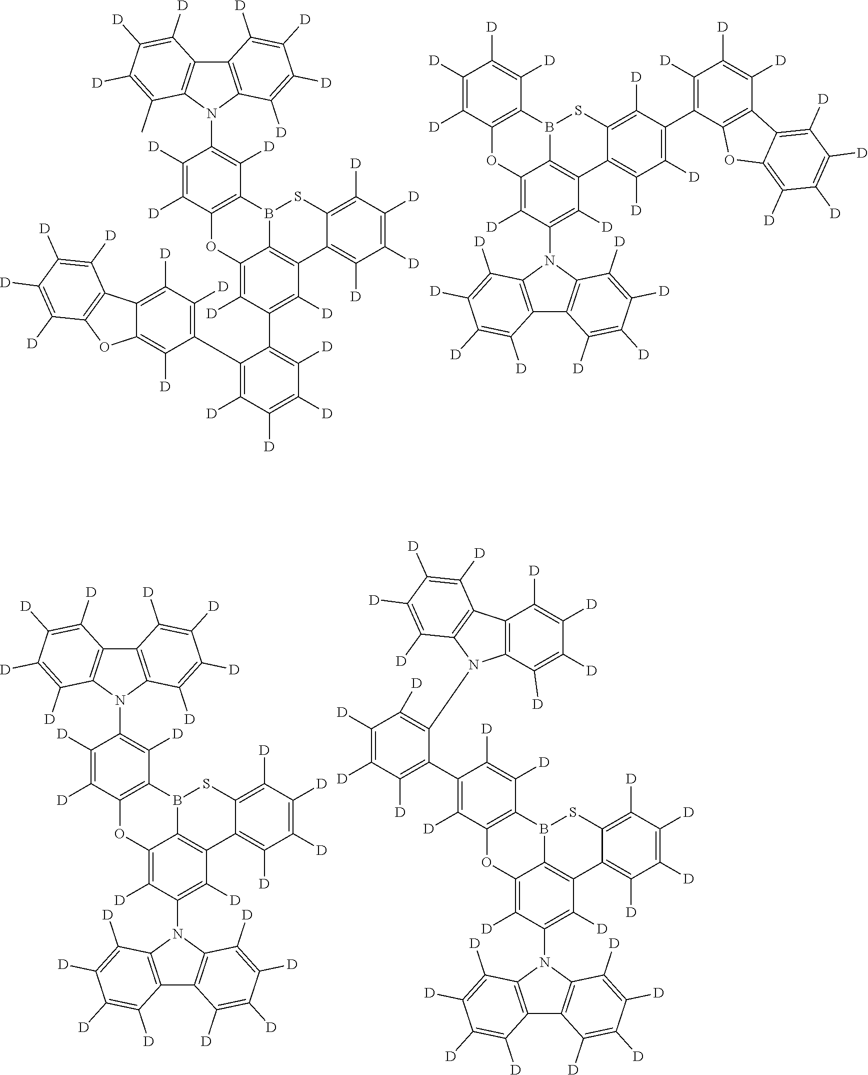

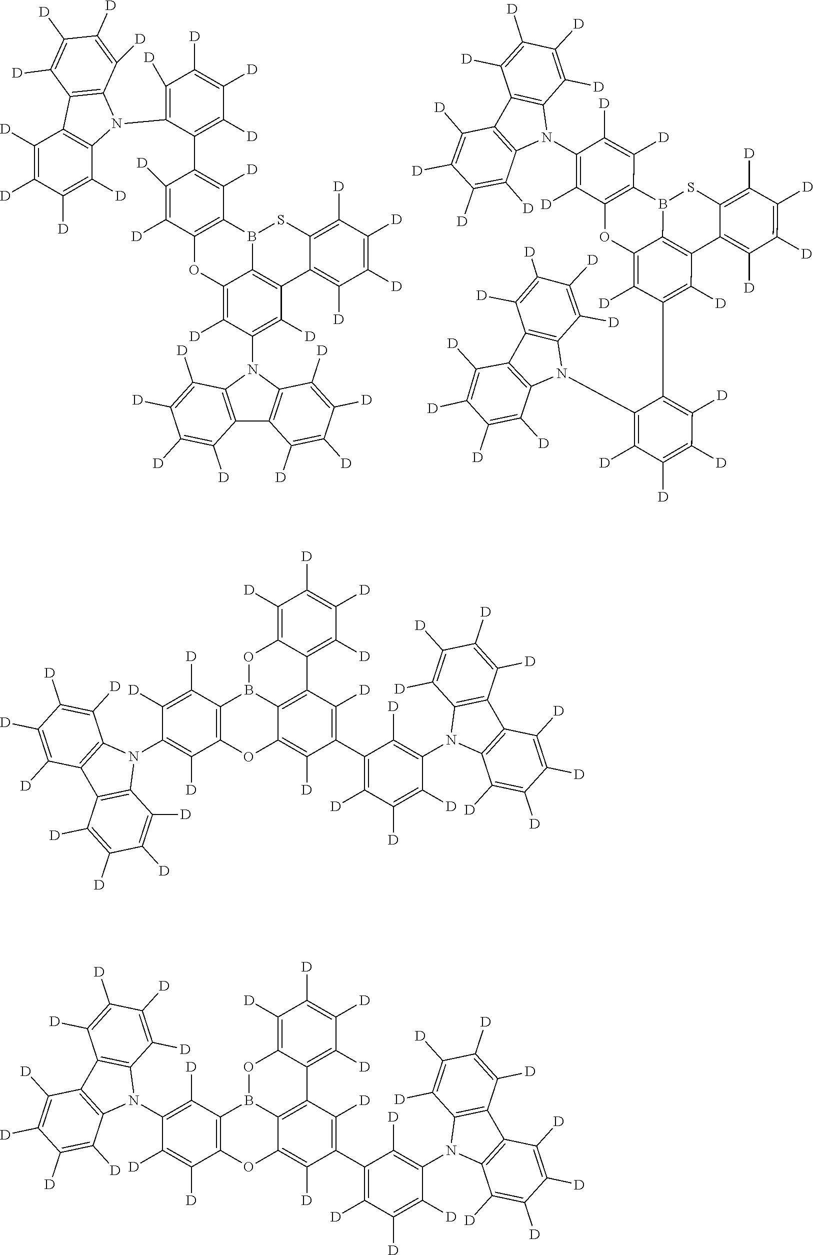

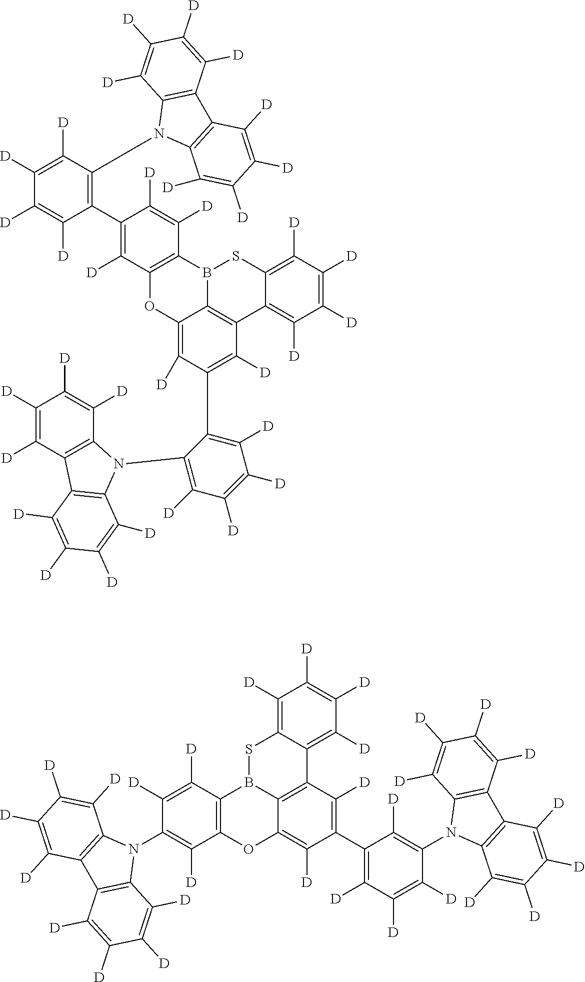

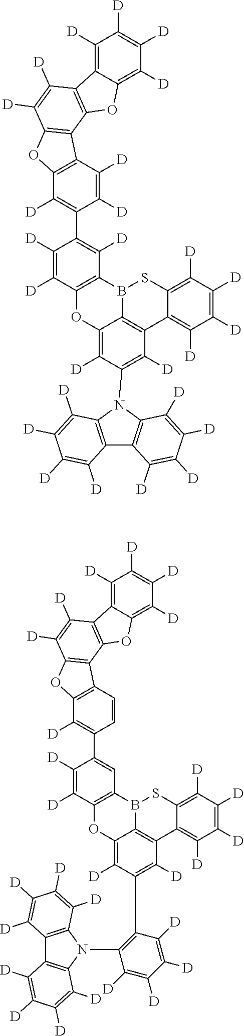

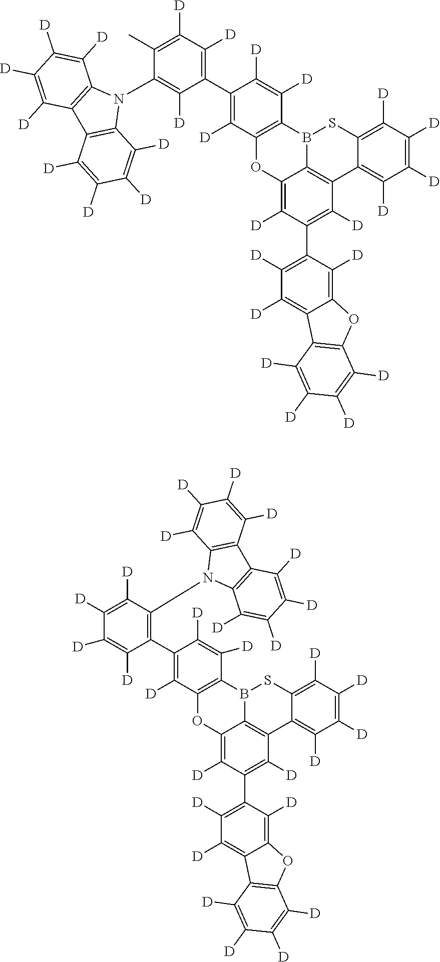

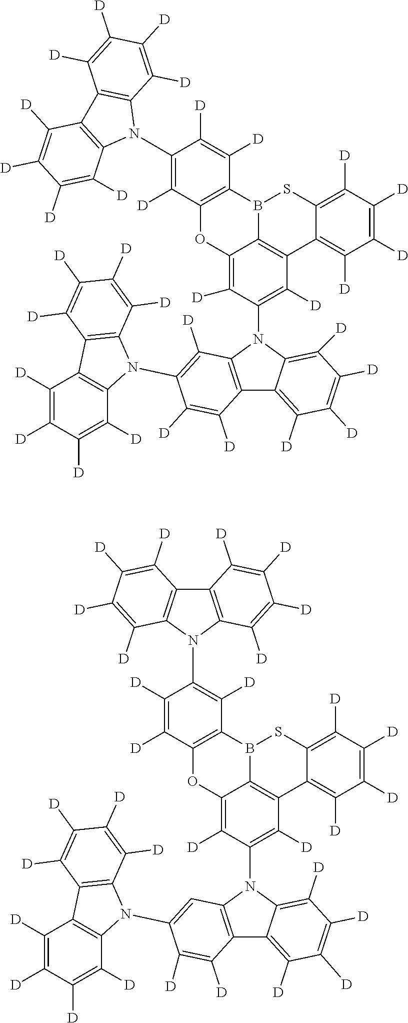

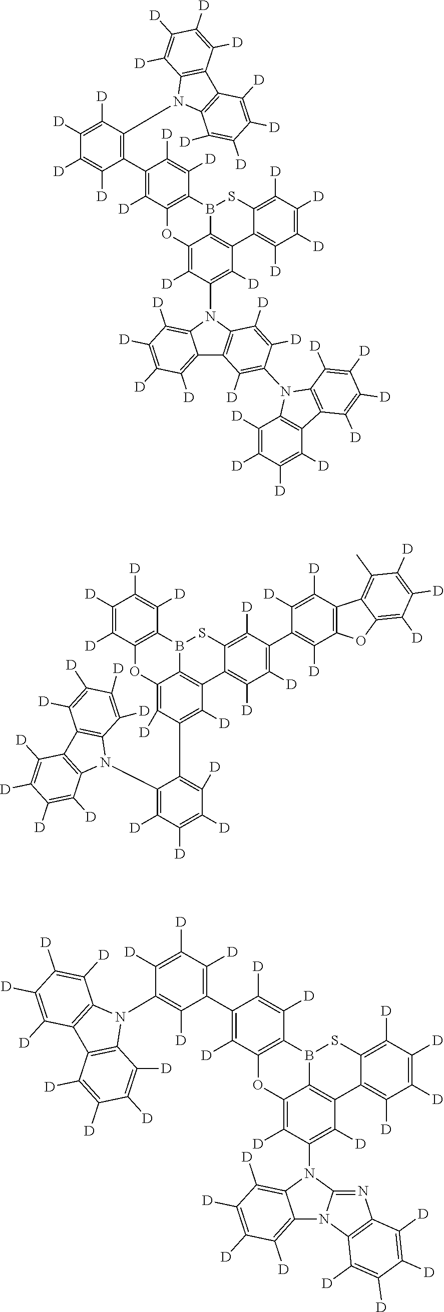

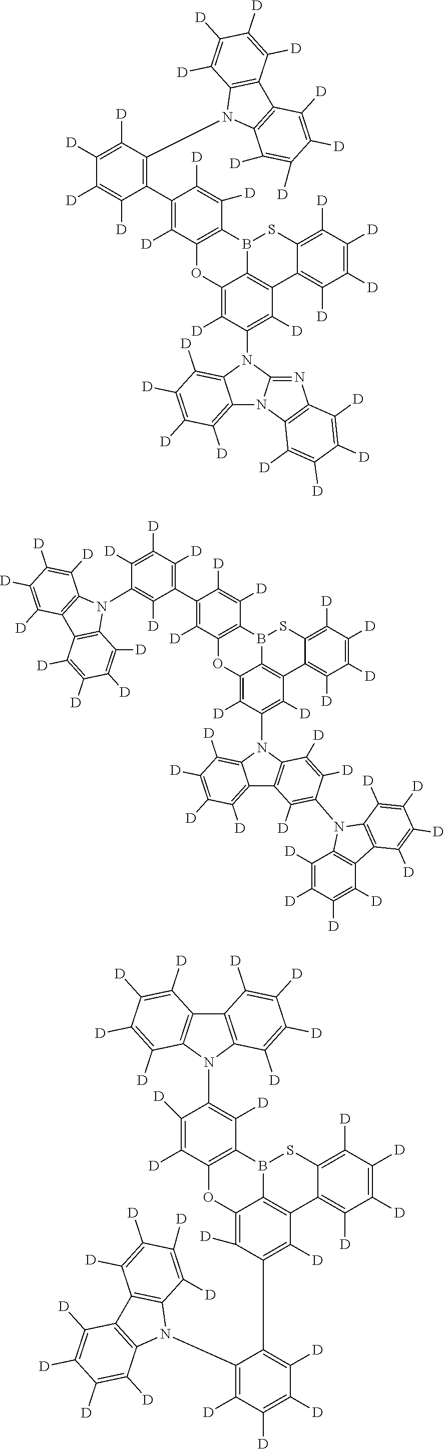

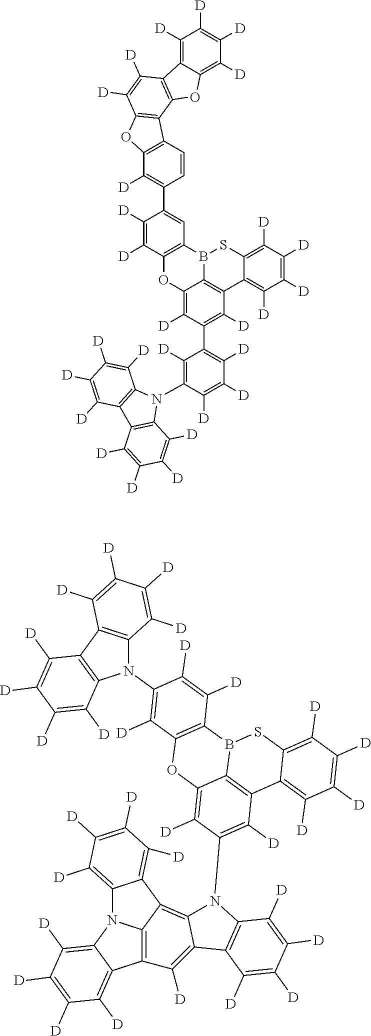

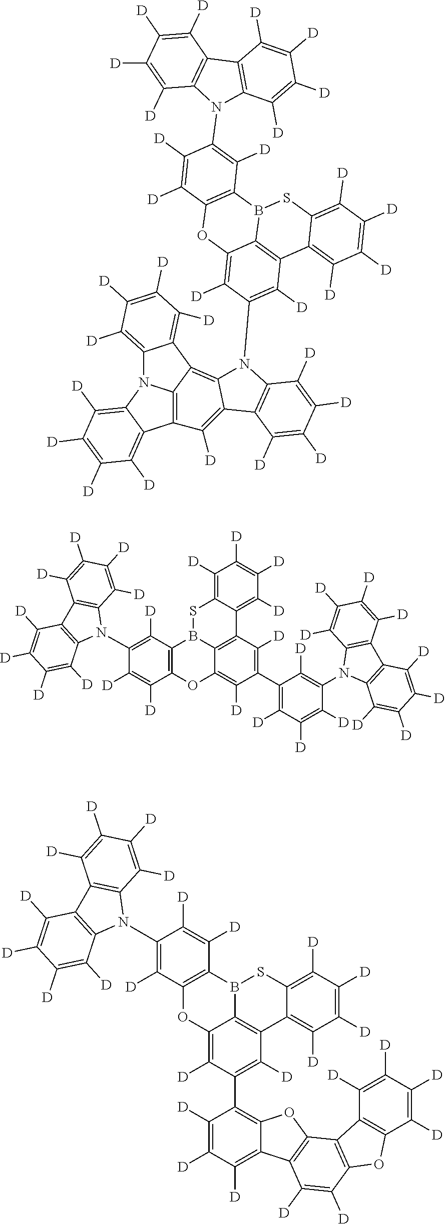

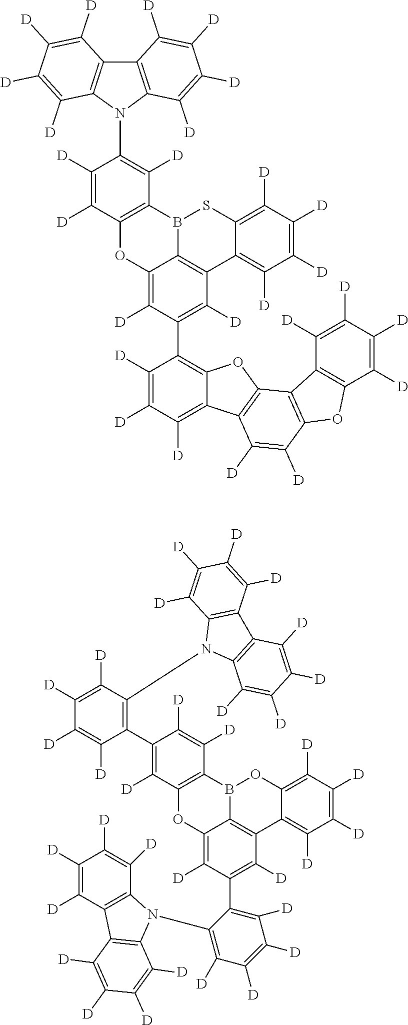

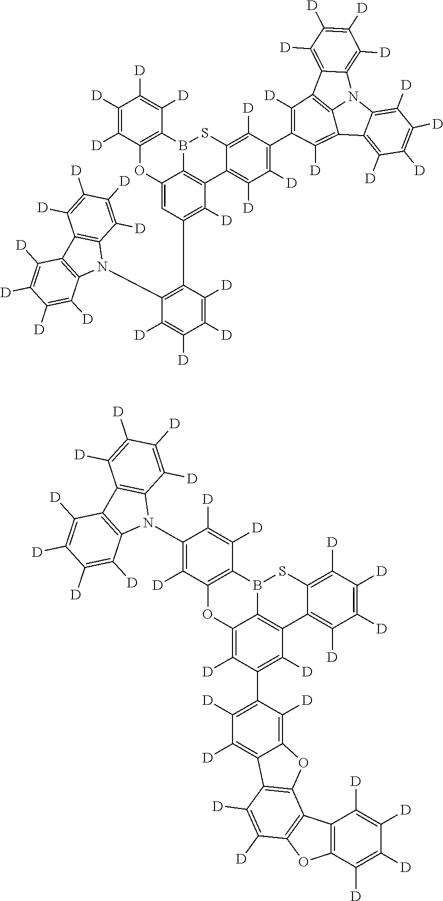

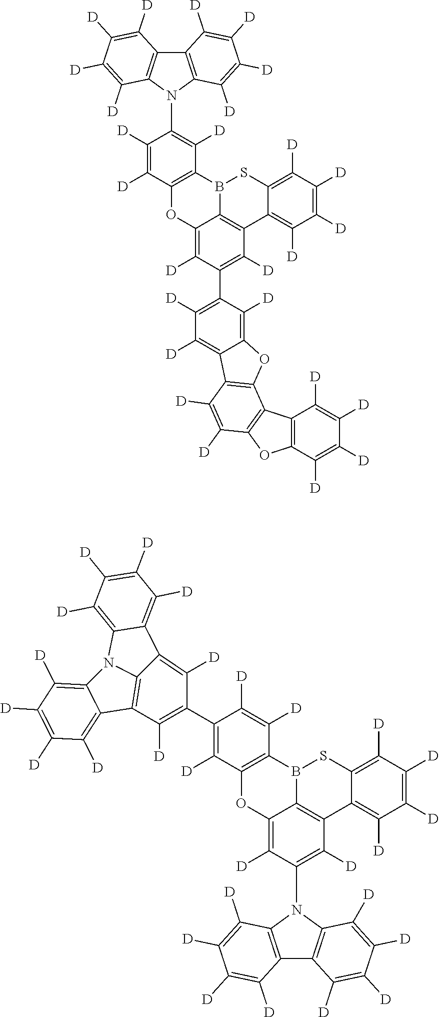 [SMILES: [2H]c1c([2H])c([2H])c2c(c1[2H])SB1c3c([2H])c(-n4c5c([2H])c([2H])c([2H])c([2H])c5c5c([2H])c([2H])c([2H])c([2H])c54)c([2H])c([2H])c3Oc3c([2H])c(-c4c([2H])c([2H])c5c(oc6c5c([2H])c([2H])c5oc7c([2H])c([2H])c([2H])c([2H])c7c56)c4[2H])c([2H])c-2c31 ; [2H]c1c([2H])c([2H])c2c(c1[2H])SB1c3c([2H])c([2H])c(-c4c([2H])c5c6c([2H])c([2H])c([2H])c([2H])c6n6c7c([2H])c([2H])c([2H])c([2H])c7c(c4[2H])c56)c([2H])c3Oc3c([2H])c(-n4c5c([2H])c([2H])c([2H])c([2H])c5c5c([2H])c([2H])c([2H])c([2H])c54)c([2H])c-2c31]

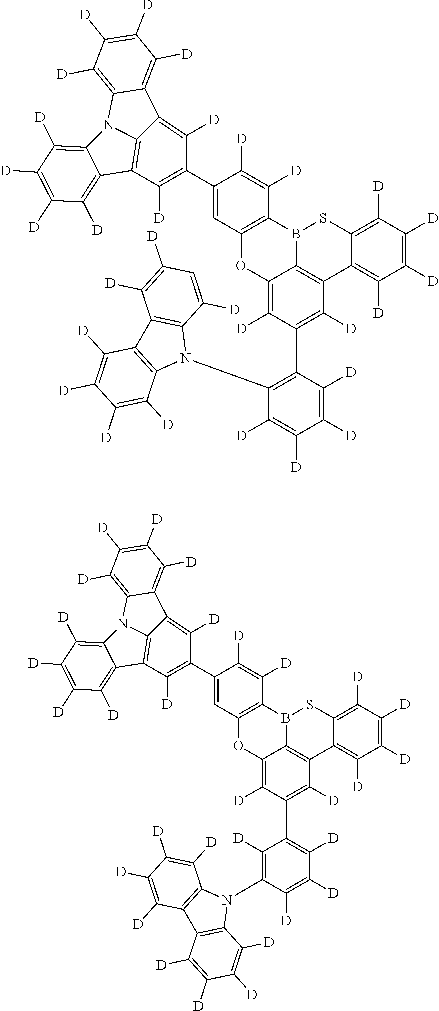

In the present specification, “[ ]_{D=x1 to x2}” means that a structure in the parenthesis comprises x1 or x2 deuteriums, and the value thereof is an integer. For example, [ ]_{D=1˜41} means including 1 to 41 deuteriums.

A core structure may be prepared as the following reaction formula from the compound represented by Formula 1 according to an exemplary embodiment of the present specification. The substituent may be bonded by a method known in the art, and the kind and position of the substituent or the number of substituents may be changed according to the technology known in the art.

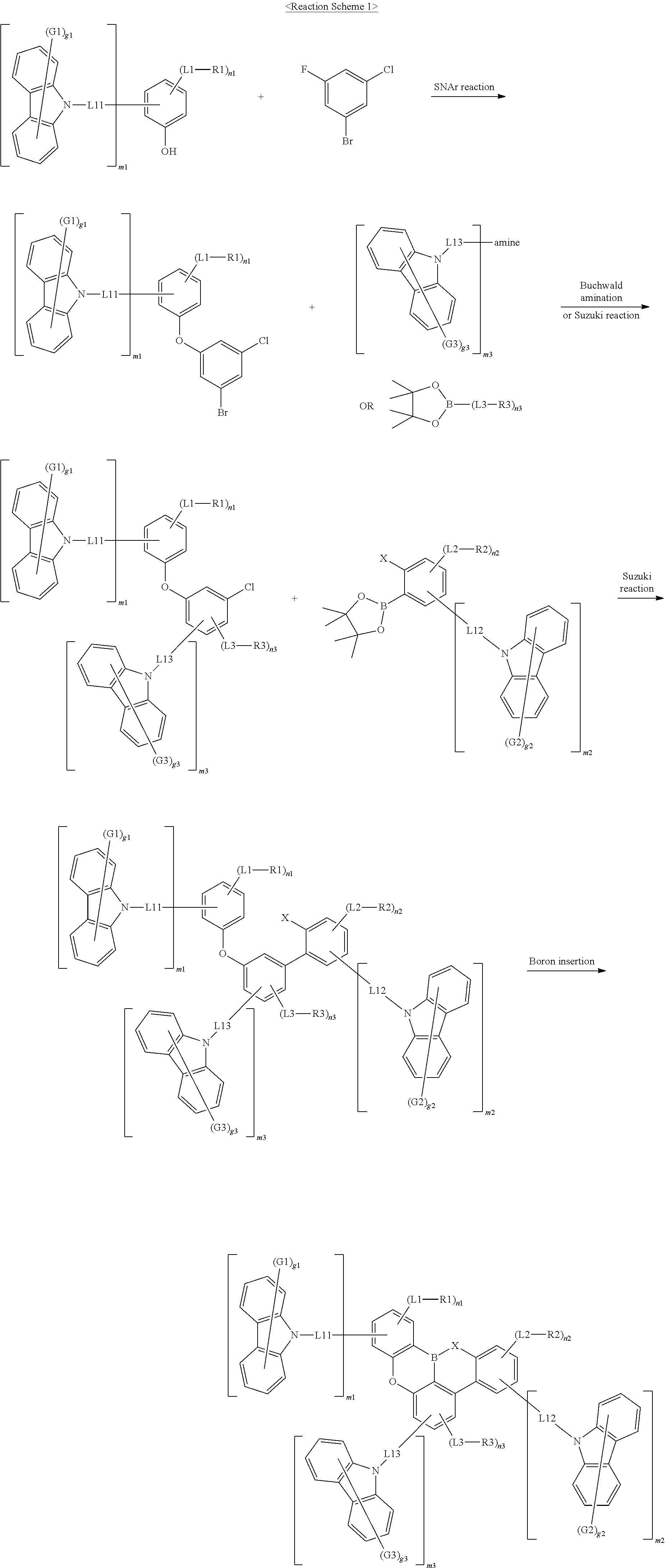

Hereinafter, Chemical Formula 2 will be described in detail.

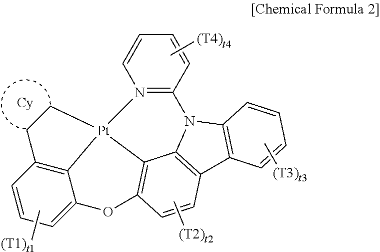

In Chemical Formula 2,
Cy is a substituted or unsubstituted N-containing monocyclic ring,
T1 to T4 are the same as or different from each other, and are each independently hydrogen; deuterium; a halogen group; a nitrile group; a substituted or unsubstituted silyl group; a substituted or unsubstituted alkyl group; a substituted or unsubstituted cycloalkyl group; a substituted or unsubstituted aryl group; or a substituted or unsubstituted heterocyclic group, or are bonded to an adjacent group to form a substituted or unsubstituted ring,
t1 and t4 are each an integer from 0 to 3,
t2 is an integer from 0 to 2,
t3 is an integer from 0 to 4,
when t1, t3, and t4 are each 2 or higher, substituents in the parenthesis are the same as or different from each other, and
when t2 is 2, substituents in the parenthesis are the same as or different from each other.

In an exemplary embodiment of the present specification, Cy is a substituted or unsubstituted N-containing pentagonal monocyclic ring, or a substituted or unsubstituted N-containing hexagonal monocyclic ring.

In an exemplary embodiment of the present specification, Cy is a substituted or unsubstituted N-containing pentagonal monocyclic ring, or a substituted or unsubstituted N-containing hexagonal monocyclic ring.

In an exemplary embodiment of the present specification, Cy may be represented by any one of the following Cy-1 to Cy-3.

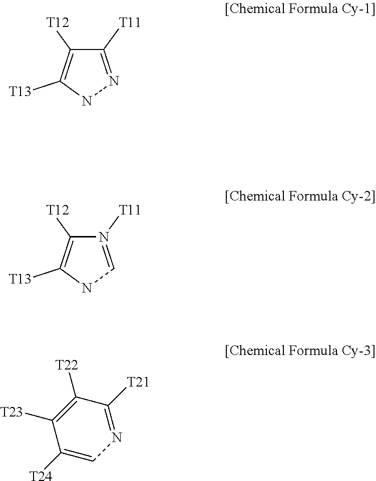

In Chemical Formulae Cy-1 to Cy-3,
T11 to T13 and T21 to T24 are the same as or different from each other, and are each independently hydrogen; deuterium; a halogen group; a nitrile group; a substituted or unsubstituted silyl group; a substituted or unsubstituted alkyl; a substituted or unsubstituted cycloalkyl group; a substituted or unsubstituted aryl group; or a substituted or unsubstituted heterocyclic group, or are bonded to an adjacent group to form a substituted or unsubstituted ring, and
the dotted line (---) means a position fused in Chemical Formula 2.

In an exemplary embodiment of the present specification, Chemical Formula 2 is represented by any one of the following Chemical Formulae 2-A-1 to 2-A-3.

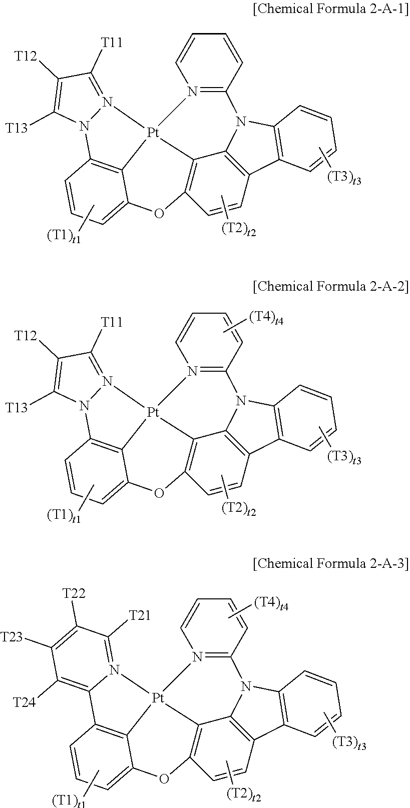

In Chemical Formulae 2-A-1 to 2-A-3,
the definitions of T1 to T4 and t1 to t4 are the same as the definitions in Chemical Formula 2, and
T11 to T13 and T21 to T24 are the same as or different from each other, and are each independently hydrogen; deuterium; a halogen group; a nitrile group; a substituted or unsubstituted silyl group; a substituted or unsubstituted alkyl group; a substituted or unsubstituted cycloalkyl group; a substituted or unsubstituted aryl group; or a substituted or unsubstituted heterocyclic group, or are bonded to an adjacent group to form a substituted or unsubstituted ring.

In an exemplary embodiment of the present specification, T1 to T4 are the same as or different from each other, and are each independently hydrogen; deuterium; a halogen group; a nitrile group; a substituted or unsubstituted silyl group; a substituted or unsubstituted alkyl group; a substituted or unsubstituted cycloalkyl group; a substituted or unsubstituted aryl group; or a substituted or unsubstituted heterocyclic group, or are bonded to an adjacent group to form a substituted or unsubstituted ring.

In an exemplary embodiment of the present specification, T1 to T4 are the same as or different from each other, and are each independently hydrogen; deuterium; a halogen group; a nitrile group; a substituted or unsubstituted silyl group; a substituted or unsubstituted alkyl group having 1 to 60 carbon atoms; a substituted or unsubstituted cycloalkyl group having 3 to 60 carbon atoms; a substituted or unsubstituted aryl group having 6 to 60 carbon atoms; or a substituted or unsubstituted heterocyclic group having 2 to 60 carbon atoms, or are bonded to an adjacent group to form a substituted or unsubstituted ring having 2 to 60 carbon atoms.

In an exemplary embodiment of the present specification, T1 to T4 are the same as or different from each other, and are each independently hydrogen; deuterium; a halogen group; a nitrile group; a substituted or unsubstituted silyl group; a substituted or unsubstituted alkyl group having 1 to 30 carbon atoms; a substituted or unsubstituted cycloalkyl group having 3 to 30 carbon atoms; a substituted or unsubstituted aryl group having 6 to 30 carbon atoms; or a substituted or unsubstituted heterocyclic group having 2 to 30 carbon atoms, or are bonded to an adjacent group to form a substituted or unsubstituted ring having 2 to 30 carbon atoms.

In an exemplary embodiment of the present specification, T1 to T4 are the same as or different from each other, and are each independently hydrogen; deuterium; a halogen group; a nitrile group; a substituted or unsubstituted silyl group; a substituted or unsubstituted alkyl group having 1 to 20 carbon atoms; a substituted or unsubstituted cycloalkyl group having 3 to 20 carbon atoms; a substituted or unsubstituted aryl group having 6 to 20 carbon atoms; or a substituted or unsubstituted heterocyclic group having 2 to 20 carbon atoms, or are bonded to an adjacent group to form a substituted or unsubstituted ring having 2 to 20 carbon atoms.

In an exemplary embodiment of the present specification, T1 to T4 are the same as or different from each other, and are each independently hydrogen; deuterium; a substituted or unsubstituted alkyl group; or a substituted or unsubstituted aryl group, or are bonded to an adjacent group to form a dibenzofuran ring; or a dibenzothiophene ring.

In an exemplary embodiment of the present specification, T1 to T4 are the same as or different from each other, and are each independently hydrogen; deuterium; a substituted or unsubstituted alkyl group having 1 to 60 carbon atoms; or a substituted or unsubstituted aryl group having 6 to 60 carbon atoms, or are bonded to an adjacent group to form a substituted or unsubstituted hetero ring having 2 to 60 carbon atoms.

In an exemplary embodiment of the present specification, T1 to T4 are the same as or different from each other, and are each independently hydrogen; deuterium; a substituted or unsubstituted alkyl group having 1 to 30 carbon atoms; or a substituted or unsubstituted aryl group having 6 to 30 carbon atoms, or are bonded to an adjacent group to form a substituted or unsubstituted hetero ring having 2 to 30 carbon atoms.

In an exemplary embodiment of the present specification, T1 to T4 are the same as or different from each other, and are each independently hydrogen; deuterium; a substituted or unsubstituted alkyl group having 1 to 20 carbon atoms; or a substituted or unsubstituted aryl group having 6 to 20 carbon atoms, or are bonded to an adjacent group to form a substituted or unsubstituted hetero ring having 2 to 20 carbon atoms.

In an exemplary embodiment of the present specification, T1 to T4 are the same as or different from each other, and are each independently hydrogen; deuterium; a substituted or unsubstituted methyl group; a substituted or unsubstituted ethyl group; a substituted or unsubstituted propyl group; a substituted or unsubstituted butyl group; a substituted or unsubstituted phenyl group; a substituted or unsubstituted biphenyl group; or a substituted or unsubstituted terphenyl group, or are bonded to an adjacent group to form a substituted or unsubstituted dibenzofuran ring; or a substituted or unsubstituted dibenzothiophene ring.

In an exemplary embodiment of the present specification, T1 to T4 are the same as or different from each other, and are each independently hydrogen; deuterium; a methyl group; an ethyl group; a propyl group; a butyl group; a phenyl group; a biphenyl group; or a terphenyl group, or are bonded to an adjacent group to form a dibenzofuran ring; or a dibenzothiophene ring.

In an exemplary embodiment of the present specification, T1 to T4 are the same as or different from each other, and are each independently hydrogen; or deuterium; a butyl group; or a phenyl group, or are bonded to an adjacent group to form a dibenzofuran ring.

In an exemplary embodiment of the present specification, T1 is bonded to an adjacent group to form a dibenzofuran ring.

In an exemplary embodiment of the present specification, T2 to T4 are the same as or different from each other, and are each independently hydrogen; or deuterium.

In an exemplary embodiment of the present specification, T2 to T4 are hydrogen.

In an exemplary embodiment of the present specification, T11 to T13 and T21 to T24 are the same as or different from each other, and are each independently hydrogen; deuterium; a halogen group; a nitrile group; a substituted or unsubstituted silyl group; a substituted or unsubstituted alkyl group; a substituted or unsubstituted cycloalkyl group; a substituted or unsubstituted aryl group; or a substituted or unsubstituted heterocyclic group, or are bonded to an adjacent group to form a substituted or unsubstituted ring.

In an exemplary embodiment of the present specification, T11 to T13 and T21 to T24 are the same as or different from each other, and are each independently hydrogen; deuterium; a halogen group; a nitrile group; a substituted or unsubstituted silyl group; a substituted or unsubstituted alkyl group having 1 to 60 carbon atoms; a substituted or unsubstituted cycloalkyl group having 3 to 60 carbon atoms; a substituted or unsubstituted aryl group having 6 to 60 carbon atoms; or a substituted or unsubstituted heterocyclic group having 2 to 60 carbon atoms, or are bonded to an adjacent group to form a substituted or unsubstituted ring having 2 to 60 carbon atoms.

In an exemplary embodiment of the present specification, T11 to T13 and T21 to T24 are the same as or different from each other, and are each independently hydrogen; deuterium; a halogen group; a nitrile group; a substituted or unsubstituted silyl group; a substituted or unsubstituted alkyl group having 1 to 30 carbon atoms; a substituted or unsubstituted cycloalkyl group having 3 to 30 carbon atoms; a substituted or unsubstituted aryl group having 6 to 30 carbon atoms; or a substituted or unsubstituted heterocyclic group having 2 to 30 carbon atoms, or are bonded to an adjacent group to form a substituted or unsubstituted ring having 2 to 30 carbon atoms.

In an exemplary embodiment of the present specification, T11 to T13 and T21 to T24 are the same as or different from each other, and are each independently hydrogen; deuterium; a halogen group; a nitrile group; a substituted or unsubstituted silyl group; a substituted or unsubstituted alkyl group having 1 to 20 carbon atoms; a substituted or unsubstituted cycloalkyl group having 3 to 20 carbon atoms; a substituted or unsubstituted aryl group having 6 to 20 carbon atoms; or a substituted or unsubstituted heterocyclic group having 2 to 20 carbon atoms, or are bonded to an adjacent group to form a substituted or unsubstituted ring having 2 to 20 carbon atoms.

In an exemplary embodiment of the present specification, T11 to T13 and T21 to T24 are the same as or different from each other, and are each independently hydrogen; deuterium; a substituted or unsubstituted phenyl group; a substituted or unsubstituted biphenyl group; or a substituted or unsubstituted terphenyl group.

In an exemplary embodiment of the present specification, T11 to T13 and T21 to T24 are the same as or different from each other, and are each independently hydrogen; deuterium; a substituted or unsubstituted phenyl group; or a substituted or unsubstituted biphenyl group.

In an exemplary embodiment of the present specification, T11 to T13 and T21 to T24 are the same as or different from each other, and are each independently hydrogen; deuterium; or a substituted or unsubstituted phenyl group.

In an exemplary embodiment of the present specification, Chemical Formula 2 is represented by the following Chemical Formula 2-B-1 or 2-B-2.

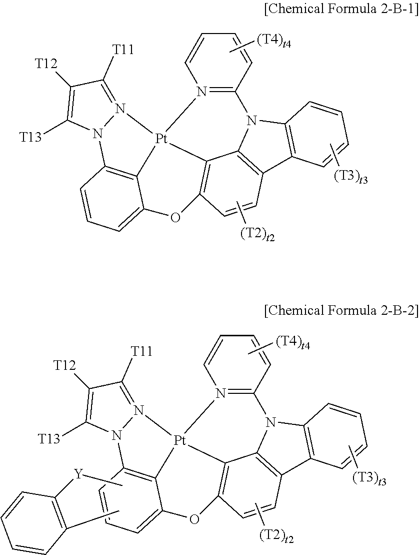

In Chemical Formulae 2-B-1 and 2-B-2,
the definitions of T2 to T4 and t2 to t4 are the same as the definitions in Chemical Formula 2, and
Y is O; or S, and
T11 to T13 are the same as or different from each other, and are each independently hydrogen; deuterium; a halogen group; a nitrile group; a substituted or unsubstituted silyl group; a substituted or unsubstituted alkyl group; a substituted or unsubstituted cycloalkyl group; a substituted or unsubstituted aryl group; or a substituted or unsubstituted heterocyclic group, or are bonded to an adjacent group to form a substituted or unsubstituted ring.

In an exemplary embodiment of the present specification, Y is O.

In an exemplary embodiment of the present specification, Y is S.

In an exemplary embodiment of the present specification, t1 is an integer from 0 to 3.

In an exemplary embodiment of the present specification, t1 is 0.

In an exemplary embodiment of the present specification, t1 is 1.

In an exemplary embodiment of the present specification, t1 is 3.

In an exemplary embodiment of the present specification, t2 is an integer from 0 to 2.

In an exemplary embodiment of the present specification, t2 is 0.

In an exemplary embodiment of the present specification, t2 is 1.

In an exemplary embodiment of the present specification, t2 is 2.

In an exemplary embodiment of the present specification, t3 is an integer from 0 to 4.

In an exemplary embodiment of the present specification, t3 is 0.

In an exemplary embodiment of the present specification, t3 is 1.

In an exemplary embodiment of the present specification, t3 is 4.

In an exemplary embodiment of the present specification, t4 is an integer from 0 to 3.

In an exemplary embodiment of the present specification, t4 is 0.

In an exemplary embodiment of the present specification, t4 is 1.

In an exemplary embodiment of the present specification, t4 is 3.

In an exemplary embodiment of the present specification, 20% or more of the compound represented by Chemical Formula 2 is substituted with deuterium. In another exemplary embodiment, 30% or more of the compound represented by Chemical Formula 2 is substituted with deuterium. In still another exemplary embodiment, 40% or more of the compound represented by Chemical Formula 2 is substituted with deuterium. In yet another exemplary embodiment, 50% or more of the compound represented by Chemical Formula 2 is substituted with deuterium. In still yet another exemplary embodiment, 60% or more of the compound represented by Chemical Formula 2 is substituted with deuterium. In a further exemplary embodiment, 70% or more of the compound represented by Chemical Formula 2 is substituted with deuterium. In another further exemplary embodiment, 80% or more of the compound represented by Chemical Formula 2 is substituted with deuterium. In still another further exemplary embodiment, 90% or more of the compound represented by Chemical Formula 2 is substituted with deuterium. In yet another further exemplary embodiment, 100% of the compound represented by Chemical Formula 2 is substituted with deuterium.

In an exemplary embodiment of the present specification, the compound represented by Chemical Formula 2 includes 40% to 60% of deuterium. In another exemplary embodiment, the compound represented by Chemical Formula 2 includes 40% to 80% of deuterium. In still another exemplary embodiment, the compound represented by Chemical Formula 2 includes 60% to 80% of deuterium. In yet another exemplary embodiment, the compound represented by Chemical Formula 2 includes 80% to 100% of deuterium.

In an exemplary embodiment of the present specification, Chemical Formula 2 is represented by any one of the following compounds.

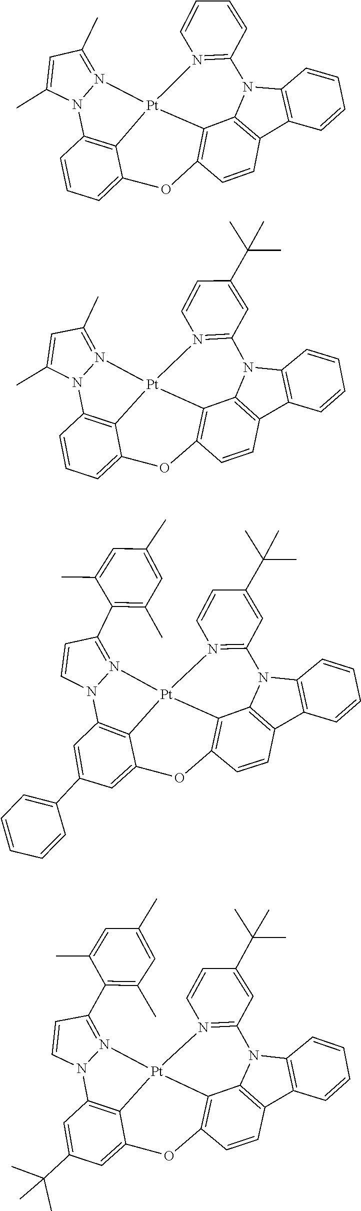

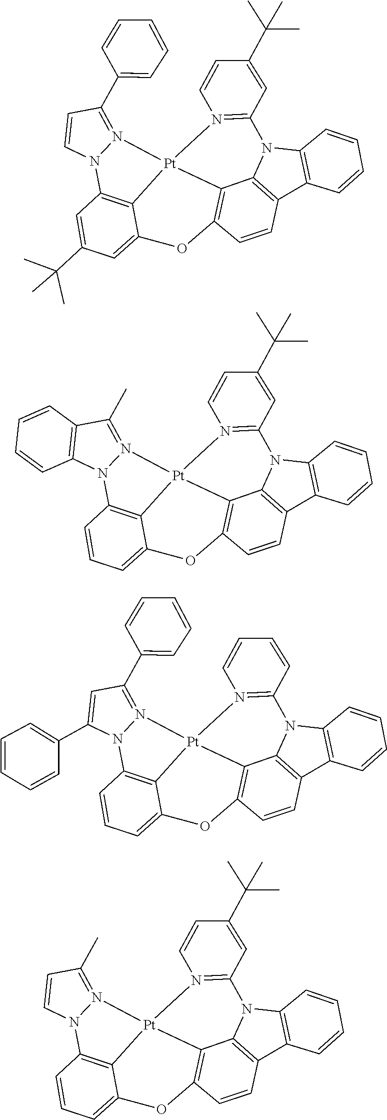

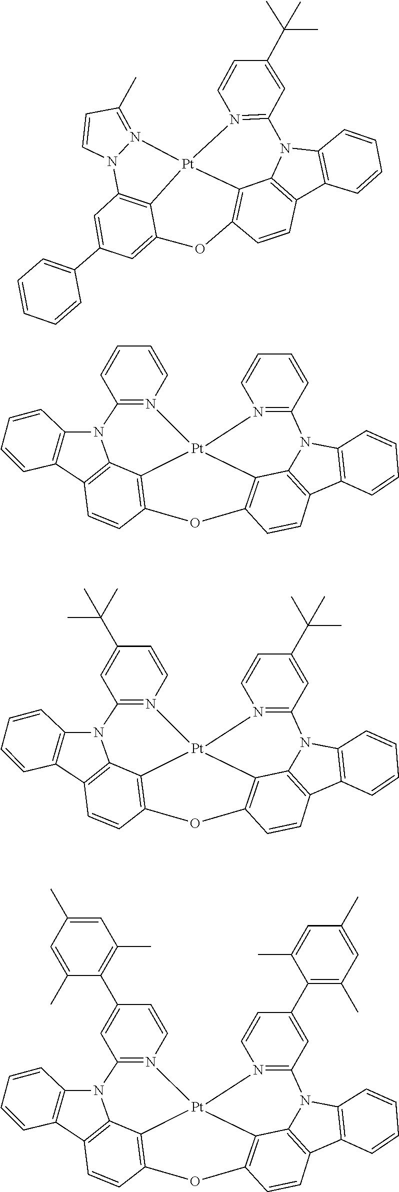

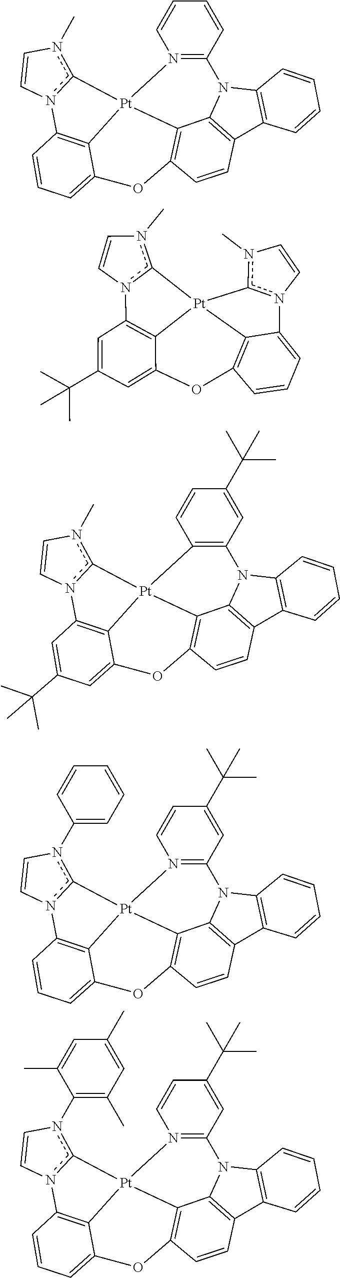

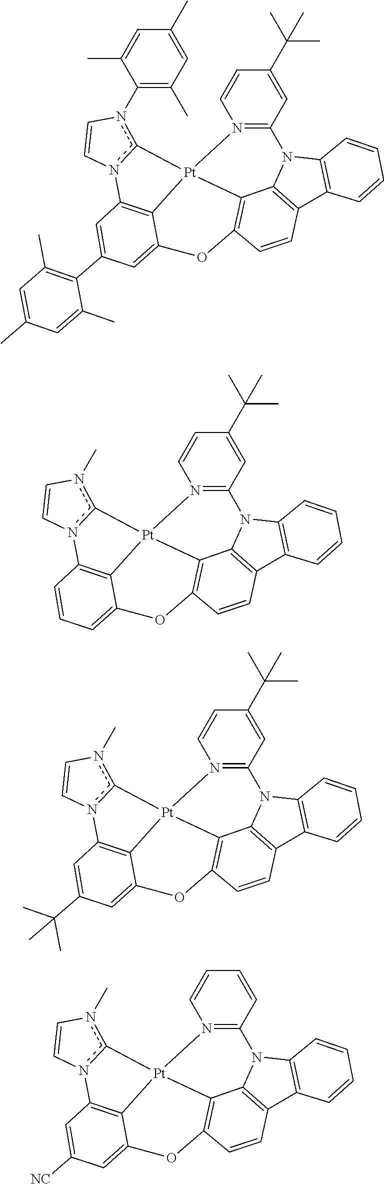

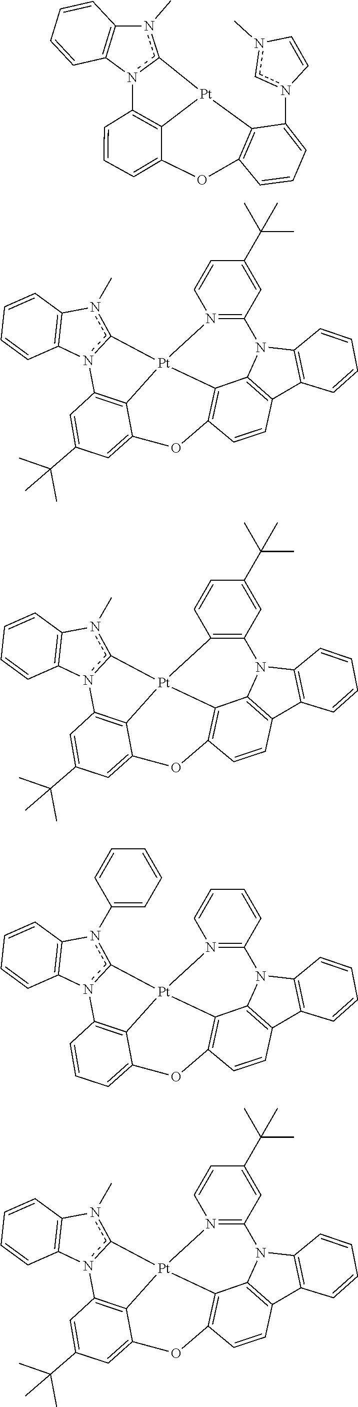

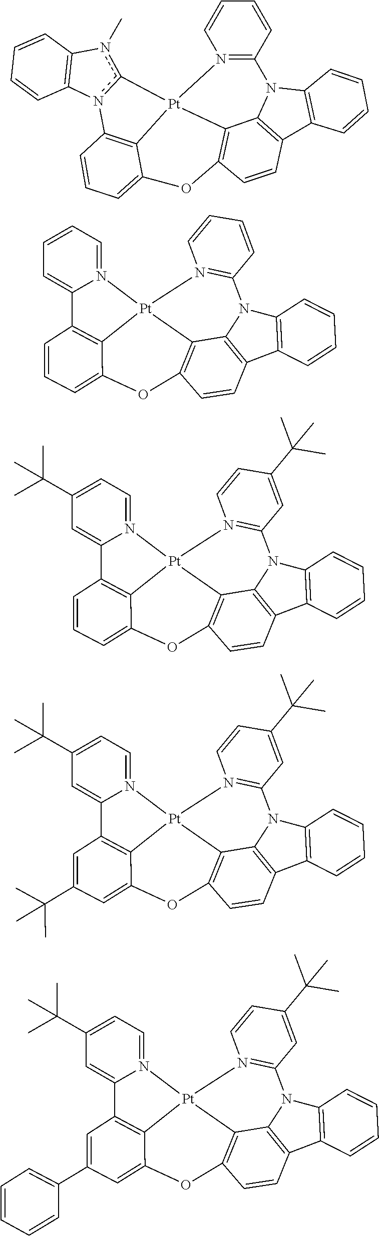

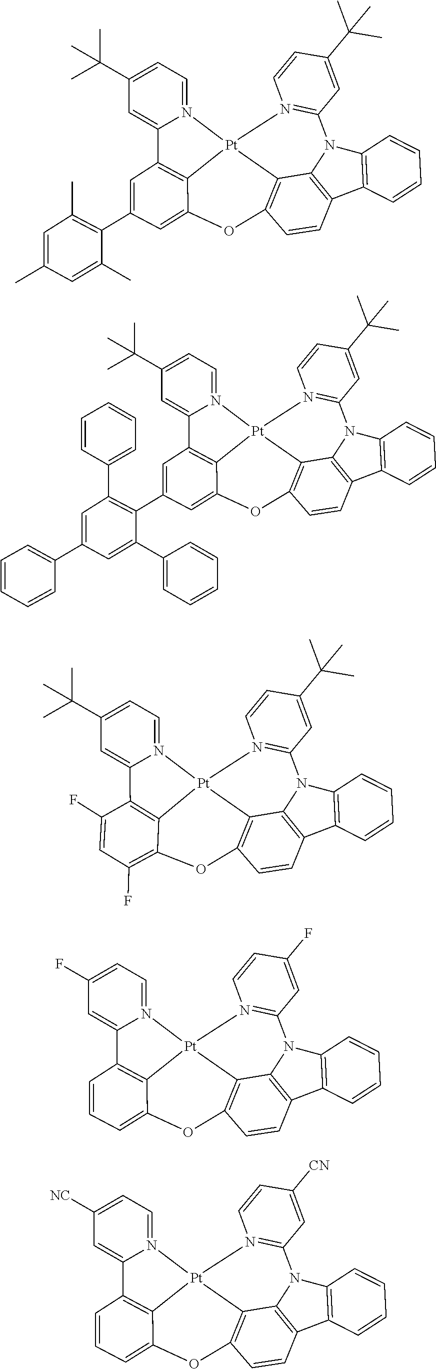

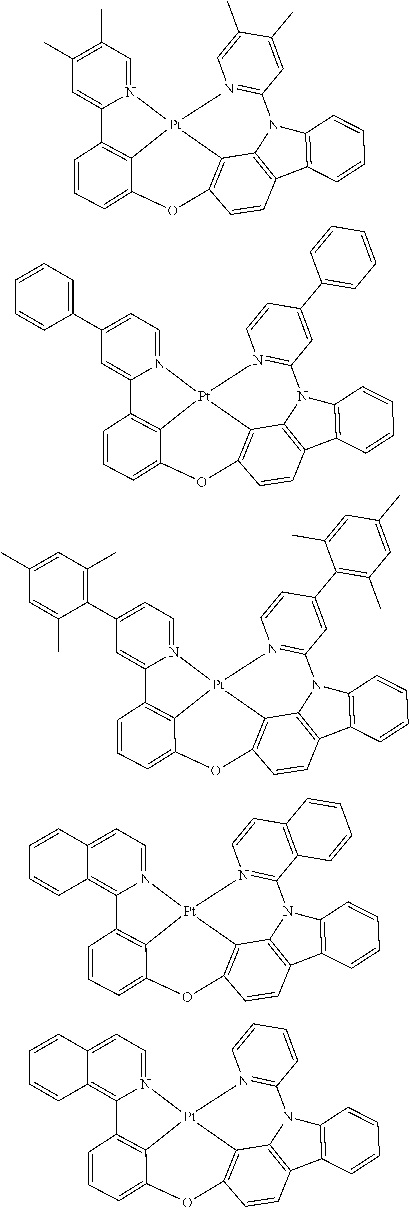

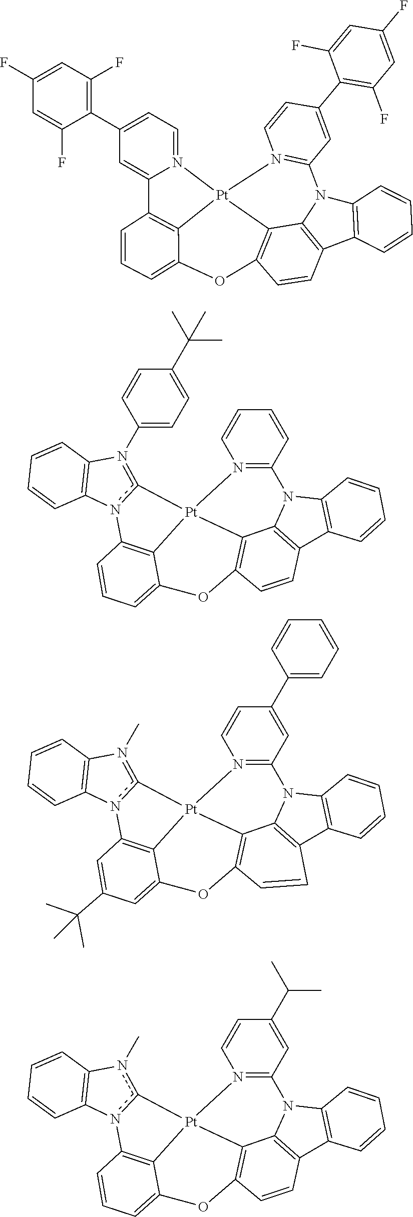

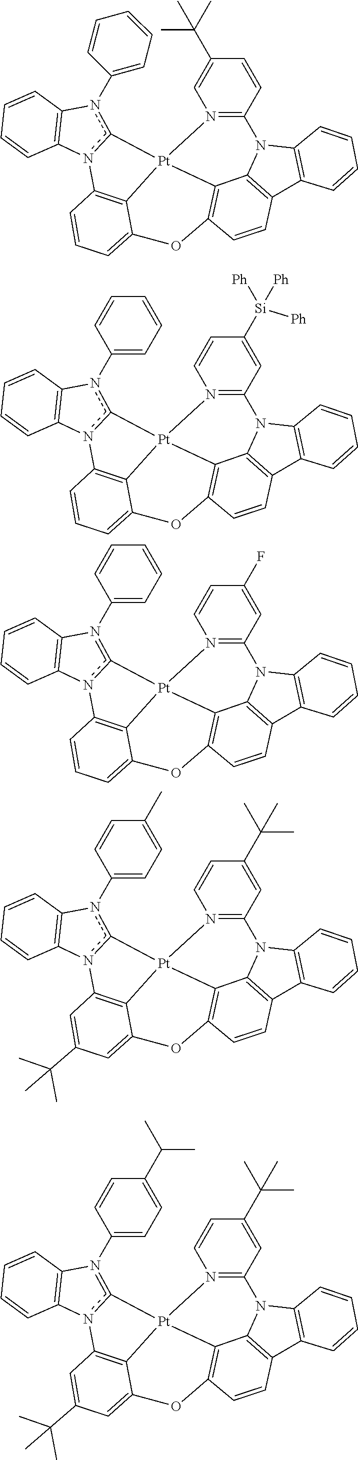

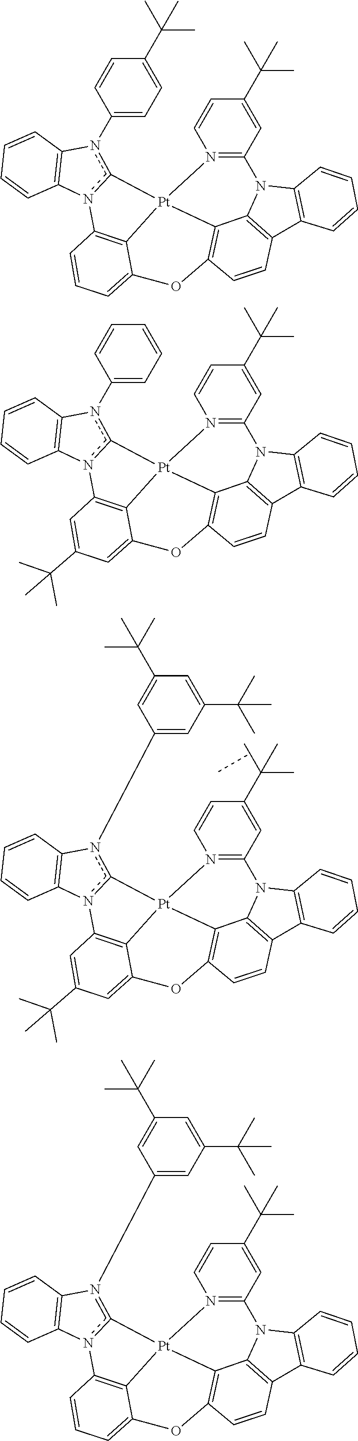

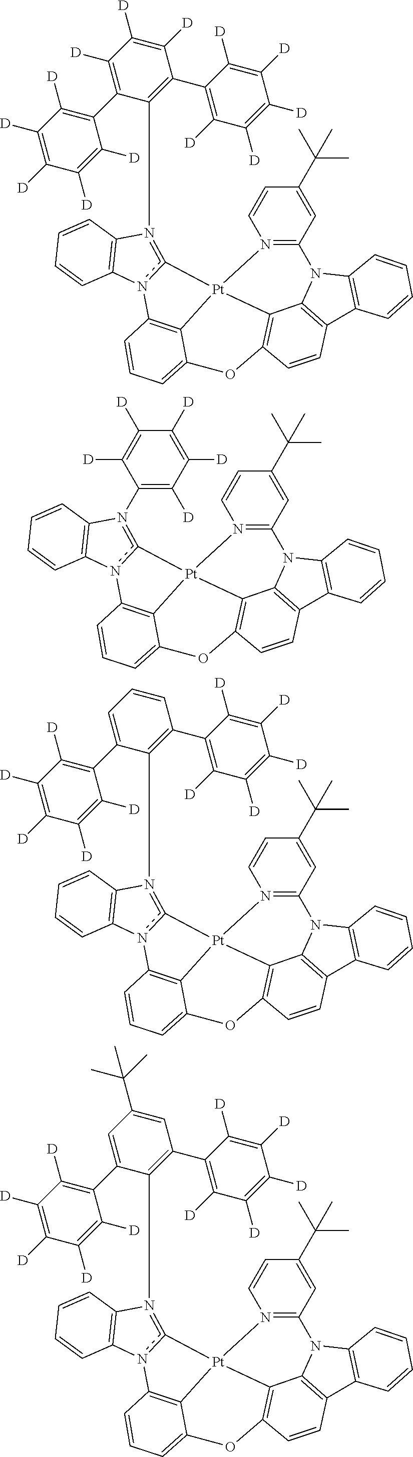

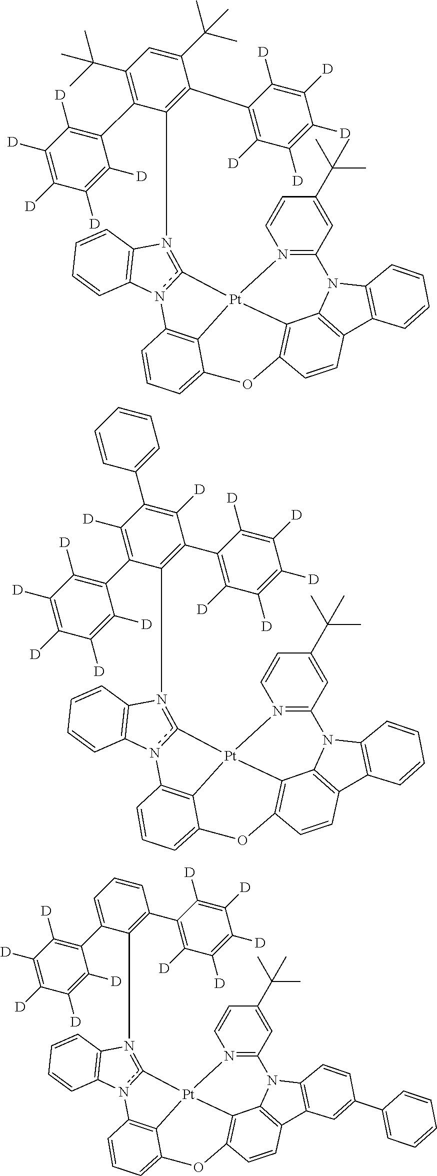

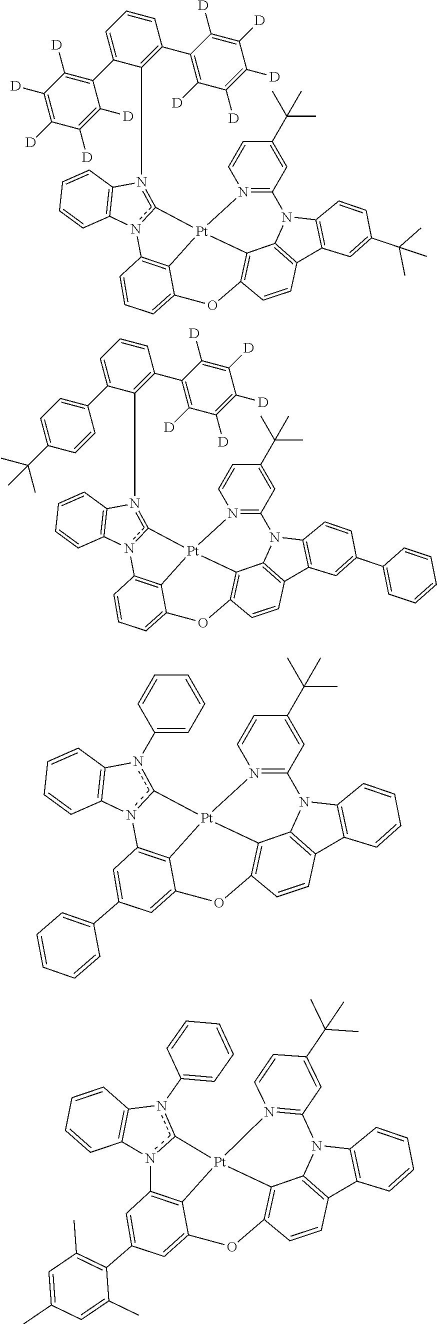

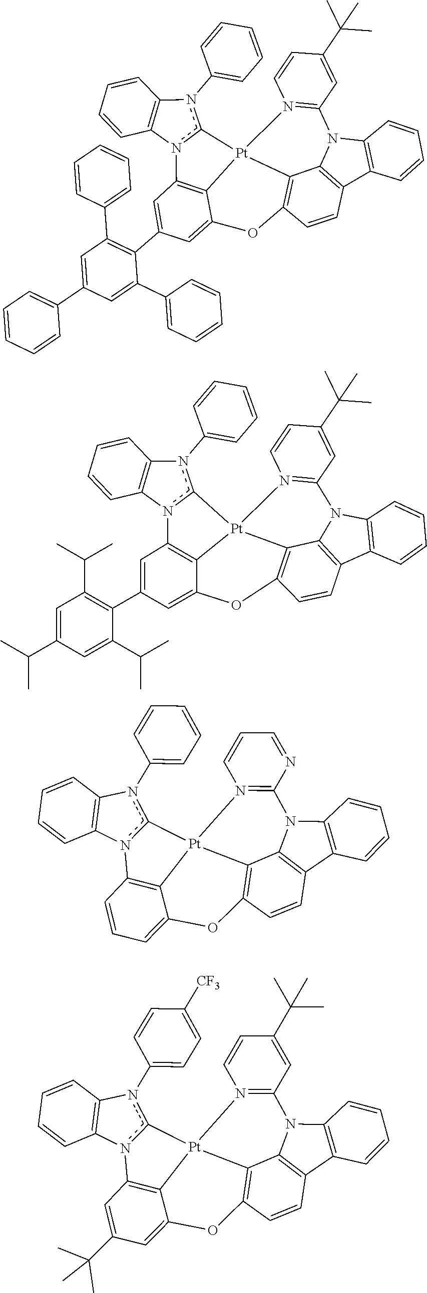

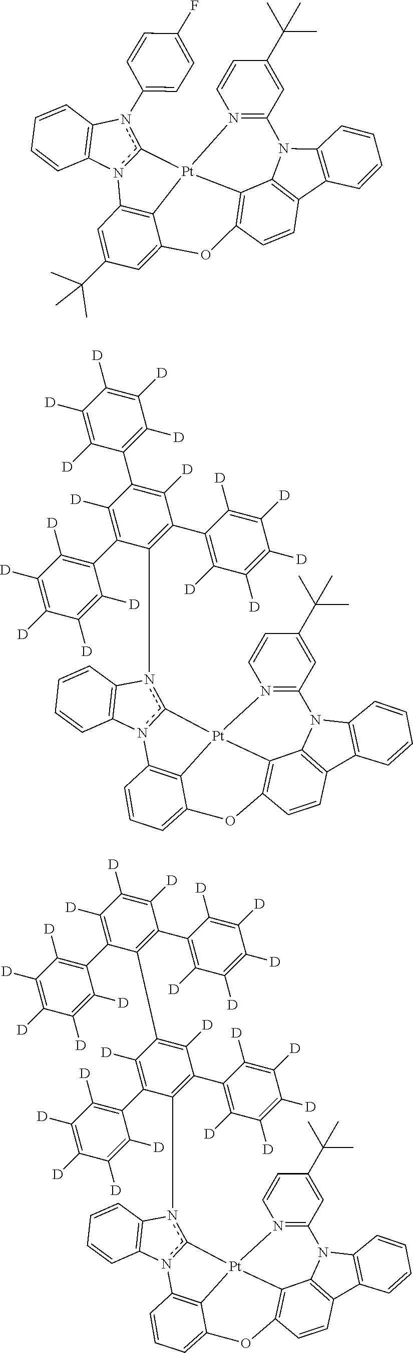

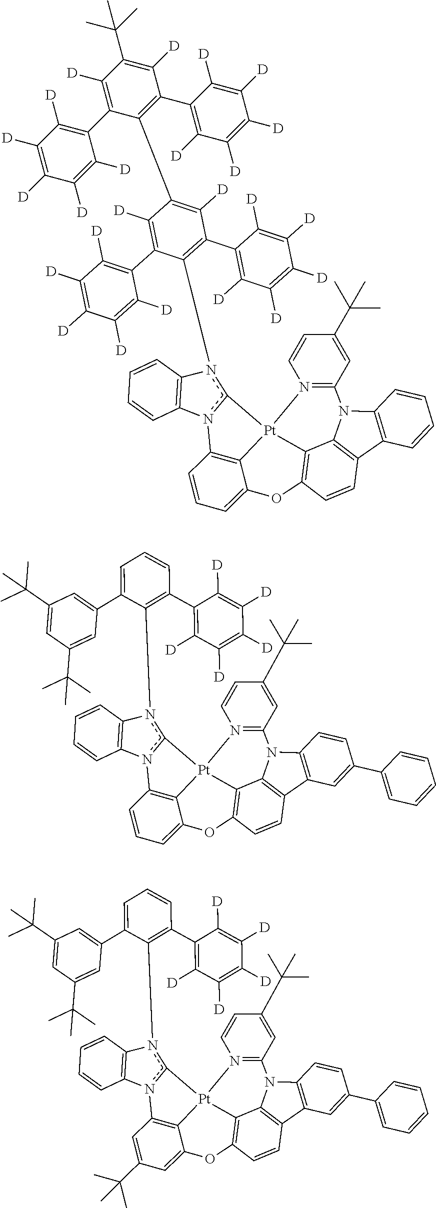

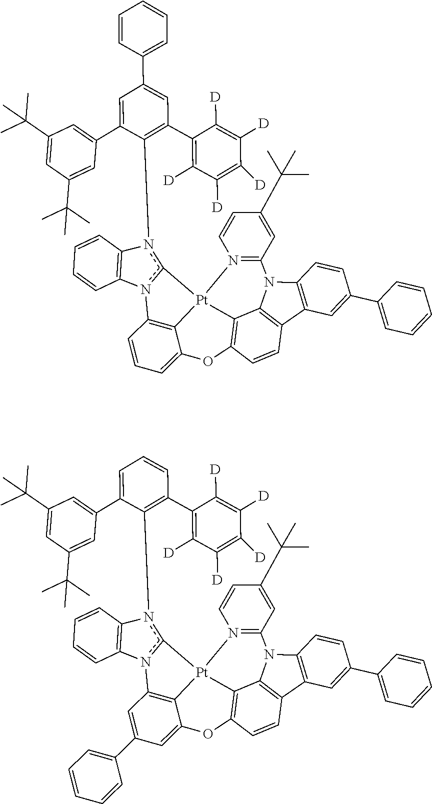

A core structure may be prepared as the following Reaction Scheme 2 from the compound represented by Chemical Formula 2 according to an exemplary embodiment of the present specification. The substituent may be bonded by a method known in the art, and the kind and position of the substituent or the number of substituents may be changed according to the technology known in the art.

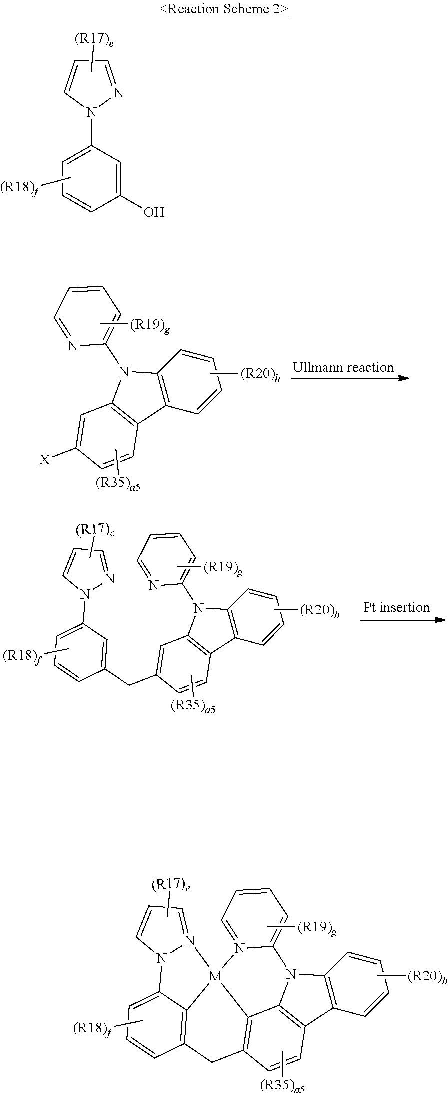

In the present specification, compounds having various energy band gaps may be synthesized by introducing various substituents into each of the core structures of the compound represented by Chemical Formula 1 and the compound represented by Chemical Formula 2. Further, in the present specification, various substituents may be introduced into the core structures having the structure described above to adjust the HOMO and LUMO energy levels of a compound.

Hereinafter, the organic light emitting device according to the present invention will be described.

In an exemplary embodiment of the present invention, provided is an organic light emitting device including: an anode; a cathode; and an organic material layer having one or more layers provided between the anode and the cathode, in which one or more layers of the organic material layer include the compound represented by Chemical Formula 1 and the compound represented by Chemical Formula 2.

The organic light emitting device of the present specification may be manufactured by typical methods and materials for manufacturing an organic light emitting device, except that an organic material layer is formed using the above-described compound of Chemical Formula 1 and the above-described compound of Chemical Formula 2.

The organic material layer of the organic light emitting device of the present specification may also have a single-layered structure, but may have a multi-layered structure in which two or more organic material layers are stacked. For example, the organic light emitting device of the present invention may have a structure including one or more layers of a hole transport layer, a hole injection layer, an electron blocking layer, a hole transport and injection layer, a light emitting layer, an electron transport layer, an electron injection layer, a hole blocking layer, and an electron transport and injection layer as organic material layers. However, the structure of the organic light emitting device of the present specification is not limited thereto, and may include a fewer or greater number of organic material layers.

In an exemplary embodiment of the present specification, the organic material layer includes a light emitting layer, and the light emitting layer may include the compound represented by Chemical Formula 2 as a dopant.

In an exemplary embodiment of the present specification, the organic material layer includes a light emitting layer, and the light emitting layer may include two or more of the compounds represented by Chemical Formula 2 as a dopant.

In an exemplary embodiment of the present specification, the organic material layer includes an electron injection layer, an electron transport layer, an electron transport and injection layer, or a hole blocking layer, and the electron injection layer, the electron transport layer, the electron transport and injection layer, or the hole blocking layer may include the compound represented by Chemical Formula 1 and the compound represented by Chemical Formula 2.

In the organic light emitting device of the present specification, the organic material layer includes an electron transport layer, an electron injection layer, or an electron transport and injection layer, and the electron transport layer, the electron injection layer, or the electron transport and injection layer may include the compound represented by Chemical Formula 1 and the compound represented by Chemical Formula 2.

In an exemplary embodiment of the present specification, the organic material layer includes an electron adjusting layer, and the electron adjusting layer may include the compound represented by Chemical Formula 1 and the compound represented by Chemical Formula 2.

In an exemplary embodiment of the present specification, the organic material layer includes a hole blocking layer, and the hole blocking layer may include the compound represented by Chemical Formula 1 and the compound represented by Chemical Formula 2.

In an exemplary embodiment of the present specification, the organic material layer includes a hole blocking layer and a light emitting layer, and the hole blocking layer and the light emitting layer may include the compound represented by Chemical Formula 1 and the compound represented by Chemical Formula 2. In this case, the compounds represented by Chemical Formula 1 included in the light emitting layer and the hole blocking layer may be the same or different, and the compounds represented by Chemical Formula 2 included in the light emitting layer and the hole blocking layer may be the same or different.

In an exemplary embodiment of the present specification, the organic material layer includes a light emitting layer, and the light emitting layer may include the compound represented by Chemical Formula 1 and the compound represented by Chemical Formula 2.

In an exemplary embodiment of the present specification, the organic material layer includes a light emitting layer, and the light emitting layer may include the compound represented by Chemical Formula 1 as a host.

In an exemplary embodiment of the present specification, the organic material layer includes a light emitting layer, and the light emitting layer may include the compound represented by Chemical Formula 1 as an n-type phosphorescent host of the light emitting layer.

In an exemplary embodiment of the present specification, the organic material layer includes a light emitting layer, and the light emitting layer may include two or more of the compounds represented by Chemical Formula 1 as a host.

In an exemplary embodiment of the present specification, the organic material layer includes a light emitting layer, and the light emitting layer includes the compound represented by Chemical Formula 1 as a first host, and may further include an additional second host.

In an exemplary embodiment of the present specification, the first host is an n-type phosphorescent host, and the second host is a p-type phosphorescent host. In this case, the weight ratio of the first host to the second host may be 2:8 to 8:2, or 4:6 to 6:4, or 5:5.

The n-type is a material capable of stealing electrons from a matrix material (a material of an organic layer), and commonly known materials may be used, but the material is not limited thereto. That is, the n-type may be defined as a material that has characteristics capable of providing electrons to the LUMO (lowest unoccupied molecular orbital) energy level of the matrix. Conversely, the p-type is a material that, when one layer is composed of only the p-type material, receives electrons at the highest occupied molecular orbital (HOMO) energy level of the material located in the adjacent cathode direction to generate holes in the adjacent cathode direction material, or a material that, when any matrix is doped with the p-type material, receives electrons from the HOMO of the matrix material and generate holes in the HOMO of the matrix as many as the number of electrons received, and for this purpose, when a layer is formed using only a p-type material, the more adjacent the HOMO level of the material located in the cathode direction is to the LUMO of the p-type material, the more likely it is that electrons are stolen from the HOMO of the adjacent layer and holes are generated in the HOMO of the adjacent layer, and further, when any matrix is doped with the p-type material, the more adjacent the LUMO of the p-type material is to the HOMO of the matrix, the more likely it is that electrons are stolen and holes are generated in the matrix.

Compounds commonly known in the art may be applied as the p-type host, and for example, the p-type host may have a structure including an N-containing monocyclic ring; dibenzofuran; and/or carbazole.

In an exemplary embodiment of the present specification, the second host is a carbazole-based compound.

In an exemplary embodiment of the present specification, the second host is a biscarbazole-based compound.

In an exemplary embodiment of the present specification, the second host is a biscarbazole-based compound substituted with an aryl group.

In an exemplary embodiment of the present specification, the light emitting layer includes a first host and a second host, and may further include a dopant, and the dopant may be a phosphorescent dopant.

In an exemplary embodiment of the present specification, the organic material layer includes a light emitting layer, and the light emitting layer may be a blue light emitting layer, a red light emitting layer, or a green light emitting layer.

In an exemplary embodiment of the present specification, the organic material layer includes a light emitting layer, and the light emitting layer may be a blue light emitting layer.

In an exemplary embodiment of the present specification, the light emitting layer may include a host and a dopant. Specifically, the dopant may be a fluorescent dopant or a phosphorescent dopant.

In an exemplary embodiment of the present specification, the organic material layer includes a light emitting layer, and the light emitting layer includes the compound represented by Chemical Formula 2 as a dopant, and may further include an additional dopant.

In an exemplary embodiment of the present specification, the dopant may include an arylamine-based compound, a heterocyclic compound including boron and nitrogen, a metal complex compound, a platinum complex compound, an iridium complex compound, an iridium-based compound, and the like.

For example, when the light emitting layer emits red light, phosphorescent materials such as bis(1-phenylisoquinoline)acetylacetonate iridium (PIQIr(acac)), bis(1-phenylquinoline)acetylacetonate iridium (PQIr(acac)), tris(1-phenylquinoline)iridium (PQIr) or octaethylporphyrin platinum (PtOEP), or fluorescent materials such as tris(8-hydroxyquinolino)aluminum (Alq₃) may be used as the light emitting dopant, however, the light emitting dopant is not limited thereto. When the light emitting layer emits green light, it is possible to use a phosphorescent material such as fac tris(2-phenylpyridine)iridium (Ir(ppy)₃), or a fluorescent material such as tris(8-hydroxyquinolino)aluminum (Alq₃), as the light emitting dopant, but the light emitting dopant is not limited thereto. When the light emitting layer emits blue light, it is possible to use a platinum complex compound, a phosphorescent material such as (4,6-F2ppy)2Irpic, or a fluorescent material such as spiro-DPVBi, spiro-6P, distyryl benzene (DSB), distyryl arylene (DSA), a PFO-based polymer or a PPV-based polymer as the light emitting dopant, but the light emitting dopant is not limited thereto.

In an exemplary embodiment of the present specification, the dopant is included in an amount of 1 to 20 parts by weight with respect to 100 parts by weight of the host.

In an exemplary embodiment of the present specification, the light emitting layer includes the host and the dopant at a weight ratio of 99:1 to 1:99. Specifically, the light emitting layer includes the host and the dopant at a weight ratio of 99:1 to 50:50, at a weight ratio of 99:1 to 70:30, at a weight ratio of 99:1 to 80:20, at a weight ratio of 99:1 to 90:10, or a weight ratio of 99:1 to 95:5. Within the above range, energy transfer from the host to the dopant occurs efficiently.

In an exemplary embodiment of the present specification, the organic material layer includes a light emitting layer, and the light emitting layer includes the compound represented by Chemical Formula 1 and the compound represented by Chemical Formula 2, and may further include another fluorescent host, phosphorescent host, fluorescent dopant, or phosphorescent dopant.

In an exemplary embodiment of the present specification, the organic material layer includes a light emitting layer having two or more layers, and one or more layers of the light emitting layer having two or more layers include the compound represented by Chemical Formula 1 and the compound represented by Chemical Formula 2.

In an exemplary embodiment of the present specification, the organic material layer includes a light emitting layer having two or more layers, and the light emitting layer having two or more layers each includes the compound represented by Chemical Formula 1 and the compound represented by Chemical Formula 2.

In an exemplary embodiment of the present specification, the organic material layer may include a light emitting layer having two or more layers, and the maximum light emitting peaks of the light emitting layer having two or more layers may be different from each other. The light emitting layer including the compound represented by Chemical Formula 1 and the compound represented by Chemical Formula 2 takes on a blue color, and a light emitting layer which does not include the compound represented by Chemical Formula 1 and the compound represented by Chemical Formula 2 may include a blue, red, or green light emitting compound known in the art.

In an exemplary embodiment of the present specification, the maximum light emission peak of the light emitting layer including the compound represented by Chemical Formula 1 and the compound represented by Chemical Formula 2 may be 400 nm to 500 nm. That is, the light emitting layer including the compound represented by Chemical Formula 1 and the compound represented by Chemical Formula 2 may emit blue light.

In an exemplary embodiment of the present specification, the organic material layer includes a light emitting layer having two or more layers, a light emitting layer having one layer (Light emitting layer 1) has a maximum light emission peak of 400 nm to 500 nm, and the maximum light emission peak of a light emitting layer having the other layer (Light emitting layer 2) may exhibit a maximum light emission peak of 510 nm to 580 nm; or 610 nm to 680 nm. In this case, Light emitting layer 1 may include the compound represented by Chemical Formula 1 and the compound represented by Chemical Formula 2. Furthermore, Light emitting layer 2 may include the compound represented by Chemical Formula 1 and the compound represented by Chemical Formula 2, or may include other compounds.

The organic light emitting device of the present specification may further include an organic material layer having one or more layers of a hole transport layer, a hole injection layer, an electron blocking layer, an electron transport and injection layer, an electron transport layer, an electron injection layer, a hole blocking layer, and a hole injection and transport layer.

In an exemplary embodiment of the present specification, the organic light emitting device includes: an anode; a cathode; and an organic material layer having two or more layers provided between the anode and the cathode, and at least one of the organic material layers having two or more layers includes the compound represented by Chemical Formula 1 and the compound represented by Chemical Formula 2.

In an exemplary embodiment of the present specification, as the organic material layer having two or more layers, two or more may be selected from the group consisting of a light emitting layer, an electron transport layer, an electron injection layer, an electron transport and injection layer, an electron adjusting layer and a hole blocking layer.

In an exemplary embodiment of the present specification, the organic material layer includes an electron transport layer having two or more layers, and at least one of the electron transport layers having two or more layers includes the compound represented by Chemical Formula 1 and the compound represented by Chemical Formula 2. Specifically, the compound represented by Chemical Formula 1 and the compound represented by Chemical Formula 2 may also be included in one layer of the electron transport layer having two or more layers, and may be included in each of the electron transport layer having two or more layers.

Further, in an exemplary embodiment of the present specification, when the compound represented by Chemical Formula 1 and the compound represented by Chemical Formula 2 are included in each of the electron transport layer having two or more layers, the other materials except for the compound represented by Chemical Formula 1 and the compound represented by Chemical Formula 2 may be the same as or different from each other.

When an organic material layer including the compound represented by Chemical Formula 1 and the compound represented by Chemical Formula 2 is an electron transport layer, an electron injection layer, or an electron transport and injection layer, the electron transport layer, the electron injection layer, or the electron transport and injection layer may further include an n-type dopant or an organic metal compound. As the n-type dopant or organic metal compound, those known in the art may be used, for example, a metal or a metal complex may be used.

For example, the n-type dopant or organic metal compound may be LiQ, and is not limited thereto. The electron transport layer, the electron injection layer, or the electron transport and injection layer, which includes the compound represented by Chemical Formula 1 and the compound represented by Chemical Formula 2, may further include lithium quinolate (LiQ).

In an exemplary embodiment of the present specification, the organic material layer includes a hole transport layer having two or more layers, and at least one of the hole transport layers having two or more layers includes the compound represented by Chemical Formula 1 and the compound represented by Chemical Formula 2. Specifically, in an exemplary embodiment of the present specification, the compound represented by Chemical Formula 1 and the compound represented by Chemical Formula 2 may also be included in one layer of the hole transport layer having two or more layers, and may be included in each of the hole transport layer having two or more layers.

In addition, in an exemplary embodiment of the present specification, when the compound represented by Chemical Formula 1 and the compound represented by Chemical Formula 2 are included in each of the hole transport layer having two or more layers, the other materials except for the compound represented by Chemical Formula 1 and the compound represented by Chemical Formula 2 may be the same as or different from each other.

In an exemplary embodiment of the present specification, the organic material layer may further include a hole injection layer or a hole transport layer, which includes a compound including an arylamine group, a carbazolyl group, or a benzocarbazolyl group, in addition to the organic material layer including the compound represented by Chemical Formula 1 and the compound represented by Chemical Formula 2.

In an exemplary embodiment of the present specification, the organic material layer including the compound represented by Chemical Formula 1 and the compound represented by Chemical Formula 2 may have a thickness of 5 Å to 2000 Å, or 5 Å to 500 Å, and has a thickness of preferably 10 Å to 400 Å.

In another exemplary embodiment, the organic material layer may further include another organic compound, metal or metal compound in addition to the above-described compound represented by Chemical Formula 1 and the above-described compound represented by Chemical Formula 2.

In an exemplary embodiment of the present specification, the organic light emitting device may be a normal type organic light emitting device in which an anode, an organic material layer having one or more layers, and a cathode are sequentially stacked on a substrate.

In an exemplary embodiment of the present specification, the organic light emitting device may be an inverted type organic light emitting device in which a cathode, an organic material layer having one or more layers, and an anode are sequentially stacked on a substrate.

The organic light emitting device may have, for example, the stacking structure described below, but the stacking structure is not limited thereto.
(1) Anode/Hole transport layer/Light emitting layer/Cathode
(2) Anode/Hole injection layer/Hole transport layer/Light emitting layer/Cathode
(3) Anode/Hole injection layer/Hole buffer layer/Hole transport layer/Light emitting layer/Cathode
(4) Anode/Hole transport layer/Light emitting layer/Electron transport layer/Cathode
(5) Anode/Hole transport layer/Light emitting layer/Electron transport layer/Electron injection layer/Cathode
(6) Anode/Hole injection layer/Hole transport layer/Light emitting layer/Electron transport layer/Cathode
(7) Anode/Hole injection layer/Hole transport layer/Light emitting layer/Electron transport layer/Electron injection layer/Cathode
(8) Anode/Hole injection layer/Hole buffer layer/Hole transport layer/Light emitting layer/Electron transport layer/Cathode
(9) Anode/Hole injection layer/Hole buffer layer/Hole transport layer/Light emitting layer/Electron transport layer/Electron injection layer/Cathode
(10) Anode/Hole transport layer/Electron blocking layer/Light emitting layer/Electron transport layer/Cathode
(11) Anode/Hole transport layer/Electron blocking layer/Light emitting layer/Electron transport layer/Electron injection layer/Cathode
(12) Anode/Hole injection layer/Hole transport layer/Electron blocking layer/Light emitting layer/Electron transport layer/Cathode
(13) Anode/Hole injection layer/Hole transport layer/Electron blocking layer/Light emitting layer/Electron transport layer/Electron injection layer/Cathode
(14) Anode/Hole injection layer/Hole transport layer/Electron blocking layer/Light emitting layer/Hole blocking layer/Electron transport layer/Electron injection layer/Cathode
(15) Anode/Hole transport layer/Light emitting layer/Hole blocking layer/Electron transport layer/Cathode
(16) Anode/Hole transport layer/Light emitting layer/Hole blocking layer/Electron transport layer/Electron injection layer/Cathode
(17) Anode/Hole injection layer/Hole transport layer/Light emitting layer/Hole blocking layer/Electron transport layer/Cathode
(18) Anode/Hole injection layer/Hole transport layer/Light emitting layer/Hole blocking layer/Electron transport layer/Electron injection layer/Cathode
(19) Anode/Hole injection layer/Hole transport layer/Electron blocking layer/Light emitting layer/Hole blocking layer/Electron transport and injection layer/Cathode

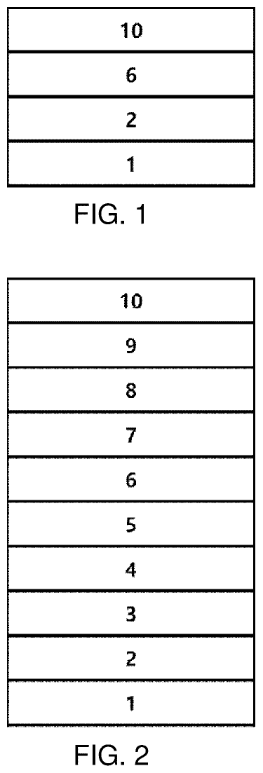

The structure of the organic light emitting device of the present specification may have structures illustrated in FIGS. 1 to 3, but is not limited thereto.

FIG. 1 illustrates an example of an organic light emitting device in which a substrate 1, an anode 2, a light emitting layer 6, and a cathode 10 are sequentially stacked. In the structure as described above, the compound represented by Chemical Formula 1 and the compound represented by Chemical Formula 2 may be included in the light emitting layer 6.

FIG. 2 illustrates an example of an organic light emitting device in which a substrate 1, an anode 2, a hole injection layer 3, a hole transport layer 4, an electron blocking layer 5, a light emitting layer 6, a hole blocking layer 7, an electron transport layer 8, an electron injection layer 9, and a cathode 10 are sequentially stacked. In the structure described above, the compound represented by Chemical Formula 1 and the compound represented by Chemical Formula 2 may be included in the hole injection layer 3, the hole transport layer 4, the electron blocking layer 5, the light emitting layer 6, the hole blocking layer 7, the electron transport layer 8, or the electron injection layer 9.

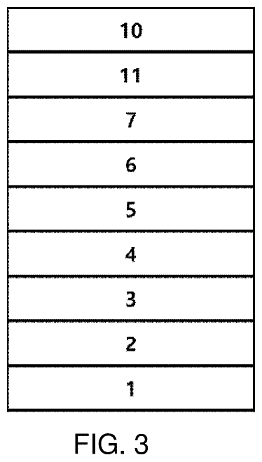

FIG. 3 illustrates an example of an organic light emitting device in which a substrate 1, an anode 2, a hole injection layer 3, a hole transport layer 4, an electron blocking layer 5, a light emitting layer 6, a hole blocking layer 7, an electron transport and injection layer 11, and a cathode 10 are sequentially stacked. In the structure described above, the compound represented by Chemical Formula 1 and the compound represented by Chemical Formula 2 may be included in the hole injection layer 3, the hole transport layer 4, the electron blocking layer 5, the light emitting layer 6, the hole blocking layer 7, or the electron transport and injection layer 11.

In an exemplary embodiment of the present specification, the hole blocking layer and the light emitting layer may be provided adjacent to each other. For example, the hole blocking layer and the light emitting layer may be provided to be brought into physical contact with each other.

The organic light emitting device of the present specification may be manufactured by the materials and methods known in the art, except that one or more layers of the organic material layer include the compound, that is, the compound represented by Chemical Formula 1 and the compound represented by Chemical Formula 2.

When the organic light emitting device includes a plurality of organic material layers, the organic material layers may be formed with materials the same as or different from each other.

For example, the organic light emitting device according to the present specification may be manufactured by depositing a metal or a metal oxide having conductivity, or an alloy thereof on a substrate to form an anode, forming an organic material layer including a hole injection layer, a hole transport layer, a light emitting layer, a hole blocking layer, an electron transport layer, and an electron injection layer thereon, and then depositing a material, which may be used as a cathode, thereon, by using a physical vapor deposition (PVD) method such as sputtering or e-beam evaporation. In addition to the method described above, an organic light emitting device may be made by sequentially depositing a cathode material, an organic material layer, and an anode material on a substrate.

The organic material layer may further include one or more layers of a hole transport layer, a hole injection layer, an electron blocking layer, an electron transport and injection layer, an electron transport layer, an electron injection layer, a hole blocking layer, and a hole injection and transport layer.

The organic material layer may have a multi-layered structure including a hole injection layer, a hole transport layer, a hole injection and transport layer, an electron blocking layer, a light emitting layer and an electron transport layer, an electron injection layer, an electron transport and injection layer, and the like, but is not limited thereto, and may also have a single-layered structure. Further, the organic material layer may be manufactured to include a fewer number of layers by a method such as a solvent process, for example, spin coating, dip coating, doctor blading, screen printing, inkjet printing, or a thermal transfer method instead of a deposition method, using various polymer materials.

In addition, the compound of Chemical Formula 1 or the compound of Chemical Formula 2 may be formed as an organic material layer by not only a vacuum deposition method, but also a solution application method when an organic light emitting device is manufactured. Here, the solution application method means spin coating, dip coating, doctor blading, inkjet printing, screen printing, a spray method, roll coating, and the like, but is not limited thereto.

In addition to the method described above, an organic light emitting device may be made by sequentially depositing a cathode material, an organic material layer, and an anode material on a substrate. However, the manufacturing method is not limited thereto.

The anode is an electrode which injects holes, and as an anode material, materials having a high work function are usually preferred so as to facilitate the injection of holes into an organic material layer. Specific examples of the anode material which may be used in the present invention include: a metal, such as vanadium, chromium, copper, zinc, and gold, or an alloy thereof; a metal oxide, such as zinc oxide, indium oxide, indium tin oxide (ITO), and indium zinc oxide (IZO); a combination of a metal and an oxide, such as ZnO:Al or SnO₂:Sb; a conductive polymer, such as poly(3-methylthiophene), poly[3,4-(ethylene-1,2-dioxy)thiophene](PEDOT), polypyrrole, and polyaniline; and the like, but are not limited thereto.

The cathode is an electrode which injects electrons, and as a cathode material, materials having a low work function are usually preferred so as to facilitate the injection of electrons into an organic material layer. Specific examples of the cathode material include: a metal such as magnesium, calcium, sodium, potassium, titanium, indium, yttrium, lithium, gadolinium, aluminum, silver, tin, and lead, or an alloy thereof; a multi-layer structured material, such as LiF/Al or LiO₂/Al; and the like, but are not limited thereto.

The hole injection layer is a layer which accepts holes from an electrode. It is preferred that the hole injection material has an ability to transport holes, and has an effect of accepting holes from an anode and an excellent hole injection effect for a light emitting layer or a light emitting material. Further, the hole injection material is preferably a material which is excellent in ability to prevent excitons produced from a light emitting layer from moving to an electron injection layer or an electron injection material. In addition, the hole injection material is preferably a material which is excellent in ability to form a thin film. In addition, the highest occupied molecular orbital (HOMO) of the hole injection material is preferably a value between the work function of the anode material and the HOMO of the neighboring organic material layer. Specific examples of the hole injection material include: metal porphyrin, oligothiophene, and arylamine-based organic materials; hexanitrile hexaazatriphenylene-based organic materials; quinacridone-based organic materials; perylene-based organic materials; polythiophene-based conductive polymers such as anthraquinone and polyaniline; and the like, but are not limited thereto.

In an exemplary embodiment of the present specification, the hole injection layer includes a compound represented by the following Chemical Formula HI-1, but is not limited thereto.

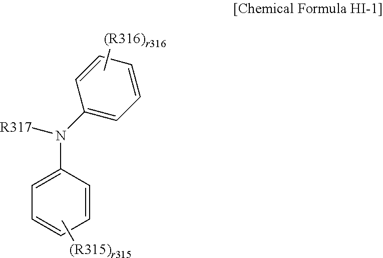

In Chemical Formula HI-1,
R315 to R317 are the same as or different from each other, and are each independently any one selected from the group consisting of hydrogen; deuterium; a substituted or unsubstituted alkyl group; a substituted or unsubstituted aryl group; a substituted or unsubstituted heteroaryl group; and a combination thereof, or are bonded to an adjacent group to form a substituted or unsubstituted ring,
r315 is an integer from 1 to 5, and when r315 is 2 or higher, two or more R315's are the same as or different from each other, and
r316 is an integer from 1 to 5, and when r316 is 2 or higher, two or more R316's are the same as or different from each other.

In an exemplary embodiment of the present specification, R317 is any one selected from the group consisting of a substituted or unsubstituted aryl group; a substituted or unsubstituted heteroaryl group; and a combination thereof.

In an exemplary embodiment of the present specification, R317 is any one selected from the group consisting of a carbazole group; a phenyl group; a biphenyl group; a triphenylene group; and a combination thereof.

In an exemplary embodiment of the present specification, R315 and R316 are the same as or different from each other, and are each independently a substituted or unsubstituted aryl group, or are bonded to an adjacent group to form an aromatic hydrocarbon ring substituted with an alkyl group.

In an exemplary embodiment of the present specification, R315 and R316 are the same as or different from each other, and are each independently a phenyl group or a biphenyl group, or are bonded to an adjacent group to form indene substituted with a methyl group.

In an exemplary embodiment of the present specification, Chemical Formula HI-1 is represented by any one of the following compounds.

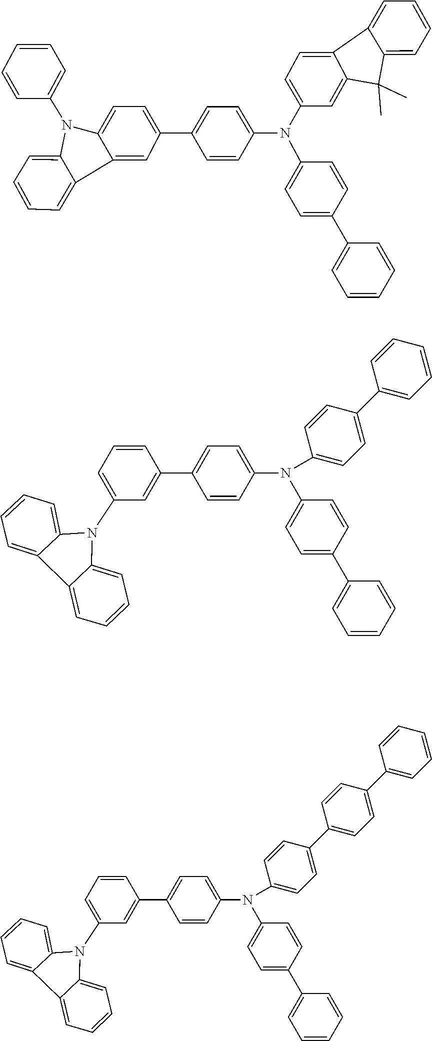 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(-c3ccc(N(c4ccc(-c5ccccc5)cc4)c4ccc(-c5cccc(-n6c7ccccc7c7ccccc76)c5)cc4)cc3)cc2)cc1]

In an exemplary embodiment of the present specification, the hole injection layer includes a compound represented by the following Chemical Formula HI-2, but is not limited thereto.

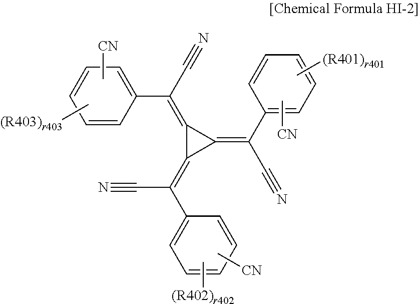

In Chemical Formula HI-2,
R401 to R403 are the same as or different from each other, and are each independently a halogen group, and
r401 to r403 are 4.

In an exemplary embodiment of the present specification, R401 to R403 are F.

In an exemplary embodiment of the present specification, Chemical Formula HI-2 is represented by the following compound.

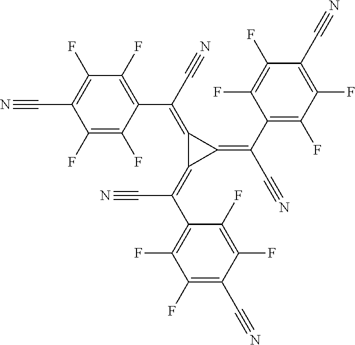 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

In an exemplary embodiment of the present specification, the hole injection includes Chemical Formulae HI-1 and HI-2.

In an exemplary embodiment of the present specification, the hole injection layer includes Chemical Formulae HI-1 and HI-2 at a weight ratio of 1:99 to 99:1.

The hole injection layer may have a thickness of 1 nm to 150 nm. When the hole injection layer has a thickness of 1 nm or more, there is an advantage in that it is possible to prevent hole injection characteristics from deteriorating, and when the hole injection layer has a thickness of 150 nm or less, there is an advantage in that it is possible to prevent the driving voltage from being increased in order to improve the movement of holes due to the too thick hole injection layer.

In an exemplary embodiment of the present specification, the hole injection layer may include an arylamine compound including a carbazole group and a p-type dopant. According to an example, the amine compound is represented by Het101-L101-N(Ar101) (Ar102), Het101 is a substituted or unsubstituted carbazole group, L101 is a direct bond or a substituted or unsubstituted arylene group, and Ar101 and Ar102 are the same as or different from each other, and may be each independently a substituted or unsubstituted aryl group. The amine compound and the p-type dopant may be included at an appropriate molar ratio, and according to an example, the amine compound and the p-type dopant may be included at a molar ratio of 99.9:0.1 to 90:10.

The hole transport layer is a layer which accepts holes from a hole injection layer and transports the holes to a light emitting layer. A hole transport material is preferably a material having high hole mobility which may accept holes from an anode or a hole injection layer and transfer the holes to a light emitting layer. Specific examples thereof include arylamine-based organic materials, conductive polymers, block copolymers having both conjugated portions and non-conjugated portions, and the like, but are not limited thereto.

In an exemplary embodiment of the present specification, the hole transport layer may include an arylamine compound including a carbazole group.

In an exemplary embodiment of the present specification, the hole transport layer includes the compound represented by Chemical Formula HI-1, but is not limited thereto.

The hole injection and transport layer is a layer which transports holes to the light emitting layer. Materials exemplified for the hole transport layer and the hole injection layer may be used, but the materials are not limited thereto.

A hole buffer layer may be additionally provided between a hole injection layer and a hole transport layer, and may include hole injection or transport materials known in the art.

An electron blocking layer may be provided between a hole transport layer and a light emitting layer. The above-described compound or a material known in the art may be used in the electron blocking layer.

The electron blocking layer is a layer which may improve the service life and efficiency of a device by preventing electrons injected from an electron injection layer from passing through a light emitting layer and entering a hole injection layer. Any known material can be used without limitation, and the materials exemplified in the description of the hole injection layer may be used, but the material is not limited thereto. The electron blocking layer may be formed between a light emitting layer and a hole transport layer, between a light emitting layer and a hole injection layer, or between a light emitting layer and a layer which simultaneously injects and transports holes.

In an exemplary embodiment of the present specification, the electron blocking layer includes a compound represented by the following Chemical Formula EB-1, but is not limited thereto.

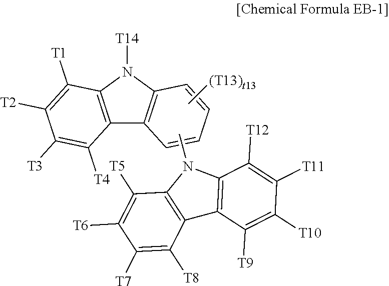

In Chemical Formula EB-1,
T1 to T14 are the same as or different from each other, and are each independently hydrogen; deuterium; a substituted or unsubstituted aryl group; or a substituted or unsubstituted heteroaryl group, and
t13 is an integer from 1 to 3, and when t13 is 2 or higher, two or more t13's are the same as or different from each other.

In an exemplary embodiment of the present specification, T1 to T14 are the same as or different from each other, and are each independently hydrogen; deuterium; or a monocyclic or polycyclic aryl group having 6 to 30 carbon atoms.

In an exemplary embodiment of the present specification, T1 to T14 are the same as or different from each other, and are each independently hydrogen; deuterium; or a monocyclic or polycyclic aryl group having 6 to 20 carbon atoms.

In an exemplary embodiment of the present specification, T1 to T14 are the same as or different from each other, and are each independently hydrogen; deuterium; a phenyl group; a biphenyl group; or a naphthyl group.

In an exemplary embodiment of the present specification, T1 to T13 are the same as or different from each other, and are each independently hydrogen; or deuterium.

In an exemplary embodiment of the present specification, T14 is a monocyclic or polycyclic aryl group having 6 to 30 carbon atoms.

In an exemplary embodiment of the present specification, T14 is a monocyclic or polycyclic aryl group having 6 to 20 carbon atoms.

In an exemplary embodiment of the present specification, T14 is a phenyl group; a biphenyl group; or a naphthyl group.

In an exemplary embodiment of the present specification, Chemical Formula EB-1 may include the following compound, but is not limited thereto.

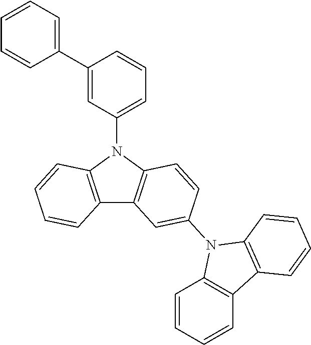 [SMILES: c1ccc(-c2cccc(-n3c4ccccc4c4cc(-n5c6ccccc6c6ccccc65)ccc43)c2)cc1]

In an exemplary embodiment of the present specification, Chemical Formula EB-1 may also be used as a second host material of the light emitting layer.

The light emitting layer may emit red, green, or blue light, and may be composed of a phosphorescent material or a fluorescent material. The light emitting material is a material which may receive holes and electrons from a hole transport layer and an electron transport layer, respectively, and combine the holes and the electrons to emit light in a visible ray region, and is preferably a material having high quantum efficiency for fluorescence or phosphorescence. Specific examples thereof include: 8-hydroxy-quinoline aluminum complexes (Alq₃); carbazole-based compounds; dimerized styryl compounds; BAlq; 10-hydroxybenzoquinoline-metal compounds; benzoxazole-based, benzothiazole-based and benzimidazole-based compounds; poly(p-phenylenevinylene) (PPV)-based polymers; spiro compounds; polyfluorene, rubrene, and the like, but are not limited thereto.

The light emitting layer may include a host material and a dopant material. When the organic light emitting device according to an exemplary embodiment of the present specification includes an additional light emitting layer other than a light emitting layer including Chemical Formula 1, examples of a host material include a fused aromatic ring derivative, a hetero ring-containing compound, and the like. Specific examples of the fused aromatic ring derivative include anthracene derivatives, pyrene derivatives, naphthalene derivatives, pentacene derivatives, phenanthrene compounds, fluoranthene compounds, and the like, and specific examples of the hetero ring-containing compound include dibenzofuran derivatives, ladder-type furan compounds, pyrimidine derivatives, and the like, but the examples are not limited thereto.

Examples of the dopant material include an aromatic amine derivative, a styrylamine compound, a boron complex, a fluoranthene compound, a metal complex, and the like. Specifically, the aromatic amine derivative is a fused aromatic ring derivative having a substituted or unsubstituted arylamine group, and examples thereof include pyrene, anthracene, chrysene, periflanthene, and the like having an arylamine group. Further, the styrylamine compound is a compound in which a substituted or unsubstituted arylamine is substituted with at least one arylvinyl group, and one or two or more substituents selected from the group consisting of an aryl group, a silyl group, an alkyl group, a cycloalkyl group, and an arylamine group are substituted or unsubstituted. Specific examples thereof include styrylamine, styryldiamine, styryltriamine, styryltetramine, and the like, but are not limited thereto. Further, examples of the metal complex include an iridium complex, a platinum complex, and the like, but are not limited thereto. In an exemplary embodiment of the present specification, the light emitting layer may include the compound represented by Chemical Formula 1 of the present invention as a phosphorescent host of the light emitting layer.

In an exemplary embodiment of the present specification, the light emitting layer may include the compound represented by Chemical Formula 2 of the present invention as a phosphorescent dopant of the light emitting layer.

According to an example, the host and the dopant may be included at an appropriate weight ratio, and according to an example, the host and the dopant may be included at a weight ratio of 100:1 to 100:10.

The hole blocking layer is a layer which blocks holes from reaching a cathode, and may be generally formed under the same condition as the electron injection layer. When the organic light emitting device according to an exemplary embodiment of the present specification includes an additional hole blocking layer other than the hole blocking layer including Chemical Formula 1, specifically, an oxadiazole derivative or a triazole derivative, a phenanthroline derivative, an aluminum complex, and the like are used, but are not limited thereto.

A hole blocking layer may be provided between the electron transport layer and the light emitting layer, and materials known in the art may be used.

In an exemplary embodiment of the present specification, the hole blocking layer may include a compound including an N-containing heterocyclic group and a fluorene ring.

The electron transport layer is a layer which accepts electrons from an electron injection layer and transports the electrons to a light emitting layer. An electron transport material is preferably a material having high electron mobility which may proficiently accept electrons from a cathode and transfer the electrons to a light emitting layer. Specific examples thereof include: Al complexes of 8-hydroxyquinoline; complexes including Alq₃; organic radical compounds; hydroxyflavone-metal complexes; and the like, but are not limited thereto. The electron transport layer may be used together with any desired cathode material as used in the art. In particular, an appropriate cathode material is a typical material which has a low work function, followed by an aluminum layer or a silver layer. Specific examples thereof include cesium, barium, calcium, ytterbium, and samarium, in each case followed by an aluminum layer or a silver layer.

The electron transport layer may have a thickness of 1 nm to 50 nm. When the electron transport layer has a thickness of 1 nm or more, there is an advantage in that it is possible to prevent electron transport characteristics from deteriorating, and when the electron transport layer has a thickness of 50 nm or less, there is an advantage in that it is possible to prevent the driving voltage from being increased in order to improve the movement of electrons due to the too thick electron transport layer.

In an exemplary embodiment of the present specification, the electron transport layer may include a compound including two N-containing heterocyclic groups, and may further include an n-type dopant or an organic metal compound. According to an example, the n-type dopant or organic metal compound may be LiQ, and the compound including two N-containing heterocyclic groups and the n-type dopant (or organic metal compound) may be included at a weight ratio of 2:8 to 8:2, for example, 4:6 to 6:4.

The electron injection layer is a layer which accepts electrons from an electrode. It is preferred that an electron injection material is excellent in ability to transport electrons and has an effect of accepting electrons from the second electrode and an excellent electron injection effect for a light emitting layer or a light emitting material. Further, the electron injection material is preferably a material which prevents excitons produced from a light emitting layer from moving to a hole injection layer and is excellent in ability to form a thin film. Specific examples thereof include fluorenone, anthraquinodimethane, diphenoquinone, thiopyran dioxide, oxazole, oxadiazole, triazole, imidazole, perylenetetracarboxylic acid, fluorenylidene methane, anthrone, and the like, and derivatives thereof, metal complex compounds, nitrogen-containing 5-membered ring derivatives, and the like, but are not limited thereto.

Examples of the metal complex compound include 8-hydroxyquinolinato lithium, bis(8-hydroxyquinolinato)zinc, bis(8-hydroxyquinolinato)copper, bis(8-hydroxy-quinolinato)manganese, tris(8-hydroxyquinolinato)aluminum, tris(2-methyl-8-hydroxyquinolinato)aluminum, tris(8-hydroxyquinolinato)gallium, bis(10-hydroxybenzo[h]-quinolinato)beryllium, bis(10-hydroxybenzo[h]-quinolinato)zinc, bis(2-methyl-8-quinolinato)chlorogallium, bis(2-methyl-8-quinolinato) (o-cresolato)gallium, bis(2-methyl-8-quinolinato) (1-naphtholato)aluminum, bis(2-methyl-8-quinolinato) (2-naphtholato)gallium and the like, but are not limited thereto.

In an exemplary embodiment of the present specification, the electron injection and transport layer is a layer that transports electrons to the light emitting layer. Materials exemplified for the electron transport layer and the electron injection layer may be used, but the materials are not limited thereto.

In an exemplary embodiment of the present specification, the electron injection and transport layer includes a compound represented by the following Chemical Formula ET-1, but is not limited thereto.

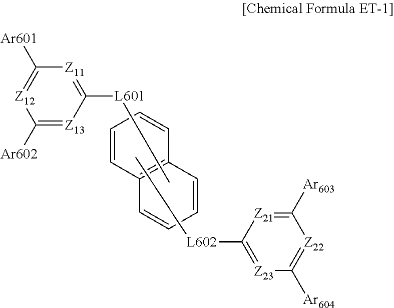

In Chemical Formula ET-1,
at least one of Z11 to Z13 is N, and the others are CH,
at least one of Z21 to Z23 is N, and the others are CH,
L601 and L602 are the same as or different from each other, and are each independently a direct bond; a substituted or unsubstituted arylene group; or a substituted or unsubstituted heteroarylene group, and
Ar601 to Ar604 are the same as or different from each other, and are each independently a substituted or unsubstituted aryl group; or a substituted or unsubstituted heteroaryl group.

In an exemplary embodiment of the present specification, L601 and L602 are the same as or different from each other, and are each independently a substituted or unsubstituted monocyclic or polycyclic arylene group having 6 to 30 carbon atoms.

In an exemplary embodiment of the present specification, L601 and L602 are a phenylene group.

In an exemplary embodiment of the present specification, Ar601 to Ar604 are the same as or different from each other, and are each independently a substituted or unsubstituted monocyclic or polycyclic aryl group having 6 to 30 carbon atoms.

In an exemplary embodiment of the present specification, Ar601 to Ar604 are a phenyl group.

In an exemplary embodiment of the present specification, Chemical Formula ET-1 is represented by the following compound.

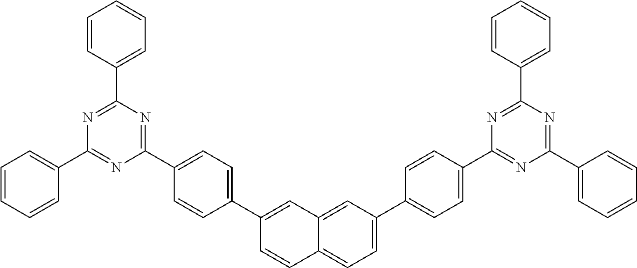 [SMILES: c1ccc(-c2nc(-c3ccccc3)nc(-c3ccc(-c4ccc5ccc(-c6ccc(-c7nc(-c8ccccc8)nc(-c8ccccc8)n7)cc6)cc5c4)cc3)n2)cc1]

In an exemplary embodiment of the present specification, the electron injection and transport layer may further include a metal complex compound. The metal complex compound is as described above.

The organic light emitting device according to the present invention may be a top emission type, a bottom emission type, or a dual emission type according to the material to be used.

The organic light emitting device according to the present specification may be included and used in various electronic devices. For example, the electronic device may be a display panel, a touch panel, a solar module, a lighting device, and the like, and is not limited thereto.

### EXAMPLES

Hereinafter, the present specification will be described in detail with reference to Examples for specifically describing the present specification. However, the Examples according to the present specification may be modified in various forms, and it is not interpreted that the scope of the present application is limited to the Examples described in detail below. The Examples of the present application are provided to explain the present specification more completely to a person with ordinary skill in the art.

### Preparation Example 1

### Preparation Examples of Compound 1

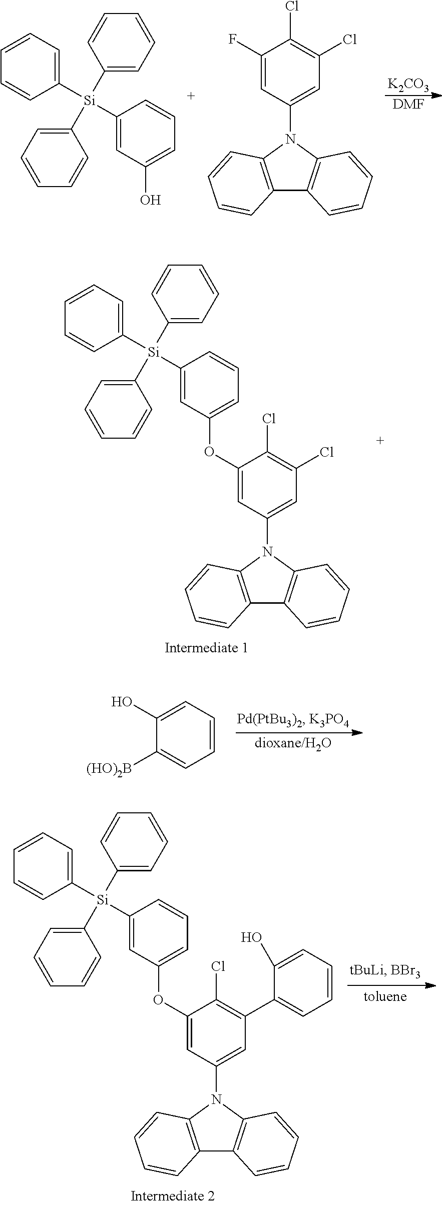

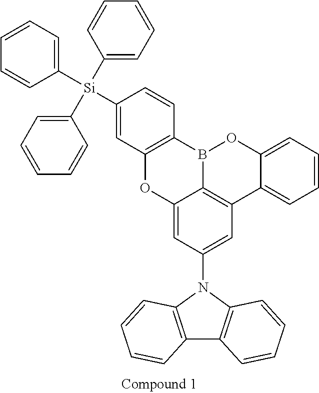 [SMILES: c1ccc([Si](c2ccccc2)(c2ccccc2)c2ccc3c(c2)Oc2cc(-n4c5ccccc5c5ccccc54)cc4c2B3Oc2ccccc2-4)cc1]

### Synthesis of Intermediate 1

After 24 g of 3-(triphenylsilyl)phenol, which is a starting material, 20 g of 9-(3,4-dichloro-5-fluorophenyl)-9H-carbazole, 17 g of potassium carbonate, and 500 mL of dimethylformamide (DMF) were put into a container under a nitrogen atmosphere, the resulting mixture was heated at 160° C. and stirred for 5 hours. After the reaction was terminated, the reaction solution was cooled to room temperature, aliquoted by adding water and ethyl acetate thereto, and then filtered by treatment with MgSO₄ (anhydrous). The filtered solution was distilled off under reduced pressure and purified with recrystallization (toluene/hexane) to obtain 28 g of Intermediate 1. (Yield 70%, Mass [M+]=663)

### Synthesis of Intermediate 2

After 28 g of Intermediate 1, 7.0 g of 2-hydroxyphenylboronic acid, 27 g of potassium phosphate, 320 mL of dioxane, and 80 mL of water were put into a container under a nitrogen atmosphere, 0.4 g of bis(tri-tert-butylphosphine)palladium(0) (Pd(PtBu₃)₂) was added thereto, and then the resulting mixture was heated at 120° C. and stirred for 8 hours. After the reaction was terminated, the reaction solution was cooled to room temperature, aliquoted by adding water and toluene thereto, and then filtered by treatment with MgSO₄ (anhydrous). The filtered solution was distilled off under reduced pressure and purified with recrystallization (toluene/hexane) to obtain 23 g of Intermediate 2. (Yield 76%, Mass [M+]=721)

### Synthesis of Compound 1

47 mL of t-butyllithium (1.7 M in hexane) was slowly added dropwise to a flask containing 23 g of Intermediate 2 dissolved in 300 mL of toluene (anhydrous) cooled to 0° C. under a nitrogen atmosphere, and then the resulting mixture was stirred at 70° C. for 5 hours. When a lithium-halogen exchange reaction was completed, the resulting product was cooled again to 0° C., 9.2 mL of boron tribromide was slowly added dropwise thereto, and then the temperature was increased to 70° C., and the resulting solution was stirred for 10 hours. After the reaction was terminated, the reaction solution was cooled to room temperature, aliquoted by adding water and aq. NH₄Cl thereto, and then filtered by treatment with MgSO₄ (anhydrous). The filtered solution was distilled off under reduced pressure and purified twice with recrystallization (toluene/hexane) to obtain 3.8 g of Compound 1. (Yield 17%, Mass [M+]=694)

### Preparation Examples of Compound 2

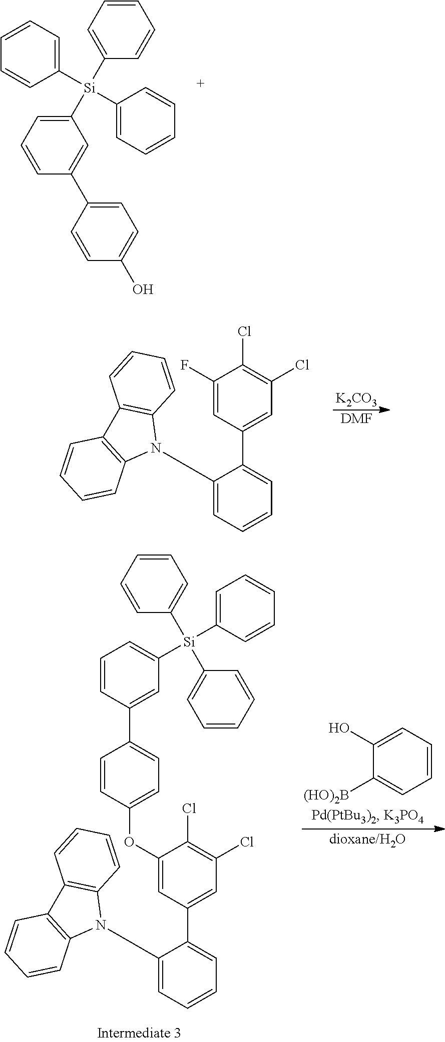

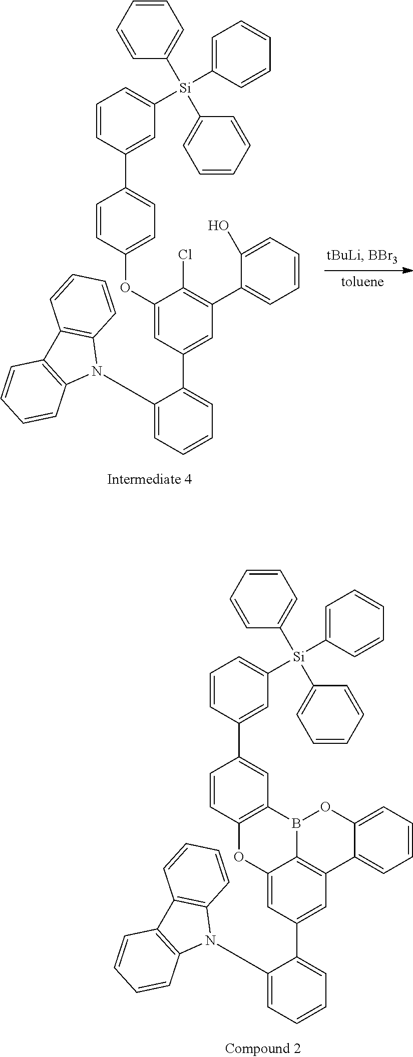 [SMILES: Oc1ccccc1-c1cc(-c2ccccc2-n2c3ccccc3c3ccccc32)cc(Oc2ccc(-c3cccc([Si](c4ccccc4)(c4ccccc4)c4ccccc4)c3)cc2)c1Cl ; c1ccc([Si](c2ccccc2)(c2ccccc2)c2cccc(-c3ccc4c(c3)B3Oc5ccccc5-c5cc(-c6ccccc6-n6c7ccccc7c7ccccc76)cc(c53)O4)c2)cc1]

### Synthesis of Intermediate 3

23 g of Intermediate 3 was obtained by preparing in the same manner as in the method of preparing Intermediate 1 in Synthesis Example 1, except that 23 g of 3′-(triphenylsilyl)-[1,1′-biphenyl]-4-ol and 20 g of 9-(3′,4′-dichloro-5′-fluoro-[1,1′-biphenyl]-2-yl)-9H-carbazole were used instead of the starting material 3-(triphenylsilyl)phenol and 9-(3,4-dichloro-5-fluorophenyl)-9H-carbazole, respectively. (Yield 57%, Mass [M+]=815)

### Synthesis of Intermediate 4

18 g of Intermediate 4 was obtained by preparing in the same manner as in the method of preparing Intermediate 2 in Synthesis Example 1, except that 23 g of Intermediate 3 was used instead of Intermediate 1. (Yield 73%, Mass [M+]=873)

### Synthesis of Compound 2

2.7 g of Compound 2 was obtained by preparing in the same manner as in the method of preparing Compound 1 in Synthesis Example 1, except that 18 g of Intermediate 4 was used instead of Intermediate 2. (Yield 15%, Mass [M+]=846)

### Preparation Examples of Compound 3

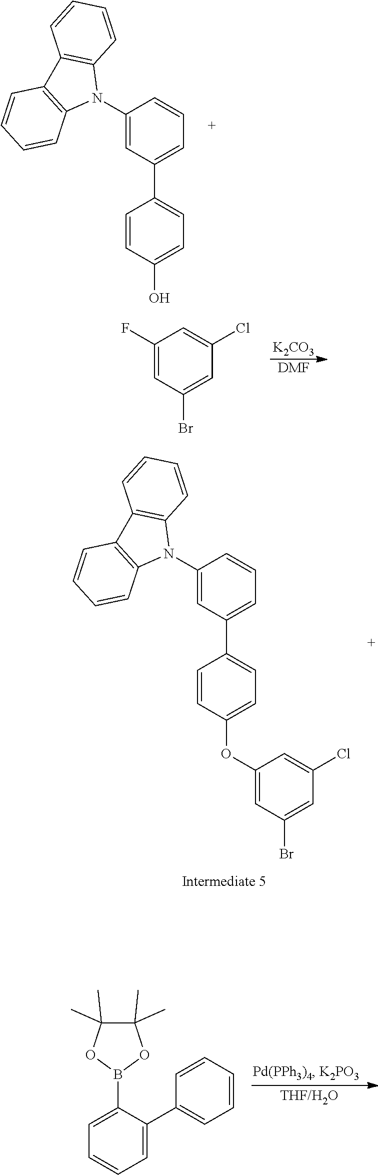

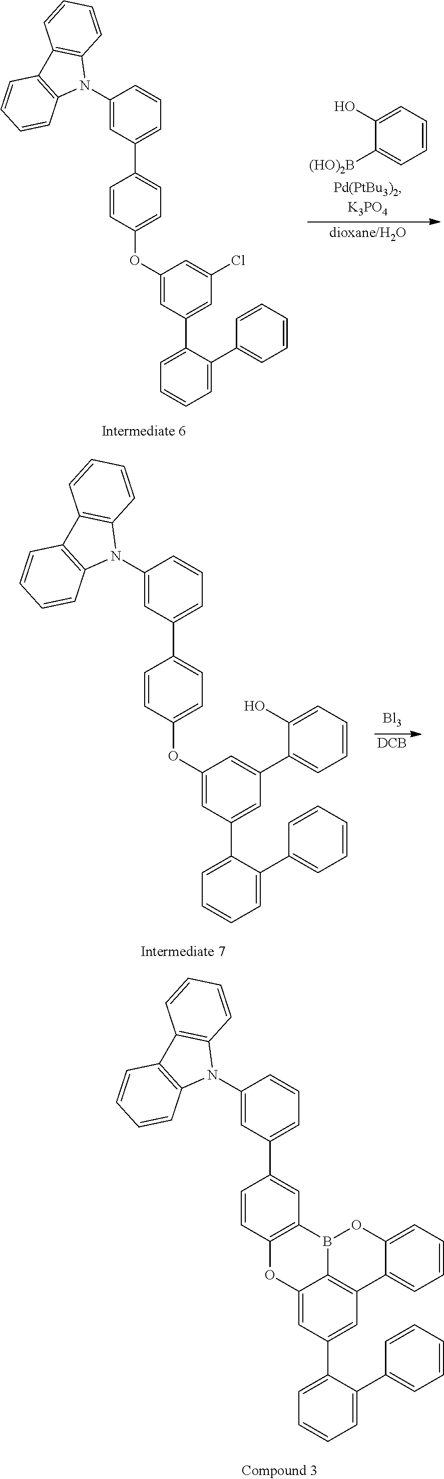

### Synthesis of Intermediate 5

28 g of Intermediate 5 was obtained by preparing in the same manner as in the method of preparing Intermediate 1 in Synthesis Example 1, except that 26 g of 3′-(9H-carbazol-9-yl)-[1,1′-biphenyl]-4-ol and 15 g of 1-bromo-3-chloro-5-fluorobenzene were used instead of the starting material 3-(triphenylsilyl)phenol and 9-(3,4-dichloro-5-fluorophenyl)-9H-carbazole, respectively. (Yield 74%, Mass [M+]=525)

### Synthesis of Intermediate 6

After 28 g of Intermediate 5, 18 g of 2-([1,1′-biphenyl]-2-yl)-4,4,5,5-tetramethyl-1,3,2-dioxaborolane, 22 g of potassium carbonate, 400 mL of tetrahydrofuran, and 100 mL of water were put into a container under a nitrogen atmosphere, 0.6 g of tetrakis(triphenylphosphine)palladium(0) (Pd(PPh₃)₄) was added thereto, and then the resulting mixture was heated at 80° C. and stirred for 8 hours. After the reaction was terminated, the reaction solution was cooled to room temperature, aliquoted by adding water and toluene thereto, and then filtered by treatment with MgSO₄ (anhydrous). The filtered solution was distilled off under reduced pressure and purified with recrystallization (toluene/hexane) to obtain 22 g of Intermediate 6. (Yield 69%, Mass [M+]=599)

### Synthesis of Intermediate 7

24 g of Intermediate 7 was obtained by preparing in the same manner as in the method of preparing Intermediate 2 in Synthesis Example 1, except that 22 g of Intermediate 6 was used instead of Intermediate 1. (Yield 74%, Mass [M+]=656)

### Synthesis of Compound 3

17 g of boron triiodide was put into a flask containing 15 g of Intermediate 7 dissolved in 500 mL of 1,2-dichlorobenzene (DCB) under a nitrogen atmosphere, and then the resulting mixture was stirred at 120° C. for 5 hours. After the reaction was terminated, the reaction solution was cooled to room temperature, aliquoted by adding water and a sodium thiosulfate solution thereto, and then filtered by treatment with MgSO₄ (anhydrous). The filtered solution was distilled off under reduced pressure and purified with recrystallization (toluene/hexane) to obtain 4.7 g of Compound 3. (Yield 31%, Mass [M+]=664)

### Preparation Examples of Compound 4

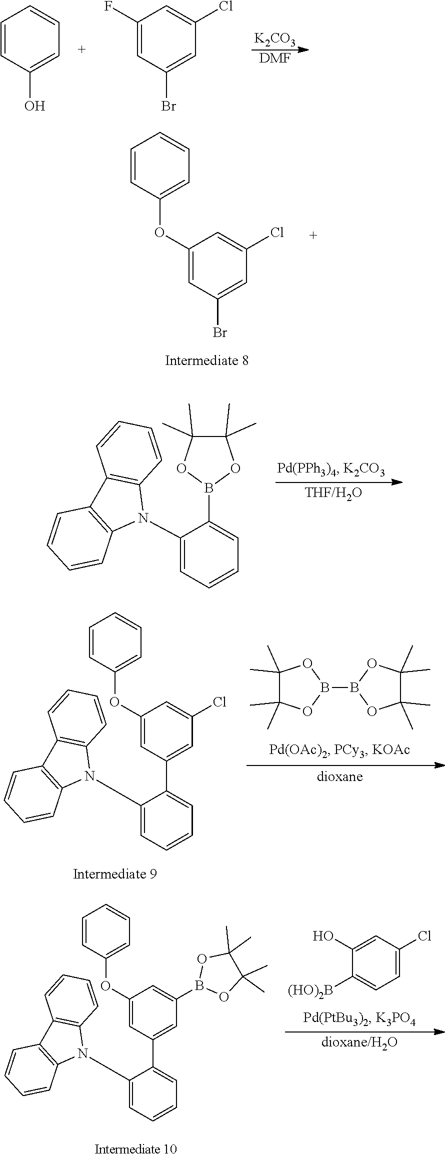

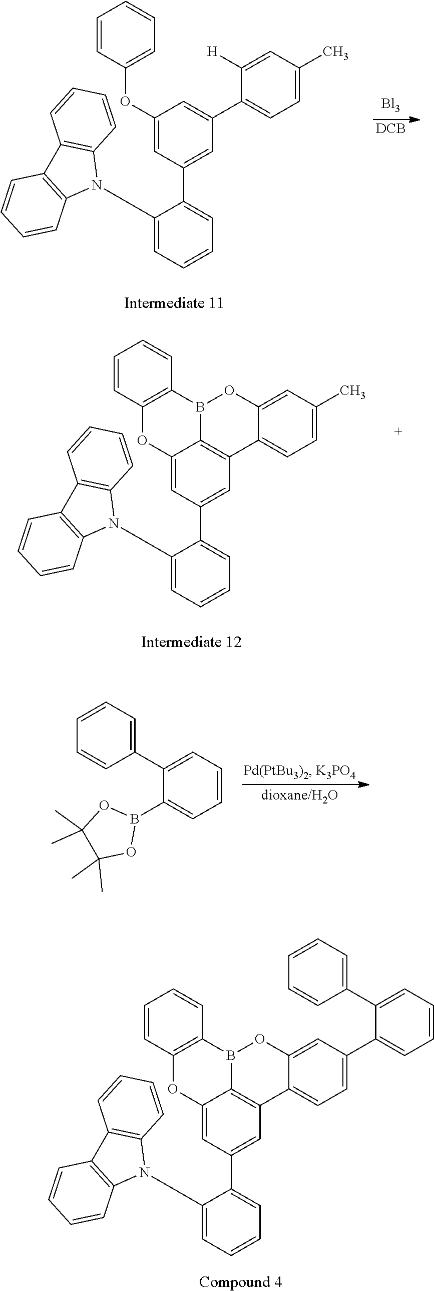

### Synthesis of Intermediate 8

21 g of Intermediate 8 was obtained by preparing in the same manner as in the method of preparing Intermediate 1 in Synthesis Example 1, except that 9.9 g of phenol and 20 g of 1-bromo-3-chloro-5-fluorobenzene were used instead of the starting material 3-(triphenylsilyl)phenol and 9-(3,4-dichloro-5-fluorophenyl)-9H-carbazole, respectively. (Yield 78%, Mass [M+]=284)

### Synthesis of Intermediate 9

23 g of Intermediate 9 was obtained by preparing in the same manner as in the method of preparing Intermediate 6 in Synthesis Example 3, except that 21 g of Intermediate 8 and 33 g of 9-(2-(4,4,5,5-tetramethyl-1,3,2-dioxaborolan-2-yl)phenyl)-9H-carbazole were used instead of Intermediate 5 and 2-([1,1′-biphenyl]-2-yl)-4,4,5,5-tetramethyl-1,3,2-dioxaborolane, respectively. (Yield 70%, Mass [M+]=446)

### Synthesis of Intermediate 10

After 23 g of Intermediate 5, 16 g of 4,4,4′,4′,5,5,5′,5′-octamethyl-2,2′-bi(1,3,2-dioxaborolane), 15 g of potassium acetate, and 400 mL of dioxane were put into a container under a nitrogen atmosphere, 0.23 g of palladium acetate(II) (Pd(OAc)₂) and 0.58 g of tricyclohexylphosphine (PCy₃) were added thereto, and then the resulting mixture was heated at 120° C. and stirred for 12 hours. After the reaction was terminated, the reaction solution was cooled to room temperature, aliquoted by adding water and toluene thereto, and then filtered by treatment with MgSO₄ (anhydrous). The filtered solution was distilled off under reduced pressure and purified with recrystallization (toluene/hexane) to obtain 20 g of Intermediate 10. (Yield 72%, Mass [M+]=538)

### Synthesis of Intermediate 11

After 20 g of Intermediate 10, 9.3 g of 2-bromo-5-chlorophenol, 24 g of potassium phosphate, 280 mL of tetrahydrofuran, and 70 mL of water were put into a container under a nitrogen atmosphere, 0.19 g of bis(tri-tert-butylphosphine)palladium(0) (Pd(PtBu₃)₂) was added thereto, and then the resulting mixture was heated at 100° C. and stirred for 6 hours. After the reaction was terminated, the reaction solution was cooled to room temperature, aliquoted by adding water and toluene thereto, and then filtered by treatment with MgSO₄ (anhydrous). The filtered solution was distilled off under reduced pressure and purified with recrystallization (toluene/hexane) to obtain 16 g of Intermediate 11. (Yield 80%, Mass [M+]=539)

### Synthesis of Intermediate 12

8.2 g of Intermediate 12 was obtained by preparing in the same manner as in the method of preparing Compound 3 in Synthesis Example 3, except that 16 g of Intermediate 11 was used instead of Intermediate 7. (Yield 51%, Mass [M+]=546)

### Synthesis of Compound 4

After 4.0 g of Intermediate 12, 2.1 g of 2-([1,1′-biphenyl]-2-yl)-4,4,5,5-tetramethyl-1,3,2-dioxaborolane, 4.7 g of potassium phosphate, 56 mL of dioxane, and 14 mL of water were put into a container under a nitrogen atmosphere, 0.07 g of bis(tri-tert-butylphosphine)-palladium(0) (Pd(PtBu₃)₂) was added thereto, and then the resulting mixture was heated at 130° C. and stirred for 14 hours. After the reaction was terminated, the reaction solution was cooled to room temperature, aliquoted by adding water and toluene thereto, and then filtered by treatment with MgSO₄ (anhydrous). The filtered solution was distilled off under reduced pressure and purified with recrystallization (toluene/hexane) to obtain 3.8 g of Compound 4. (Yield 78%, Mass [M+]=664)

### Preparation Examples of Compound 5

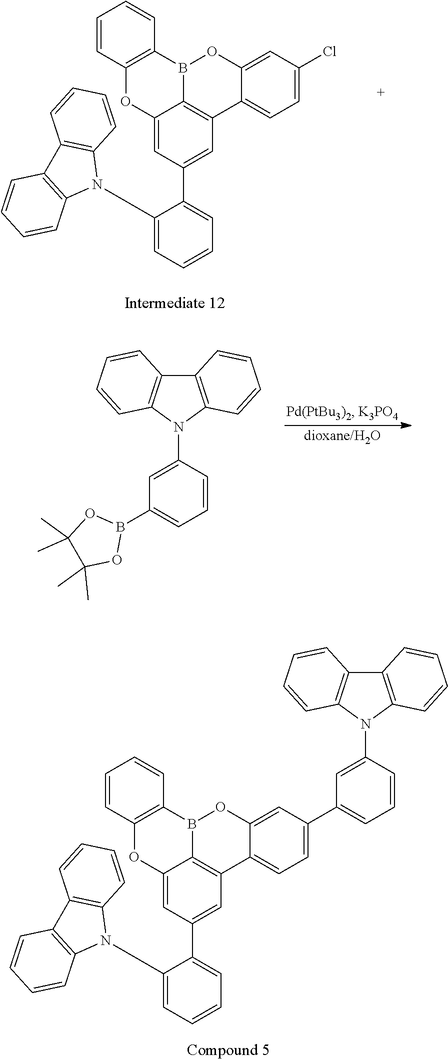 [SMILES: Clc1ccc2c(c1)OB1c3ccccc3Oc3cc(-c4ccccc4-n4c5ccccc5c5ccccc54)cc-2c31 ; CC1(C)OB(c2cccc(-n3c4ccccc4c4ccccc43)c2)OC1(C)C ; c1cc(-c2ccc3c(c2)OB2c4ccccc4Oc4cc(-c5ccccc5-n5c6ccccc6c6ccccc65)cc-3c42)cc(-n2c3ccccc3c3ccccc32)c1]

4.1 g of Compound 5 was obtained by preparing in the same manner as in the method of preparing Compound 4 in Synthesis Example 4, except that 2.8 g of 9-(3-(4,4,5,5-tetramethyl-1,3,2-dioxaborolan-2-yl)phenyl)-9H-carbazole was used instead of 2-([1,1′-biphenyl]-2-yl)-4,4,5,5-tetramethyl-1,3,2-dioxaborolane. (Yield 74%, Mass [M+]=753)

### Preparation Examples of Compound 6

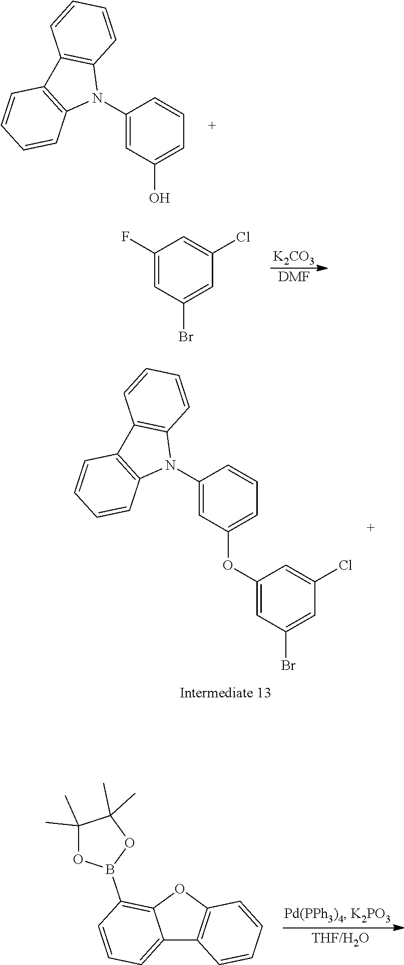

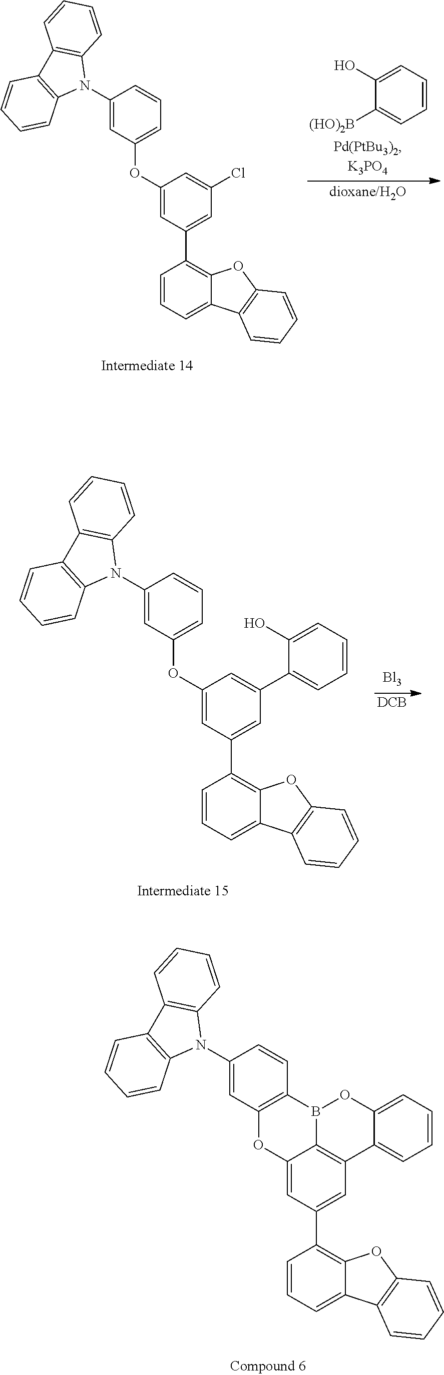

### Synthesis of Intermediate 13

25 g of Intermediate 13 was obtained by preparing in the same manner as in the method of preparing Intermediate 1 in Synthesis Example 1, except that 20 g of 3-(9H-carbazol-9-yl)phenol and 15 g of 1-bromo-3-chloro-5-chlorobenzene were used instead of the starting material 3-(triphenylsilyl)phenol and 9-(3,4-dichloro-5-fluorophenyl)-9H-carbazole, respectively. (Yield 78%, Mass [M+]=449)

### Synthesis of Intermediate 14

23 g of Intermediate 14 was obtained by preparing in the same manner as in the method of preparing Intermediate 6 in Synthesis Example 3, except that 25 g of Intermediate 13 and 20 g of 2-(dibenzo[b,d]furan-4-yl)-4,4,5,5-tetramethyl-1,3,2-dioxaborolane were used instead of Intermediate 5 and 2-([1,1′-biphenyl]-2-yl)-4,4,5,5-tetramethyl-1,3,2-dioxaborolane, respectively. (Yield 77%, Mass [M+]=537)

### Synthesis of Intermediate 15

19 g of Intermediate 15 was obtained by preparing in the same manner as in the method of preparing Intermediate 2 in Synthesis Example 1, except that 23 g of Intermediate 14 was used instead of Intermediate 1. (Yield 75%, Mass [M+]=594)

### Synthesis of Compound 6

4.2 g of Compound 6 was obtained by preparing in the same manner as in the method of preparing Compound 3 in Synthesis Example 3, except that 10 g of Intermediate 15 was used instead of Intermediate 7. (Yield 41%, Mass [M+]=602)

### Preparation Examples of Compound 7

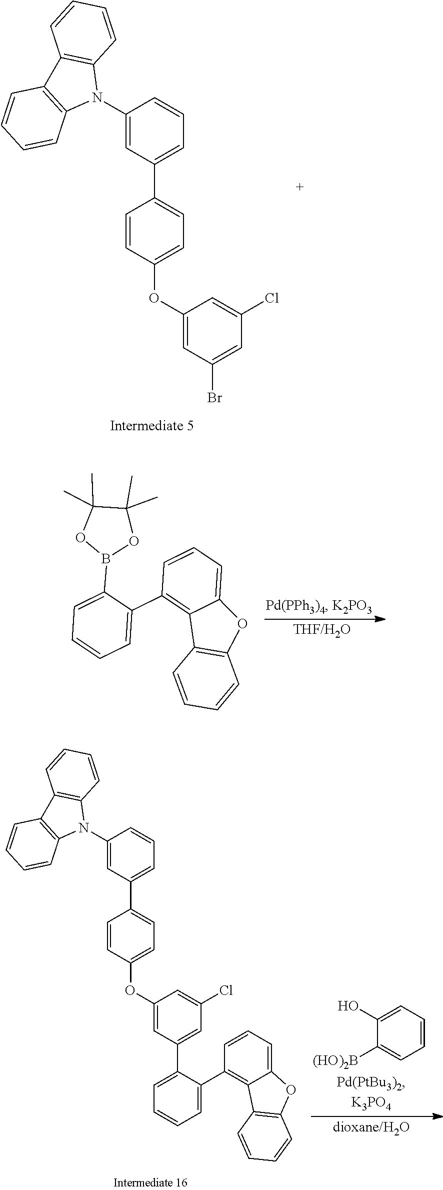 [SMILES: Clc1cc(Br)cc(Oc2ccc(-c3cccc(-n4c5ccccc5c5ccccc54)c3)cc2)c1 ; CC1(C)OB(c2ccccc2-c2cccc3oc4ccccc4c23)OC1(C)C ; Clc1cc(Oc2ccc(-c3cccc(-n4c5ccccc5c5ccccc54)c3)cc2)cc(-c2ccccc2-c2cccc3oc4ccccc4c23)c1 ; OB(O)c1ccccc1O]

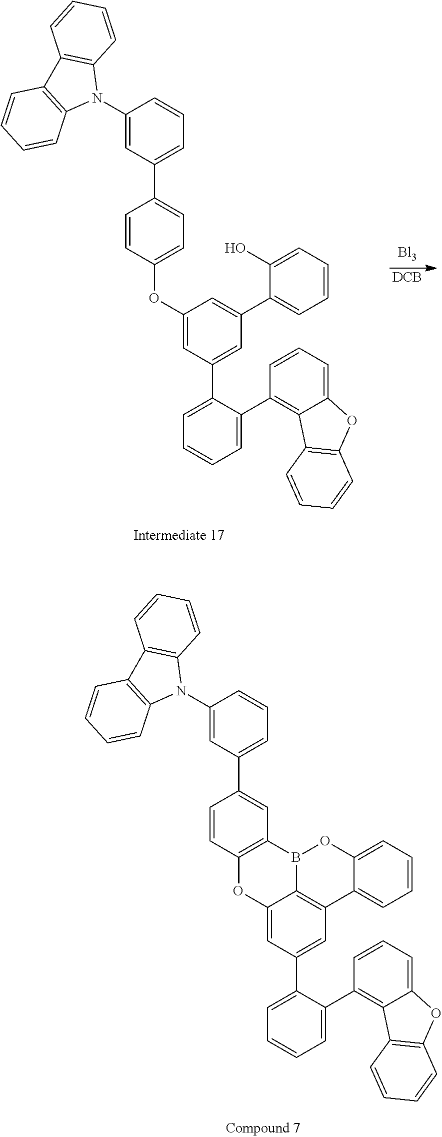

### Synthesis of Intermediate 16

10 g of Intermediate 16 was obtained by preparing in the same manner as in the method of preparing Intermediate 6 in Synthesis Example 3, except that 8.5 g of 2-(2-(dibenzo[b,d]furan-1-yl)phenyl)-4,4,5,5-tetramethyl-1,3,2-dioxaborolane was used instead of 2-([1,1′-biphenyl]-2-yl)-4,4,5,5-tetramethyl-1,3,2-dioxaborolane. (Yield 76%, Mass [M+]=689)

### Synthesis of Intermediate 17

7.6 g of Intermediate 17 was obtained by preparing in the same manner as in the method of preparing Intermediate 2 in Synthesis Example 1, except that 10 g of Intermediate 16 was used instead of Intermediate 1. (Yield 70%, Mass [M+]=746)

### Synthesis of Compound 7

3.1 g of Compound 7 was obtained by preparing in the same manner as in the method of preparing Compound 3 in Synthesis Example 3, except that 7.6 g of Intermediate 17 was used instead of Intermediate 7. (Yield 40%, Mass [M+]=754)

### Preparation Examples of Compound 8

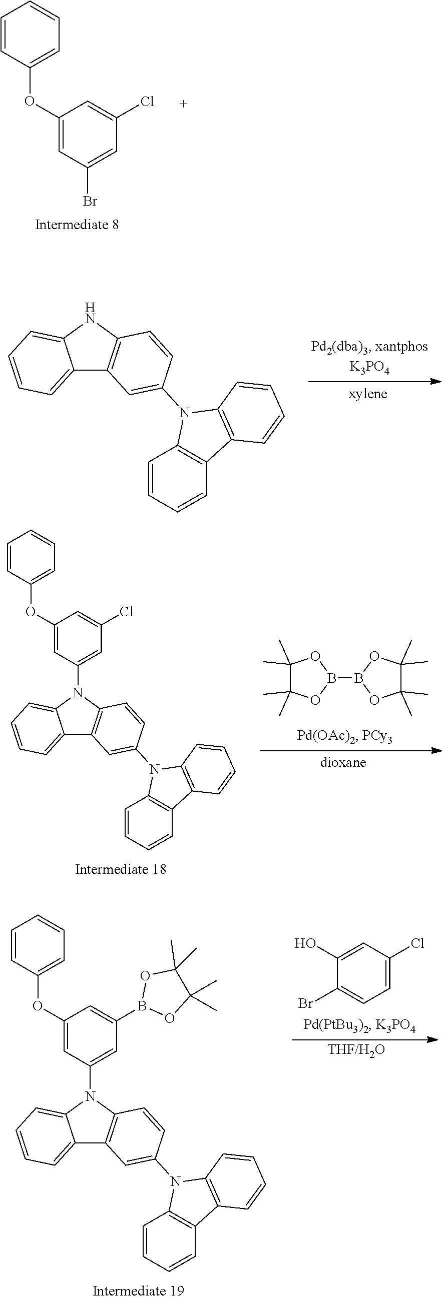

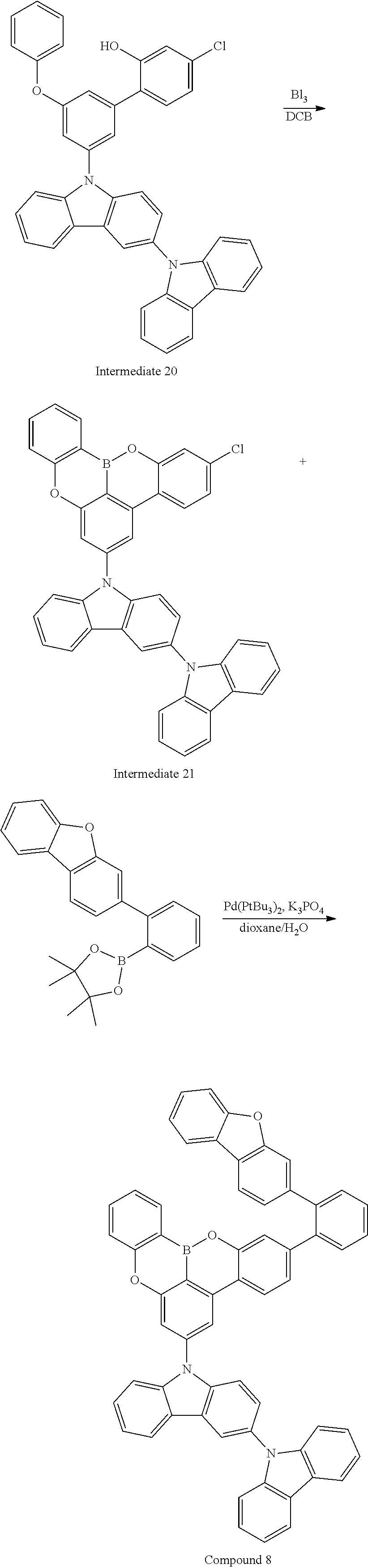 [SMILES: Oc1cc(Cl)ccc1-c1cc(Oc2ccccc2)cc(-n2c3ccccc3c3cc(-n4c5ccccc5c5ccccc54)ccc32)c1 ; "DCB" ; Clc1ccc2c(c1)OB1c3ccccc3Oc3cc(-n4c5ccccc5c5cc(-n6c7ccccc7c7ccccc76)ccc54)cc-2c31 ; CC1(C)OB(c2ccccc2-c2ccc3c(c2)oc2ccccc23)OC1(C)C ; c1ccc2c(c1)Oc1cc(-n3c4ccccc4c4cc(-n5c6ccccc6c6ccccc65)ccc43)cc3c1B2Oc1cc(-c2ccccc2-c2ccc4c(c2)oc2ccccc24)ccc1-3]

### Synthesis of Intermediate 18

After 15 g of Intermediate 8, 21 g of 9H-3,9′-bicarbazole, 34 g of potassium phosphate, and 56 mL of xylene were put into a container under a nitrogen atmosphere, 0.97 g of tris(dibenzylideneacetone)-dipalladium(0) (Pd₂(dba)₃) and 1.2 g of Xantphos were added thereto, and then the resulting mixture was heated at 160° C. and stirred for 5 hours. After the reaction was terminated, the reaction solution was cooled to room temperature, aliquoted by adding water and toluene thereto, and then filtered by treatment with MgSO₄ (anhydrous). The filtered solution was distilled off under reduced pressure and purified with recrystallization (toluene/hexane) to obtain 24 g of Intermediate 18. (Yield 85%, Mass [M+]=536)

### Synthesis of Intermediate 19

21 g of Intermediate 19 was obtained by preparing in the same manner as in the method of preparing Intermediate 10 in Synthesis Example 4, except that 24 g of Intermediate 18 was used instead of Intermediate 9. (Yield 75%, Mass [M+]=627)

### Synthesis of Intermediate 20

16 g of Intermediate 20 was obtained by preparing in the same manner as in the method of preparing Intermediate 11 in Synthesis Example 4, except that 21 g of Intermediate 19 was used instead of Intermediate 10. (Yield 76%, Mass [M+]=628)

### Synthesis of Intermediate 21

7.1 g of Intermediate 21 was obtained by preparing in the same manner as in the method of preparing Compound 3 in Synthesis Example 3, except that 16 g of Intermediate 20 was used instead of Intermediate 7. (Yield 44%, Mass [M+]=635)

### Synthesis of Compound 8

3.5 g of Compound 8 was obtained by preparing in the same manner as in the method of preparing Compound 4 in Synthesis Example 4, except that 3.5 g of Intermediate 21 and 2.1 g of 2-(2-(dibenzo[b,d]furan-3-yl)phenyl)-4,4,5,5-tetramethyl-1,3,2-dioxaborolane were used instead of Intermediate 12 and 2-([1,1′-biphenyl]-2-yl)-4,4,5,5-tetramethyl-1,3,2-dioxaborolane, respectively. (Yield 75%, Mass [M+]=843)

### Preparation Examples of Compound 9

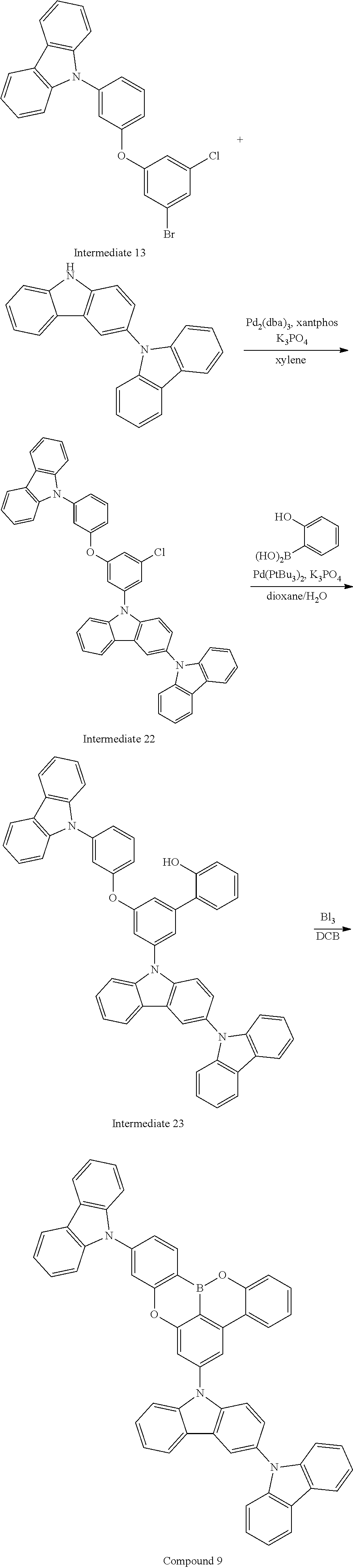

### Synthesis of Intermediate 22

26 g of Intermediate 22 was obtained by preparing in the same manner as in the method of preparing Intermediate 18 in Synthesis Example 8, except that 20 g of Intermediate 13 was used instead of Intermediate 8. (Yield 83%, Mass [M+]=701)

### Synthesis of Intermediate 23

22 g of Intermediate 23 was obtained by preparing in the same manner as in the method of preparing Intermediate 2 in Synthesis Example 1, except that 26 g of Intermediate 22 was used instead of Intermediate 1. (Yield 78%, Mass [M+]=758)

### Synthesis of Compound 9

3.2 g of Compound 9 was obtained by preparing in the same manner as in the method of preparing Compound 3 in Synthesis Example 3, except that 10 g of Intermediate 23 was used instead of Intermediate 7. (Yield 32%, Mass [M+]=766)

### Preparation Examples of Compound 10

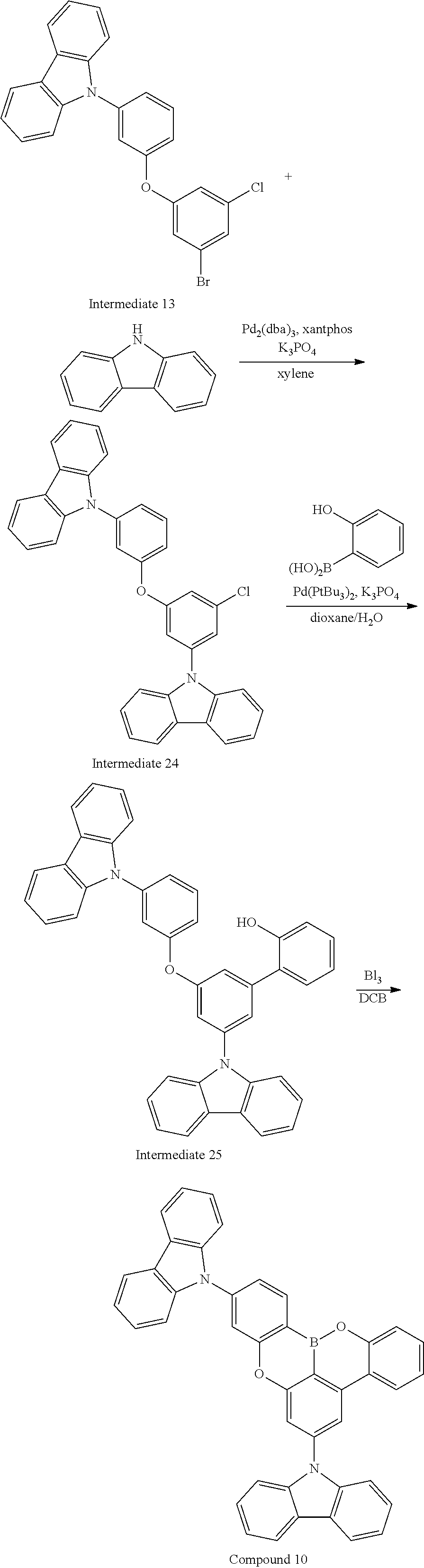

### Synthesis of Intermediate 24

20 g of Intermediate 24 was obtained by preparing in the same manner as in the method of preparing Intermediate 18 in Synthesis Example 8, except that 20 g of Intermediate 13 and 9.0 g of carbazole were used instead of Intermediate 8 and 9H-3,9′-bicarbazole, respectively. (Yield 84%, Mass [M+]=536)

### Synthesis of Intermediate 25

17 g of Intermediate 25 was obtained by preparing in the same manner as in the method of preparing Intermediate 2 in Synthesis Example 1, except that 20 g of Intermediate 24 was used instead of Intermediate 1. (Yield 77%, Mass [M+]=593)

### Synthesis of Compound 10

4.3 g of Compound 10 was obtained by preparing in the same manner as in the method of preparing Compound 3 in Synthesis Example 3, except that 10 g of Intermediate 25 was used instead of Intermediate 7. (Yield 42%, Mass [M+]=601)

### Preparation Examples of Compound 11

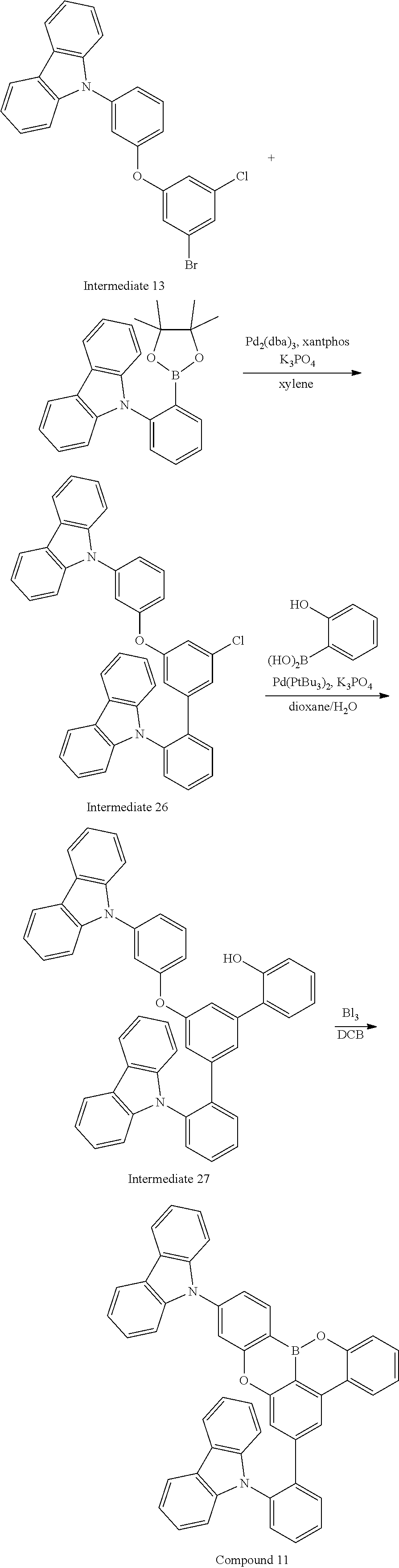

### Synthesis of Intermediate 26

21 g of Intermediate 26 was obtained by preparing in the same manner as in the method of preparing Intermediate 6 in Synthesis Example 3, except that 20 g of Intermediate 13 and 20 g of 9-(2-(4,4,5,5-tetramethyl-1,3,2-dioxaborolan-2-yl)phenyl)-9H-carbazole were used instead of Intermediate 5 and 2-([1,1′-biphenyl]-2-yl)-4,4,5,5-tetramethyl-1,3,2-dioxaborolane, respectively. (Yield 77%, Mass [M+]=612)

### Synthesis of Intermediate 27

17 g of Intermediate 27 was obtained by preparing in the same manner as in the method of preparing Intermediate 2 in Synthesis Example 1, except that 21 g of Intermediate 26 was used instead of Intermediate 1. (Yield 74%, Mass [M+]=669)

### Synthesis of Compound 11

3.8 g of Compound 11 was obtained by preparing in the same manner as in the method of preparing Compound 3 in Synthesis Example 3, except that 10 g of Intermediate 27 was used instead of Intermediate 7. (Yield 38%, Mass [M+]=677)

### Preparation Examples of Compound 12

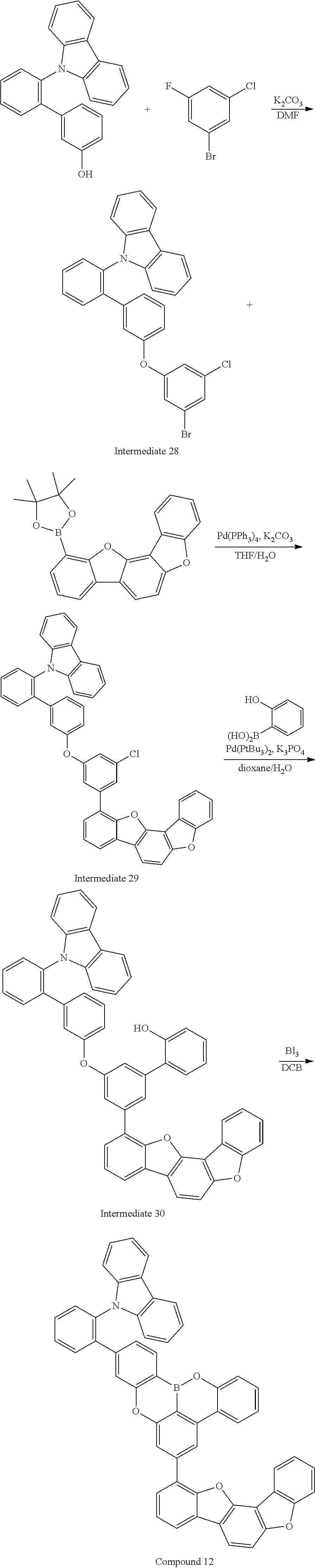

### Synthesis of Intermediate 28

19 g of Intermediate 28 was obtained by preparing in the same manner as in the method of preparing Intermediate 1 in Synthesis Example 1, except that 18 g of 2′-(9H-carbazol-9-yl)-[1,1′-biphenyl]-3-ol and 10 g of 1-bromo-3-chloro-5-fluorobenzene were used instead of the starting material 3-(tetraphenylsilyl)phenol and 9-(3,4-dichloro-5-fluorophenyl)-9H-carbazole, respectively. (Yield 76%, Mass [M+]=525)

### Synthesis of Intermediate 29

16 g of Intermediate 29 was obtained by preparing in the same manner as in the method of preparing Intermediate 6 in Synthesis Example 3, except that 19 g of Intermediate 28 and 17 g of tribenzodifuran-dioxaboralane were used instead of Intermediate 5 and 2-([1,1′-biphenyl]-2-yl)-4,4,5,5-tetramethyl-1,3,2-dioxaborolane, respectively. (Yield 63%, Mass [M+]=703)

### Synthesis of Intermediate 30

12 g of Intermediate 30 was obtained by preparing in the same manner as in the method of preparing Intermediate 2 in Synthesis Example 1, except that 16 g of Intermediate 29 was used instead of Intermediate 1. (Yield 69%, Mass [M+]=760)

### Synthesis of Compound 12

3.1 g of Compound 12 was obtained by preparing in the same manner as in the method of preparing Compound 3 in Synthesis Example 3, except that 8.0 g of Intermediate 30 was used instead of Intermediate 7. (Yield 38%, Mass [M+]=768)

### Preparation Examples of Compound 13

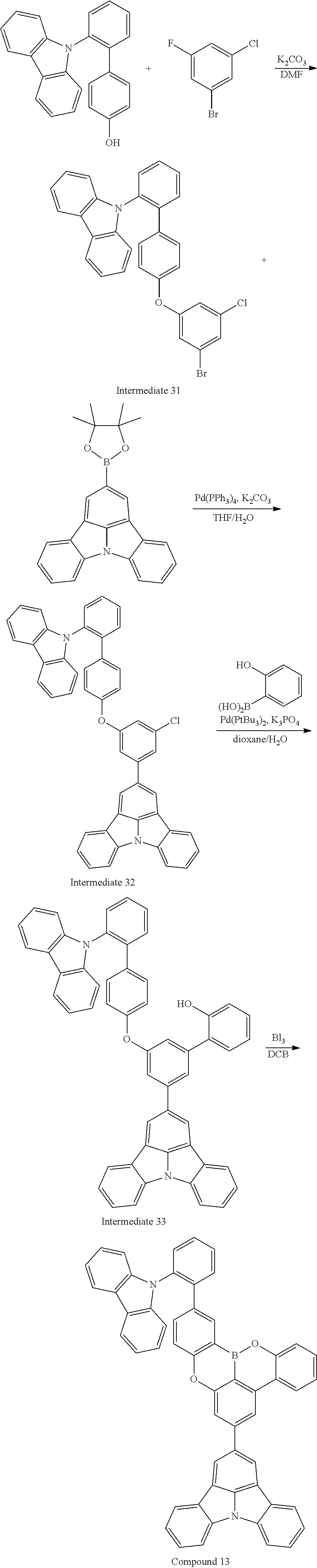

### Synthesis of Intermediate 31

28 g of Intermediate 31 was obtained by preparing in the same manner as in the method of preparing Intermediate 1 in Synthesis Example 1, except that 17 g of 2′-(9H-carbazol-9-yl)-[1,1′-biphenyl]-4-ol and 10 g of 1-bromo-3-chloro-5-fluorobenzene were used instead of the starting material 3-(triphenylsilyl)phenol and 9-(3,4-dichloro-5-fluorophenyl)-9H-carbazole, respectively. (Yield 74%, Mass [M+]=525)

### Synthesis of Intermediate 32

26 g of Intermediate 32 was obtained by preparing in the same manner as in the method of preparing Intermediate 6 in Synthesis Example 3, except that 28 g of Intermediate 31 and 24 g of 2-(4,4,5,5-tetramethyl-1,3,2-dioxaborolan-2-yl)indolo[3,2,1-jk]carbazole were used instead of Intermediate 5 and 2-([1,1′-biphenyl]-2-yl)-4,4,5,5-tetramethyl-1,3,2-dioxaborolane, respectively. (Yield 71%, Mass [M+]=689)

### Synthesis of Intermediate 33

20 g of Intermediate 33 was obtained by preparing in the same manner as in the method of preparing Intermediate 2 in Synthesis Example 1, except that 26 g of Intermediate 32 was used instead of Intermediate 1. (Yield 71%, Mass [M+]=743)

### Synthesis of Compound 13

3.2 g of Compound 13 was obtained by preparing in the same manner as in the method of preparing Compound 3 in Synthesis Example 3, except that 10 g of Intermediate 33 was used instead of Intermediate 7. (Yield 32%, Mass [M+]=751)

### Preparation Examples of Compound 14

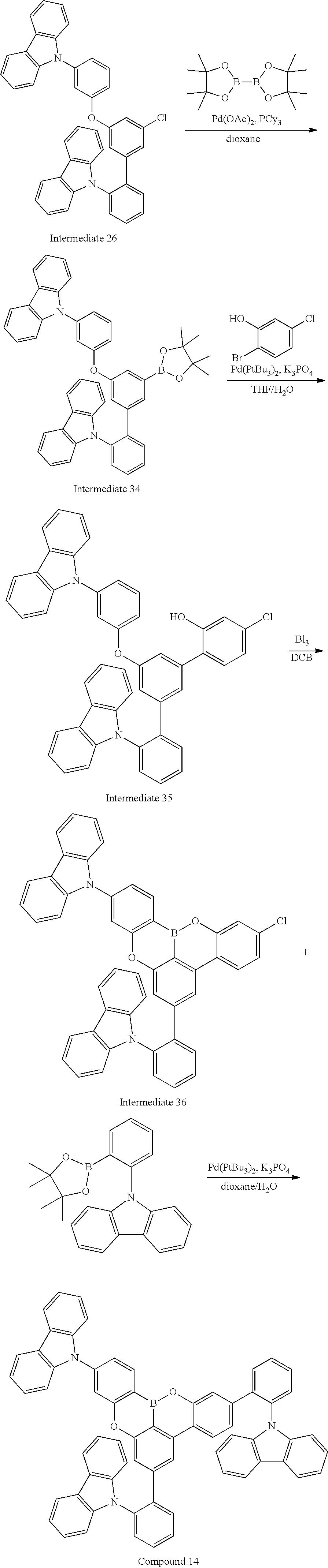

### Synthesis of Intermediate 34

16 g of Intermediate 34 was obtained by preparing in the same manner as in the method of preparing Intermediate 19 in Synthesis Example 8, except that 20 g of Intermediate 26 was used instead of Intermediate 18. (Yield 70%, Mass [M+]=703)

### Synthesis of Intermediate 35

12 g of Intermediate 35 was obtained by preparing in the same manner as in the method of preparing Intermediate 11 in Synthesis Example 4, except that 16 g of Intermediate 34 was used instead of Intermediate 10. (Yield 75%, Mass [M+]=704)

### Synthesis of Intermediate 36

4.8 g of Intermediate 36 was obtained by preparing in the same manner as in the method of preparing Compound 3 in Synthesis Example 3, except that 12 g of Intermediate 35 was used instead of Intermediate 7. (Yield 40%, Mass [M+]=712)

### Synthesis of Compound 14

4.3 g of Intermediate 14 was obtained by preparing in the same manner as in the method of preparing Compound 4 in Synthesis Example 4, except that 4.8 g of Intermediate 36 and 2.6 g of 9-(2-(4,4,5,5-tetramethyl-1,3,2-dioxaborolan-2-yl)phenyl)-9H-carbazole were used instead of Intermediate 12 and 2-([1,1′-biphenyl]-2-yl)-4,4,5,5-tetramethyl-1,3,2-dioxaborolane, respectively. (Yield 69%, Mass [M+]=918)

### Preparation Examples of Compound 15

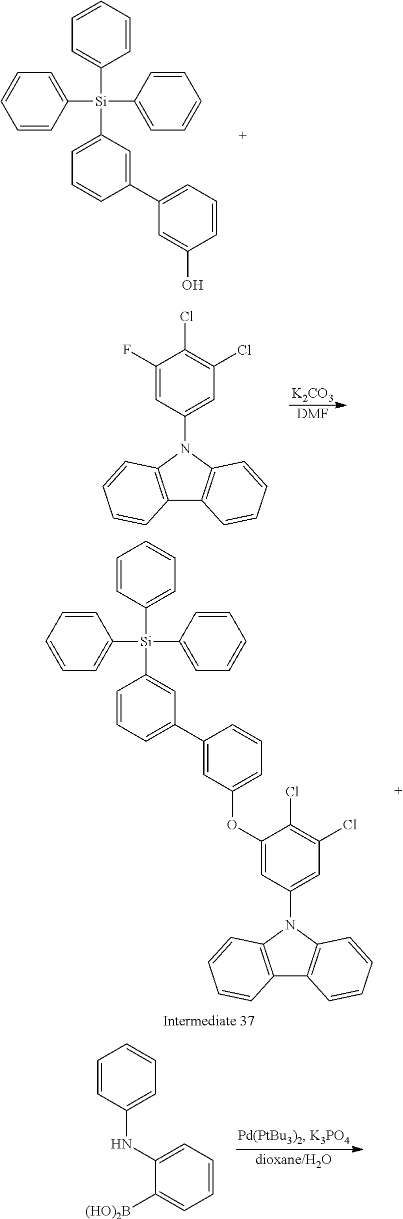

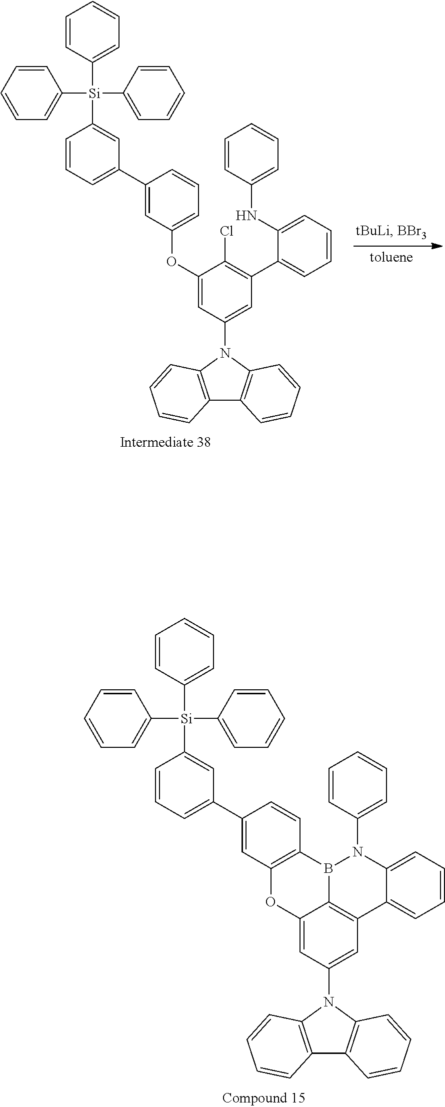 [SMILES: Clc1c(Oc2cccc(-c3cccc([Si](c4ccccc4)(c4ccccc4)c4ccccc4)c3)c2)cc(-n2c3ccccc3c3ccccc32)cc1-c1ccccc1Nc1ccccc1 ; c1ccc(N2B3c4ccc(-c5cccc([Si](c6ccccc6)(c6ccccc6)c6ccccc6)c5)cc4Oc4cc(-n5c6ccccc6c6ccccc65)cc(c43)-c3ccccc32)cc1]

### Synthesis of Intermediate 37

16 g of Intermediate 37 was obtained by preparing in the same manner as in the method of preparing Intermediate 1 in Synthesis Example 1, except that 10 g of 3′-(triphenylsilyl)-[1,1′-biphenyl]-3-ol and 14 g of 9-(3,4-dichloro-5-fluorophenyl)-9H-carbazole were used instead of the starting material 3-(triphenylsilyl)phenol and 9-(3,4-dichloro-5-fluorophenyl)-9H-carbazole, respectively. (Yield 72%, Mass [M+]=739)

### Synthesis of Intermediate 38

12 g of Intermediate 38 was obtained by preparing in the same manner as in the method of preparing Intermediate 2 in Synthesis Example 1, except that 16 g of Intermediate 37 and 5.5 g of 2-(phenylamino)phenyl)boronic acid were used instead of Intermediate 1 and 2-hydroxyphenylboronic acid, respectively. (Yield 64%, Mass [M+]=872)

### Synthesis of Compound 15

2.3 g of Compound 15 was obtained by preparing in the same manner as in the method of preparing Compound 1 in Synthesis Example 1, except that 12 g of Intermediate 38 was used instead of Intermediate 2. (Yield 20%, Mass [M+]=845)

### Preparation Examples of Compound 16

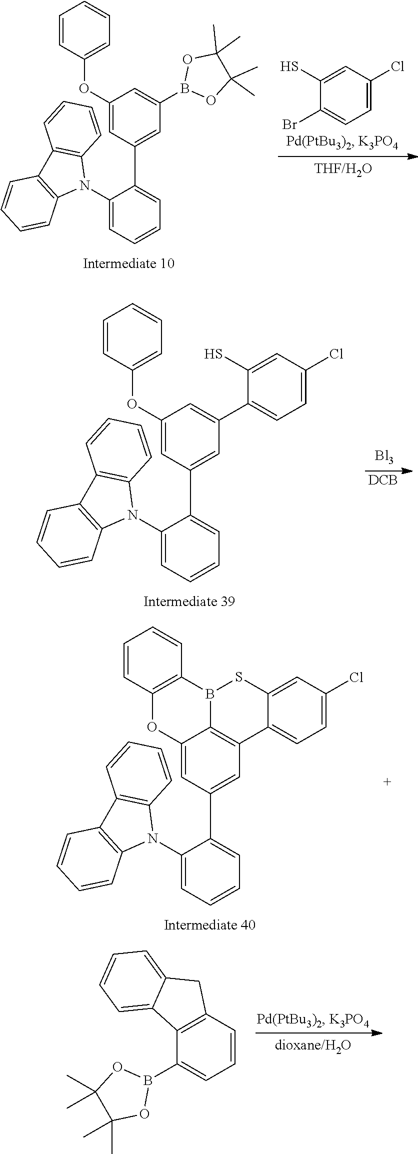

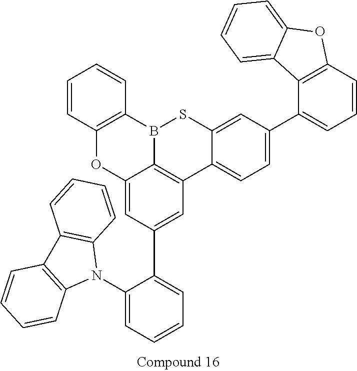 [SMILES: c1ccc2c(c1)Oc1cc(-c3ccccc3-n3c4ccccc4c4ccccc43)cc3c1B2Sc1cc(-c2cccc4oc5ccccc5c24)ccc1-3]

### Synthesis of Intermediate 39

10 g of Intermediate 39 was obtained in the same manner as in the method of preparing Intermediate 11 in Synthesis Example 4, except that 15 g of Intermediate 10 and 7.5 g of 2-bromo-5-chlorobenzenethiol instead of 2-bromo-5-chlorophenol were used. (Yield 65%, Mass [M+]=555)

### Synthesis of Intermediate 40

3.5 g of Intermediate 40 was obtained by preparing in the same manner as in the method of preparing Compound 3 in Synthesis Example 3, except that 10 g of Intermediate 39 was used instead of Intermediate 7. (Yield 35%, Mass [M+]=562)

### Synthesis of Compound 16

3.4 g of Compound 16 was obtained by preparing in the same manner as in the method of preparing Compound 4 in Synthesis Example 4, except that 3.5 g of Intermediate 40 and 1.9 g of 2-(dibenzo[b,d]furan-1-yl)-4,4,5,5-tetramethyl-1,3,2-dioxaborolane were used instead of Intermediate 12 and 2-([1,1′-biphenyl]-2-yl)-4,4,5,5-tetramethyl-1,3,2-dioxaborolane, respectively. (Yield 79%, Mass [M+]=694)

### Preparation Examples of Compound 17

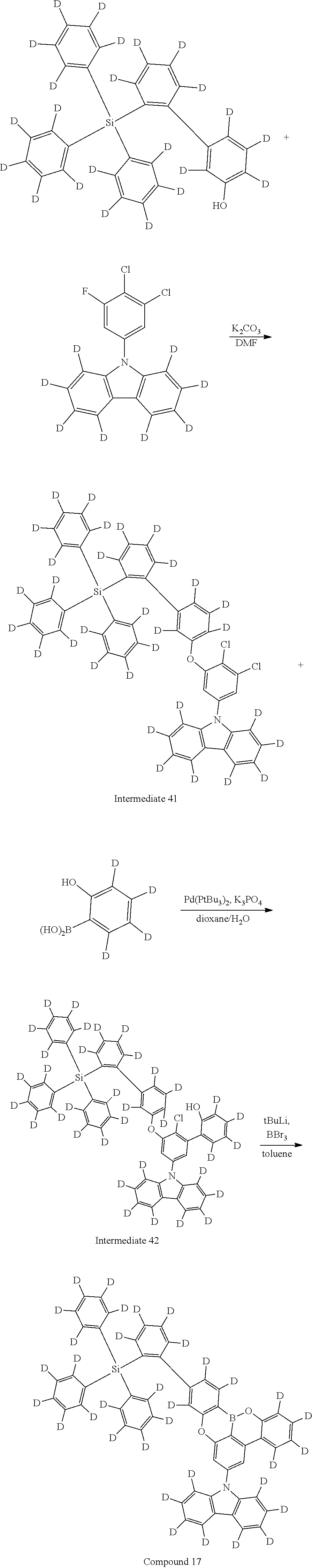

### Synthesis of Intermediate 41

16 g of Intermediate 41 was obtained by preparing in the same manner as in the method of preparing Intermediate 1 in Synthesis Example 1, except that 15 g of 2′-(tris(phenyl-d5)silyl)-[1,1′-biphenyl]-2,3′,4,4′,5,5′,6,6′-d8-3-ol and 10 g of 9-(3,4-dichloro-5-fluorophenyl)-9H-carbazole were used instead of the starting material 3-(triphenylsilyl)phenol and 9-(3,4-dichloro-5-fluorophenyl)-9H-carbazole-1,2,3,4,5,6,7,8-d8, respectively. (Yield 70%, Mass [M+]=770)

### Synthesis of Intermediate 42

13 g of Intermediate 42 was obtained by preparing in the same manner as in the method of preparing Intermediate 2 in Synthesis Example 1, except that 16 g of Intermediate 41 was used instead of Intermediate 1. (Yield 75%, Mass [M+]=832)

### Synthesis of Compound 17

2.2 g of Compound 17 was obtained by preparing in the same manner as in the method of preparing Compound 1 in Synthesis Example 1, except that 13 g of Intermediate 42 was used instead of Intermediate 2. (Yield 18%, Mass [M+]=804)

### Preparation Examples of Compound 18

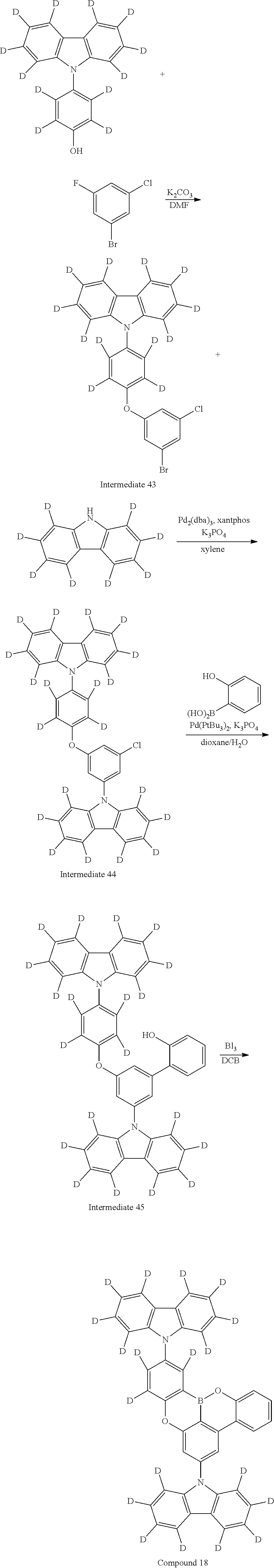

### Synthesis of Intermediate 43

18 g of Intermediate 43 was obtained by preparing in the same manner as in the method of preparing Intermediate 1 in Synthesis Example 1, except that 14 g of 4-(9H-carbazol-9-yl-d8)phen-2,3,5,6-d4-ol and 10 g of 1-bromo-3-chloro-5-fluorobenzene were used instead of the starting material 3-(triphenylsilyl)phenol and 9-(3,4-dichloro-5-fluorophenyl)-9H-carbazole, respectively. (Yield 82%, Mass [M+]=461)

### Synthesis of Intermediate 44

17 g of Intermediate 44 was obtained by preparing in the same manner as in the method of preparing Intermediate 18 in Synthesis Example 8, except that 18 g of Intermediate 43 and 8.2 g of 9H-carbazole-1,2,3,4,5,6,7,8-d8 were used instead of Intermediate 8 and 9H-3,9′-bicarbazole, respectively. (Yield 78%, Mass [M+]=556)

### Synthesis of Intermediate 45

13 g of Intermediate 45 was obtained by preparing in the same manner as in the method of preparing Intermediate 2 in Synthesis Example 1, except that 18 g of Intermediate 44 was used instead of Intermediate 1. (Yield 69%, Mass [M+]=613)

### Synthesis of Compound 18

3.5 g of Compound 18 was obtained by preparing in the same manner as in the method of preparing Compound 3 in Synthesis Example 3, except that 8.0 g of Intermediate 45 was used instead of Intermediate 7. (Yield 43%, Mass [M+]=620)

### Preparation Examples of Compound 19

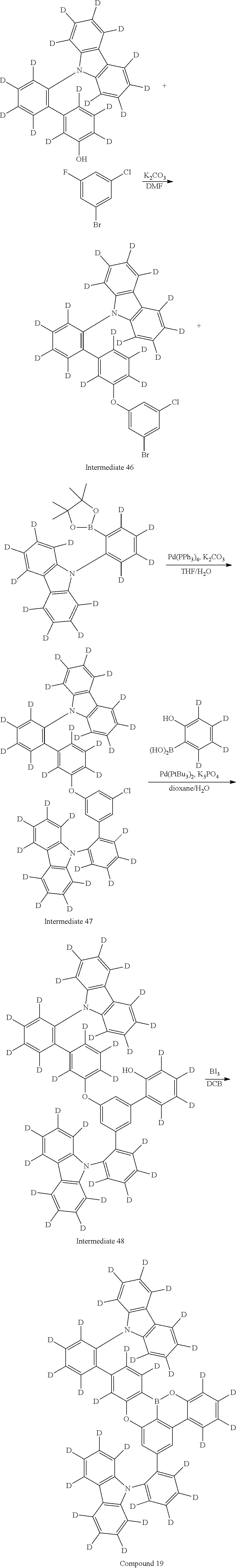

### Synthesis of Intermediate 46

20 g of Intermediate 46 was obtained by preparing in the same manner as in the method of preparing Intermediate 1 in Synthesis Example 1, except that 18 g of 2′-(9H-carbazol-9-yl-d8)-[1,1′-biphenyl]-2,3′,4,4′,5,5′,6,6′-d8-3-ol and 10 g of 1-bromo-3-chloro-5-fluorobenzene were used instead of the starting material 3-(triphenylsilyl)phenol and 9-(3,4-dichloro-5-fluorophenyl)-9H-carbazole, respectively. (Yield 78%, Mass [M+]=540)

### Synthesis of Intermediate 47

20 g of Intermediate 47 was obtained by preparing in the same manner as in the method of preparing Intermediate 6 in Synthesis Example 3, except that 20 g of Intermediate 46 and 17 g of 9-(2-(4,4,5,5-tetramethyl-1,3,2-dioxaborolan-2-yl)phenyl)-3,4,5,6-d4)-9H-carbazol-1,2,3,4,5,6,7,8-d8 were used instead of Intermediate 5 and 2-([1,1′-biphenyl]-2-yl)-4,4,5,5-tetramethyl-1,3,2-dioxaborolane, respectively. (Yield 76%, Mass [M+]=715)

### Synthesis of Intermediate 48

16 g of Intermediate 48 was obtained by preparing in the same manner as in the method of preparing Intermediate 2 in Synthesis Example 1, except that 20 g of Intermediate 47 was used instead of Intermediate 1. (Yield 74%, Mass [M+]=777)

### Synthesis of Compound 19

3.6 g of Compound 19 was obtained by preparing in the same manner as in the method of preparing Compound 3 in Synthesis Example 3, except that 8.0 g of Intermediate 48 was used instead of Intermediate 7. (Yield 45%, Mass [M+]=784)

Preparation Examples of Compound 20

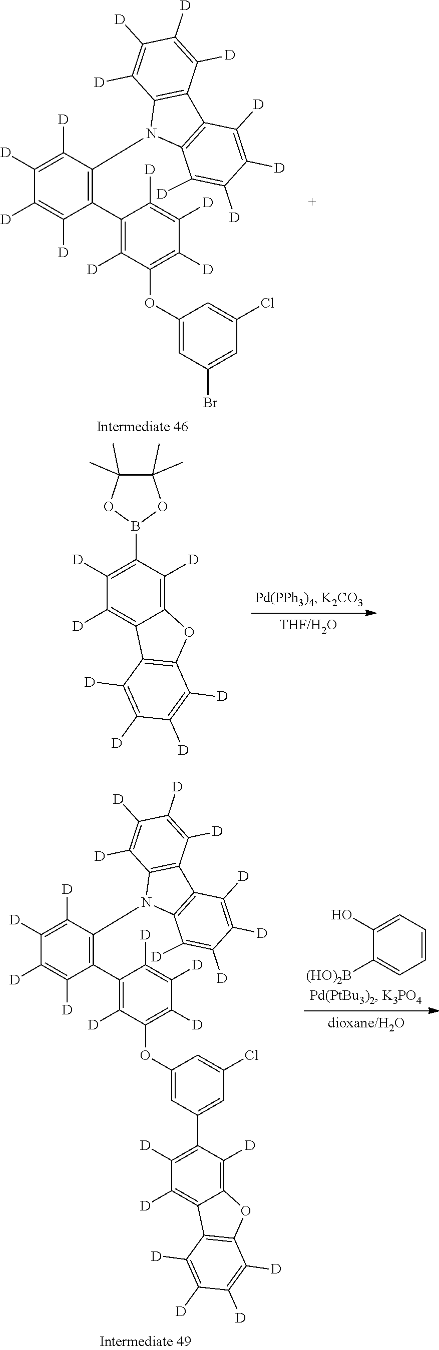

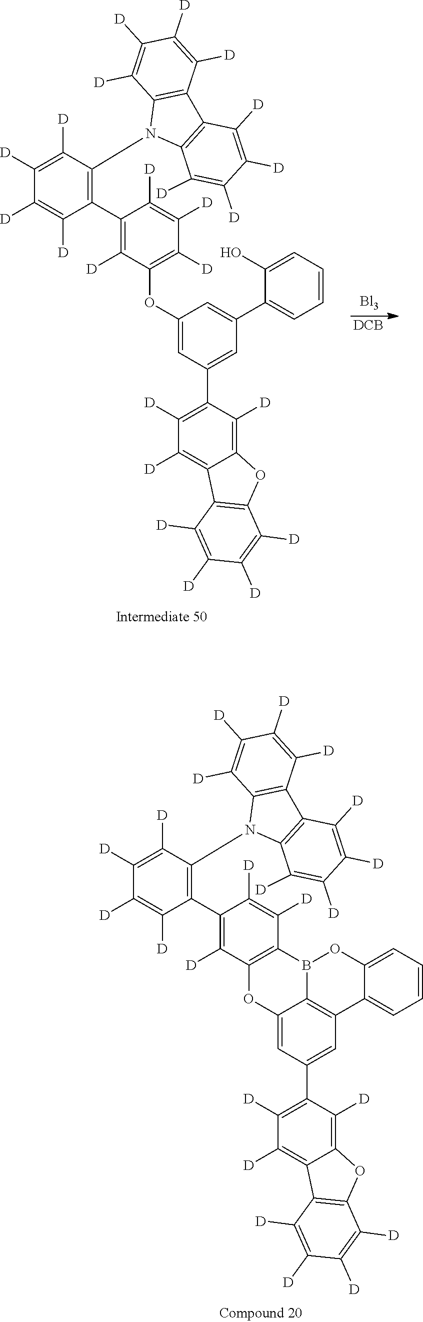

### Synthesis of Intermediate 49

13 g of Intermediate 49 was obtained by preparing in the same manner as in the method of preparing Intermediate 6 in Synthesis Example 3, except that 15 g of Intermediate 46 and 10 g of 2-(dibenzo[b,d]furan-3-yl-d7)-4,4,5,5-tetramethyl-1,3,2-dioxaborolane were used instead of Intermediate 5 and 2-([1,1′-biphenyl]-2-yl)-4,4,5,5-tetramethyl-1,3,2-dioxaborolane, respectively. (Yield 74%, Mass [M+]=635)

### Synthesis of Intermediate 50

11 g of Intermediate 50 was obtained by preparing in the same manner as in the method of preparing Intermediate 2 in Synthesis Example 1, except that 13 g of Intermediate 49 was used instead of Intermediate 1. (Yield 78%, Mass [M+]=692)

### Synthesis of Compound 20

4.4 g of Compound 20 was obtained by preparing in the same manner as in the method of preparing Compound 3 in Synthesis Example 3, except that 11 g of Intermediate 50 was used instead of Intermediate 7. (Yield 40%, Mass [M+]=700)

### Preparation Example 2

### Preparation Example of Compound D1

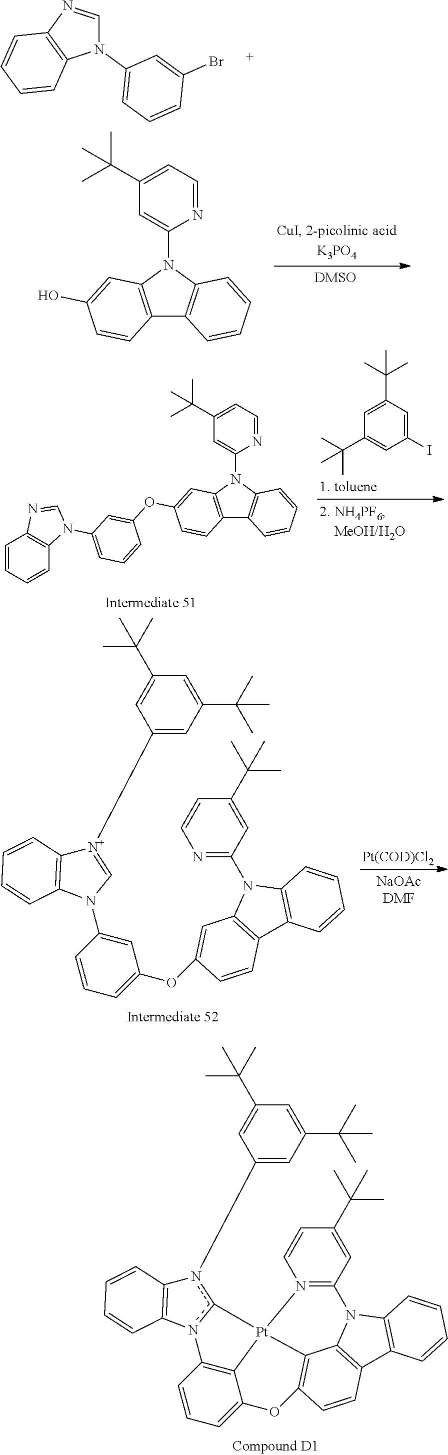

### Synthesis of Intermediate 51

After 20 g of 1-(3-bromophenyl)-1H-benzo[d]imidazole, 23 g of 9-(4-(tert-butyl)pyridin-2-yl)-9H-carbazol-2-ol, 31 g of potassium phosphate, 1.4 g of copper iodide (CuI), 1.8 g of picolinic acid, and 500 mL of dimethylsulfoxide (DMSO) were put into a container under a nitrogen atmosphere, the resulting mixture was heated at 150° C. and stirred for 72 hours. After the reaction was terminated, the reaction solution was cooled to room temperature, aliquoted by adding water and ethyl acetate thereto, and then filtered by treatment with MgSO₄ (anhydrous). The filtered solution was distilled off under reduced pressure and purified by column chromatography (ethyl acetate/hexane) to obtain 30 g of Intermediate 51. (Yield 81%, Mass [M+]=509)

### Synthesis of Intermediate 52

After 15 g of Intermediate 5-1, 11.2 g of 1,3-di-tert-butyl-5-iodobenzene, and 200 mL of toluene were put into a container under a nitrogen atmosphere, the resulting mixture was heated at 100° C. and stirred for 50 hours. After the reaction was terminated, the reaction solution was cooled to room temperature, and then the resulting solid was filtered and washed with diethyl ether. The obtained solid was dissolved by adding 200 mL of methanol and 20 mL of water thereto and stirring the resulting mixture. And, 7.2 g of ammonium hexafluorophosphate (NH₄PF₆) was added thereto, and the resulting mixture was stirred at room temperature for 3 days. After the reaction was terminated, water was added thereto, and the resulting solid was filtered and washed with diethyl ether. The washed solid was dried to obtain 10 g of Intermediate 52. (Yield 49%, Mass [M+]=698)

### Synthesis of Compound D1

After 10 g of Intermediate 5-2, 3.5 g of sodium acetate, 5.9 g of dichloro(1,5-cyclooctadiene)platinum (Pt(COD)Cl₂), and 100 mL of dimethylformamide (DMF) were put into a container under a nitrogen atmosphere, the resulting mixture was heated at 120° C. and stirred for 72 hours. After the reaction was terminated, the reaction solution was cooled to room temperature, then aliquoted by adding water and ethyl acetate thereto, and then filtered by treatment with MgSO₄ (anhydrous). The filtered solution was distilled off under reduced pressure and purified by column chromatography (ethyl acetate/hexane) to obtain 1.1 g of Compound D1. (Yield 9%, Mass [M+]=891)

### Preparation Example of Compound D2

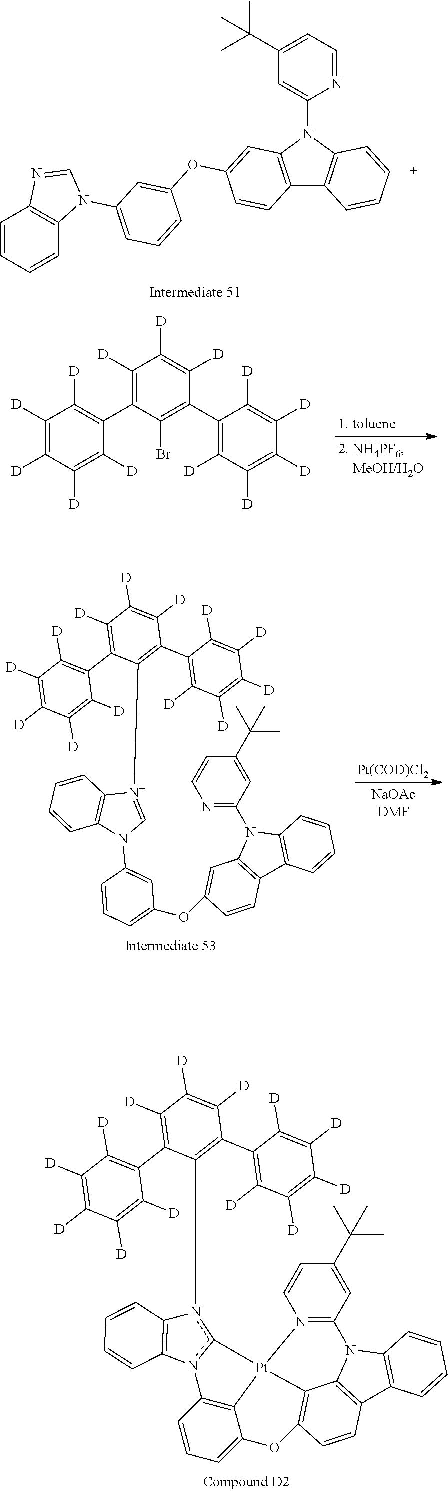

### Synthesis of Intermediate 53

10 g of Intermediate 53 was obtained by preparing in the same manner as in the method of preparing Intermediate 52, which is the compound in Synthesis Example H21, except that 15 g of 2′-bromo-1,1′:3′,1″-terphenyl-2,2″,3,3″,4,4′,4″,5,5′,5,6,6′,6″-d13 was used instead of the starting material 1,3-di-tert-butyl-5-iodobenzene. (Yield 45%, Mass [M+]=752)

### Synthesis of Compound D2

1.0 g of Compound D2 was obtained by preparing in the same manner as in the method of preparing Compound D1 in Synthesis Example 21, except that 10 g of Intermediate 53 was used instead of the starting material Intermediate 52. (Yield 8%, Mass [M+]=944)

### Preparation Example of Compound D3

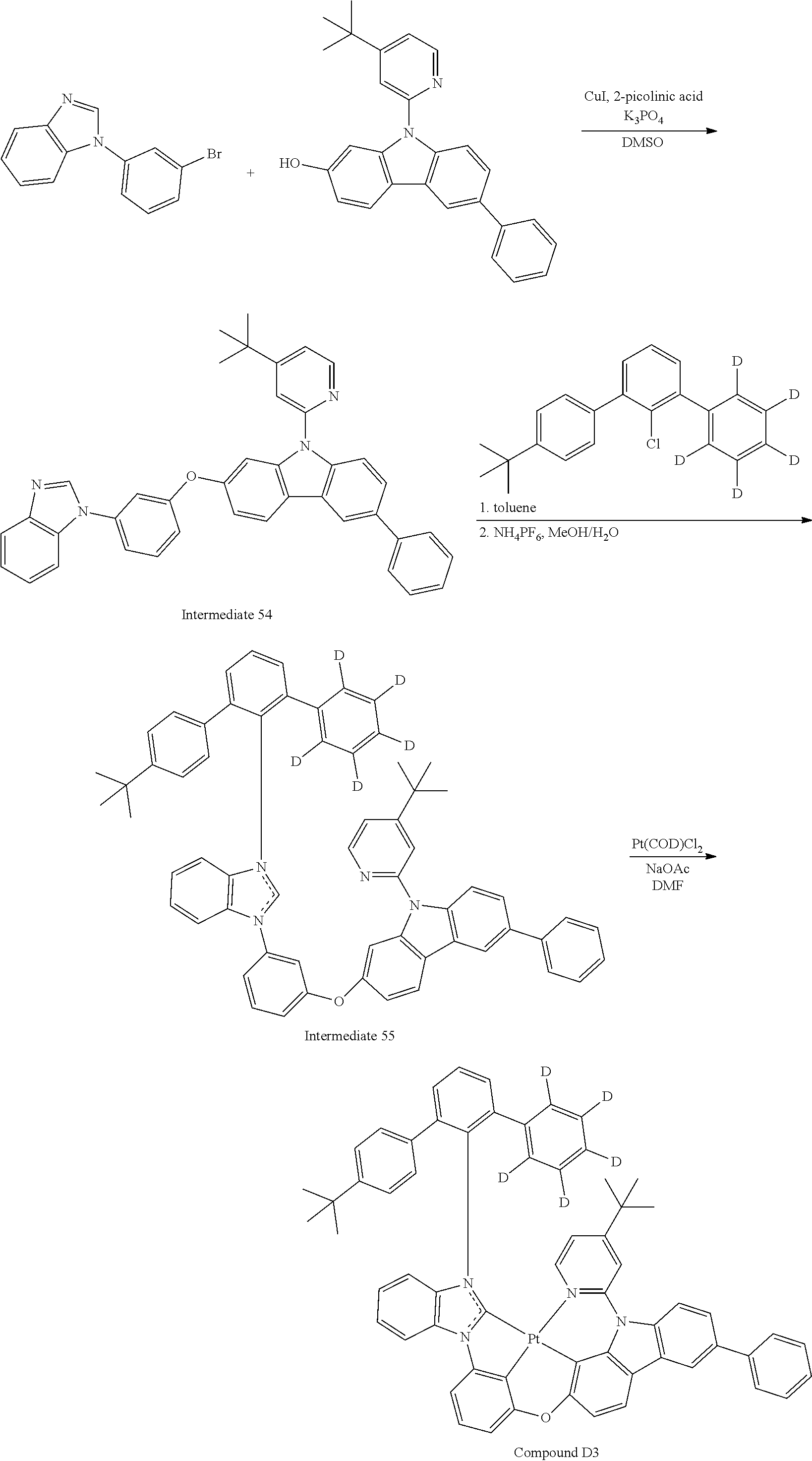

### Synthesis of Intermediate 54

35 g of Intermediate 54 was obtained by preparing in the same manner as in the method of preparing Intermediate 51, which is the compound in Synthesis Example H21, except that 29 g of 9-(4-(tert-butyl)pyridin-2-yl)-6-phenyl-9H-carbazol-2-ol was used instead of the starting material 9-(4-(tert-butyl)pyridin-2-yl)-9H-carbazol-2-ol. (Yield 82%, Mass [M+]=585)

### Synthesis of Intermediate 55

21 g of Intermediate 55 was obtained by preparing in the same manner as in the method of preparing Intermediate 52, which is the compound in Synthesis Example H21, except that 35 g of Intermediate 54 and 23 g of 4-(tert-butyl)-2′-chloro-1,1′:3′,1-terphenyl-2″,3″,4″,5,6″-d5 were used instead of Intermediate 51 and 1,3-di-tert-butyl-5-iodobenzene, respectively. (Yield 40%, Mass [M+]=876)

### Synthesis of Compound D3

1.1 g of Compound D3 was obtained by preparing in the same manner as in the method of preparing Compound D1 in Synthesis Example H21, except that 10 g of Intermediate 55 was used instead of Intermediate 52. (Yield 9%, Mass [M+]=1068)

### Examples and Comparative Examples

### Example 1

A glass substrate thinly coated with indium tin oxide (ITO) to have a thickness of 800 Å was put into distilled water in which a detergent was dissolved, and ultrasonically washed. In this case, a product manufactured by the Fischer Co., was used as the detergent, and distilled water twice filtered using a filter manufactured by Millipore Co., was used as the distilled water. After the ITO was washed for 30 minutes, ultrasonic washing was repeated twice by using distilled water for 10 minutes. After the washing using distilled water was completed, ultrasonic washing was conducted by using isopropyl alcohol, acetone, and methanol solvents, and the resulting product was dried and then transported to a plasma washing machine. Furthermore, the substrate was cleaned by using oxygen plasma for 5 minutes, and then was transported to a vacuum deposition machine.

Compounds of the following Compound HT1 and the following Compound HI1 were thermally vacuum deposited to have a thickness of 100 Å at a ratio of 98:2 (molar ratio) on a transparent ITO electrode, which is the positive electrode thus prepared, thereby forming a hole injection layer. A compound represented by the following Chemical Formula HT1 (400 Å) was vacuum deposited on the hole injection layer, thereby forming a hole transport layer. Subsequently, a compound of BH (p-type) was vacuum deposited to have a film thickness of 50 Å on the hole transport layer, thereby forming an electron blocking layer. Subsequently, on the electron blocking layer, a compound, in which the following Chemical Formula BH (p-type) and Compound 1 were mixed at 1:1, as a host of the light emitting layer, and a dopant compound represented by Compound D1 were vacuum deposited at a weight ratio of 88:12 to form a light emitting layer. Compound 1 was vacuum deposited to have a film thickness of 50 Å on the light emitting layer, thereby forming a hole blocking layer. Subsequently, a compound represented by the following Chemical Formula ET1 and a compound represented by the following Chemical Formula LiQ were vacuum deposited at a weight ratio of 1:1 on the hole blocking layer, thereby forming an electron injection and transport layer having a thickness of 300 Å. Lithium fluoride (LiF) and aluminum were sequentially deposited on the electron injection and transport layer to have a thickness of 10 Å and 800 Å, respectively, thereby forming a negative electrode.

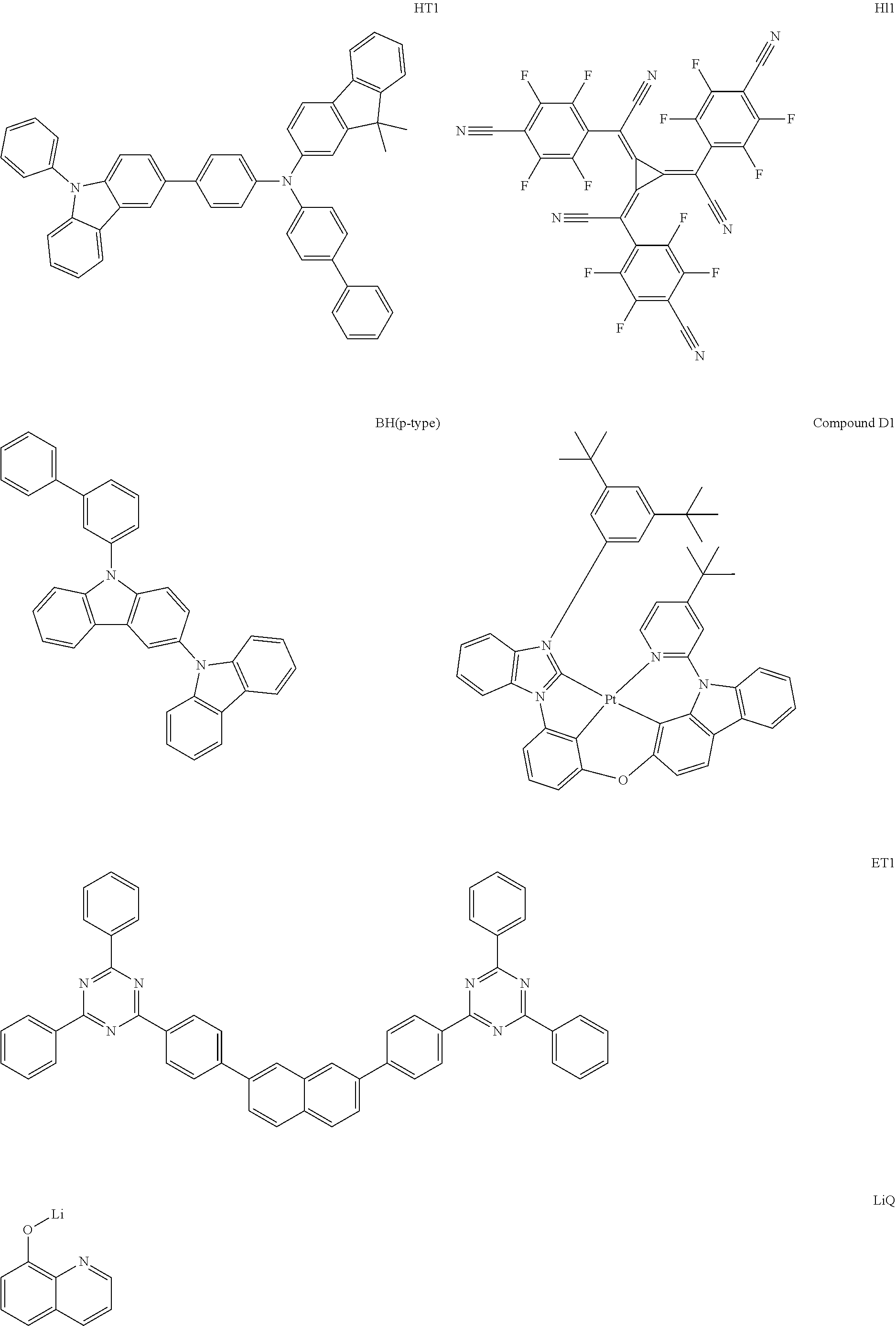

In the aforementioned procedure, the deposition rate of the organic material was maintained at 0.4 to 0.7 Å/sec, the deposition rates of lithium fluoride and aluminum of the negative electrode were maintained at 0.3 Å/sec and at 2 Å/sec, respectively, and the degree of vacuum during the deposition was maintained at 2×10⁻⁷ to 5×10⁻⁶ torr, thereby manufacturing an organic light emitting device.

### Examples 2 to 30

Organic light emitting devices were manufactured in the same manner as in Example 1, except that the compounds described in the following Table 1 were used instead of Compound 1 as a host and Compound D1 as a dopant in the light emitting layer in Example 1.

### Examples 31 and 32

Organic light emitting devices were manufactured in the same manner as in Example 1, except that the compounds described in the following Table 1 were used instead of Compound 1 as a host and Compound D1 as a dopant in the light emitting layer in Example 1 and Compound 5 was used instead of Compound 1 as a hole blocking layer in Example 1.

### [Compounds of the Examples]

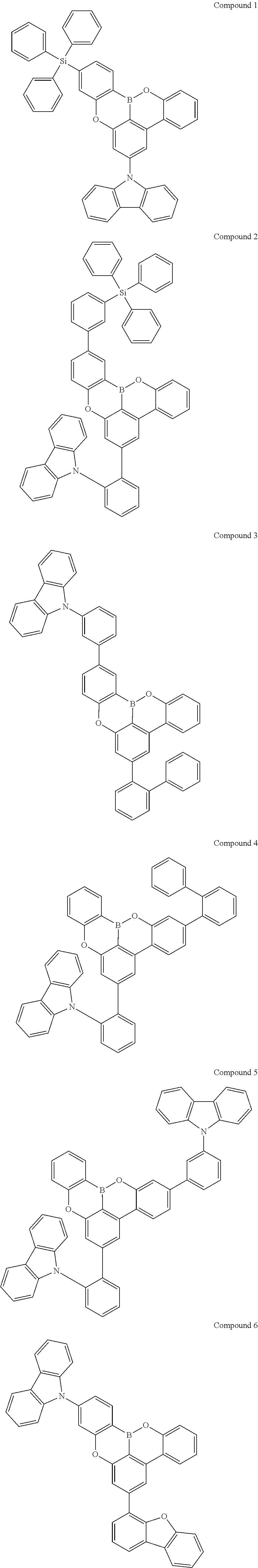

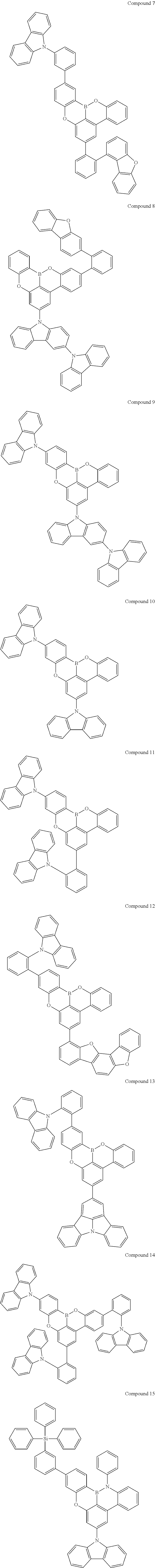

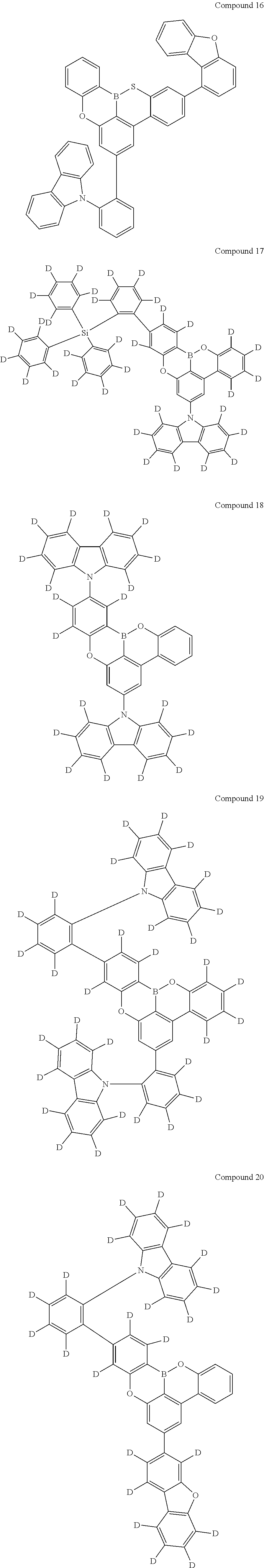

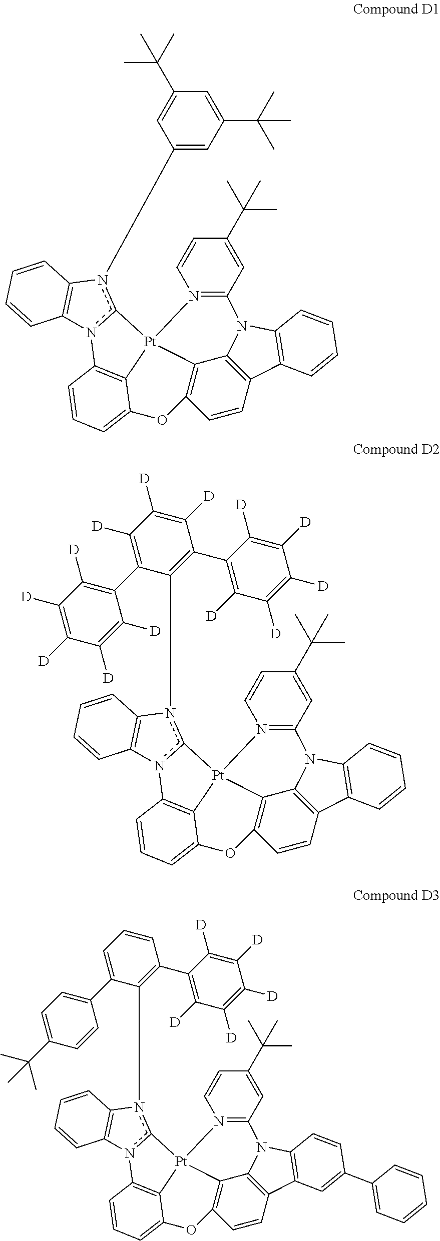

### Comparative Examples 1 to 7

Organic light emitting devices were manufactured in the same manner as in Example 1, except that the compounds described in the following Table 1 were used instead of Compound 1 as a host and Compound D1 as a dopant in the light emitting layer in Example 1.

### [Comparative Example Compound]

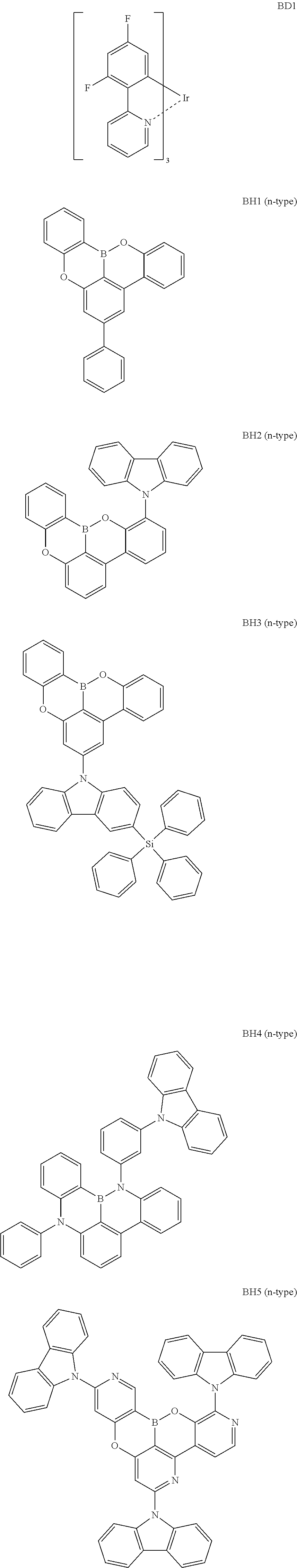

When current was applied to the organic light emitting devices manufactured in Examples 1 to 32 and Comparative Examples 1 to 7, the voltage, efficiency, and service life of each organic light emitting device were measured (based on 1600 nit), and the results thereof are shown in the following Table 1. Service life T90 means the time taken for the luminance to be reduced to 90% of the initial luminance (1600 nit).

TABLE 1

| | | | | Light | |
|---|---|---|---|---|---|
| | Chemical | Chemical | | emitting | |
| | Formula 1 | Formula 2 | | efficiency | Service |
| | (Host | (Dopant | Voltage (V) | (Cd/A) | life, |
| | compound) | compound) | @10 mA/cm² | @10 mA/cm² | T90(h) |
| Example 1 | Compound 1 | Compound D1 | 3.92 | 20.2 | 119 |
| Example 2 | Compound 2 | Compound D3 | 3.86 | 21.8 | 131 |
| Example 3 | Compound 3 | Compound D1 | 3.85 | 20.4 | 121 |
| Example 4 | Compound 3 | Compound D2 | 3.89 | 21.0 | 129 |
| Example 5 | Compound 4 | Compound D1 | 3.90 | 20.6 | 123 |
| Example 6 | Compound 5 | Compound D2 | 3.87 | 21.1 | 136 |
| Example 7 | Compound 6 | Compound D2 | 3.93 | 21.4 | 139 |
| Example 8 | Compound 6 | Compound D3 | 3.87 | 21.8 | 137 |
| Example 9 | Compound 7 | Compound D1 | 3.90 | 21.6 | 129 |
| Example 10 | Compound 8 | Compound D2 | 3.92 | 21.2 | 135 |
| Example 11 | Compound 9 | Compound D3 | 3.86 | 21.8 | 130 |
| Example 12 | Compound 10 | Compound D1 | 3.85 | 21.1 | 135 |
| Example 13 | Compound 10 | Compound D2 | 3.89 | 21.7 | 144 |
| Example 14 | Compound 10 | Compound D3 | 3.83 | 22.1 | 142 |
| Example 15 | Compound 11 | Compound D1 | 3.85 | 21.3 | 132 |
| Example 16 | Compound 11 | Compound D2 | 3.89 | 21.9 | 141 |
| Example 17 | Compound 12 | Compound D1 | 3.89 | 20.7 | 122 |
| Example 18 | Compound 13 | Compound D2 | 3.94 | 20.3 | 134 |
| Example 19 | Compound 14 | Compound D2 | 3.88 | 22.3 | 138 |
| Example 20 | Compound 15 | Compound D3 | 3.90 | 21.4 | 127 |
| Example 21 | Compound 16 | Compound D2 | 3.94 | 21.8 | 126 |
| Example 22 | Compound 17 | Compound D1 | 3.85 | 21.3 | 138 |
| Example 23 | Compound 17 | Compound D2 | 3.89 | 21.9 | 148 |
| Example 24 | Compound 17 | Compound D3 | 3.83 | 22.3 | 145 |
| Example 25 | Compound 18 | Compound D1 | 3.83 | 21.9 | 152 |
| Example 26 | Compound 18 | Compound D2 | 3.87 | 22.5 | 163 |
| Example 27 | Compound 19 | Compound D1 | 3.85 | 21.5 | 166 |
| Example 28 | Compound 19 | Compound D3 | 3.83 | 22.5 | 171 |
| Example 29 | Compound 20 | Compound D2 | 3.91 | 21.7 | 168 |
| Example 30 | Compound 20 | Compound D3 | 3.85 | 22.1 | 165 |
| Example 31 | Compound 11 | Compound D3 | 3.88 | 22.2 | 135 |
| Example 32 | Compound 18 | Compound D3 | 3.85 | 22.4 | 155 |
| Comparative | Compound 4 | Compound BD1 | 4.15 | 18.6 | 101 |
| Example 1 | | | | | |
| Comparative | Compound 11 | Compound BD1 | 4.10 | 18.8 | 108 |
| Example 2 | | | | | |
| Comparative | Compound BH1 | Compound D1 | 4.20 | 13.7 | 94 |
| Example 3 | | | | | |
| Comparative | Compound BH2 | Compound D2 | 4.19 | 19.0 | 113 |
| Example 4 | | | | | |
| Comparative | Compound BH3 | Compound D3 | 4.09 | 18.3 | 103 |
| Example 5 | | | | | |
| Comparative | Compound BH4 | Compound D1 | 4.27 | 16.5 | 106 |
| Example 6 | | | | | |
| Comparative | Compound BH5 | Compound D1 | 4.44 | 10.0 | 33 |
| Example 7 | | | | | |

In Comparative Examples 1 and 2, Compound BD used as a dopant is Ir(dFppy)₃, and the compound represented by Chemical Formula 1 and the compound represented by Chemical Formula 2 are not used simultaneously, so that it could be confirmed that no synergistic effect appeared in the organic light emitting devices.

In Comparative Example 3, Compound BH1 used as a host has a benzene ring included in the core structure, which is unsubstituted with a carbazole group and a silyl group or an aryl group, so that it could be confirmed that the voltage, efficiency, and service life remarkably deteriorated compared to Examples 1 to 32.

In Comparative Example 4, Compound BH2 used as a host has a benzene ring included in the core structure, which is substituted with only a carbazole group, so that it could be confirmed that the voltage, efficiency, and service life remarkably deteriorated compared to Examples 1 to 32.

In Comparative Example 5, Compound BH3 used as a host has a benzene ring included in the core structure, which is substituted with only a carbazole group, and has a silyl group substituted with a carbazole group, so that it could be confirmed that the voltage, efficiency and service life remarkably deteriorated compared to Examples 1 to 32.

In Comparative Examples 6 and 7, Compound BH4 and Compound BH5 used as hosts have different core structures, so that it could be confirmed that the voltage, efficiency, and service life remarkably deteriorated compared to Examples 1 to 32.

What is claimed is:

1. An organic light emitting device comprising:
an anode;
a cathode; and
one or more organic material layers provided between the anode and the cathode,
wherein one or more layers of the organic material layer comprise a compound represented by the following Chemical Formula 1 and a compound represented by the following Chemical Formula 2: 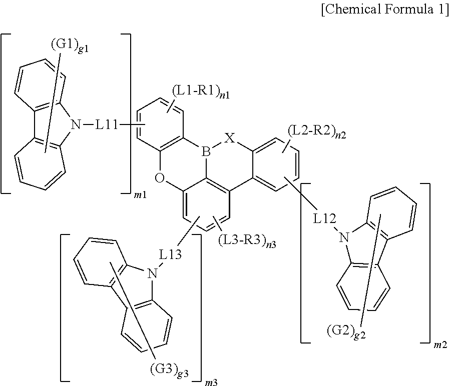
in Chemical Formula 1,
X is NR; O; or S,
at least one of R and R1 to R3 is a substituted or unsubstituted silyl group; a substituted or unsubstituted aryl group; or a substituted or unsubstituted heterocyclic group, and the other are the same as or different from each other, and are each independently hydrogen; deuterium; a halogen group; a nitrile group; a substituted or unsubstituted alkyl group; or a substituted or unsubstituted cycloalkyl group,
L1 to L3 and L11 to L13 are the same as or different from each other, and are each independently a direct bond; a substituted or unsubstituted arylene group; or a substituted or unsubstituted divalent heterocyclic group,
G1 to G3 are the same as or different from each other, and are each independently hydrogen; deuterium; a halogen group; a nitrile group; a substituted or unsubstituted silyl group; a substituted or unsubstituted alkyl group; a substituted or unsubstituted cycloalkyl group; a substituted or unsubstituted aryl group; or a substituted or unsubstituted heterocyclic group,
n1 and n2 are each an integer from 1 to 4, and m1 and m2 are each an integer from 0 to 4,
n3 is an integer from 1 to 3, and m3 is an integer from 0 to 3,
g1 to g3 are each an integer from 0 to 8,
when n1 to n3, m1 to m3 and g1 to g3 are each 2 or higher, substituents in the parenthesis are the same as or different from each other,
n1+m1 is 4 or less, n2+m2 is 4 or less, and n3+m3 is 3 or less, and
m1+m2+m3 is an integer of 1 or higher, 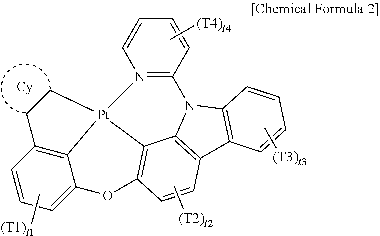
in Chemical Formula 2,
Cy is a substituted or unsubstituted N-containing monocyclic ring,
T1 to T4 are the same as or different from each other, and are each independently hydrogen; deuterium; a halogen group; a nitrile group; a substituted or unsubstituted silyl group; a substituted or unsubstituted alkyl group; a substituted or unsubstituted cycloalkyl group; a substituted or unsubstituted aryl group; or a substituted or unsubstituted heterocyclic group, or are bonded to an adjacent group to form a substituted or unsubstituted ring,
t1 and t4 are each an integer from 0 to 3,
t2 is an integer from 0 to 2,
t3 is an integer from 0 to 4,
when t1, t3, and t4 are each 2 or higher, substituents in the parenthesis are the same as or different from each other, and
when t2 is 2, substituents in the parenthesis are the same as or different from each other.

2. The organic light emitting device of claim 1, wherein L1 to L3 and L11 to L13 are the same as or different from each other, and are each independently a direct bond; an arylene group; or a divalent heterocyclic group.

3. The organic light emitting device of claim 1, wherein at least one of R1 to R3 is a silyl group unsubstituted or substituted with deuterium, an alkyl group or an aryl group; an aryl group unsubstituted or substituted with deuterium or an aryl group; or a heterocyclic group unsubstituted or substituted with deuterium or a heterocyclic group, and the others are the same as or different from each other, and are each independently hydrogen; or deuterium.

4. The organic light emitting device of claim 1, wherein m1+m2+m3 is 1 or 2.

5. The organic light emitting device of claim 1, wherein Chemical Formula 1 is represented by any one of the following Chemical Formulae 1-A-1 to 1-A-3: 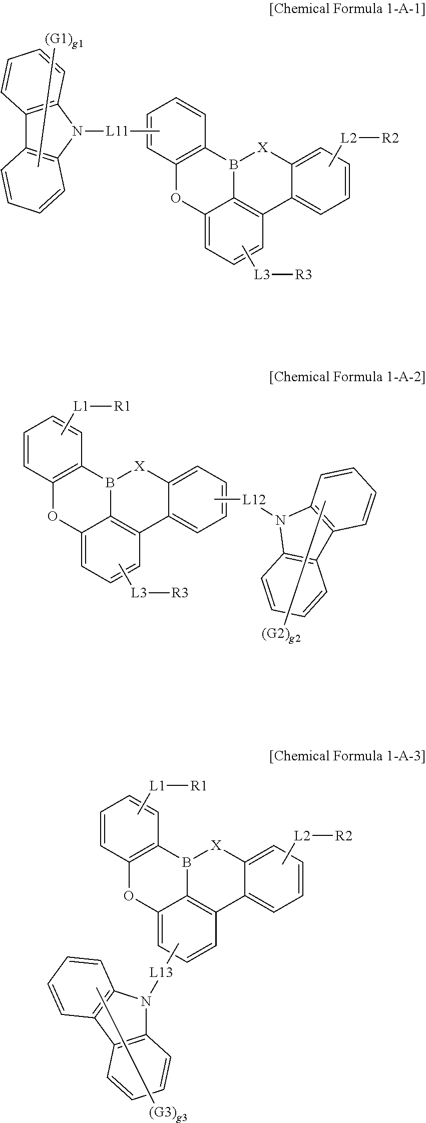
in Chemical Formulae 1-A-1 to 1-A-3,
the definitions of X, R1 to R3, L1 to L3, L11 to L13, G1 to G3, and g1 to g3 are the same as the definitions in Chemical Formula 1.

6. The organic light emitting device of claim 1, wherein Chemical Formula 1 is represented by any one of the following Chemical Formulae 1-B-1 to 1-B-3: 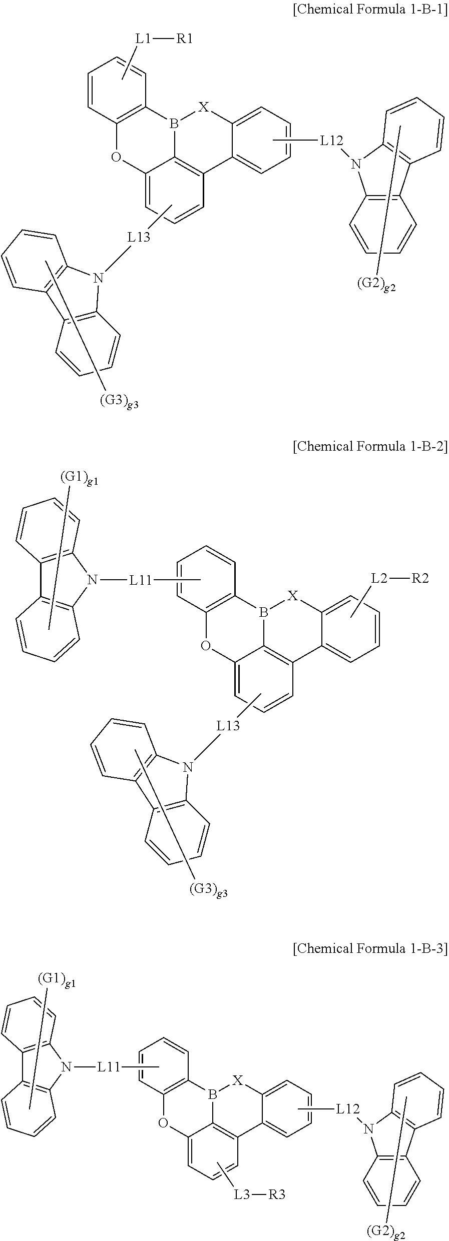
in Chemical Formulae 1-B-1 to 1-B-3,
the definitions of X, R1 to R3, L1 to L3, L11 to L13, G1 to G3, and g1 to g3 are the same as the definitions in Chemical Formula 1.

7. The organic light emitting device of claim 1, wherein at least one of R1 to R3 is a triphenylsilyl group; a phenyl group; a biphenyl group; a carbazole group; a dibenzofuran group; a dibenzothiophene group; a benzofurano dibenzofuran group; or an indolocarbazole group, and the others are the same as or different from each other, and are each independently hydrogen; or deuterium,
L1 to L3 and L11 to L13 are the same as or different from each other, and are each independently a direct bond; or a phenylene group, and
G1 to G3 are the same as or different from each other, and are each independently hydrogen; or deuterium.

8. The organic light emitting device of claim 1, wherein Chemical Formula 2 is represented by any one of the following Chemical Formulae 2-A-1 to 2-A-3: 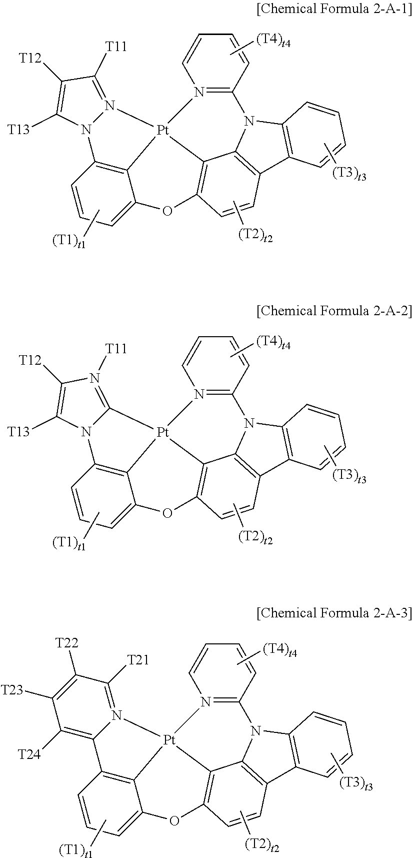
in Chemical Formulae 2-A-1 to 2-A-3,
the definitions of T1 to T4 and t1 to t4 are the same as the definitions in Chemical Formula 2, and
T11 to T13 and T21 to T24 are the same as or different from each other, and are each independently hydrogen; deuterium; a halogen group; a nitrile group; a substituted or unsubstituted silyl group; a substituted or unsubstituted alkyl group; a substituted or unsubstituted cycloalkyl group; a substituted or unsubstituted aryl group; or a substituted or unsubstituted heterocyclic group, or are bonded to an adjacent group to form a substituted or unsubstituted ring.

9. The organic light emitting device of claim 1, wherein T1 to T4 are the same as or different from each other, and are each independently hydrogen; deuterium; a substituted or unsubstituted alkyl group; or a substituted or unsubstituted aryl group, or are bonded to an adjacent group to form a dibenzofuran ring; or a dibenzothiophene ring.

10. The organic light emitting device of claim 8, wherein T11 to T13 and T21 to T24 are the same as or different from each other, and are each independently hydrogen; deuterium; a substituted or unsubstituted phenyl group; a substituted or unsubstituted biphenyl group; or a substituted or unsubstituted terphenyl group.

11. The organic light emitting device of claim 1, wherein Chemical Formula 1 is represented by any one of the 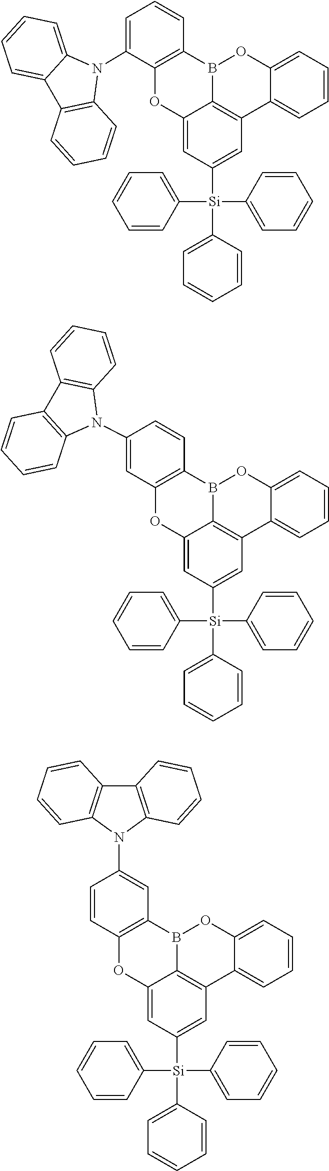 [SMILES: c1ccc([Si](c2ccccc2)(c2ccccc2)c2cc3c4c(c2)-c2ccccc2OB4c2cccc(-n4c5ccccc5c5ccccc54)c2O3)cc1 ; c1ccc([Si](c2ccccc2)(c2ccccc2)c2cc3c4c(c2)-c2ccccc2OB4c2ccc(-n4c5ccccc5c5ccccc54)cc2O3)cc1 ; c1ccc([Si](c2ccccc2)(c2ccccc2)c2cc3c4c(c2)-c2ccccc2OB4c2cc(-n4c5ccccc5c5ccccc54)ccc2O3)cc1] 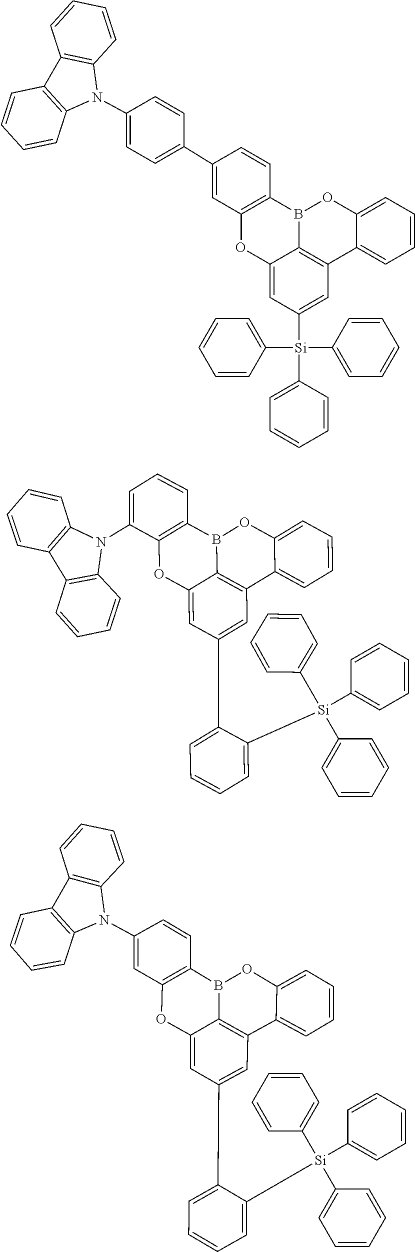 [SMILES: c1ccc([Si](c2ccccc2)(c2ccccc2)c2cc3c4c(c2)-c2ccccc2OB4c2ccc(-c4ccc(-n5c6ccccc6c6ccccc65)cc4)cc2O3)cc1 ; c1ccc([Si](c2ccccc2)(c2ccccc2)c2ccccc2-c2cc3c4c(c2)-c2ccccc2OB4c2cccc(-n4c5ccccc5c5ccccc54)c2O3)cc1 ; c1ccc([Si](c2ccccc2)(c2ccccc2)c2ccccc2-c2cc3c4c(c2)-c2ccccc2OB4c2ccc(-n4c5ccccc5c5ccccc54)cc2O3)cc1] 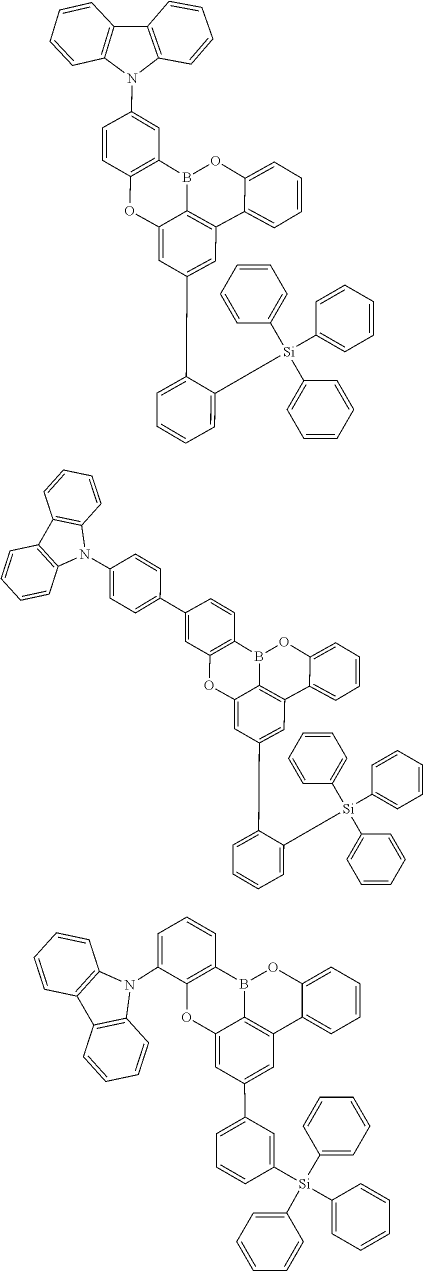 [SMILES: c1ccc([Si](c2ccccc2)(c2ccccc2)c2ccccc2-c2cc3c4c(c2)-c2ccccc2OB4c2cc(-n4c5ccccc5c5ccccc54)ccc2O3)cc1 ; c1ccc([Si](c2ccccc2)(c2ccccc2)c2ccccc2-c2cc3c4c(c2)-c2ccccc2OB4c2ccc(-c4ccc(-n5c6ccccc6c6ccccc65)cc4)cc2O3)cc1 ; c1ccc([Si](c2ccccc2)(c2ccccc2)c2cccc(-c3cc4c5c(c3)-c3ccccc3OB5c3cccc(-n5c6ccccc6c6ccccc65)c3O4)c2)cc1] 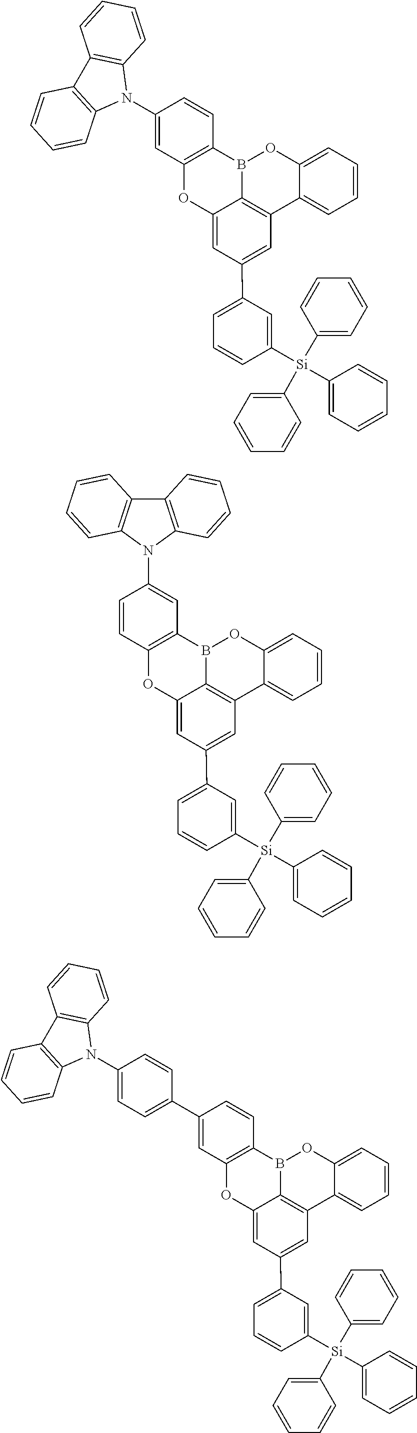 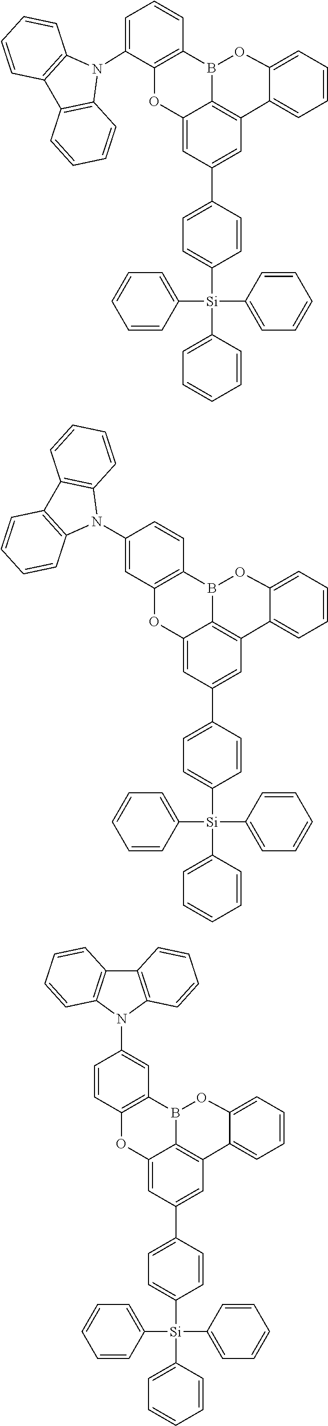 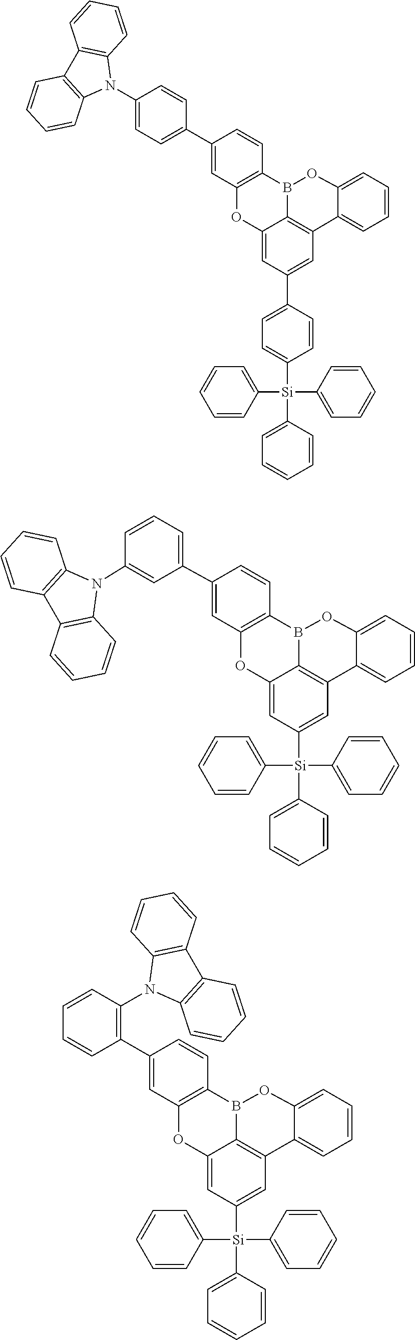 [SMILES: c1ccc([Si](c2ccccc2)(c2ccccc2)c2ccc(-c3cc4c5c(c3)-c3ccccc3OB5c3ccc(-c5ccc(-n6c7ccccc7c7ccccc76)cc5)cc3O4)cc2)cc1 ; c1ccc([Si](c2ccccc2)(c2ccccc2)c2cc3c4c(c2)-c2ccccc2OB4c2ccc(-c4cccc(-n5c6ccccc6c6ccccc65)c4)cc2O3)cc1 ; c1ccc([Si](c2ccccc2)(c2ccccc2)c2cc3c4c(c2)-c2ccccc2OB4c2ccc(-c4ccccc4-n4c5ccccc5c5ccccc54)cc2O3)cc1] 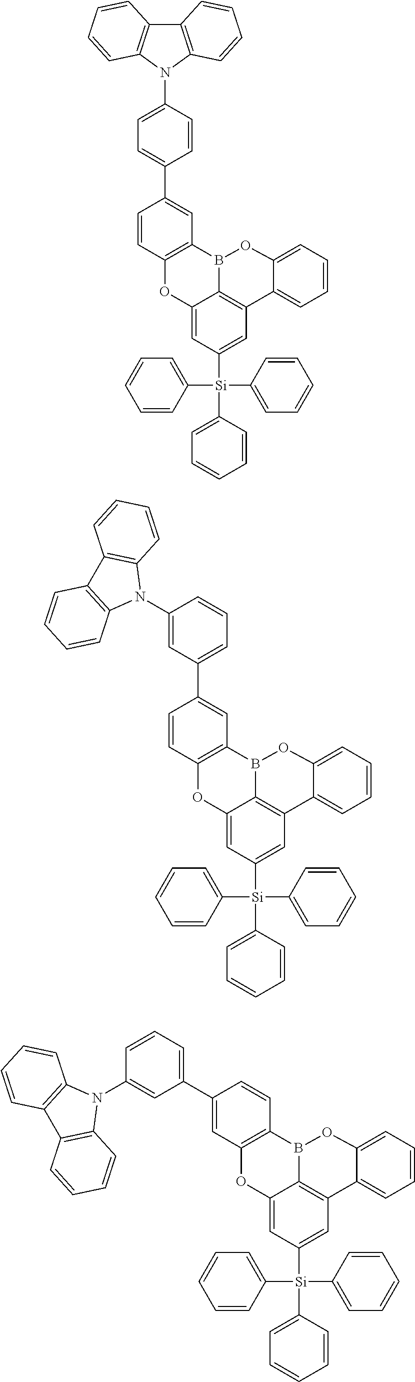 [SMILES: c1ccc([Si](c2ccccc2)(c2ccccc2)c2cc3c4c(c2)-c2ccccc2OB4c2cc(-c4ccc(-n5c6ccccc6c6ccccc65)cc4)ccc2O3)cc1 ; c1ccc([Si](c2ccccc2)(c2ccccc2)c2cc3c4c(c2)-c2ccccc2OB4c2cc(-c4cccc(-n5c6ccccc6c6ccccc65)c4)ccc2O3)cc1 ; c1ccc([Si](c2ccccc2)(c2ccccc2)c2cc3c4c(c2)-c2ccccc2OB4c2ccc(-c4cccc(-n5c6ccccc6c6ccccc65)c4)cc2O3)cc1] 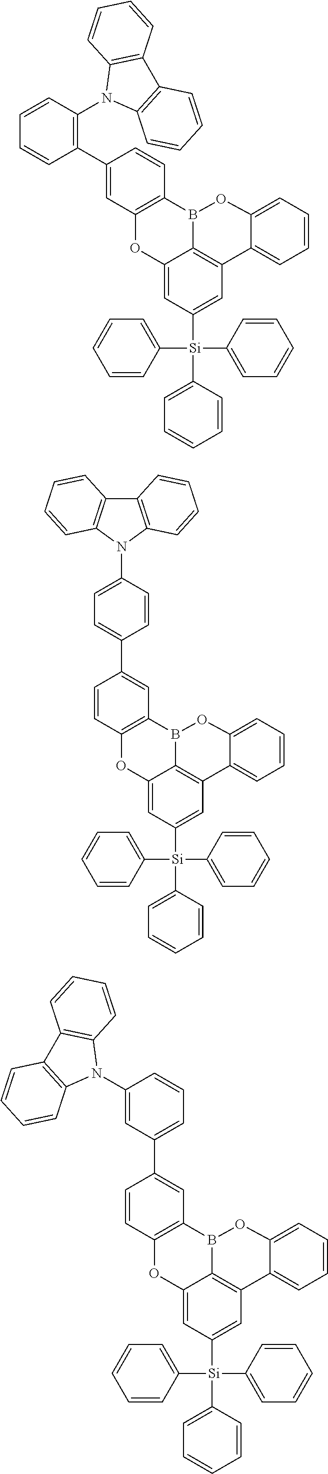 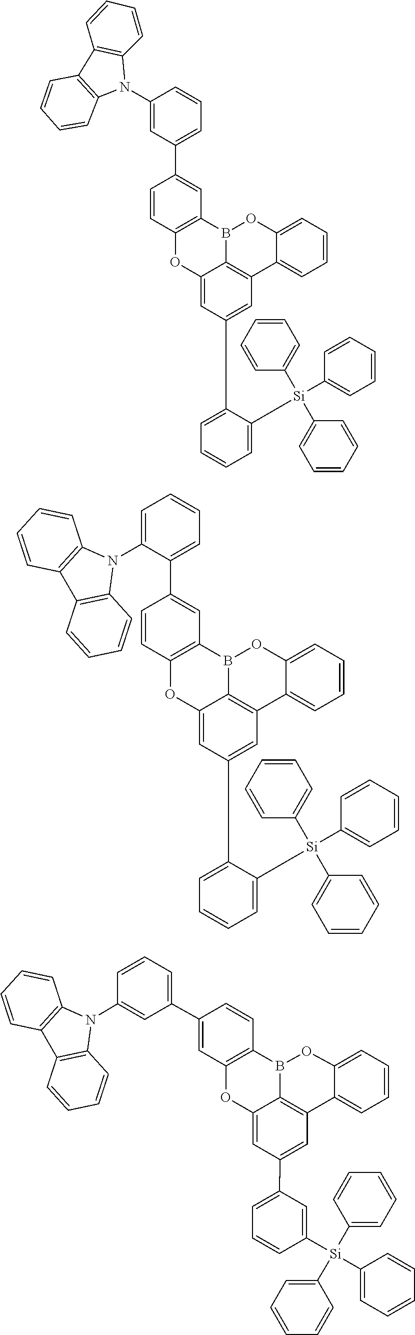 [SMILES: c1ccc([Si](c2ccccc2)(c2ccccc2)c2ccccc2-c2cc3c4c(c2)-c2ccccc2OB4c2cc(-c4cccc(-n5c6ccccc6c6ccccc65)c4)ccc2O3)cc1 ; c1ccc([Si](c2ccccc2)(c2ccccc2)c2ccccc2-c2cc3c4c(c2)-c2ccccc2OB4c2cc(-c4ccccc4-n4c5ccccc5c5ccccc54)ccc2O3)cc1 ; c1ccc([Si](c2ccccc2)(c2ccccc2)c2cccc(-c3cc4c5c(c3)-c3ccccc3OB5c3ccc(-c5cccc(-n6c7ccccc7c7ccccc76)c5)cc3O4)c2)cc1] 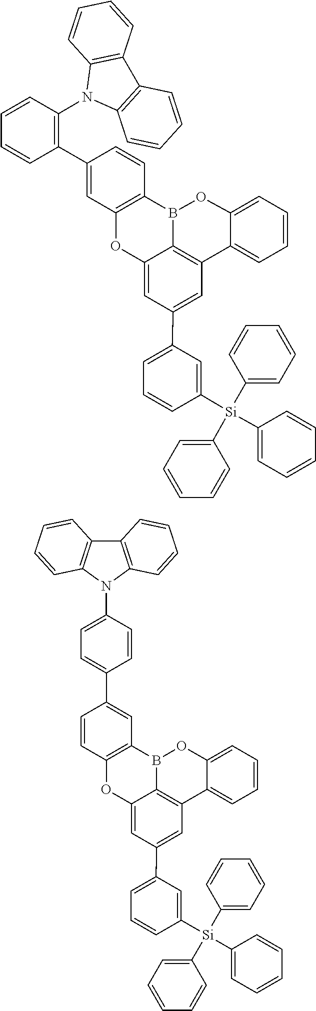 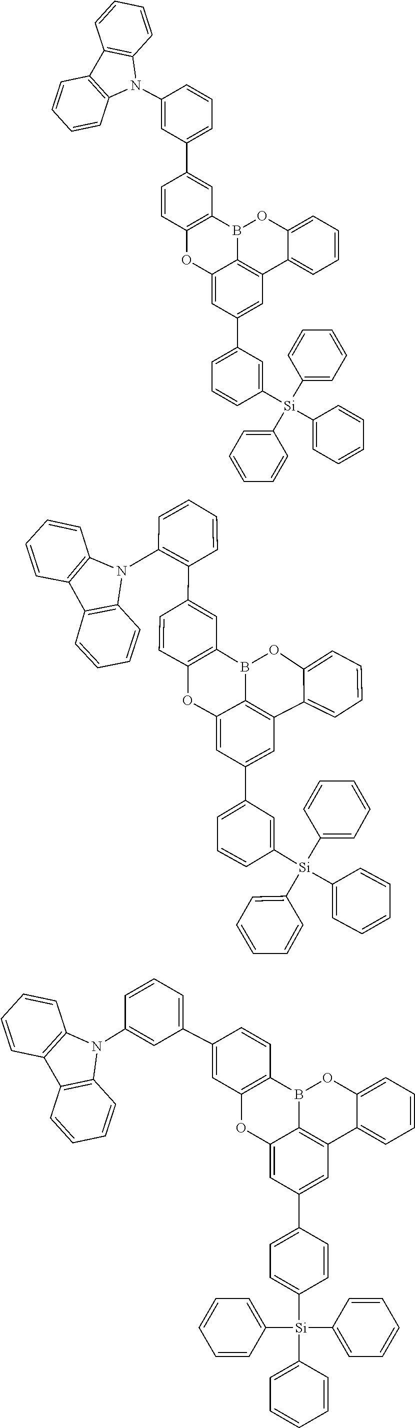 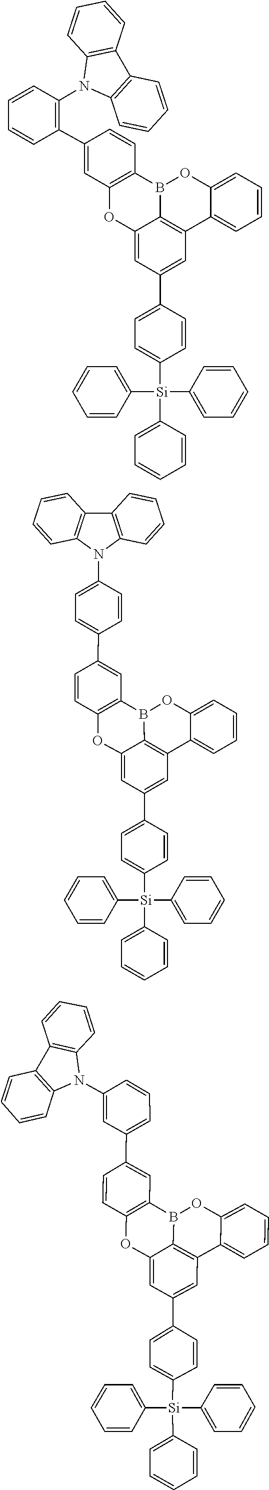 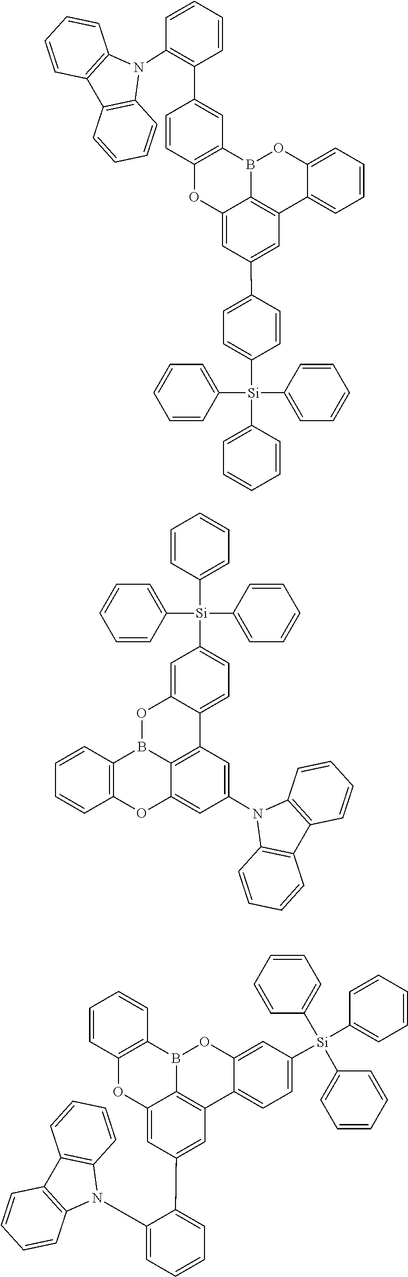 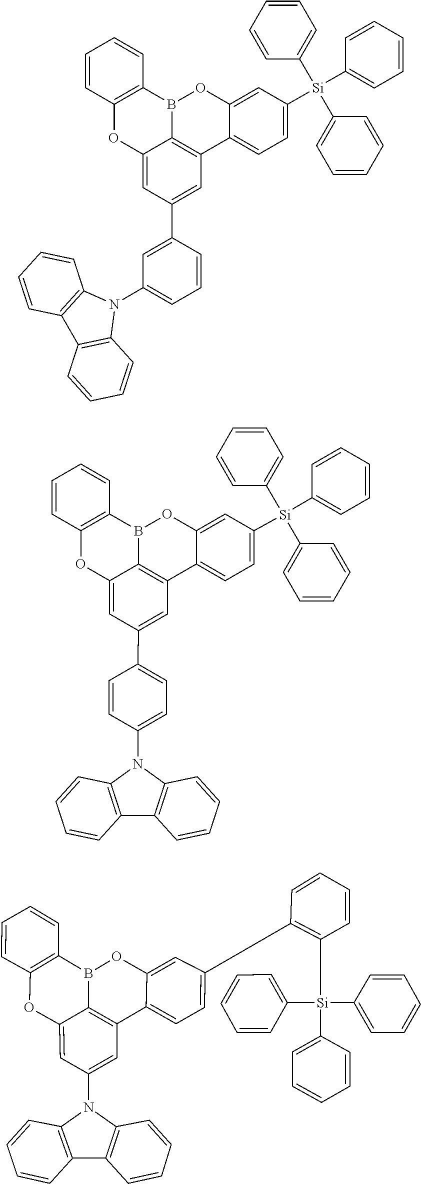 [SMILES: c1ccc([Si](c2ccccc2)(c2ccccc2)c2ccc3c(c2)OB2c4ccccc4Oc4cc(-c5cccc(-n6c7ccccc7c7ccccc76)c5)cc-3c42)cc1 ; c1ccc([Si](c2ccccc2)(c2ccccc2)c2ccc3c(c2)OB2c4ccccc4Oc4cc(-c5ccc(-n6c7ccccc7c7ccccc76)cc5)cc-3c42)cc1 ; c1ccc([Si](c2ccccc2)(c2ccccc2)c2ccccc2-c2ccc3c(c2)OB2c4ccccc4Oc4cc(-n5c6ccccc6c6ccccc65)cc-3c42)cc1] 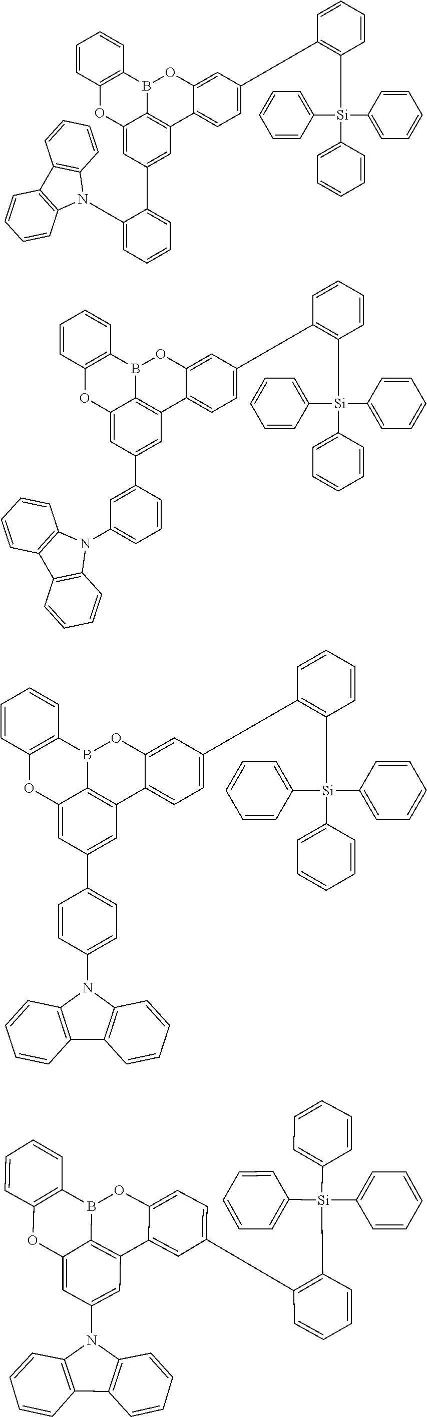 [SMILES: c1ccc([Si](c2ccccc2)(c2ccccc2)c2ccccc2-c2ccc3c(c2)OB2c4ccccc4Oc4cc(-c5ccccc5-n5c6ccccc6c6ccccc65)cc-3c42)cc1 ; c1ccc([Si](c2ccccc2)(c2ccccc2)c2ccccc2-c2ccc3c(c2)OB2c4ccccc4Oc4cc(-c5cccc(-n6c7ccccc7c7ccccc76)c5)cc-3c42)cc1 ; c1ccc([Si](c2ccccc2)(c2ccccc2)c2ccccc2-c2ccc3c(c2)OB2c4ccccc4Oc4cc(-c5ccc(-n6c7ccccc7c7ccccc76)cc5)cc-3c42)cc1 ; c1ccc([Si](c2ccccc2)(c2ccccc2)c2ccccc2-c2ccc3c(c2)-c2cc(-n4c5ccccc5c5ccccc54)cc4c2B(O3)c2ccccc2O4)cc1] 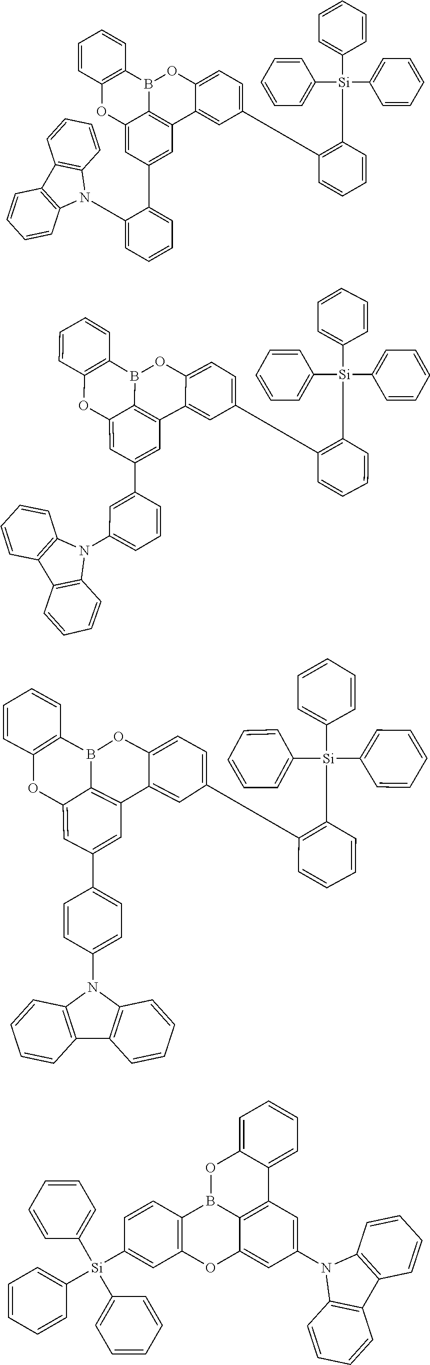 [SMILES: c1ccc([Si](c2ccccc2)(c2ccccc2)c2ccccc2-c2ccc3c(c2)-c2cc(-c4ccccc4-n4c5ccccc5c5ccccc54)cc4c2B(O3)c2ccccc2O4)cc1 ; c1ccc([Si](c2ccccc2)(c2ccccc2)c2ccccc2-c2ccc3c(c2)-c2cc(-c4cccc(-n5c6ccccc6c6ccccc65)c4)cc4c2B(O3)c2ccccc2O4)cc1 ; c1ccc([Si](c2ccccc2)(c2ccccc2)c2ccccc2-c2ccc3c(c2)-c2cc(-c4ccc(-n5c6ccccc6c6ccccc65)cc4)cc4c2B(O3)c2ccccc2O4)cc1 ; c1ccc([Si](c2ccccc2)(c2ccccc2)c2ccc3c(c2)Oc2cc(-n4c5ccccc5c5ccccc54)cc4c2B3Oc2ccccc2-4)cc1] 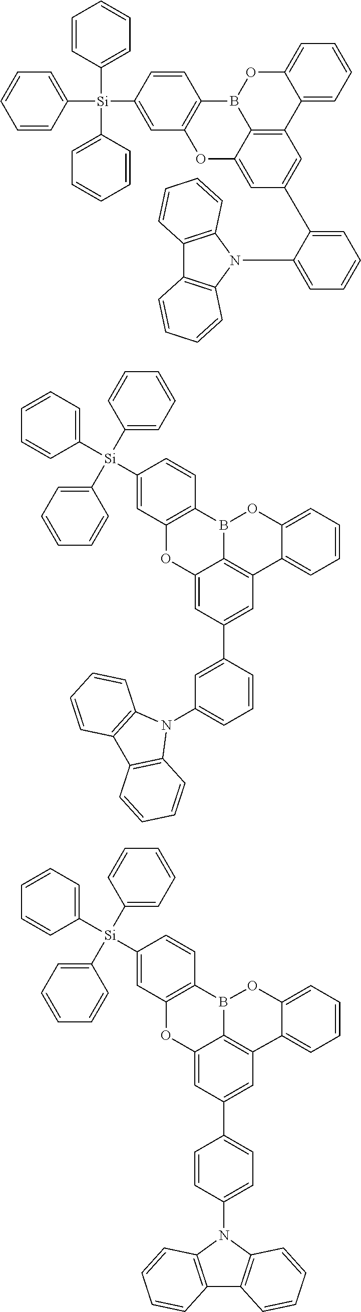 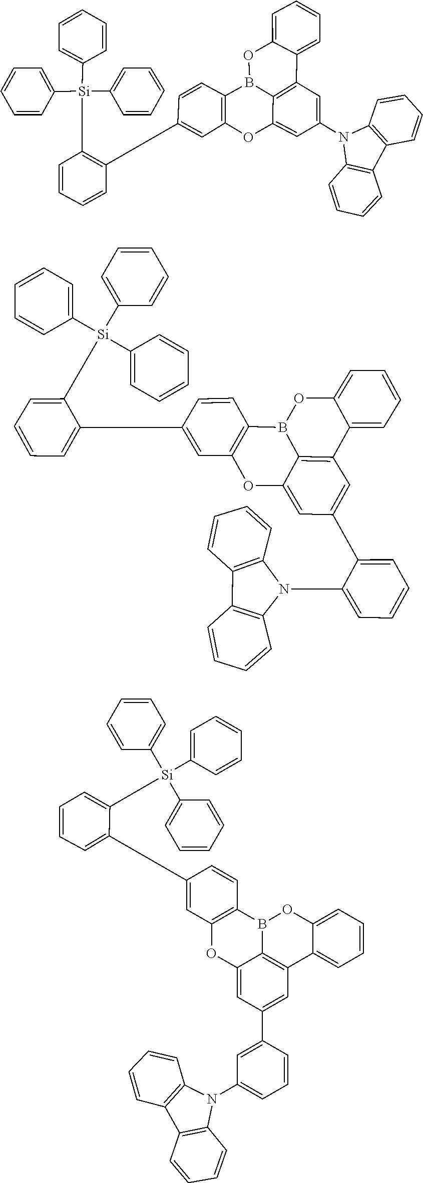 [SMILES: c1ccc([Si](c2ccccc2)(c2ccccc2)c2ccccc2-c2ccc3c(c2)Oc2cc(-n4c5ccccc5c5ccccc54)cc4c2B3Oc2ccccc2-4)cc1 ; c1ccc([Si](c2ccccc2)(c2ccccc2)c2ccccc2-c2ccc3c(c2)Oc2cc(-c4ccccc4-n4c5ccccc5c5ccccc54)cc4c2B3Oc2ccccc2-4)cc1 ; c1ccc([Si](c2ccccc2)(c2ccccc2)c2ccccc2-c2ccc3c(c2)Oc2cc(-c4cccc(-n5c6ccccc6c6ccccc65)c4)cc4c2B3Oc2ccccc2-4)cc1] 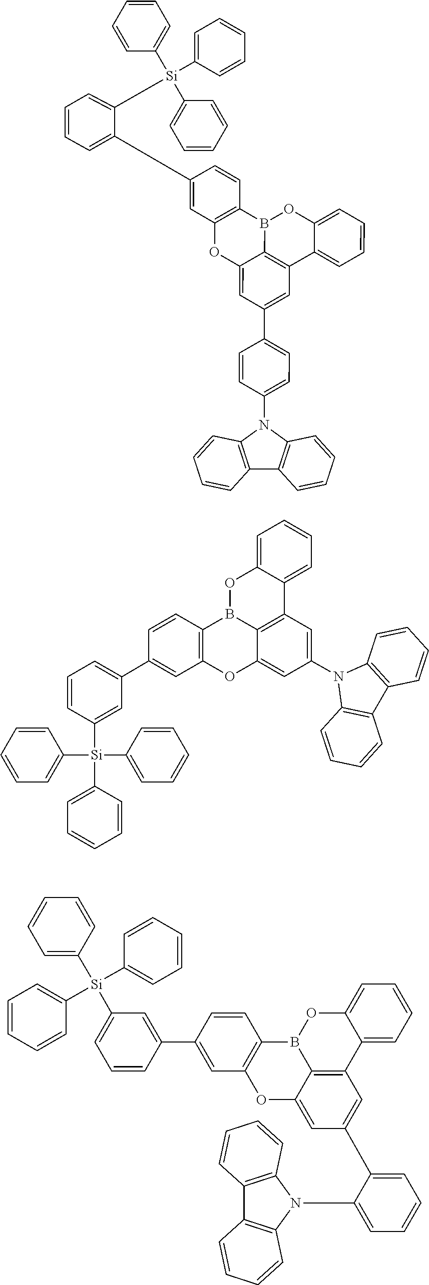 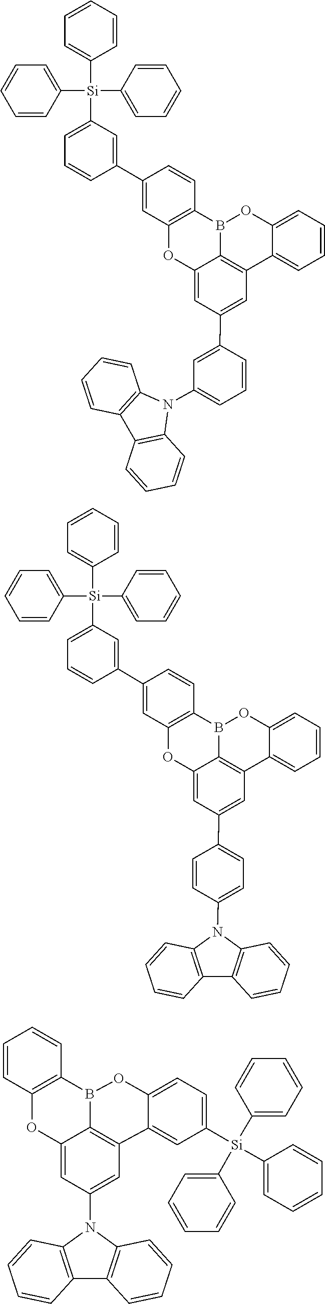 [SMILES: c1ccc([Si](c2ccccc2)(c2ccccc2)c2cccc(-c3ccc4c(c3)Oc3cc(-c5cccc(-n6c7ccccc7c7ccccc76)c5)cc5c3B4Oc3ccccc3-5)c2)cc1 ; c1ccc([Si](c2ccccc2)(c2ccccc2)c2cccc(-c3ccc4c(c3)Oc3cc(-c5ccc(-n6c7ccccc7c7ccccc76)cc5)cc5c3B4Oc3ccccc3-5)c2)cc1 ; c1ccc([Si](c2ccccc2)(c2ccccc2)c2ccc3c(c2)-c2cc(-n4c5ccccc5c5ccccc54)cc4c2B(O3)c2ccccc2O4)cc1] 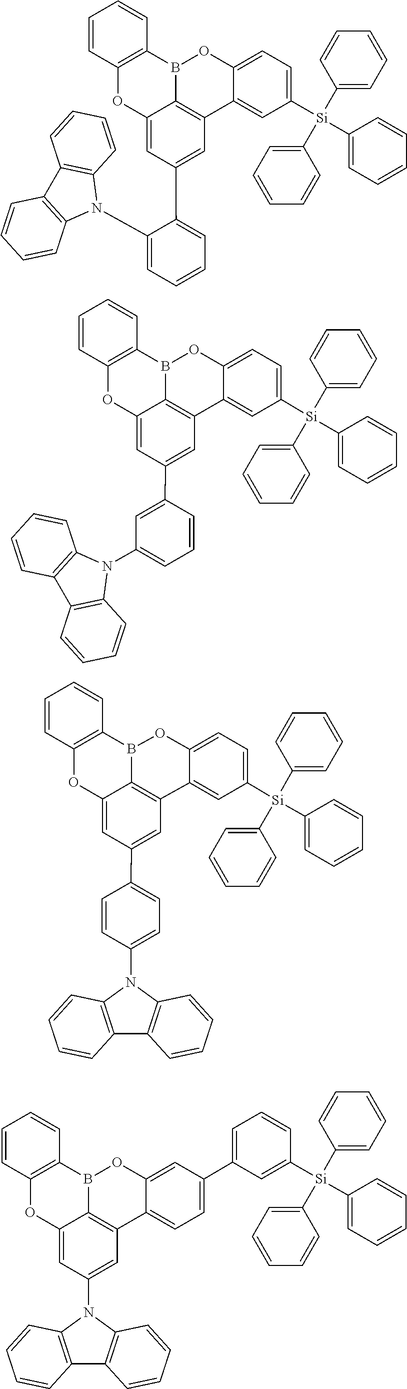 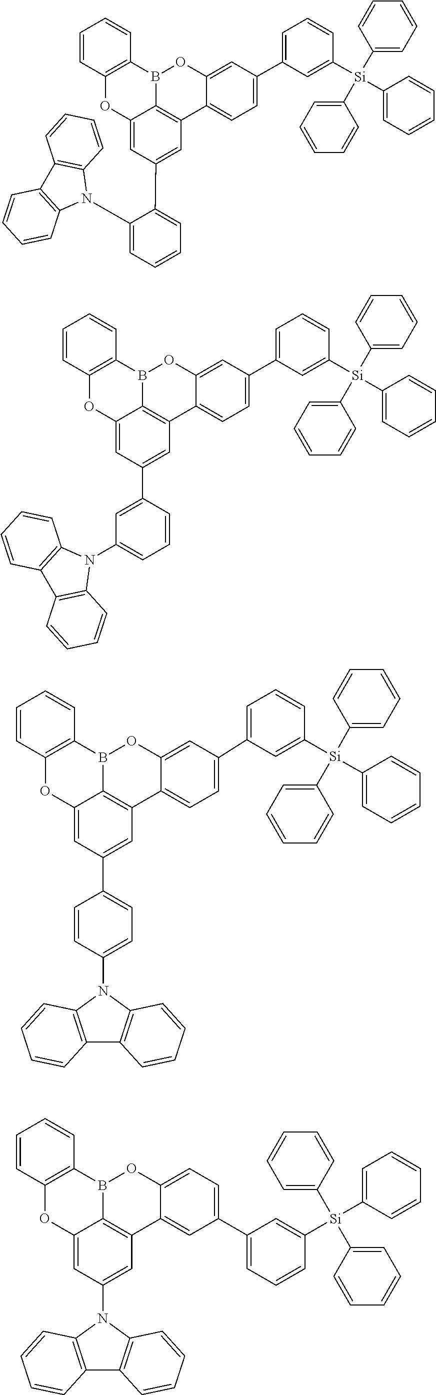 [SMILES: c1ccc([Si](c2ccccc2)(c2ccccc2)c2cccc(-c3ccc4c(c3)OB3c5ccccc5Oc5cc(-c6ccccc6-n6c7ccccc7c7ccccc76)cc-4c53)c2)cc1 ; c1ccc([Si](c2ccccc2)(c2ccccc2)c2cccc(-c3ccc4c(c3)OB3c5ccccc5Oc5cc(-c6cccc(-n7c8ccccc8c8ccccc87)c6)cc-4c53)c2)cc1 ; c1ccc([Si](c2ccccc2)(c2ccccc2)c2cccc(-c3ccc4c(c3)OB3c5ccccc5Oc5cc(-c6ccc(-n7c8ccccc8c8ccccc87)cc6)cc-4c53)c2)cc1 ; c1ccc([Si](c2ccccc2)(c2ccccc2)c2cccc(-c3ccc4c(c3)-c3cc(-n5c6ccccc6c6ccccc65)cc5c3B(O4)c3ccccc3O5)c2)cc1] 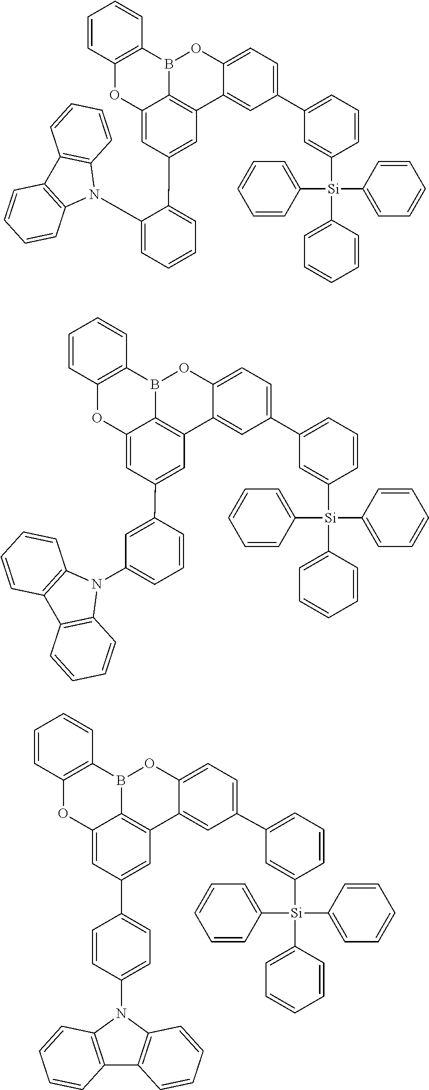 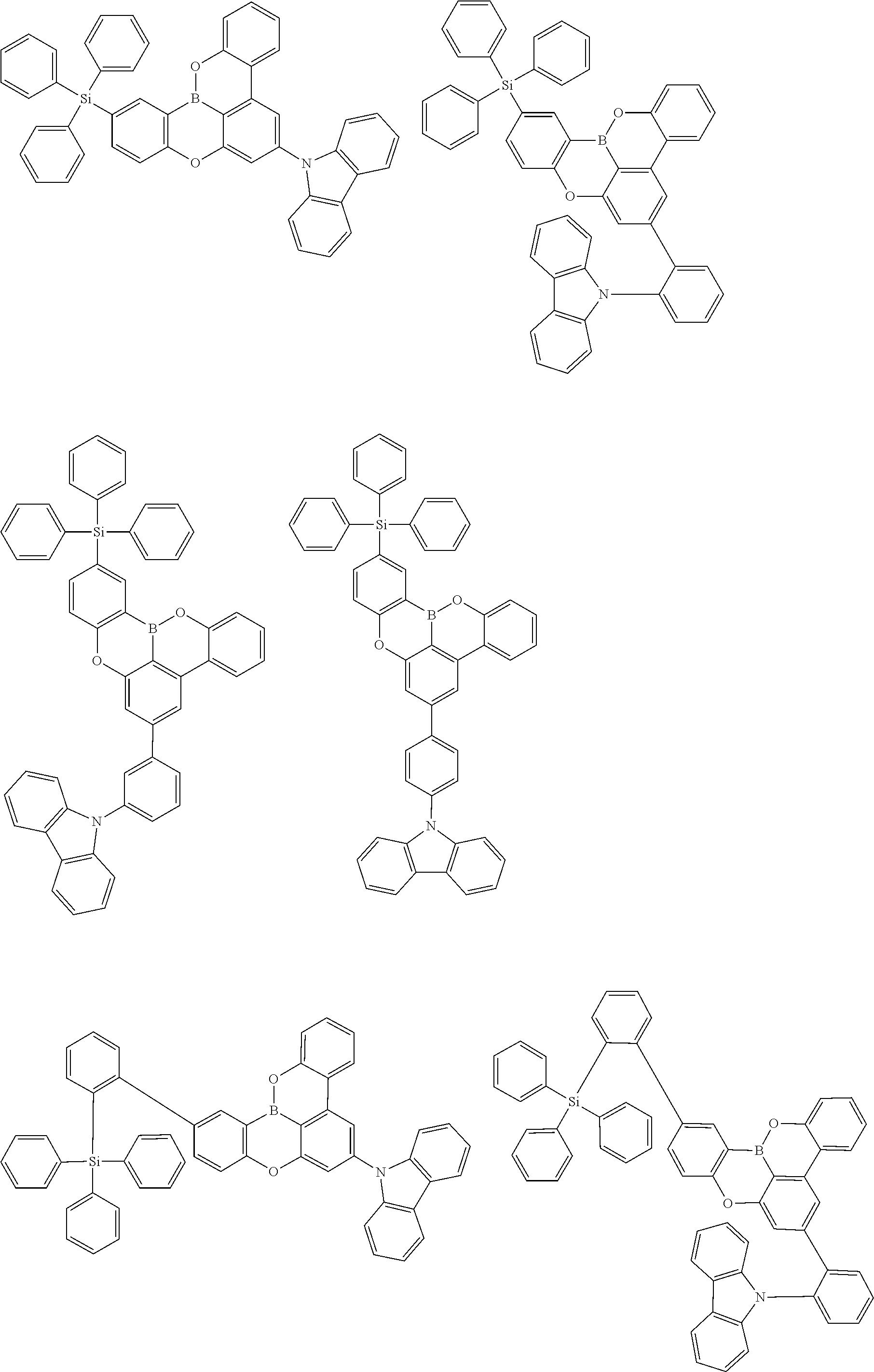 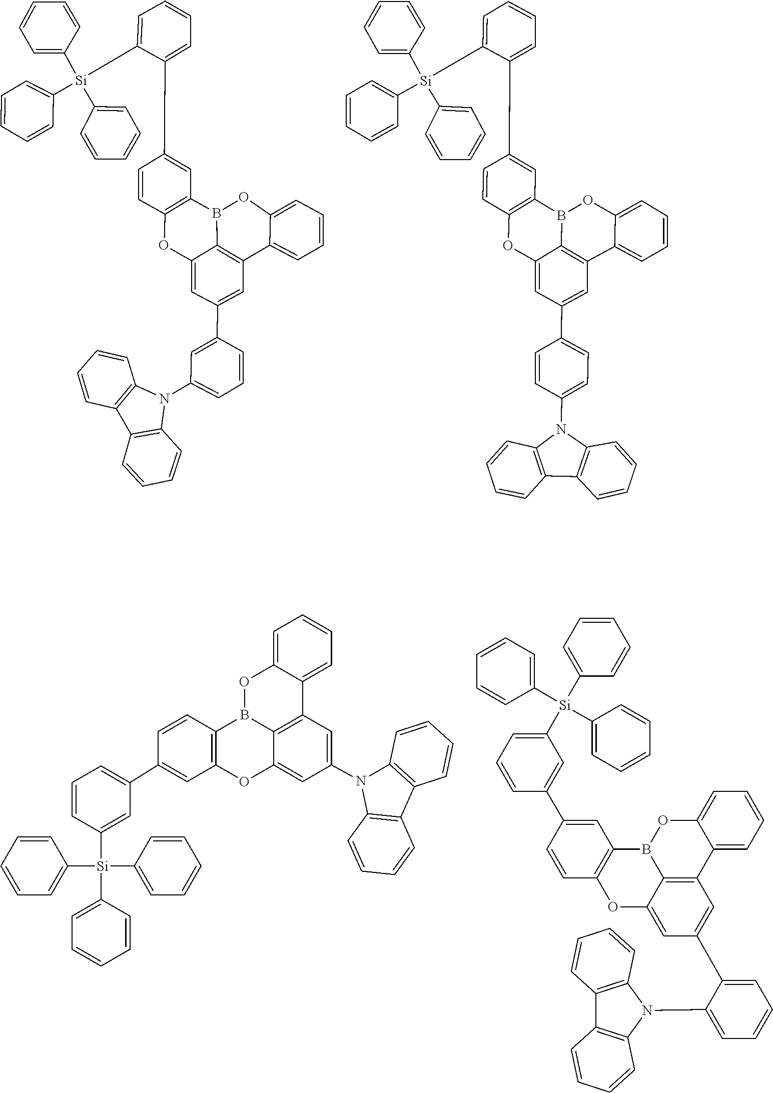 [SMILES: c1ccc([Si](c2ccccc2)(c2ccccc2)c2ccccc2-c2ccc3c(c2)B2Oc4ccccc4-c4cc(-c5cccc(-n6c7ccccc7c7ccccc76)c5)cc(c42)O3)cc1 ; c1ccc([Si](c2ccccc2)(c2ccccc2)c2ccccc2-c2ccc3c(c2)B2Oc4ccccc4-c4cc(-c5ccc(-n6c7ccccc7c7ccccc76)cc5)cc(c42)O3)cc1 ; c1ccc([Si](c2ccccc2)(c2ccccc2)c2cccc(-c3ccc4c(c3)Oc3cc(-n5c6ccccc6c6ccccc65)cc5c3B4Oc3ccccc3-5)c2)cc1 ; c1ccc([Si](c2ccccc2)(c2ccccc2)c2cccc(-c3ccc4c(c3)B3Oc5ccccc5-c5cc(-c6ccccc6-n6c7ccccc7c7ccccc76)cc(c53)O4)c2)cc1] 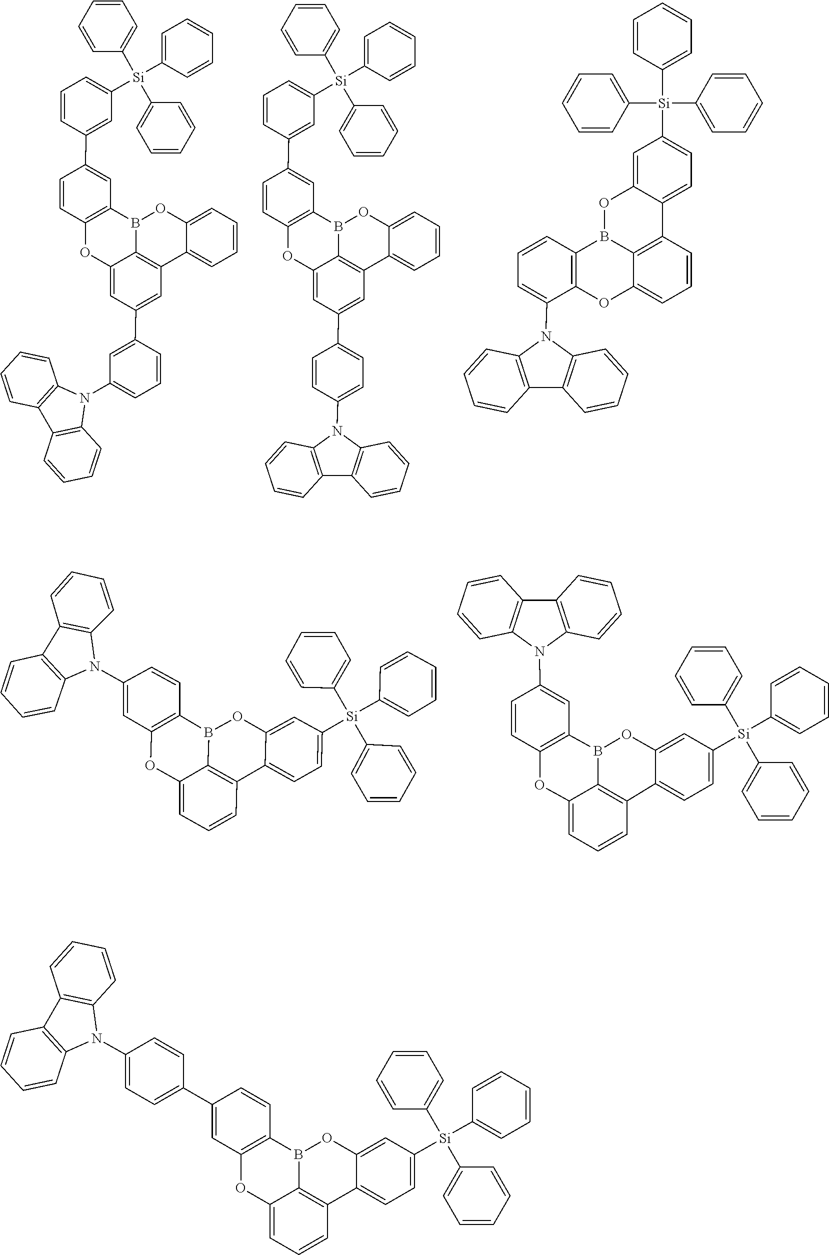 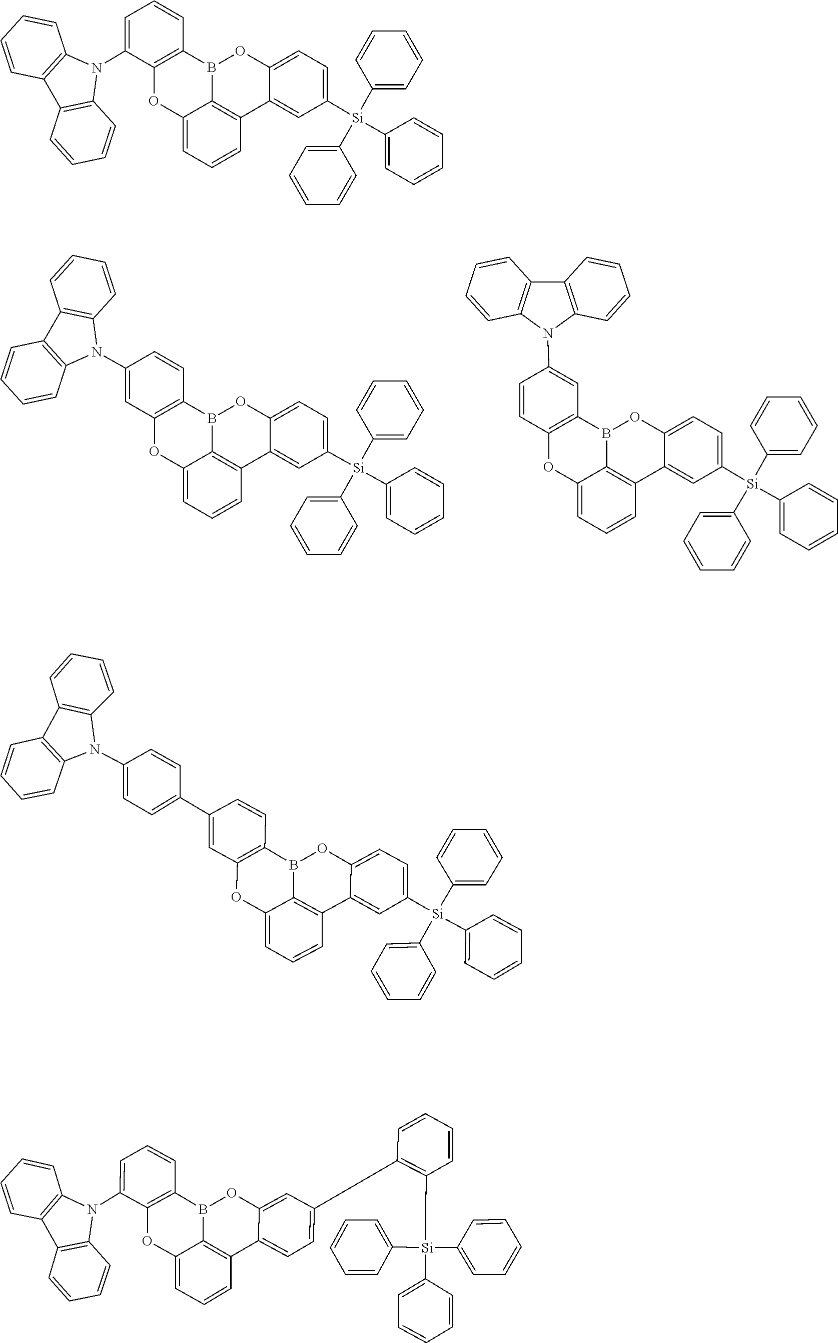 [SMILES: c1ccc([Si](c2ccccc2)(c2ccccc2)c2ccc3c(c2)-c2cccc4c2B(O3)c2cccc(-n3c5ccccc5c5ccccc53)c2O4)cc1 ; c1ccc([Si](c2ccccc2)(c2ccccc2)c2ccc3c(c2)-c2cccc4c2B(O3)c2ccc(-n3c5ccccc5c5ccccc53)cc2O4)cc1 ; c1ccc([Si](c2ccccc2)(c2ccccc2)c2ccc3c(c2)-c2cccc4c2B(O3)c2cc(-n3c5ccccc5c5ccccc53)ccc2O4)cc1 ; c1ccc([Si](c2ccccc2)(c2ccccc2)c2ccc3c(c2)-c2cccc4c2B(O3)c2ccc(-c3ccc(-n5c6ccccc6c6ccccc65)cc3)cc2O4)cc1 ; c1ccc([Si](c2ccccc2)(c2ccccc2)c2ccccc2-c2ccc3c(c2)OB2c4cccc(-n5c6ccccc6c6ccccc65)c4Oc4cccc-3c42)cc1] 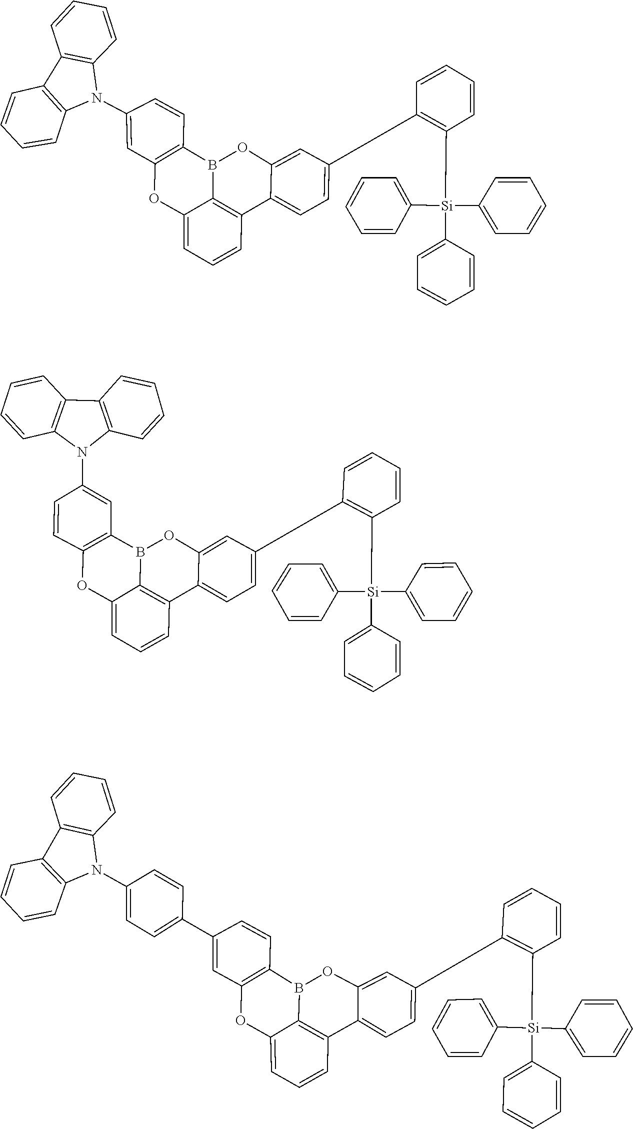 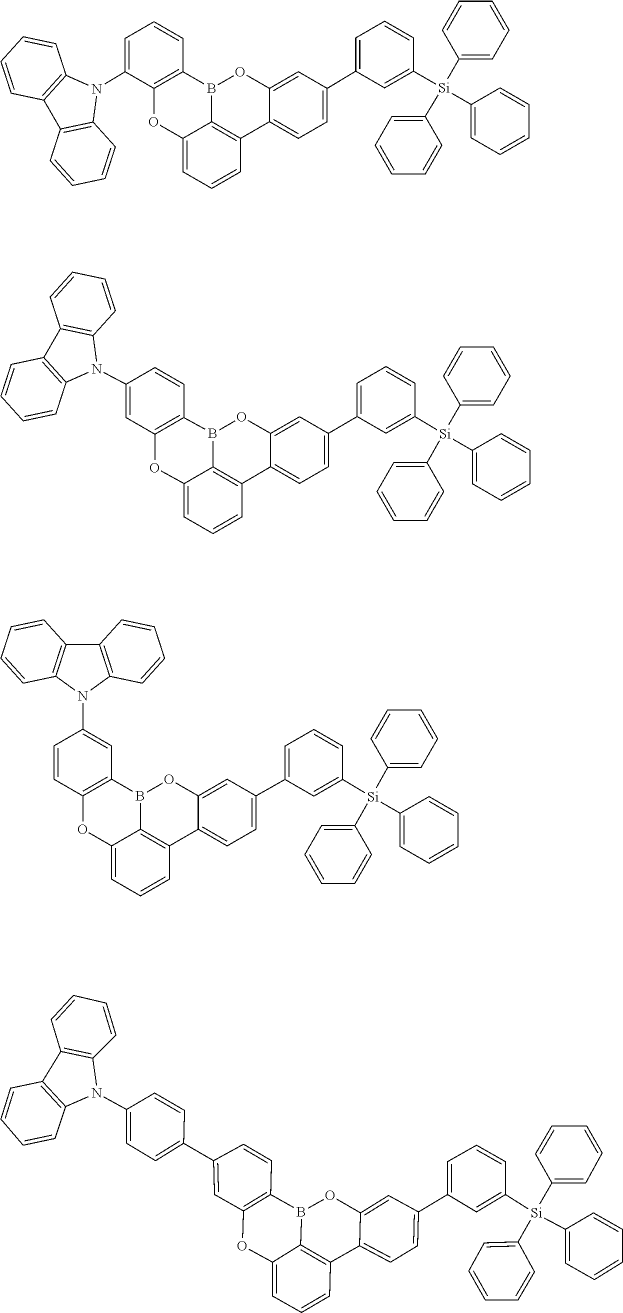 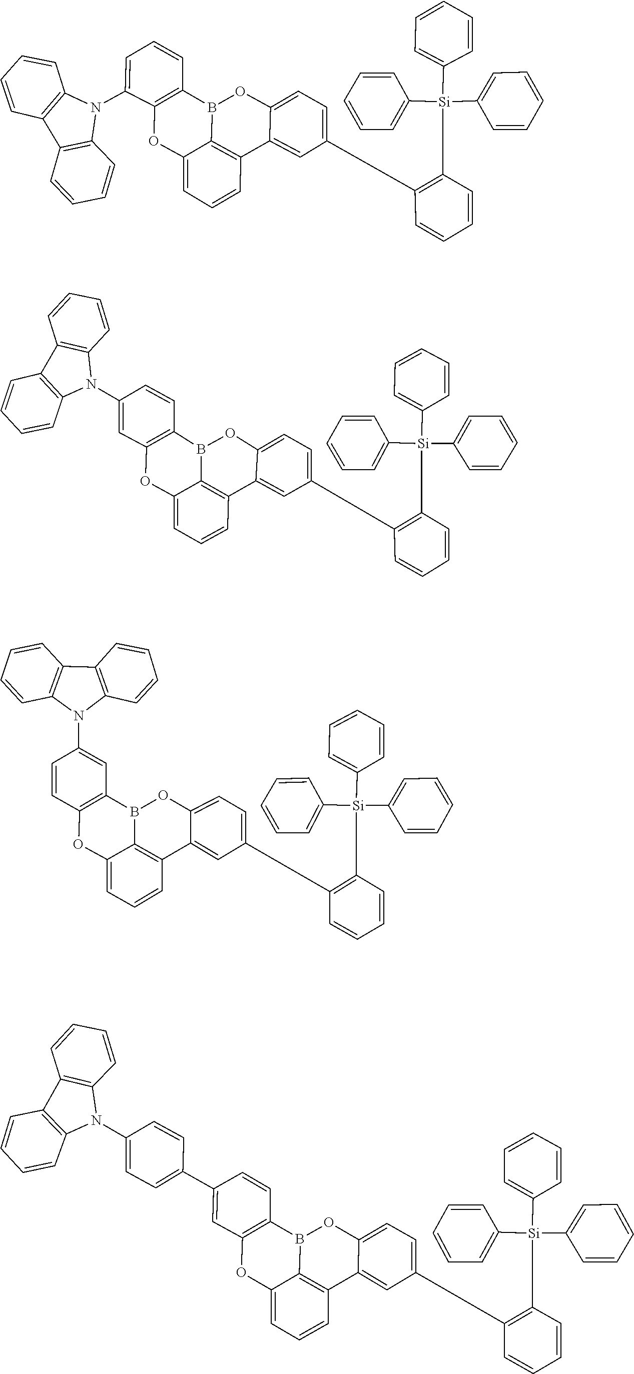 [SMILES: c1ccc([Si](c2ccccc2)(c2ccccc2)c2ccccc2-c2ccc3c(c2)-c2cccc4c2B(O3)c2cccc(-n3c5ccccc5c5ccccc53)c2O4)cc1 ; c1ccc([Si](c2ccccc2)(c2ccccc2)c2ccccc2-c2ccc3c(c2)-c2cccc4c2B(O3)c2ccc(-n3c5ccccc5c5ccccc53)cc2O4)cc1 ; c1ccc([Si](c2ccccc2)(c2ccccc2)c2ccccc2-c2ccc3c(c2)-c2cccc4c2B(O3)c2cc(-n3c5ccccc5c5ccccc53)ccc2O4)cc1 ; c1ccc([Si](c2ccccc2)(c2ccccc2)c2ccccc2-c2ccc3c(c2)-c2cccc4c2B(O3)c2ccc(-c3ccc(-n5c6ccccc6c6ccccc65)cc3)cc2O4)cc1] 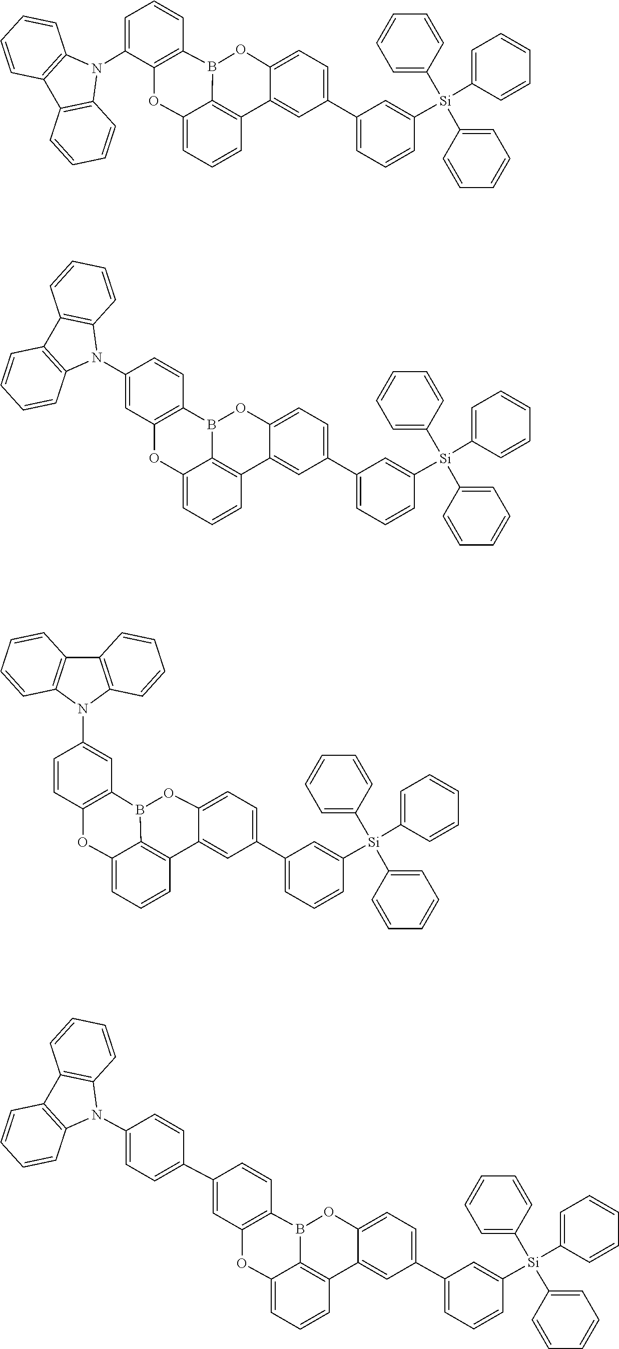 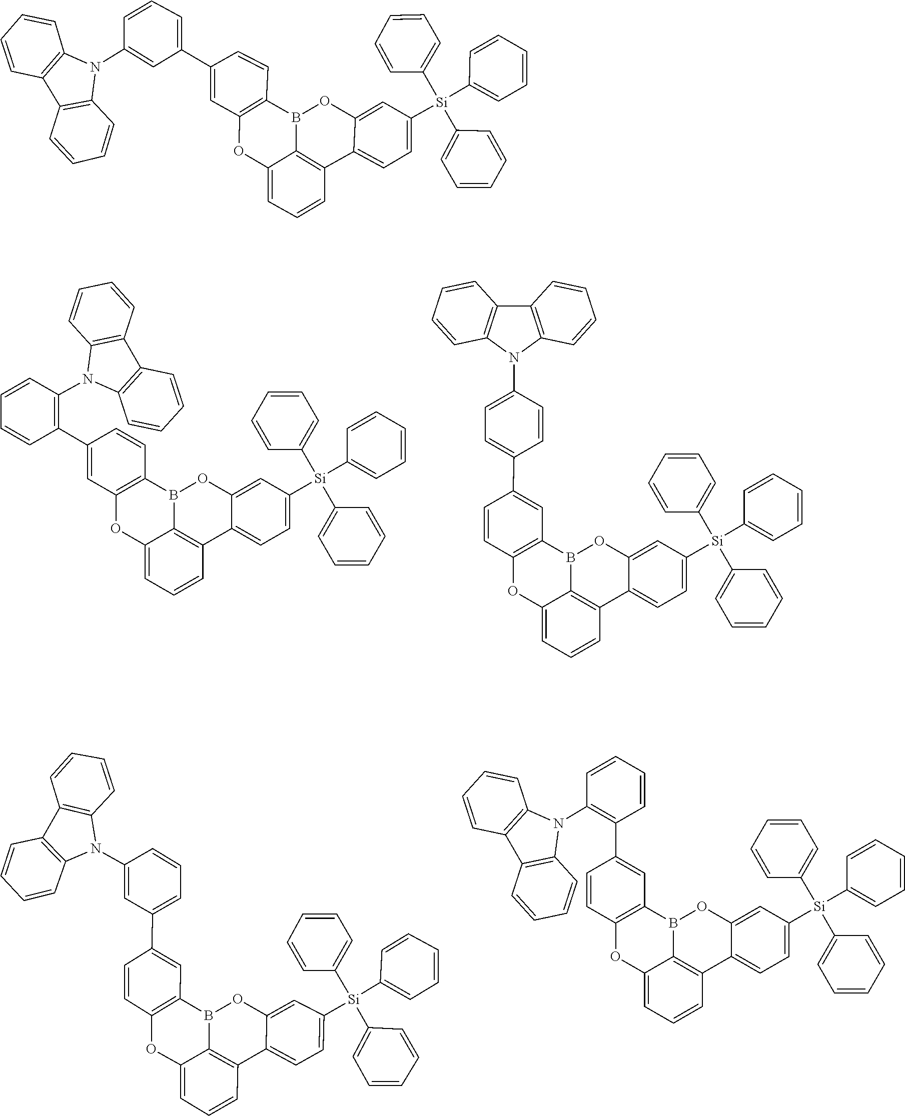 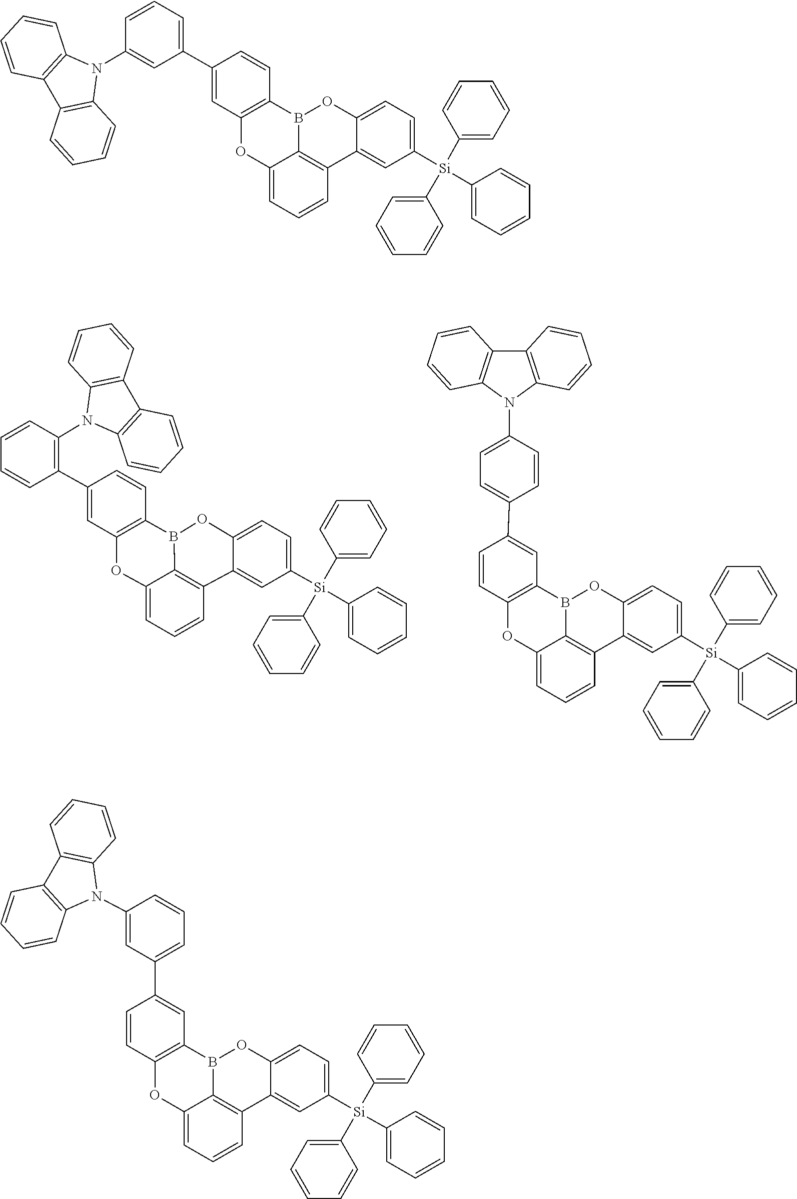 [SMILES: c1ccc([Si](c2ccccc2)(c2ccccc2)c2ccc3c(c2)-c2cccc4c2B(O3)c2ccc(-c3cccc(-n5c6ccccc6c6ccccc65)c3)cc2O4)cc1 ; c1ccc([Si](c2ccccc2)(c2ccccc2)c2ccc3c(c2)-c2cccc4c2B(O3)c2ccc(-c3ccccc3-n3c5ccccc5c5ccccc53)cc2O4)cc1 ; c1ccc([Si](c2ccccc2)(c2ccccc2)c2ccc3c(c2)-c2cccc4c2B(O3)c2cc(-c3ccc(-n5c6ccccc6c6ccccc65)cc3)ccc2O4)cc1 ; c1ccc([Si](c2ccccc2)(c2ccccc2)c2ccc3c(c2)-c2cccc4c2B(O3)c2cc(-c3cccc(-n5c6ccccc6c6ccccc65)c3)ccc2O4)cc1] 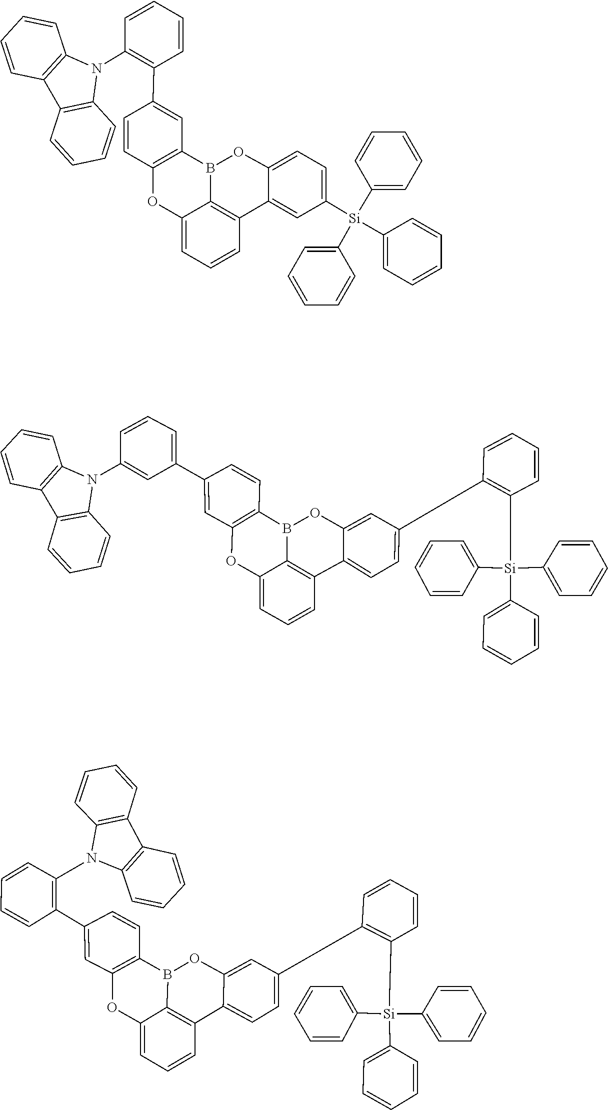 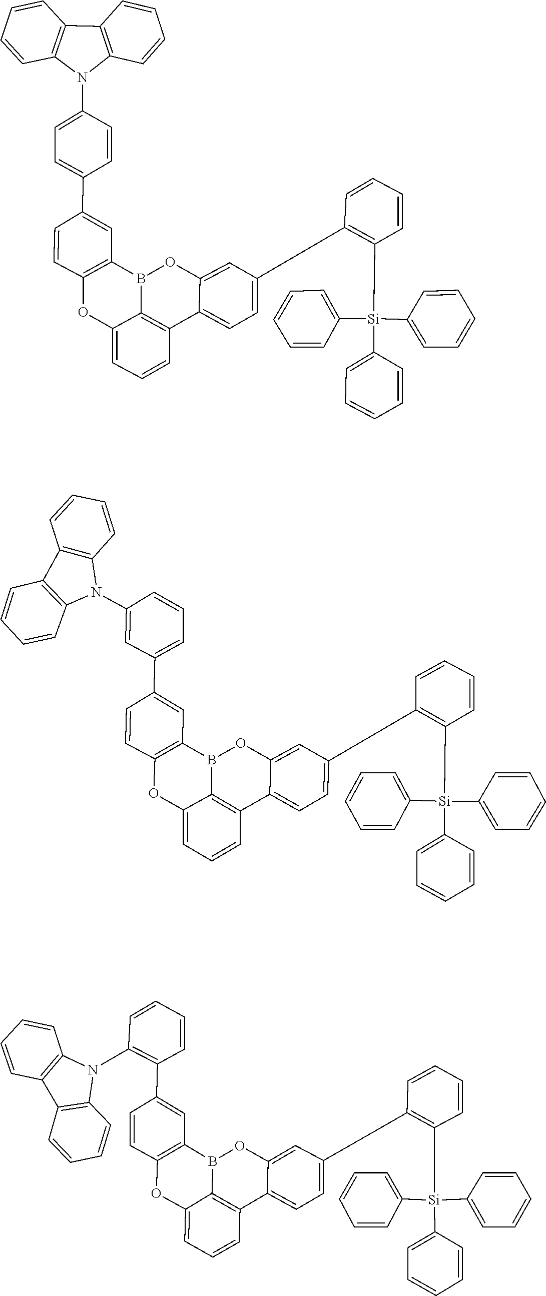 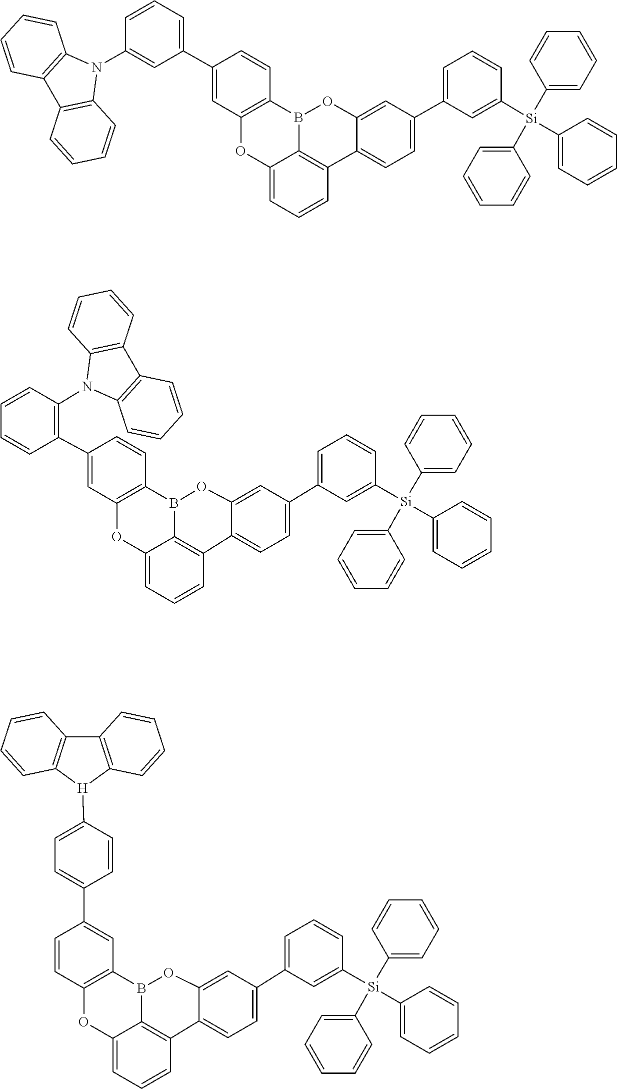 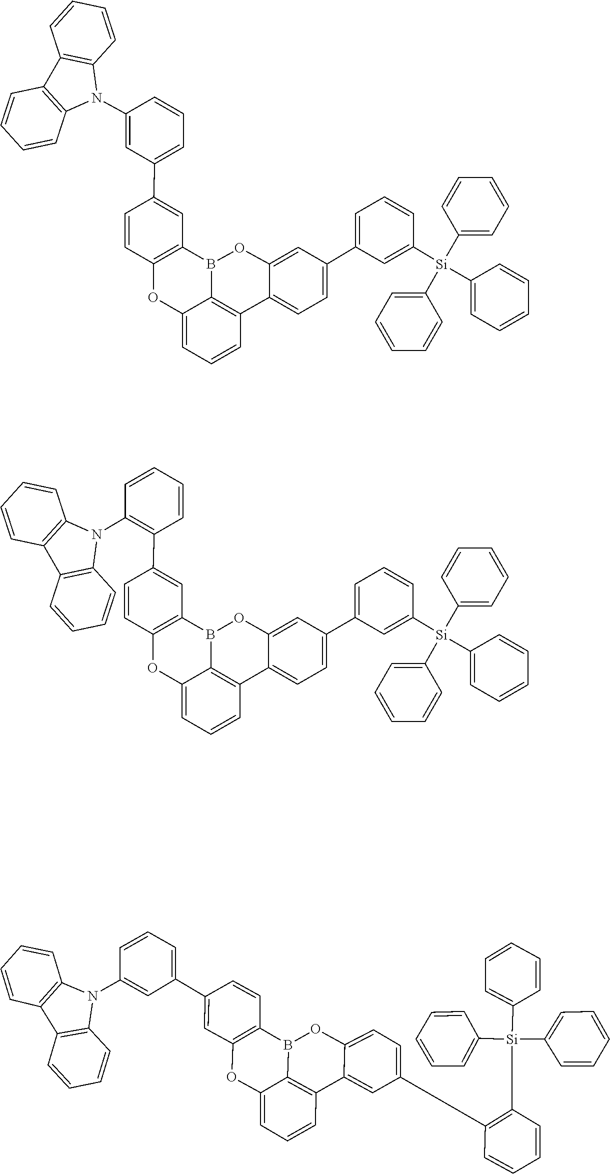 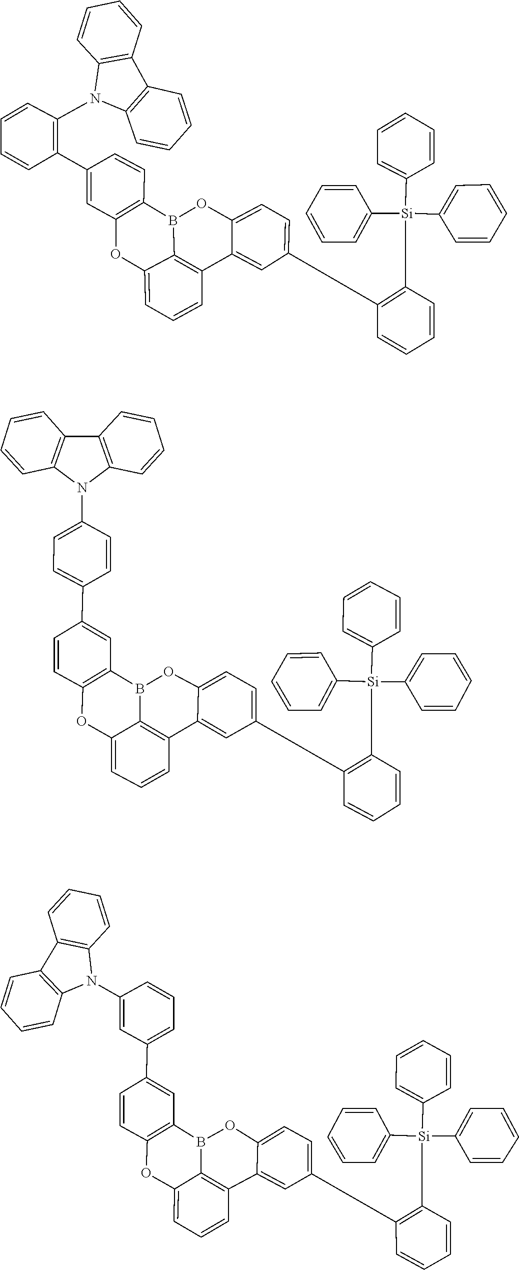 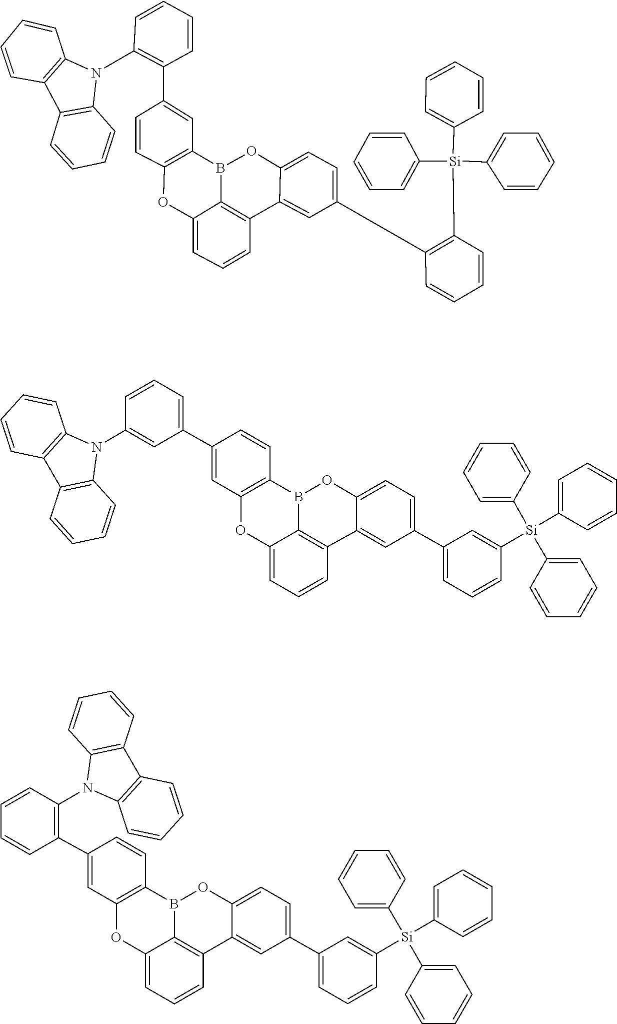 [SMILES: c1ccc([Si](c2ccccc2)(c2ccccc2)c2ccccc2-c2ccc3c(c2)-c2cccc4c2B(O3)c2cc(-c3ccccc3-n3c5ccccc5c5ccccc53)ccc2O4)cc1 ; c1ccc([Si](c2ccccc2)(c2ccccc2)c2cccc(-c3ccc4c(c3)-c3cccc5c3B(O4)c3ccc(-c4cccc(-n6c7ccccc7c7ccccc76)c4)cc3O5)c2)cc1 ; c1ccc([Si](c2ccccc2)(c2ccccc2)c2cccc(-c3ccc4c(c3)-c3cccc5c3B(O4)c3ccc(-c4ccccc4-n4c6ccccc6c6ccccc64)cc3O5)c2)cc1] 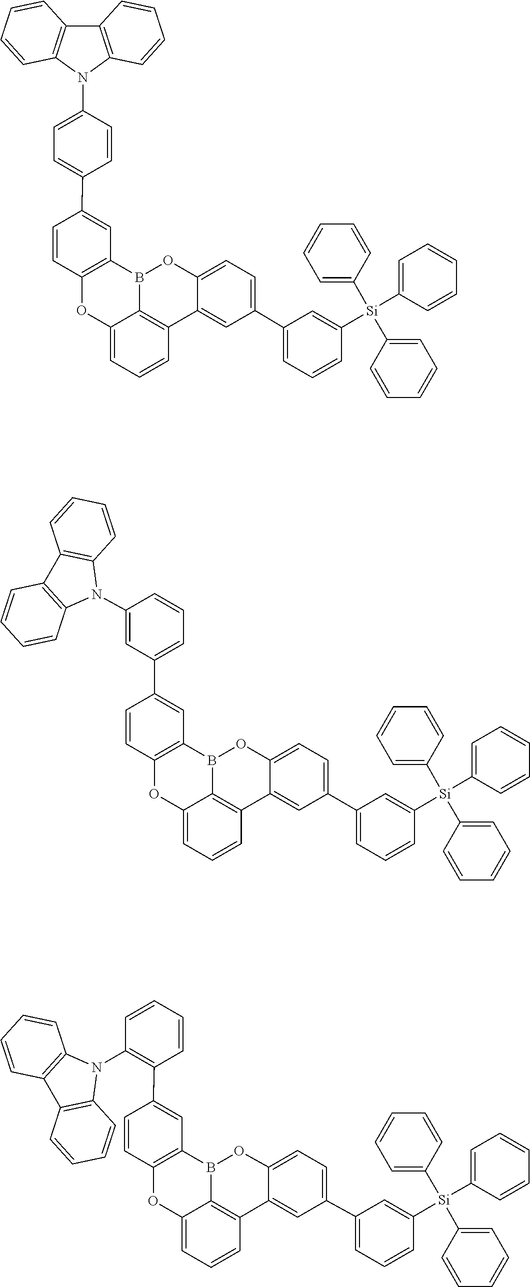 [SMILES: c1ccc([Si](c2ccccc2)(c2ccccc2)c2cccc(-c3ccc4c(c3)-c3cccc5c3B(O4)c3cc(-c4ccc(-n6c7ccccc7c7ccccc76)cc4)ccc3O5)c2)cc1 ; c1ccc([Si](c2ccccc2)(c2ccccc2)c2cccc(-c3ccc4c(c3)-c3cccc5c3B(O4)c3cc(-c4cccc(-n6c7ccccc7c7ccccc76)c4)ccc3O5)c2)cc1 ; c1ccc([Si](c2ccccc2)(c2ccccc2)c2cccc(-c3ccc4c(c3)-c3cccc5c3B(O4)c3cc(-c4ccccc4-n4c6ccccc6c6ccccc64)ccc3O5)c2)cc1] 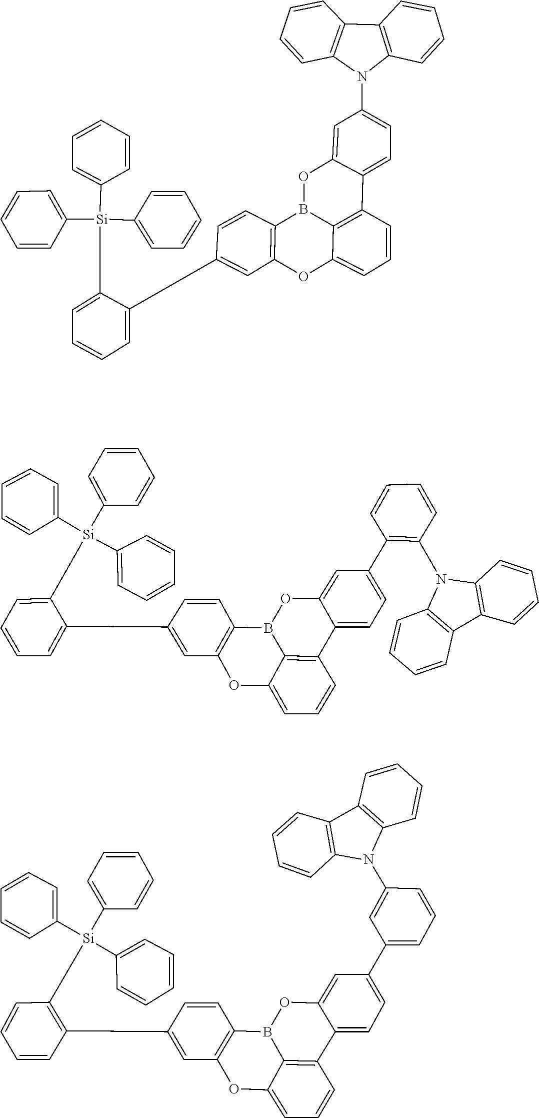 [SMILES: c1ccc([Si](c2ccccc2)(c2ccccc2)c2ccccc2-c2ccc3c(c2)Oc2cccc4c2B3Oc2cc(-n3c5ccccc5c5ccccc53)ccc2-4)cc1 ; c1ccc([Si](c2ccccc2)(c2ccccc2)c2ccccc2-c2ccc3c(c2)Oc2cccc4c2B3Oc2cc(-c3ccccc3-n3c5ccccc5c5ccccc53)ccc2-4)cc1 ; c1ccc([Si](c2ccccc2)(c2ccccc2)c2ccccc2-c2ccc3c(c2)Oc2cccc4c2B3Oc2cc(-c3cccc(-n5c6ccccc6c6ccccc65)c3)ccc2-4)cc1] 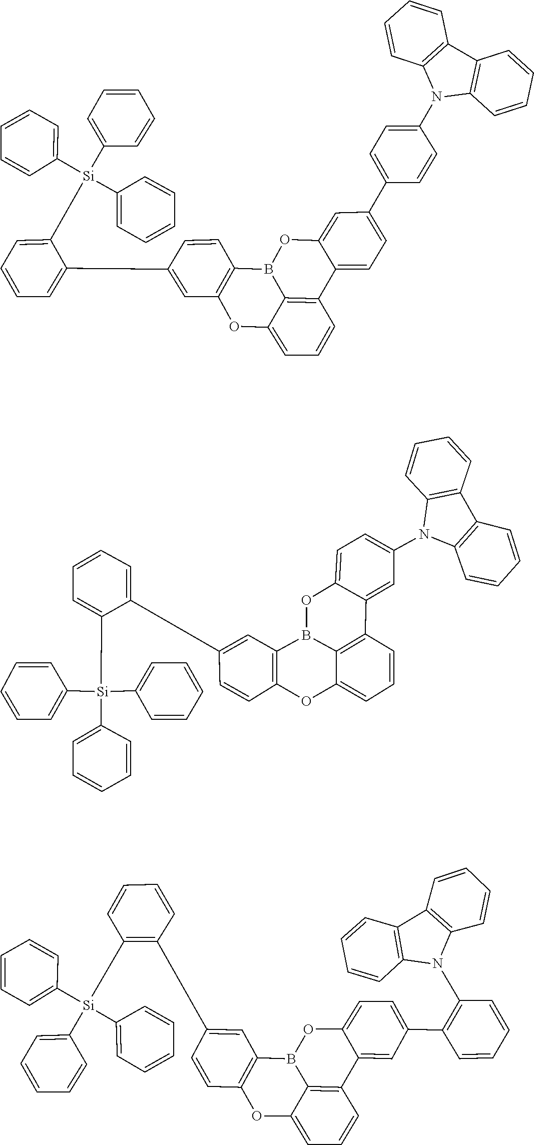 [SMILES: c1ccc([Si](c2ccccc2)(c2ccccc2)c2ccccc2-c2ccc3c(c2)Oc2cccc4c2B3Oc2cc(-c3ccc(-n5c6ccccc6c6ccccc65)cc3)ccc2-4)cc1 ; c1ccc([Si](c2ccccc2)(c2ccccc2)c2ccccc2-c2ccc3c(c2)B2Oc4ccc(-n5c6ccccc6c6ccccc65)cc4-c4cccc(c42)O3)cc1 ; c1ccc([Si](c2ccccc2)(c2ccccc2)c2ccccc2-c2ccc3c(c2)B2Oc4ccc(-c5ccccc5-n5c6ccccc6c6ccccc65)cc4-c4cccc(c42)O3)cc1] 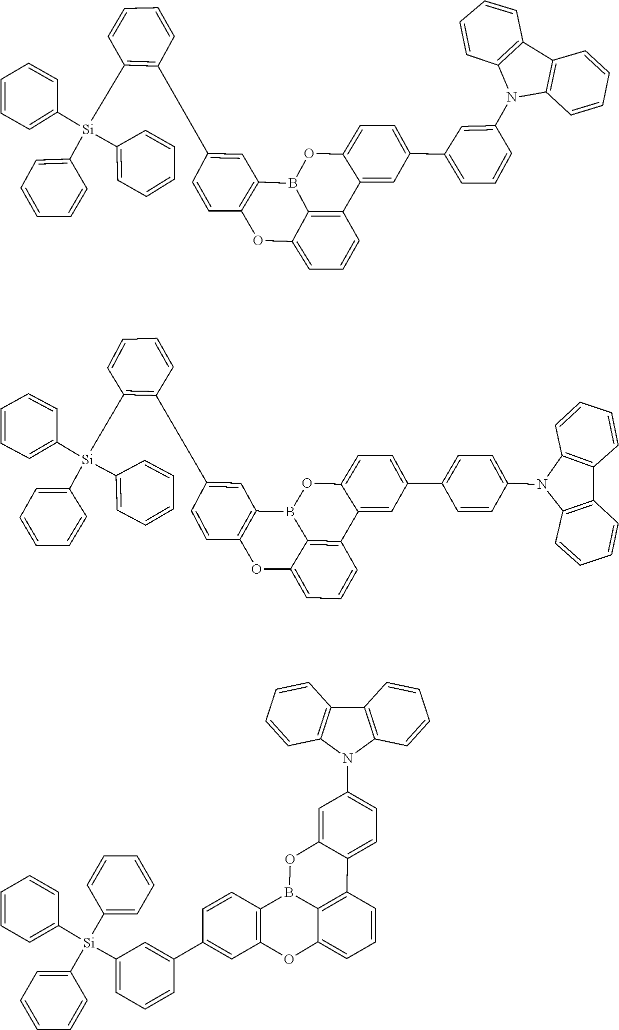 [SMILES: c1ccc([Si](c2ccccc2)(c2ccccc2)c2ccccc2-c2ccc3c(c2)B2Oc4ccc(-c5cccc(-n6c7ccccc7c7ccccc76)c5)cc4-c4cccc(c42)O3)cc1 ; c1ccc([Si](c2ccccc2)(c2ccccc2)c2ccccc2-c2ccc3c(c2)B2Oc4ccc(-c5ccc(-n6c7ccccc7c7ccccc76)cc5)cc4-c4cccc(c42)O3)cc1 ; c1ccc([Si](c2ccccc2)(c2ccccc2)c2cccc(-c3ccc4c(c3)Oc3cccc5c3B4Oc3cc(-n4c6ccccc6c6ccccc64)ccc3-5)c2)cc1] 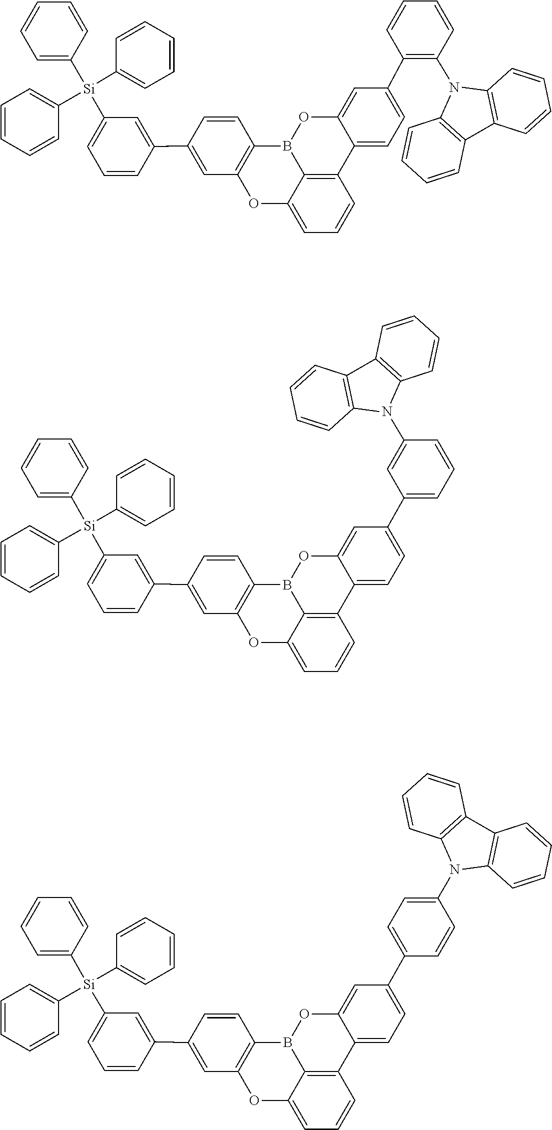 [SMILES: c1ccc([Si](c2ccccc2)(c2ccccc2)c2cccc(-c3ccc4c(c3)Oc3cccc5c3B4Oc3cc(-c4ccccc4-n4c6ccccc6c6ccccc64)ccc3-5)c2)cc1 ; c1ccc([Si](c2ccccc2)(c2ccccc2)c2cccc(-c3ccc4c(c3)Oc3cccc5c3B4Oc3cc(-c4cccc(-n6c7ccccc7c7ccccc76)c4)ccc3-5)c2)cc1 ; c1ccc([Si](c2ccccc2)(c2ccccc2)c2cccc(-c3ccc4c(c3)Oc3cccc5c3B4Oc3cc(-c4ccc(-n6c7ccccc7c7ccccc76)cc4)ccc3-5)c2)cc1] 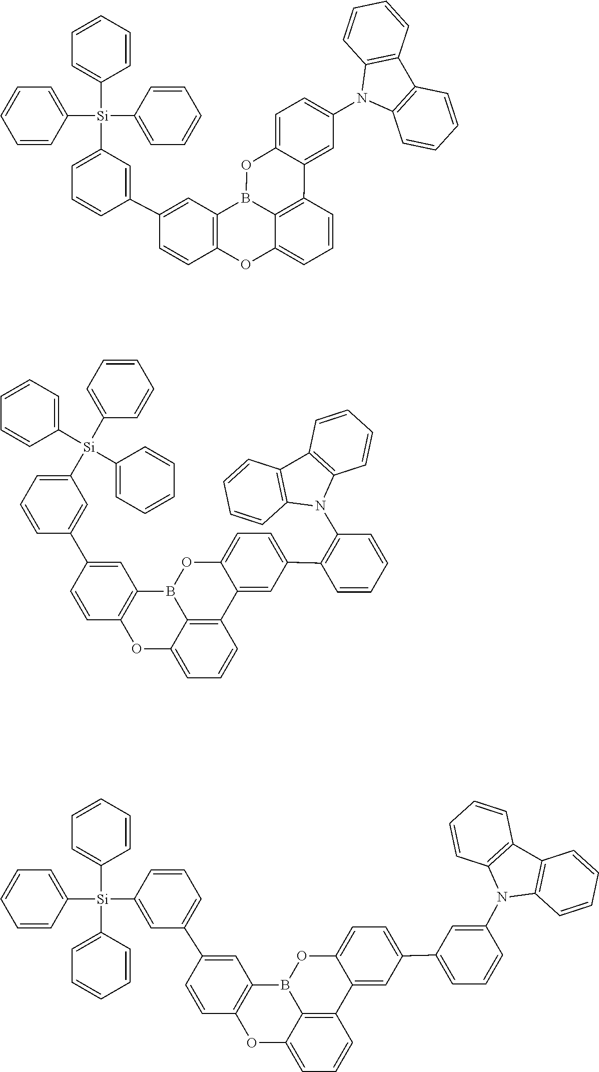 [SMILES: c1ccc([Si](c2ccccc2)(c2ccccc2)c2cccc(-c3ccc4c(c3)B3Oc5ccc(-n6c7ccccc7c7ccccc76)cc5-c5cccc(c53)O4)c2)cc1 ; c1ccc([Si](c2ccccc2)(c2ccccc2)c2cccc(-c3ccc4c(c3)B3Oc5ccc(-c6ccccc6-n6c7ccccc7c7ccccc76)cc5-c5cccc(c53)O4)c2)cc1 ; c1ccc([Si](c2ccccc2)(c2ccccc2)c2cccc(-c3ccc4c(c3)B3Oc5ccc(-c6cccc(-n7c8ccccc8c8ccccc87)c6)cc5-c5cccc(c53)O4)c2)cc1] 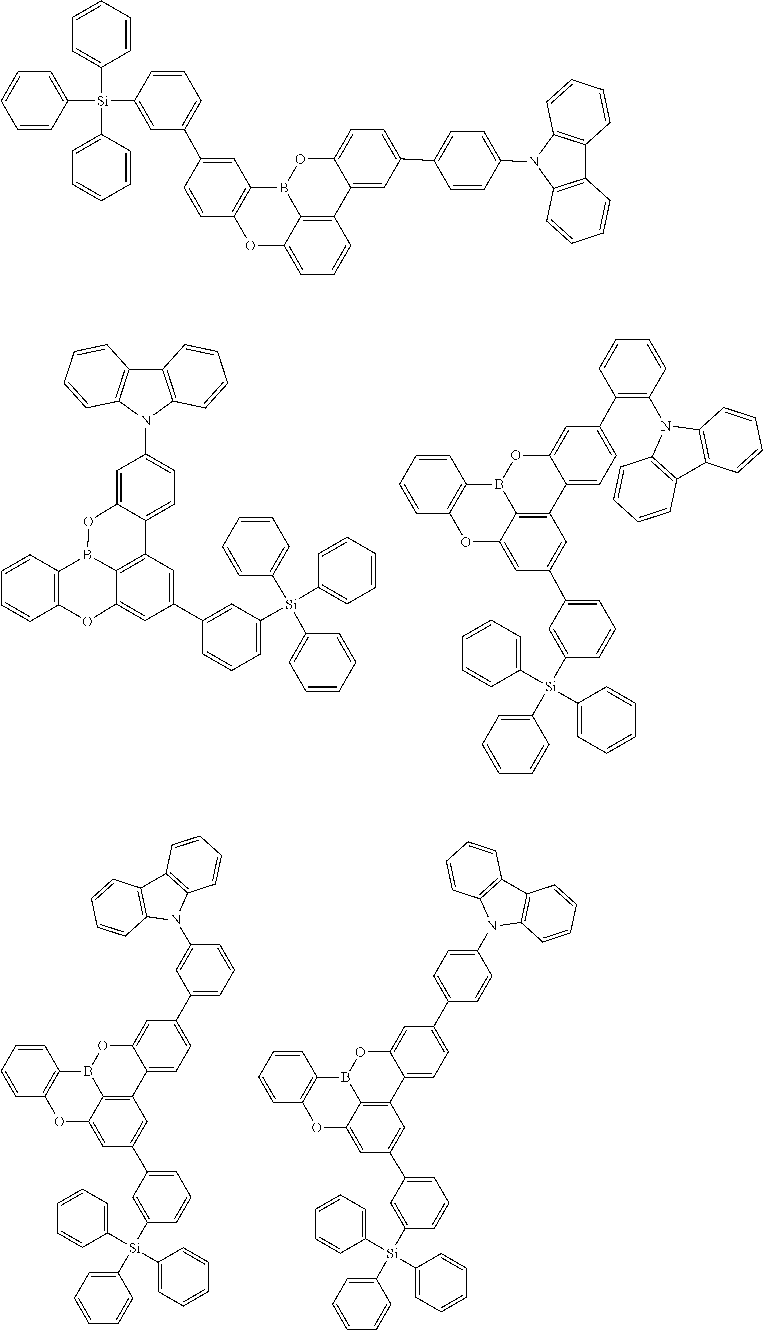 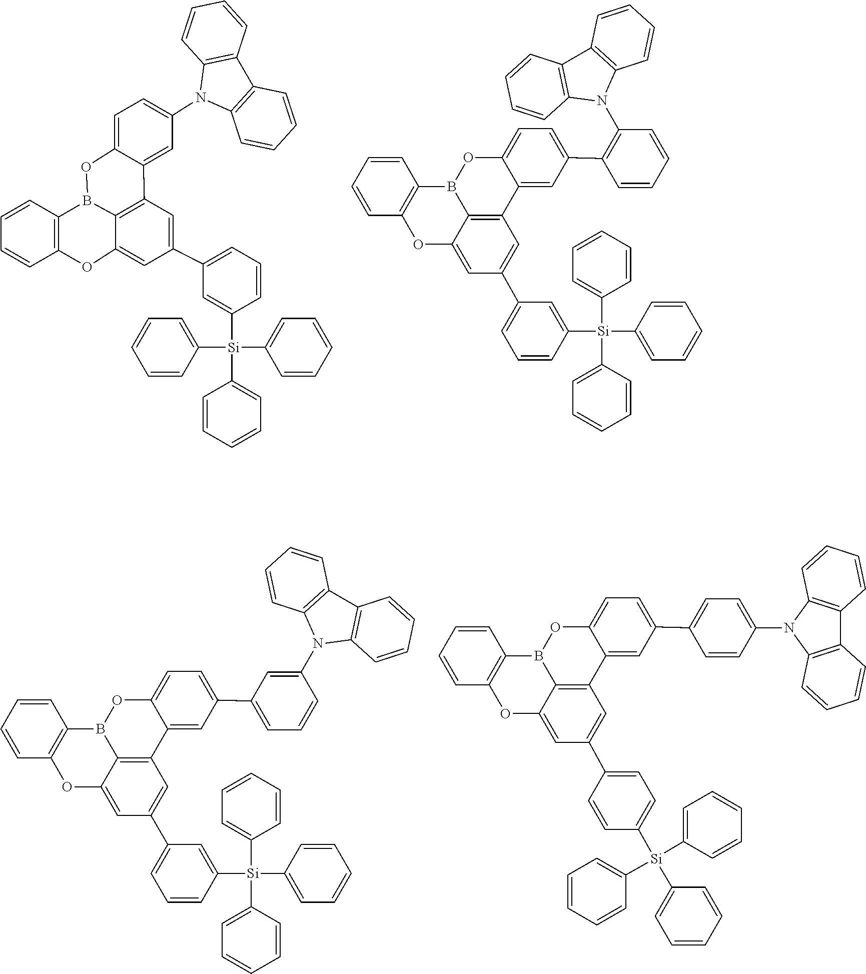 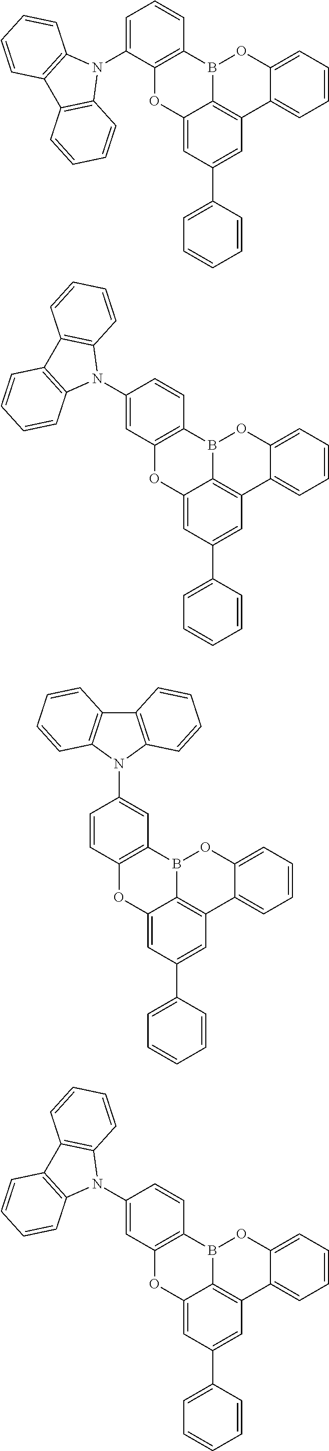 [SMILES: c1ccc(-c2cc3c4c(c2)-c2ccccc2OB4c2cccc(-n4c5ccccc5c5ccccc54)c2O3)cc1 ; c1ccc(-c2cc3c4c(c2)-c2ccccc2OB4c2ccc(-n4c5ccccc5c5ccccc54)cc2O3)cc1 ; c1ccc(-c2cc3c4c(c2)-c2ccccc2OB4c2cc(-n4c5ccccc5c5ccccc54)ccc2O3)cc1 ; c1ccc(-c2cc3c4c(c2)-c2ccccc2OB4c2ccc(-n4c5ccccc5c5ccccc54)cc2O3)cc1] 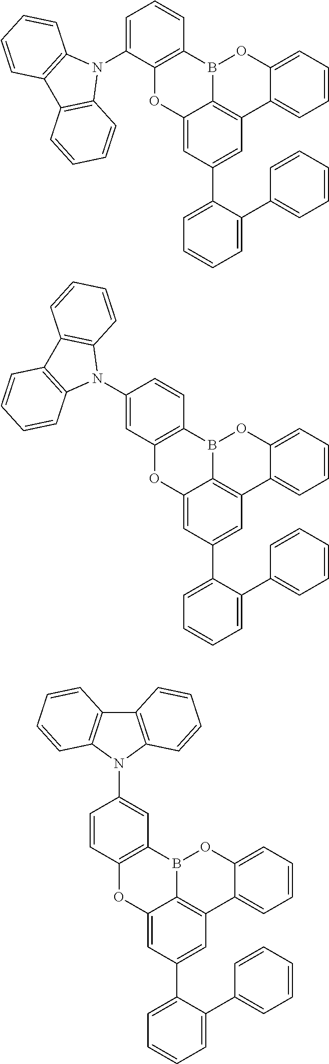 [SMILES: c1ccc(-c2ccccc2-c2cc3c4c(c2)-c2ccccc2OB4c2cccc(-n4c5ccccc5c5ccccc54)c2O3)cc1 ; c1ccc(-c2ccccc2-c2cc3c4c(c2)-c2ccccc2OB4c2ccc(-n4c5ccccc5c5ccccc54)cc2O3)cc1 ; c1ccc(-c2ccccc2-c2cc3c4c(c2)-c2ccccc2OB4c2cc(-n4c5ccccc5c5ccccc54)ccc2O3)cc1] 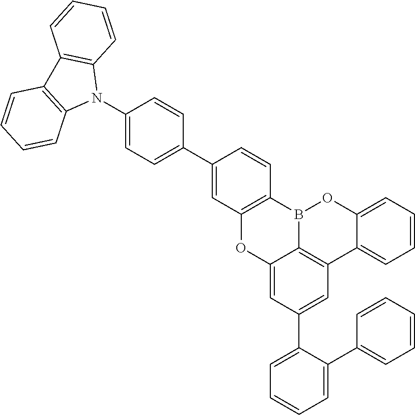 [SMILES: c1ccc(-c2ccccc2-c2cc3c4c(c2)-c2ccccc2OB4c2ccc(-c4ccc(-n5c6ccccc6c6ccccc65)cc4)cc2O3)cc1] 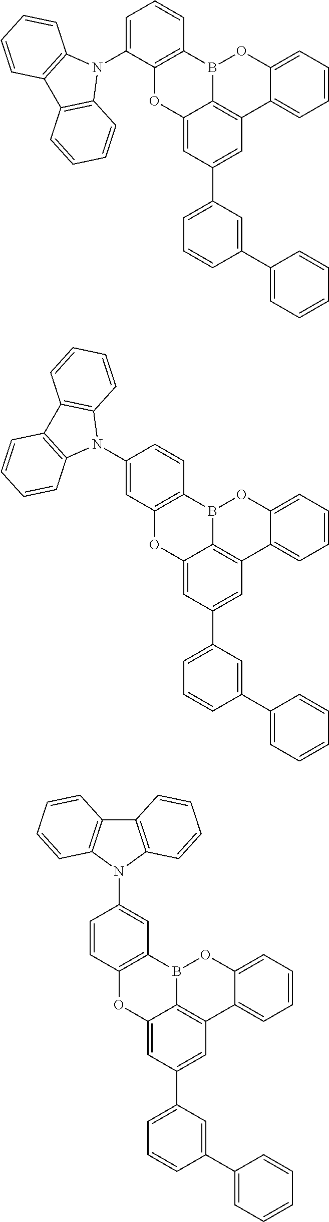 [SMILES: c1ccc(-c2cccc(-c3cc4c5c(c3)-c3ccccc3OB5c3cccc(-n5c6ccccc6c6ccccc65)c3O4)c2)cc1 ; c1ccc(-c2cccc(-c3cc4c5c(c3)-c3ccccc3OB5c3ccc(-n5c6ccccc6c6ccccc65)cc3O4)c2)cc1 ; c1ccc(-c2cccc(-c3cc4c5c(c3)-c3ccccc3OB5c3cc(-n5c6ccccc6c6ccccc65)ccc3O4)c2)cc1] 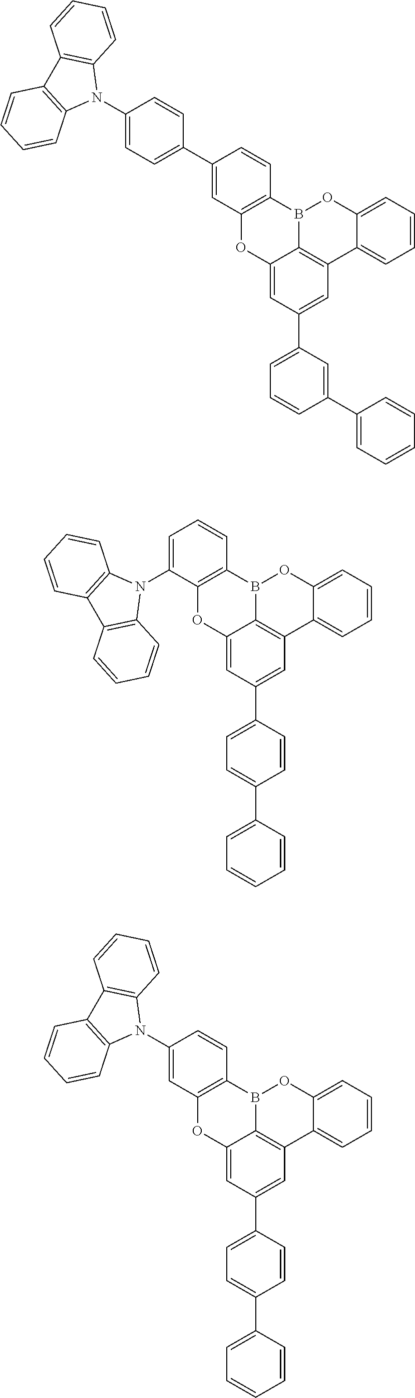 [SMILES: c1ccc(-c2cccc(-c3cc4c5c(c3)-c3ccccc3OB5c3ccc(-c5ccc(-n6c7ccccc7c7ccccc76)cc5)cc3O4)c2)cc1 ; c1ccc(-c2ccc(-c3cc4c5c(c3)-c3ccccc3OB5c3cccc(-n5c6ccccc6c6ccccc65)c3O4)cc2)cc1 ; c1ccc(-c2ccc(-c3cc4c5c(c3)-c3ccccc3OB5c3ccc(-n5c6ccccc6c6ccccc65)cc3O4)cc2)cc1] 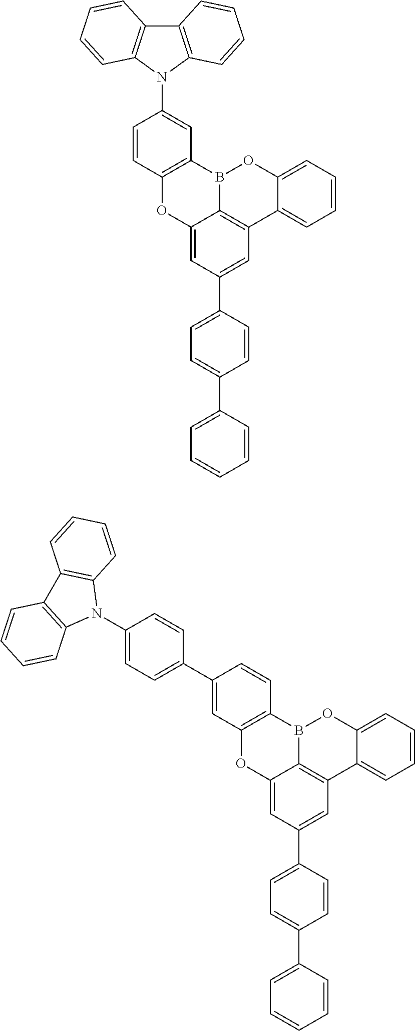 [SMILES: c1ccc(-c2ccc(-c3cc4c5c(c3)-c3ccccc3OB5c3cc(-n5c6ccccc6c6ccccc65)ccc3O4)cc2)cc1 ; c1ccc(-c2ccc(-c3cc4c5c(c3)-c3ccccc3OB5c3ccc(-c5ccc(-n6c7ccccc7c7ccccc76)cc5)cc3O4)cc2)cc1] 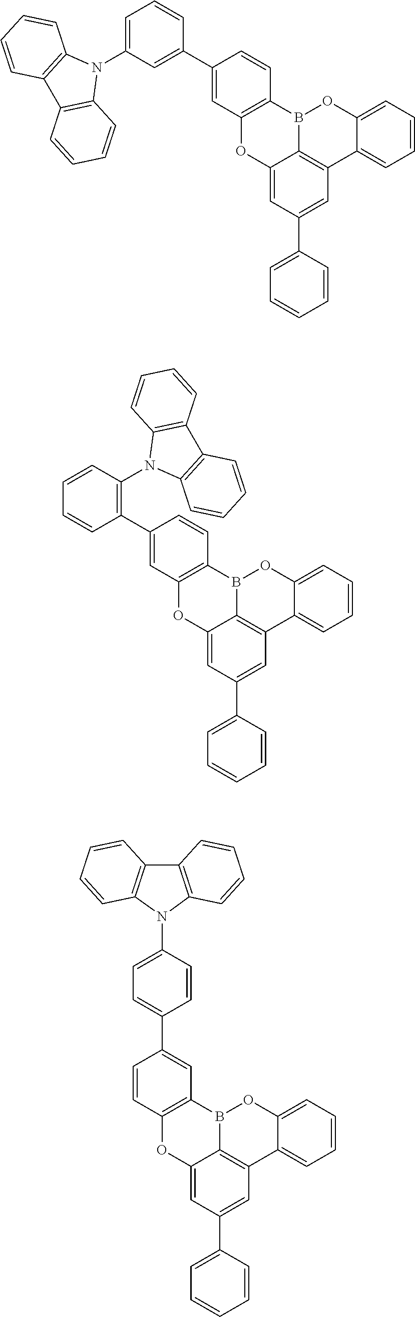 [SMILES: c1ccc(-c2cc3c4c(c2)-c2ccccc2OB4c2ccc(-c4cccc(-n5c6ccccc6c6ccccc65)c4)cc2O3)cc1 ; c1ccc(-c2cc3c4c(c2)-c2ccccc2OB4c2ccc(-c4ccccc4-n4c5ccccc5c5ccccc54)cc2O3)cc1 ; c1ccc(-c2cc3c4c(c2)-c2ccccc2OB4c2cc(-c4ccc(-n5c6ccccc6c6ccccc65)cc4)ccc2O3)cc1] 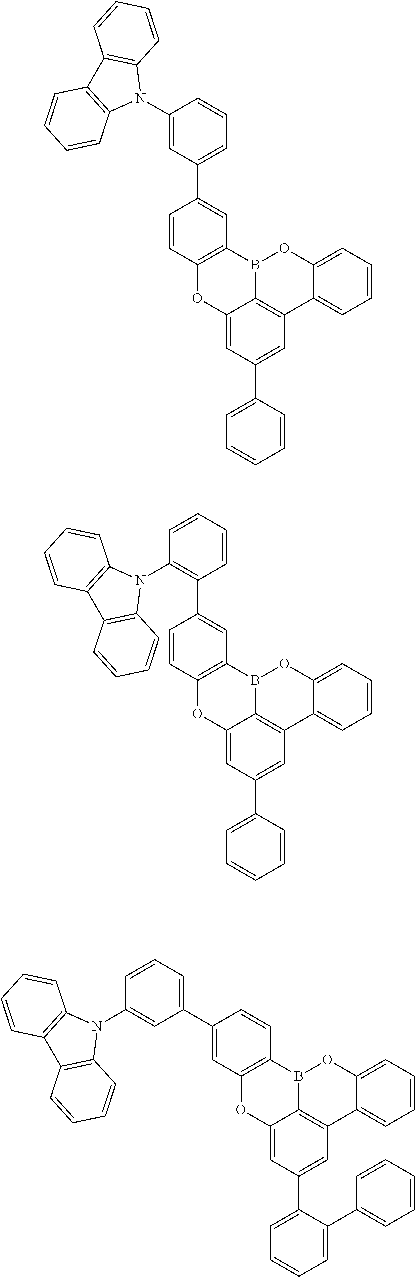 [SMILES: c1ccc(-c2cc3c4c(c2)-c2ccccc2OB4c2cc(-c4cccc(-n5c6ccccc6c6ccccc65)c4)ccc2O3)cc1 ; c1ccc(-c2cc3c4c(c2)-c2ccccc2OB4c2cc(-c4ccccc4-n4c5ccccc5c5ccccc54)ccc2O3)cc1 ; c1ccc(-c2ccccc2-c2cc3c4c(c2)-c2ccccc2OB4c2ccc(-c4cccc(-n5c6ccccc6c6ccccc65)c4)cc2O3)cc1] 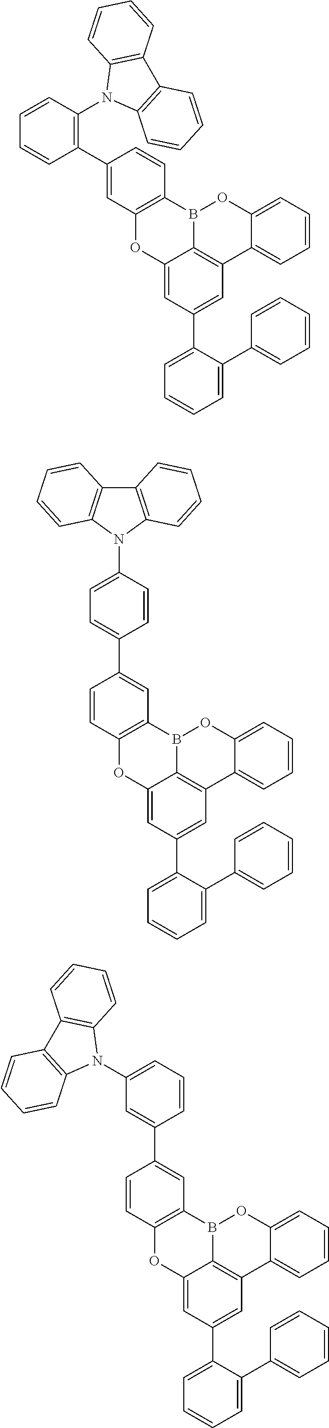 [SMILES: c1ccc(-c2ccccc2-c2cc3c4c(c2)-c2ccccc2OB4c2ccc(-c4ccccc4-n4c5ccccc5c5ccccc54)cc2O3)cc1 ; c1ccc(-c2ccccc2-c2cc3c4c(c2)-c2ccccc2OB4c2cc(-c4ccc(-n5c6ccccc6c6ccccc65)cc4)ccc2O3)cc1 ; c1ccc(-c2ccccc2-c2cc3c4c(c2)-c2ccccc2OB4c2cc(-c4cccc(-n5c6ccccc6c6ccccc65)c4)ccc2O3)cc1] 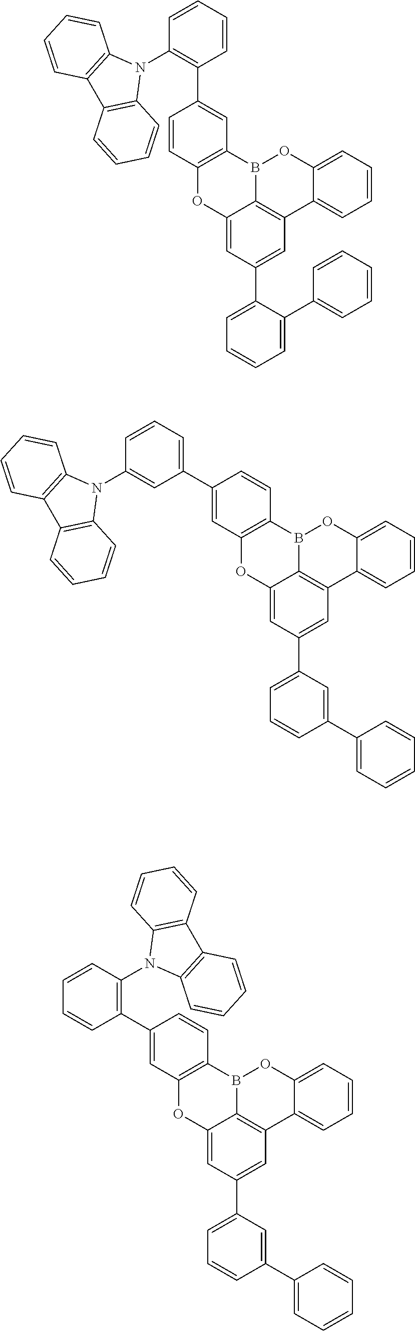 [SMILES: c1ccc(-c2ccccc2-c2cc3c4c(c2)-c2ccccc2OB4c2cc(-c4ccccc4-n4c5ccccc5c5ccccc54)ccc2O3)cc1 ; c1ccc(-c2cccc(-c3cc4c5c(c3)-c3ccccc3OB5c3ccc(-c5cccc(-n6c7ccccc7c7ccccc76)c5)cc3O4)c2)cc1 ; c1ccc(-c2cccc(-c3cc4c5c(c3)-c3ccccc3OB5c3ccc(-c5ccccc5-n5c6ccccc6c6ccccc65)cc3O4)c2)cc1] 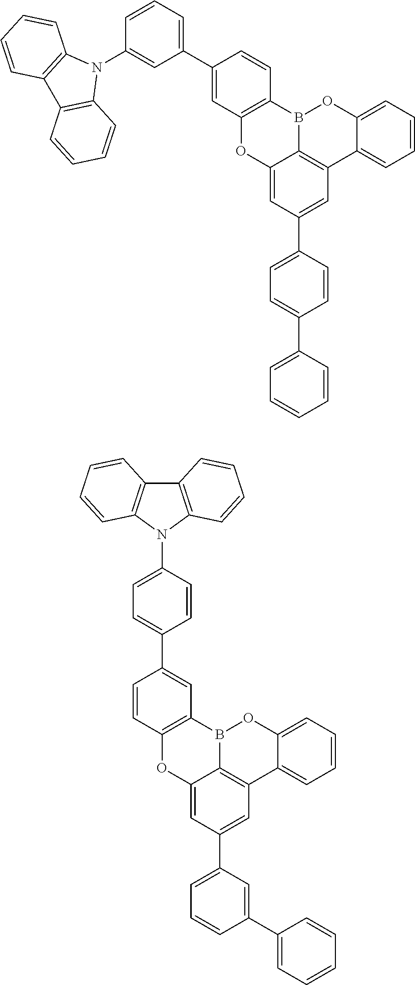 [SMILES: c1ccc(-c2ccc(-c3cc4c5c(c3)-c3ccccc3OB5c3ccc(-c5cccc(-n6c7ccccc7c7ccccc76)c5)cc3O4)cc2)cc1 ; c1ccc(-c2cccc(-c3cc4c5c(c3)-c3ccccc3OB5c3cc(-c5ccc(-n6c7ccccc7c7ccccc76)cc5)ccc3O4)c2)cc1] 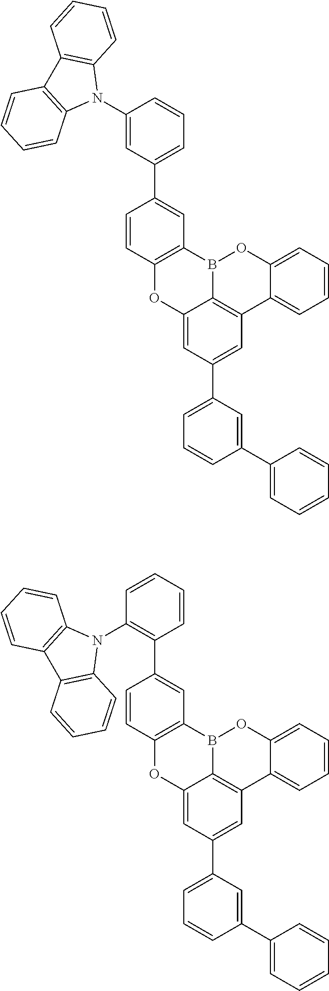 [SMILES: c1ccc(-c2cccc(-c3cc4c5c(c3)-c3ccccc3OB5c3cc(-c5cccc(-n6c7ccccc7c7ccccc76)c5)ccc3O4)c2)cc1 ; c1ccc(-c2cccc(-c3cc4c5c(c3)-c3ccccc3OB5c3cc(-c5ccccc5-n5c6ccccc6c6ccccc65)ccc3O4)c2)cc1] 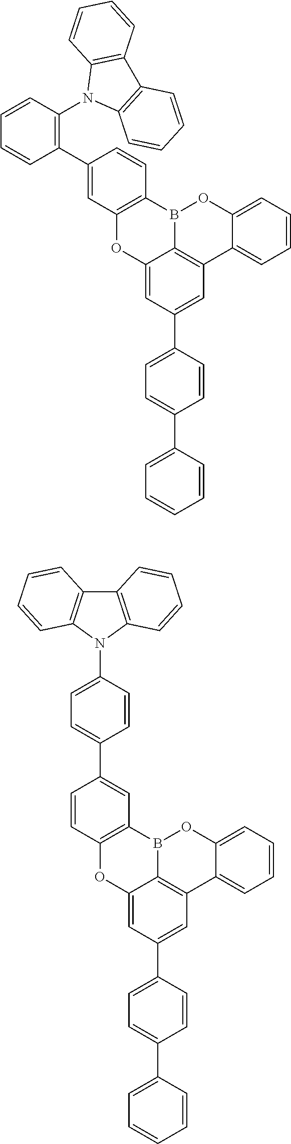 [SMILES: c1ccc(-c2ccc(-c3cc4c5c(c3)-c3ccccc3OB5c3ccc(-c5ccccc5-n5c6ccccc6c6ccccc65)cc3O4)cc2)cc1 ; c1ccc(-c2ccc(-c3cc4c5c(c3)-c3ccccc3OB5c3cc(-c5ccc(-n6c7ccccc7c7ccccc76)cc5)ccc3O4)cc2)cc1] 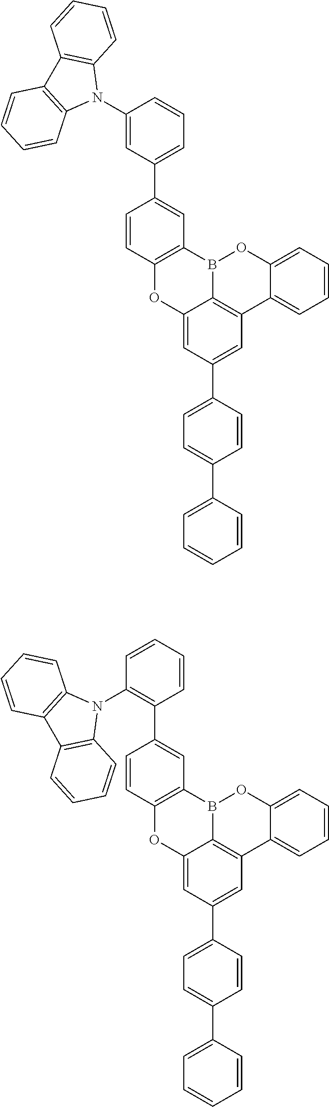 [SMILES: c1ccc(-c2ccc(-c3cc4c5c(c3)-c3ccccc3OB5c3cc(-c5cccc(-n6c7ccccc7c7ccccc76)c5)ccc3O4)cc2)cc1 ; c1ccc(-c2ccc(-c3cc4c5c(c3)-c3ccccc3OB5c3cc(-c5ccccc5-n5c6ccccc6c6ccccc65)ccc3O4)cc2)cc1] 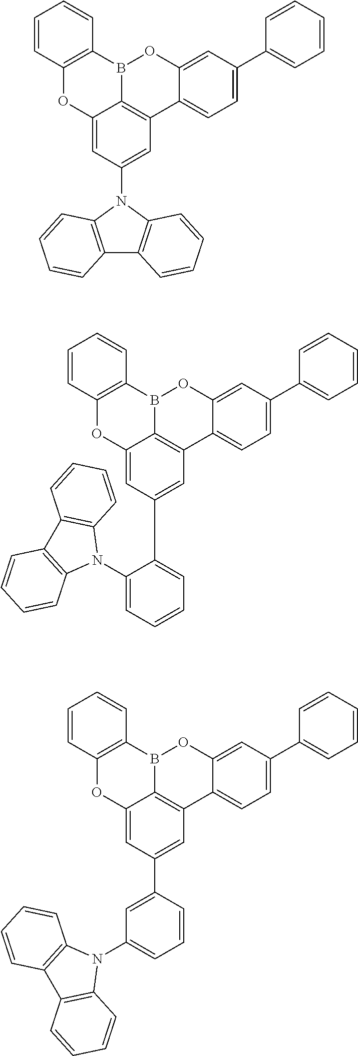 [SMILES: c1ccc(-c2ccc3c(c2)OB2c4ccccc4Oc4cc(-n5c6ccccc6c6ccccc65)cc-3c42)cc1 ; c1ccc(-c2ccc3c(c2)OB2c4ccccc4Oc4cc(-c5ccccc5-n5c6ccccc6c6ccccc65)cc-3c42)cc1 ; c1ccc(-c2ccc3c(c2)OB2c4ccccc4Oc4cc(-c5cccc(-n6c7ccccc7c7ccccc76)c5)cc-3c42)cc1] 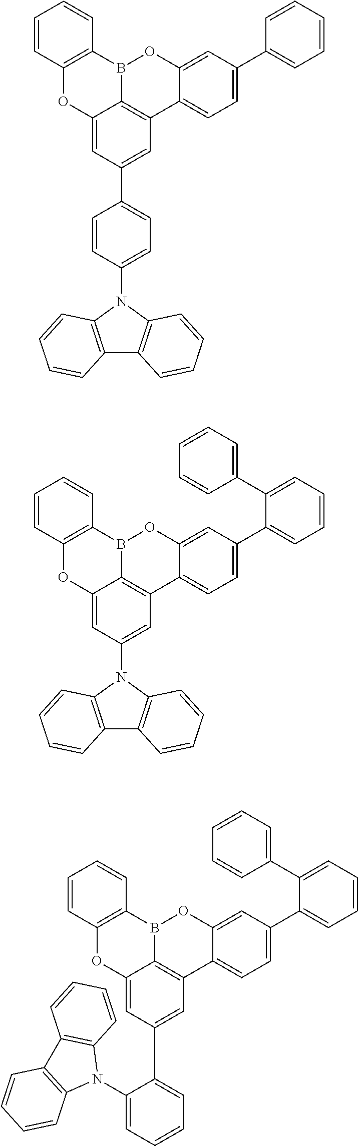 [SMILES: c1ccc(-c2ccc3c(c2)OB2c4ccccc4Oc4cc(-c5ccc(-n6c7ccccc7c7ccccc76)cc5)cc-3c42)cc1 ; c1ccc(-c2ccccc2-c2ccc3c(c2)OB2c4ccccc4Oc4cc(-n5c6ccccc6c6ccccc65)cc-3c42)cc1 ; c1ccc(-c2ccccc2-c2ccc3c(c2)OB2c4ccccc4Oc4cc(-c5ccccc5-n5c6ccccc6c6ccccc65)cc-3c42)cc1] 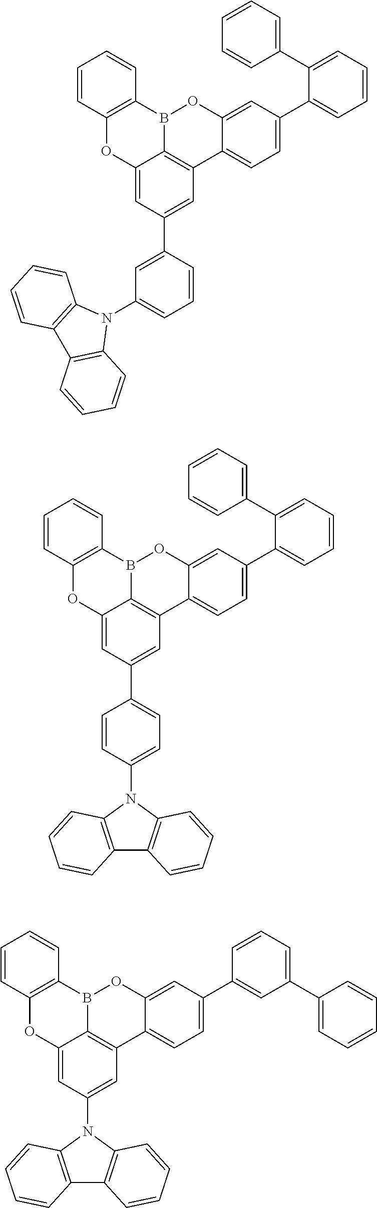 [SMILES: c1ccc(-c2ccccc2-c2ccc3c(c2)OB2c4ccccc4Oc4cc(-c5cccc(-n6c7ccccc7c7ccccc76)c5)cc-3c42)cc1 ; c1ccc(-c2ccccc2-c2ccc3c(c2)OB2c4ccccc4Oc4cc(-c5ccc(-n6c7ccccc7c7ccccc76)cc5)cc-3c42)cc1 ; c1ccc(-c2cccc(-c3ccc4c(c3)OB3c5ccccc5Oc5cc(-n6c7ccccc7c7ccccc76)cc-4c53)c2)cc1] 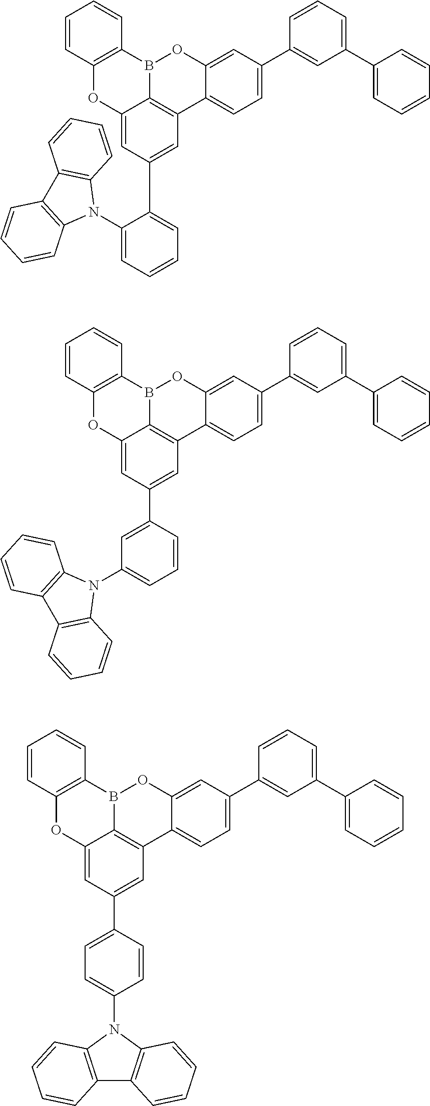 [SMILES: c1ccc(-c2cccc(-c3ccc4c(c3)OB3c5ccccc5Oc5cc(-c6ccccc6-n6c7ccccc7c7ccccc76)cc-4c53)c2)cc1 ; c1ccc(-c2cccc(-c3ccc4c(c3)OB3c5ccccc5Oc5cc(-c6cccc(-n7c8ccccc8c8ccccc87)c6)cc-4c53)c2)cc1 ; c1ccc(-c2cccc(-c3ccc4c(c3)OB3c5ccccc5Oc5cc(-c6ccc(-n7c8ccccc8c8ccccc87)cc6)cc-4c53)c2)cc1] 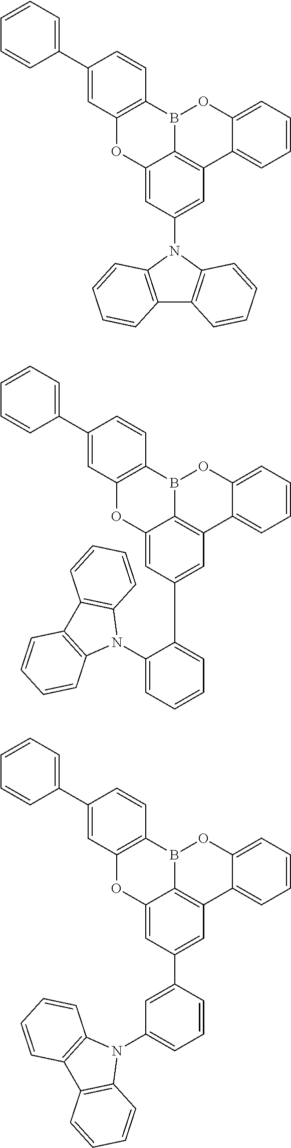 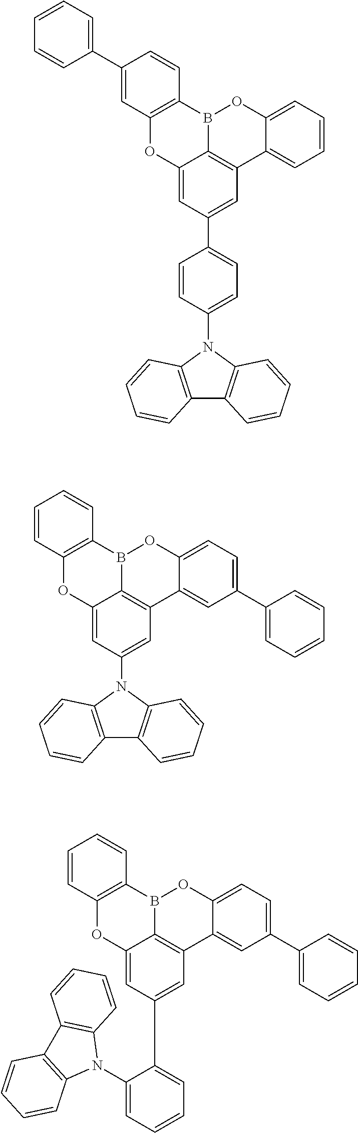 [SMILES: c1ccc(-c2ccc3c(c2)Oc2cc(-c4ccc(-n5c6ccccc6c6ccccc65)cc4)cc4c2B3Oc2ccccc2-4)cc1 ; c1ccc(-c2ccc3c(c2)-c2cc(-n4c5ccccc5c5ccccc54)cc4c2B(O3)c2ccccc2O4)cc1 ; c1ccc(-c2ccc3c(c2)-c2cc(-c4ccccc4-n4c5ccccc5c5ccccc54)cc4c2B(O3)c2ccccc2O4)cc1] 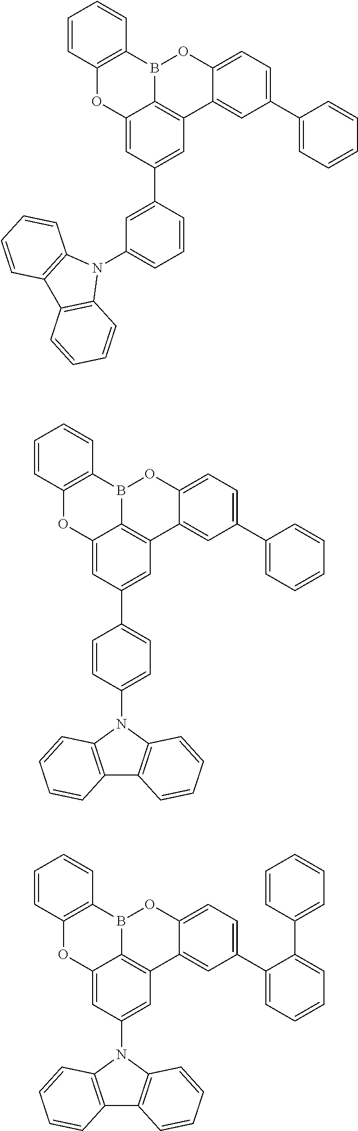 [SMILES: c1ccc(-c2ccc3c(c2)-c2cc(-c4cccc(-n5c6ccccc6c6ccccc65)c4)cc4c2B(O3)c2ccccc2O4)cc1 ; c1ccc(-c2ccc3c(c2)-c2cc(-c4ccc(-n5c6ccccc6c6ccccc65)cc4)cc4c2B(O3)c2ccccc2O4)cc1 ; c1ccc(-c2ccccc2-c2ccc3c(c2)-c2cc(-n4c5ccccc5c5ccccc54)cc4c2B(O3)c2ccccc2O4)cc1] 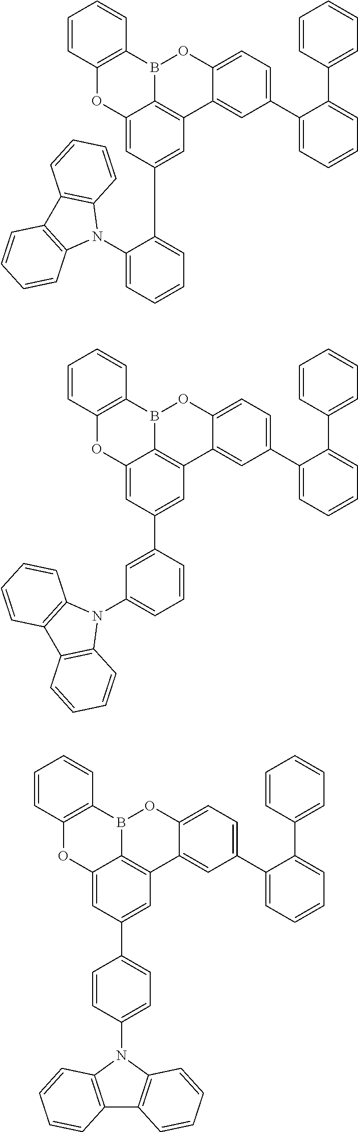 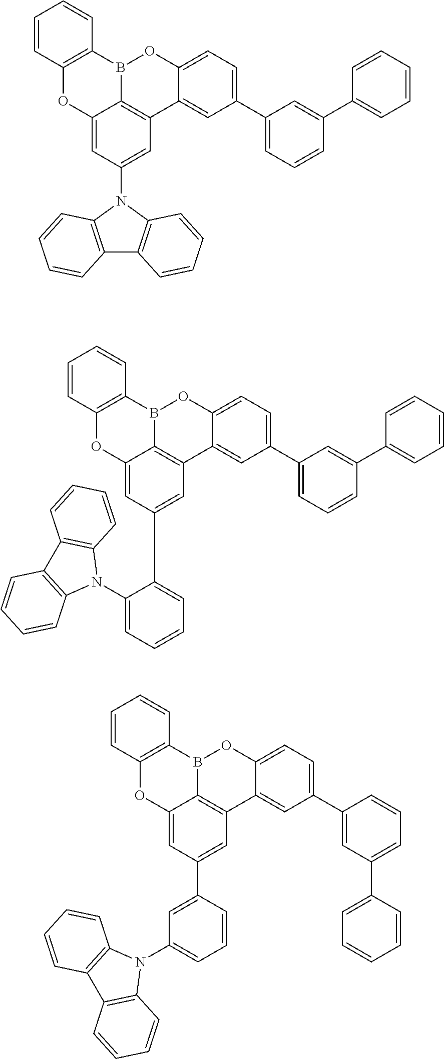 [SMILES: c1ccc(-c2cccc(-c3ccc4c(c3)-c3cc(-n5c6ccccc6c6ccccc65)cc5c3B(O4)c3ccccc3O5)c2)cc1 ; c1ccc(-c2cccc(-c3ccc4c(c3)-c3cc(-c5ccccc5-n5c6ccccc6c6ccccc65)cc5c3B(O4)c3ccccc3O5)c2)cc1 ; c1ccc(-c2cccc(-c3ccc4c(c3)-c3cc(-c5cccc(-n6c7ccccc7c7ccccc76)c5)cc5c3B(O4)c3ccccc3O5)c2)cc1] 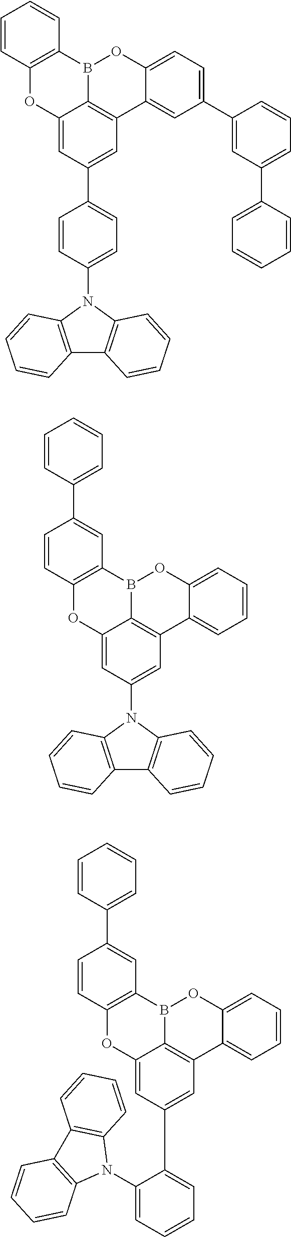 [SMILES: c1ccc(-c2cccc(-c3ccc4c(c3)-c3cc(-c5ccc(-n6c7ccccc7c7ccccc76)cc5)cc5c3B(O4)c3ccccc3O5)c2)cc1 ; c1ccc(-c2ccc3c(c2)B2Oc4ccccc4-c4cc(-n5c6ccccc6c6ccccc65)cc(c42)O3)cc1 ; c1ccc(-c2ccc3c(c2)B2Oc4ccccc4-c4cc(-c5ccccc5-n5c6ccccc6c6ccccc65)cc(c42)O3)cc1] 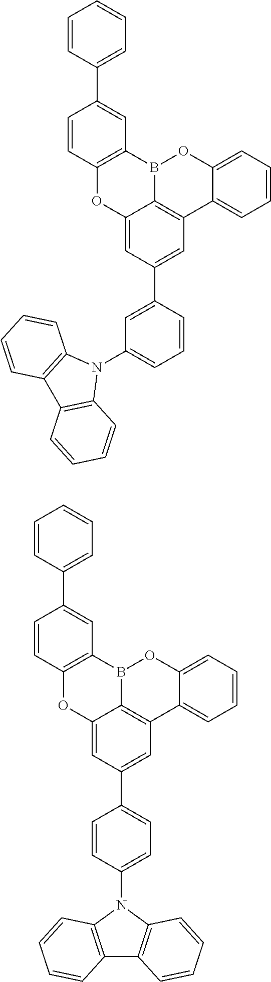 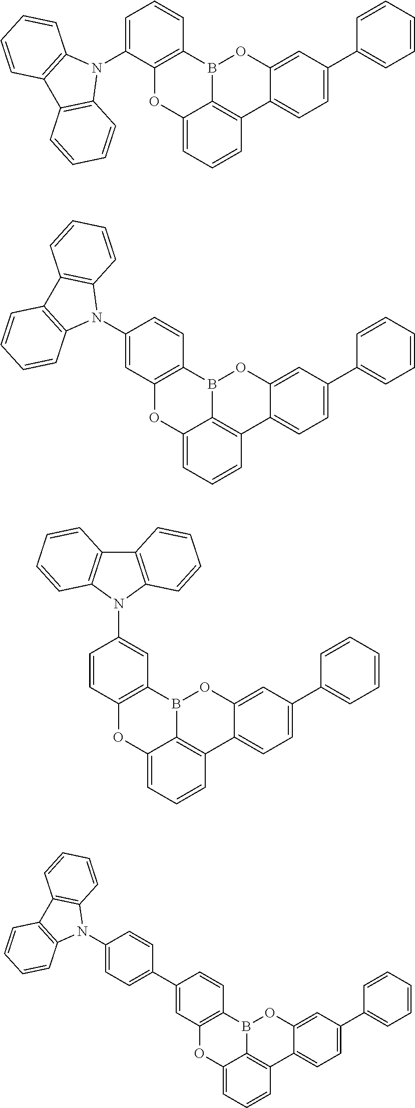 [SMILES: c1ccc(-c2ccc3c(c2)OB2c4cccc(-n5c6ccccc6c6ccccc65)c4Oc4cccc-3c42)cc1 ; c1ccc(-c2ccc3c(c2)OB2c4ccc(-n5c6ccccc6c6ccccc65)cc4Oc4cccc-3c42)cc1 ; c1ccc(-c2ccc3c(c2)OB2c4cc(-n5c6ccccc6c6ccccc65)ccc4Oc4cccc-3c42)cc1 ; c1ccc(-c2ccc3c(c2)OB2c4ccc(-c5ccc(-n6c7ccccc7c7ccccc76)cc5)cc4Oc4cccc-3c42)cc1] 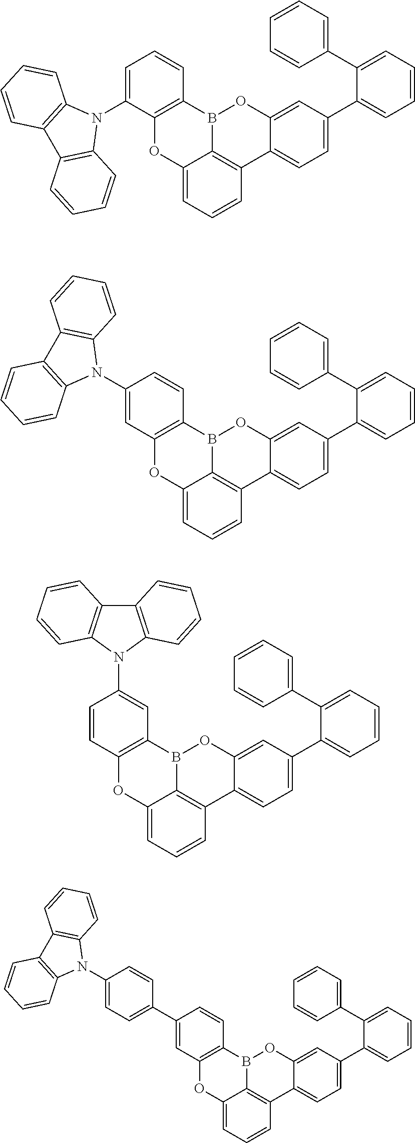 [SMILES: c1ccc(-c2ccccc2-c2ccc3c(c2)OB2c4cccc(-n5c6ccccc6c6ccccc65)c4Oc4cccc-3c42)cc1 ; c1ccc(-c2ccccc2-c2ccc3c(c2)OB2c4ccc(-n5c6ccccc6c6ccccc65)cc4Oc4cccc-3c42)cc1 ; c1ccc(-c2ccccc2-c2ccc3c(c2)OB2c4cc(-n5c6ccccc6c6ccccc65)ccc4Oc4cccc-3c42)cc1 ; c1ccc(-c2ccccc2-c2ccc3c(c2)OB2c4ccc(-c5ccc(-n6c7ccccc7c7ccccc76)cc5)cc4Oc4cccc-3c42)cc1] 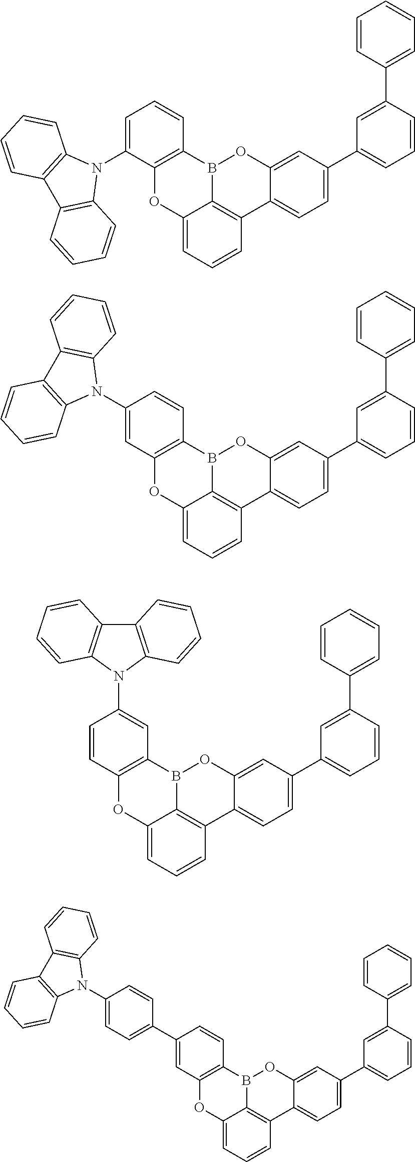 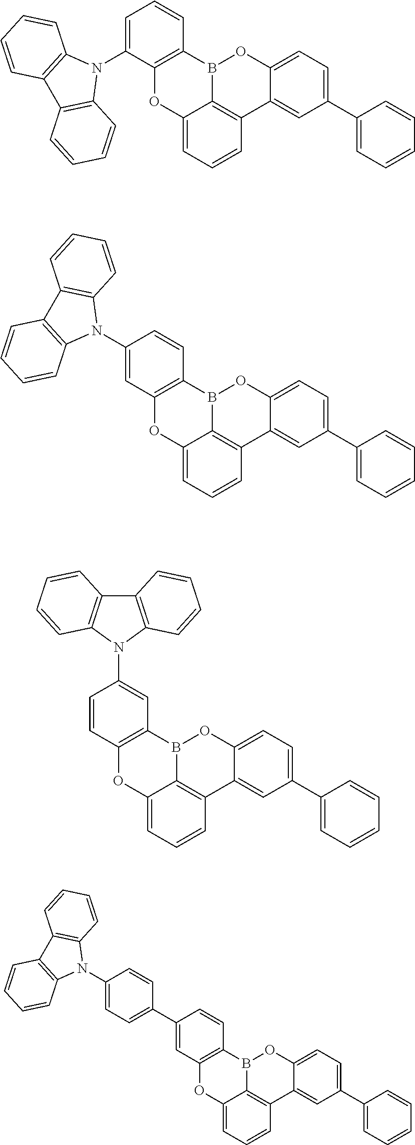 [SMILES: c1ccc(-c2ccc3c(c2)-c2cccc4c2B(O3)c2cccc(-n3c5ccccc5c5ccccc53)c2O4)cc1 ; c1ccc(-c2ccc3c(c2)-c2cccc4c2B(O3)c2ccc(-n3c5ccccc5c5ccccc53)cc2O4)cc1 ; c1ccc(-c2ccc3c(c2)-c2cccc4c2B(O3)c2cc(-n3c5ccccc5c5ccccc53)ccc2O4)cc1 ; c1ccc(-c2ccc3c(c2)-c2cccc4c2B(O3)c2ccc(-c3ccc(-n5c6ccccc6c6ccccc65)cc3)cc2O4)cc1] 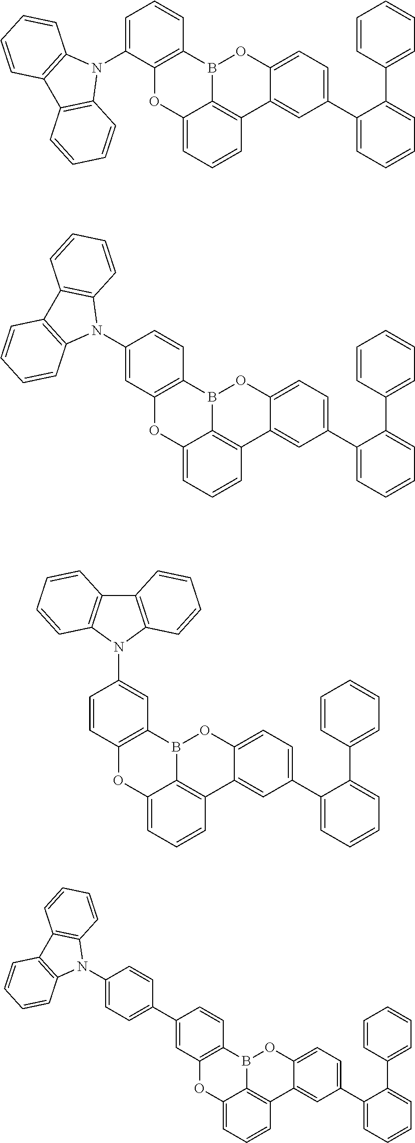 [SMILES: c1ccc(-c2ccccc2-c2ccc3c(c2)-c2cccc4c2B(O3)c2cccc(-n3c5ccccc5c5ccccc53)c2O4)cc1 ; c1ccc(-c2ccccc2-c2ccc3c(c2)-c2cccc4c2B(O3)c2ccc(-n3c5ccccc5c5ccccc53)cc2O4)cc1 ; c1ccc(-c2ccccc2-c2ccc3c(c2)-c2cccc4c2B(O3)c2cc(-n3c5ccccc5c5ccccc53)ccc2O4)cc1 ; c1ccc(-c2ccccc2-c2ccc3c(c2)-c2cccc4c2B(O3)c2ccc(-c3ccc(-n5c6ccccc6c6ccccc65)cc3)cc2O4)cc1] 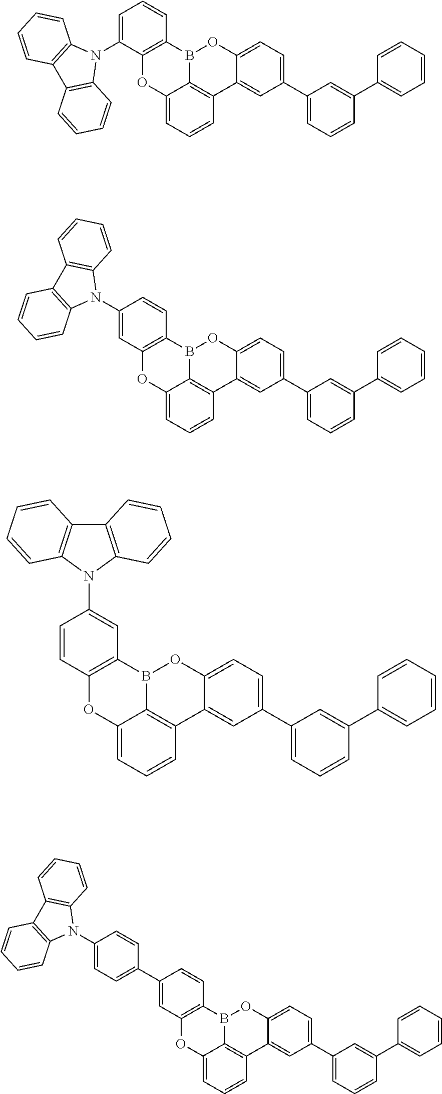 [SMILES: c1ccc(-c2cccc(-c3ccc4c(c3)-c3cccc5c3B(O4)c3cccc(-n4c6ccccc6c6ccccc64)c3O5)c2)cc1 ; c1ccc(-c2cccc(-c3ccc4c(c3)-c3cccc5c3B(O4)c3ccc(-n4c6ccccc6c6ccccc64)cc3O5)c2)cc1 ; c1ccc(-c2cccc(-c3ccc4c(c3)-c3cccc5c3B(O4)c3cc(-n4c6ccccc6c6ccccc64)ccc3O5)c2)cc1 ; c1ccc(-c2cccc(-c3ccc4c(c3)-c3cccc5c3B(O4)c3ccc(-c4ccc(-n6c7ccccc7c7ccccc76)cc4)cc3O5)c2)cc1] 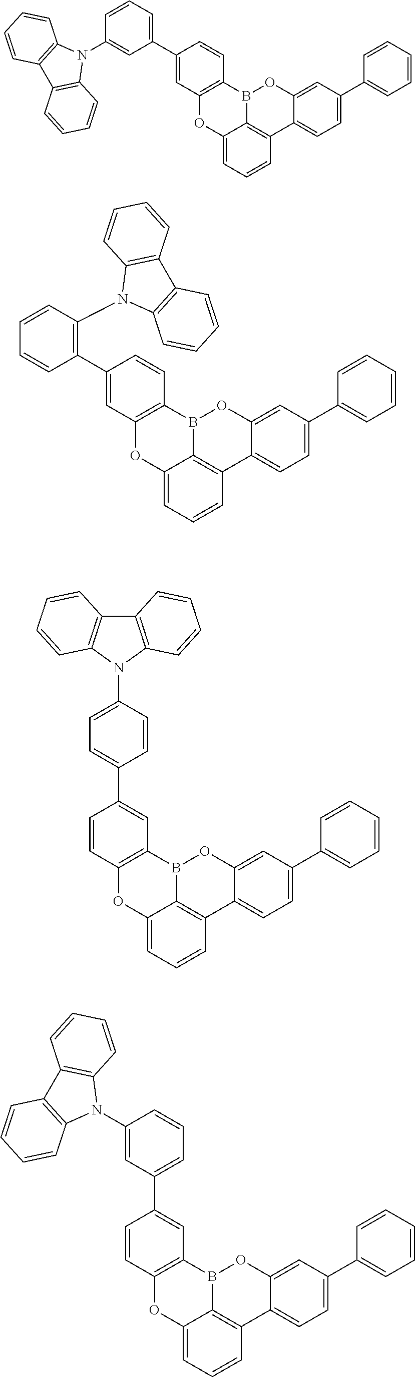 [SMILES: c1ccc(-c2ccc3c(c2)OB2c4ccc(-c5cccc(-n6c7ccccc7c7ccccc76)c5)cc4Oc4cccc-3c42)cc1 ; c1ccc(-c2ccc3c(c2)OB2c4ccc(-c5ccccc5-n5c6ccccc6c6ccccc65)cc4Oc4cccc-3c42)cc1 ; c1ccc(-c2ccc3c(c2)OB2c4cc(-c5ccc(-n6c7ccccc7c7ccccc76)cc5)ccc4Oc4cccc-3c42)cc1 ; c1ccc(-c2ccc3c(c2)OB2c4cc(-c5cccc(-n6c7ccccc7c7ccccc76)c5)ccc4Oc4cccc-3c42)cc1] 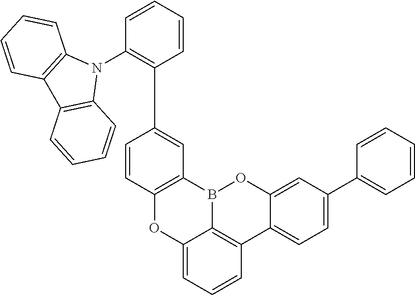 [SMILES: c1ccc(-c2ccc3c(c2)OB2c4cc(-c5ccccc5-n5c6ccccc6c6ccccc65)ccc4Oc4cccc-3c42)cc1] 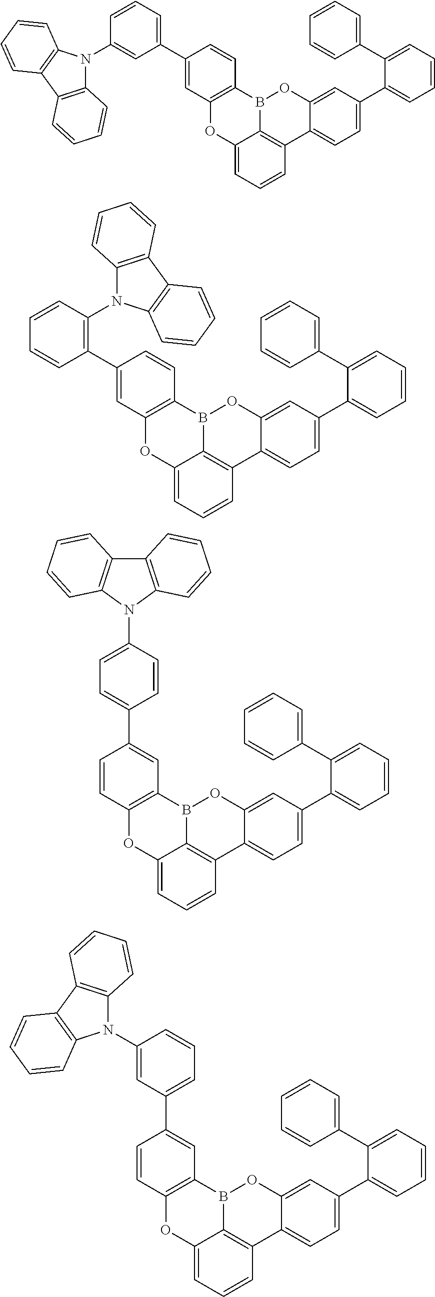 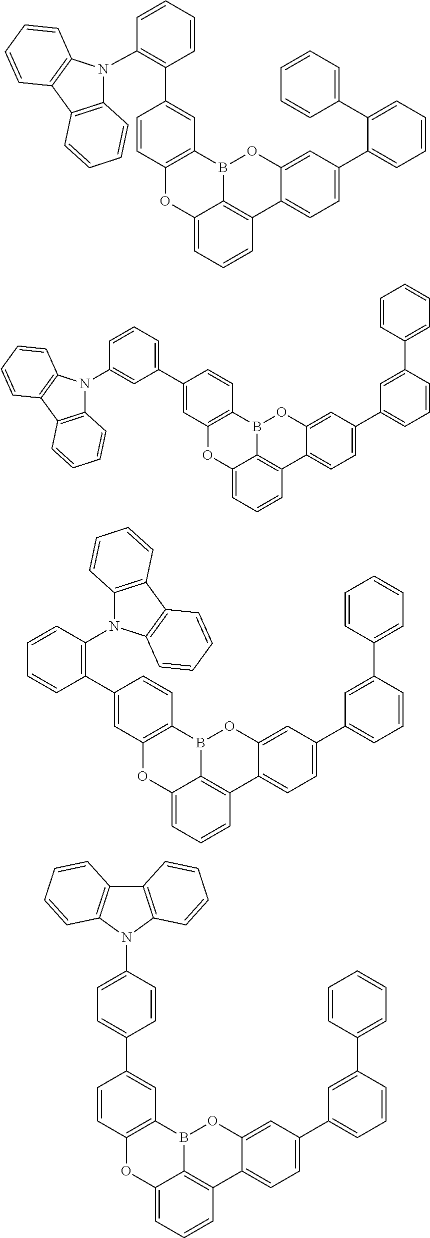 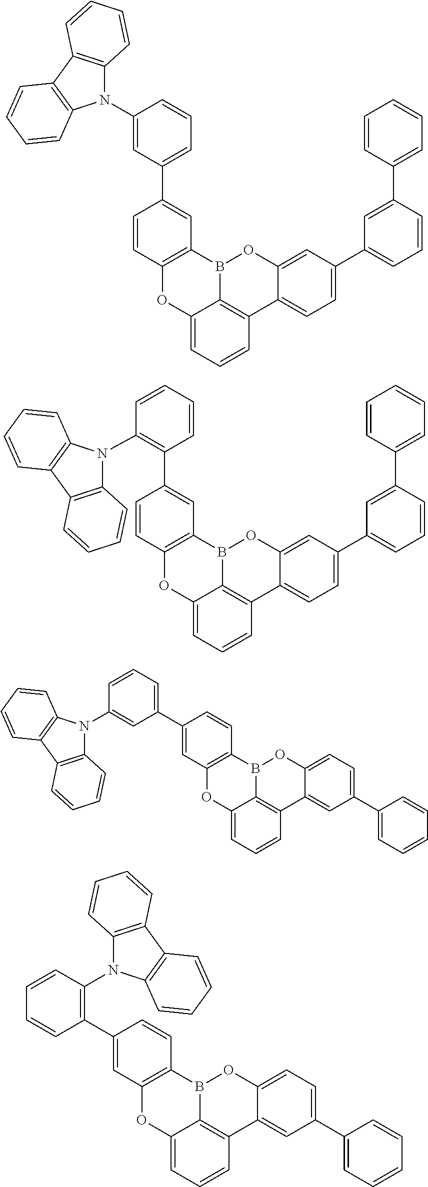 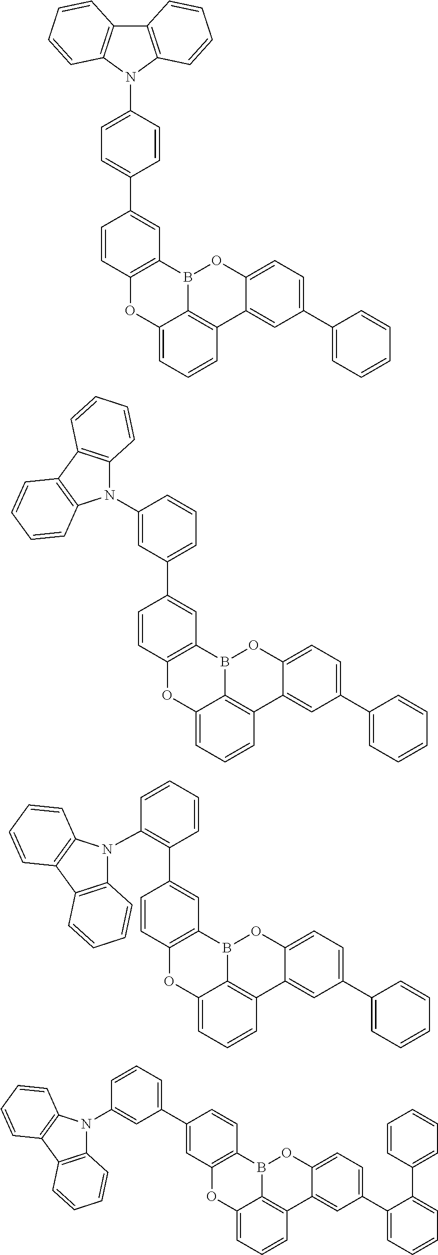 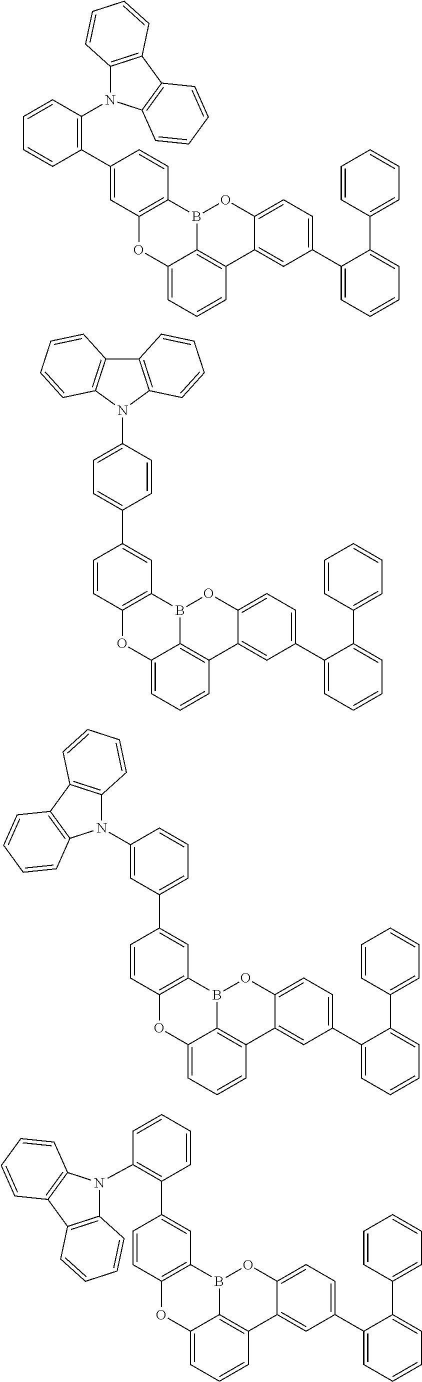 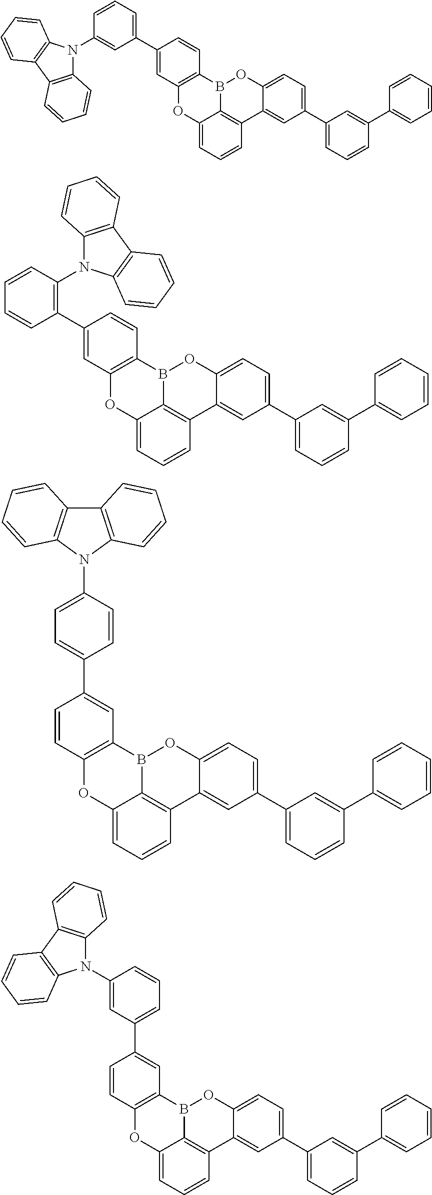 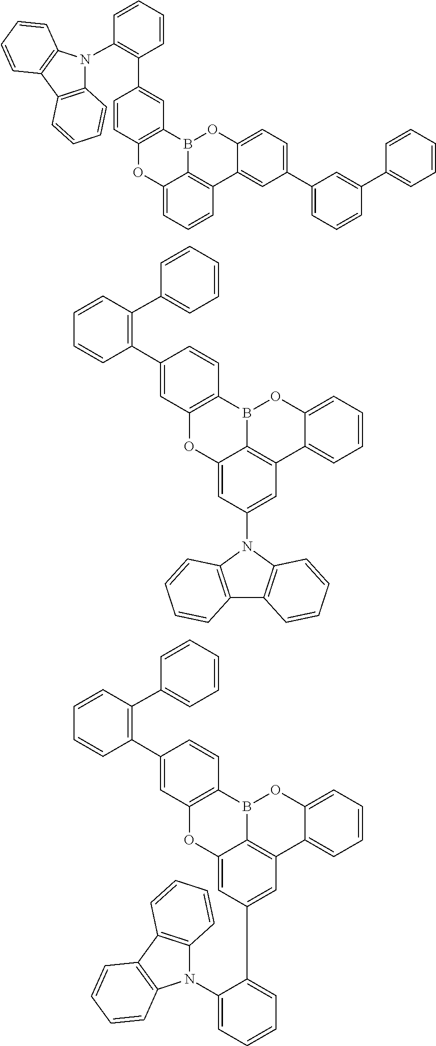 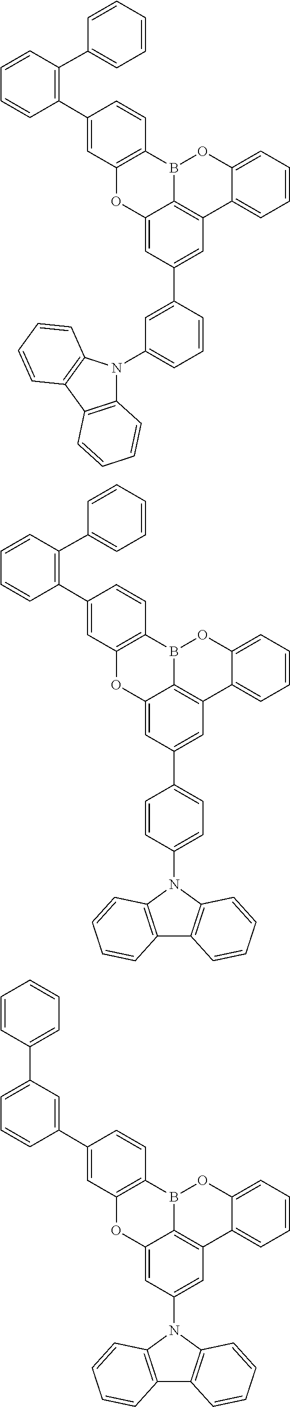 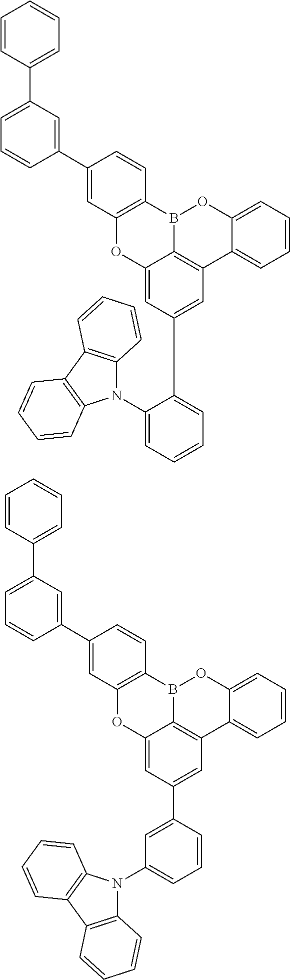 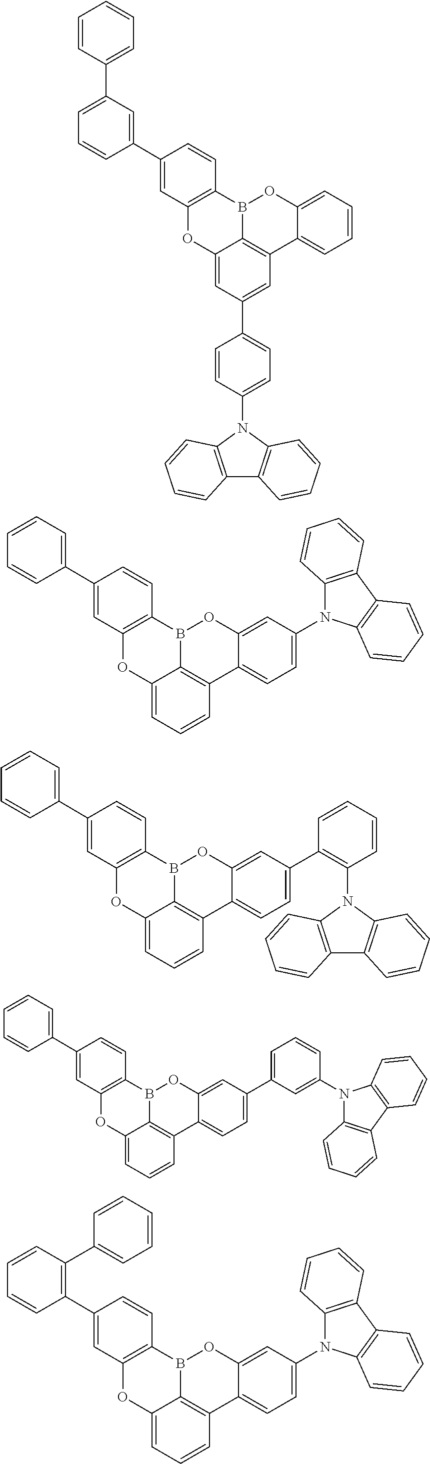 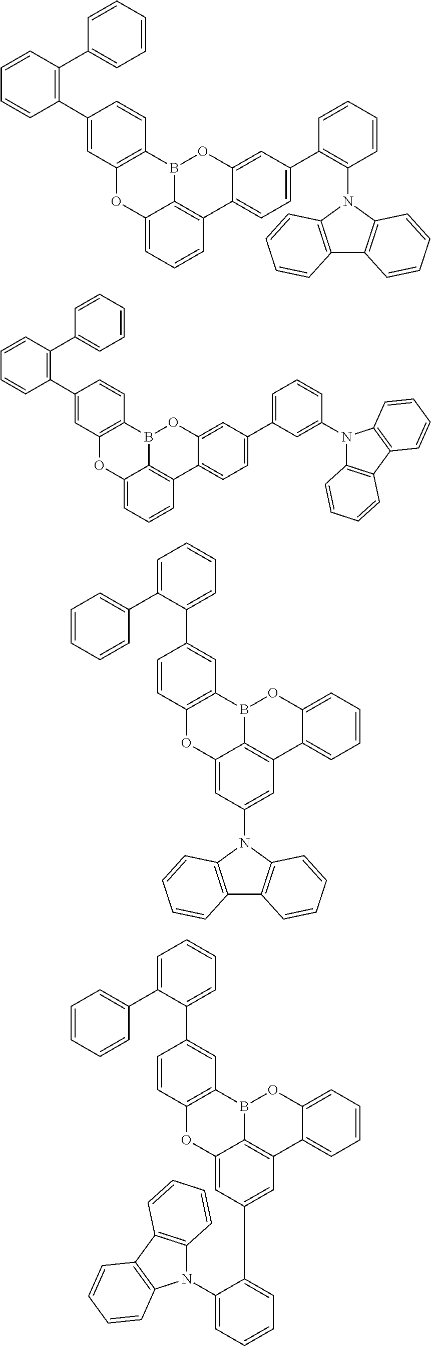 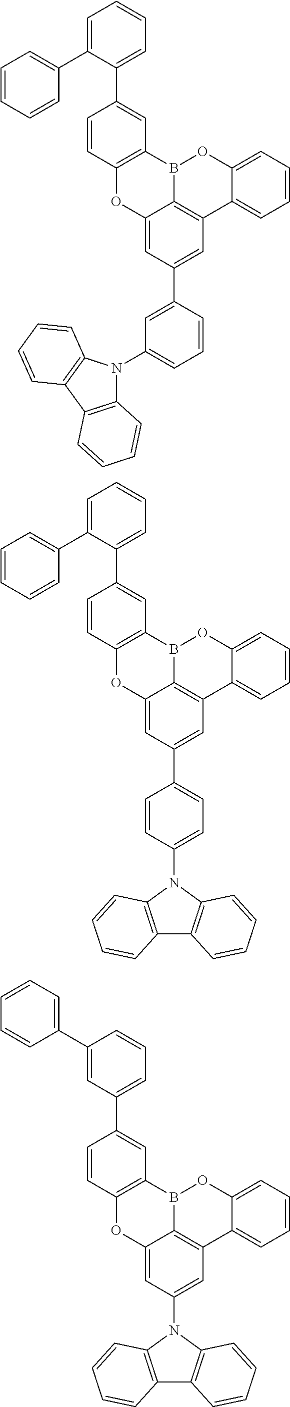 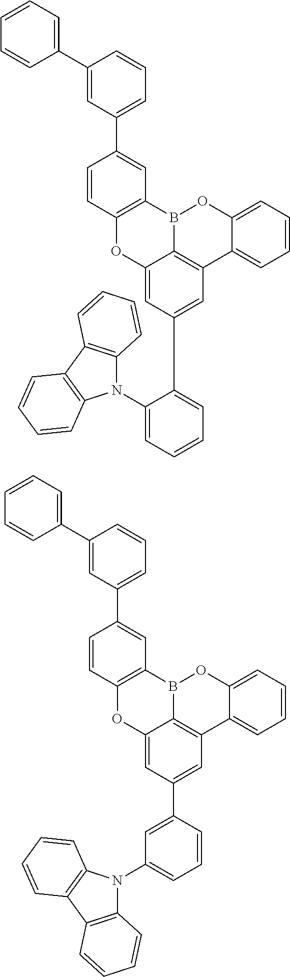 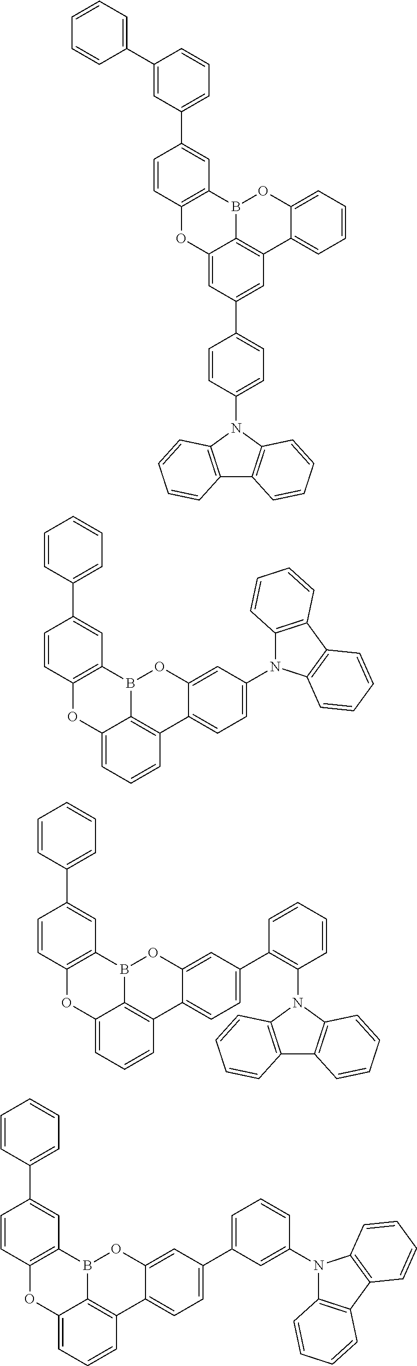 [SMILES: c1ccc(-c2cccc(-c3ccc4c(c3)B3Oc5ccccc5-c5cc(-c6ccc(-n7c8ccccc8c8ccccc87)cc6)cc(c53)O4)c2)cc1 ; c1ccc(-c2ccc3c(c2)B2Oc4cc(-n5c6ccccc6c6ccccc65)ccc4-c4cccc(c42)O3)cc1 ; c1ccc(-c2ccc3c(c2)B2Oc4cc(-c5ccccc5-n5c6ccccc6c6ccccc65)ccc4-c4cccc(c42)O3)cc1 ; c1ccc(-c2ccc3c(c2)B2Oc4cc(-c5cccc(-n6c7ccccc7c7ccccc76)c5)ccc4-c4cccc(c42)O3)cc1] 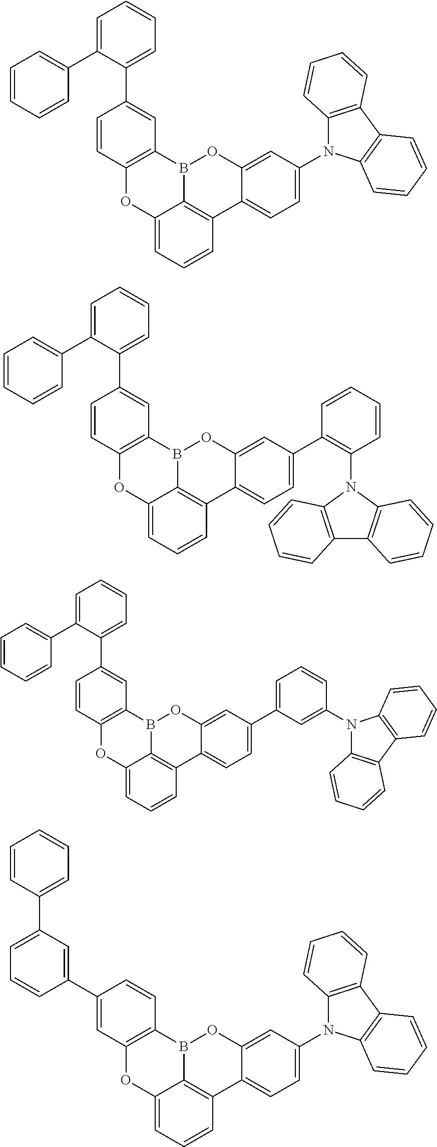 [SMILES: c1ccc(-c2ccccc2-c2ccc3c(c2)B2Oc4cc(-n5c6ccccc6c6ccccc65)ccc4-c4cccc(c42)O3)cc1 ; c1ccc(-c2ccccc2-c2ccc3c(c2)B2Oc4cc(-c5ccccc5-n5c6ccccc6c6ccccc65)ccc4-c4cccc(c42)O3)cc1 ; c1ccc(-c2ccccc2-c2ccc3c(c2)B2Oc4cc(-c5cccc(-n6c7ccccc7c7ccccc76)c5)ccc4-c4cccc(c42)O3)cc1 ; c1ccc(-c2cccc(-c3ccc4c(c3)Oc3cccc5c3B4Oc3cc(-n4c6ccccc6c6ccccc64)ccc3-5)c2)cc1] 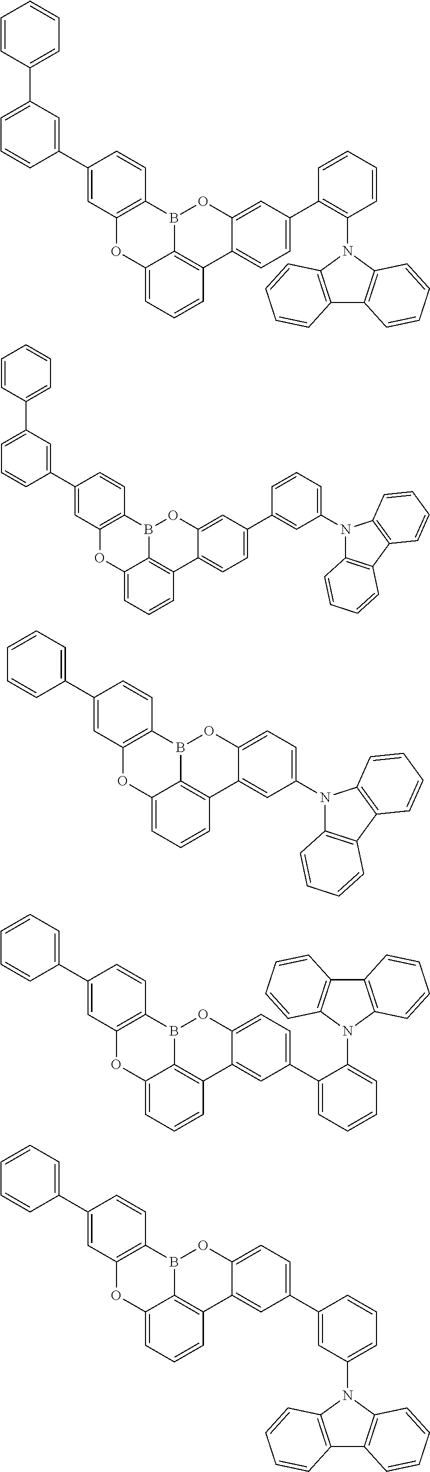 [SMILES: c1ccc(-c2cccc(-c3ccc4c(c3)Oc3cccc5c3B4Oc3cc(-c4ccccc4-n4c6ccccc6c6ccccc64)ccc3-5)c2)cc1 ; c1ccc(-c2cccc(-c3ccc4c(c3)Oc3cccc5c3B4Oc3cc(-c4cccc(-n6c7ccccc7c7ccccc76)c4)ccc3-5)c2)cc1 ; c1ccc(-c2ccc3c(c2)Oc2cccc4c2B3Oc2ccc(-n3c5ccccc5c5ccccc53)cc2-4)cc1 ; c1ccc(-c2ccc3c(c2)Oc2cccc4c2B3Oc2ccc(-c3ccccc3-n3c5ccccc5c5ccccc53)cc2-4)cc1 ; c1ccc(-c2ccc3c(c2)Oc2cccc4c2B3Oc2ccc(-c3cccc(-n5c6ccccc6c6ccccc65)c3)cc2-4)cc1] 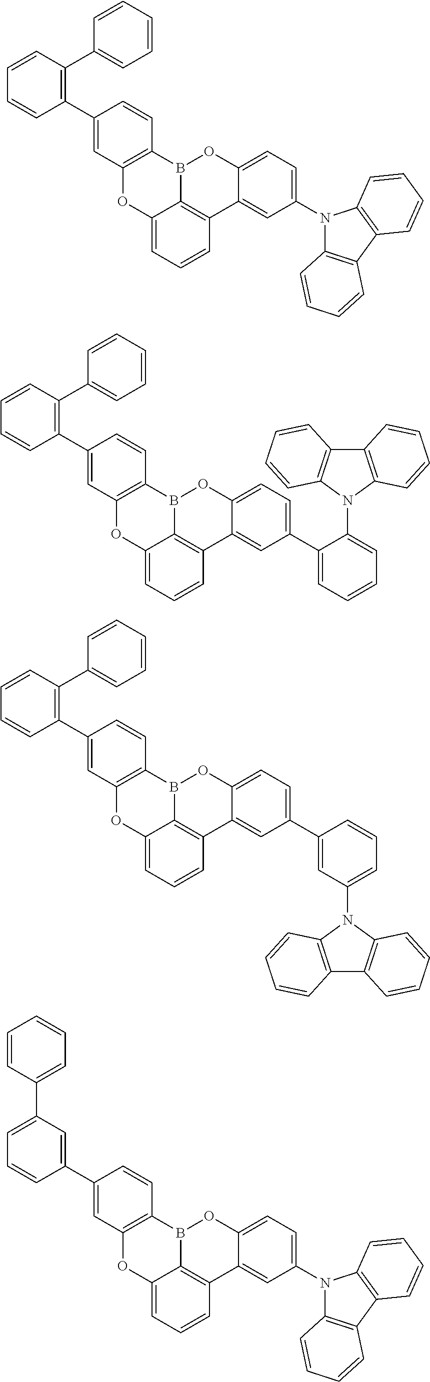 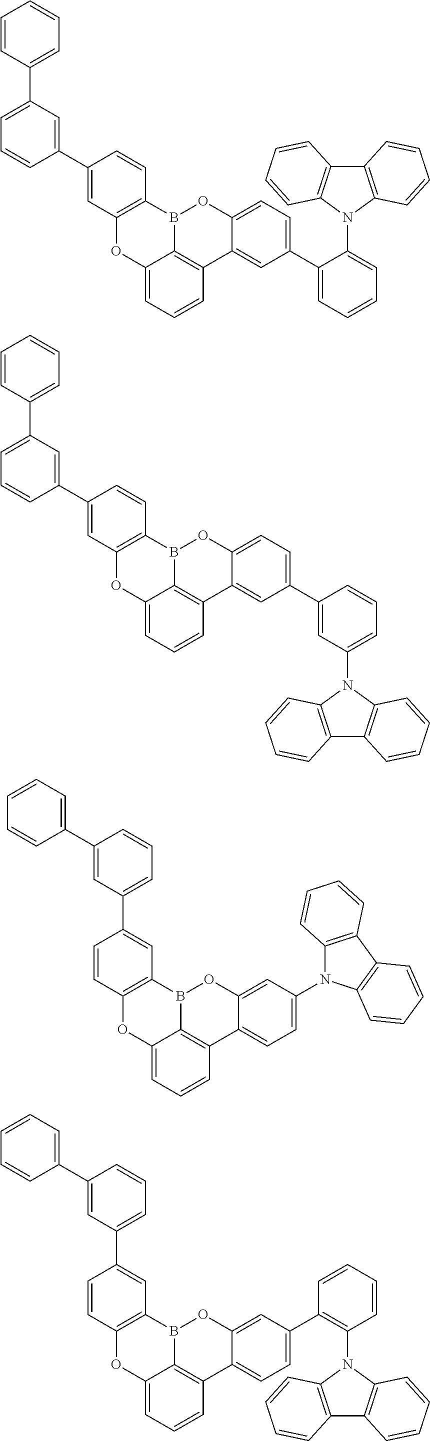 [SMILES: c1ccc(-c2cccc(-c3ccc4c(c3)Oc3cccc5c3B4Oc3ccc(-c4ccccc4-n4c6ccccc6c6ccccc64)cc3-5)c2)cc1 ; c1ccc(-c2cccc(-c3ccc4c(c3)Oc3cccc5c3B4Oc3ccc(-c4cccc(-n6c7ccccc7c7ccccc76)c4)cc3-5)c2)cc1 ; c1ccc(-c2cccc(-c3ccc4c(c3)B3Oc5cc(-n6c7ccccc7c7ccccc76)ccc5-c5cccc(c53)O4)c2)cc1 ; c1ccc(-c2cccc(-c3ccc4c(c3)B3Oc5cc(-c6ccccc6-n6c7ccccc7c7ccccc76)ccc5-c5cccc(c53)O4)c2)cc1] 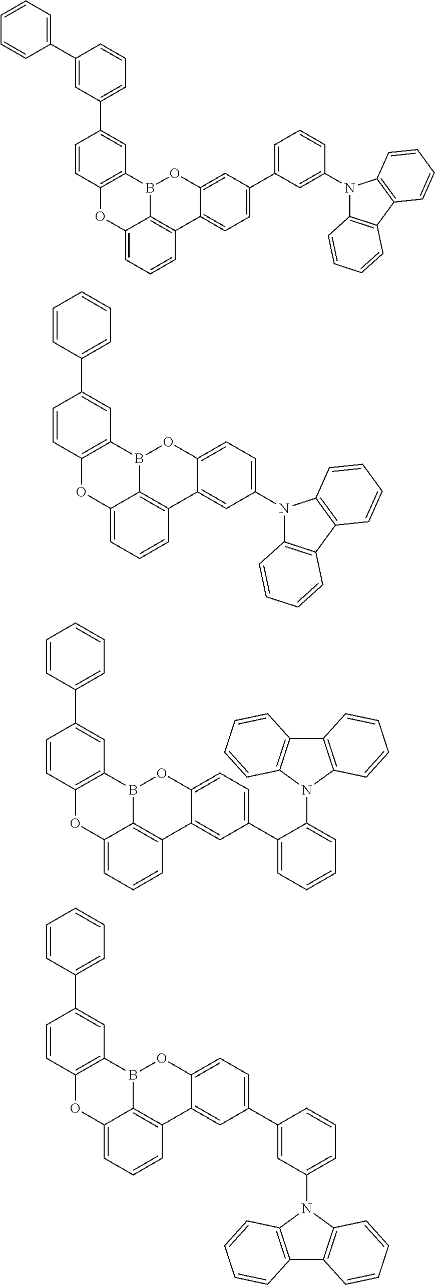 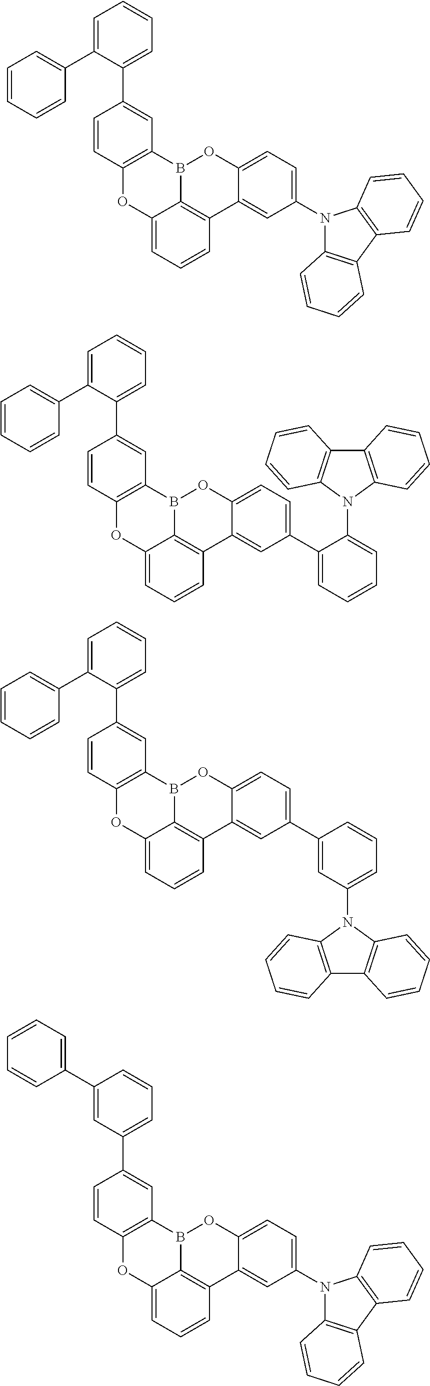 [SMILES: c1ccc(-c2ccccc2-c2ccc3c(c2)B2Oc4ccc(-n5c6ccccc6c6ccccc65)cc4-c4cccc(c42)O3)cc1 ; c1ccc(-c2ccccc2-c2ccc3c(c2)B2Oc4ccc(-c5ccccc5-n5c6ccccc6c6ccccc65)cc4-c4cccc(c42)O3)cc1 ; c1ccc(-c2ccccc2-c2ccc3c(c2)B2Oc4ccc(-c5cccc(-n6c7ccccc7c7ccccc76)c5)cc4-c4cccc(c42)O3)cc1 ; c1ccc(-c2cccc(-c3ccc4c(c3)B3Oc5ccc(-n6c7ccccc7c7ccccc76)cc5-c5cccc(c53)O4)c2)cc1] 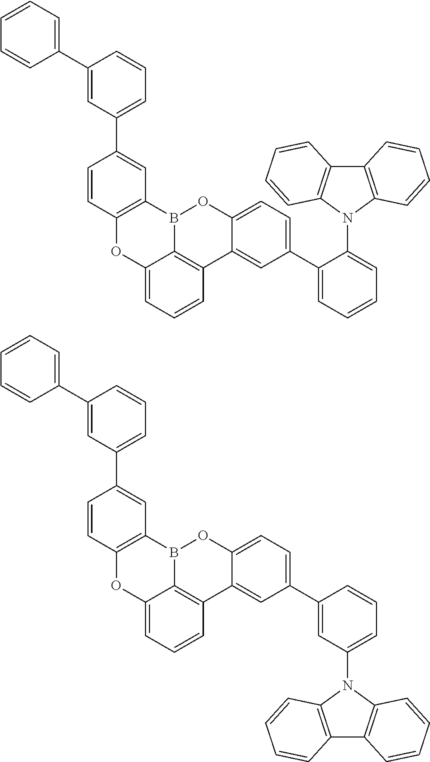 [SMILES: c1ccc(-c2cccc(-c3ccc4c(c3)B3Oc5ccc(-c6ccccc6-n6c7ccccc7c7ccccc76)cc5-c5cccc(c53)O4)c2)cc1 ; c1ccc(-c2cccc(-c3ccc4c(c3)B3Oc5ccc(-c6cccc(-n7c8ccccc8c8ccccc87)c6)cc5-c5cccc(c53)O4)c2)cc1] 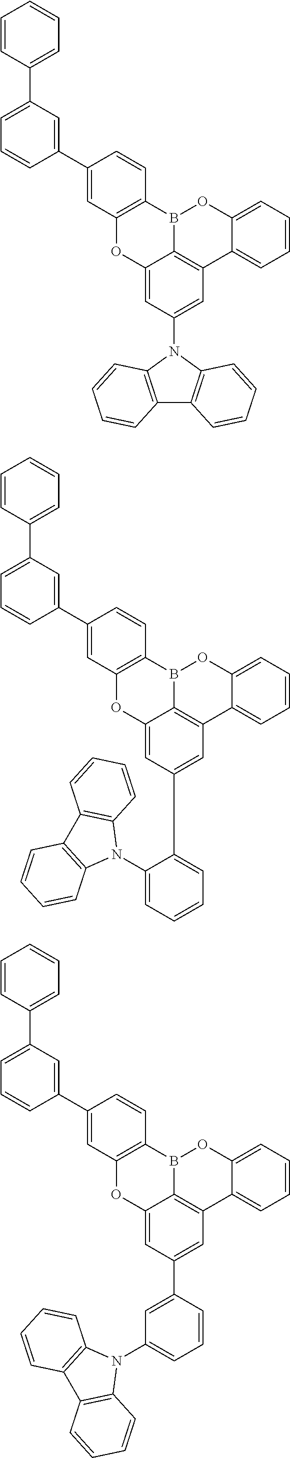 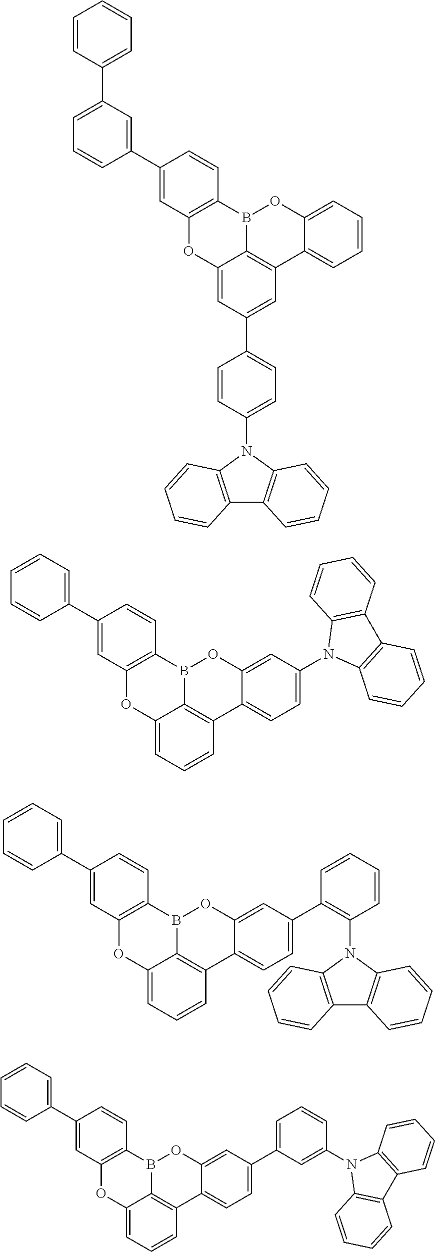 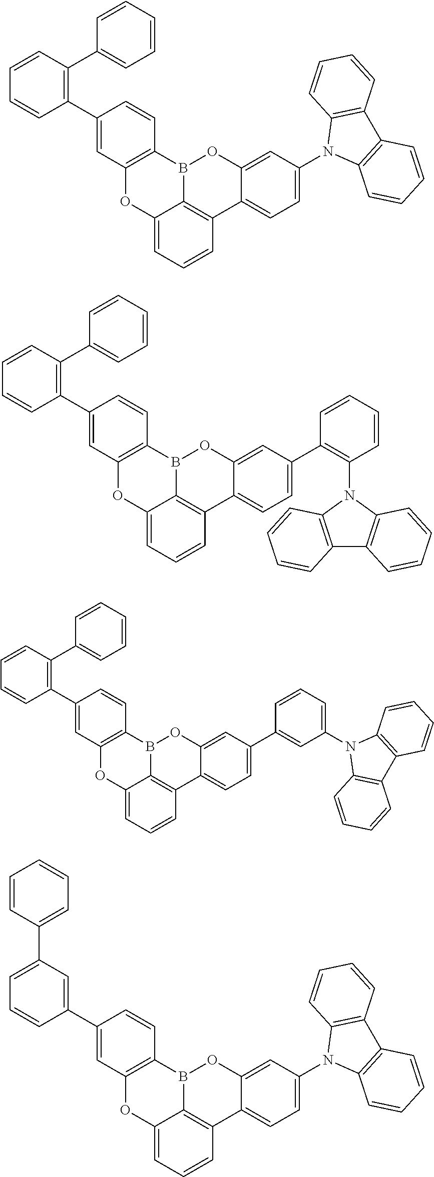 [SMILES: c1ccc(-c2ccccc2-c2ccc3c(c2)Oc2cccc4c2B3Oc2cc(-n3c5ccccc5c5ccccc53)ccc2-4)cc1 ; c1ccc(-c2ccccc2-c2ccc3c(c2)Oc2cccc4c2B3Oc2cc(-c3ccccc3-n3c5ccccc5c5ccccc53)ccc2-4)cc1 ; c1ccc(-c2ccccc2-c2ccc3c(c2)Oc2cccc4c2B3Oc2cc(-c3cccc(-n5c6ccccc6c6ccccc65)c3)ccc2-4)cc1 ; c1ccc(-c2cccc(-c3ccc4c(c3)Oc3cccc5c3B4Oc3cc(-n4c6ccccc6c6ccccc64)ccc3-5)c2)cc1] 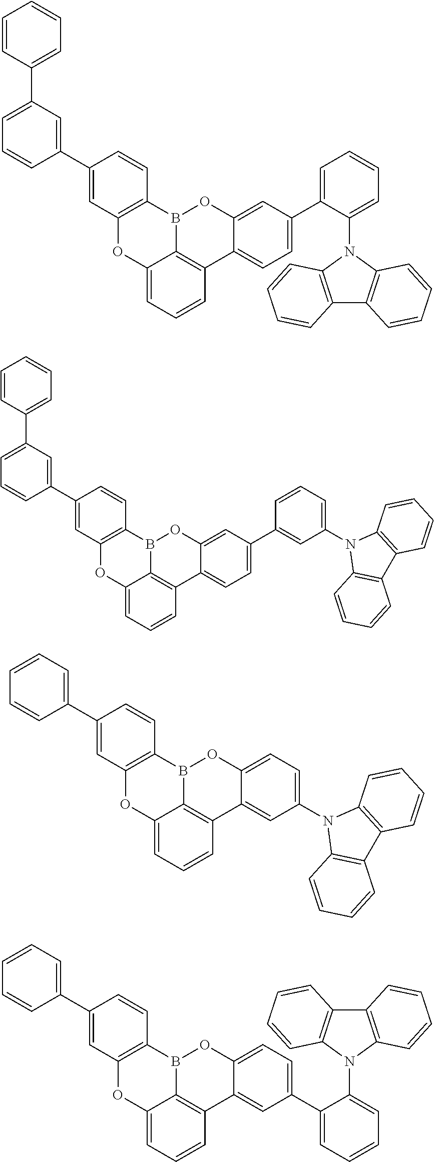 [SMILES: c1ccc(-c2cccc(-c3ccc4c(c3)Oc3cccc5c3B4Oc3cc(-c4ccccc4-n4c6ccccc6c6ccccc64)ccc3-5)c2)cc1 ; c1ccc(-c2cccc(-c3ccc4c(c3)Oc3cccc5c3B4Oc3cc(-c4cccc(-n6c7ccccc7c7ccccc76)c4)ccc3-5)c2)cc1 ; c1ccc(-c2ccc3c(c2)Oc2cccc4c2B3Oc2ccc(-n3c5ccccc5c5ccccc53)cc2-4)cc1 ; c1ccc(-c2ccc3c(c2)Oc2cccc4c2B3Oc2ccc(-c3ccccc3-n3c5ccccc5c5ccccc53)cc2-4)cc1] 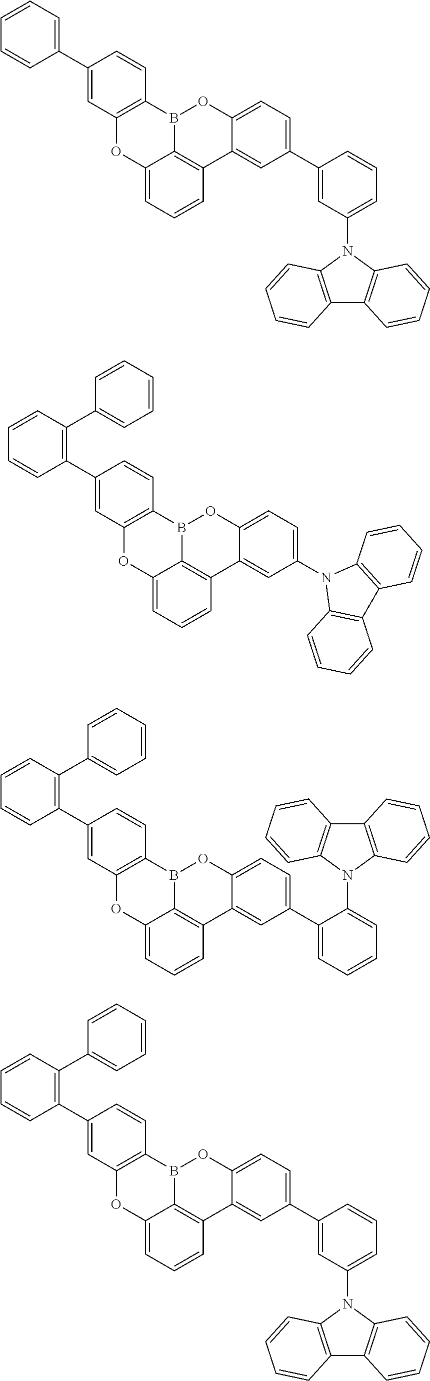 [SMILES: c1ccc(-c2ccc3c(c2)Oc2cccc4c2B3Oc2ccc(-c3cccc(-n5c6ccccc6c6ccccc65)c3)cc2-4)cc1 ; c1ccc(-c2ccccc2-c2ccc3c(c2)Oc2cccc4c2B3Oc2ccc(-n3c5ccccc5c5ccccc53)cc2-4)cc1 ; c1ccc(-c2ccccc2-c2ccc3c(c2)Oc2cccc4c2B3Oc2ccc(-c3ccccc3-n3c5ccccc5c5ccccc53)cc2-4)cc1 ; c1ccc(-c2ccccc2-c2ccc3c(c2)Oc2cccc4c2B3Oc2ccc(-c3cccc(-n5c6ccccc6c6ccccc65)c3)cc2-4)cc1] 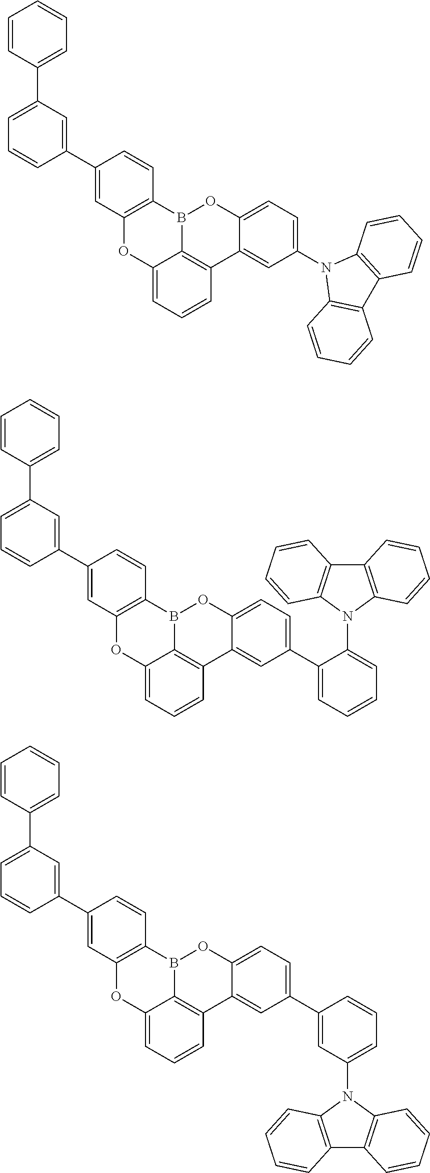 [SMILES: c1ccc(-c2cccc(-c3ccc4c(c3)Oc3cccc5c3B4Oc3ccc(-n4c6ccccc6c6ccccc64)cc3-5)c2)cc1 ; c1ccc(-c2cccc(-c3ccc4c(c3)Oc3cccc5c3B4Oc3ccc(-c4ccccc4-n4c6ccccc6c6ccccc64)cc3-5)c2)cc1 ; c1ccc(-c2cccc(-c3ccc4c(c3)Oc3cccc5c3B4Oc3ccc(-c4cccc(-n6c7ccccc7c7ccccc76)c4)cc3-5)c2)cc1] 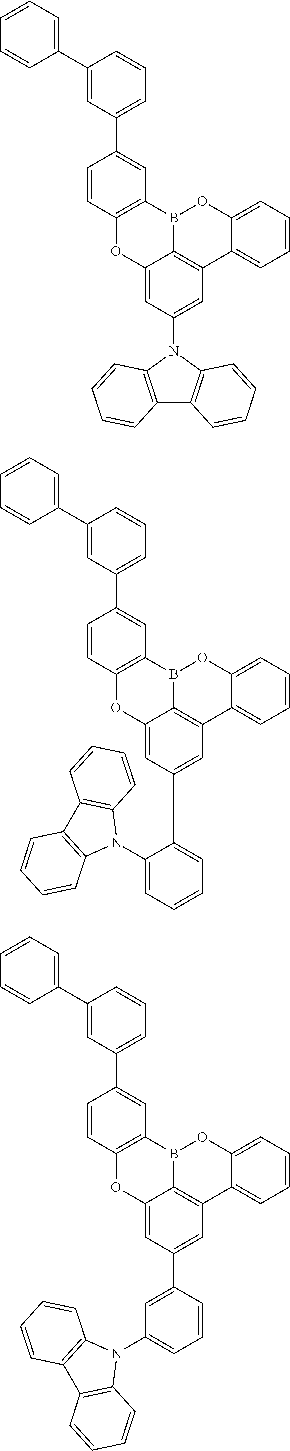 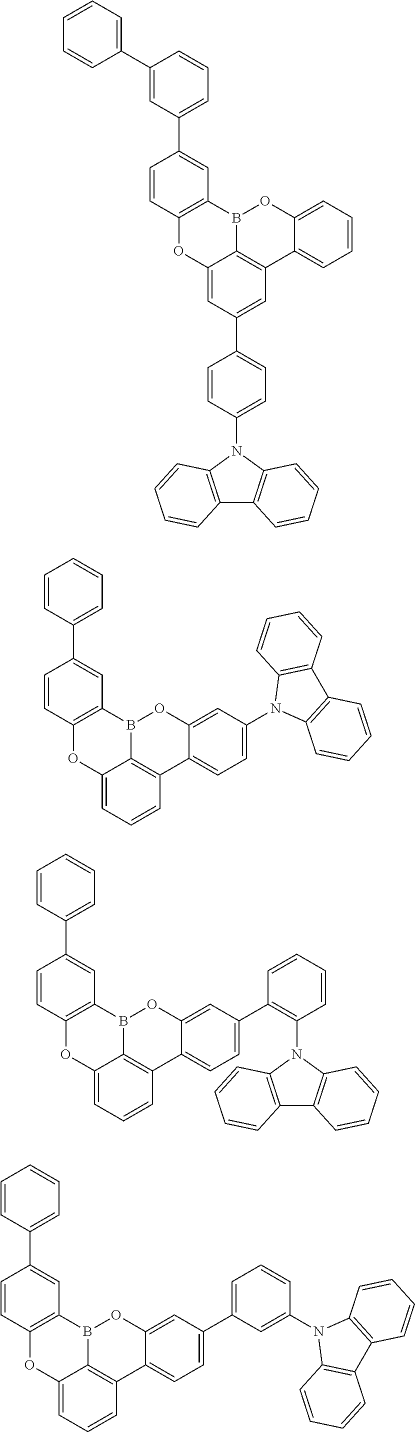 [SMILES: c1ccc(-c2cccc(-c3ccc4c(c3)B3Oc5ccccc5-c5cc(-c6ccc(-n7c8ccccc8c8ccccc87)cc6)cc(c53)O4)c2)cc1 ; c1ccc(-c2ccc3c(c2)B2Oc4cc(-n5c6ccccc6c6ccccc65)ccc4-c4cccc(c42)O3)cc1 ; c1ccc(-c2ccc3c(c2)B2Oc4cc(-c5ccccc5-n5c6ccccc6c6ccccc65)ccc4-c4cccc(c42)O3)cc1 ; c1ccc(-c2ccc3c(c2)B2Oc4cc(-c5cccc(-n6c7ccccc7c7ccccc76)c5)ccc4-c4cccc(c42)O3)cc1] 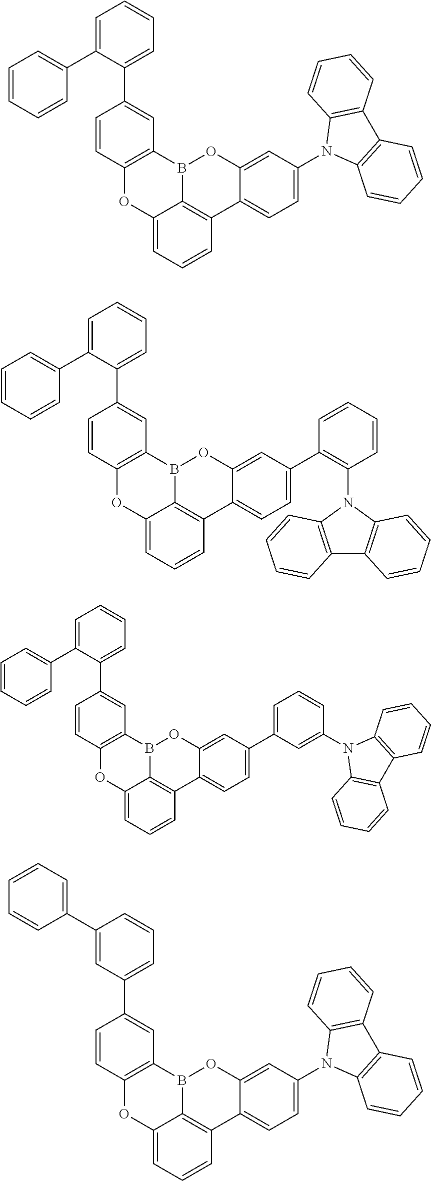 [SMILES: c1ccc(-c2ccccc2-c2ccc3c(c2)B2Oc4cc(-n5c6ccccc6c6ccccc65)ccc4-c4cccc(c42)O3)cc1 ; c1ccc(-c2ccccc2-c2ccc3c(c2)B2Oc4cc(-c5ccccc5-n5c6ccccc6c6ccccc65)ccc4-c4cccc(c42)O3)cc1 ; c1ccc(-c2ccccc2-c2ccc3c(c2)B2Oc4cc(-c5cccc(-n6c7ccccc7c7ccccc76)c5)ccc4-c4cccc(c42)O3)cc1 ; c1ccc(-c2cccc(-c3ccc4c(c3)B3Oc5cc(-n6c7ccccc7c7ccccc76)ccc5-c5cccc(c53)O4)c2)cc1] 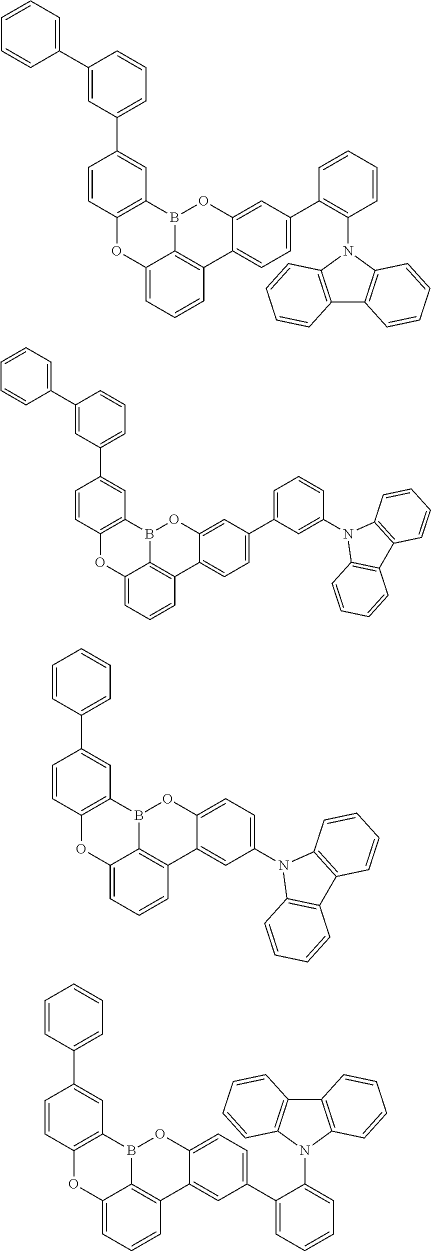 [SMILES: c1ccc(-c2cccc(-c3ccc4c(c3)B3Oc5cc(-c6ccccc6-n6c7ccccc7c7ccccc76)ccc5-c5cccc(c53)O4)c2)cc1 ; c1ccc(-c2cccc(-c3ccc4c(c3)B3Oc5cc(-c6cccc(-n7c8ccccc8c8ccccc87)c6)ccc5-c5cccc(c53)O4)c2)cc1 ; c1ccc(-c2ccc3c(c2)B2Oc4ccc(-n5c6ccccc6c6ccccc65)cc4-c4cccc(c42)O3)cc1 ; c1ccc(-c2ccc3c(c2)B2Oc4ccc(-c5ccccc5-n5c6ccccc6c6ccccc65)cc4-c4cccc(c42)O3)cc1] 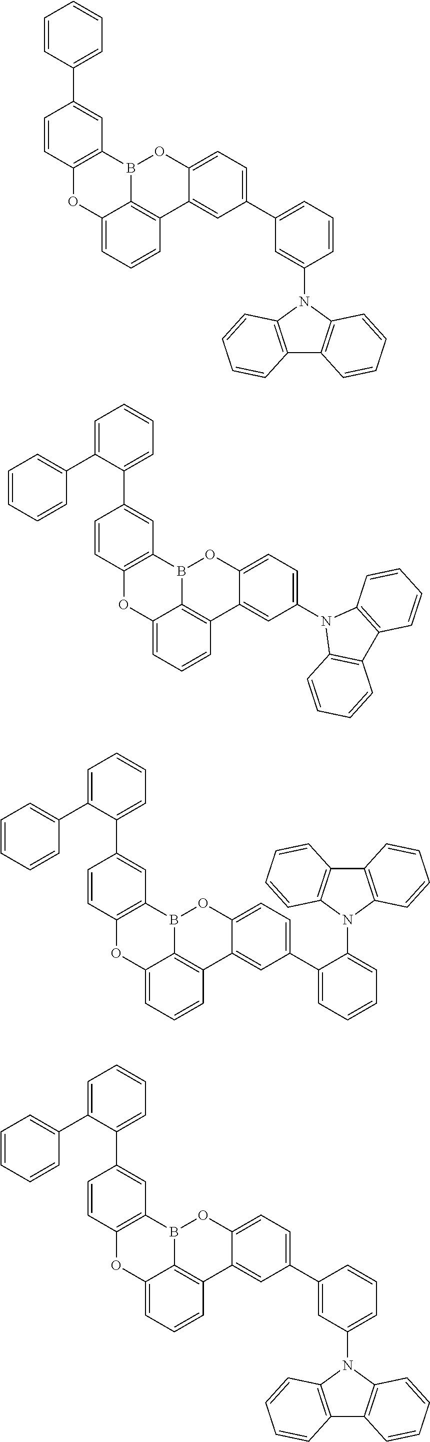 [SMILES: c1ccc(-c2ccc3c(c2)B2Oc4ccc(-c5cccc(-n6c7ccccc7c7ccccc76)c5)cc4-c4cccc(c42)O3)cc1 ; c1ccc(-c2ccccc2-c2ccc3c(c2)B2Oc4ccc(-n5c6ccccc6c6ccccc65)cc4-c4cccc(c42)O3)cc1 ; c1ccc(-c2ccccc2-c2ccc3c(c2)B2Oc4ccc(-c5ccccc5-n5c6ccccc6c6ccccc65)cc4-c4cccc(c42)O3)cc1 ; c1ccc(-c2ccccc2-c2ccc3c(c2)B2Oc4ccc(-c5cccc(-n6c7ccccc7c7ccccc76)c5)cc4-c4cccc(c42)O3)cc1] 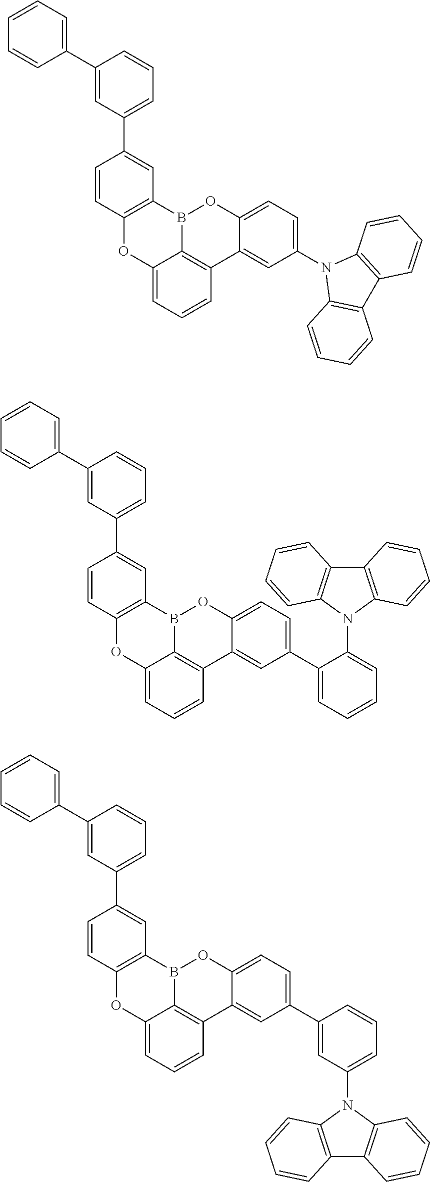 [SMILES: c1ccc(-c2cccc(-c3ccc4c(c3)B3Oc5ccc(-n6c7ccccc7c7ccccc76)cc5-c5cccc(c53)O4)c2)cc1 ; c1ccc(-c2cccc(-c3ccc4c(c3)B3Oc5ccc(-c6ccccc6-n6c7ccccc7c7ccccc76)cc5-c5cccc(c53)O4)c2)cc1 ; c1ccc(-c2cccc(-c3ccc4c(c3)B3Oc5ccc(-c6cccc(-n7c8ccccc8c8ccccc87)c6)cc5-c5cccc(c53)O4)c2)cc1] 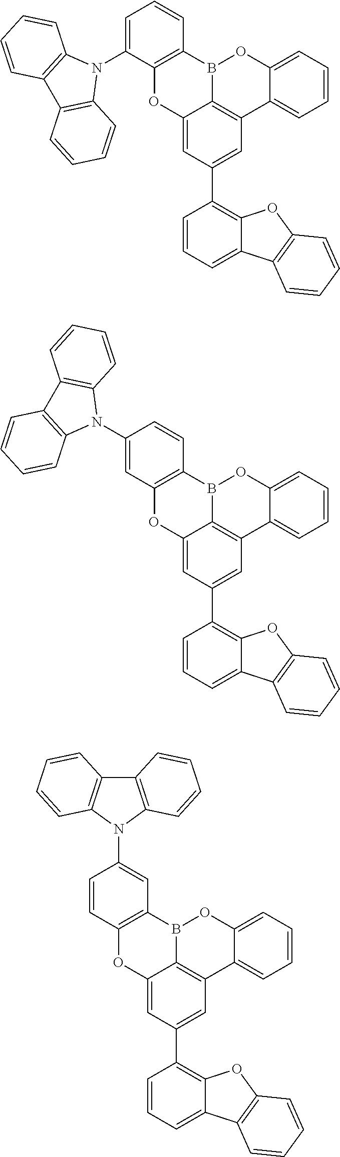 [SMILES: c1ccc2c(c1)OB1c3cccc(-n4c5ccccc5c5ccccc54)c3Oc3cc(-c4cccc5c4oc4ccccc45)cc-2c31 ; c1ccc2c(c1)OB1c3ccc(-n4c5ccccc5c5ccccc54)cc3Oc3cc(-c4cccc5c4oc4ccccc45)cc-2c31 ; c1ccc2c(c1)OB1c3cc(-n4c5ccccc5c5ccccc54)ccc3Oc3cc(-c4cccc5c4oc4ccccc45)cc-2c31] 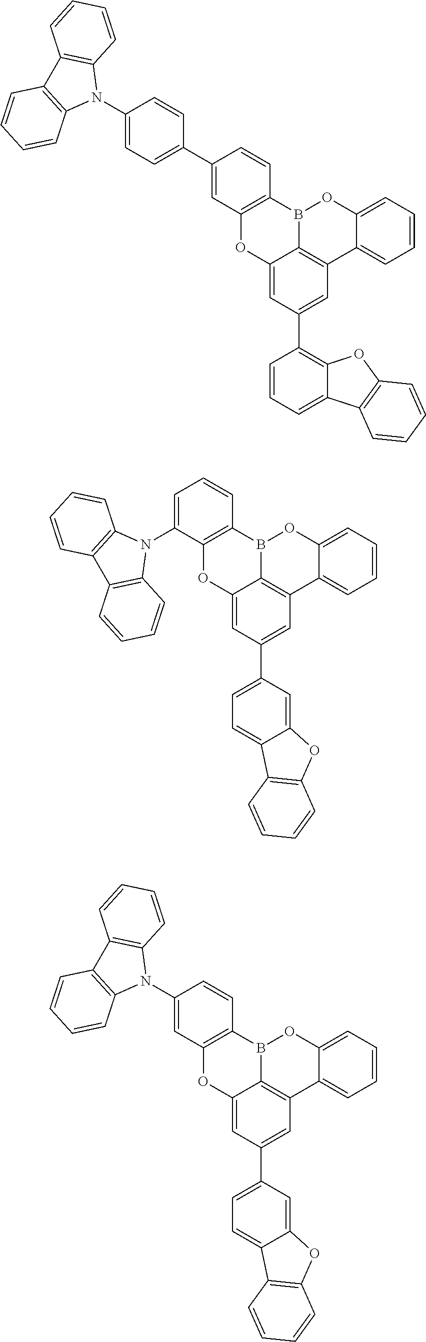 [SMILES: c1ccc2c(c1)OB1c3ccc(-c4ccc(-n5c6ccccc6c6ccccc65)cc4)cc3Oc3cc(-c4cccc5c4oc4ccccc45)cc-2c31 ; c1ccc2c(c1)OB1c3cccc(-n4c5ccccc5c5ccccc54)c3Oc3cc(-c4ccc5c(c4)oc4ccccc45)cc-2c31 ; c1ccc2c(c1)OB1c3ccc(-n4c5ccccc5c5ccccc54)cc3Oc3cc(-c4ccc5c(c4)oc4ccccc45)cc-2c31] 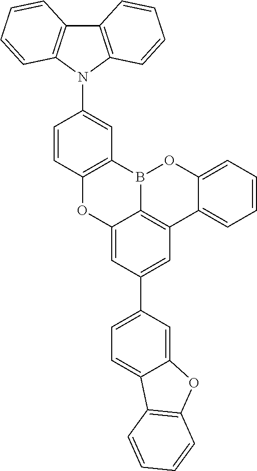 [SMILES: c1ccc2c(c1)OB1c3cc(-n4c5ccccc5c5ccccc54)ccc3Oc3cc(-c4ccc5c(c4)oc4ccccc45)cc-2c31] 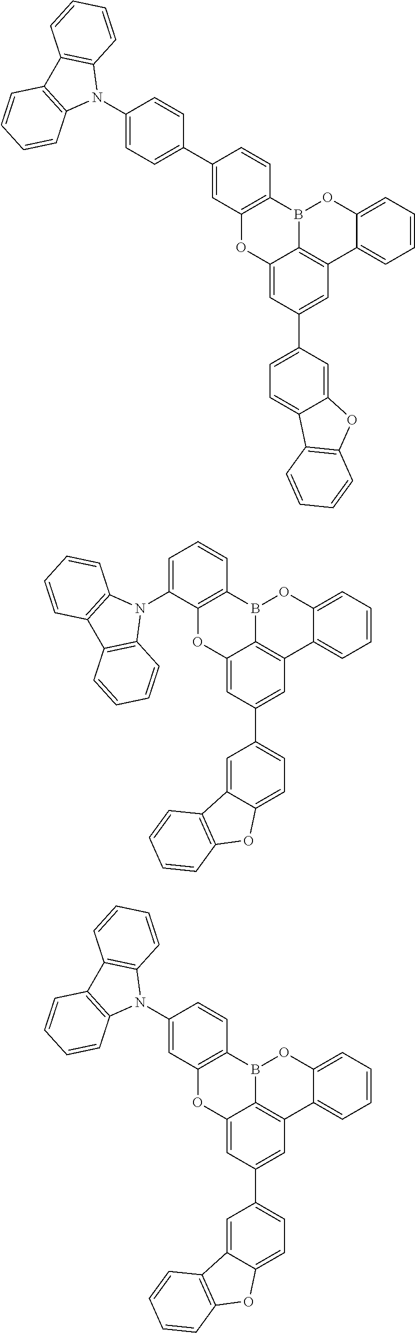 [SMILES: c1ccc2c(c1)OB1c3ccc(-c4ccc(-n5c6ccccc6c6ccccc65)cc4)cc3Oc3cc(-c4ccc5c(c4)oc4ccccc45)cc-2c31 ; c1ccc2c(c1)OB1c3cccc(-n4c5ccccc5c5ccccc54)c3Oc3cc(-c4ccc5oc6ccccc6c5c4)cc-2c31 ; c1ccc2c(c1)OB1c3ccc(-n4c5ccccc5c5ccccc54)cc3Oc3cc(-c4ccc5oc6ccccc6c5c4)cc-2c31] 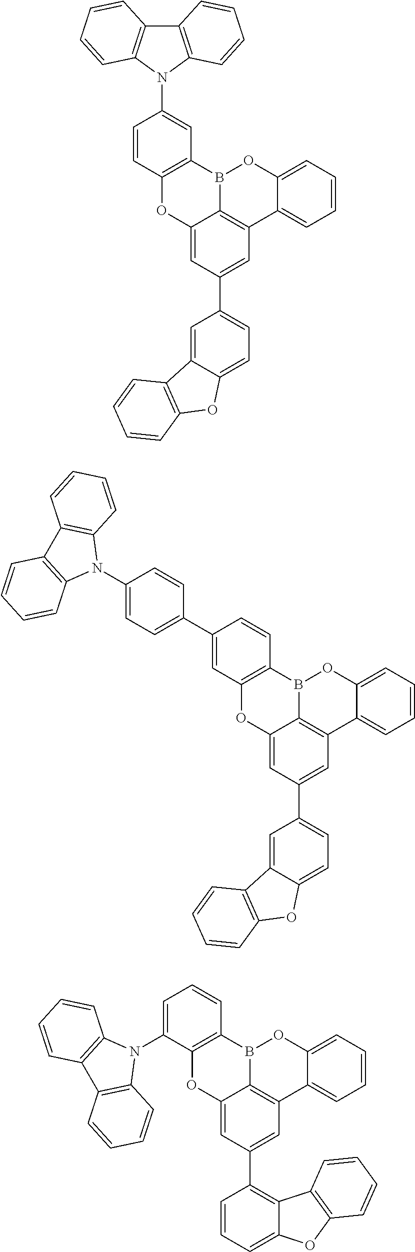 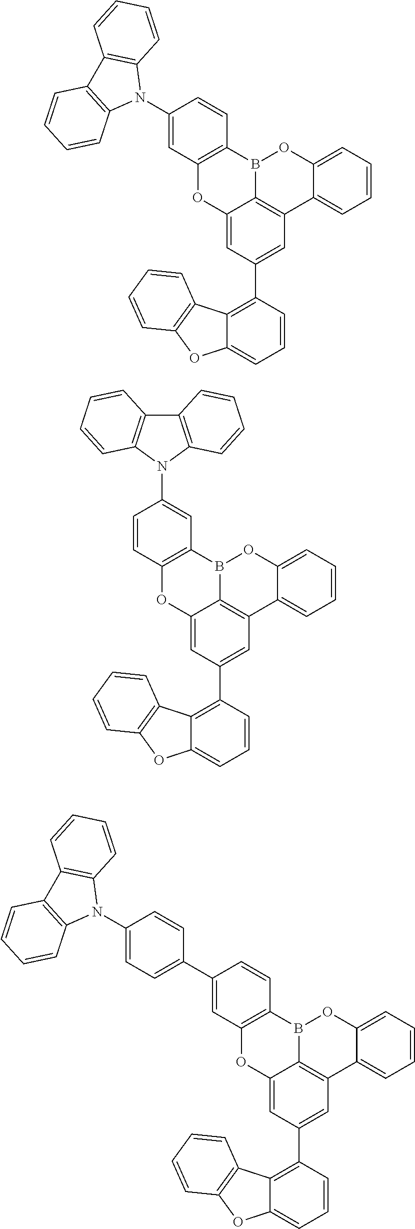 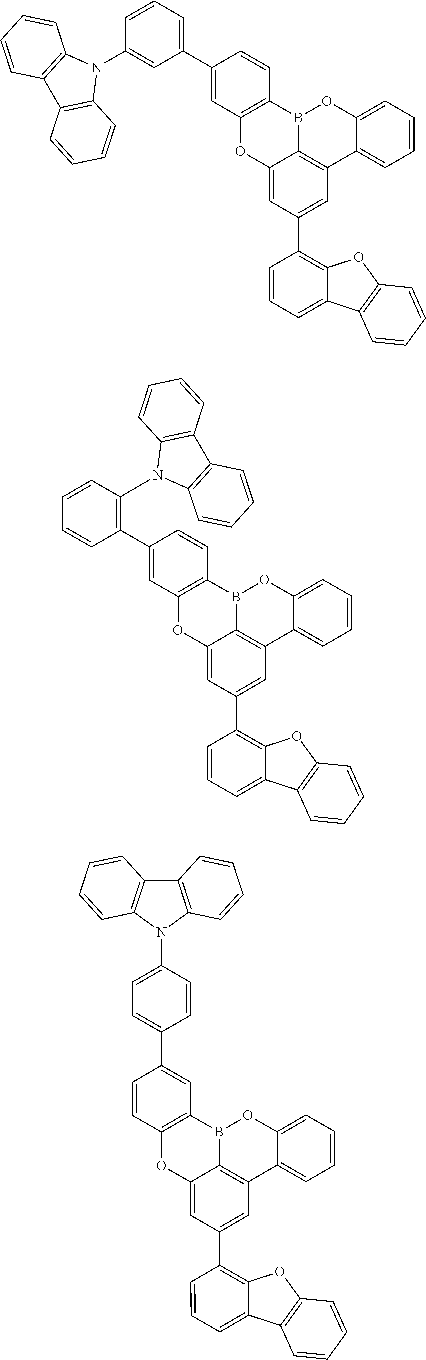 [SMILES: c1cc(-c2ccc3c(c2)Oc2cc(-c4cccc5c4oc4ccccc45)cc4c2B3Oc2ccccc2-4)cc(-n2c3ccccc3c3ccccc32)c1 ; c1ccc2c(c1)OB1c3ccc(-c4ccccc4-n4c5ccccc5c5ccccc54)cc3Oc3cc(-c4cccc5c4oc4ccccc45)cc-2c31 ; c1ccc2c(c1)OB1c3cc(-c4ccc(-n5c6ccccc6c6ccccc65)cc4)ccc3Oc3cc(-c4cccc5c4oc4ccccc45)cc-2c31] 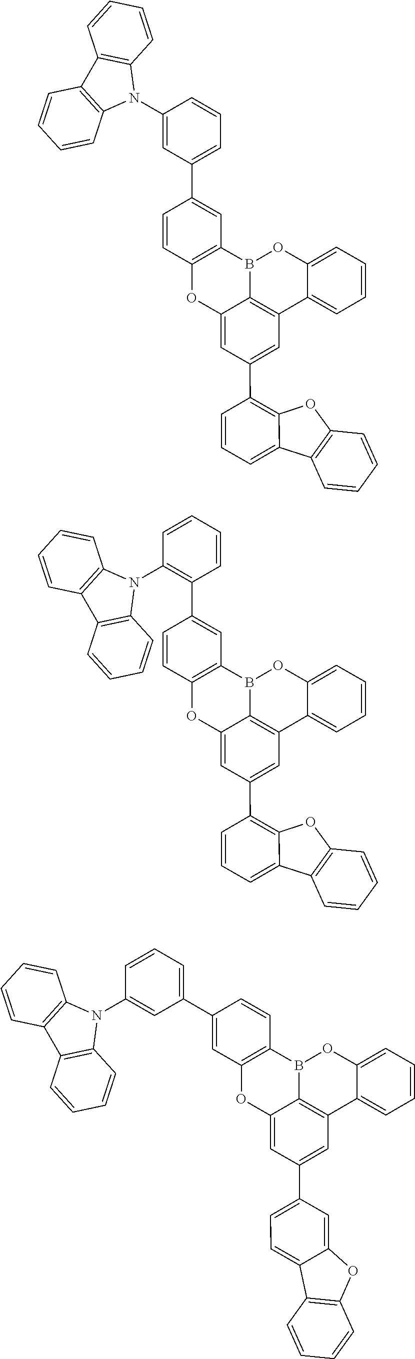 [SMILES: c1cc(-c2ccc3c(c2)B2Oc4ccccc4-c4cc(-c5cccc6c5oc5ccccc56)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-c4cccc5c4oc4ccccc45)cc-2c31 ; c1cc(-c2ccc3c(c2)Oc2cc(-c4ccc5c(c4)oc4ccccc45)cc4c2B3Oc2ccccc2-4)cc(-n2c3ccccc3c3ccccc32)c1] 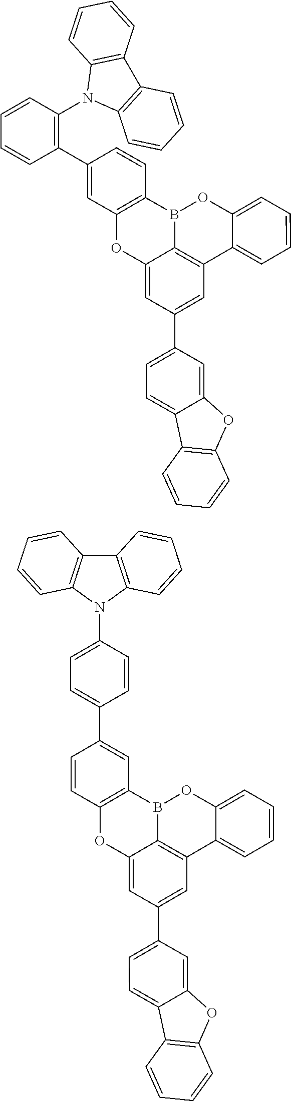 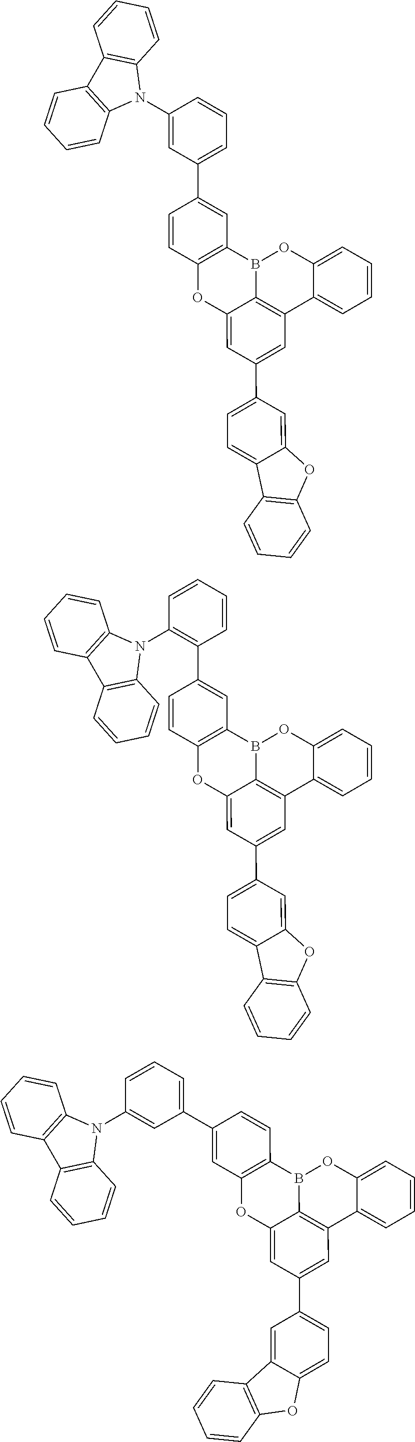 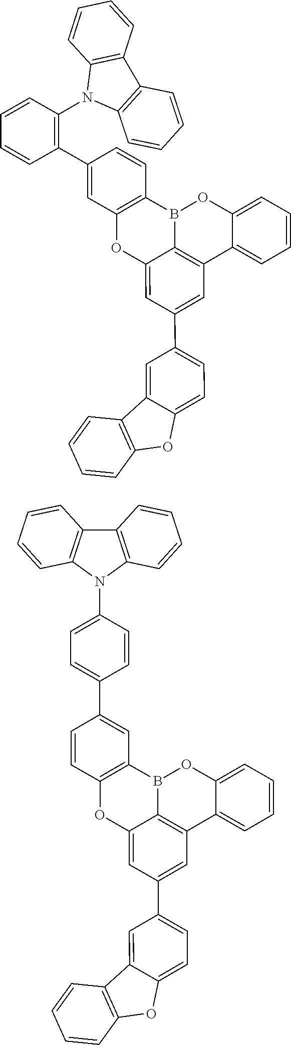 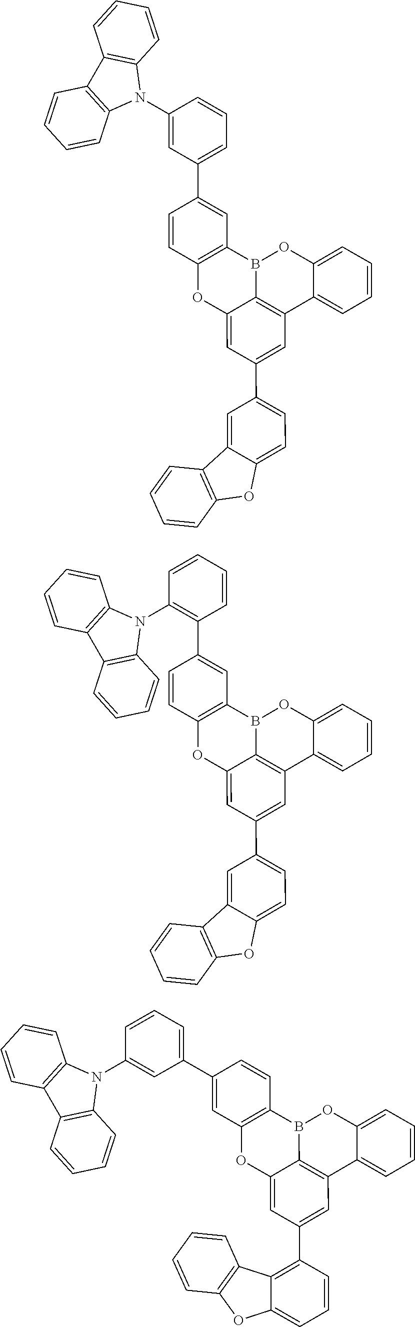 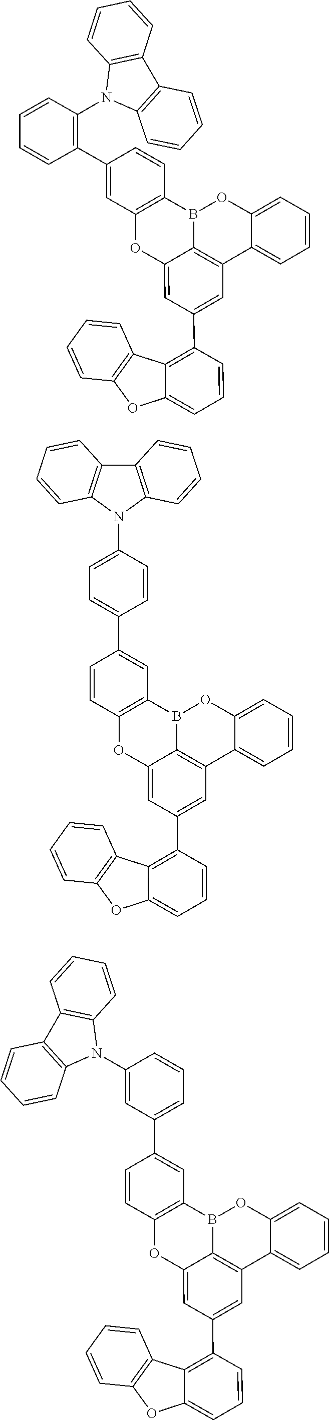 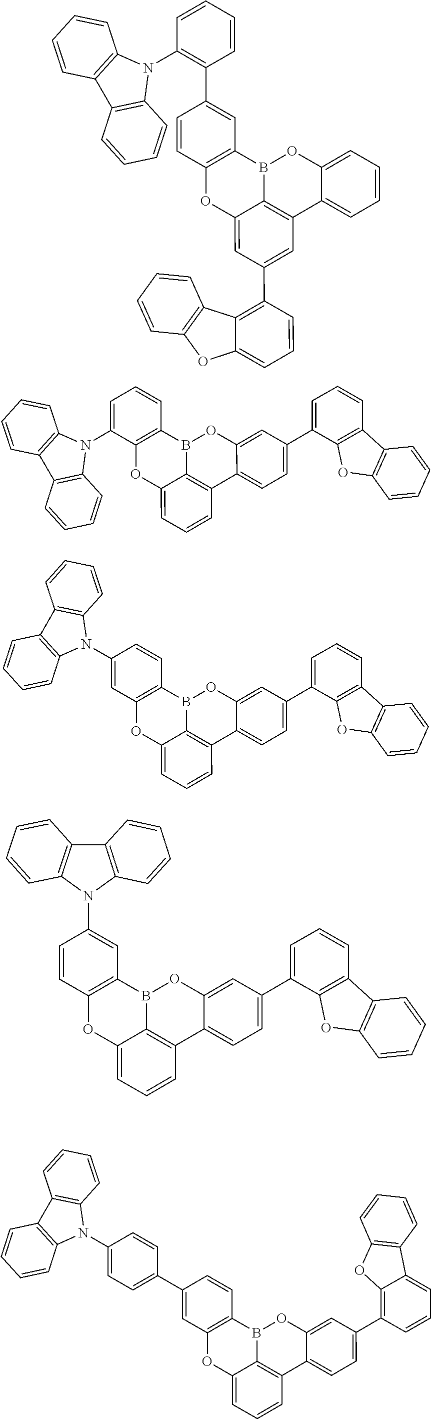 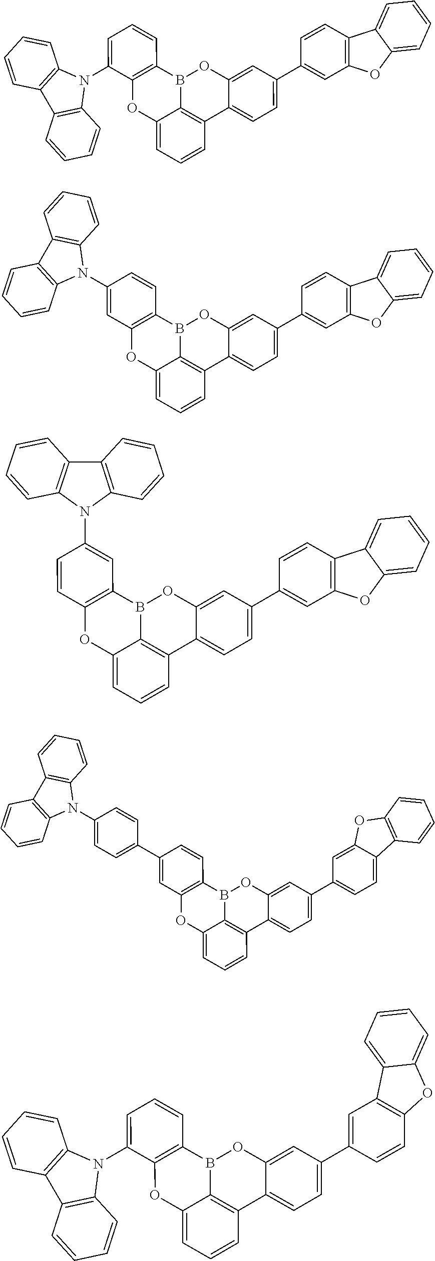 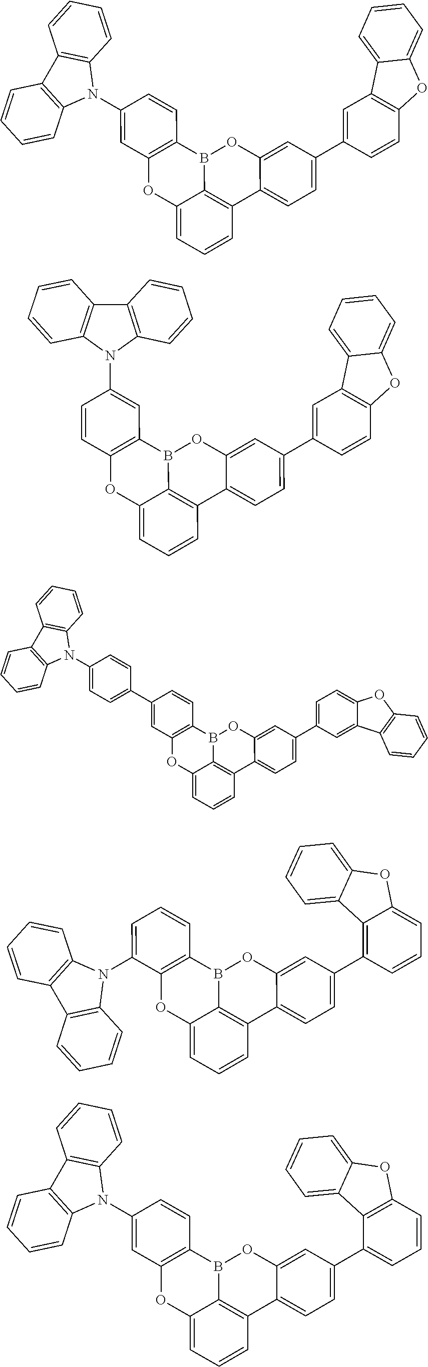 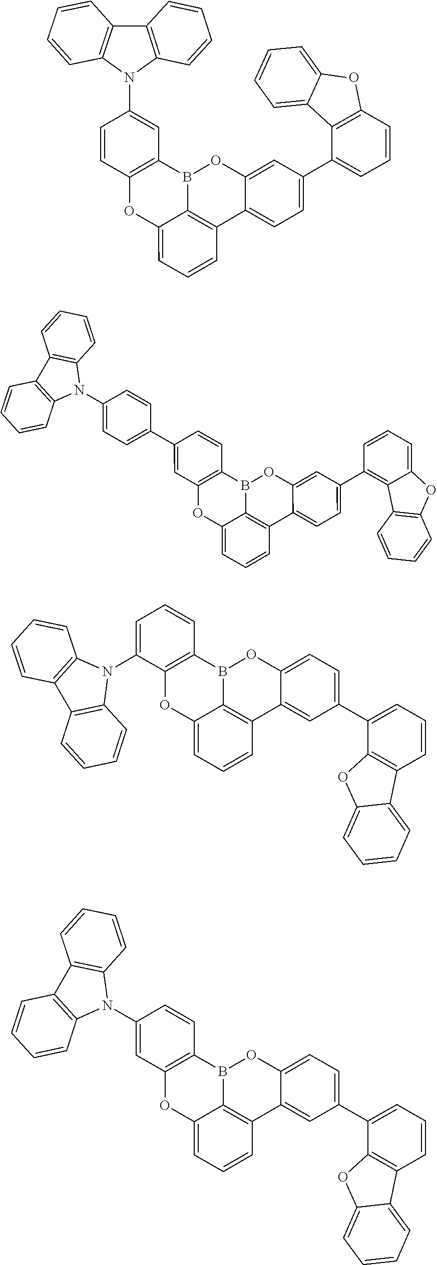 [SMILES: c1cc2c3c(c1)-c1ccc(-c4cccc5oc6ccccc6c45)cc1OB3c1cc(-n3c4ccccc4c4ccccc43)ccc1O2 ; c1cc2c3c(c1)-c1ccc(-c4cccc5oc6ccccc6c45)cc1OB3c1ccc(-c3ccc(-n4c5ccccc5c5ccccc54)cc3)cc1O2 ; c1cc2c3c(c1)-c1cc(-c4cccc5c4oc4ccccc45)ccc1OB3c1cccc(-n3c4ccccc4c4ccccc43)c1O2 ; c1cc2c3c(c1)-c1cc(-c4cccc5c4oc4ccccc45)ccc1OB3c1ccc(-n3c4ccccc4c4ccccc43)cc1O2] 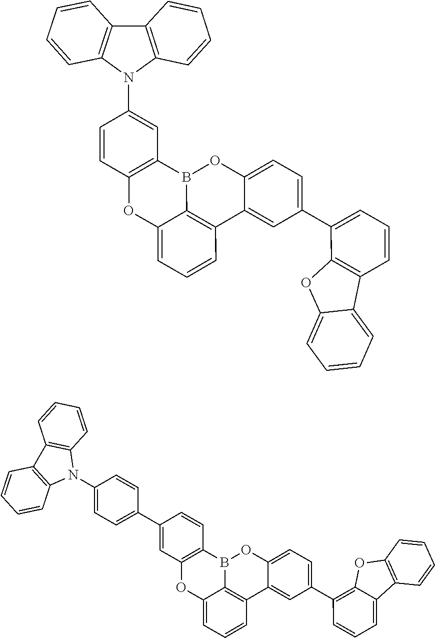 [SMILES: c1cc2c3c(c1)-c1cc(-c4cccc5c4oc4ccccc45)ccc1OB3c1cc(-n3c4ccccc4c4ccccc43)ccc1O2 ; c1cc2c3c(c1)-c1cc(-c4cccc5c4oc4ccccc45)ccc1OB3c1ccc(-c3ccc(-n4c5ccccc5c5ccccc54)cc3)cc1O2] 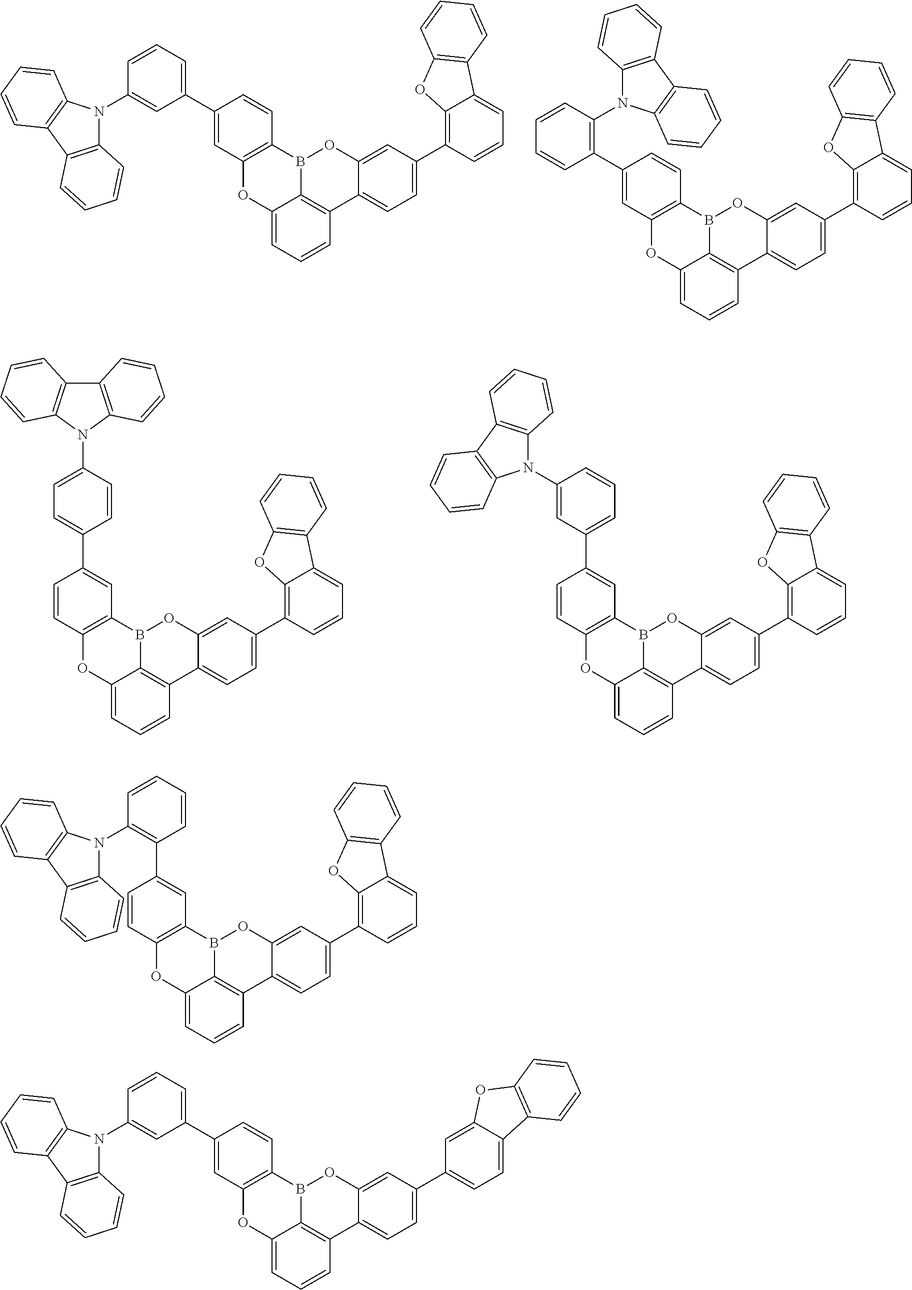 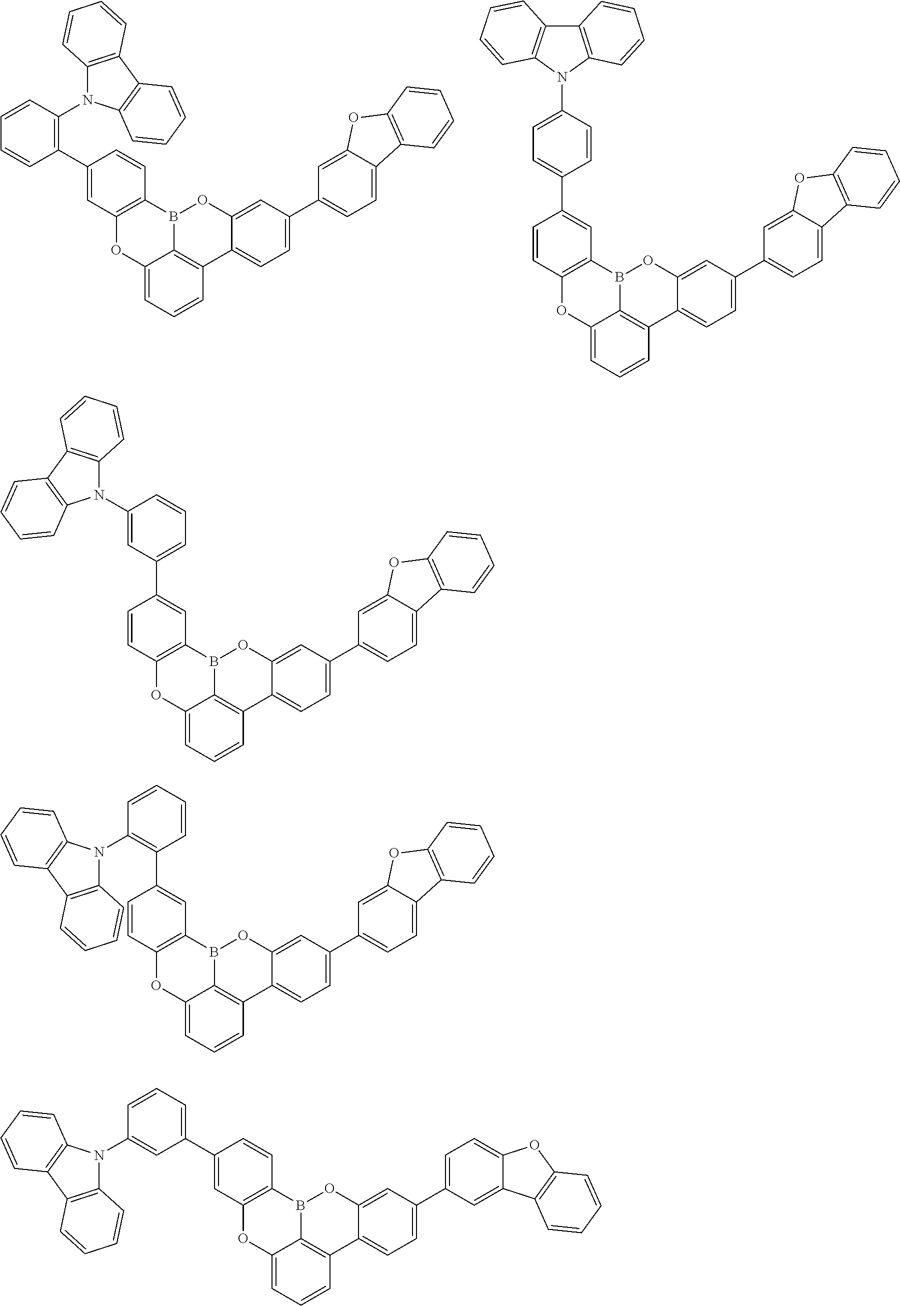 [SMILES: c1ccc(-n2c3ccccc3c3ccccc32)c(-c2ccc3c(c2)Oc2cccc4c2B3Oc2cc(-c3ccc5c(c3)oc3ccccc35)ccc2-4)c1 ; c1cc2c3c(c1)-c1ccc(-c4ccc5c(c4)oc4ccccc45)cc1OB3c1cc(-c3ccc(-n4c5ccccc5c5ccccc54)cc3)ccc1O2 ; c1cc(-c2ccc3c(c2)B2Oc4cc(-c5ccc6c(c5)oc5ccccc56)ccc4-c4cccc(c42)O3)cc(-n2c3ccccc3c3ccccc32)c1 ; c1ccc(-n2c3ccccc3c3ccccc32)c(-c2ccc3c(c2)B2Oc4cc(-c5ccc6c(c5)oc5ccccc56)ccc4-c4cccc(c42)O3)c1 ; c1cc(-c2ccc3c(c2)Oc2cccc4c2B3Oc2cc(-c3ccc5oc6ccccc6c5c3)ccc2-4)cc(-n2c3ccccc3c3ccccc32)c1] 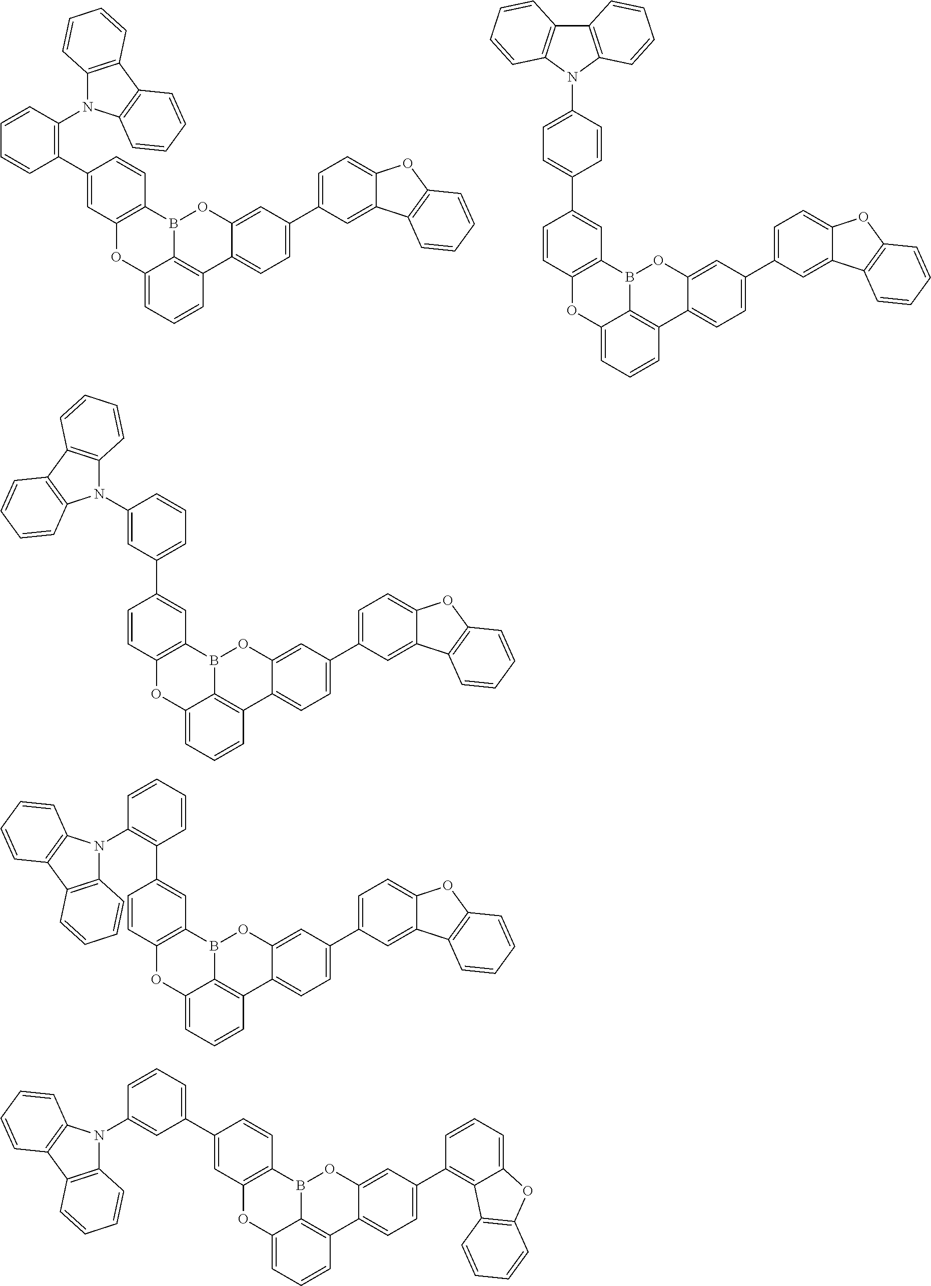 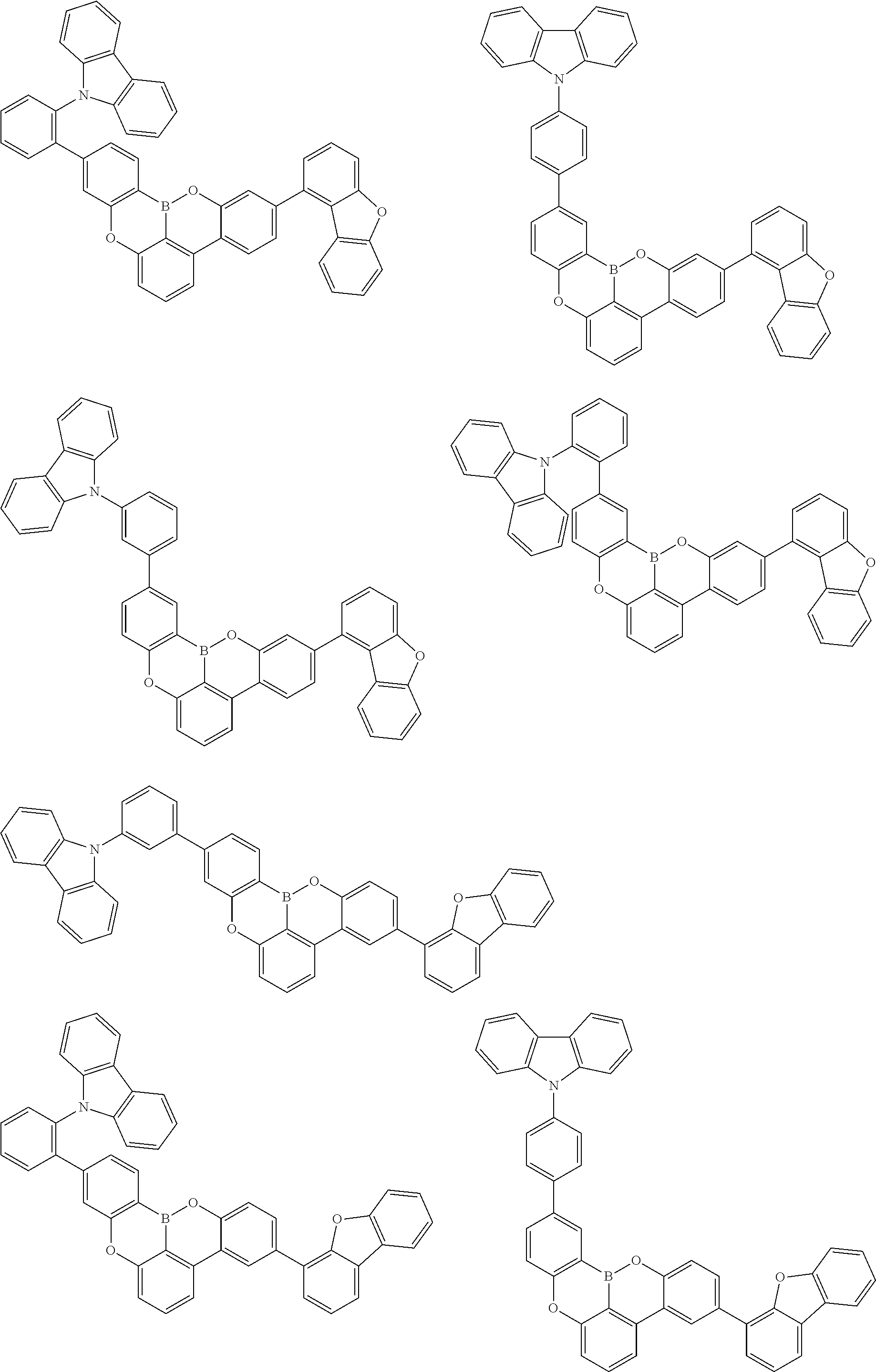 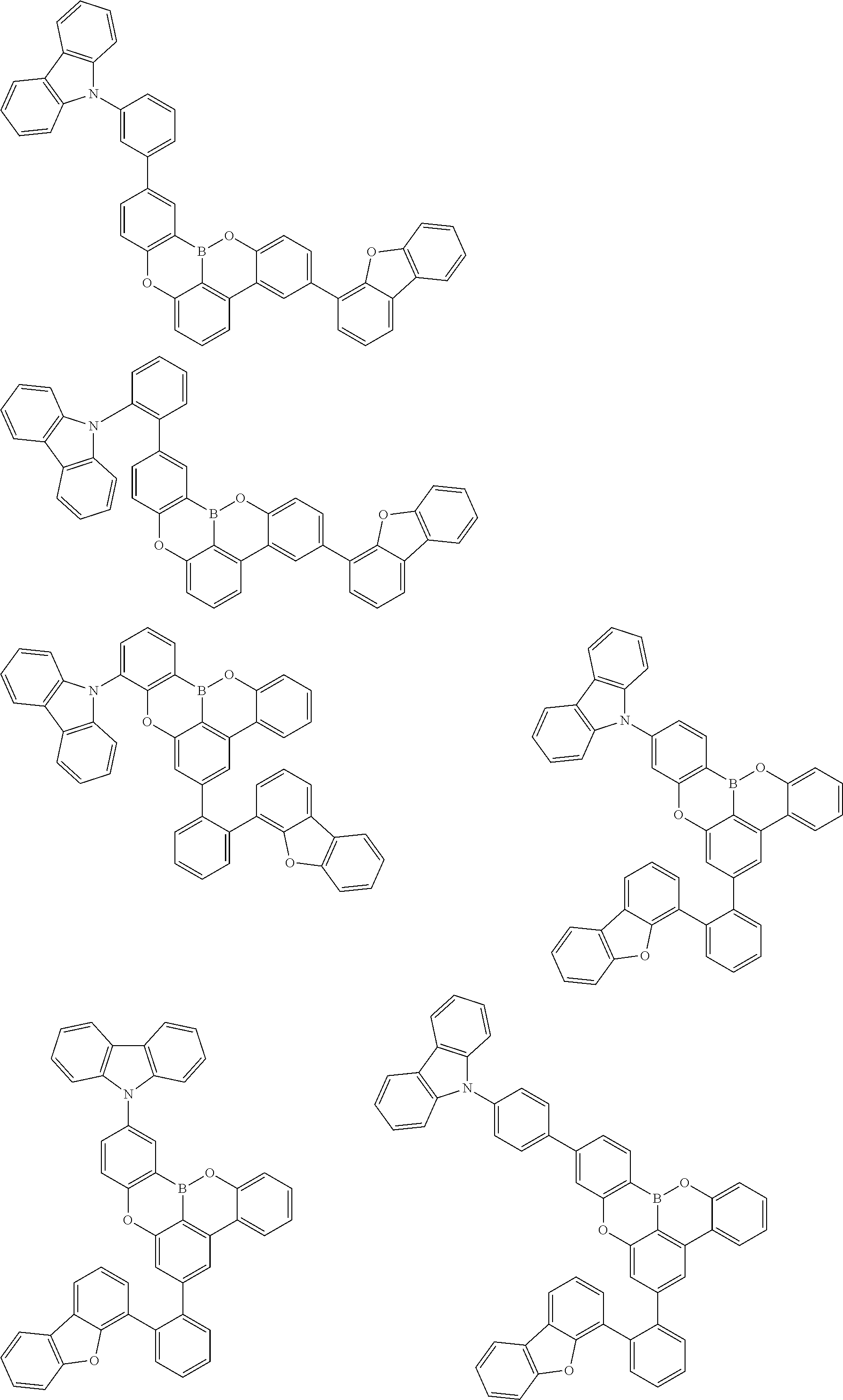 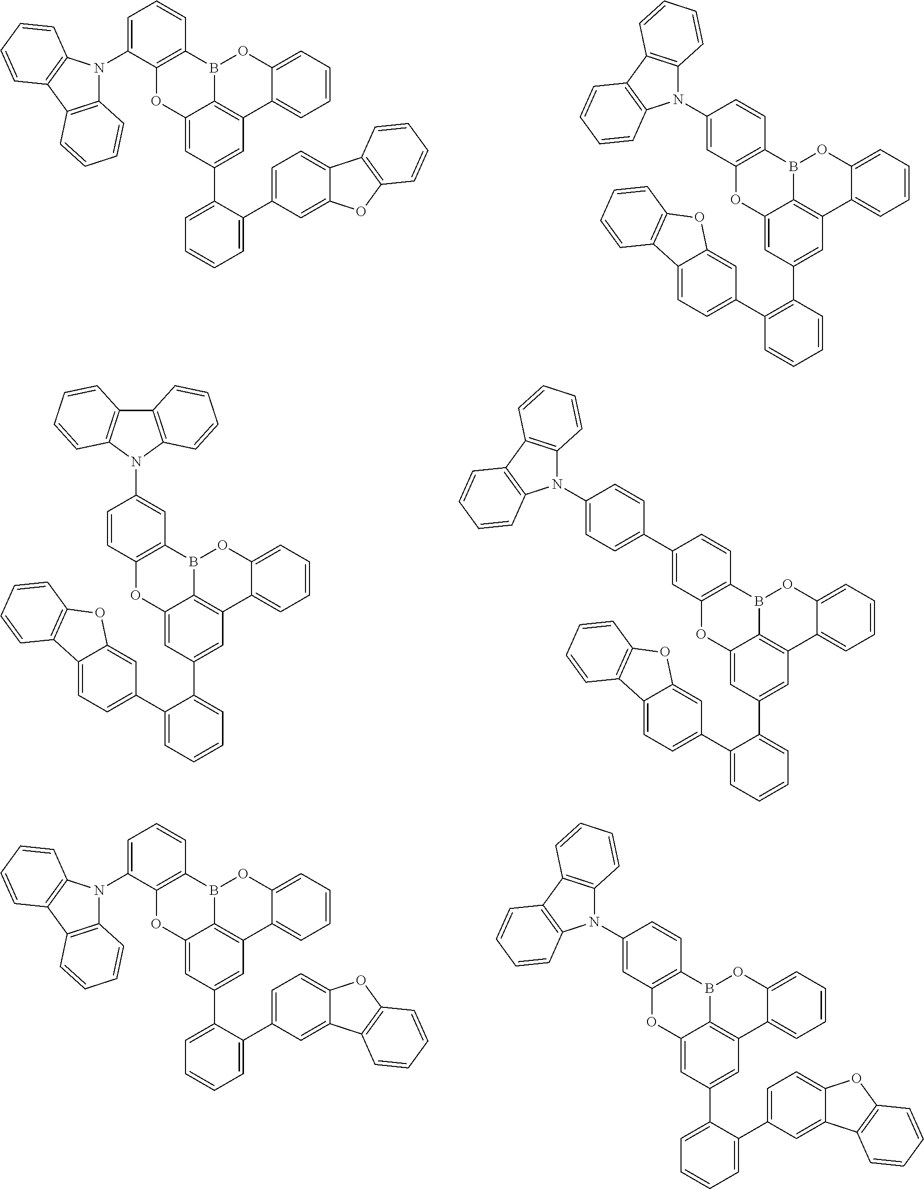 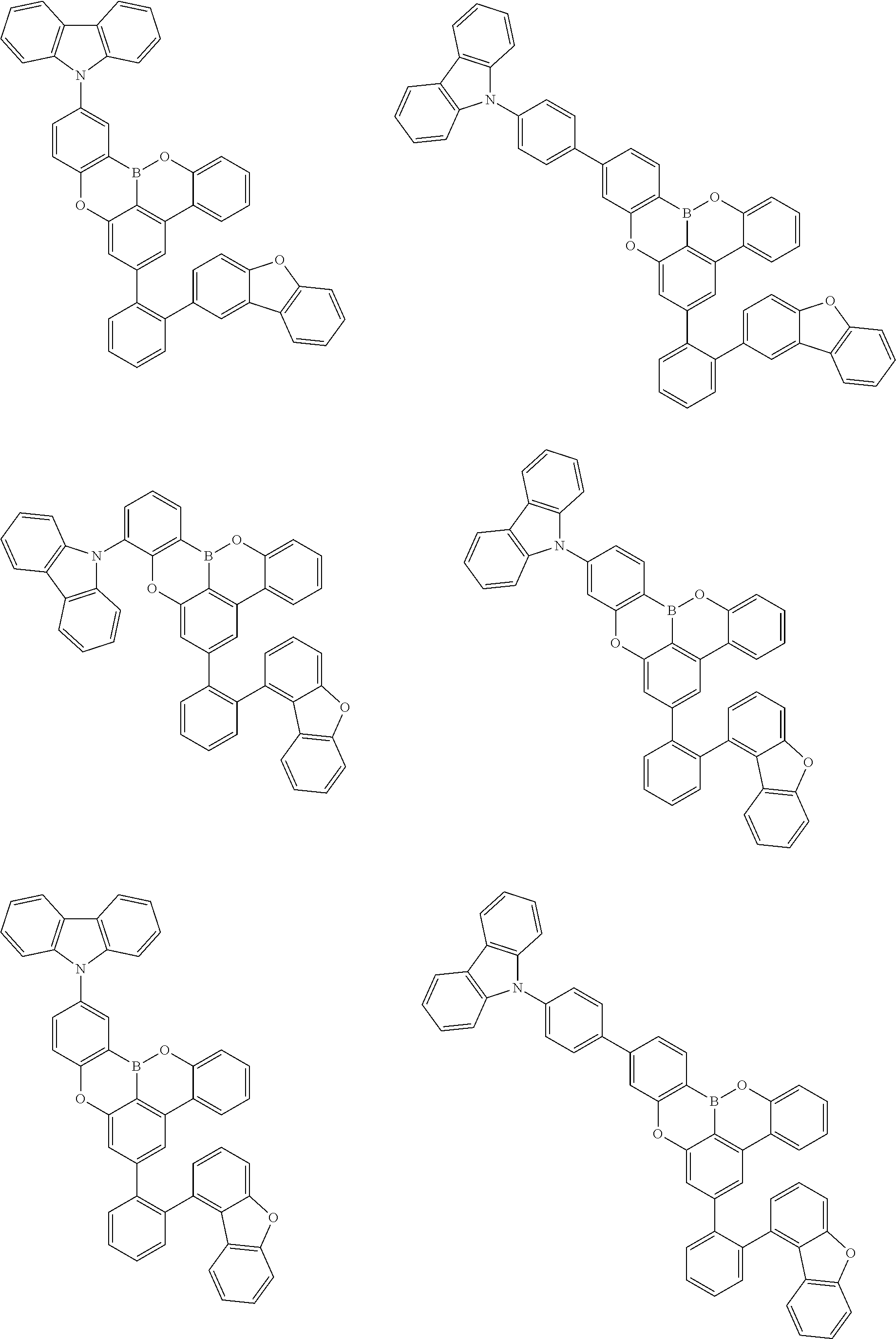 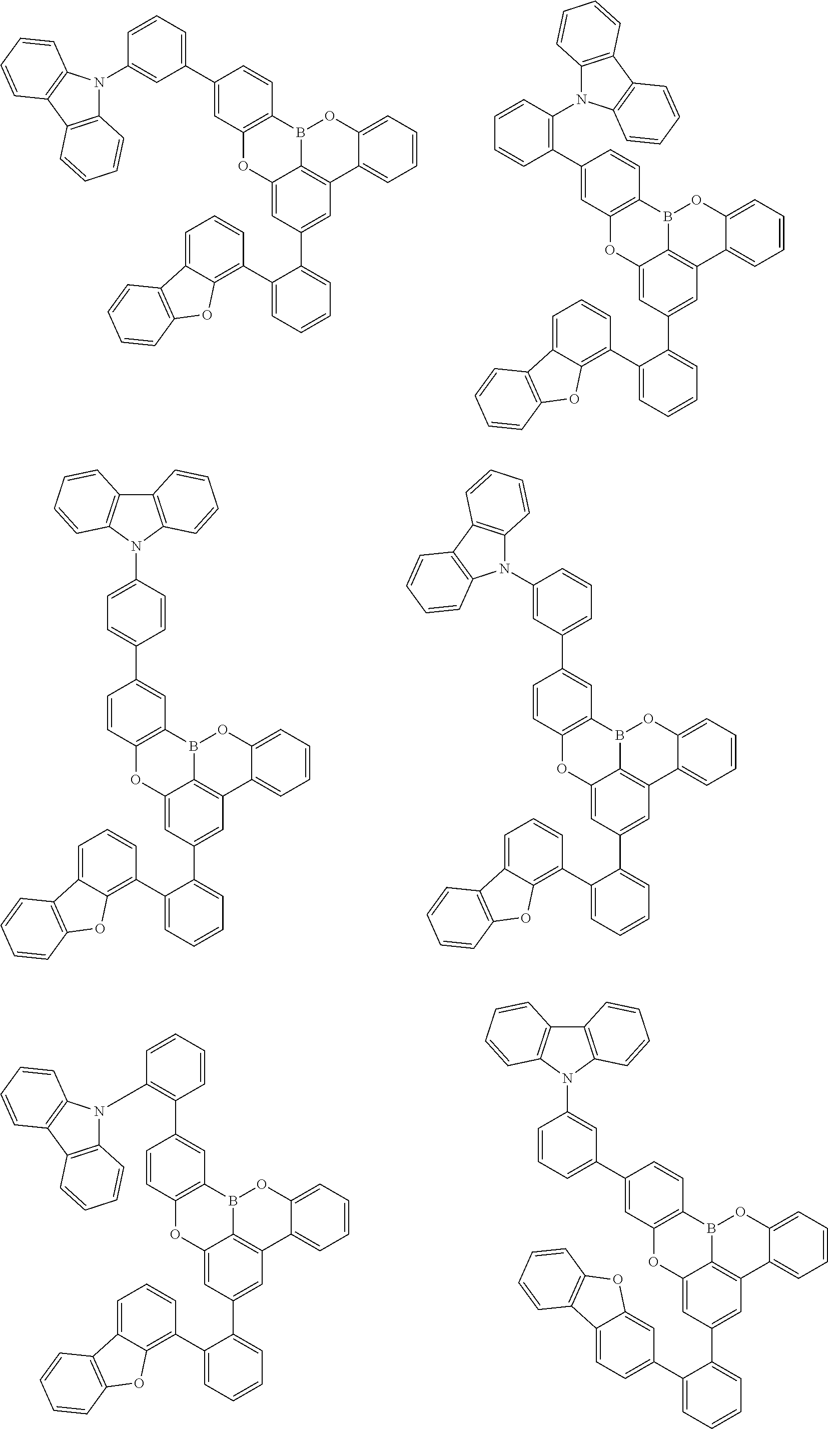 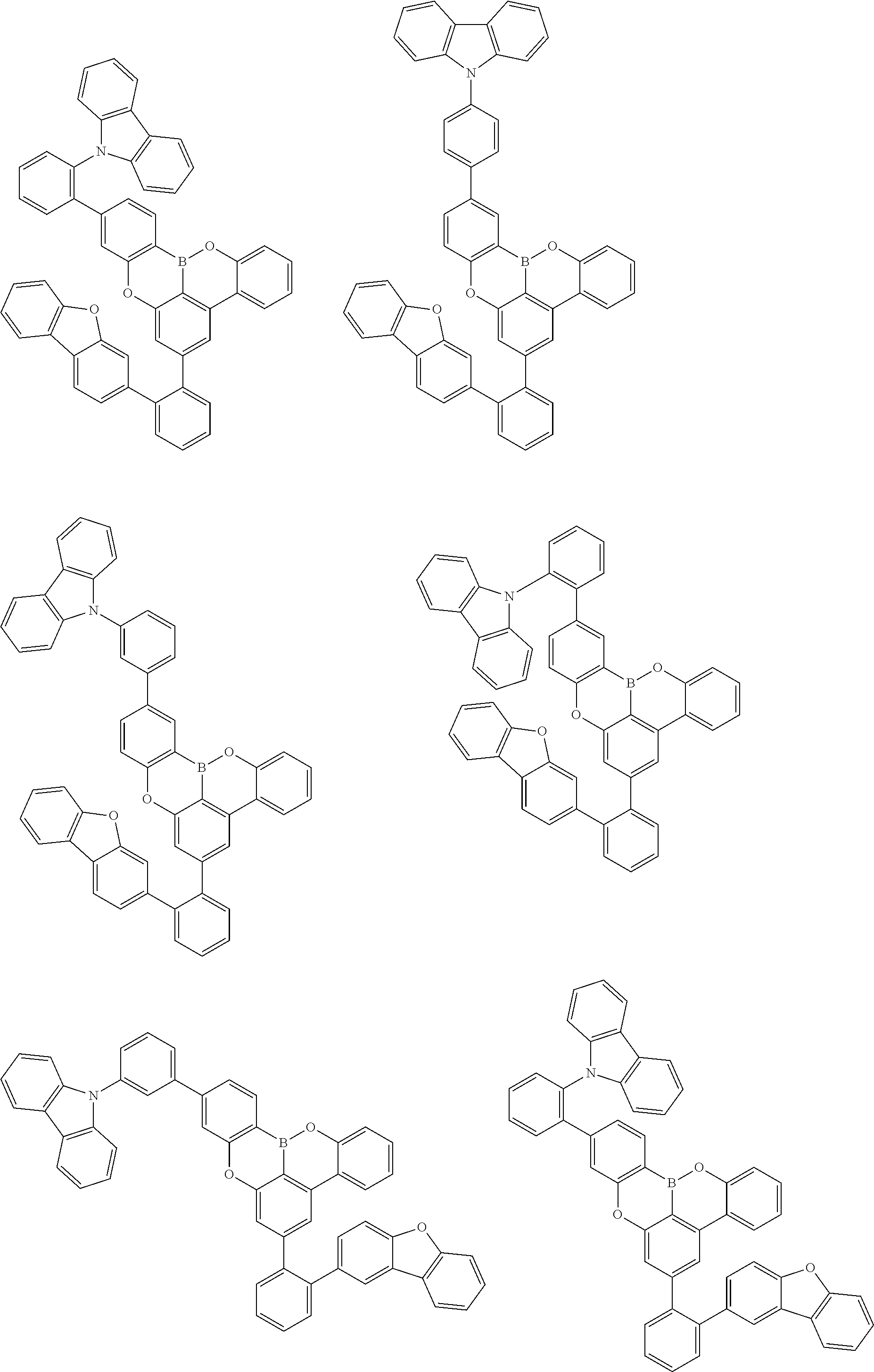 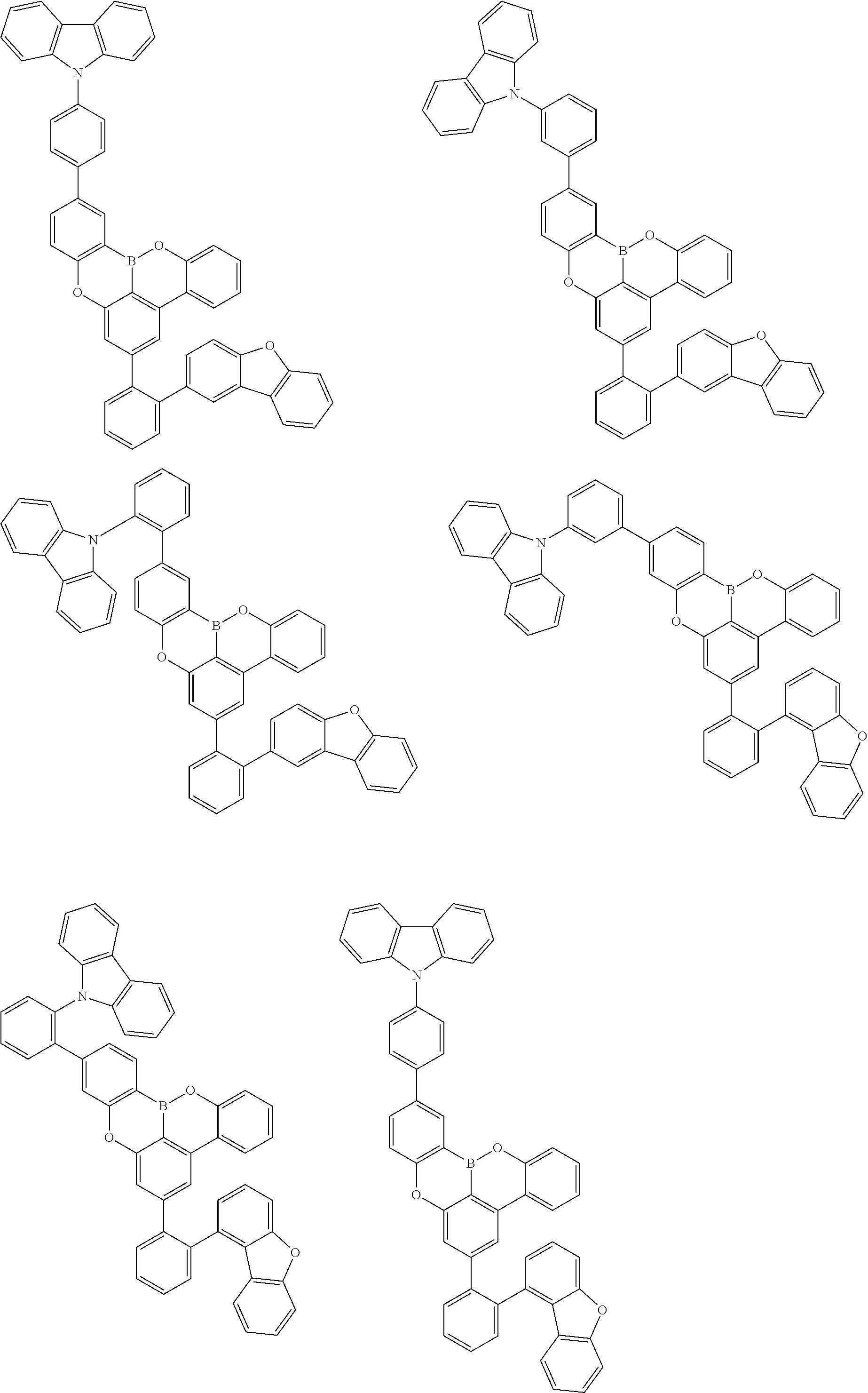 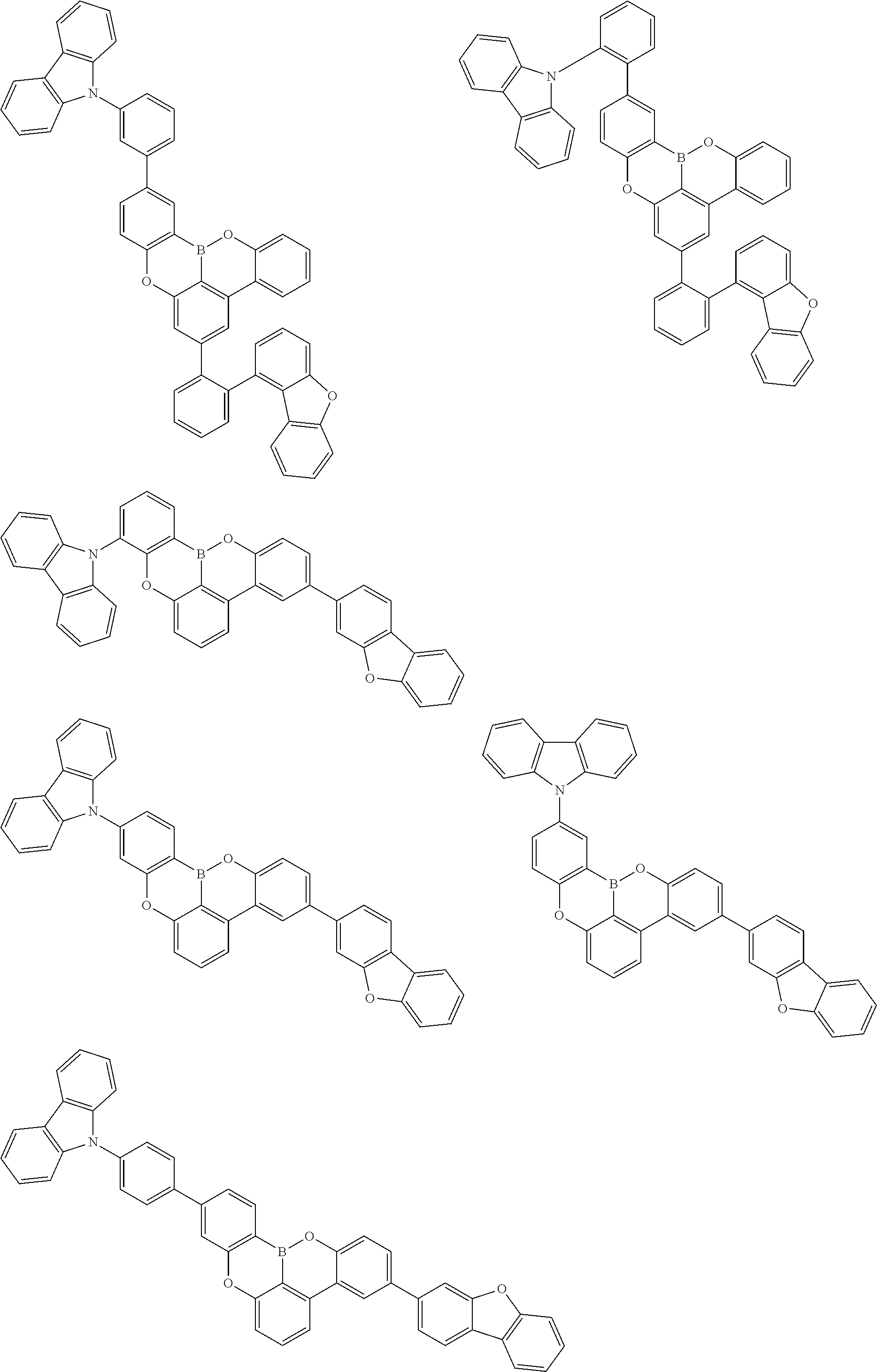 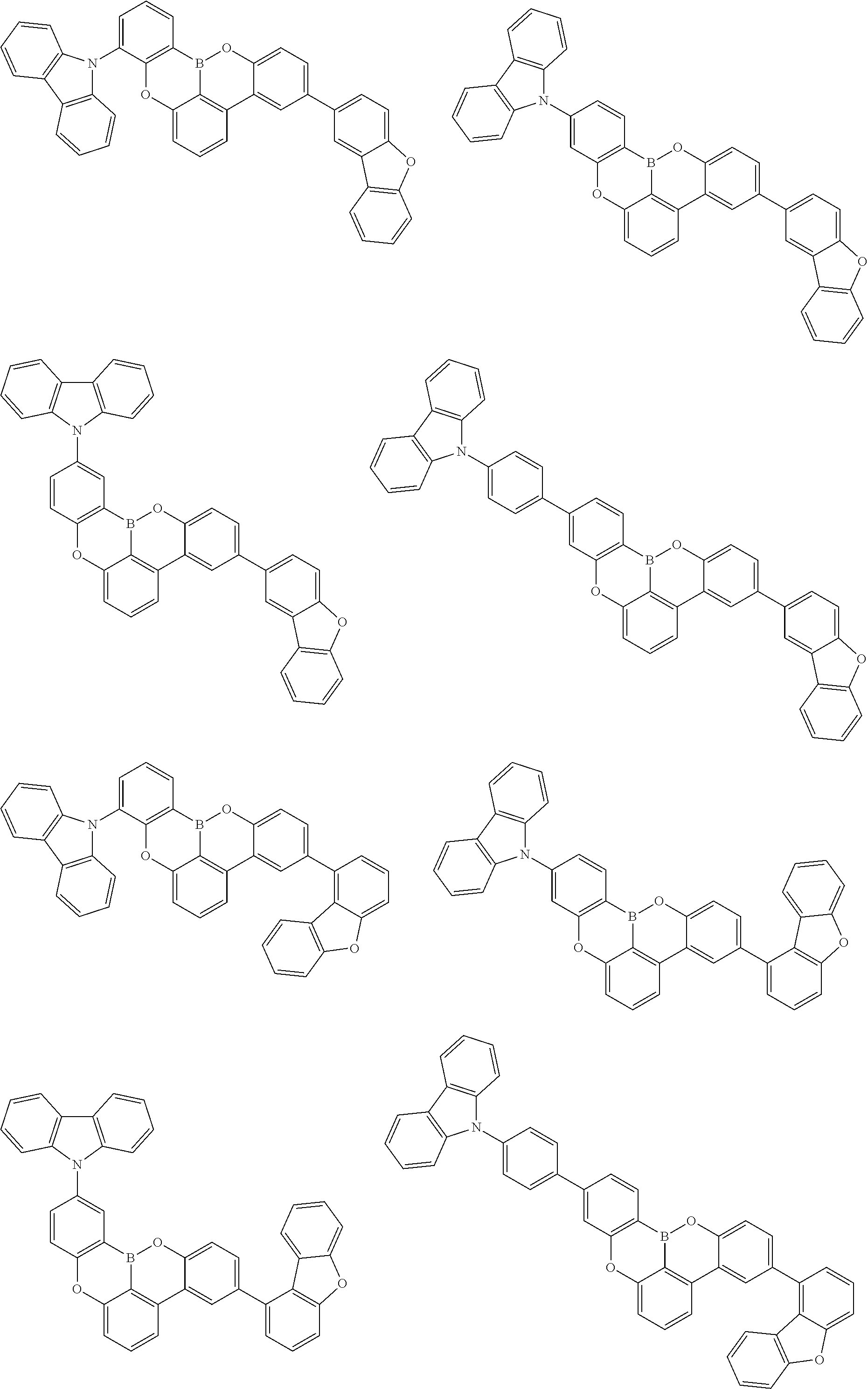 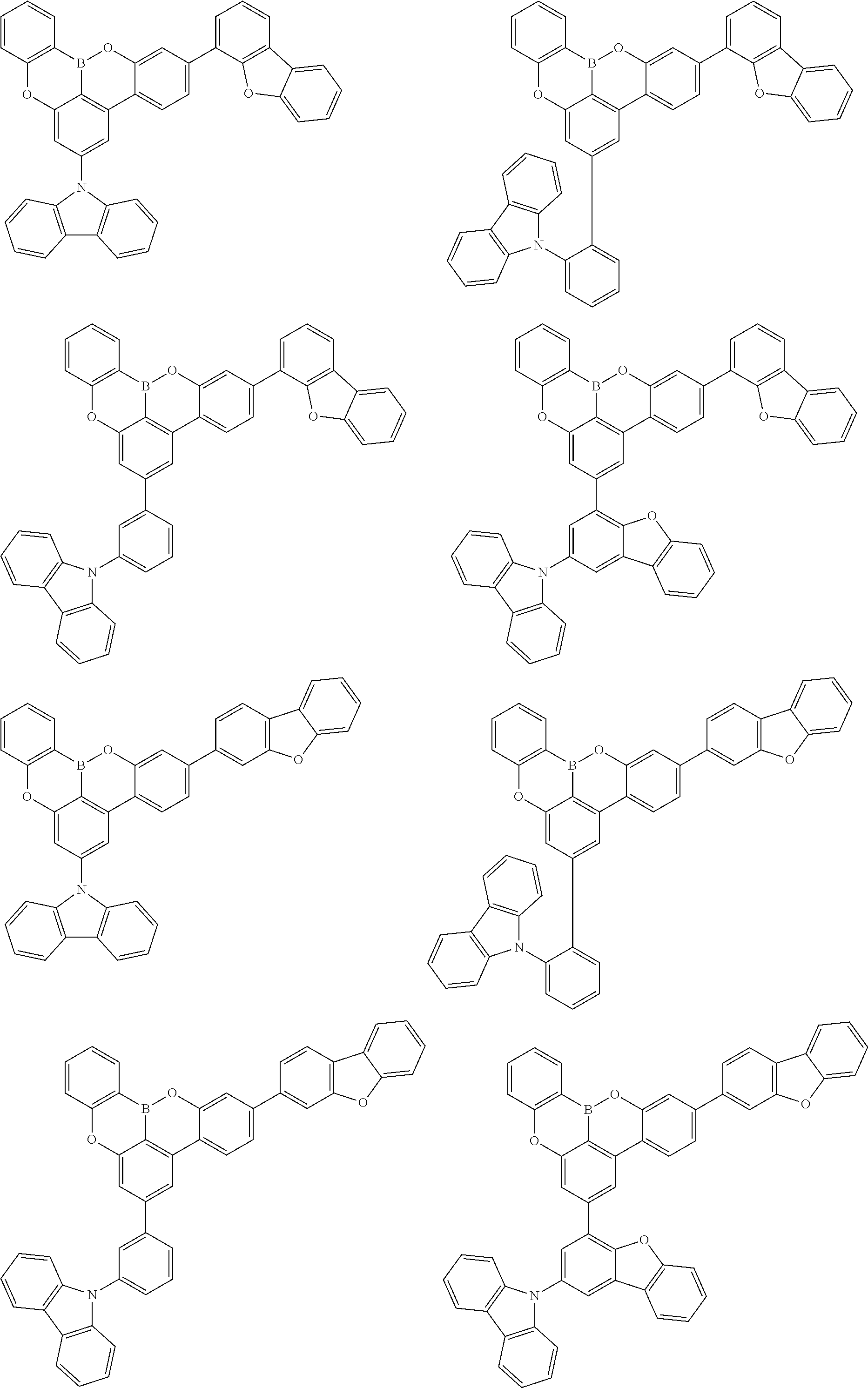 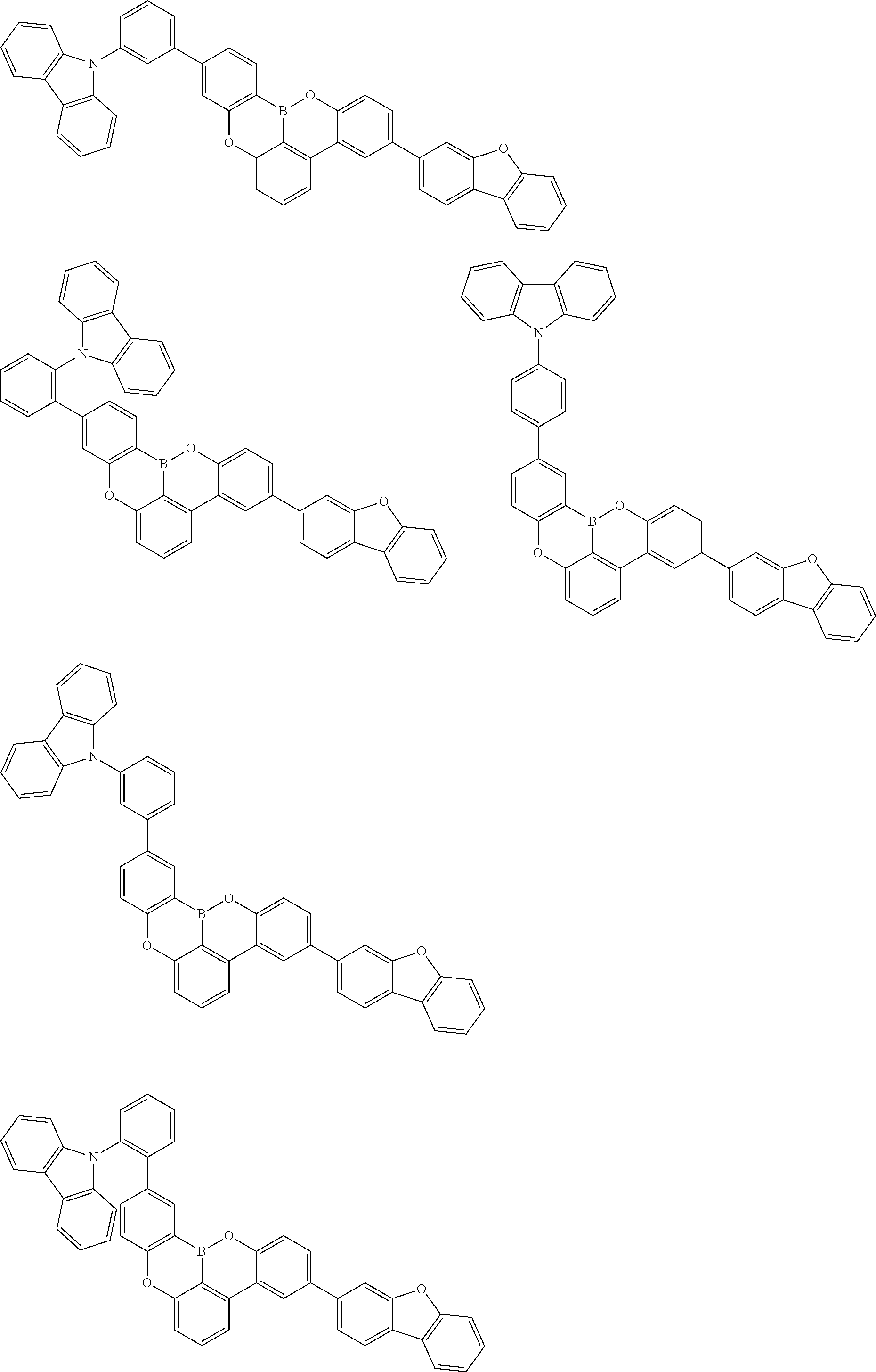 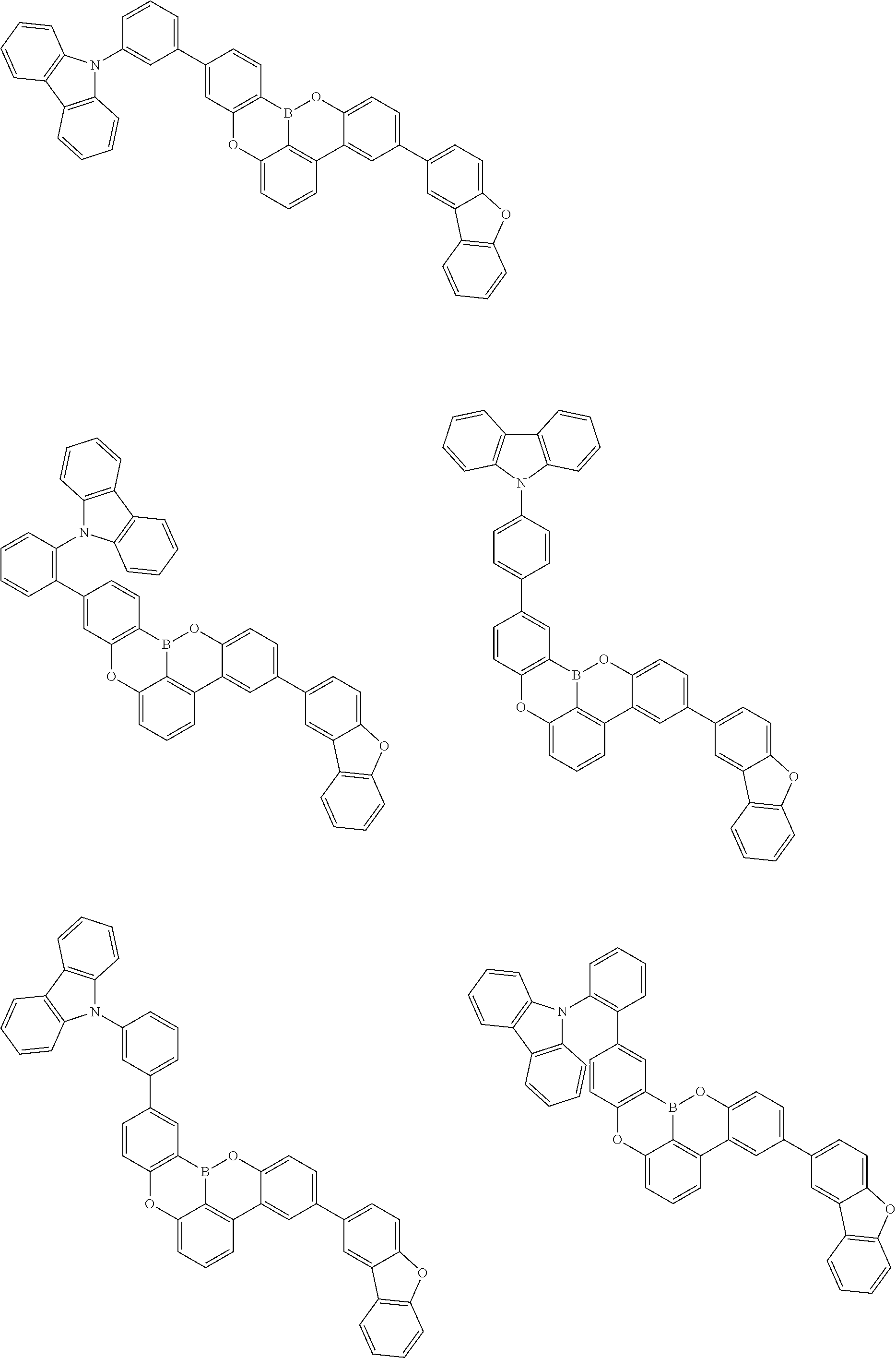 [SMILES: c1cc(-c2ccc3c(c2)Oc2cccc4c2B3Oc2ccc(-c3ccc5oc6ccccc6c5c3)cc2-4)cc(-n2c3ccccc3c3ccccc32)c1 ; c1ccc(-n2c3ccccc3c3ccccc32)c(-c2ccc3c(c2)Oc2cccc4c2B3Oc2ccc(-c3ccc5oc6ccccc6c5c3)cc2-4)c1 ; c1cc2c3c(c1)-c1cc(-c4ccc5oc6ccccc6c5c4)ccc1OB3c1cc(-c3ccc(-n4c5ccccc5c5ccccc54)cc3)ccc1O2 ; c1cc(-c2ccc3c(c2)B2Oc4ccc(-c5ccc6oc7ccccc7c6c5)cc4-c4cccc(c42)O3)cc(-n2c3ccccc3c3ccccc32)c1 ; c1ccc(-n2c3ccccc3c3ccccc32)c(-c2ccc3c(c2)B2Oc4ccc(-c5ccc6oc7ccccc7c6c5)cc4-c4cccc(c42)O3)c1] 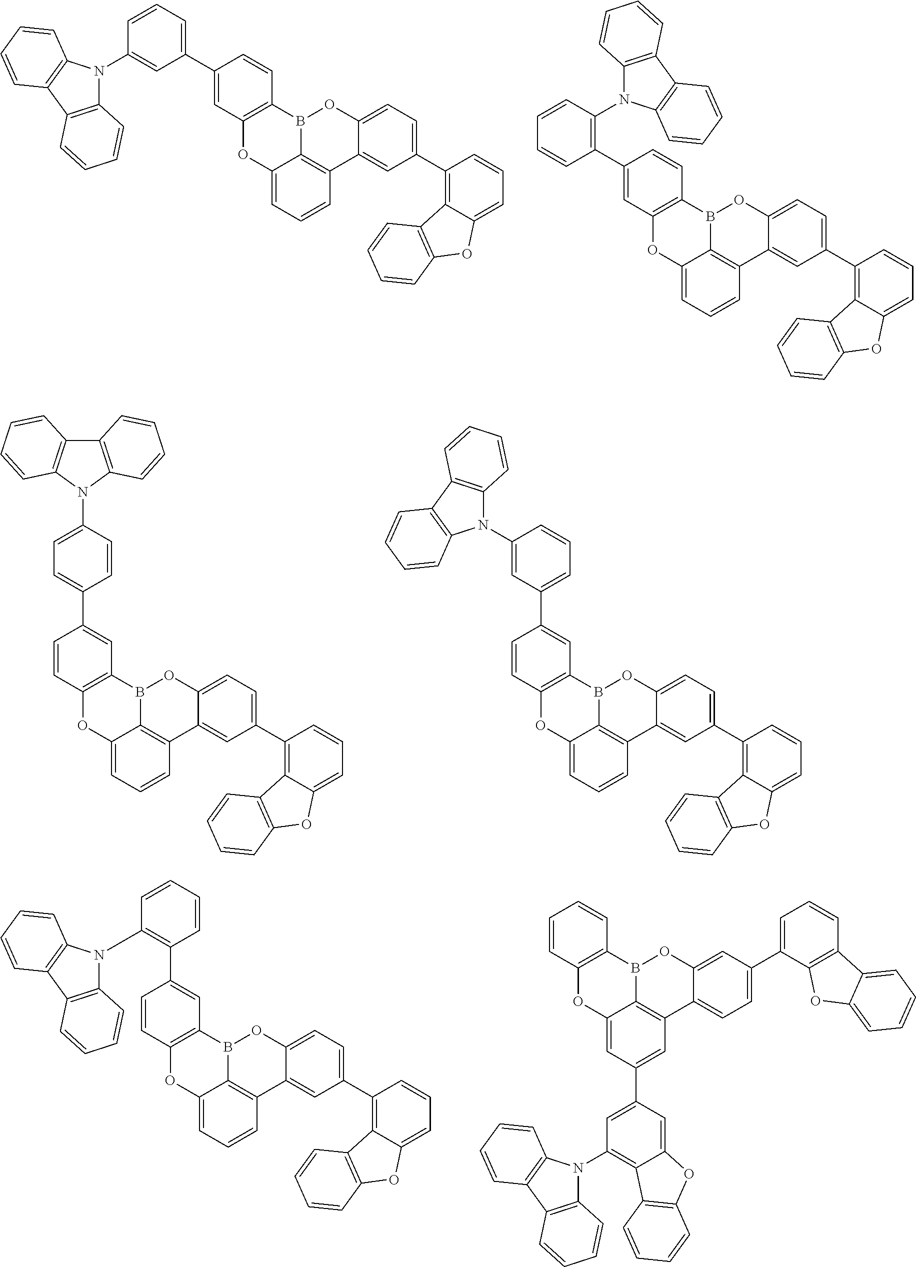 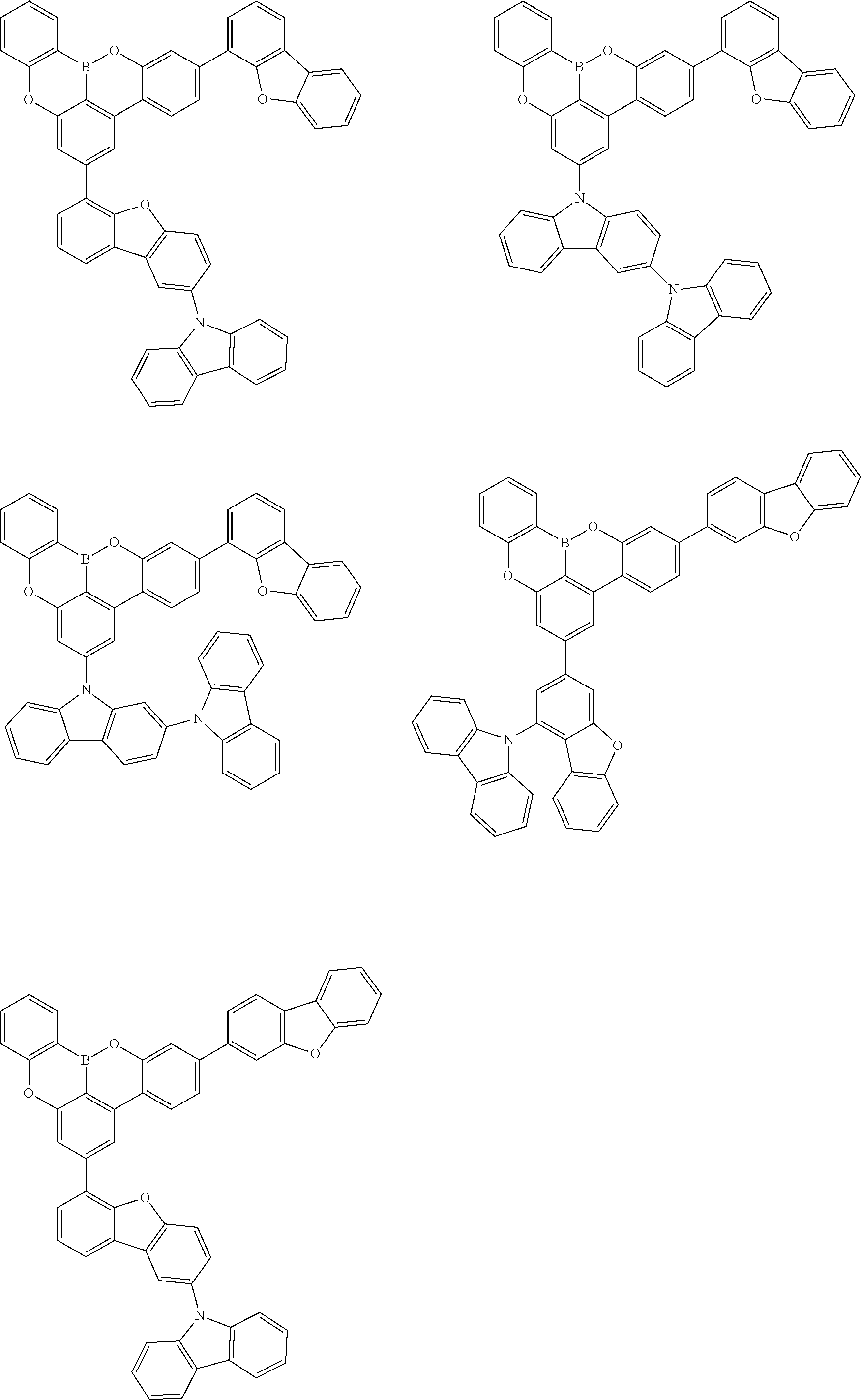 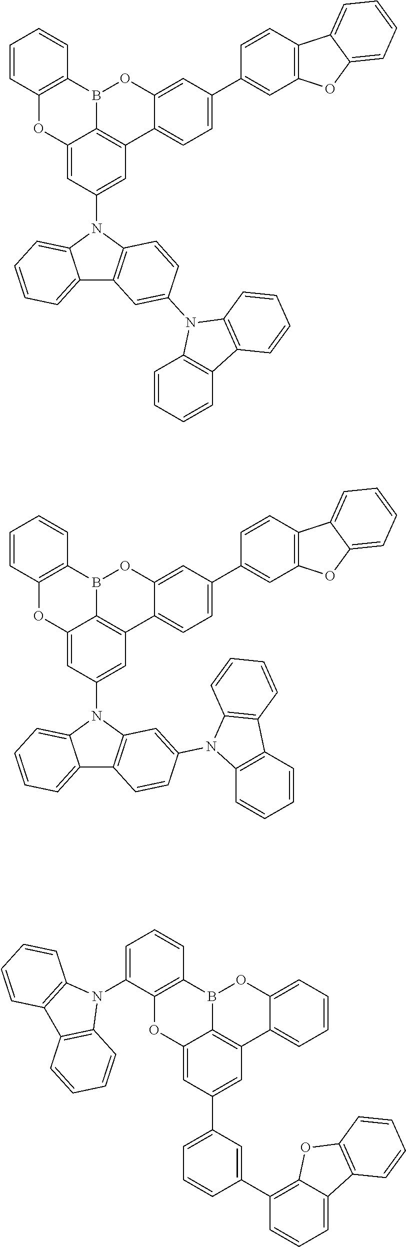 [SMILES: c1ccc2c(c1)Oc1cc(-n3c4ccccc4c4cc(-n5c6ccccc6c6ccccc65)ccc43)cc3c1B2Oc1cc(-c2ccc4c(c2)oc2ccccc24)ccc1-3 ; c1ccc2c(c1)Oc1cc(-n3c4ccccc4c4ccc(-n5c6ccccc6c6ccccc65)cc43)cc3c1B2Oc1cc(-c2ccc4c(c2)oc2ccccc24)ccc1-3 ; c1cc(-c2cc3c4c(c2)-c2ccccc2OB4c2cccc(-n4c5ccccc5c5ccccc54)c2O3)cc(-c2cccc3c2oc2ccccc23)c1] 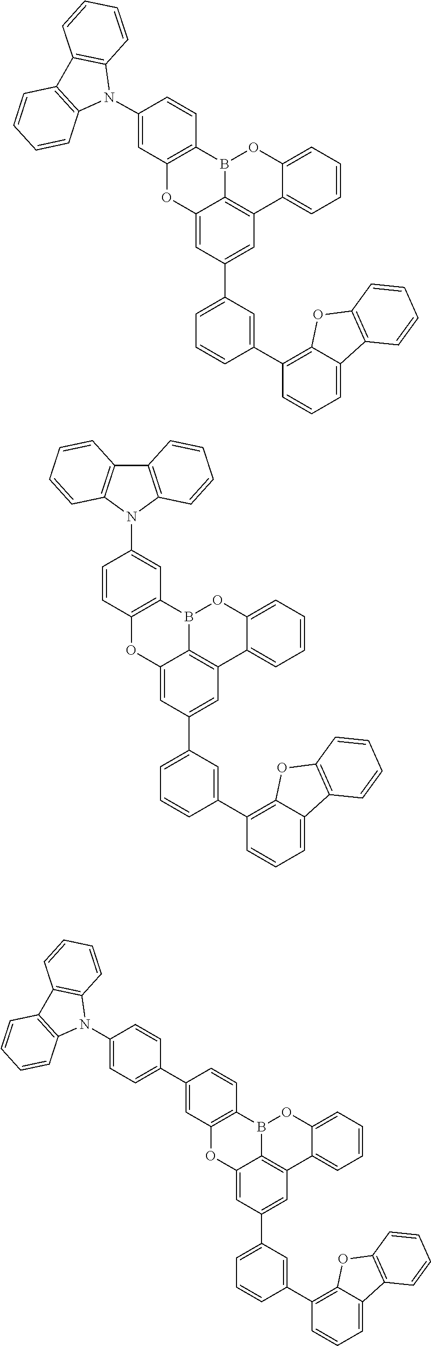 [SMILES: c1cc(-c2cc3c4c(c2)-c2ccccc2OB4c2ccc(-n4c5ccccc5c5ccccc54)cc2O3)cc(-c2cccc3c2oc2ccccc23)c1 ; c1cc(-c2cc3c4c(c2)-c2ccccc2OB4c2cc(-n4c5ccccc5c5ccccc54)ccc2O3)cc(-c2cccc3c2oc2ccccc23)c1 ; c1cc(-c2cc3c4c(c2)-c2ccccc2OB4c2ccc(-c4ccc(-n5c6ccccc6c6ccccc65)cc4)cc2O3)cc(-c2cccc3c2oc2ccccc23)c1] 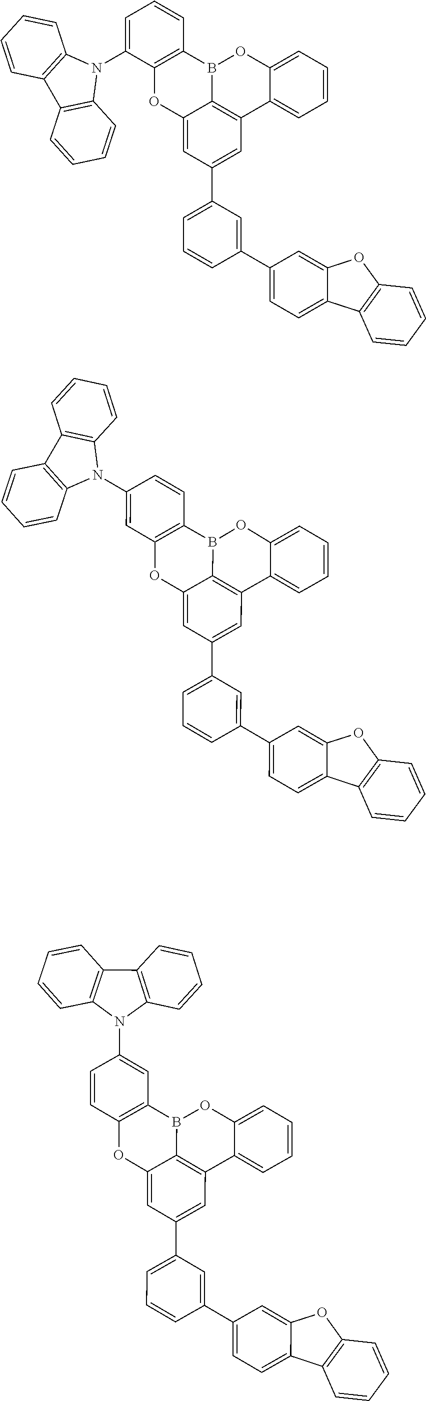 [SMILES: c1cc(-c2cc3c4c(c2)-c2ccccc2OB4c2cccc(-n4c5ccccc5c5ccccc54)c2O3)cc(-c2ccc3c(c2)oc2ccccc23)c1 ; c1cc(-c2cc3c4c(c2)-c2ccccc2OB4c2ccc(-n4c5ccccc5c5ccccc54)cc2O3)cc(-c2ccc3c(c2)oc2ccccc23)c1 ; c1cc(-c2cc3c4c(c2)-c2ccccc2OB4c2cc(-n4c5ccccc5c5ccccc54)ccc2O3)cc(-c2ccc3c(c2)oc2ccccc23)c1] 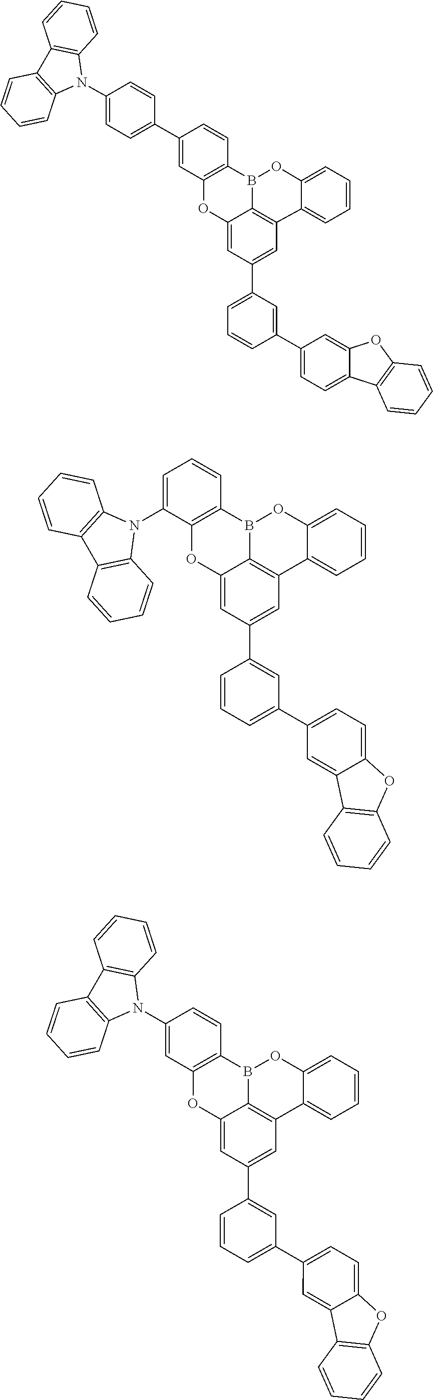 [SMILES: c1cc(-c2cc3c4c(c2)-c2ccccc2OB4c2ccc(-c4ccc(-n5c6ccccc6c6ccccc65)cc4)cc2O3)cc(-c2ccc3c(c2)oc2ccccc23)c1 ; c1cc(-c2cc3c4c(c2)-c2ccccc2OB4c2cccc(-n4c5ccccc5c5ccccc54)c2O3)cc(-c2ccc3oc4ccccc4c3c2)c1 ; c1cc(-c2cc3c4c(c2)-c2ccccc2OB4c2ccc(-n4c5ccccc5c5ccccc54)cc2O3)cc(-c2ccc3oc4ccccc4c3c2)c1] 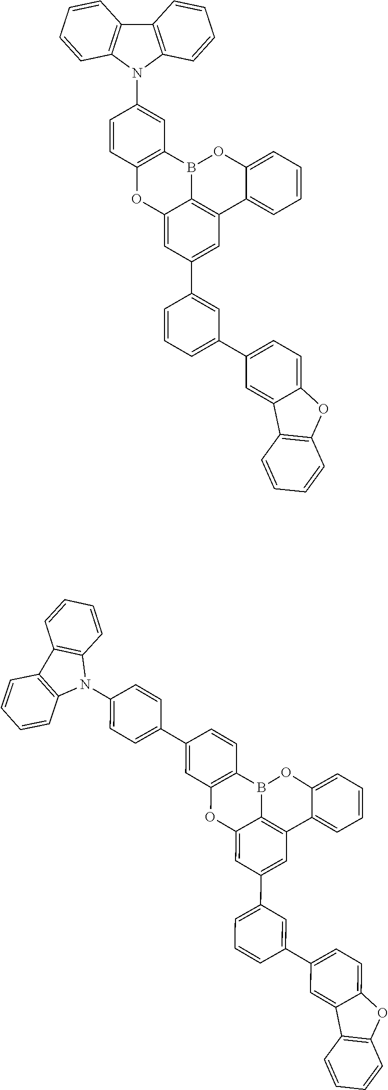 [SMILES: c1cc(-c2cc3c4c(c2)-c2ccccc2OB4c2cc(-n4c5ccccc5c5ccccc54)ccc2O3)cc(-c2ccc3oc4ccccc4c3c2)c1 ; c1cc(-c2cc3c4c(c2)-c2ccccc2OB4c2ccc(-c4ccc(-n5c6ccccc6c6ccccc65)cc4)cc2O3)cc(-c2ccc3oc4ccccc4c3c2)c1] 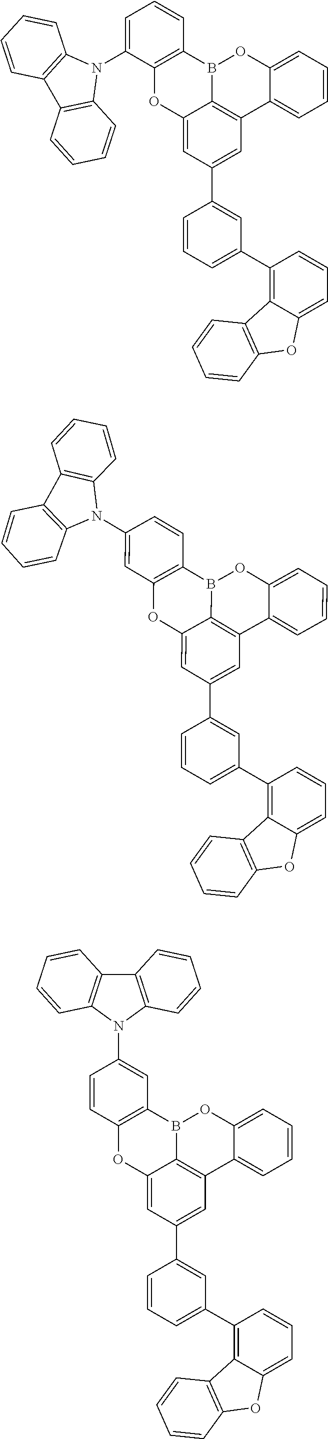 [SMILES: c1cc(-c2cc3c4c(c2)-c2ccccc2OB4c2cccc(-n4c5ccccc5c5ccccc54)c2O3)cc(-c2cccc3oc4ccccc4c23)c1 ; c1cc(-c2cc3c4c(c2)-c2ccccc2OB4c2ccc(-n4c5ccccc5c5ccccc54)cc2O3)cc(-c2cccc3oc4ccccc4c23)c1 ; c1cc(-c2cc3c4c(c2)-c2ccccc2OB4c2cc(-n4c5ccccc5c5ccccc54)ccc2O3)cc(-c2cccc3oc4ccccc4c23)c1] 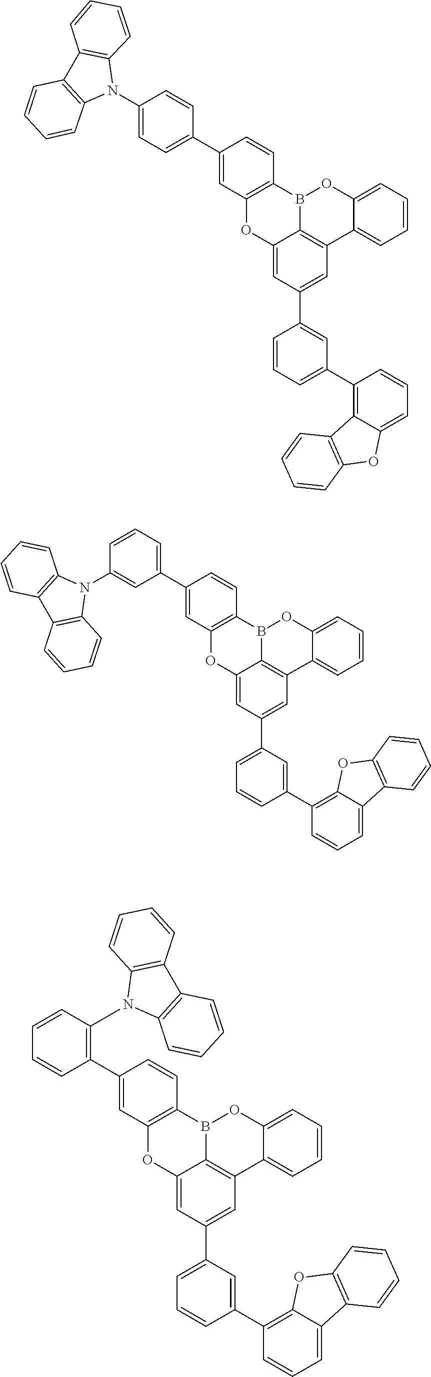 [SMILES: c1cc(-c2cc3c4c(c2)-c2ccccc2OB4c2ccc(-c4ccc(-n5c6ccccc6c6ccccc65)cc4)cc2O3)cc(-c2cccc3oc4ccccc4c23)c1 ; c1cc(-c2cc3c4c(c2)-c2ccccc2OB4c2ccc(-c4cccc(-n5c6ccccc6c6ccccc65)c4)cc2O3)cc(-c2cccc3c2oc2ccccc23)c1 ; c1cc(-c2cc3c4c(c2)-c2ccccc2OB4c2ccc(-c4ccccc4-n4c5ccccc5c5ccccc54)cc2O3)cc(-c2cccc3c2oc2ccccc23)c1] 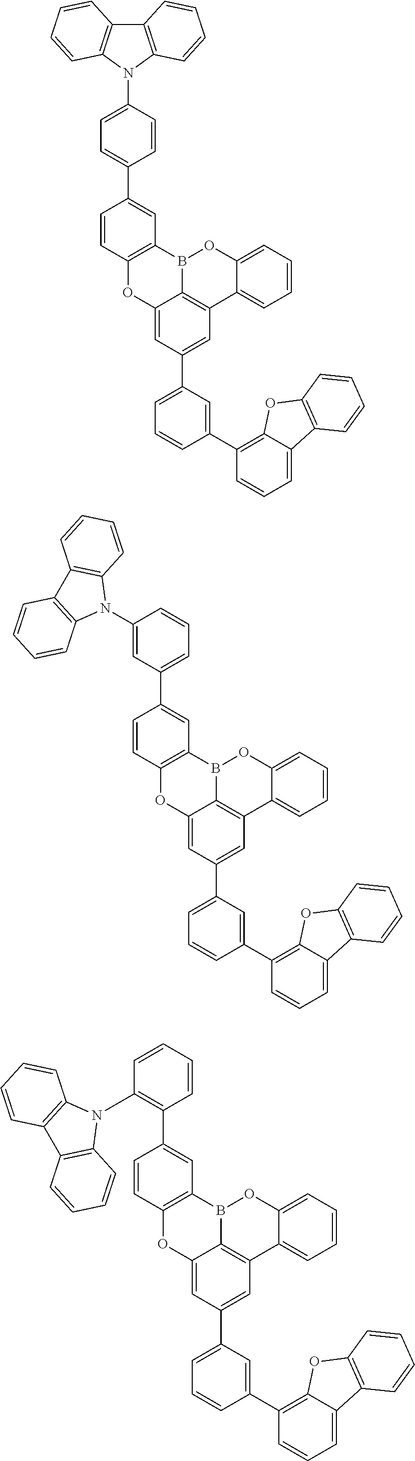 [SMILES: c1cc(-c2cc3c4c(c2)-c2ccccc2OB4c2cc(-c4ccc(-n5c6ccccc6c6ccccc65)cc4)ccc2O3)cc(-c2cccc3c2oc2ccccc23)c1 ; c1cc(-c2cc3c4c(c2)-c2ccccc2OB4c2cc(-c4cccc(-n5c6ccccc6c6ccccc65)c4)ccc2O3)cc(-c2cccc3c2oc2ccccc23)c1 ; c1cc(-c2cc3c4c(c2)-c2ccccc2OB4c2cc(-c4ccccc4-n4c5ccccc5c5ccccc54)ccc2O3)cc(-c2cccc3c2oc2ccccc23)c1] 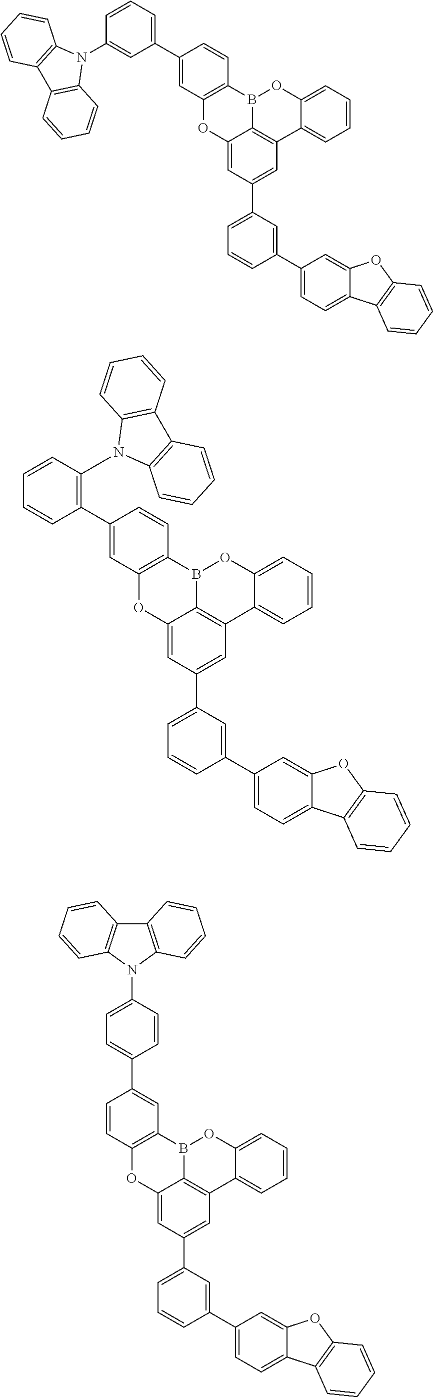 [SMILES: c1cc(-c2cc3c4c(c2)-c2ccccc2OB4c2ccc(-c4cccc(-n5c6ccccc6c6ccccc65)c4)cc2O3)cc(-c2ccc3c(c2)oc2ccccc23)c1 ; c1cc(-c2cc3c4c(c2)-c2ccccc2OB4c2ccc(-c4ccccc4-n4c5ccccc5c5ccccc54)cc2O3)cc(-c2ccc3c(c2)oc2ccccc23)c1 ; c1cc(-c2cc3c4c(c2)-c2ccccc2OB4c2cc(-c4ccc(-n5c6ccccc6c6ccccc65)cc4)ccc2O3)cc(-c2ccc3c(c2)oc2ccccc23)c1] 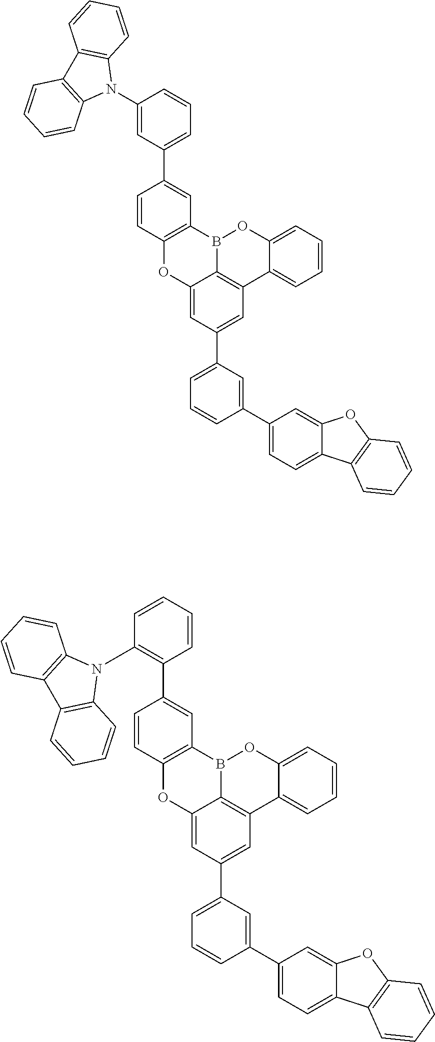 [SMILES: c1cc(-c2cc3c4c(c2)-c2ccccc2OB4c2cc(-c4cccc(-n5c6ccccc6c6ccccc65)c4)ccc2O3)cc(-c2ccc3c(c2)oc2ccccc23)c1 ; c1cc(-c2cc3c4c(c2)-c2ccccc2OB4c2cc(-c4ccccc4-n4c5ccccc5c5ccccc54)ccc2O3)cc(-c2ccc3c(c2)oc2ccccc23)c1] 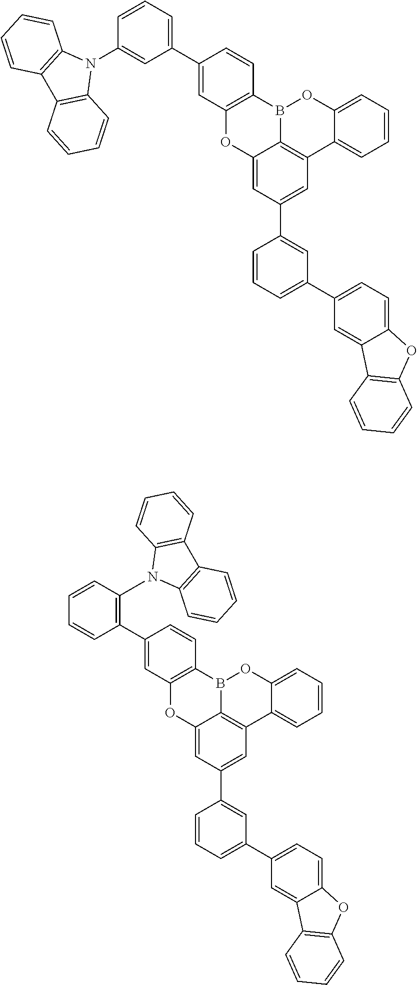 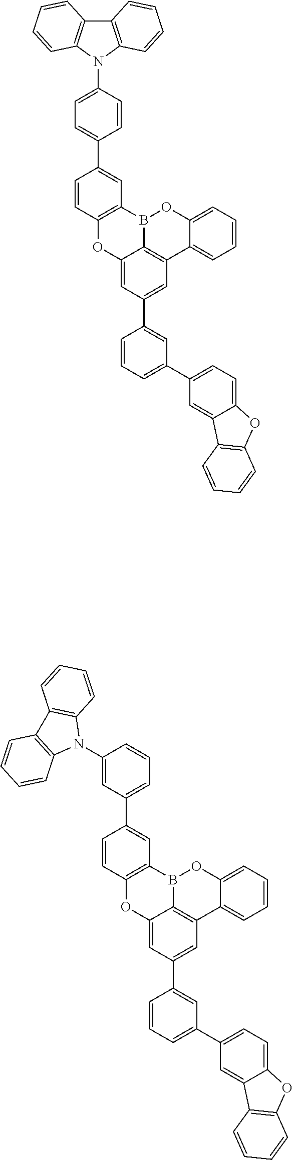 [SMILES: c1cc(-c2cc3c4c(c2)-c2ccccc2OB4c2cc(-c4ccc(-n5c6ccccc6c6ccccc65)cc4)ccc2O3)cc(-c2ccc3oc4ccccc4c3c2)c1 ; c1cc(-c2cc3c4c(c2)-c2ccccc2OB4c2cc(-c4cccc(-n5c6ccccc6c6ccccc65)c4)ccc2O3)cc(-c2ccc3oc4ccccc4c3c2)c1] 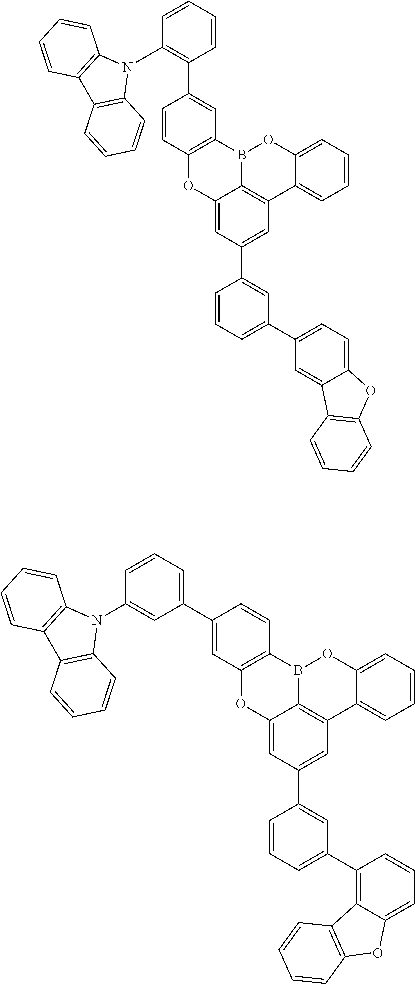 [SMILES: c1cc(-c2cc3c4c(c2)-c2ccccc2OB4c2cc(-c4ccccc4-n4c5ccccc5c5ccccc54)ccc2O3)cc(-c2ccc3oc4ccccc4c3c2)c1 ; c1cc(-c2cc3c4c(c2)-c2ccccc2OB4c2ccc(-c4cccc(-n5c6ccccc6c6ccccc65)c4)cc2O3)cc(-c2cccc3oc4ccccc4c23)c1] 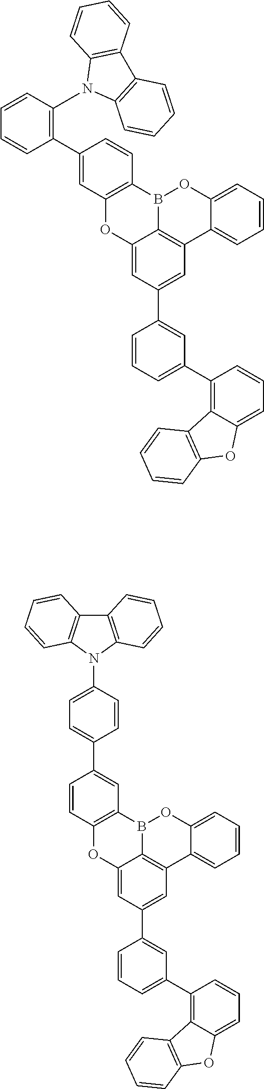 [SMILES: c1cc(-c2cc3c4c(c2)-c2ccccc2OB4c2ccc(-c4ccccc4-n4c5ccccc5c5ccccc54)cc2O3)cc(-c2cccc3oc4ccccc4c23)c1 ; c1cc(-c2cc3c4c(c2)-c2ccccc2OB4c2cc(-c4ccc(-n5c6ccccc6c6ccccc65)cc4)ccc2O3)cc(-c2cccc3oc4ccccc4c23)c1] 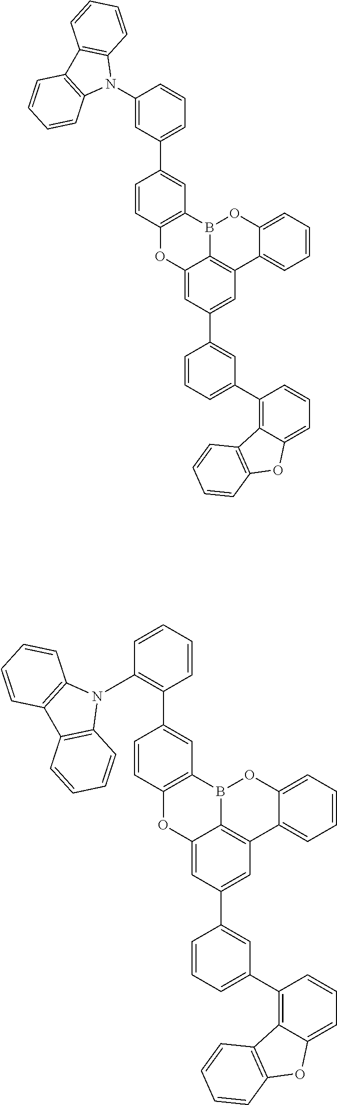 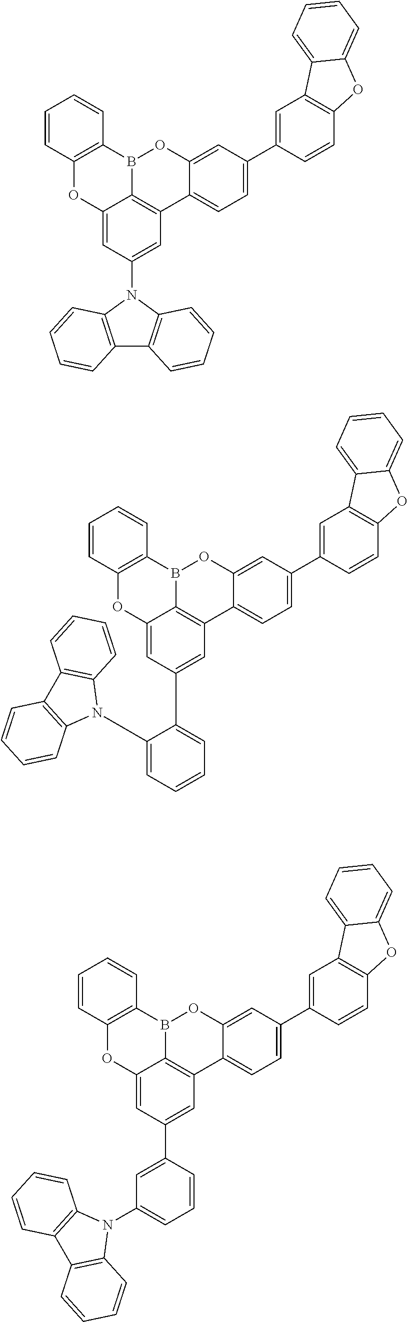 [SMILES: c1ccc2c(c1)Oc1cc(-n3c4ccccc4c4ccccc43)cc3c1B2Oc1cc(-c2ccc4oc5ccccc5c4c2)ccc1-3 ; c1ccc2c(c1)Oc1cc(-c3ccccc3-n3c4ccccc4c4ccccc43)cc3c1B2Oc1cc(-c2ccc4oc5ccccc5c4c2)ccc1-3 ; c1cc(-c2cc3c4c(c2)-c2ccc(-c5ccc6oc7ccccc7c6c5)cc2OB4c2ccccc2O3)cc(-n2c3ccccc3c3ccccc32)c1] 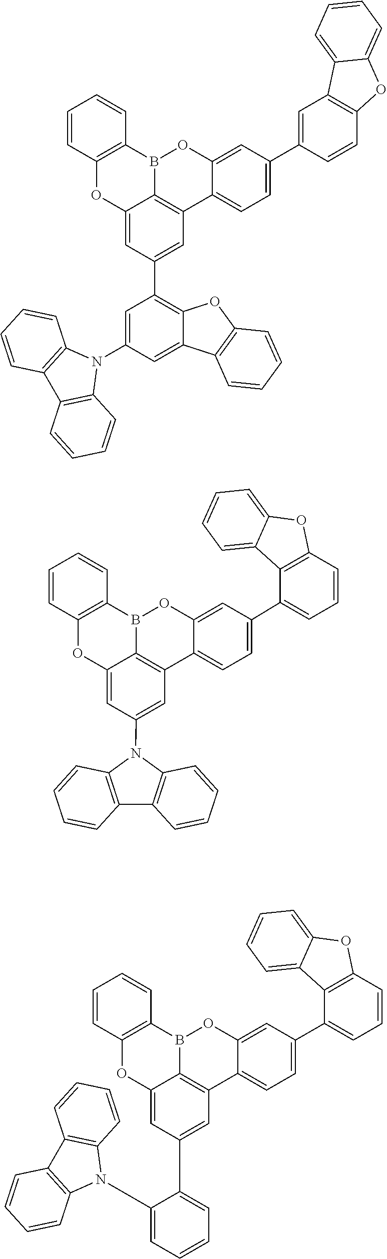 [SMILES: c1ccc2c(c1)Oc1cc(-c3cc(-n4c5ccccc5c5ccccc54)cc4c3oc3ccccc34)cc3c1B2Oc1cc(-c2ccc4oc5ccccc5c4c2)ccc1-3 ; c1ccc2c(c1)Oc1cc(-n3c4ccccc4c4ccccc43)cc3c1B2Oc1cc(-c2cccc4oc5ccccc5c24)ccc1-3 ; c1ccc2c(c1)Oc1cc(-c3ccccc3-n3c4ccccc4c4ccccc43)cc3c1B2Oc1cc(-c2cccc4oc5ccccc5c24)ccc1-3] 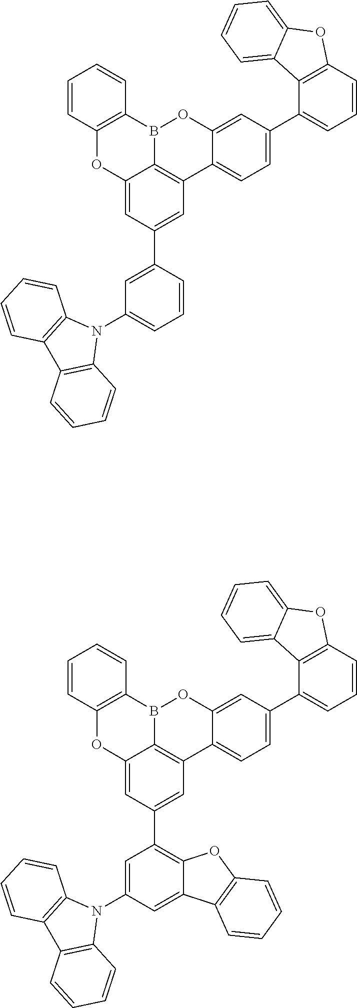 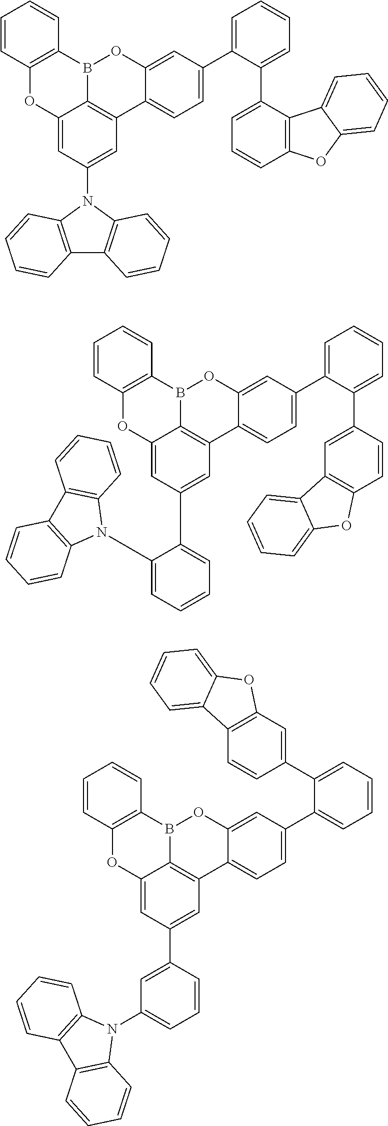 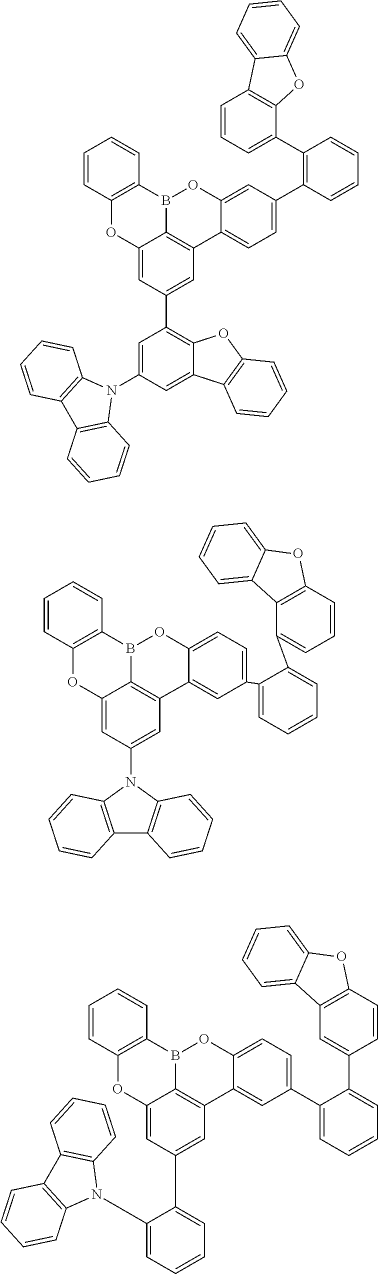 [SMILES: c1ccc2c(c1)Oc1cc(-c3cc(-n4c5ccccc5c5ccccc54)cc4c3oc3ccccc34)cc3c1B2Oc1cc(-c2ccccc2-c2cccc4c2oc2ccccc24)ccc1-3 ; c1ccc2c(c1)Oc1cc(-n3c4ccccc4c4ccccc43)cc3c1B2Oc1ccc(-c2ccccc2-c2cccc4oc5ccccc5c24)cc1-3 ; c1ccc2c(c1)Oc1cc(-c3ccccc3-n3c4ccccc4c4ccccc43)cc3c1B2Oc1ccc(-c2ccccc2-c2ccc4oc5ccccc5c4c2)cc1-3] 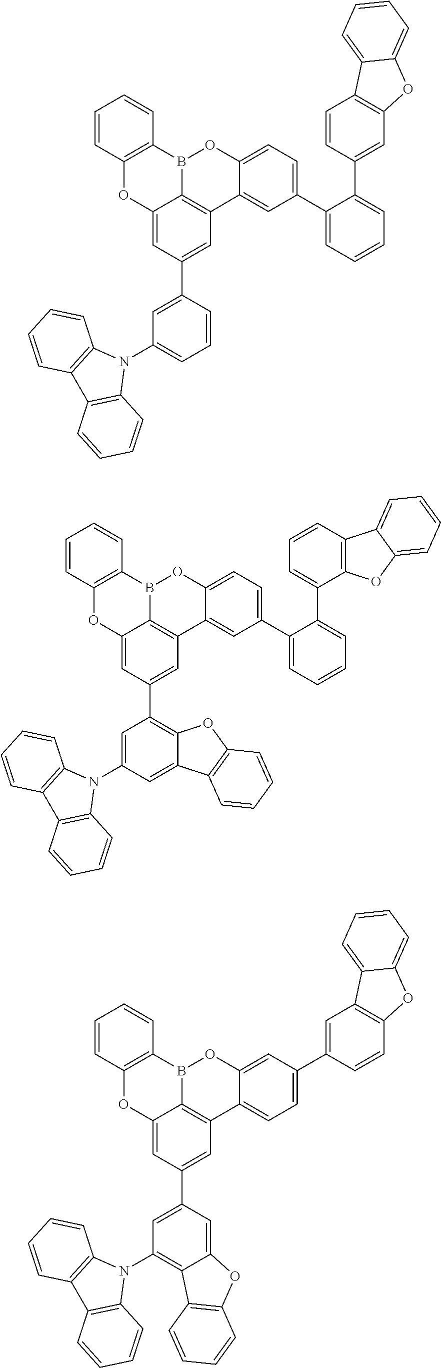 [SMILES: c1cc(-c2cc3c4c(c2)-c2cc(-c5ccccc5-c5ccc6c(c5)oc5ccccc56)ccc2OB4c2ccccc2O3)cc(-n2c3ccccc3c3ccccc32)c1 ; c1ccc2c(c1)Oc1cc(-c3cc(-n4c5ccccc5c5ccccc54)cc4c3oc3ccccc34)cc3c1B2Oc1ccc(-c2ccccc2-c2cccc4c2oc2ccccc24)cc1-3 ; c1ccc2c(c1)Oc1cc(-c3cc(-n4c5ccccc5c5ccccc54)c4c(c3)oc3ccccc34)cc3c1B2Oc1cc(-c2ccc4oc5ccccc5c4c2)ccc1-3] 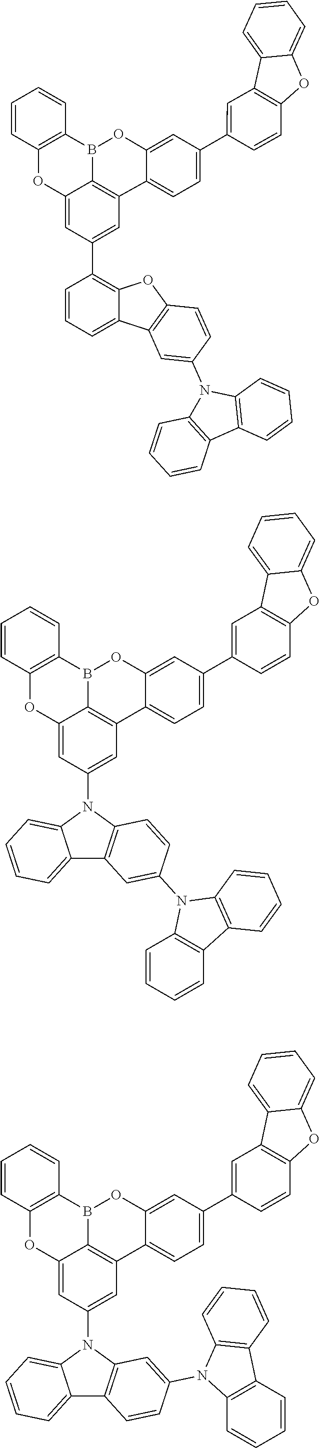 [SMILES: c1ccc2c(c1)Oc1cc(-c3cccc4c3oc3ccc(-n5c6ccccc6c6ccccc65)cc34)cc3c1B2Oc1cc(-c2ccc4oc5ccccc5c4c2)ccc1-3 ; c1ccc2c(c1)Oc1cc(-n3c4ccccc4c4cc(-n5c6ccccc6c6ccccc65)ccc43)cc3c1B2Oc1cc(-c2ccc4oc5ccccc5c4c2)ccc1-3 ; c1ccc2c(c1)Oc1cc(-n3c4ccccc4c4ccc(-n5c6ccccc6c6ccccc65)cc43)cc3c1B2Oc1cc(-c2ccc4oc5ccccc5c4c2)ccc1-3] 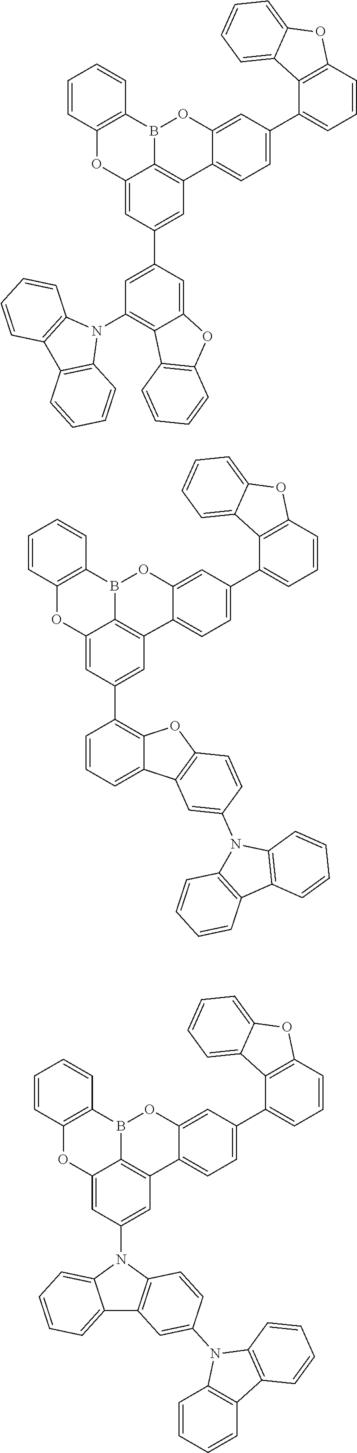 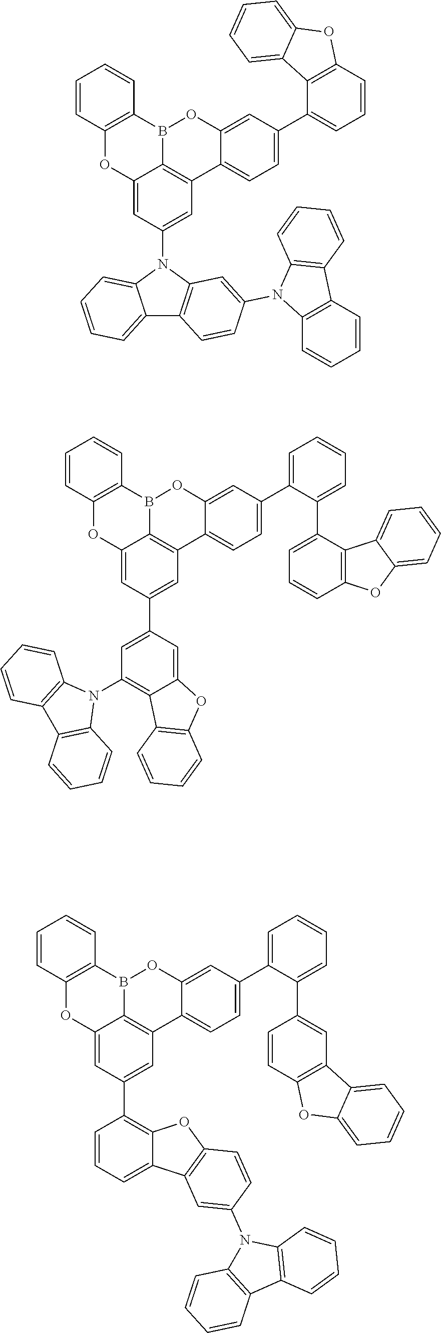 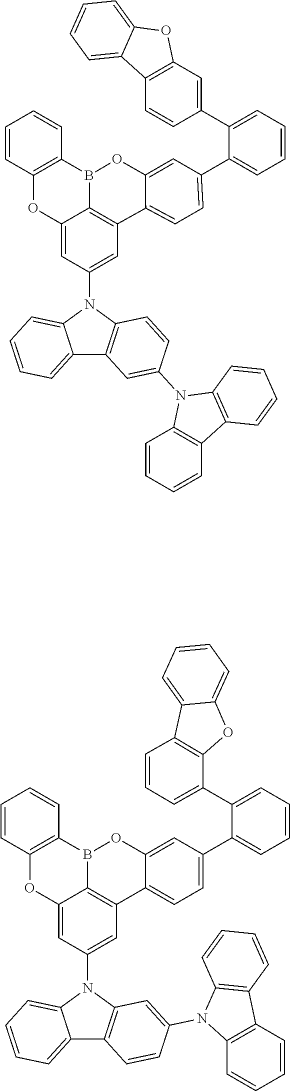 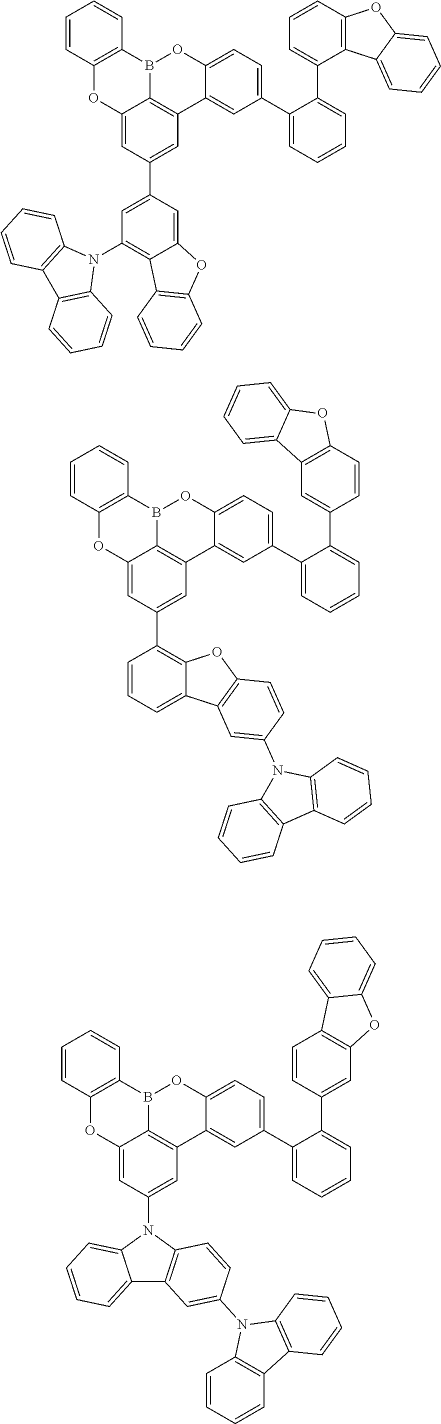 [SMILES: c1ccc2c(c1)Oc1cc(-c3cc(-n4c5ccccc5c5ccccc54)c4c(c3)oc3ccccc34)cc3c1B2Oc1ccc(-c2ccccc2-c2cccc4oc5ccccc5c24)cc1-3 ; c1ccc2c(c1)Oc1cc(-c3cccc4c3oc3ccc(-n5c6ccccc6c6ccccc65)cc34)cc3c1B2Oc1ccc(-c2ccccc2-c2ccc4oc5ccccc5c4c2)cc1-3 ; c1ccc2c(c1)Oc1cc(-n3c4ccccc4c4cc(-n5c6ccccc6c6ccccc65)ccc43)cc3c1B2Oc1ccc(-c2ccccc2-c2ccc4c(c2)oc2ccccc24)cc1-3] 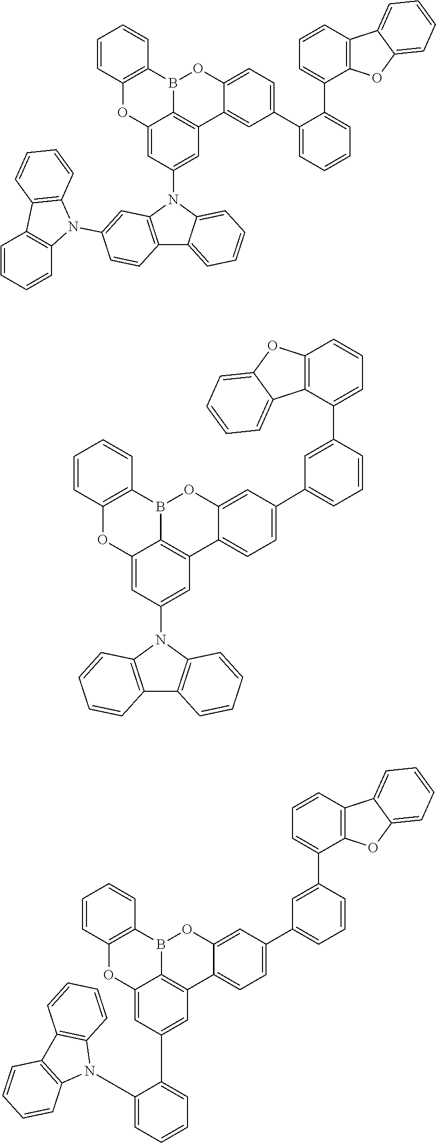 [SMILES: c1ccc2c(c1)Oc1cc(-n3c4ccccc4c4ccc(-n5c6ccccc6c6ccccc65)cc43)cc3c1B2Oc1ccc(-c2ccccc2-c2cccc4c2oc2ccccc24)cc1-3 ; c1cc(-c2ccc3c(c2)OB2c4ccccc4Oc4cc(-n5c6ccccc6c6ccccc65)cc-3c42)cc(-c2cccc3oc4ccccc4c23)c1 ; c1cc(-c2ccc3c(c2)OB2c4ccccc4Oc4cc(-c5ccccc5-n5c6ccccc6c6ccccc65)cc-3c42)cc(-c2cccc3c2oc2ccccc23)c1] 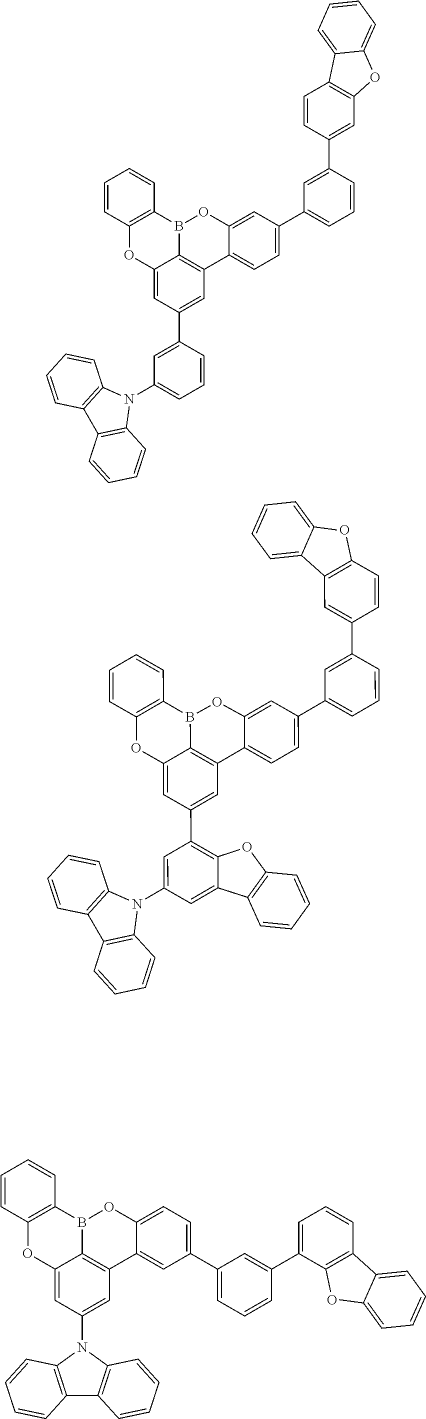 [SMILES: c1cc(-c2ccc3c(c2)OB2c4ccccc4Oc4cc(-c5cccc(-n6c7ccccc7c7ccccc76)c5)cc-3c42)cc(-c2ccc3c(c2)oc2ccccc23)c1 ; c1cc(-c2ccc3c(c2)OB2c4ccccc4Oc4cc(-c5cc(-n6c7ccccc7c7ccccc76)cc6c5oc5ccccc56)cc-3c42)cc(-c2ccc3oc4ccccc4c3c2)c1 ; c1cc(-c2ccc3c(c2)-c2cc(-n4c5ccccc5c5ccccc54)cc4c2B(O3)c2ccccc2O4)cc(-c2cccc3c2oc2ccccc23)c1] 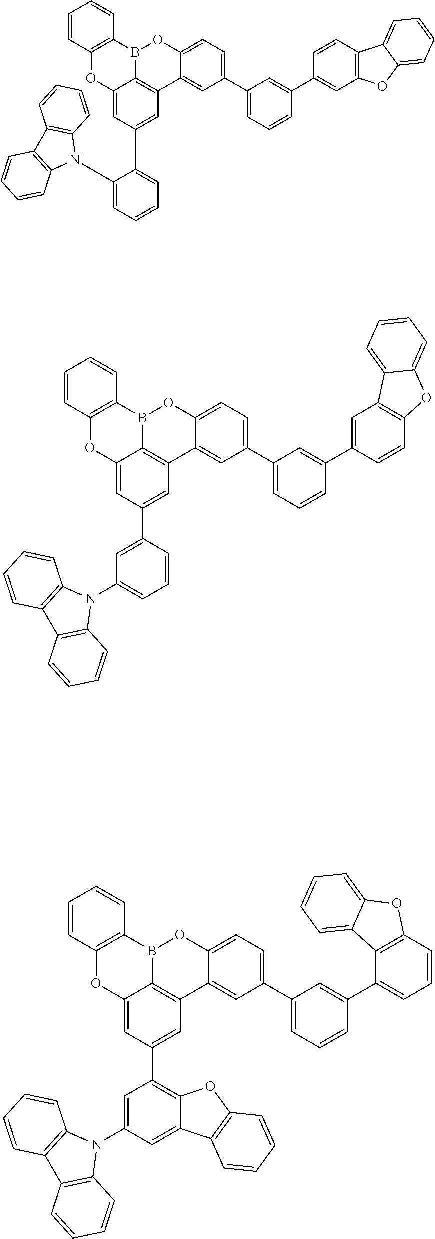 [SMILES: c1cc(-c2ccc3c(c2)-c2cc(-c4ccccc4-n4c5ccccc5c5ccccc54)cc4c2B(O3)c2ccccc2O4)cc(-c2ccc3c(c2)oc2ccccc23)c1 ; c1cc(-c2ccc3c(c2)-c2cc(-c4cccc(-n5c6ccccc6c6ccccc65)c4)cc4c2B(O3)c2ccccc2O4)cc(-c2ccc3oc4ccccc4c3c2)c1 ; c1cc(-c2ccc3c(c2)-c2cc(-c4cc(-n5c6ccccc6c6ccccc65)cc5c4oc4ccccc45)cc4c2B(O3)c2ccccc2O4)cc(-c2cccc3oc4ccccc4c23)c1] 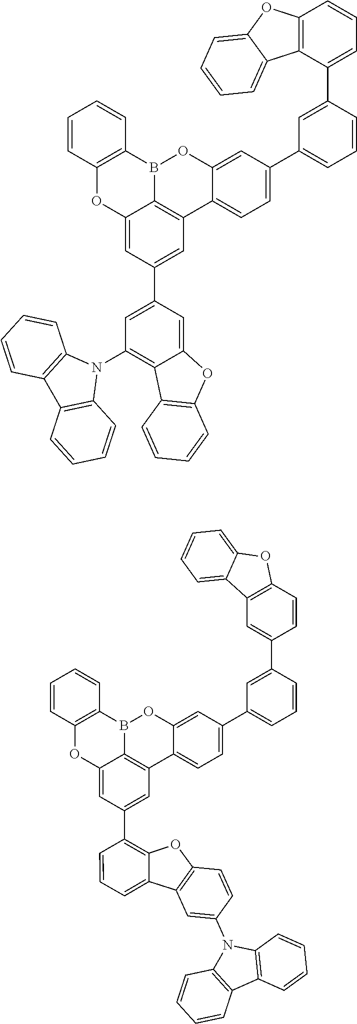 [SMILES: c1cc(-c2ccc3c(c2)OB2c4ccccc4Oc4cc(-c5cc(-n6c7ccccc7c7ccccc76)c6c(c5)oc5ccccc56)cc-3c42)cc(-c2cccc3oc4ccccc4c23)c1 ; c1cc(-c2ccc3c(c2)OB2c4ccccc4Oc4cc(-c5cccc6c5oc5ccc(-n7c8ccccc8c8ccccc87)cc56)cc-3c42)cc(-c2ccc3oc4ccccc4c3c2)c1] 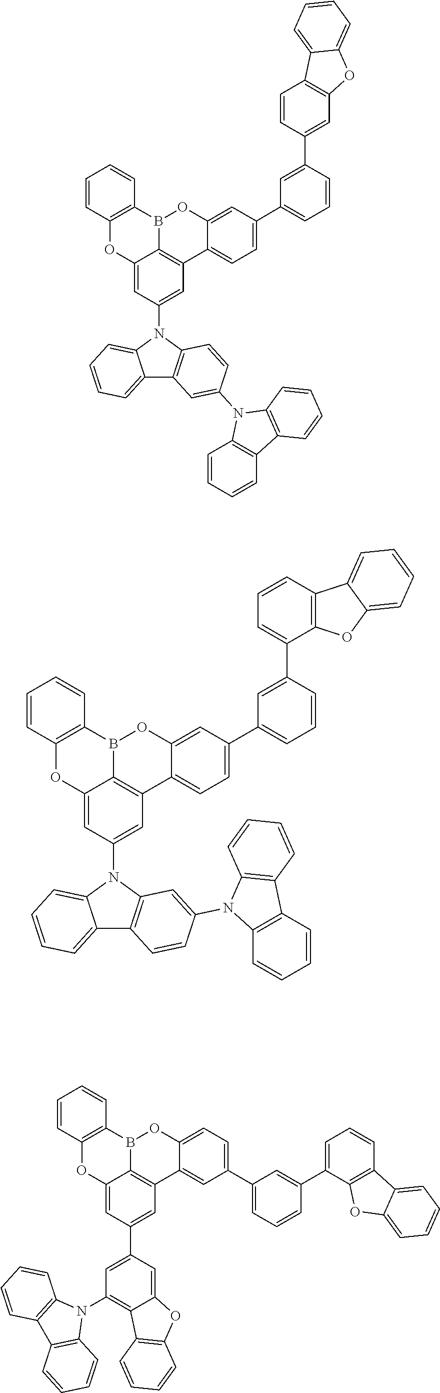 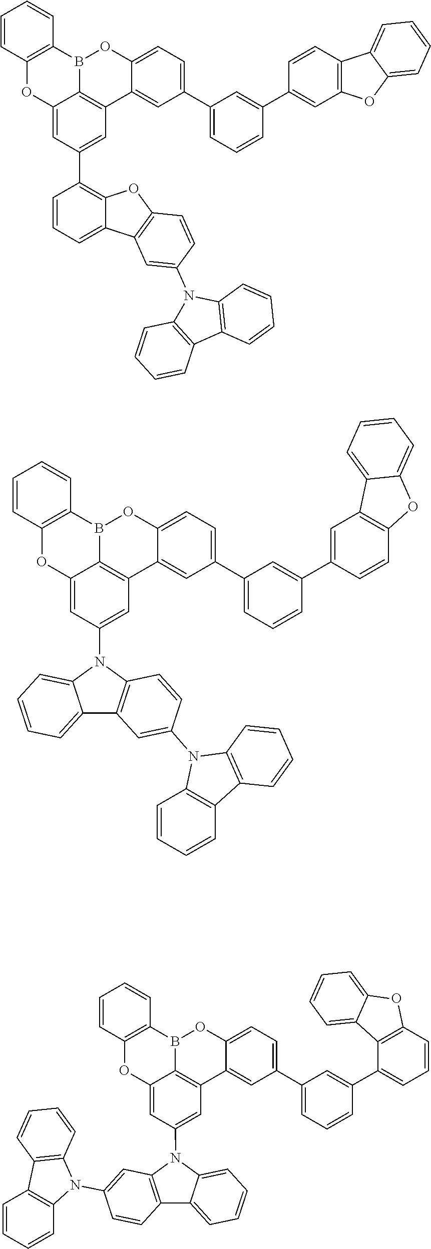 [SMILES: c1cc(-c2ccc3c(c2)-c2cc(-c4cccc5c4oc4ccc(-n6c7ccccc7c7ccccc76)cc45)cc4c2B(O3)c2ccccc2O4)cc(-c2ccc3c(c2)oc2ccccc23)c1 ; c1cc(-c2ccc3c(c2)-c2cc(-n4c5ccccc5c5cc(-n6c7ccccc7c7ccccc76)ccc54)cc4c2B(O3)c2ccccc2O4)cc(-c2ccc3oc4ccccc4c3c2)c1 ; c1cc(-c2ccc3c(c2)-c2cc(-n4c5ccccc5c5ccc(-n6c7ccccc7c7ccccc76)cc54)cc4c2B(O3)c2ccccc2O4)cc(-c2cccc3oc4ccccc4c23)c1] 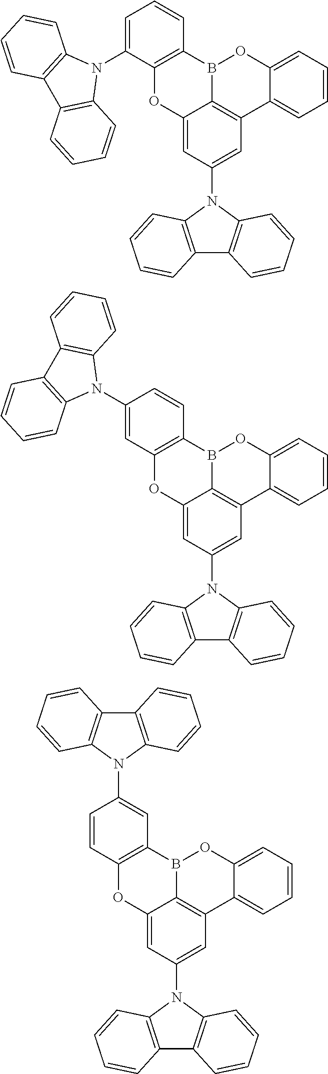 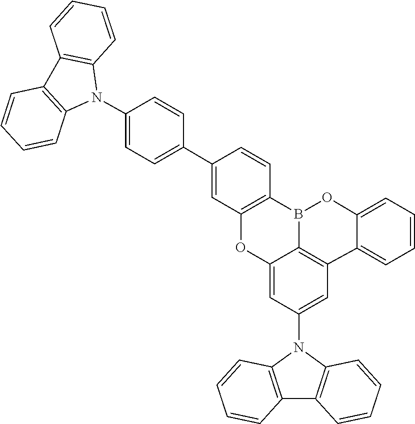 [SMILES: c1ccc2c(c1)OB1c3ccc(-c4ccc(-n5c6ccccc6c6ccccc65)cc4)cc3Oc3cc(-n4c5ccccc5c5ccccc54)cc-2c31] 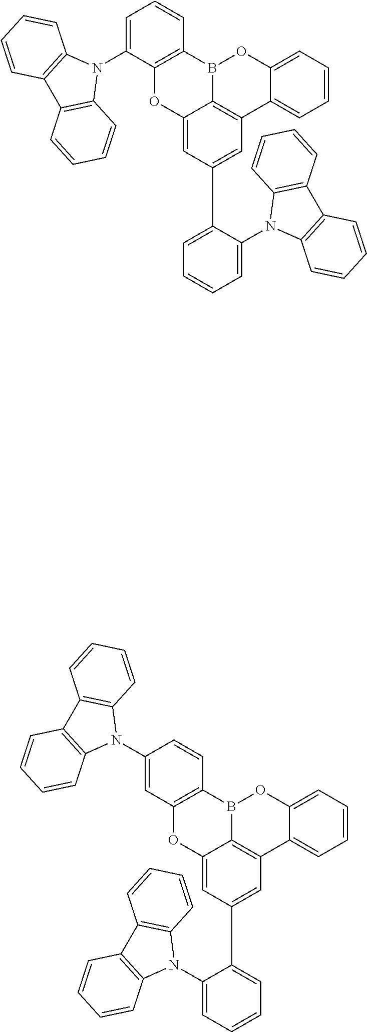 [SMILES: c1ccc2c(c1)OB1c3cccc(-n4c5ccccc5c5ccccc54)c3Oc3cc(-c4ccccc4-n4c5ccccc5c5ccccc54)cc-2c31 ; c1ccc2c(c1)OB1c3ccc(-n4c5ccccc5c5ccccc54)cc3Oc3cc(-c4ccccc4-n4c5ccccc5c5ccccc54)cc-2c31] 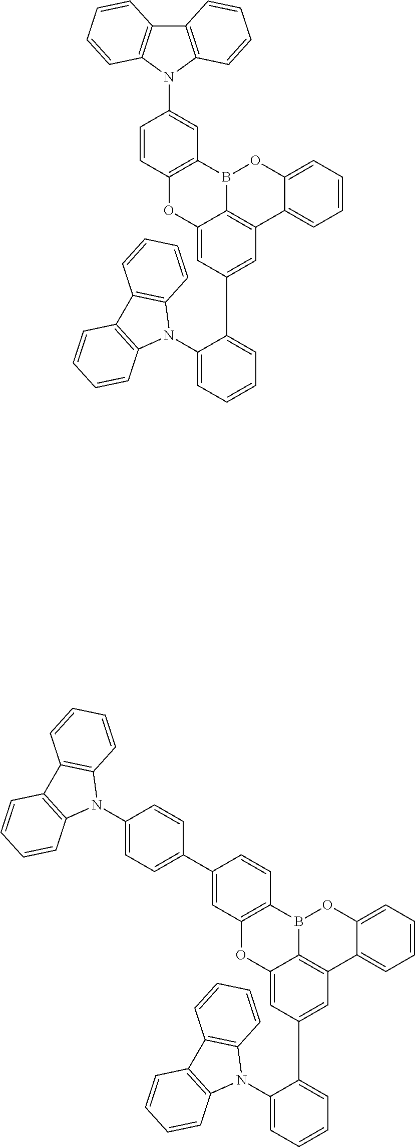 [SMILES: c1ccc2c(c1)OB1c3cc(-n4c5ccccc5c5ccccc54)ccc3Oc3cc(-c4ccccc4-n4c5ccccc5c5ccccc54)cc-2c31 ; c1ccc2c(c1)OB1c3ccc(-c4ccc(-n5c6ccccc6c6ccccc65)cc4)cc3Oc3cc(-c4ccccc4-n4c5ccccc5c5ccccc54)cc-2c31] 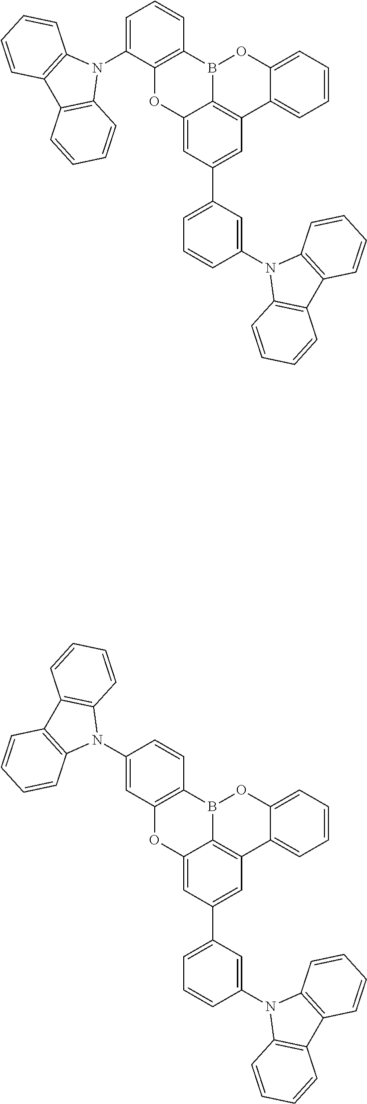 [SMILES: c1cc(-c2cc3c4c(c2)-c2ccccc2OB4c2cccc(-n4c5ccccc5c5ccccc54)c2O3)cc(-n2c3ccccc3c3ccccc32)c1 ; c1cc(-c2cc3c4c(c2)-c2ccccc2OB4c2ccc(-n4c5ccccc5c5ccccc54)cc2O3)cc(-n2c3ccccc3c3ccccc32)c1] 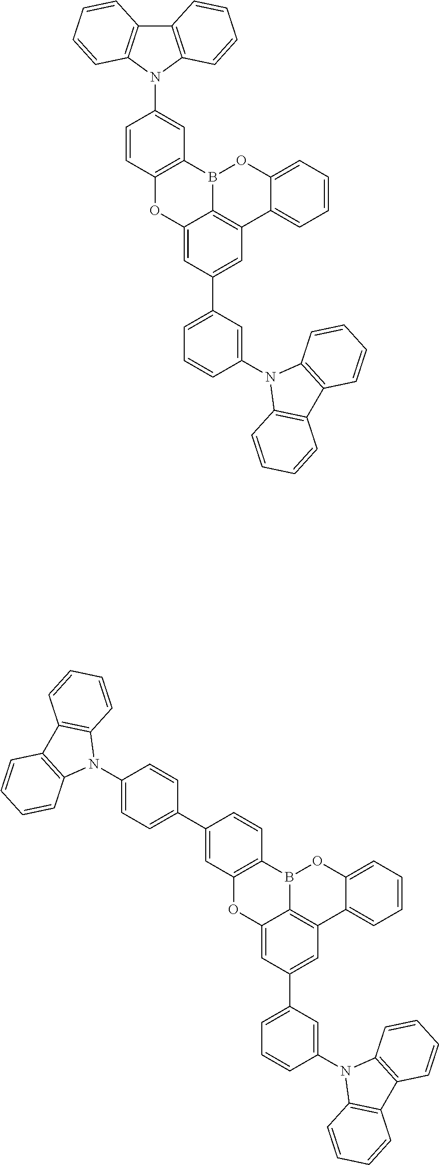 [SMILES: c1cc(-c2cc3c4c(c2)-c2ccccc2OB4c2cc(-n4c5ccccc5c5ccccc54)ccc2O3)cc(-n2c3ccccc3c3ccccc32)c1 ; c1cc(-c2cc3c4c(c2)-c2ccccc2OB4c2ccc(-c4ccc(-n5c6ccccc6c6ccccc65)cc4)cc2O3)cc(-n2c3ccccc3c3ccccc32)c1] 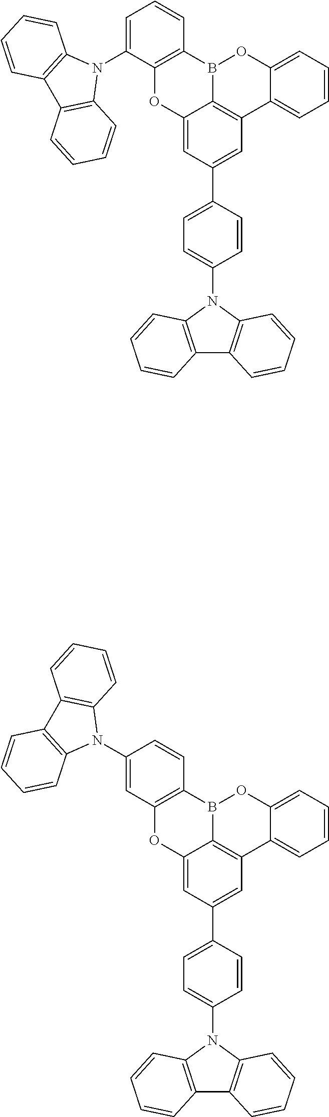 [SMILES: c1ccc2c(c1)OB1c3cccc(-n4c5ccccc5c5ccccc54)c3Oc3cc(-c4ccc(-n5c6ccccc6c6ccccc65)cc4)cc-2c31 ; c1ccc2c(c1)OB1c3ccc(-n4c5ccccc5c5ccccc54)cc3Oc3cc(-c4ccc(-n5c6ccccc6c6ccccc65)cc4)cc-2c31] 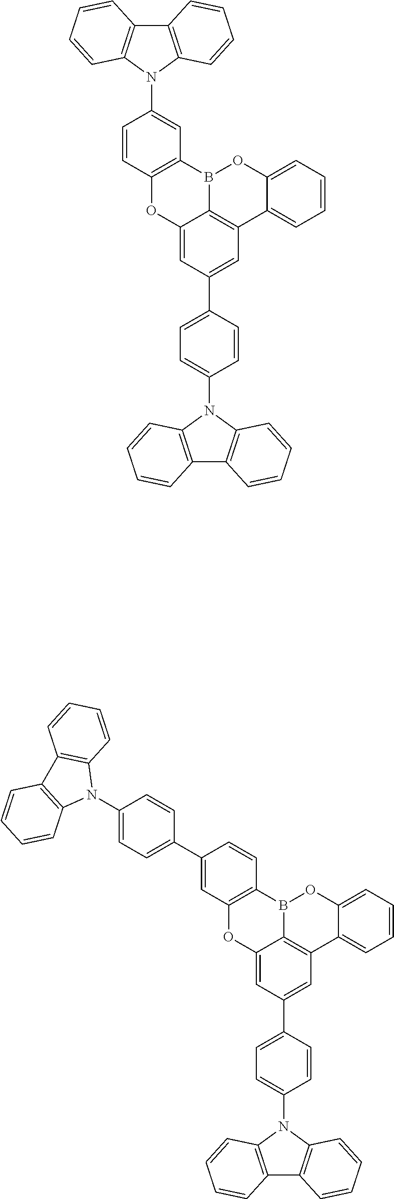 [SMILES: c1ccc2c(c1)OB1c3cc(-n4c5ccccc5c5ccccc54)ccc3Oc3cc(-c4ccc(-n5c6ccccc6c6ccccc65)cc4)cc-2c31 ; c1ccc2c(c1)OB1c3ccc(-c4ccc(-n5c6ccccc6c6ccccc65)cc4)cc3Oc3cc(-c4ccc(-n5c6ccccc6c6ccccc65)cc4)cc-2c31] 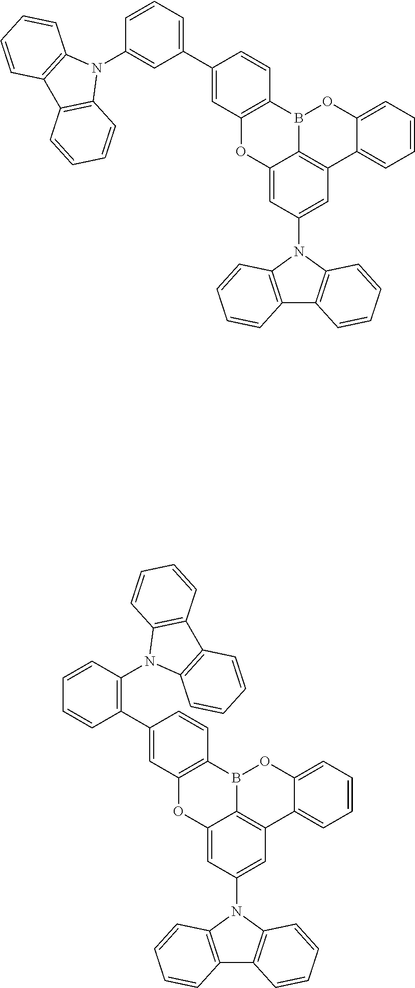 [SMILES: c1cc(-c2ccc3c(c2)Oc2cc(-n4c5ccccc5c5ccccc54)cc4c2B3Oc2ccccc2-4)cc(-n2c3ccccc3c3ccccc32)c1 ; c1ccc2c(c1)OB1c3ccc(-c4ccccc4-n4c5ccccc5c5ccccc54)cc3Oc3cc(-n4c5ccccc5c5ccccc54)cc-2c31] 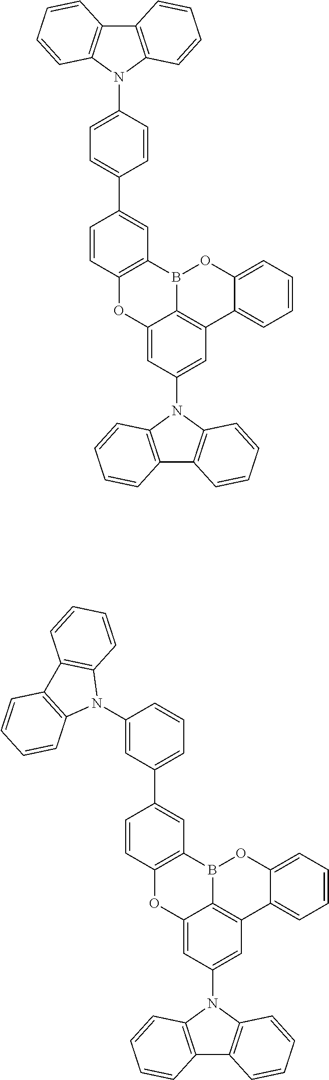 [SMILES: c1ccc2c(c1)OB1c3cc(-c4ccc(-n5c6ccccc6c6ccccc65)cc4)ccc3Oc3cc(-n4c5ccccc5c5ccccc54)cc-2c31 ; c1cc(-c2ccc3c(c2)B2Oc4ccccc4-c4cc(-n5c6ccccc6c6ccccc65)cc(c42)O3)cc(-n2c3ccccc3c3ccccc32)c1] 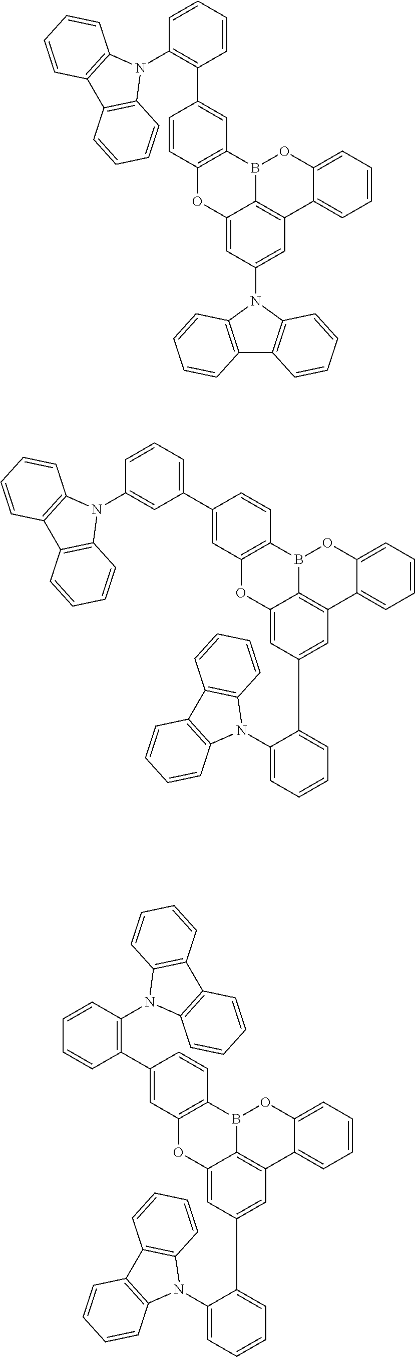 [SMILES: c1ccc2c(c1)OB1c3cc(-c4ccccc4-n4c5ccccc5c5ccccc54)ccc3Oc3cc(-n4c5ccccc5c5ccccc54)cc-2c31 ; c1cc(-c2ccc3c(c2)Oc2cc(-c4ccccc4-n4c5ccccc5c5ccccc54)cc4c2B3Oc2ccccc2-4)cc(-n2c3ccccc3c3ccccc32)c1 ; c1ccc2c(c1)OB1c3ccc(-c4ccccc4-n4c5ccccc5c5ccccc54)cc3Oc3cc(-c4ccccc4-n4c5ccccc5c5ccccc54)cc-2c31] 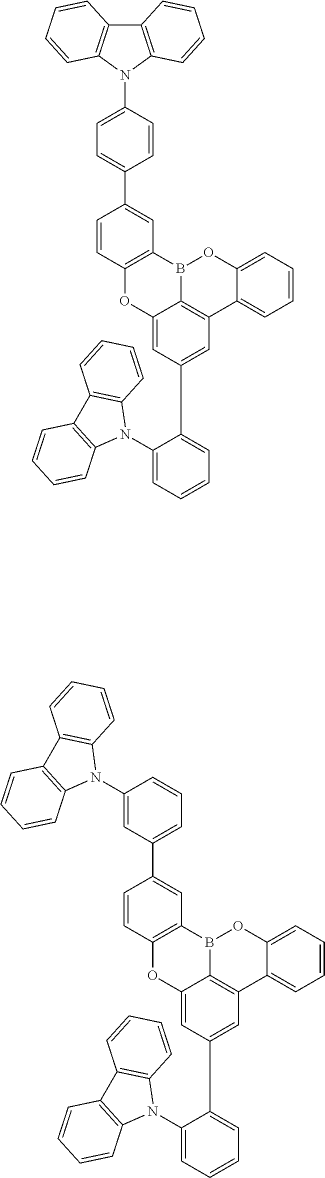 [SMILES: c1ccc2c(c1)OB1c3cc(-c4ccc(-n5c6ccccc6c6ccccc65)cc4)ccc3Oc3cc(-c4ccccc4-n4c5ccccc5c5ccccc54)cc-2c31 ; c1cc(-c2ccc3c(c2)B2Oc4ccccc4-c4cc(-c5ccccc5-n5c6ccccc6c6ccccc65)cc(c42)O3)cc(-n2c3ccccc3c3ccccc32)c1] 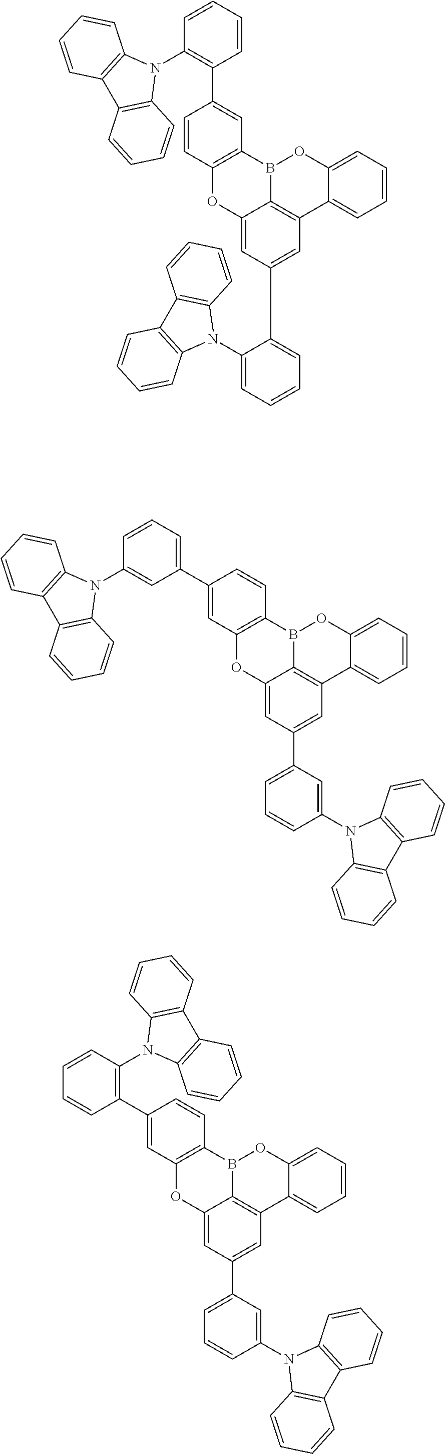 [SMILES: c1ccc2c(c1)OB1c3cc(-c4ccccc4-n4c5ccccc5c5ccccc54)ccc3Oc3cc(-c4ccccc4-n4c5ccccc5c5ccccc54)cc-2c31 ; c1cc(-c2ccc3c(c2)Oc2cc(-c4cccc(-n5c6ccccc6c6ccccc65)c4)cc4c2B3Oc2ccccc2-4)cc(-n2c3ccccc3c3ccccc32)c1 ; c1cc(-c2cc3c4c(c2)-c2ccccc2OB4c2ccc(-c4ccccc4-n4c5ccccc5c5ccccc54)cc2O3)cc(-n2c3ccccc3c3ccccc32)c1] 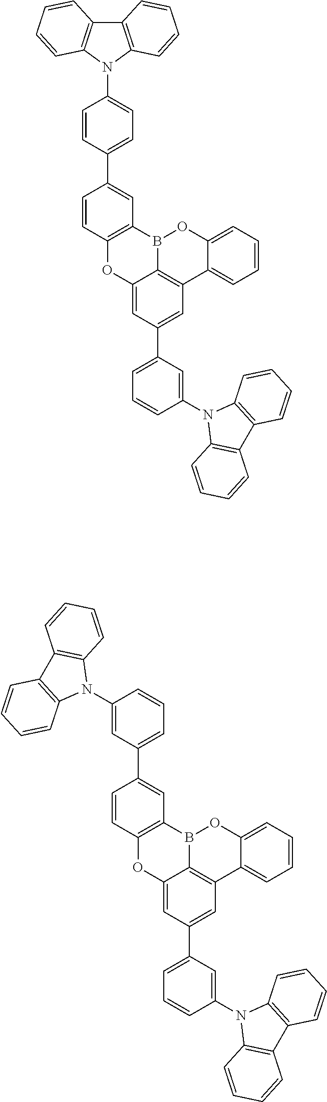 [SMILES: c1cc(-c2cc3c4c(c2)-c2ccccc2OB4c2cc(-c4ccc(-n5c6ccccc6c6ccccc65)cc4)ccc2O3)cc(-n2c3ccccc3c3ccccc32)c1 ; c1cc(-c2ccc3c(c2)B2Oc4ccccc4-c4cc(-c5cccc(-n6c7ccccc7c7ccccc76)c5)cc(c42)O3)cc(-n2c3ccccc3c3ccccc32)c1] 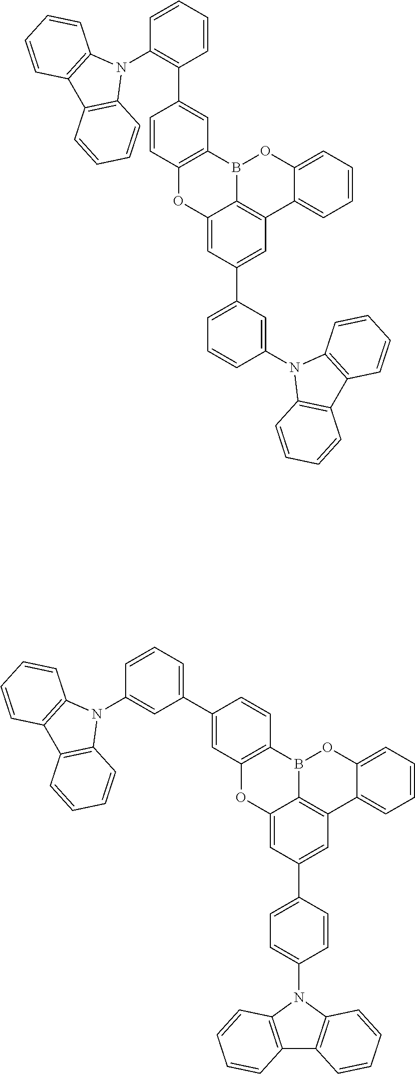 [SMILES: c1cc(-c2cc3c4c(c2)-c2ccccc2OB4c2cc(-c4ccccc4-n4c5ccccc5c5ccccc54)ccc2O3)cc(-n2c3ccccc3c3ccccc32)c1 ; c1cc(-c2ccc3c(c2)Oc2cc(-c4ccc(-n5c6ccccc6c6ccccc65)cc4)cc4c2B3Oc2ccccc2-4)cc(-n2c3ccccc3c3ccccc32)c1] 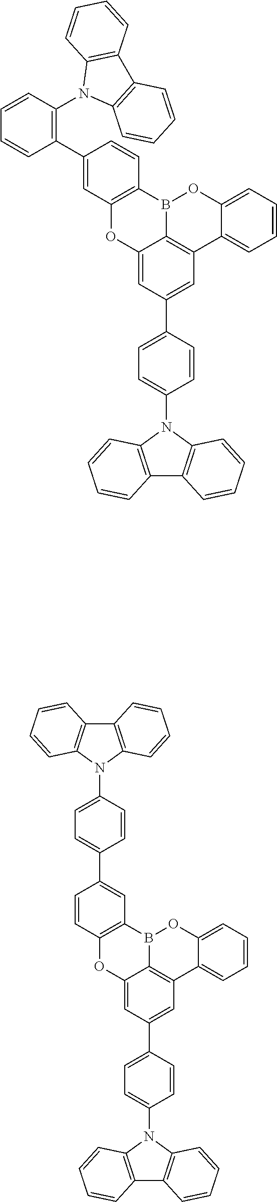 [SMILES: c1ccc2c(c1)OB1c3ccc(-c4ccccc4-n4c5ccccc5c5ccccc54)cc3Oc3cc(-c4ccc(-n5c6ccccc6c6ccccc65)cc4)cc-2c31 ; c1ccc2c(c1)OB1c3cc(-c4ccc(-n5c6ccccc6c6ccccc65)cc4)ccc3Oc3cc(-c4ccc(-n5c6ccccc6c6ccccc65)cc4)cc-2c31] 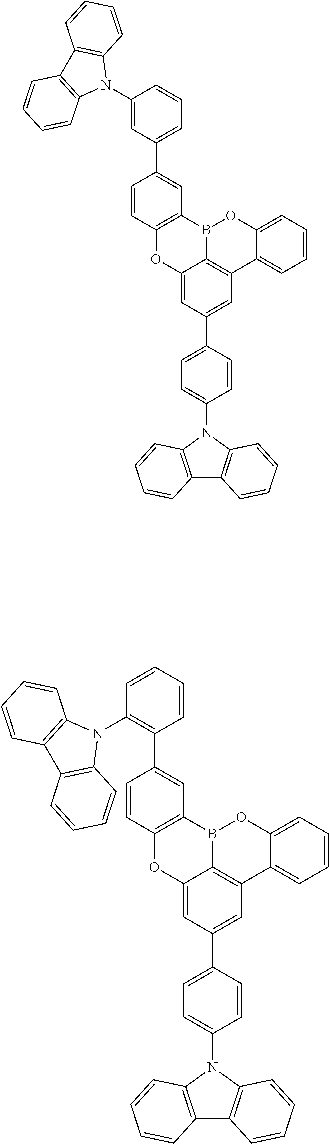 [SMILES: c1cc(-c2ccc3c(c2)B2Oc4ccccc4-c4cc(-c5ccc(-n6c7ccccc7c7ccccc76)cc5)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-c4ccc(-n5c6ccccc6c6ccccc65)cc4)cc-2c31] 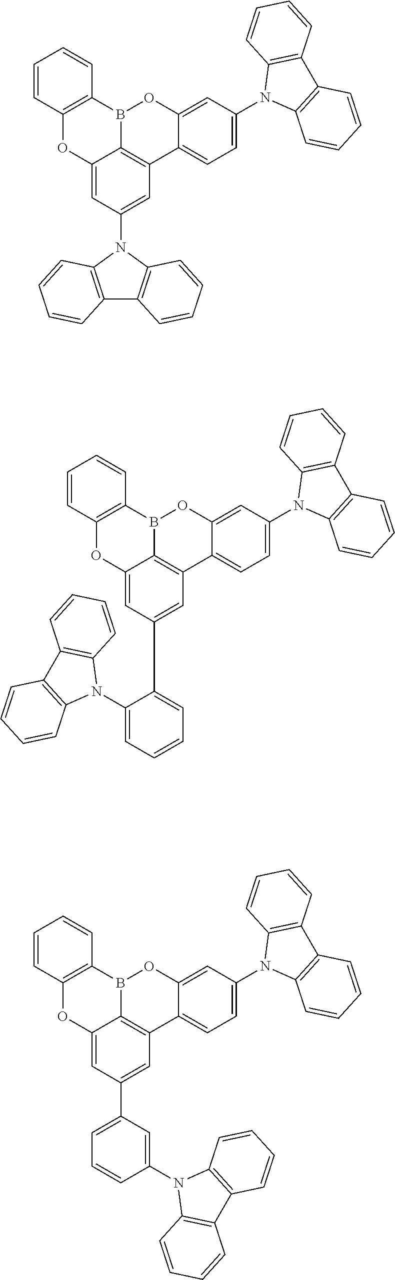 [SMILES: c1ccc2c(c1)Oc1cc(-n3c4ccccc4c4ccccc43)cc3c1B2Oc1cc(-n2c4ccccc4c4ccccc42)ccc1-3 ; c1ccc2c(c1)Oc1cc(-c3ccccc3-n3c4ccccc4c4ccccc43)cc3c1B2Oc1cc(-n2c4ccccc4c4ccccc42)ccc1-3 ; c1cc(-c2cc3c4c(c2)-c2ccc(-n5c6ccccc6c6ccccc65)cc2OB4c2ccccc2O3)cc(-n2c3ccccc3c3ccccc32)c1] 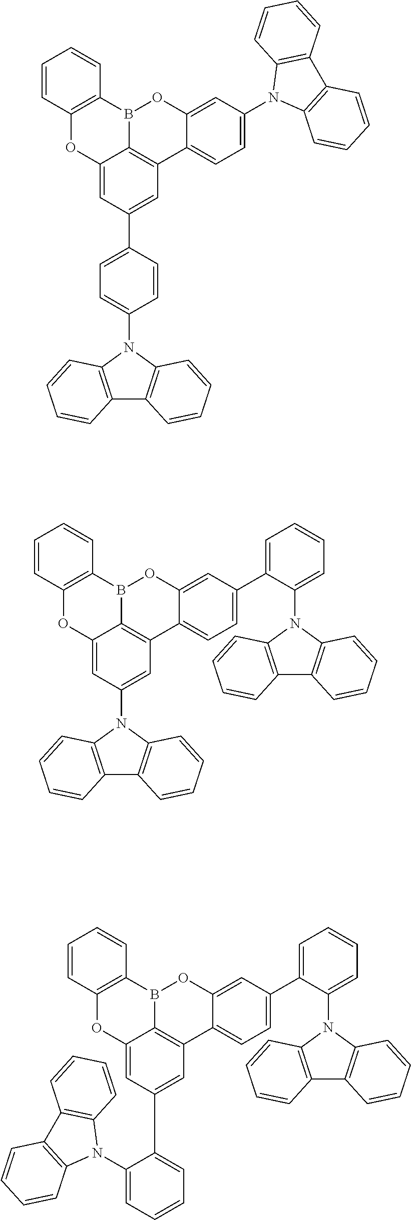 [SMILES: c1ccc2c(c1)Oc1cc(-c3ccc(-n4c5ccccc5c5ccccc54)cc3)cc3c1B2Oc1cc(-n2c4ccccc4c4ccccc42)ccc1-3 ; c1ccc2c(c1)Oc1cc(-n3c4ccccc4c4ccccc43)cc3c1B2Oc1cc(-c2ccccc2-n2c4ccccc4c4ccccc42)ccc1-3 ; c1ccc2c(c1)Oc1cc(-c3ccccc3-n3c4ccccc4c4ccccc43)cc3c1B2Oc1cc(-c2ccccc2-n2c4ccccc4c4ccccc42)ccc1-3] 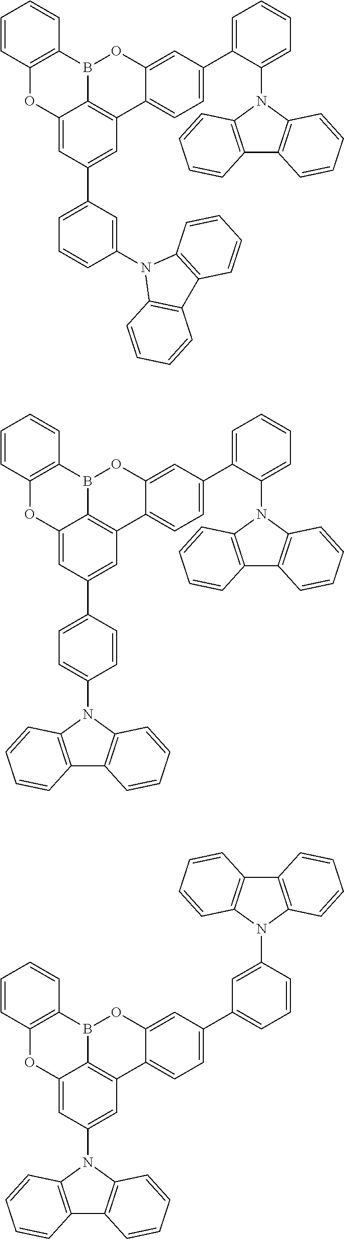 [SMILES: c1cc(-c2cc3c4c(c2)-c2ccc(-c5ccccc5-n5c6ccccc6c6ccccc65)cc2OB4c2ccccc2O3)cc(-n2c3ccccc3c3ccccc32)c1 ; c1ccc2c(c1)Oc1cc(-c3ccc(-n4c5ccccc5c5ccccc54)cc3)cc3c1B2Oc1cc(-c2ccccc2-n2c4ccccc4c4ccccc42)ccc1-3 ; c1cc(-c2ccc3c(c2)OB2c4ccccc4Oc4cc(-n5c6ccccc6c6ccccc65)cc-3c42)cc(-n2c3ccccc3c3ccccc32)c1] 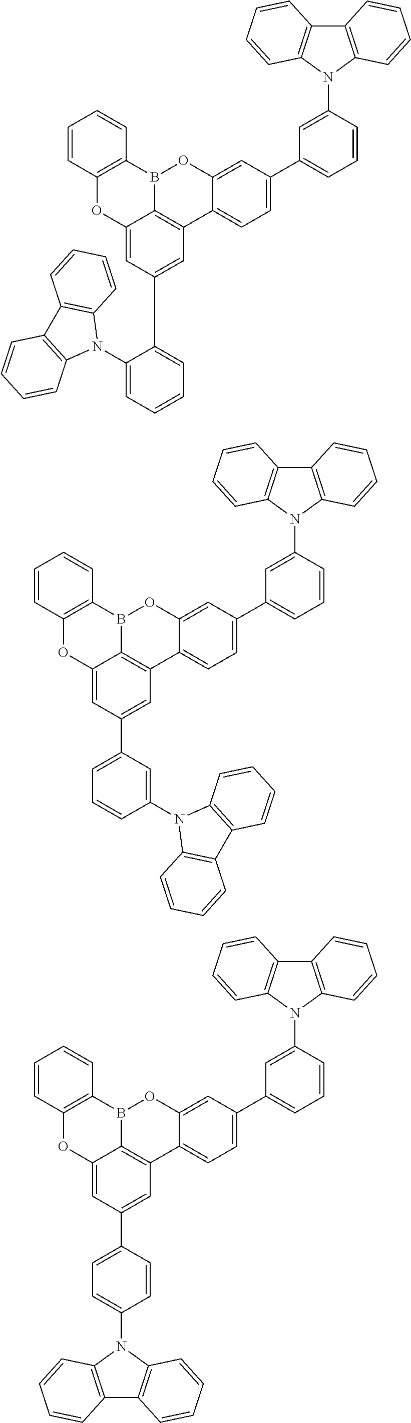 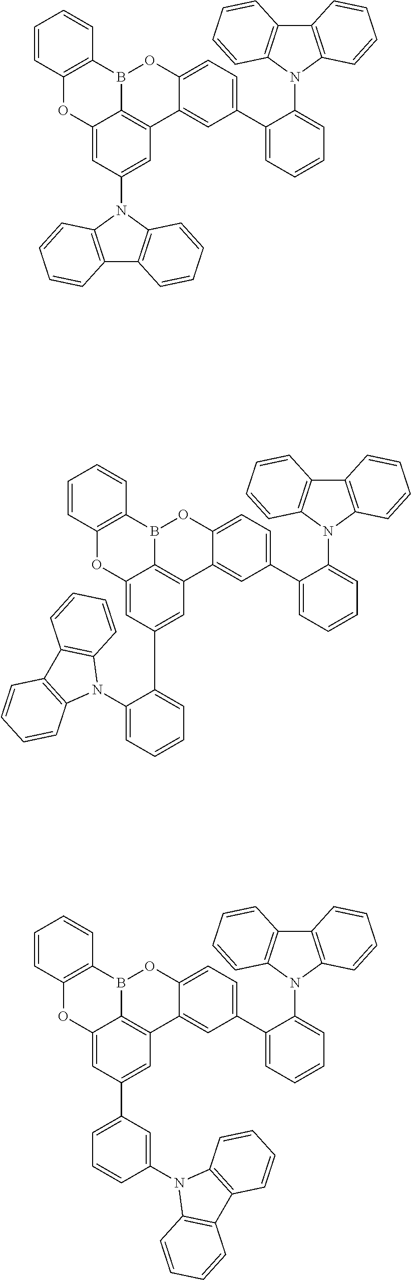 [SMILES: c1ccc2c(c1)Oc1cc(-n3c4ccccc4c4ccccc43)cc3c1B2Oc1ccc(-c2ccccc2-n2c4ccccc4c4ccccc42)cc1-3 ; c1ccc2c(c1)Oc1cc(-c3ccccc3-n3c4ccccc4c4ccccc43)cc3c1B2Oc1ccc(-c2ccccc2-n2c4ccccc4c4ccccc42)cc1-3 ; c1cc(-c2cc3c4c(c2)-c2cc(-c5ccccc5-n5c6ccccc6c6ccccc65)ccc2OB4c2ccccc2O3)cc(-n2c3ccccc3c3ccccc32)c1] 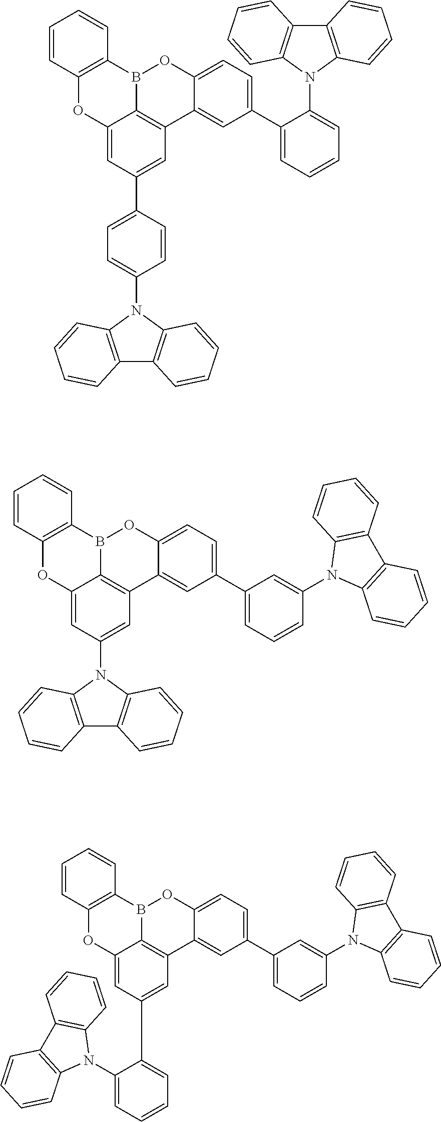 [SMILES: c1ccc2c(c1)Oc1cc(-c3ccc(-n4c5ccccc5c5ccccc54)cc3)cc3c1B2Oc1ccc(-c2ccccc2-n2c4ccccc4c4ccccc42)cc1-3 ; c1cc(-c2ccc3c(c2)-c2cc(-n4c5ccccc5c5ccccc54)cc4c2B(O3)c2ccccc2O4)cc(-n2c3ccccc3c3ccccc32)c1 ; c1cc(-c2ccc3c(c2)-c2cc(-c4ccccc4-n4c5ccccc5c5ccccc54)cc4c2B(O3)c2ccccc2O4)cc(-n2c3ccccc3c3ccccc32)c1] 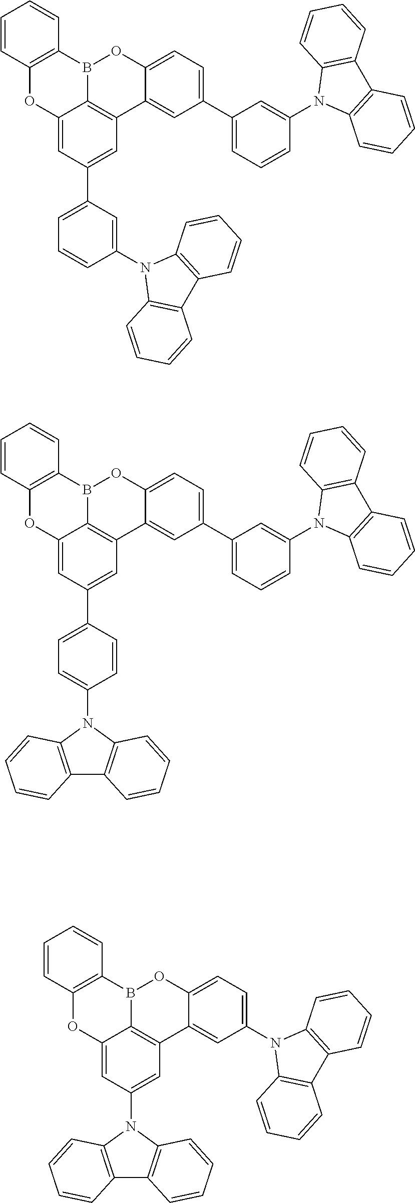 [SMILES: c1cc(-c2ccc3c(c2)-c2cc(-c4cccc(-n5c6ccccc6c6ccccc65)c4)cc4c2B(O3)c2ccccc2O4)cc(-n2c3ccccc3c3ccccc32)c1 ; c1cc(-c2ccc3c(c2)-c2cc(-c4ccc(-n5c6ccccc6c6ccccc65)cc4)cc4c2B(O3)c2ccccc2O4)cc(-n2c3ccccc3c3ccccc32)c1 ; c1ccc2c(c1)Oc1cc(-n3c4ccccc4c4ccccc43)cc3c1B2Oc1ccc(-n2c4ccccc4c4ccccc42)cc1-3] 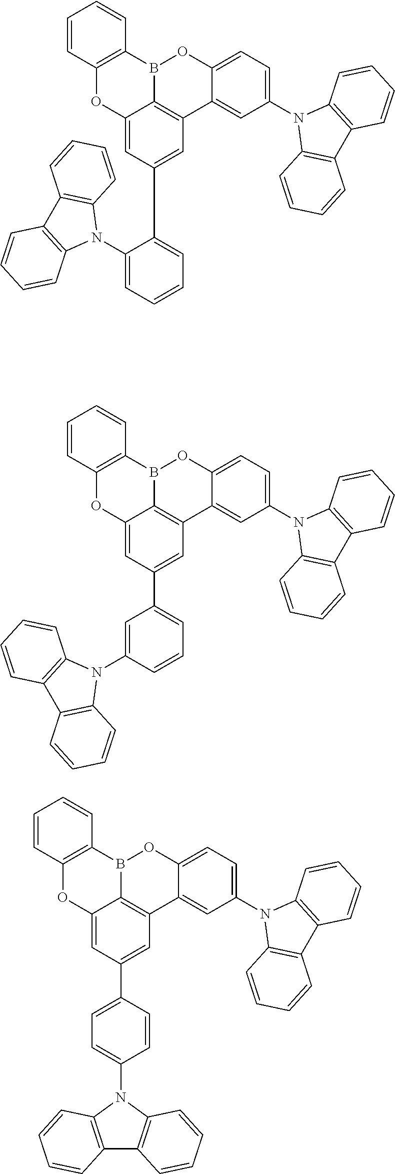 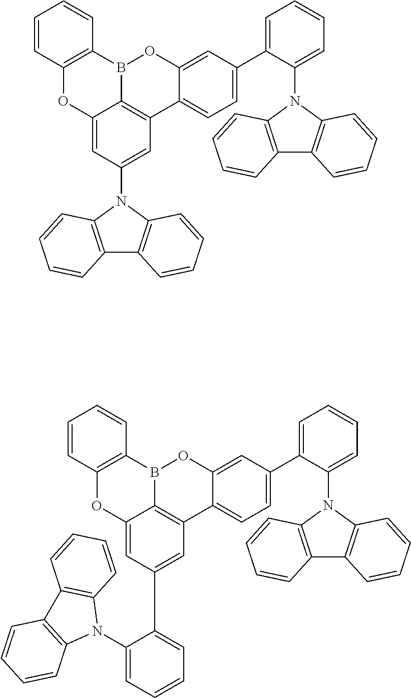 [SMILES: c1ccc2c(c1)Oc1cc(-n3c4ccccc4c4ccccc43)cc3c1B2Oc1cc(-c2ccccc2-n2c4ccccc4c4ccccc42)ccc1-3 ; c1ccc2c(c1)Oc1cc(-c3ccccc3-n3c4ccccc4c4ccccc43)cc3c1B2Oc1cc(-c2ccccc2-n2c4ccccc4c4ccccc42)ccc1-3] 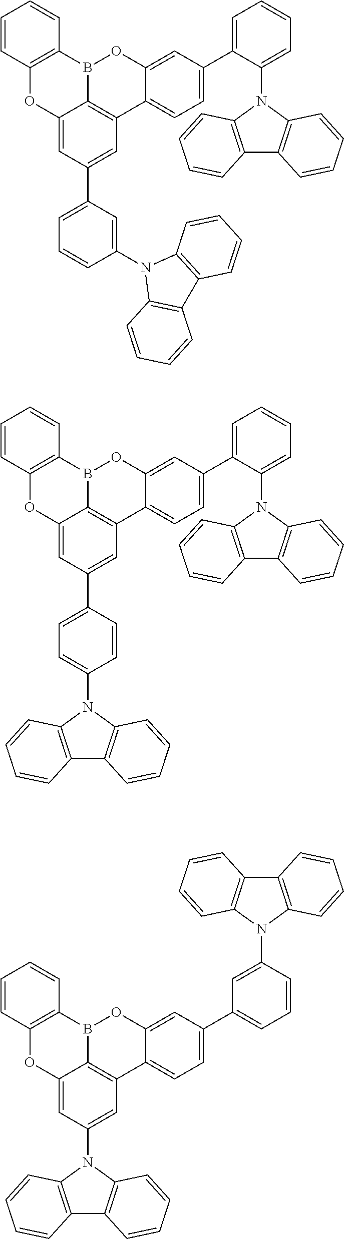 [SMILES: c1cc(-c2cc3c4c(c2)-c2ccc(-c5ccccc5-n5c6ccccc6c6ccccc65)cc2OB4c2ccccc2O3)cc(-n2c3ccccc3c3ccccc32)c1 ; c1ccc2c(c1)Oc1cc(-c3ccc(-n4c5ccccc5c5ccccc54)cc3)cc3c1B2Oc1cc(-c2ccccc2-n2c4ccccc4c4ccccc42)ccc1-3 ; c1cc(-c2ccc3c(c2)OB2c4ccccc4Oc4cc(-n5c6ccccc6c6ccccc65)cc-3c42)cc(-n2c3ccccc3c3ccccc32)c1] 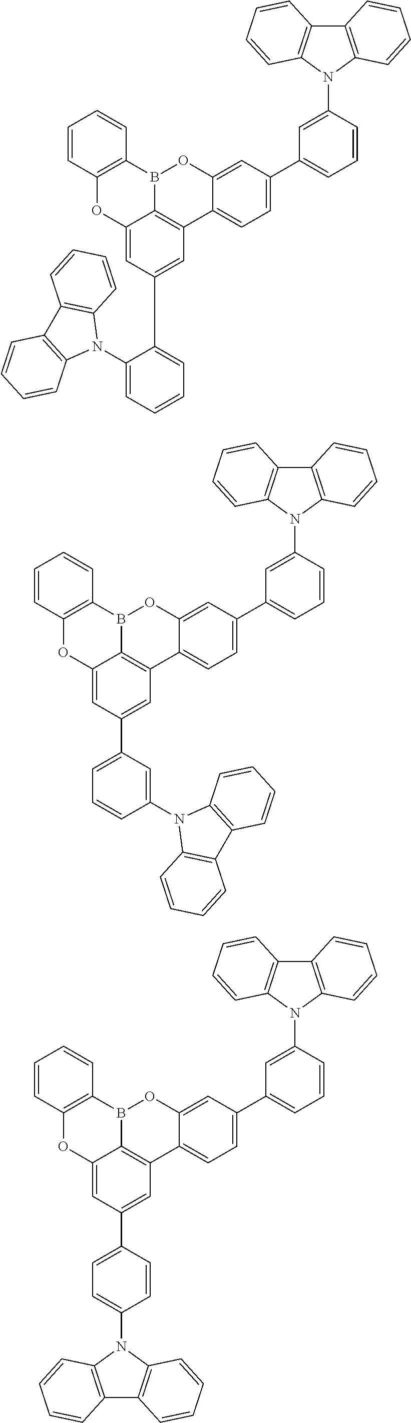 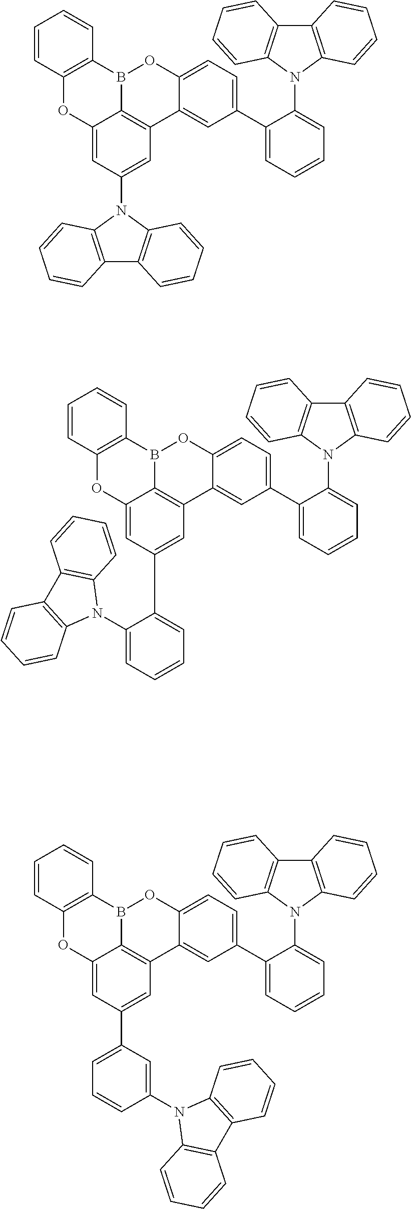 [SMILES: c1ccc2c(c1)Oc1cc(-n3c4ccccc4c4ccccc43)cc3c1B2Oc1ccc(-c2ccccc2-n2c4ccccc4c4ccccc42)cc1-3 ; c1ccc2c(c1)Oc1cc(-c3ccccc3-n3c4ccccc4c4ccccc43)cc3c1B2Oc1ccc(-c2ccccc2-n2c4ccccc4c4ccccc42)cc1-3 ; c1cc(-c2cc3c4c(c2)-c2cc(-c5ccccc5-n5c6ccccc6c6ccccc65)ccc2OB4c2ccccc2O3)cc(-n2c3ccccc3c3ccccc32)c1] 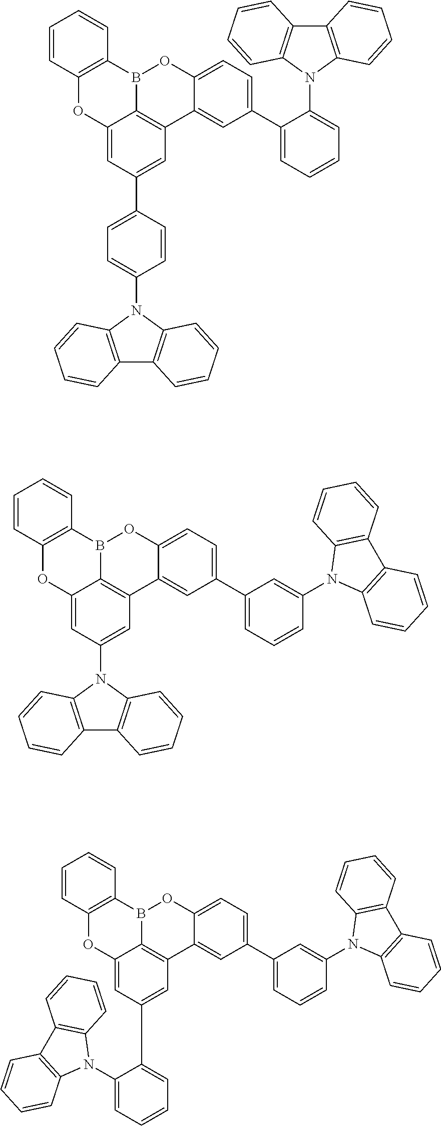 [SMILES: c1ccc2c(c1)Oc1cc(-c3ccc(-n4c5ccccc5c5ccccc54)cc3)cc3c1B2Oc1ccc(-c2ccccc2-n2c4ccccc4c4ccccc42)cc1-3 ; c1cc(-c2ccc3c(c2)-c2cc(-n4c5ccccc5c5ccccc54)cc4c2B(O3)c2ccccc2O4)cc(-n2c3ccccc3c3ccccc32)c1 ; c1cc(-c2ccc3c(c2)-c2cc(-c4ccccc4-n4c5ccccc5c5ccccc54)cc4c2B(O3)c2ccccc2O4)cc(-n2c3ccccc3c3ccccc32)c1] 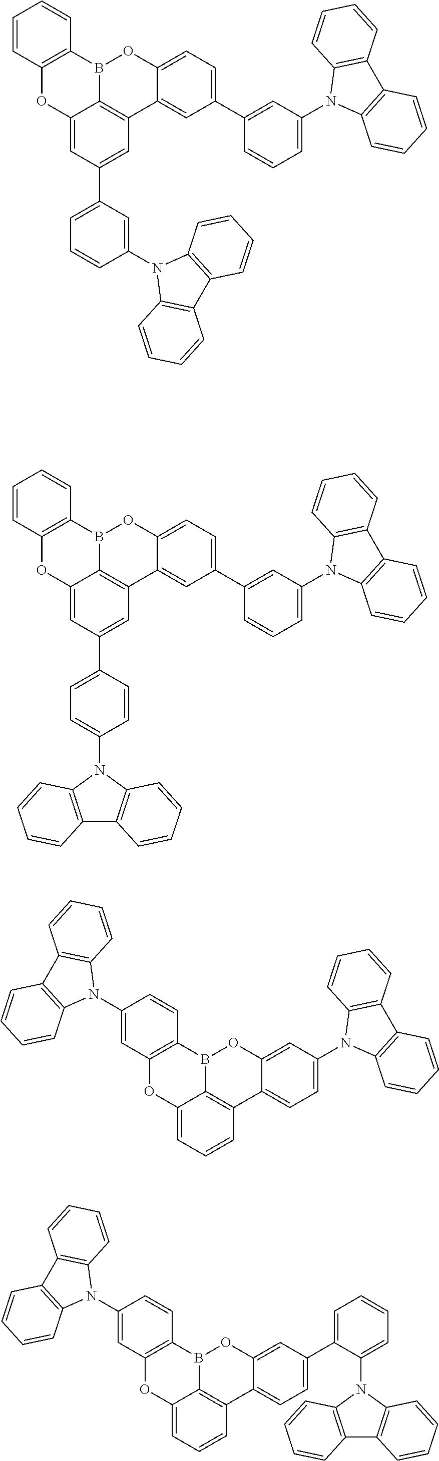 [SMILES: c1cc(-c2ccc3c(c2)-c2cc(-c4cccc(-n5c6ccccc6c6ccccc65)c4)cc4c2B(O3)c2ccccc2O4)cc(-n2c3ccccc3c3ccccc32)c1 ; c1cc(-c2ccc3c(c2)-c2cc(-c4ccc(-n5c6ccccc6c6ccccc65)cc4)cc4c2B(O3)c2ccccc2O4)cc(-n2c3ccccc3c3ccccc32)c1 ; c1cc2c3c(c1)-c1ccc(-n4c5ccccc5c5ccccc54)cc1OB3c1ccc(-n3c4ccccc4c4ccccc43)cc1O2 ; c1ccc(-n2c3ccccc3c3ccccc32)c(-c2ccc3c(c2)OB2c4ccc(-n5c6ccccc6c6ccccc65)cc4Oc4cccc-3c42)c1] 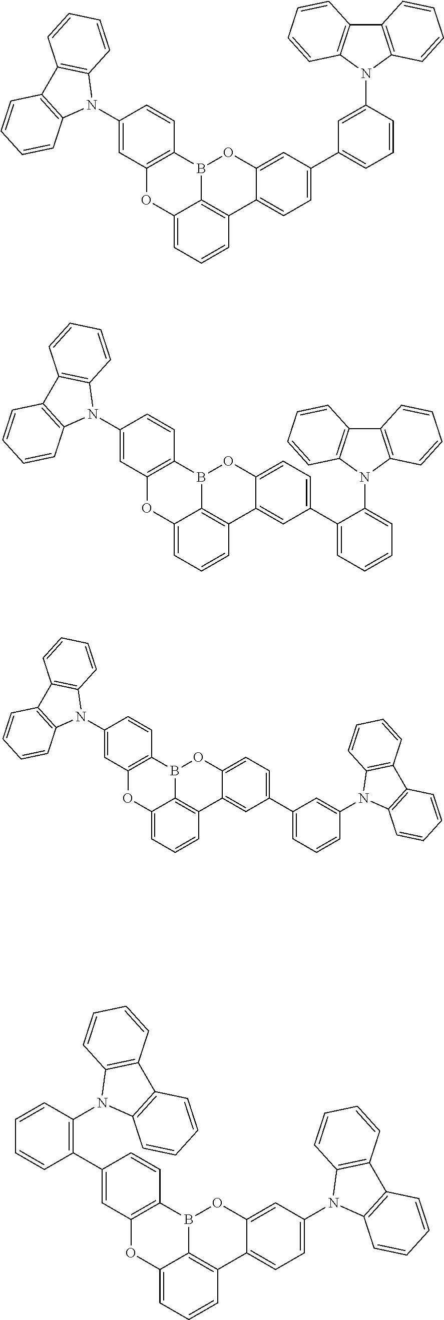 [SMILES: c1cc(-c2ccc3c(c2)OB2c4ccc(-n5c6ccccc6c6ccccc65)cc4Oc4cccc-3c42)cc(-n2c3ccccc3c3ccccc32)c1 ; c1ccc(-n2c3ccccc3c3ccccc32)c(-c2ccc3c(c2)-c2cccc4c2B(O3)c2ccc(-n3c5ccccc5c5ccccc53)cc2O4)c1 ; c1cc(-c2ccc3c(c2)-c2cccc4c2B(O3)c2ccc(-n3c5ccccc5c5ccccc53)cc2O4)cc(-n2c3ccccc3c3ccccc32)c1 ; c1ccc(-n2c3ccccc3c3ccccc32)c(-c2ccc3c(c2)Oc2cccc4c2B3Oc2cc(-n3c5ccccc5c5ccccc53)ccc2-4)c1] 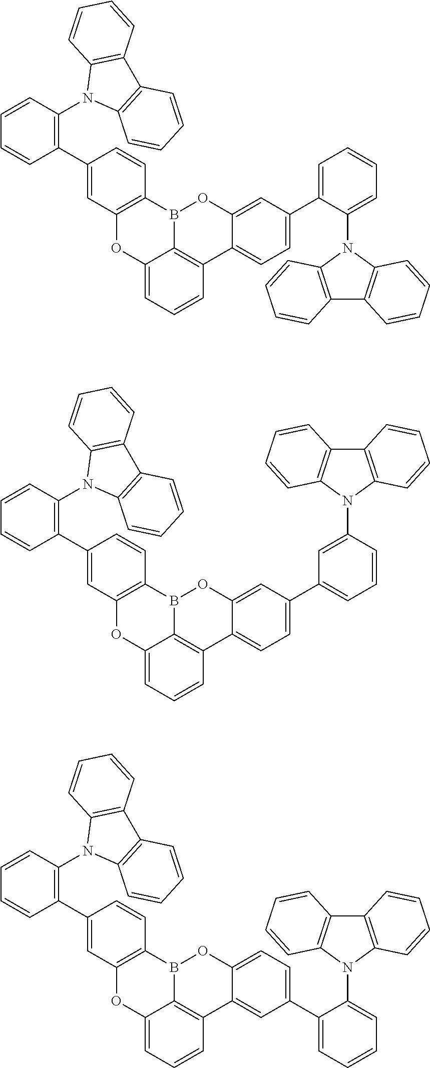 [SMILES: c1ccc(-n2c3ccccc3c3ccccc32)c(-c2ccc3c(c2)Oc2cccc4c2B3Oc2cc(-c3ccccc3-n3c5ccccc5c5ccccc53)ccc2-4)c1 ; c1cc(-c2ccc3c(c2)OB2c4ccc(-c5ccccc5-n5c6ccccc6c6ccccc65)cc4Oc4cccc-3c42)cc(-n2c3ccccc3c3ccccc32)c1 ; c1ccc(-n2c3ccccc3c3ccccc32)c(-c2ccc3c(c2)Oc2cccc4c2B3Oc2ccc(-c3ccccc3-n3c5ccccc5c5ccccc53)cc2-4)c1] 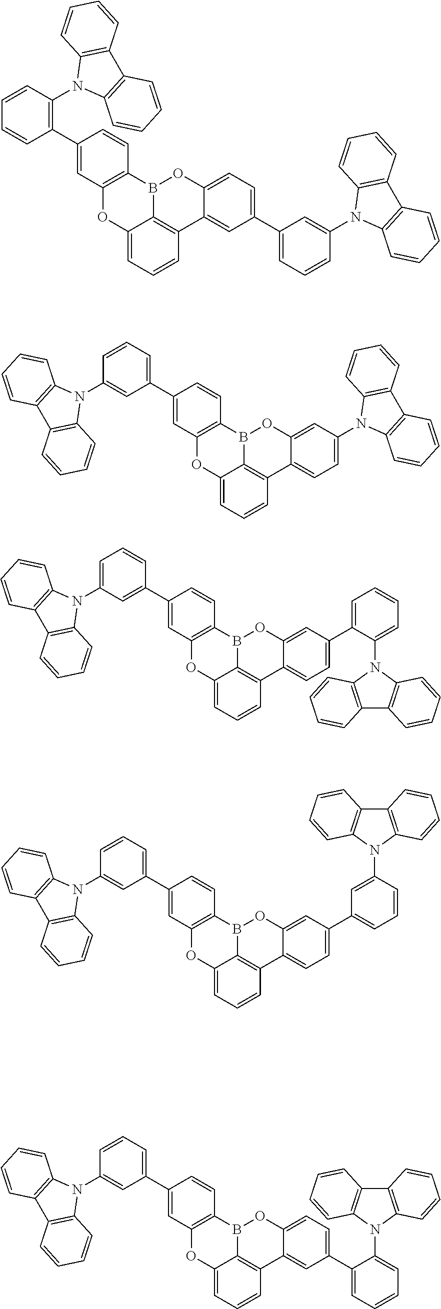 [SMILES: c1cc(-c2ccc3c(c2)-c2cccc4c2B(O3)c2ccc(-c3ccccc3-n3c5ccccc5c5ccccc53)cc2O4)cc(-n2c3ccccc3c3ccccc32)c1 ; c1cc(-c2ccc3c(c2)Oc2cccc4c2B3Oc2cc(-n3c5ccccc5c5ccccc53)ccc2-4)cc(-n2c3ccccc3c3ccccc32)c1 ; c1cc(-c2ccc3c(c2)Oc2cccc4c2B3Oc2cc(-c3ccccc3-n3c5ccccc5c5ccccc53)ccc2-4)cc(-n2c3ccccc3c3ccccc32)c1 ; c1cc(-c2ccc3c(c2)Oc2cccc4c2B3Oc2cc(-c3cccc(-n5c6ccccc6c6ccccc65)c3)ccc2-4)cc(-n2c3ccccc3c3ccccc32)c1 ; c1cc(-c2ccc3c(c2)Oc2cccc4c2B3Oc2ccc(-c3ccccc3-n3c5ccccc5c5ccccc53)cc2-4)cc(-n2c3ccccc3c3ccccc32)c1] 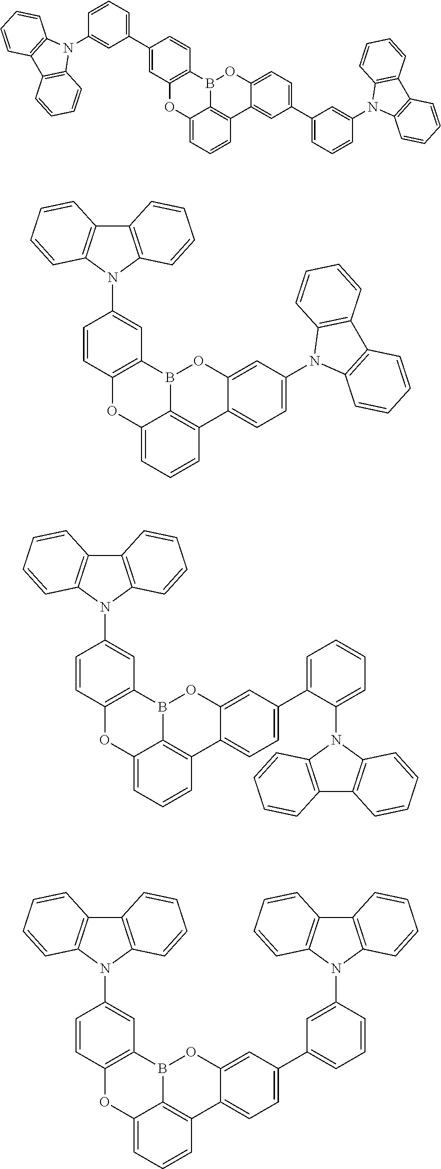 [SMILES: c1cc(-c2ccc3c(c2)Oc2cccc4c2B3Oc2ccc(-c3cccc(-n5c6ccccc6c6ccccc65)c3)cc2-4)cc(-n2c3ccccc3c3ccccc32)c1 ; c1cc2c3c(c1)-c1ccc(-n4c5ccccc5c5ccccc54)cc1OB3c1cc(-n3c4ccccc4c4ccccc43)ccc1O2 ; c1ccc(-n2c3ccccc3c3ccccc32)c(-c2ccc3c(c2)OB2c4cc(-n5c6ccccc6c6ccccc65)ccc4Oc4cccc-3c42)c1 ; c1cc(-c2ccc3c(c2)OB2c4cc(-n5c6ccccc6c6ccccc65)ccc4Oc4cccc-3c42)cc(-n2c3ccccc3c3ccccc32)c1] 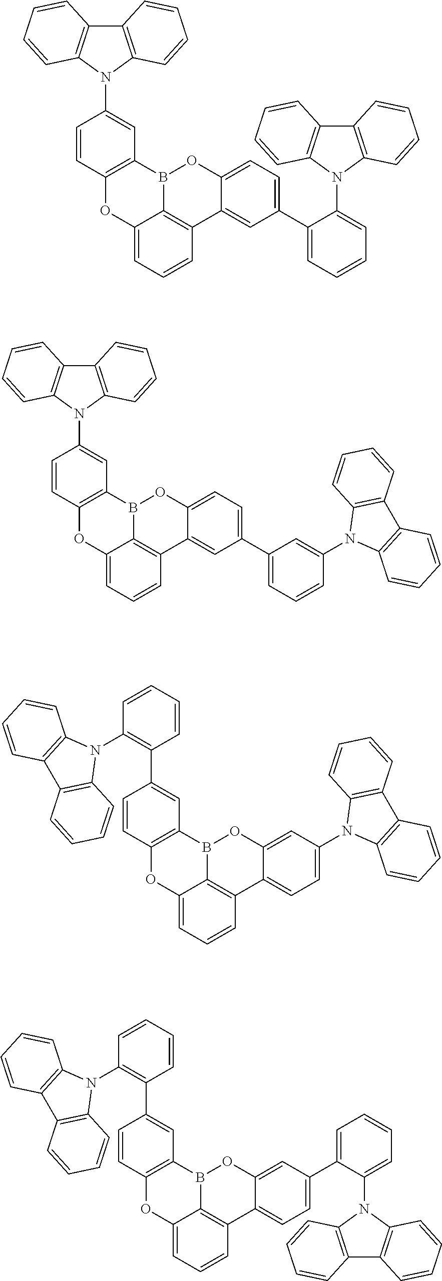 [SMILES: c1ccc(-n2c3ccccc3c3ccccc32)c(-c2ccc3c(c2)-c2cccc4c2B(O3)c2cc(-n3c5ccccc5c5ccccc53)ccc2O4)c1 ; c1cc(-c2ccc3c(c2)-c2cccc4c2B(O3)c2cc(-n3c5ccccc5c5ccccc53)ccc2O4)cc(-n2c3ccccc3c3ccccc32)c1 ; c1ccc(-n2c3ccccc3c3ccccc32)c(-c2ccc3c(c2)B2Oc4cc(-n5c6ccccc6c6ccccc65)ccc4-c4cccc(c42)O3)c1 ; c1ccc(-n2c3ccccc3c3ccccc32)c(-c2ccc3c(c2)OB2c4cc(-c5ccccc5-n5c6ccccc6c6ccccc65)ccc4Oc4cccc-3c42)c1] 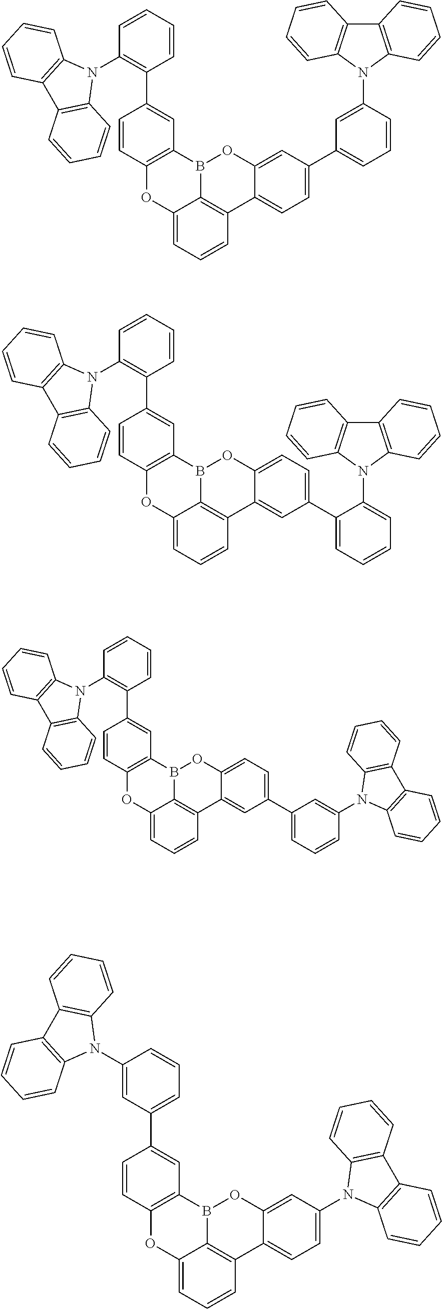 [SMILES: c1cc(-c2ccc3c(c2)OB2c4cc(-c5ccccc5-n5c6ccccc6c6ccccc65)ccc4Oc4cccc-3c42)cc(-n2c3ccccc3c3ccccc32)c1 ; c1ccc(-n2c3ccccc3c3ccccc32)c(-c2ccc3c(c2)B2Oc4ccc(-c5ccccc5-n5c6ccccc6c6ccccc65)cc4-c4cccc(c42)O3)c1 ; c1cc(-c2ccc3c(c2)-c2cccc4c2B(O3)c2cc(-c3ccccc3-n3c5ccccc5c5ccccc53)ccc2O4)cc(-n2c3ccccc3c3ccccc32)c1 ; c1cc(-c2ccc3c(c2)B2Oc4cc(-n5c6ccccc6c6ccccc65)ccc4-c4cccc(c42)O3)cc(-n2c3ccccc3c3ccccc32)c1] 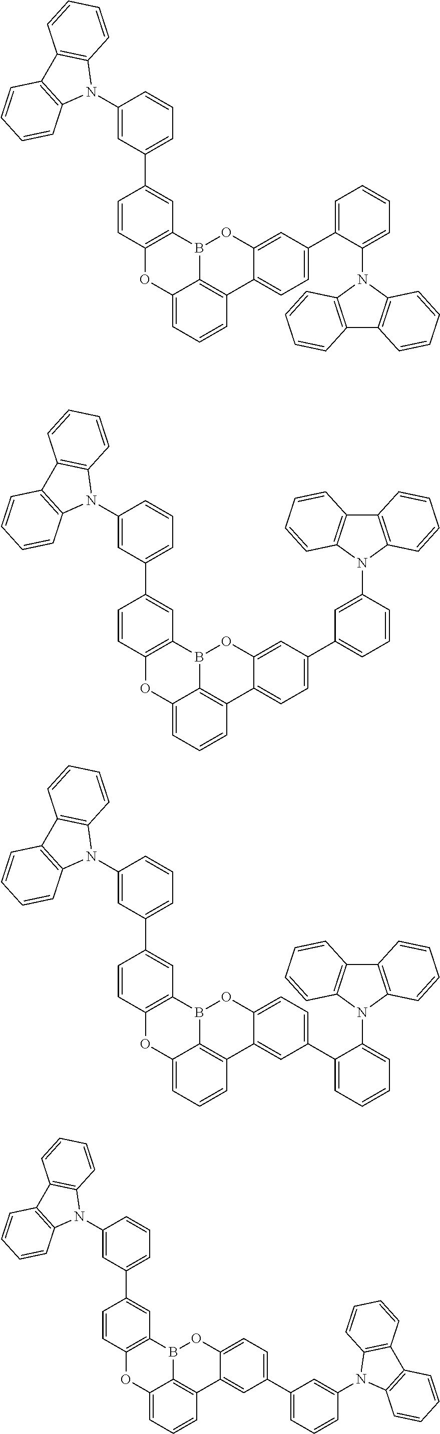 [SMILES: c1cc(-c2ccc3c(c2)B2Oc4cc(-c5ccccc5-n5c6ccccc6c6ccccc65)ccc4-c4cccc(c42)O3)cc(-n2c3ccccc3c3ccccc32)c1 ; c1cc(-c2ccc3c(c2)OB2c4cc(-c5cccc(-n6c7ccccc7c7ccccc76)c5)ccc4Oc4cccc-3c42)cc(-n2c3ccccc3c3ccccc32)c1 ; c1cc(-c2ccc3c(c2)B2Oc4ccc(-c5ccccc5-n5c6ccccc6c6ccccc65)cc4-c4cccc(c42)O3)cc(-n2c3ccccc3c3ccccc32)c1 ; c1cc(-c2ccc3c(c2)B2Oc4ccc(-c5cccc(-n6c7ccccc7c7ccccc76)c5)cc4-c4cccc(c42)O3)cc(-n2c3ccccc3c3ccccc32)c1] 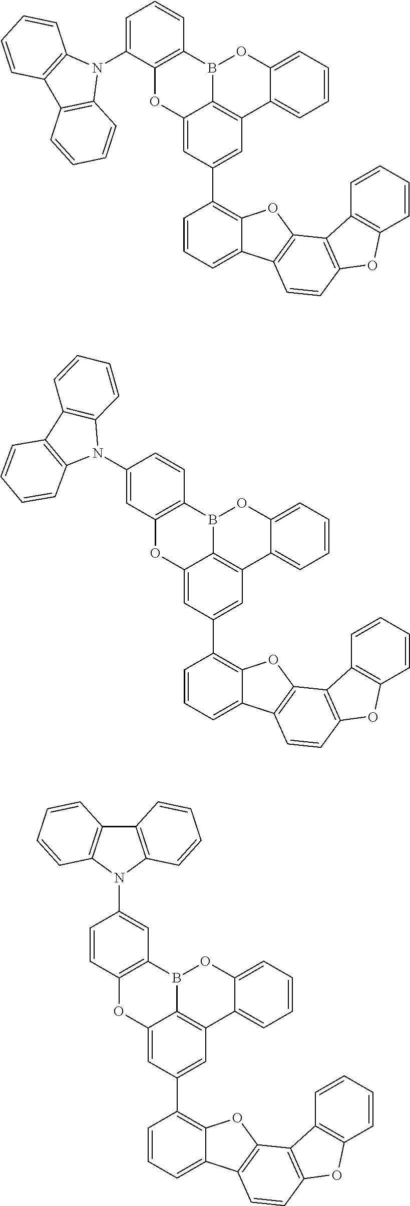 [SMILES: c1ccc2c(c1)OB1c3cccc(-n4c5ccccc5c5ccccc54)c3Oc3cc(-c4cccc5c4oc4c5ccc5oc6ccccc6c54)cc-2c31 ; c1ccc2c(c1)OB1c3ccc(-n4c5ccccc5c5ccccc54)cc3Oc3cc(-c4cccc5c4oc4c5ccc5oc6ccccc6c54)cc-2c31 ; c1ccc2c(c1)OB1c3cc(-n4c5ccccc5c5ccccc54)ccc3Oc3cc(-c4cccc5c4oc4c5ccc5oc6ccccc6c54)cc-2c31] 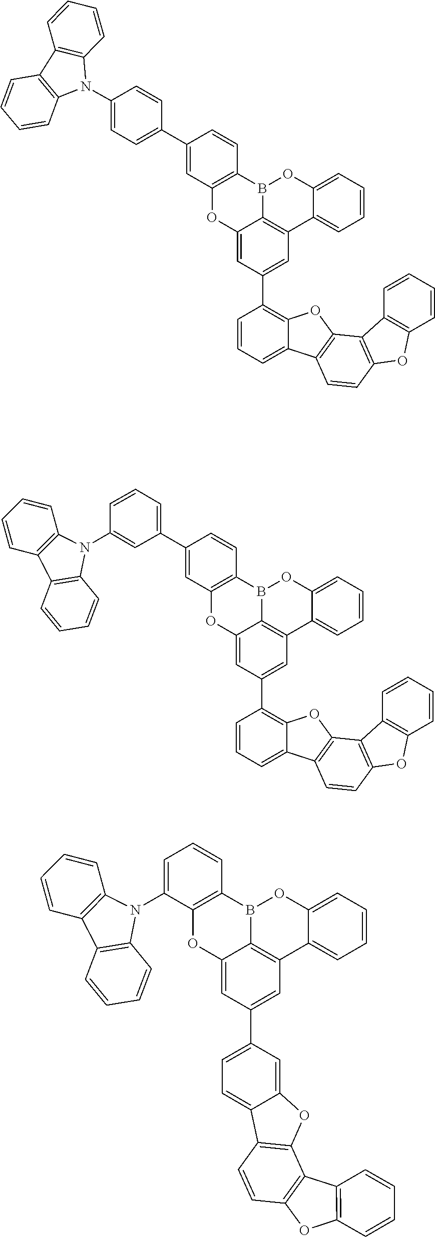 [SMILES: c1ccc2c(c1)OB1c3ccc(-c4ccc(-n5c6ccccc6c6ccccc65)cc4)cc3Oc3cc(-c4cccc5c4oc4c5ccc5oc6ccccc6c54)cc-2c31 ; c1cc(-c2ccc3c(c2)Oc2cc(-c4cccc5c4oc4c5ccc5oc6ccccc6c54)cc4c2B3Oc2ccccc2-4)cc(-n2c3ccccc3c3ccccc32)c1 ; c1ccc2c(c1)OB1c3cccc(-n4c5ccccc5c5ccccc54)c3Oc3cc(-c4ccc5c(c4)oc4c5ccc5oc6ccccc6c54)cc-2c31] 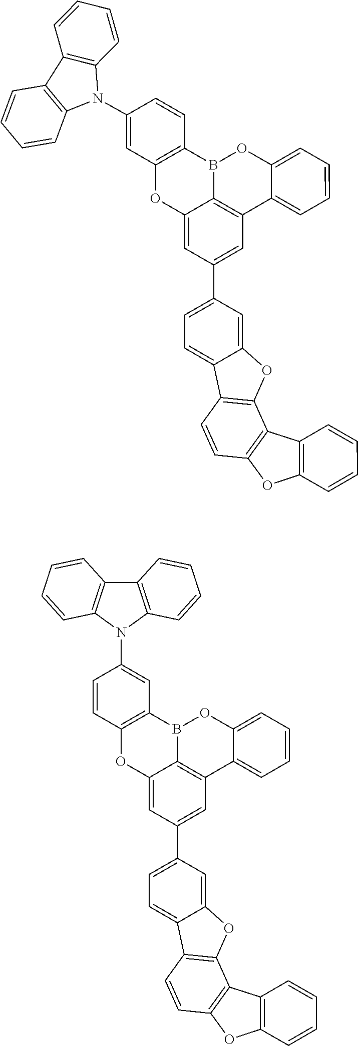 [SMILES: c1ccc2c(c1)OB1c3ccc(-n4c5ccccc5c5ccccc54)cc3Oc3cc(-c4ccc5c(c4)oc4c5ccc5oc6ccccc6c54)cc-2c31 ; c1ccc2c(c1)OB1c3cc(-n4c5ccccc5c5ccccc54)ccc3Oc3cc(-c4ccc5c(c4)oc4c5ccc5oc6ccccc6c54)cc-2c31] 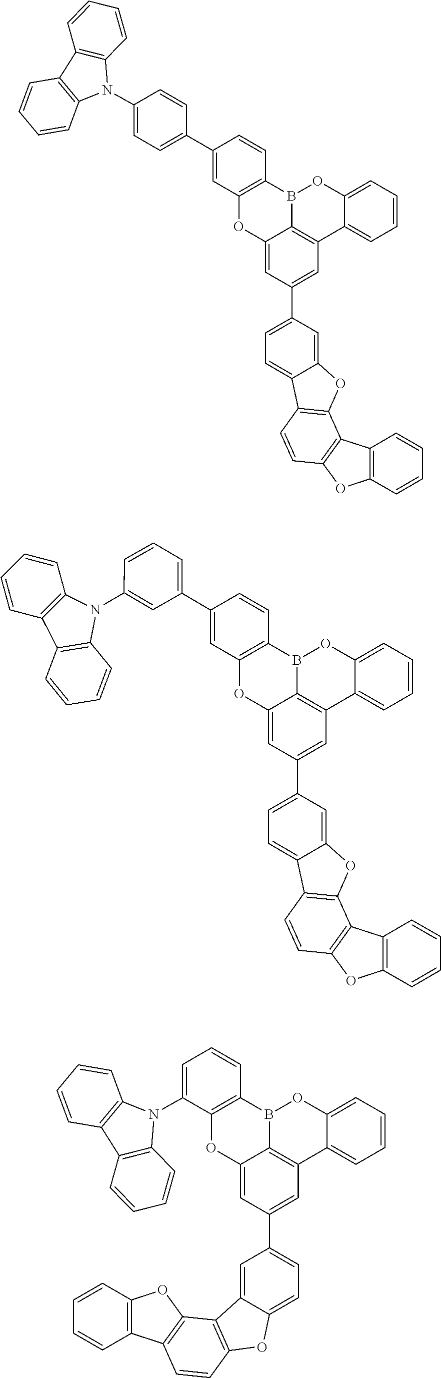 [SMILES: c1ccc2c(c1)OB1c3ccc(-c4ccc(-n5c6ccccc6c6ccccc65)cc4)cc3Oc3cc(-c4ccc5c(c4)oc4c5ccc5oc6ccccc6c54)cc-2c31 ; c1cc(-c2ccc3c(c2)Oc2cc(-c4ccc5c(c4)oc4c5ccc5oc6ccccc6c54)cc4c2B3Oc2ccccc2-4)cc(-n2c3ccccc3c3ccccc32)c1 ; c1ccc2c(c1)OB1c3cccc(-n4c5ccccc5c5ccccc54)c3Oc3cc(-c4ccc5oc6ccc7c8ccccc8oc7c6c5c4)cc-2c31] 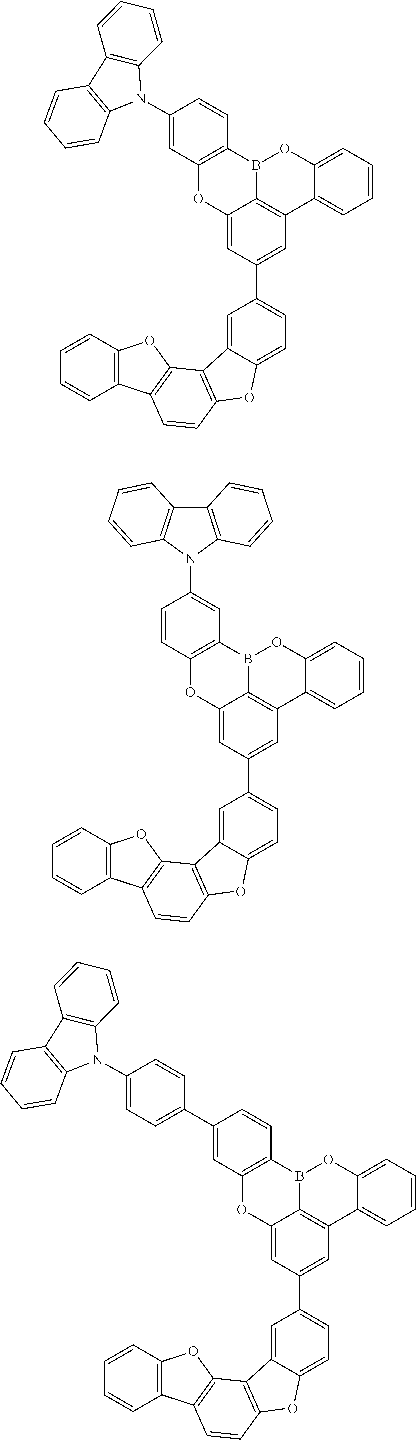 [SMILES: c1ccc2c(c1)OB1c3ccc(-n4c5ccccc5c5ccccc54)cc3Oc3cc(-c4ccc5oc6ccc7c8ccccc8oc7c6c5c4)cc-2c31 ; c1ccc2c(c1)OB1c3cc(-n4c5ccccc5c5ccccc54)ccc3Oc3cc(-c4ccc5oc6ccc7c8ccccc8oc7c6c5c4)cc-2c31 ; c1ccc2c(c1)OB1c3ccc(-c4ccc(-n5c6ccccc6c6ccccc65)cc4)cc3Oc3cc(-c4ccc5oc6ccc7c8ccccc8oc7c6c5c4)cc-2c31] 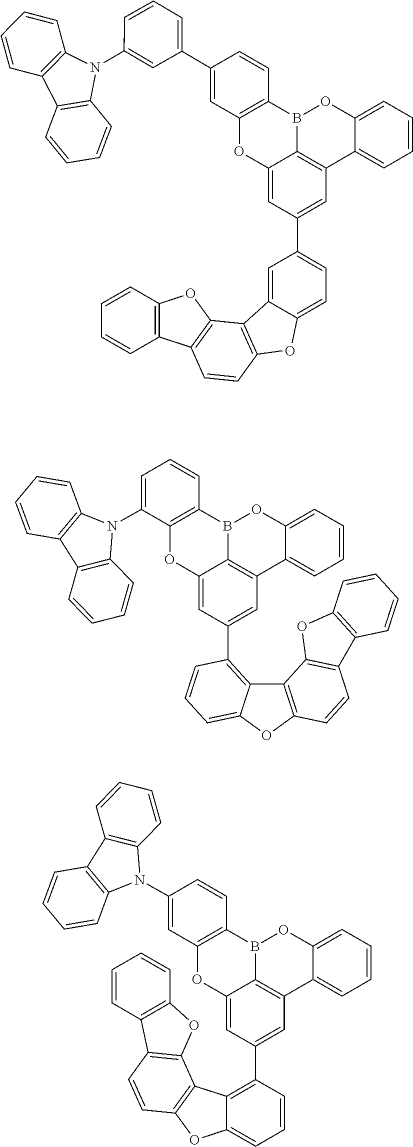 [SMILES: c1cc(-c2ccc3c(c2)Oc2cc(-c4ccc5oc6ccc7c8ccccc8oc7c6c5c4)cc4c2B3Oc2ccccc2-4)cc(-n2c3ccccc3c3ccccc32)c1 ; c1ccc2c(c1)OB1c3cccc(-n4c5ccccc5c5ccccc54)c3Oc3cc(-c4cccc5oc6ccc7c8ccccc8oc7c6c45)cc-2c31 ; c1ccc2c(c1)OB1c3ccc(-n4c5ccccc5c5ccccc54)cc3Oc3cc(-c4cccc5oc6ccc7c8ccccc8oc7c6c45)cc-2c31] 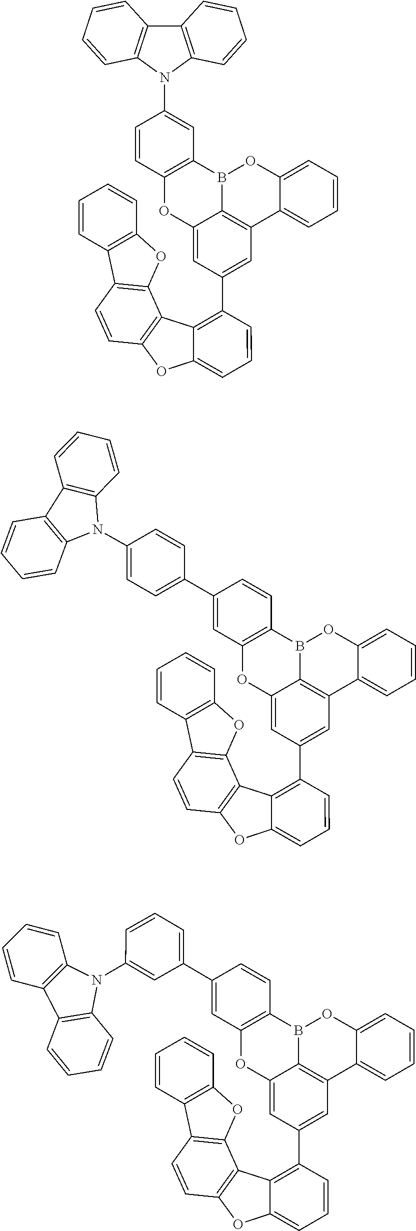 [SMILES: c1ccc2c(c1)OB1c3cc(-n4c5ccccc5c5ccccc54)ccc3Oc3cc(-c4cccc5oc6ccc7c8ccccc8oc7c6c45)cc-2c31 ; c1ccc2c(c1)OB1c3ccc(-c4ccc(-n5c6ccccc6c6ccccc65)cc4)cc3Oc3cc(-c4cccc5oc6ccc7c8ccccc8oc7c6c45)cc-2c31 ; c1cc(-c2ccc3c(c2)Oc2cc(-c4cccc5oc6ccc7c8ccccc8oc7c6c45)cc4c2B3Oc2ccccc2-4)cc(-n2c3ccccc3c3ccccc32)c1] 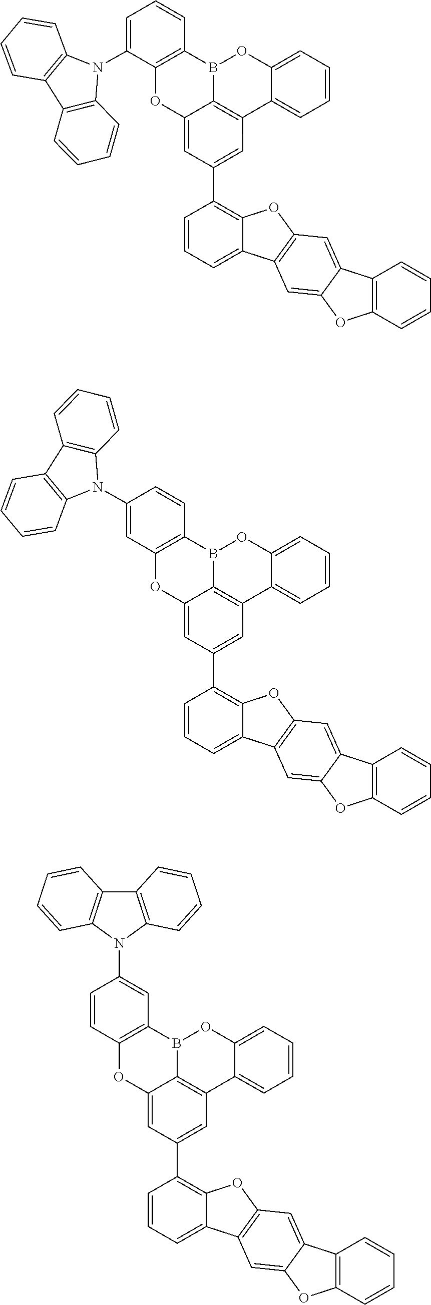 [SMILES: c1ccc2c(c1)OB1c3cccc(-n4c5ccccc5c5ccccc54)c3Oc3cc(-c4cccc5c4oc4cc6c(cc45)oc4ccccc46)cc-2c31 ; c1ccc2c(c1)OB1c3ccc(-n4c5ccccc5c5ccccc54)cc3Oc3cc(-c4cccc5c4oc4cc6c(cc45)oc4ccccc46)cc-2c31 ; c1ccc2c(c1)OB1c3cc(-n4c5ccccc5c5ccccc54)ccc3Oc3cc(-c4cccc5c4oc4cc6c(cc45)oc4ccccc46)cc-2c31] 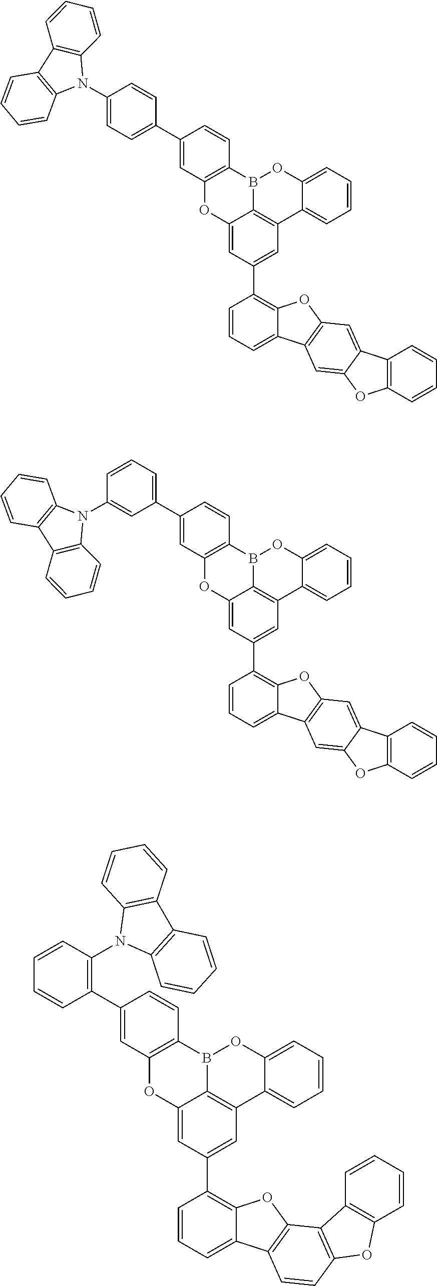 [SMILES: c1ccc2c(c1)OB1c3ccc(-c4ccc(-n5c6ccccc6c6ccccc65)cc4)cc3Oc3cc(-c4cccc5c4oc4cc6c(cc45)oc4ccccc46)cc-2c31 ; c1cc(-c2ccc3c(c2)Oc2cc(-c4cccc5c4oc4cc6c(cc45)oc4ccccc46)cc4c2B3Oc2ccccc2-4)cc(-n2c3ccccc3c3ccccc32)c1 ; c1ccc2c(c1)OB1c3ccc(-c4ccccc4-n4c5ccccc5c5ccccc54)cc3Oc3cc(-c4cccc5c4oc4c5ccc5oc6ccccc6c54)cc-2c31] 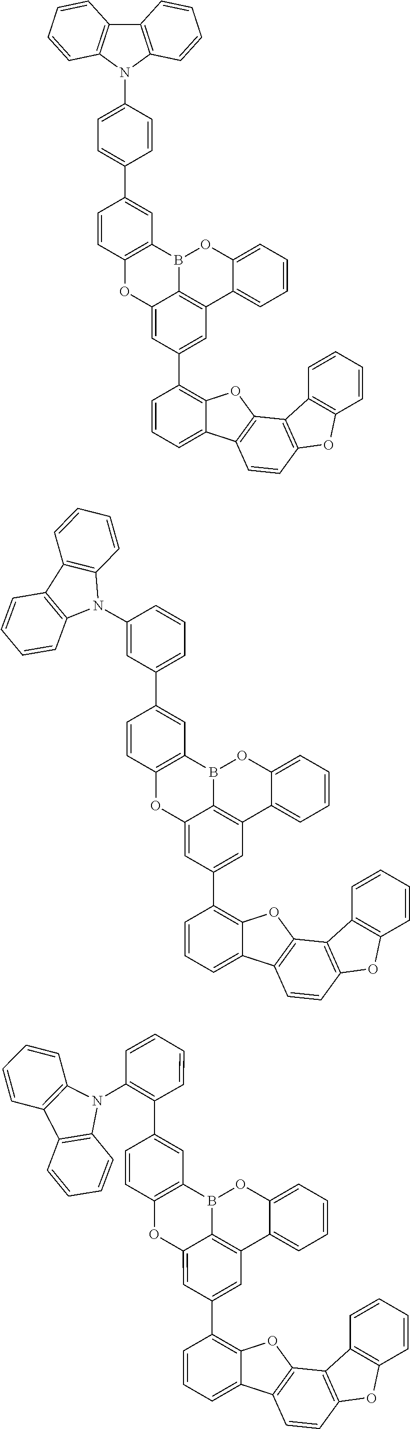 [SMILES: c1ccc2c(c1)OB1c3cc(-c4ccc(-n5c6ccccc6c6ccccc65)cc4)ccc3Oc3cc(-c4cccc5c4oc4c5ccc5oc6ccccc6c54)cc-2c31 ; c1cc(-c2ccc3c(c2)B2Oc4ccccc4-c4cc(-c5cccc6c5oc5c6ccc6oc7ccccc7c65)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-c4cccc5c4oc4c5ccc5oc6ccccc6c54)cc-2c31] 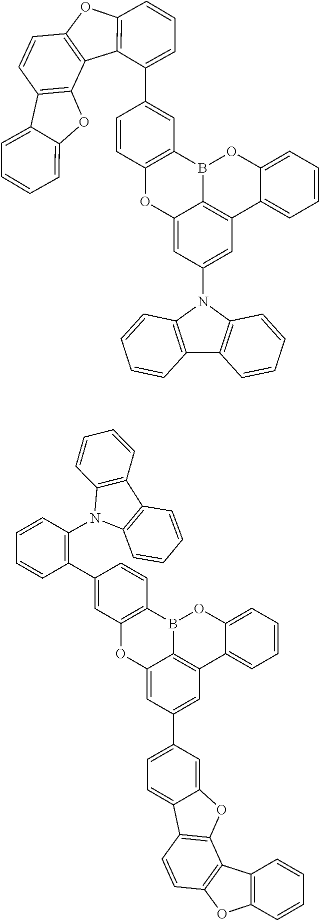 [SMILES: c1ccc2c(c1)OB1c3cc(-c4cccc5oc6ccc7c8ccccc8oc7c6c45)ccc3Oc3cc(-n4c5ccccc5c5ccccc54)cc-2c31 ; c1ccc2c(c1)OB1c3ccc(-c4ccccc4-n4c5ccccc5c5ccccc54)cc3Oc3cc(-c4ccc5c(c4)oc4c5ccc5oc6ccccc6c54)cc-2c31] 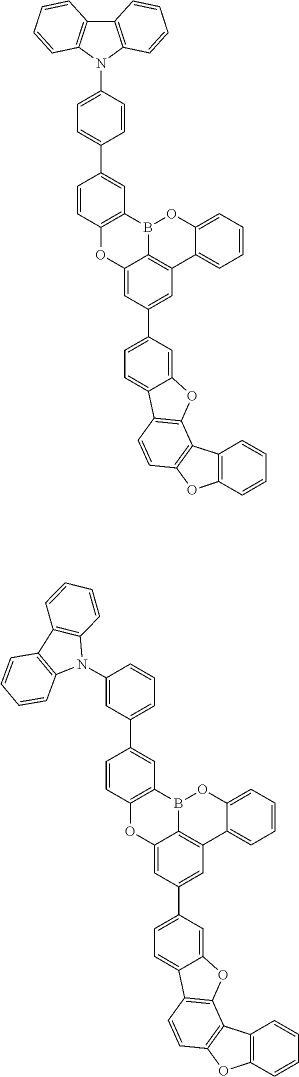 [SMILES: c1ccc2c(c1)OB1c3cc(-c4ccc(-n5c6ccccc6c6ccccc65)cc4)ccc3Oc3cc(-c4ccc5c(c4)oc4c5ccc5oc6ccccc6c54)cc-2c31 ; c1cc(-c2ccc3c(c2)B2Oc4ccccc4-c4cc(-c5ccc6c(c5)oc5c6ccc6oc7ccccc7c65)cc(c42)O3)cc(-n2c3ccccc3c3ccccc32)c1] 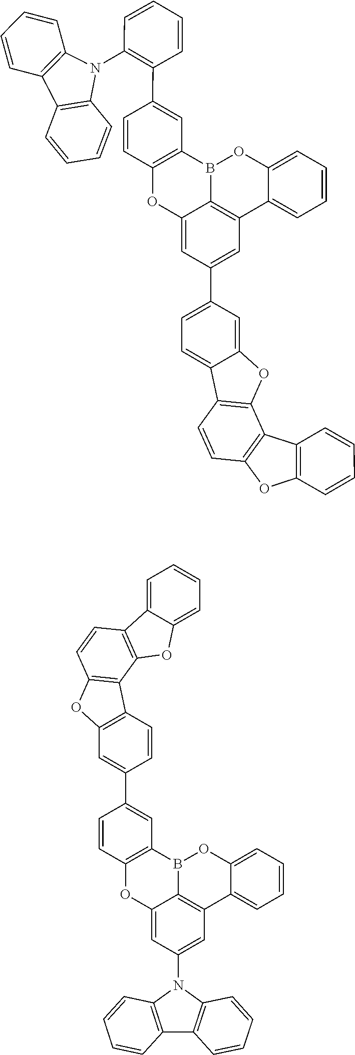 [SMILES: c1ccc2c(c1)OB1c3cc(-c4ccccc4-n4c5ccccc5c5ccccc54)ccc3Oc3cc(-c4ccc5c(c4)oc4c5ccc5oc6ccccc6c54)cc-2c31 ; c1ccc2c(c1)OB1c3cc(-c4ccc5c(c4)oc4ccc6c7ccccc7oc6c45)ccc3Oc3cc(-n4c5ccccc5c5ccccc54)cc-2c31] 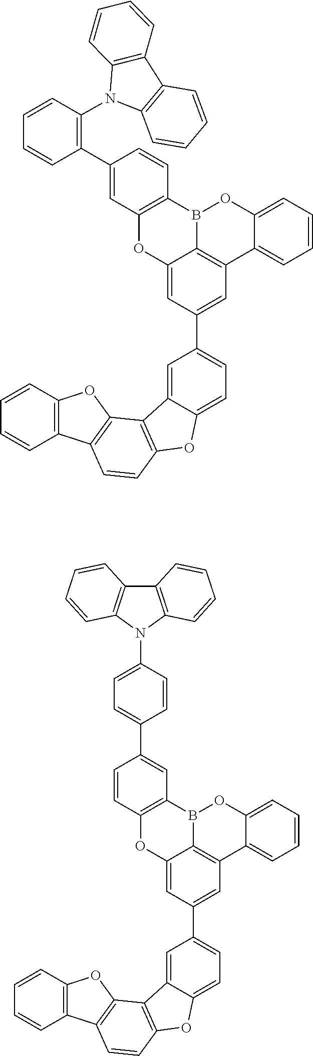 [SMILES: c1ccc2c(c1)OB1c3ccc(-c4ccccc4-n4c5ccccc5c5ccccc54)cc3Oc3cc(-c4ccc5oc6ccc7c8ccccc8oc7c6c5c4)cc-2c31 ; c1ccc2c(c1)OB1c3cc(-c4ccc(-n5c6ccccc6c6ccccc65)cc4)ccc3Oc3cc(-c4ccc5oc6ccc7c8ccccc8oc7c6c5c4)cc-2c31] 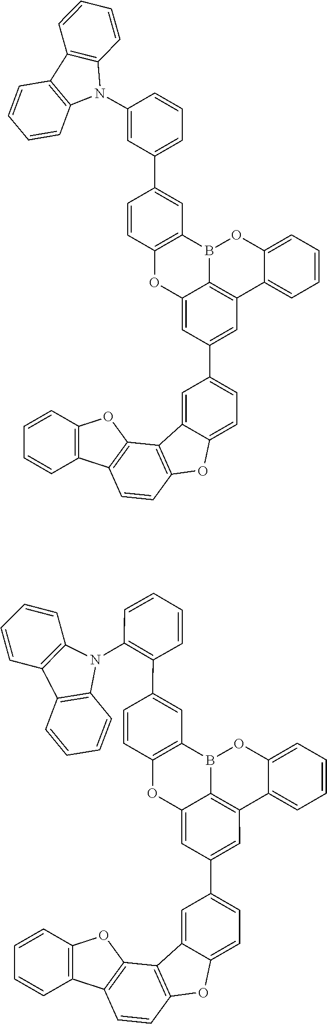 [SMILES: c1cc(-c2ccc3c(c2)B2Oc4ccccc4-c4cc(-c5ccc6oc7ccc8c9ccccc9oc8c7c6c5)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-c4ccc5oc6ccc7c8ccccc8oc7c6c5c4)cc-2c31] 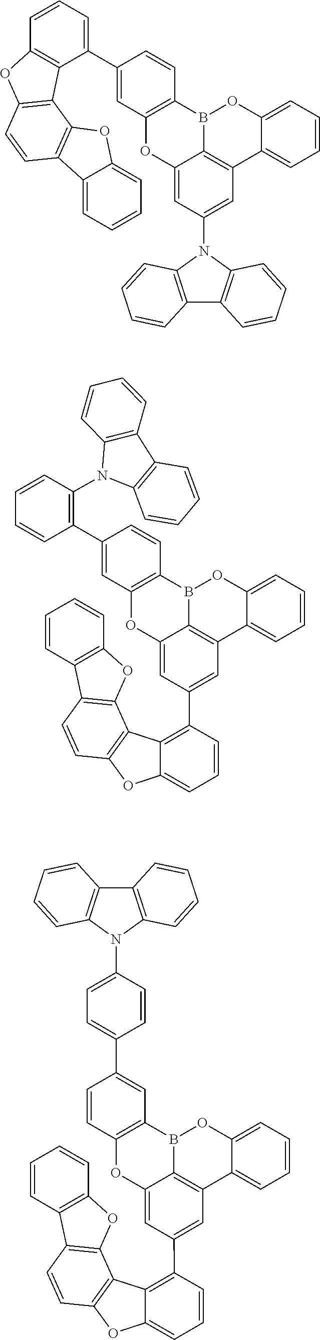 [SMILES: c1ccc2c(c1)OB1c3ccc(-c4cccc5oc6ccc7c8ccccc8oc7c6c45)cc3Oc3cc(-n4c5ccccc5c5ccccc54)cc-2c31 ; c1ccc2c(c1)OB1c3ccc(-c4ccccc4-n4c5ccccc5c5ccccc54)cc3Oc3cc(-c4cccc5oc6ccc7c8ccccc8oc7c6c45)cc-2c31 ; c1ccc2c(c1)OB1c3cc(-c4ccc(-n5c6ccccc6c6ccccc65)cc4)ccc3Oc3cc(-c4cccc5oc6ccc7c8ccccc8oc7c6c45)cc-2c31] 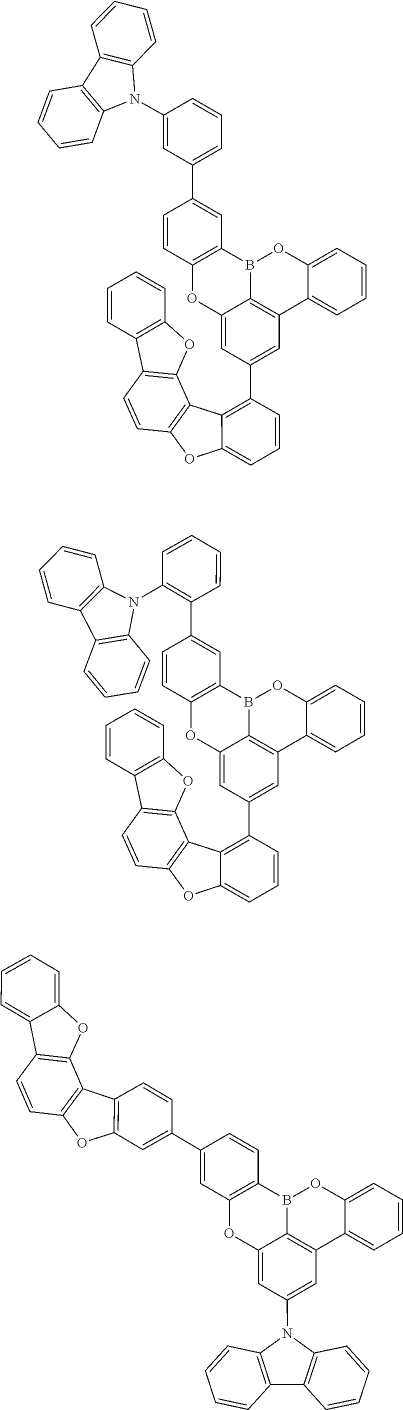 [SMILES: c1cc(-c2ccc3c(c2)B2Oc4ccccc4-c4cc(-c5cccc6oc7ccc8c9ccccc9oc8c7c56)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-c4cccc5oc6ccc7c8ccccc8oc7c6c45)cc-2c31 ; c1ccc2c(c1)OB1c3ccc(-c4ccc5c(c4)oc4ccc6c7ccccc7oc6c45)cc3Oc3cc(-n4c5ccccc5c5ccccc54)cc-2c31] 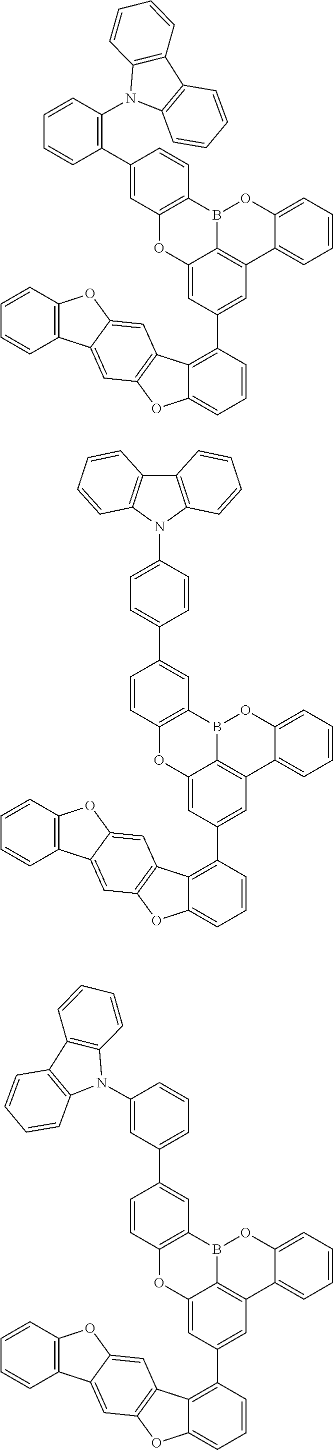 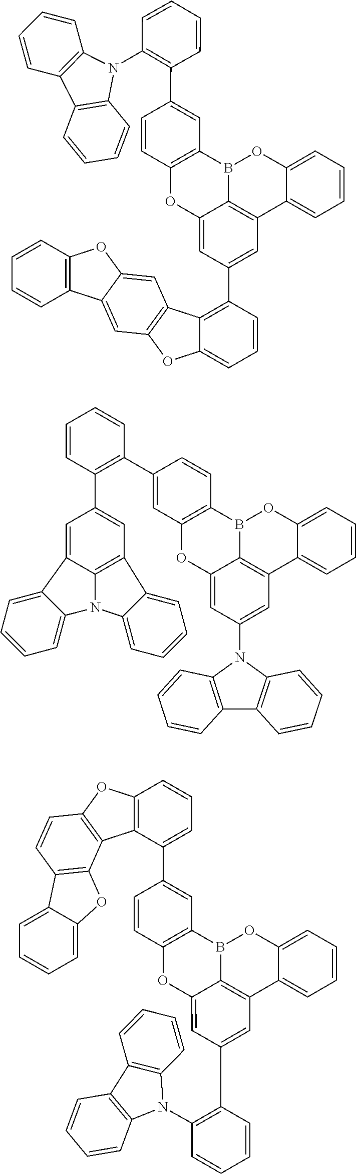 [SMILES: c1ccc2c(c1)OB1c3cc(-c4ccccc4-n4c5ccccc5c5ccccc54)ccc3Oc3cc(-c4cccc5oc6cc7c(cc6c45)oc4ccccc47)cc-2c31 ; c1ccc2c(c1)OB1c3ccc(-c4ccccc4-c4cc5c6ccccc6n6c7ccccc7c(c4)c56)cc3Oc3cc(-n4c5ccccc5c5ccccc54)cc-2c31 ; c1ccc2c(c1)OB1c3cc(-c4cccc5oc6ccc7c8ccccc8oc7c6c45)ccc3Oc3cc(-c4ccccc4-n4c5ccccc5c5ccccc54)cc-2c31] 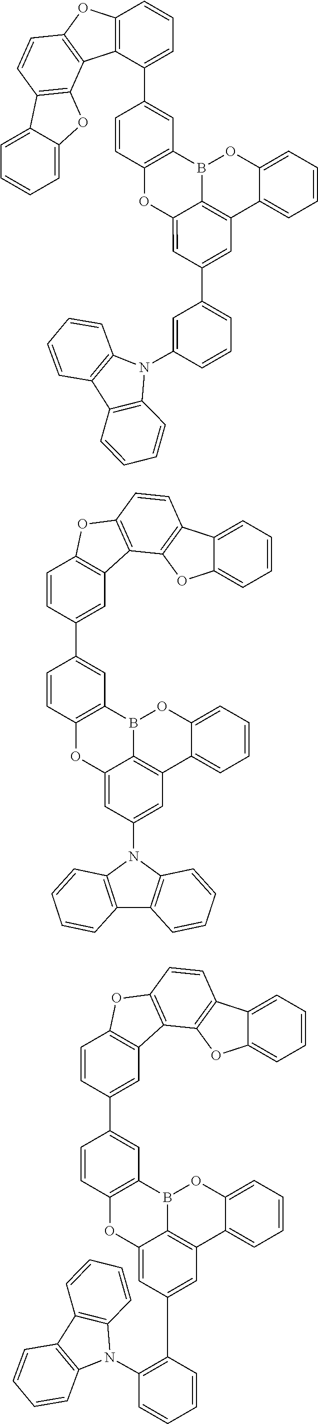 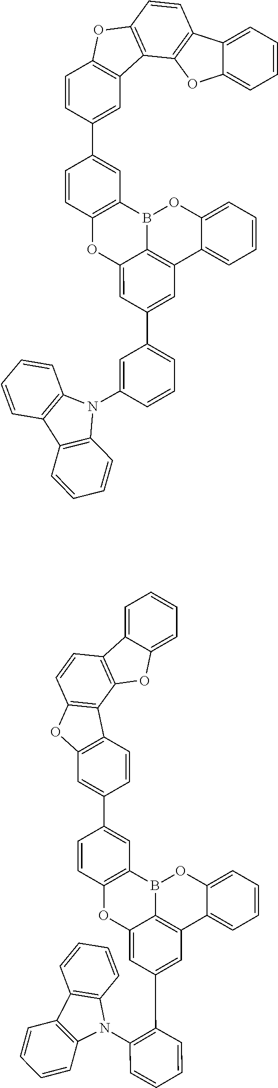 [SMILES: c1cc(-c2cc3c4c(c2)-c2ccccc2OB4c2cc(-c4ccc5oc6ccc7c8ccccc8oc7c6c5c4)ccc2O3)cc(-n2c3ccccc3c3ccccc32)c1 ; c1ccc2c(c1)OB1c3cc(-c4ccc5c(c4)oc4ccc6c7ccccc7oc6c45)ccc3Oc3cc(-c4ccccc4-n4c5ccccc5c5ccccc54)cc-2c31] 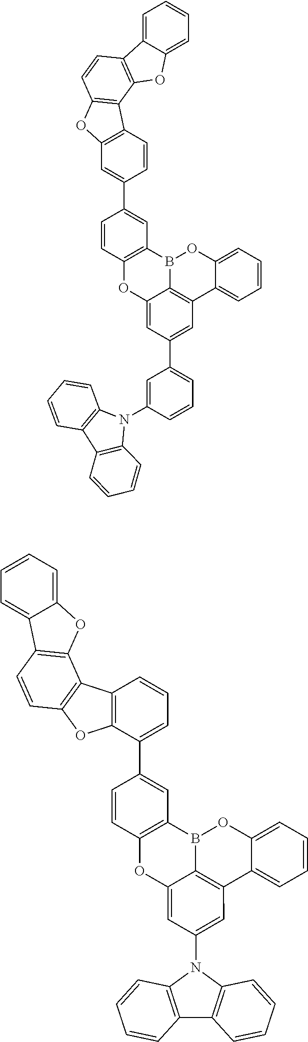 [SMILES: c1cc(-c2cc3c4c(c2)-c2ccccc2OB4c2cc(-c4ccc5c(c4)oc4ccc6c7ccccc7oc6c45)ccc2O3)cc(-n2c3ccccc3c3ccccc32)c1 ; c1ccc2c(c1)OB1c3cc(-c4cccc5c4oc4ccc6c7ccccc7oc6c45)ccc3Oc3cc(-n4c5ccccc5c5ccccc54)cc-2c31] 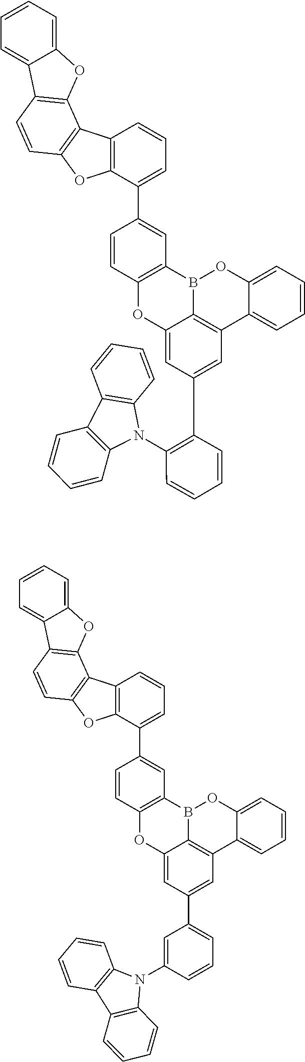 [SMILES: c1ccc2c(c1)OB1c3cc(-c4cccc5c4oc4ccc6c7ccccc7oc6c45)ccc3Oc3cc(-c4ccccc4-n4c5ccccc5c5ccccc54)cc-2c31 ; c1cc(-c2cc3c4c(c2)-c2ccccc2OB4c2cc(-c4cccc5c4oc4ccc6c7ccccc7oc6c45)ccc2O3)cc(-n2c3ccccc3c3ccccc32)c1] 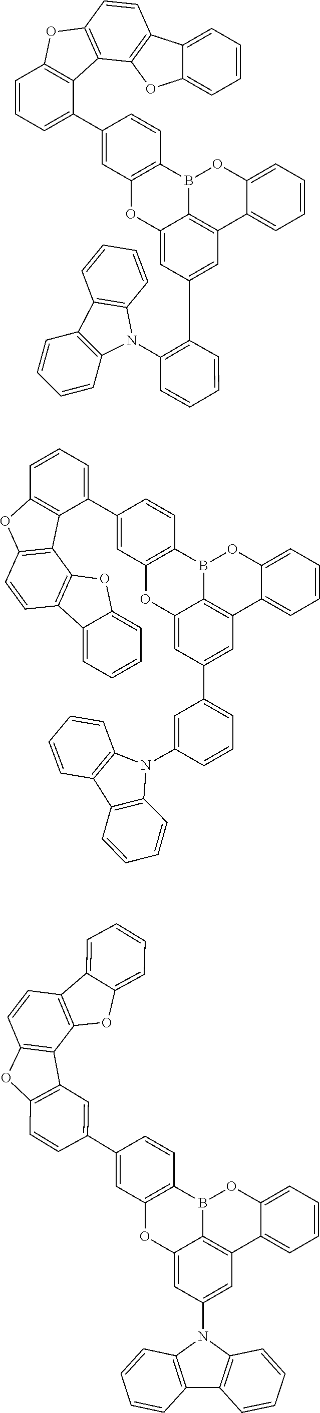 [SMILES: c1ccc2c(c1)OB1c3ccc(-c4cccc5oc6ccc7c8ccccc8oc7c6c45)cc3Oc3cc(-c4ccccc4-n4c5ccccc5c5ccccc54)cc-2c31 ; c1cc(-c2cc3c4c(c2)-c2ccccc2OB4c2ccc(-c4cccc5oc6ccc7c8ccccc8oc7c6c45)cc2O3)cc(-n2c3ccccc3c3ccccc32)c1 ; c1ccc2c(c1)OB1c3ccc(-c4ccc5oc6ccc7c8ccccc8oc7c6c5c4)cc3Oc3cc(-n4c5ccccc5c5ccccc54)cc-2c31] 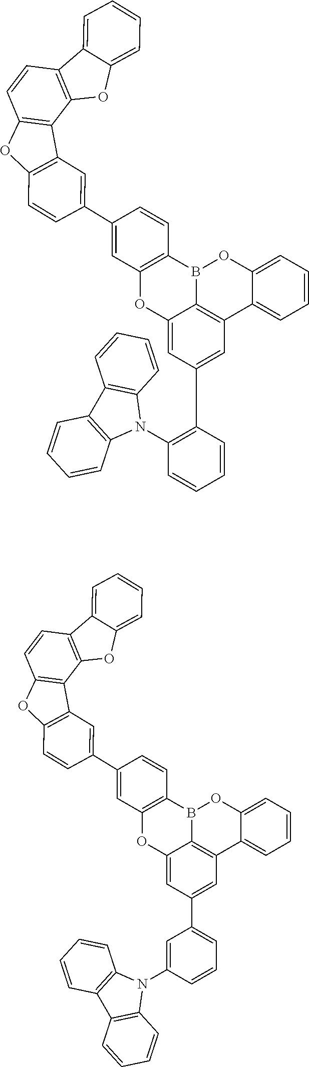 [SMILES: c1ccc2c(c1)OB1c3ccc(-c4ccc5oc6ccc7c8ccccc8oc7c6c5c4)cc3Oc3cc(-c4ccccc4-n4c5ccccc5c5ccccc54)cc-2c31 ; c1cc(-c2cc3c4c(c2)-c2ccccc2OB4c2ccc(-c4ccc5oc6ccc7c8ccccc8oc7c6c5c4)cc2O3)cc(-n2c3ccccc3c3ccccc32)c1] 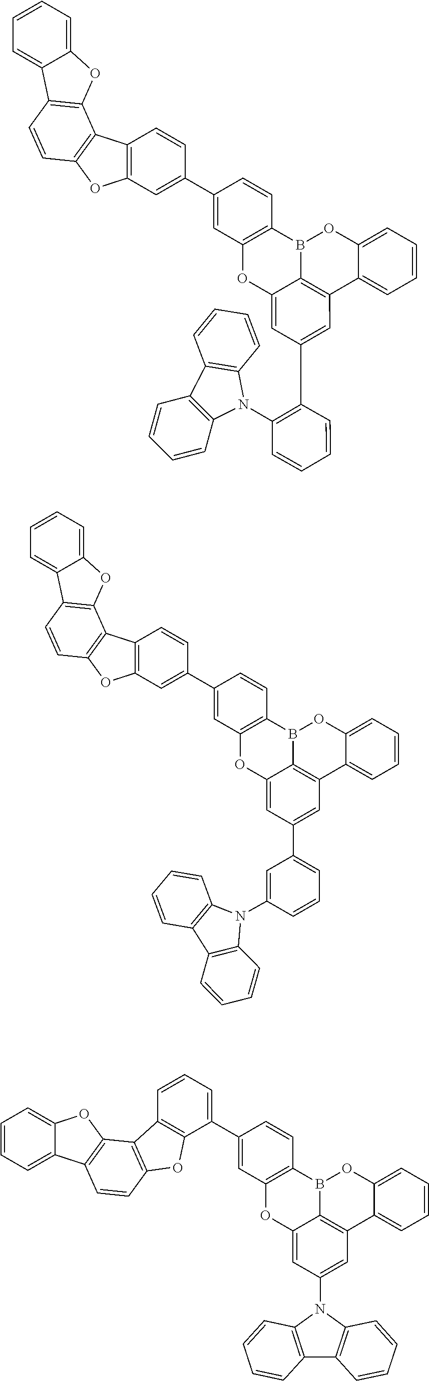 [SMILES: c1ccc2c(c1)OB1c3ccc(-c4ccc5c(c4)oc4ccc6c7ccccc7oc6c45)cc3Oc3cc(-c4ccccc4-n4c5ccccc5c5ccccc54)cc-2c31 ; c1cc(-c2cc3c4c(c2)-c2ccccc2OB4c2ccc(-c4ccc5c(c4)oc4ccc6c7ccccc7oc6c45)cc2O3)cc(-n2c3ccccc3c3ccccc32)c1 ; c1ccc2c(c1)OB1c3ccc(-c4cccc5c4oc4ccc6c7ccccc7oc6c45)cc3Oc3cc(-n4c5ccccc5c5ccccc54)cc-2c31] 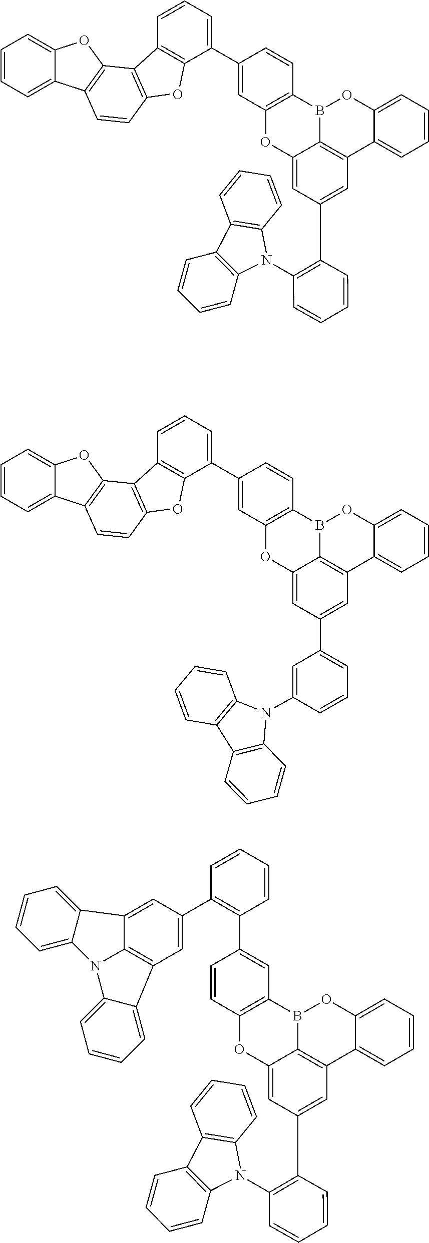 [SMILES: c1ccc2c(c1)OB1c3ccc(-c4cccc5c4oc4ccc6c7ccccc7oc6c45)cc3Oc3cc(-c4ccccc4-n4c5ccccc5c5ccccc54)cc-2c31 ; c1cc(-c2cc3c4c(c2)-c2ccccc2OB4c2ccc(-c4cccc5c4oc4ccc6c7ccccc7oc6c45)cc2O3)cc(-n2c3ccccc3c3ccccc32)c1 ; c1ccc2c(c1)OB1c3cc(-c4ccccc4-c4cc5c6ccccc6n6c7ccccc7c(c4)c56)ccc3Oc3cc(-c4ccccc4-n4c5ccccc5c5ccccc54)cc-2c31] 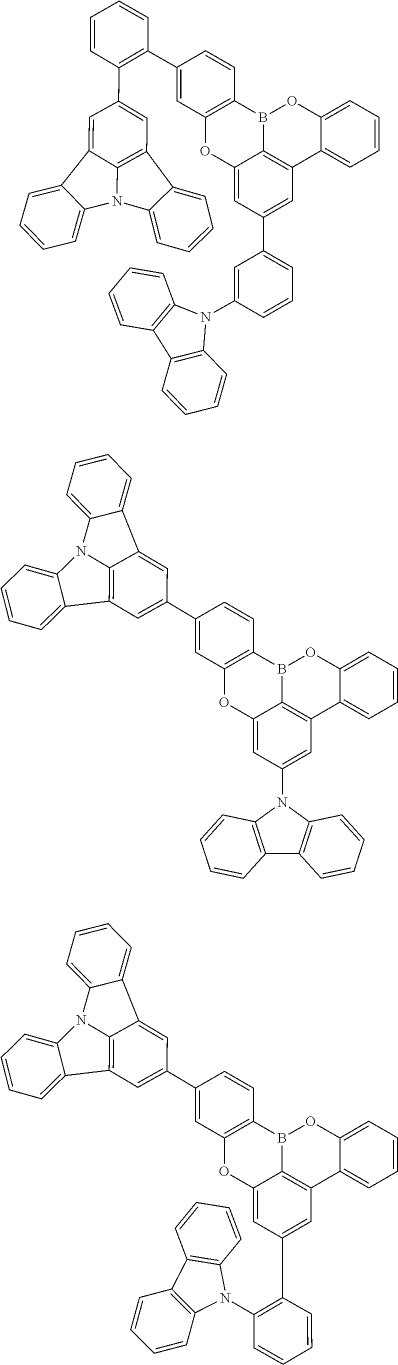 [SMILES: c1cc(-c2cc3c4c(c2)-c2ccccc2OB4c2ccc(-c4ccccc4-c4cc5c6ccccc6n6c7ccccc7c(c4)c56)cc2O3)cc(-n2c3ccccc3c3ccccc32)c1 ; c1ccc2c(c1)OB1c3ccc(-c4cc5c6ccccc6n6c7ccccc7c(c4)c56)cc3Oc3cc(-n4c5ccccc5c5ccccc54)cc-2c31 ; c1ccc2c(c1)OB1c3ccc(-c4cc5c6ccccc6n6c7ccccc7c(c4)c56)cc3Oc3cc(-c4ccccc4-n4c5ccccc5c5ccccc54)cc-2c31] 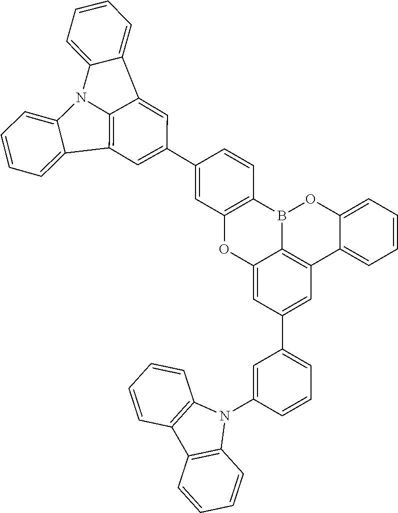 [SMILES: c1cc(-c2cc3c4c(c2)-c2ccccc2OB4c2ccc(-c4cc5c6ccccc6n6c7ccccc7c(c4)c56)cc2O3)cc(-n2c3ccccc3c3ccccc32)c1] 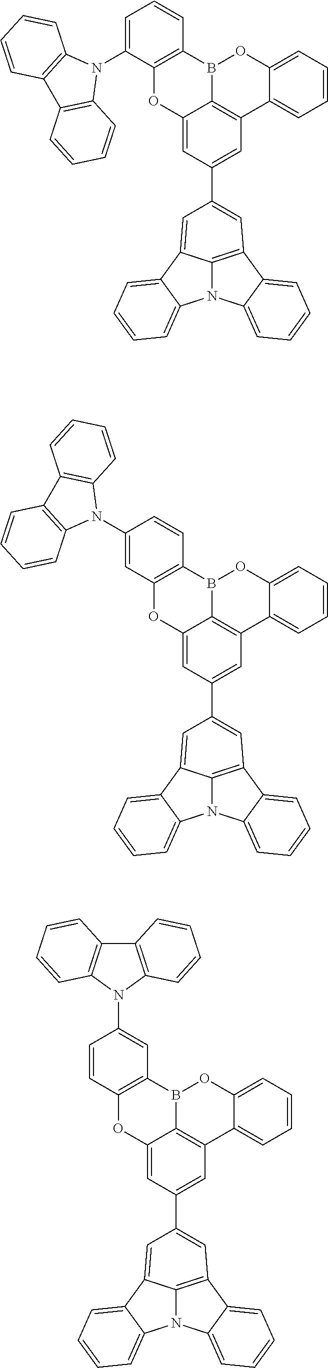 [SMILES: c1ccc2c(c1)OB1c3cccc(-n4c5ccccc5c5ccccc54)c3Oc3cc(-c4cc5c6ccccc6n6c7ccccc7c(c4)c56)cc-2c31 ; c1ccc2c(c1)OB1c3ccc(-n4c5ccccc5c5ccccc54)cc3Oc3cc(-c4cc5c6ccccc6n6c7ccccc7c(c4)c56)cc-2c31 ; c1ccc2c(c1)OB1c3cc(-n4c5ccccc5c5ccccc54)ccc3Oc3cc(-c4cc5c6ccccc6n6c7ccccc7c(c4)c56)cc-2c31] 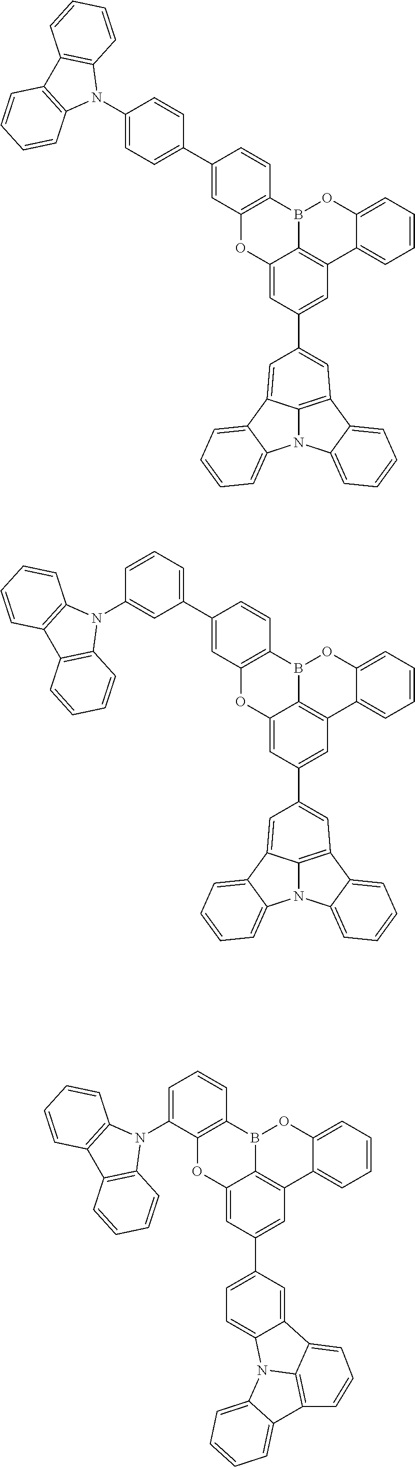 [SMILES: c1ccc2c(c1)OB1c3ccc(-c4ccc(-n5c6ccccc6c6ccccc65)cc4)cc3Oc3cc(-c4cc5c6ccccc6n6c7ccccc7c(c4)c56)cc-2c31 ; c1cc(-c2ccc3c(c2)Oc2cc(-c4cc5c6ccccc6n6c7ccccc7c(c4)c56)cc4c2B3Oc2ccccc2-4)cc(-n2c3ccccc3c3ccccc32)c1 ; c1ccc2c(c1)OB1c3cccc(-n4c5ccccc5c5ccccc54)c3Oc3cc(-c4ccc5c(c4)c4cccc6c7ccccc7n5c64)cc-2c31] 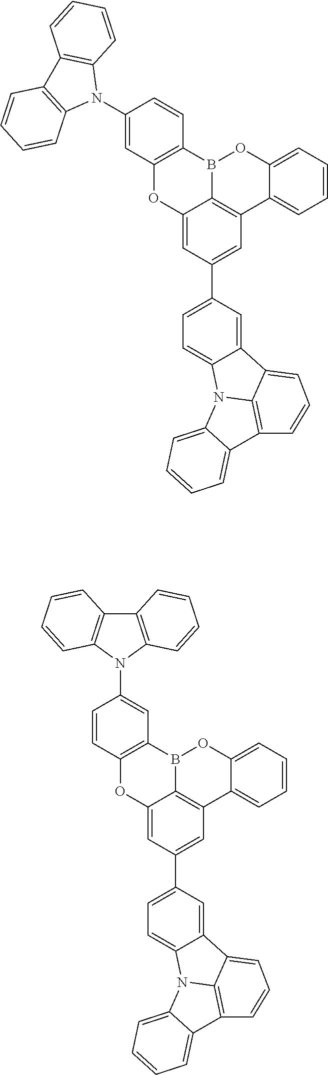 [SMILES: c1ccc2c(c1)OB1c3ccc(-n4c5ccccc5c5ccccc54)cc3Oc3cc(-c4ccc5c(c4)c4cccc6c7ccccc7n5c64)cc-2c31 ; c1ccc2c(c1)OB1c3cc(-n4c5ccccc5c5ccccc54)ccc3Oc3cc(-c4ccc5c(c4)c4cccc6c7ccccc7n5c64)cc-2c31] 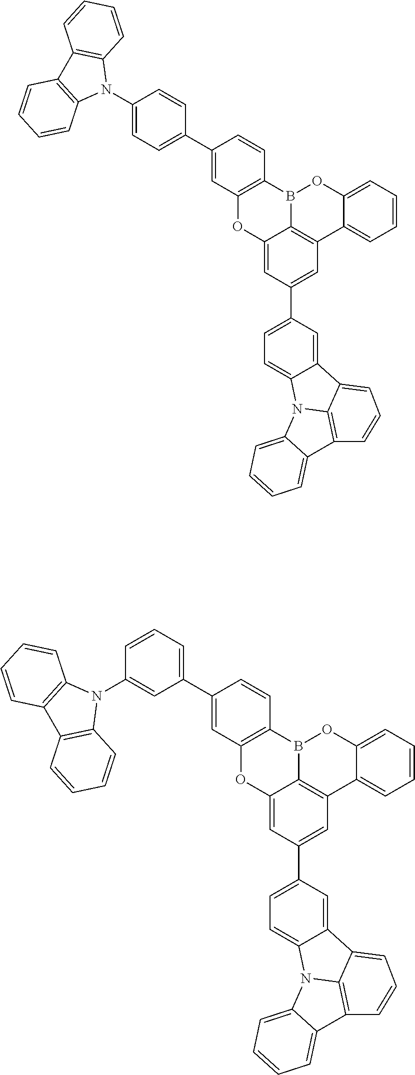 [SMILES: c1ccc2c(c1)OB1c3ccc(-c4ccc(-n5c6ccccc6c6ccccc65)cc4)cc3Oc3cc(-c4ccc5c(c4)c4cccc6c7ccccc7n5c64)cc-2c31 ; c1cc(-c2ccc3c(c2)Oc2cc(-c4ccc5c(c4)c4cccc6c7ccccc7n5c64)cc4c2B3Oc2ccccc2-4)cc(-n2c3ccccc3c3ccccc32)c1] 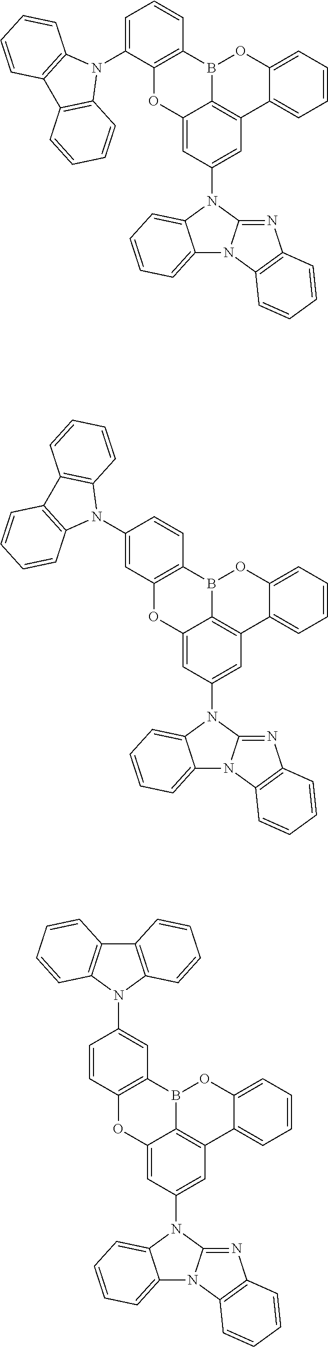 [SMILES: c1ccc2c(c1)OB1c3cccc(-n4c5ccccc5c5ccccc54)c3Oc3cc(-n4c5ccccc5n5c6ccccc6nc45)cc-2c31 ; c1ccc2c(c1)OB1c3ccc(-n4c5ccccc5c5ccccc54)cc3Oc3cc(-n4c5ccccc5n5c6ccccc6nc45)cc-2c31 ; c1ccc2c(c1)OB1c3cc(-n4c5ccccc5c5ccccc54)ccc3Oc3cc(-n4c5ccccc5n5c6ccccc6nc45)cc-2c31] 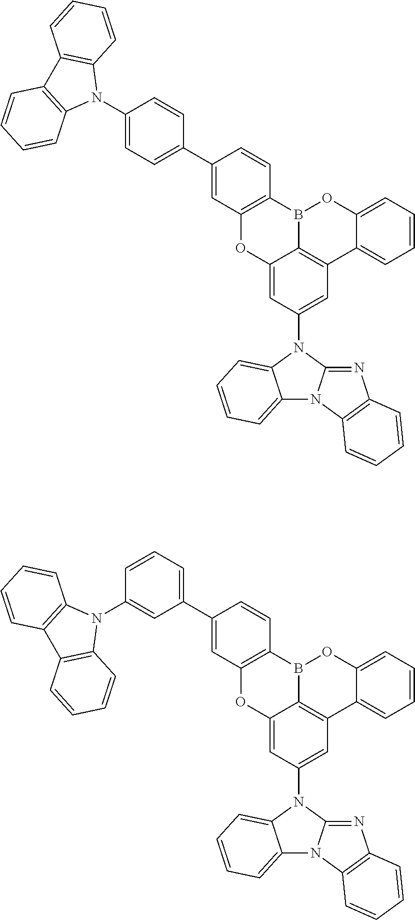 [SMILES: c1ccc2c(c1)OB1c3ccc(-c4ccc(-n5c6ccccc6c6ccccc65)cc4)cc3Oc3cc(-n4c5ccccc5n5c6ccccc6nc45)cc-2c31 ; c1cc(-c2ccc3c(c2)Oc2cc(-n4c5ccccc5n5c6ccccc6nc45)cc4c2B3Oc2ccccc2-4)cc(-n2c3ccccc3c3ccccc32)c1] 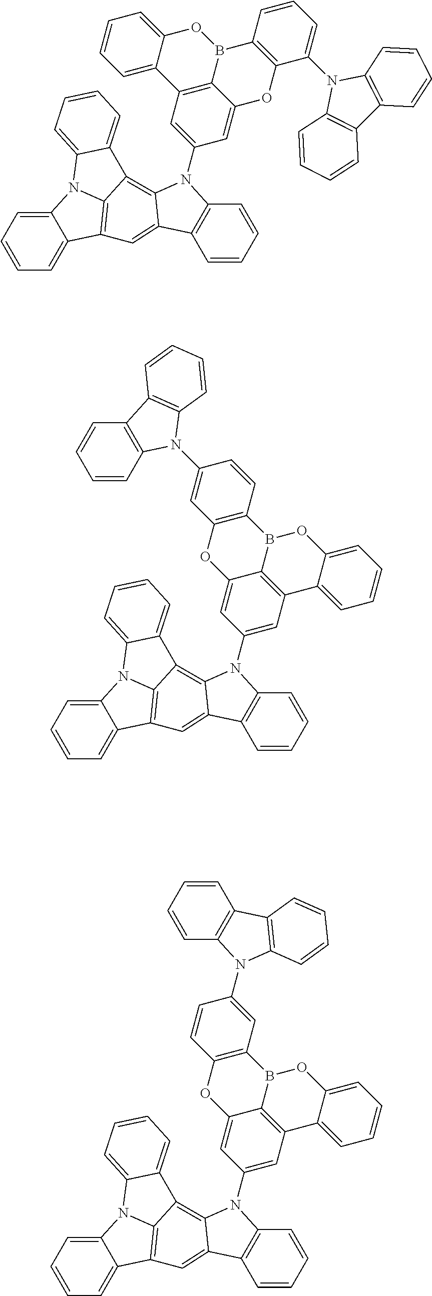 [SMILES: c1ccc2c(c1)OB1c3cccc(-n4c5ccccc5c5ccccc54)c3Oc3cc(-n4c5ccccc5c5cc6c7ccccc7n7c8ccccc8c(c54)c67)cc-2c31 ; c1ccc2c(c1)OB1c3ccc(-n4c5ccccc5c5ccccc54)cc3Oc3cc(-n4c5ccccc5c5cc6c7ccccc7n7c8ccccc8c(c54)c67)cc-2c31 ; c1ccc2c(c1)OB1c3cc(-n4c5ccccc5c5ccccc54)ccc3Oc3cc(-n4c5ccccc5c5cc6c7ccccc7n7c8ccccc8c(c54)c67)cc-2c31] 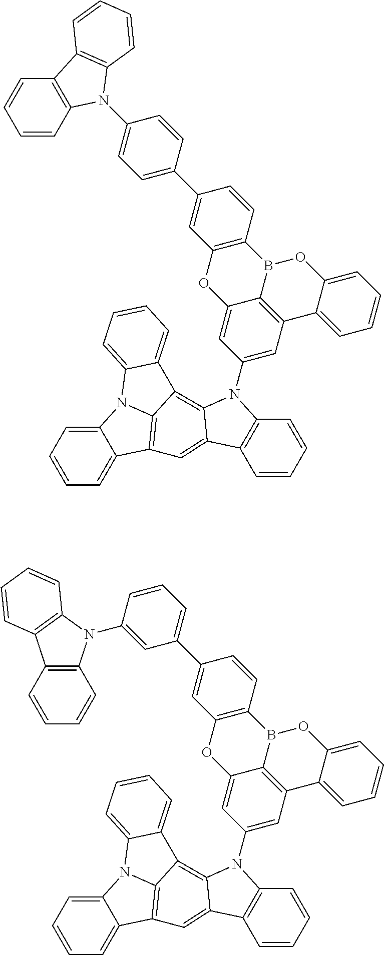 [SMILES: c1ccc2c(c1)OB1c3ccc(-c4ccc(-n5c6ccccc6c6ccccc65)cc4)cc3Oc3cc(-n4c5ccccc5c5cc6c7ccccc7n7c8ccccc8c(c54)c67)cc-2c31 ; c1cc(-c2ccc3c(c2)Oc2cc(-n4c5ccccc5c5cc6c7ccccc7n7c8ccccc8c(c54)c67)cc4c2B3Oc2ccccc2-4)cc(-n2c3ccccc3c3ccccc32)c1] 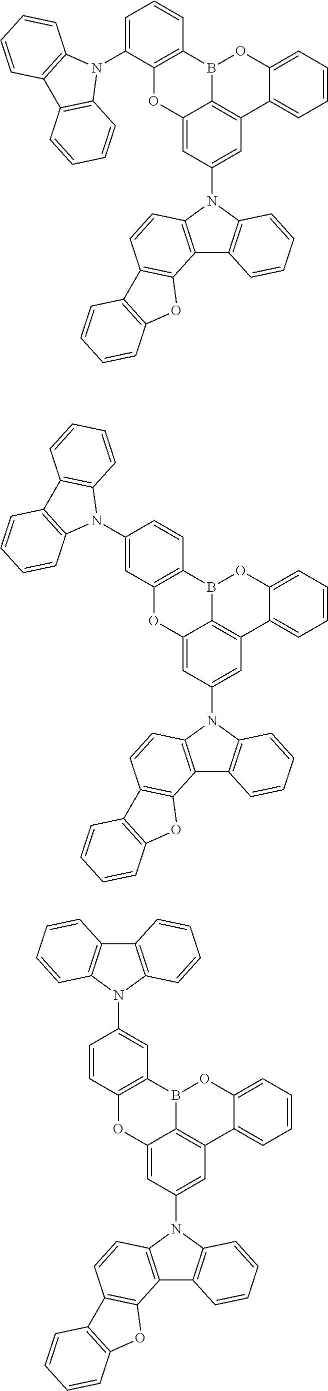 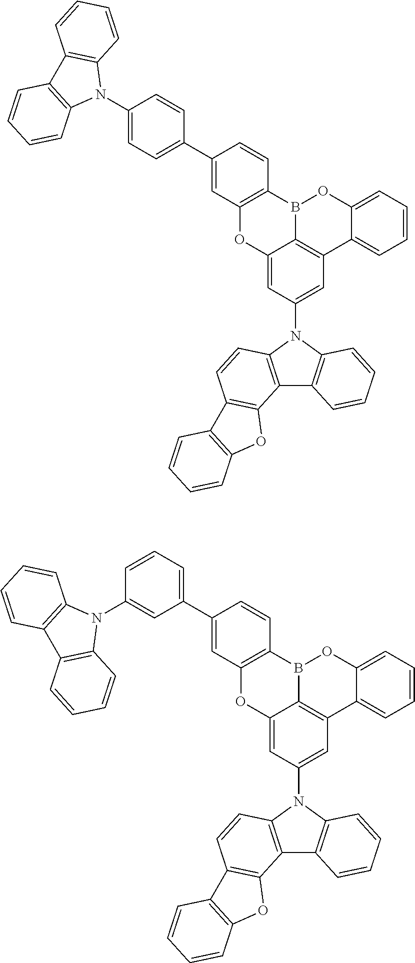 [SMILES: c1ccc2c(c1)OB1c3ccc(-c4ccc(-n5c6ccccc6c6ccccc65)cc4)cc3Oc3cc(-n4c5ccccc5c5c6oc7ccccc7c6ccc54)cc-2c31 ; c1cc(-c2ccc3c(c2)Oc2cc(-n4c5ccccc5c5c6oc7ccccc7c6ccc54)cc4c2B3Oc2ccccc2-4)cc(-n2c3ccccc3c3ccccc32)c1] 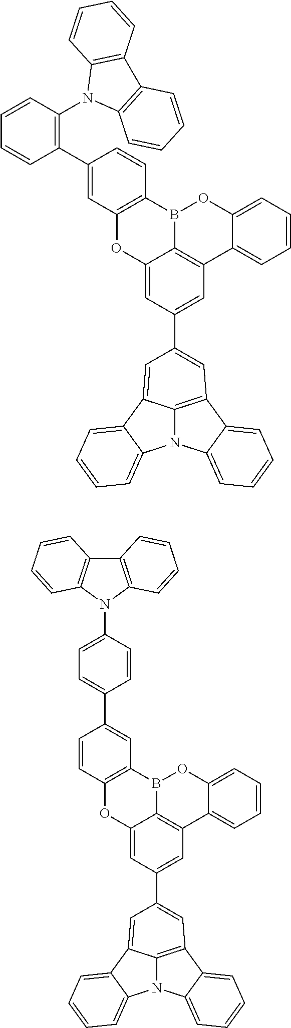 [SMILES: c1ccc2c(c1)OB1c3ccc(-c4ccccc4-n4c5ccccc5c5ccccc54)cc3Oc3cc(-c4cc5c6ccccc6n6c7ccccc7c(c4)c56)cc-2c31 ; c1ccc2c(c1)OB1c3cc(-c4ccc(-n5c6ccccc6c6ccccc65)cc4)ccc3Oc3cc(-c4cc5c6ccccc6n6c7ccccc7c(c4)c56)cc-2c31] 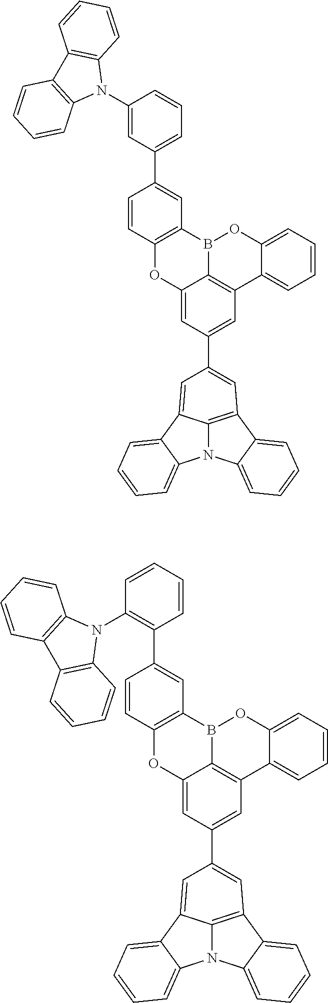 [SMILES: c1cc(-c2ccc3c(c2)B2Oc4ccccc4-c4cc(-c5cc6c7ccccc7n7c8ccccc8c(c5)c67)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-c4cc5c6ccccc6n6c7ccccc7c(c4)c56)cc-2c31] 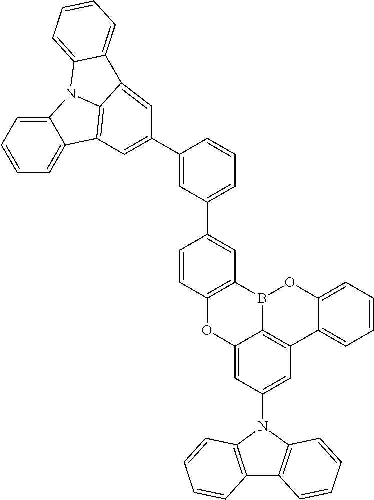 [SMILES: c1cc(-c2ccc3c(c2)B2Oc4ccccc4-c4cc(-n5c6ccccc6c6ccccc65)cc(c42)O3)cc(-c2cc3c4ccccc4n4c5ccccc5c(c2)c34)c1] 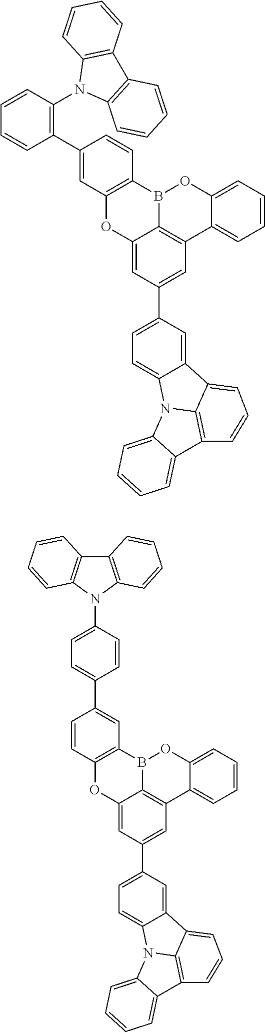 [SMILES: c1ccc2c(c1)OB1c3ccc(-c4ccccc4-n4c5ccccc5c5ccccc54)cc3Oc3cc(-c4ccc5c(c4)c4cccc6c7ccccc7n5c64)cc-2c31 ; c1ccc2c(c1)OB1c3cc(-c4ccc(-n5c6ccccc6c6ccccc65)cc4)ccc3Oc3cc(-c4ccc5c(c4)c4cccc6c7ccccc7n5c64)cc-2c31] 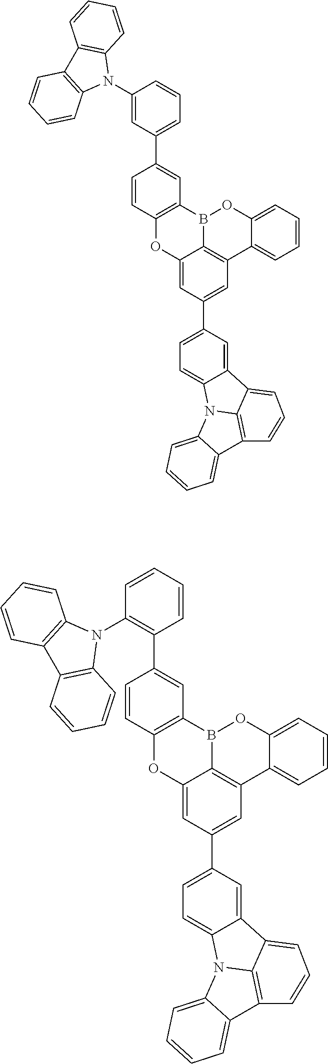 [SMILES: c1cc(-c2ccc3c(c2)B2Oc4ccccc4-c4cc(-c5ccc6c(c5)c5cccc7c8ccccc8n6c75)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-c4ccc5c(c4)c4cccc6c7ccccc7n5c64)cc-2c31] 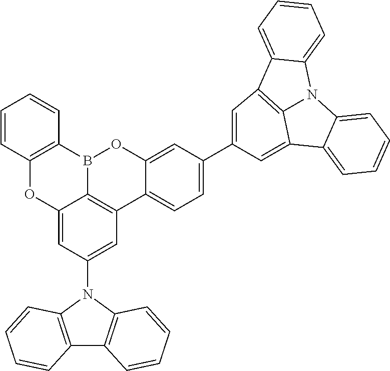 [SMILES: c1ccc2c(c1)Oc1cc(-n3c4ccccc4c4ccccc43)cc3c1B2Oc1cc(-c2cc4c5ccccc5n5c6ccccc6c(c2)c45)ccc1-3] 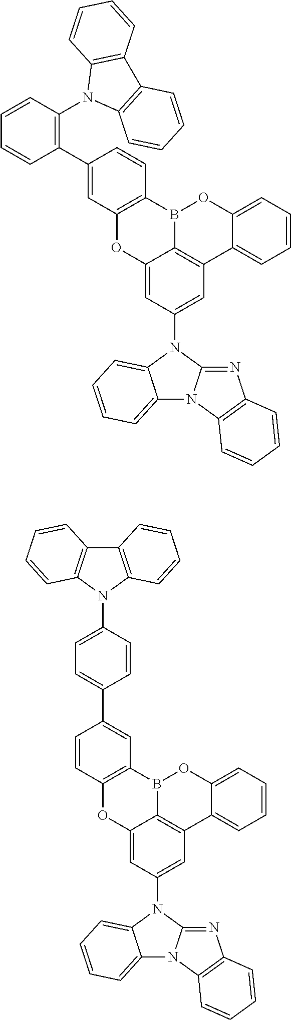 [SMILES: c1ccc2c(c1)OB1c3ccc(-c4ccccc4-n4c5ccccc5c5ccccc54)cc3Oc3cc(-n4c5ccccc5n5c6ccccc6nc45)cc-2c31 ; c1ccc2c(c1)OB1c3cc(-c4ccc(-n5c6ccccc6c6ccccc65)cc4)ccc3Oc3cc(-n4c5ccccc5n5c6ccccc6nc45)cc-2c31] 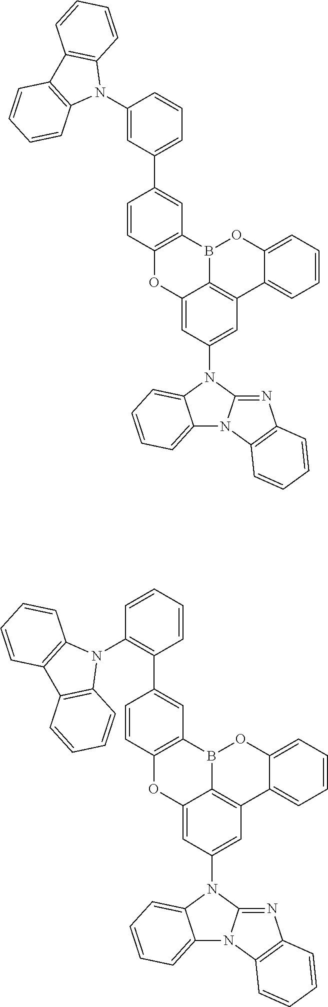 [SMILES: c1cc(-c2ccc3c(c2)B2Oc4ccccc4-c4cc(-n5c6ccccc6n6c7ccccc7nc56)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-n4c5ccccc5n5c6ccccc6nc45)cc-2c31] 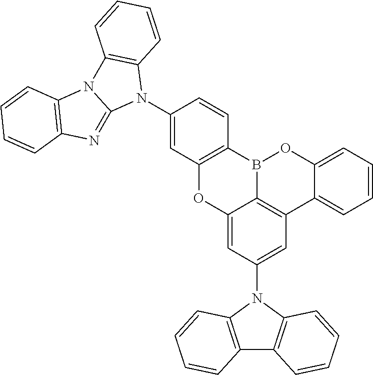 [SMILES: c1ccc2c(c1)OB1c3ccc(-n4c5ccccc5n5c6ccccc6nc45)cc3Oc3cc(-n4c5ccccc5c5ccccc54)cc-2c31] 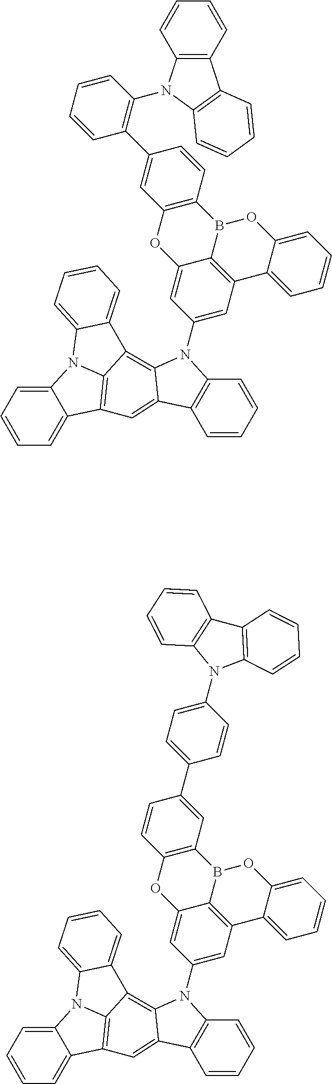 [SMILES: c1ccc2c(c1)OB1c3ccc(-c4ccccc4-n4c5ccccc5c5ccccc54)cc3Oc3cc(-n4c5ccccc5c5cc6c7ccccc7n7c8ccccc8c(c54)c67)cc-2c31 ; c1ccc2c(c1)OB1c3cc(-c4ccc(-n5c6ccccc6c6ccccc65)cc4)ccc3Oc3cc(-n4c5ccccc5c5cc6c7ccccc7n7c8ccccc8c(c54)c67)cc-2c31] 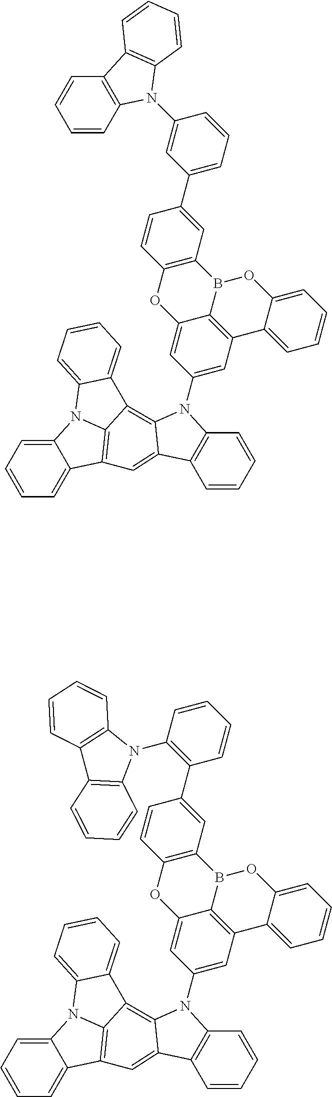 [SMILES: c1cc(-c2ccc3c(c2)B2Oc4ccccc4-c4cc(-n5c6ccccc6c6cc7c8ccccc8n8c9ccccc9c(c65)c78)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-n4c5ccccc5c5cc6c7ccccc7n7c8ccccc8c(c54)c67)cc-2c31] 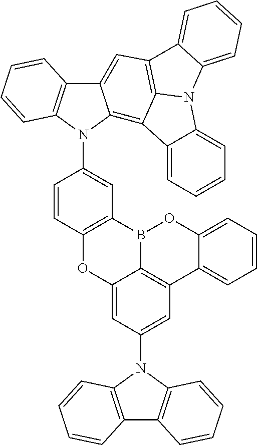 [SMILES: c1ccc2c(c1)OB1c3cc(-n4c5ccccc5c5cc6c7ccccc7n7c8ccccc8c(c54)c67)ccc3Oc3cc(-n4c5ccccc5c5ccccc54)cc-2c31] 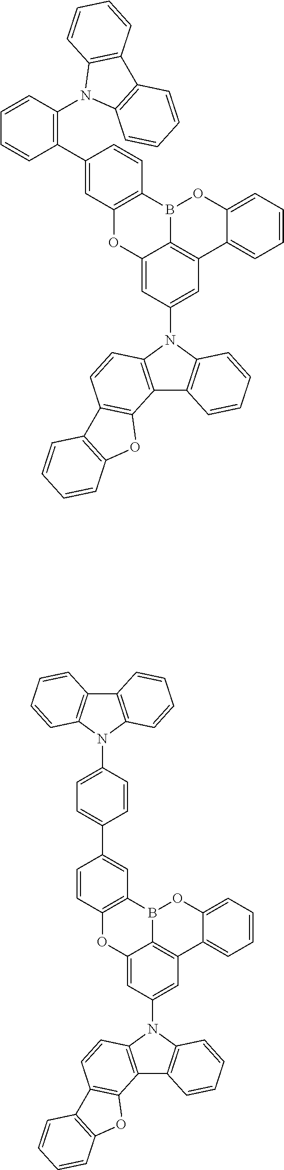 [SMILES: c1ccc2c(c1)OB1c3ccc(-c4ccccc4-n4c5ccccc5c5ccccc54)cc3Oc3cc(-n4c5ccccc5c5c6oc7ccccc7c6ccc54)cc-2c31 ; c1ccc2c(c1)OB1c3cc(-c4ccc(-n5c6ccccc6c6ccccc65)cc4)ccc3Oc3cc(-n4c5ccccc5c5c6oc7ccccc7c6ccc54)cc-2c31] 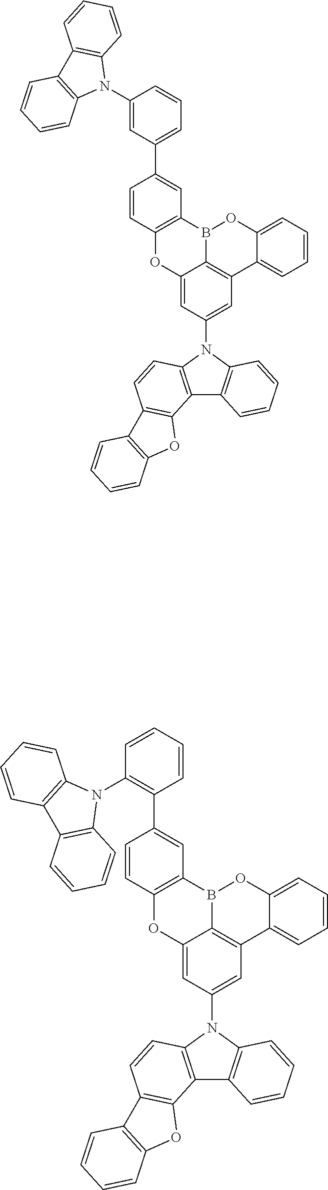 [SMILES: c1cc(-c2ccc3c(c2)B2Oc4ccccc4-c4cc(-n5c6ccccc6c6c7oc8ccccc8c7ccc65)cc(c42)O3)cc(-n2c3ccccc3c3ccccc32)c1 ; c1ccc2c(c1)OB1c3cc(-c4ccccc4-n4c5ccccc5c5ccccc54)ccc3Oc3cc(-n4c5ccccc5c5c6oc7ccccc7c6ccc54)cc-2c31] 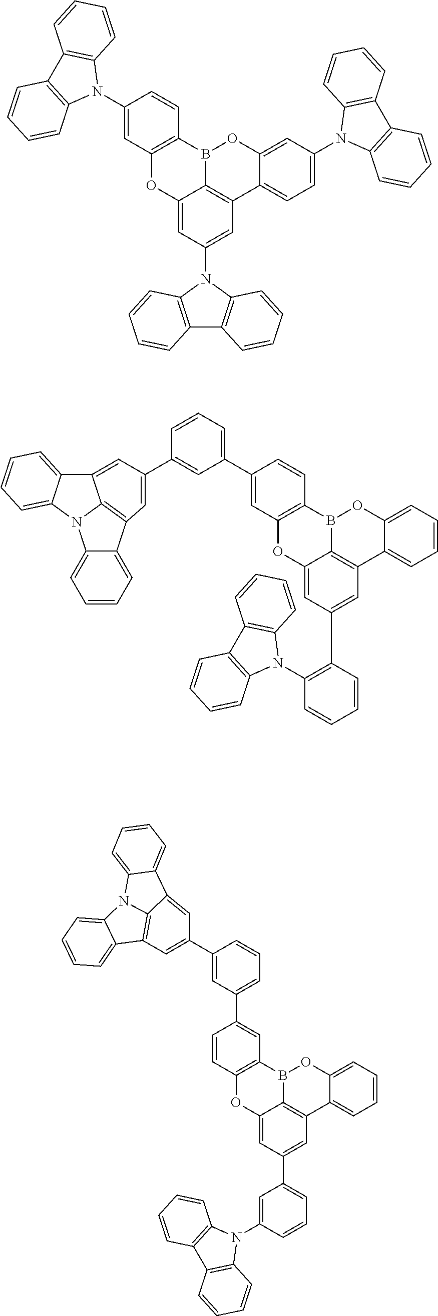 [SMILES: c1ccc2c(c1)c1ccccc1n2-c1ccc2c(c1)Oc1cc(-n3c4ccccc4c4ccccc43)cc3c1B2Oc1cc(-n2c4ccccc4c4ccccc42)ccc1-3 ; c1cc(-c2ccc3c(c2)Oc2cc(-c4ccccc4-n4c5ccccc5c5ccccc54)cc4c2B3Oc2ccccc2-4)cc(-c2cc3c4ccccc4n4c5ccccc5c(c2)c34)c1 ; c1cc(-c2ccc3c(c2)B2Oc4ccccc4-c4cc(-c5cccc(-n6c7ccccc7c7ccccc76)c5)cc(c42)O3)cc(-c2cc3c4ccccc4n4c5ccccc5c(c2)c34)c1] 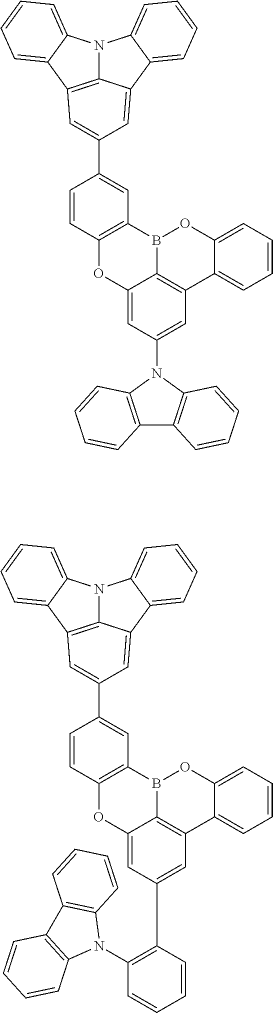 [SMILES: c1ccc2c(c1)OB1c3cc(-c4cc5c6ccccc6n6c7ccccc7c(c4)c56)ccc3Oc3cc(-n4c5ccccc5c5ccccc54)cc-2c31 ; c1ccc2c(c1)OB1c3cc(-c4cc5c6ccccc6n6c7ccccc7c(c4)c56)ccc3Oc3cc(-c4ccccc4-n4c5ccccc5c5ccccc54)cc-2c31] 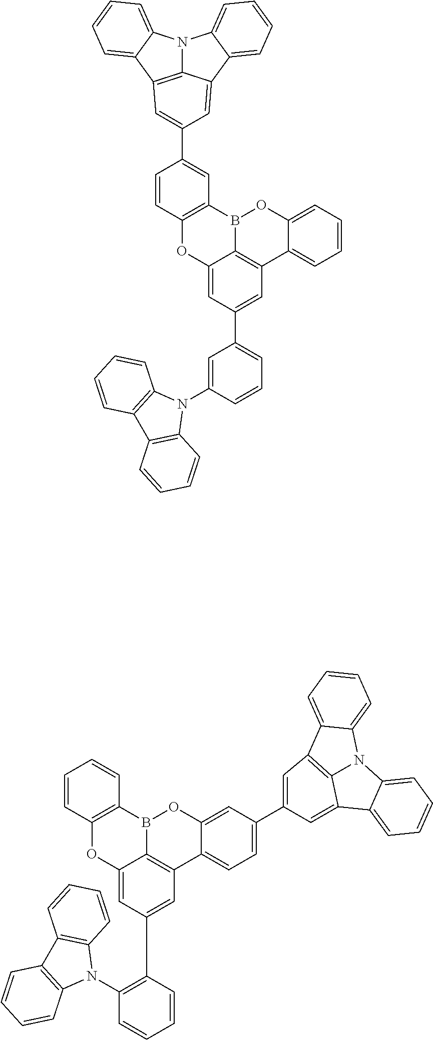 [SMILES: c1cc(-c2cc3c4c(c2)-c2ccccc2OB4c2cc(-c4cc5c6ccccc6n6c7ccccc7c(c4)c56)ccc2O3)cc(-n2c3ccccc3c3ccccc32)c1 ; c1ccc2c(c1)Oc1cc(-c3ccccc3-n3c4ccccc4c4ccccc43)cc3c1B2Oc1cc(-c2cc4c5ccccc5n5c6ccccc6c(c2)c45)ccc1-3] 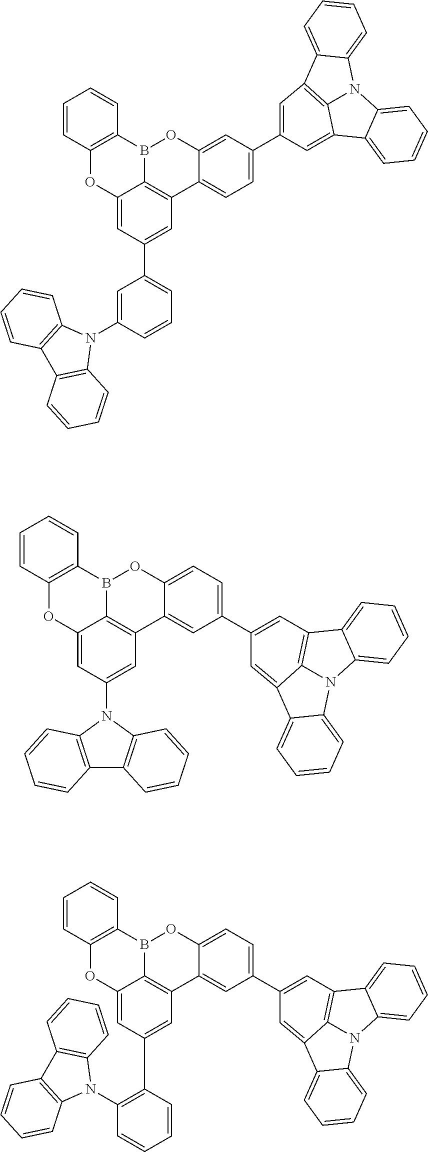 [SMILES: c1cc(-c2cc3c4c(c2)-c2ccc(-c5cc6c7ccccc7n7c8ccccc8c(c5)c67)cc2OB4c2ccccc2O3)cc(-n2c3ccccc3c3ccccc32)c1 ; c1ccc2c(c1)Oc1cc(-n3c4ccccc4c4ccccc43)cc3c1B2Oc1ccc(-c2cc4c5ccccc5n5c6ccccc6c(c2)c45)cc1-3 ; c1ccc2c(c1)Oc1cc(-c3ccccc3-n3c4ccccc4c4ccccc43)cc3c1B2Oc1ccc(-c2cc4c5ccccc5n5c6ccccc6c(c2)c45)cc1-3] 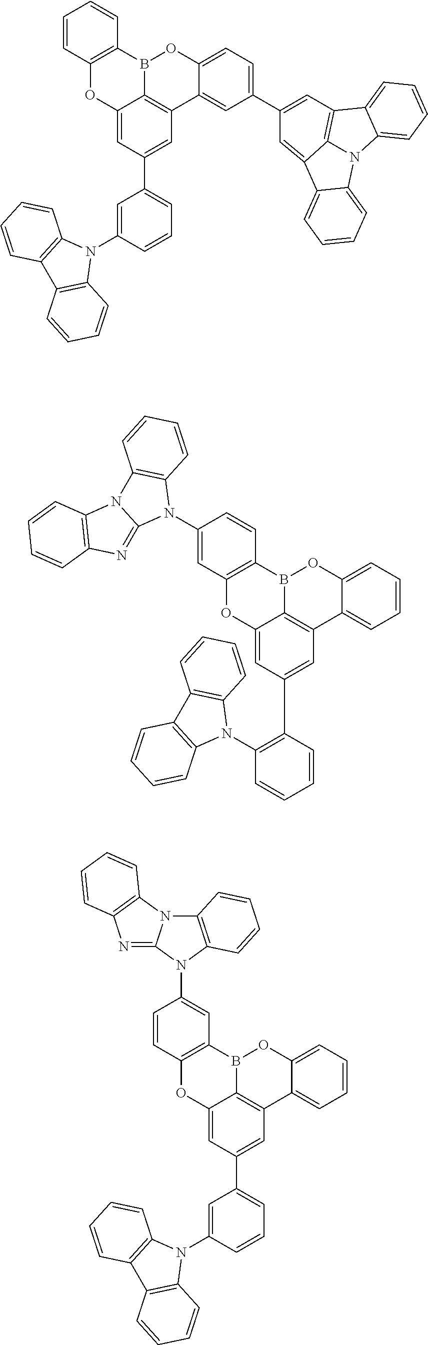 [SMILES: c1cc(-c2cc3c4c(c2)-c2cc(-c5cc6c7ccccc7n7c8ccccc8c(c5)c67)ccc2OB4c2ccccc2O3)cc(-n2c3ccccc3c3ccccc32)c1 ; c1ccc2c(c1)OB1c3ccc(-n4c5ccccc5n5c6ccccc6nc45)cc3Oc3cc(-c4ccccc4-n4c5ccccc5c5ccccc54)cc-2c31 ; c1cc(-c2cc3c4c(c2)-c2ccccc2OB4c2cc(-n4c5ccccc5n5c6ccccc6nc45)ccc2O3)cc(-n2c3ccccc3c3ccccc32)c1] 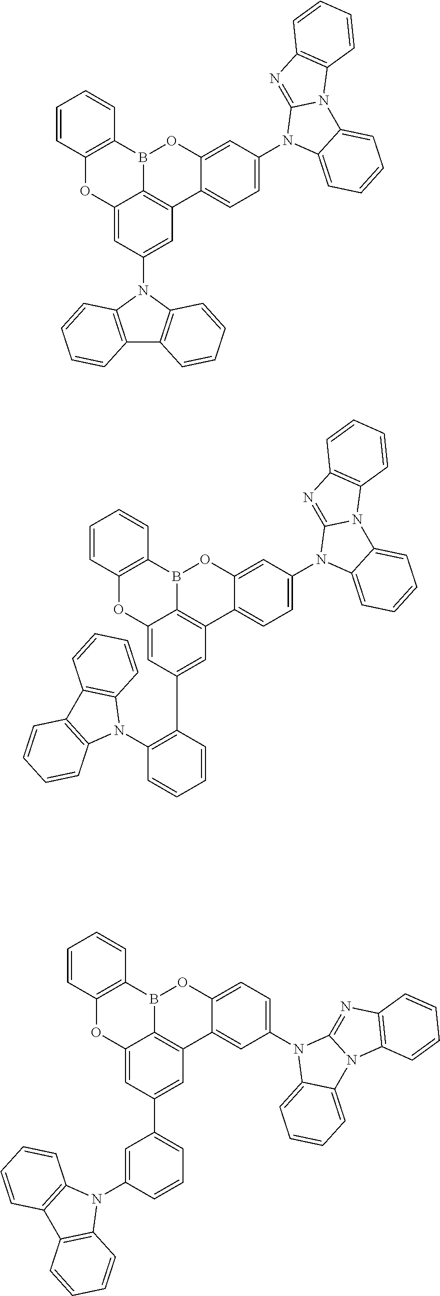 [SMILES: c1ccc2c(c1)Oc1cc(-n3c4ccccc4c4ccccc43)cc3c1B2Oc1cc(-n2c4ccccc4n4c5ccccc5nc24)ccc1-3 ; c1ccc2c(c1)Oc1cc(-c3ccccc3-n3c4ccccc4c4ccccc43)cc3c1B2Oc1cc(-n2c4ccccc4n4c5ccccc5nc24)ccc1-3 ; c1cc(-c2cc3c4c(c2)-c2cc(-n5c6ccccc6n6c7ccccc7nc56)ccc2OB4c2ccccc2O3)cc(-n2c3ccccc3c3ccccc32)c1] 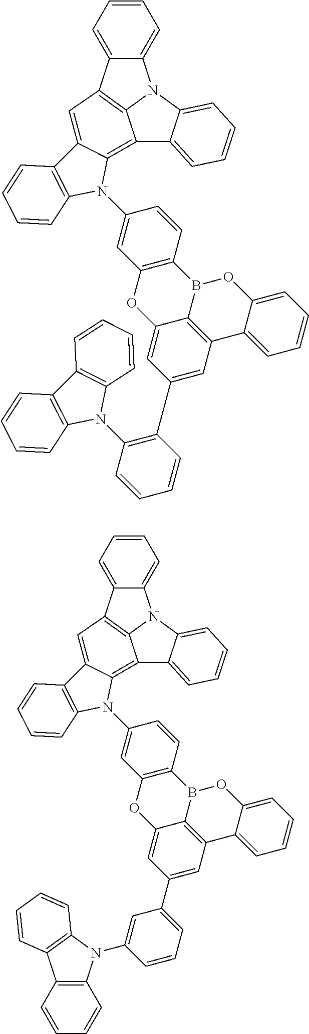 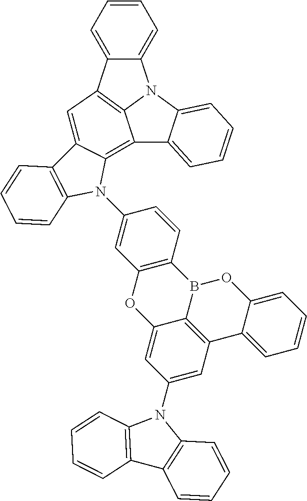 [SMILES: c1ccc2c(c1)OB1c3ccc(-n4c5ccccc5c5cc6c7ccccc7n7c8ccccc8c(c54)c67)cc3Oc3cc(-n4c5ccccc5c5ccccc54)cc-2c31] 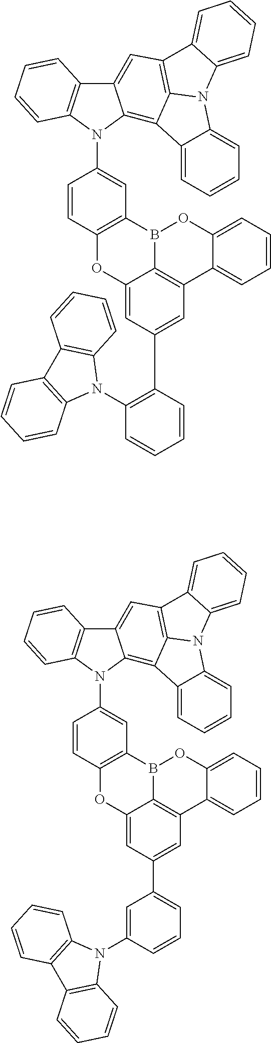 [SMILES: c1ccc2c(c1)OB1c3cc(-n4c5ccccc5c5cc6c7ccccc7n7c8ccccc8c(c54)c67)ccc3Oc3cc(-c4ccccc4-n4c5ccccc5c5ccccc54)cc-2c31 ; c1cc(-c2cc3c4c(c2)-c2ccccc2OB4c2cc(-n4c5ccccc5c5cc6c7ccccc7n7c8ccccc8c(c54)c67)ccc2O3)cc(-n2c3ccccc3c3ccccc32)c1] 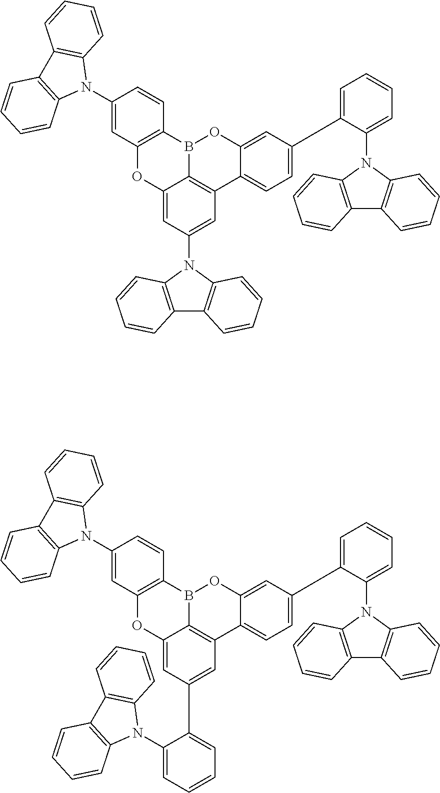 [SMILES: c1ccc(-n2c3ccccc3c3ccccc32)c(-c2ccc3c(c2)OB2c4ccc(-n5c6ccccc6c6ccccc65)cc4Oc4cc(-n5c6ccccc6c6ccccc65)cc-3c42)c1 ; c1ccc(-n2c3ccccc3c3ccccc32)c(-c2ccc3c(c2)OB2c4ccc(-n5c6ccccc6c6ccccc65)cc4Oc4cc(-c5ccccc5-n5c6ccccc6c6ccccc65)cc-3c42)c1] 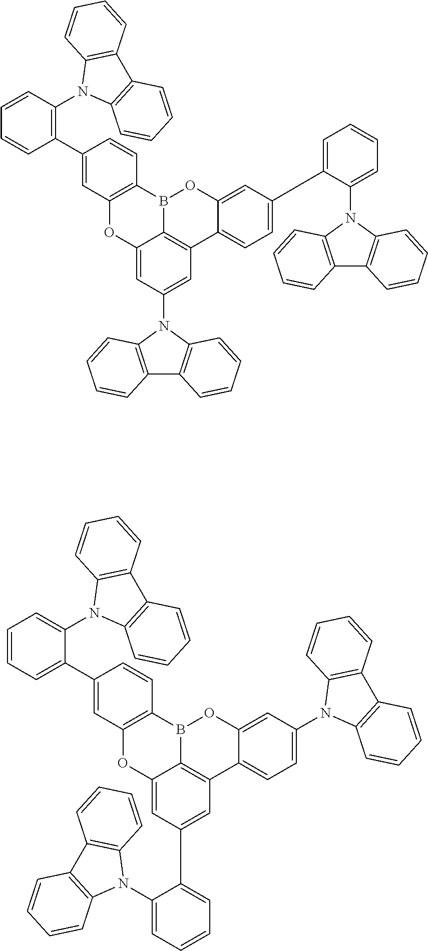 [SMILES: c1ccc(-n2c3ccccc3c3ccccc32)c(-c2ccc3c(c2)Oc2cc(-n4c5ccccc5c5ccccc54)cc4c2B3Oc2cc(-c3ccccc3-n3c5ccccc5c5ccccc53)ccc2-4)c1 ; c1ccc(-n2c3ccccc3c3ccccc32)c(-c2ccc3c(c2)Oc2cc(-c4ccccc4-n4c5ccccc5c5ccccc54)cc4c2B3Oc2cc(-n3c5ccccc5c5ccccc53)ccc2-4)c1] 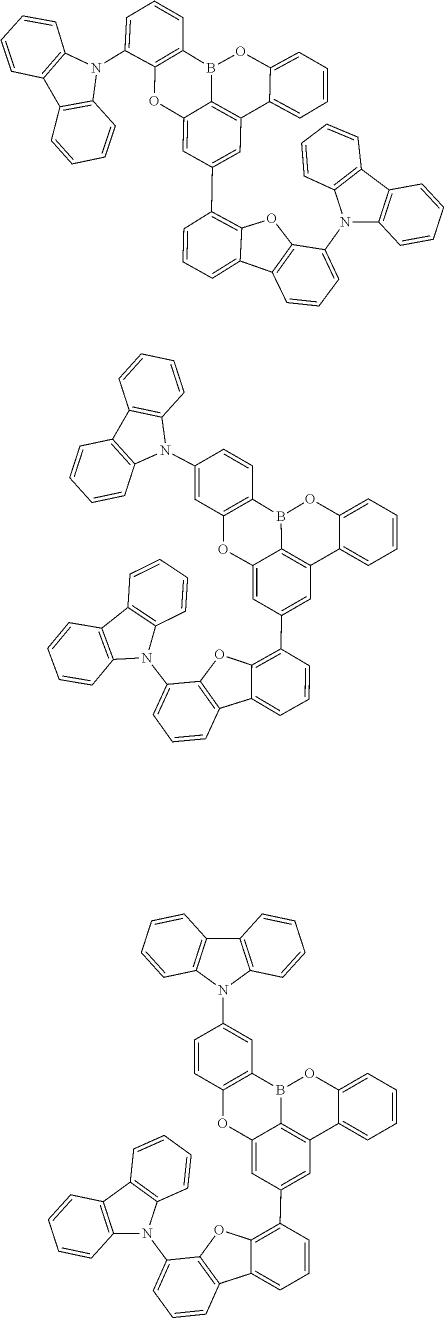 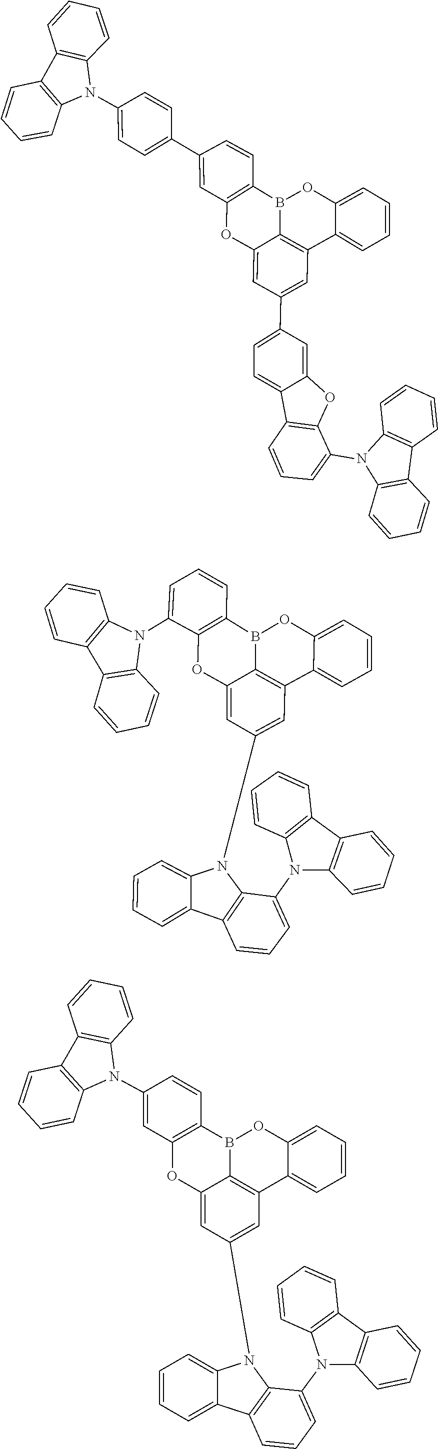 [SMILES: c1ccc2c(c1)OB1c3ccc(-c4ccc(-n5c6ccccc6c6ccccc65)cc4)cc3Oc3cc(-c4ccc5c(c4)oc4c(-n6c7ccccc7c7ccccc76)cccc45)cc-2c31 ; c1ccc2c(c1)OB1c3cccc(-n4c5ccccc5c5ccccc54)c3Oc3cc(-n4c5ccccc5c5cccc(-n6c7ccccc7c7ccccc76)c54)cc-2c31 ; c1ccc2c(c1)OB1c3ccc(-n4c5ccccc5c5ccccc54)cc3Oc3cc(-n4c5ccccc5c5cccc(-n6c7ccccc7c7ccccc76)c54)cc-2c31] 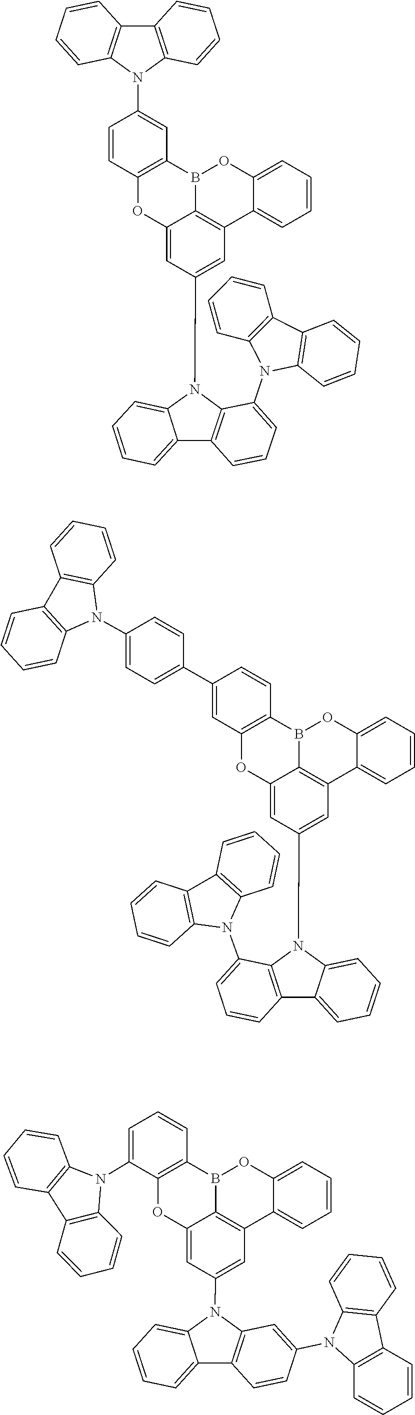 [SMILES: c1ccc2c(c1)OB1c3cc(-n4c5ccccc5c5ccccc54)ccc3Oc3cc(-n4c5ccccc5c5cccc(-n6c7ccccc7c7ccccc76)c54)cc-2c31 ; c1ccc2c(c1)OB1c3ccc(-c4ccc(-n5c6ccccc6c6ccccc65)cc4)cc3Oc3cc(-n4c5ccccc5c5cccc(-n6c7ccccc7c7ccccc76)c54)cc-2c31 ; c1ccc2c(c1)OB1c3cccc(-n4c5ccccc5c5ccccc54)c3Oc3cc(-n4c5ccccc5c5ccc(-n6c7ccccc7c7ccccc76)cc54)cc-2c31] 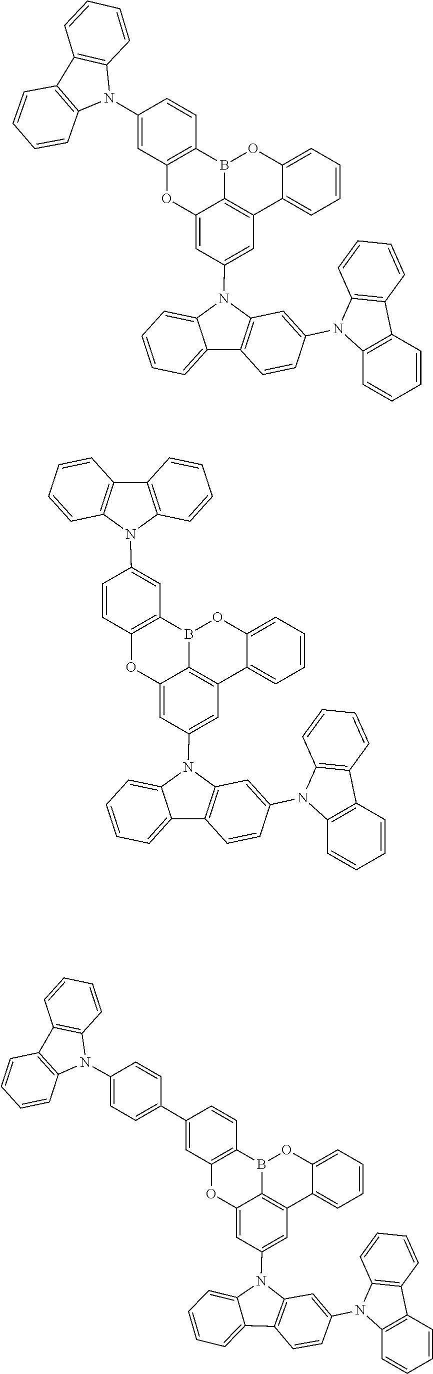 [SMILES: c1ccc2c(c1)OB1c3ccc(-n4c5ccccc5c5ccccc54)cc3Oc3cc(-n4c5ccccc5c5ccc(-n6c7ccccc7c7ccccc76)cc54)cc-2c31 ; c1ccc2c(c1)OB1c3cc(-n4c5ccccc5c5ccccc54)ccc3Oc3cc(-n4c5ccccc5c5ccc(-n6c7ccccc7c7ccccc76)cc54)cc-2c31 ; c1ccc2c(c1)OB1c3ccc(-c4ccc(-n5c6ccccc6c6ccccc65)cc4)cc3Oc3cc(-n4c5ccccc5c5ccc(-n6c7ccccc7c7ccccc76)cc54)cc-2c31] 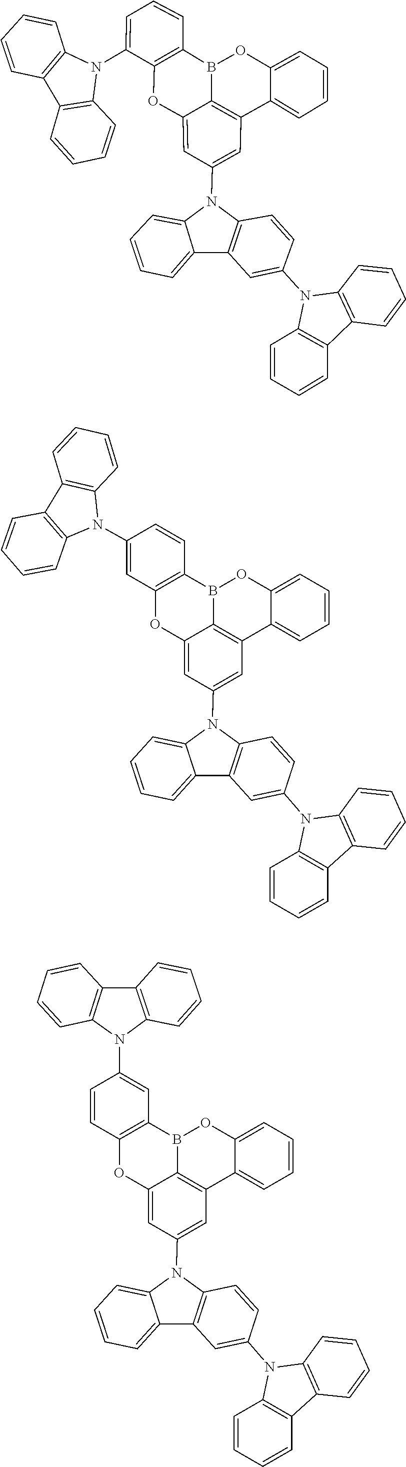 [SMILES: c1ccc2c(c1)OB1c3cccc(-n4c5ccccc5c5ccccc54)c3Oc3cc(-n4c5ccccc5c5cc(-n6c7ccccc7c7ccccc76)ccc54)cc-2c31 ; c1ccc2c(c1)OB1c3ccc(-n4c5ccccc5c5ccccc54)cc3Oc3cc(-n4c5ccccc5c5cc(-n6c7ccccc7c7ccccc76)ccc54)cc-2c31 ; c1ccc2c(c1)OB1c3cc(-n4c5ccccc5c5ccccc54)ccc3Oc3cc(-n4c5ccccc5c5cc(-n6c7ccccc7c7ccccc76)ccc54)cc-2c31] 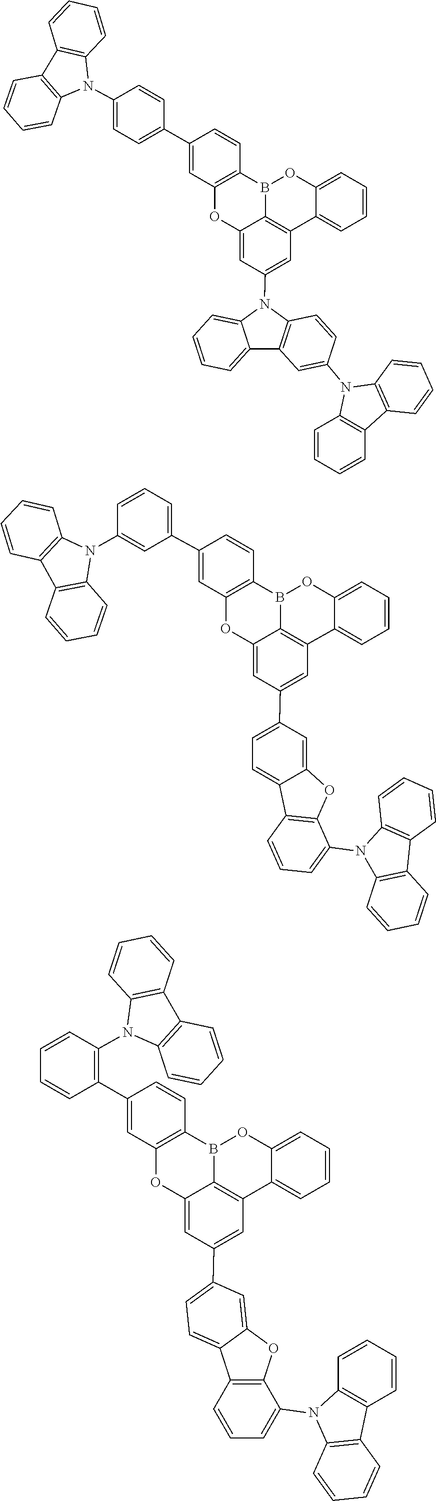 [SMILES: c1ccc2c(c1)OB1c3ccc(-c4ccc(-n5c6ccccc6c6ccccc65)cc4)cc3Oc3cc(-n4c5ccccc5c5cc(-n6c7ccccc7c7ccccc76)ccc54)cc-2c31 ; c1cc(-c2ccc3c(c2)Oc2cc(-c4ccc5c(c4)oc4c(-n6c7ccccc7c7ccccc76)cccc45)cc4c2B3Oc2ccccc2-4)cc(-n2c3ccccc3c3ccccc32)c1 ; c1ccc2c(c1)OB1c3ccc(-c4ccccc4-n4c5ccccc5c5ccccc54)cc3Oc3cc(-c4ccc5c(c4)oc4c(-n6c7ccccc7c7ccccc76)cccc45)cc-2c31] 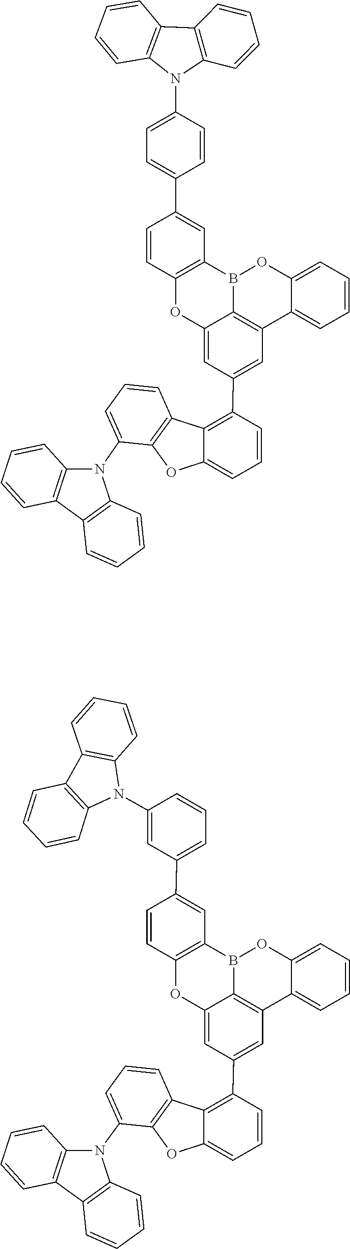 [SMILES: c1ccc2c(c1)OB1c3cc(-c4ccc(-n5c6ccccc6c6ccccc65)cc4)ccc3Oc3cc(-c4cccc5oc6c(-n7c8ccccc8c8ccccc87)cccc6c45)cc-2c31 ; c1cc(-c2ccc3c(c2)B2Oc4ccccc4-c4cc(-c5cccc6oc7c(-n8c9ccccc9c9ccccc98)cccc7c56)cc(c42)O3)cc(-n2c3ccccc3c3ccccc32)c1] 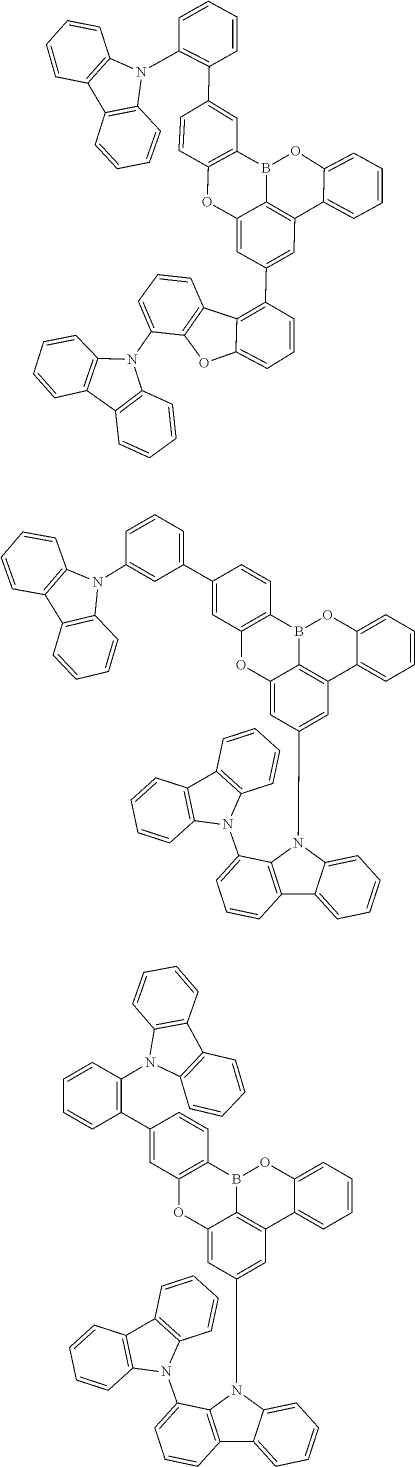 [SMILES: c1ccc2c(c1)OB1c3cc(-c4ccccc4-n4c5ccccc5c5ccccc54)ccc3Oc3cc(-c4cccc5oc6c(-n7c8ccccc8c8ccccc87)cccc6c45)cc-2c31 ; c1cc(-c2ccc3c(c2)Oc2cc(-n4c5ccccc5c5cccc(-n6c7ccccc7c7ccccc76)c54)cc4c2B3Oc2ccccc2-4)cc(-n2c3ccccc3c3ccccc32)c1 ; c1ccc2c(c1)OB1c3ccc(-c4ccccc4-n4c5ccccc5c5ccccc54)cc3Oc3cc(-n4c5ccccc5c5cccc(-n6c7ccccc7c7ccccc76)c54)cc-2c31] 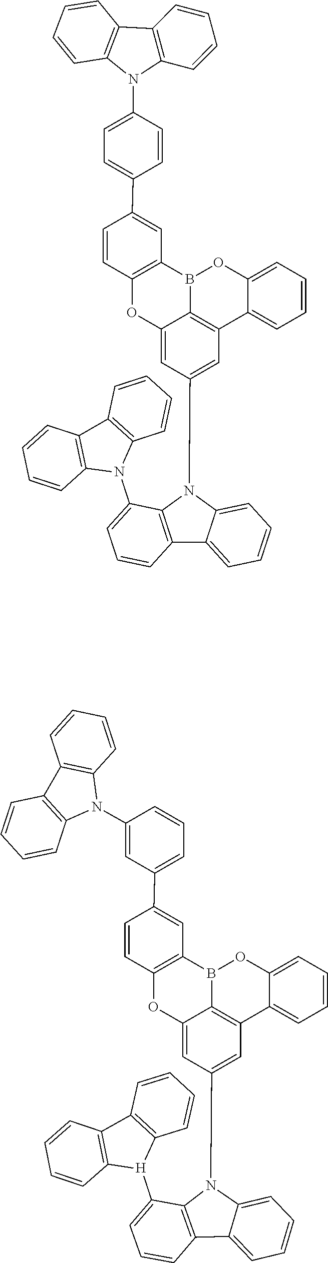 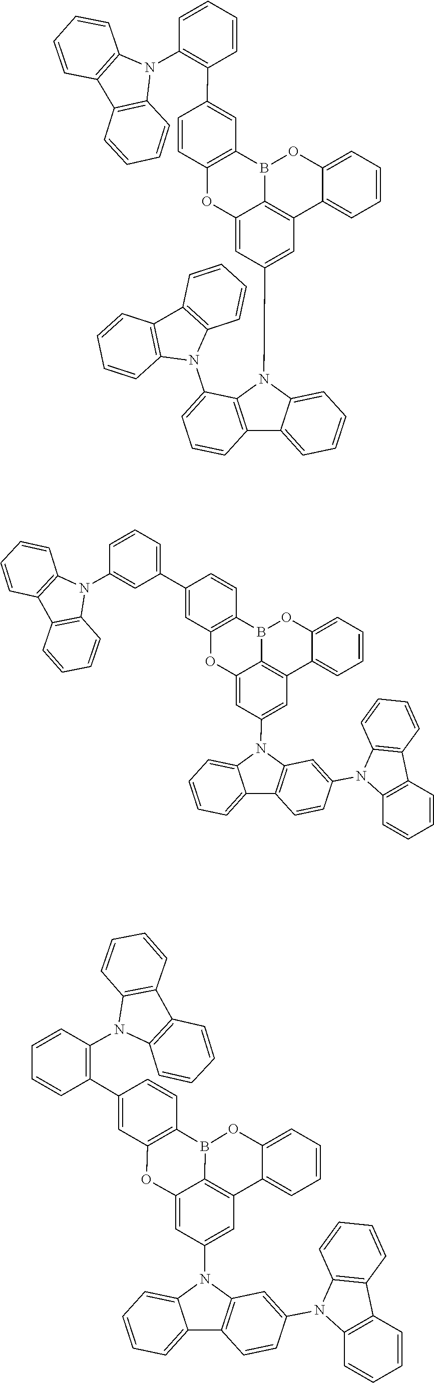 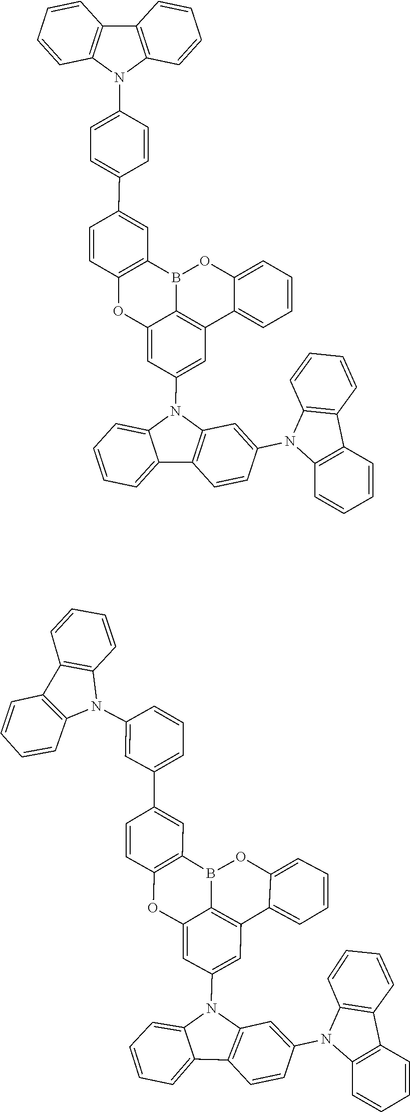 [SMILES: c1ccc2c(c1)OB1c3cc(-c4ccc(-n5c6ccccc6c6ccccc65)cc4)ccc3Oc3cc(-n4c5ccccc5c5ccc(-n6c7ccccc7c7ccccc76)cc54)cc-2c31 ; c1cc(-c2ccc3c(c2)B2Oc4ccccc4-c4cc(-n5c6ccccc6c6ccc(-n7c8ccccc8c8ccccc87)cc65)cc(c42)O3)cc(-n2c3ccccc3c3ccccc32)c1] 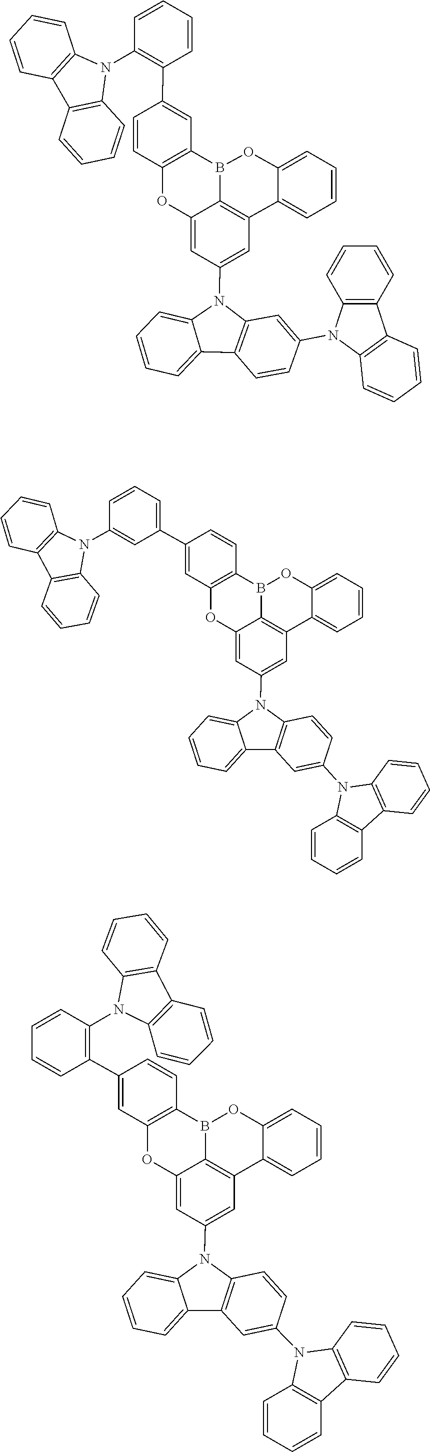 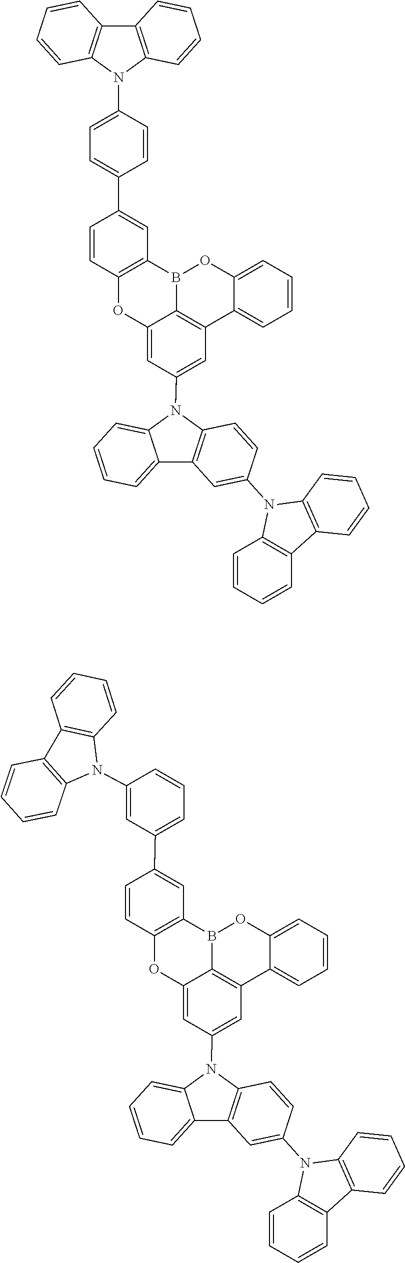 [SMILES: c1ccc2c(c1)OB1c3cc(-c4ccc(-n5c6ccccc6c6ccccc65)cc4)ccc3Oc3cc(-n4c5ccccc5c5cc(-n6c7ccccc7c7ccccc76)ccc54)cc-2c31 ; c1cc(-c2ccc3c(c2)B2Oc4ccccc4-c4cc(-n5c6ccccc6c6cc(-n7c8ccccc8c8ccccc87)ccc65)cc(c42)O3)cc(-n2c3ccccc3c3ccccc32)c1] 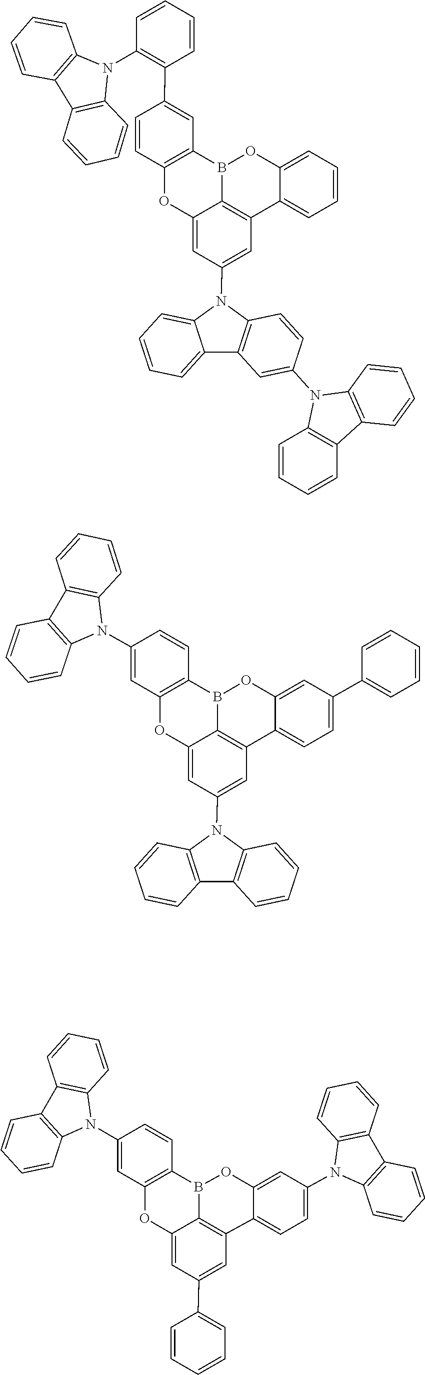 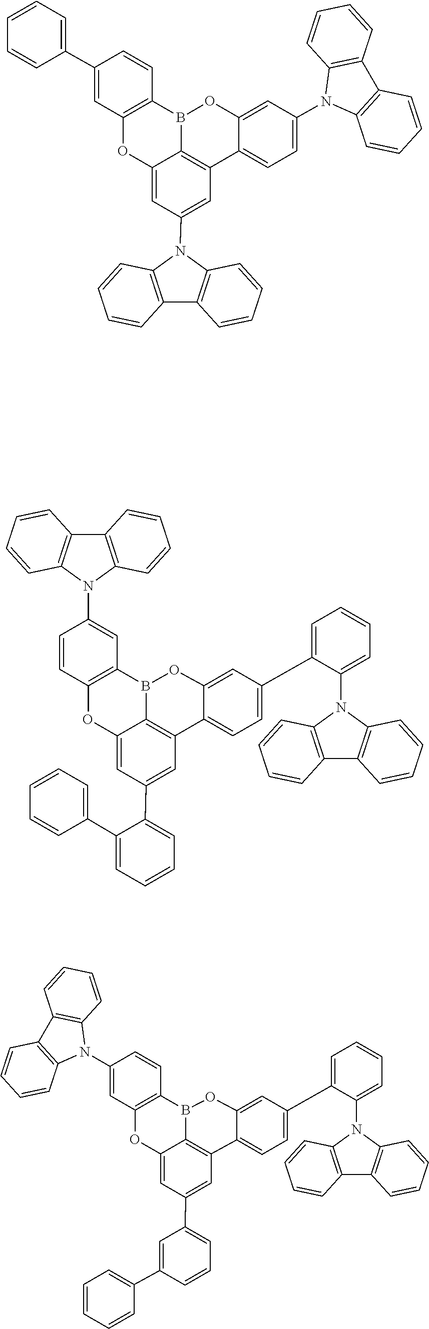 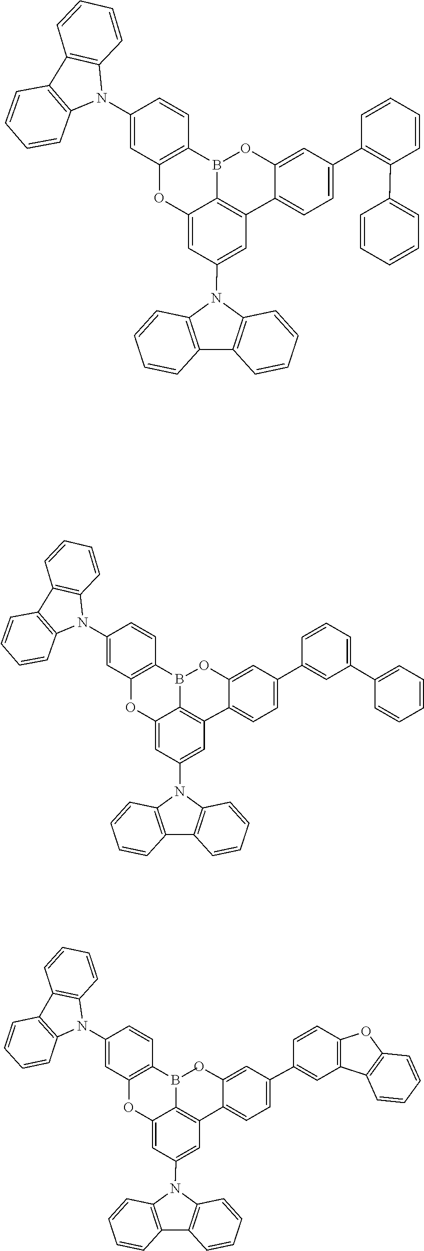 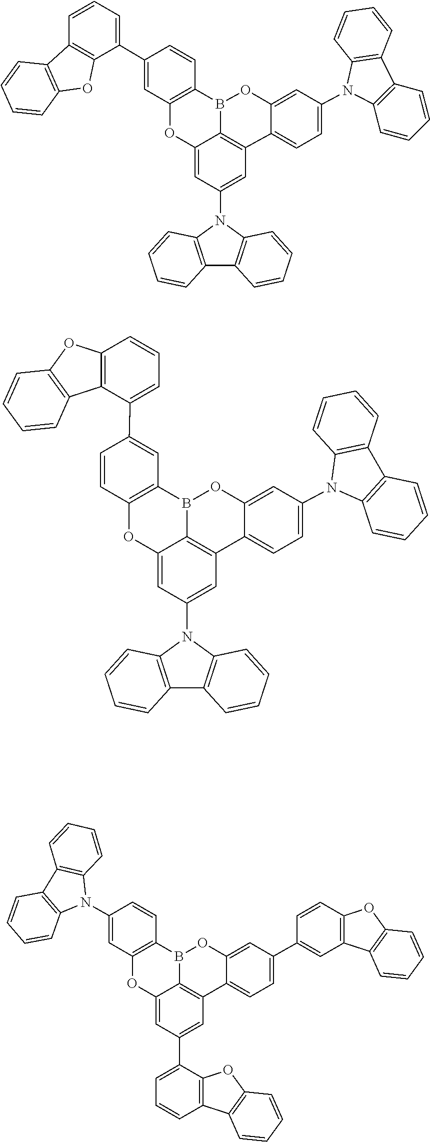 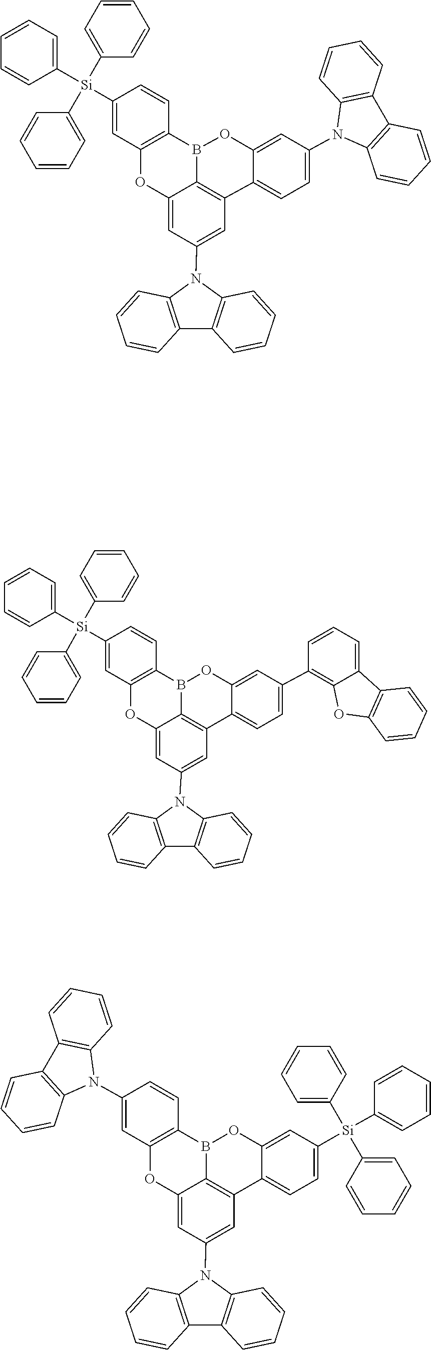 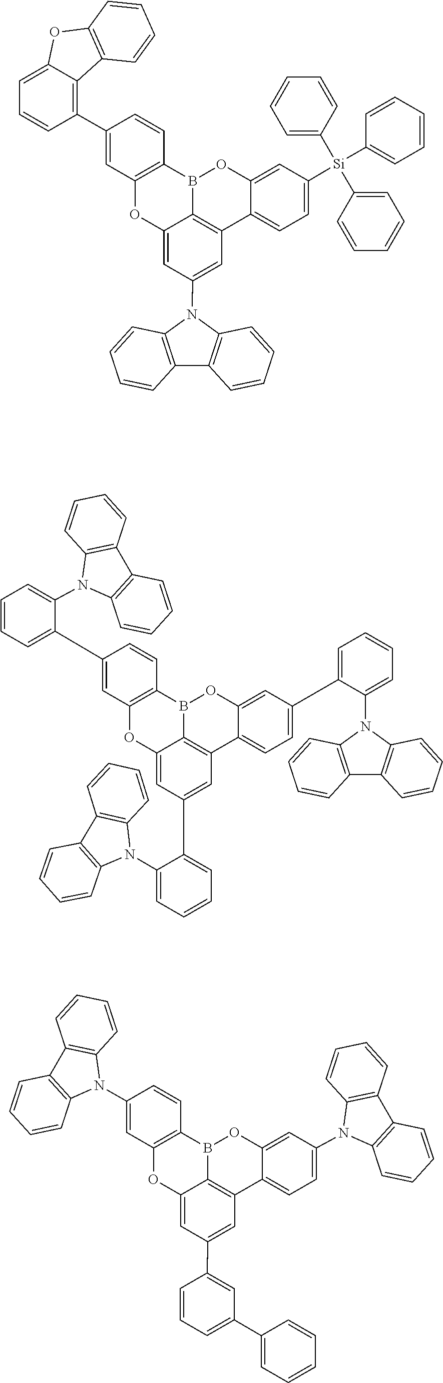 [SMILES: c1ccc([Si](c2ccccc2)(c2ccccc2)c2ccc3c(c2)OB2c4ccc(-c5cccc6oc7ccccc7c56)cc4Oc4cc(-n5c6ccccc6c6ccccc65)cc-3c42)cc1 ; c1ccc(-n2c3ccccc3c3ccccc32)c(-c2ccc3c(c2)Oc2cc(-c4ccccc4-n4c5ccccc5c5ccccc54)cc4c2B3Oc2cc(-c3ccccc3-n3c5ccccc5c5ccccc53)ccc2-4)c1 ; c1ccc(-c2cccc(-c3cc4c5c(c3)-c3ccc(-n6c7ccccc7c7ccccc76)cc3OB5c3ccc(-n5c6ccccc6c6ccccc65)cc3O4)c2)cc1] 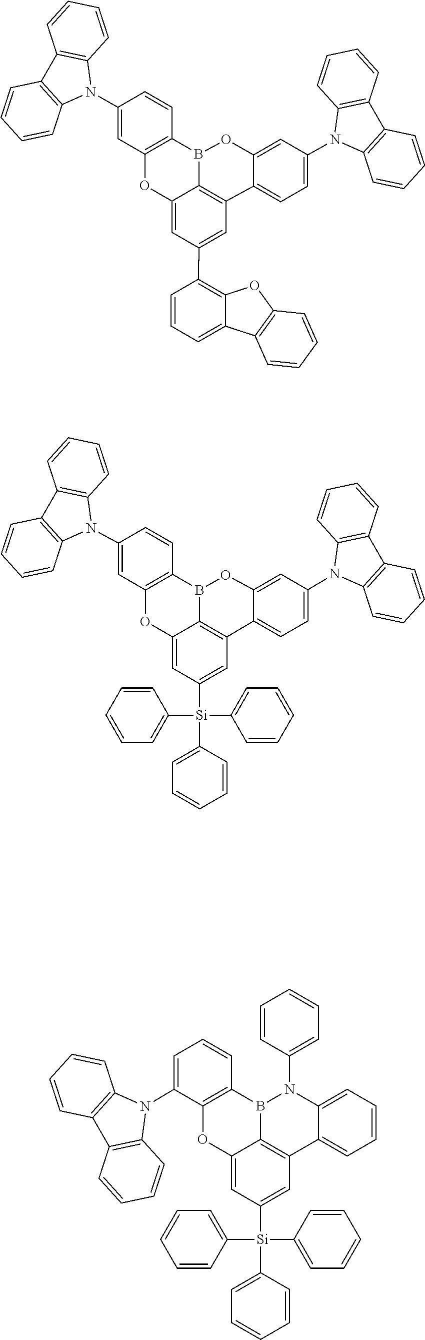 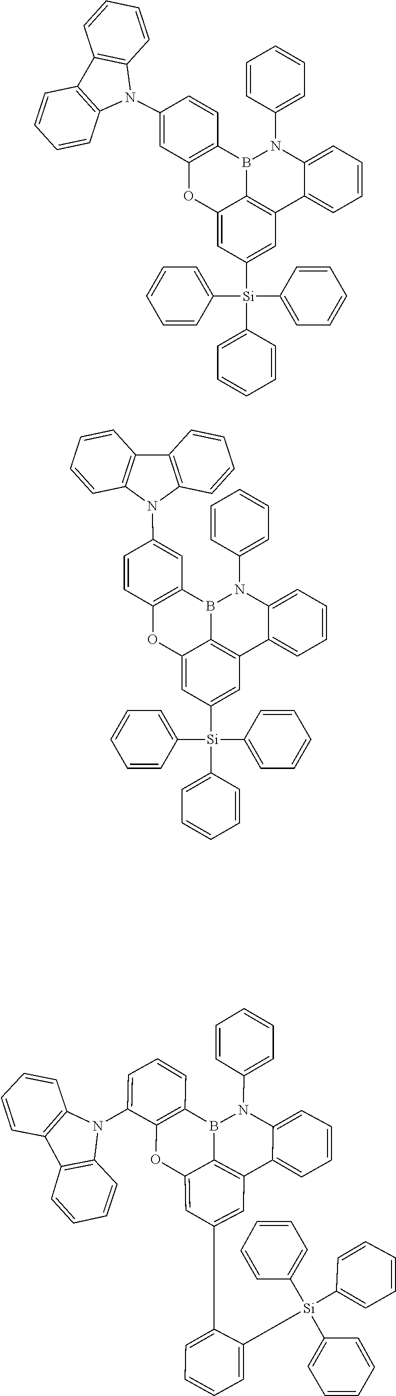 [SMILES: c1ccc(N2B3c4ccc(-n5c6ccccc6c6ccccc65)cc4Oc4cc([Si](c5ccccc5)(c5ccccc5)c5ccccc5)cc(c43)-c3ccccc32)cc1 ; c1ccc(N2B3c4cc(-n5c6ccccc6c6ccccc65)ccc4Oc4cc([Si](c5ccccc5)(c5ccccc5)c5ccccc5)cc(c43)-c3ccccc32)cc1 ; c1ccc(N2B3c4cccc(-n5c6ccccc6c6ccccc65)c4Oc4cc(-c5ccccc5[Si](c5ccccc5)(c5ccccc5)c5ccccc5)cc(c43)-c3ccccc32)cc1] 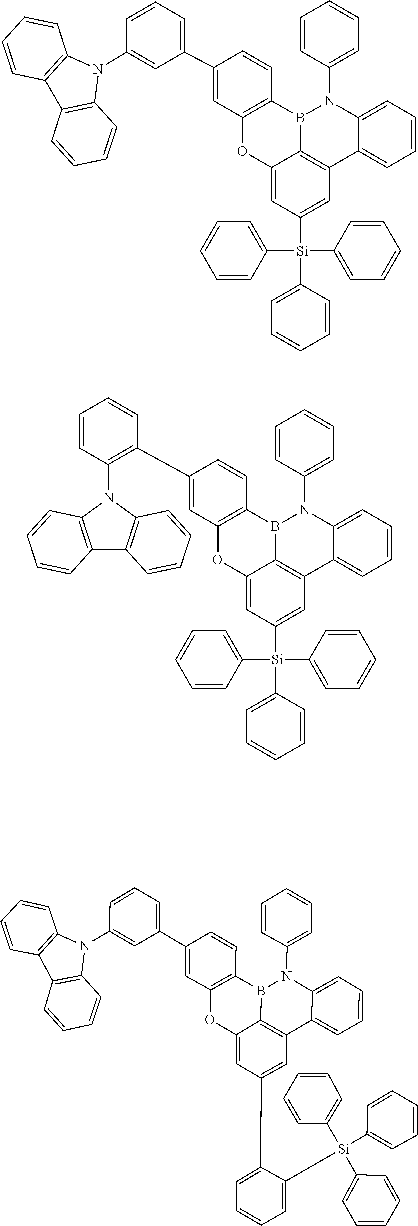 [SMILES: c1ccc(N2B3c4ccc(-c5cccc(-n6c7ccccc7c7ccccc76)c5)cc4Oc4cc([Si](c5ccccc5)(c5ccccc5)c5ccccc5)cc(c43)-c3ccccc32)cc1 ; c1ccc(N2B3c4ccc(-c5ccccc5-n5c6ccccc6c6ccccc65)cc4Oc4cc([Si](c5ccccc5)(c5ccccc5)c5ccccc5)cc(c43)-c3ccccc32)cc1 ; c1ccc(N2B3c4ccc(-c5cccc(-n6c7ccccc7c7ccccc76)c5)cc4Oc4cc(-c5ccccc5[Si](c5ccccc5)(c5ccccc5)c5ccccc5)cc(c43)-c3ccccc32)cc1] 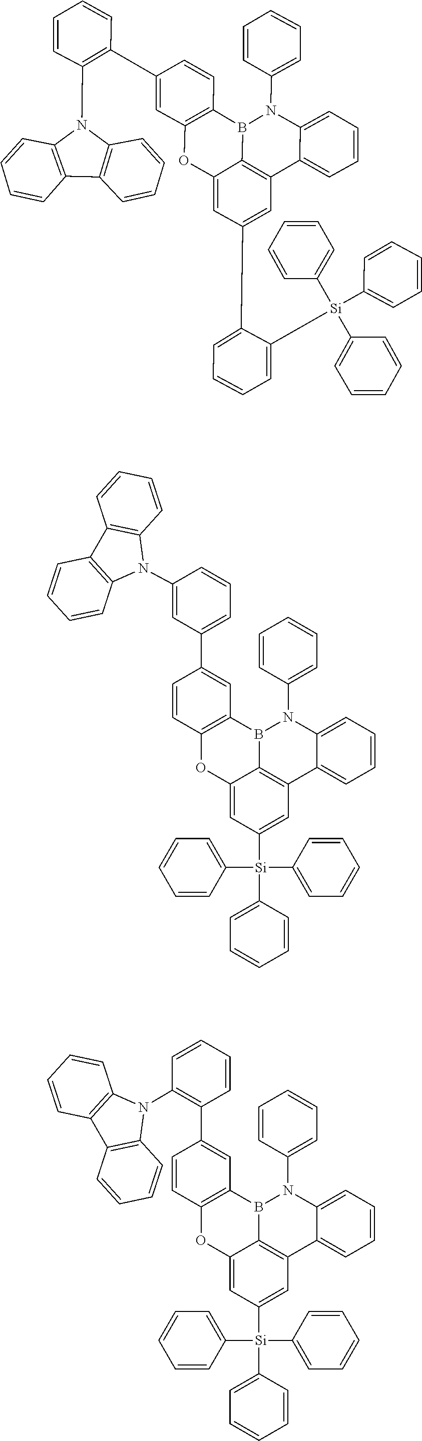 [SMILES: c1ccc(N2B3c4ccc(-c5ccccc5-n5c6ccccc6c6ccccc65)cc4Oc4cc(-c5ccccc5[Si](c5ccccc5)(c5ccccc5)c5ccccc5)cc(c43)-c3ccccc32)cc1 ; c1ccc(N2B3c4cc(-c5cccc(-n6c7ccccc7c7ccccc76)c5)ccc4Oc4cc([Si](c5ccccc5)(c5ccccc5)c5ccccc5)cc(c43)-c3ccccc32)cc1 ; c1ccc(N2B3c4cc(-c5ccccc5-n5c6ccccc6c6ccccc65)ccc4Oc4cc([Si](c5ccccc5)(c5ccccc5)c5ccccc5)cc(c43)-c3ccccc32)cc1] 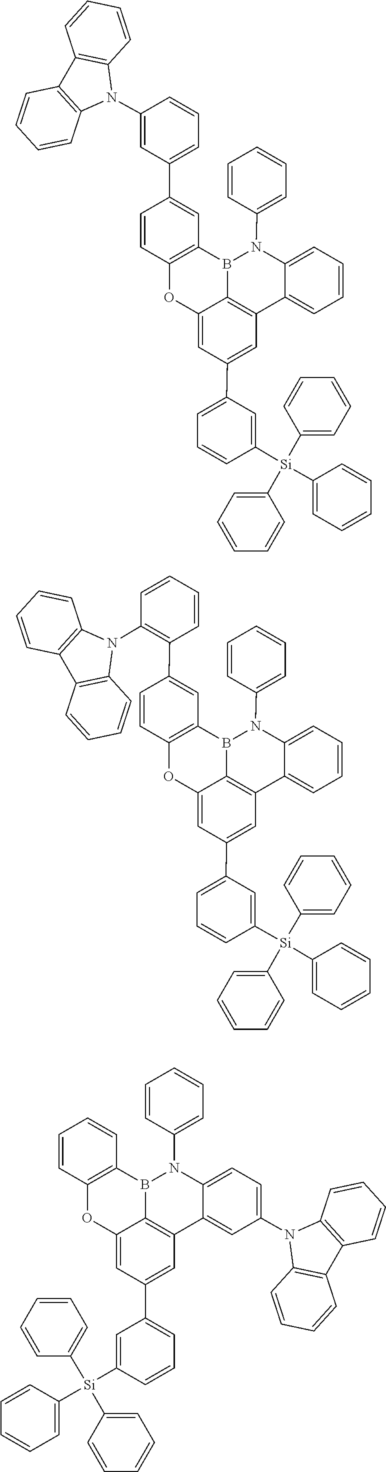 [SMILES: c1ccc(N2B3c4cc(-c5cccc(-n6c7ccccc7c7ccccc76)c5)ccc4Oc4cc(-c5cccc([Si](c6ccccc6)(c6ccccc6)c6ccccc6)c5)cc(c43)-c3ccccc32)cc1 ; c1ccc(N2B3c4cc(-c5ccccc5-n5c6ccccc6c6ccccc65)ccc4Oc4cc(-c5cccc([Si](c6ccccc6)(c6ccccc6)c6ccccc6)c5)cc(c43)-c3ccccc32)cc1 ; c1ccc(N2B3c4ccccc4Oc4cc(-c5cccc([Si](c6ccccc6)(c6ccccc6)c6ccccc6)c5)cc(c43)-c3cc(-n4c5ccccc5c5ccccc54)ccc32)cc1] 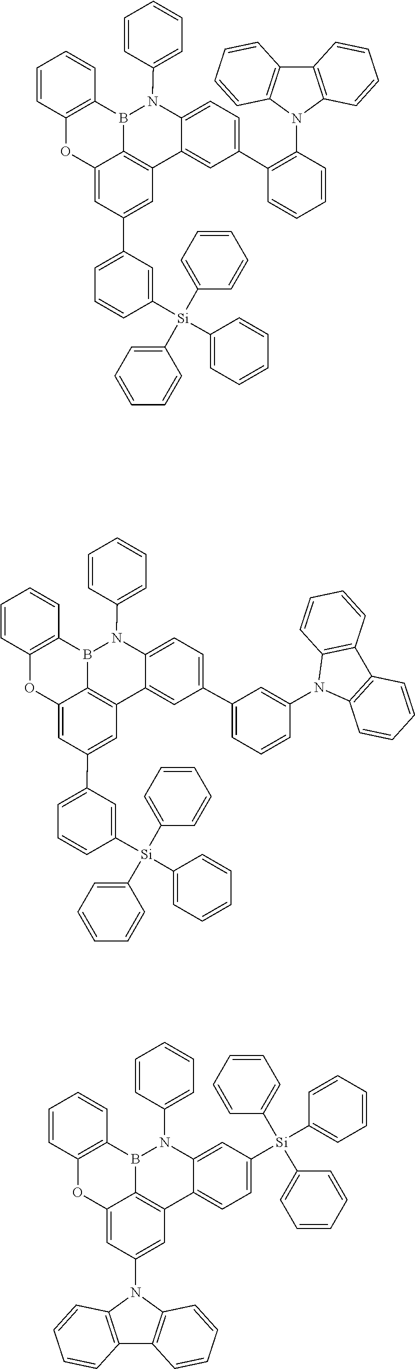 [SMILES: c1ccc(N2B3c4ccccc4Oc4cc(-c5cccc([Si](c6ccccc6)(c6ccccc6)c6ccccc6)c5)cc(c43)-c3cc(-c4ccccc4-n4c5ccccc5c5ccccc54)ccc32)cc1 ; c1ccc(N2B3c4ccccc4Oc4cc(-c5cccc([Si](c6ccccc6)(c6ccccc6)c6ccccc6)c5)cc(c43)-c3cc(-c4cccc(-n5c6ccccc6c6ccccc65)c4)ccc32)cc1 ; c1ccc(N2B3c4ccccc4Oc4cc(-n5c6ccccc6c6ccccc65)cc(c43)-c3ccc([Si](c4ccccc4)(c4ccccc4)c4ccccc4)cc32)cc1] 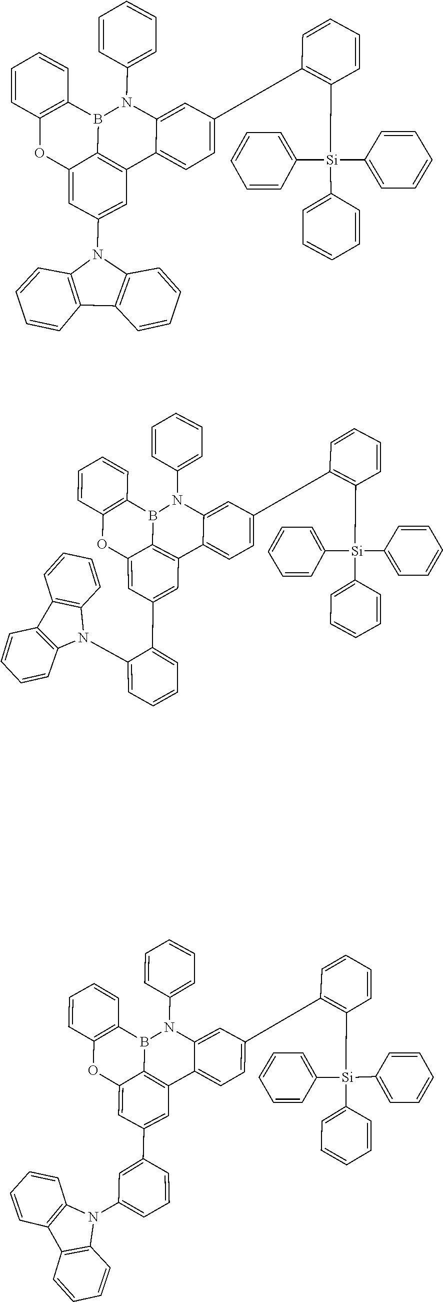 [SMILES: c1ccc(N2B3c4ccccc4Oc4cc(-n5c6ccccc6c6ccccc65)cc(c43)-c3ccc(-c4ccccc4[Si](c4ccccc4)(c4ccccc4)c4ccccc4)cc32)cc1 ; c1ccc(N2B3c4ccccc4Oc4cc(-c5ccccc5-n5c6ccccc6c6ccccc65)cc(c43)-c3ccc(-c4ccccc4[Si](c4ccccc4)(c4ccccc4)c4ccccc4)cc32)cc1 ; c1ccc(N2B3c4ccccc4Oc4cc(-c5cccc(-n6c7ccccc7c7ccccc76)c5)cc(c43)-c3ccc(-c4ccccc4[Si](c4ccccc4)(c4ccccc4)c4ccccc4)cc32)cc1] 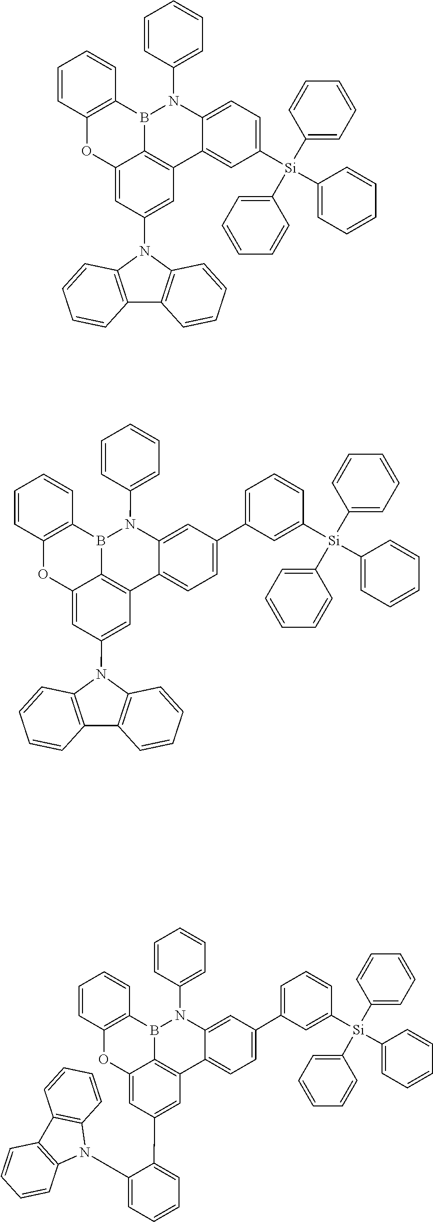 [SMILES: c1ccc(N2B3c4ccccc4Oc4cc(-n5c6ccccc6c6ccccc65)cc(c43)-c3cc([Si](c4ccccc4)(c4ccccc4)c4ccccc4)ccc32)cc1 ; c1ccc(N2B3c4ccccc4Oc4cc(-n5c6ccccc6c6ccccc65)cc(c43)-c3ccc(-c4cccc([Si](c5ccccc5)(c5ccccc5)c5ccccc5)c4)cc32)cc1 ; c1ccc(N2B3c4ccccc4Oc4cc(-c5ccccc5-n5c6ccccc6c6ccccc65)cc(c43)-c3ccc(-c4cccc([Si](c5ccccc5)(c5ccccc5)c5ccccc5)c4)cc32)cc1] 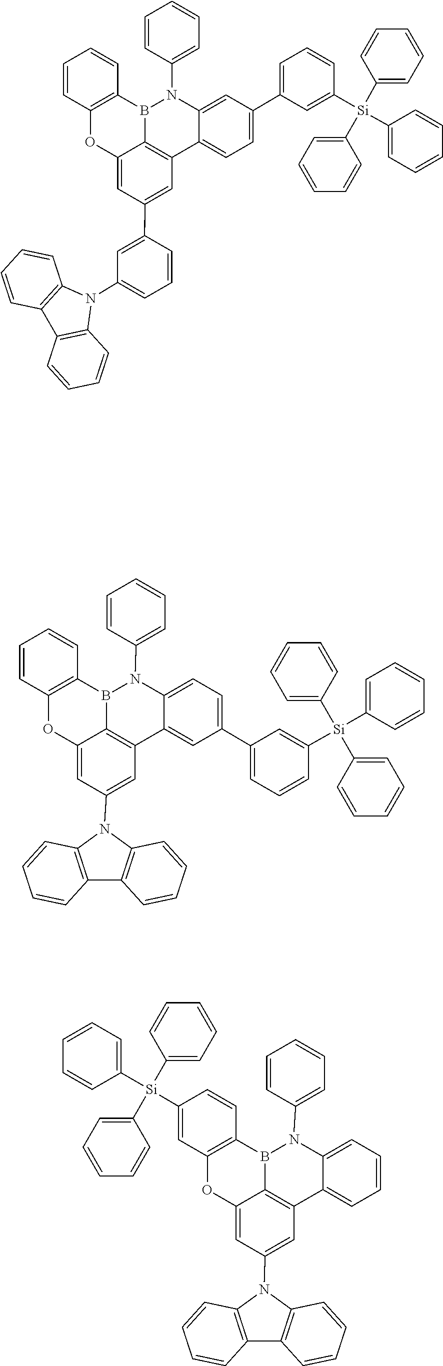 [SMILES: c1ccc(N2B3c4ccccc4Oc4cc(-c5cccc(-n6c7ccccc7c7ccccc76)c5)cc(c43)-c3ccc(-c4cccc([Si](c5ccccc5)(c5ccccc5)c5ccccc5)c4)cc32)cc1 ; c1ccc(N2B3c4ccccc4Oc4cc(-n5c6ccccc6c6ccccc65)cc(c43)-c3cc(-c4cccc([Si](c5ccccc5)(c5ccccc5)c5ccccc5)c4)ccc32)cc1 ; c1ccc(N2B3c4ccc([Si](c5ccccc5)(c5ccccc5)c5ccccc5)cc4Oc4cc(-n5c6ccccc6c6ccccc65)cc(c43)-c3ccccc32)cc1] 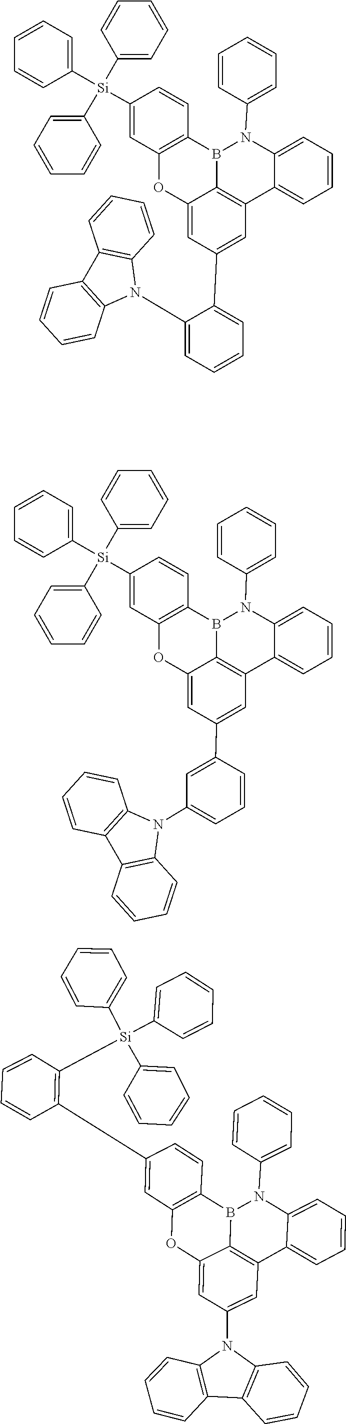 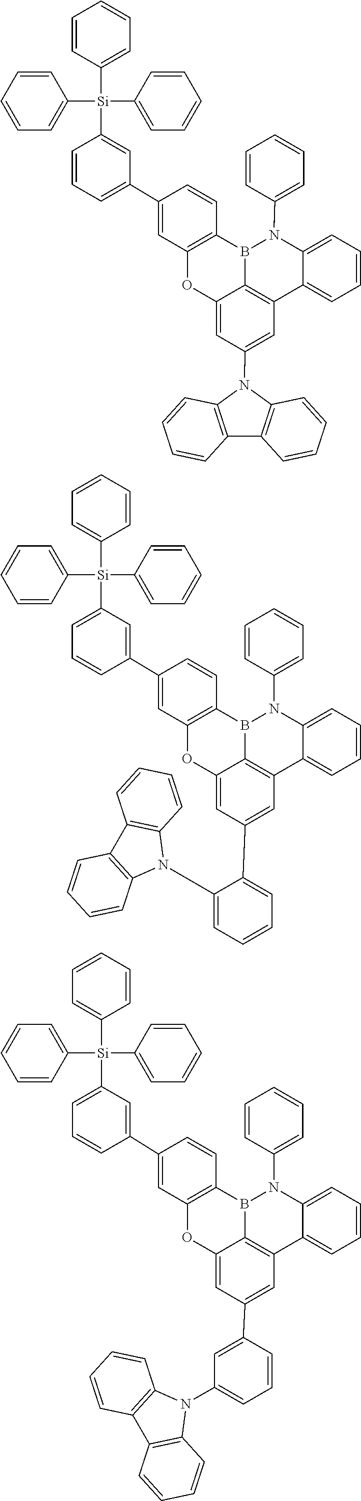 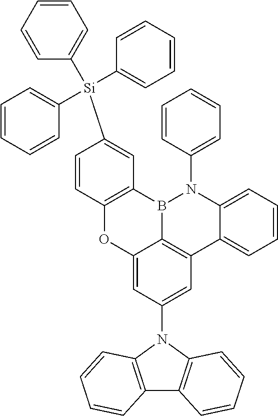 [SMILES: c1ccc(N2B3c4cc([Si](c5ccccc5)(c5ccccc5)c5ccccc5)ccc4Oc4cc(-n5c6ccccc6c6ccccc65)cc(c43)-c3ccccc32)cc1] 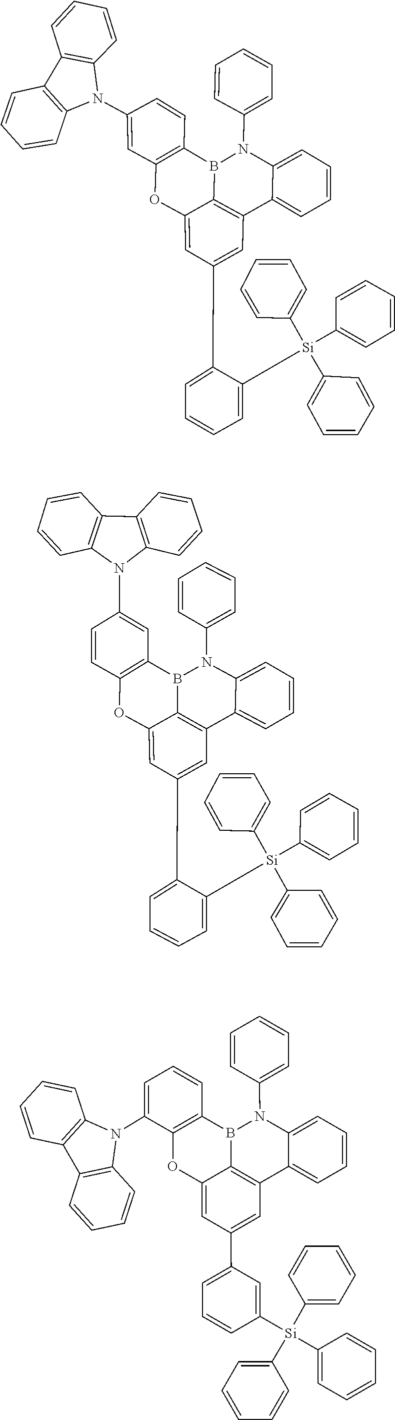 [SMILES: c1ccc(N2B3c4ccc(-n5c6ccccc6c6ccccc65)cc4Oc4cc(-c5ccccc5[Si](c5ccccc5)(c5ccccc5)c5ccccc5)cc(c43)-c3ccccc32)cc1 ; c1ccc(N2B3c4cc(-n5c6ccccc6c6ccccc65)ccc4Oc4cc(-c5ccccc5[Si](c5ccccc5)(c5ccccc5)c5ccccc5)cc(c43)-c3ccccc32)cc1 ; c1ccc(N2B3c4cccc(-n5c6ccccc6c6ccccc65)c4Oc4cc(-c5cccc([Si](c6ccccc6)(c6ccccc6)c6ccccc6)c5)cc(c43)-c3ccccc32)cc1] 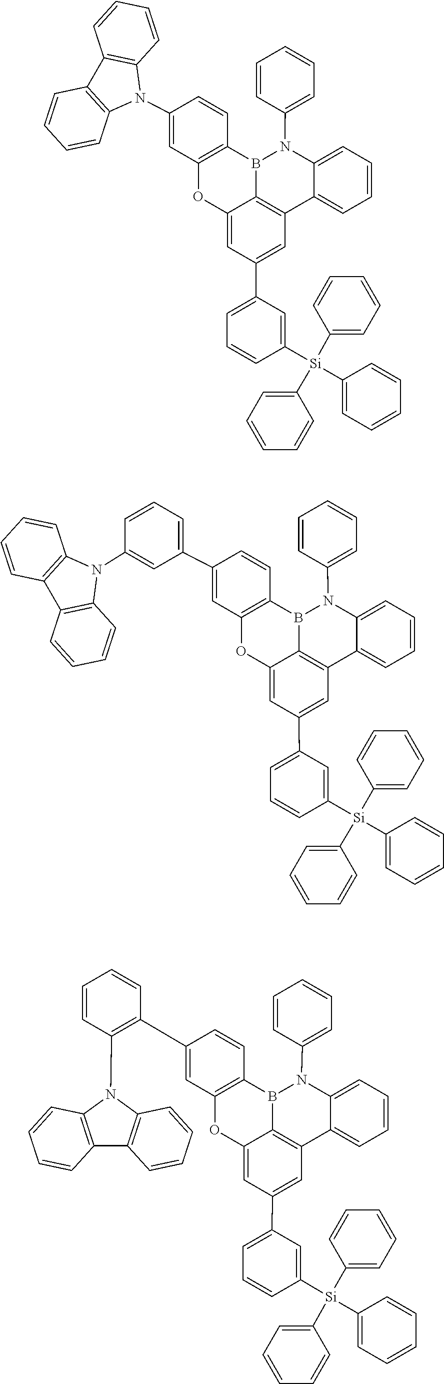 [SMILES: c1ccc(N2B3c4ccc(-n5c6ccccc6c6ccccc65)cc4Oc4cc(-c5cccc([Si](c6ccccc6)(c6ccccc6)c6ccccc6)c5)cc(c43)-c3ccccc32)cc1 ; c1ccc(N2B3c4ccc(-c5cccc(-n6c7ccccc7c7ccccc76)c5)cc4Oc4cc(-c5cccc([Si](c6ccccc6)(c6ccccc6)c6ccccc6)c5)cc(c43)-c3ccccc32)cc1 ; c1ccc(N2B3c4ccc(-c5ccccc5-n5c6ccccc6c6ccccc65)cc4Oc4cc(-c5cccc([Si](c6ccccc6)(c6ccccc6)c6ccccc6)c5)cc(c43)-c3ccccc32)cc1] 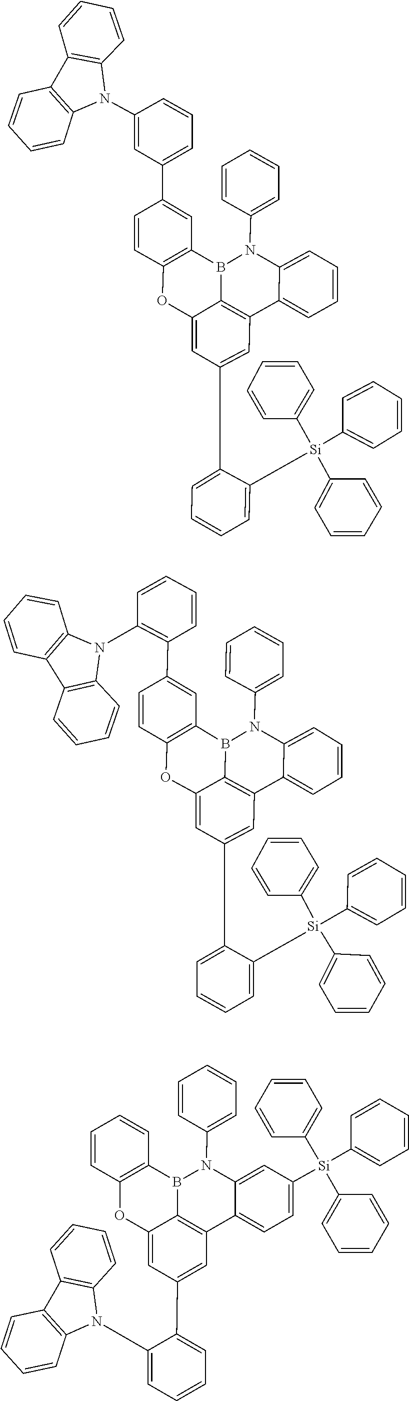 [SMILES: c1ccc(N2B3c4cc(-c5cccc(-n6c7ccccc7c7ccccc76)c5)ccc4Oc4cc(-c5ccccc5[Si](c5ccccc5)(c5ccccc5)c5ccccc5)cc(c43)-c3ccccc32)cc1 ; c1ccc(N2B3c4cc(-c5ccccc5-n5c6ccccc6c6ccccc65)ccc4Oc4cc(-c5ccccc5[Si](c5ccccc5)(c5ccccc5)c5ccccc5)cc(c43)-c3ccccc32)cc1 ; c1ccc(N2B3c4ccccc4Oc4cc(-c5ccccc5-n5c6ccccc6c6ccccc65)cc(c43)-c3ccc([Si](c4ccccc4)(c4ccccc4)c4ccccc4)cc32)cc1] 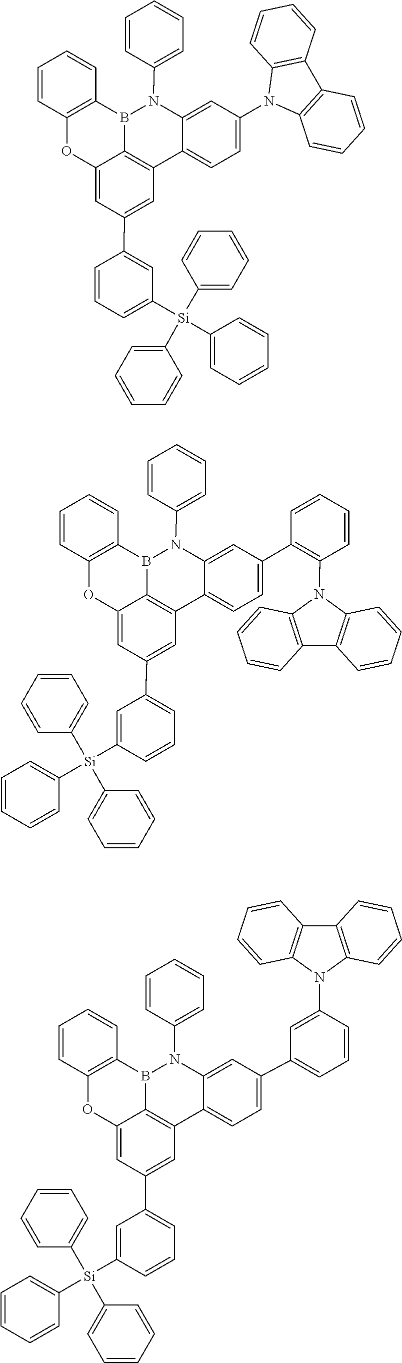 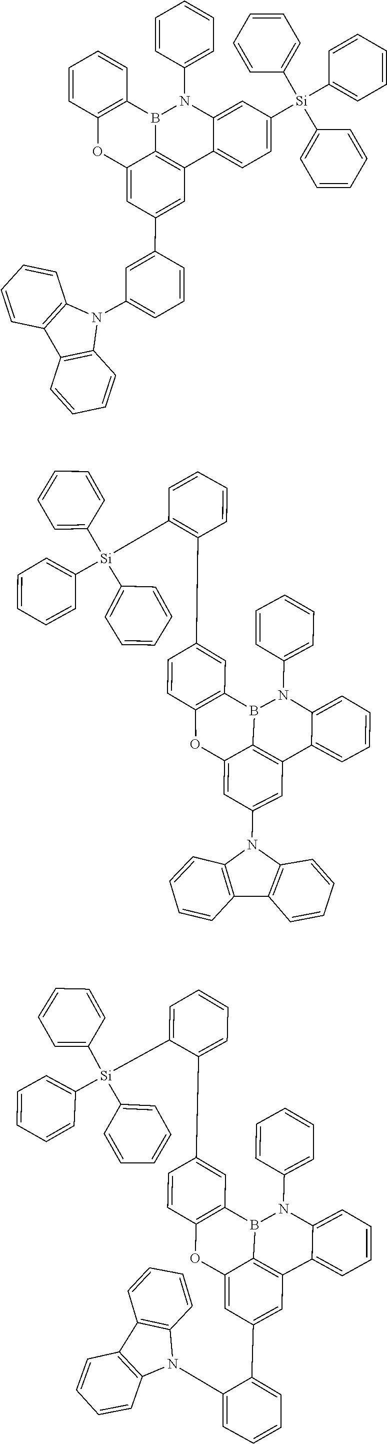 [SMILES: c1ccc(N2B3c4ccccc4Oc4cc(-c5cccc(-n6c7ccccc7c7ccccc76)c5)cc(c43)-c3ccc([Si](c4ccccc4)(c4ccccc4)c4ccccc4)cc32)cc1 ; c1ccc(N2B3c4cc(-c5ccccc5[Si](c5ccccc5)(c5ccccc5)c5ccccc5)ccc4Oc4cc(-n5c6ccccc6c6ccccc65)cc(c43)-c3ccccc32)cc1 ; c1ccc(N2B3c4cc(-c5ccccc5[Si](c5ccccc5)(c5ccccc5)c5ccccc5)ccc4Oc4cc(-c5ccccc5-n5c6ccccc6c6ccccc65)cc(c43)-c3ccccc32)cc1] 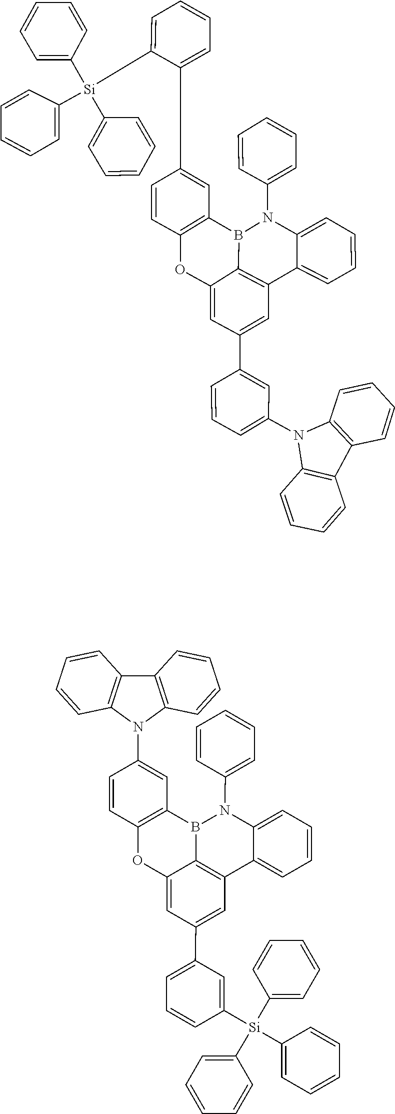 [SMILES: c1ccc(N2B3c4cc(-c5ccccc5[Si](c5ccccc5)(c5ccccc5)c5ccccc5)ccc4Oc4cc(-c5cccc(-n6c7ccccc7c7ccccc76)c5)cc(c43)-c3ccccc32)cc1 ; c1ccc(N2B3c4cc(-n5c6ccccc6c6ccccc65)ccc4Oc4cc(-c5cccc([Si](c6ccccc6)(c6ccccc6)c6ccccc6)c5)cc(c43)-c3ccccc32)cc1] 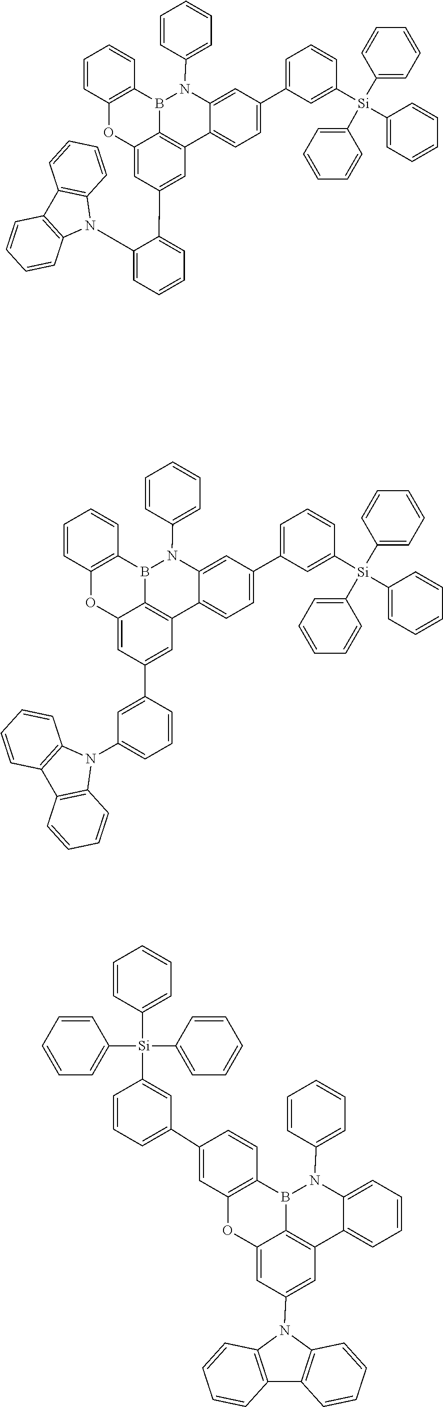 [SMILES: c1ccc(N2B3c4ccccc4Oc4cc(-c5ccccc5-n5c6ccccc6c6ccccc65)cc(c43)-c3ccc(-c4cccc([Si](c5ccccc5)(c5ccccc5)c5ccccc5)c4)cc32)cc1 ; c1ccc(N2B3c4ccccc4Oc4cc(-c5cccc(-n6c7ccccc7c7ccccc76)c5)cc(c43)-c3ccc(-c4cccc([Si](c5ccccc5)(c5ccccc5)c5ccccc5)c4)cc32)cc1 ; c1ccc(N2B3c4ccc(-c5cccc([Si](c6ccccc6)(c6ccccc6)c6ccccc6)c5)cc4Oc4cc(-n5c6ccccc6c6ccccc65)cc(c43)-c3ccccc32)cc1] 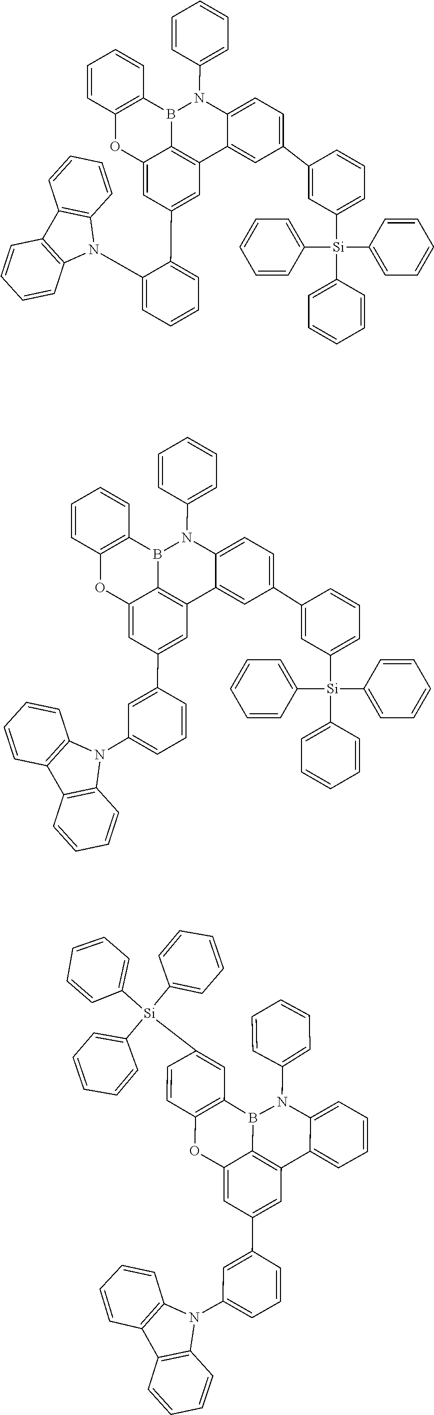 [SMILES: c1ccc(N2B3c4ccccc4Oc4cc(-c5ccccc5-n5c6ccccc6c6ccccc65)cc(c43)-c3cc(-c4cccc([Si](c5ccccc5)(c5ccccc5)c5ccccc5)c4)ccc32)cc1 ; c1ccc(N2B3c4ccccc4Oc4cc(-c5cccc(-n6c7ccccc7c7ccccc76)c5)cc(c43)-c3cc(-c4cccc([Si](c5ccccc5)(c5ccccc5)c5ccccc5)c4)ccc32)cc1 ; c1ccc(N2B3c4cc([Si](c5ccccc5)(c5ccccc5)c5ccccc5)ccc4Oc4cc(-c5cccc(-n6c7ccccc7c7ccccc76)c5)cc(c43)-c3ccccc32)cc1] 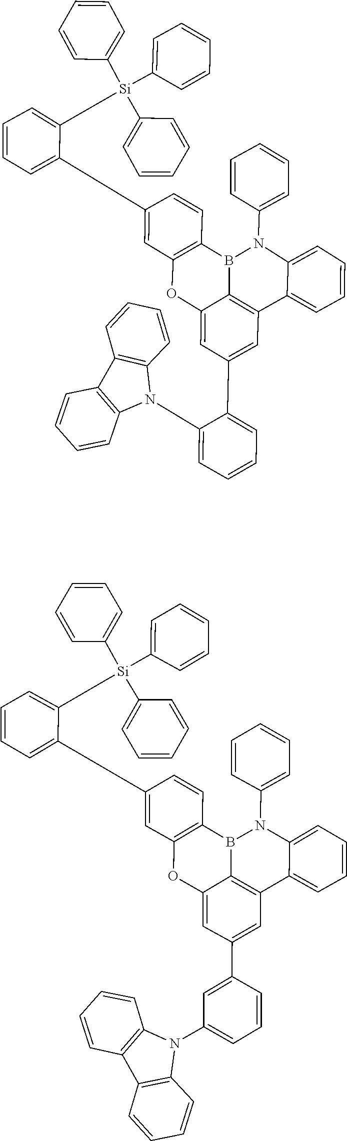 [SMILES: c1ccc(N2B3c4ccc(-c5ccccc5[Si](c5ccccc5)(c5ccccc5)c5ccccc5)cc4Oc4cc(-c5ccccc5-n5c6ccccc6c6ccccc65)cc(c43)-c3ccccc32)cc1 ; c1ccc(N2B3c4ccc(-c5ccccc5[Si](c5ccccc5)(c5ccccc5)c5ccccc5)cc4Oc4cc(-c5cccc(-n6c7ccccc7c7ccccc76)c5)cc(c43)-c3ccccc32)cc1] 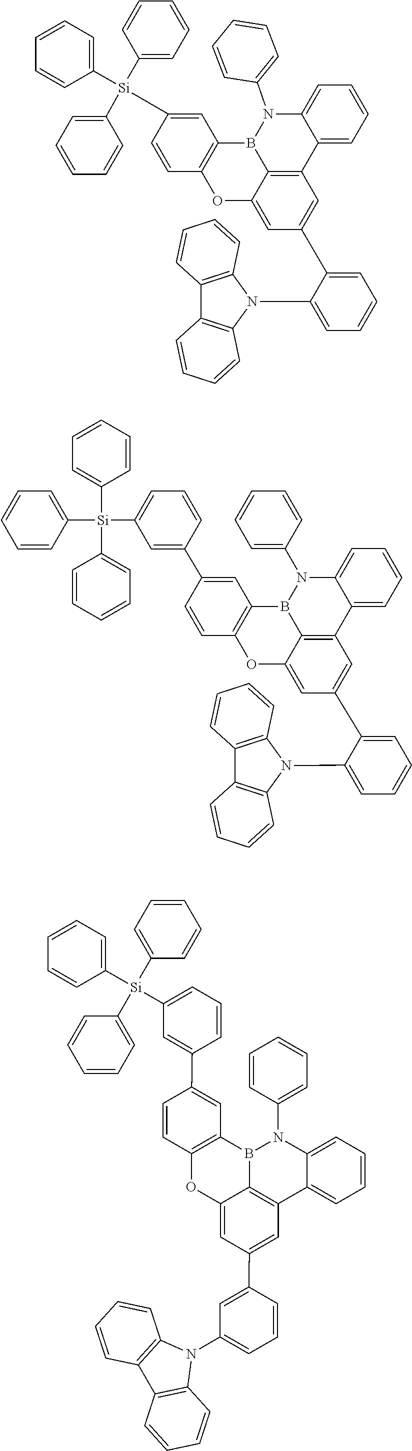 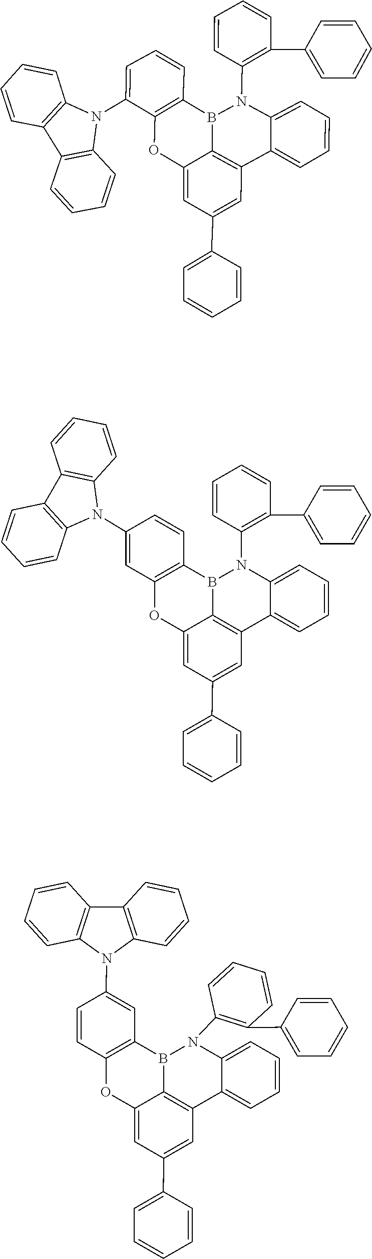 [SMILES: c1ccc(-c2cc3c4c(c2)-c2ccccc2N(c2ccccc2-c2ccccc2)B4c2cccc(-n4c5ccccc5c5ccccc54)c2O3)cc1 ; c1ccc(-c2cc3c4c(c2)-c2ccccc2N(c2ccccc2-c2ccccc2)B4c2ccc(-n4c5ccccc5c5ccccc54)cc2O3)cc1 ; c1ccc(-c2cc3c4c(c2)-c2ccccc2N(c2ccccc2-c2ccccc2)B4c2cc(-n4c5ccccc5c5ccccc54)ccc2O3)cc1] 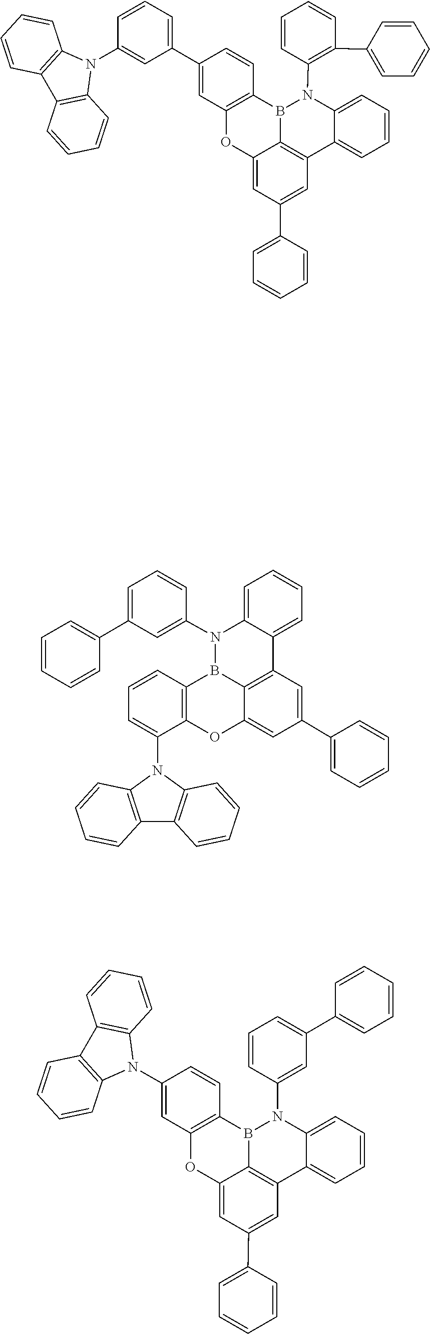 [SMILES: c1ccc(-c2cc3c4c(c2)-c2ccccc2N(c2ccccc2-c2ccccc2)B4c2ccc(-c4cccc(-n5c6ccccc6c6ccccc65)c4)cc2O3)cc1 ; c1ccc(-c2cccc(N3B4c5cccc(-n6c7ccccc7c7ccccc76)c5Oc5cc(-c6ccccc6)cc(c54)-c4ccccc43)c2)cc1 ; c1ccc(-c2cccc(N3B4c5ccc(-n6c7ccccc7c7ccccc76)cc5Oc5cc(-c6ccccc6)cc(c54)-c4ccccc43)c2)cc1] 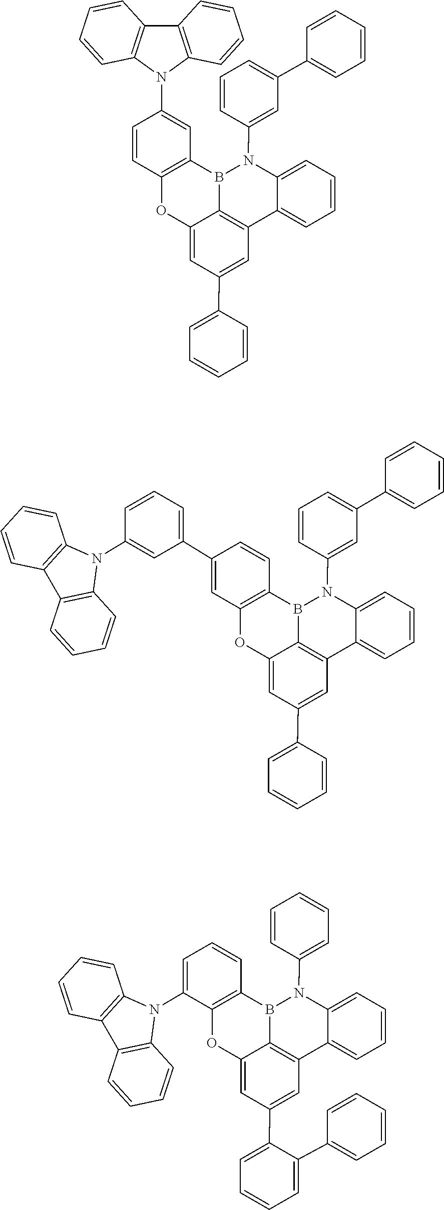 [SMILES: c1ccc(-c2cccc(N3B4c5cc(-n6c7ccccc7c7ccccc76)ccc5Oc5cc(-c6ccccc6)cc(c54)-c4ccccc43)c2)cc1 ; c1ccc(-c2cccc(N3B4c5ccc(-c6cccc(-n7c8ccccc8c8ccccc87)c6)cc5Oc5cc(-c6ccccc6)cc(c54)-c4ccccc43)c2)cc1 ; c1ccc(-c2ccccc2-c2cc3c4c(c2)-c2ccccc2N(c2ccccc2)B4c2cccc(-n4c5ccccc5c5ccccc54)c2O3)cc1] 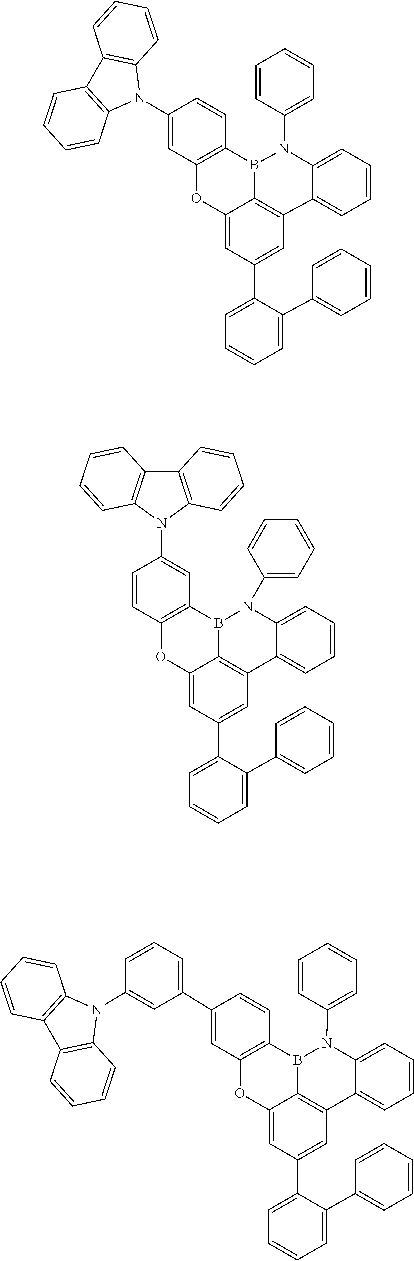 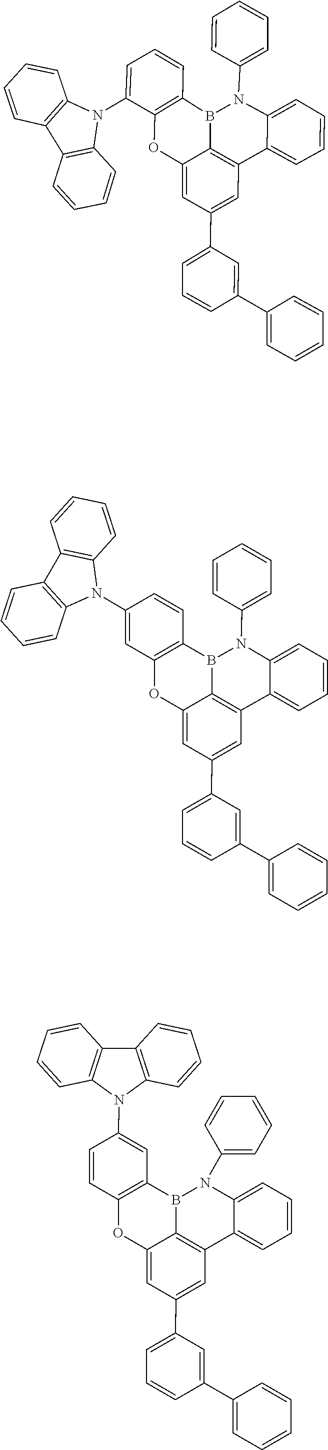 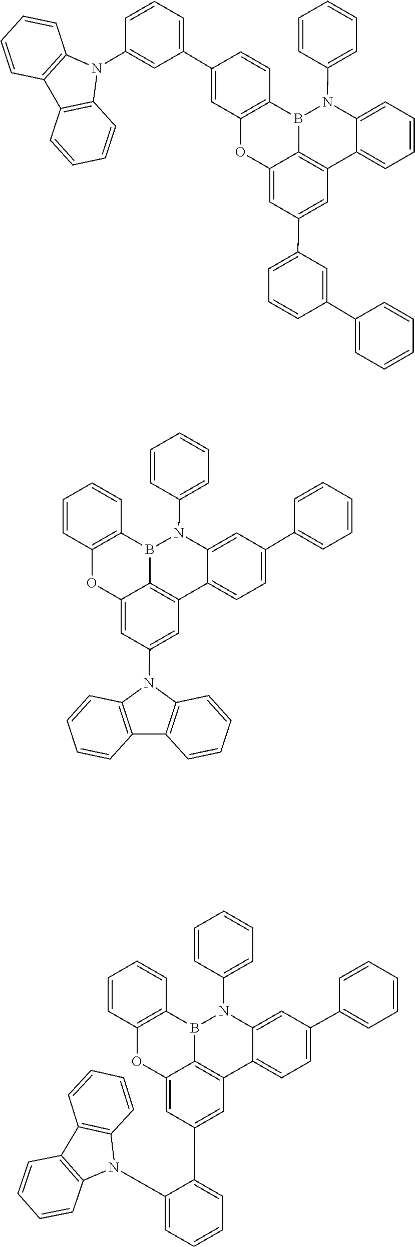 [SMILES: c1ccc(-c2cccc(-c3cc4c5c(c3)-c3ccccc3N(c3ccccc3)B5c3ccc(-c5cccc(-n6c7ccccc7c7ccccc76)c5)cc3O4)c2)cc1 ; c1ccc(-c2ccc3c(c2)N(c2ccccc2)B2c4ccccc4Oc4cc(-n5c6ccccc6c6ccccc65)cc-3c42)cc1 ; c1ccc(-c2ccc3c(c2)N(c2ccccc2)B2c4ccccc4Oc4cc(-c5ccccc5-n5c6ccccc6c6ccccc65)cc-3c42)cc1] 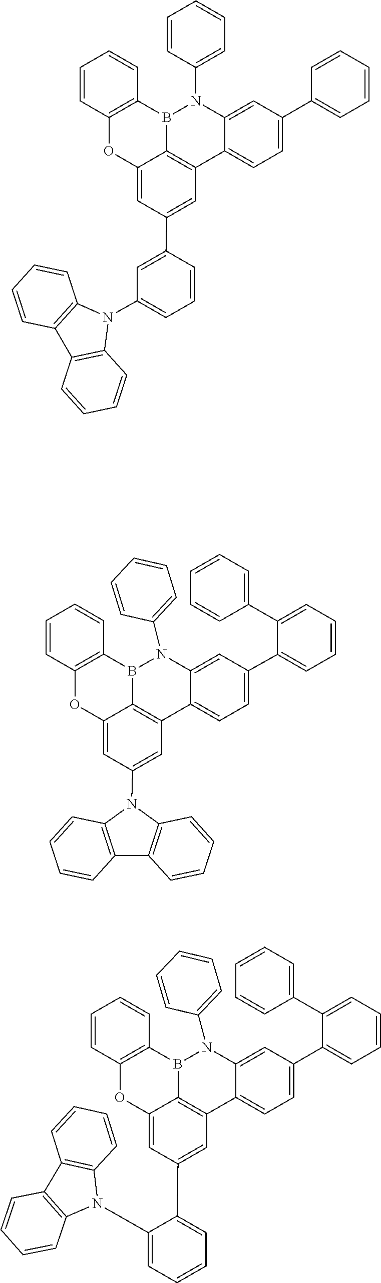 [SMILES: c1ccc(-c2ccc3c(c2)N(c2ccccc2)B2c4ccccc4Oc4cc(-c5cccc(-n6c7ccccc7c7ccccc76)c5)cc-3c42)cc1 ; c1ccc(-c2ccccc2-c2ccc3c(c2)N(c2ccccc2)B2c4ccccc4Oc4cc(-n5c6ccccc6c6ccccc65)cc-3c42)cc1 ; c1ccc(-c2ccccc2-c2ccc3c(c2)N(c2ccccc2)B2c4ccccc4Oc4cc(-c5ccccc5-n5c6ccccc6c6ccccc65)cc-3c42)cc1] 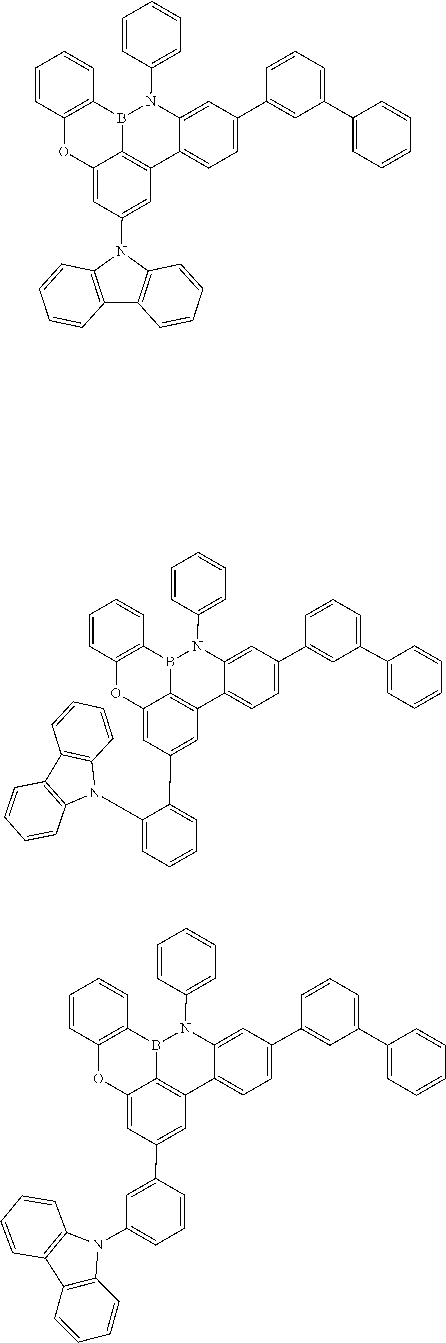 [SMILES: c1ccc(-c2cccc(-c3ccc4c(c3)N(c3ccccc3)B3c5ccccc5Oc5cc(-n6c7ccccc7c7ccccc76)cc-4c53)c2)cc1 ; c1ccc(-c2cccc(-c3ccc4c(c3)N(c3ccccc3)B3c5ccccc5Oc5cc(-c6ccccc6-n6c7ccccc7c7ccccc76)cc-4c53)c2)cc1 ; c1ccc(-c2cccc(-c3ccc4c(c3)N(c3ccccc3)B3c5ccccc5Oc5cc(-c6cccc(-n7c8ccccc8c8ccccc87)c6)cc-4c53)c2)cc1] 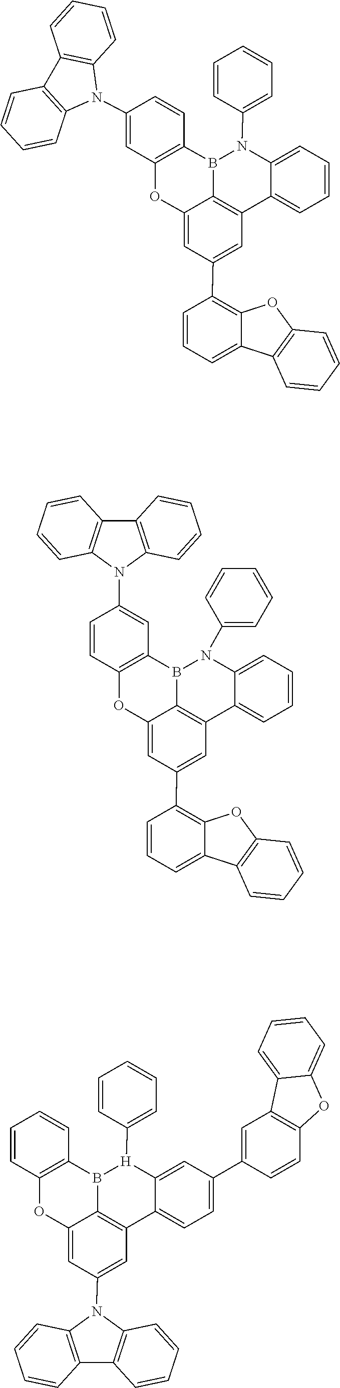 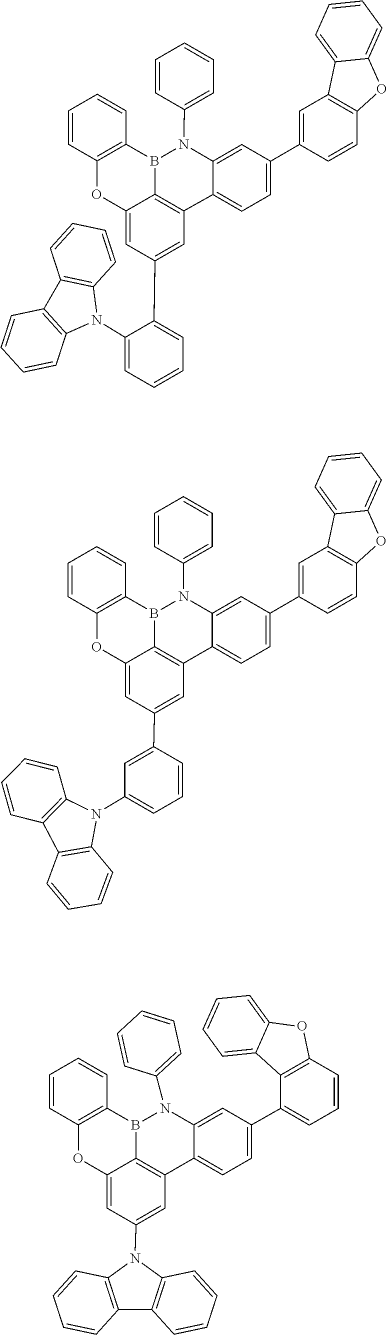 [SMILES: c1ccc(N2B3c4ccccc4Oc4cc(-c5ccccc5-n5c6ccccc6c6ccccc65)cc(c43)-c3ccc(-c4ccc5oc6ccccc6c5c4)cc32)cc1 ; c1ccc(N2B3c4ccccc4Oc4cc(-c5cccc(-n6c7ccccc7c7ccccc76)c5)cc(c43)-c3ccc(-c4ccc5oc6ccccc6c5c4)cc32)cc1 ; c1ccc(N2B3c4ccccc4Oc4cc(-n5c6ccccc6c6ccccc65)cc(c43)-c3ccc(-c4cccc5oc6ccccc6c45)cc32)cc1] 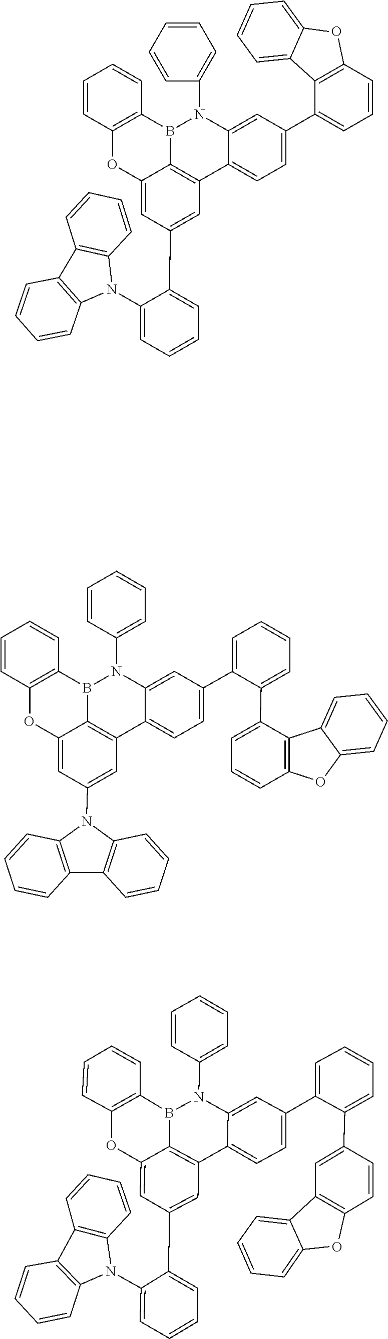 [SMILES: c1ccc(N2B3c4ccccc4Oc4cc(-c5ccccc5-n5c6ccccc6c6ccccc65)cc(c43)-c3ccc(-c4cccc5oc6ccccc6c45)cc32)cc1 ; c1ccc(N2B3c4ccccc4Oc4cc(-n5c6ccccc6c6ccccc65)cc(c43)-c3ccc(-c4ccccc4-c4cccc5oc6ccccc6c45)cc32)cc1 ; c1ccc(N2B3c4ccccc4Oc4cc(-c5ccccc5-n5c6ccccc6c6ccccc65)cc(c43)-c3ccc(-c4ccccc4-c4ccc5oc6ccccc6c5c4)cc32)cc1] 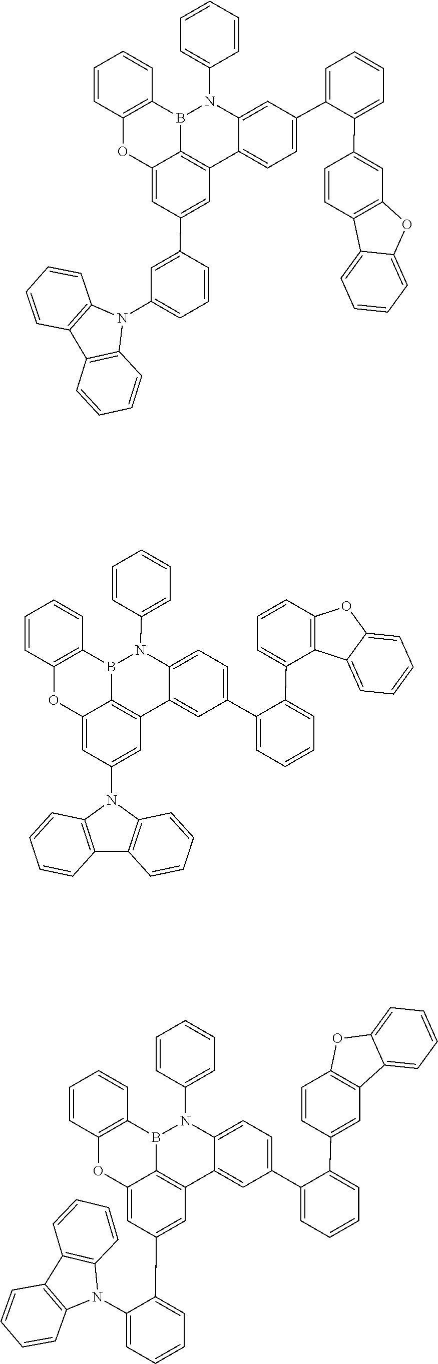 [SMILES: c1ccc(N2B3c4ccccc4Oc4cc(-c5cccc(-n6c7ccccc7c7ccccc76)c5)cc(c43)-c3ccc(-c4ccccc4-c4ccc5c(c4)oc4ccccc45)cc32)cc1 ; c1ccc(N2B3c4ccccc4Oc4cc(-n5c6ccccc6c6ccccc65)cc(c43)-c3cc(-c4ccccc4-c4cccc5oc6ccccc6c45)ccc32)cc1 ; c1ccc(N2B3c4ccccc4Oc4cc(-c5ccccc5-n5c6ccccc6c6ccccc65)cc(c43)-c3cc(-c4ccccc4-c4ccc5oc6ccccc6c5c4)ccc32)cc1] 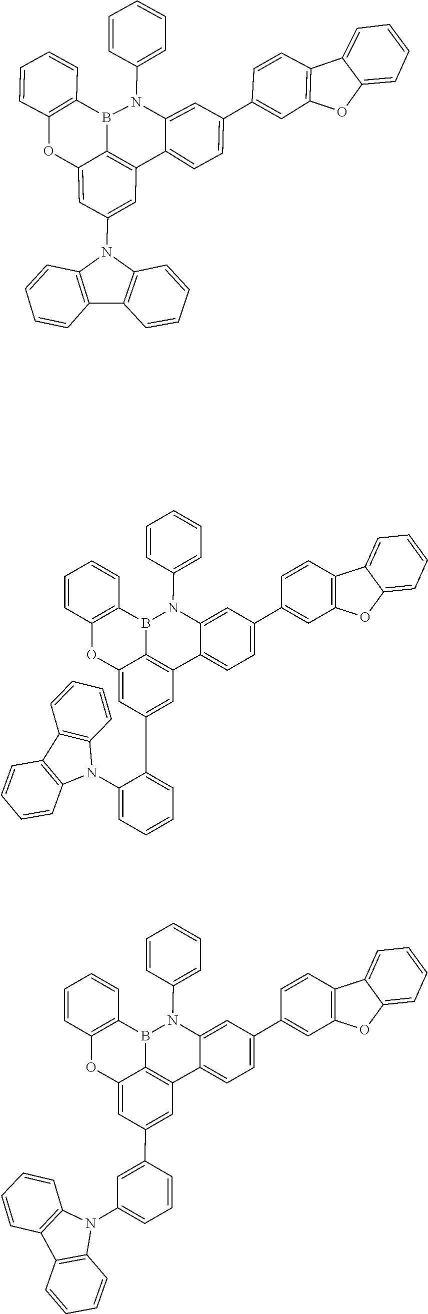 [SMILES: c1ccc(N2B3c4ccccc4Oc4cc(-n5c6ccccc6c6ccccc65)cc(c43)-c3ccc(-c4ccc5c(c4)oc4ccccc45)cc32)cc1 ; c1ccc(N2B3c4ccccc4Oc4cc(-c5ccccc5-n5c6ccccc6c6ccccc65)cc(c43)-c3ccc(-c4ccc5c(c4)oc4ccccc45)cc32)cc1 ; c1ccc(N2B3c4ccccc4Oc4cc(-c5cccc(-n6c7ccccc7c7ccccc76)c5)cc(c43)-c3ccc(-c4ccc5c(c4)oc4ccccc45)cc32)cc1] 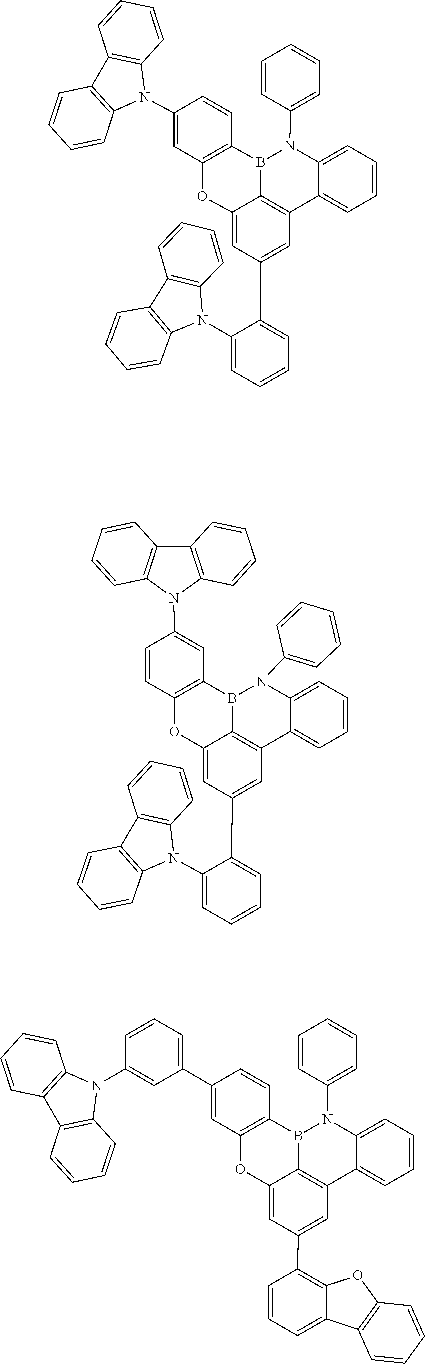 [SMILES: c1ccc(N2B3c4ccc(-n5c6ccccc6c6ccccc65)cc4Oc4cc(-c5ccccc5-n5c6ccccc6c6ccccc65)cc(c43)-c3ccccc32)cc1 ; c1ccc(N2B3c4cc(-n5c6ccccc6c6ccccc65)ccc4Oc4cc(-c5ccccc5-n5c6ccccc6c6ccccc65)cc(c43)-c3ccccc32)cc1 ; c1ccc(N2B3c4ccc(-c5cccc(-n6c7ccccc7c7ccccc76)c5)cc4Oc4cc(-c5cccc6c5oc5ccccc56)cc(c43)-c3ccccc32)cc1] 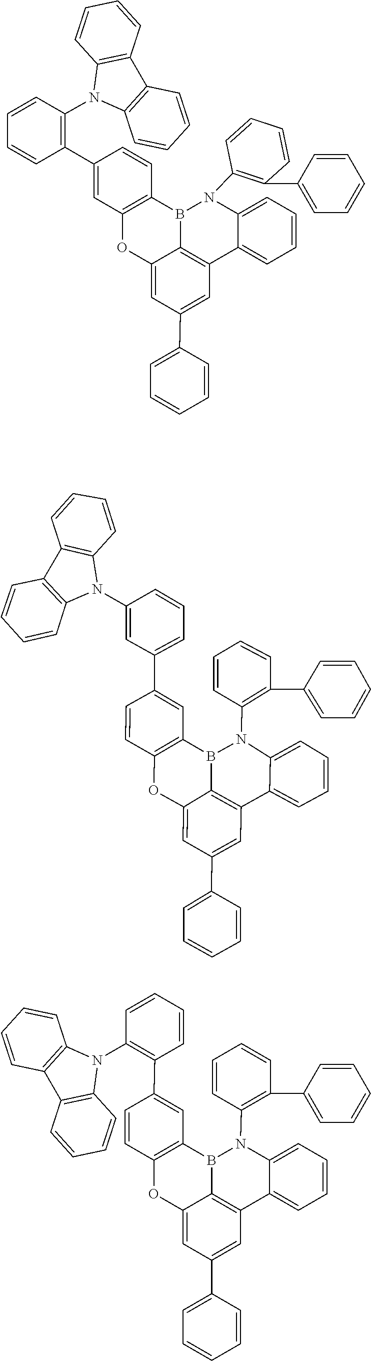 [SMILES: c1ccc(-c2cc3c4c(c2)-c2ccccc2N(c2ccccc2-c2ccccc2)B4c2ccc(-c4ccccc4-n4c5ccccc5c5ccccc54)cc2O3)cc1 ; c1ccc(-c2cc3c4c(c2)-c2ccccc2N(c2ccccc2-c2ccccc2)B4c2cc(-c4cccc(-n5c6ccccc6c6ccccc65)c4)ccc2O3)cc1 ; c1ccc(-c2cc3c4c(c2)-c2ccccc2N(c2ccccc2-c2ccccc2)B4c2cc(-c4ccccc4-n4c5ccccc5c5ccccc54)ccc2O3)cc1] 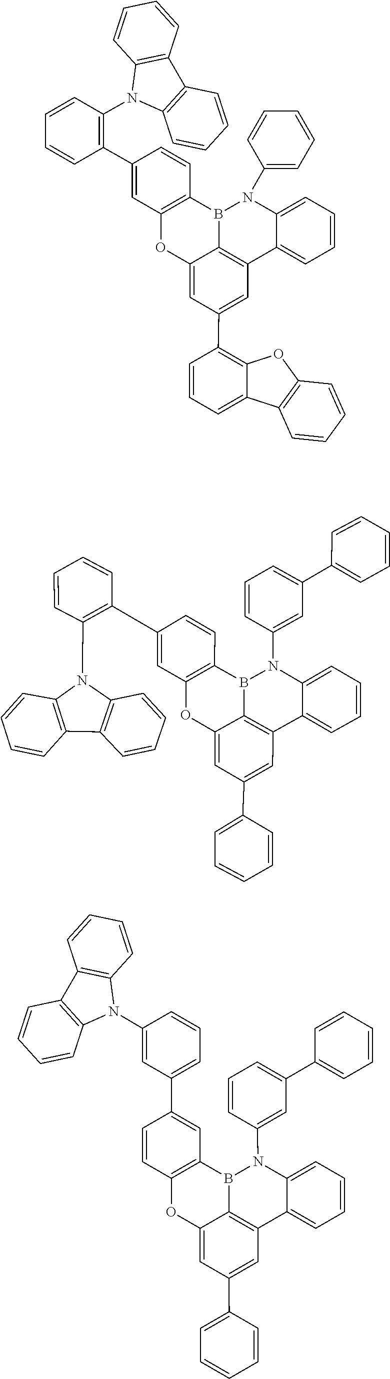 [SMILES: c1ccc(N2B3c4ccc(-c5ccccc5-n5c6ccccc6c6ccccc65)cc4Oc4cc(-c5cccc6c5oc5ccccc56)cc(c43)-c3ccccc32)cc1 ; c1ccc(-c2cccc(N3B4c5ccc(-c6ccccc6-n6c7ccccc7c7ccccc76)cc5Oc5cc(-c6ccccc6)cc(c54)-c4ccccc43)c2)cc1 ; c1ccc(-c2cccc(N3B4c5cc(-c6cccc(-n7c8ccccc8c8ccccc87)c6)ccc5Oc5cc(-c6ccccc6)cc(c54)-c4ccccc43)c2)cc1] 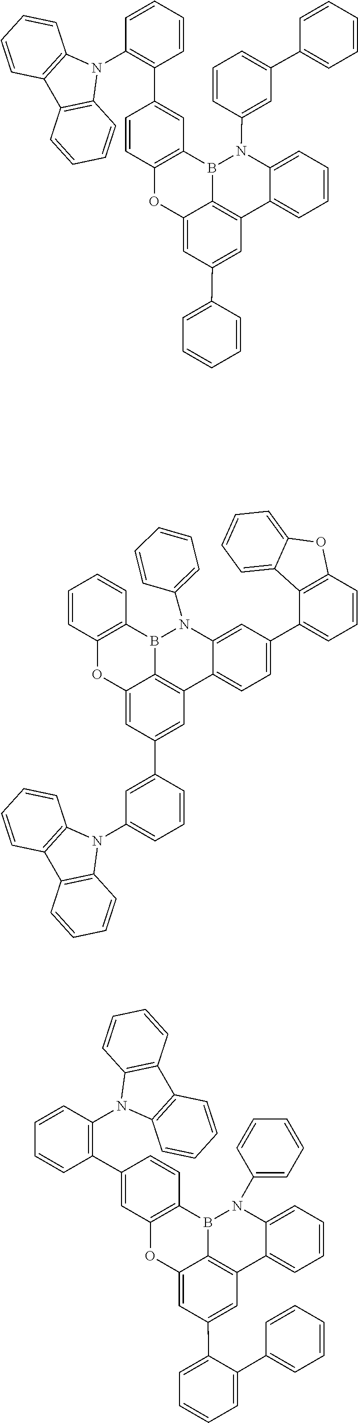 [SMILES: c1ccc(-c2cccc(N3B4c5cc(-c6ccccc6-n6c7ccccc7c7ccccc76)ccc5Oc5cc(-c6ccccc6)cc(c54)-c4ccccc43)c2)cc1 ; c1ccc(N2B3c4ccccc4Oc4cc(-c5cccc(-n6c7ccccc7c7ccccc76)c5)cc(c43)-c3ccc(-c4cccc5oc6ccccc6c45)cc32)cc1 ; c1ccc(-c2ccccc2-c2cc3c4c(c2)-c2ccccc2N(c2ccccc2)B4c2ccc(-c4ccccc4-n4c5ccccc5c5ccccc54)cc2O3)cc1] 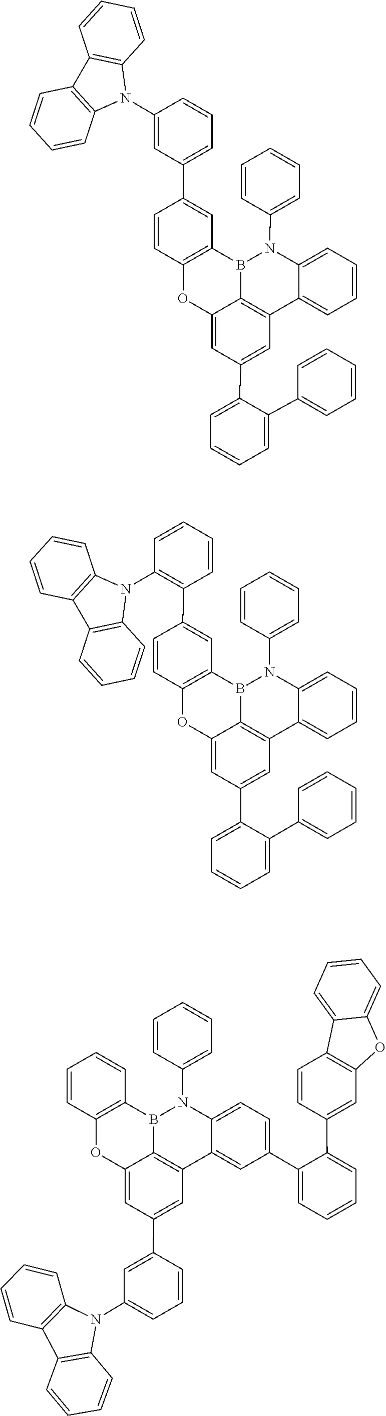 [SMILES: c1ccc(-c2ccccc2-c2cc3c4c(c2)-c2ccccc2N(c2ccccc2)B4c2cc(-c4cccc(-n5c6ccccc6c6ccccc65)c4)ccc2O3)cc1 ; c1ccc(-c2ccccc2-c2cc3c4c(c2)-c2ccccc2N(c2ccccc2)B4c2cc(-c4ccccc4-n4c5ccccc5c5ccccc54)ccc2O3)cc1 ; c1ccc(N2B3c4ccccc4Oc4cc(-c5cccc(-n6c7ccccc7c7ccccc76)c5)cc(c43)-c3cc(-c4ccccc4-c4ccc5c(c4)oc4ccccc45)ccc32)cc1] 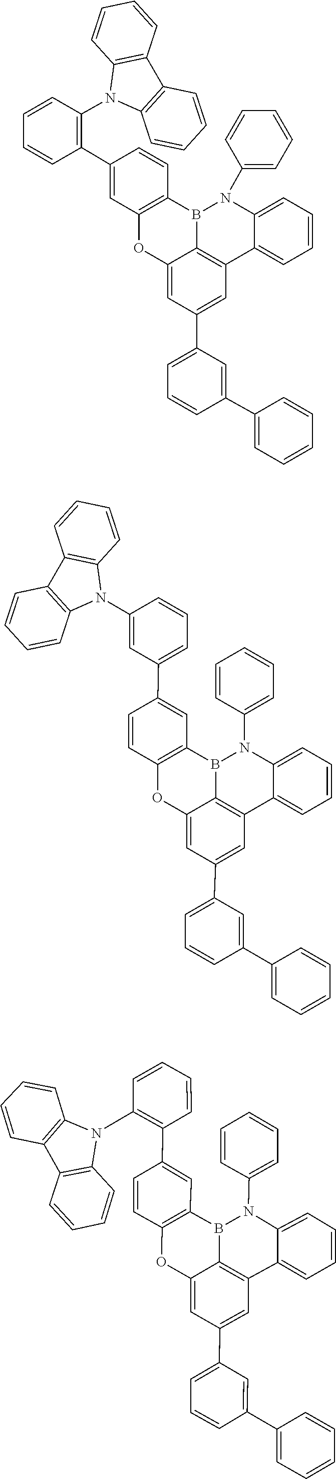 [SMILES: c1ccc(-c2cccc(-c3cc4c5c(c3)-c3ccccc3N(c3ccccc3)B5c3ccc(-c5ccccc5-n5c6ccccc6c6ccccc65)cc3O4)c2)cc1 ; c1ccc(-c2cccc(-c3cc4c5c(c3)-c3ccccc3N(c3ccccc3)B5c3cc(-c5cccc(-n6c7ccccc7c7ccccc76)c5)ccc3O4)c2)cc1 ; c1ccc(-c2cccc(-c3cc4c5c(c3)-c3ccccc3N(c3ccccc3)B5c3cc(-c5ccccc5-n5c6ccccc6c6ccccc65)ccc3O4)c2)cc1] 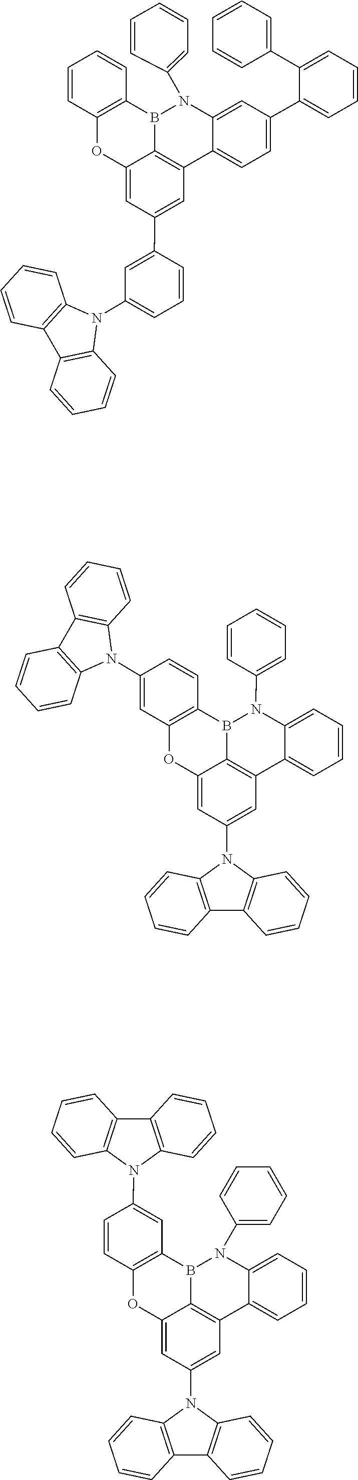 [SMILES: c1ccc(-c2ccccc2-c2ccc3c(c2)N(c2ccccc2)B2c4ccccc4Oc4cc(-c5cccc(-n6c7ccccc7c7ccccc76)c5)cc-3c42)cc1 ; c1ccc(N2B3c4ccc(-n5c6ccccc6c6ccccc65)cc4Oc4cc(-n5c6ccccc6c6ccccc65)cc(c43)-c3ccccc32)cc1 ; c1ccc(N2B3c4cc(-n5c6ccccc6c6ccccc65)ccc4Oc4cc(-n5c6ccccc6c6ccccc65)cc(c43)-c3ccccc32)cc1] 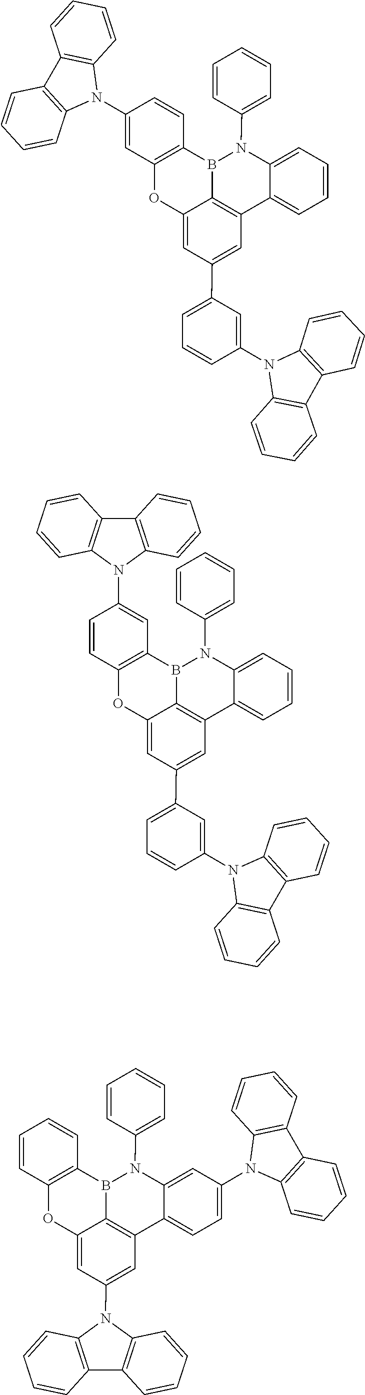 [SMILES: c1ccc(N2B3c4ccc(-n5c6ccccc6c6ccccc65)cc4Oc4cc(-c5cccc(-n6c7ccccc7c7ccccc76)c5)cc(c43)-c3ccccc32)cc1 ; c1ccc(N2B3c4cc(-n5c6ccccc6c6ccccc65)ccc4Oc4cc(-c5cccc(-n6c7ccccc7c7ccccc76)c5)cc(c43)-c3ccccc32)cc1 ; c1ccc(N2B3c4ccccc4Oc4cc(-n5c6ccccc6c6ccccc65)cc(c43)-c3ccc(-n4c5ccccc5c5ccccc54)cc32)cc1] 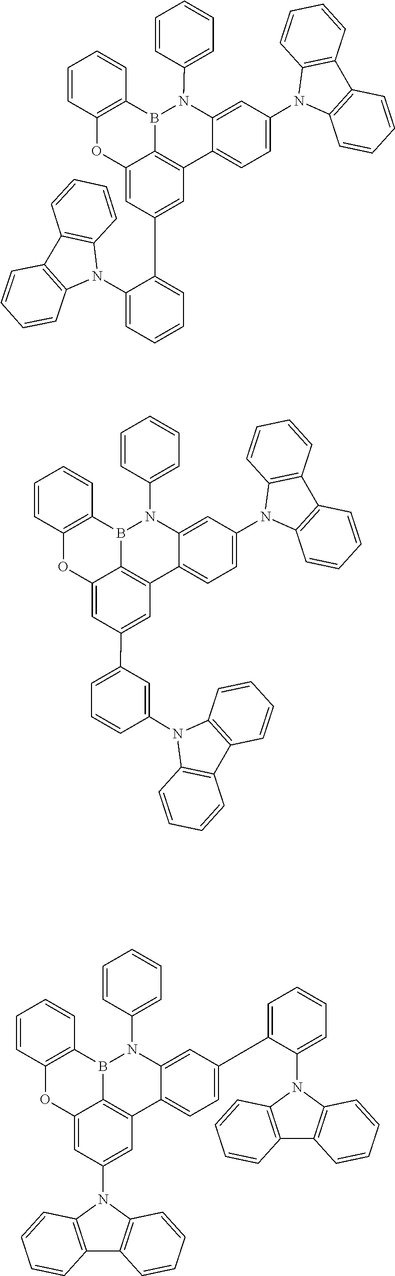 [SMILES: c1ccc(N2B3c4ccccc4Oc4cc(-c5ccccc5-n5c6ccccc6c6ccccc65)cc(c43)-c3ccc(-n4c5ccccc5c5ccccc54)cc32)cc1 ; c1ccc(N2B3c4ccccc4Oc4cc(-c5cccc(-n6c7ccccc7c7ccccc76)c5)cc(c43)-c3ccc(-n4c5ccccc5c5ccccc54)cc32)cc1 ; c1ccc(N2B3c4ccccc4Oc4cc(-n5c6ccccc6c6ccccc65)cc(c43)-c3ccc(-c4ccccc4-n4c5ccccc5c5ccccc54)cc32)cc1] 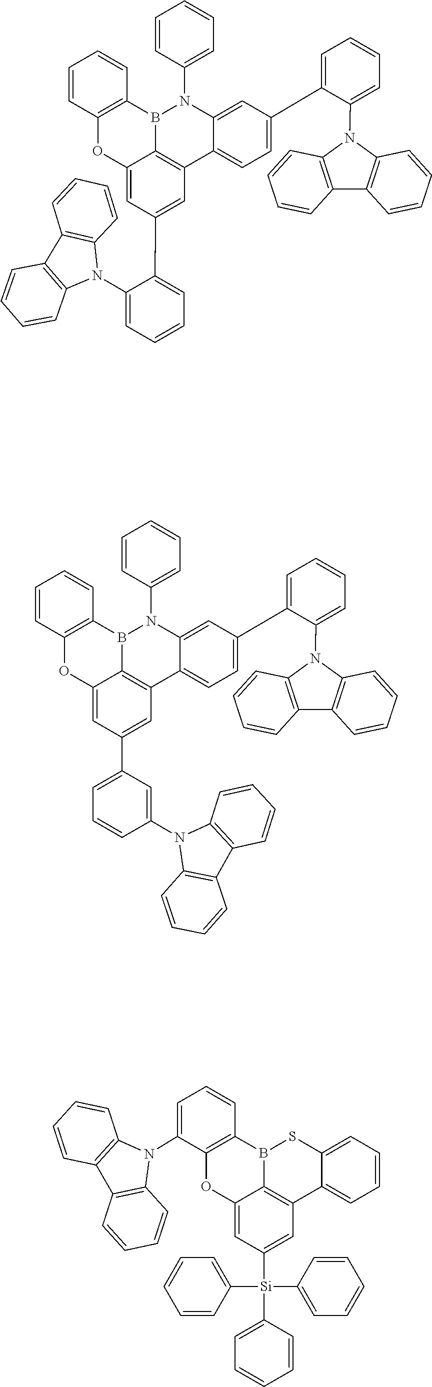 [SMILES: c1ccc(N2B3c4ccccc4Oc4cc(-c5ccccc5-n5c6ccccc6c6ccccc65)cc(c43)-c3ccc(-c4ccccc4-n4c5ccccc5c5ccccc54)cc32)cc1 ; c1ccc(N2B3c4ccccc4Oc4cc(-c5cccc(-n6c7ccccc7c7ccccc76)c5)cc(c43)-c3ccc(-c4ccccc4-n4c5ccccc5c5ccccc54)cc32)cc1 ; c1ccc([Si](c2ccccc2)(c2ccccc2)c2cc3c4c(c2)-c2ccccc2SB4c2cccc(-n4c5ccccc5c5ccccc54)c2O3)cc1] 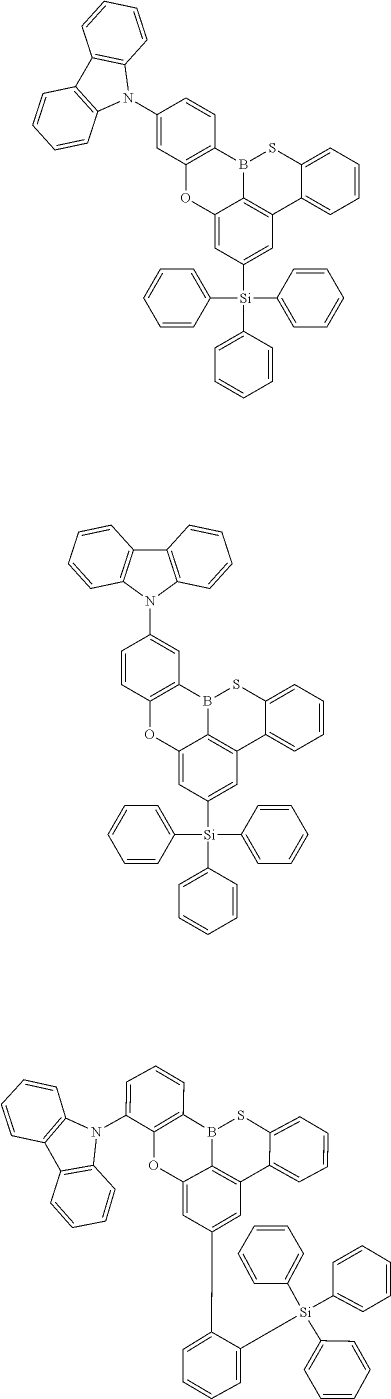 [SMILES: c1ccc([Si](c2ccccc2)(c2ccccc2)c2cc3c4c(c2)-c2ccccc2SB4c2ccc(-n4c5ccccc5c5ccccc54)cc2O3)cc1 ; c1ccc([Si](c2ccccc2)(c2ccccc2)c2cc3c4c(c2)-c2ccccc2SB4c2cc(-n4c5ccccc5c5ccccc54)ccc2O3)cc1 ; c1ccc([Si](c2ccccc2)(c2ccccc2)c2ccccc2-c2cc3c4c(c2)-c2ccccc2SB4c2cccc(-n4c5ccccc5c5ccccc54)c2O3)cc1] 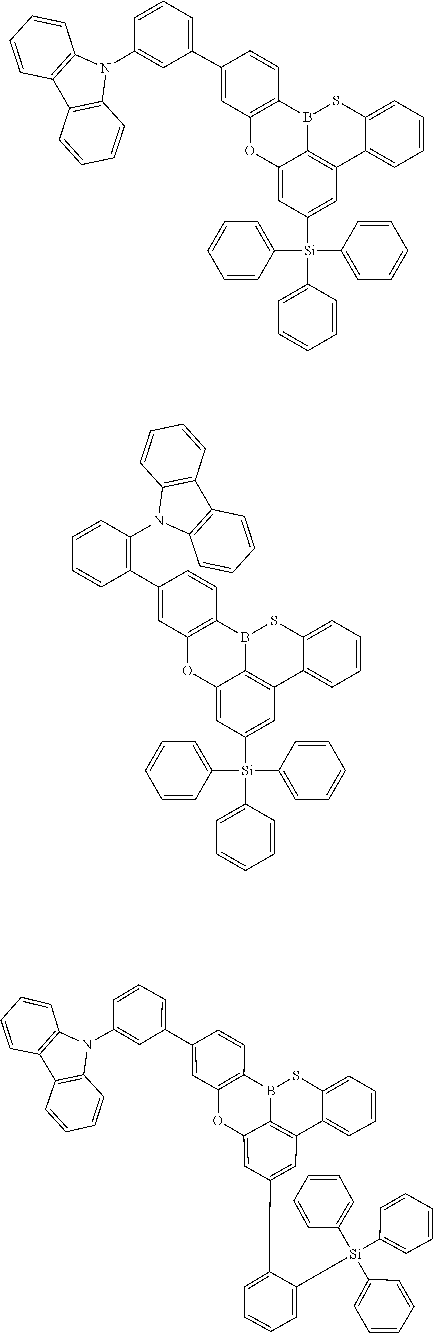 [SMILES: c1ccc([Si](c2ccccc2)(c2ccccc2)c2cc3c4c(c2)-c2ccccc2SB4c2ccc(-c4cccc(-n5c6ccccc6c6ccccc65)c4)cc2O3)cc1 ; c1ccc([Si](c2ccccc2)(c2ccccc2)c2cc3c4c(c2)-c2ccccc2SB4c2ccc(-c4ccccc4-n4c5ccccc5c5ccccc54)cc2O3)cc1 ; c1ccc([Si](c2ccccc2)(c2ccccc2)c2ccccc2-c2cc3c4c(c2)-c2ccccc2SB4c2ccc(-c4cccc(-n5c6ccccc6c6ccccc65)c4)cc2O3)cc1] 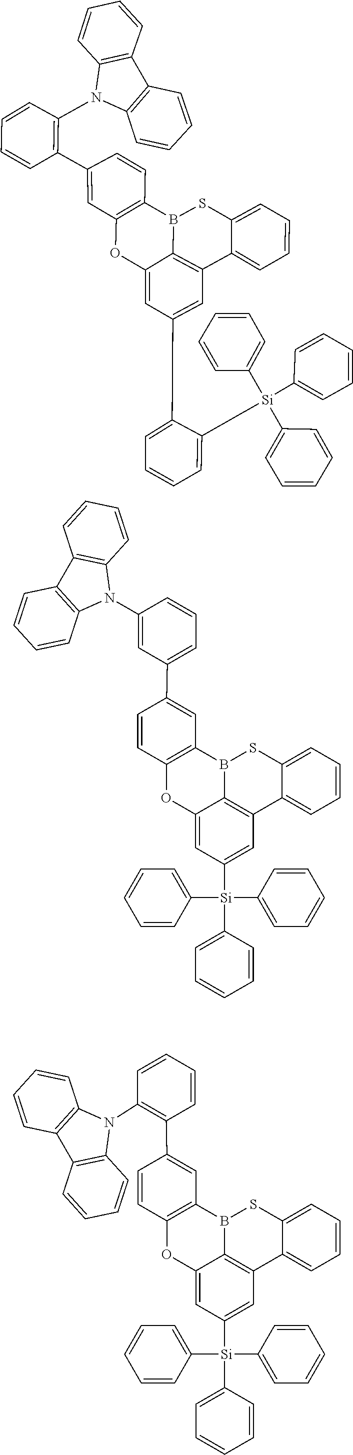 [SMILES: c1ccc([Si](c2ccccc2)(c2ccccc2)c2ccccc2-c2cc3c4c(c2)-c2ccccc2SB4c2ccc(-c4ccccc4-n4c5ccccc5c5ccccc54)cc2O3)cc1 ; c1ccc([Si](c2ccccc2)(c2ccccc2)c2cc3c4c(c2)-c2ccccc2SB4c2cc(-c4cccc(-n5c6ccccc6c6ccccc65)c4)ccc2O3)cc1 ; c1ccc([Si](c2ccccc2)(c2ccccc2)c2cc3c4c(c2)-c2ccccc2SB4c2cc(-c4ccccc4-n4c5ccccc5c5ccccc54)ccc2O3)cc1] 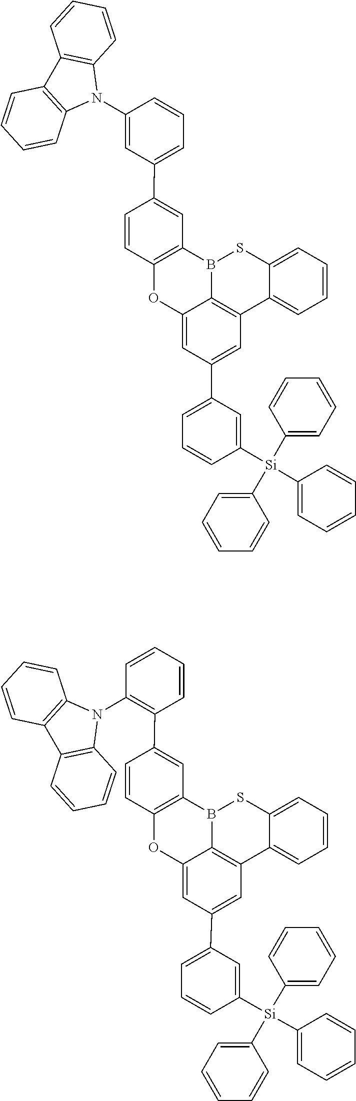 [SMILES: c1ccc([Si](c2ccccc2)(c2ccccc2)c2cccc(-c3cc4c5c(c3)-c3ccccc3SB5c3cc(-c5cccc(-n6c7ccccc7c7ccccc76)c5)ccc3O4)c2)cc1 ; c1ccc([Si](c2ccccc2)(c2ccccc2)c2cccc(-c3cc4c5c(c3)-c3ccccc3SB5c3cc(-c5ccccc5-n5c6ccccc6c6ccccc65)ccc3O4)c2)cc1] 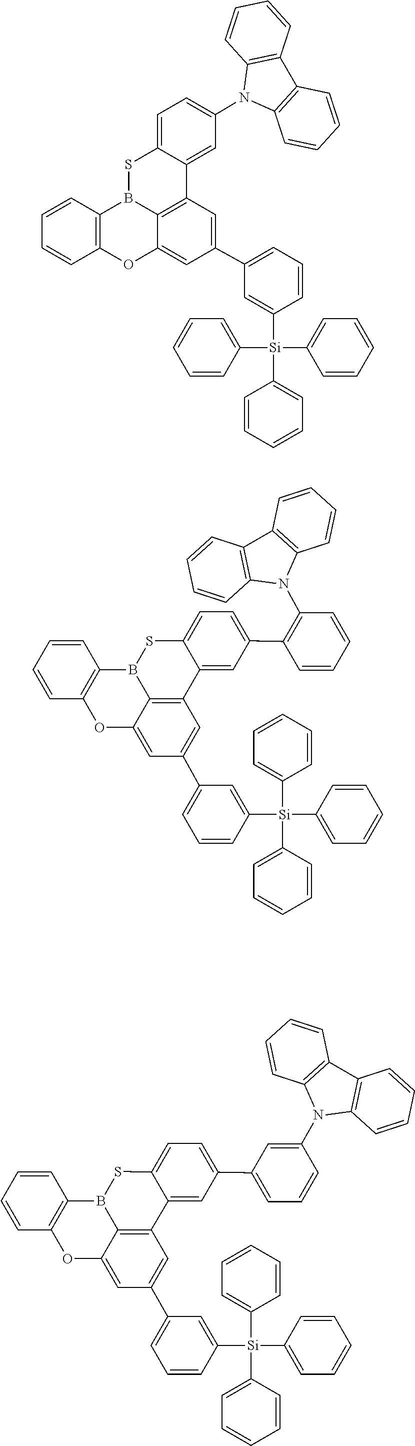 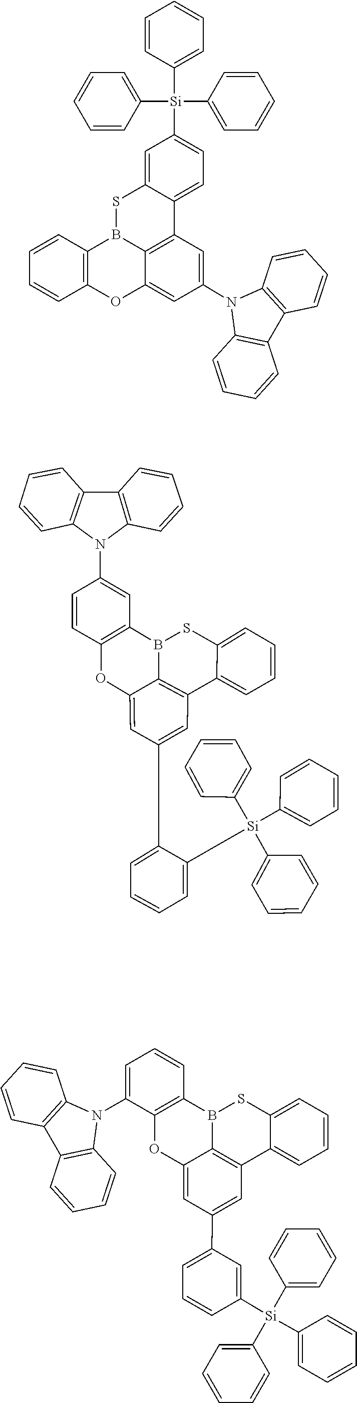 [SMILES: c1ccc([Si](c2ccccc2)(c2ccccc2)c2ccc3c(c2)SB2c4ccccc4Oc4cc(-n5c6ccccc6c6ccccc65)cc-3c42)cc1 ; c1ccc([Si](c2ccccc2)(c2ccccc2)c2ccccc2-c2cc3c4c(c2)-c2ccccc2SB4c2cc(-n4c5ccccc5c5ccccc54)ccc2O3)cc1 ; c1ccc([Si](c2ccccc2)(c2ccccc2)c2cccc(-c3cc4c5c(c3)-c3ccccc3SB5c3cccc(-n5c6ccccc6c6ccccc65)c3O4)c2)cc1] 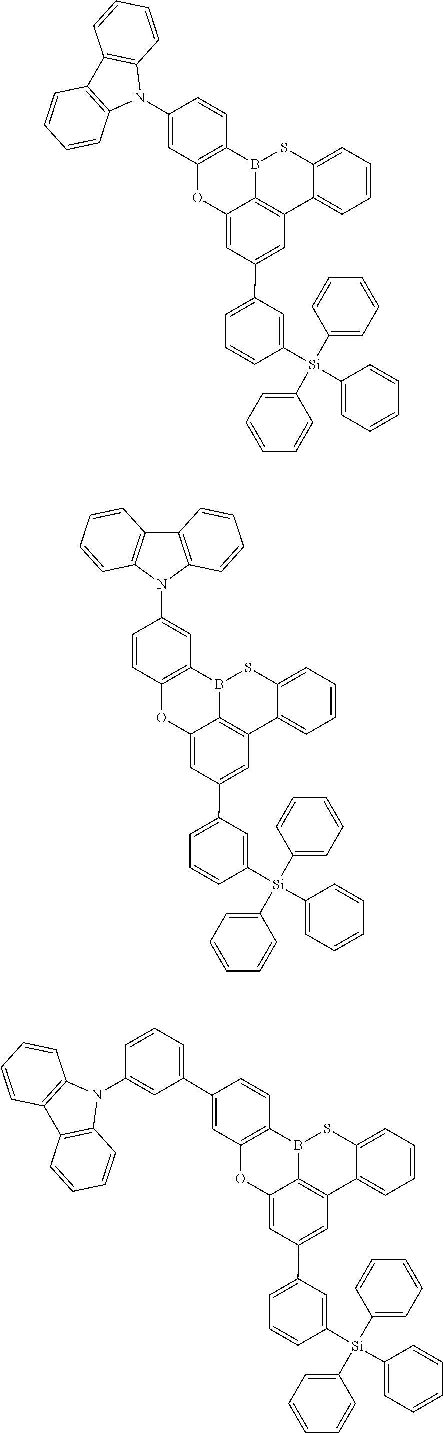 [SMILES: c1ccc([Si](c2ccccc2)(c2ccccc2)c2cccc(-c3cc4c5c(c3)-c3ccccc3SB5c3ccc(-n5c6ccccc6c6ccccc65)cc3O4)c2)cc1 ; c1ccc([Si](c2ccccc2)(c2ccccc2)c2cccc(-c3cc4c5c(c3)-c3ccccc3SB5c3cc(-n5c6ccccc6c6ccccc65)ccc3O4)c2)cc1 ; c1ccc([Si](c2ccccc2)(c2ccccc2)c2cccc(-c3cc4c5c(c3)-c3ccccc3SB5c3ccc(-c5cccc(-n6c7ccccc7c7ccccc76)c5)cc3O4)c2)cc1] 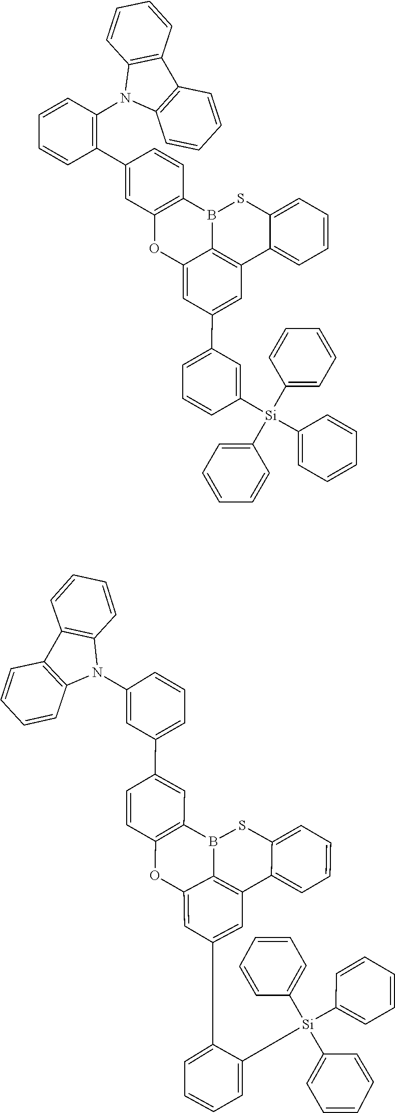 [SMILES: c1ccc([Si](c2ccccc2)(c2ccccc2)c2cccc(-c3cc4c5c(c3)-c3ccccc3SB5c3ccc(-c5ccccc5-n5c6ccccc6c6ccccc65)cc3O4)c2)cc1 ; c1ccc([Si](c2ccccc2)(c2ccccc2)c2ccccc2-c2cc3c4c(c2)-c2ccccc2SB4c2cc(-c4cccc(-n5c6ccccc6c6ccccc65)c4)ccc2O3)cc1] 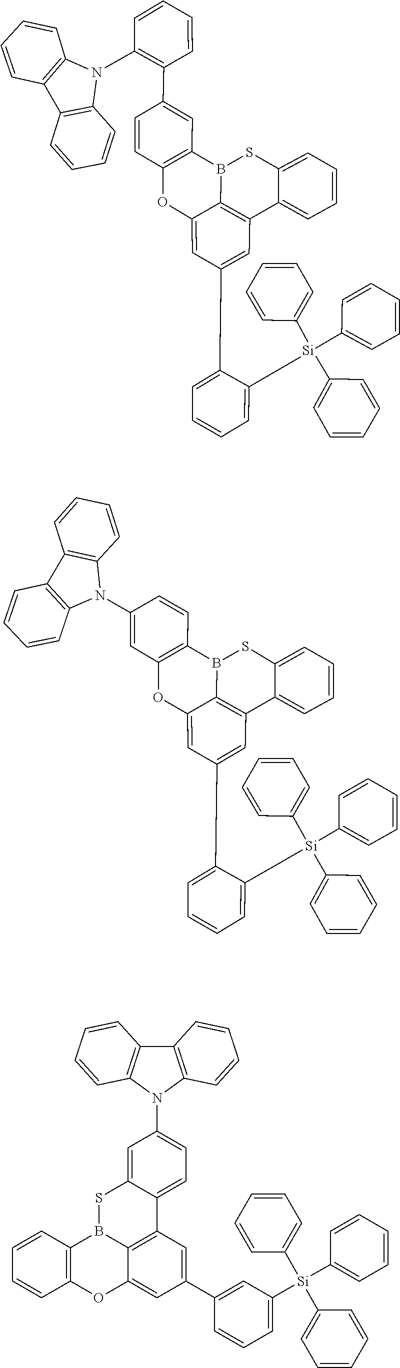 [SMILES: c1ccc([Si](c2ccccc2)(c2ccccc2)c2ccccc2-c2cc3c4c(c2)-c2ccccc2SB4c2cc(-c4ccccc4-n4c5ccccc5c5ccccc54)ccc2O3)cc1 ; c1ccc([Si](c2ccccc2)(c2ccccc2)c2ccccc2-c2cc3c4c(c2)-c2ccccc2SB4c2ccc(-n4c5ccccc5c5ccccc54)cc2O3)cc1 ; c1ccc([Si](c2ccccc2)(c2ccccc2)c2cccc(-c3cc4c5c(c3)-c3ccc(-n6c7ccccc7c7ccccc76)cc3SB5c3ccccc3O4)c2)cc1] 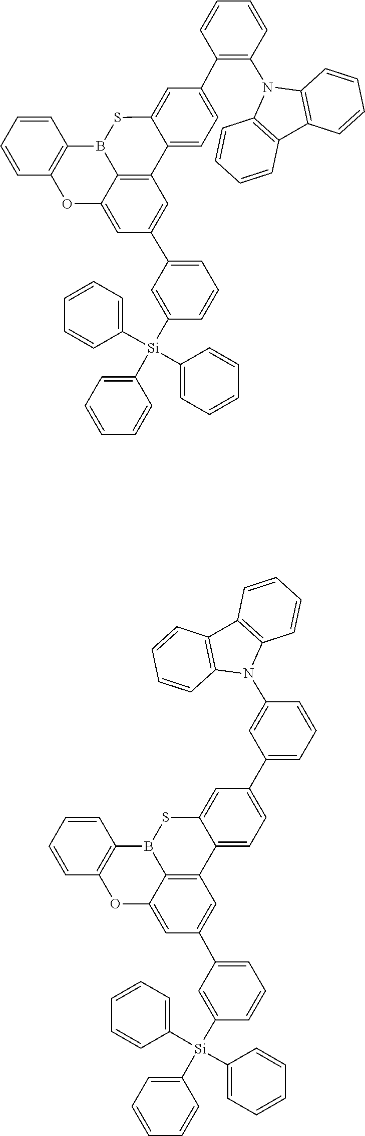 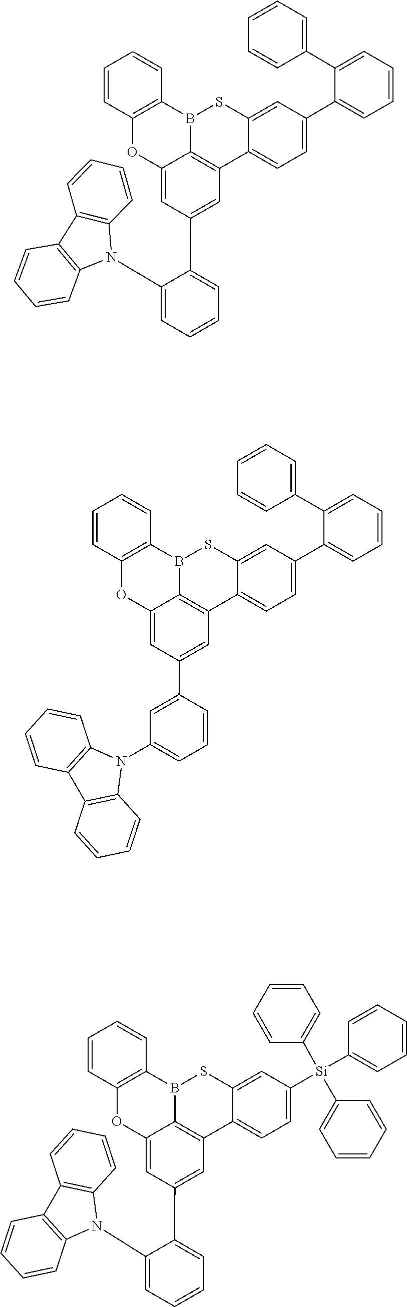 [SMILES: c1ccc(-c2ccccc2-c2ccc3c(c2)SB2c4ccccc4Oc4cc(-c5ccccc5-n5c6ccccc6c6ccccc65)cc-3c42)cc1 ; c1ccc(-c2ccccc2-c2ccc3c(c2)SB2c4ccccc4Oc4cc(-c5cccc(-n6c7ccccc7c7ccccc76)c5)cc-3c42)cc1 ; c1ccc([Si](c2ccccc2)(c2ccccc2)c2ccc3c(c2)SB2c4ccccc4Oc4cc(-c5ccccc5-n5c6ccccc6c6ccccc65)cc-3c42)cc1] 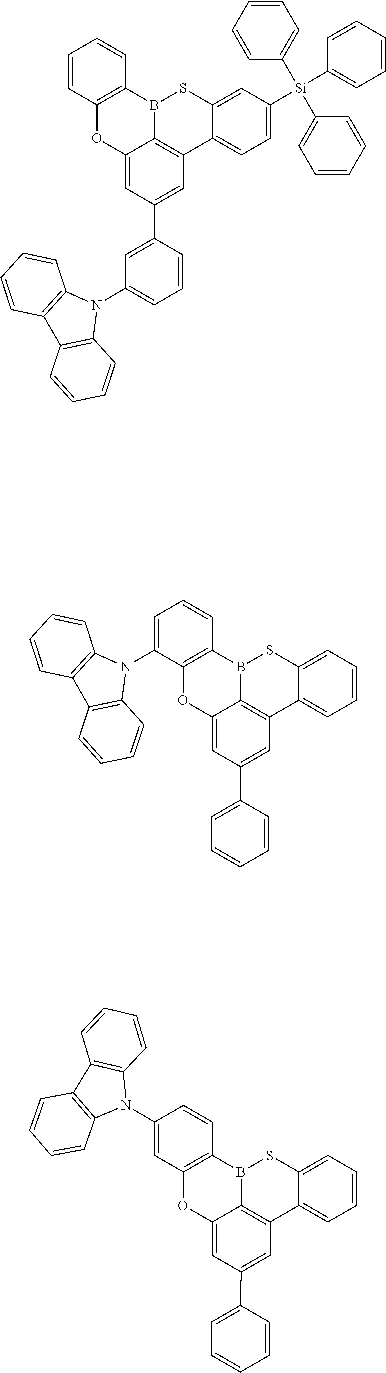 [SMILES: c1ccc([Si](c2ccccc2)(c2ccccc2)c2ccc3c(c2)SB2c4ccccc4Oc4cc(-c5cccc(-n6c7ccccc7c7ccccc76)c5)cc-3c42)cc1 ; c1ccc(-c2cc3c4c(c2)-c2ccccc2SB4c2cccc(-n4c5ccccc5c5ccccc54)c2O3)cc1 ; c1ccc(-c2cc3c4c(c2)-c2ccccc2SB4c2ccc(-n4c5ccccc5c5ccccc54)cc2O3)cc1] 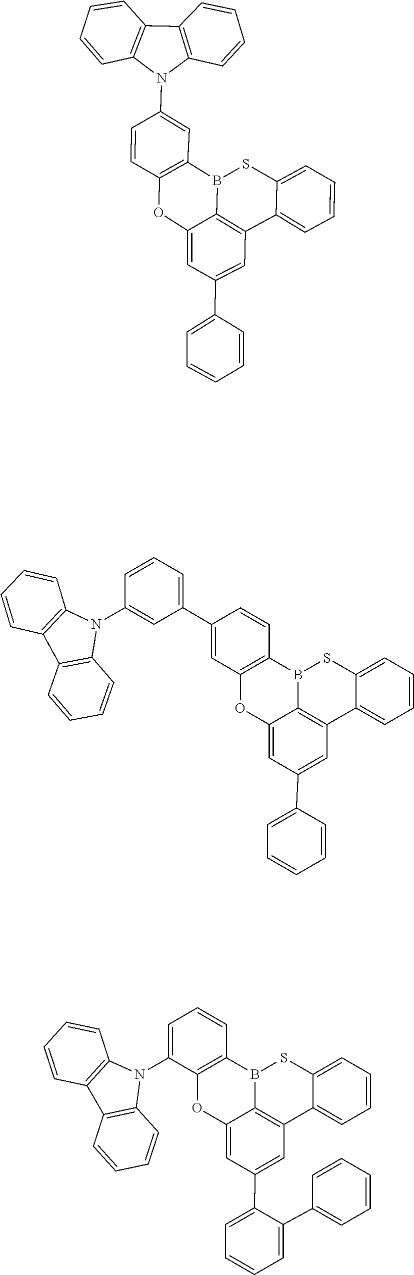 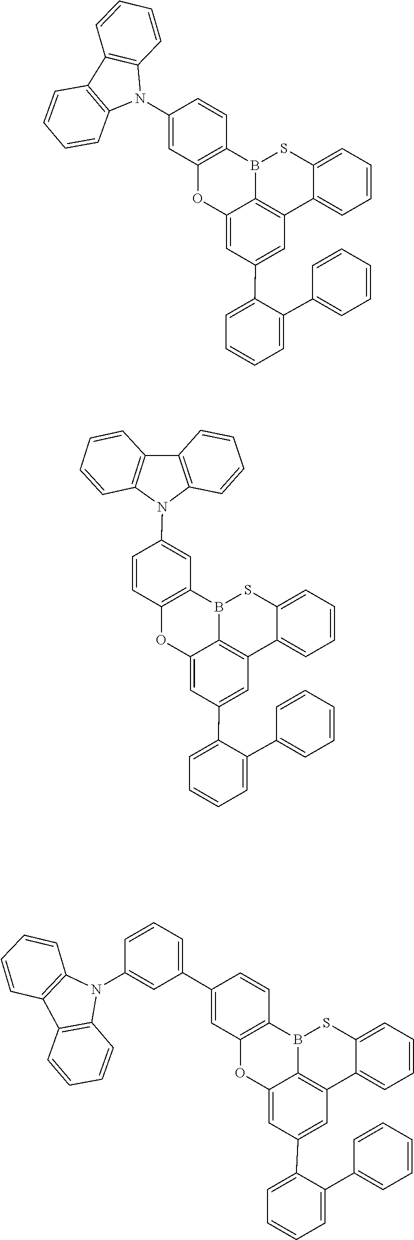 [SMILES: c1ccc(-c2ccccc2-c2cc3c4c(c2)-c2ccccc2SB4c2ccc(-n4c5ccccc5c5ccccc54)cc2O3)cc1 ; c1ccc(-c2ccccc2-c2cc3c4c(c2)-c2ccccc2SB4c2cc(-n4c5ccccc5c5ccccc54)ccc2O3)cc1 ; c1ccc(-c2ccccc2-c2cc3c4c(c2)-c2ccccc2SB4c2ccc(-c4cccc(-n5c6ccccc6c6ccccc65)c4)cc2O3)cc1] 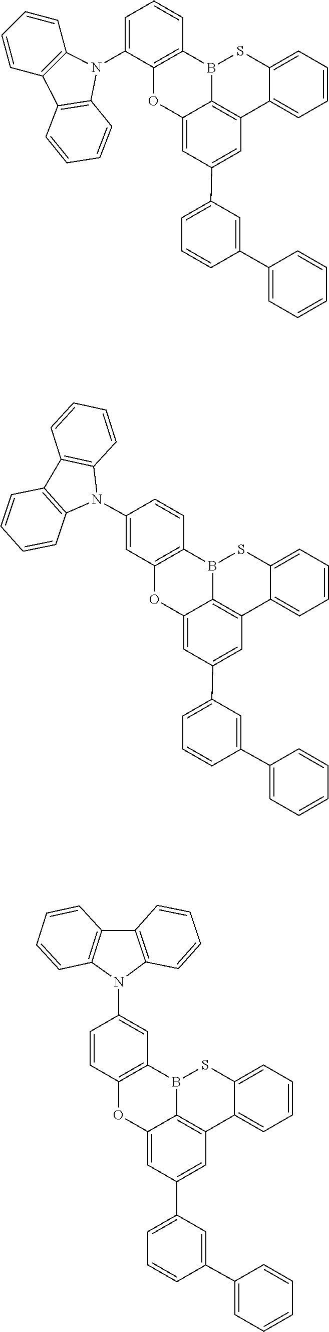 [SMILES: c1ccc(-c2cccc(-c3cc4c5c(c3)-c3ccccc3SB5c3cccc(-n5c6ccccc6c6ccccc65)c3O4)c2)cc1 ; c1ccc(-c2cccc(-c3cc4c5c(c3)-c3ccccc3SB5c3ccc(-n5c6ccccc6c6ccccc65)cc3O4)c2)cc1 ; c1ccc(-c2cccc(-c3cc4c5c(c3)-c3ccccc3SB5c3cc(-n5c6ccccc6c6ccccc65)ccc3O4)c2)cc1] 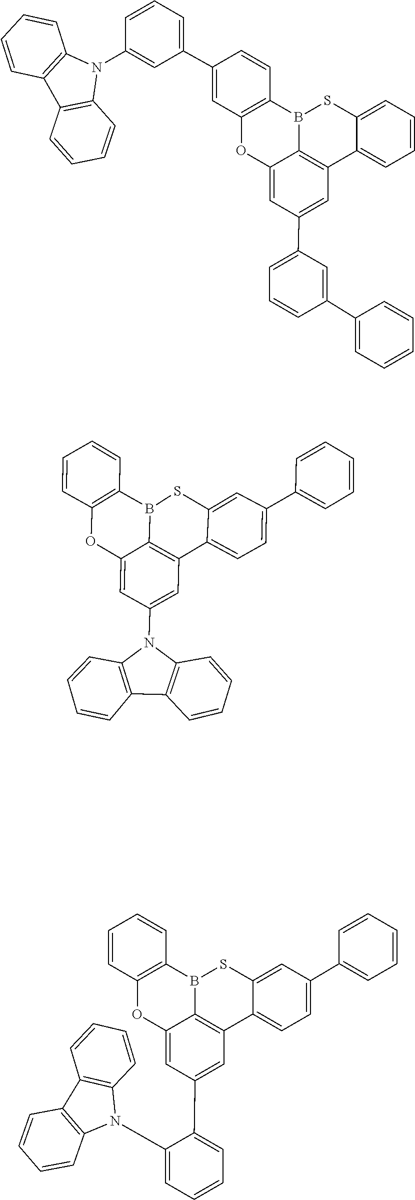 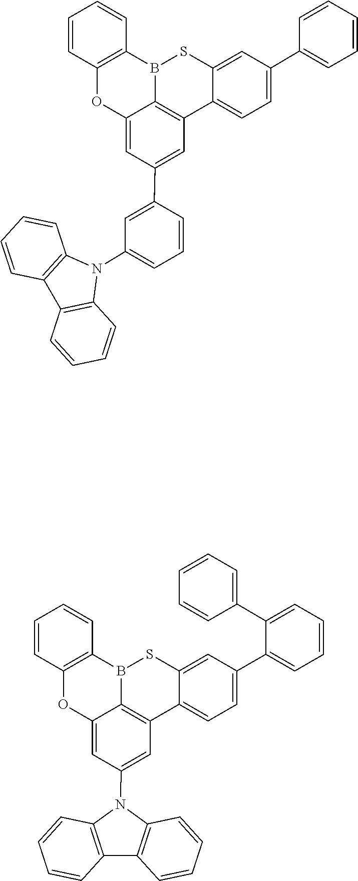 [SMILES: c1ccc(-c2ccc3c(c2)SB2c4ccccc4Oc4cc(-c5cccc(-n6c7ccccc7c7ccccc76)c5)cc-3c42)cc1 ; c1ccc(-c2ccccc2-c2ccc3c(c2)SB2c4ccccc4Oc4cc(-n5c6ccccc6c6ccccc65)cc-3c42)cc1] 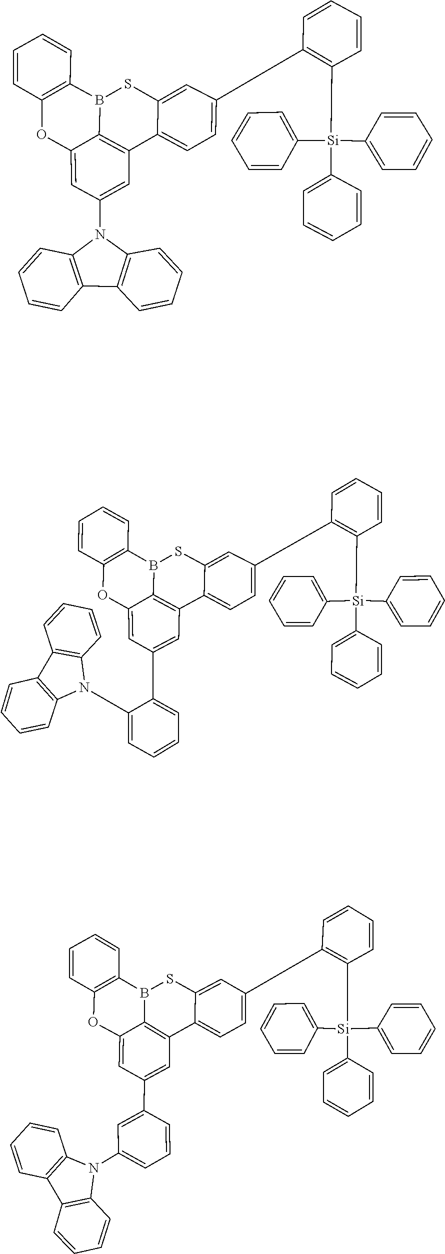 [SMILES: c1ccc([Si](c2ccccc2)(c2ccccc2)c2ccccc2-c2ccc3c(c2)SB2c4ccccc4Oc4cc(-n5c6ccccc6c6ccccc65)cc-3c42)cc1 ; c1ccc([Si](c2ccccc2)(c2ccccc2)c2ccccc2-c2ccc3c(c2)SB2c4ccccc4Oc4cc(-c5ccccc5-n5c6ccccc6c6ccccc65)cc-3c42)cc1 ; c1ccc([Si](c2ccccc2)(c2ccccc2)c2ccccc2-c2ccc3c(c2)SB2c4ccccc4Oc4cc(-c5cccc(-n6c7ccccc7c7ccccc76)c5)cc-3c42)cc1] 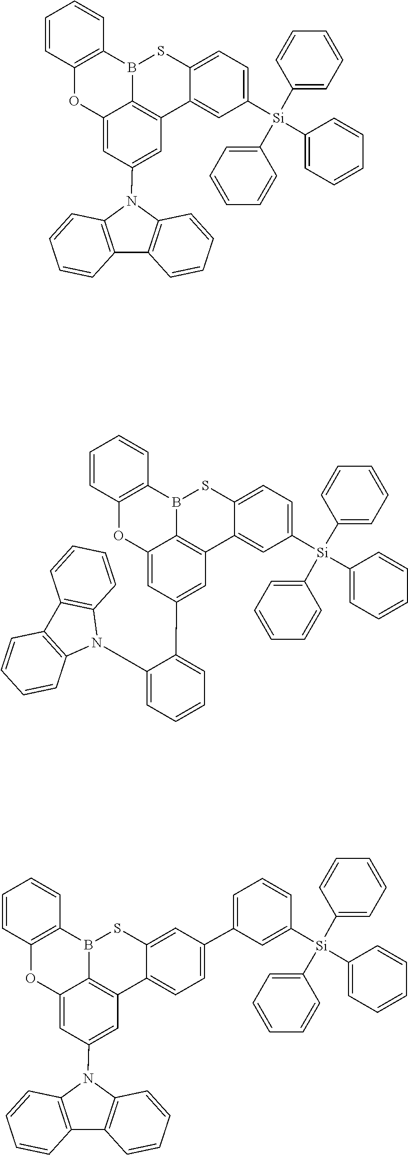 [SMILES: c1ccc([Si](c2ccccc2)(c2ccccc2)c2ccc3c(c2)-c2cc(-n4c5ccccc5c5ccccc54)cc4c2B(S3)c2ccccc2O4)cc1 ; c1ccc([Si](c2ccccc2)(c2ccccc2)c2ccc3c(c2)-c2cc(-c4ccccc4-n4c5ccccc5c5ccccc54)cc4c2B(S3)c2ccccc2O4)cc1 ; c1ccc([Si](c2ccccc2)(c2ccccc2)c2cccc(-c3ccc4c(c3)SB3c5ccccc5Oc5cc(-n6c7ccccc7c7ccccc76)cc-4c53)c2)cc1] 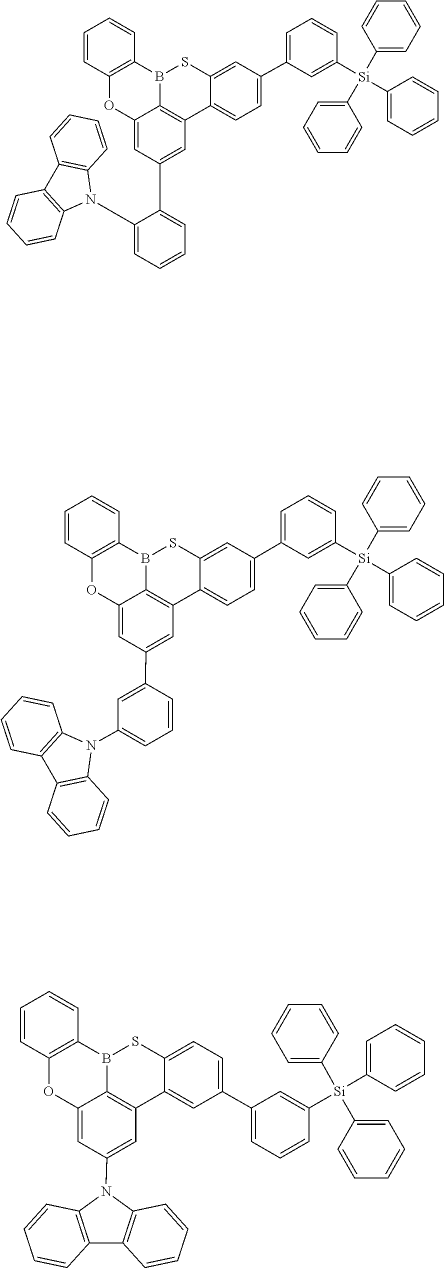 [SMILES: c1ccc([Si](c2ccccc2)(c2ccccc2)c2cccc(-c3ccc4c(c3)SB3c5ccccc5Oc5cc(-c6ccccc6-n6c7ccccc7c7ccccc76)cc-4c53)c2)cc1 ; c1ccc([Si](c2ccccc2)(c2ccccc2)c2cccc(-c3ccc4c(c3)SB3c5ccccc5Oc5cc(-c6cccc(-n7c8ccccc8c8ccccc87)c6)cc-4c53)c2)cc1 ; c1ccc([Si](c2ccccc2)(c2ccccc2)c2cccc(-c3ccc4c(c3)-c3cc(-n5c6ccccc6c6ccccc65)cc5c3B(S4)c3ccccc3O5)c2)cc1] 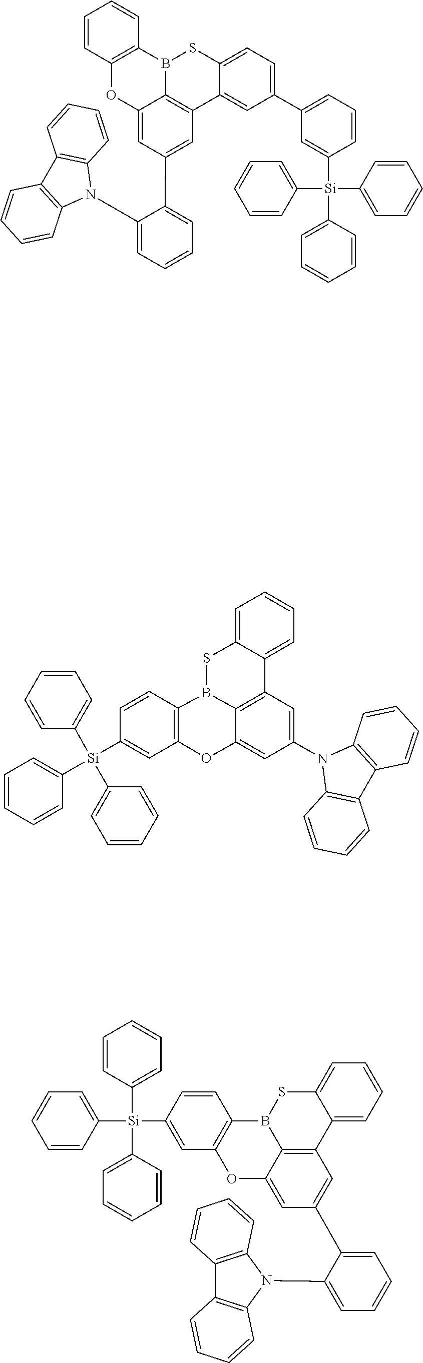 [SMILES: c1ccc([Si](c2ccccc2)(c2ccccc2)c2cccc(-c3ccc4c(c3)-c3cc(-c5ccccc5-n5c6ccccc6c6ccccc65)cc5c3B(S4)c3ccccc3O5)c2)cc1 ; c1ccc([Si](c2ccccc2)(c2ccccc2)c2ccc3c(c2)Oc2cc(-n4c5ccccc5c5ccccc54)cc4c2B3Sc2ccccc2-4)cc1 ; c1ccc([Si](c2ccccc2)(c2ccccc2)c2ccc3c(c2)Oc2cc(-c4ccccc4-n4c5ccccc5c5ccccc54)cc4c2B3Sc2ccccc2-4)cc1] 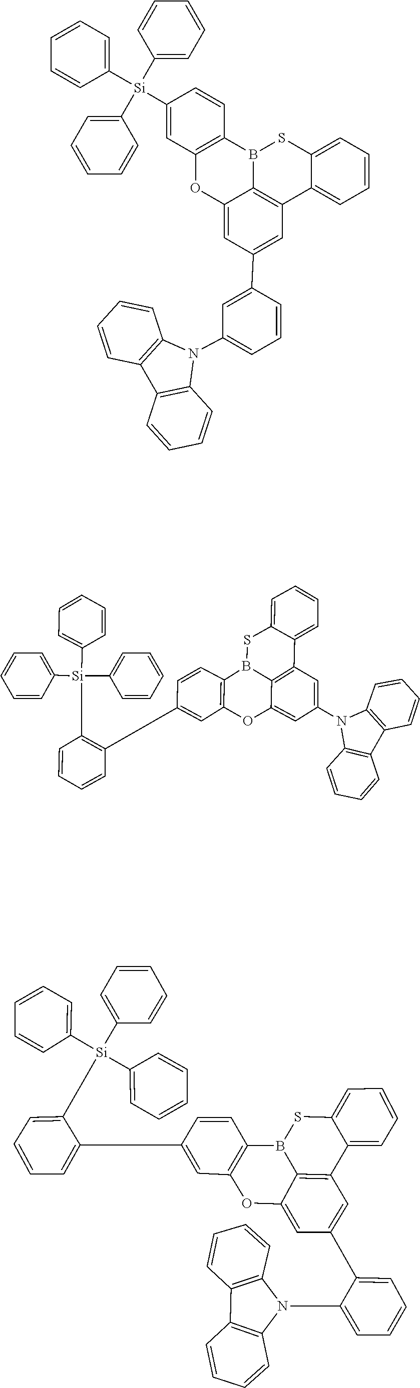 [SMILES: c1ccc([Si](c2ccccc2)(c2ccccc2)c2ccc3c(c2)Oc2cc(-c4cccc(-n5c6ccccc6c6ccccc65)c4)cc4c2B3Sc2ccccc2-4)cc1 ; c1ccc([Si](c2ccccc2)(c2ccccc2)c2ccccc2-c2ccc3c(c2)Oc2cc(-n4c5ccccc5c5ccccc54)cc4c2B3Sc2ccccc2-4)cc1 ; c1ccc([Si](c2ccccc2)(c2ccccc2)c2ccccc2-c2ccc3c(c2)Oc2cc(-c4ccccc4-n4c5ccccc5c5ccccc54)cc4c2B3Sc2ccccc2-4)cc1] 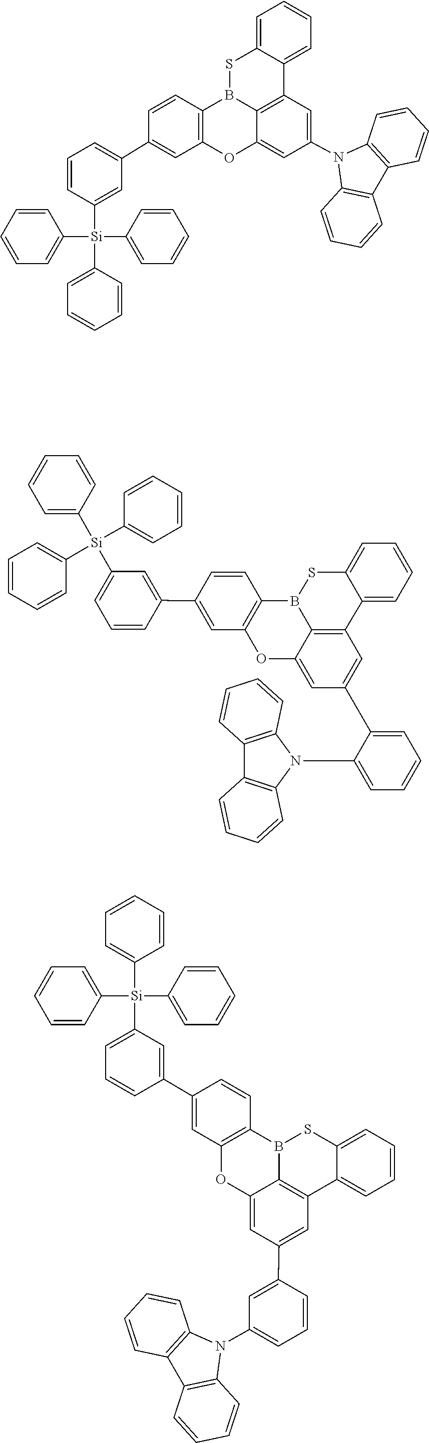 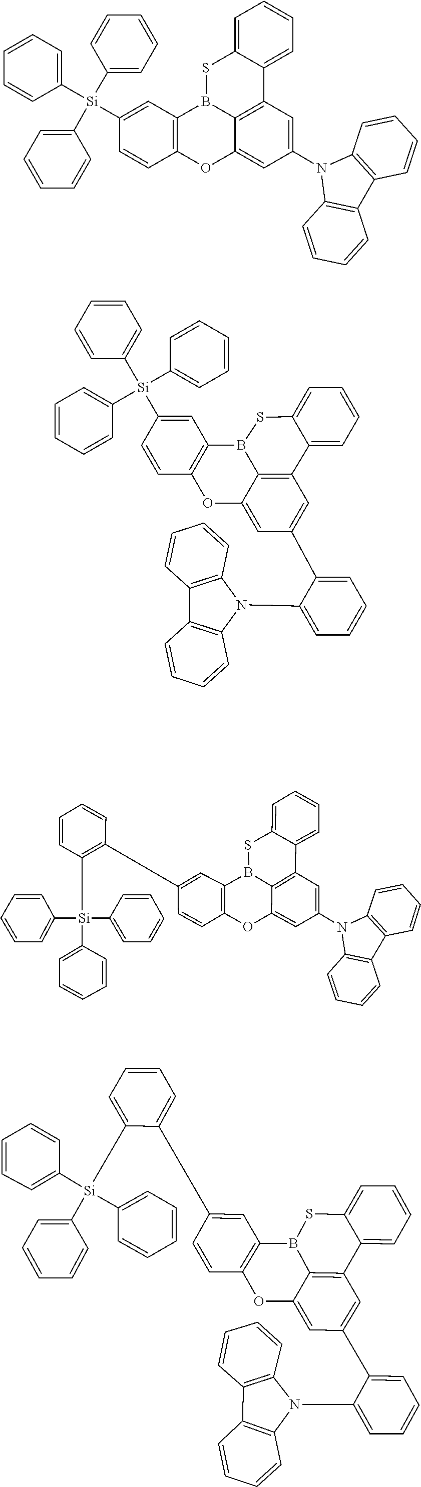 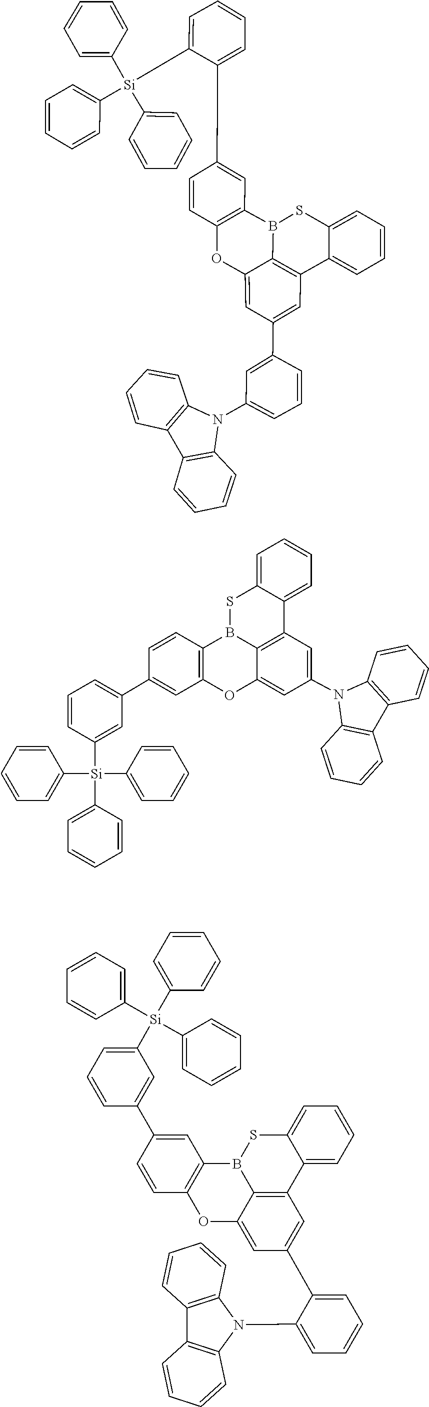 [SMILES: c1ccc([Si](c2ccccc2)(c2ccccc2)c2ccccc2-c2ccc3c(c2)B2Sc4ccccc4-c4cc(-c5cccc(-n6c7ccccc7c7ccccc76)c5)cc(c42)O3)cc1 ; c1ccc([Si](c2ccccc2)(c2ccccc2)c2cccc(-c3ccc4c(c3)Oc3cc(-n5c6ccccc6c6ccccc65)cc5c3B4Sc3ccccc3-5)c2)cc1 ; c1ccc([Si](c2ccccc2)(c2ccccc2)c2cccc(-c3ccc4c(c3)B3Sc5ccccc5-c5cc(-c6ccccc6-n6c7ccccc7c7ccccc76)cc(c53)O4)c2)cc1] 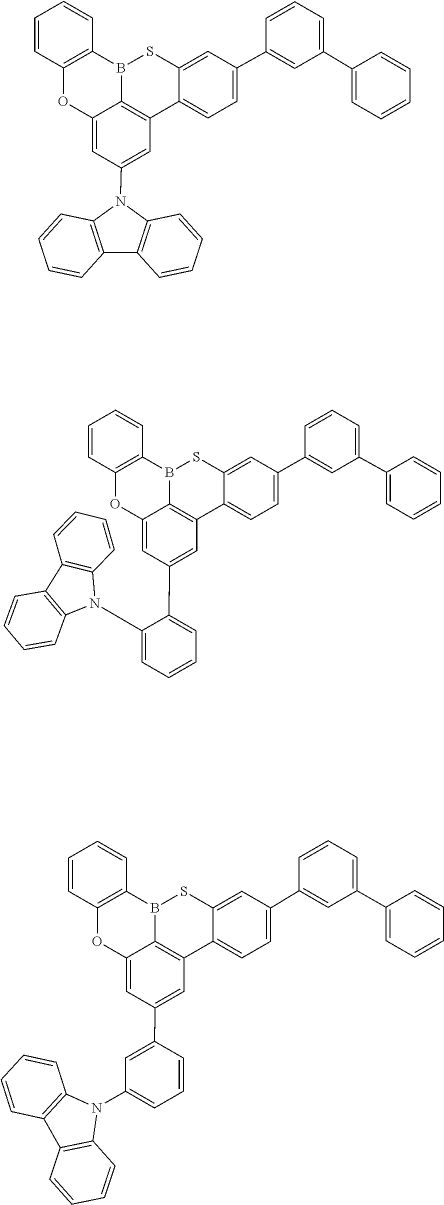 [SMILES: c1ccc(-c2cccc(-c3ccc4c(c3)SB3c5ccccc5Oc5cc(-n6c7ccccc7c7ccccc76)cc-4c53)c2)cc1 ; c1ccc(-c2cccc(-c3ccc4c(c3)SB3c5ccccc5Oc5cc(-c6ccccc6-n6c7ccccc7c7ccccc76)cc-4c53)c2)cc1 ; c1ccc(-c2cccc(-c3ccc4c(c3)SB3c5ccccc5Oc5cc(-c6cccc(-n7c8ccccc8c8ccccc87)c6)cc-4c53)c2)cc1] 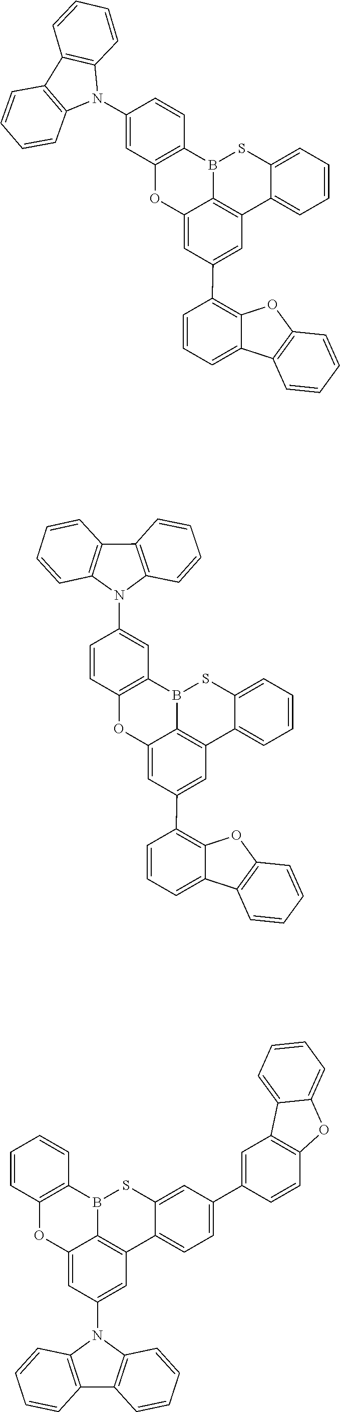 [SMILES: c1ccc2c(c1)SB1c3ccc(-n4c5ccccc5c5ccccc54)cc3Oc3cc(-c4cccc5c4oc4ccccc45)cc-2c31 ; c1ccc2c(c1)SB1c3cc(-n4c5ccccc5c5ccccc54)ccc3Oc3cc(-c4cccc5c4oc4ccccc45)cc-2c31 ; c1ccc2c(c1)Oc1cc(-n3c4ccccc4c4ccccc43)cc3c1B2Sc1cc(-c2ccc4oc5ccccc5c4c2)ccc1-3] 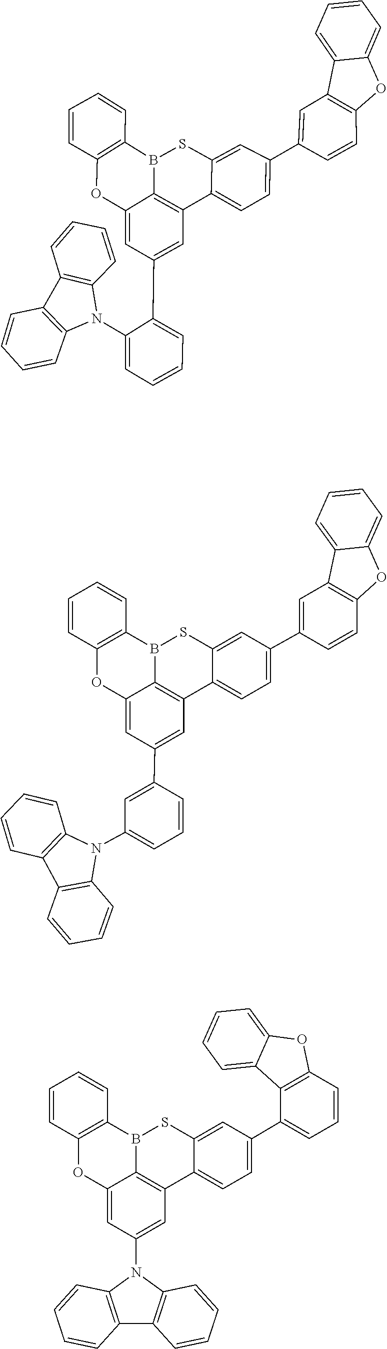 [SMILES: c1ccc2c(c1)Oc1cc(-c3ccccc3-n3c4ccccc4c4ccccc43)cc3c1B2Sc1cc(-c2ccc4oc5ccccc5c4c2)ccc1-3 ; c1cc(-c2cc3c4c(c2)-c2ccc(-c5ccc6oc7ccccc7c6c5)cc2SB4c2ccccc2O3)cc(-n2c3ccccc3c3ccccc32)c1 ; c1ccc2c(c1)Oc1cc(-n3c4ccccc4c4ccccc43)cc3c1B2Sc1cc(-c2cccc4oc5ccccc5c24)ccc1-3] 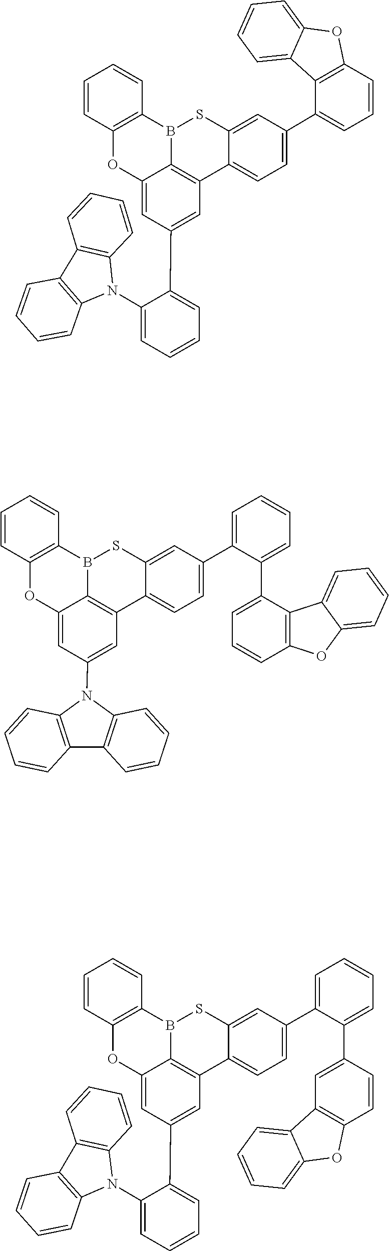 [SMILES: c1ccc2c(c1)Oc1cc(-c3ccccc3-n3c4ccccc4c4ccccc43)cc3c1B2Sc1cc(-c2cccc4oc5ccccc5c24)ccc1-3 ; c1ccc2c(c1)Oc1cc(-n3c4ccccc4c4ccccc43)cc3c1B2Sc1cc(-c2ccccc2-c2cccc4oc5ccccc5c24)ccc1-3 ; c1ccc2c(c1)Oc1cc(-c3ccccc3-n3c4ccccc4c4ccccc43)cc3c1B2Sc1cc(-c2ccccc2-c2ccc4oc5ccccc5c4c2)ccc1-3] 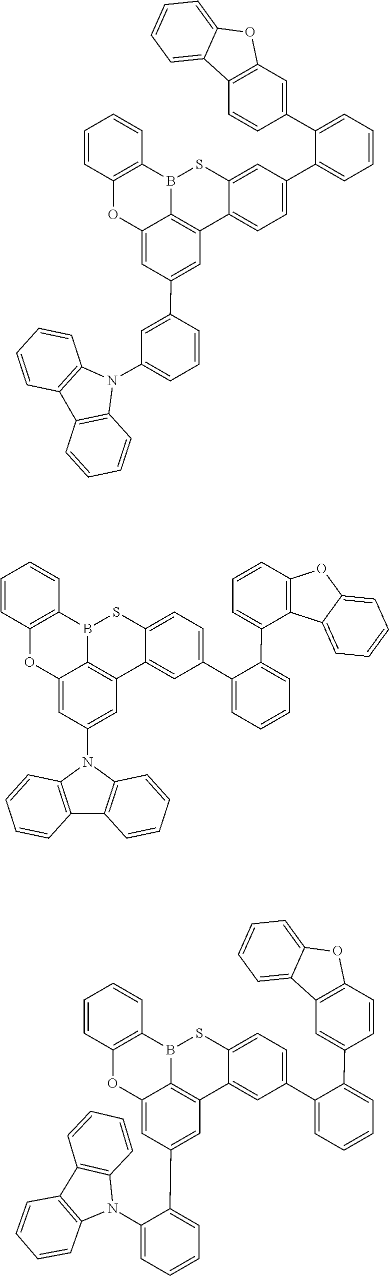 [SMILES: c1cc(-c2cc3c4c(c2)-c2ccc(-c5ccccc5-c5ccc6c(c5)oc5ccccc56)cc2SB4c2ccccc2O3)cc(-n2c3ccccc3c3ccccc32)c1 ; c1ccc2c(c1)Oc1cc(-n3c4ccccc4c4ccccc43)cc3c1B2Sc1ccc(-c2ccccc2-c2cccc4oc5ccccc5c24)cc1-3 ; c1ccc2c(c1)Oc1cc(-c3ccccc3-n3c4ccccc4c4ccccc43)cc3c1B2Sc1ccc(-c2ccccc2-c2ccc4oc5ccccc5c4c2)cc1-3] 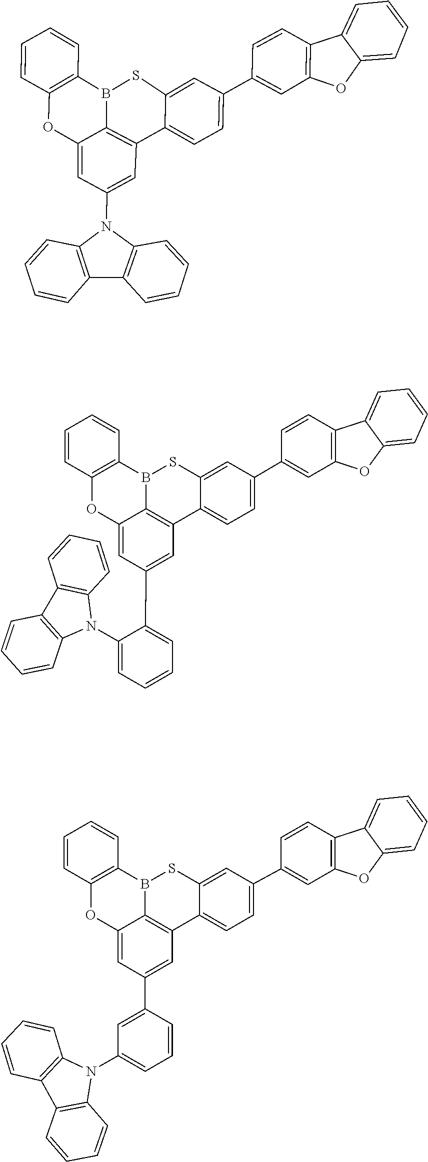 [SMILES: c1ccc2c(c1)Oc1cc(-n3c4ccccc4c4ccccc43)cc3c1B2Sc1cc(-c2ccc4c(c2)oc2ccccc24)ccc1-3 ; c1ccc2c(c1)Oc1cc(-c3ccccc3-n3c4ccccc4c4ccccc43)cc3c1B2Sc1cc(-c2ccc4c(c2)oc2ccccc24)ccc1-3 ; c1cc(-c2cc3c4c(c2)-c2ccc(-c5ccc6c(c5)oc5ccccc56)cc2SB4c2ccccc2O3)cc(-n2c3ccccc3c3ccccc32)c1] 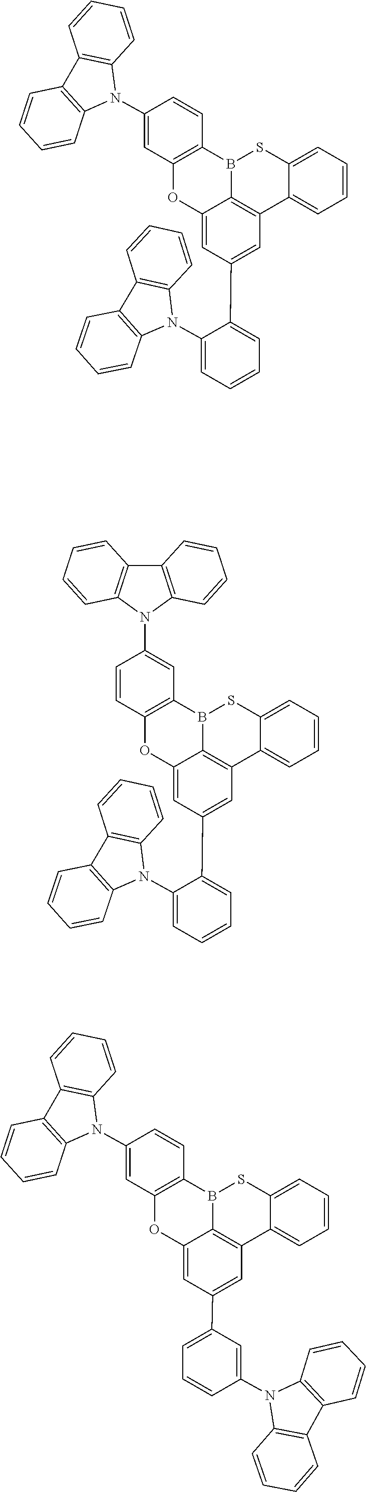 [SMILES: c1ccc2c(c1)SB1c3ccc(-n4c5ccccc5c5ccccc54)cc3Oc3cc(-c4ccccc4-n4c5ccccc5c5ccccc54)cc-2c31 ; c1ccc2c(c1)SB1c3cc(-n4c5ccccc5c5ccccc54)ccc3Oc3cc(-c4ccccc4-n4c5ccccc5c5ccccc54)cc-2c31 ; c1cc(-c2cc3c4c(c2)-c2ccccc2SB4c2ccc(-n4c5ccccc5c5ccccc54)cc2O3)cc(-n2c3ccccc3c3ccccc32)c1] 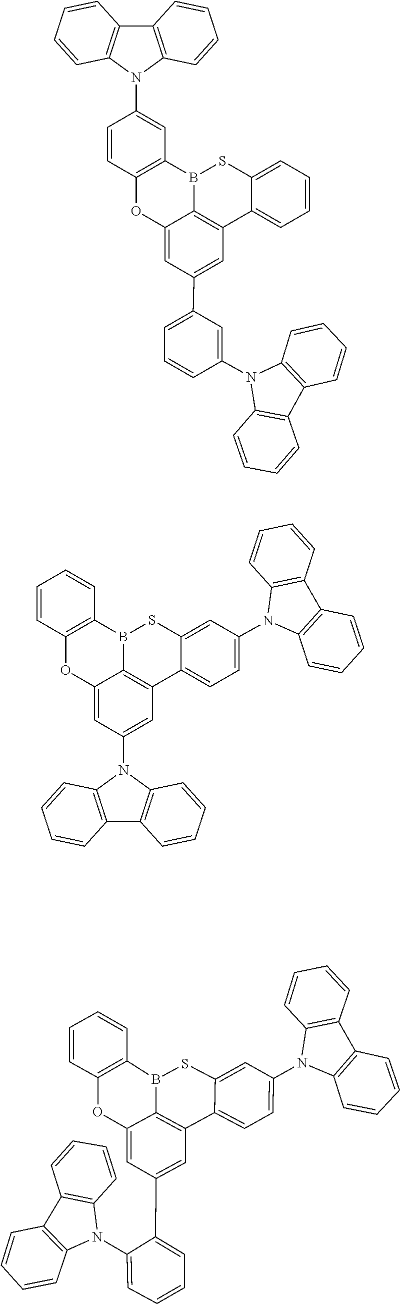 [SMILES: c1cc(-c2cc3c4c(c2)-c2ccccc2SB4c2cc(-n4c5ccccc5c5ccccc54)ccc2O3)cc(-n2c3ccccc3c3ccccc32)c1 ; c1ccc2c(c1)Oc1cc(-n3c4ccccc4c4ccccc43)cc3c1B2Sc1cc(-n2c4ccccc4c4ccccc42)ccc1-3 ; c1ccc2c(c1)Oc1cc(-c3ccccc3-n3c4ccccc4c4ccccc43)cc3c1B2Sc1cc(-n2c4ccccc4c4ccccc42)ccc1-3] 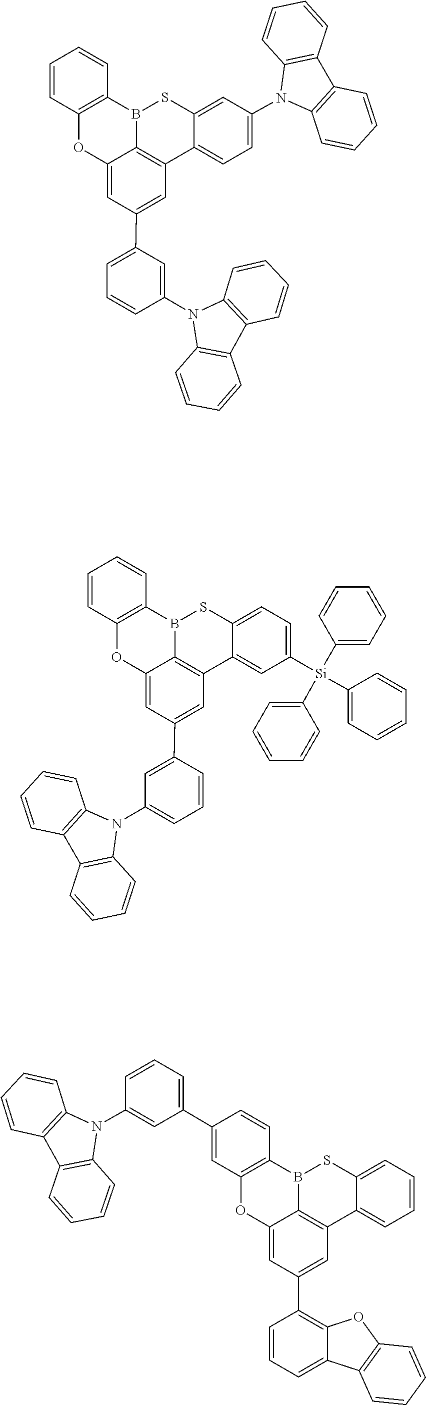 [SMILES: c1cc(-c2cc3c4c(c2)-c2ccc(-n5c6ccccc6c6ccccc65)cc2SB4c2ccccc2O3)cc(-n2c3ccccc3c3ccccc32)c1 ; c1ccc([Si](c2ccccc2)(c2ccccc2)c2ccc3c(c2)-c2cc(-c4cccc(-n5c6ccccc6c6ccccc65)c4)cc4c2B(S3)c2ccccc2O4)cc1 ; c1cc(-c2ccc3c(c2)Oc2cc(-c4cccc5c4oc4ccccc45)cc4c2B3Sc2ccccc2-4)cc(-n2c3ccccc3c3ccccc32)c1] 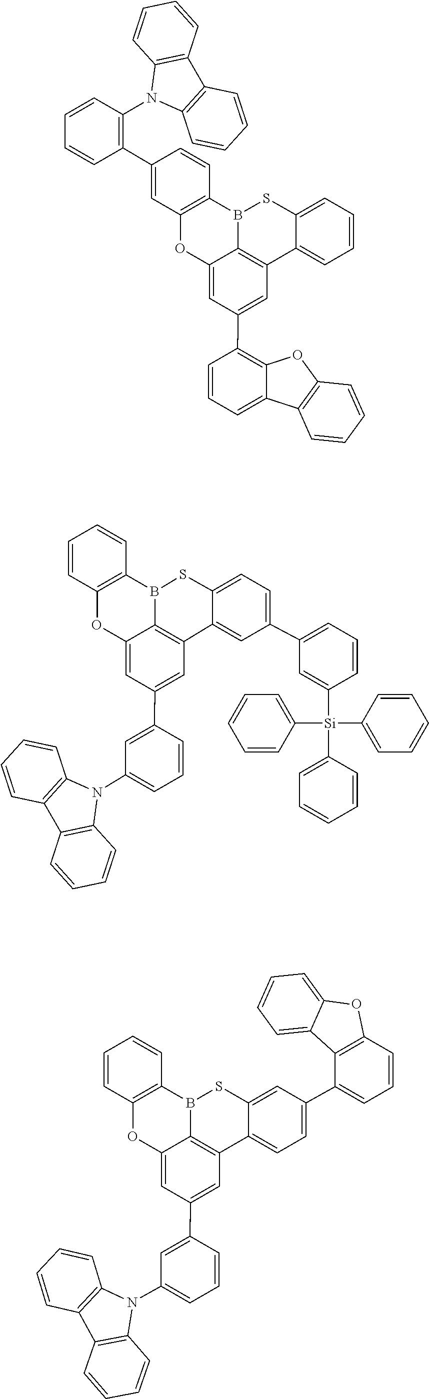 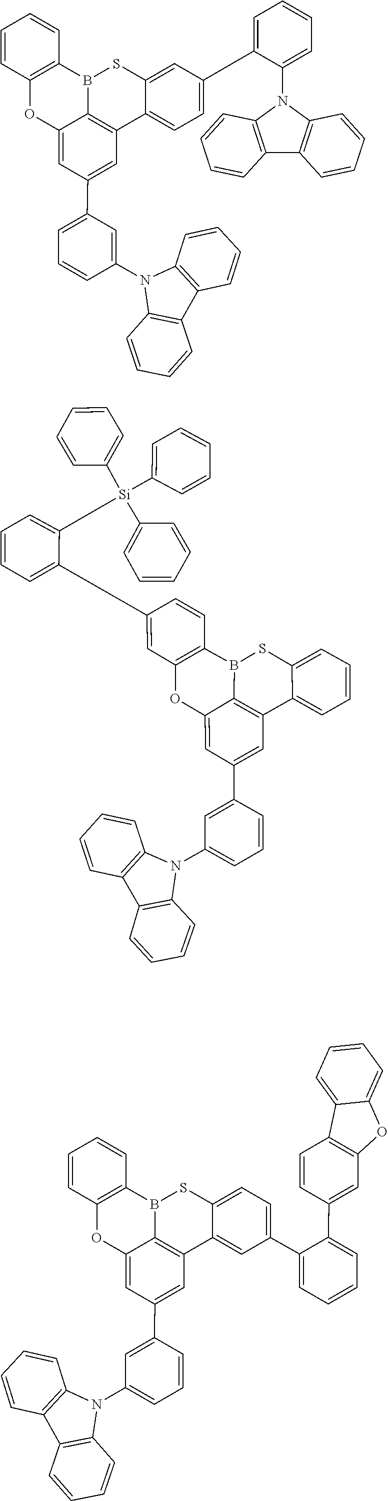 [SMILES: c1cc(-c2cc3c4c(c2)-c2ccc(-c5ccccc5-n5c6ccccc6c6ccccc65)cc2SB4c2ccccc2O3)cc(-n2c3ccccc3c3ccccc32)c1 ; c1ccc([Si](c2ccccc2)(c2ccccc2)c2ccccc2-c2ccc3c(c2)Oc2cc(-c4cccc(-n5c6ccccc6c6ccccc65)c4)cc4c2B3Sc2ccccc2-4)cc1 ; c1cc(-c2cc3c4c(c2)-c2cc(-c5ccccc5-c5ccc6c(c5)oc5ccccc56)ccc2SB4c2ccccc2O3)cc(-n2c3ccccc3c3ccccc32)c1] 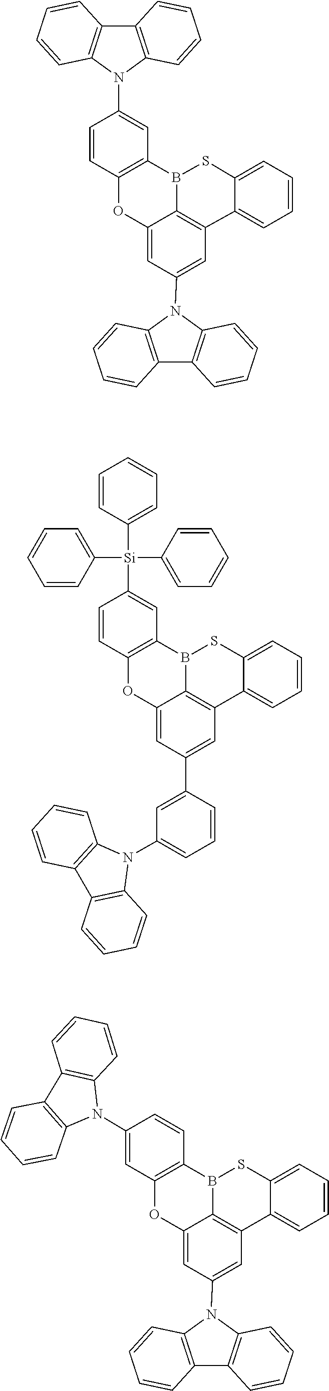 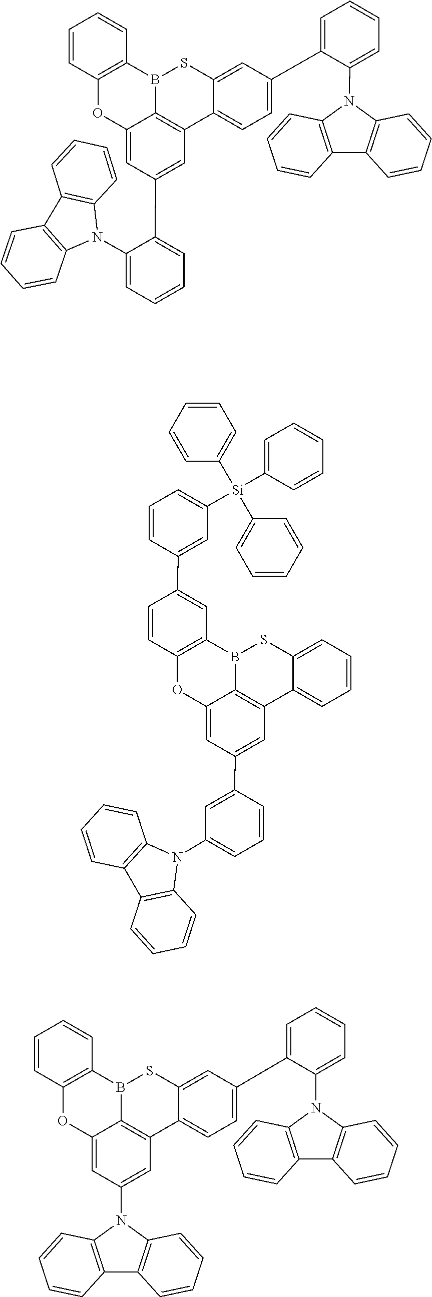 [SMILES: c1ccc2c(c1)Oc1cc(-c3ccccc3-n3c4ccccc4c4ccccc43)cc3c1B2Sc1cc(-c2ccccc2-n2c4ccccc4c4ccccc42)ccc1-3 ; c1ccc([Si](c2ccccc2)(c2ccccc2)c2cccc(-c3ccc4c(c3)B3Sc5ccccc5-c5cc(-c6cccc(-n7c8ccccc8c8ccccc87)c6)cc(c53)O4)c2)cc1 ; c1ccc2c(c1)Oc1cc(-n3c4ccccc4c4ccccc43)cc3c1B2Sc1cc(-c2ccccc2-n2c4ccccc4c4ccccc42)ccc1-3] 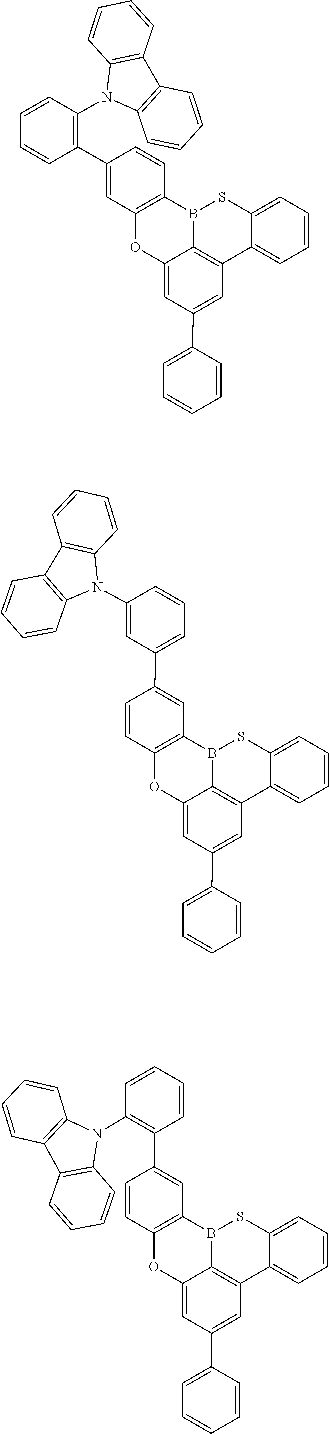 [SMILES: c1ccc(-c2cc3c4c(c2)-c2ccccc2SB4c2ccc(-c4ccccc4-n4c5ccccc5c5ccccc54)cc2O3)cc1 ; c1ccc(-c2cc3c4c(c2)-c2ccccc2SB4c2cc(-c4cccc(-n5c6ccccc6c6ccccc65)c4)ccc2O3)cc1 ; c1ccc(-c2cc3c4c(c2)-c2ccccc2SB4c2cc(-c4ccccc4-n4c5ccccc5c5ccccc54)ccc2O3)cc1] 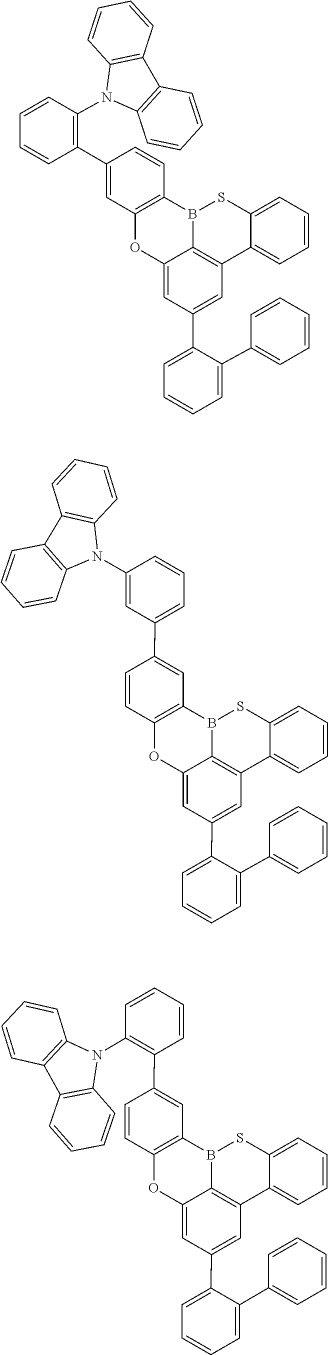 [SMILES: c1ccc(-c2ccccc2-c2cc3c4c(c2)-c2ccccc2SB4c2ccc(-c4ccccc4-n4c5ccccc5c5ccccc54)cc2O3)cc1 ; c1ccc(-c2ccccc2-c2cc3c4c(c2)-c2ccccc2SB4c2cc(-c4cccc(-n5c6ccccc6c6ccccc65)c4)ccc2O3)cc1 ; c1ccc(-c2ccccc2-c2cc3c4c(c2)-c2ccccc2SB4c2cc(-c4ccccc4-n4c5ccccc5c5ccccc54)ccc2O3)cc1] 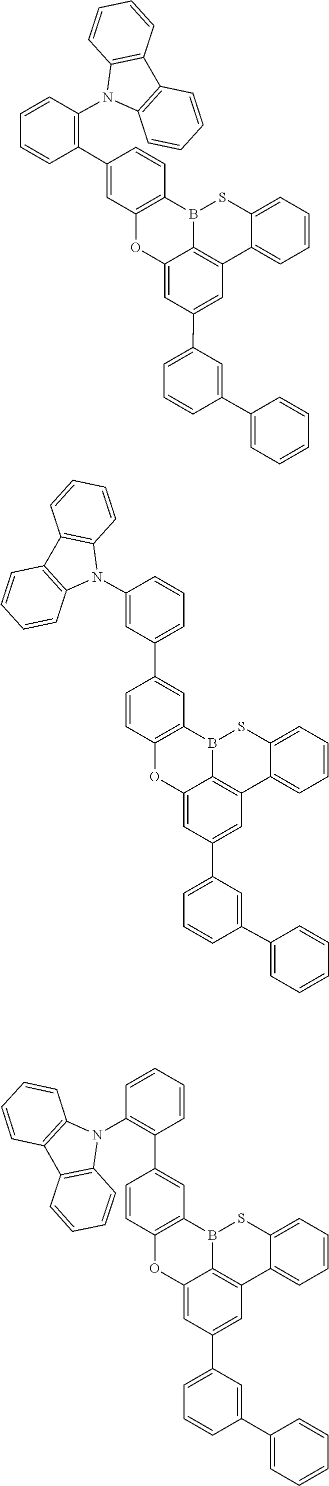 [SMILES: c1ccc(-c2cccc(-c3cc4c5c(c3)-c3ccccc3SB5c3ccc(-c5ccccc5-n5c6ccccc6c6ccccc65)cc3O4)c2)cc1 ; c1ccc(-c2cccc(-c3cc4c5c(c3)-c3ccccc3SB5c3cc(-c5cccc(-n6c7ccccc7c7ccccc76)c5)ccc3O4)c2)cc1 ; c1ccc(-c2cccc(-c3cc4c5c(c3)-c3ccccc3SB5c3cc(-c5ccccc5-n5c6ccccc6c6ccccc65)ccc3O4)c2)cc1] 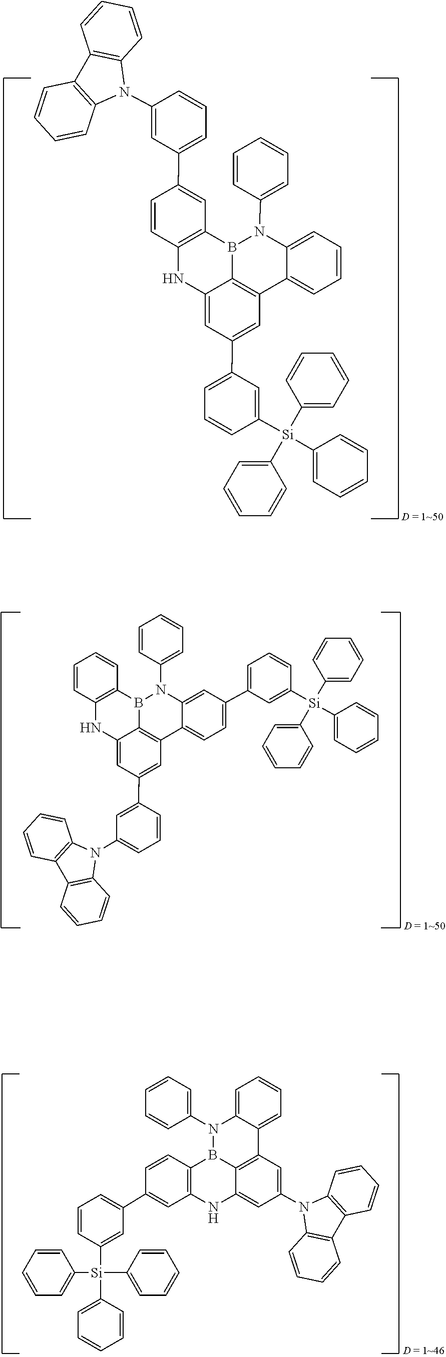 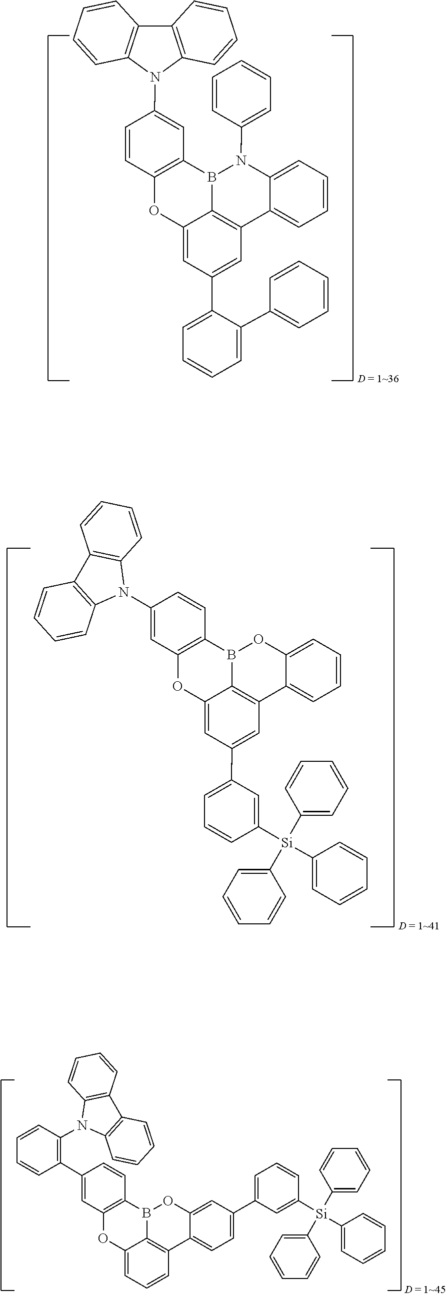 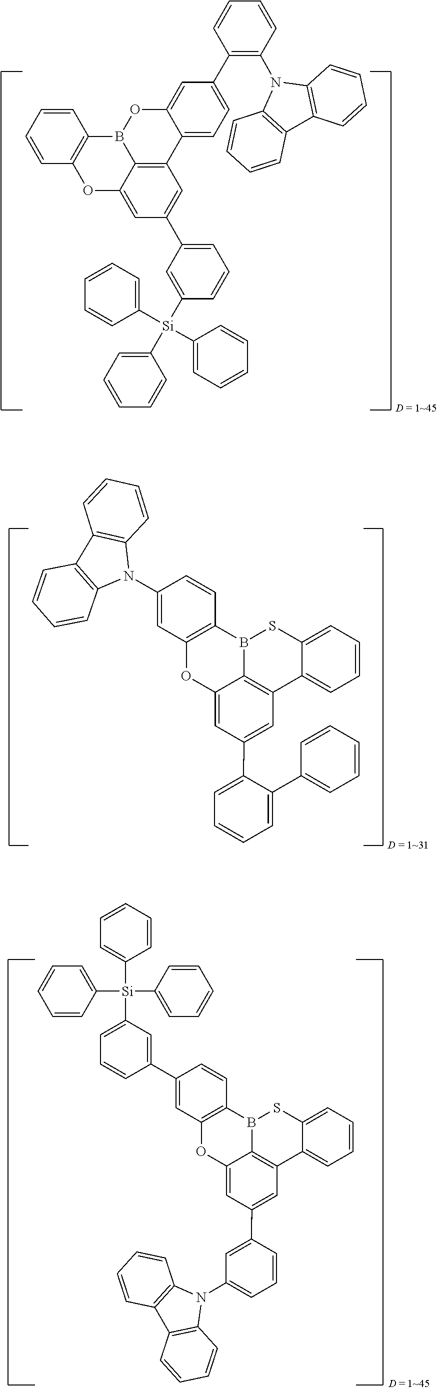 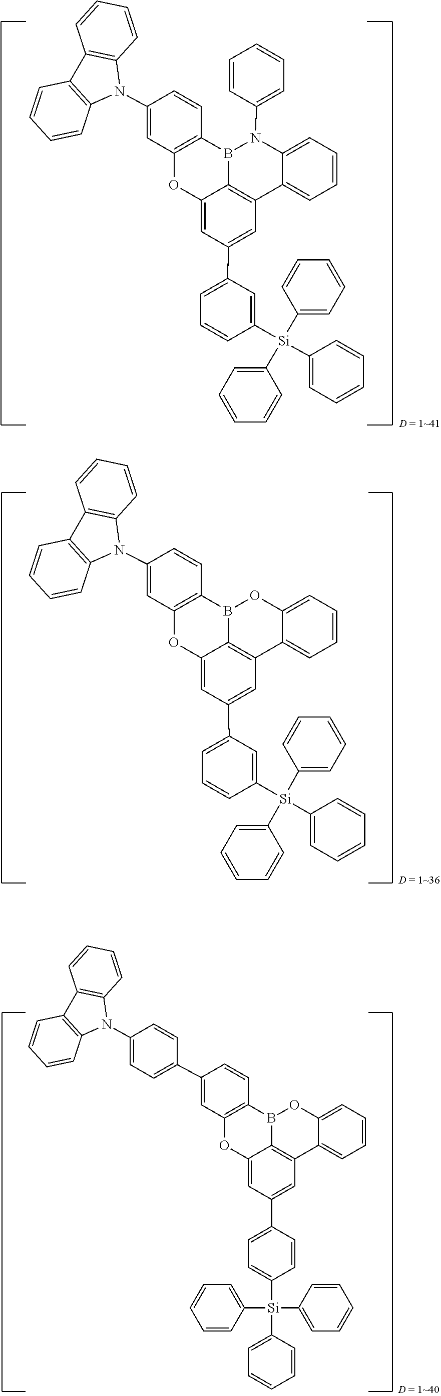 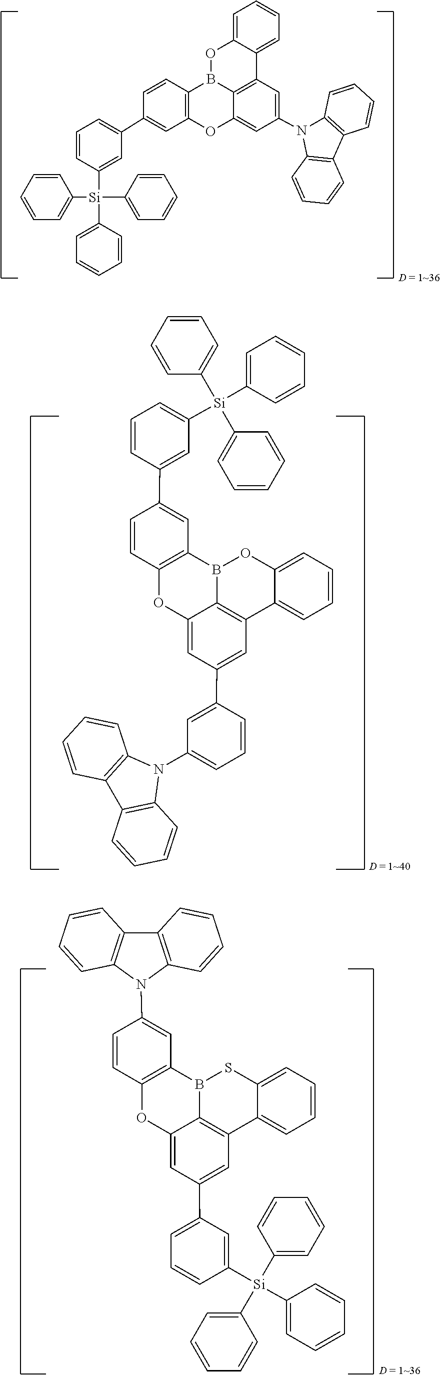 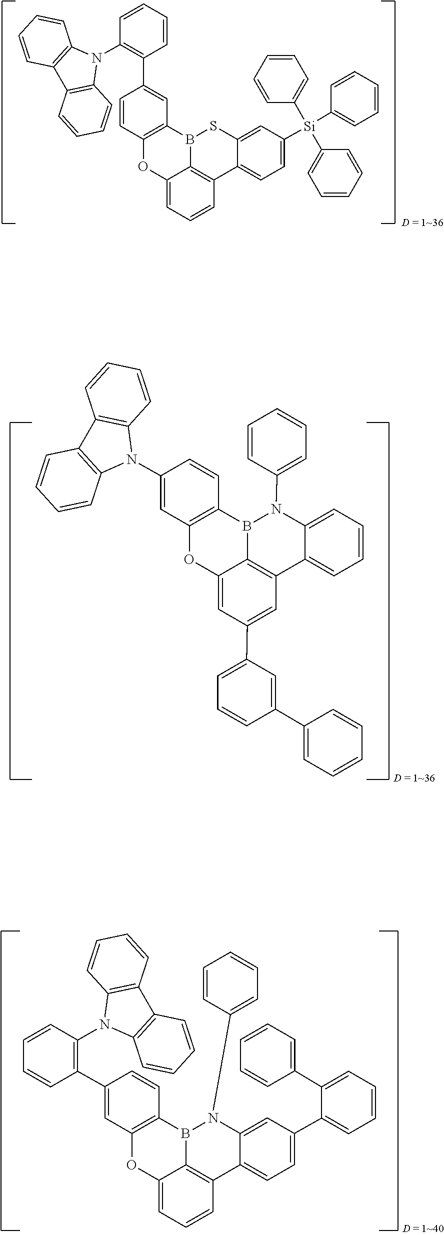 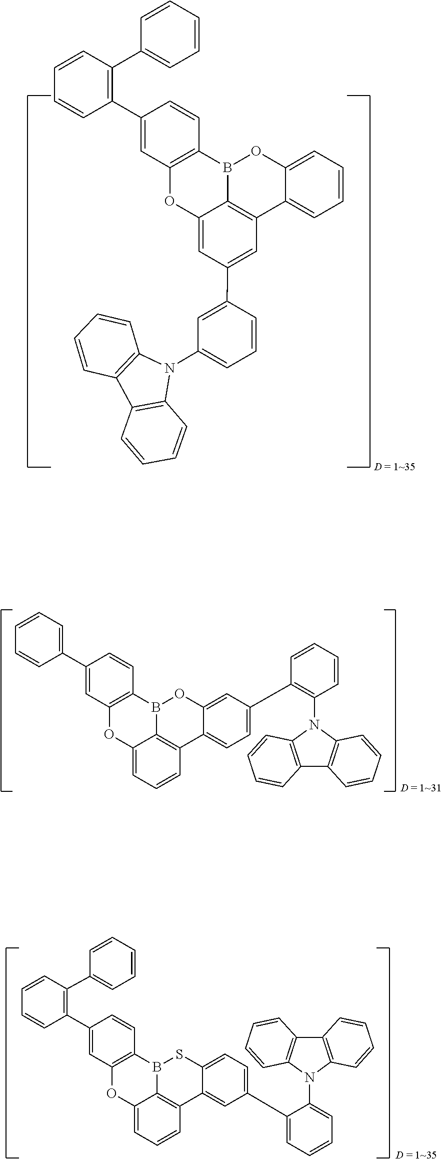 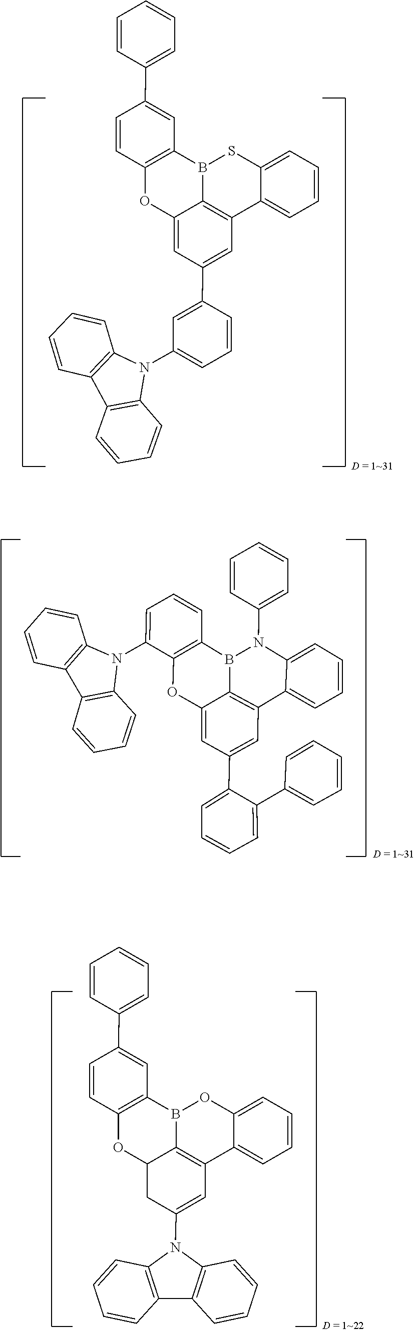 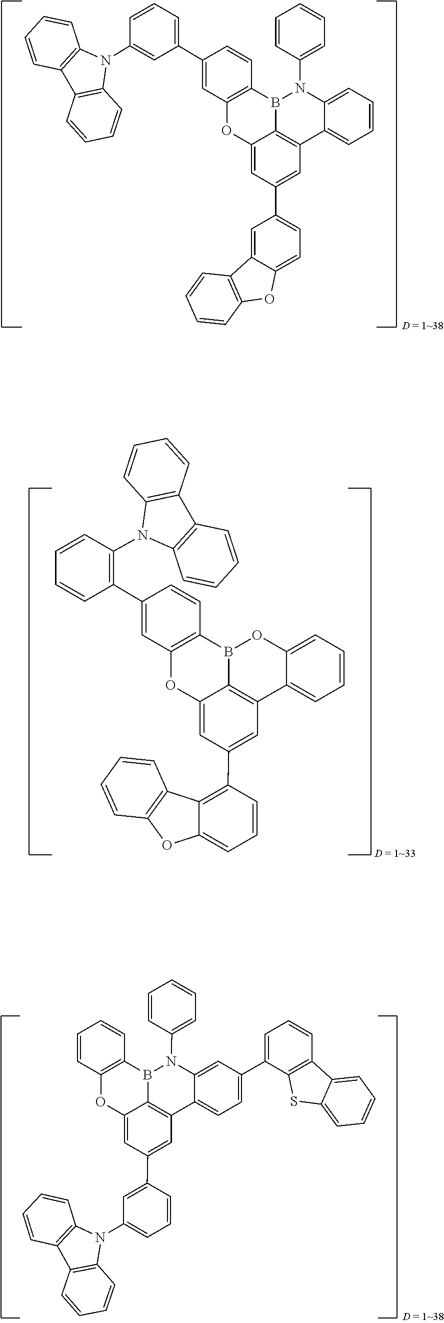 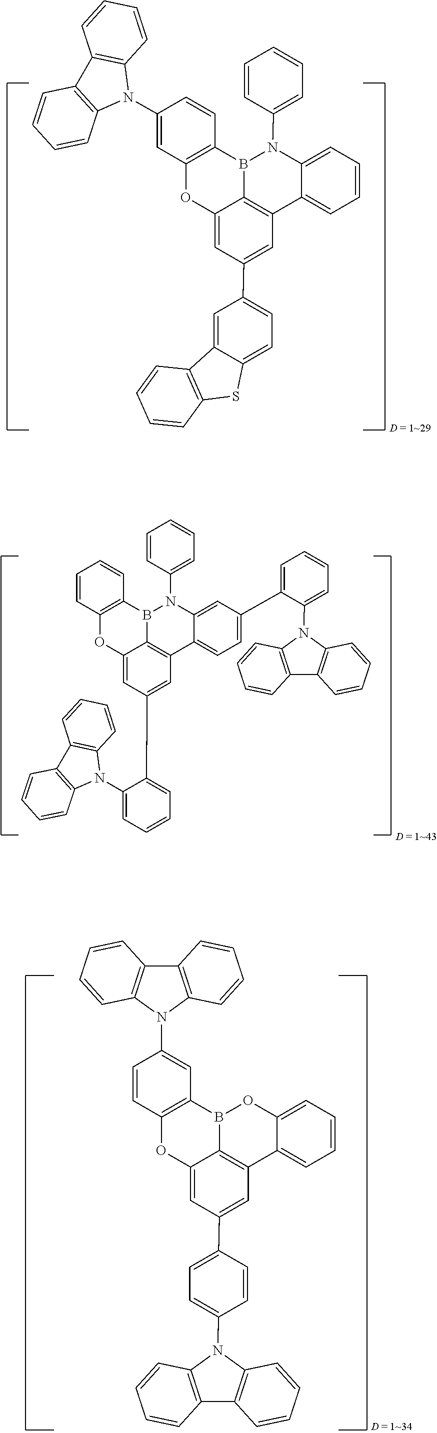 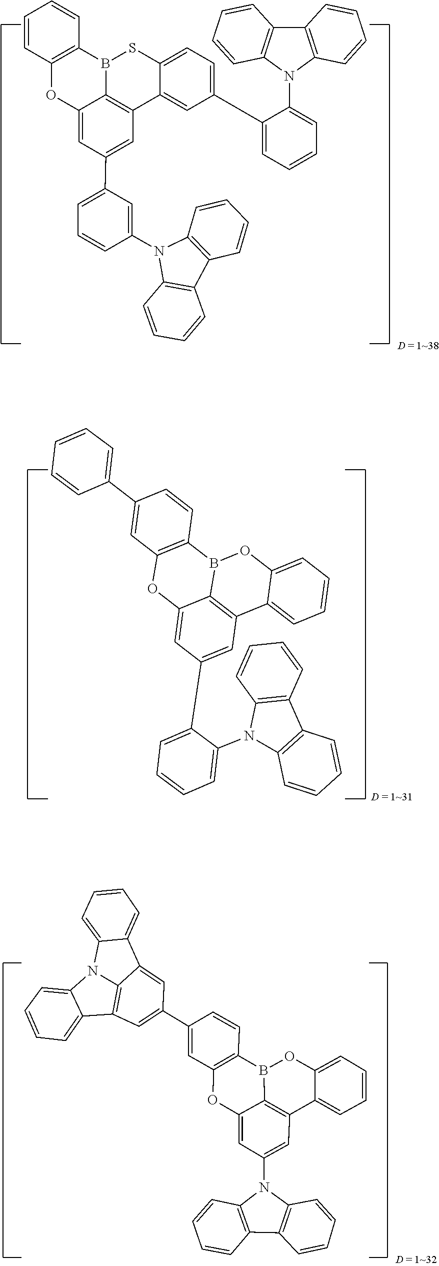 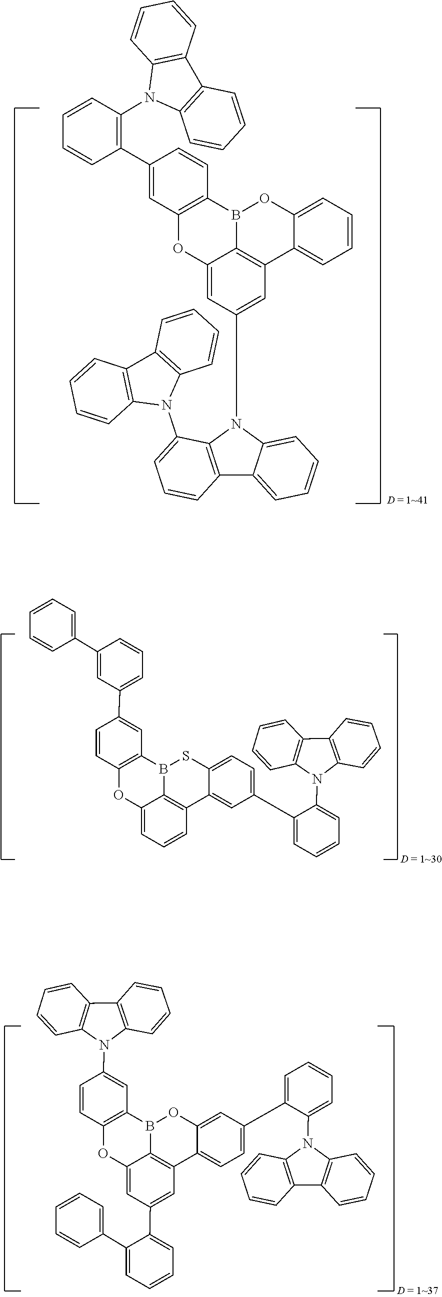 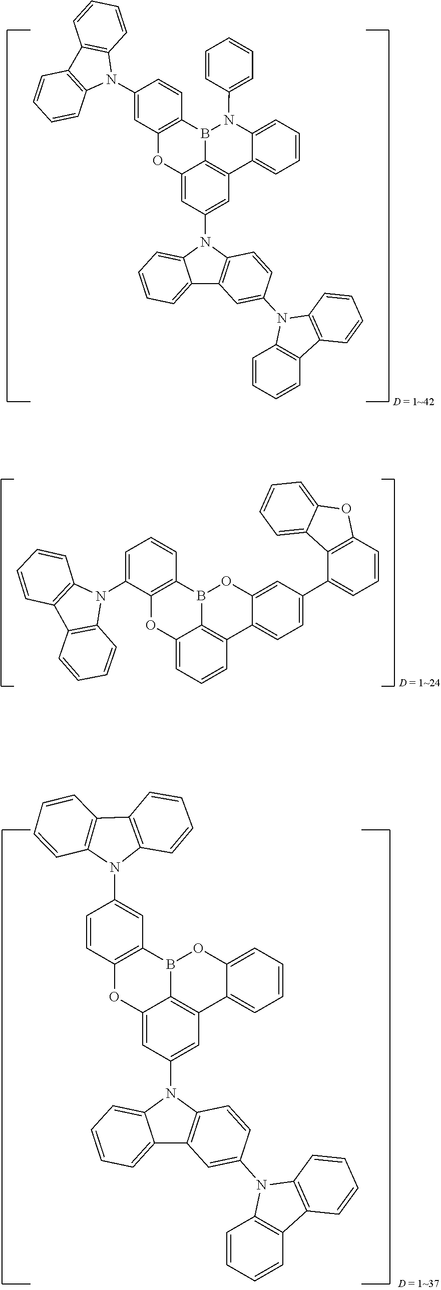 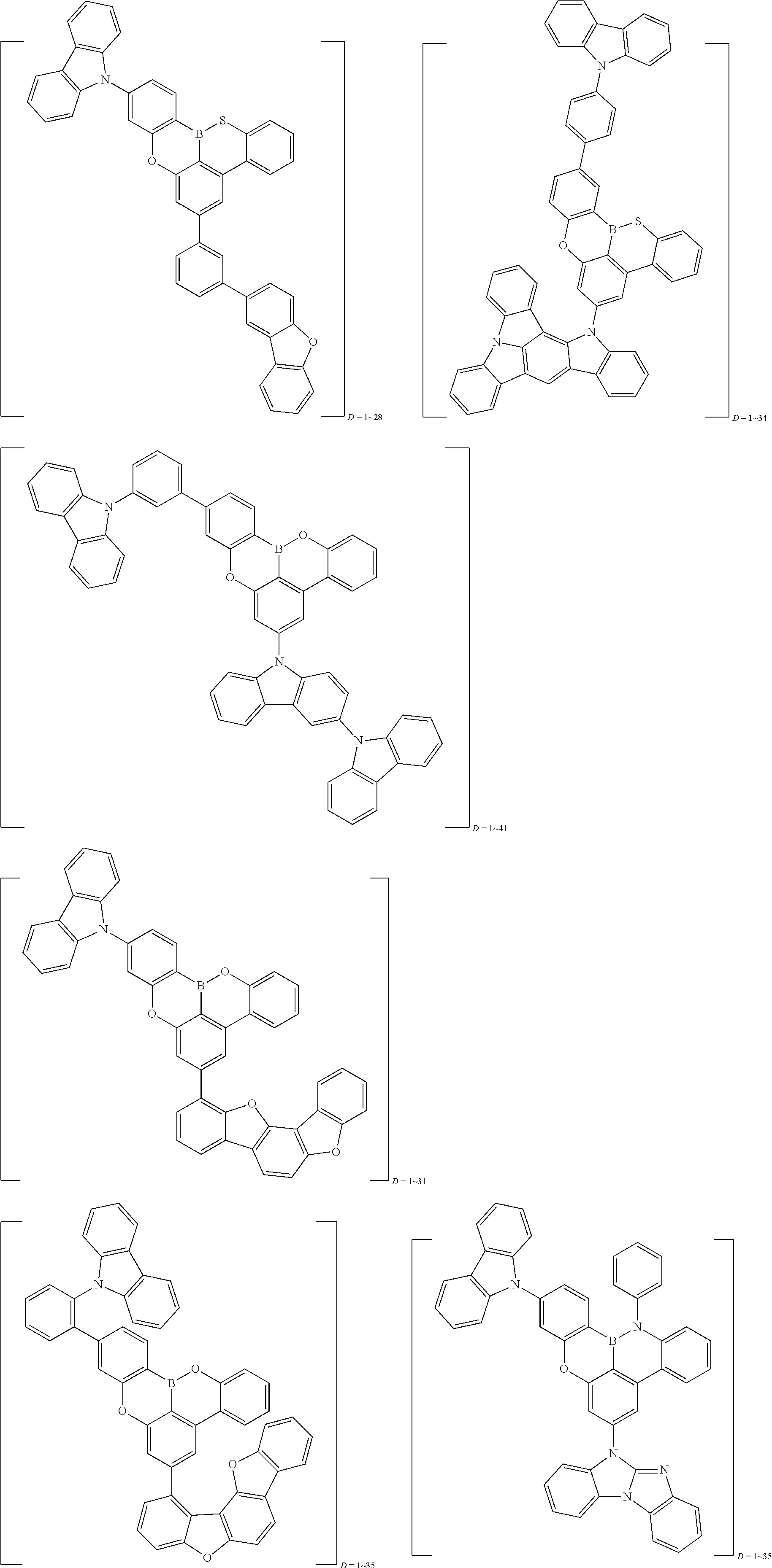 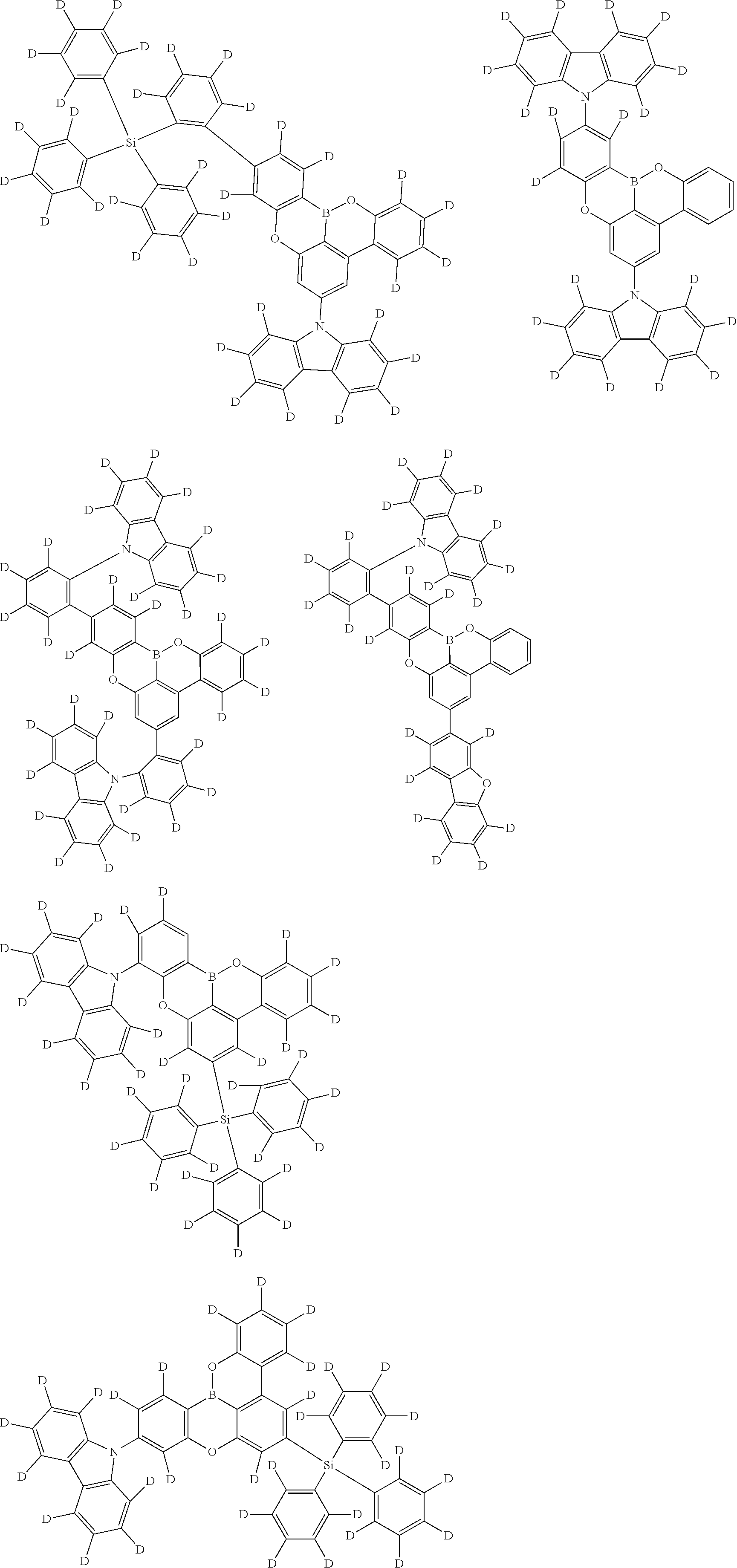 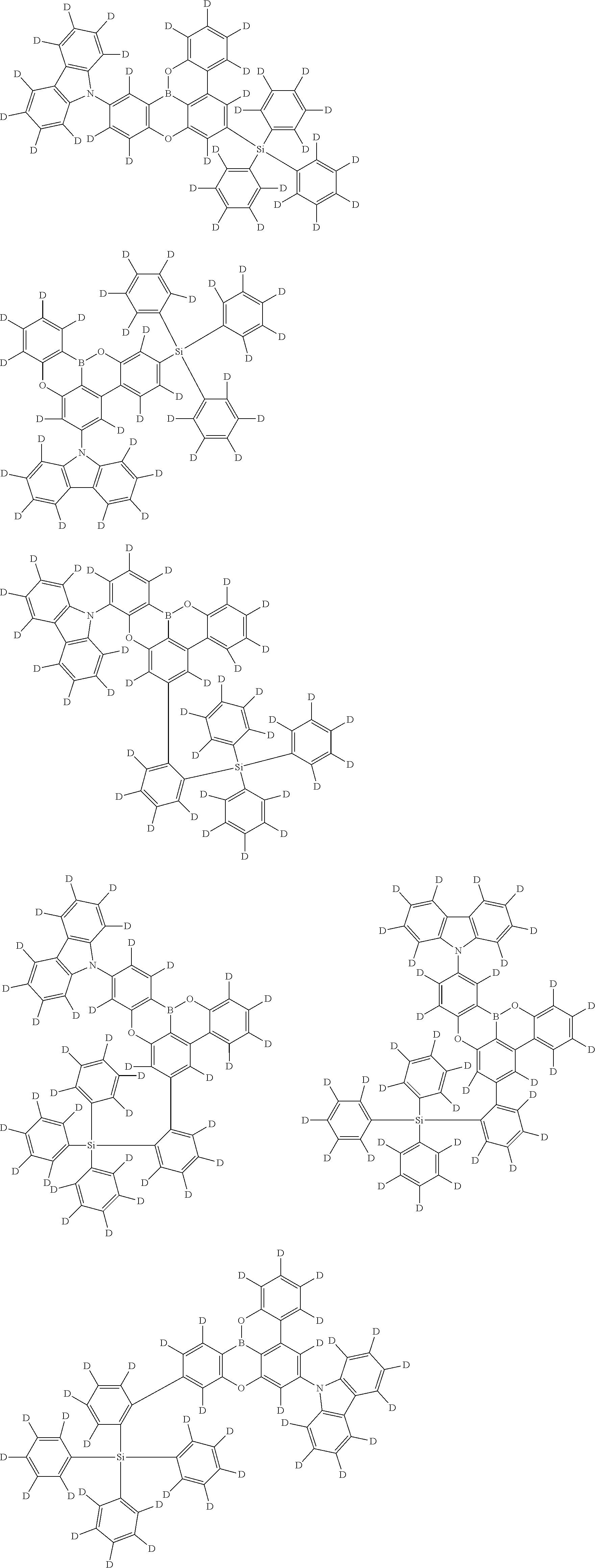 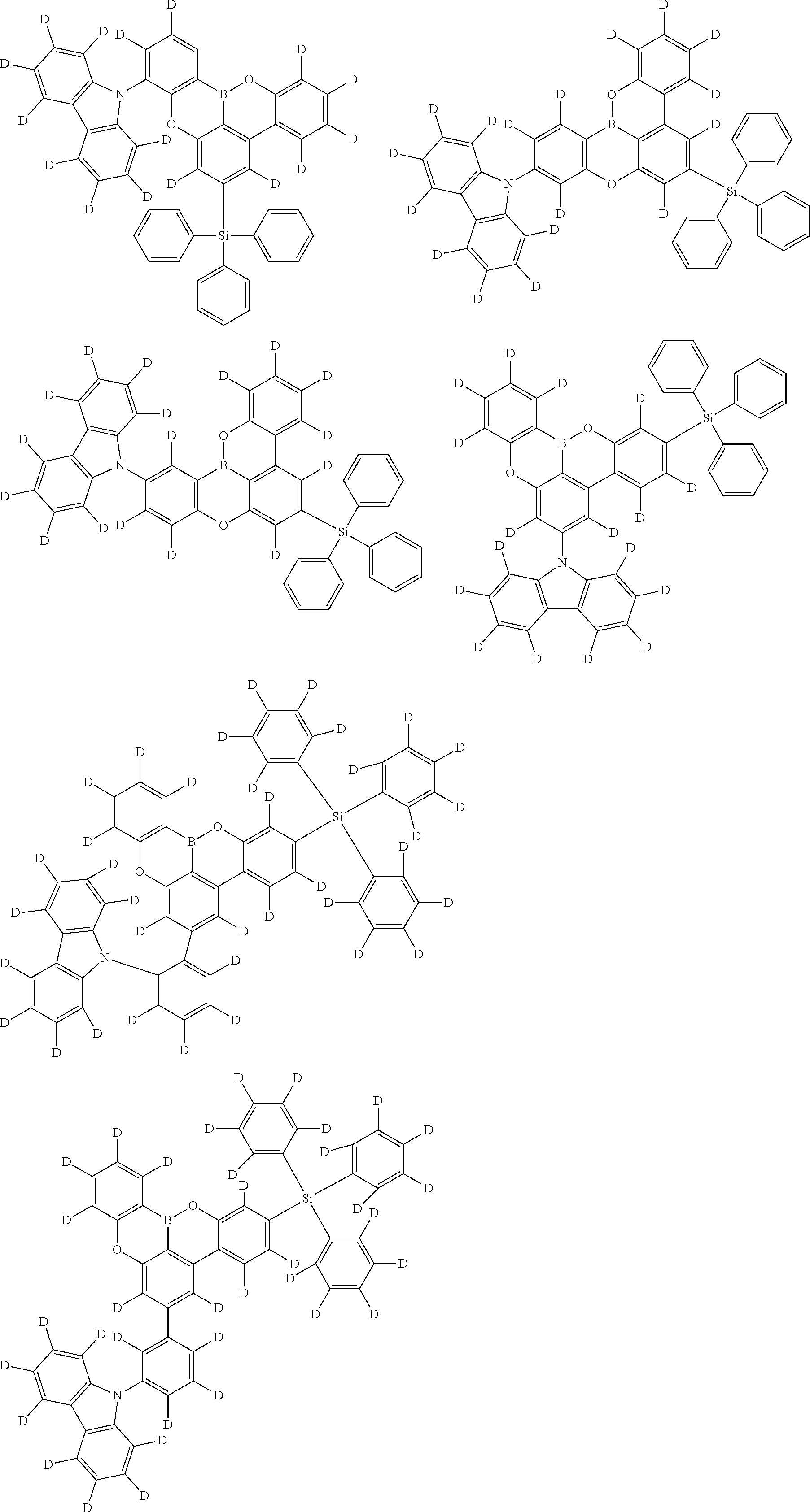 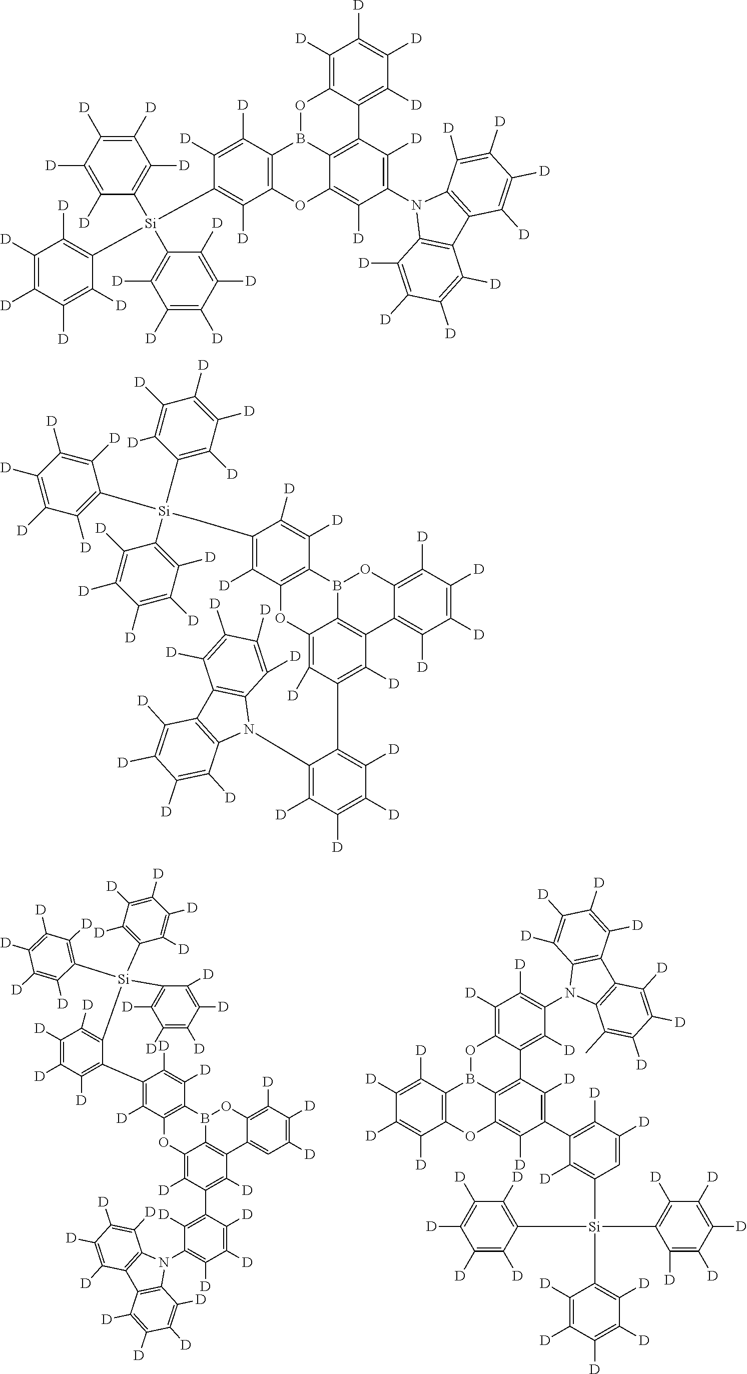 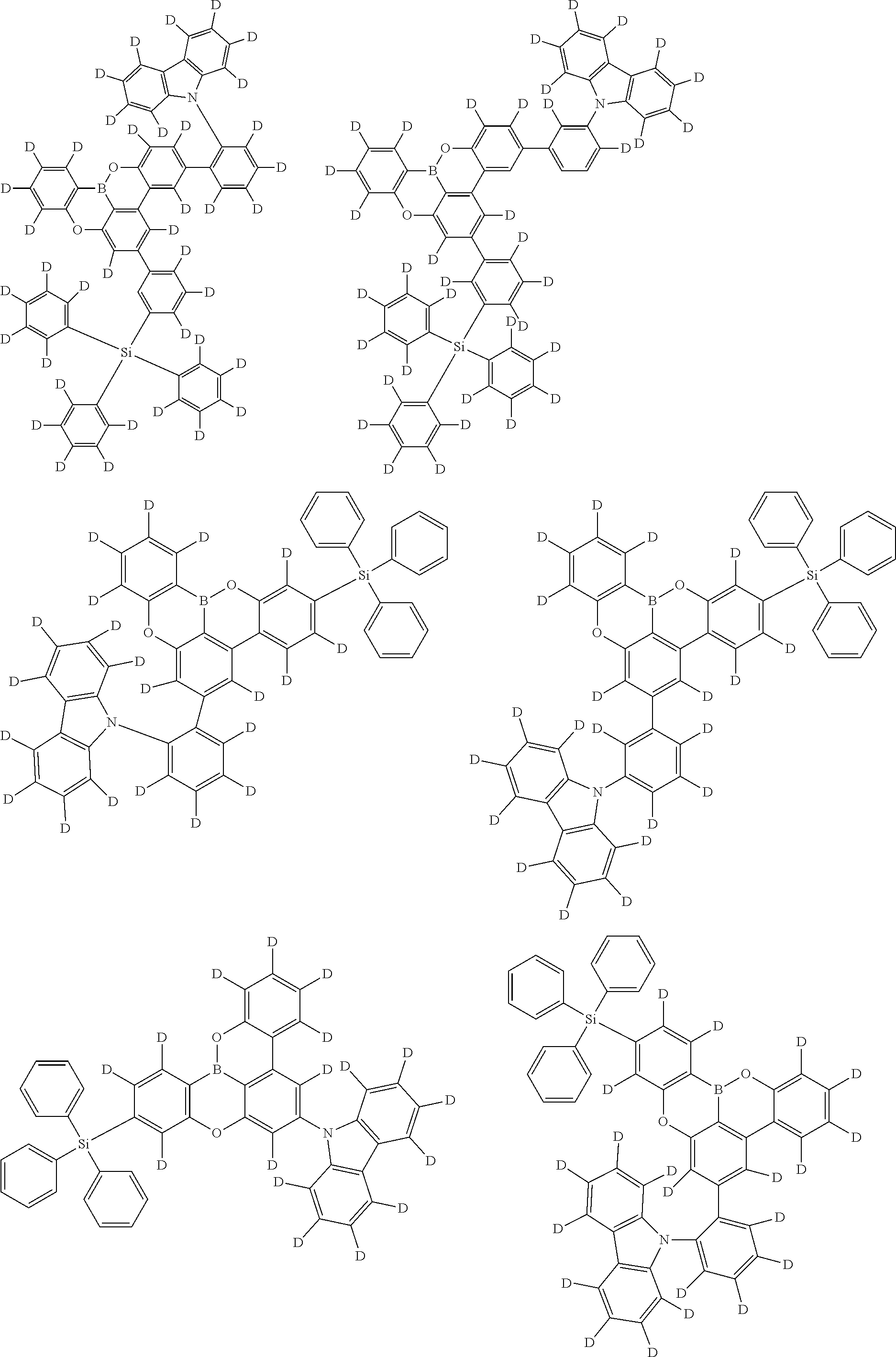 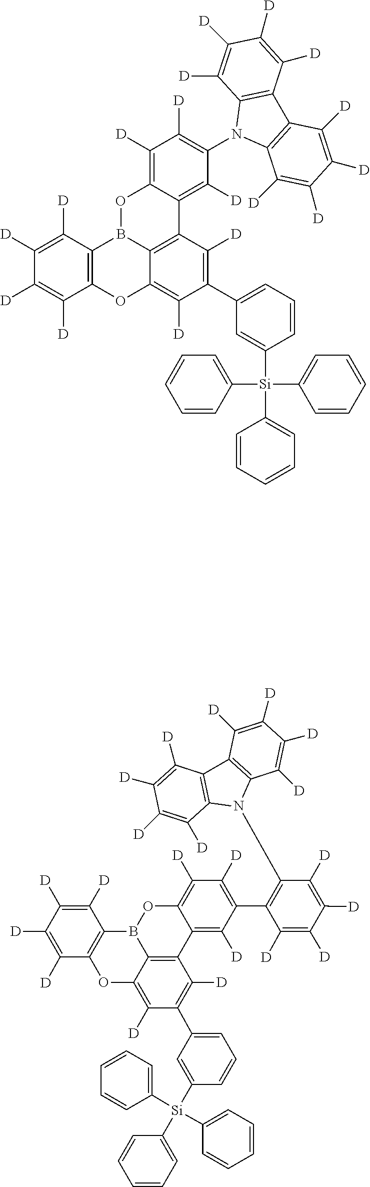 [SMILES: [2H]c1c([2H])c([2H])c2c(c1[2H])Oc1c([2H])c(-c3cccc([Si](c4ccccc4)(c4ccccc4)c4ccccc4)c3)c([2H])c3c1B2Oc1c([2H])c([2H])c(-n2c4c([2H])c([2H])c([2H])c([2H])c4c4c([2H])c([2H])c([2H])c([2H])c42)c([2H])c1-3 ; [2H]c1c([2H])c([2H])c2c(c1[2H])Oc1c([2H])c(-c3cccc([Si](c4ccccc4)(c4ccccc4)c4ccccc4)c3)c([2H])c3c1B2Oc1c([2H])c([2H])c(-c2c([2H])c([2H])c([2H])c([2H])c2-n2c4c([2H])c([2H])c([2H])c([2H])c4c4c([2H])c([2H])c([2H])c([2H])c42)c([2H])c1-3] 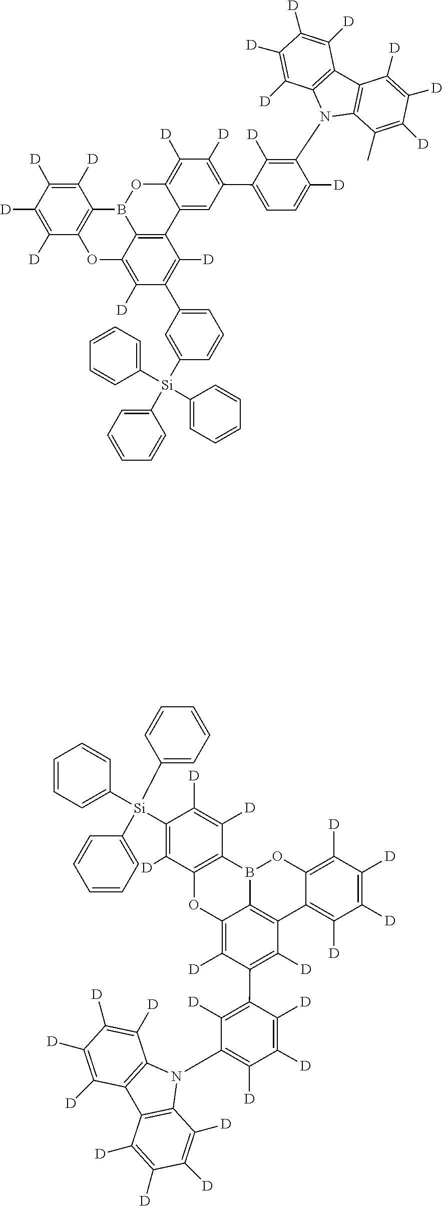 [SMILES: [2H]c1ccc(-c2cc3c(c([2H])c2[2H])OB2c4c([2H])c([2H])c([2H])c([2H])c4Oc4c([2H])c(-c5cccc([Si](c6ccccc6)(c6ccccc6)c6ccccc6)c5)c([2H])c-3c42)c([2H])c1-n1c2c([2H])c([2H])c([2H])c([2H])c2c2c([2H])c([2H])c([2H])c(C)c21 ; [2H]c1c([2H])c([2H])c2c(c1[2H])OB1c3c([2H])c([2H])c([Si](c4ccccc4)(c4ccccc4)c4ccccc4)c([2H])c3Oc3c([2H])c(-c4c([2H])c([2H])c([2H])c(-n5c6c([2H])c([2H])c([2H])c([2H])c6c6c([2H])c([2H])c([2H])c([2H])c65)c4[2H])c([2H])c-2c31] 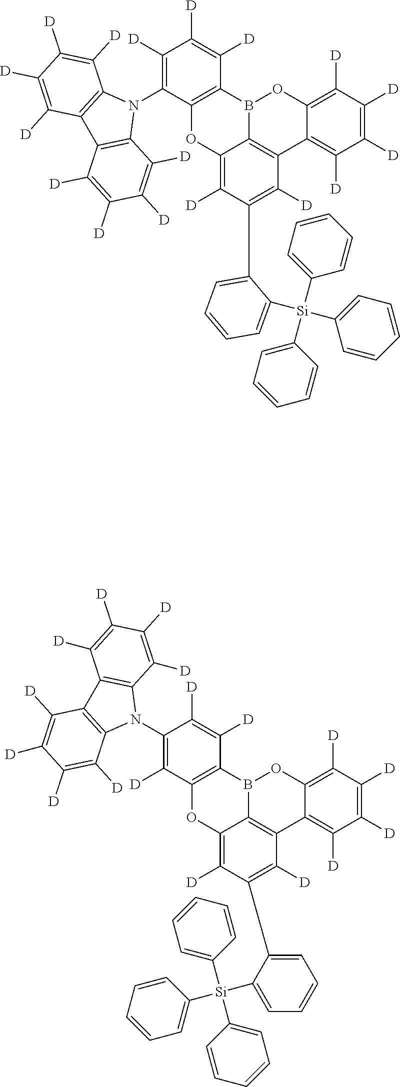 [SMILES: [2H]c1c([2H])c([2H])c2c(c1[2H])OB1c3c([2H])c([2H])c([2H])c(-n4c5c([2H])c([2H])c([2H])c([2H])c5c5c([2H])c([2H])c([2H])c([2H])c54)c3Oc3c([2H])c(-c4ccccc4[Si](c4ccccc4)(c4ccccc4)c4ccccc4)c([2H])c-2c31 ; [2H]c1c([2H])c([2H])c2c(c1[2H])OB1c3c([2H])c([2H])c(-n4c5c([2H])c([2H])c([2H])c([2H])c5c5c([2H])c([2H])c([2H])c([2H])c54)c([2H])c3Oc3c([2H])c(-c4ccccc4[Si](c4ccccc4)(c4ccccc4)c4ccccc4)c([2H])c-2c31] 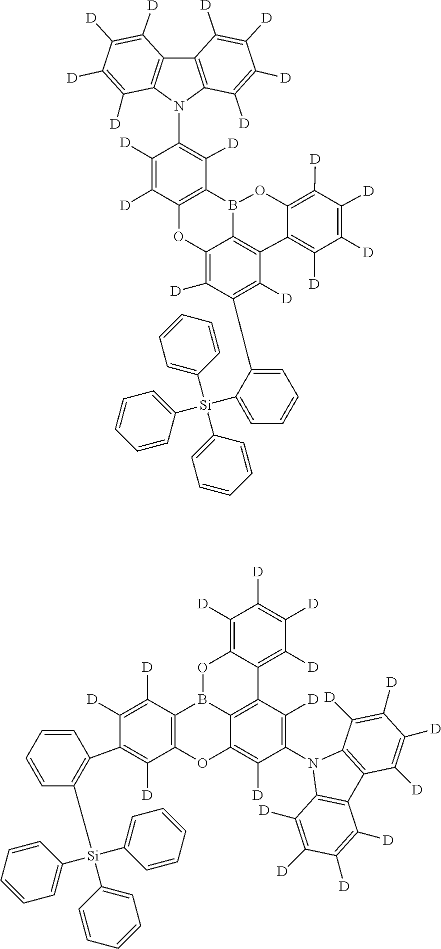 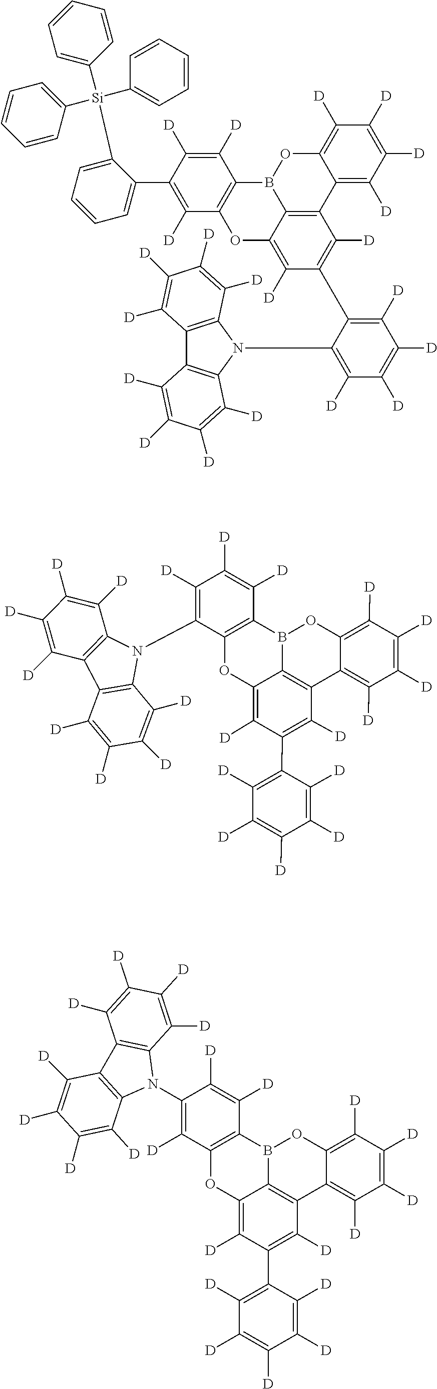 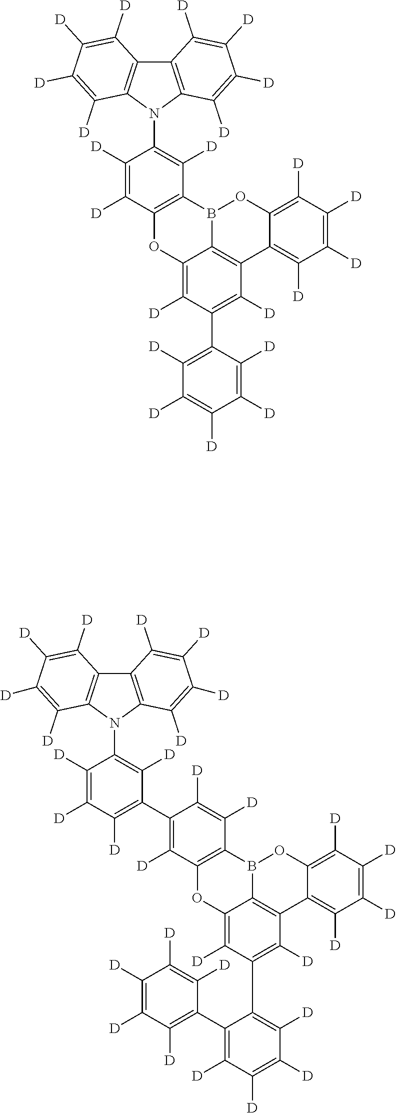 [SMILES: [2H]c1c([2H])c([2H])c(-c2c([2H])c3c4c(c2[2H])-c2c([2H])c([2H])c([2H])c([2H])c2OB4c2c([2H])c(-n4c5c([2H])c([2H])c([2H])c([2H])c5c5c([2H])c([2H])c([2H])c([2H])c54)c([2H])c([2H])c2O3)c([2H])c1[2H] ; [2H]c1c([2H])c([2H])c(-c2c([2H])c([2H])c([2H])c([2H])c2-c2c([2H])c3c4c(c2[2H])-c2c([2H])c([2H])c([2H])c([2H])c2OB4c2c([2H])c([2H])c(-c4c([2H])c([2H])c([2H])c(-n5c6c([2H])c([2H])c([2H])c([2H])c6c6c([2H])c([2H])c([2H])c([2H])c65)c4[2H])c([2H])c2O3)c([2H])c1[2H]] 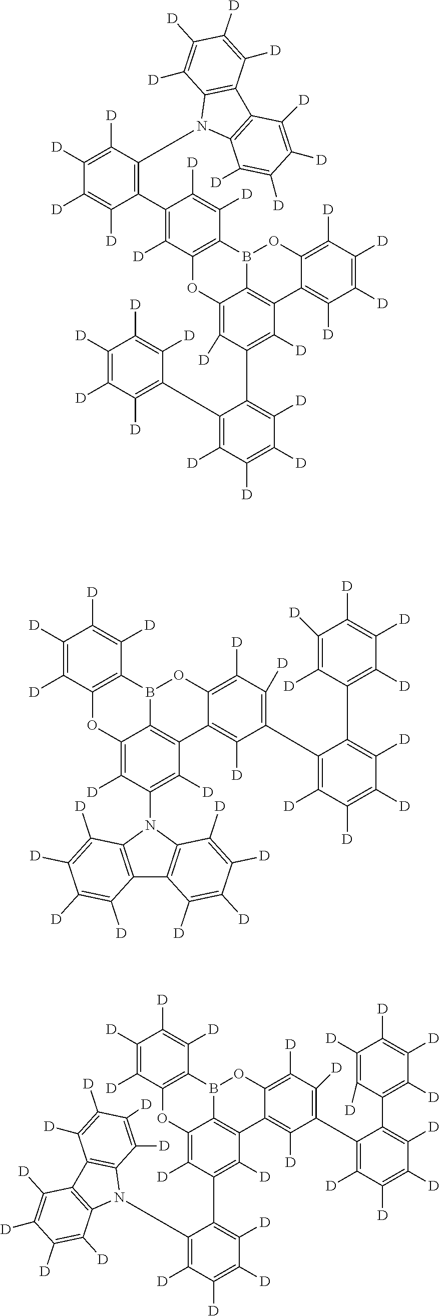 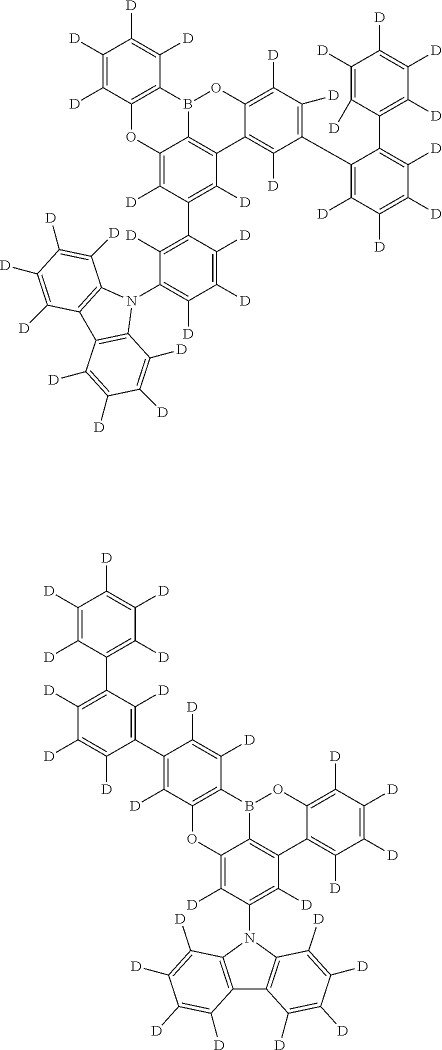 [SMILES: [2H]c1c([2H])c([2H])c(-c2c([2H])c([2H])c([2H])c([2H])c2-c2c([2H])c([2H])c3c(c2[2H])-c2c([2H])c(-c4c([2H])c([2H])c([2H])c(-n5c6c([2H])c([2H])c([2H])c([2H])c6c6c([2H])c([2H])c([2H])c([2H])c65)c4[2H])c([2H])c4c2B(O3)c2c([2H])c([2H])c([2H])c([2H])c2O4)c([2H])c1[2H] ; [2H]c1c([2H])c([2H])c(-c2c([2H])c([2H])c([2H])c(-c3c([2H])c([2H])c4c(c3[2H])Oc3c([2H])c(-n5c6c([2H])c([2H])c([2H])c([2H])c6c6c([2H])c([2H])c([2H])c([2H])c65)c([2H])c5c3B4Oc3c([2H])c([2H])c([2H])c([2H])c3-5)c2[2H])c([2H])c1[2H]] 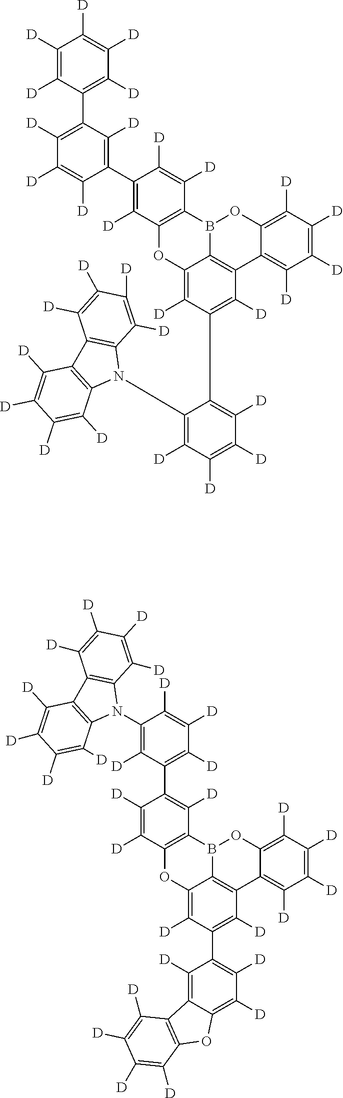 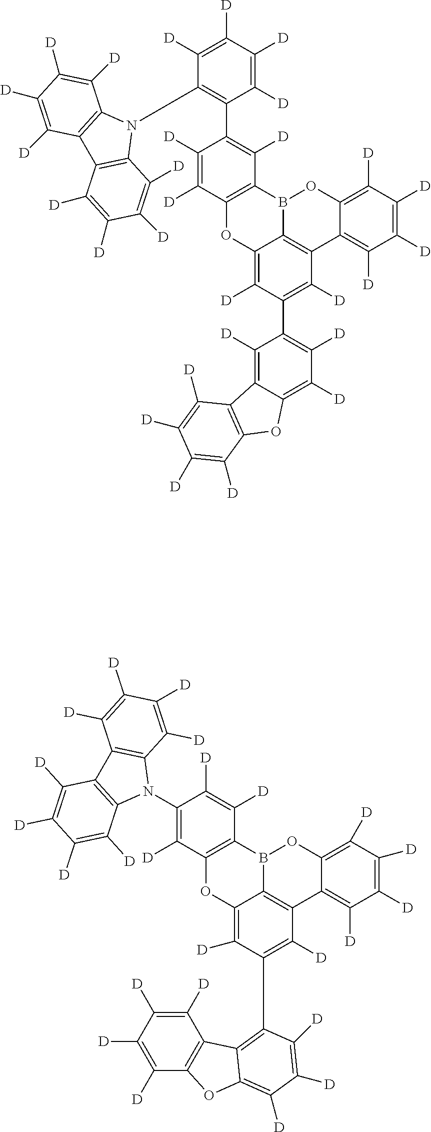 [SMILES: [2H]c1c([2H])c([2H])c2c(c1[2H])OB1c3c([2H])c(-c4c([2H])c([2H])c([2H])c([2H])c4-n4c5c([2H])c([2H])c([2H])c([2H])c5c5c([2H])c([2H])c([2H])c([2H])c54)c([2H])c([2H])c3Oc3c([2H])c(-c4c([2H])c([2H])c5oc6c([2H])c([2H])c([2H])c([2H])c6c5c4[2H])c([2H])c-2c31 ; [2H]c1c([2H])c([2H])c2c(c1[2H])OB1c3c([2H])c([2H])c(-n4c5c([2H])c([2H])c([2H])c([2H])c5c5c([2H])c([2H])c([2H])c([2H])c54)c([2H])c3Oc3c([2H])c(-c4c([2H])c([2H])c([2H])c5oc6c([2H])c([2H])c([2H])c([2H])c6c45)c([2H])c-2c31] 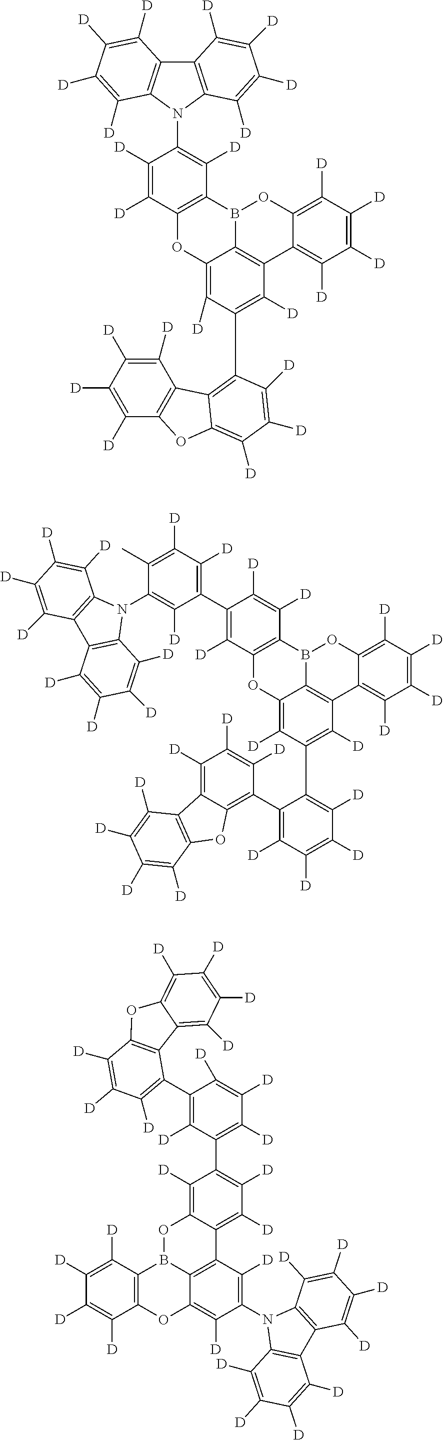 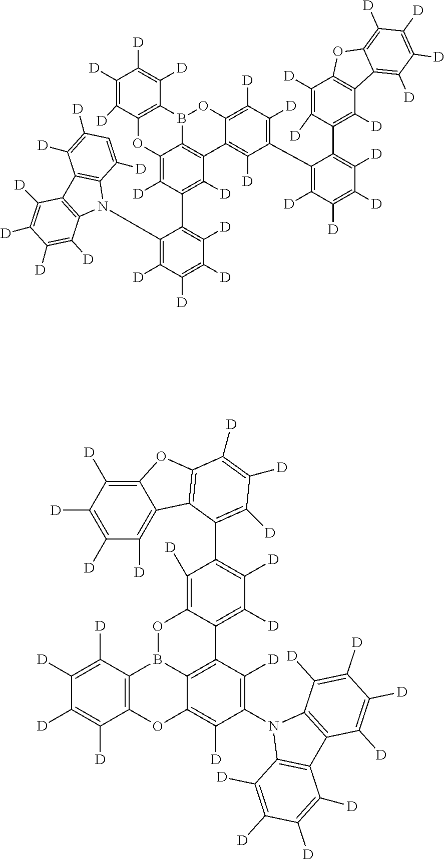 [SMILES: [2H]c1cc([2H])c2c(c1[2H])c1c([2H])c([2H])c([2H])c([2H])c1n2-c1c([2H])c([2H])c([2H])c([2H])c1-c1c([2H])c2c3c(c1[2H])-c1c([2H])c(-c4c([2H])c([2H])c([2H])c([2H])c4-c4c([2H])c([2H])c5oc6c([2H])c([2H])c([2H])c([2H])c6c5c4[2H])c([2H])c([2H])c1OB3c1c([2H])c([2H])c([2H])c([2H])c1O2 ; [2H]c1c([2H])c([2H])c2c(c1[2H])Oc1c([2H])c(-n3c4c([2H])c([2H])c([2H])c([2H])c4c4c([2H])c([2H])c([2H])c([2H])c43)c([2H])c3c1B2Oc1c([2H])c(-c2c([2H])c([2H])c([2H])c4oc5c([2H])c([2H])c([2H])c([2H])c5c24)c([2H])c([2H])c1-3] 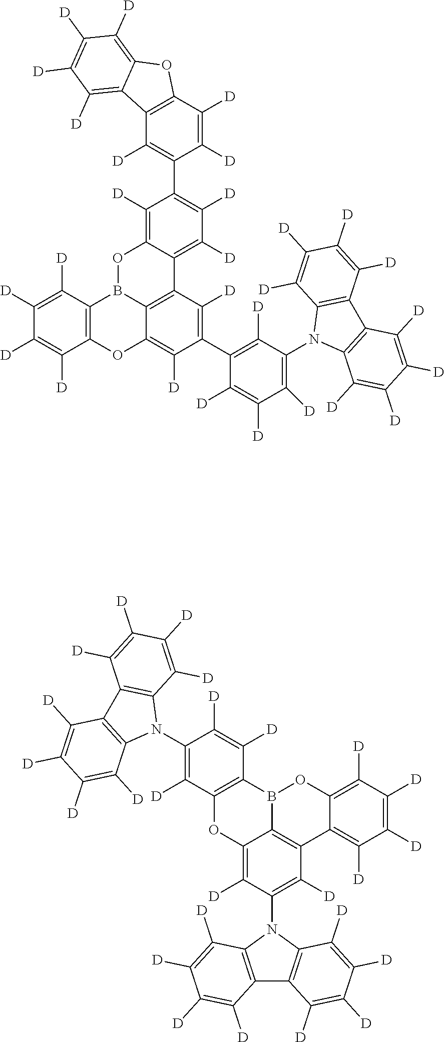 [SMILES: [2H]c1c([2H])c([2H])c2c(c1[2H])Oc1c([2H])c(-c3c([2H])c([2H])c([2H])c(-n4c5c([2H])c([2H])c([2H])c([2H])c5c5c([2H])c([2H])c([2H])c([2H])c54)c3[2H])c([2H])c3c1B2Oc1c([2H])c(-c2c([2H])c([2H])c4oc5c([2H])c([2H])c([2H])c([2H])c5c4c2[2H])c([2H])c([2H])c1-3 ; [2H]c1c([2H])c([2H])c2c(c1[2H])OB1c3c([2H])c([2H])c(-n4c5c([2H])c([2H])c([2H])c([2H])c5c5c([2H])c([2H])c([2H])c([2H])c54)c([2H])c3Oc3c([2H])c(-n4c5c([2H])c([2H])c([2H])c([2H])c5c5c([2H])c([2H])c([2H])c([2H])c54)c([2H])c-2c31] 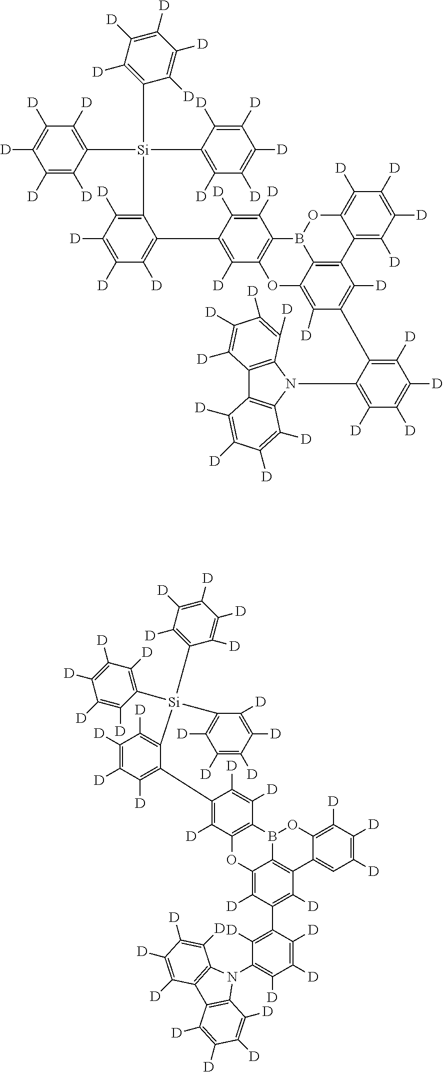 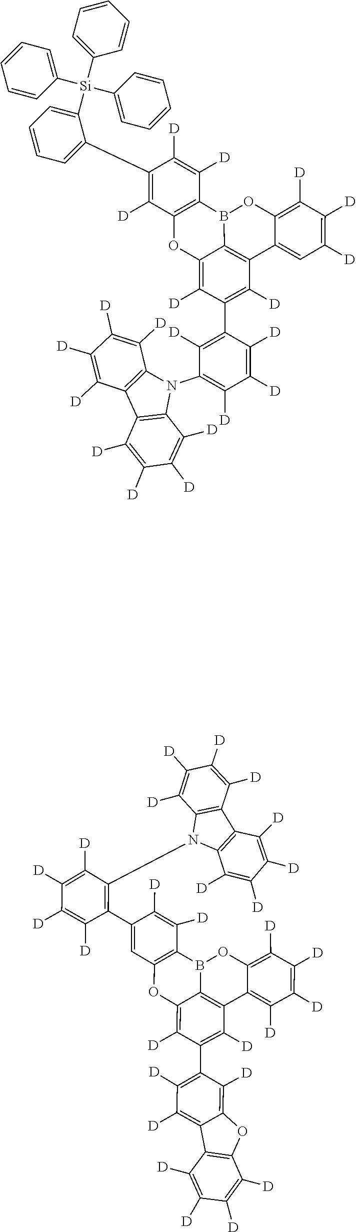 [SMILES: [2H]c1cc2c(c([2H])c1[2H])OB1c3c([2H])c([2H])c(-c4ccccc4[Si](c4ccccc4)(c4ccccc4)c4ccccc4)c([2H])c3Oc3c([2H])c(-c4c([2H])c([2H])c([2H])c(-n5c6c([2H])c([2H])c([2H])c([2H])c6c6c([2H])c([2H])c([2H])c([2H])c65)c4[2H])c([2H])c-2c31 ; [2H]c1c(-c2c([2H])c([2H])c([2H])c([2H])c2-n2c3c([2H])c([2H])c([2H])c([2H])c3c3c([2H])c([2H])c([2H])c([2H])c32)cc2c(c1[2H])B1Oc3c([2H])c([2H])c([2H])c([2H])c3-c3c([2H])c(-c4c([2H])c([2H])c5c(oc6c([2H])c([2H])c([2H])c([2H])c65)c4[2H])c([2H])c(c31)O2] 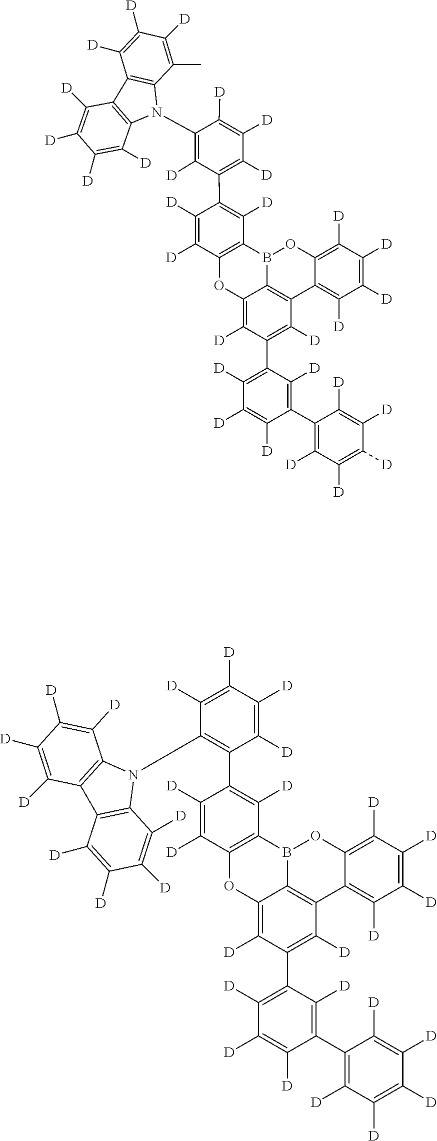 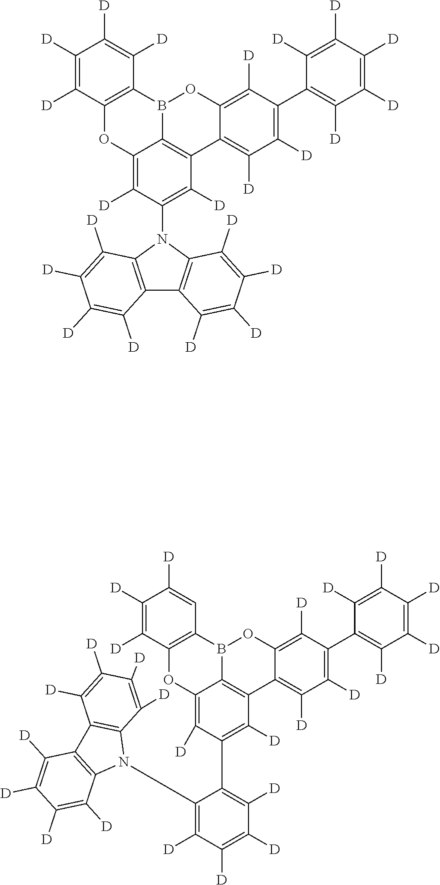 [SMILES: [2H]c1c([2H])c([2H])c(-c2c([2H])c([2H])c3c(c2[2H])OB2c4c([2H])c([2H])c([2H])c([2H])c4Oc4c([2H])c(-n5c6c([2H])c([2H])c([2H])c([2H])c6c6c([2H])c([2H])c([2H])c([2H])c65)c([2H])c-3c42)c([2H])c1[2H] ; [2H]c1cc2c(c([2H])c1[2H])Oc1c([2H])c(-c3c([2H])c([2H])c([2H])c([2H])c3-n3c4c([2H])c([2H])c([2H])c([2H])c4c4c([2H])c([2H])c([2H])c([2H])c43)c([2H])c3c1B2Oc1c([2H])c(-c2c([2H])c([2H])c([2H])c([2H])c2[2H])c([2H])c([2H])c1-3] 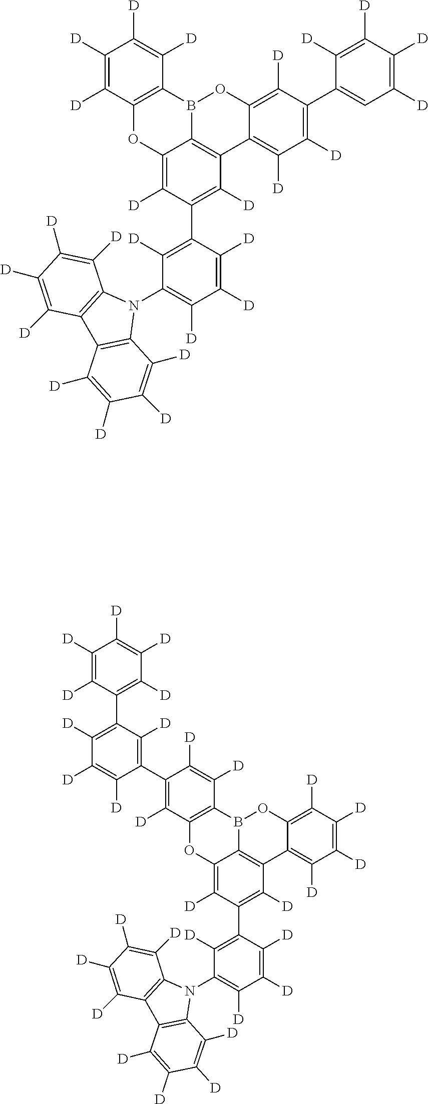 [SMILES: [2H]c1cc(-c2c([2H])c([2H])c3c(c2[2H])OB2c4c([2H])c([2H])c([2H])c([2H])c4Oc4c([2H])c(-c5c([2H])c([2H])c([2H])c(-n6c7c([2H])c([2H])c([2H])c([2H])c7c7c([2H])c([2H])c([2H])c([2H])c76)c5[2H])c([2H])c-3c42)c([2H])c([2H])c1[2H] ; [2H]c1c([2H])c([2H])c(-c2c([2H])c([2H])c([2H])c(-c3c([2H])c([2H])c4c(c3[2H])Oc3c([2H])c(-c5c([2H])c([2H])c([2H])c(-n6c7c([2H])c([2H])c([2H])c([2H])c7c7c([2H])c([2H])c([2H])c([2H])c76)c5[2H])c([2H])c5c3B4Oc3c([2H])c([2H])c([2H])c([2H])c3-5)c2[2H])c([2H])c1[2H]] 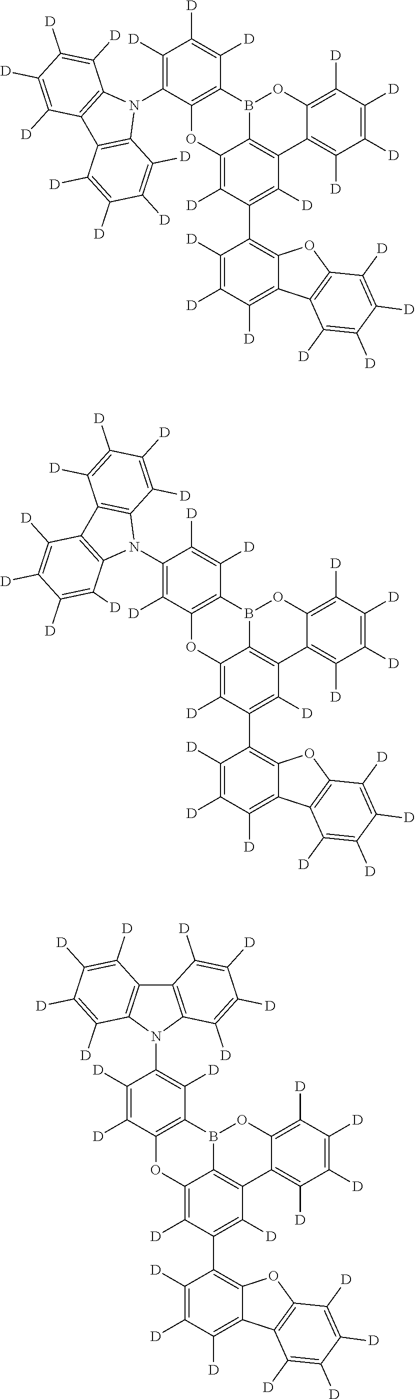 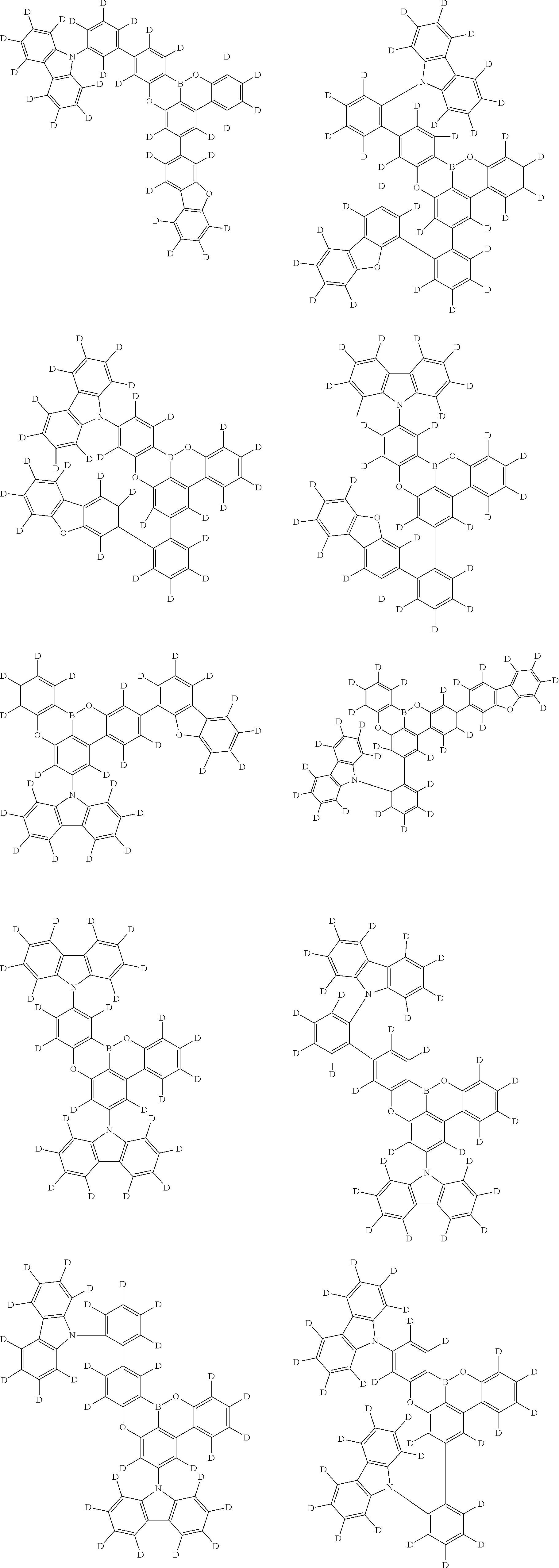 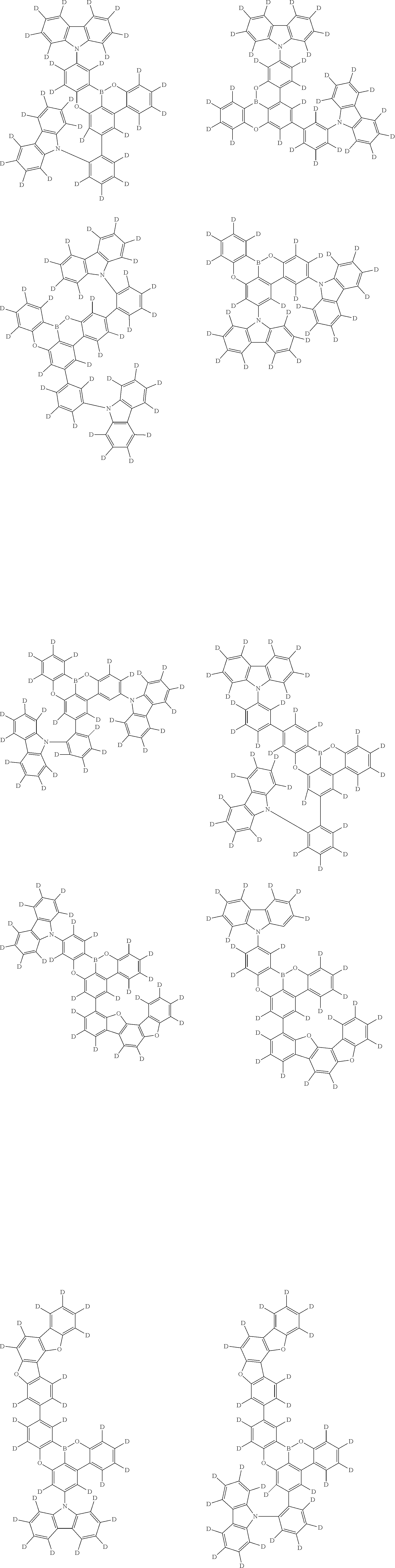 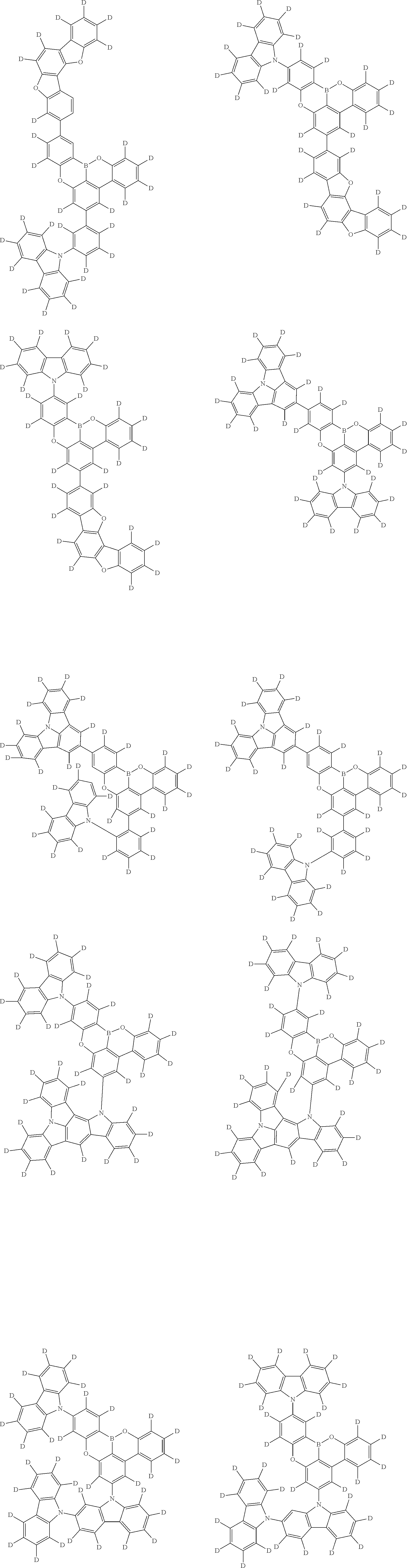 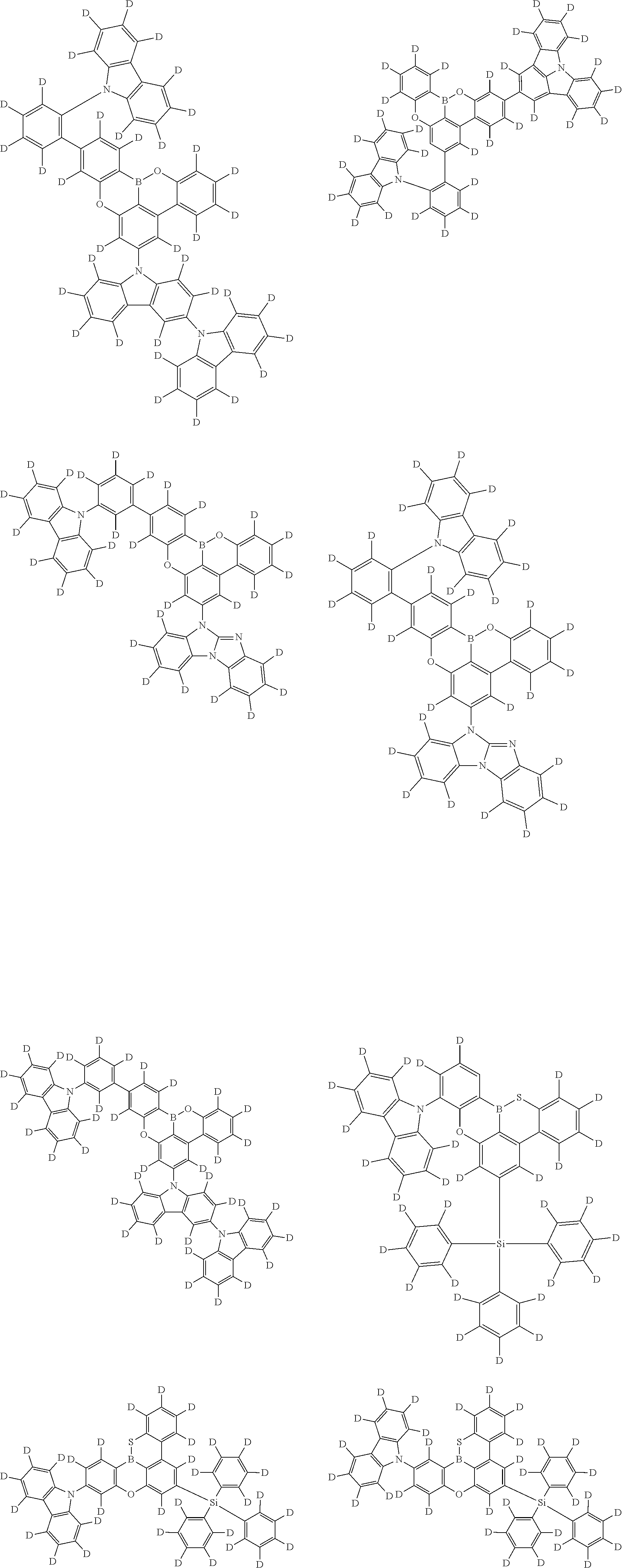 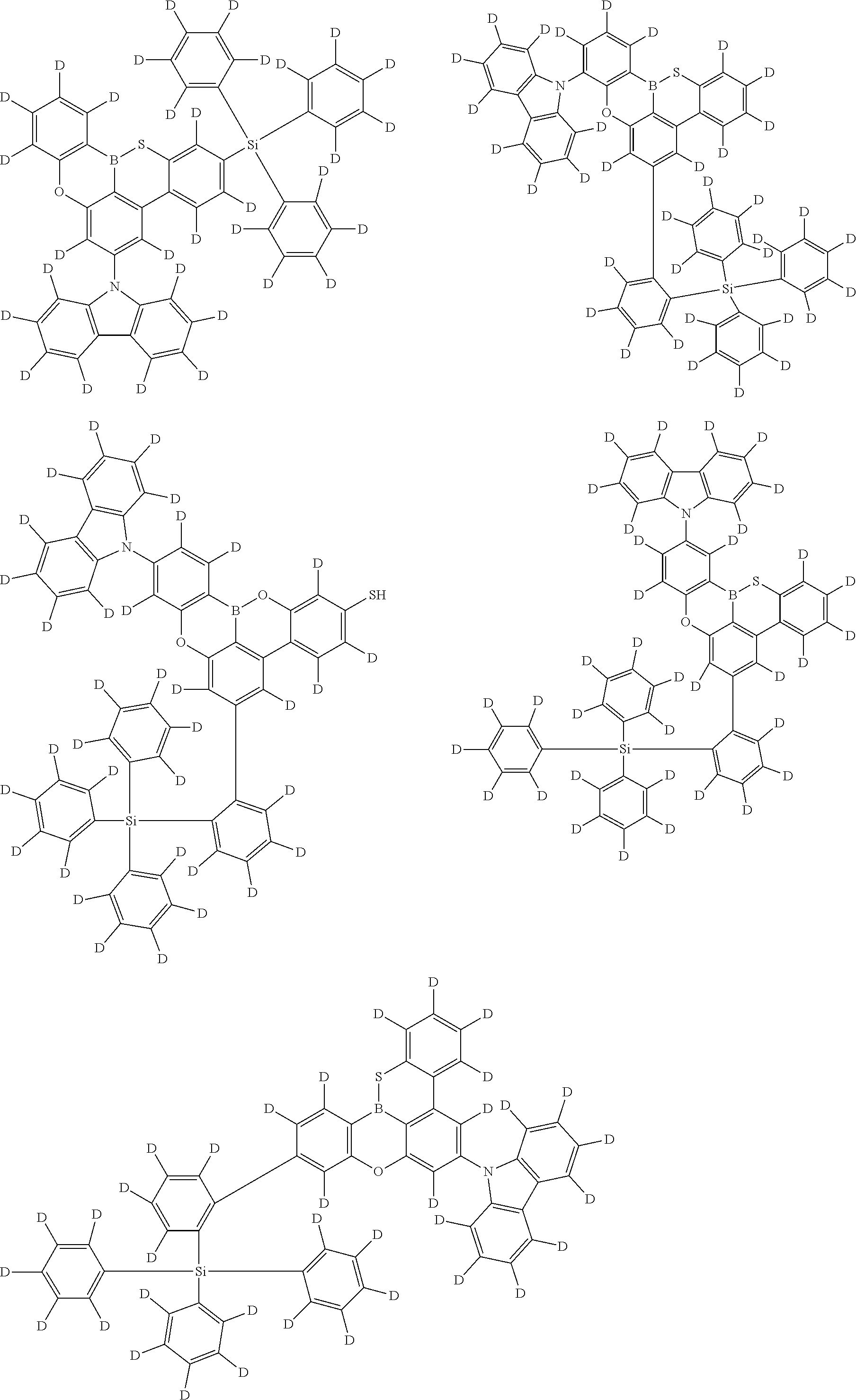 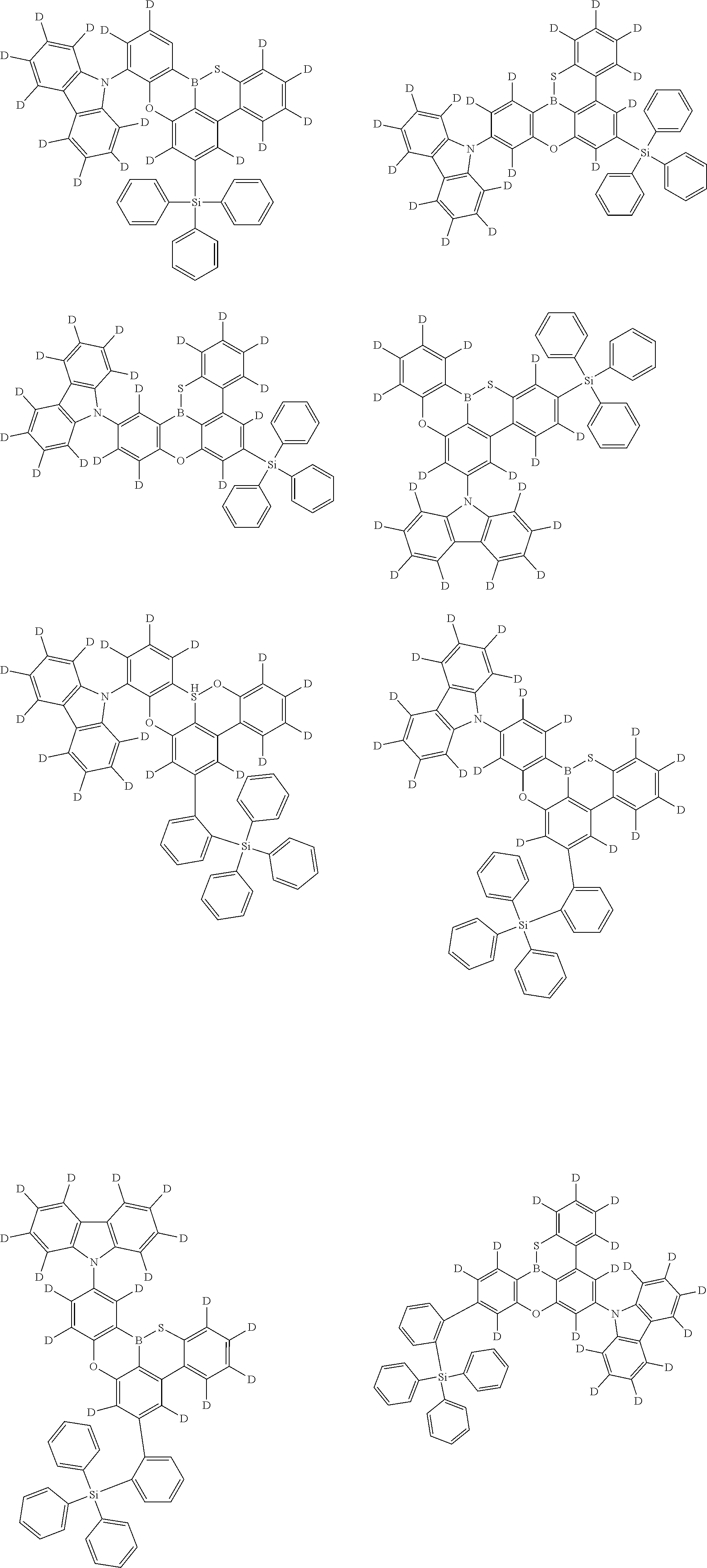 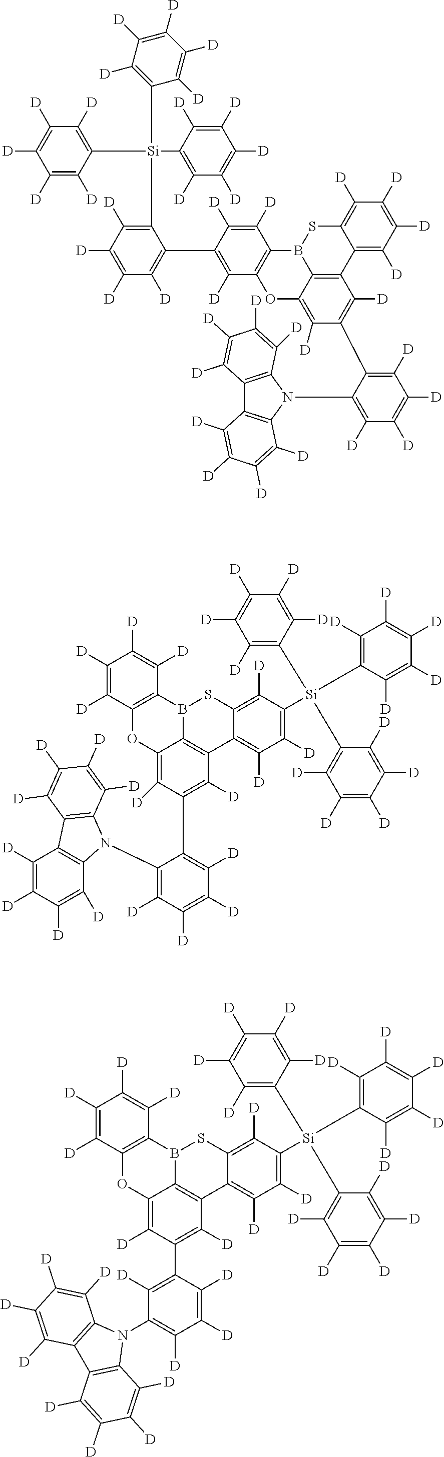 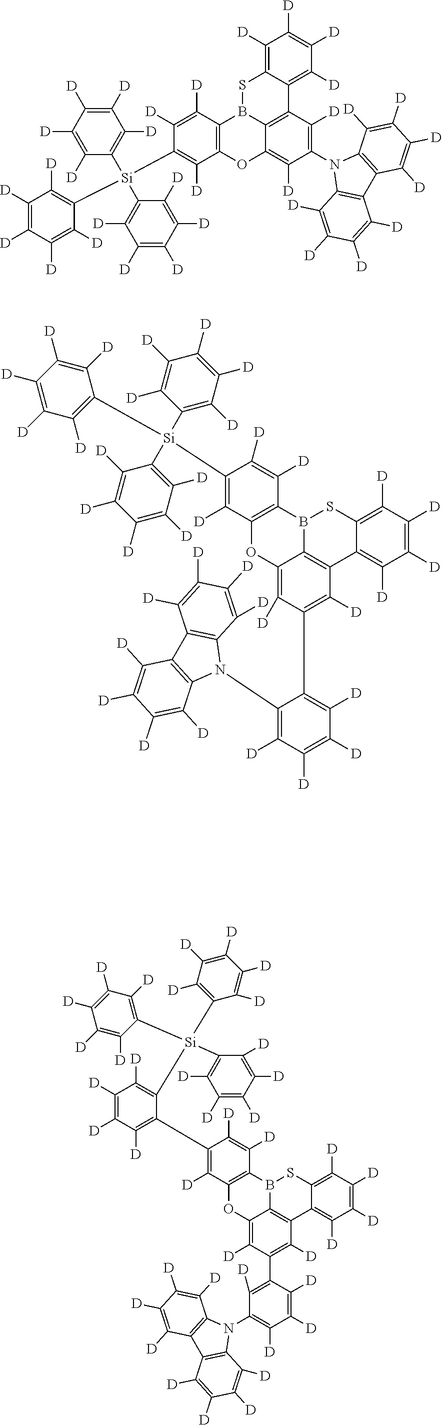 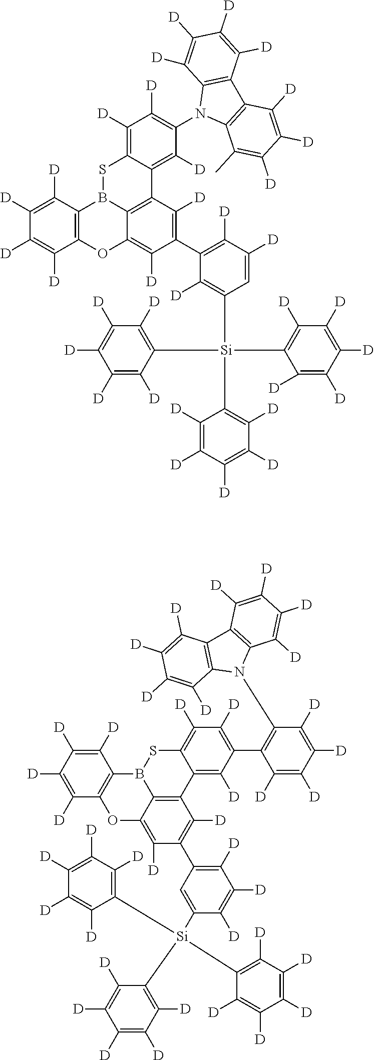 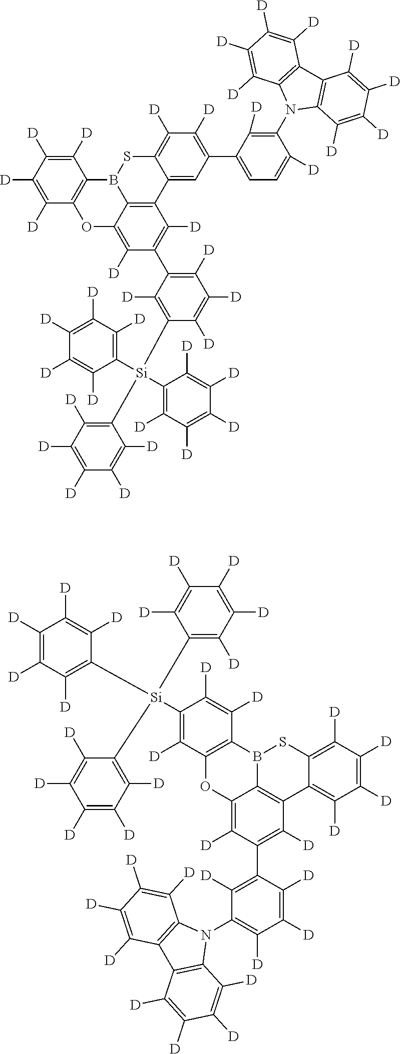 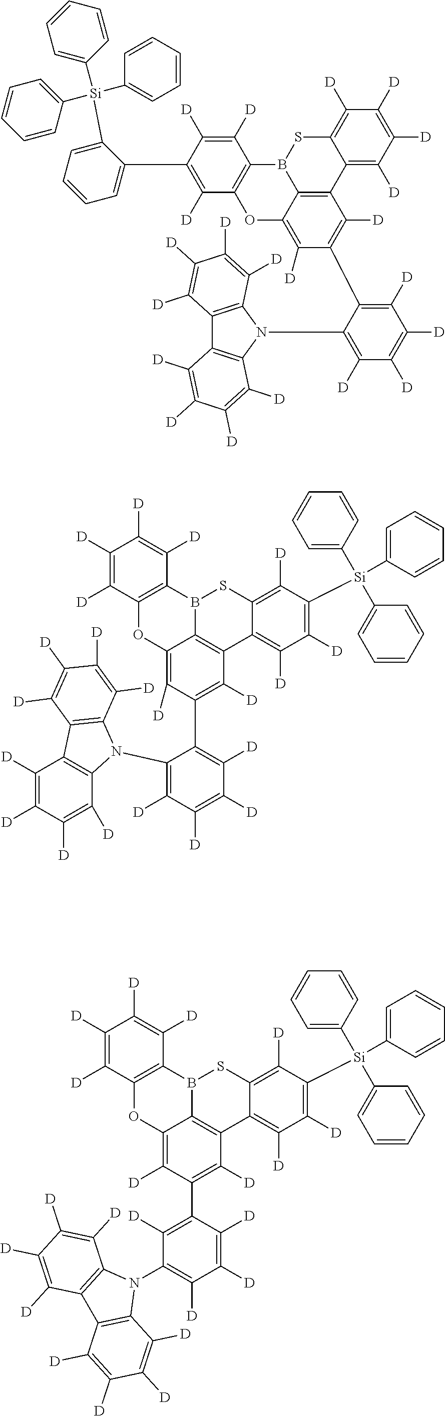 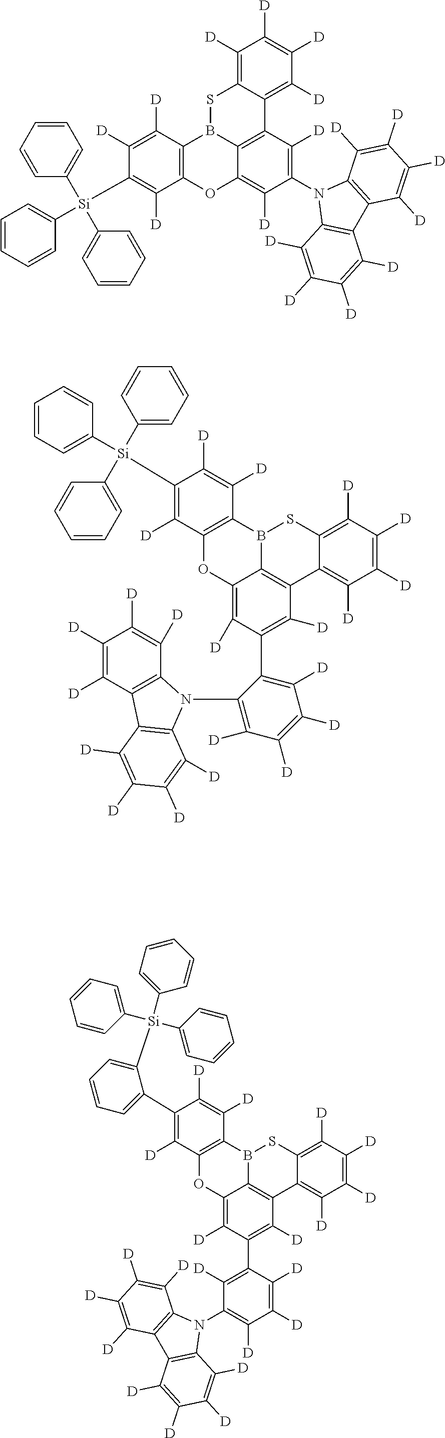 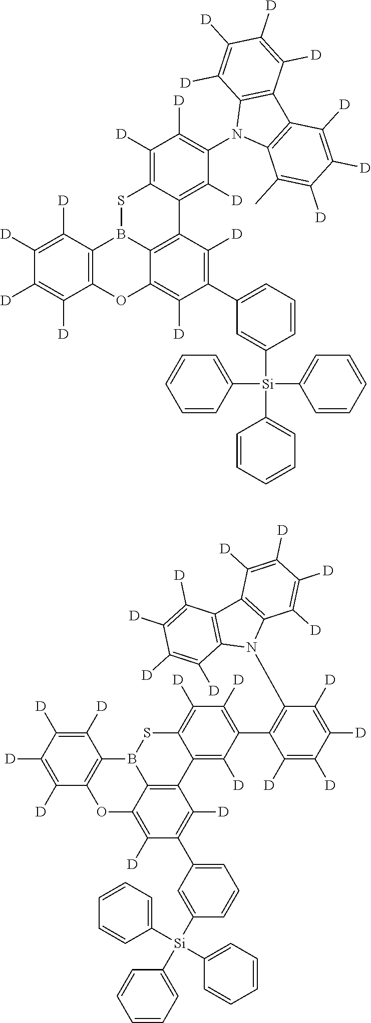 [SMILES: [2H]c1c([2H])c([2H])c2c(c1[2H])Oc1c([2H])c(-c3cccc([Si](c4ccccc4)(c4ccccc4)c4ccccc4)c3)c([2H])c3c1B2Sc1c([2H])c([2H])c(-n2c4c([2H])c([2H])c([2H])c([2H])c4c4c([2H])c([2H])c([2H])c(C)c42)c([2H])c1-3 ; [2H]c1c([2H])c([2H])c2c(c1[2H])Oc1c([2H])c(-c3cccc([Si](c4ccccc4)(c4ccccc4)c4ccccc4)c3)c([2H])c3c1B2Sc1c([2H])c([2H])c(-c2c([2H])c([2H])c([2H])c([2H])c2-n2c4c([2H])c([2H])c([2H])c([2H])c4c4c([2H])c([2H])c([2H])c([2H])c42)c([2H])c1-3] 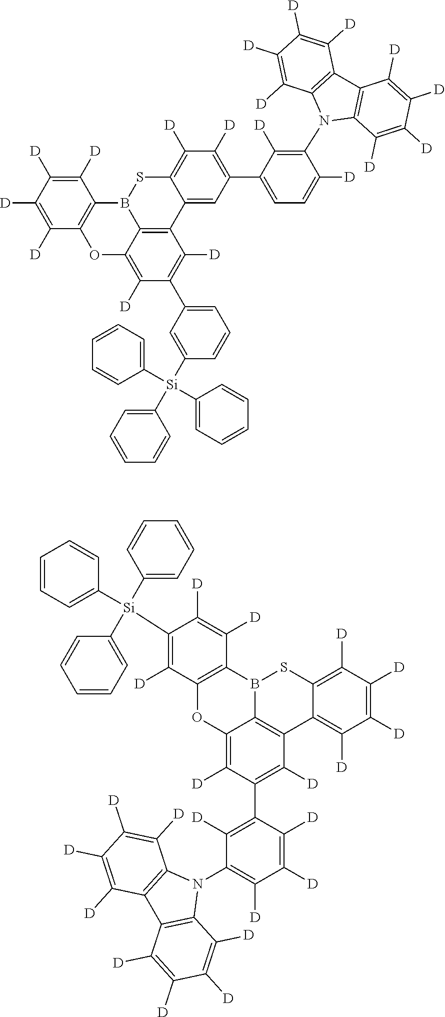 [SMILES: [2H]c1ccc(-c2cc3c(c([2H])c2[2H])SB2c4c([2H])c([2H])c([2H])c([2H])c4Oc4c([2H])c(-c5cccc([Si](c6ccccc6)(c6ccccc6)c6ccccc6)c5)c([2H])c-3c42)c([2H])c1-n1c2c([2H])c([2H])c([2H])c([2H])c2c2c([2H])c([2H])c([2H])c([2H])c21 ; [2H]c1c([2H])c([2H])c2c(c1[2H])SB1c3c([2H])c([2H])c([Si](c4ccccc4)(c4ccccc4)c4ccccc4)c([2H])c3Oc3c([2H])c(-c4c([2H])c([2H])c([2H])c(-n5c6c([2H])c([2H])c([2H])c([2H])c6c6c([2H])c([2H])c([2H])c([2H])c65)c4[2H])c([2H])c-2c31] 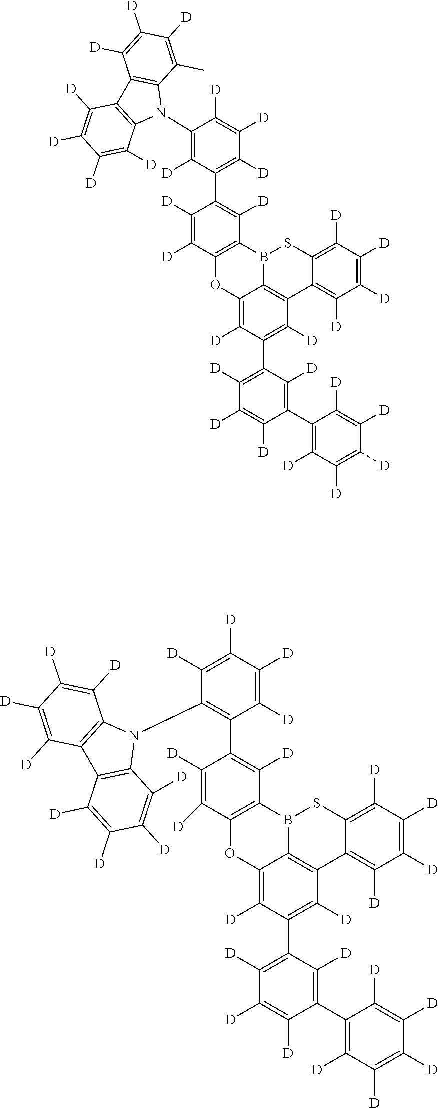 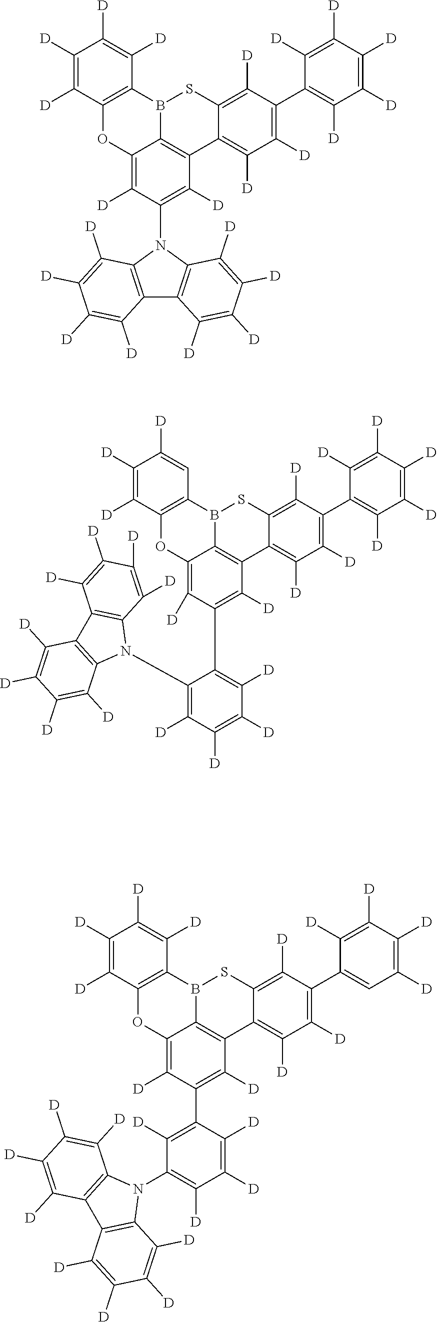 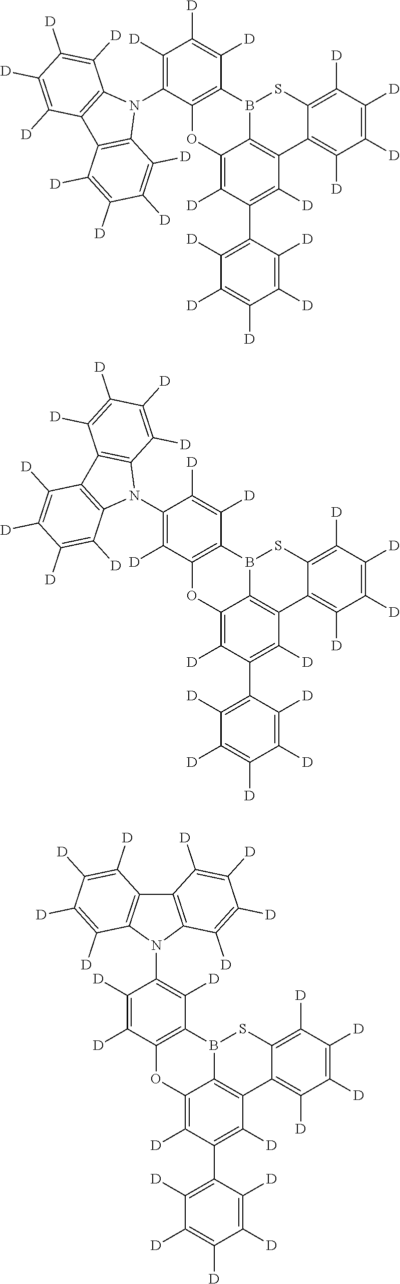 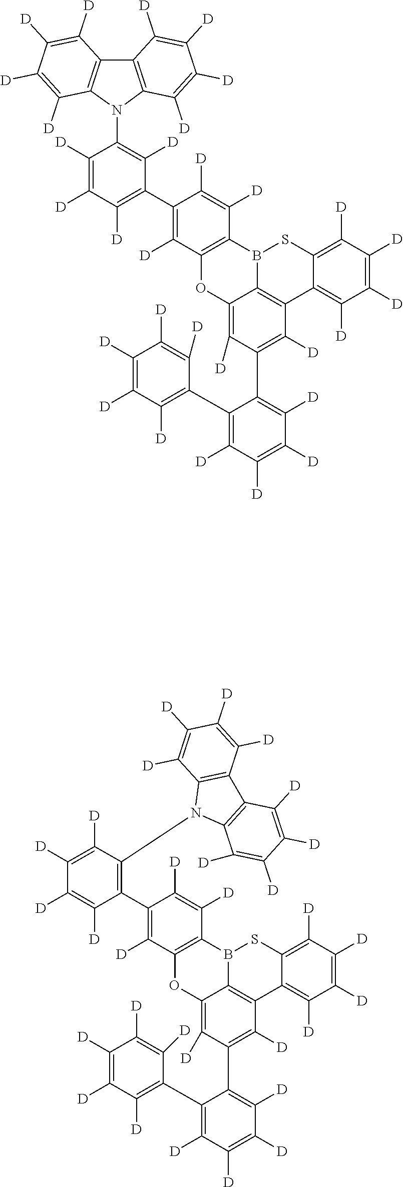 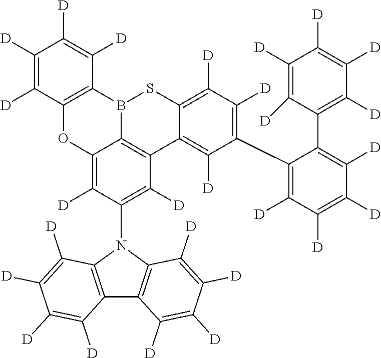 [SMILES: [2H]c1c([2H])c([2H])c(-c2c([2H])c([2H])c([2H])c([2H])c2-c2c([2H])c([2H])c3c(c2[2H])-c2c([2H])c(-n4c5c([2H])c([2H])c([2H])c([2H])c5c5c([2H])c([2H])c([2H])c([2H])c54)c([2H])c4c2B(S3)c2c([2H])c([2H])c([2H])c([2H])c2O4)c([2H])c1[2H]] 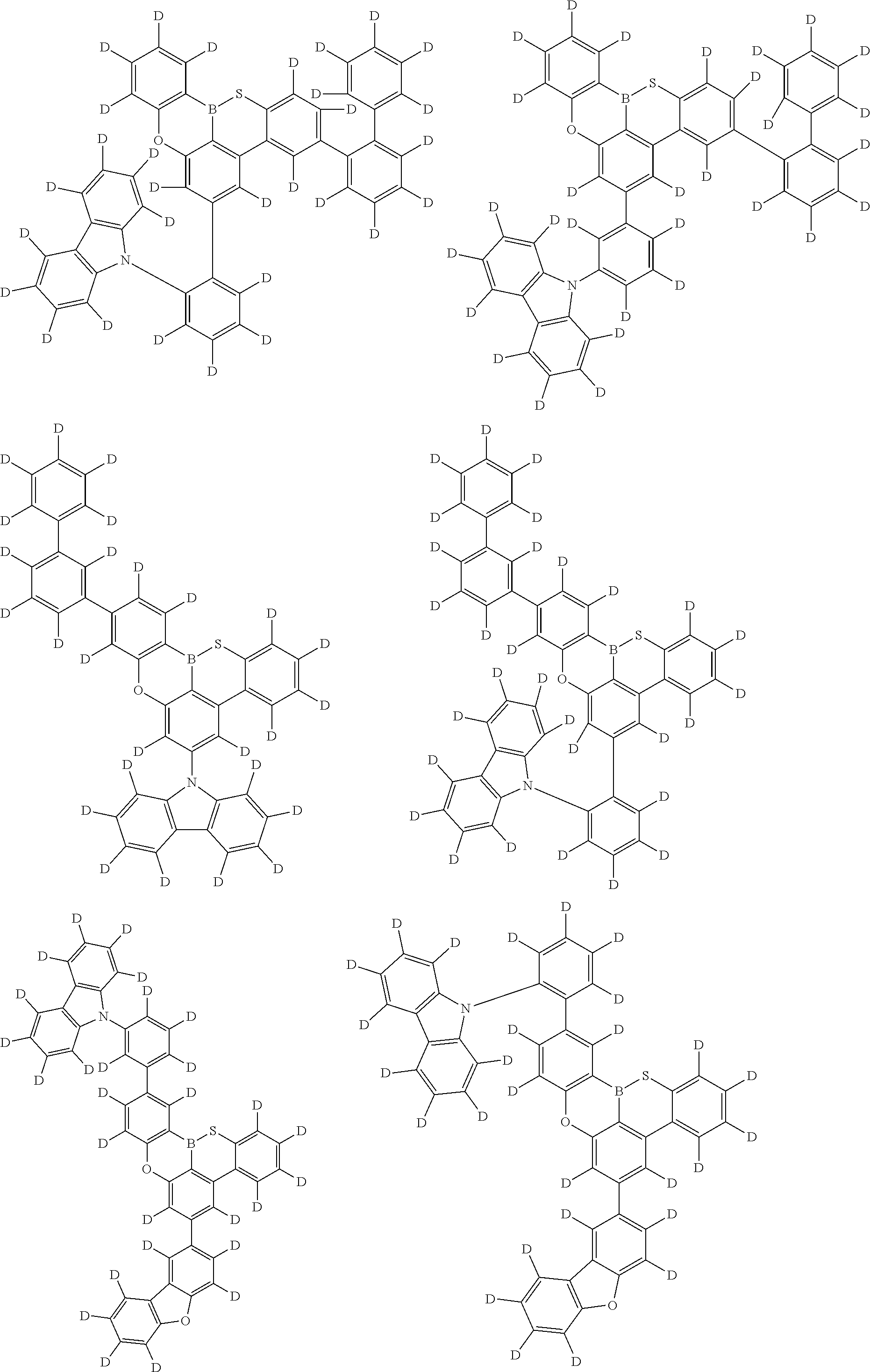 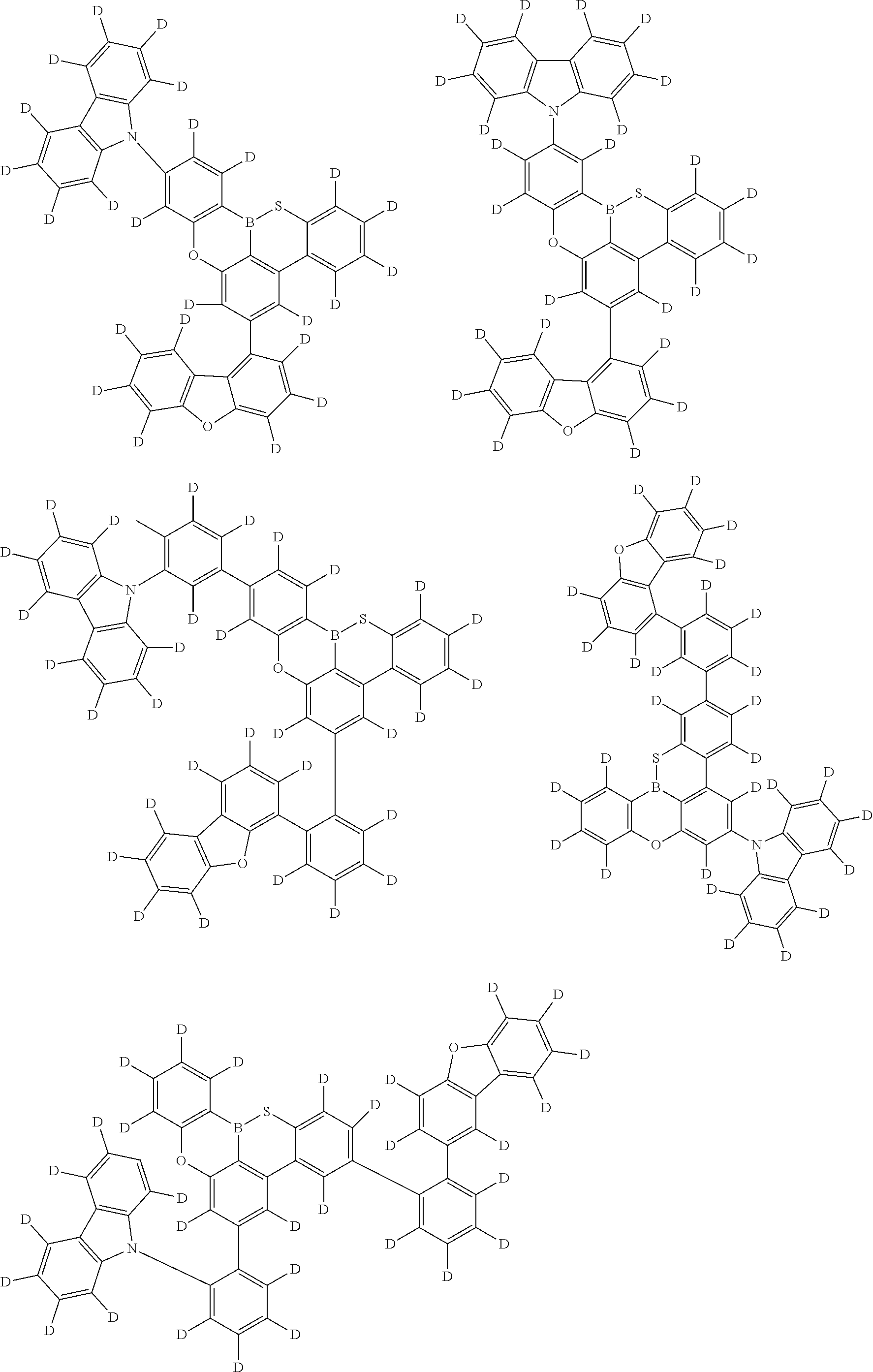 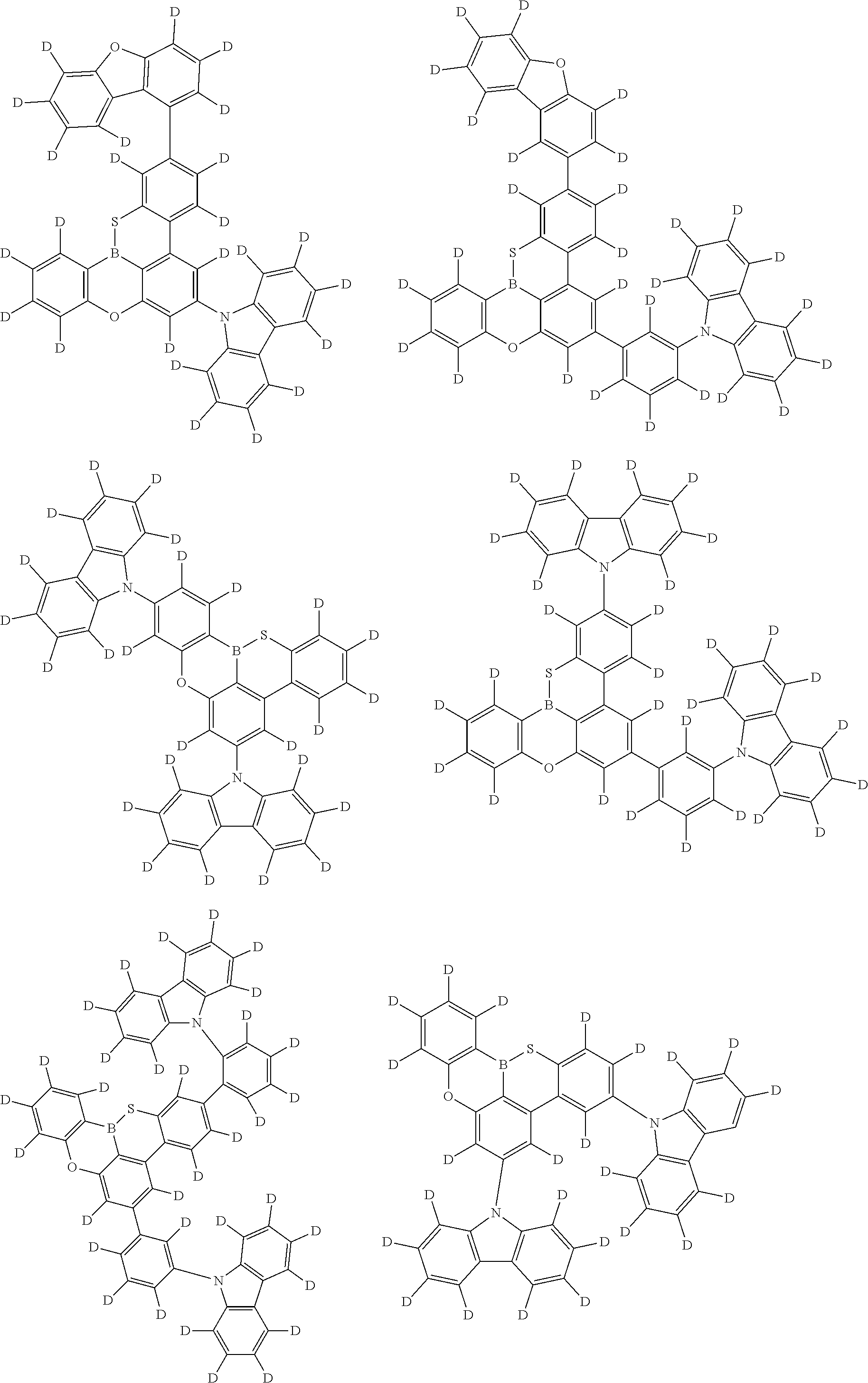 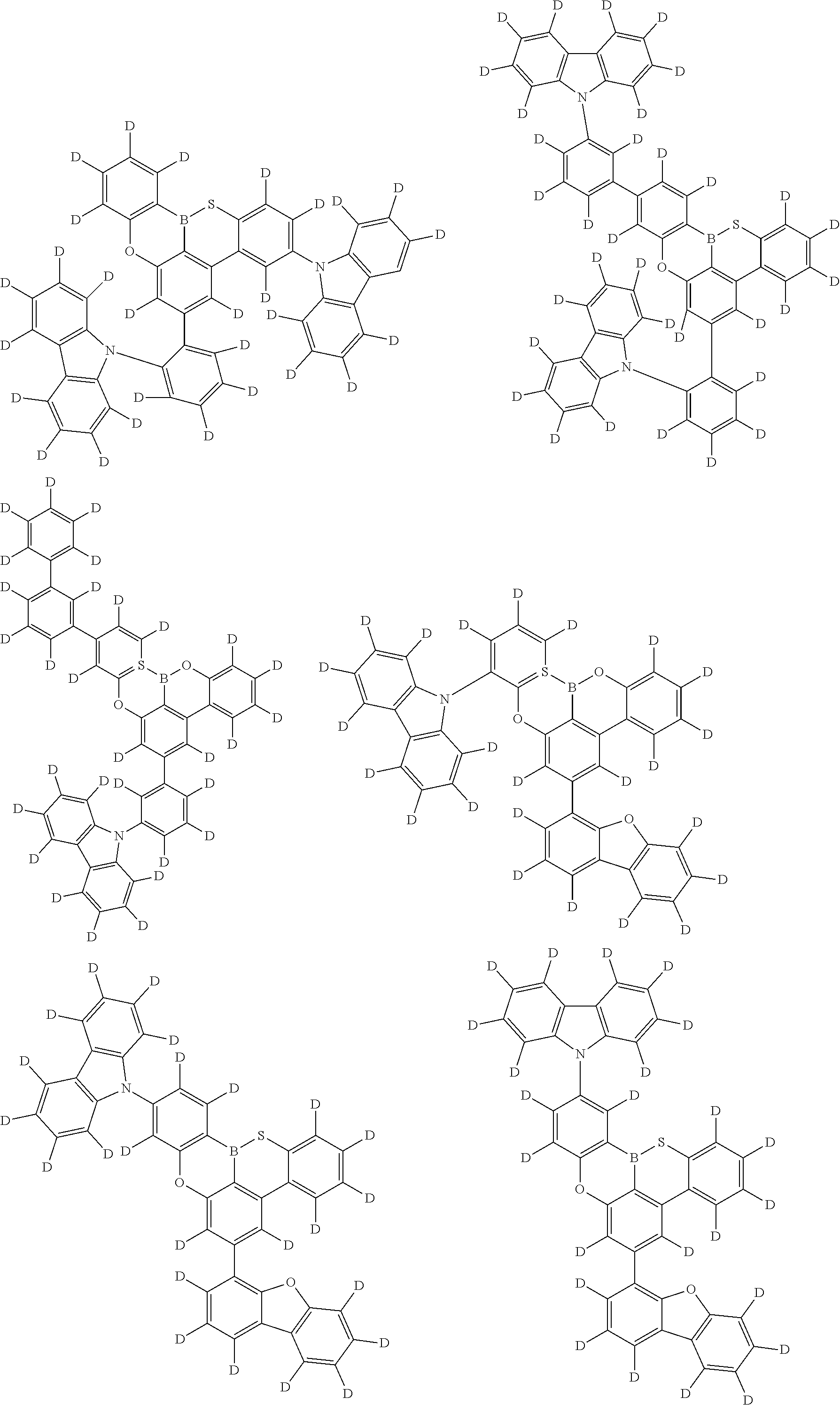 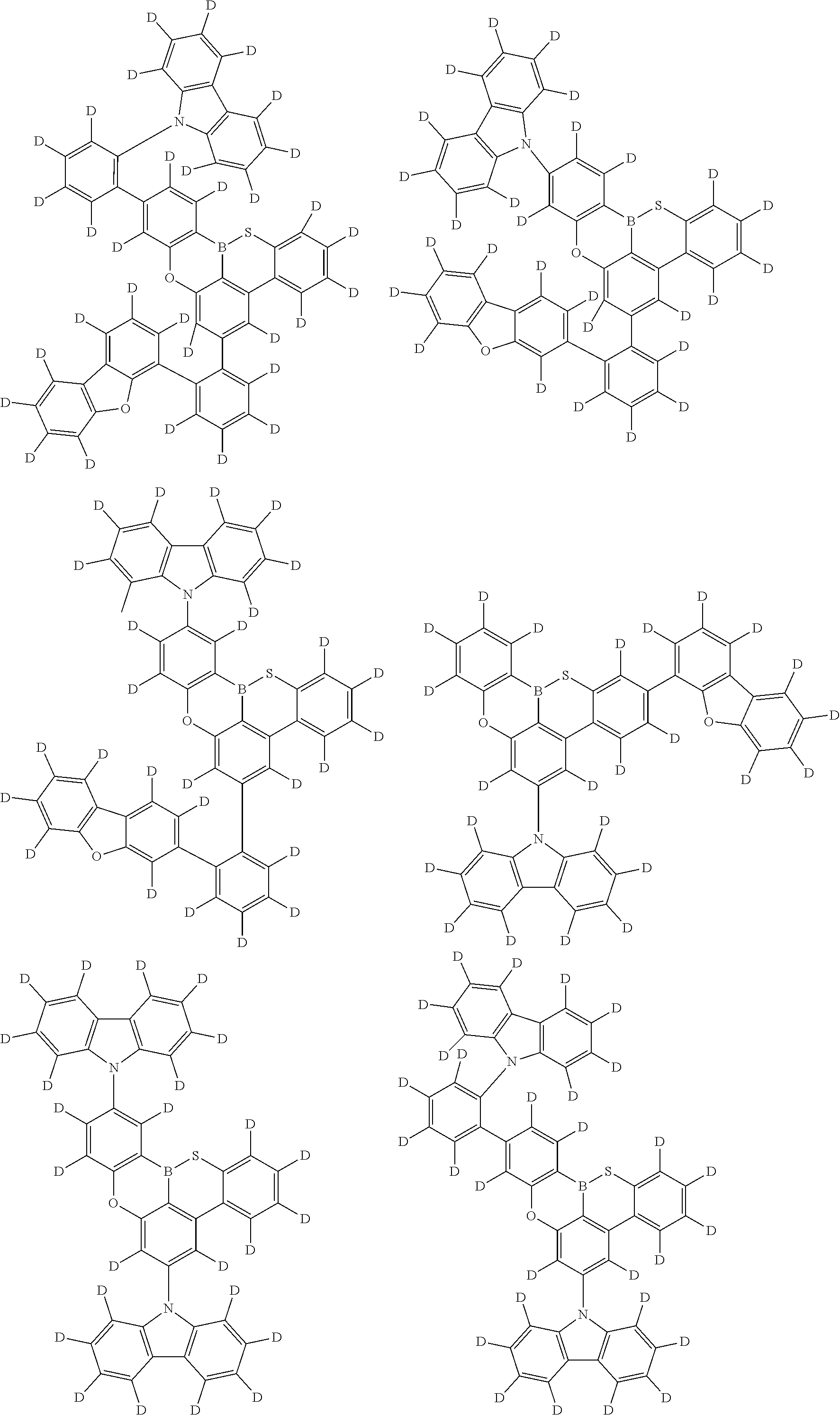 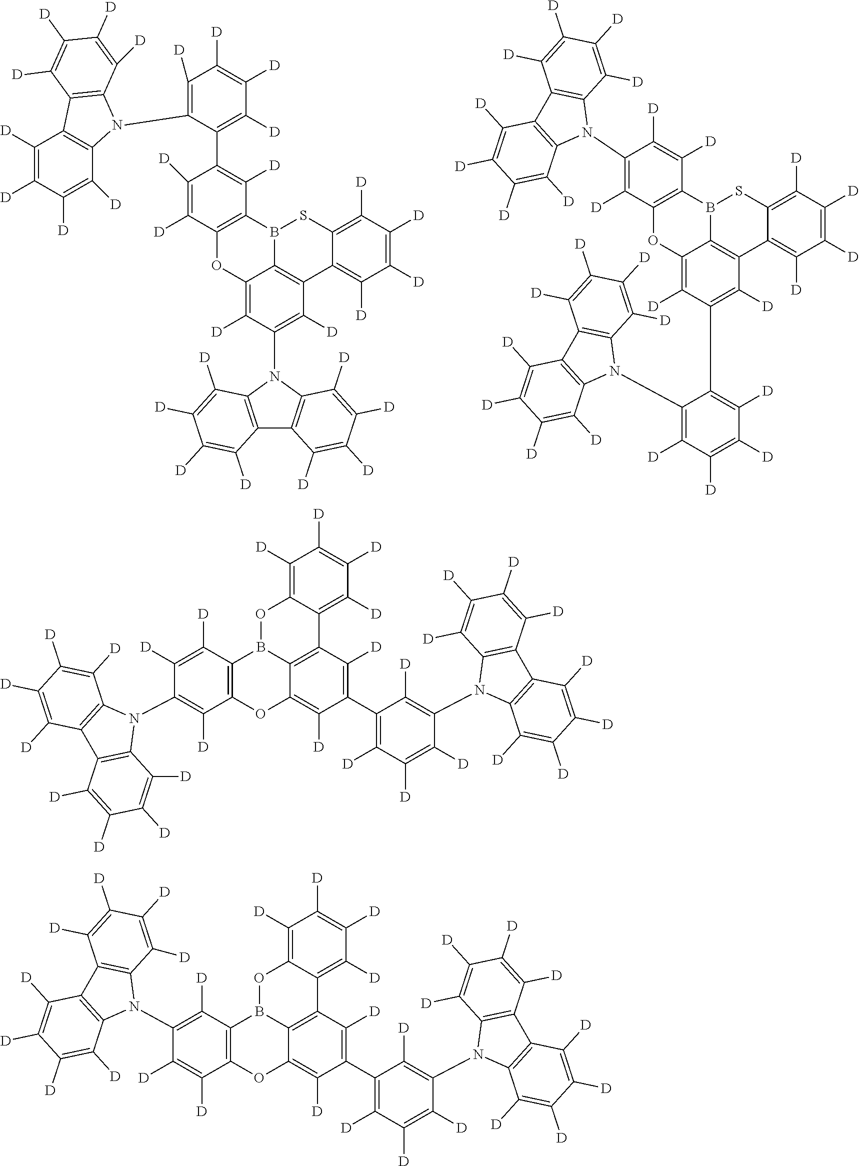 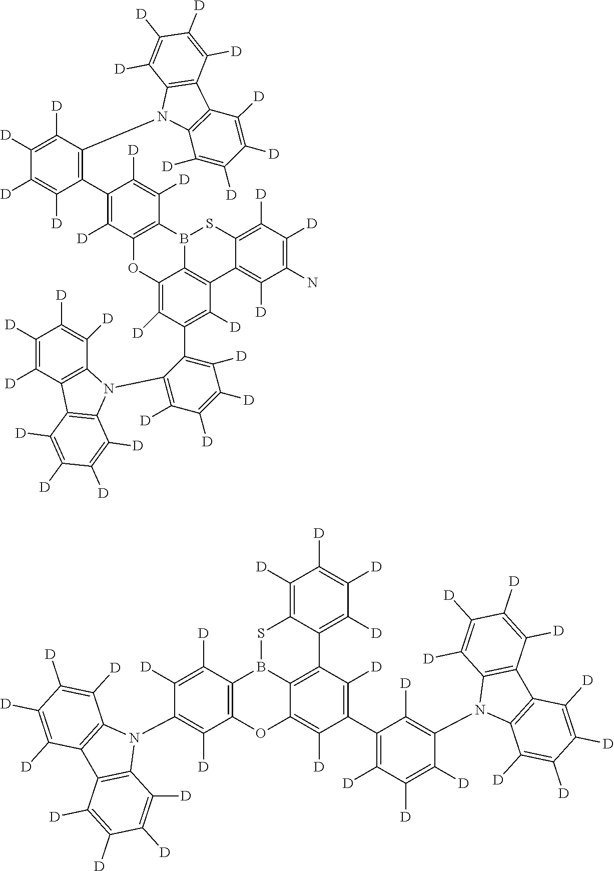 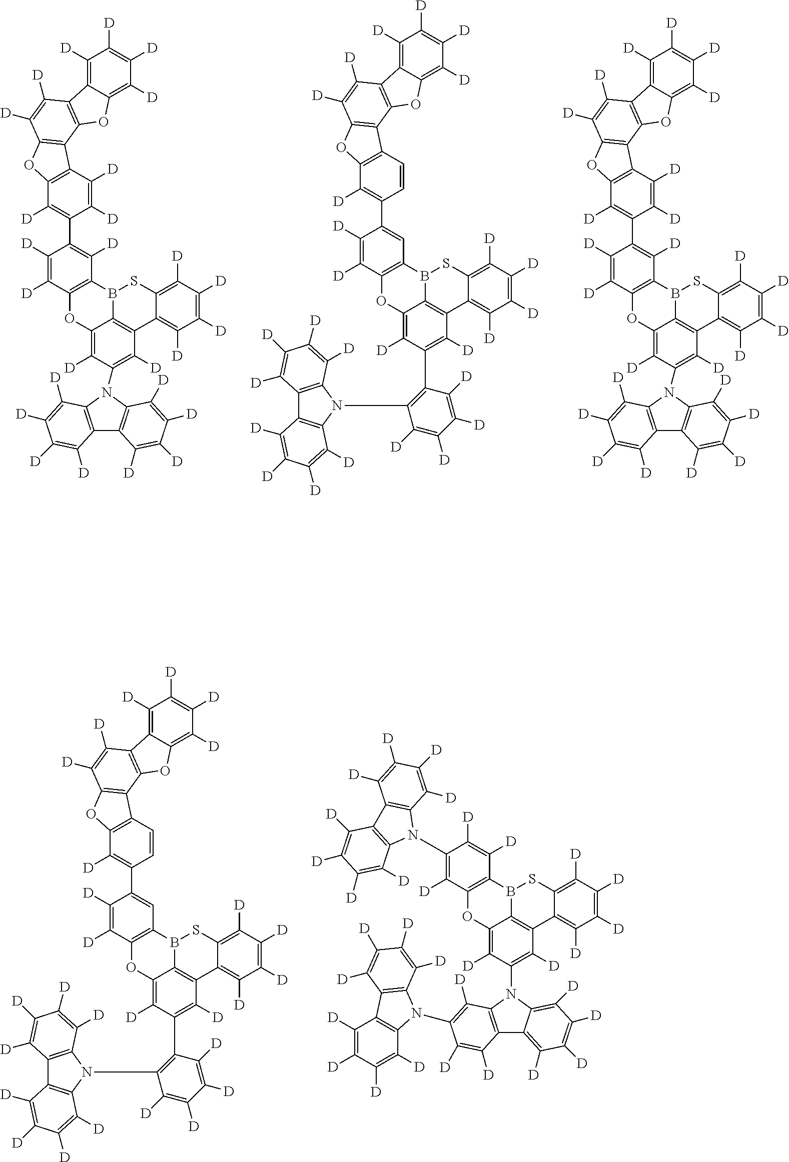 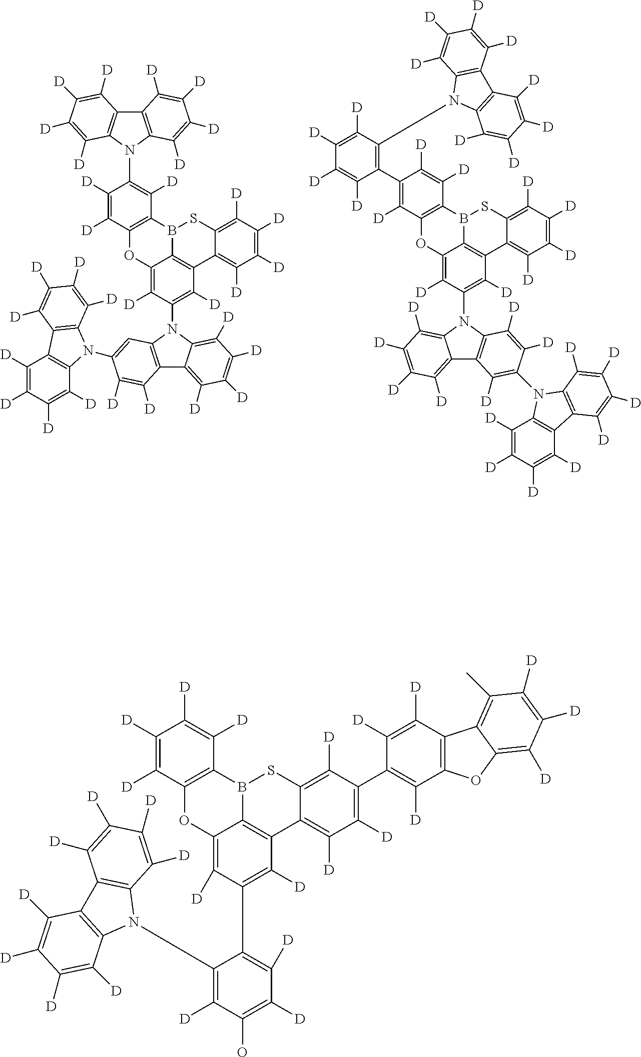 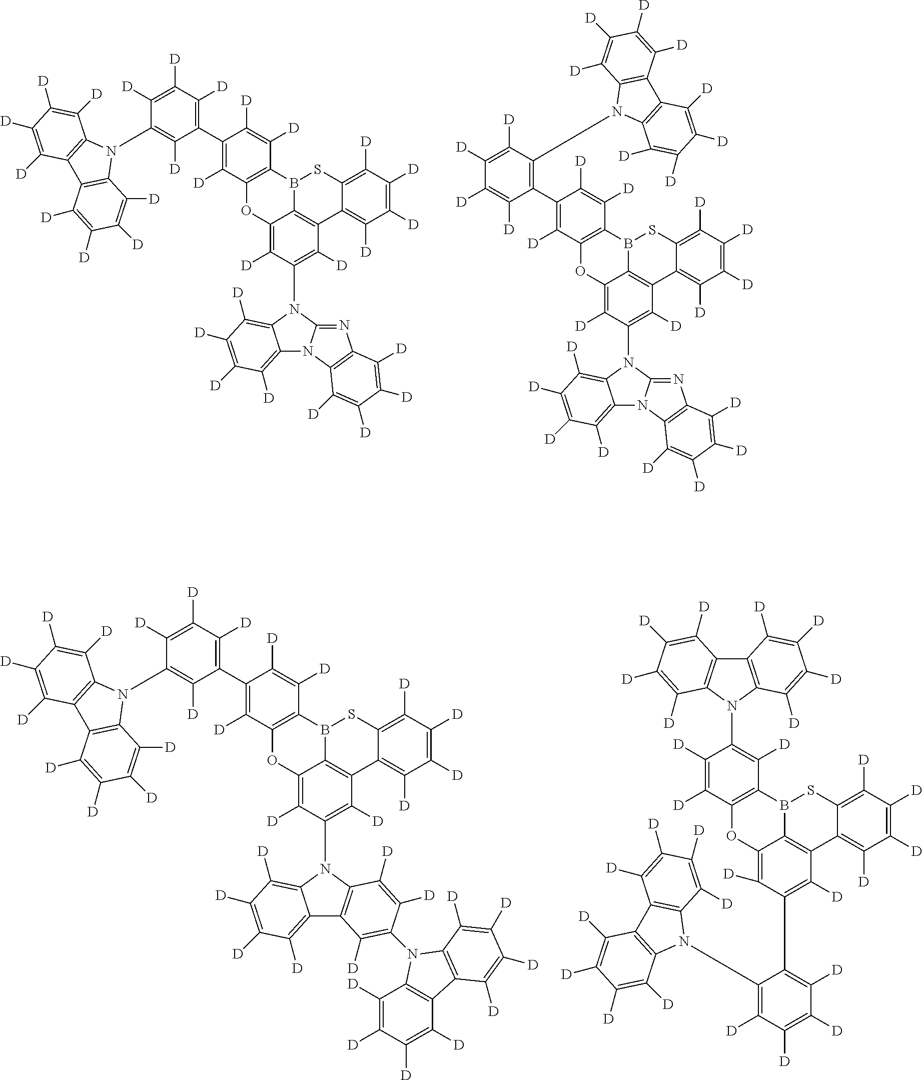 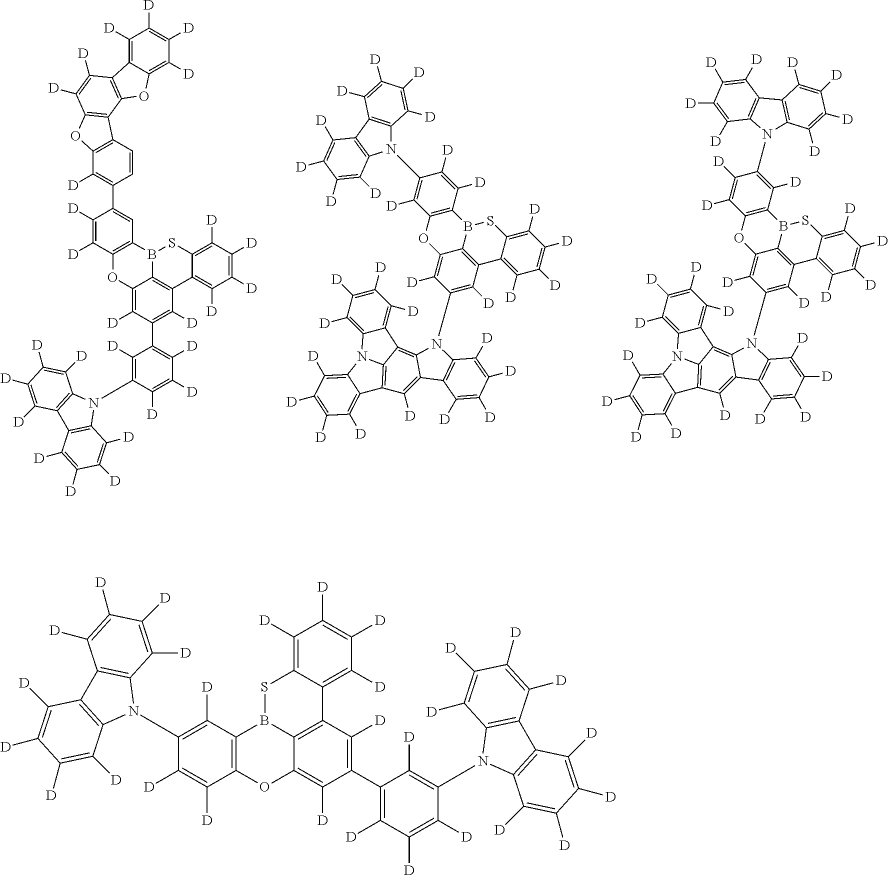 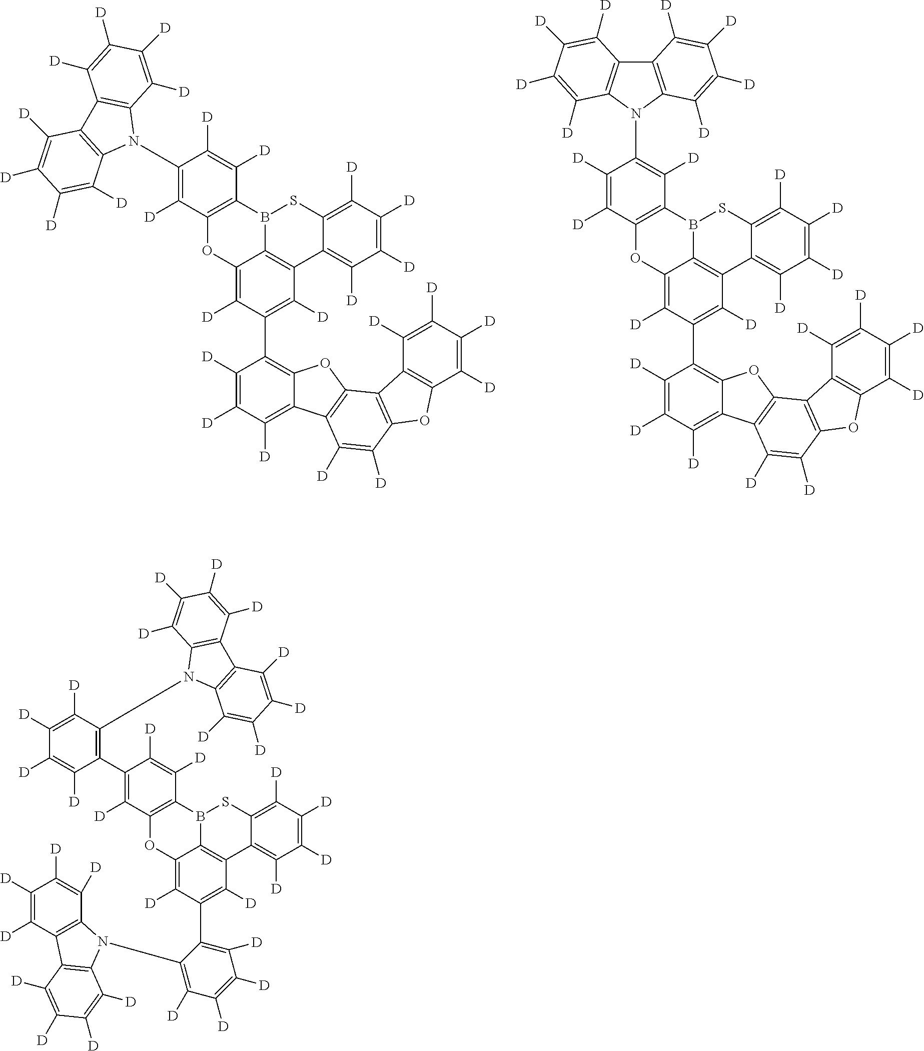 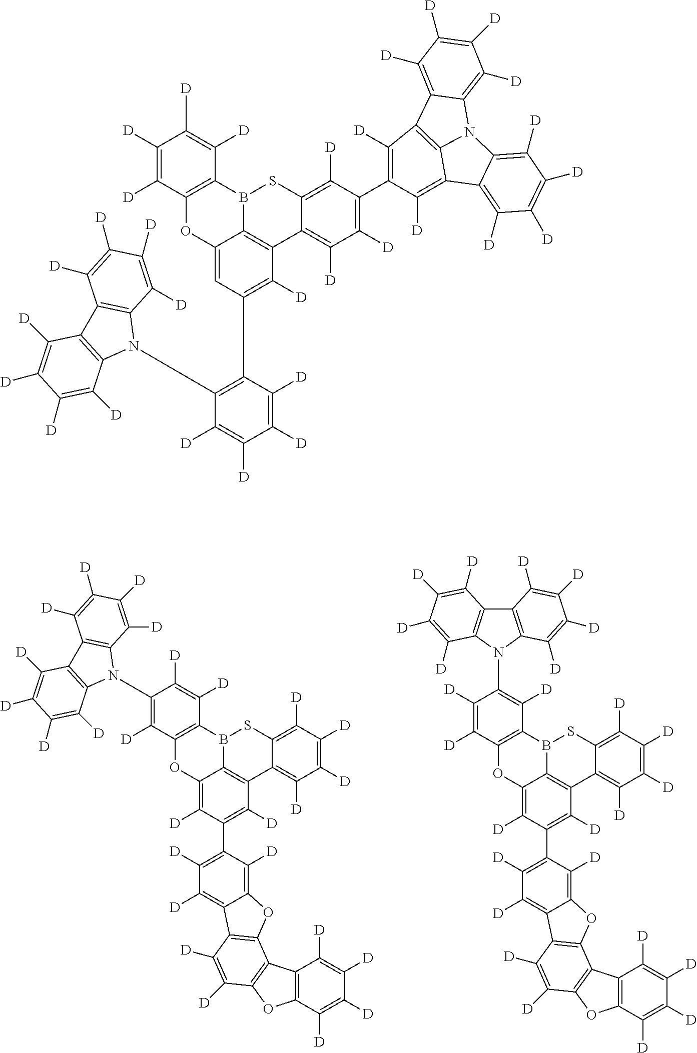 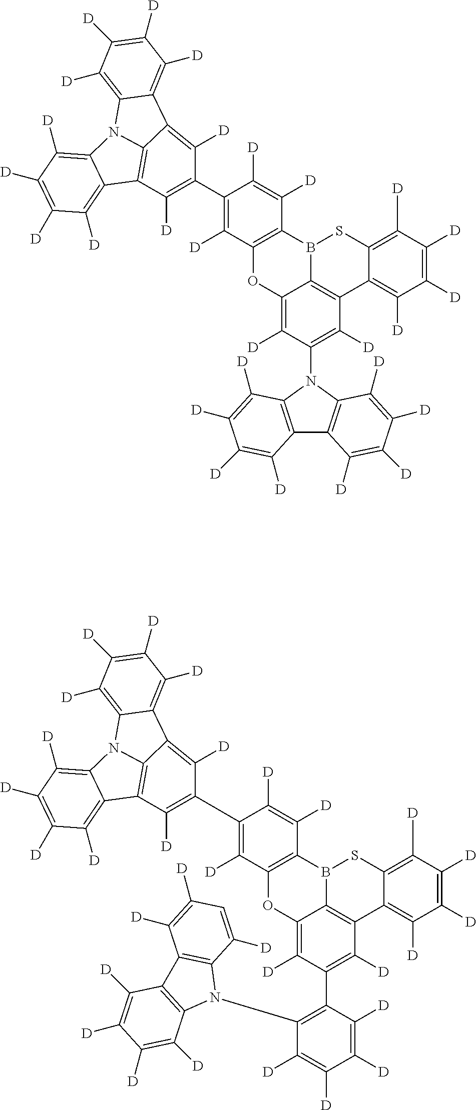 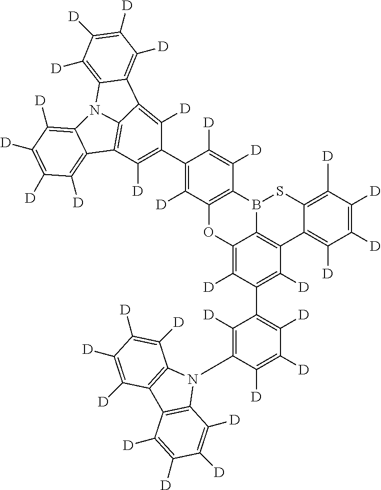 [SMILES: [2H]c1c([2H])c([2H])c2c(c1[2H])SB1c3c([2H])c([2H])c(-c4c([2H])c5c6c([2H])c([2H])c([2H])c([2H])c6n6c7c([2H])c([2H])c([2H])c([2H])c7c(c4[2H])c56)c([2H])c3Oc3c([2H])c(-c4c([2H])c([2H])c([2H])c(-n5c6c([2H])c([2H])c([2H])c([2H])c6c6c([2H])c([2H])c([2H])c([2H])c65)c4[2H])c([2H])c-2c31]
wherein [ ]_{D=x1 to x2} means that a structure in the parenthesis comprises x1 or x2 deuteriums, and the value thereof is an integer.

12. The organic light emitting device of claim 1, wherein Chemical Formula 2 is represented by any one of the following compounds:

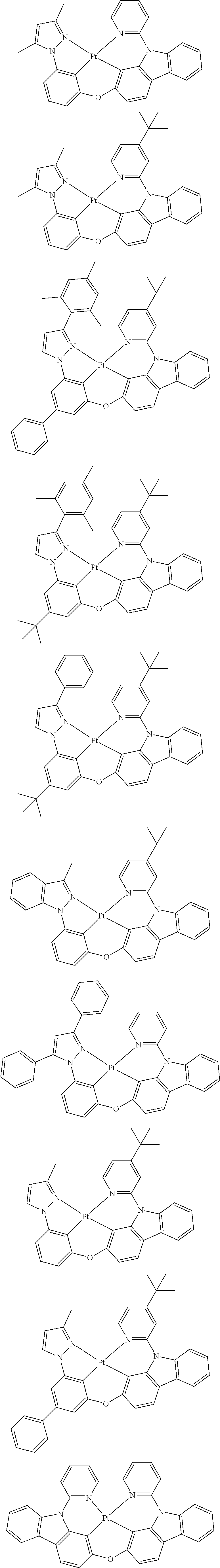

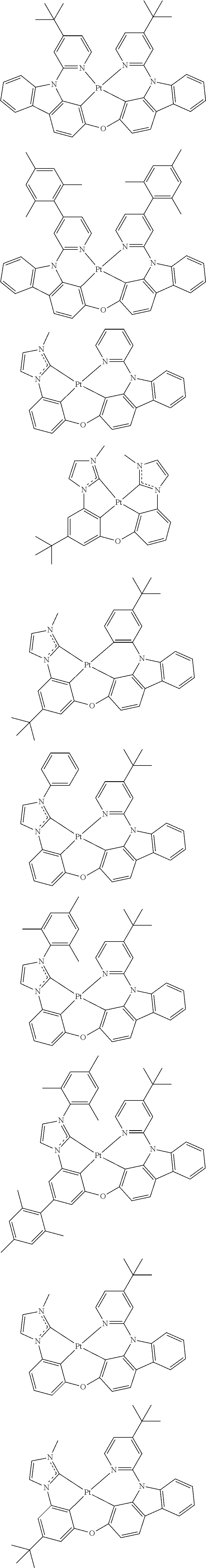

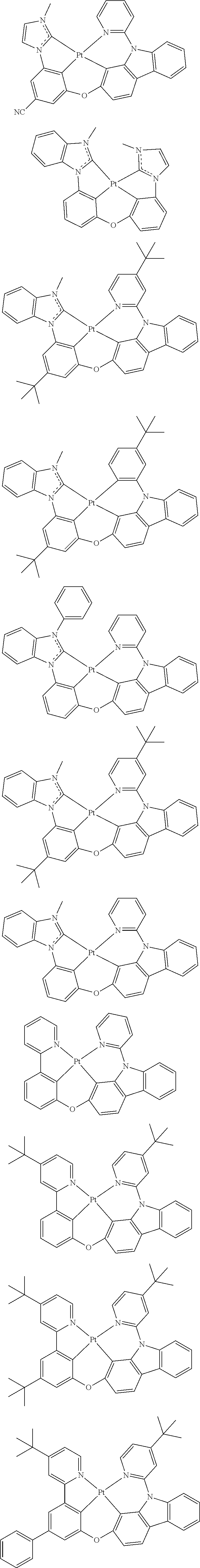

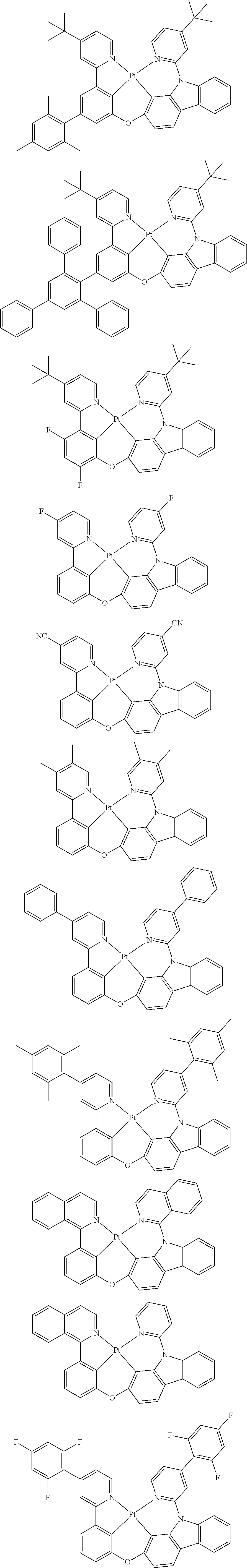

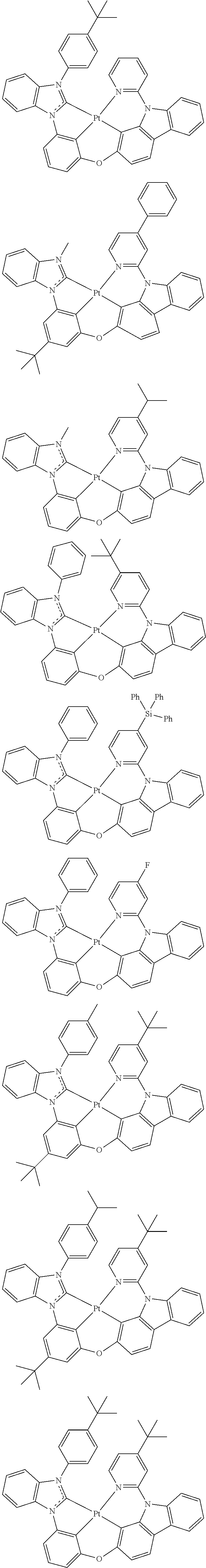

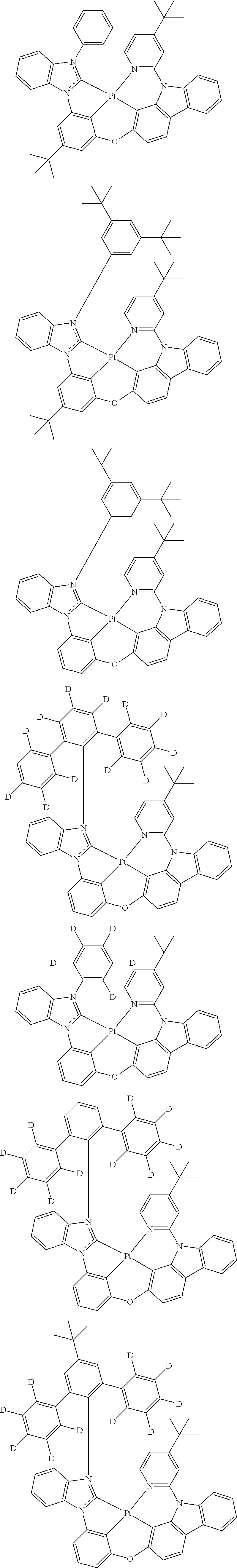

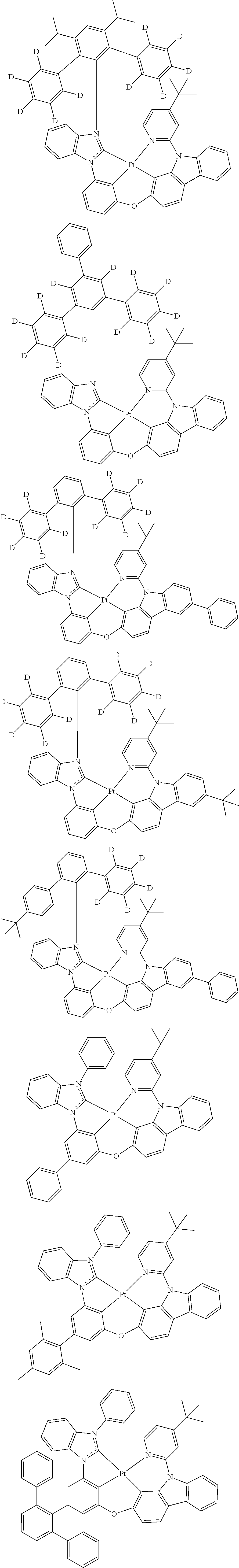

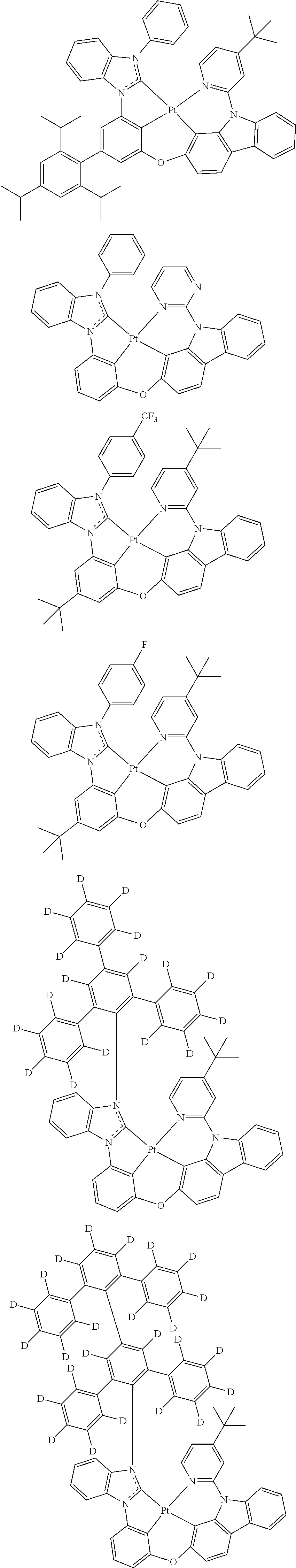

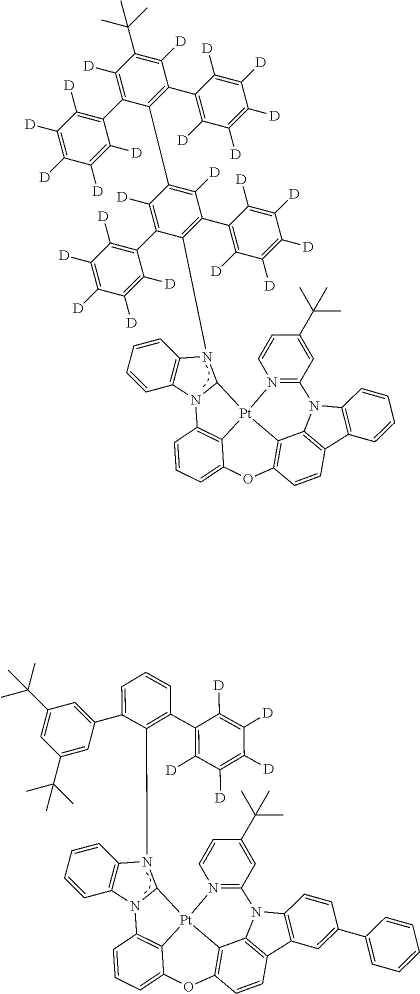

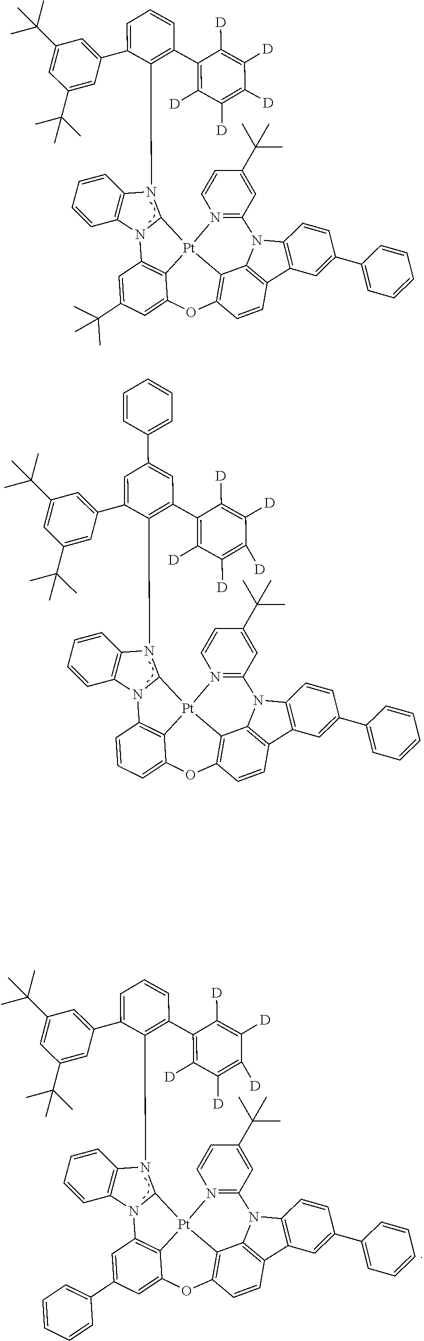

13. The organic light emitting device of claim 1, wherein the organic material layer comprises a light emitting layer, and the light emitting layer comprises the compound represented by Chemical Formula 1 and the compound represented by Chemical Formula 2.

14. The organic light emitting device of claim 13, wherein the light emitting layer comprises the compound represented by Chemical Formula 1 as a host and the compound represented by Chemical Formula 2 as a dopant.

15. The organic light emitting device of claim 13, wherein the organic material layer further comprises one or more layers of a hole transport layer, a hole injection layer, an electron blocking layer, a hole injection and transport layer, an electron transport layer, an electron injection layer, a hole blocking layer, and an electron transport and injection layer.
